(19) United States
(12) Patent Application Publication
(10) Pub. No.: US 2024/0147843 A1
(43) Pub. Date: May 2, 2024

(54) ORGANIC ELECTROLUMINESCENT ELEMENT, ORGANIC ELECTROLUMINESCENT DISPLAY APPARATUS, AND DIGITAL DEVICE

(71) Applicant: IDEMITSU KOSAN CO., LTD., Tokyo (JP)

(72) Inventors: Satomi TASAKI, Tokyo (JP); Kazuki NISHIMURA, Tokyo (JP); Tetsuya MASUDA, Tokyo (JP); Hiroaki TOYOSHIMA, Tokyo (JP); Masato NAKAMURA, Tokyo (JP); Hiroaki ITOI, Tokyo (JP); Emiko KAMBE, Tokyo (JP); Tasuku HAKETA, Tokyo (JP); Yusuke TAKAHASHI, Tokyo (JP); Keitaro YAMADA, Tokyo (JP); Takeshi IKEDA, Tokyo (JP)

(21) Appl. No.: 18/261,247

(22) PCT Filed: Jan. 13, 2022
(86) PCT No.: PCT/JP2022/000809

§ 371 Date: Jul. 12, 2023

Related U.S. Application Data
(63) Continuation-in-part of application No. 17/511,477, filed on Oct. 26, 2021.

(30) Foreign Application Priority Data
Jan. 13, 2021 (JP) 2021-003672
Feb. 17, 2021 (JP) 2021-023381
Apr. 26, 2021 (JP) 2021-074498
Apr. 28, 2021 (JP) 2021-076715
Jun. 9, 2021 (JP) 2021-096578
Jun. 25, 2021 (JP) 2021-106128
Oct. 1, 2021 (JP) 2021-163147

(51) Int. Cl. H10K 85/60

(52) U.S. Cl. CPC H10K 85/633; H10K 85/636; H10K 50/156; H10K 85/615; H10K 85/624; H10K 85/626; H10K 85/6572; H10K 85/6574

(57) ABSTRACT

An organic EL device includes an emitting region provided between a cathode and an anode, a first anode-side-organic layer, a second anode-side-organic layer, and a third anode-side-organic layer, in which the emitting region includes at least a first emitting layer, the first anode-side-organic layer is in direct contact with the second anode-side-organic layer, the second anode-side-organic layer is in direct contact with the third anode-side-organic layer, the third anode-side-organic layer has a film thickness of 20 nm or more, the second anode-side-organic layer contains at least one compound different from a compound contained in the third anode-side-organic layer, the first emitting layer is a fluorescent emitting layer, and a refractive index NM₂ of a constituent material contained in the second anode-side-organic layer and a refractive index NM₃ of a constituent material contained in the third anode-side-organic layer satisfy a relationship of Numerical Formula NM,

NM₂>NM₃ (Numerical Formula NM).

### TECHNICAL FIELD

The present invention relates to an organic electroluminescence device, an organic electroluminescence display device, and a digital device.

### BACKGROUND ART

An organic electroluminescence device (hereinafter, occasionally referred to as “organic EL device”) has found its application in a full-color display for mobile phones, televisions, and the like. When voltage is applied to an organic EL device, holes are injected from an anode and electrons are injected from a cathode into an emitting layer. The injected holes and electrons are recombined in the emitting layer to form excitons. Specifically, according to the electron spin statistics theory, singlet excitons and triplet excitons are generated at a ratio of 25%:75%.

For instance, studies for improving performance of an organic EL device have been made in Patent Literatures 1 to 6. The performance of the organic EL device is evaluable in terms of, for instance, luminance, emission wavelength, chromaticity, luminous efficiency, drive voltage, and lifetime.

Patent Literatures 1 to 6 also each disclose an organic EL device including a hole transporting zone formed of a plurality of layers.

### CITATION LIST

### Patent Literature(s)

Patent Literature 1: International Publication No. WO 2020/189316
Patent Literature 2 JP 2019-161218 A
Patent Literature 3: International Publication No. WO 2011/093056
Patent Literature 4 US Patent Application Publication No. 2021/0159418
Patent Literature 5 US Patent Application Publication No. 2021/234098
Patent Literature 6 JP 2019-161218 A

### SUMMARY OF THE INVENTION

### Problem(s) to be Solved by the Invention

An object of the invention is to provide an organic electroluminescence device and an organic electroluminescence display device with enhanced luminous efficiency, an electronic device provided with the organic electroluminescence device, and an electronic device provided with the organic electroluminescence display device.

### Means for Solving the Problem(s)

According to an aspect of the invention, there is provided an organic electroluminescence device including: a cathode; an anode; an emitting region provided between the cathode and the anode; and a hole transporting zone provided between the anode and the emitting region, in which the emitting region includes at least one emitting layer, the at least one emitting layer includes a first emitting layer, the hole transporting zone includes a first anode side organic layer, a second anode side organic layer and a third anode side organic layer, the first anode side organic layer is in direct contact with the second anode side organic layer, the second anode side organic layer is in direct contact with the third anode side organic layer, the first anode side organic layer, the second anode side organic layer and the third anode side organic layer are arranged between the anode and the emitting region in this order from a side close to the anode, the second anode side organic layer contains a second hole transporting zone material, the second hole transporting zone material is a monoamine compound having one substituted or unsubstituted amino group in a molecule or a diamine compound having two substituted or unsubstituted amino groups in a molecule, the third anode side organic layer contains a third hole transporting zone material, the third hole transporting zone material is a monoamine compound having one substituted or unsubstituted amino group in a molecule or a diamine compound having two substituted or unsubstituted amino groups in a molecule, the third anode side organic layer has a film thickness of 20 nm or more, the second hole transporting zone material and the third hole transporting zone material are mutually the same or different, the second anode side organic layer contains at least one compound different from a compound contained in the third anode side organic layer, the first emitting layer is a fluorescent emitting layer, and a refractive index NM₂ of a constituent material contained in the second anode side organic layer and a refractive index NM₃ of a constituent material contained in the third anode side organic layer satisfy a relationship of a numerical formula (Numerical Formula NM) below.

NM₂>NM₃ (Numerical Formula NM)

According to another aspect of the invention, there is provided an organic electroluminescence device including: a cathode; an anode; an emitting region provided between the cathode and the anode; a hole transporting zone provided between the anode and the emitting region; and an electron transporting zone provided between the cathode and the emitting region, in which the emitting region includes at least one emitting layer, the at least one emitting layer includes a first emitting layer, the hole transporting zone includes a first anode side organic layer, a second anode side organic layer and a third anode side organic layer, the first anode side organic layer is in direct contact with the second anode side organic layer, the second anode side organic layer is in direct contact with the third anode side organic layer, the first anode side organic layer, the second anode side organic layer and the third anode side organic layer are arranged in this order from a side close to the anode between the anode and the emitting region, the second anode side organic layer contains a second hole transporting zone material, the second hole transporting zone material is a monoamine compound having one substituted or unsubstituted amino group in a molecule or a diamine compound having two substituted or unsubstituted amino groups in a molecule, the third anode side organic layer contains a third hole transporting zone material, the third hole transporting zone material is a monoamine compound having one substituted or unsubstituted amino group in a molecule or a diamine compound having two substituted or unsubstituted amino groups in a molecule, the third anode side organic layer has a film thickness of 20 nm or more, the second hole transporting zone material and the third hole transporting zone material are mutually the same or different, the second anode side organic layer contains at least one compound different from a compound contained in the third anode side organic layer, at least one electron transporting layer in the electron transporting zone contains a phenanthroline compound having a phenanthroline skeleton, the phenanthroline compound is a compound represented by a formula (20) below and having at least one group represented by a formula (21) below, the first emitting layer is a fluorescent emitting layer, and a refractive index NM₂ of a constituent material contained in the second anode side organic layer and a refractive index NM₃ of a constituent material contained in the third anode side organic layer satisfy a relationship of a numerical formula (Numerical Formula NM) below.

NM₂>NM₃ (Numerical Formula NM)

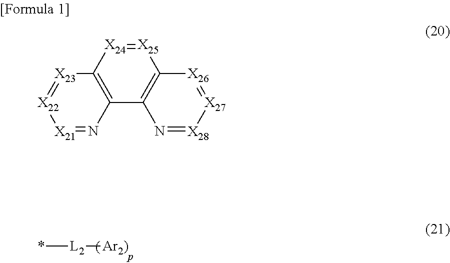

In the formula (20):
X₂₁ to X₂₈ are each independently a nitrogen atom, CR₂₁ or a carbon atom bonded to a group represented by the formula (21);
at least one of X₂₁ to X₂₈ is a carbon atom bonded to a group represented by the formula (21);
when a plurality of groups represented by the formula (21) are present, the plurality of groups represented by the formula (21) are mutually the same or different;
at least one combination of adjacent two or more of a plurality of R₂₁ are mutually bonded to form a substituted or unsubstituted monocyclic ring, mutually bonded to form a substituted or unsubstituted fused ring, or not mutually bonded; and
R₂₁ forming neither the substituted or unsubstituted monocyclic ring nor the substituted or unsubstituted fused ring are each independently a hydrogen atom, or a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₃₁, a group represented by —COOR₉₃₂, a group represented by —S(═O)₂R₉₃₃, a group represented by —B(R₉₃₄)(R₉₃₅), a group represented by —P(═O)(R₉₃₆)(R₉₃₇), a halogen atom, a cyano group, a nitro group, a substituted or unsubstituted aryl group having 6 to 50 ring carbon atoms, a substituted or unsubstituted heterocyclic group having 5 to 50 ring atoms.

In the formula (21):
Ar₂ is a substituted or unsubstituted aryl group having 6 to 50 ring carbon atoms, a substituted or unsubstituted heterocyclic group having 5 to 50 ring atoms, p is 1, 2, 3, 4, or 5;
when two or more Ar₂ are present, the two or more Ar₂ are mutually the same or different;
L₂ is a single bond or a linking group;
L₂ as a linking group is a substituted or unsubstituted polyvalent linear, branched or cyclic aliphatic hydrocarbon group having 1 to 50 carbon atoms, a substituted or unsubstituted polyvalent aromatic hydrocarbon group having 6 to 50 ring carbon atoms group, a substituted or unsubstituted polyvalent heterocyclic group having 5 to 50 ring atoms, or a polyvalent multiple linking group obtained by bonding two or three groups selected from the polyvalent aromatic hydrocarbon ring group and the polyvalent heterocyclic group;
the aromatic hydrocarbon ring group and the heterocyclic group forming L₂ as the multiple linking group are mutually the same or different, and adjacent ones of the aromatic hydrocarbon ring group and the heterocyclic group are mutually bonded to form a ring, or not mutually bonded;
Ar₂ and L₂ as a linking group are mutually bonded to form a ring, or not mutually bonded;
L₂ as a linking group and a carbon atom or R₂₁ of CR₂₁ in one of X₂₁ to X₂₈ adjacent to a carbon atom bonded to L₂ are mutually bonded to form a ring, or not mutually bonded; and
in the formula (21) represents a bonding position to a ring represented by the formula (20).

In the phenanthroline compound, R₉₀₁, R₉₀₂, R₉₀₃, R₉₀₄, R₉₀₅, R₉₀₆, R₉₀₇, R₉₃₁, R₉₃₂, R₉₃₃, R₉₃₄, R₉₃₅, R₉₃₆, and R₉₃₇ are each independently a hydrogen atom, or a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, when a plurality of R₉₀₁ are present, the plurality of R₉₀₁ are mutually the same or different; when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

According to still another aspect of the invention, there is provided an organic electroluminescence device including: a cathode; an anode; an emitting region provided between the cathode and the anode; and a hole transporting zone provided between the anode and the emitting region, in which the emitting region includes at least one emitting layer, the at least one emitting layer includes a first emitting layer, the first emitting layer includes a first host material and a first emitting compound, the first host material is a compound represented by a formula (H1) below, the compound represented by the formula (H1) has at least one deuterium atom, the hole transporting zone includes a first anode side organic layer, a second anode side organic layer and a third anode side organic layer, the first anode side organic layer is in direct contact with the second anode side organic layer, the second anode side organic layer is in direct contact with the third anode side organic layer, the first anode side organic layer, the second anode side organic layer and the third anode side organic layer are arranged in this order from a side close to the anode between the anode and the emitting region, the second anode side organic layer contains a second hole transporting zone material, the second hole transporting zone material is a monoamine compound having one substituted or unsubstituted amino group in a molecule or a diamine compound having two substituted or unsubstituted amino groups in a molecule, the third anode side organic layer contains a third hole transporting zone material, the third hole transporting zone material is a monoamine compound having one substituted or unsubstituted amino group in a molecule or a diamine compound having two substituted or unsubstituted amino groups in a molecule, the third anode side organic layer has a film thickness of 20 nm or more, the second hole transporting zone material and the third hole transporting zone material are mutually the same or different, the second anode side organic layer contains at least one compound different from a compound contained in the third anode side organic layer, the first emitting layer is a fluorescent emitting layer, and a refractive index NM₂ of a constituent material contained in the second anode side organic layer and a refractive index NM₃ of a constituent material contained in the third anode side organic layer satisfy a relationship of a numerical formula (Numerical Formula NM) below.

NM₂>NM₃ (Numerical Formula NM)

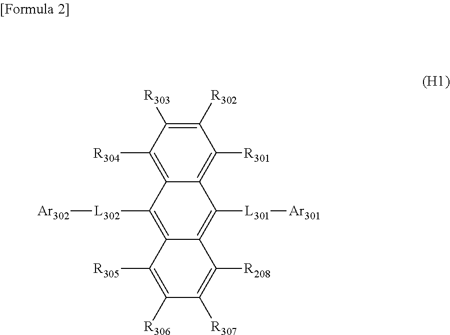

In the formula (H1):

R₃₀₁ to R₃₀₈ are each independently a hydrogen atom, or a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, L₃₀₁ and L₃₀₂ are each independently a single bond, a substituted or unsubstituted arylene group having 6 to 50 ring carbon atoms, or a substituted or unsubstituted divalent heterocyclic group having 5 to 50 ring atoms; and
Ar₃₀₁ and Ar₃₀₂ are each independently a substituted or unsubstituted aryl group having 6 to 50 ring carbon atoms, a substituted or unsubstituted heterocyclic group having 5 to 50 ring atoms.

In a compound represented by the formula (H1), R₉₀₁, R₉₀₂, R₉₀₃, R₉₀₄, R₉₀₅, R₉₀₆, R₉₀₇, R₈₀₁, and R₈₀₂ are each independently a hydrogen atom, or a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

According to a further aspect of the invention, there is provided an organic electroluminescence display device including: an anode and a cathode arranged opposite each other; and a first organic electroluminescence device as a first pixel and a second organic electroluminescence device as a second pixel, in which the first pixel includes the organic electroluminescence device according to the above aspect of the invention as the first organic electroluminescence device; the first organic electroluminescence device includes a first emitting region as the emitting region, and a first hole transporting zone as the hole transporting zone provided between the first emitting region and the anode; the first anode side organic layer, the second anode side organic layer, and the third anode side organic layer are provided in a shared manner across the second organic electroluminescence device; the first emitting layer of the first emitting region includes a first emitting compound; the second organic electroluminescence device includes a second emitting region provided between the anode and the cathode, and a second hole transporting zone provided between the second emitting region and the anode; the second hole transporting zone includes the first anode side organic layer, the second anode side organic layer, and the third anode side organic layer; in the second hole transporting zone, the first anode side organic layer is in direct contact with the second anode side organic layer and the second anode side organic layer is in direct contact with the third anode side organic layer; the first anode side organic layer, the second anode side organic layer, and the third anode side organic layer are arranged in this order from a side close to the anode between the anode and the second emitting region; the second emitting region includes at least one emitting layer; the at least one emitting layer of the second emitting region includes a third emitting layer; the third emitting layer of the second emitting region contains a third emitting compound; a maximum peak wavelength of the first emitting compound contained in the first emitting layer and a maximum peak wavelength of the third emitting compound contained in the third emitting layer are mutually the same or different; and a refractive index NM₁ of a constituent material contained in the first anode side organic layer and a refractive index NM₂ of a constituent material contained in the second anode side organic layer satisfy a relationship of a numerical formula (Numerical Formula L1) below.

NM₁>NM₂ (Numerical Formula L1)

According to a still further aspect of the invention, an electronic device including the organic electroluminescence device according to the aspect of the invention is provided.

According to a still further aspect of the invention, there is provided an electronic device provided with the organic electroluminescence display device according to the aspect of the invention.

According to the aspects of the invention, there are provided an organic electroluminescence device and an organic electroluminescence display device with enhanced luminous efficiency, an electronic device provided with the organic electroluminescence device, and an electronic device provided with the organic electroluminescence display device.

### BRIEF EXPLANATION OF DRAWINGS

FIG. 1 schematically depicts an exemplary arrangement of an organic electroluminescence device according to a first exemplary embodiment.

FIG. 2 schematically depicts another exemplary arrangement of the organic electroluminescence device according to the first exemplary embodiment.

FIG. 3 schematically depicts still another exemplary arrangement of the organic electroluminescence device according to the first exemplary embodiment.

FIG. 4 schematically depicts a further exemplary arrangement of the organic electroluminescence device according to the first exemplary embodiment.

FIG. 5 schematically depicts an exemplary arrangement of an organic electroluminescence display device according to a second exemplary embodiment.

FIG. 6 schematically depicts another exemplary arrangement of the organic electroluminescence display device according to the second exemplary embodiment.

FIG. 7 schematically depicts still another exemplary arrangement of the organic electroluminescence display device according to the second exemplary embodiment.

FIG. 8 schematically depicts a further exemplary arrangement of the organic electroluminescence display device according to the second exemplary embodiment.

FIG. 9 schematically depicts a still further exemplary arrangement of the organic electroluminescence display device according to the second exemplary embodiment.

FIG. 10 schematically depicts a still further exemplary arrangement of the organic electroluminescence display device according to the second exemplary embodiment.

### DESCRIPTION OF EMBODIMENT(S)

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, crosslinking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless specifically described, the same applies to the “ring carbon atoms” described later. For instance, a benzene ring has 6 ring carbon atoms, a naphthalene ring has 10 ring carbon atoms, a pyridine pyridine ring has 5 ring carbon atoms, and a furan ring 4 ring carbon atoms. For instance, a 9,9-diphenylfluorenyl group has 13 ring carbon atoms and 9,9′-spirobifluorenyl group has 25 ring carbon atoms.

When a benzene ring is substituted by a substituent (e.g., an alkyl group), the number of carbon atoms of the alkyl group is not counted in the number of the ring carbon atoms. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted as ring atoms of the pyridine ring. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

Substituents Mentioned Herein Substituents mentioned herein will be described below.

An “unsubstituted aryl group” mentioned herein has, unless otherwise specified herein, 6 to 50, preferably 6 to 30, more preferably 6 to 18 ring carbon atoms.

An “unsubstituted heterocyclic group” mentioned herein has, unless otherwise specified herein, 5 to 50, preferably 5 to 30, more preferably 5 to 18 ring atoms.

An “unsubstituted alkyl group” mentioned herein has, unless otherwise specified herein, 1 to 50, preferably 1 to 20, more preferably 1 to 6 carbon atoms.

An “unsubstituted alkenyl group” mentioned herein has, unless otherwise specified herein, 2 to 50, preferably 2 to 20, more preferably 2 to 6 carbon atoms.

An “unsubstituted alkynyl group” mentioned herein has, unless otherwise specified herein, 2 to 50, preferably 2 to 20, more preferably 2 to 6 carbon atoms.

An “unsubstituted cycloalkyl group” mentioned herein has, unless otherwise specified herein, 3 to 50, preferably 3 to 20, more preferably 3 to 6 ring carbon atoms.

An “unsubstituted arylene group” mentioned herein has, unless otherwise specified herein, 6 to 50, preferably 6 to 30, more preferably 6 to 18 ring carbon atoms.

An “unsubstituted divalent heterocyclic group” mentioned herein has, unless otherwise specified herein, 5 to 50, preferably 5 to 30, more preferably 5 to 18 ring atoms.

An “unsubstituted alkylene group” mentioned herein has, unless otherwise specified herein, 1 to 50, preferably 1 to 20, more preferably 1 to 6 carbon atoms.

Substituted or Unsubstituted Aryl Group Specific examples (specific example group G1) of the “substituted or unsubstituted aryl group” mentioned herein include unsubstituted aryl groups (specific example group G1A) below and substituted aryl groups (specific example group G11B). (Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.”) A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1 B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1 B below, and a group derived by further substituting a hydrogen atom of a substituent of the “substituted aryl group” in the specific example group G1 B below.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

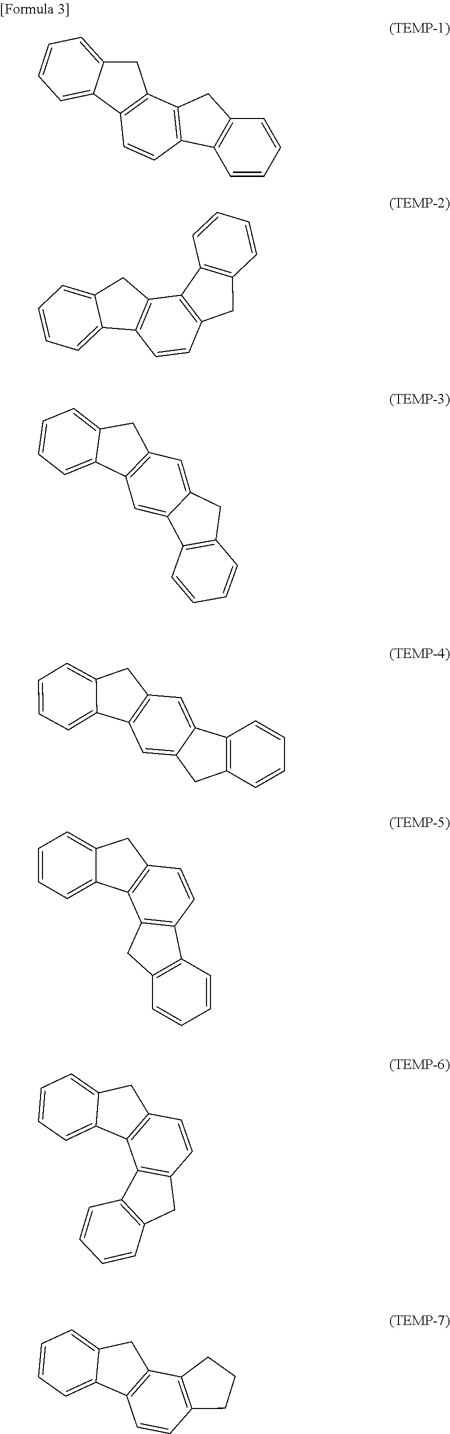

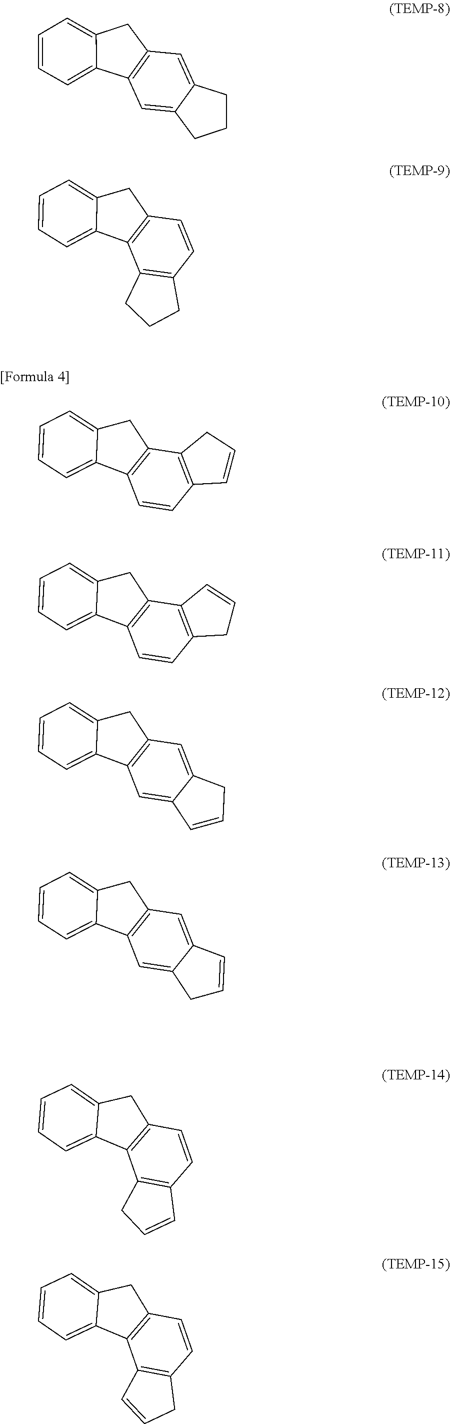

### Substituted Aryl Group (Specific Example Group G1 B):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B). (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below, and a group derived by further substituting a hydrogen atom of a substituent of the “substituted heterocyclic group” in the specific example group G2B below.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4) derived from the cyclic structures represented by formulae (TEMP-16) to (TEMP-33) below.

### Unsubstituted Heterocyclic Groups Including Nitrogen Atom (Specific Example Group G2A1):

a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2):

a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3):

a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).
Monovalent Heterocyclic Groups Derived by Removing One Hydrogen Atom from Cyclic Structures Represented by Formulae (TEMP-16) to (TEMP-33) (Specific Example Group G2A4):

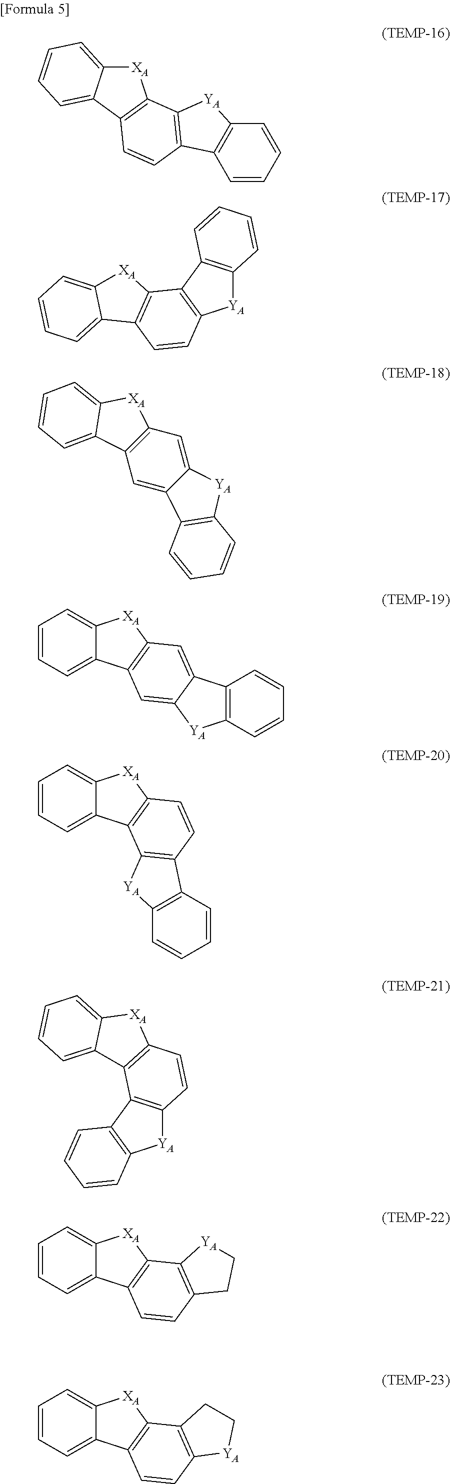

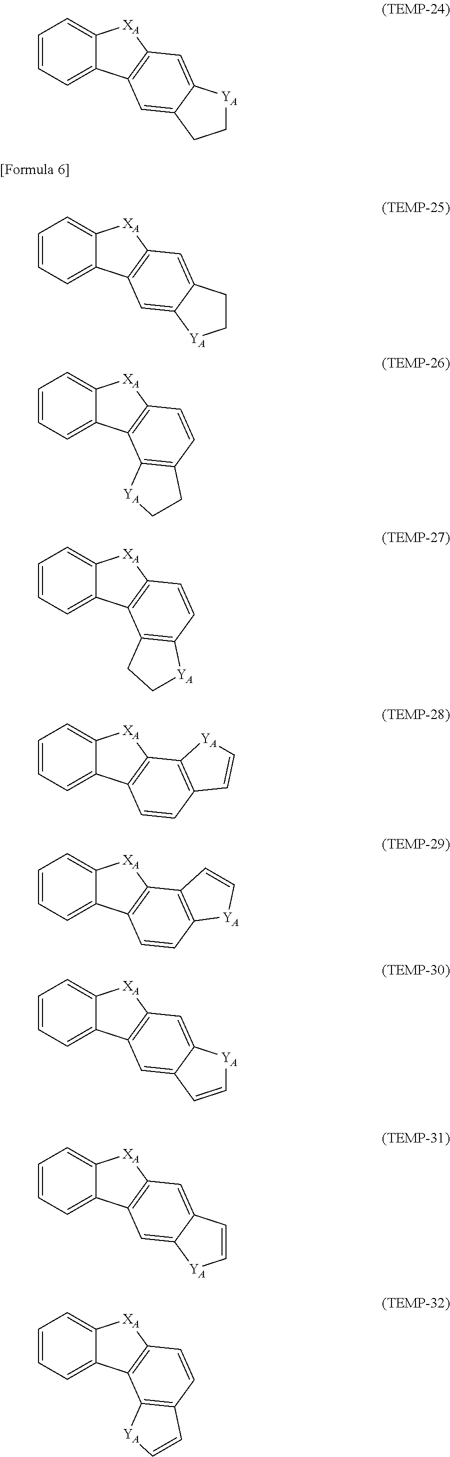

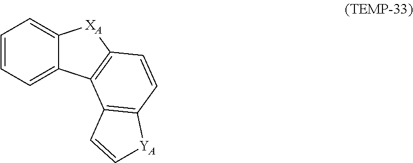

In the formulae (TEMP-16) to (TEMP-33), X_{A} and Y_{A} are each independently an oxygen atom, a sulfur atom, NH or CH₂, with a proviso that at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B1):

a (9-phenyl)carbazolyl group, (9-biphenylyl)carbazolyl group, (9-phenyl)phenylcarbazolylgroup, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2):

a phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G2B3):

a phenyldibenzothiophenyl group, methyldibenzothiophenyl group, t-butyldibenzothiophenyl group, and monovalent residue of spiro[9H-thioxanthene-9,9′-[9H]fluorene].
Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of X_{A} or Y_{A} in a form of NH, and a hydrogen atom of one of X_{A} and Y_{A} in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. (Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.”) A simply termed “alkyl group” herein includes both of an “unsubstituted alkyl group” and a “substituted alkyl group”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B, and a group derived by further substituting a hydrogen atom of a substituent of the “substituted alkyl group” in the specific example group G3B.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Group (Specific Example Group G3B):

a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. (Herein, an unsubstituted alkynyl group refers to an “unsubstituted alkynyl group” in a “substituted or unsubstituted alkynyl group.”) A simply termed “alkynyl group” herein includes both of “unsubstituted alkynyl group” and “substituted alkynyl group”.

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

Unsubstituted Alkynyl Group (Specific Example Group G5A): an ethynyl group

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). (Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.”) A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.

### Substituted Cycloalkyl Group (Specific Example Group G6B):

a 4-methylcyclohexyl group.
Group Represented by —Si(R₉₀₁)(R₉₀₂)(R₉₀₃)

Specific examples (specific example group G7) of the group represented herein by —Si(R₉₀₁)(R₉₀₂)(R₉₀₃) include:

### —Si(G1)(G1)(G1); —Si(G1)(G2)(G2); —Si(G1)(G1)(G2); —Si(G2)(G2)(G2); —Si(G3)(G3)(G3); and —Si(G6)(G6)(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —Si(G1)(G1)(G1) are mutually the same or different;
a plurality of G2 in —Si(G1)(G2)(G2) are mutually the same or different;
a plurality of G1 in —Si(G1)(G1)(G2) are mutually the same or different;
a plurality of G2 in —Si(G2)(G2)(G2) are mutually the same or different;
a plurality of G3 in —Si(G3)(G3)(G3) are mutually the same or different; and
a plurality of G6 in —Si(G6)(G6)(G6) are mutually the same or different.

### Group Represented by —O—(R₉₀₄)

Specific examples (specific example group G8) of a group represented by —O—(R₉₀₄) herein include: —O(G1); —O(G2); —O(G3); and —O(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1); —S(G2); —S(G3); and —S(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6),
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “substituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, and more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “substituted haloalkyl group” include a group derived by substituting at least one hydrogen atom of the “alkyl group” (specific example group G3) with a halogen atom. The haloalkyl group is sometimes referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. A plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

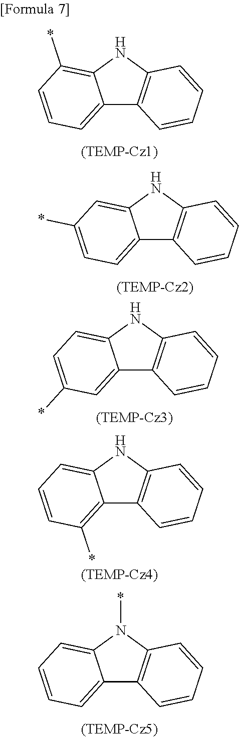 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

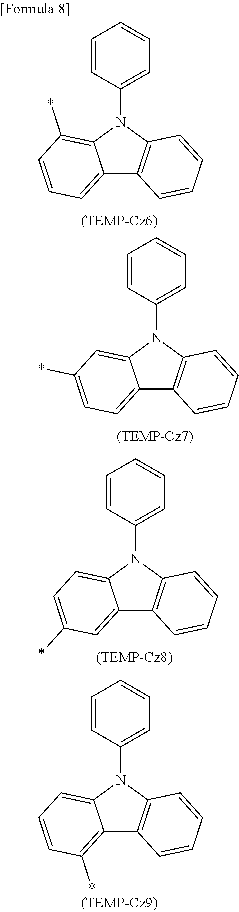

In the formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

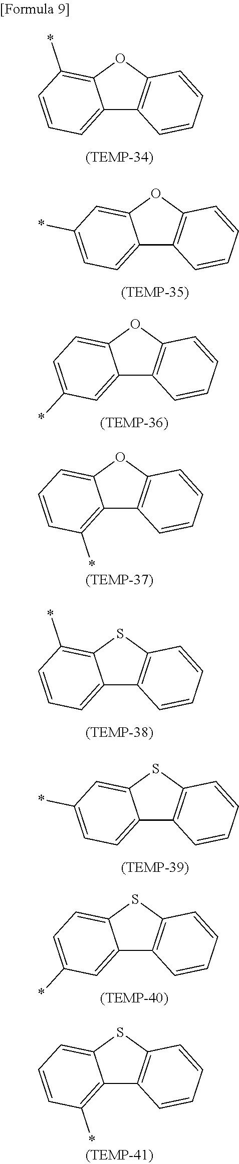

In the formulae (TEMP-34) to (TEMP-41), * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocyclic ring of the “substituted or unsubstituted heterocyclic group.” Specific examples of the “substituted or unsubstituted divalent heterocyclic group” (specific example group G13) include a divalent group derived by removing one hydrogen atom on a heterocyclic ring of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

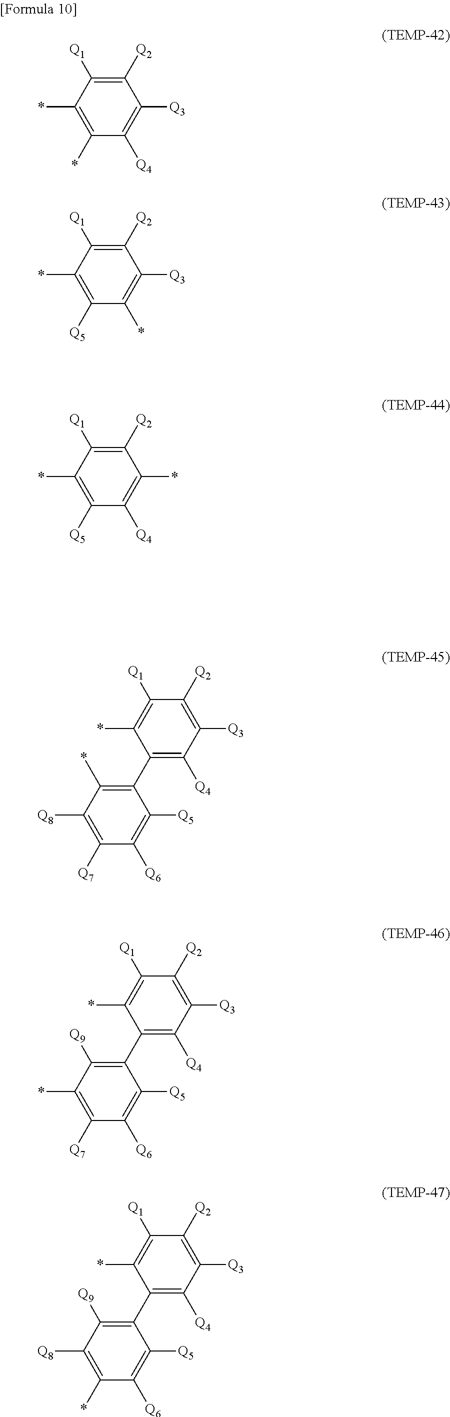

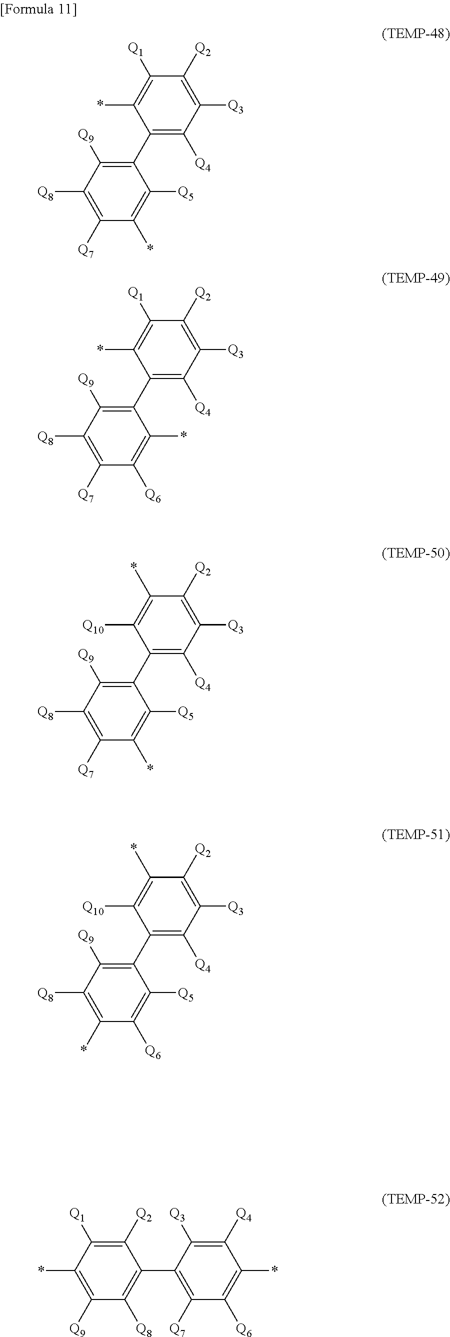

In the formulae (TEMP-42) to (TEMP-52), Q₁ to Q₁₀ are each independently a hydrogen atom or a substituent.

In the formulae (TEMP-42) to (TEMP-52), * represents a bonding position.

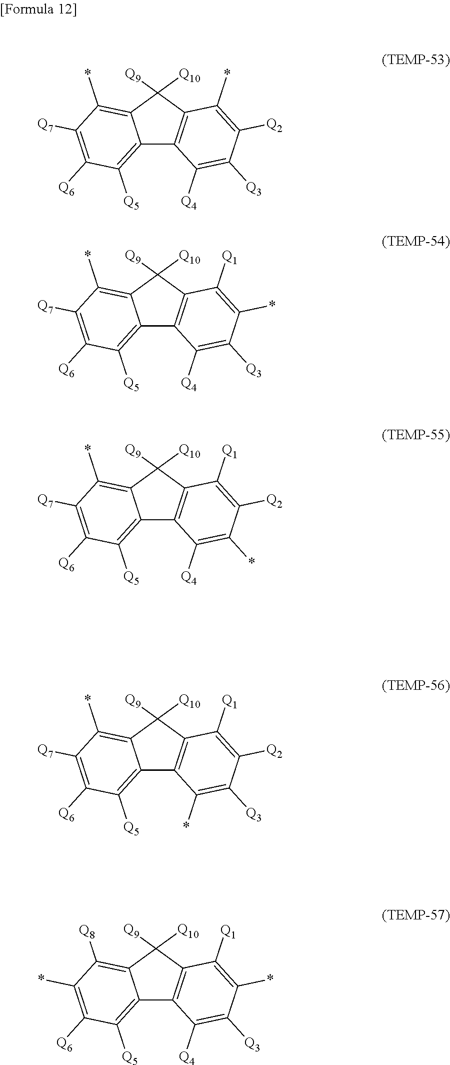

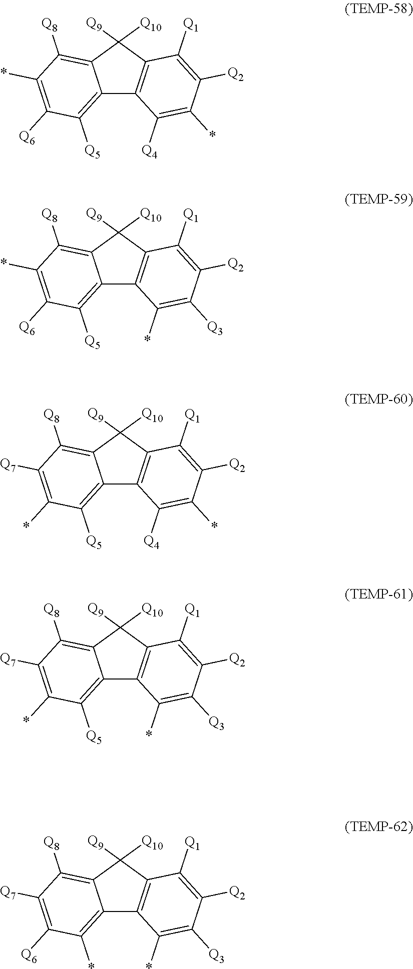

In the formulae (TEMP-53) to (TEMP-62), Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62), * represents a bonding position.

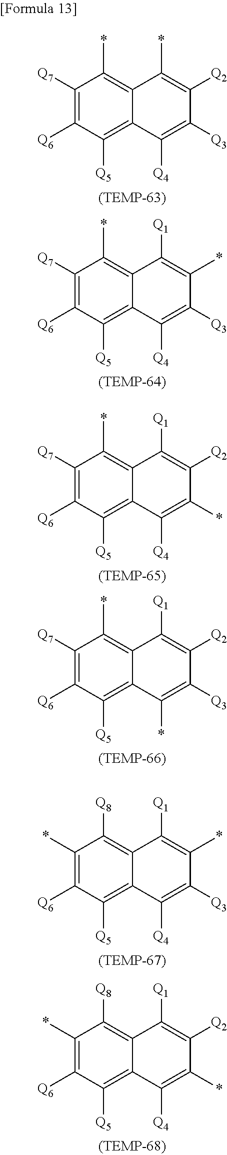

In the formulae (TEMP-63) to (TEMP-68), Q₁ to Q₈ are each independently a hydrogen atom or a substituent.

In the formulae (TEMP-63) to (TEMP-68), * represents a bonding position.

The substituted or unsubstituted divalent heterocyclic group mentioned herein is, unless otherwise specified herein, preferably a group represented by any one of formulae (TEMP-69) to (TEMP-102) below.

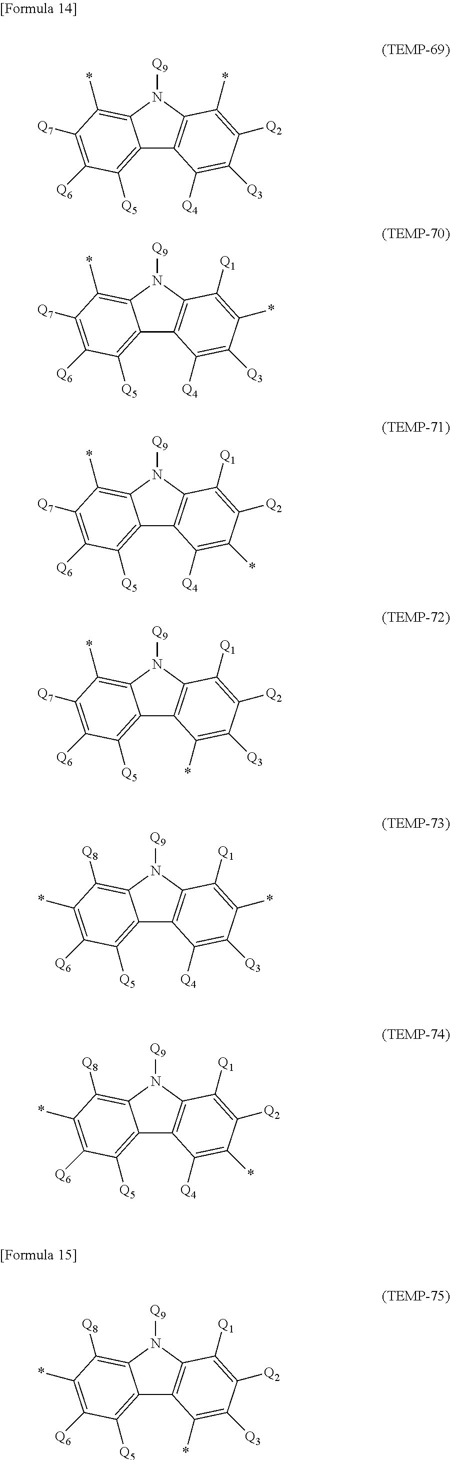

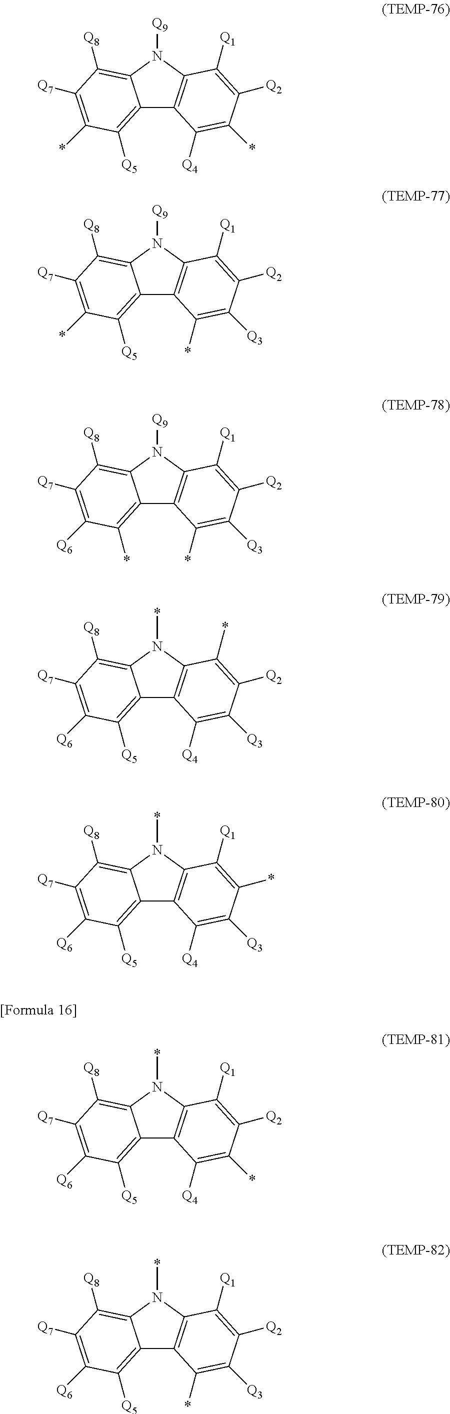

In the formulae (TEMP-69) to (TEMP-82), Q₁ to Q₉ are each independently a hydrogen atom or a substituent.

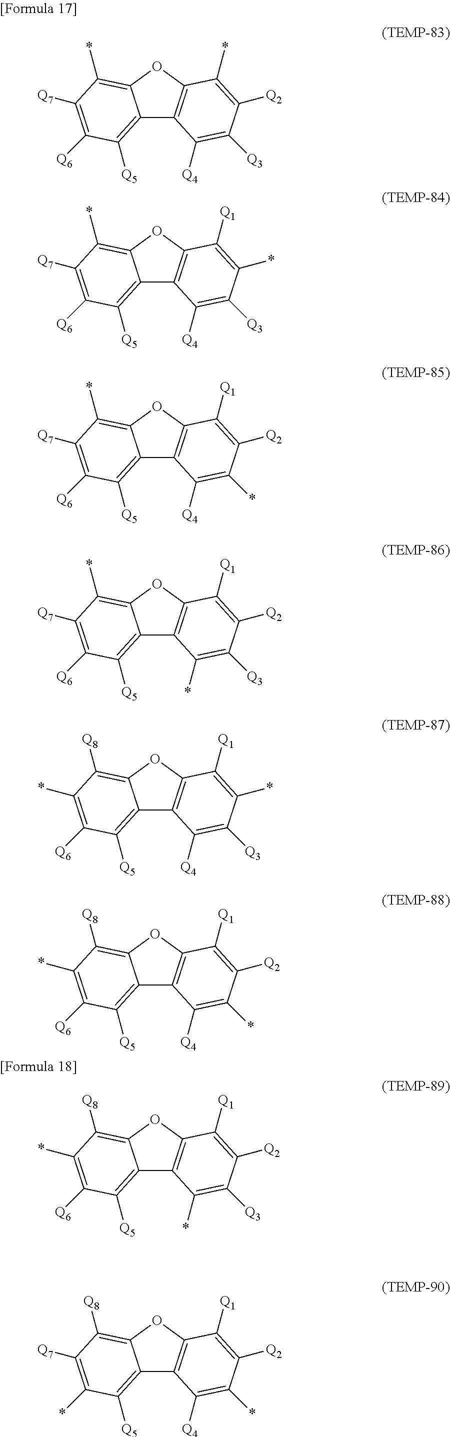

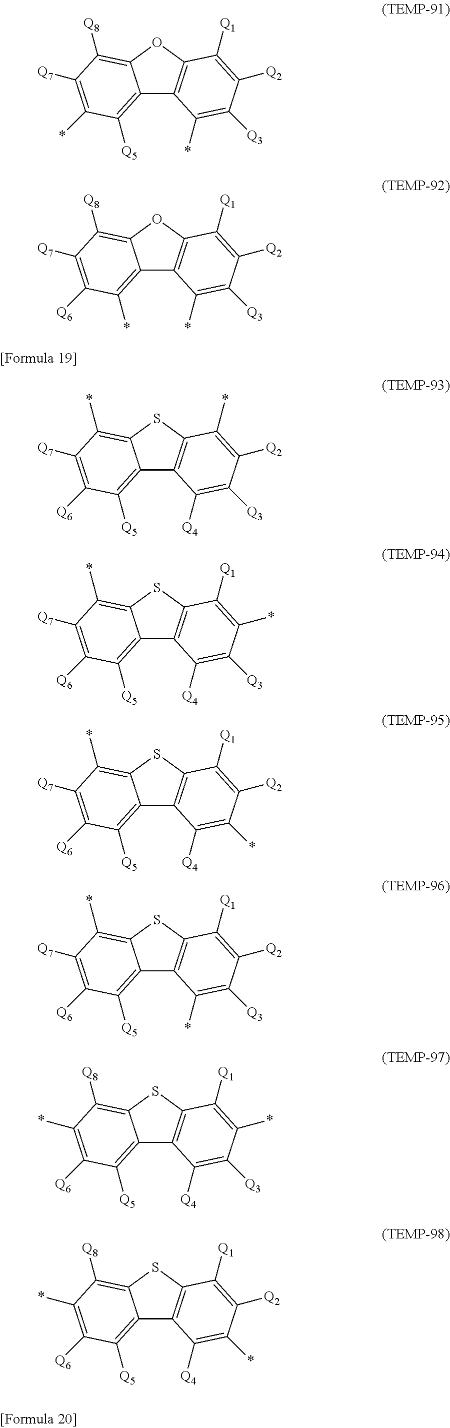

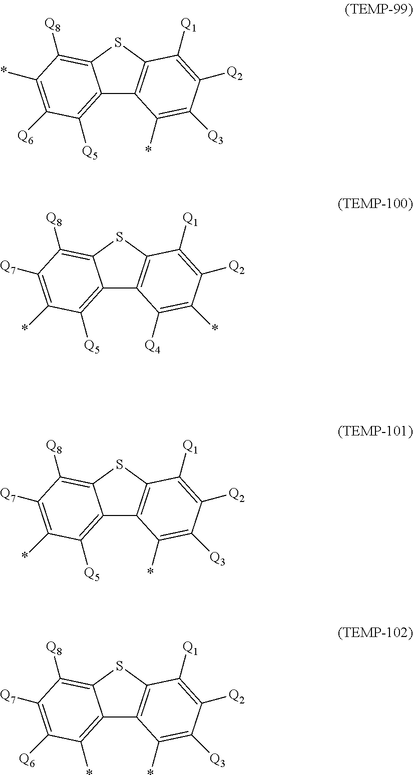

In the formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring,” at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

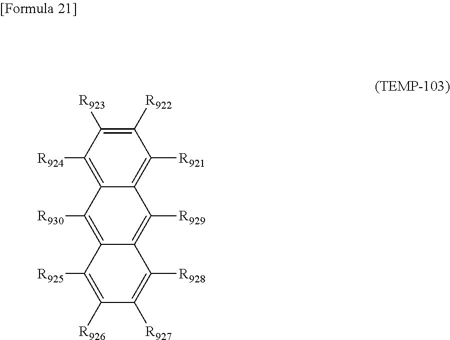

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring Q_{A} and R₉₂₅ and R₉₂₆ are simultaneously mutually bonded to form a ring Q_{B}, the anthracene compound represented by the formula (TEMP-103) is represented by a formula (TEMP-104) below.

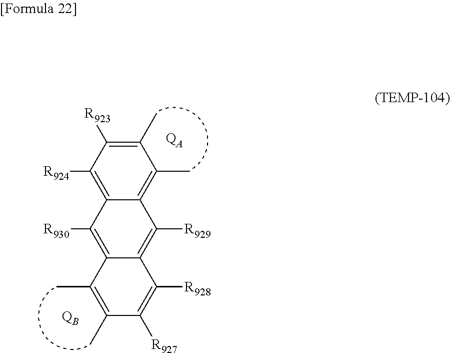

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring Q_{A} and the ring Q_{C} share R₉₂₂.

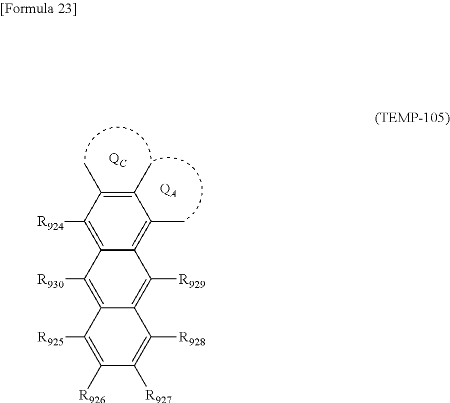

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in the formula (TEMP-104) are each independently a “monocyclic ring” or a “fused ring.” Further, the ring Q_{A} and the ring Q_{c} formed in the formula (TEMP-105) are each a “fused ring.” The ring Q_{A} and the ring Q_{c} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific examples of the specific example group G1 with a hydrogen atom.

Specific examples of the aromatic heterocyclic ring include a ring formed by terminating a bond of an aromatic heterocyclic group in the specific examples of the specific example group G2 with a hydrogen atom.

Specific examples of the aliphatic hydrocarbon ring include a ring formed by terminating a bond of a group in the specific examples of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes an optional element other than carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (sometimes referred to as an “optional substituent”. hereinafter), is for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;

R₉₀₁ to R₉₀₇ are each independently a hydrogen atom, or a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more R₉₀₆ are present, the two or more R₉₀₆ are mutually the same or different; and
when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

### First Exemplary Embodiment

### Organic Electroluminescence Device

An organic electroluminescence device (organic EL device) according to a first exemplary embodiment includes: a cathode; an anode; an emitting region provided between the cathode and the anode; and a hole transporting zone provided between the anode and the emitting region, in which the emitting region includes at least one emitting layer, the at least one emitting layer includes a first emitting layer, the hole transporting zone includes a first anode side organic layer, a second anode side organic layer and a third anode side organic layer, the first anode side organic layer is in direct contact with the second anode side organic layer, the second anode side organic layer is in direct contact with the third anode side organic layer, the first anode side organic layer, the second anode side organic layer and the third anode side organic layer are arranged between the anode and the emitting region in this order from a side close to the anode, the second anode side organic layer contains a second hole transporting zone material, the second hole transporting zone material is a monoamine compound having one substituted or unsubstituted amino group in a molecule or a diamine compound having two substituted or unsubstituted amino groups in a molecule, the third anode side organic layer contains a third hole transporting zone material, the third hole transporting zone material is a monoamine compound having one substituted or unsubstituted amino group in a molecule or a diamine compound having two substituted or unsubstituted amino groups in a molecule, the third anode side organic layer has a film thickness of 20 nm or more, the second hole transporting zone material and the third hole transporting zone material are mutually the same or different, the second anode side organic layer contains at least one compound different from a compound contained in the third anode side organic layer, the first emitting layer is a fluorescent emitting layer, and a refractive index NM₂ of a constituent material contained in the second anode side organic layer and a refractive index NM₃ of a constituent material contained in the third anode side organic layer satisfy a relationship of a numerical formula (Numerical Formula NM) below.

NM₂>NM₃ (Numerical Formula NM)

According to the exemplary embodiment, the device performance of the organic EL device is improvable. In an exemplary arrangement according to the exemplary embodiment, the organic EL device has an improved luminous efficiency. In an exemplary arrangement according to the exemplary embodiment, the organic EL device has a longer lifetime.

### Hole Transporting Zone

Herein, a zone disposed between the anode and the emitting region and formed by a plurality of organic layers is occasionally referred to as a hole transporting zone.

The hole transporting zone includes a first anode side organic layer second anode side organic layer, and a third anode side organic layer.

In an exemplary arrangement of the organic EL device of the exemplary embodiment, the anode is in direct contact with the hole transporting zone and the emitting region in direct contact with the hole transporting zone. First Anode Side Organic Layer, Second Anode Side Organic Layer, and Third Anode Side Organic Layer

In an exemplary arrangement of the organic EL device of the exemplary embodiment, a difference NM₂-NM₃ between a refractive index NM₂ of a constituent material contained in the second anode side organic layer and a refractive index NM₃ of a constituent material contained in the third anode side organic layer satisfy a relationship of a numerical formula (Numerical Formula NM), thereby improving a light-extraction efficiency. When the second anode side organic layer contains a single type of compound, the refractive index NM₂ of the constituent material contained in the second anode side organic layer corresponds to a refractive index of the single type of compound. When the second anode side organic layer contains a plurality of types of compounds, the refractive index NM₂ of the constituent material contained in the second anode side organic layer corresponds to a refractive index of a mixture containing the plurality types of compounds. The refractive index NM₃ of the constituent material contained in the third anode side organic layer is also defined similarly to the refractive index NM₂ of the constituent material contained in the second anode side organic layer. The refractive index can be measured by a measurement method described in Examples below.

In an exemplary arrangement of the organic EL device of the exemplary embodiment, a difference NM₂-NM₃ between the refractive index NM₂ of the constituent material contained in the second anode side organic layer and the refractive index NM₃ of the constituent material contained in the third anode side organic layer satisfies a relationship of a numerical formula (Numerical Formula NM1) below.

NM₂−NM₃≥0.01 (Numerical Formula NM1)

In an exemplary arrangement of the organic EL device of the exemplary embodiment, the difference NM₂-NM₃ between the refractive index NM₂ of the constituent material contained in the wherein second anode side organic layer and the refractive index NM₃ of the constituent material contained in the third anode side organic layer satisfies a relationship of a numerical formula (Numerical Formula NM2), a numerical formula (Numerical Formula NM3), or a numerical formula (Numerical Formula NM4) below.

NM₂−NM₃≥0.05 (Numerical Formula NM2)

NM₂−NM₃≥0.075 (Numerical Formula NM3)

NM₂−NM₃≥0.10 (Numerical Formula NM4)

In an exemplary arrangement of the organic EL device of the exemplary embodiment, the refractive index NM₂ of the constituent material contained in the second anode side organic layer is 1.90 or more.

In an exemplary arrangement of the organic EL device of the exemplary embodiment, the refractive index of the compound contained in the second anode side organic layer is 1.90 or more.

In an exemplary arrangement of the organic EL device of the exemplary embodiment, the refractive index NM₂ of the constituent material contained in the second anode side organic layer is 1.94 or more.

In an exemplary arrangement of the organic EL device of the exemplary embodiment, the refractive index of the compound contained in the second anode side organic layer is 1.94 or more.

In an exemplary arrangement of the organic EL device of the exemplary embodiment, the refractive index NM₃ of the constituent material contained in third anode side organic layer is 1.89 or less.

In an exemplary arrangement of the organic EL device of the exemplary embodiment, the refractive index of a compound contained in the third anode side organic layer is 1.89 or less.

In an exemplary arrangement of the organic EL device of the exemplary embodiment, a refractive index NM₁ of a constituent material contained in the first anode side organic layer and the refractive index NM₂ of the constituent material contained in the second anode side organic layer satisfy a relationship of a numerical formula (Numerical Formula L1) below.

NM₁>NM₂ (Numerical Formula 1)

In an exemplary arrangement of the organic EL device of the exemplary embodiment, the hole transporting zone consists of the first anode side organic layer, the second anode side organic layer, and the third anode side organic layer. In this case, a total film thickness of the hole transporting zone corresponds to a total of a film thickness of the first anode side organic layer, a film thickness of the second anode side organic layer, and a film thickness of the third anode side organic layer.

In the organic EL device of the exemplary embodiment, the third anode side organic layer has a film thickness of 20 nm or more.

In an exemplary arrangement of the organic EL device of the exemplary embodiment, the third anode side organic layer has a film thickness of 25 nm or more.

In an exemplary arrangement of the organic EL device of the exemplary embodiment, the third anode side organic layer has a film thickness in a range from 30 nm to 150 nm.

In an exemplary arrangement of the organic EL device of the exemplary embodiment, the third anode side organic layer has a film thickness in a range from 30 nm to 80 nm.

In an exemplary arrangement of the organic EL device of the exemplary embodiment, the third anode side organic layer has a film thickness in a range from 80 nm to 150 nm.

It is considered that the third anode side organic layer having a film thickness of 20 nm or more readily inhibits the transfer of the excitation energy of the emitting layer.

In the organic EL device of the exemplary embodiment, the first anode side organic layer has a film thickness of 20 nm or less.

In an exemplary arrangement of the organic EL device of the exemplary embodiment, a ratio TL₃/TL₂ of a film thickness TL₃ of the third anode side organic layer to a film thickness TL₂ of the second anode side organic layer satisfies a predetermined relationship.

In an exemplary arrangement of the organic EL device of the exemplary embodiment, the ratio of the film thickness of the third anode side organic layer to the film thickness of the second anode side organic layer satisfies a relationship of a numerical formula (Numerical Formula A1), numerical formula (Numerical Formula A2), numerical formula (Numerical Formula A3), or numerical formula (Numerical Formula A4) below.

0.50<TL₃/TL₂<4.0 (Numerical Formula A1)

0.30<TL₃/TL₂<4.0 (Numerical Formula A2)

0.75<TL₃/TL₂<3.0 (Numerical Formula A3)

0.30<TL₃/TL₂<5.0 (Numerical Formula A4)

where TL₂ is a film thickness of the second anode side organic layer, TL₃ is a film thickness of the third anode side organic layer, and a unit of the film thickness is denoted by nm.

In an exemplary arrangement of the organic EL device of the exemplary embodiment, the ratio TL₃/TL₂ is 1 or more.

In an exemplary arrangement of the organic EL device of the exemplary embodiment, the ratio TL₃/TL₂ is 2.5 or less.

In the organic EL device of the exemplary embodiment, the first anode side organic layer, the second anode side organic layer, and the third anode side organic layer are in direct contact with each other.

In an exemplary arrangement of the organic EL device of the exemplary embodiment, in a case where the hole transporting zone consists of the first anode side organic layer, the second anode side organic layer, and the third anode side organic layer, the third anode side organic layer is in direct contact with the emitting region.

In an exemplary arrangement of the organic EL device of the exemplary embodiment, the first anode side organic layer is in direct contact with the anode.

In an exemplary arrangement of the organic EL device of the exemplary embodiment, the first anode side organic layer, the second anode side organic layer, and the third anode side organic layer each contain at least one compound, the compounds respectively contained in the first, second, and third anode side organic layers being different from each other.

In an exemplary arrangement of the organic EL device of the exemplary embodiment, although each of the first anode side organic layer and the second anode side organic layer may contain a compound represented by the formula (C1) or a compound represented by the formula (C3), the compound(s) contained in the first anode side organic layer and the second anode side organic layer is/are different from a compound contained in the third anode side organic layer in a molecular structure.

In an exemplary arrangement of the organic EL device of the exemplary embodiment, the compound contained in the second anode side organic layer is occasionally referred to as a second hole transporting zone material.

In an exemplary arrangement of the organic EL device of the exemplary embodiment, the compound contained in the third anode side organic layer is occasionally referred to as a third hole transporting zone material.

In an exemplary arrangement of the organic EL device of the exemplary embodiment, all the compound(s) contained in the second anode side organic layer (second hole transporting zone material) is/are different from all the compound(s) contained in the third anode side organic layer (third hole transporting zone material).

An arrangement satisfying the above condition is exemplified by a case where the second anode side organic layer contains a compound AA and the third anode side organic layer contains a compound BB.

Further, for instance, the above condition is satisfied also when the second anode side organic layer contains two types of compounds (compound AA and compound AB) and the third anode side organic layer contains a compound (compound BB), because both the compounds AA and AB are different from the compound BB. The compounds AA, AB, and BB are compounds different from each other.

On the other hand, for instance, the above condition is not satisfied when the second anode side organic layer contains two types of compounds (compound AA and compound AB) and the third anode side organic layer contains a compound (compound AB), because the second anode side organic layer and the third anode side organic layer contain the same compound (compound AB).

In an exemplary arrangement of the organic EL device of the exemplary embodiment, the hole mobility of the third hole transporting zone material μh(cHT3) is larger than 1.0×10⁻⁵ cm²/Vs.

In an exemplary arrangement of the organic EL device of the exemplary embodiment, the energy level of the highest occupied molecular orbital of the third hole transporting zone material HOMO(cHT3) is −5.6 eV or less.

In an exemplary arrangement of the organic EL device of the exemplary embodiment, the hole mobility of the third hole transporting zone material μh(cHT3) is larger than 1.0×10⁻⁵ cm²/Vs, and the energy level of the highest occupied molecular orbital of the third hole transporting zone material HOMO(cHT3) is −5.6 eV or less. When the hole mobility μh(cHT3) and the energy level HOMO(cHT3) of the third hole transporting zone material fall within the above ranges, the third anode side organic layer has a high hole mobility and a high hole injectability to the emitting layer in the emitting region.

In an exemplary arrangement of the organic EL device of the exemplary embodiment, the singlet energy of the third hole transporting zone material is larger than 3.12 eV.

In an exemplary arrangement of the organic EL device of the exemplary embodiment, the singlet energy of the third hole transporting zone material is 3.15 eV or more.

In an exemplary arrangement of the organic EL device of the exemplary embodiment, the singlet energy of the third hole transporting zone material is 3.40 eV or less or 3.30 eV or less.

In an exemplary arrangement of the organic EL device of the exemplary embodiment, the first anode side organic layer does not contain the compound(s) contained in the second anode side organic layer.

In an exemplary arrangement of the organic EL device of the exemplary embodiment, the compound contained in the third anode side organic layer (third hole transporting zone material) is at least one compound selected from the group consisting of a compound represented by a formula (C1) below and a compound represented by a formula (C3) below.

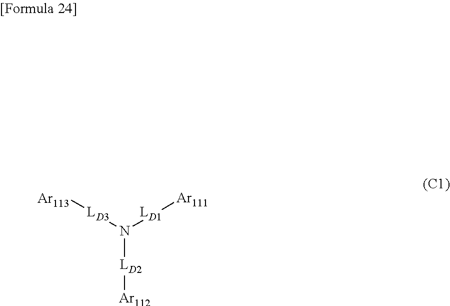

In the formula (C1):
Ar₃₁₁, Ar₃₁₂, and Ar₃₁₃ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different; and
L_{D1}, L_{D2}, and L_{D3} are each independently a single bond, a substituted or unsubstituted arylene group having 6 to 50 ring carbon atoms, or a substituted or unsubstituted divalent heterocyclic group having 5 to 50 ring atoms.

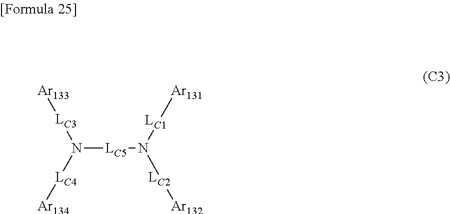

In the formula (C3):
L_{C1}, L_{C2}, L_{C3}, and L_{C4} are each independently a single bond, a substituted or unsubstituted arylene group having 6 to 50 ring carbon atoms, or a substituted or unsubstituted divalent heterocyclic group having 5 to 50 ring atoms;
n2 is 1, 2, 3, or 4;
when n2 is 1, L_{C5} is a substituted or unsubstituted arylene group having 6 to 50 ring carbon atoms, or a substituted or unsubstituted divalent heterocyclic group having 5 to 50 ring atoms;
when n2 is 2, 3, or 4, a plurality of L_{C5} are mutually the same or different;
when n2 is 2, 3, or 4, a plurality of L_{C5} are mutually bonded to form a substituted or unsubstituted monocyclic ring, mutually bonded to form a substituted or unsubstituted fused ring, or not mutually bonded;
L_{C5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
Ar₁₃₁, Ar₁₃₂, Ar₁₃₃, and Ar₁₃₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3}); R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different; and
a first amino group represented by a formula (C3-1) below and a second amino group represented by a formula (C3-2) below are the same or different.

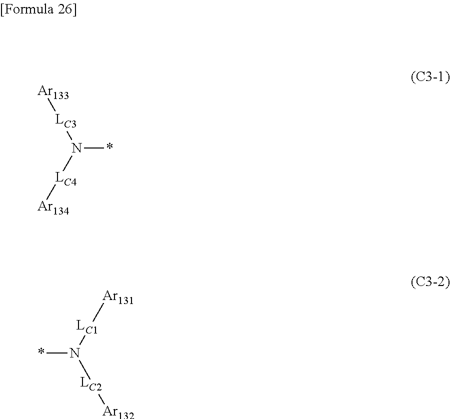

In the formulae (C3-1) and (C3-2), each * represents a bonding position to L_{C5}.

In an exemplary arrangement of the organic EL device of the exemplary embodiment, in the compound represented by the formulae (C3), the substituent for the “substituted or unsubstituted” group is not a group represented by —N(R_{C6})(R_{C7}).

In an exemplary arrangement of the organic EL device of the exemplary embodiment, in the compound represented by the formulae (C1), the substituent for the “substituted or unsubstituted” group is not a group represented by —N(R_{C6})(R_{C7}).

In the exemplary embodiment, R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms. A plurality of R_{C6} are mutually the same or different, and a plurality of R_{C7} are mutually the same or different.

In an exemplary arrangement of the organic EL device of the exemplary embodiment, the compound represented by the formula (C1) is at least one compound selected from the group consisting of a compound represented by the formula (cHT3-1), a compound represented by the formula (cHT3-2), a compound represented by the formula (cHT3-3), and a compound represented by the formula (cHT3-4).

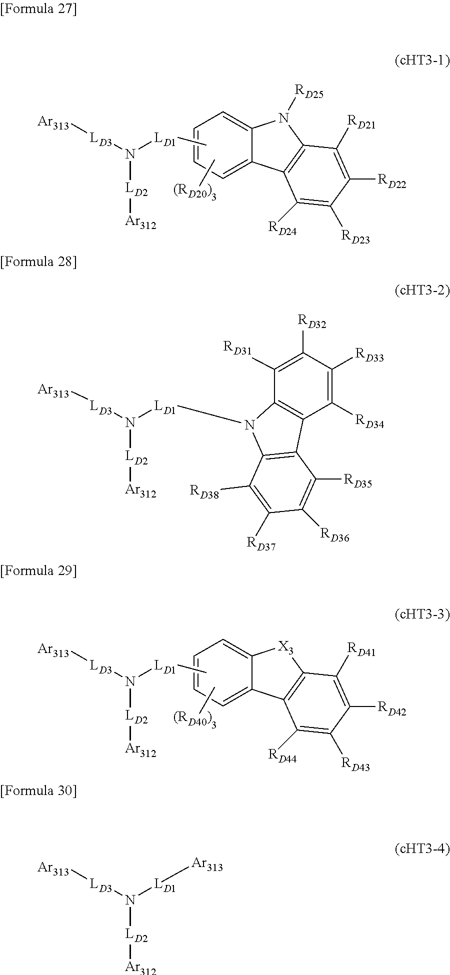

In the formulae (cHT3-1), (cHT3-2), (cHT3-3), and (cHT3-4):
Ar₃₁₂, Ar₃₁₃, L_{D1}, L_{D2}, and L_{D3} respectively represent the same as Ar₃₁₂, Ar₃₁₃, L_{D1}, L_{D2}, and L_{D3} in the formula (C1);
Ar₃₁₁ is a group represented by one of formulae (1-a), (1-b), (1-c), and (1-d) below;
at least one combination of adjacent two or more of R_{D20} to R_{D24} are mutually bonded to form a substituted or unsubstituted monocyclic ring, mutually bonded to form a substituted or unsubstituted fused ring, or not mutually bonded;
at least one combination of adjacent two or more of R_{D31} to R_{D38} are mutually bonded to form a substituted or unsubstituted monocyclic ring, mutually bonded to form a substituted or unsubstituted fused ring, or not mutually bonded;
at least one combination of adjacent two or more of R_{D40} to R_{D44} are mutually bonded to form a substituted or unsubstituted monocyclic ring, mutually bonded to form a substituted or unsubstituted fused ring, or not mutually bonded;
X₃ is an oxygen atom, a sulfur atom, or C(R_{D45})(R_{D46});
a combination of R_{D45} and R_{D46} are mutually bonded to form a substituted or unsubstituted monocyclic ring, mutually bonded to form a substituted or unsubstituted fused ring, or not mutually bonded;
R_{D25}, and R_{D20} to R_{D24}, R_{D31} to R_{D38}, R_{D40} to R_{D44}, R_{D45} and R_{D46} forming neither the substituted or unsubstituted monocyclic ring nor the substituted or unsubstituted fused ring are each independently a hydrogen atom, or a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, a substituted or unsubstituted heterocyclic group having 5 to 50 ring atoms, a plurality of R_{D20} are mutually the same or different;
a plurality of R_{D40} are mutually the same or different;
R₉₀₁ to R₉₀₄ in the compounds represented by the formulae (cHT3-1), (cHT3-2), (cHT3-3), and (cHT3-4) are each independently a hydrogen atom, or a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

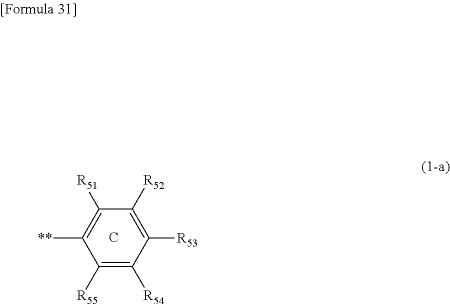

In the formula (1-a):
none of a combination(s) of adjacent two or more of R₅₁ to R₅₅ are bonded to each other;
R₅₁ to R₅₅ are each independently a hydrogen atom or a substituted or unsubstituted alkyl group having 1 to 6 carbon atoms; and
* represents a bonding position to L_{D1}.

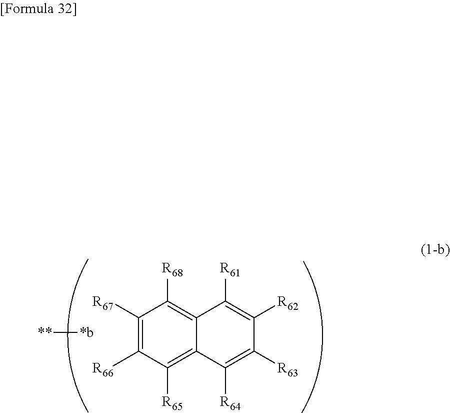

In the formula (1-b):
one of R₆₁ to R₆₈ is a single bond with *b;
none of a combination(s) of adjacent two or more of R₆₁ to R₆₈ not being the single bond with *b are bonded to each other;
R₆₁ to R₆₈ not being the single bond with *b are each independently a hydrogen atom, a substituted or unsubstituted alkyl group having 1 to 6 carbon atoms, or a substituted or unsubstituted aryl group having 6 to 12 ring carbon atoms; and
* represents a bonding position to L_{D1}.

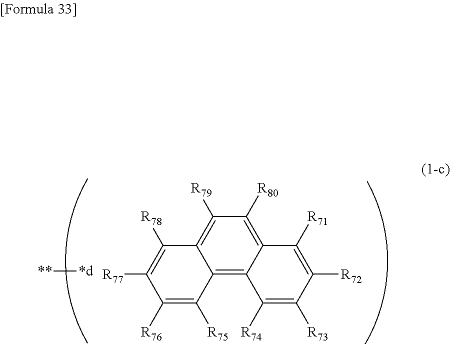

In the formula (1-c):
one of R₇₁ to R₈₀ is a single bond with *d;
none of a combination(s) of adjacent two or more of R₇₁ to R₈₀ not being the single bond with *d are bonded to each other;
R₇₁ to R₈₀ not being the single bond with * d each independently a hydrogen atom, a substituted or unsubstituted alkyl group having 1 to 6 carbon atoms, or a substituted or unsubstituted aryl group having 6 to 12 ring carbon atoms; and
* represents a bonding position to L_{D1}.

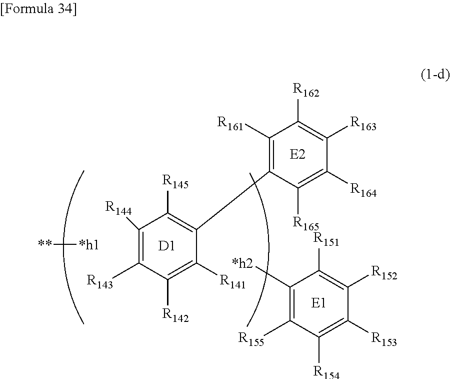

In the formula (1-d):
one of R₁₄₁ to R₁₄₅ is a single bond with *h1, and another one of R₁₄₁ to R₁₄₅ is a single bond with *h2;
none of a combination(s) of adjacent two or more of R₁₄₁ to R₁₄₅ not being the single bond with *h1 and not being the single bond with *h2 are bonded to each other;
at least one combination of adjacent two or more of R₁₅₁ to R₁₅₅ are mutually bonded to form a substituted or unsubstituted monocyclic ring, mutually bonded to form a substituted or unsubstituted fused ring, or not mutually bonded;
at least one combination of adjacent two or more of R₁₆₁ to R₁₆₅ are mutually bonded to form a substituted or unsubstituted monocyclic ring, mutually bonded to form a substituted or unsubstituted fused ring, or not mutually bonded;
R₁₄₁ to R₁₄₅ not being the single bond with *h1 and not being the single bond with *h2 as well as R₁₅₁ to R₁₅₅ and R₁₆₁ to R₁₆₅ forming neither the substituted or unsubstituted monocyclic ring nor the substituted or unsubstituted fused ring are each independently a hydrogen atom or a substituted or unsubstituted alkyl group having 1 to 6 carbon atoms, or a substituted or unsubstituted aryl group having 6 to 12 ring carbon atoms; and
* represents a bonding position to L_{D1}.

In an exemplary arrangement of the organic EL device of the exemplary embodiment, in the compounds represented by the formulae (cHT3-1), (cHT3-2), (cHT3-3), and (cHT3-4), the substituent for the “substituted or unsubstituted” group is not a group represented by —N(R_{C6})(R_{C7}).

In the exemplary embodiment, R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms. A plurality of R_{C6} are mutually the same or different, and a plurality of R_{C7} are mutually the same or different.

When the substituent for the “substituted or unsubstituted” group is not a group represented by —N(R_{C6})(R_{C7}), the compounds represented by the formulae (cHT3-1), (cHT3-2), (cHT3-3), and (cHT3-4) are each a monoamine compound.

In an exemplary arrangement of the organic EL device of the exemplary embodiment, the compound contained in the third anode side organic layer (third hole transporting zone material) is a diamine compound having two substituted or unsubstituted amino groups in a molecule.

In an exemplary arrangement of the organic EL device of the exemplary embodiment, the compound contained in the third anode side organic layer is a triamine compound having three substituted or unsubstituted amino groups in a molecule.

In an exemplary arrangement of the organic EL device of the exemplary embodiment, the compound contained in the third anode side organic layer is a tetraamine compound having four substituted or unsubstituted amino groups in a molecule.

When the compounds represented by the formulae (cHT3-1), (cHT3-2), (cHT3-3), and (cHT3-4) are each a diamine compound, the compounds represented by the formulae (cHT3-1), (cHT3-2), (cHT3-3), and (cHT3-4) each have one group represented by —N(R_{C6})(R_{C7}) as the substituent for the “substituted or unsubstituted” group.

When the compounds represented by the formulae (cHT3-1), (cHT3-2), (cHT3-3), and (cHT3-4) are each a triamine compound, the compounds represented by the formulae (cHT3-1) to (cHT3-2), (cHT3-3), and (cHT3-4) each have two groups represented by —N(R_{C6})(R_{C7}) as the substituents for the “substituted or unsubstituted” group.

When the compounds represented by the formulae (cHT3-1) to (cHT3-2), (cHT3-3), and (cHT3-4) are each a tetraamine compound, the compounds represented by the formulae (cHT3-1) to (cHT3-2), (cHT3-3), and (cHT3-4) each have three groups represented by —N(R_{C6})(R_{C7}) as the substituents for the “substituted or unsubstituted” group.

In an exemplary arrangement of the organic EL device of the exemplary embodiment, the third hole transporting zone material is at least one compound selected from the group consisting of a compound represented by the formula (cHT3-1), a compound represented by the formula (cHT3-2), a compound represented by the formula (cHT3-3), and a compound represented by the formula (cHT3-4).

In an exemplary arrangement of the organic EL device of the exemplary embodiment, the third hole transporting zone material is a monoamine compound, a diamine compound, a triamine compound, or a tetraamine compound.

In an exemplary arrangement of the organic EL device of the exemplary embodiment, the third hole transporting zone material is a monoamine compound having one substituted or unsubstituted amino group in a molecule.

In an exemplary arrangement of the organic EL device of the exemplary embodiment, the compound represented by the formula (C1) is a compound represented by a formula (C11) below.

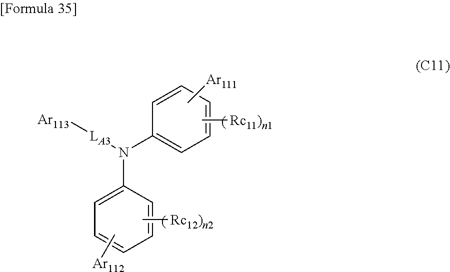

In the formula (C11):

Ar₁₁₁, Ar₁₁₂, Ar₁₁₃, and L_{A3} respectively represent the same as Ar₁₁₁, Ar₁₁₂, Ar₁₁₃, and L_{A3} in the formula (C1);
n1 and n2 are 4;
a plurality of R_{C11} are mutually the same or different;
at least one combination of adjacent two or more of a plurality of R_{C11} are mutually bonded to form a substituted or unsubstituted monocyclic ring, mutually bonded to form a substituted or unsubstituted fused ring, or not mutually bonded; and
a plurality of R_{C12} are mutually the same or different;
at least one combination of adjacent two or more of a plurality of R_{C12} are mutually bonded to form a substituted or unsubstituted monocyclic ring, mutually bonded to form a substituted or unsubstituted fused ring, or not mutually bonded; and
R_{C11} and R_{C12} forming neither the substituted or unsubstituted monocyclic ring nor the substituted or unsubstituted fused ring are each independently a hydrogen atom, or a cyano group, a substituted or unsubstituted alkyl group having 1 to 50 carbon atoms, a substituted or unsubstituted cycloalkyl group having 3 to 50 ring carbon atoms, —Si(R₉₀₁)(R₉₀₂)(R₉₀₃), —O—(R₉₀₄), a substituted or unsubstituted aryl group having 6 to 50 ring carbon atoms, a substituted or unsubstituted heterocyclic group having 5 to 50 ring atoms.

In the compound represented by the formula (C1), at least one of Ar₃₁₁, Ar₃₁₂, or Ar₃₁₃ is preferably a group selected from the group consisting of groups represented by formulae (21a), (21b), (21c), (21d), and (21e) below.

In the compound represented by the formula (C11), at least one of Ar₁₁₁, Ar₁₁₂, or Ar₁₁₃ is preferably a group selected from the group consisting of groups represented by formulae (21a), (21b), (21c), (21d), and (21e) below.

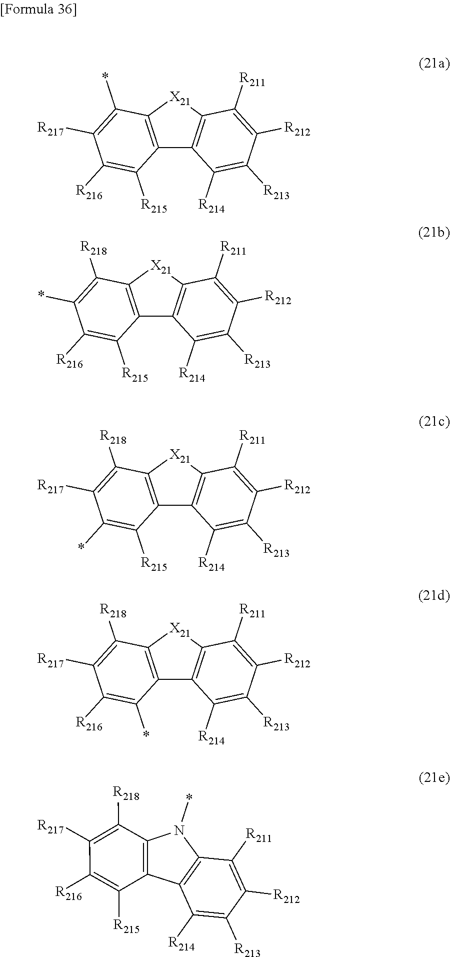

In the formulae (21a), (21b), (21c), (21d), and (21e):
X₂₁ is NR₂₁, CR₂₂R₂₃, an oxygen atom, or a sulfur atom;
when a plurality of X₂₁ are present, the plurality of X₂₁ are mutually the same or different;
when X₂₁ is CR₂₂R₂₃, a combination of R₂₂ and R₂₃ are mutually bonded to form a substituted or unsubstituted monocyclic ring, mutually bonded to form a substituted or unsubstituted fused ring, or not mutually bonded;
R₂₁, and R₂₂ and R₂₃ forming neither the substituted or unsubstituted monocyclic ring nor the substituted or unsubstituted fused ring are each independently a hydrogen atom, or a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, a substituted or unsubstituted heterocyclic group having 5 to 50 ring atoms, at least one combination of adjacent two or more of R₂₁₁ to R₂₁₈ are mutually bonded to form a substituted or unsubstituted monocyclic ring, mutually bonded to form a substituted or unsubstituted fused ring, or not mutually bonded; and
R₂₁₁ to R₂₁₈ forming neither the substituted or unsubstituted monocyclic ring nor the substituted or unsubstituted fused ring are each independently a hydrogen atom, or a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, a substituted or unsubstituted heterocyclic group having 5 to 50 ring atoms, * in the formulae (21a), (21b), (21c), (21d), and (21e) each independently represent a bonding position to L_{A1}, L_{A2}, and L_{A3}.

Ar₁₁₁, Ar₁₁₂, and Ar₁₁₃ not being the group selected from the group consisting of groups represented by the formulae (21a), (21b), (21c), (21d) and (21e) are preferably each independently a substituted or unsubstituted aryl group having 6 to 30 ring carbon atoms, more preferably a substituted or unsubstituted phenyl group or a substituted or unsubstituted biphenyl group.

In the compound represented by the formula (C1), it is also preferable that two of Ar₃₁₁, Ar₃₁₂, and Ar₃₁₃ are each a group selected from the group consisting of groups represented by the formulae (21a), (21b), (21c), (21d), and (21e), and a remaining one of Ar₃₁₁, Ar₃₁₂, and Ar₃₁₃ is a substituted or unsubstituted aryl group having 6 to 30 ring carbon atoms.

In the compound represented by the formula (C11), it is also preferable that two of Ar₁₁₁, Ar₁₁₂, and Ar₁₁₃ are each a group selected from the group consisting of groups represented by the formulae (21a), (21b), (21c), (21d), and (21e), and a remaining one of Ar₁₁₁, Ar₁₁₂, and Ar₁₁₃ is a substituted or unsubstituted aryl group having 6 to 30 ring carbon atoms.

In the compound represented by the formula (C1), it is also preferable that one of Ar₃₁₁, Ar₃₁₂, and Ar₃₁₃ is a group selected from the group consisting of groups represented by the formulae (21a), (21 b), (21c), (21d), and (21e), and remaining two of Ar₃₁₁, Ar₃₁₂, and Ar₃₁₃ are each a substituted or unsubstituted aryl group having 6 to 30 ring carbon atoms.

In the compound represented by the formula (C11), it is also preferable that one of Ar₁₁₁, Ar₁₁₂, and Ar₁₁₃ is a group selected from the group consisting of groups represented by the formulae (21a), (21 b), (21c), (21d), and (21e), and remaining two of Ar₁₁₁, Ar₁₁₂, and Ar₁₁₃ are each a substituted or unsubstituted aryl group having 6 to 30 ring carbon atoms.

In an exemplary arrangement of the organic EL device of the exemplary embodiment, the second hole transporting zone material and the third hole transporting zone material are different compounds.

In an exemplary arrangement of the organic EL device of the exemplary embodiment, a hole mobility of the second hole transporting zone material μh(cHT2) is larger than 1.0×10⁴ cm²/Vs.

In an exemplary arrangement of the organic EL device of the exemplary embodiment, the hole mobility of the second hole transporting zone material μh(cHT2) is larger than the hole mobility of the third hole transporting zone material μh(cHT3).

In an exemplary arrangement of the organic EL device of the exemplary embodiment, an energy level of the highest occupied molecular orbital of the second hole transporting zone material HOMO(cHT2) and the energy level of the highest occupied molecular orbital of the third hole transporting zone material HOMO(cHT3) satisfy a relationship of a numerical formula (Numerical Formula B1) below.

HOMO(cHT2)<HOMO(cHT3) . . . (Numerical Formula B1)

In an exemplary arrangement of the organic EL device of the exemplary embodiment, the hole mobility of the second hole transporting zone material μh(cHT2) is larger than 1.0×10⁴ cm²/Vs, the hole mobility of the third hole transporting zone material μh(cHT3) is larger than 1.0×10⁻⁵ cm²/Vs, and the energy level of the highest occupied molecular orbital of the second hole transporting zone material HOMO(cHT2) and the energy level of the highest occupied molecular orbital of the third hole transporting zone material HOMO(cHT3) satisfy the relationship of the numerical formula (Numerical Formula B1).

In an exemplary arrangement of the organic EL device of the exemplary embodiment, the second hole transporting zone material is a compound represented by the formula (C1) or a compound represented by the formula (C3).

In an exemplary arrangement of the organic EL device of the exemplary embodiment, although both the second anode side organic layer and the third anode side organic layer may contain a compound represented by the formula (C1), the compound contained in the second anode side organic layer and the compound contained in the third anode side organic layer are mutually different in a molecular structure.

In an exemplary arrangement of the organic EL device of the exemplary embodiment, although both the second anode side organic layer and the third anode side organic layer may contain a compound represented by the formula (C3), the compound contained in the second anode side organic layer and the compound contained in the third anode side organic layer are mutually different in a molecular structure.

In an exemplary arrangement of the organic EL device of the exemplary embodiment, the second hole transporting zone material contained in the second anode side organic layer is at least one compound selected from the group consisting of a compound represented by the formula (cHT2-1), a compound represented by the formula (cHT2-2), and a compound represented by the formula (cHT2-3).

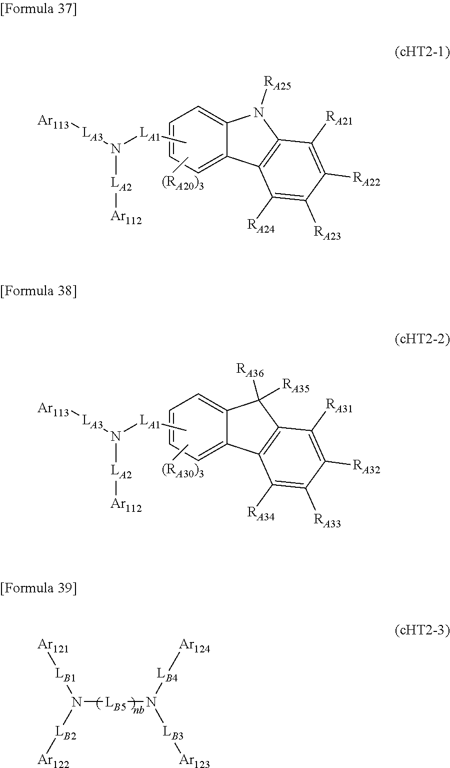

In the formulae (cHT2-1), (cHT2-2), and (cHT2-3):

Ar₁₁₂, Ar₁₁₃, Ar₁₂₁, Ar₁₂₂, Ar₁₂₃, and Ar₁₂₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different;
L_{A1}, L_{A2}, L_{A3}, L_{B1}, L_{B2}, L_{B3}, and L_{B4} are each independently a single bond, a substituted or unsubstituted arylene group having 6 to 50 ring carbon atoms, or a substituted or unsubstituted divalent heterocyclic group having 5 to 50 ring atoms;
nb is 1, 2, 3 or 4;
when nb is 1, L_{B5} is a substituted or unsubstituted arylene group having 6 to 50 ring carbon atoms, or a substituted or unsubstituted divalent heterocyclic group having 5 to 50 ring atoms;
when nb is 2, 3, or 4, a plurality of L_{B5} are mutually the same or different;
when nb is 2, 3, or 4, a plurality of L_{B5} are mutually bonded to form a substituted or unsubstituted monocyclic ring, mutually bonded to form a substituted or unsubstituted fused ring, or not mutually bonded;
L_{B5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
a combination of R_{A35} and R_{A36} are mutually bonded to form a substituted or unsubstituted monocyclic ring, mutually bonded to form a substituted or unsubstituted fused ring, or not mutually bonded;
R_{A25}, and R_{A35} and R_{A36} forming neither the substituted or unsubstituted monocyclic ring nor the substituted or unsubstituted fused ring are each independently a hydrogen atom, or a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, a substituted or unsubstituted heterocyclic group having 5 to 50 ring atoms, at least one combination of adjacent two or more of R_{A20} to R_{A24} are mutually bonded to form a substituted or unsubstituted monocyclic ring, mutually bonded to form a substituted or unsubstituted fused ring, or not mutually bonded;
at least one combination of adjacent two or more of R_{A30} to R_{A34} are mutually bonded to form a substituted or unsubstituted monocyclic ring, mutually bonded to form a substituted or unsubstituted fused ring, or not mutually bonded;
R_{A20} to R_{A24} and R_{A30} to R_{A34} forming neither the substituted or unsubstituted monocyclic ring nor the substituted or unsubstituted fused ring are each independently a hydrogen atom, or a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, a substituted or unsubstituted heterocyclic group having 5 to 50 ring atoms, a plurality of R_{A20} are mutually the same or different;
a plurality of R_{A30} are mutually the same or different;
R₉₀₁ to R₉₀₄ in the compounds represented by the formulae (cHT2-1), (cHT2-2), and (cHT2-3) are each independently a hydrogen atom, or a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

In an exemplary arrangement of the organic EL device of the exemplary embodiment, a first amino group represented by a formula (c21) below and a second amino group represented by a formula (c22) below in the compound represented by the formula (cHT2-3) are the same or different.

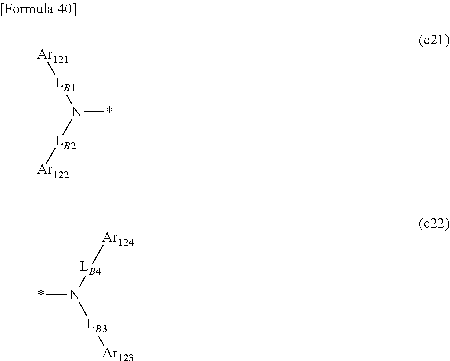

In the formulae (c21) and (c22), each * represents a bonding position to L_{B5}.

In an exemplary arrangement of the organic EL device of the exemplary embodiment, the second anode side organic layer contains at least one compound selected from the group consisting of a compound represented by the formula (cHT2-1), a compound represented by the formula (cHT2-2), and a compound represented by the formula (cHT2-3), and the third anode side organic layer contains at least one compound selected from the group consisting of a compound represented by the formula (cHT3-1), a compound represented by the formula (cHT3-2), a compound represented by the formula (cHT3-3), and a compound represented by the formula (cHT3-4).

In an exemplary arrangement of the organic EL device of the exemplary embodiment, in the compounds represented by the formulae (cHT2-1), (cHT2-2), and (cHT2-3), the substituent for the “substituted or unsubstituted” group is not a group represented by —N(R_{C6})(R_{C7}).

In the exemplary embodiment, R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms. A plurality of R_{C6} are mutually the same or different, and a plurality of R_{C7} are mutually the same or different.

When the substituent for the “substituted or unsubstituted” group is not a group represented by —N(R_{C6})(R_{C7}), the compounds represented by the formulae (cHT2-1) and (cHT2-2) are each a monoamine compound.

When the substituent for the “substituted or unsubstituted” group is not a group represented by —N(R_{C6})(R_{C7}), the compound represented by the formula (cHT2-3) is a diamine compound.

In an exemplary arrangement of the organic EL device of the exemplary embodiment, the second hole transporting zone material contained in the second anode side organic layer is a diamine compound having two substituted or unsubstituted amino groups in a molecule.

In an exemplary arrangement of the organic EL device of the exemplary embodiment, the second hole transporting zone material contained in the second anode side organic layer is a monoamine compound.

In the monoamine compound and the diamine compound, a nitrogen atom of an amino group is not an atom forming a ring (i.e., a ring atom). When a nitrogen atom is a ring atom in a carbazole ring, an azine ring and the like, the nitrogen atom is not a nitrogen atom as an amino group.

For instance, a compound HT-X below has two nitrogen atoms in a molecule: one nitrogen atom in the compound HT-X is a ring atom of a carbazole ring and the other nitrogen atom is not a ring atom but a nitrogen atom as an amino group. The compound HT-X is a compound having a structure in which 9-phenyl-3-carbazolyl group is bonded to a nitrogen atom of an amino group via a linking group, that is, a monoamine compound.

A compound HT-Y below is also a compound having a structure in which 9-carbazolyl group is bonded to a nitrogen atom of an amino group via a linking group, that is, a monoamine compound.

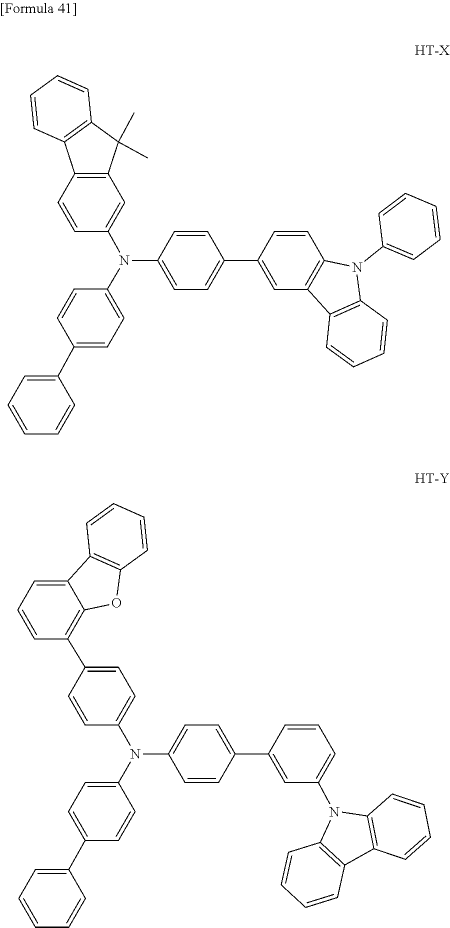 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

In an exemplary arrangement of the organic EL device of the exemplary embodiment, the second hole transporting zone material is a triamine compound having three substituted or unsubstituted amino groups in a molecule.

In an exemplary arrangement of the organic EL device of the exemplary embodiment, the second hole transporting zone material is a tetraamine compound having four substituted or unsubstituted amino groups in a molecule.

When the compounds represented by the formulae (cHT2-1) and (cHT2-2) are each a triamine compound, the compounds represented by the formulae (cHT2-1) and (cHT2-2) each have two groups represented by —N(R_{C6})(R_{C7}) as the substituents for the “substituted or unsubstituted” group.

When the compounds represented by the formulae (cHT2-1) and (cHT2-2) are each a tetraamine compound, the compounds represented by the formulae (cHT2-1) and (cHT2-2) each have three groups represented by —N(R_{C6})(R_{C7}) as the substituents for the “substituted or unsubstituted” group.

When the compound represented by the formula (cHT2-3) is a triamine compound, the compound represented by the formula (cHT2-3) has one group represented by —N(R_{C6})(R_{C7}) as the substituent for the “substituted or unsubstituted” group.

When the compound represented by the formula (cHT2-3) is a tetraamine compound, the compound represented by the formula (cHT2-3) has two groups represented by —N(R_{C6})(R_{C7}) as the substituents for the “substituted or unsubstituted” group.

In an exemplary arrangement of the organic EL device of the exemplary embodiment, the second hole transporting zone material contained in the second anode side organic layer has at least one group selected from the group consisting of a group represented by a formula (2-a), a group represented by a formula (2-b), a group represented by a formula (2-c), a group represented by a formula (2-d), a group represented by a formula (2-e), and a group represented by a formula (2-f) below.

In an exemplary arrangement of the organic EL device of the exemplary embodiment, the second hole transporting zone material contained in the second anode side organic layer is a monoamine compound having one substituted or unsubstituted amino group in a molecule, and the group represented by the formula (2-a), the group represented by the formula (2-b), the group represented by the formula (2-c), the group represented by the formula (2-d), the group represented by the formula (2-e), and the group represented by the formula (2-f) are each independently bonded directly, with a phenylene group, or with a biphenylene group to a nitrogen atom of an amino group of the monoamine compound.

In an exemplary arrangement of the organic EL device of the exemplary embodiment, the second hole transporting zone material contained in the second anode side organic layer is at least one compound selected from the group consisting of a compound represented by the formula (cHT2-1), a compound represented by the formula (cHT2-2), and a compound represented by the formula (cHT2-3), and at least one of Ar₁₁₂, Ar₁₁₃, Ar₁₂₁, Ar₁₂₂, Ar₁₂₃ or Ar₁₂₄ in the formulae (cHT2-1), (cHT2-2), and (cHT2-3) has at least one group selected from the group consisting of a group represented by the formula (2-a), a group represented by the formula (2-b), a group represented by the formula (2-c), a group represented by the formula (2-d), a group represented by the formula (2-e), and a group represented by the formula (2-f) below.

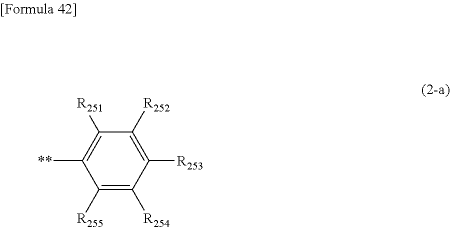

In the formula (2-a):
none of a combination(s) of adjacent two or more of R₂₅₁ to R₂₅₅ are bonded to each other;
R₂₅₁ to R₂₅₅ are each independently a hydrogen atom, or a substituted or unsubstituted alkyl group having 1 to 6 carbon atoms; and
* represents a bonding position.

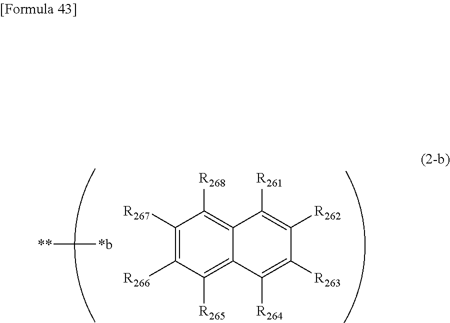

In the formula (2-b):
one of R₂₆₁ to R₂₆₈ is a single bond with *b;
none of a combination(s) of adjacent two or more of R₂₆₁ to R₂₆₈ not being the single bond with *b are bonded to each other;
R₂₆₁ to R₂₆₈ not being the single bond with *b are each independently a hydrogen atom, or a substituted or unsubstituted alkyl group having 1 to 6 carbon atoms, or a substituted or unsubstituted aryl group having 6 to 12 ring carbon atoms; and
* represents a bonding position.

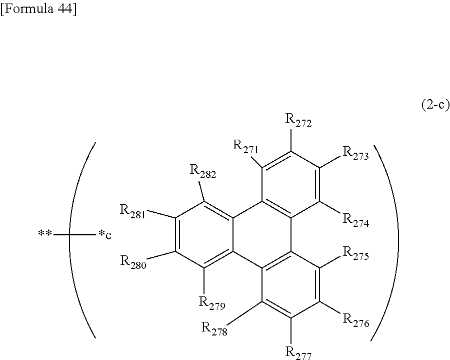

In the formula (2-c):
one of R₂₇₁ to R₂₈₂ is a single bond with *c;
none of a combination(s) of adjacent two or more of R₂₇₁ to R₂₈₂ not being the single bond with *c are bonded to each other;
R₂₇₁ to R₂₈₂ not being the single bond with *c are each independently a hydrogen atom, or a substituted or unsubstituted alkyl group having 1 to 6 carbon atoms, or a substituted or unsubstituted aryl group having 6 to 12 ring carbon atoms; and
* represents a bonding position.

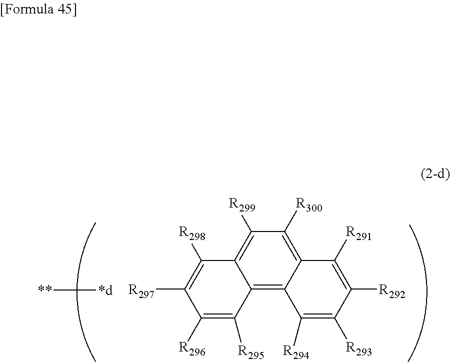

In the formula (2-d):
one of R₂₉₁ to R₃₀₀ is a single bond with *d;
none of a combination(s) of adjacent two or more of R₂₉₁ to R₃₀₀ not being the single bond with *d are bonded to each other;
R₂₉₁ to R₃₀₀ not being the single bond with *d are each independently a hydrogen atom, or a substituted or unsubstituted alkyl group having 1 to 6 carbon atoms, or a substituted or unsubstituted aryl group having 6 to 12 ring carbon atoms; and
* represents a bonding position.

For instance, ** may be a bonding position bonded to at least one of Ar₁₁₂, Ar₁₁₃, Ar₁₂₁, Ar₁₂₂, Ar₁₂₃, or Ar₁₂₄ in the formulae (cHT2-1), (cHT2-2) and (cHT2-3).

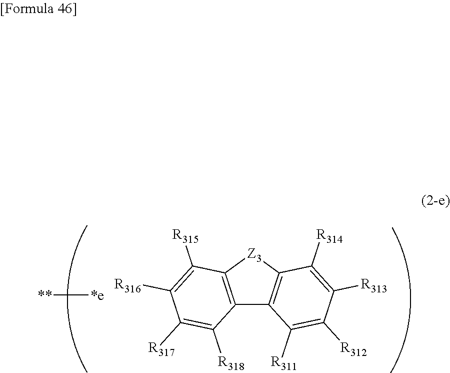

In the formula (2-e):
Z₃ is an oxygen atom, a sulfur atom, NR₃₁₉, or C(R₃₂₀)(R₃₂₁);
one of R₃₁₁ to R₃₂₁ is a single bond with *e, or one of carbon atoms of a substituted or unsubstituted benzene ring, described below, formed by mutually bonding a combination of adjacent two or more of R₃₁₁ to R₃₁₈ is bonded to *e by a single bond;
a combination of adjacent two or more of R₃₁₁ to R₃₁₈ not being the single bond with *e are mutually bonded to form a substituted or unsubstituted benzene ring, or not mutually bonded;
R₃₁₁ to R₃₁₈ not being the single bond with *e and not forming the substituted or unsubstituted benzene ring are each independently a hydrogen atom, or a substituted or unsubstituted alkyl group having 1 to 6 carbon atoms, a substituted or unsubstituted aryl group having 6 to 12 ring carbon atoms, a substituted or unsubstituted heterocyclic group having 5 to 10 ring atoms, R₃₁₉ not being the single bond with *e is a hydrogen atom, or a substituted or unsubstituted alkyl group having 1 to 6 carbon atoms, or a substituted or unsubstituted aryl group having 6 to 12 ring carbon atoms;
a combination of R₃₂₀ and R₃₂₁ not being the single bond with *e are mutually bonded to form a substituted or unsubstituted monocyclic ring, mutually bonded to form a substituted or unsubstituted fused ring, or not mutually bonded;
R₃₂₀ and R₃₂₁ not being the single bond with *e, not forming the substituted or unsubstituted monocyclic ring, and not forming the substituted or unsubstituted fused ring are each independently a hydrogen atom, or a substituted or unsubstituted alkyl group having 1 to 6 carbon atoms, or a substituted or unsubstituted aryl group having 6 to 12 ring carbon atoms; and
* represents a bonding position.

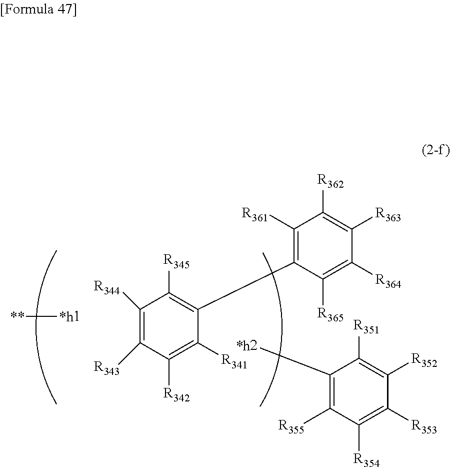

In the formula (2-f):
one of R₃₄₁ to R₃₄₅ is a single bond with *h1, and another one of R₃₄₁ to R₃₄₅ is a single bond with *h2;
none of a combination(s) of adjacent two or more of R₃₄₁ to R₃₄₅ not being the single bond with *h1 and not being the single bond with *h2 are bonded to each other;
at least one combination of adjacent two or more of R₃₅₁ to R₃₅₅ are mutually bonded to form a substituted or unsubstituted monocyclic ring, mutually bonded to form a substituted or unsubstituted fused ring, or not mutually bonded;
at least one combination of adjacent two or more of R₃₆₁ to R₃₆₅ are mutually bonded to form a substituted or unsubstituted monocyclic ring, mutually bonded to form a substituted or unsubstituted fused ring, or not mutually bonded;
R₃₄₁ to R₃₄₅ not being the single bond with *h1 and not being the single bond with *h2 as well as R₃₅₁ to R₃₅₅ and R₃₆₁ to R₃₆₅ forming neither the substituted or unsubstituted monocyclic ring nor the substituted or unsubstituted fused ring are each independently a hydrogen atom, or a substituted or unsubstituted alkyl group having 1 to 6 carbon atoms, or a substituted or unsubstituted aryl group having 6 to 12 ring carbon atoms; and
* represents a bonding position.

In an exemplary arrangement of the organic EL device of the exemplary embodiment, the group represented by the formula (2-a), the group represented by the formula (2-b), the group represented by the formula (2-c), the group represented by the formula (2-d), the group represented by the formula (2-e), and the group represented by the formula (2-f) are each independently bonded directly, with a phenylene group, or with a biphenylene group to a nitrogen atom of an amino group of the monoamine compound.

In the organic EL device of the exemplary embodiment, when Z₃ is NR₃₁₉, R₃₁₂ or R₃₁₇ is preferably a single bond with *e.

In an exemplary arrangement of the organic EL device of the exemplary embodiment, the group represented by the formula (2-e) is a group represented by a formula (2-e7) below.

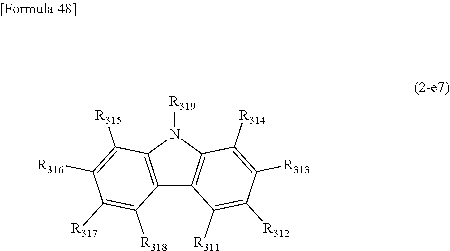

In the formula (2-e7), R₃₁₁ to R₃₁₆, R₃₁₈ and R₃₁₉ respectively represent the same as R₃₁₁ to R₃₁₆, R₃₁₈ and R₃₁₉ in the formula (2-e); and ** represents a bonding position.

In the organic EL device of the exemplary embodiment, when Z₃ is NR₃₁₉, R₃₁₅, R₃₁₆, or R₃₁₈ is also preferably a single bond with *e.

In an exemplary arrangement of the organic EL device of the exemplary embodiment, the group represented by the formula (2-e) is a group represented by a formula (2-e4), a formula (2-e5), or a formula (2-e6) below.

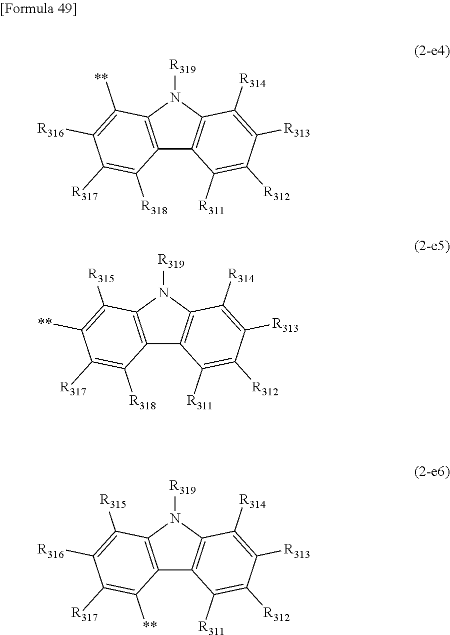

In the formulae (2-e4), (2-e5), and (2-e6), R₃₁₁ to R₃₁₉ respectively represent the same as R₃₁₁ to R₃₁₉ in the formula (2-e); and ** represents a bonding position.

In an exemplary arrangement of the organic EL device of the exemplary embodiment, the group represented by the formula (2-e) is a group represented by a formula (2-e1), a formula (2-e2), or a formula (2-e3) below.

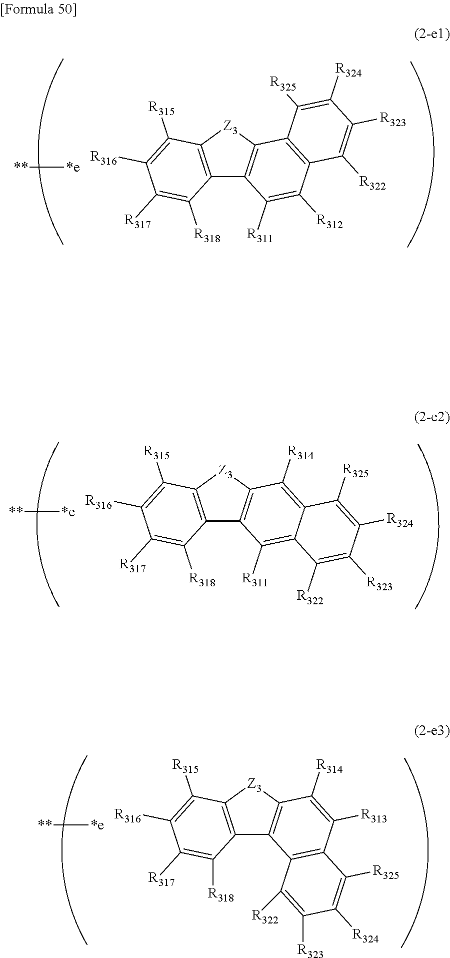

In the formulae (2-e1), (2-e2), and (2-e3):
Z₃ is an oxygen atom, a sulfur atom, NR₃₁₉, or C(R₃₂₀)(R₃₂₁),
one of R₃₁₁ to R₃₂₅ is a single bond with *e;
R₃₁₁ to R₃₁₈ and R₃₂₂ and R₃₂₅ not being the single bond with *e are each independently a hydrogen atom, or a substituted or unsubstituted alkyl group having 1 to 6 carbon atoms, a substituted or unsubstituted aryl group having 6 to 12 ring carbon atoms, a substituted or unsubstituted heterocyclic group having 5 to 10 ring atoms, R₃₁₉ not being the single bond with *e is a hydrogen atom, or a substituted or unsubstituted alkyl group having 1 to 6 carbon atoms, or a substituted or unsubstituted aryl group having 6 to 12 ring carbon atoms;
a combination of R₃₂₀ and R₃₂₁ not being the single bond with *e are mutually bonded to form a substituted or unsubstituted monocyclic ring, mutually bonded to form a substituted or unsubstituted fused ring, or not mutually bonded;
R₃₂₀ and R₃₂₁ not being the single bond with *e, not forming the substituted or unsubstituted monocyclic ring, and not forming the substituted or unsubstituted fused ring are each independently a hydrogen atom, or a substituted or unsubstituted alkyl group having 1 to 6 carbon atoms, or a substituted or unsubstituted aryl group having 6 to 12 ring carbon atoms; and
* represents a bonding position.

In an exemplary arrangement of the organic EL device of the exemplary embodiment, the second hole transporting zone material contained in the second anode side organic layer is a compound having no thiophene ring in a molecule.

In an exemplary arrangement of the organic EL device of the exemplary embodiment, the first anode side organic layer contains a first hole transporting zone material.

In an exemplary arrangement of the organic EL device of the exemplary embodiment, the first hole transporting zone material and the third hole transporting zone material are different compounds.

In an exemplary arrangement of the organic EL device of the exemplary embodiment, the first hole transporting zone material and the second hole transporting zone material may be different compounds or the same compound. When the first hole transporting zone material and the second hole transporting zone material are the same compound, the first anode side organic layer preferably contains a compound (e.g., a doped compound) having a molecular structure different from that of the first hole transporting zone material, the second hole transporting zone material, and the third hole transporting zone material.

In an exemplary arrangement of the organic EL device of the exemplary embodiment, the first anode side organic layer contains a first organic material and a second organic material. The second organic material is preferably the first hole transporting zone material. The first organic material is preferably a doped compound.

In an exemplary arrangement of the organic EL device of the exemplary embodiment, the first anode side organic layer contains a doped compound as the first organic material and the first hole transporting zone material as the second organic material.

In an exemplary arrangement of the organic EL device of the exemplary embodiment, the second organic material contained in the first anode side organic layer is at least one compound selected from the group consisting of a compound represented by the formula (cHT2-1), a compound represented by the formula (cHT2-2), and a compound represented by the formula (cHT2-3).

In an exemplary arrangement of the organic EL device of the exemplary embodiment, the second organic material contained in the first anode side organic layer is a monoamine compound.

In an exemplary arrangement of the organic EL device of the exemplary embodiment, the second organic material contained in the first anode side organic layer has at least one group selected from the group consisting of a group represented by the formula (2-a), a group represented by the formula (2-b), a group represented by the formula (2-c), a group represented by the formula (2-d), a group represented by the formula (2-e), and a group represented by the formula (2-f) below.

In an exemplary arrangement of the organic EL device of the exemplary embodiment, the second organic material contained in the first anode side organic layer is a monoamine compound having one substituted or unsubstituted amino group in a molecule, and the group represented by the formula (2-a), the group represented by the formula (2-b), the group represented by the formula (2-c), the group represented by the formula (2-d), the group represented by the formula (2-e), and the group represented by the formula (2-f) are each independently bonded directly, with a phenylene group, or with a biphenylene group to a nitrogen atom of an amino group of the monoamine compound.

In an exemplary arrangement of the organic EL device of the exemplary embodiment, the second organic material is one compound selected from the group consisting of a compound represented by the formula (cHT2-1) and a compound represented by the formula (cHT2-2).

In an exemplary arrangement of the organic EL device of the exemplary embodiment, the compound represented by the formula (cHT2-1) and the compound represented by the formula (cHT2-2) as the second organic material are each a monoamine compound.

In an exemplary arrangement of the organic EL device of the exemplary embodiment, the second organic material contained in first anode side organic layer is a diamine compound having two substituted or unsubstituted amino groups in a molecule.

In an exemplary arrangement of the organic EL device of the exemplary embodiment, the compound represented by the formula (cHT2-3) is a diamine compound.

In an exemplary arrangement of the organic EL device of the exemplary embodiment, the second organic material is a triamine compound having three substituted or unsubstituted amino groups in a molecule.

In an exemplary arrangement of the organic EL device of the exemplary embodiment, the second organic material is a tetraamine compound having four substituted or unsubstituted amino groups in a molecule.

When the compounds represented by the formulae (cHT2-1) and (cHT2-2) are each a triamine compound, the compounds represented by the formulae (cHT2-1) and (cHT2-2) each have two groups represented by —N(R_{C6})(R_{C7}) as the substituents for the “substituted or unsubstituted” group.

When the compounds represented by the formulae (cHT2-1) and (cHT2-2) are each a tetraamine compound, the compounds represented by the formulae (cHT2-1) and (cHT2-2) each have three groups represented by —N(R_{C6})(R_{C7}) as the substituents for the “substituted or unsubstituted” group.

When the compound represented by the formula (cHT2-3) is a triamine compound, the compound represented by the formula (cHT2-3) has one group represented by —N(R_{C6})(R_{C7}) as the substituent for the “substituted or unsubstituted” group.

When the compound represented by the formula (cHT2-3) is a tetraamine compound, the compound represented by the formula (cHT2-3) has two groups represented by —N(R_{C6})(R_{C7}) as the substituents for the “substituted or unsubstituted” group.

In an exemplary arrangement of the organic EL device of the exemplary embodiment, the second organic material is at least one compound selected from the group consisting of a compound represented by the formula (cHT2-1), a compound represented by the formula (cHT2-2), and a compound represented by the formula (cHT2-3), and at least one of Ar₁₁₂, Ar₁₁₃, Ar₁₂₁, Ar₁₂₂, Ar₁₂₃ or Ar₁₂₄ in the formulae (cHT2-1), (cHT2-2), and (cHT2-3) has at least one group selected from the group consisting of a group represented by a formula (2-a), a group represented by a formula (2-b), a group represented by a formula (2-c), a group represented by a formula (2-d), a group represented by a formula (2-e), and a group represented by a formula (2-f) below.

In an exemplary arrangement of the organic EL device of the exemplary, when the first anode side organic layer contains the first hole transporting zone material (second organic material) and the doped compound (first organic material), a content of the first organic material in the first anode side organic layer is 15 mass % or less.

In an exemplary arrangement of the organic EL device of the exemplary embodiment, the content of the first organic material in the first anode side organic layer is 5 mass % or more.

In an exemplary arrangement of the organic EL device of the exemplary embodiment, when the first anode side organic layer contains the first hole transporting zone material and the doped compound (first organic material), the content of the doped compound in the first anode side organic layer is preferably in a range from 0.5 mass % to 5 mass %, more preferably in a range from 1.0 mass % to 3 mass %. The content of the first hole transporting zone material in the first anode side organic layer is preferably 40 mass % or more, more preferably 45 mass % or more, and still more preferably 50 mass % or more. The content of the first hole transporting zone material in the first anode side organic layer is preferably 99.5 mass % or less. The total of a content of the first hole transporting zone material and a content of the doped compound in the first anode side organic layer is 100 mass % or less.

In an exemplary arrangement of the organic EL device of the exemplary embodiment, the doped compound has at least one of a first cyclic structure represented by a formula (P11) below or a second cyclic structure represented by a formula (P12) below.

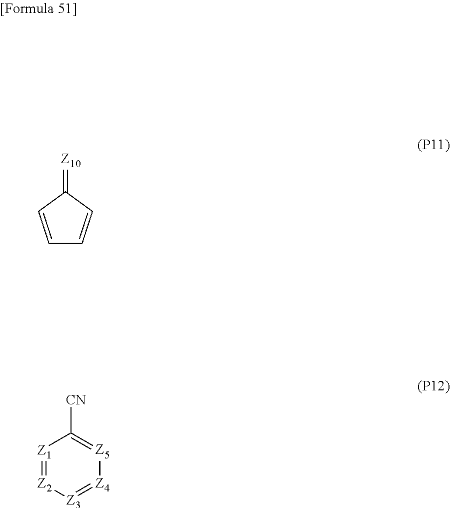

The first cyclic structure represented by the formula (P11) is fused to at least one cyclic structure of a substituted or unsubstituted aromatic hydrocarbon ring having 6 to 50 ring carbon atoms or a substituted or unsubstituted heterocycle having 5 to 50 ring atoms in a molecule of the doped compound.

A structure represented by =Z₁₀ is represented by a formula (11a), (11b), (11 c), (11 d), (11 e), (11f), (11 g), (11 h), (11 i), (11j), (11 k), or (11 m).

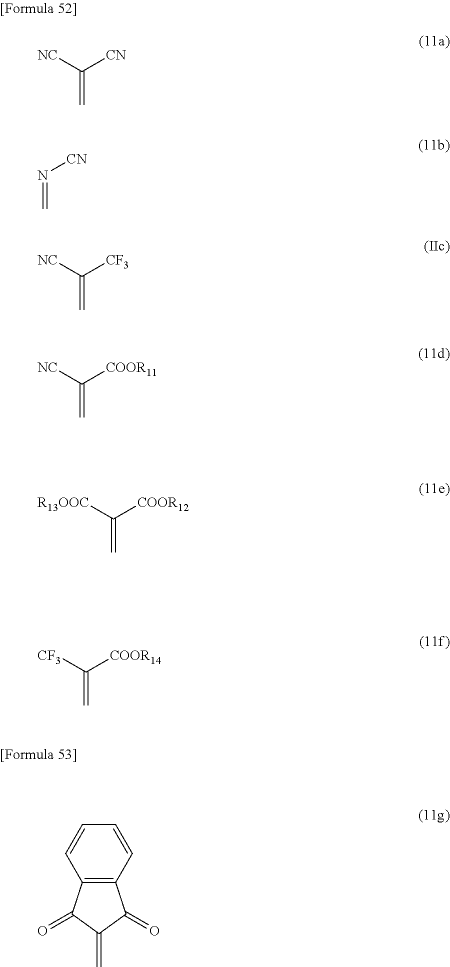

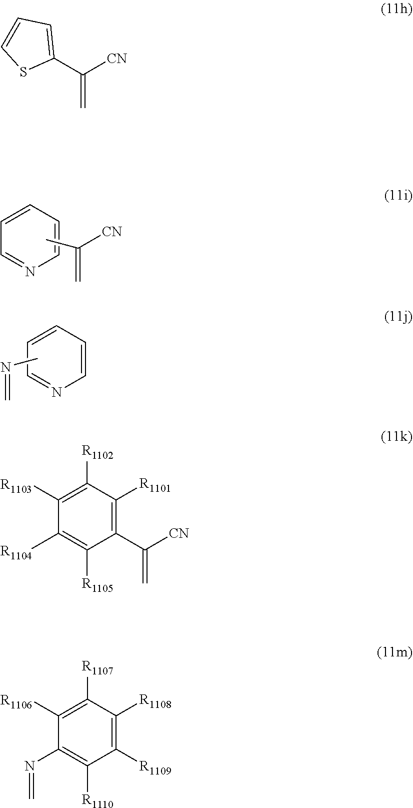

In the formulae (11 a), (11 b), (11 c), (11 d), (11 e), (11f), (11 g), (11 h), (11 i), (11j), (11k), or (11m): R₁₁ to R₁₄ and R₁₁₀₁ to R₁₁₁₀ are each independently a hydrogen atom, or a halogen atom, a hydroxy group, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, a substituted or unsubstituted heterocyclic group having 5 to 50 ring atoms. In the formula (P12): Z₁ to Z₅ are each independently a nitrogen atom, a carbon atom bonded to R₁₅, or a carbon atom bonded to another atom in a molecule of the doped compound;
at least one of Z₁ to Z₅ is a carbon atom bonded to another atom in a molecule of the doped compound;
R₁₅ is a hydrogen atom, or a halogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted alkenyl group having 2 to 50 carbon atoms, a substituted or unsubstituted aralkyl group having 7 to 50 carbon atoms, a carboxy group, a substituted or unsubstituted ester group, a substituted or unsubstituted carbamoyl group, a nitro group, and a substituted or unsubstituted siloxanyl group; and
when a plurality of R₁₅ are present, the plurality of R₁₅ are mutually the same or different.

In the doped compound, R₉₀₁ to R₉₀₇ are each independently a hydrogen atom, or a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, when a plurality of R₉₀₁ are present, the plurality of R₉₀₁ are mutually the same or different; when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

An ester group herein is at least one group selected from the group consisting of an alkyl ester group and an aryl ester group.

An alkyl ester group herein is represented, for instance, by —C(═O)OR^{E}. R^{E} is exemplified by a substituted or unsubstituted alkyl group having 1 to 50 carbon atoms (preferably 1 to 10 carbon atoms).

An aryl ester group herein is represented, for instance, by —C(═O)OR^{Ar}. R^{Ar} is exemplified by a substituted or unsubstituted aryl group having 6 to 30 ring carbon atoms.

A siloxanyl group herein, which is a silicon compound group through an ether bond, is exemplified by a trimethylsiloxanyl group.

A carbamoyl group herein is represented by —CONH₂.

A substituted carbamoyl group herein is represented, for instance, by —CONH—Ar^{C} or —CONH—R^{C}. Ar^{C} is, for instance, at least one group selected from the group consisting of a substituted or unsubstituted aryl group having 6 to 50 ring carbon atoms (preferably 6 to 10 ring carbon atoms) and a heterocyclic group having 5 to 50 ring atoms (preferably 5 to 14 ring atoms). Ar^{C} may be a group in which a substituted or unsubstituted aryl group having 6 to 50 ring carbon atoms is bonded to a substituted or unsubstituted heterocyclic group having 5 to 50 ring atoms.

R^{C} is exemplified by a substituted or unsubstituted alkyl group having 1 to 50 carbon atoms (preferably 1 to 6 carbon atoms).

In the doped compound, all groups specified as “substituted or unsubstituted” groups are preferably “unsubstituted” groups.

### Specific Examples of Doped Compound

Specific examples of the doped compound include the following compounds. It should however be noted that the invention is not limited to the specific examples of the doped compound.

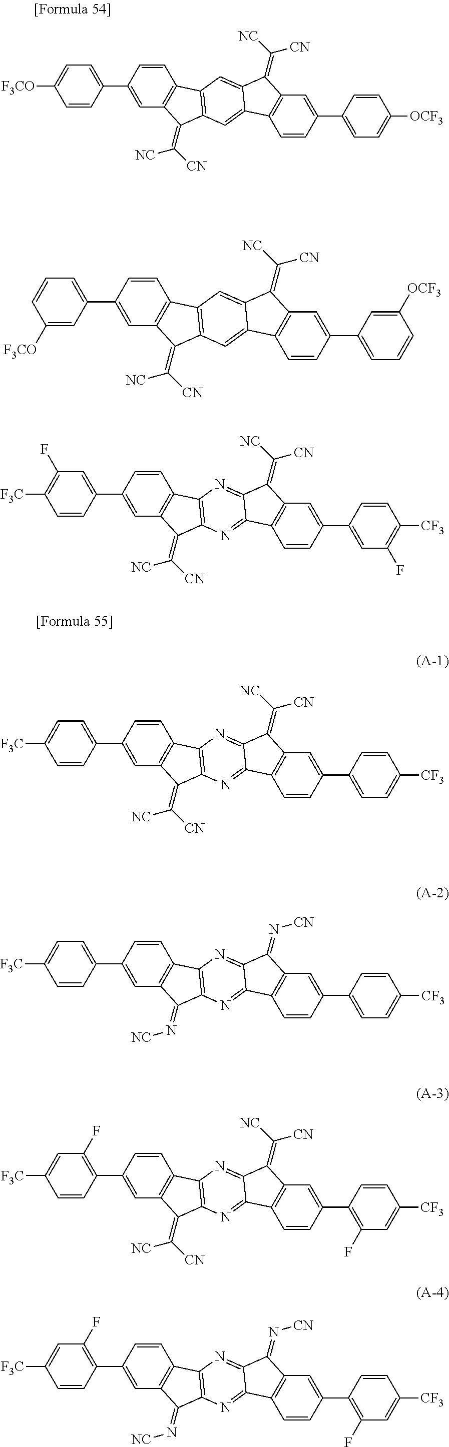

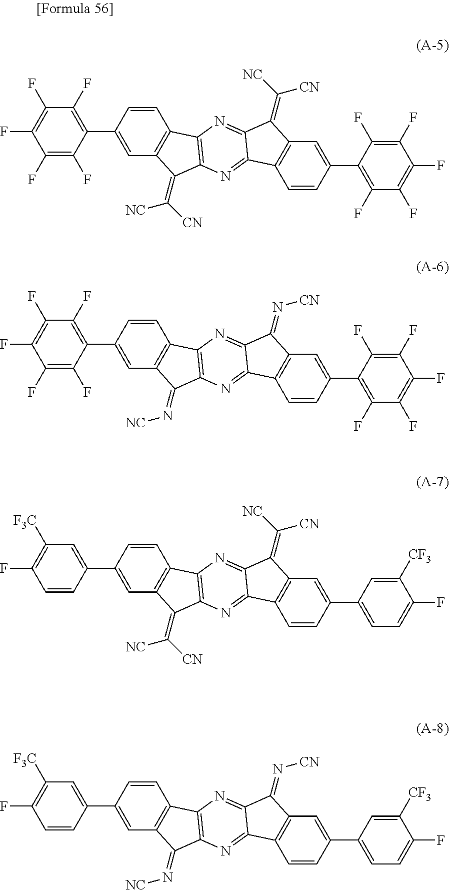 [SMILES: N#CC(C#N)=C1c2cc(-c3c(F)c(F)c(F)c(F)c3F)ccc2-c2nc3c(nc21)-c1ccc(-c2c(F)c(F)c(F)c(F)c2F)cc1C3=C(C#N)C#N ; N#C/N=c1\c2cc(-c3c(F)c(F)c(F)c(F)c3F)ccc2c2nc3/c(=N/C#N)c4cc(-c5c(F)c(F)c(F)c(F)c5F)ccc4c3nc12 ; N#CC(C#N)=C1c2cc(-c3ccc(F)c(C(F)(F)F)c3)ccc2-c2nc3c(nc21)-c1ccc(-c2ccc(F)c(C(F)(F)F)c2)cc1C3=C(C#N)C#N ; N#C/N=c1\c2cc(-c3ccc(F)c(C(F)(F)F)c3)ccc2c2nc3/c(=N/C#N)c4cc(-c5ccc(F)c(C(F)(F)F)c5)ccc4c3nc12]

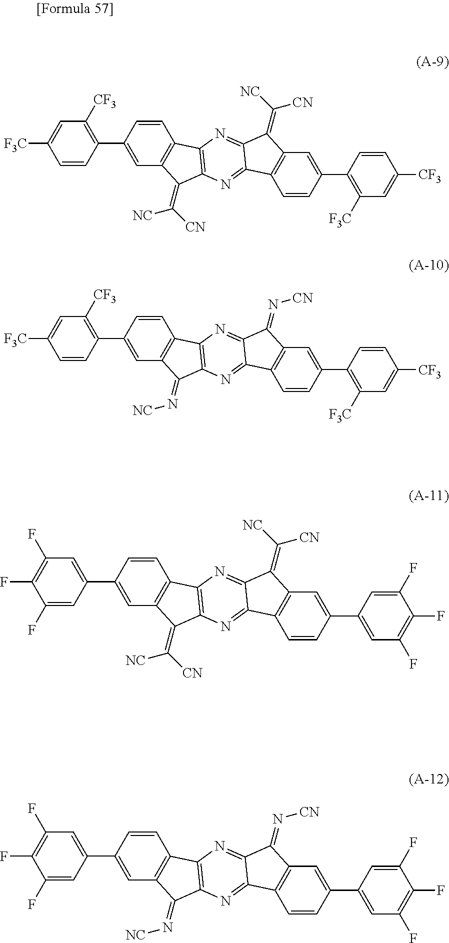 [SMILES: N#CC(C#N)=C1c2cc(-c3ccc(C(F)(F)F)cc3C(F)(F)F)ccc2-c2nc3c(nc21)-c1ccc(-c2ccc(C(F)(F)F)cc2C(F)(F)F)cc1C3=C(C#N)C#N ; N#C/N=c1\c2cc(-c3ccc(C(F)(F)F)cc3C(F)(F)F)ccc2c2nc3/c(=N/C#N)c4cc(-c5ccc(C(F)(F)F)cc5C(F)(F)F)ccc4c3nc12 ; N#CC(C#N)=C1c2cc(-c3cc(F)c(F)c(F)c3)ccc2-c2nc3c(nc21)-c1ccc(-c2cc(F)c(F)c(F)c2)cc1C3=C(C#N)C#N ; N#C/N=c1\c2cc(-c3cc(F)c(F)c(F)c3)ccc2c2nc3/c(=N/C#N)c4cc(-c5cc(F)c(F)c(F)c5)ccc4c3nc12]

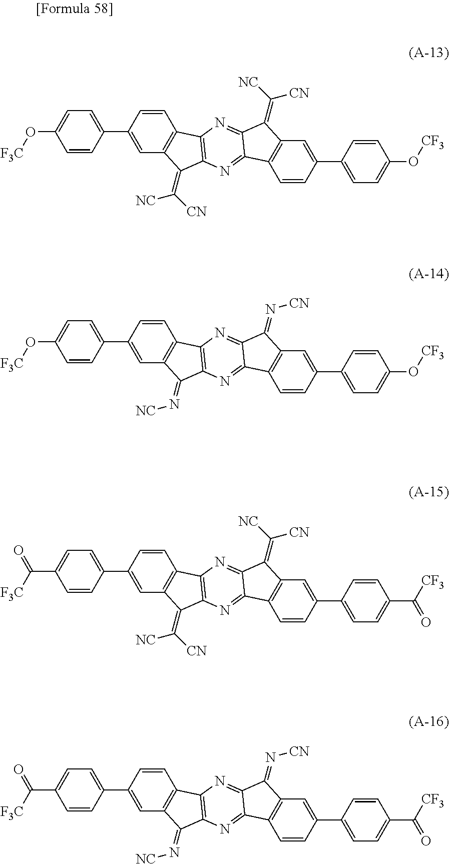 [SMILES: N#CC(C#N)=C1c2cc(-c3ccc(OC(F)(F)F)cc3)ccc2-c2nc3c(nc21)-c1ccc(-c2ccc(OC(F)(F)F)cc2)cc1C3=C(C#N)C#N ; N#C/N=c1\c2cc(-c3ccc(OC(F)(F)F)cc3)ccc2c2nc3/c(=N/C#N)c4cc(-c5ccc(OC(F)(F)F)cc5)ccc4c3nc12 ; N#CC(C#N)=C1c2cc(-c3ccc(C(=O)C(F)(F)F)cc3)ccc2-c2nc3c(nc21)-c1ccc(-c2ccc(C(=O)C(F)(F)F)cc2)cc1C3=C(C#N)C#N ; N#C/N=c1\c2cc(-c3ccc(C(=O)C(F)(F)F)cc3)ccc2c2nc3/c(=N/C#N)c4cc(-c5ccc(C(=O)C(F)(F)F)cc5)ccc4c3nc12]

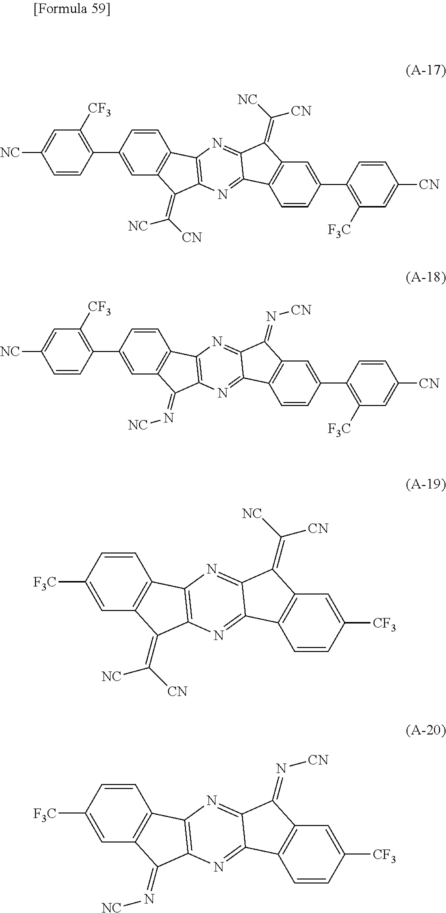 [SMILES: N#CC(C#N)=C1c2cc(-c3ccc(C#N)cc3C(F)(F)F)ccc2-c2nc3c(nc21)-c1ccc(-c2ccc(C#N)cc2C(F)(F)F)cc1C3=C(C#N)C#N ; N#C/N=c1\c2cc(-c3ccc(C#N)cc3C(F)(F)F)ccc2c2nc3/c(=N/C#N)c4cc(-c5ccc(C#N)cc5C(F)(F)F)ccc4c3nc12 ; N#CC(C#N)=C1c2cc(C(F)(F)F)ccc2-c2nc3c(nc21)-c1ccc(C(F)(F)F)cc1C3=C(C#N)C#N ; N#C/N=c1\c2cc(C(F)(F)F)ccc2c2nc3/c(=N/C#N)c4cc(C(F)(F)F)ccc4c3nc12]

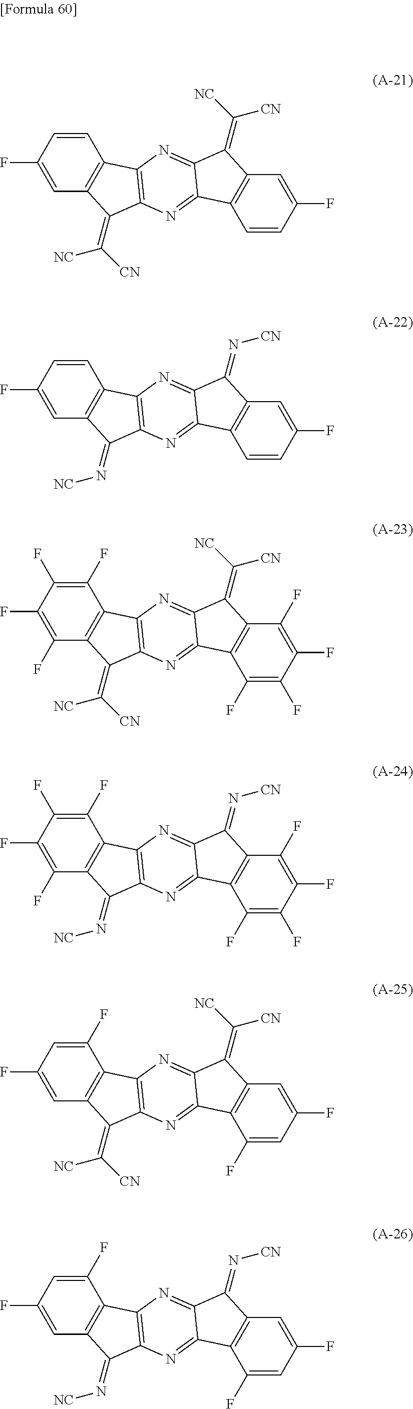 [SMILES: N#CC(C#N)=C1c2cc(F)ccc2-c2nc3c(nc21)-c1ccc(F)cc1C3=C(C#N)C#N ; N#C/N=c1\c2cc(F)ccc2c2nc3/c(=N/C#N)c4cc(F)ccc4c3nc12 ; N#CC(C#N)=C1c2nc3c(nc2-c2c(F)c(F)c(F)c(F)c21)C(=C(C#N)C#N)c1c(F)c(F)c(F)c(F)c1-3 ; N#C/N=c1/c2nc3c(nc2c2c(F)c(F)c(F)c(F)c12)/c(=N/C#N)c1c(F)c(F)c(F)c(F)c13 ; N#CC(C#N)=C1c2cc(F)cc(F)c2-c2nc3c(nc21)-c1c(F)cc(F)cc1C3=C(C#N)C#N ; N#C/N=c1\c2cc(F)cc(F)c2c2nc3/c(=N/C#N)c4cc(F)cc(F)c4c3nc12]

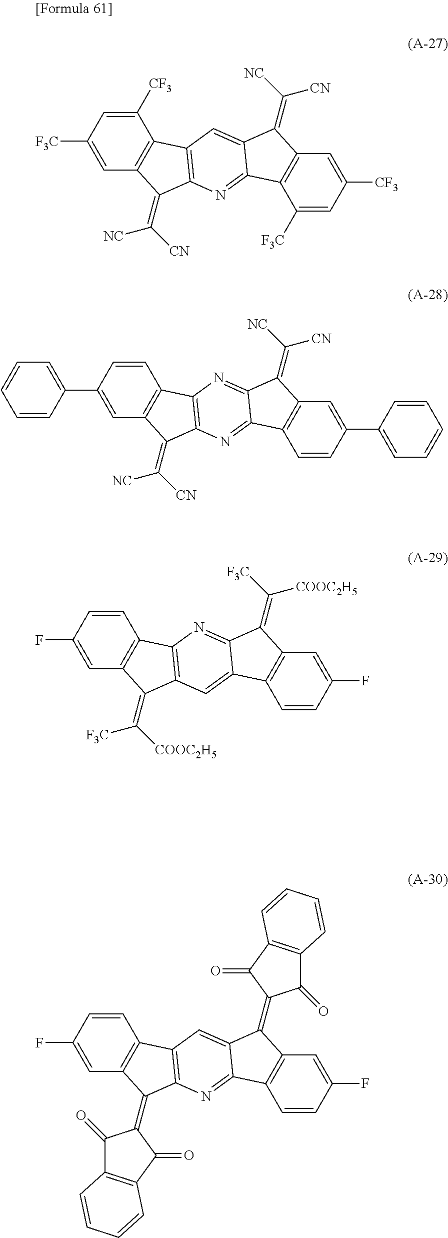

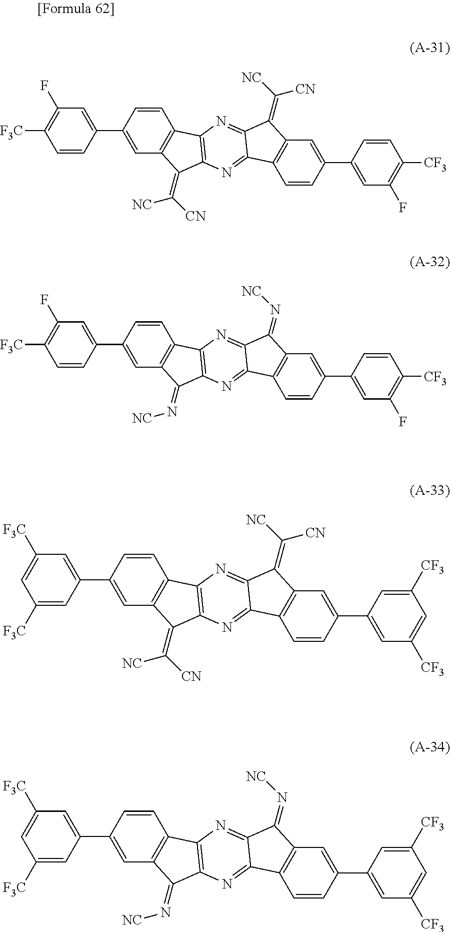 [SMILES: N#CC(C#N)=C1c2cc(-c3ccc(C(F)(F)F)c(F)c3)ccc2-c2nc3c(nc21)-c1ccc(-c2ccc(C(F)(F)F)c(F)c2)cc1C3=C(C#N)C#N ; N#C/N=c1/c2cc(-c3ccc(C(F)(F)F)c(F)c3)ccc2c2nc3/c(=N/C#N)c4cc(-c5ccc(C(F)(F)F)c(F)c5)ccc4c3nc12 ; N#CC(C#N)=C1c2cc(-c3cc(C(F)(F)F)cc(C(F)(F)F)c3)ccc2-c2nc3c(nc21)-c1ccc(-c2cc(C(F)(F)F)cc(C(F)(F)F)c2)cc1C3=C(C#N)C#N ; N#C/N=c1/c2cc(-c3cc(C(F)(F)F)cc(C(F)(F)F)c3)ccc2c2nc3/c(=N/C#N)c4cc(-c5cc(C(F)(F)F)cc(C(F)(F)F)c5)ccc4c3nc12]

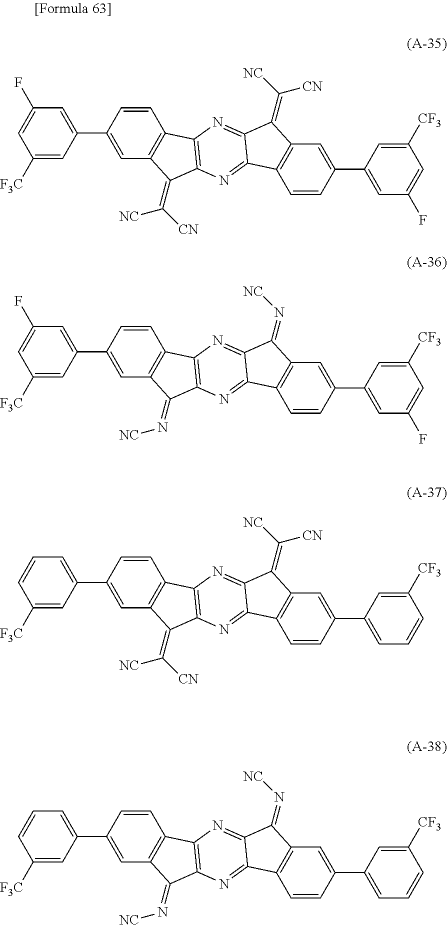 [SMILES: N#CC(C#N)=C1c2cc(-c3cc(F)cc(C(F)(F)F)c3)ccc2-c2nc3c(nc21)-c1ccc(-c2cc(F)cc(C(F)(F)F)c2)cc1C3=C(C#N)C#N ; N#C/N=c1/c2cc(-c3cc(F)cc(C(F)(F)F)c3)ccc2c2nc3/c(=N/C#N)c4cc(-c5cc(F)cc(C(F)(F)F)c5)ccc4c3nc12 ; N#CC(C#N)=C1c2cc(-c3cccc(C(F)(F)F)c3)ccc2-c2nc3c(nc21)-c1ccc(-c2cccc(C(F)(F)F)c2)cc1C3=C(C#N)C#N ; N#C/N=c1/c2cc(-c3cccc(C(F)(F)F)c3)ccc2c2nc3/c(=N/C#N)c4cc(-c5cccc(C(F)(F)F)c5)ccc4c3nc12]

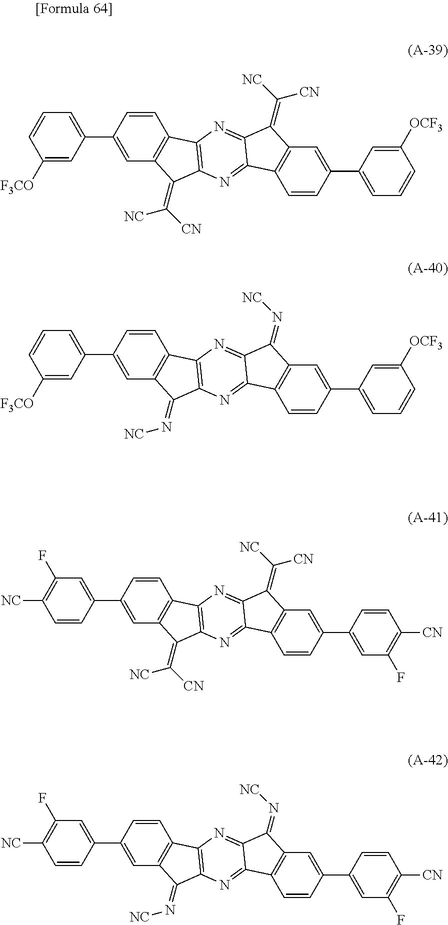 [SMILES: N#CC(C#N)=C1c2cc(-c3cccc(OC(F)(F)F)c3)ccc2-c2nc3c(nc21)-c1ccc(-c2cccc(OC(F)(F)F)c2)cc1C3=C(C#N)C#N ; N#C/N=c1/c2cc(-c3cccc(OC(F)(F)F)c3)ccc2c2nc3/c(=N/C#N)c4cc(-c5cccc(OC(F)(F)F)c5)ccc4c3nc12 ; N#CC(C#N)=C1c2cc(-c3ccc(C#N)c(F)c3)ccc2-c2nc3c(nc21)-c1ccc(-c2ccc(C#N)c(F)c2)cc1C3=C(C#N)C#N ; N#C/N=c1/c2cc(-c3ccc(C#N)c(F)c3)ccc2c2nc3/c(=N/C#N)c4cc(-c5ccc(C#N)c(F)c5)ccc4c3nc12]

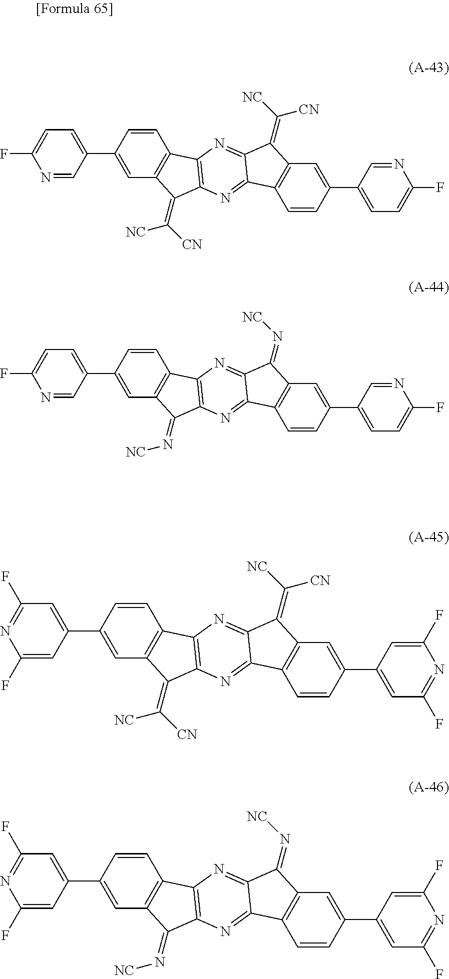 [SMILES: N#CC(C#N)=C1c2cc(-c3ccc(F)nc3)ccc2-c2nc3c(nc21)-c1ccc(-c2ccc(F)nc2)cc1C3=C(C#N)C#N ; N#C/N=c1/c2cc(-c3ccc(F)nc3)ccc2c2nc3/c(=N/C#N)c4cc(-c5ccc(F)nc5)ccc4c3nc12 ; N#CC(C#N)=C1c2cc(-c3cc(F)nc(F)c3)ccc2-c2nc3c(nc21)-c1ccc(-c2cc(F)nc(F)c2)cc1C3=C(C#N)C#N ; N#C/N=c1/c2cc(-c3cc(F)nc(F)c3)ccc2c2nc3/c(=N/C#N)c4cc(-c5cc(F)nc(F)c5)ccc4c3nc12]

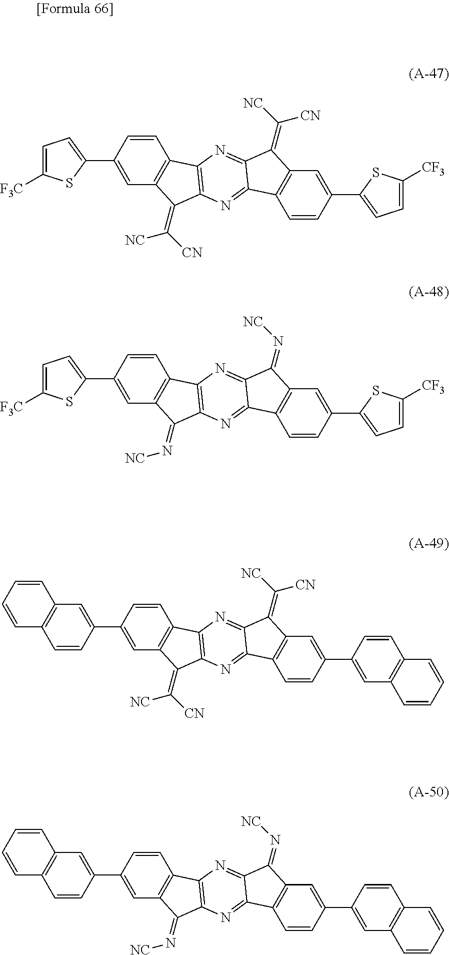 [SMILES: N#CC(C#N)=C1c2cc(-c3ccc(C(F)(F)F)s3)ccc2-c2nc3c(nc21)-c1ccc(-c2ccc(C(F)(F)F)s2)cc1C3=C(C#N)C#N ; N#C/N=c1/c2cc(-c3ccc(C(F)(F)F)s3)ccc2c2nc3/c(=N/C#N)c4cc(-c5ccc(C(F)(F)F)s5)ccc4c3nc12 ; N#CC(C#N)=C1c2cc(-c3ccc4ccccc4c3)ccc2-c2nc3c(nc21)-c1ccc(-c2ccc4ccccc4c2)cc1C3=C(C#N)C#N ; N#C/N=c1/c2cc(-c3ccc4ccccc4c3)ccc2c2nc3/c(=N/C#N)c4cc(-c5ccc6ccccc6c5)ccc4c3nc12]

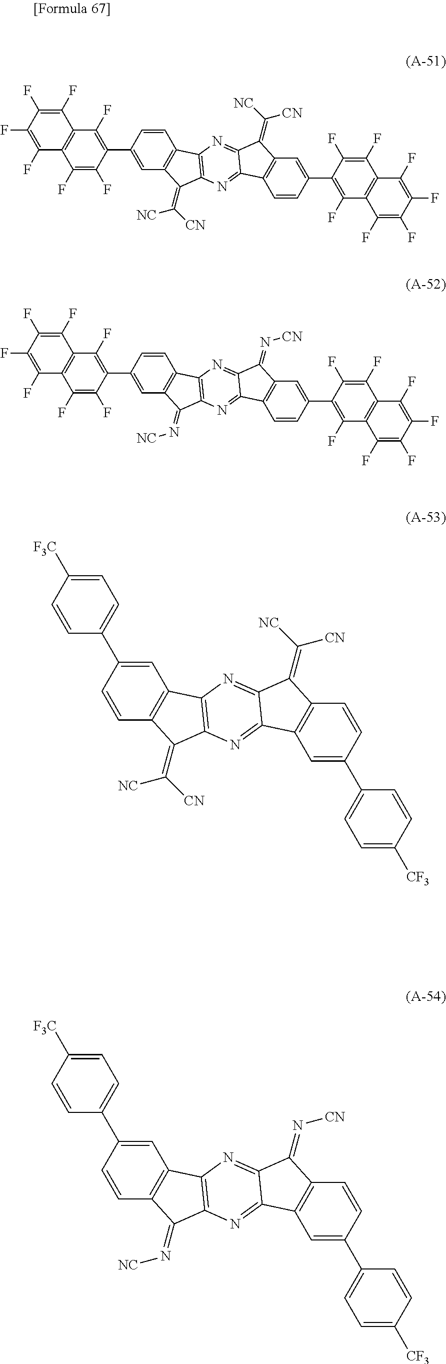 [SMILES: N#CC(C#N)=C1c2cc(-c3c(F)c(F)c4c(F)c(F)c(F)c(F)c4c3F)ccc2-c2nc3c(nc21)-c1ccc(-c2c(F)c(F)c4c(F)c(F)c(F)c(F)c4c2F)cc1C3=C(C#N)C#N ; N#C/N=c1\c2cc(-c3c(F)c(F)c4c(F)c(F)c(F)c(F)c4c3F)ccc2c2nc3/c(=N/C#N)c4cc(-c5c(F)c(F)c6c(F)c(F)c(F)c(F)c6c5F)ccc4c3nc12 ; N#CC(C#N)=C1c2ccc(-c3ccc(C(F)(F)F)cc3)cc2-c2nc3c(nc21)-c1cc(-c2ccc(C(F)(F)F)cc2)ccc1C3=C(C#N)C#N ; N#C/N=c1\c2ccc(-c3ccc(C(F)(F)F)cc3)cc2c2nc3/c(=N/C#N)c4ccc(-c5ccc(C(F)(F)F)cc5)cc4c3nc12]

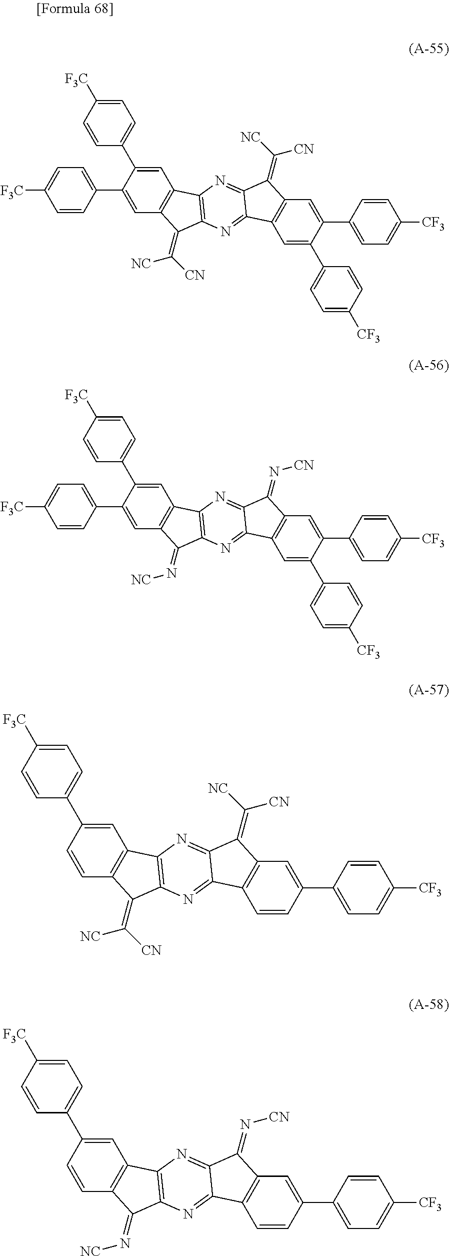 [SMILES: N#CC(C#N)=C1c2cc(-c3ccc(C(F)(F)F)cc3)c(-c3ccc(C(F)(F)F)cc3)cc2-c2nc3c(nc21)-c1cc(-c2ccc(C(F)(F)F)cc2)c(-c2ccc(C(F)(F)F)cc2)cc1C3=C(C#N)C#N ; N#C/N=c1\c2cc(-c3ccc(C(F)(F)F)cc3)c(-c3ccc(C(F)(F)F)cc3)cc2c2nc3/c(=N/C#N)c4cc(-c5ccc(C(F)(F)F)cc5)c(-c5ccc(C(F)(F)F)cc5)cc4c3nc12 ; N#CC(C#N)=C1c2cc(-c3ccc(C(F)(F)F)cc3)ccc2-c2nc3c(nc21)-c1cc(-c2ccc(C(F)(F)F)cc2)ccc1C3=C(C#N)C#N ; N#C/N=c1\c2cc(-c3ccc(C(F)(F)F)cc3)ccc2c2nc3/c(=N/C#N)c4ccc(-c5ccc(C(F)(F)F)cc5)cc4c3nc12]

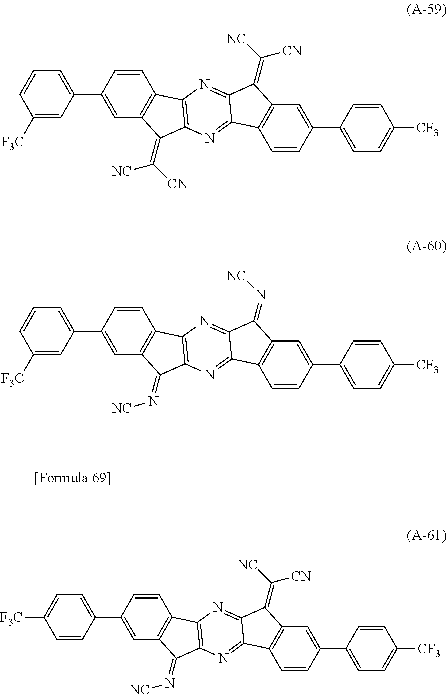 [SMILES: N#CC(C#N)=C1c2cc(-c3ccc(C(F)(F)F)cc3)ccc2-c2nc3c(nc21)-c1ccc(-c2cccc(C(F)(F)F)c2)cc1C3=C(C#N)C#N ; N#C/N=c1/c2cc(-c3ccc(C(F)(F)F)cc3)ccc2c2nc3/c(=N/C#N)c4cc(-c5cccc(C(F)(F)F)c5)ccc4c3nc12 ; N#C/N=C1\c2cc(-c3ccc(C(F)(F)F)cc3)ccc2-c2nc3c(nc21)-c1ccc(-c2ccc(C(F)(F)F)cc2)cc1C3=C(C#N)C#N]

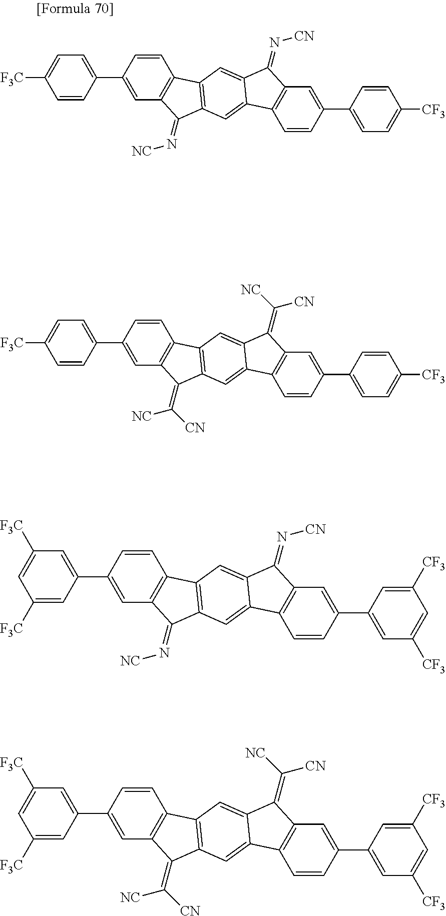 [SMILES: N#C/N=c1\c2cc(-c3ccc(C(F)(F)F)cc3)ccc2c2cc3/c(=N/C#N)c4cc(-c5ccc(C(F)(F)F)cc5)ccc4c3cc12 ; N#CC(C#N)=C1c2cc(-c3ccc(C(F)(F)F)cc3)ccc2-c2cc3c(cc21)-c1ccc(-c2ccc(C(F)(F)F)cc2)cc1C3=C(C#N)C#N ; N#C/N=c1\c2cc(-c3cc(C(F)(F)F)cc(C(F)(F)F)c3)ccc2c2cc3/c(=N/C#N)c4cc(-c5cc(C(F)(F)F)cc(C(F)(F)F)c5)ccc4c3cc12 ; N#CC(C#N)=C1c2cc(-c3cc(C(F)(F)F)cc(C(F)(F)F)c3)ccc2-c2cc3c(cc21)-c1ccc(-c2cc(C(F)(F)F)cc(C(F)(F)F)c2)cc1C3=C(C#N)C#N]

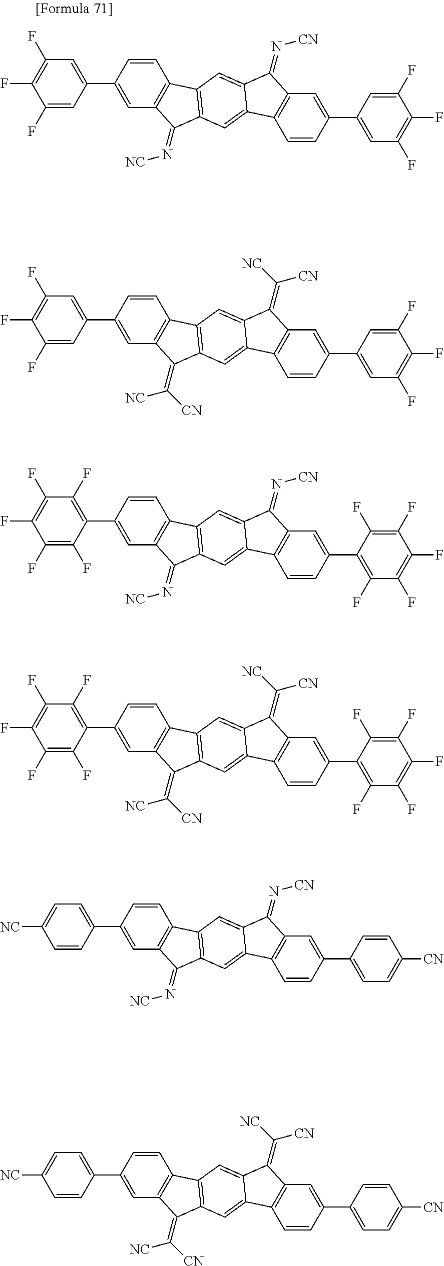

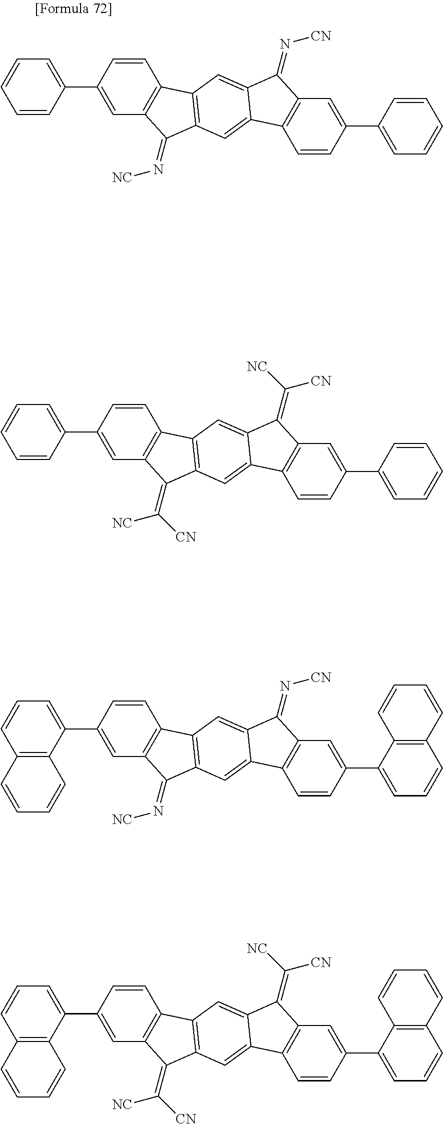 [SMILES: N#C/N=c1\c2cc(-c3ccccc3)ccc2c2cc3/c(=N/C#N)c4cc(-c5ccccc5)ccc4c3cc12 ; N#CC(C#N)=C1c2cc(-c3ccccc3)ccc2-c2cc3c(cc21)-c1ccc(-c2ccccc2)cc1C3=C(C#N)C#N ; N#C/N=c1\c2cc(-c3cccc4ccccc34)ccc2c2cc3/c(=N/C#N)c4cc(-c5cccc6ccccc56)ccc4c3cc12 ; N#CC(C#N)=C1c2cc(-c3cccc4ccccc34)ccc2-c2cc3c(cc21)-c1ccc(-c2cccc4ccccc24)cc1C3=C(C#N)C#N]

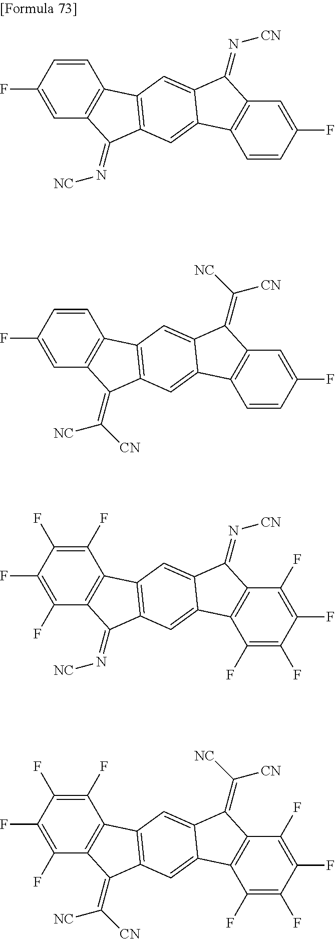 [SMILES: N#C/N=c1\c2cc(F)ccc2c2cc3/c(=N/C#N)c4cc(F)ccc4c3cc12 ; N#CC(C#N)=C1c2cc(F)ccc2-c2cc3c(cc21)-c1ccc(F)cc1C3=C(C#N)C#N ; N#C/N=c1/c2cc3c(cc2c2c(F)c(F)c(F)c(F)c12)/c(=N/C#N)c1c(F)c(F)c(F)c(F)c13 ; N#CC(C#N)=C1c2cc3c(cc2-c2c(F)c(F)c(F)c(F)c21)C(=C(C#N)C#N)c1c(F)c(F)c(F)c(F)c1-3]

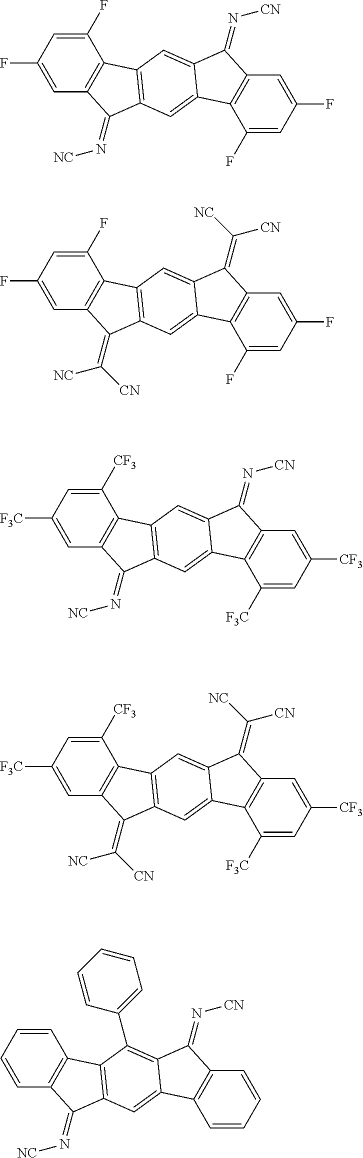 [SMILES: N#C/N=c1/c2cc3c(cc2c2c(F)cc(F)cc12)/c(=N/C#N)c1cc(F)cc(F)c13 ; N#CC(C#N)=C1c2cc3c(cc2-c2c(F)cc(F)cc21)C(=C(C#N)C#N)c1cc(F)cc(F)c1-3 ; N#C/N=c1/c2cc3c(cc2c2c(C(F)(F)F)cc(C(F)(F)F)cc12)/c(=N/C#N)c1cc(C(F)(F)F)cc(C(F)(F)F)c13 ; N#CC(C#N)=C1c2cc3c(cc2-c2c1cc(C(F)(F)F)cc2C(F)(F)F)C(=C(C#N)C#N)c1cc(C(F)(F)F)cc(C(F)(F)F)c1-3 ; N#C/N=c1\c2ccccc2c2c(-c3ccccc3)c3/c(=N/C#N)c4ccccc4c3cc12]

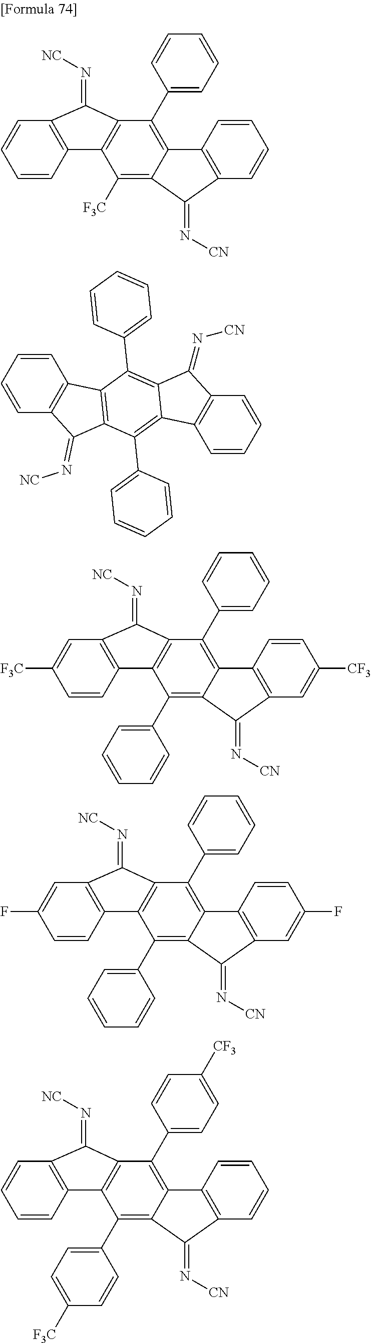

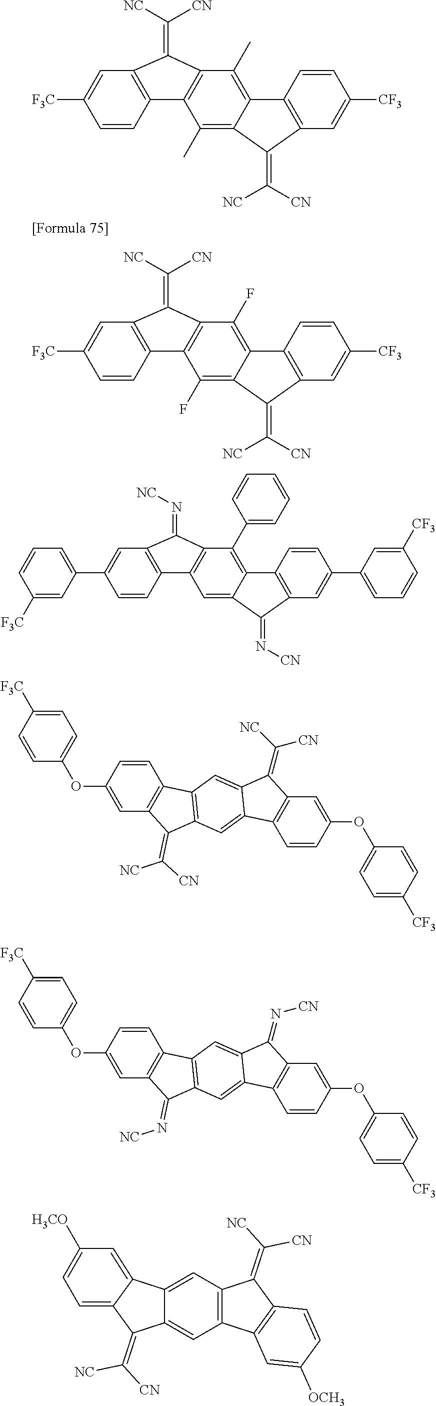

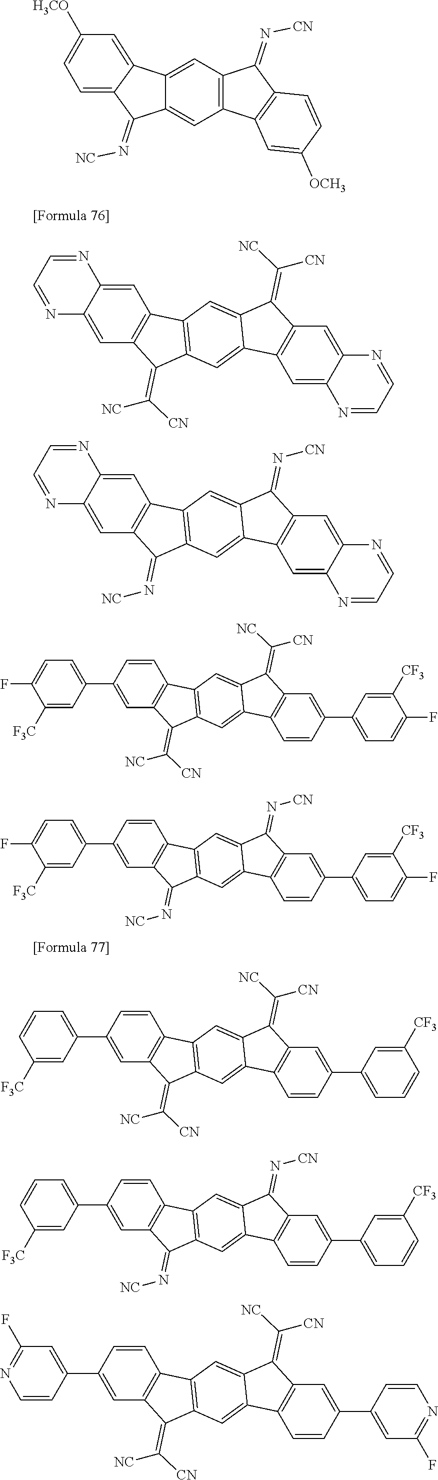

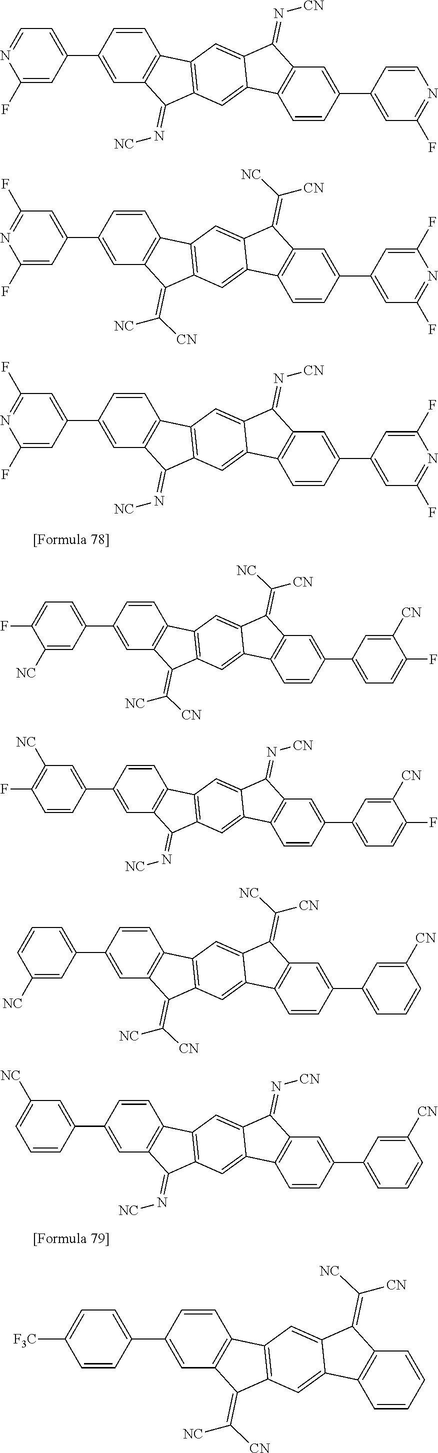

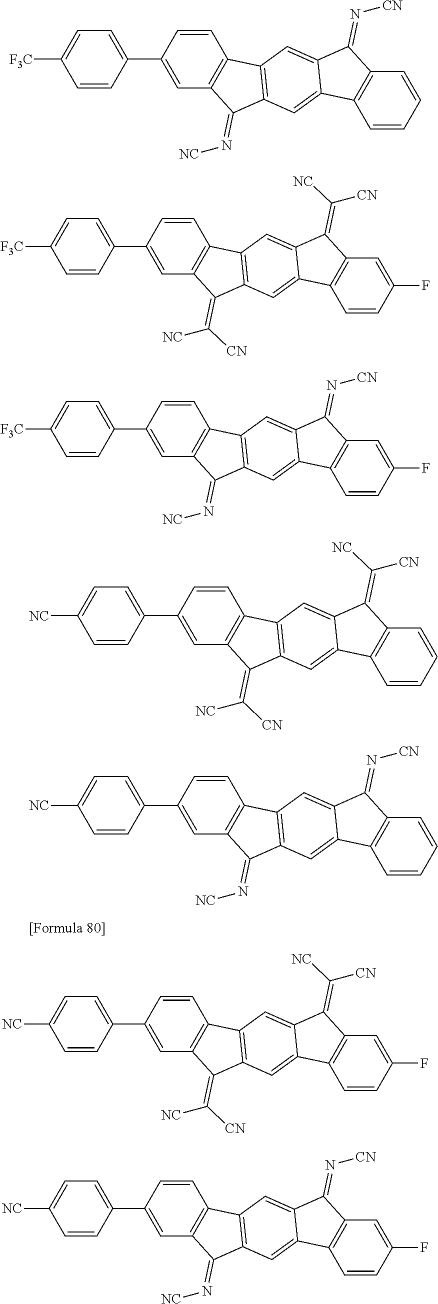

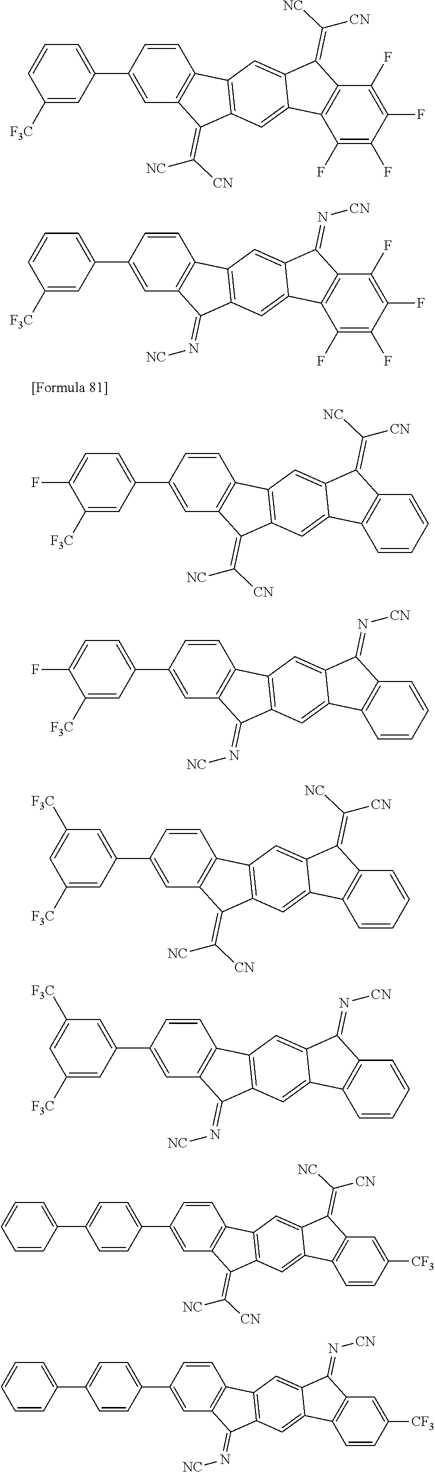

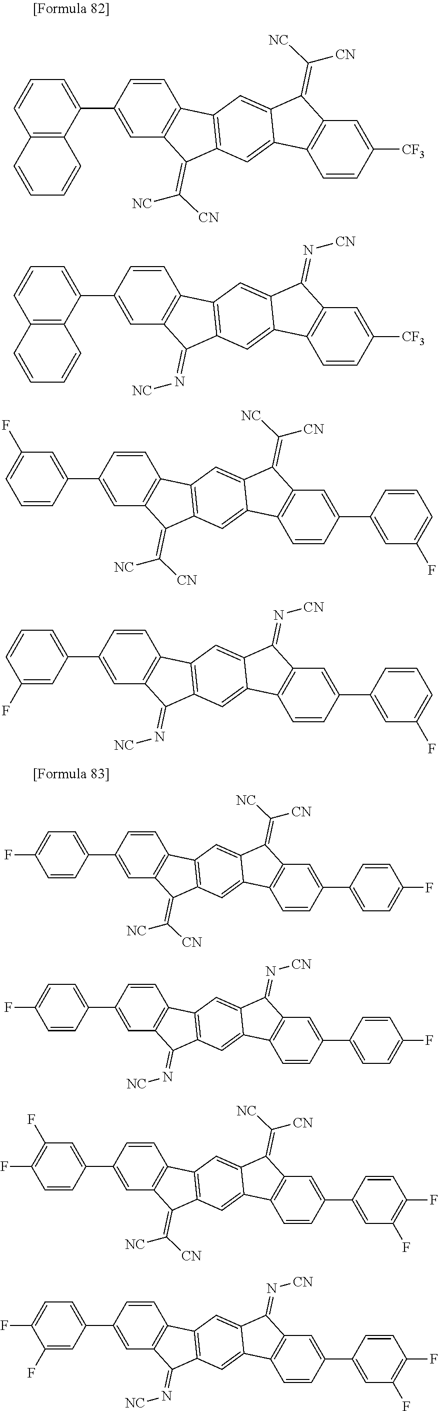

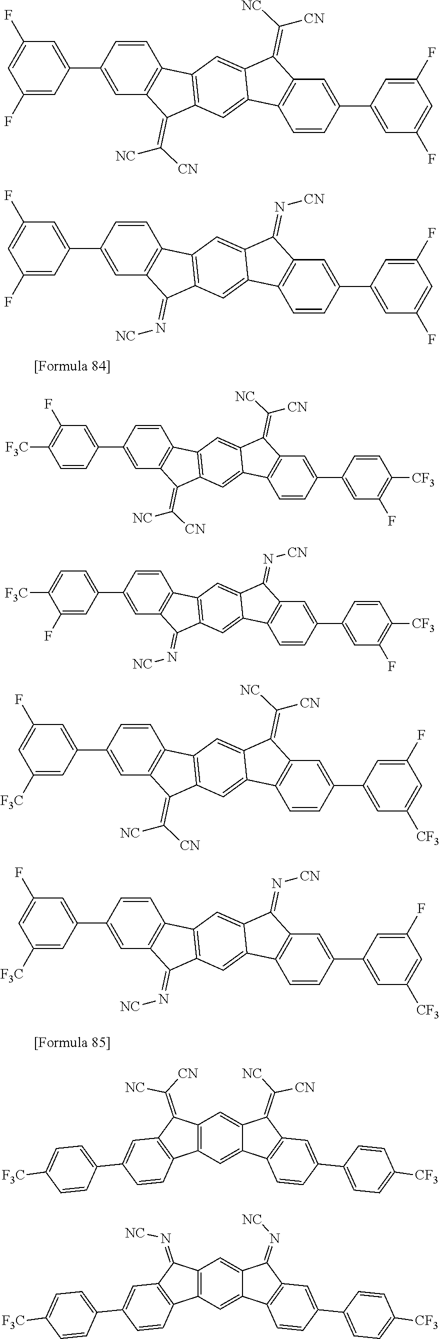

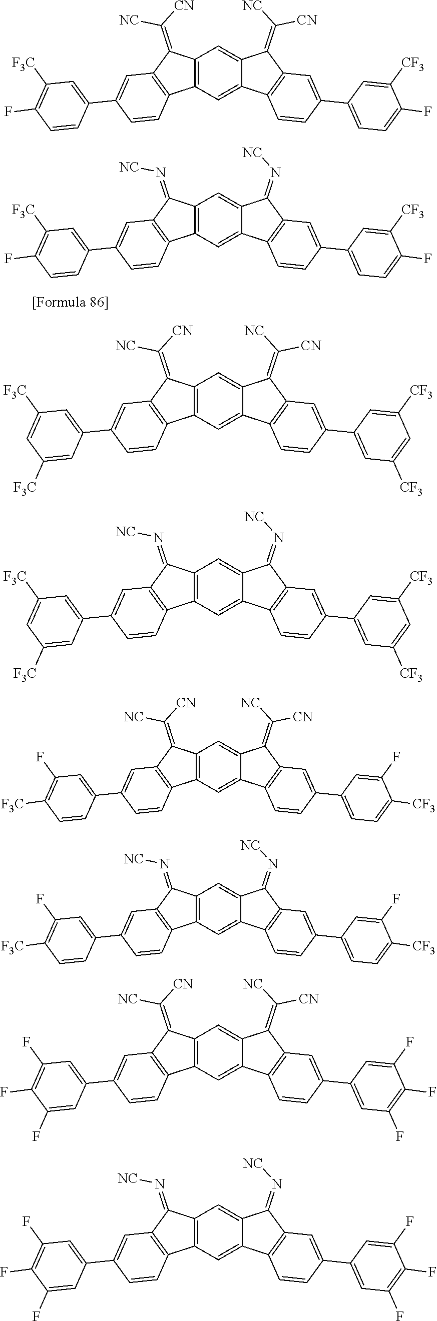

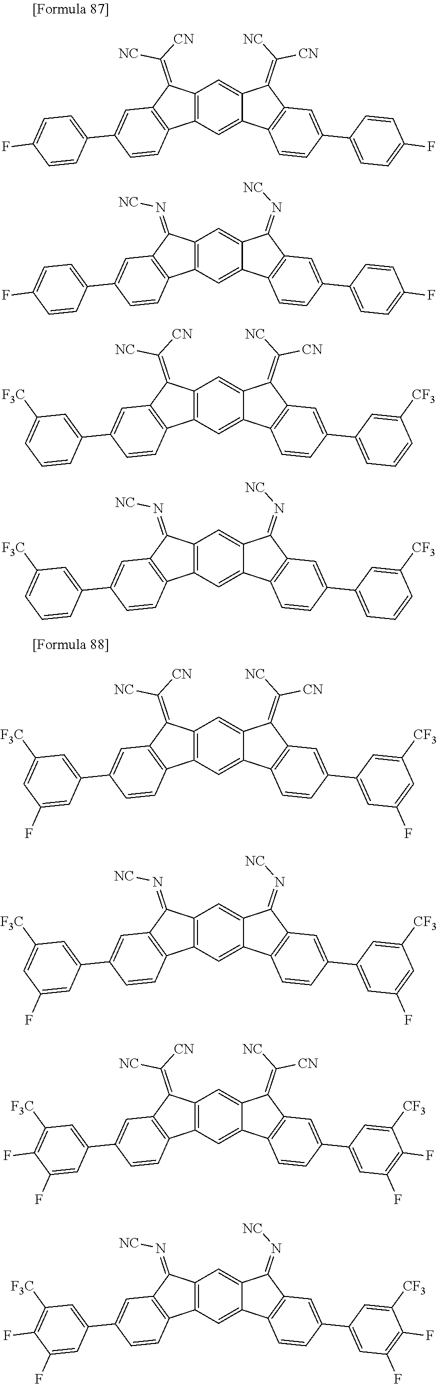

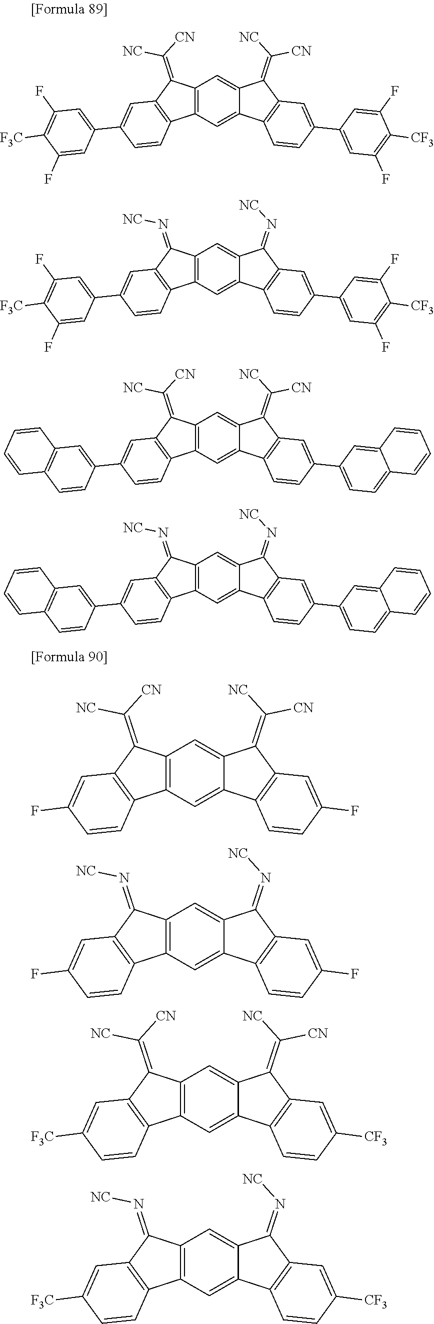

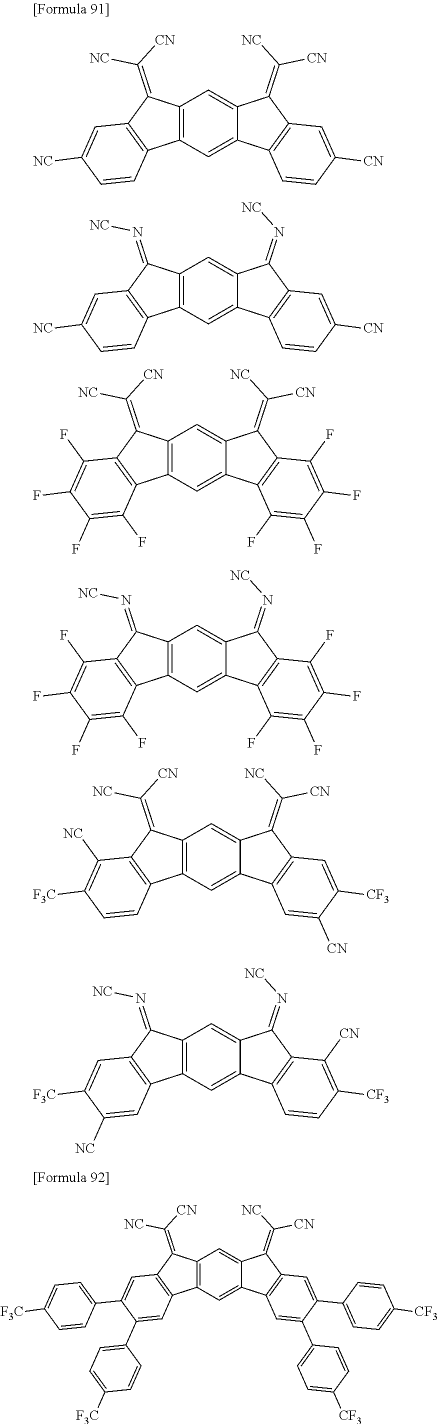

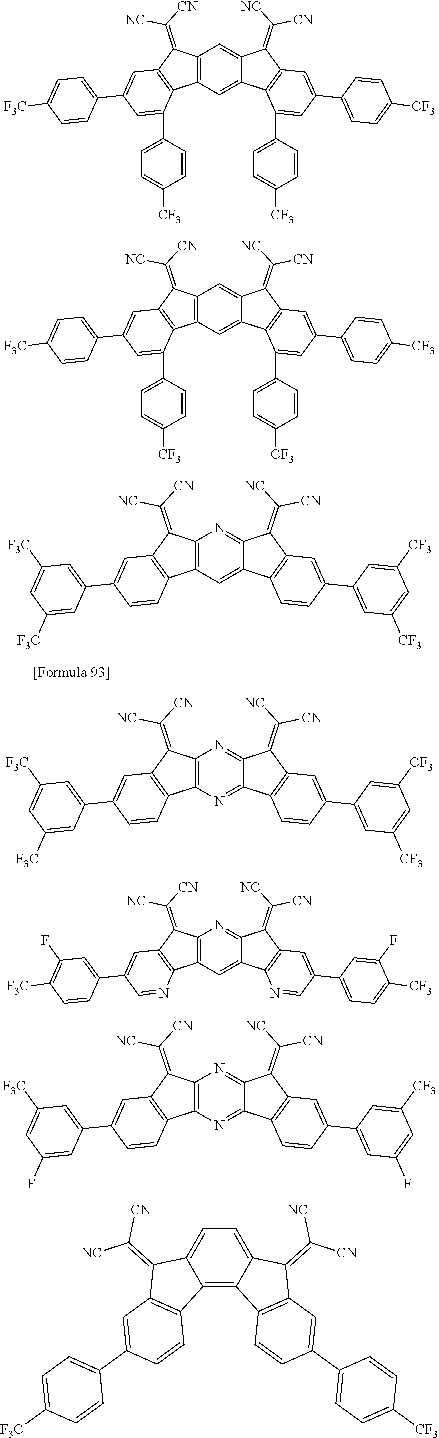

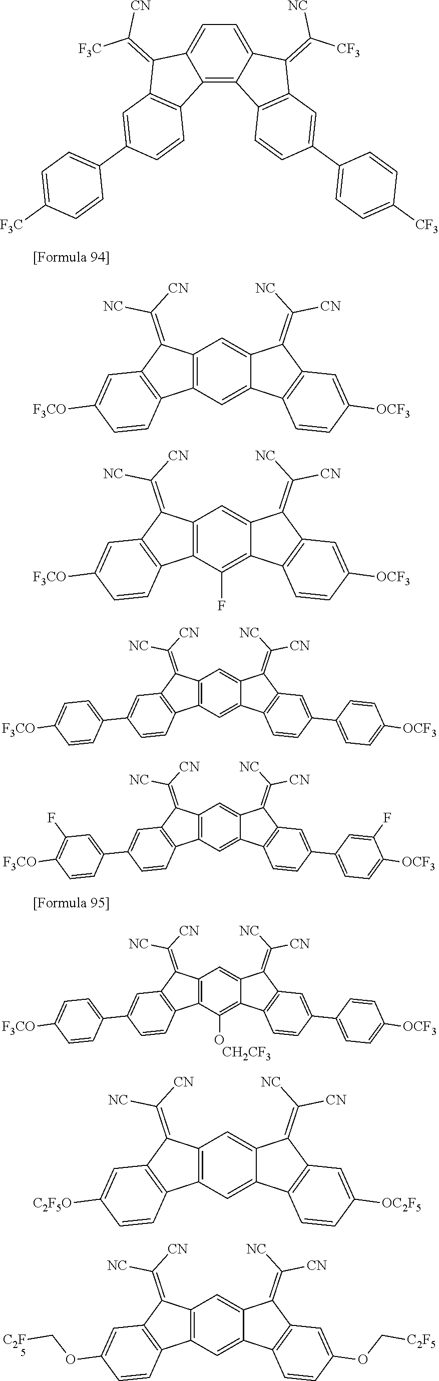

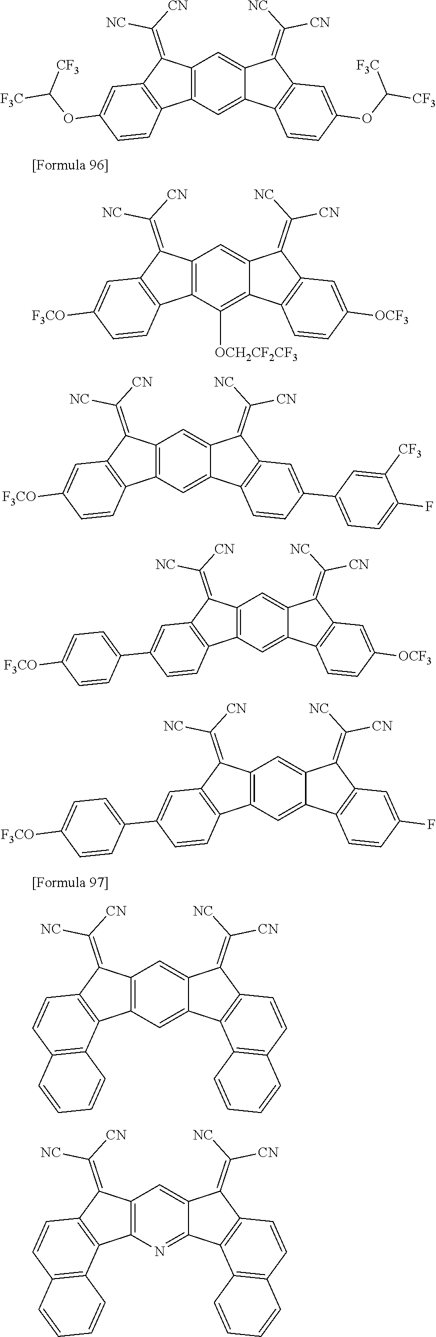

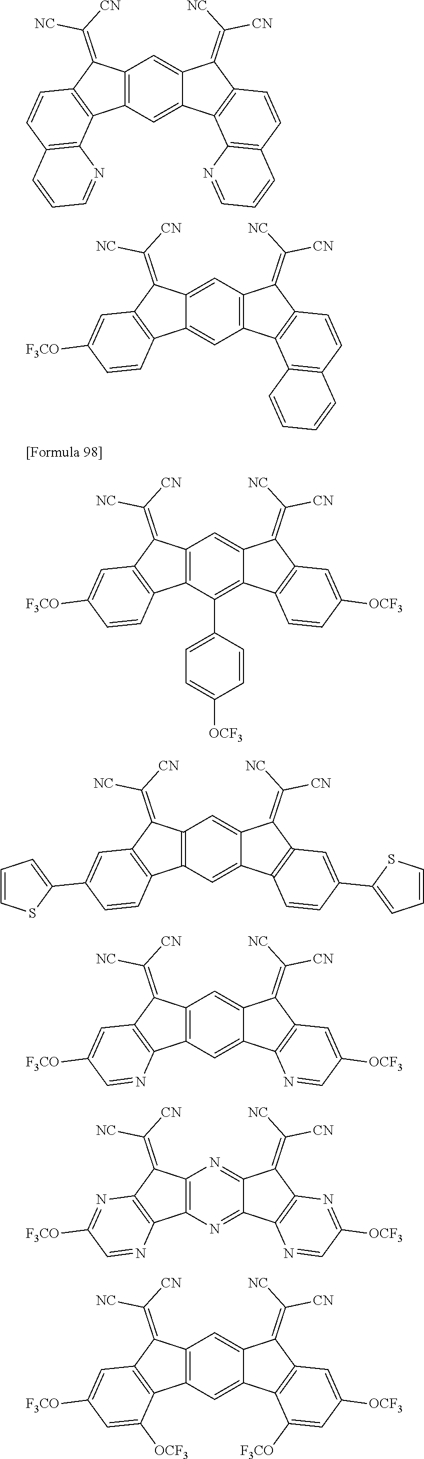

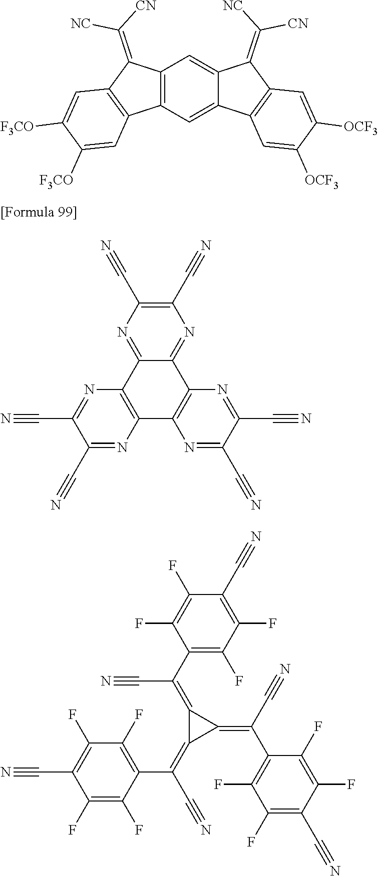

### Fourth Anode Side Organic Layer

In an exemplary arrangement of the organic EL device of the exemplary embodiment, the hole transporting zone further includes a fourth anode side organic layer disposed between the third anode side organic layer and the emitting region.

In an exemplary arrangement of the organic EL device of the exemplary embodiment, the fourth anode side organic layer is in direct contact with the emitting region.

In an exemplary arrangement of the organic EL device of the exemplary embodiment, the fourth anode side organic layer is in direct contact with the third anode side organic layer.

In an exemplary arrangement of the organic EL device of the exemplary embodiment, the first anode side organic layer, the second anode side organic layer, the third anode side organic layer, and the fourth anode side organic layer are arranged in this order from a side close to the anode.

In an exemplary arrangement of the organic EL device of the exemplary embodiment, the fourth anode side organic layer is a blocking layer. For instance, when the blocking layer is disposed on a side of the first emitting layer close to the anode, the blocking layer permits transport of holes and blocks electrons from reaching each organic layer in the hole transporting zone provided closer to the anode with respect to the blocking layer. Alternatively, the blocking layer may be provided in direct contact with the first emitting layer so that excitation energy does not leak out from the first emitting layer toward neighboring layer(s). The blocking layer disposed on the side of the first emitting layer close to the anode blocks excitons generated in the emitting layer from transferring to each organic layer in the hole transporting zone. The first emitting layer is preferably in direct contact with the blocking layer.

In an exemplary arrangement of the organic EL device of the exemplary embodiment, the fourth anode side organic layer is thinner than the third anode side organic layer.

In an exemplary arrangement of the organic EL device of the exemplary embodiment, the fourth anode side organic layer has a film thickness of 20 nm or less.

In an exemplary arrangement of the organic EL device of the exemplary embodiment, the fourth anode side organic layer has a film thickness of 5 nm or more.

Presumably, the organic EL device according to the exemplary embodiment has a long lifetime by being provided with the fourth anode side organic layer (preferably an electron blocking layer) smaller in film thickness than that of the third anode side organic layer.

In an exemplary arrangement of the organic EL device of the exemplary embodiment, the fourth anode side organic layer contains a fourth hole transporting zone material.

In an exemplary arrangement of the organic EL device of the exemplary embodiment, the fourth hole transporting zone material and the third hole transporting zone material are different compounds.

In an exemplary arrangement of the organic EL device of the exemplary embodiment, the fourth hole transporting zone material, the third hole transporting zone material, and the second hole transporting zone material are different compounds.

In an exemplary arrangement of the organic EL device of the exemplary embodiment, the fourth anode side organic layer contains a compound represented by the formula (C1) or a compound represented by the formula (C3).

In an exemplary arrangement of the organic EL device of the exemplary embodiment, although the third anode side organic layer and the fourth anode side organic layer may each contain a compound represented by the formula (C1), the compound contained in the third anode side organic layer and the compound contained in the fourth anode side organic layer are mutually different in a molecular structure.

In an exemplary arrangement of the organic EL device of the exemplary embodiment, the fourth hole transporting zone material is at least one compound selected from the group consisting of a compound represented by the formula (cHT3-1), a compound represented by the formula (cHT3-2), a compound represented by the formula (cHT3-3), and a compound represented by the formula (cHT3-4).

In an exemplary arrangement of the organic EL device of the exemplary embodiment, the fourth hole transporting zone material is a monoamine compound, a diamine compound, a triamine compound, or a tetraamine compound.

In an exemplary arrangement of the organic EL device of the exemplary embodiment, the first anode side organic layer, the second anode side organic layer, the third anode side organic layer, and the fourth anode side organic layer each contain at least one compound, the compounds respectively contained in the first, second, third, and fourth anode side organic layers being different from each other.

In an exemplary arrangement of the organic EL device of the exemplary embodiment, the first anode side organic layer, the second anode side organic layer, the third anode side organic layer, and the fourth anode side organic layer each contain a monoamine compound having only one substituted or unsubstituted amino group in a molecule.

In an exemplary arrangement of the organic EL device of the exemplary embodiment, the first anode side organic layer, the second anode side organic layer, the third anode side organic layer, and the fourth anode side organic layer contain no diamine compound. The diamine compound has two substituted or unsubstituted amino groups in a molecule.

The compound represented by the formula (C1) is preferably a monoamine compound.

In an exemplary arrangement of the organic EL device of the exemplary embodiment, at least one of the first anode side organic layer, the second anode side organic layer, the third anode side organic layer, or the fourth anode side organic layer may also contain a diamine compound. The compound represented by the formula (C3) is preferably a diamine compound.

In the organic EL device according to the exemplary embodiment, R₉₀₁, R₉₀₂, R₉₀₃, and R₉₀₄ in the compounds contained in the hole transporting zone are each independently a hydrogen atom, or a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and

when a plurality of R₉₀₄ are present, the plurality of R₉₀₄ are mutually the same or different.

In the exemplary embodiment, all groups specified as “substituted or unsubstituted” groups are preferably “unsubstituted” groups.

In the exemplary embodiment, the first hole transporting zone material, the second hole transporting zone material, the third hole transporting zone material, and the fourth hole transporting zone material each may be occasionally referred to as a hole transporting zone material.

In the organic EL device according to the exemplary embodiment, the hole transporting zone material may be a compound that contains a substituted or unsubstituted 3-carbazolyl group in a molecule. In the organic EL device according to the exemplary embodiment, the hole transporting zone material may be a compound that does not contain a substituted or unsubstituted 3-carbazolyl group in a molecule.

### Method of Producing Hole Transporting Zone Material

The hole transporting zone material according to the exemplary embodiment can be produced by a known method or through a known alternative reaction using a known material(s) tailored for the target compound in accordance with the known method.

### Specific Examples of Hole Transporting Zone Material

Specific examples of the hole transporting zone material according to the exemplary embodiment include the following compounds. However, the invention is by no means limited to the specific examples.

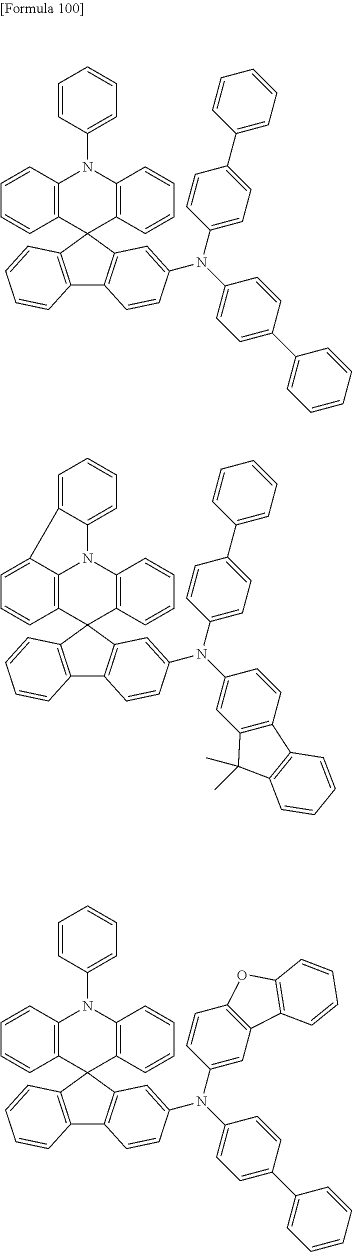 [SMILES: c1ccc(-c2ccc(N(c3ccc(-c4ccccc4)cc3)c3ccc4c(c3)C3(c5ccccc5-4)c4ccccc4N(c4ccccc4)c4ccccc43)cc2)cc1 ; CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21 ; c1ccc(-c2ccc(N(c3ccc4c(c3)C3(c5ccccc5-4)c4ccccc4N(c4ccccc4)c4ccccc43)c3ccc4oc5ccccc5c4c3)cc2)cc1]

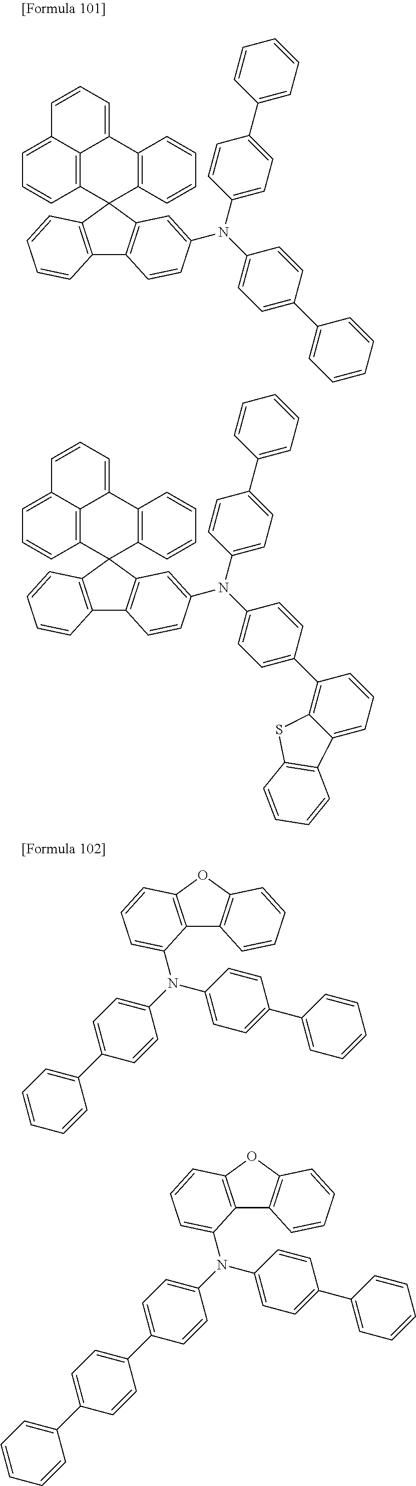 [SMILES: c1ccc(-c2ccc(N(c3ccc(-c4ccccc4)cc3)c3ccc4c(c3)C3(c5ccccc5-4)c4ccccc4-c4cccc5cccc3c45)cc2)cc1 ; c1ccc(-c2ccc(N(c3ccc(-c4cccc5c4sc4ccccc45)cc3)c3ccc4c(c3)C3(c5ccccc5-4)c4ccccc4-c4cccc5cccc3c45)cc2)cc1 ; c1ccc(-c2ccc(N(c3ccc(-c4ccccc4)cc3)c3cccc4oc5ccccc5c34)cc2)cc1 ; c1ccc(-c2ccc(-c3ccc(N(c4ccc(-c5ccccc5)cc4)c4cccc5oc6ccccc6c45)cc3)cc2)cc1]

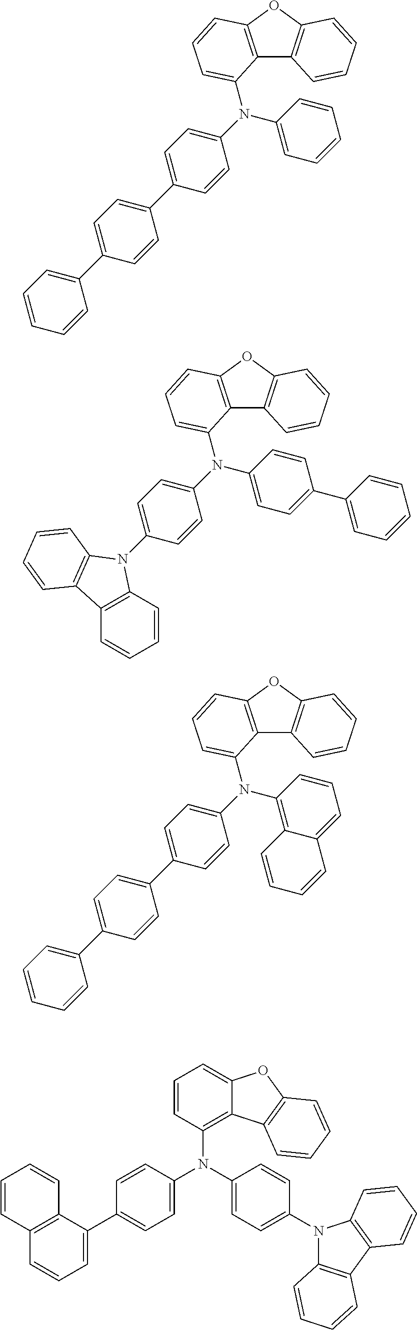 [SMILES: c1ccc(-c2ccc(-c3ccc(N(c4ccccc4)c4cccc5oc6ccccc6c45)cc3)cc2)cc1 ; c1ccc(-c2ccc(N(c3ccc(-n4c5ccccc5c5ccccc54)cc3)c3cccc4oc5ccccc5c34)cc2)cc1 ; c1ccc(-c2ccc(-c3ccc(N(c4cccc5ccccc45)c4cccc5oc6ccccc6c45)cc3)cc2)cc1 ; c1ccc2c(-c3ccc(N(c4ccc(-n5c6ccccc6c6ccccc65)cc4)c4cccc5oc6ccccc6c45)cc3)cccc2c1]

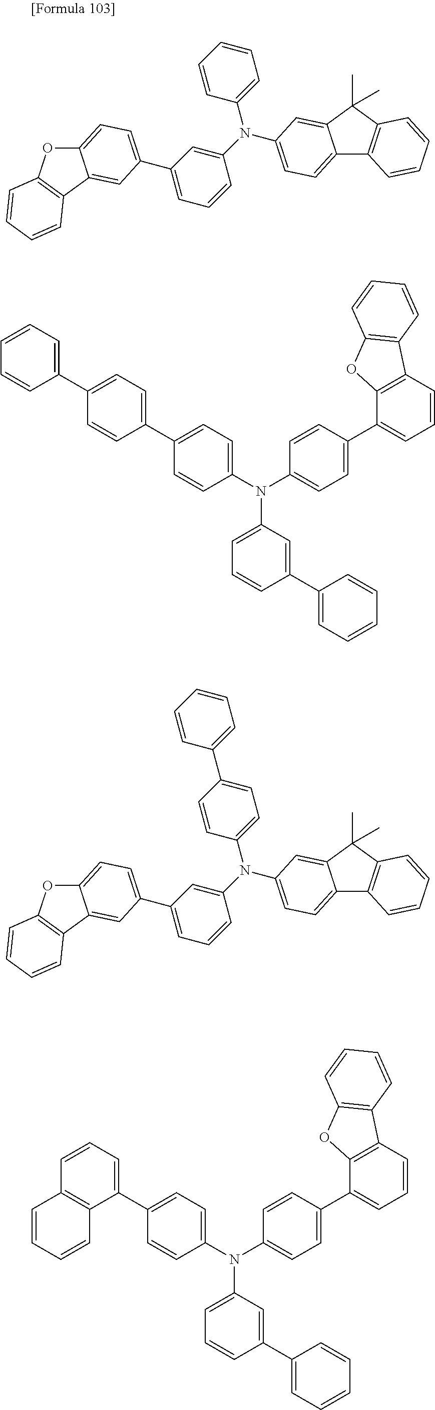 [SMILES: CC1(C)c2ccccc2-c2ccc(N(c3ccccc3)c3cccc(-c4ccc5oc6ccccc6c5c4)c3)cc21 ; c1ccc(-c2ccc(-c3ccc(N(c4ccc(-c5cccc6c5oc5ccccc56)cc4)c4cccc(-c5ccccc5)c4)cc3)cc2)cc1 ; CC1(C)c2ccccc2-c2ccc(N(c3ccc(-c4ccccc4)cc3)c3cccc(-c4ccc5oc6ccccc6c5c4)c3)cc21 ; c1ccc(-c2cccc(N(c3ccc(-c4cccc5ccccc45)cc3)c3ccc(-c4cccc5c4oc4ccccc45)cc3)c2)cc1]

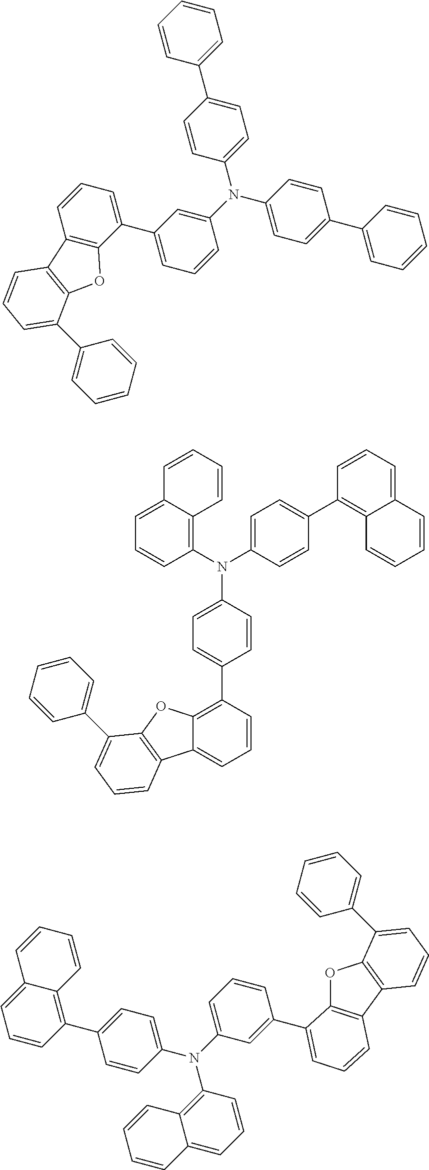 [SMILES: c1ccc(-c2ccc(N(c3ccc(-c4ccccc4)cc3)c3cccc(-c4cccc5c4oc4c(-c6ccccc6)cccc45)c3)cc2)cc1 ; c1ccc(-c2cccc3c2oc2c(-c4ccc(N(c5ccc(-c6cccc7ccccc67)cc5)c5cccc6ccccc56)cc4)cccc23)cc1 ; c1ccc(-c2cccc3c2oc2c(-c4cccc(N(c5ccc(-c6cccc7ccccc67)cc5)c5cccc6ccccc56)c4)cccc23)cc1]

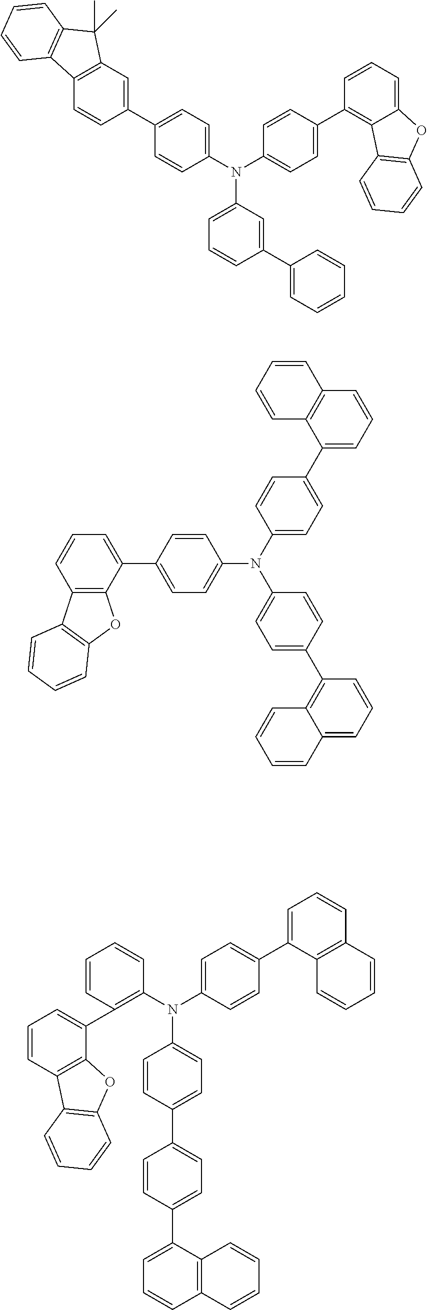 [SMILES: CC1(C)c2ccccc2-c2ccc(-c3ccc(N(c4ccc(-c5cccc6oc7ccccc7c56)cc4)c4cccc(-c5ccccc5)c4)cc3)cc21 ; c1ccc2c(-c3ccc(N(c4ccc(-c5cccc6ccccc56)cc4)c4ccc(-c5cccc6c5oc5ccccc56)cc4)cc3)cccc2c1 ; c1ccc(N(c2ccc(-c3ccc(-c4cccc5ccccc45)cc3)cc2)c2ccc(-c3cccc4ccccc34)cc2)c(-c2cccc3c2oc2ccccc23)c1]

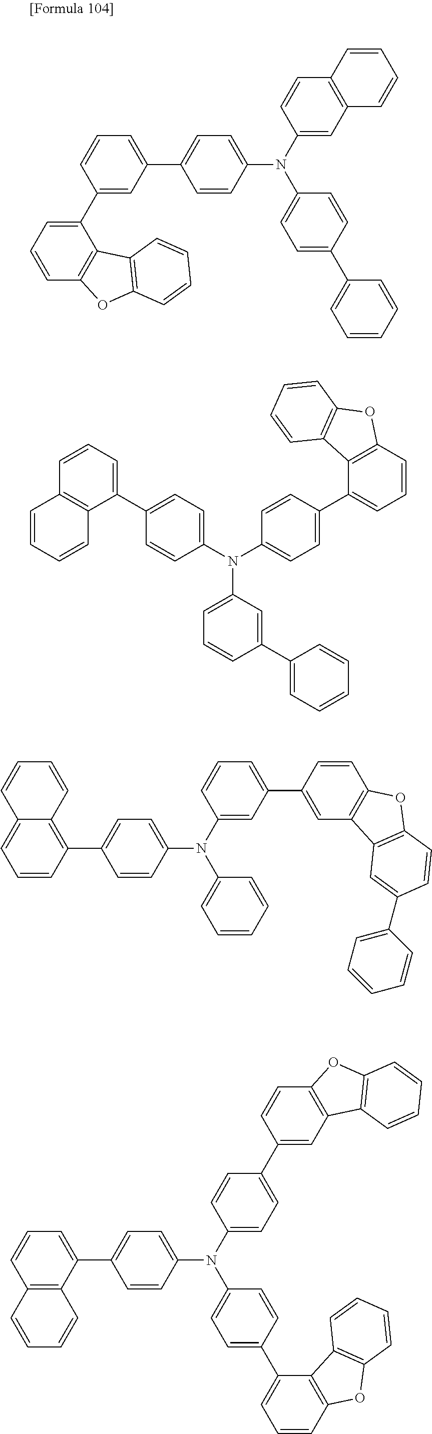 [SMILES: c1ccc(-c2ccc(N(c3ccc(-c4cccc(-c5cccc6oc7ccccc7c56)c4)cc3)c3ccc4ccccc4c3)cc2)cc1 ; c1ccc(-c2cccc(N(c3ccc(-c4cccc5ccccc45)cc3)c3ccc(-c4cccc5oc6ccccc6c45)cc3)c2)cc1 ; c1ccc(-c2ccc3oc4ccc(-c5cccc(N(c6ccccc6)c6ccc(-c7cccc8ccccc78)cc6)c5)cc4c3c2)cc1 ; c1ccc2c(-c3ccc(N(c4ccc(-c5ccc6oc7ccccc7c6c5)cc4)c4ccc(-c5cccc6oc7ccccc7c56)cc4)cc3)cccc2c1]

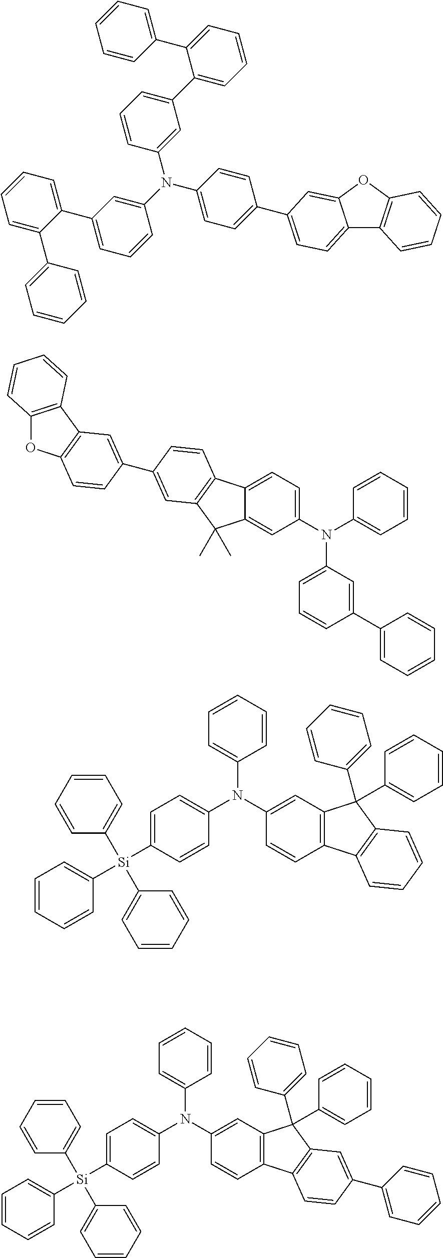

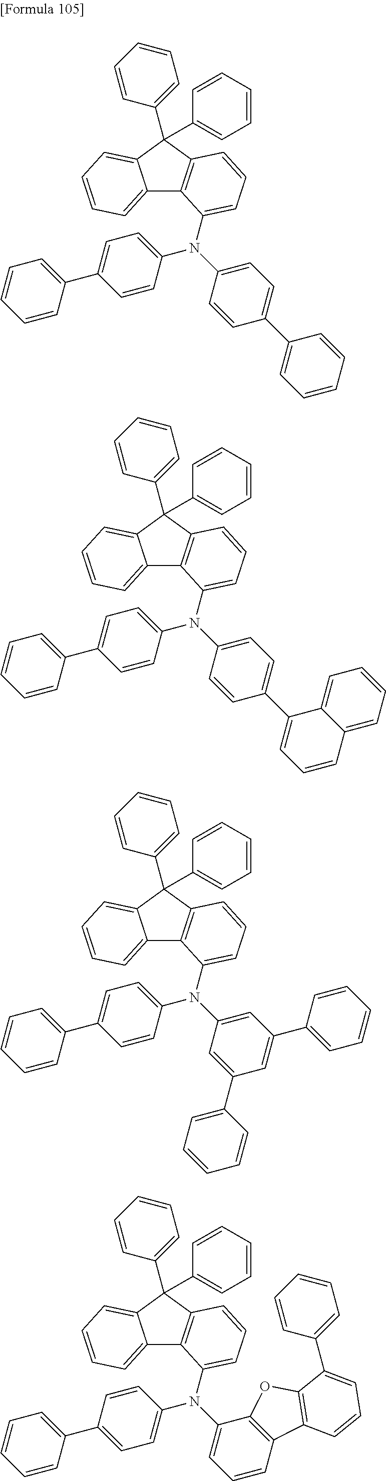 [SMILES: c1ccc(-c2ccc(N(c3ccc(-c4ccccc4)cc3)c3cccc4c3-c3ccccc3C4(c3ccccc3)c3ccccc3)cc2)cc1 ; c1ccc(-c2ccc(N(c3ccc(-c4cccc5ccccc45)cc3)c3cccc4c3-c3ccccc3C4(c3ccccc3)c3ccccc3)cc2)cc1 ; c1ccc(-c2ccc(N(c3cc(-c4ccccc4)cc(-c4ccccc4)c3)c3cccc4c3-c3ccccc3C4(c3ccccc3)c3ccccc3)cc2)cc1 ; c1ccc(-c2ccc(N(c3cccc4c3-c3ccccc3C4(c3ccccc3)c3ccccc3)c3cccc4c3oc3c(-c5ccccc5)cccc34)cc2)cc1]

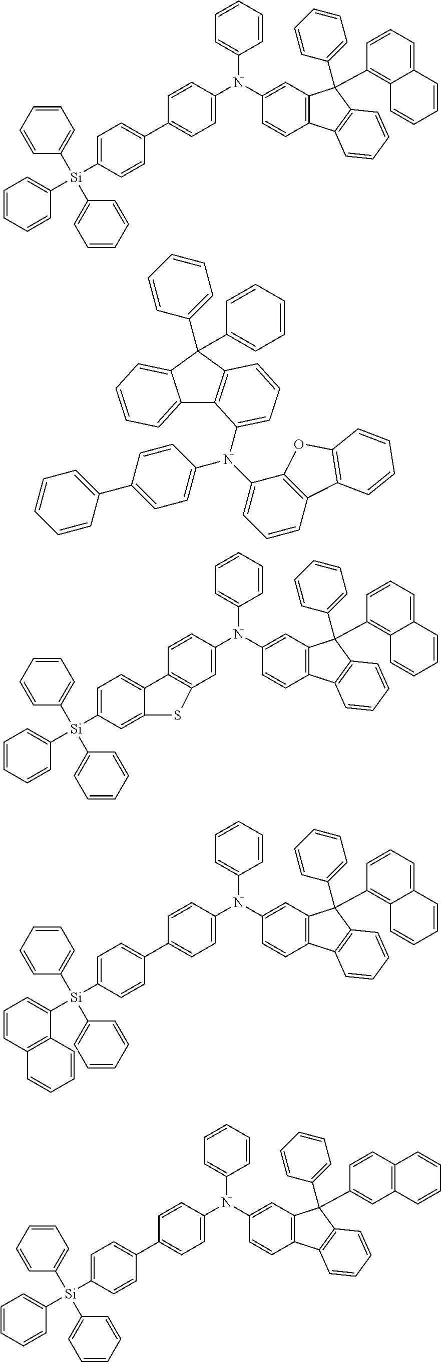

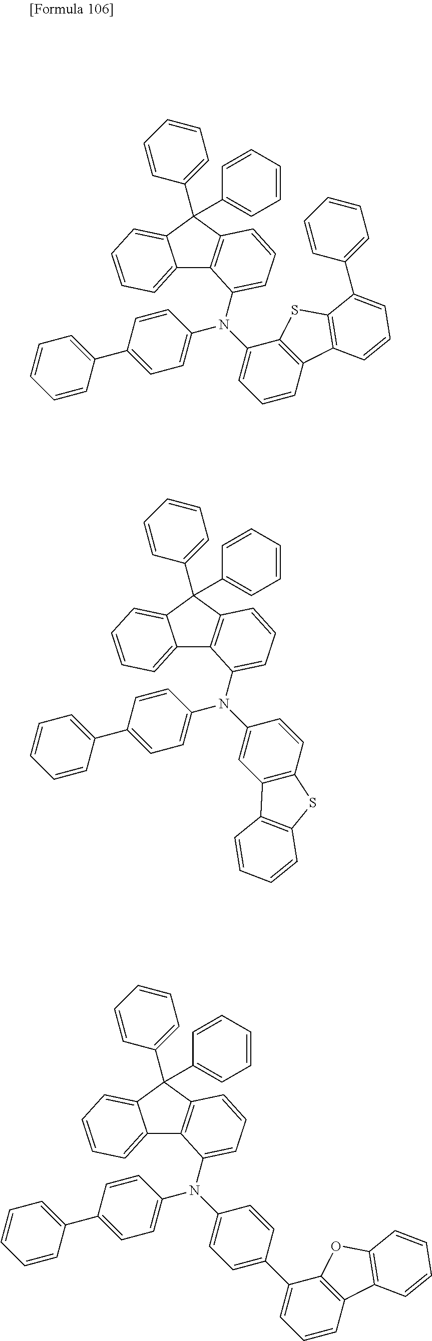 [SMILES: c1ccc(-c2ccc(N(c3cccc4c3-c3ccccc3C4(c3ccccc3)c3ccccc3)c3cccc4c3sc3c(-c5ccccc5)cccc34)cc2)cc1 ; c1ccc(-c2ccc(N(c3ccc4sc5ccccc5c4c3)c3cccc4c3-c3ccccc3C4(c3ccccc3)c3ccccc3)cc2)cc1 ; c1ccc(-c2ccc(N(c3ccc(-c4cccc5c4oc4ccccc45)cc3)c3cccc4c3-c3ccccc3C4(c3ccccc3)c3ccccc3)cc2)cc1]

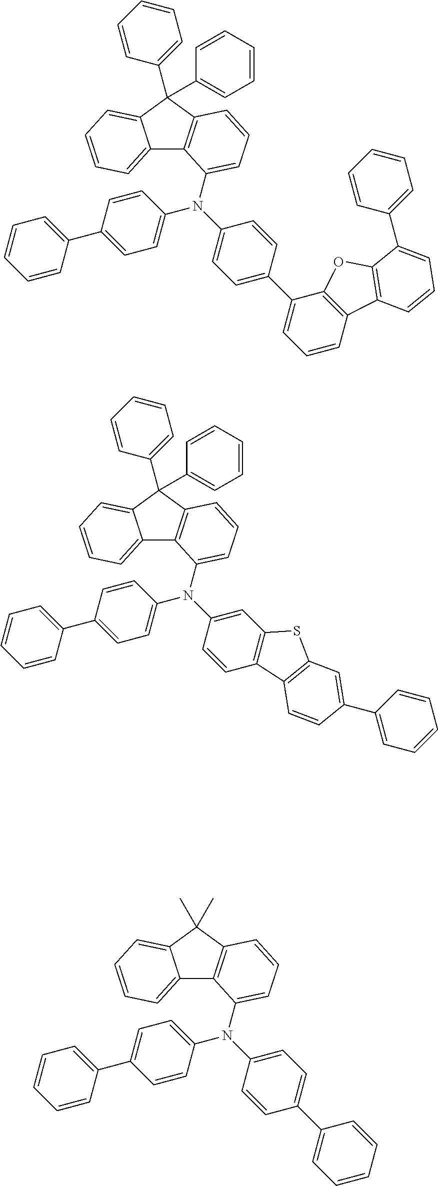 [SMILES: c1ccc(-c2ccc(N(c3ccc(-c4cccc5c4oc4c(-c6ccccc6)cccc45)cc3)c3cccc4c3-c3ccccc3C4(c3ccccc3)c3ccccc3)cc2)cc1 ; c1ccc(-c2ccc(N(c3ccc4c(c3)sc3cc(-c5ccccc5)ccc34)c3cccc4c3-c3ccccc3C4(c3ccccc3)c3ccccc3)cc2)cc1 ; CC1(C)c2ccccc2-c2c(N(c3ccc(-c4ccccc4)cc3)c3ccc(-c4ccccc4)cc3)cccc21]

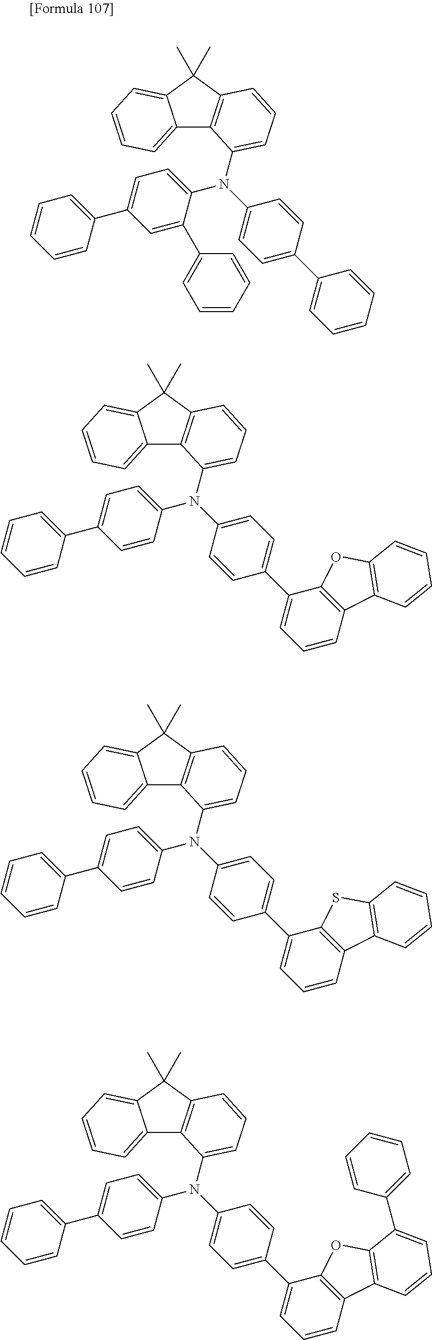 [SMILES: CC1(C)c2ccccc2-c2c(N(c3ccc(-c4ccccc4)cc3)c3ccc(-c4ccccc4)cc3-c3ccccc3)cccc21 ; CC1(C)c2ccccc2-c2c(N(c3ccc(-c4ccccc4)cc3)c3ccc(-c4cccc5c4oc4ccccc45)cc3)cccc21 ; CC1(C)c2ccccc2-c2c(N(c3ccc(-c4ccccc4)cc3)c3ccc(-c4cccc5c4sc4ccccc45)cc3)cccc21 ; CC1(C)c2ccccc2-c2c(N(c3ccc(-c4ccccc4)cc3)c3ccc(-c4cccc5c4oc4c(-c6ccccc6)cccc45)cc3)cccc21]

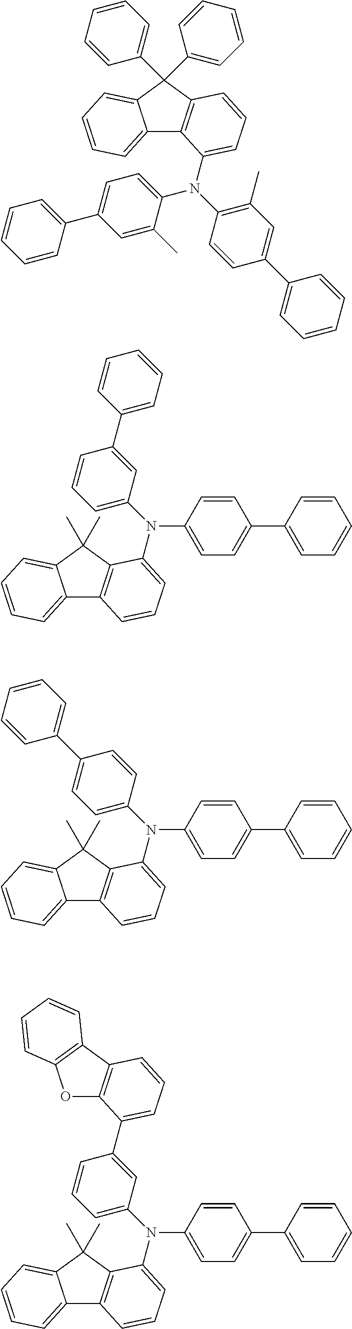 [SMILES: Cc1cc(-c2ccccc2)ccc1N(c1ccc(-c2ccccc2)cc1C)c1cccc2c1-c1ccccc1C2(c1ccccc1)c1ccccc1 ; CC1(C)c2ccccc2-c2cccc(N(c3ccc(-c4ccccc4)cc3)c3cccc(-c4ccccc4)c3)c21 ; CC1(C)c2ccccc2-c2cccc(N(c3ccc(-c4ccccc4)cc3)c3ccc(-c4ccccc4)cc3)c21 ; CC1(C)c2ccccc2-c2cccc(N(c3ccc(-c4ccccc4)cc3)c3cccc(-c4cccc5c4oc4ccccc45)c3)c21]

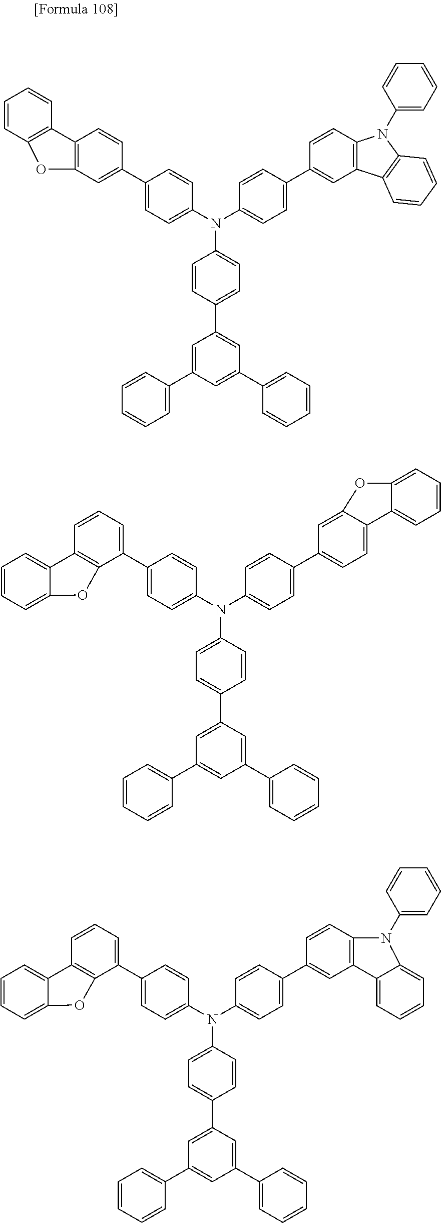 [SMILES: c1ccc(-c2cc(-c3ccccc3)cc(-c3ccc(N(c4ccc(-c5ccc6c(c5)oc5ccccc56)cc4)c4ccc(-c5ccc6c(c5)c5ccccc5n6-c5ccccc5)cc4)cc3)c2)cc1 ; c1ccc(-c2cc(-c3ccccc3)cc(-c3ccc(N(c4ccc(-c5ccc6c(c5)oc5ccccc56)cc4)c4ccc(-c5cccc6c5oc5ccccc56)cc4)cc3)c2)cc1 ; c1ccc(-c2cc(-c3ccccc3)cc(-c3ccc(N(c4ccc(-c5ccc6c(c5)c5ccccc5n6-c5ccccc5)cc4)c4ccc(-c5cccc6c5oc5ccccc56)cc4)cc3)c2)cc1]

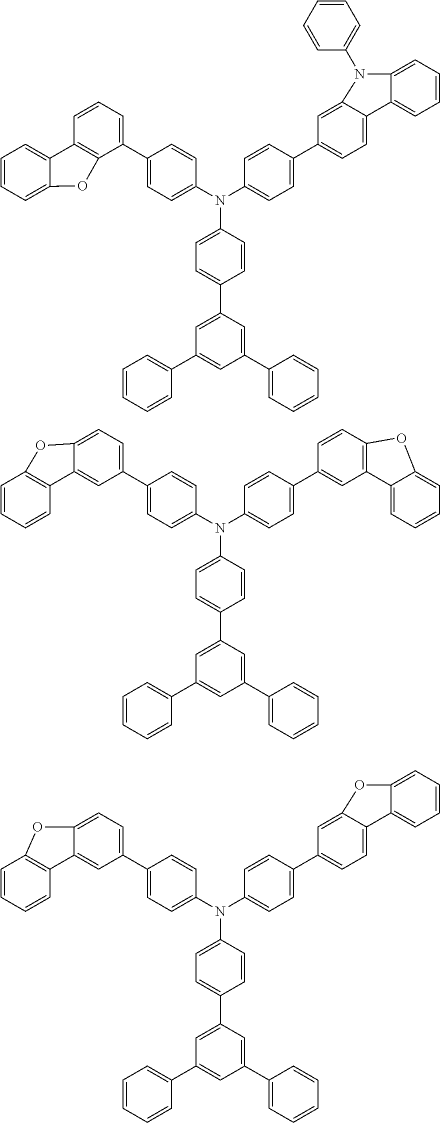 [SMILES: c1ccc(-c2cc(-c3ccccc3)cc(-c3ccc(N(c4ccc(-c5ccc6c7ccccc7n(-c7ccccc7)c6c5)cc4)c4ccc(-c5cccc6c5oc5ccccc56)cc4)cc3)c2)cc1 ; c1ccc(-c2cc(-c3ccccc3)cc(-c3ccc(N(c4ccc(-c5ccc6oc7ccccc7c6c5)cc4)c4ccc(-c5ccc6oc7ccccc7c6c5)cc4)cc3)c2)cc1 ; c1ccc(-c2cc(-c3ccccc3)cc(-c3ccc(N(c4ccc(-c5ccc6c(c5)oc5ccccc56)cc4)c4ccc(-c5ccc6oc7ccccc7c6c5)cc4)cc3)c2)cc1]

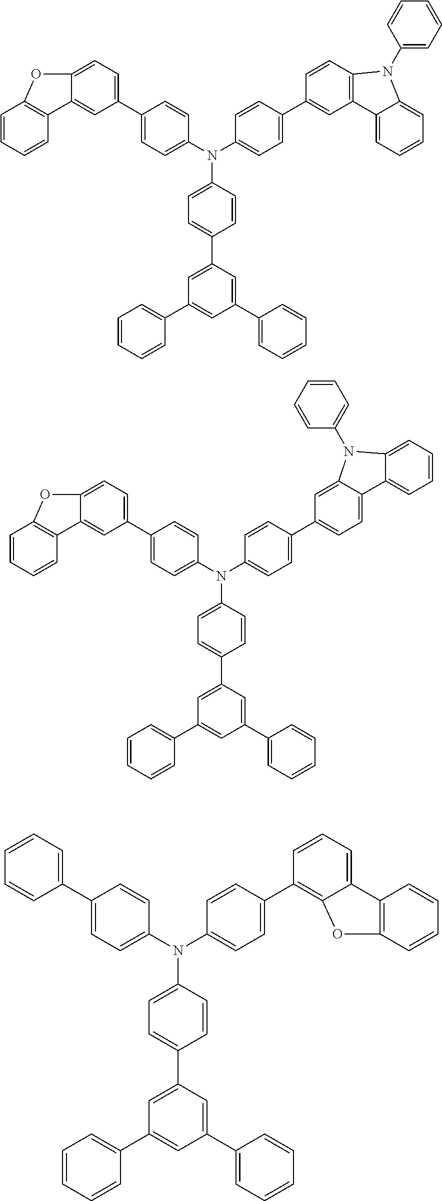

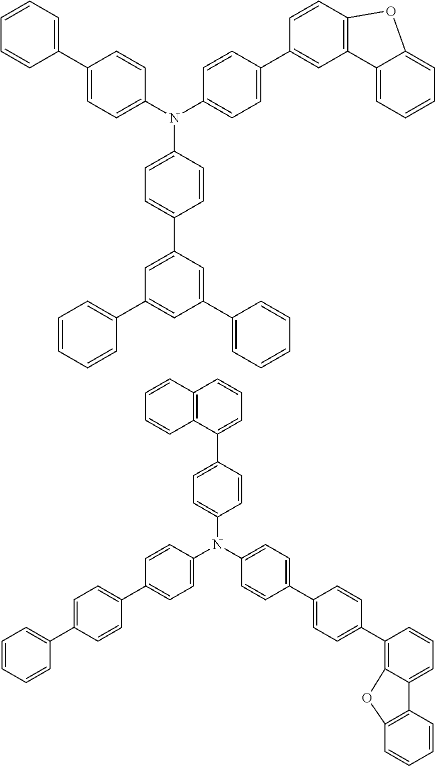

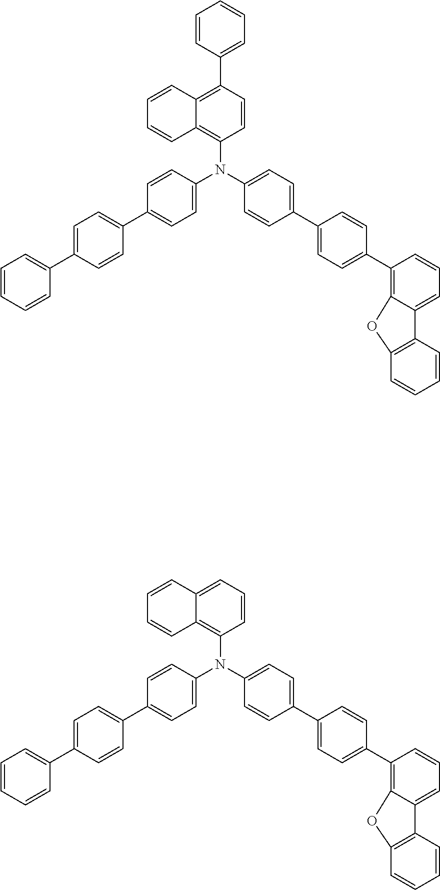 [SMILES: c1ccc(-c2ccc(-c3ccc(N(c4ccc(-c5ccc(-c6cccc7c6oc6ccccc67)cc5)cc4)c4ccc(-c5ccccc5)c5ccccc45)cc3)cc2)cc1 ; c1ccc(-c2ccc(-c3ccc(N(c4ccc(-c5ccc(-c6cccc7c6oc6ccccc67)cc5)cc4)c4cccc5ccccc45)cc3)cc2)cc1]

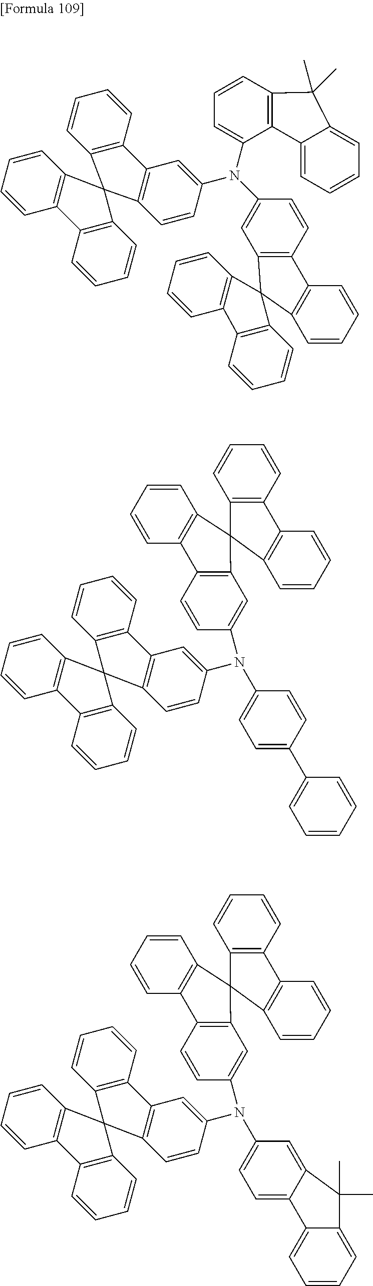 [SMILES: CC1(C)c2ccccc2-c2c(N(c3ccc4c(c3)-c3ccccc3C43c4ccccc4-c4ccccc43)c3ccc4c(c3)C3(c5ccccc5-c5ccccc53)c3ccccc3-4)cccc21 ; c1ccc(-c2ccc(N(c3ccc4c(c3)-c3ccccc3C43c4ccccc4-c4ccccc43)c3ccc4c(c3)C3(c5ccccc5-c5ccccc53)c3ccccc3-4)cc2)cc1 ; CC1(C)c2ccccc2-c2ccc(N(c3ccc4c(c3)-c3ccccc3C43c4ccccc4-c4ccccc43)c3ccc4c(c3)C3(c5ccccc5-c5ccccc53)c3ccccc3-4)cc21]

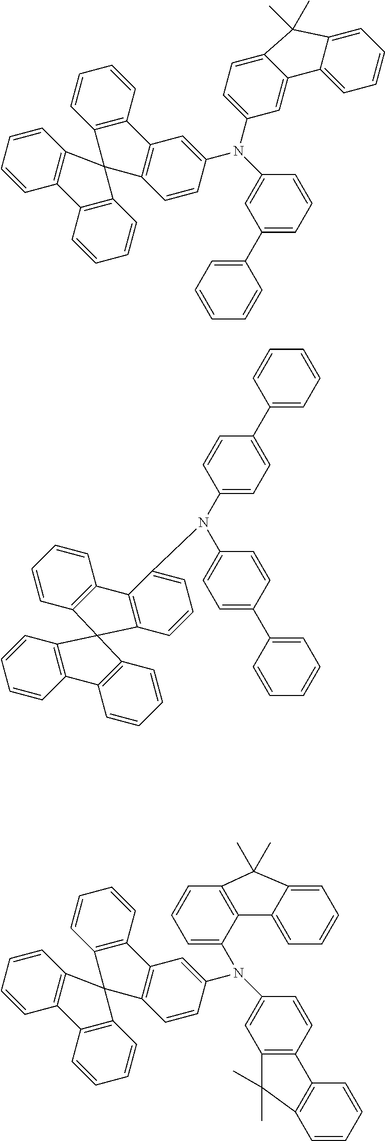

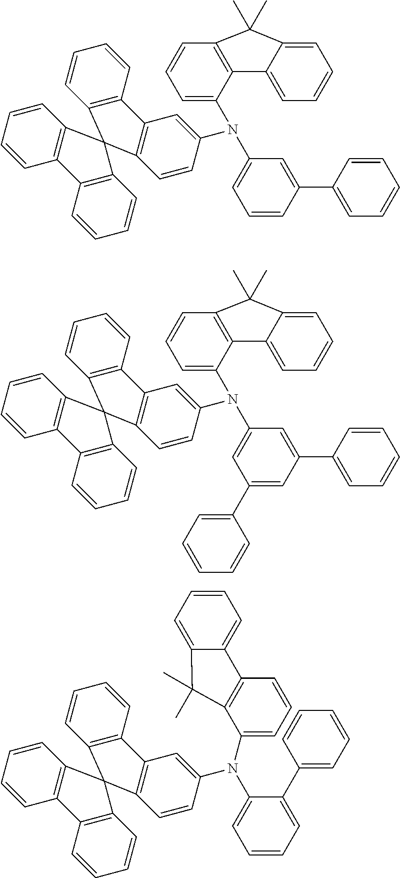

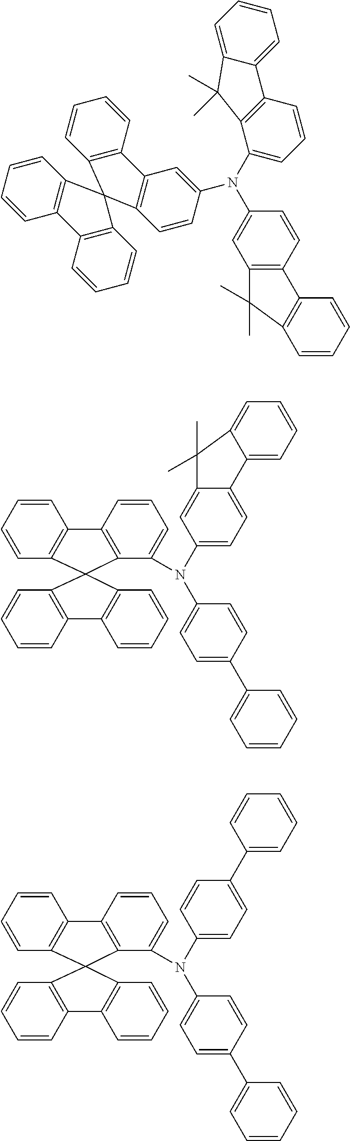

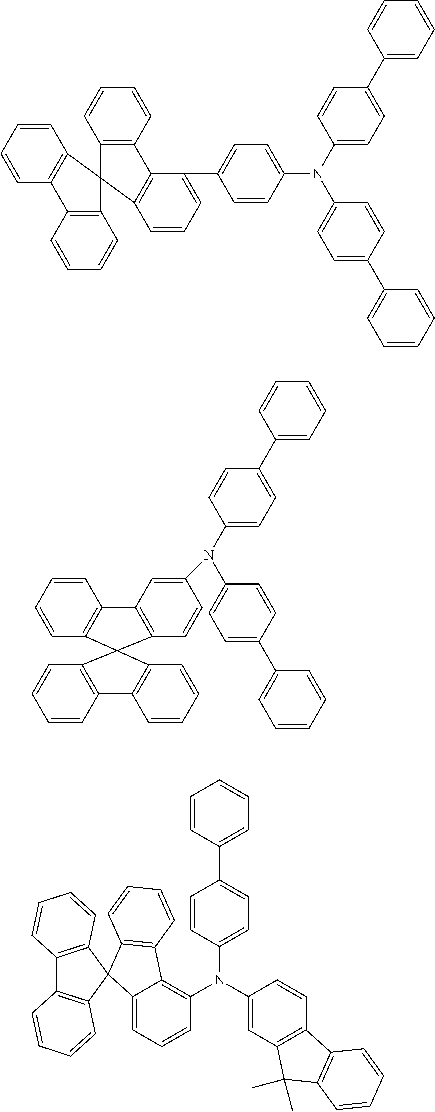 [SMILES: c1ccc(-c2ccc(N(c3ccc(-c4ccccc4)cc3)c3ccc(-c4cccc5c4-c4ccccc4C54c5ccccc5-c5ccccc54)cc3)cc2)cc1 ; c1ccc(-c2ccc(N(c3ccc(-c4ccccc4)cc3)c3ccc4c(c3)-c3ccccc3C43c4ccccc4-c4ccccc43)cc2)cc1 ; CC1(C)c2ccccc2-c2ccc(N(c3ccc(-c4ccccc4)cc3)c3cccc4c3-c3ccccc3C43c4ccccc4-c4ccccc43)cc21]

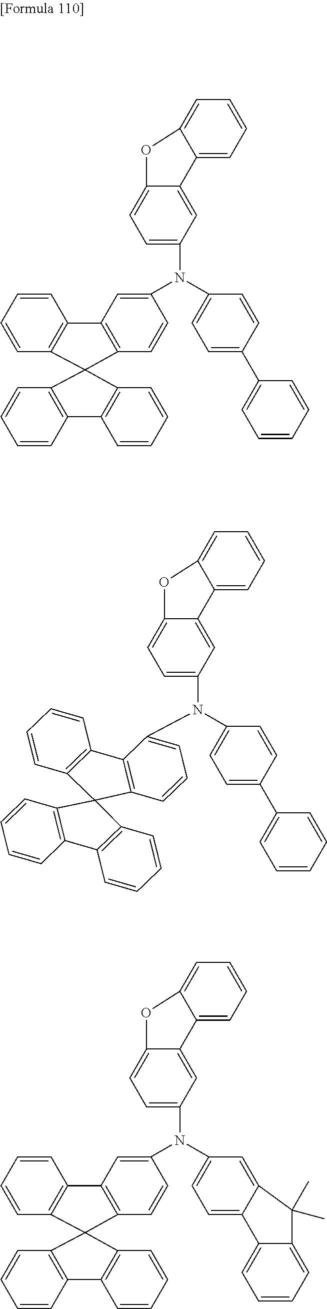 [SMILES: c1ccc(-c2ccc(N(c3ccc4c(c3)-c3ccccc3C43c4ccccc4-c4ccccc43)c3ccc4oc5ccccc5c4c3)cc2)cc1 ; c1ccc(-c2ccc(N(c3ccc4oc5ccccc5c4c3)c3cccc4c3-c3ccccc3C43c4ccccc4-c4ccccc43)cc2)cc1 ; CC1(C)c2ccccc2-c2ccc(N(c3ccc4c(c3)-c3ccccc3C43c4ccccc4-c4ccccc43)c3ccc4oc5ccccc5c4c3)cc21]

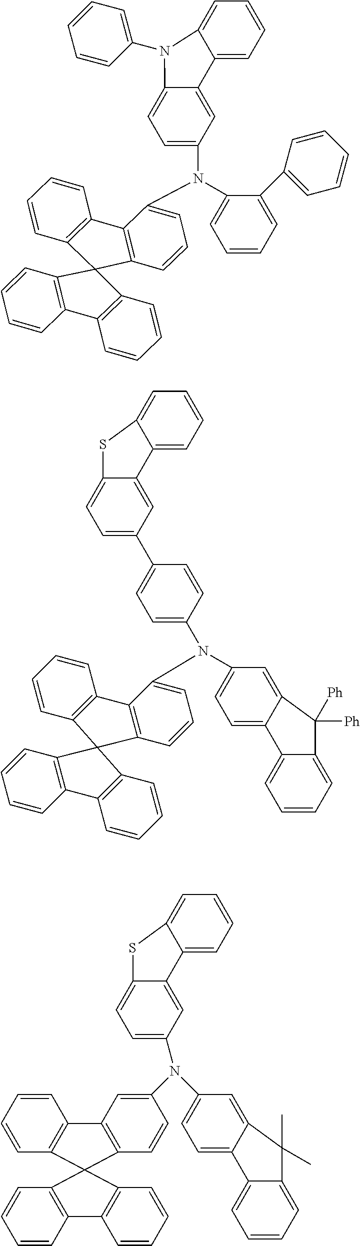

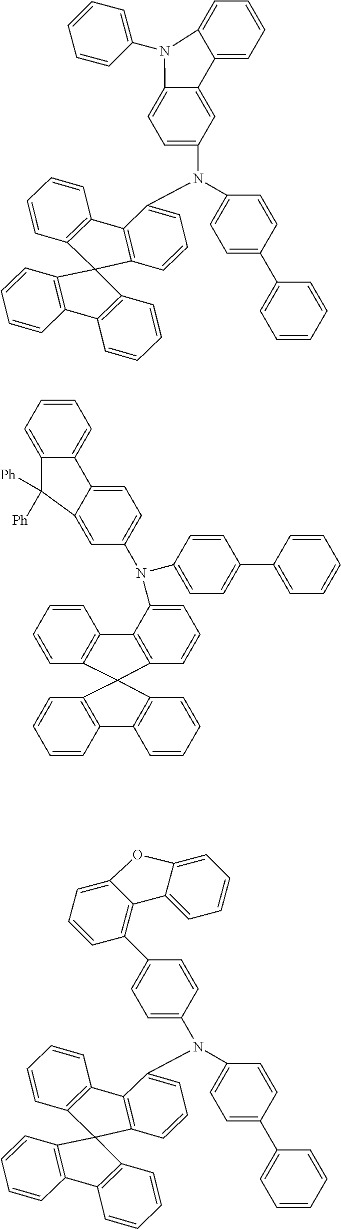 [SMILES: c1ccc(-c2ccc(N(c3ccc4c(c3)c3ccccc3n4-c3ccccc3)c3cccc4c3-c3ccccc3C43c4ccccc4-c4ccccc43)cc2)cc1 ; c1ccc(-c2ccc(N(c3ccc4c(c3)C(c3ccccc3)(c3ccccc3)c3ccccc3-4)c3cccc4c3-c3ccccc3C43c4ccccc4-c4ccccc43)cc2)cc1 ; c1ccc(-c2ccc(N(c3ccc(-c4cccc5oc6ccccc6c45)cc3)c3cccc4c3-c3ccccc3C43c4ccccc4-c4ccccc43)cc2)cc1]

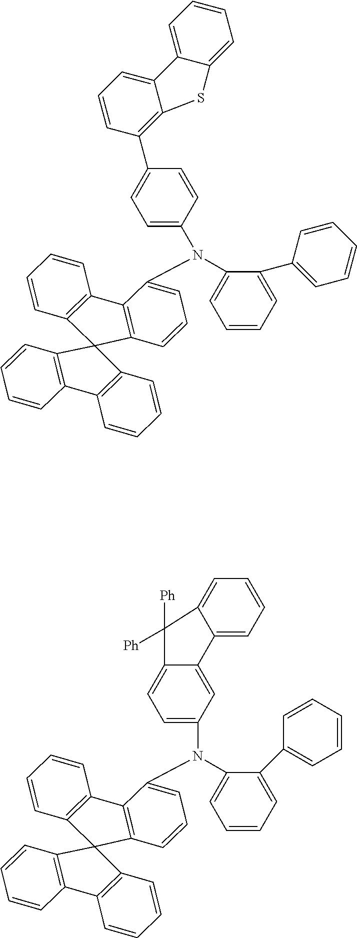 [SMILES: c1ccc(-c2ccccc2N(c2ccc(-c3cccc4c3sc3ccccc34)cc2)c2cccc3c2-c2ccccc2C32c3ccccc3-c3ccccc32)cc1 ; c1ccc(-c2ccccc2N(c2ccc3c(c2)-c2ccccc2C3(c2ccccc2)c2ccccc2)c2cccc3c2-c2ccccc2C32c3ccccc3-c3ccccc32)cc1]

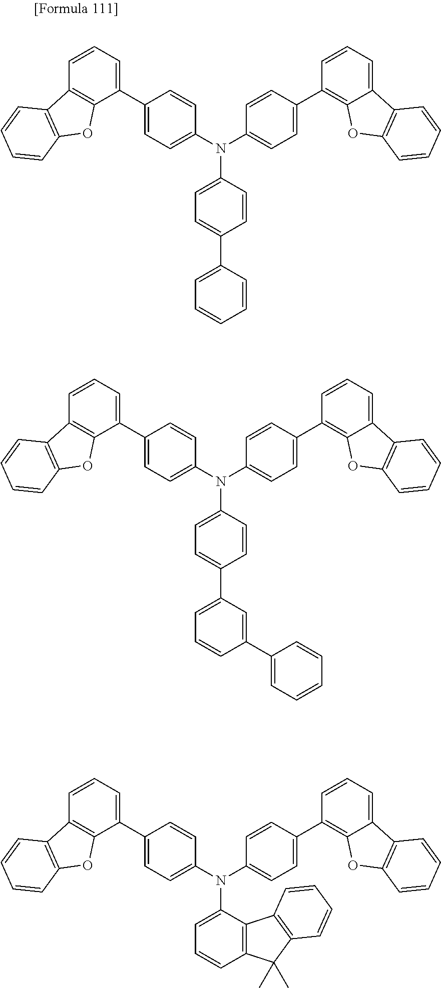 [SMILES: c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2cccc(-c3ccc(N(c4ccc(-c5cccc6c5oc5ccccc56)cc4)c4ccc(-c5cccc6c5oc5ccccc56)cc4)cc3)c2)cc1 ; CC1(C)c2ccccc2-c2c(N(c3ccc(-c4cccc5c4oc4ccccc45)cc3)c3ccc(-c4cccc5c4oc4ccccc45)cc3)cccc21]

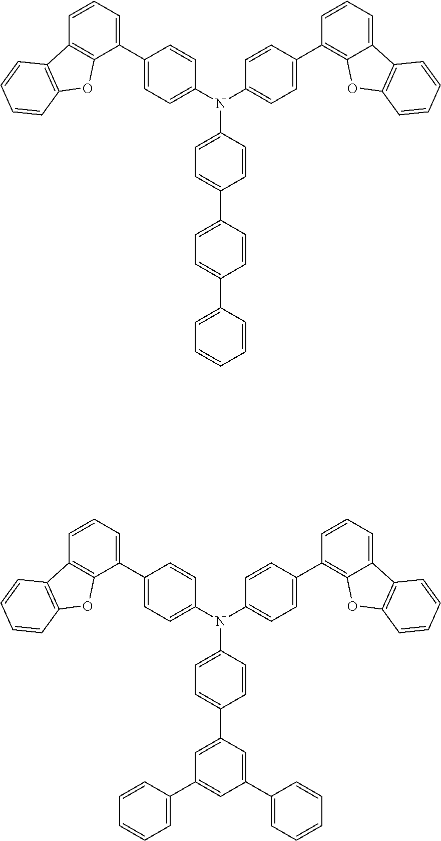 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1]

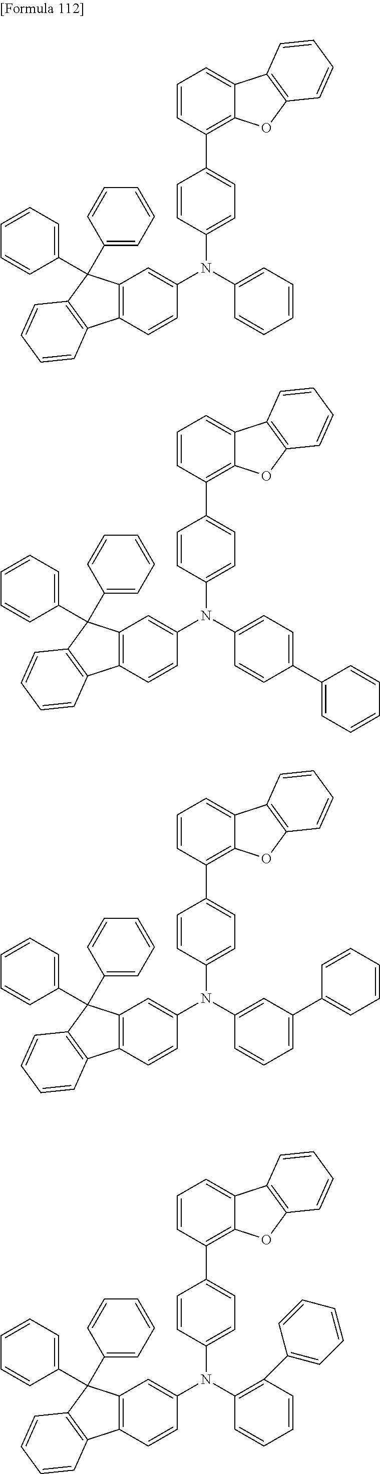 [SMILES: c1ccc(N(c2ccc(-c3cccc4c3oc3ccccc34)cc2)c2ccc3c(c2)C(c2ccccc2)(c2ccccc2)c2ccccc2-3)cc1 ; c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; c1ccc(-c2cccc(N(c3ccc(-c4cccc5c4oc4ccccc45)cc3)c3ccc4c(c3)C(c3ccccc3)(c3ccccc3)c3ccccc3-4)c2)cc1 ; c1ccc(-c2ccccc2N(c2ccc(-c3cccc4c3oc3ccccc34)cc2)c2ccc3c(c2)C(c2ccccc2)(c2ccccc2)c2ccccc2-3)cc1]

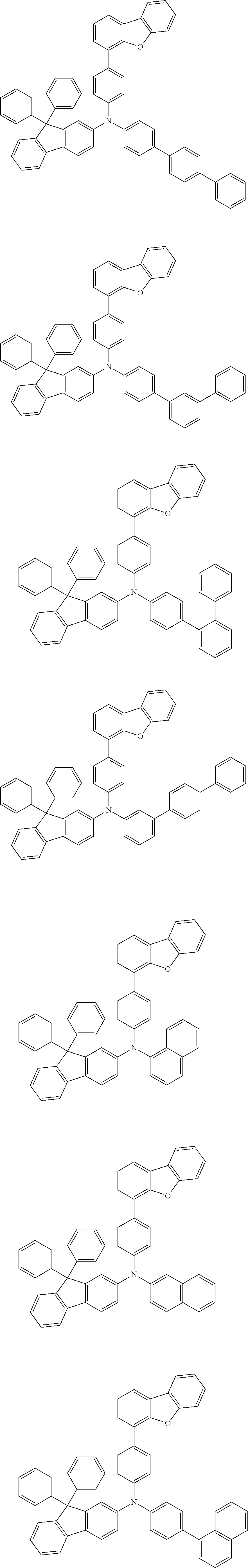

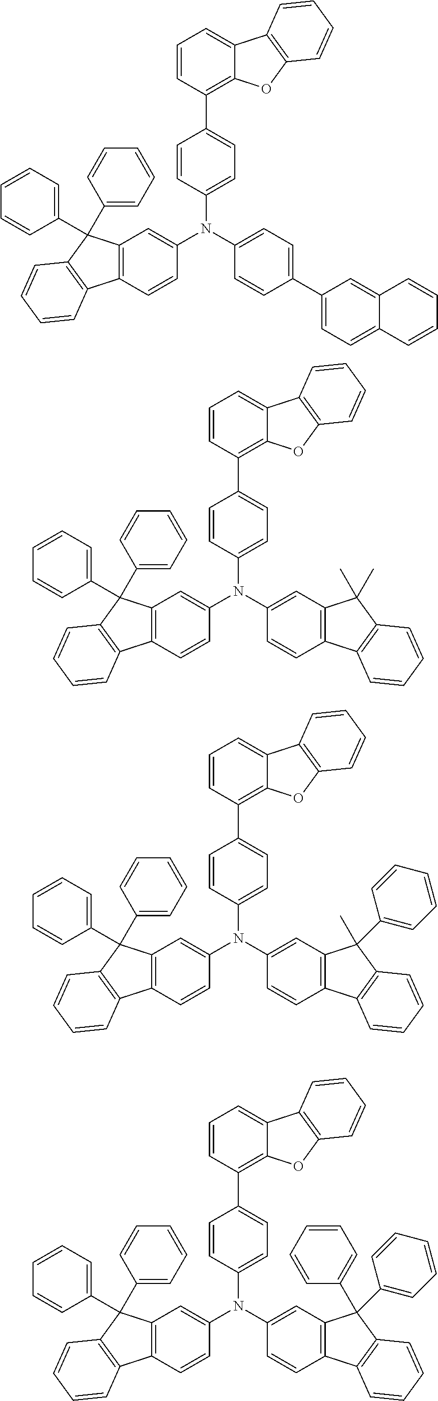

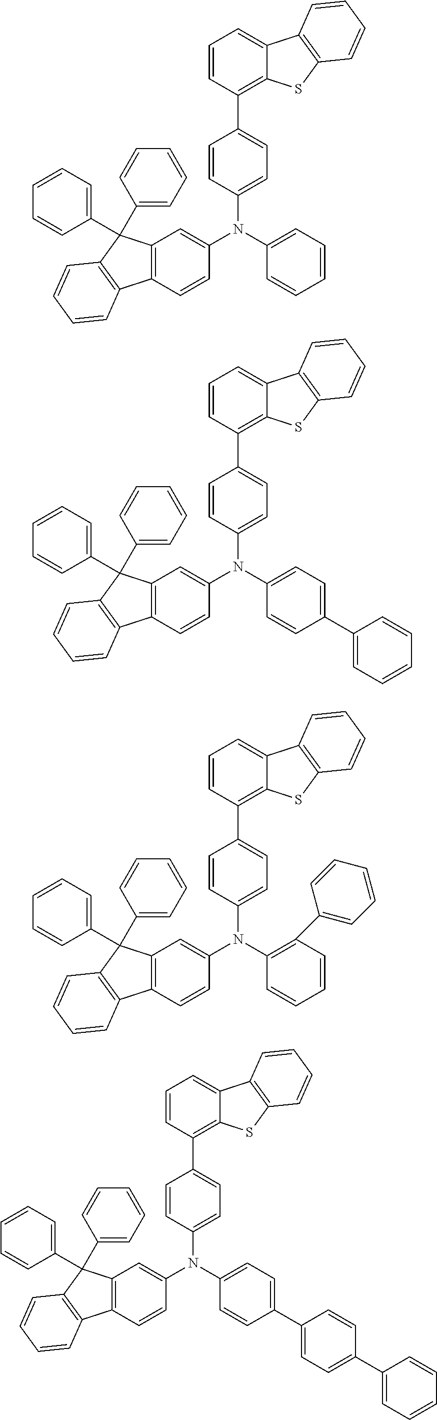

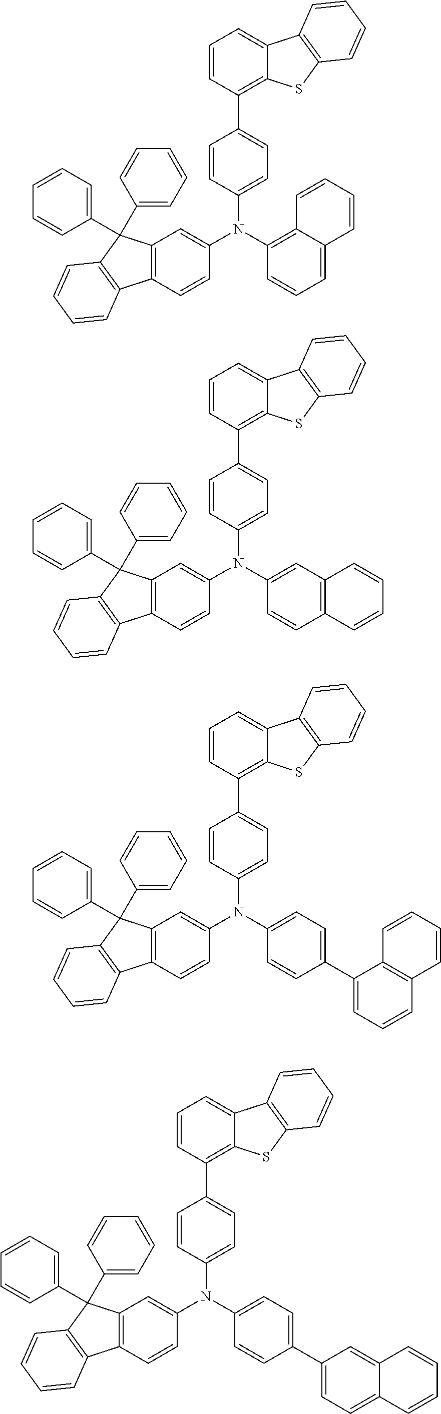

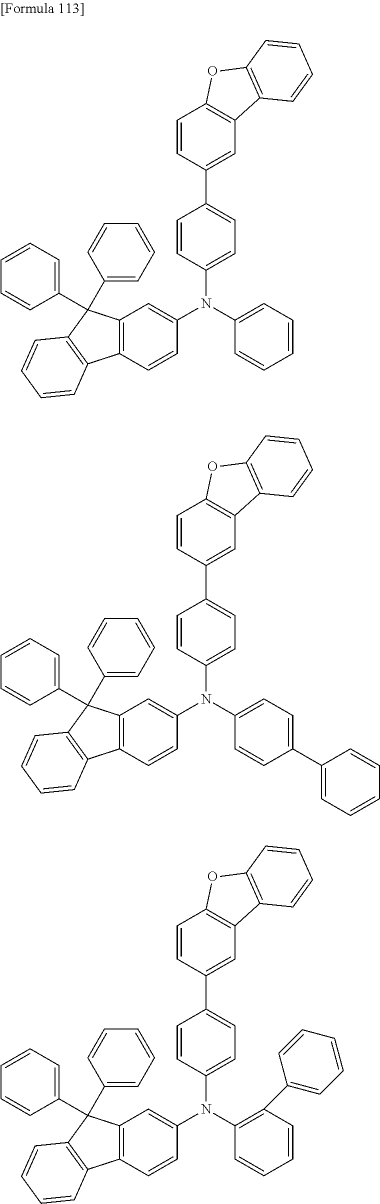 [SMILES: c1ccc(N(c2ccc(-c3ccc4oc5ccccc5c4c3)cc2)c2ccc3c(c2)C(c2ccccc2)(c2ccccc2)c2ccccc2-3)cc1 ; c1ccc(-c2ccc(N(c3ccc(-c4ccc5oc6ccccc6c5c4)cc3)c3ccc4c(c3)C(c3ccccc3)(c3ccccc3)c3ccccc3-4)cc2)cc1 ; c1ccc(-c2ccccc2N(c2ccc(-c3ccc4oc5ccccc5c4c3)cc2)c2ccc3c(c2)C(c2ccccc2)(c2ccccc2)c2ccccc2-3)cc1]

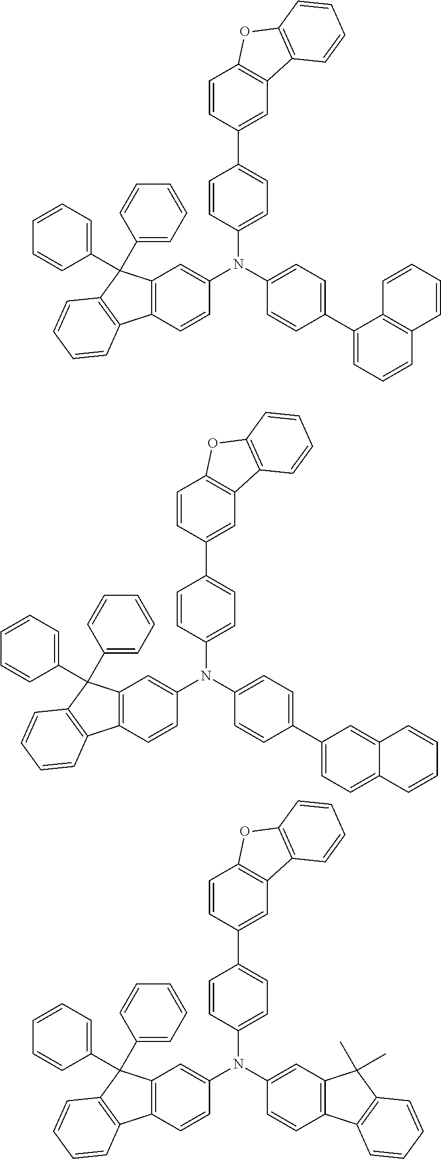

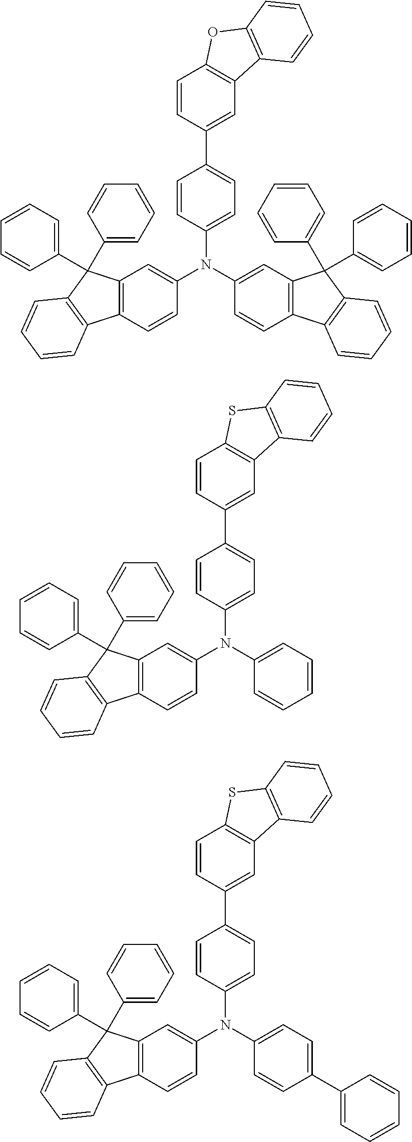

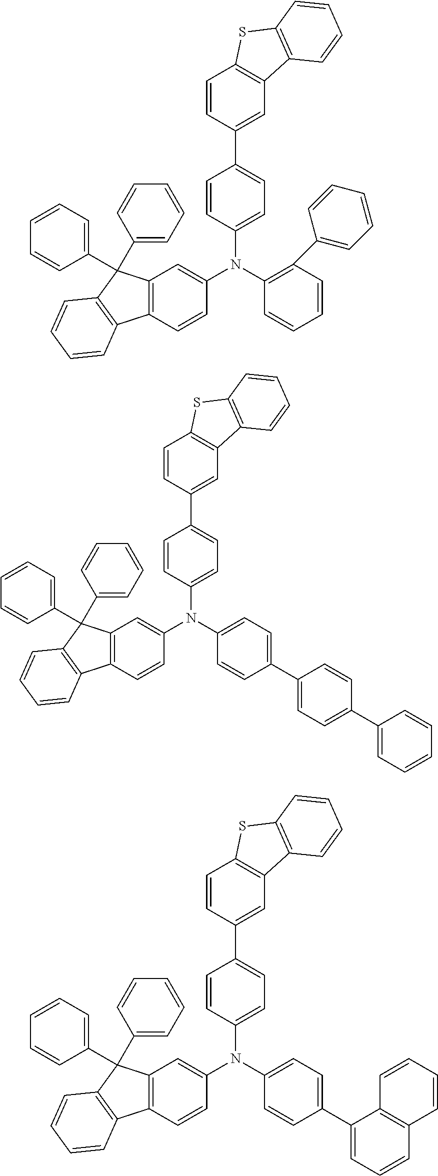 [SMILES: c1ccc(-c2ccccc2N(c2ccc(-c3ccc4sc5ccccc5c4c3)cc2)c2ccc3c(c2)C(c2ccccc2)(c2ccccc2)c2ccccc2-3)cc1 ; c1ccc(-c2ccc(-c3ccc(N(c4ccc(-c5ccc6sc7ccccc7c6c5)cc4)c4ccc5c(c4)C(c4ccccc4)(c4ccccc4)c4ccccc4-5)cc3)cc2)cc1 ; c1ccc(C2(c3ccccc3)c3ccccc3-c3ccc(N(c4ccc(-c5ccc6sc7ccccc7c6c5)cc4)c4ccc(-c5cccc6ccccc56)cc4)cc32)cc1]

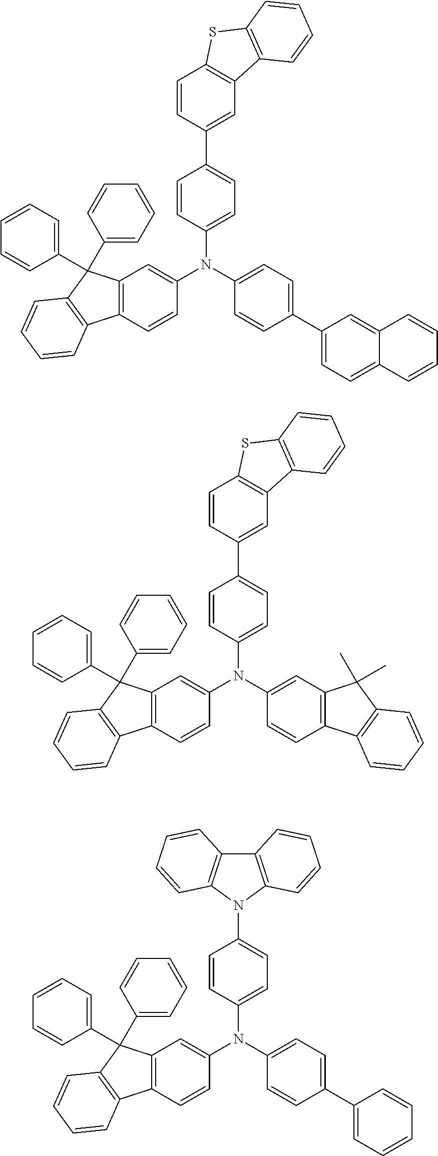

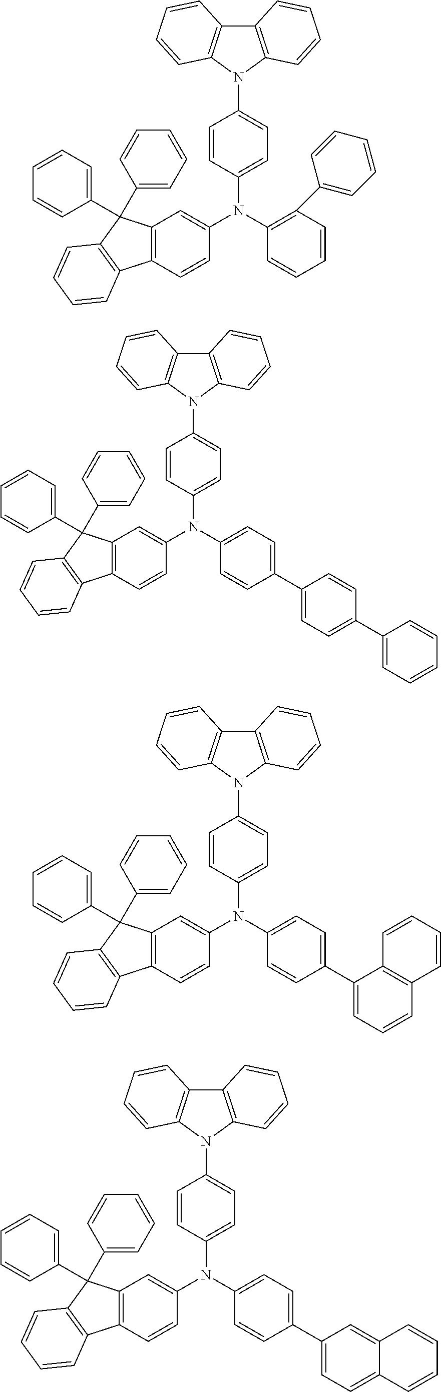

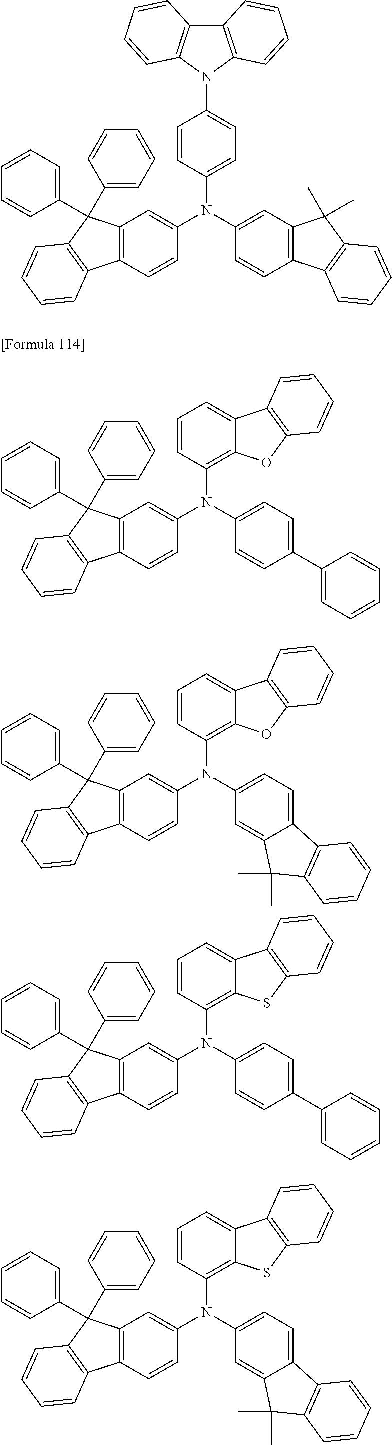

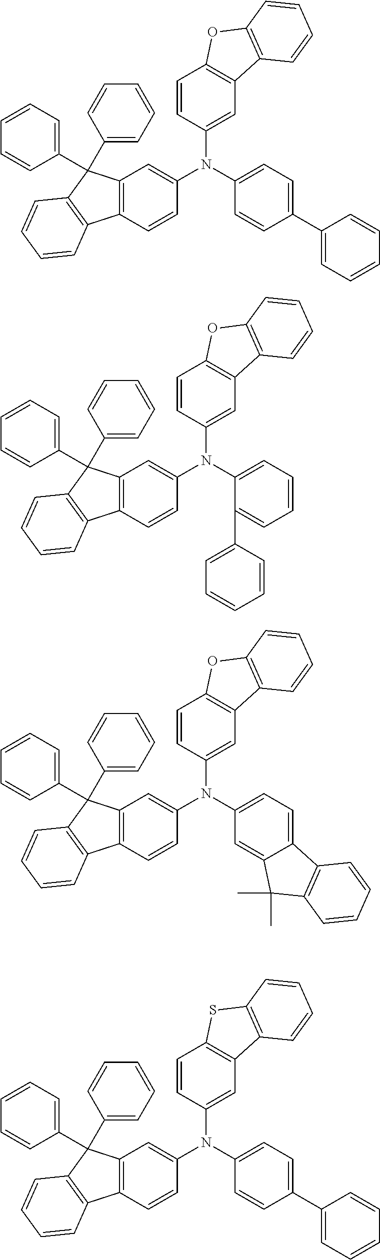

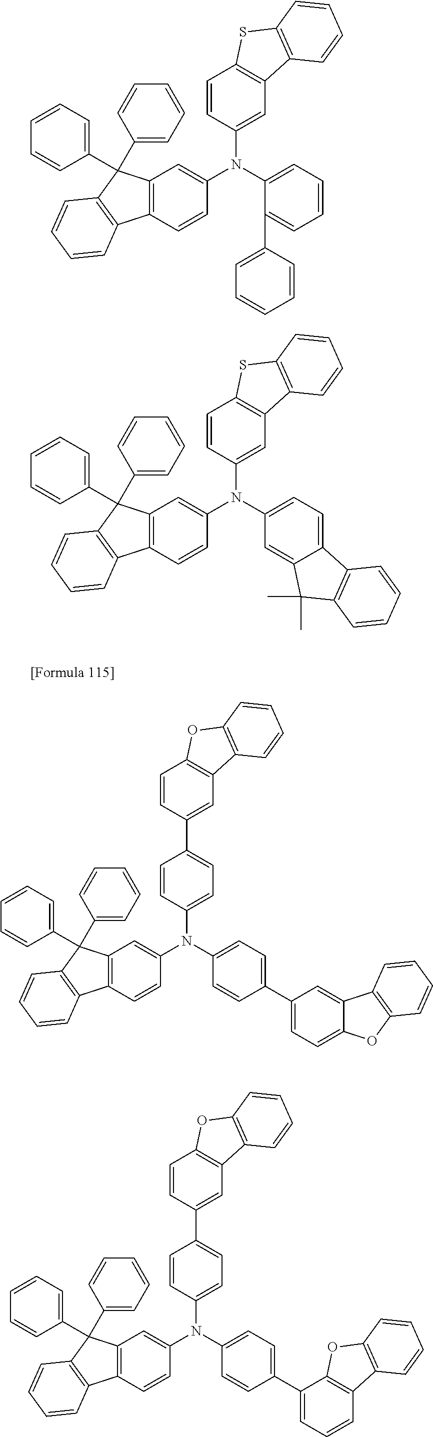

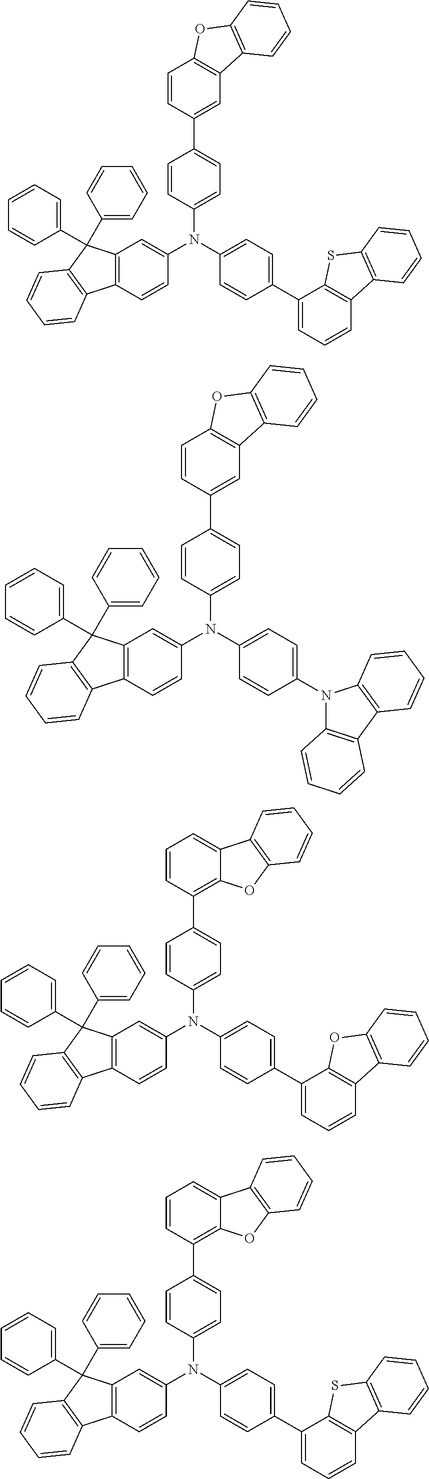

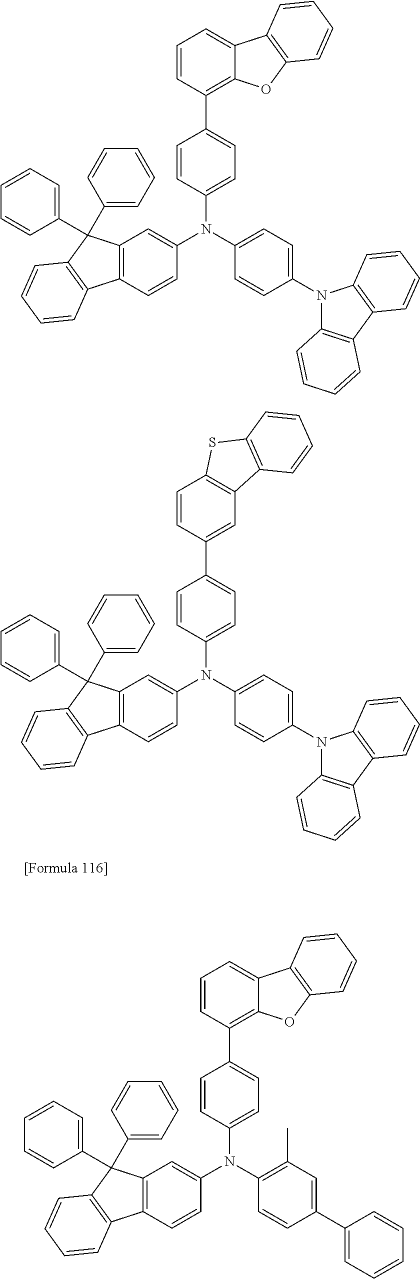

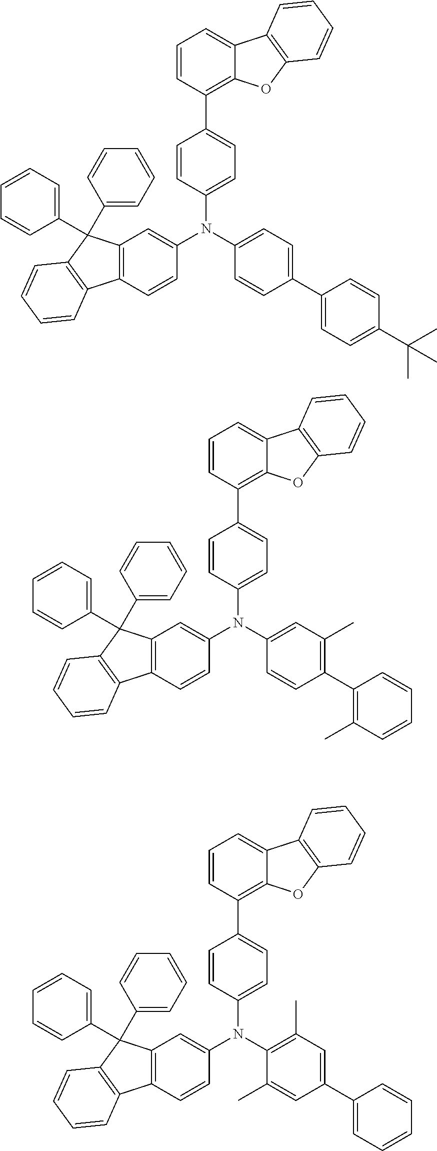 [SMILES: CC(C)(C)c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; Cc1ccccc1-c1ccc(N(c2ccc(-c3cccc4c3oc3ccccc34)cc2)c2ccc3c(c2)C(c2ccccc2)(c2ccccc2)c2ccccc2-3)cc1C ; Cc1cc(-c2ccccc2)cc(C)c1N(c1ccc(-c2cccc3c2oc2ccccc23)cc1)c1ccc2c(c1)C(c1ccccc1)(c1ccccc1)c1ccccc1-2]

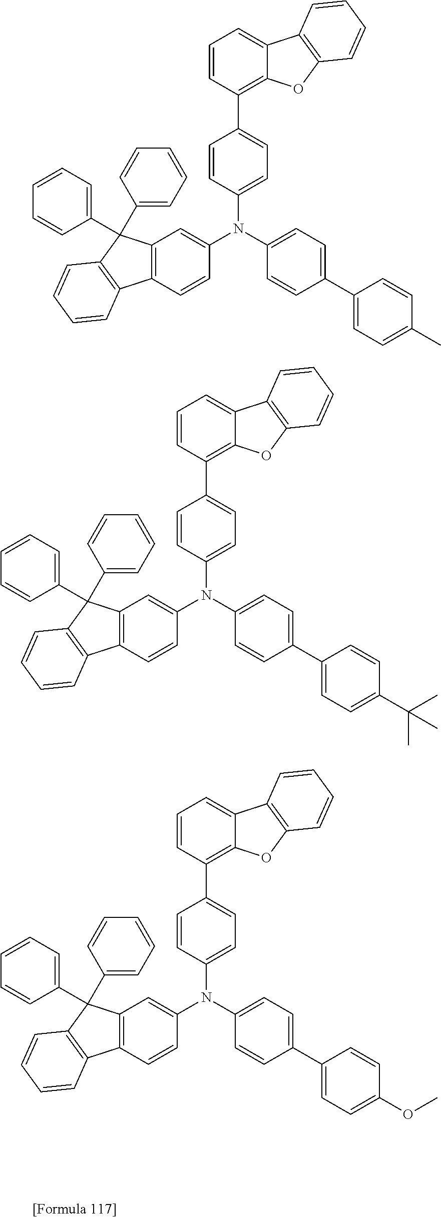 [SMILES: Cc1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; CC(C)(C)c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; COc1ccc(-c2ccc(N(c3ccc(-c4cccc5c4oc4ccccc45)cc3)c3ccc4c(c3)C(c3ccccc3)(c3ccccc3)c3ccccc3-4)cc2)cc1]

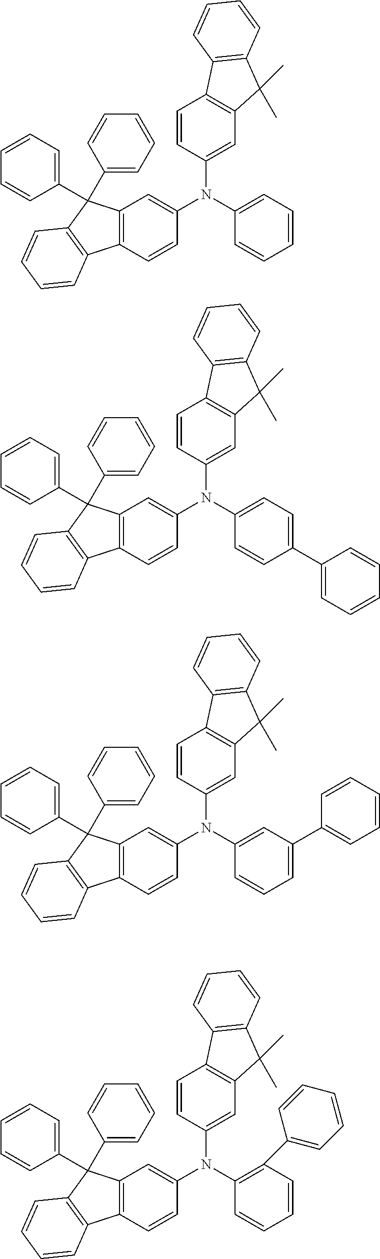 [SMILES: CC1(C)c2ccccc2-c2ccc(N(c3ccccc3)c3ccc4c(c3)C(c3ccccc3)(c3ccccc3)c3ccccc3-4)cc21 ; CC1(C)c2ccccc2-c2ccc(N(c3ccc(-c4ccccc4)cc3)c3ccc4c(c3)C(c3ccccc3)(c3ccccc3)c3ccccc3-4)cc21 ; CC1(C)c2ccccc2-c2ccc(N(c3cccc(-c4ccccc4)c3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccccc3-c3ccccc3)cc21]

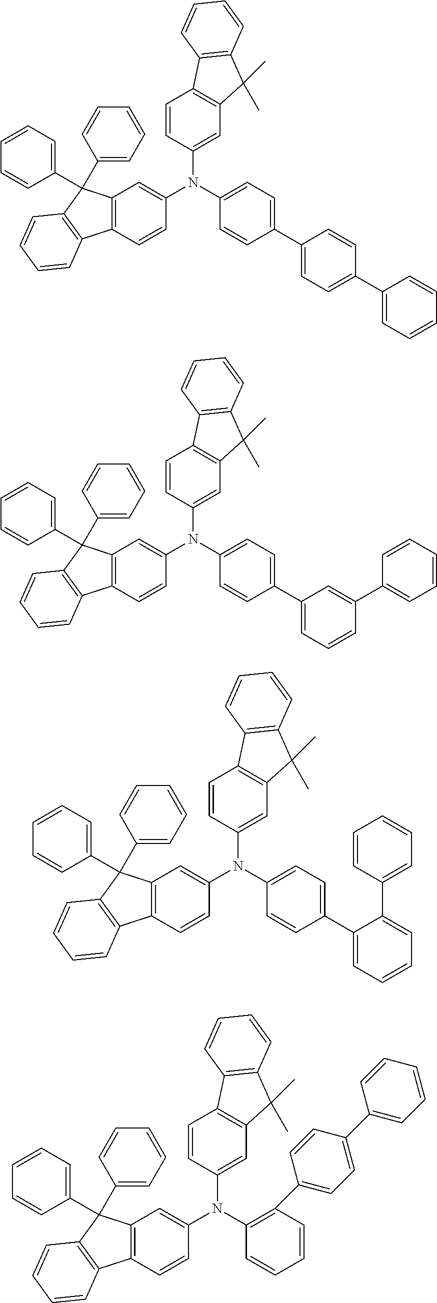 [SMILES: CC1(C)c2ccccc2-c2ccc(N(c3ccc(-c4ccc(-c5ccccc5)cc4)cc3)c3ccc4c(c3)C(c3ccccc3)(c3ccccc3)c3ccccc3-4)cc21 ; CC1(C)c2ccccc2-c2ccc(N(c3ccc(-c4cccc(-c5ccccc5)c4)cc3)c3ccc4c(c3)C(c3ccccc3)(c3ccccc3)c3ccccc3-4)cc21 ; CC1(C)c2ccccc2-c2ccc(N(c3ccc(-c4ccccc4-c4ccccc4)cc3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccccc3-c3ccc(-c4ccccc4)cc3)cc21]

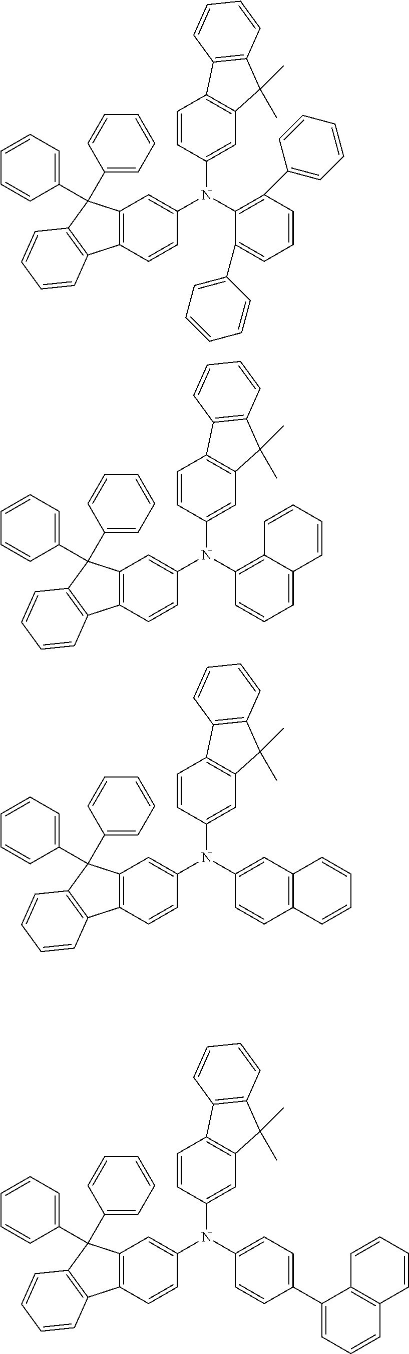

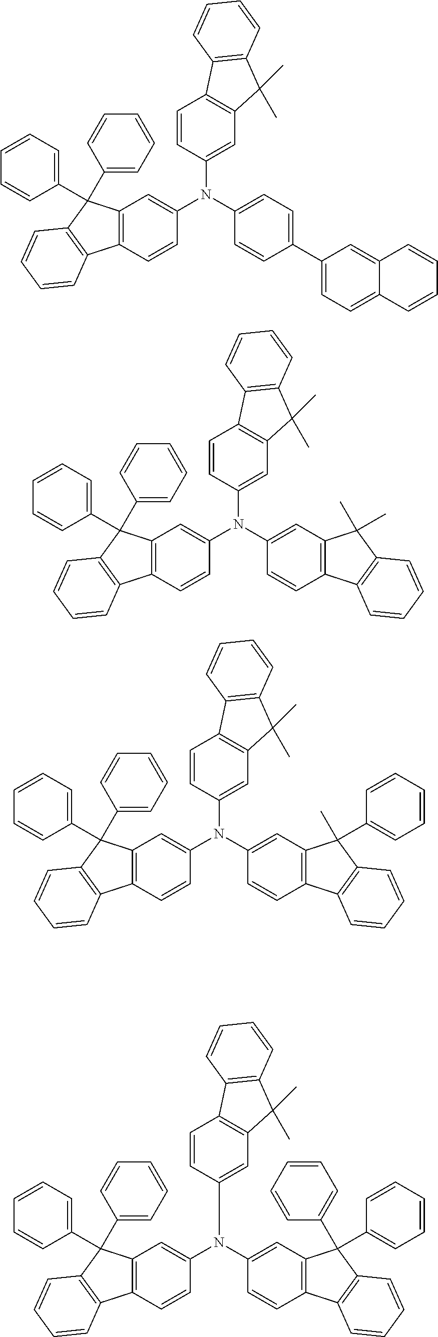 [SMILES: CC1(C)c2ccccc2-c2ccc(N(c3ccc(-c4ccc5ccccc5c4)cc3)c3ccc4c(c3)C(c3ccccc3)(c3ccccc3)c3ccccc3-4)cc21 ; CC1(C)c2ccccc2-c2ccc(N(c3ccc4c(c3)C(C)(C)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C(C)(c3ccccc3)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21]

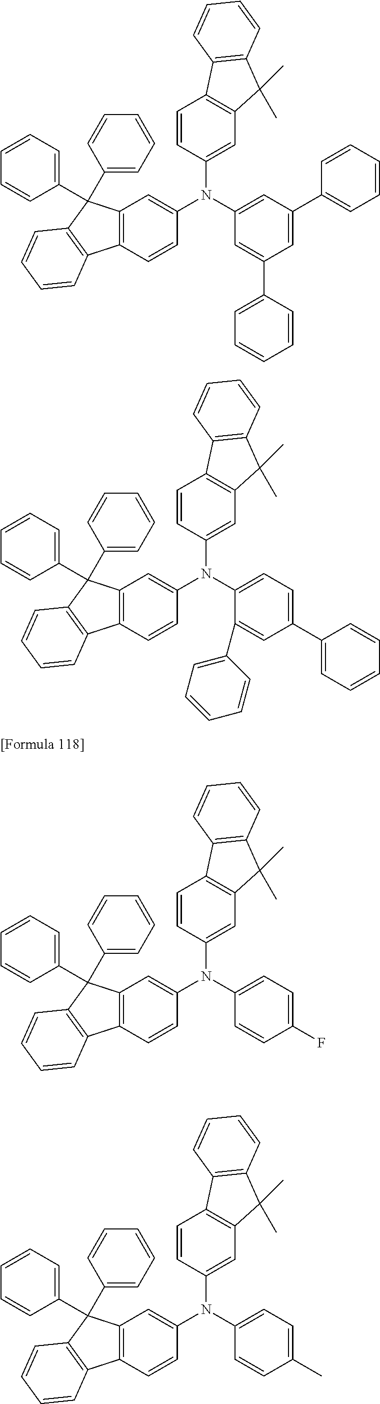

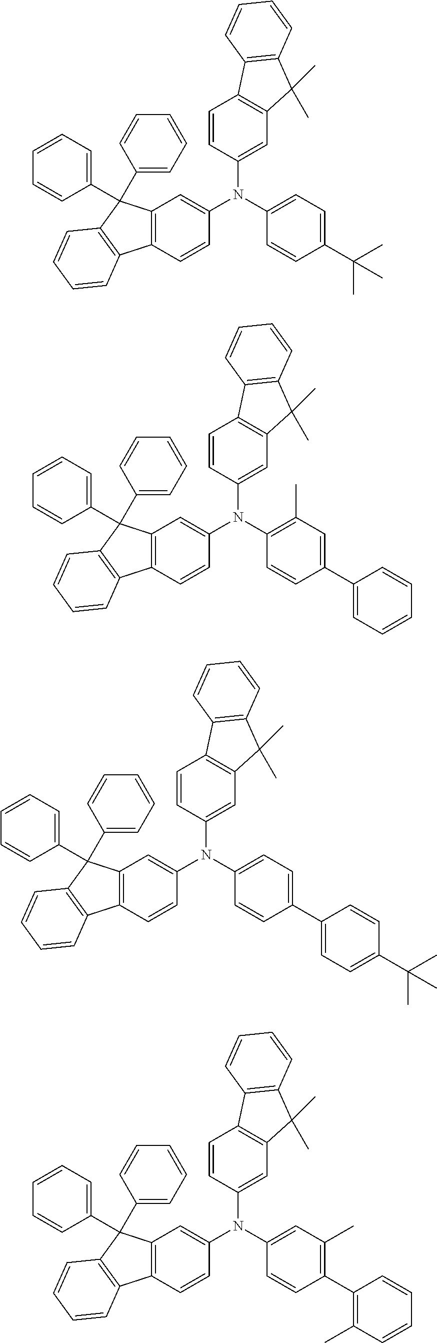 [SMILES: CC(C)(C)c1ccc(N(c2ccc3c(c2)C(C)(C)c2ccccc2-3)c2ccc3c(c2)C(c2ccccc2)(c2ccccc2)c2ccccc2-3)cc1 ; Cc1cc(-c2ccccc2)ccc1N(c1ccc2c(c1)C(C)(C)c1ccccc1-2)c1ccc2c(c1)C(c1ccccc1)(c1ccccc1)c1ccccc1-2 ; CC(C)(C)c1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; Cc1ccccc1-c1ccc(N(c2ccc3c(c2)C(C)(C)c2ccccc2-3)c2ccc3c(c2)C(c2ccccc2)(c2ccccc2)c2ccccc2-3)cc1C]

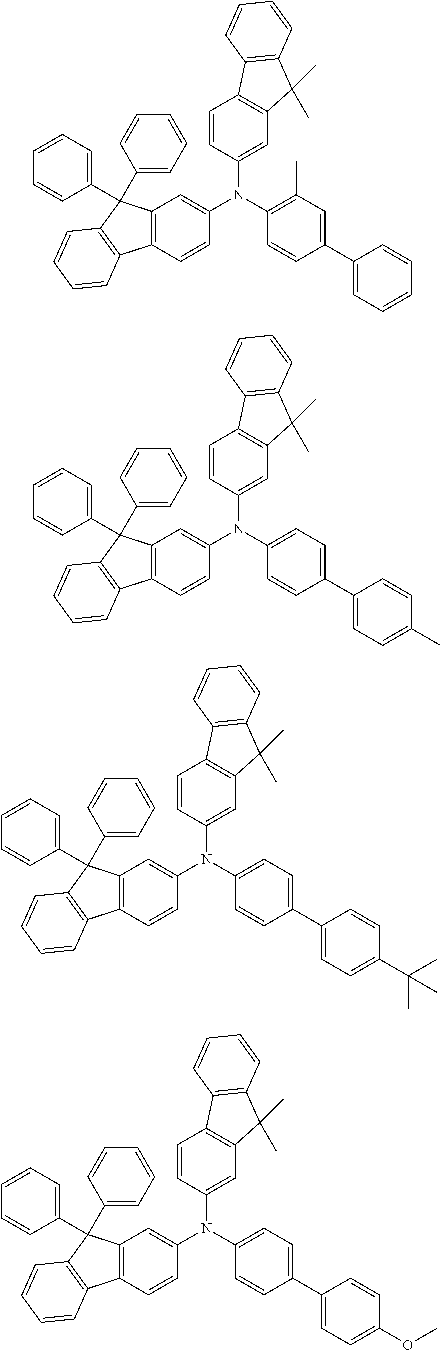 [SMILES: Cc1cc(-c2ccccc2)ccc1N(c1ccc2c(c1)C(C)(C)c1ccccc1-2)c1ccc2c(c1)C(c1ccccc1)(c1ccccc1)c1ccccc1-2 ; Cc1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; CC(C)(C)c1ccc(-c2ccc(N(c3ccc4c(c3)C(C)(C)c3ccccc3-4)c3ccc4c(c3)C(c3ccccc3)(c3ccccc3)c3ccccc3-4)cc2)cc1 ; COc1ccc(-c2ccc(N(c3ccc4c(c3)C(C)(C)c3ccccc3-4)c3ccc4c(c3)C(c3ccccc3)(c3ccccc3)c3ccccc3-4)cc2)cc1]

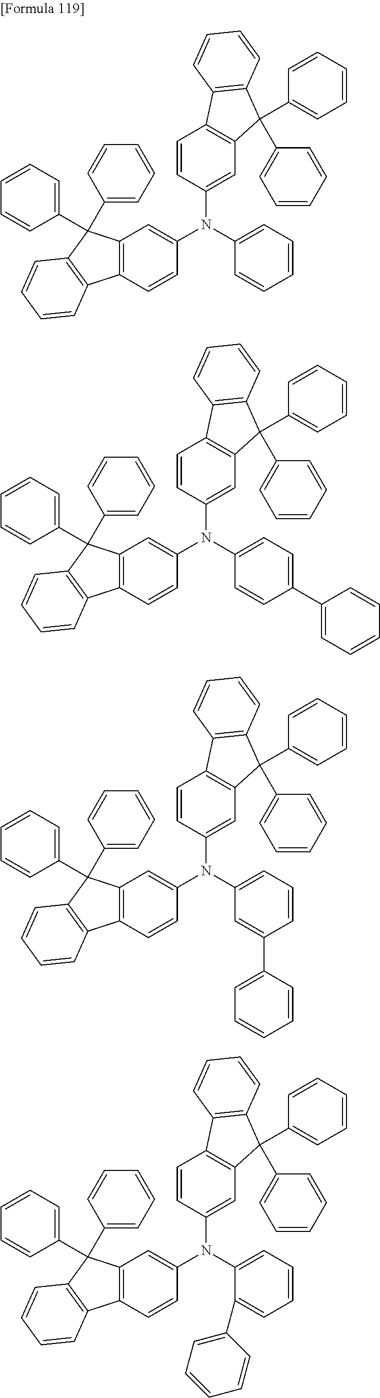

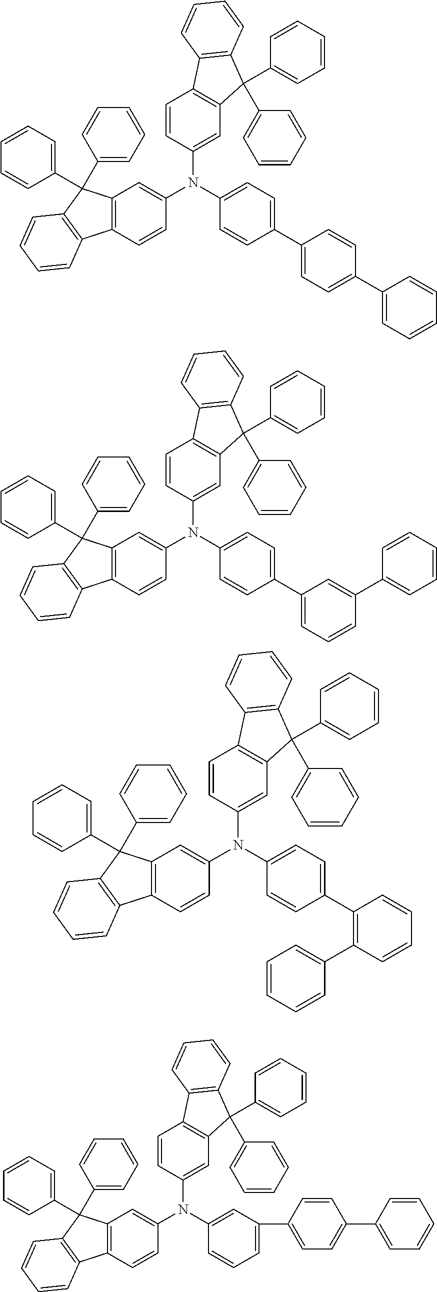

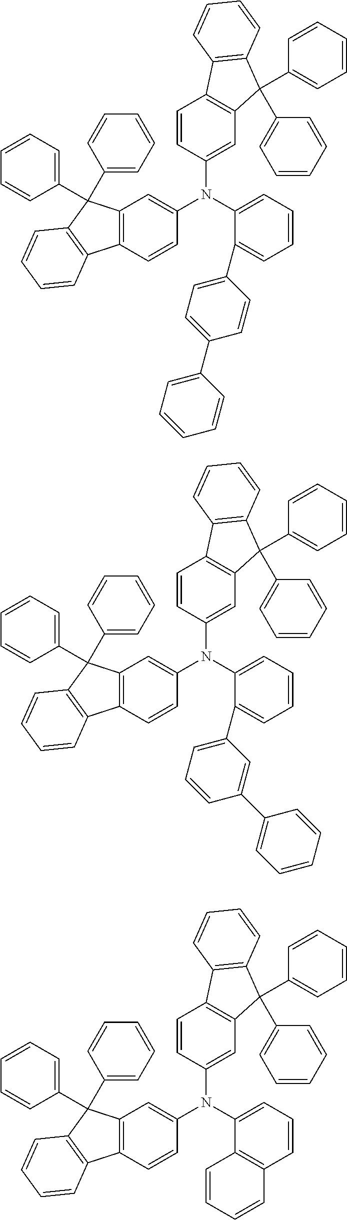

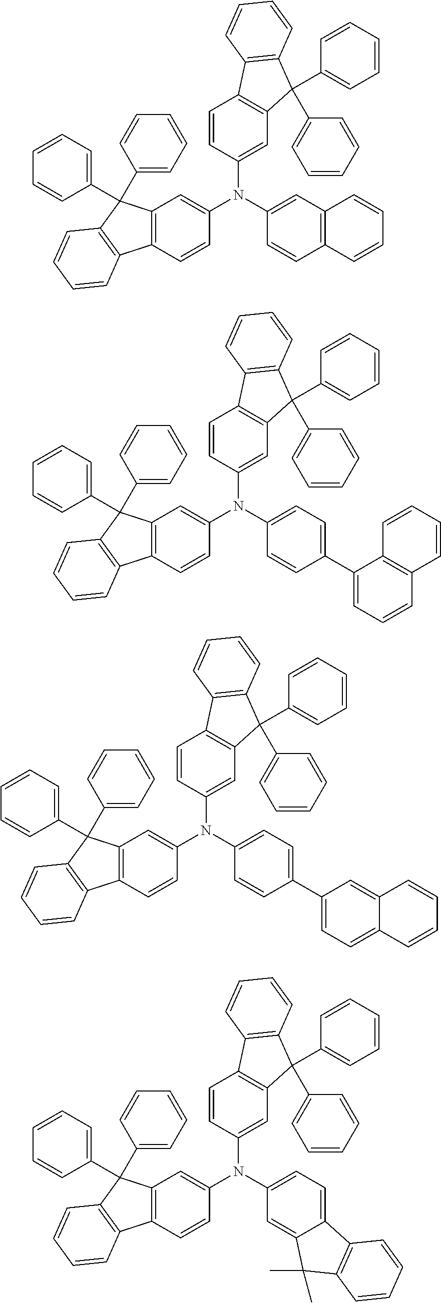 [SMILES: c1ccc(C2(c3ccccc3)c3ccccc3-c3ccc(N(c4ccc5c(c4)C(c4ccccc4)(c4ccccc4)c4ccccc4-5)c4ccc5ccccc5c4)cc32)cc1 ; c1ccc(C2(c3ccccc3)c3ccccc3-c3ccc(N(c4ccc(-c5cccc6ccccc56)cc4)c4ccc5c(c4)C(c4ccccc4)(c4ccccc4)c4ccccc4-5)cc32)cc1 ; c1ccc(C2(c3ccccc3)c3ccccc3-c3ccc(N(c4ccc(-c5ccc6ccccc6c5)cc4)c4ccc5c(c4)C(c4ccccc4)(c4ccccc4)c4ccccc4-5)cc32)cc1 ; CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21]

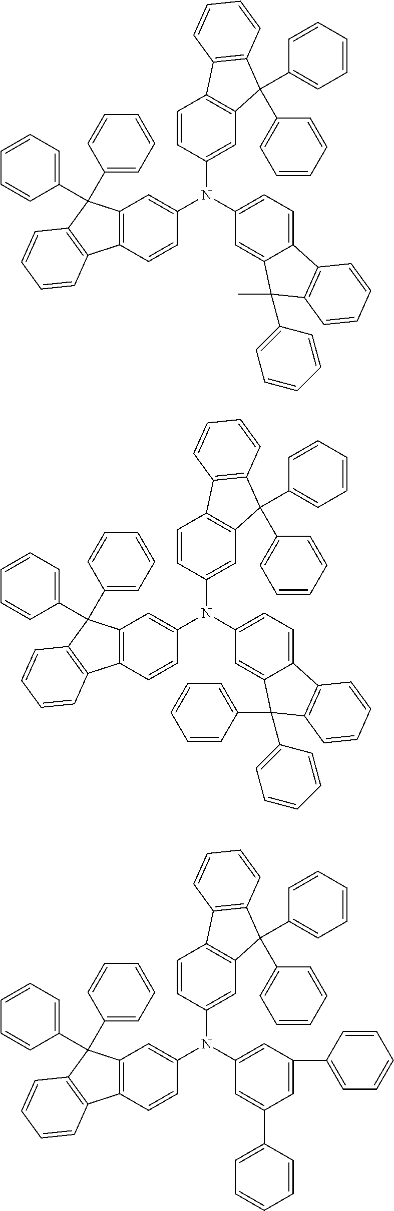

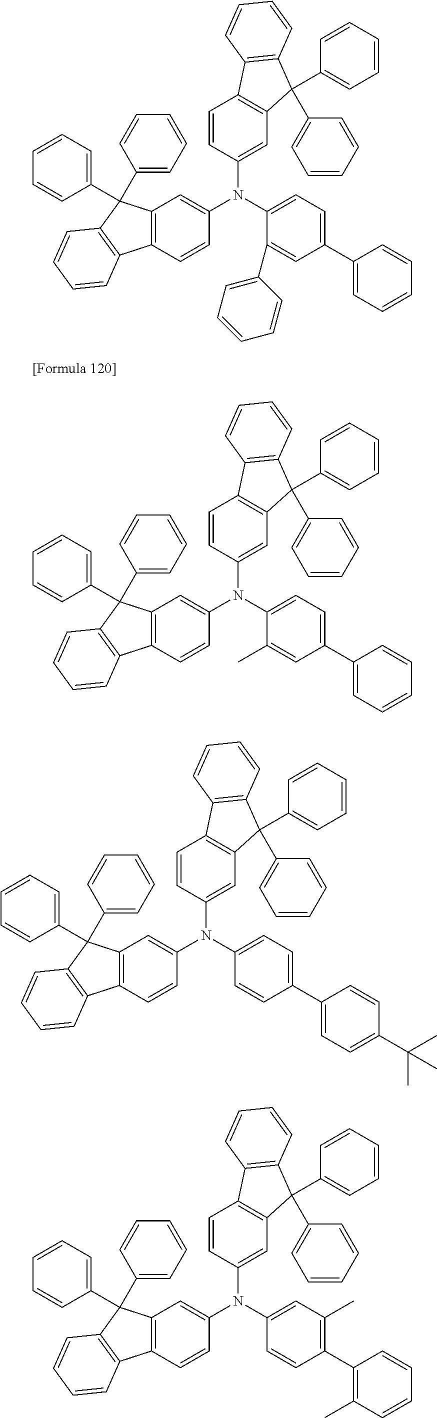 [SMILES: c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)c(-c3ccccc3)c2)cc1 ; Cc1cc(-c2ccccc2)ccc1N(c1ccc2c(c1)C(c1ccccc1)(c1ccccc1)c1ccccc1-2)c1ccc2c(c1)C(c1ccccc1)(c1ccccc1)c1ccccc1-2 ; CC(C)(C)c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; Cc1ccccc1-c1ccc(N(c2ccc3c(c2)C(c2ccccc2)(c2ccccc2)c2ccccc2-3)c2ccc3c(c2)C(c2ccccc2)(c2ccccc2)c2ccccc2-3)cc1C]

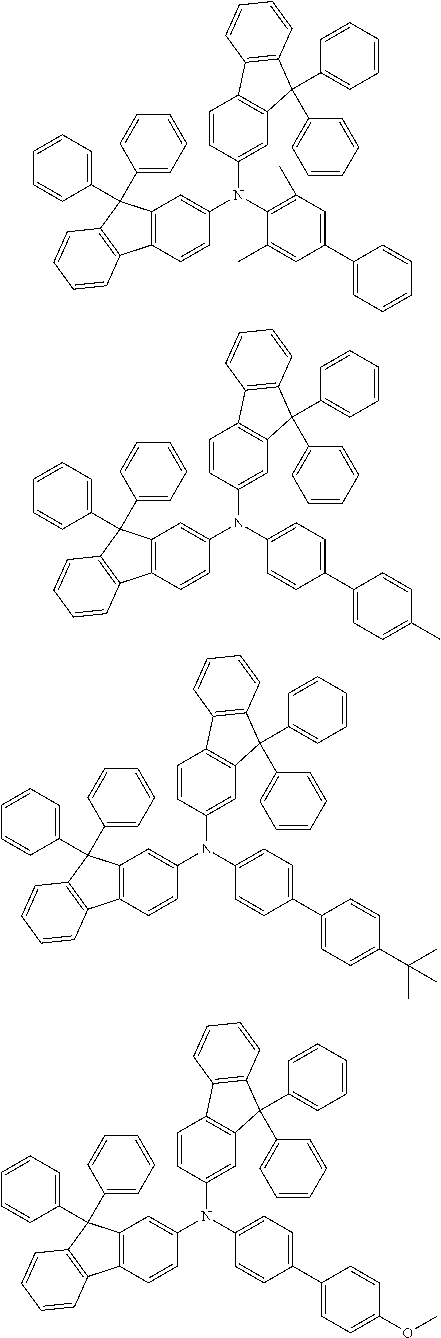 [SMILES: Cc1cc(-c2ccccc2)cc(C)c1N(c1ccc2c(c1)C(c1ccccc1)(c1ccccc1)c1ccccc1-2)c1ccc2c(c1)C(c1ccccc1)(c1ccccc1)c1ccccc1-2 ; Cc1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; CC(C)(C)c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; COc1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1]

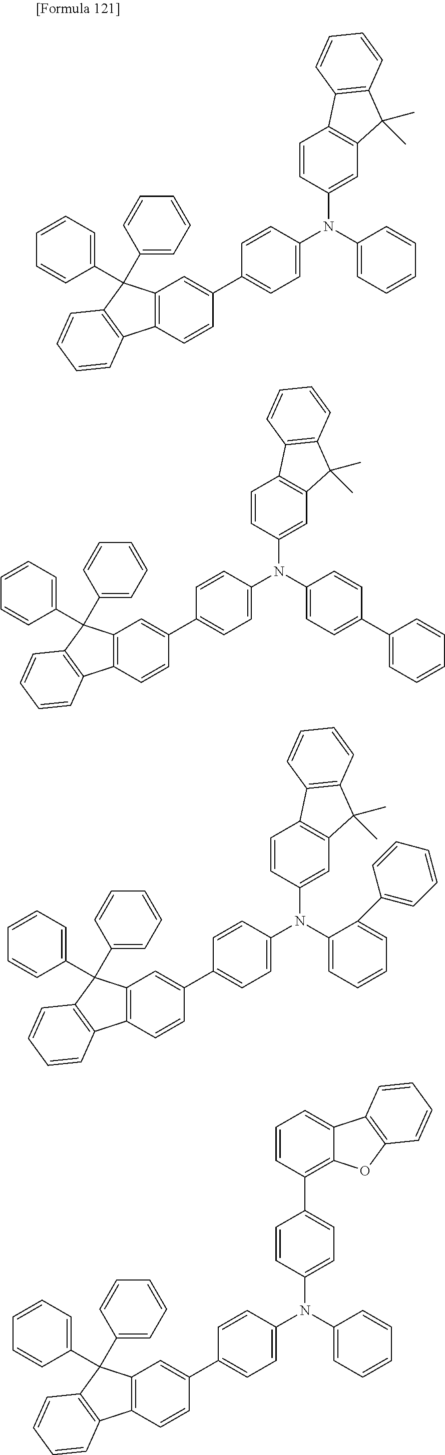 [SMILES: CC1(C)c2ccccc2-c2ccc(N(c3ccccc3)c3ccc(-c4ccc5c(c4)C(c4ccccc4)(c4ccccc4)c4ccccc4-5)cc3)cc21 ; CC1(C)c2ccccc2-c2ccc(N(c3ccc(-c4ccccc4)cc3)c3ccc(-c4ccc5c(c4)C(c4ccccc4)(c4ccccc4)c4ccccc4-5)cc3)cc21 ; CC1(C)c2ccccc2-c2ccc(N(c3ccc(-c4ccc5c(c4)C(c4ccccc4)(c4ccccc4)c4ccccc4-5)cc3)c3ccccc3-c3ccccc3)cc21 ; c1ccc(N(c2ccc(-c3ccc4c(c3)C(c3ccccc3)(c3ccccc3)c3ccccc3-4)cc2)c2ccc(-c3cccc4c3oc3ccccc34)cc2)cc1]

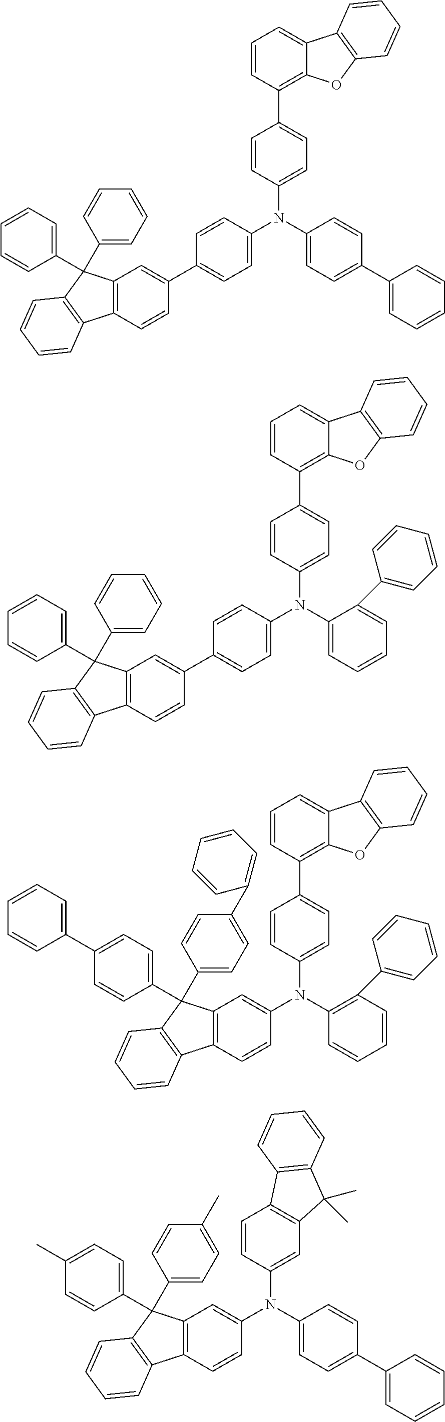 [SMILES: c1ccc(-c2ccc(N(c3ccc(-c4ccc5c(c4)C(c4ccccc4)(c4ccccc4)c4ccccc4-5)cc3)c3ccc(-c4cccc5c4oc4ccccc45)cc3)cc2)cc1 ; c1ccc(-c2ccccc2N(c2ccc(-c3ccc4c(c3)C(c3ccccc3)(c3ccccc3)c3ccccc3-4)cc2)c2ccc(-c3cccc4c3oc3ccccc34)cc2)cc1 ; c1ccc(-c2ccc(C3(c4ccc(-c5ccccc5)cc4)c4ccccc4-c4ccc(N(c5ccc(-c6cccc7c6oc6ccccc67)cc5)c5ccccc5-c5ccccc5)cc43)cc2)cc1 ; Cc1ccc(C2(c3ccc(C)cc3)c3ccccc3-c3ccc(N(c4ccc(-c5ccccc5)cc4)c4ccc5c(c4)C(C)(C)c4ccccc4-5)cc32)cc1]

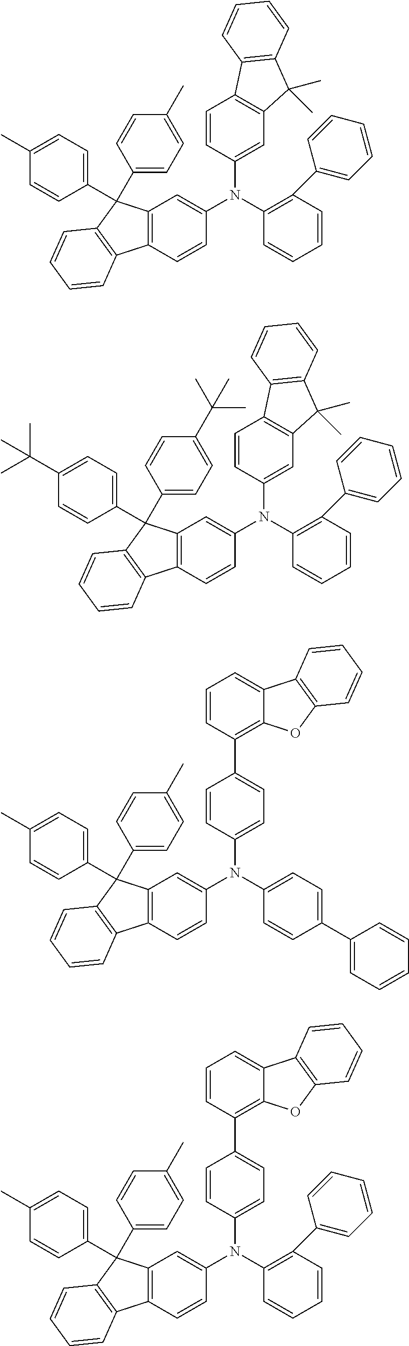 [SMILES: Cc1ccc(C2(c3ccc(C)cc3)c3ccccc3-c3ccc(N(c4ccc5c(c4)C(C)(C)c4ccccc4-5)c4ccccc4-c4ccccc4)cc32)cc1 ; CC(C)(C)c1ccc(C2(c3ccc(C(C)(C)C)cc3)c3ccccc3-c3ccc(N(c4ccc5c(c4)C(C)(C)c4ccccc4-5)c4ccccc4-c4ccccc4)cc32)cc1 ; Cc1ccc(C2(c3ccc(C)cc3)c3ccccc3-c3ccc(N(c4ccc(-c5ccccc5)cc4)c4ccc(-c5cccc6c5oc5ccccc56)cc4)cc32)cc1 ; Cc1ccc(C2(c3ccc(C)cc3)c3ccccc3-c3ccc(N(c4ccc(-c5cccc6c5oc5ccccc56)cc4)c4ccccc4-c4ccccc4)cc32)cc1]

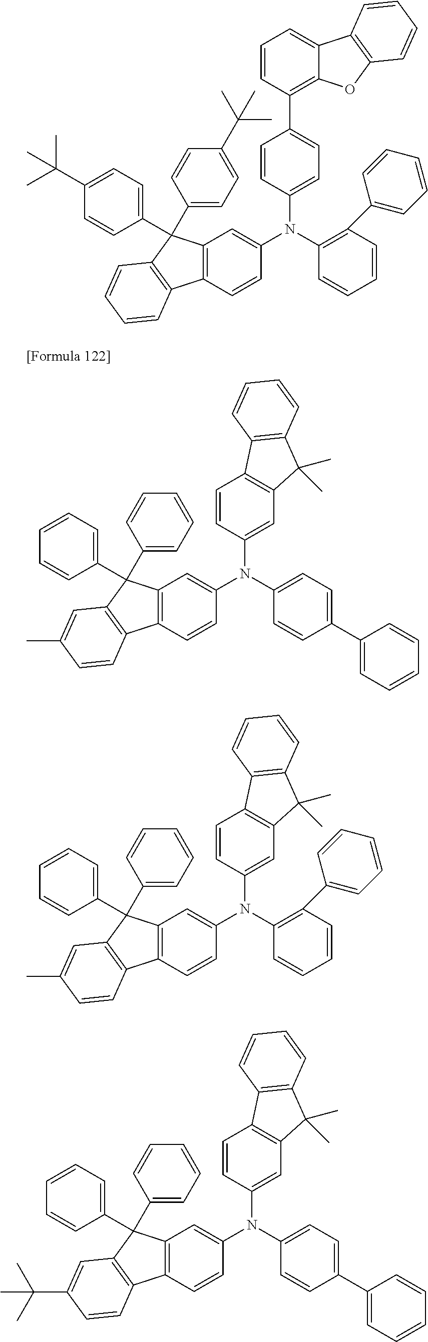 [SMILES: CC(C)(C)c1ccc(C2(c3ccc(C(C)(C)C)cc3)c3ccccc3-c3ccc(N(c4ccc(-c5cccc6c5oc5ccccc56)cc4)c4ccccc4-c4ccccc4)cc32)cc1 ; Cc1ccc2c(c1)C(c1ccccc1)(c1ccccc1)c1cc(N(c3ccc(-c4ccccc4)cc3)c3ccc4c(c3)C(C)(C)c3ccccc3-4)ccc1-2 ; Cc1ccc2c(c1)C(c1ccccc1)(c1ccccc1)c1cc(N(c3ccc4c(c3)C(C)(C)c3ccccc3-4)c3ccccc3-c3ccccc3)ccc1-2 ; CC(C)(C)c1ccc2c(c1)C(c1ccccc1)(c1ccccc1)c1cc(N(c3ccc(-c4ccccc4)cc3)c3ccc4c(c3)C(C)(C)c3ccccc3-4)ccc1-2]

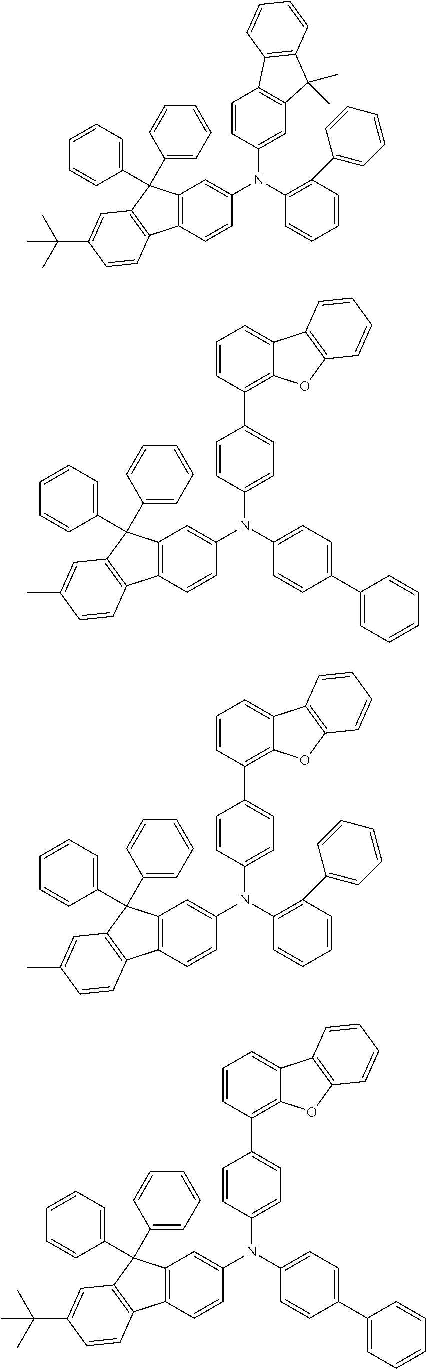 [SMILES: CC(C)(C)c1ccc2c(c1)C(c1ccccc1)(c1ccccc1)c1cc(N(c3ccc4c(c3)C(C)(C)c3ccccc3-4)c3ccccc3-c3ccccc3)ccc1-2 ; Cc1ccc2c(c1)C(c1ccccc1)(c1ccccc1)c1cc(N(c3ccc(-c4ccccc4)cc3)c3ccc(-c4cccc5c4oc4ccccc45)cc3)ccc1-2 ; Cc1ccc2c(c1)C(c1ccccc1)(c1ccccc1)c1cc(N(c3ccc(-c4cccc5c4oc4ccccc45)cc3)c3ccccc3-c3ccccc3)ccc1-2 ; CC(C)(C)c1ccc2c(c1)C(c1ccccc1)(c1ccccc1)c1cc(N(c3ccc(-c4ccccc4)cc3)c3ccc(-c4cccc5c4oc4ccccc45)cc3)ccc1-2]

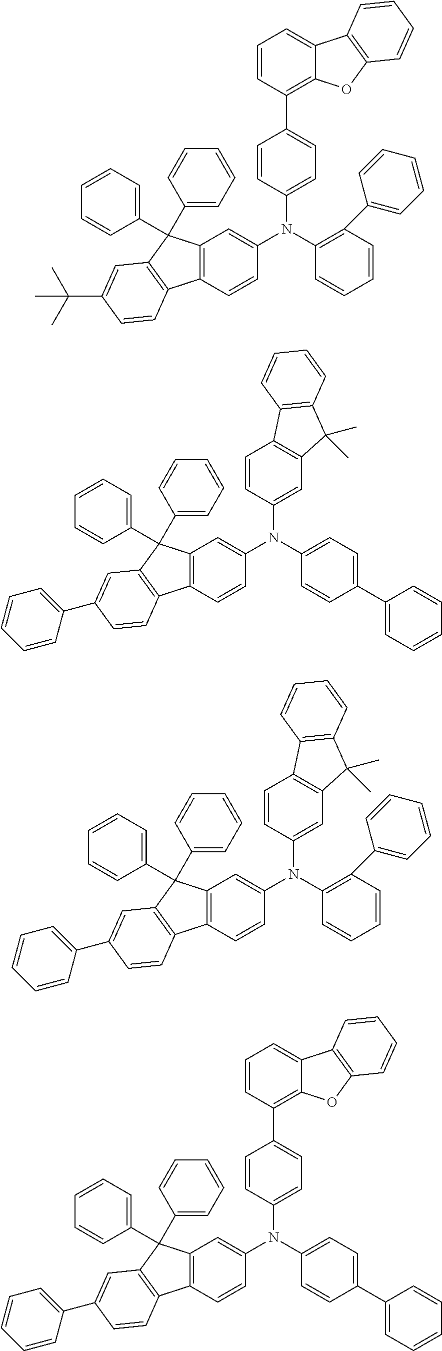 [SMILES: CC(C)(C)c1ccc2c(c1)C(c1ccccc1)(c1ccccc1)c1cc(N(c3ccc(-c4cccc5c4oc4ccccc45)cc3)c3ccccc3-c3ccccc3)ccc1-2 ; CC1(C)c2ccccc2-c2ccc(N(c3ccc(-c4ccccc4)cc3)c3ccc4c(c3)C(c3ccccc3)(c3ccccc3)c3cc(-c5ccccc5)ccc3-4)cc21 ; CC1(C)c2ccccc2-c2ccc(N(c3ccc4c(c3)C(c3ccccc3)(c3ccccc3)c3cc(-c5ccccc5)ccc3-4)c3ccccc3-c3ccccc3)cc21 ; c1ccc(-c2ccc(N(c3ccc(-c4cccc5c4oc4ccccc45)cc3)c3ccc4c(c3)C(c3ccccc3)(c3ccccc3)c3cc(-c5ccccc5)ccc3-4)cc2)cc1]

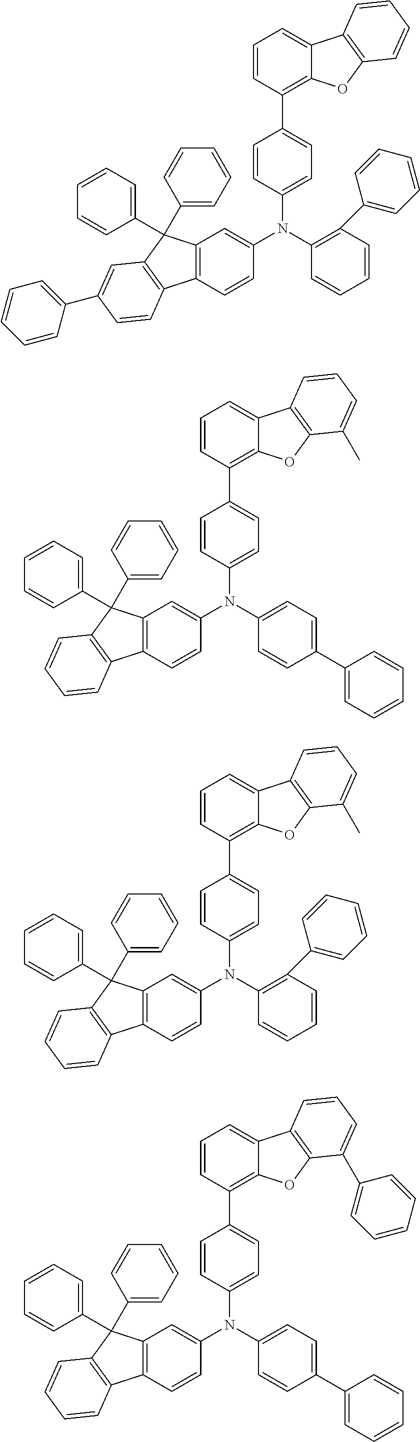

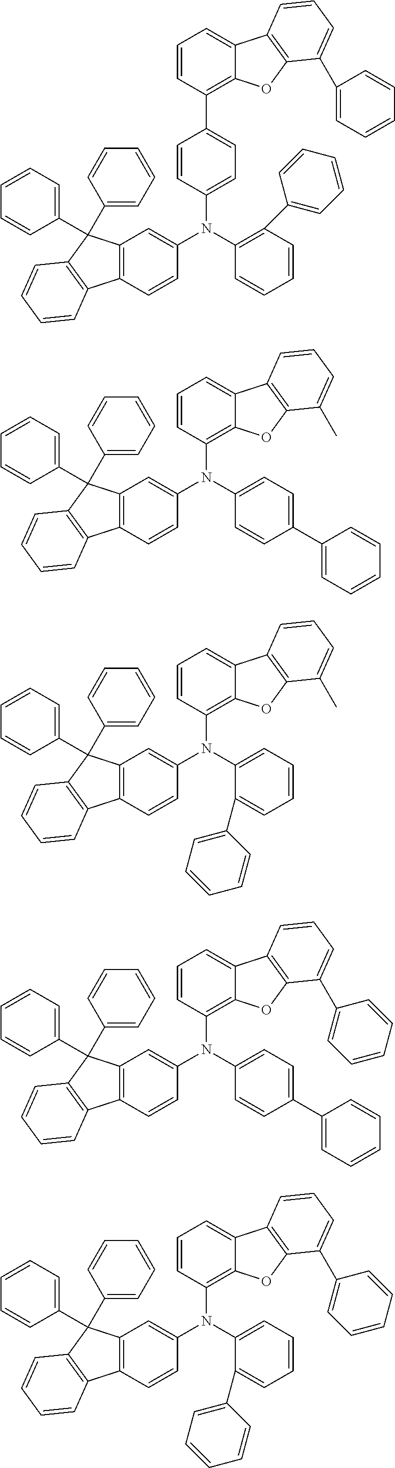

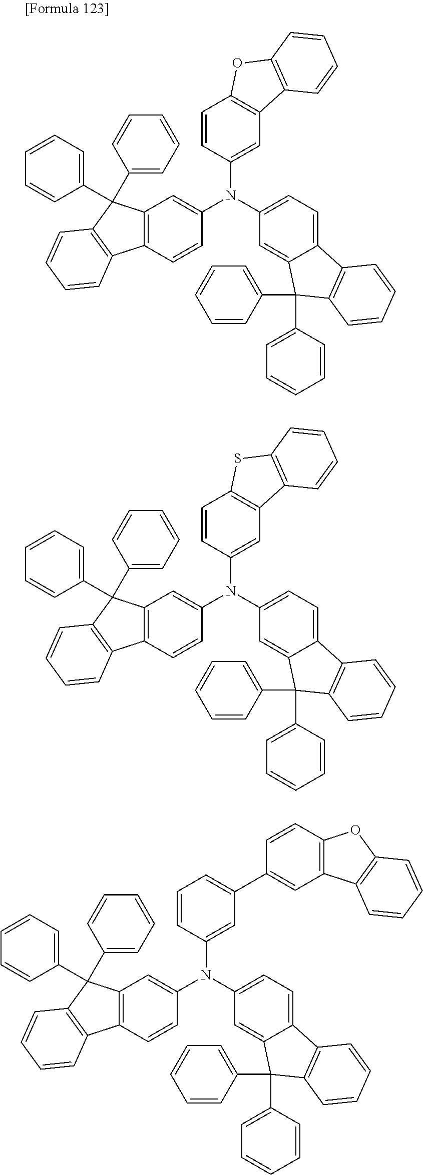

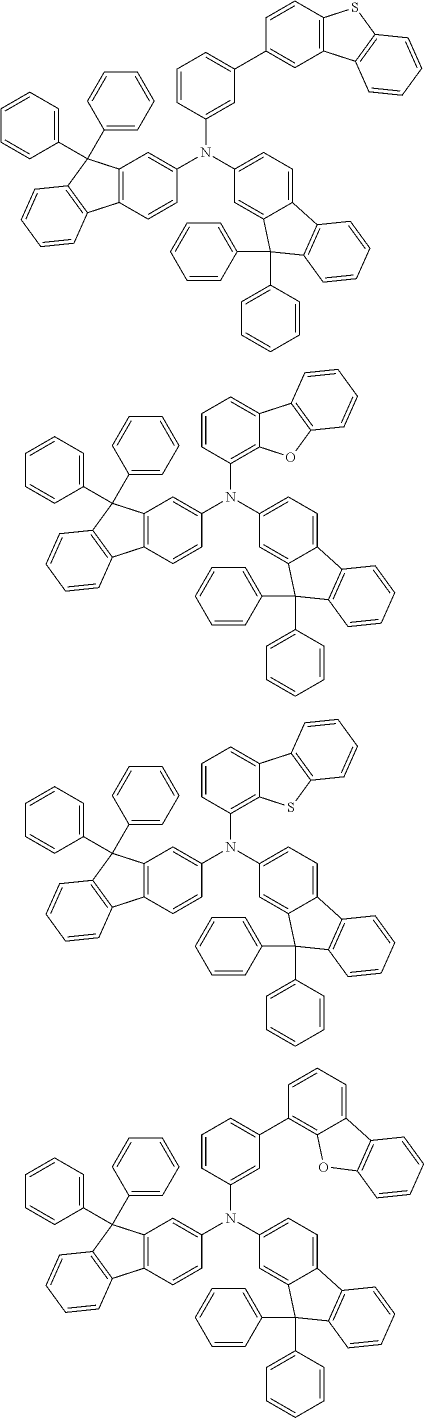

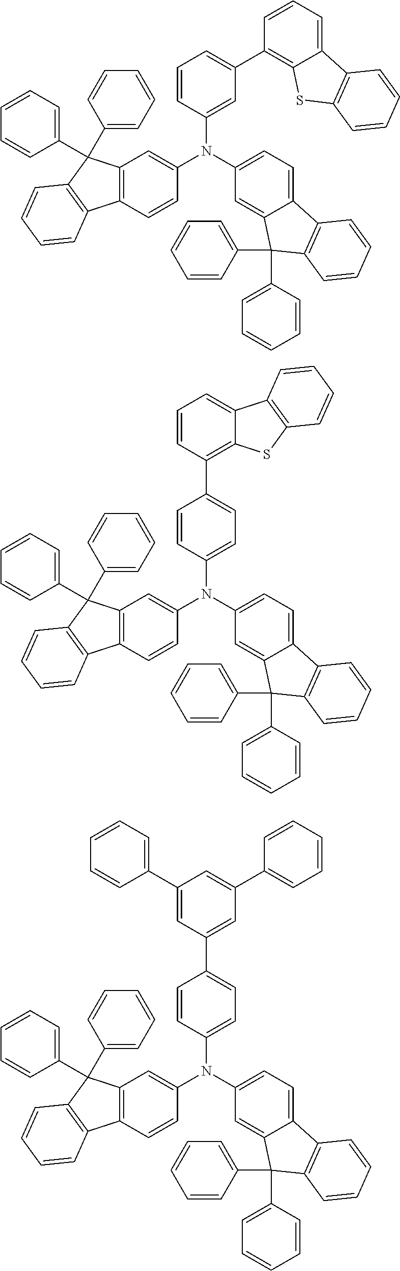

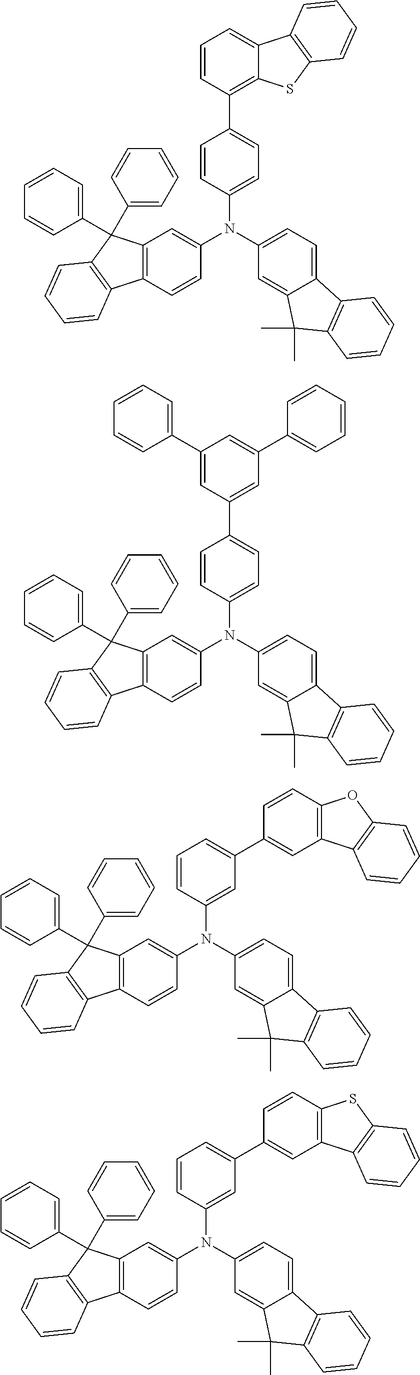

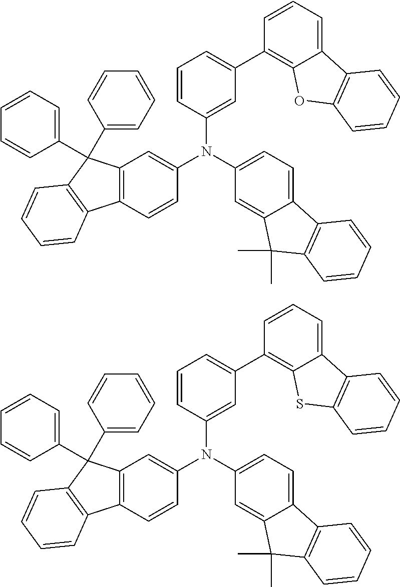

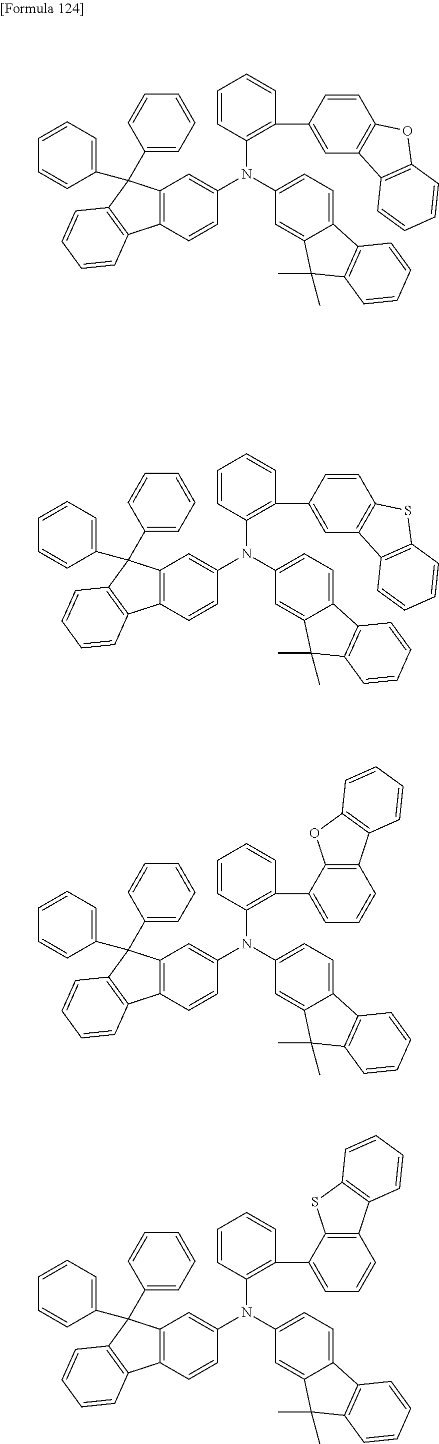 [SMILES: CC1(C)c2ccccc2-c2ccc(N(c3ccc4c(c3)C(c3ccccc3)(c3ccccc3)c3ccccc3-4)c3ccccc3-c3ccc4oc5ccccc5c4c3)cc21 ; CC1(C)c2ccccc2-c2ccc(N(c3ccc4c(c3)C(c3ccccc3)(c3ccccc3)c3ccccc3-4)c3ccccc3-c3ccc4sc5ccccc5c4c3)cc21 ; CC1(C)c2ccccc2-c2ccc(N(c3ccc4c(c3)C(c3ccccc3)(c3ccccc3)c3ccccc3-4)c3ccccc3-c3cccc4c3oc3ccccc34)cc21 ; CC1(C)c2ccccc2-c2ccc(N(c3ccc4c(c3)C(c3ccccc3)(c3ccccc3)c3ccccc3-4)c3ccccc3-c3cccc4c3sc3ccccc34)cc21]

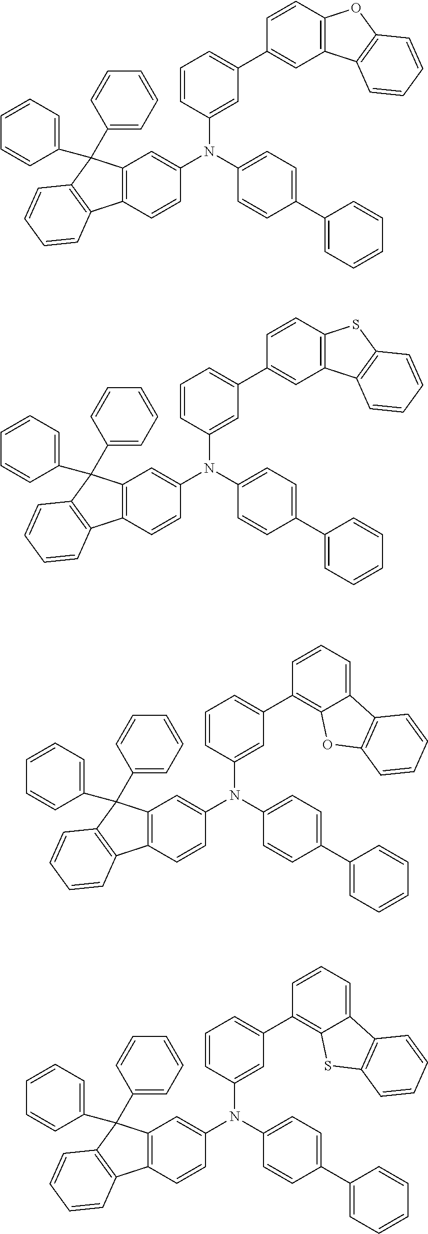 [SMILES: c1ccc(-c2ccc(N(c3cccc(-c4ccc5oc6ccccc6c5c4)c3)c3ccc4c(c3)C(c3ccccc3)(c3ccccc3)c3ccccc3-4)cc2)cc1 ; c1ccc(-c2ccc(N(c3cccc(-c4ccc5sc6ccccc6c5c4)c3)c3ccc4c(c3)C(c3ccccc3)(c3ccccc3)c3ccccc3-4)cc2)cc1 ; c1ccc(-c2ccc(N(c3cccc(-c4cccc5c4oc4ccccc45)c3)c3ccc4c(c3)C(c3ccccc3)(c3ccccc3)c3ccccc3-4)cc2)cc1 ; c1ccc(-c2ccc(N(c3cccc(-c4cccc5c4sc4ccccc45)c3)c3ccc4c(c3)C(c3ccccc3)(c3ccccc3)c3ccccc3-4)cc2)cc1]

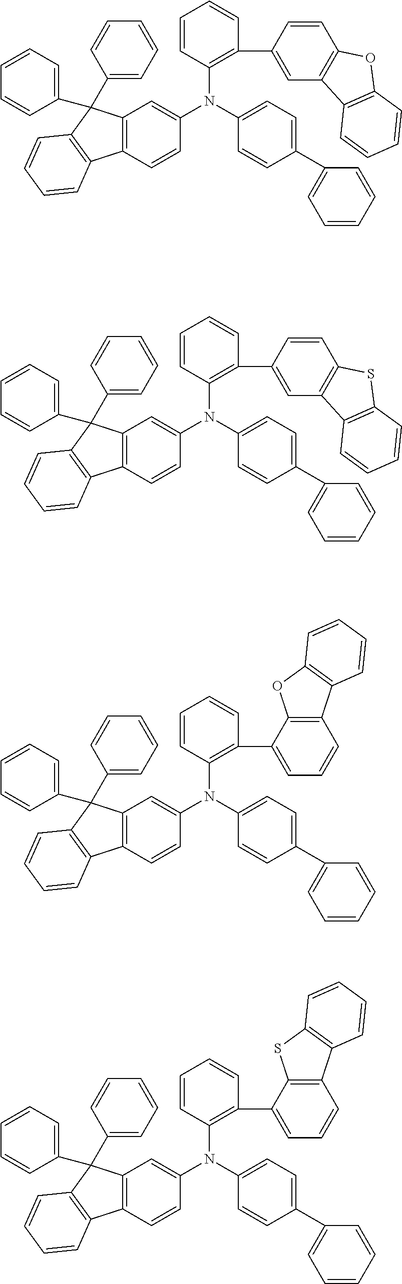 [SMILES: c1ccc(-c2ccc(N(c3ccc4c(c3)C(c3ccccc3)(c3ccccc3)c3ccccc3-4)c3ccccc3-c3ccc4oc5ccccc5c4c3)cc2)cc1 ; c1ccc(-c2ccc(N(c3ccc4c(c3)C(c3ccccc3)(c3ccccc3)c3ccccc3-4)c3ccccc3-c3ccc4sc5ccccc5c4c3)cc2)cc1 ; c1ccc(-c2ccc(N(c3ccc4c(c3)C(c3ccccc3)(c3ccccc3)c3ccccc3-4)c3ccccc3-c3cccc4c3oc3ccccc34)cc2)cc1 ; c1ccc(-c2ccc(N(c3ccc4c(c3)C(c3ccccc3)(c3ccccc3)c3ccccc3-4)c3ccccc3-c3cccc4c3sc3ccccc34)cc2)cc1]

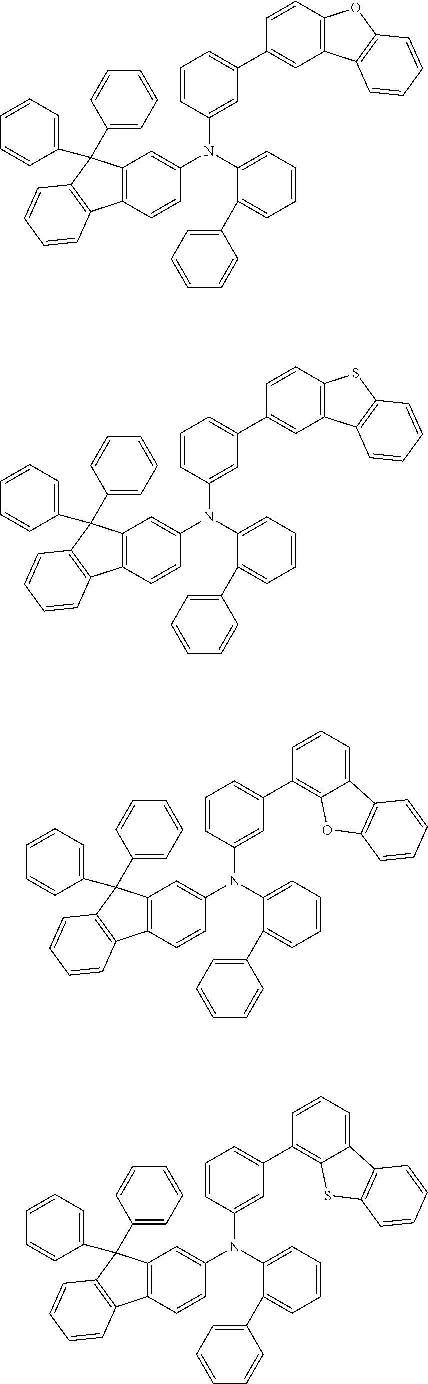 [SMILES: c1ccc(-c2ccccc2N(c2cccc(-c3ccc4oc5ccccc5c4c3)c2)c2ccc3c(c2)C(c2ccccc2)(c2ccccc2)c2ccccc2-3)cc1 ; c1ccc(-c2ccccc2N(c2cccc(-c3ccc4sc5ccccc5c4c3)c2)c2ccc3c(c2)C(c2ccccc2)(c2ccccc2)c2ccccc2-3)cc1 ; c1ccc(-c2ccccc2N(c2cccc(-c3cccc4c3oc3ccccc34)c2)c2ccc3c(c2)C(c2ccccc2)(c2ccccc2)c2ccccc2-3)cc1 ; c1ccc(-c2ccccc2N(c2cccc(-c3cccc4c3sc3ccccc34)c2)c2ccc3c(c2)C(c2ccccc2)(c2ccccc2)c2ccccc2-3)cc1]

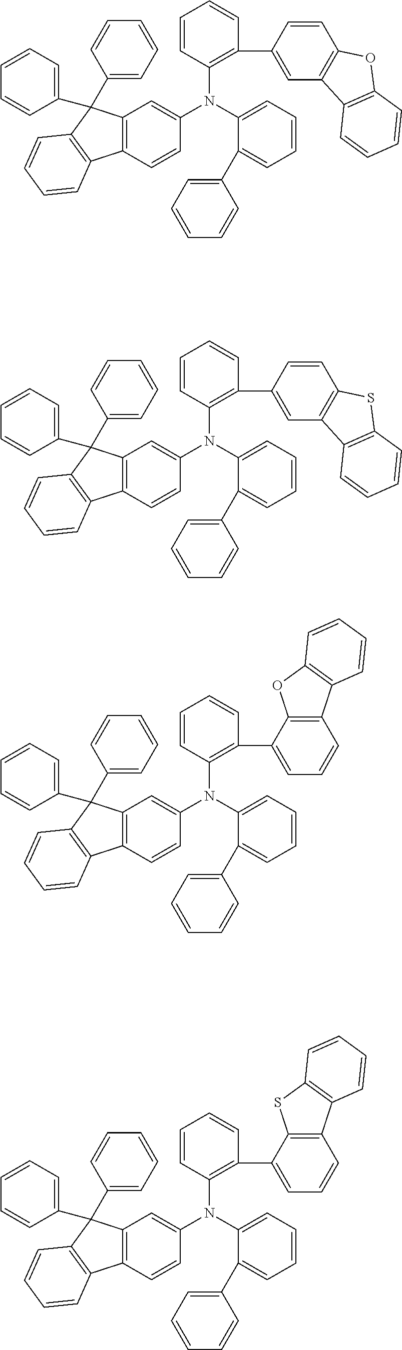 [SMILES: c1ccc(-c2ccccc2N(c2ccc3c(c2)C(c2ccccc2)(c2ccccc2)c2ccccc2-3)c2ccccc2-c2ccc3oc4ccccc4c3c2)cc1 ; c1ccc(-c2ccccc2N(c2ccc3c(c2)C(c2ccccc2)(c2ccccc2)c2ccccc2-3)c2ccccc2-c2ccc3sc4ccccc4c3c2)cc1 ; c1ccc(-c2ccccc2N(c2ccc3c(c2)C(c2ccccc2)(c2ccccc2)c2ccccc2-3)c2ccccc2-c2cccc3c2oc2ccccc23)cc1 ; c1ccc(-c2ccccc2N(c2ccc3c(c2)C(c2ccccc2)(c2ccccc2)c2ccccc2-3)c2ccccc2-c2cccc3c2sc2ccccc23)cc1]

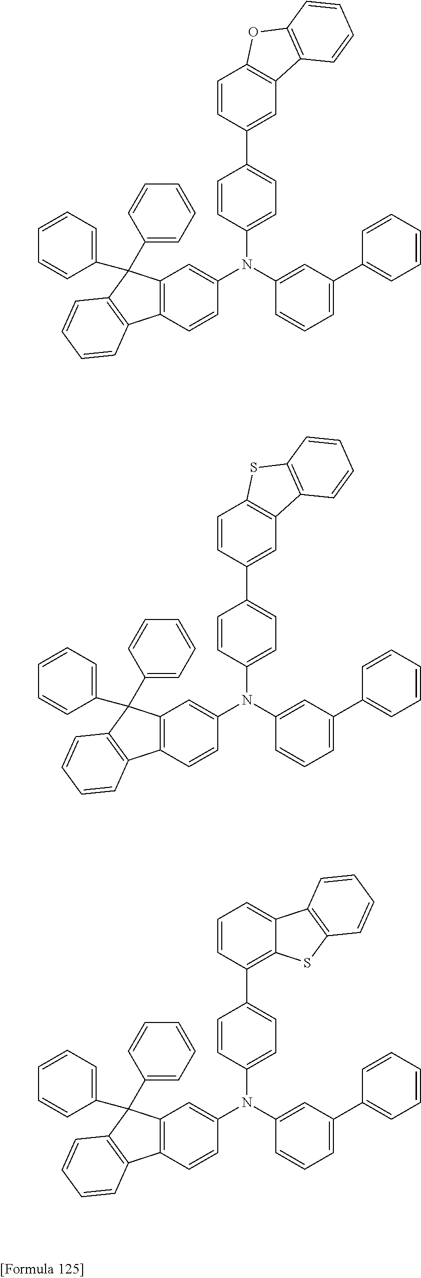 [SMILES: c1ccc(-c2cccc(N(c3ccc(-c4ccc5oc6ccccc6c5c4)cc3)c3ccc4c(c3)C(c3ccccc3)(c3ccccc3)c3ccccc3-4)c2)cc1 ; c1ccc(-c2cccc(N(c3ccc(-c4ccc5sc6ccccc6c5c4)cc3)c3ccc4c(c3)C(c3ccccc3)(c3ccccc3)c3ccccc3-4)c2)cc1 ; c1ccc(-c2cccc(N(c3ccc(-c4cccc5c4sc4ccccc45)cc3)c3ccc4c(c3)C(c3ccccc3)(c3ccccc3)c3ccccc3-4)c2)cc1]

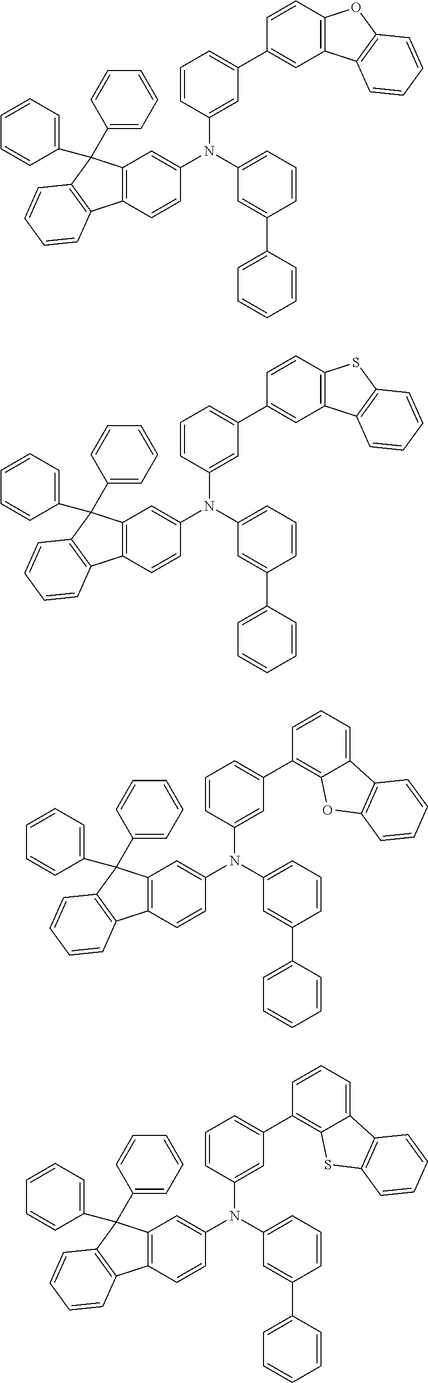 [SMILES: c1ccc(-c2cccc(N(c3cccc(-c4ccc5oc6ccccc6c5c4)c3)c3ccc4c(c3)C(c3ccccc3)(c3ccccc3)c3ccccc3-4)c2)cc1 ; c1ccc(-c2cccc(N(c3cccc(-c4ccc5sc6ccccc6c5c4)c3)c3ccc4c(c3)C(c3ccccc3)(c3ccccc3)c3ccccc3-4)c2)cc1 ; c1ccc(-c2cccc(N(c3cccc(-c4cccc5c4oc4ccccc45)c3)c3ccc4c(c3)C(c3ccccc3)(c3ccccc3)c3ccccc3-4)c2)cc1 ; c1ccc(-c2cccc(N(c3cccc(-c4cccc5c4sc4ccccc45)c3)c3ccc4c(c3)C(c3ccccc3)(c3ccccc3)c3ccccc3-4)c2)cc1]

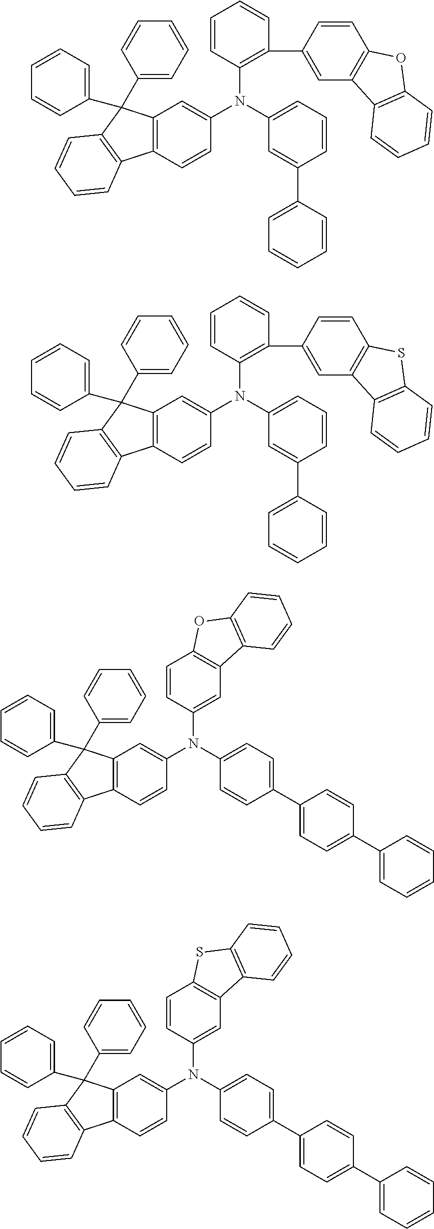

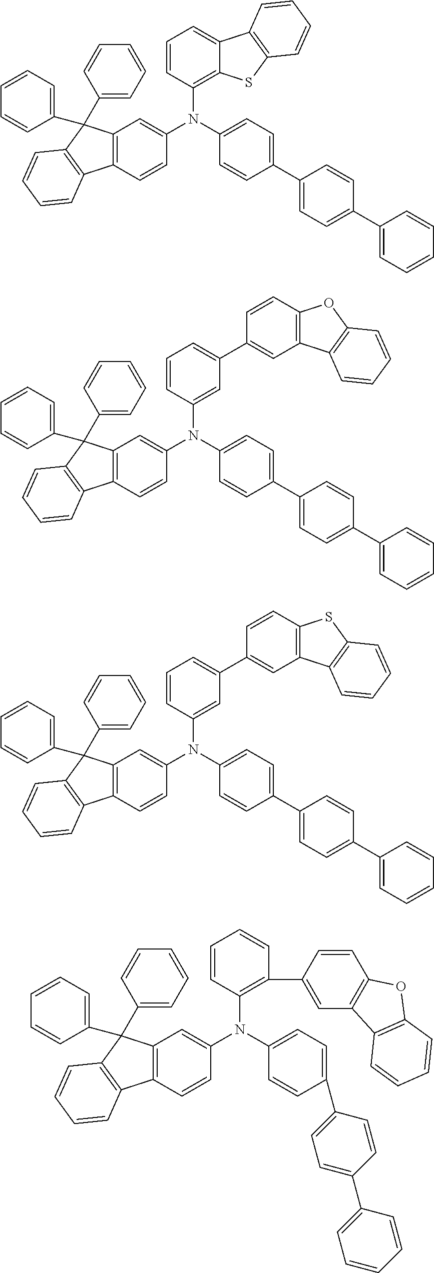 [SMILES: c1ccc(-c2ccc(-c3ccc(N(c4ccc5c(c4)C(c4ccccc4)(c4ccccc4)c4ccccc4-5)c4cccc5c4sc4ccccc45)cc3)cc2)cc1 ; c1ccc(-c2ccc(-c3ccc(N(c4cccc(-c5ccc6oc7ccccc7c6c5)c4)c4ccc5c(c4)C(c4ccccc4)(c4ccccc4)c4ccccc4-5)cc3)cc2)cc1 ; c1ccc(-c2ccc(-c3ccc(N(c4cccc(-c5ccc6sc7ccccc7c6c5)c4)c4ccc5c(c4)C(c4ccccc4)(c4ccccc4)c4ccccc4-5)cc3)cc2)cc1 ; c1ccc(-c2ccc(-c3ccc(N(c4ccc5c(c4)C(c4ccccc4)(c4ccccc4)c4ccccc4-5)c4ccccc4-c4ccc5oc6ccccc6c5c4)cc3)cc2)cc1]

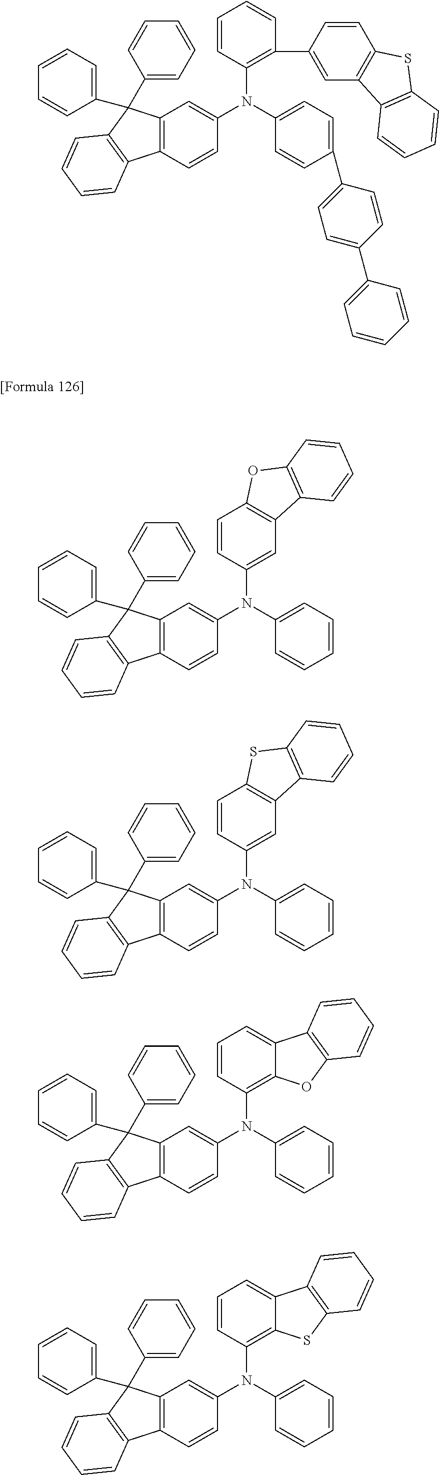 [SMILES: c1ccc(-c2ccc(-c3ccc(N(c4ccc5c(c4)C(c4ccccc4)(c4ccccc4)c4ccccc4-5)c4ccccc4-c4ccc5sc6ccccc6c5c4)cc3)cc2)cc1 ; c1ccc(N(c2ccc3c(c2)C(c2ccccc2)(c2ccccc2)c2ccccc2-3)c2ccc3oc4ccccc4c3c2)cc1 ; c1ccc(N(c2ccc3c(c2)C(c2ccccc2)(c2ccccc2)c2ccccc2-3)c2ccc3sc4ccccc4c3c2)cc1 ; c1ccc(N(c2ccc3c(c2)C(c2ccccc2)(c2ccccc2)c2ccccc2-3)c2cccc3c2oc2ccccc23)cc1 ; c1ccc(N(c2ccc3c(c2)C(c2ccccc2)(c2ccccc2)c2ccccc2-3)c2cccc3c2sc2ccccc23)cc1]

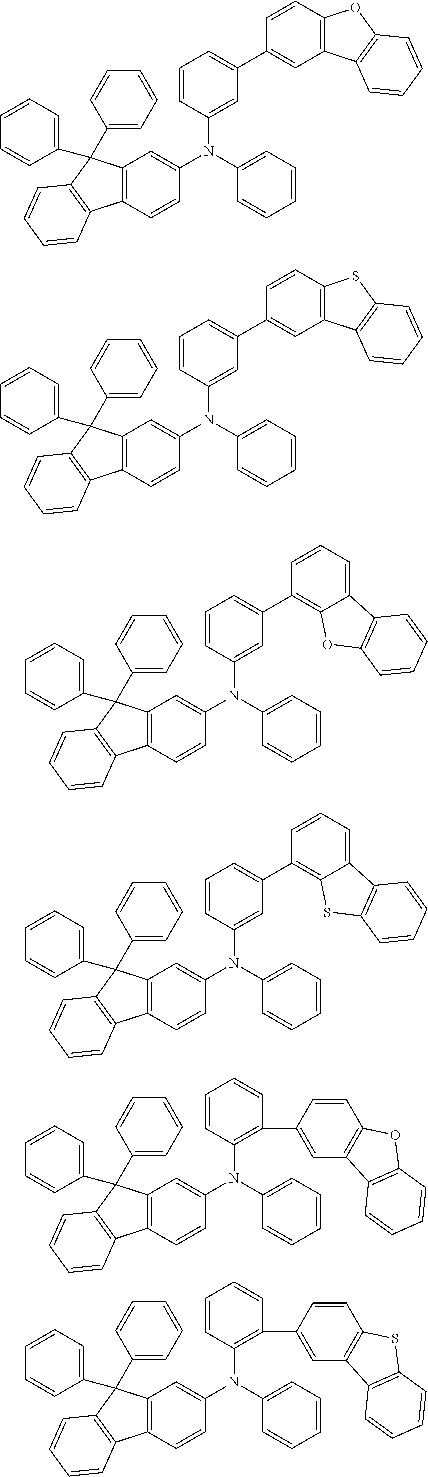

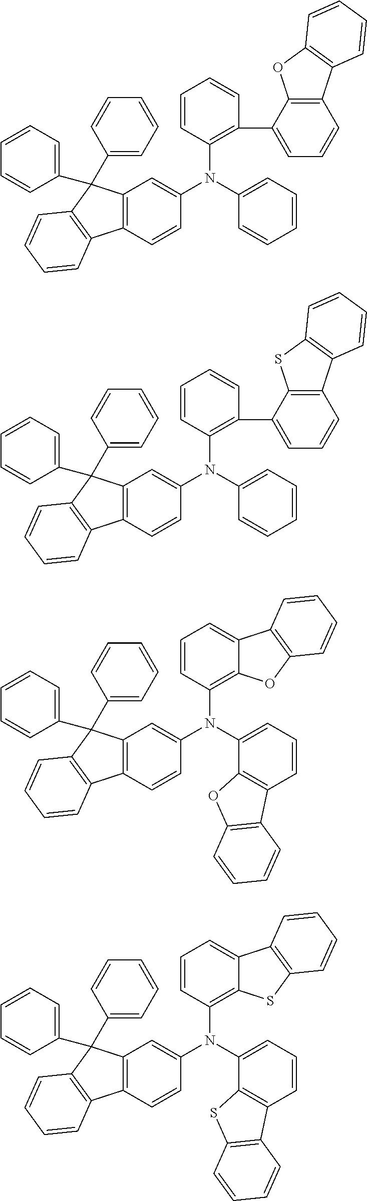

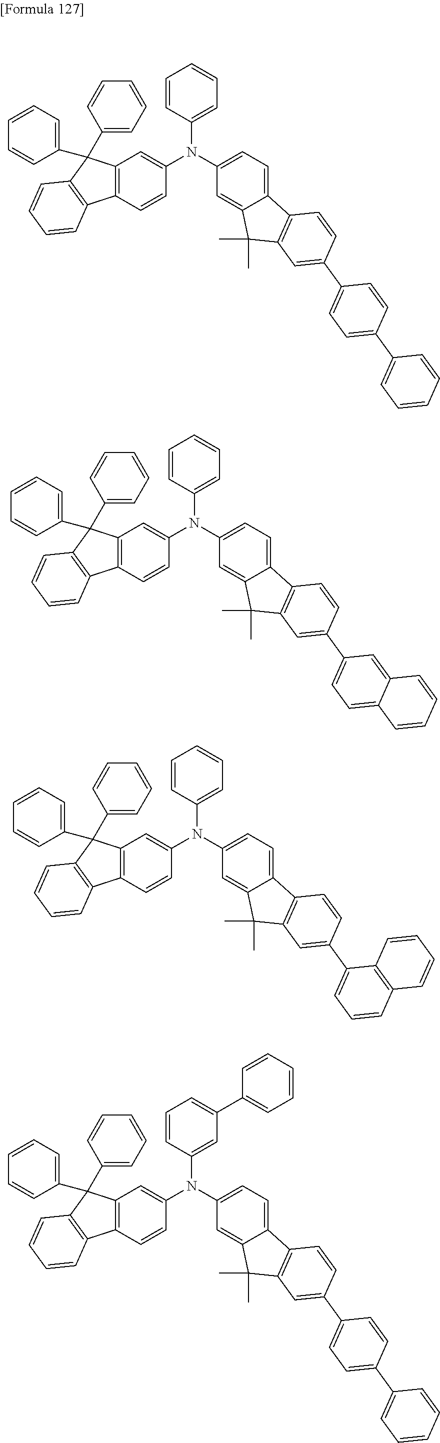 [SMILES: CC1(C)c2cc(-c3ccc(-c4ccccc4)cc3)ccc2-c2ccc(N(c3ccccc3)c3ccc4c(c3)C(c3ccccc3)(c3ccccc3)c3ccccc3-4)cc21 ; CC1(C)c2cc(-c3ccc4ccccc4c3)ccc2-c2ccc(N(c3ccccc3)c3ccc4c(c3)C(c3ccccc3)(c3ccccc3)c3ccccc3-4)cc21 ; CC1(C)c2cc(-c3cccc4ccccc34)ccc2-c2ccc(N(c3ccccc3)c3ccc4c(c3)C(c3ccccc3)(c3ccccc3)c3ccccc3-4)cc21 ; CC1(C)c2cc(-c3ccc(-c4ccccc4)cc3)ccc2-c2ccc(N(c3cccc(-c4ccccc4)c3)c3ccc4c(c3)C(c3ccccc3)(c3ccccc3)c3ccccc3-4)cc21]

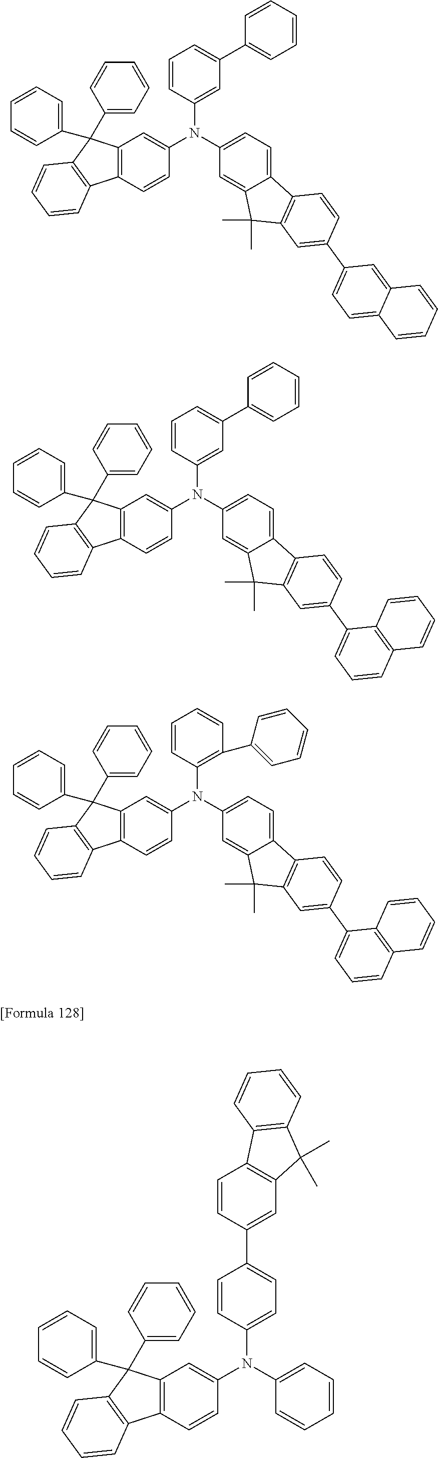 [SMILES: CC1(C)c2cc(-c3ccc4ccccc4c3)ccc2-c2ccc(N(c3cccc(-c4ccccc4)c3)c3ccc4c(c3)C(c3ccccc3)(c3ccccc3)c3ccccc3-4)cc21 ; CC1(C)c2cc(-c3cccc4ccccc34)ccc2-c2ccc(N(c3cccc(-c4ccccc4)c3)c3ccc4c(c3)C(c3ccccc3)(c3ccccc3)c3ccccc3-4)cc21 ; CC1(C)c2cc(-c3cccc4ccccc34)ccc2-c2ccc(N(c3ccc4c(c3)C(c3ccccc3)(c3ccccc3)c3ccccc3-4)c3ccccc3-c3ccccc3)cc21 ; CC1(C)c2ccccc2-c2ccc(-c3ccc(N(c4ccccc4)c4ccc5c(c4)C(c4ccccc4)(c4ccccc4)c4ccccc4-5)cc3)cc21]

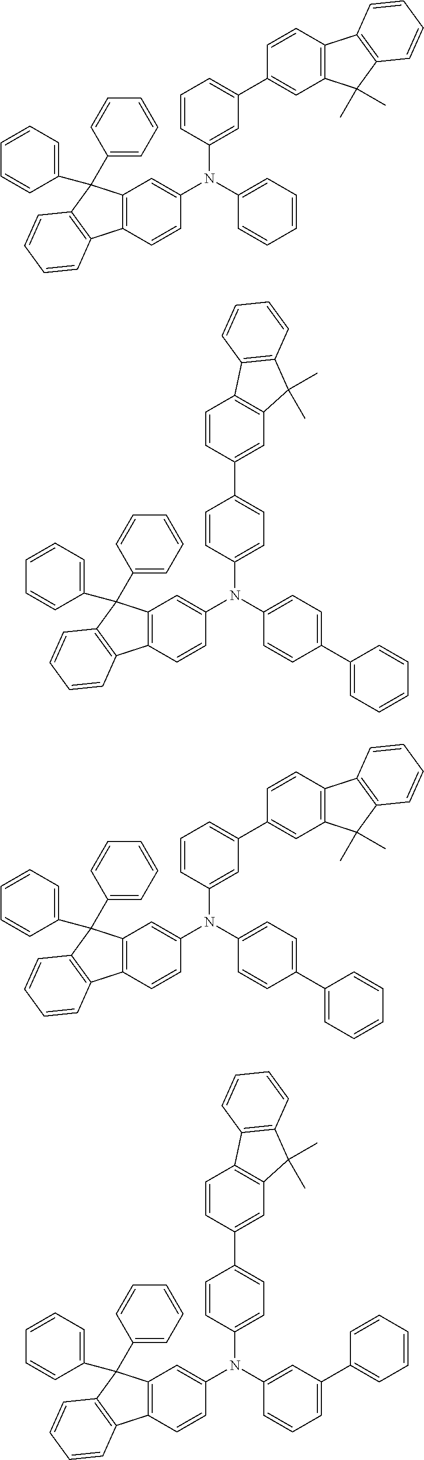

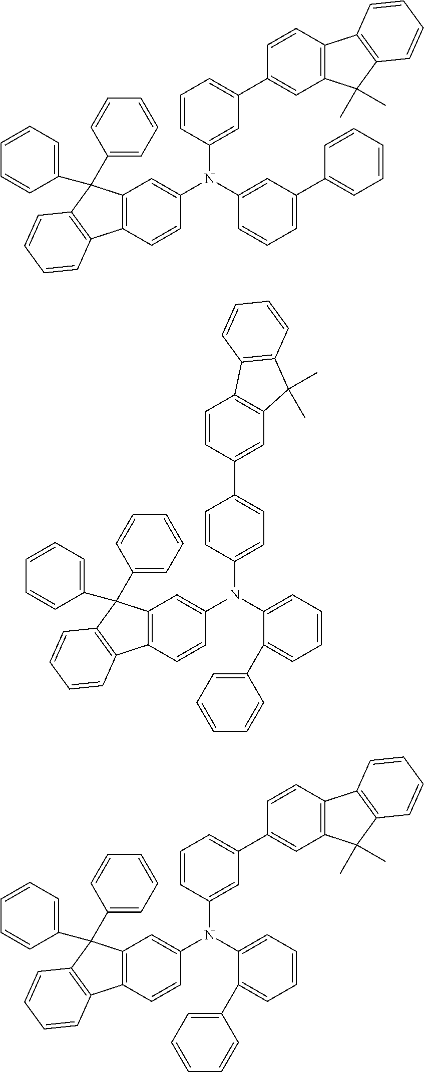 [SMILES: CC1(C)c2ccccc2-c2ccc(-c3cccc(N(c4cccc(-c5ccccc5)c4)c4ccc5c(c4)C(c4ccccc4)(c4ccccc4)c4ccccc4-5)c3)cc21 ; CC1(C)c2ccccc2-c2ccc(-c3ccc(N(c4ccc5c(c4)C(c4ccccc4)(c4ccccc4)c4ccccc4-5)c4ccccc4-c4ccccc4)cc3)cc21 ; CC1(C)c2ccccc2-c2ccc(-c3cccc(N(c4ccc5c(c4)C(c4ccccc4)(c4ccccc4)c4ccccc4-5)c4ccccc4-c4ccccc4)c3)cc21]

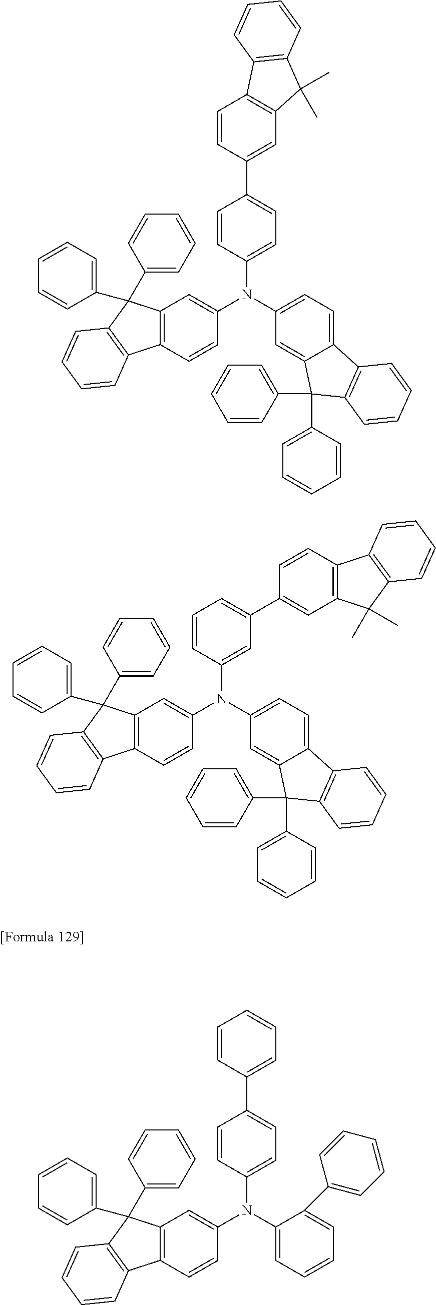 [SMILES: CC1(C)c2ccccc2-c2ccc(-c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3)cc21 ; CC1(C)c2ccccc2-c2ccc(-c3cccc(N(c4ccc5c(c4)C(c4ccccc4)(c4ccccc4)c4ccccc4-5)c4ccc5c(c4)C(c4ccccc4)(c4ccccc4)c4ccccc4-5)c3)cc21 ; c1ccc(-c2ccc(N(c3ccc4c(c3)C(c3ccccc3)(c3ccccc3)c3ccccc3-4)c3ccccc3-c3ccccc3)cc2)cc1]

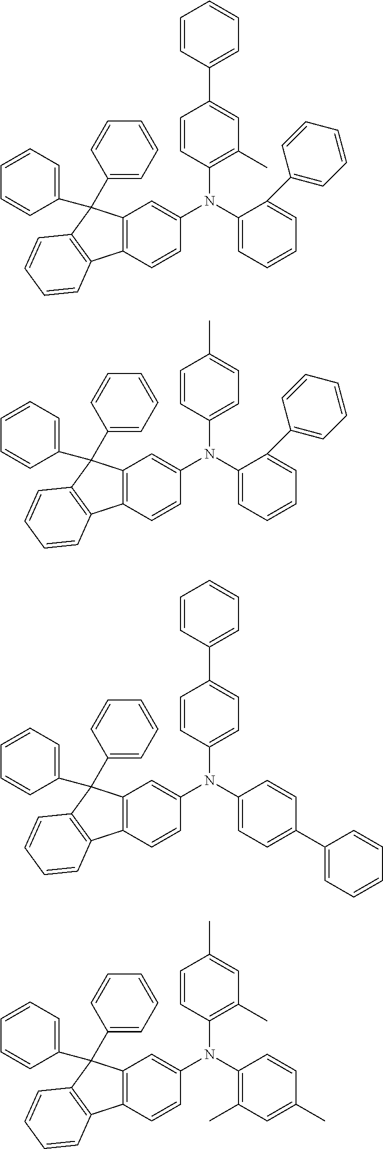 [SMILES: Cc1cc(-c2ccccc2)ccc1N(c1ccc2c(c1)C(c1ccccc1)(c1ccccc1)c1ccccc1-2)c1ccccc1-c1ccccc1 ; Cc1ccc(N(c2ccc3c(c2)C(c2ccccc2)(c2ccccc2)c2ccccc2-3)c2ccccc2-c2ccccc2)cc1 ; c1ccc(-c2ccc(N(c3ccc(-c4ccccc4)cc3)c3ccc4c(c3)C(c3ccccc3)(c3ccccc3)c3ccccc3-4)cc2)cc1 ; Cc1ccc(N(c2ccc3c(c2)C(c2ccccc2)(c2ccccc2)c2ccccc2-3)c2ccc(C)cc2C)c(C)c1]

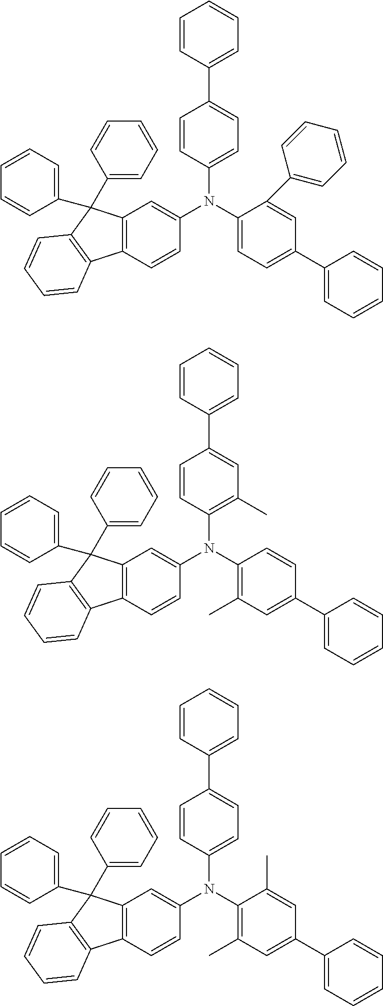 [SMILES: c1ccc(-c2ccc(N(c3ccc4c(c3)C(c3ccccc3)(c3ccccc3)c3ccccc3-4)c3ccc(-c4ccccc4)cc3-c3ccccc3)cc2)cc1 ; Cc1cc(-c2ccccc2)ccc1N(c1ccc2c(c1)C(c1ccccc1)(c1ccccc1)c1ccccc1-2)c1ccc(-c2ccccc2)cc1C ; Cc1cc(-c2ccccc2)cc(C)c1N(c1ccc(-c2ccccc2)cc1)c1ccc2c(c1)C(c1ccccc1)(c1ccccc1)c1ccccc1-2]

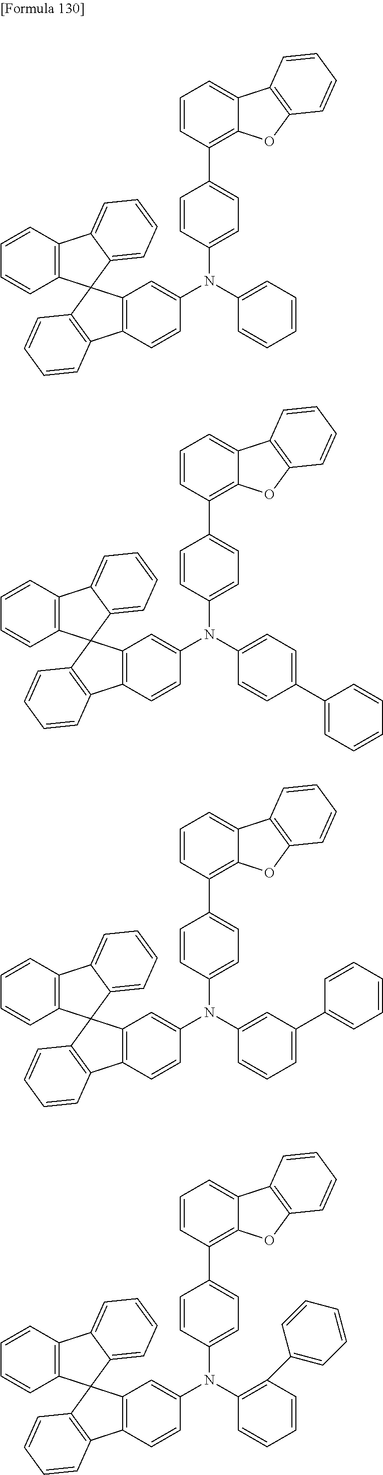 [SMILES: c1ccc(N(c2ccc(-c3cccc4c3oc3ccccc34)cc2)c2ccc3c(c2)C2(c4ccccc4-c4ccccc42)c2ccccc2-3)cc1 ; c1ccc(-c2ccc(N(c3ccc(-c4cccc5c4oc4ccccc45)cc3)c3ccc4c(c3)C3(c5ccccc5-c5ccccc53)c3ccccc3-4)cc2)cc1 ; c1ccc(-c2cccc(N(c3ccc(-c4cccc5c4oc4ccccc45)cc3)c3ccc4c(c3)C3(c5ccccc5-c5ccccc53)c3ccccc3-4)c2)cc1 ; c1ccc(-c2ccccc2N(c2ccc(-c3cccc4c3oc3ccccc34)cc2)c2ccc3c(c2)C2(c4ccccc4-c4ccccc42)c2ccccc2-3)cc1]

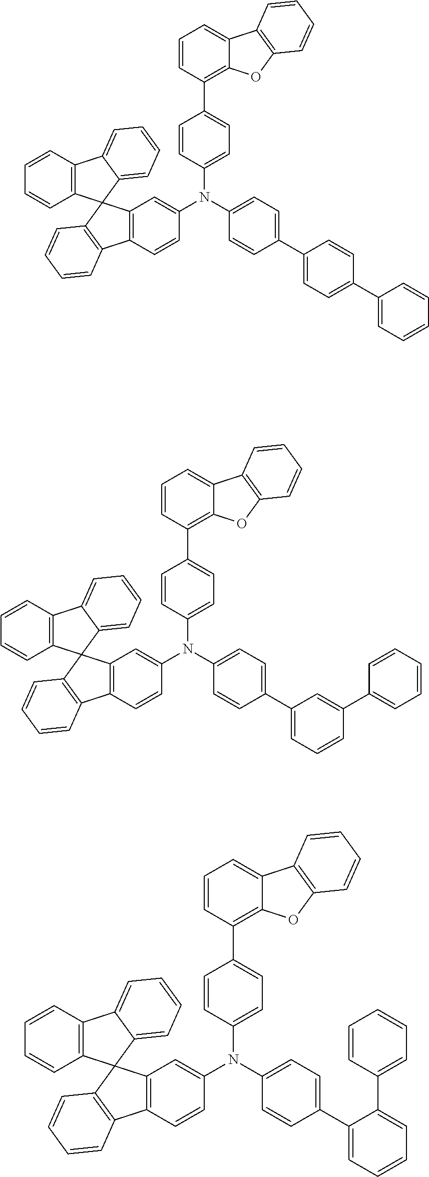 [SMILES: c1ccc(-c2ccc(-c3ccc(N(c4ccc(-c5cccc6c5oc5ccccc56)cc4)c4ccc5c(c4)C4(c6ccccc6-c6ccccc64)c4ccccc4-5)cc3)cc2)cc1 ; c1ccc(-c2cccc(-c3ccc(N(c4ccc(-c5cccc6c5oc5ccccc56)cc4)c4ccc5c(c4)C4(c6ccccc6-c6ccccc64)c4ccccc4-5)cc3)c2)cc1 ; c1ccc(-c2ccccc2-c2ccc(N(c3ccc(-c4cccc5c4oc4ccccc45)cc3)c3ccc4c(c3)C3(c5ccccc5-c5ccccc53)c3ccccc3-4)cc2)cc1]

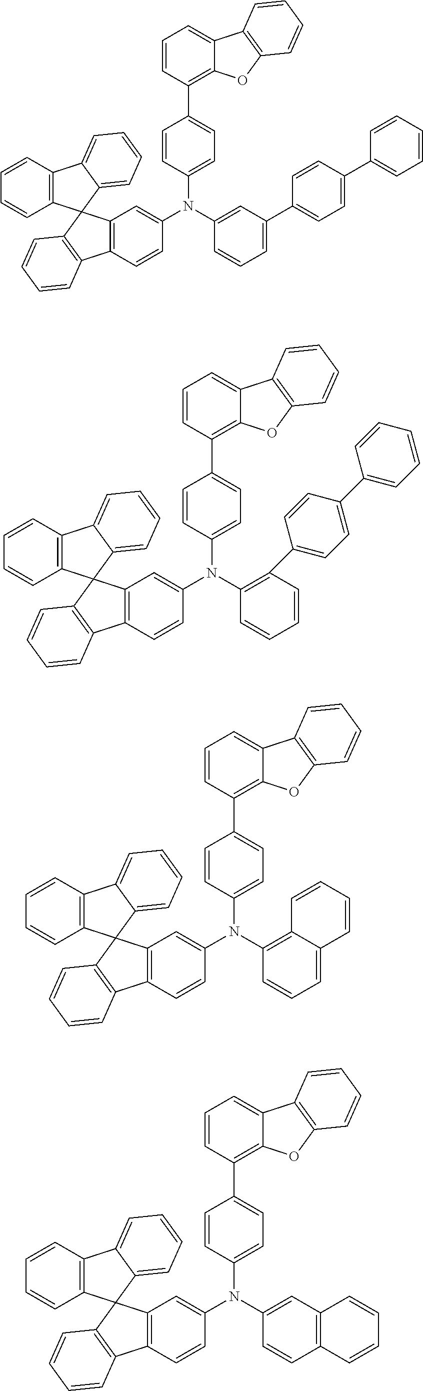 [SMILES: c1ccc(-c2ccc(-c3cccc(N(c4ccc(-c5cccc6c5oc5ccccc56)cc4)c4ccc5c(c4)C4(c6ccccc6-c6ccccc64)c4ccccc4-5)c3)cc2)cc1 ; c1ccc(-c2ccc(-c3ccccc3N(c3ccc(-c4cccc5c4oc4ccccc45)cc3)c3ccc4c(c3)C3(c5ccccc5-c5ccccc53)c3ccccc3-4)cc2)cc1 ; c1ccc2c(c1)-c1ccccc1C21c2ccccc2-c2ccc(N(c3ccc(-c4cccc5c4oc4ccccc45)cc3)c3cccc4ccccc34)cc21 ; c1ccc2c(c1)-c1ccccc1C21c2ccccc2-c2ccc(N(c3ccc(-c4cccc5c4oc4ccccc45)cc3)c3ccc4ccccc4c3)cc21]

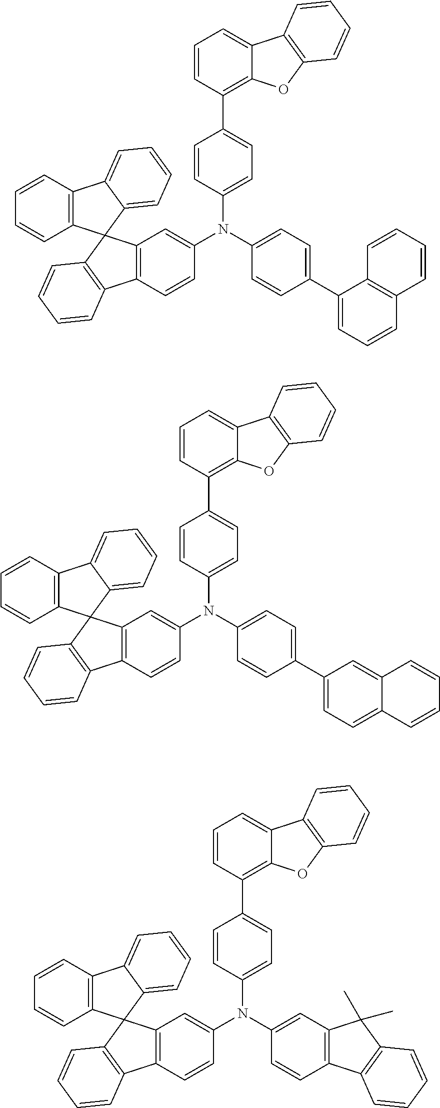 [SMILES: c1ccc2c(c1)-c1ccccc1C21c2ccccc2-c2ccc(N(c3ccc(-c4cccc5ccccc45)cc3)c3ccc(-c4cccc5c4oc4ccccc45)cc3)cc21 ; c1ccc2c(c1)-c1ccccc1C21c2ccccc2-c2ccc(N(c3ccc(-c4ccc5ccccc5c4)cc3)c3ccc(-c4cccc5c4oc4ccccc45)cc3)cc21 ; CC1(C)c2ccccc2-c2ccc(N(c3ccc(-c4cccc5c4oc4ccccc45)cc3)c3ccc4c(c3)C3(c5ccccc5-c5ccccc53)c3ccccc3-4)cc21]

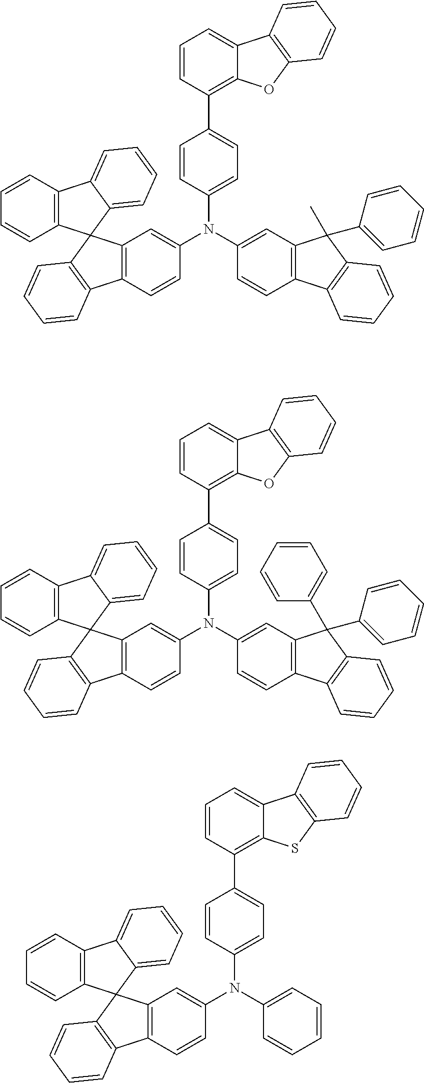

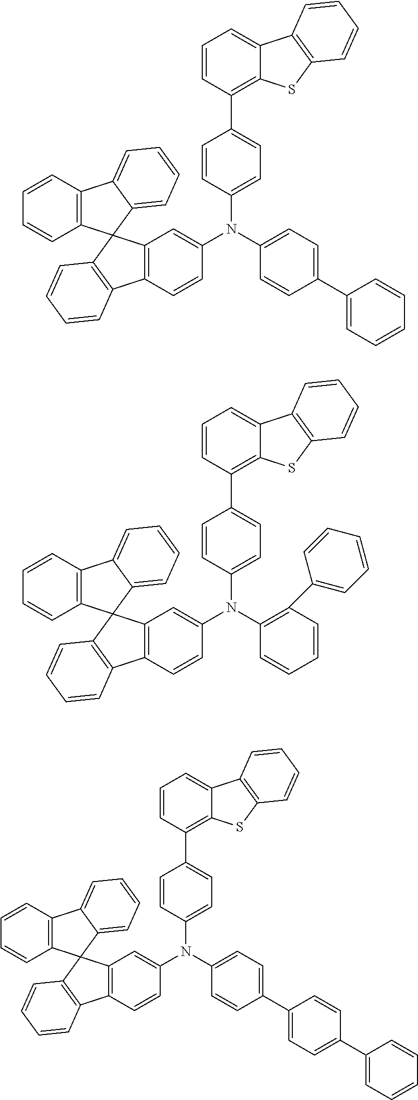 [SMILES: c1ccc(-c2ccc(N(c3ccc(-c4cccc5c4sc4ccccc45)cc3)c3ccc4c(c3)C3(c5ccccc5-c5ccccc53)c3ccccc3-4)cc2)cc1 ; c1ccc(-c2ccccc2N(c2ccc(-c3cccc4c3sc3ccccc34)cc2)c2ccc3c(c2)C2(c4ccccc4-c4ccccc42)c2ccccc2-3)cc1 ; c1ccc(-c2ccc(-c3ccc(N(c4ccc(-c5cccc6c5sc5ccccc56)cc4)c4ccc5c(c4)C4(c6ccccc6-c6ccccc64)c4ccccc4-5)cc3)cc2)cc1]

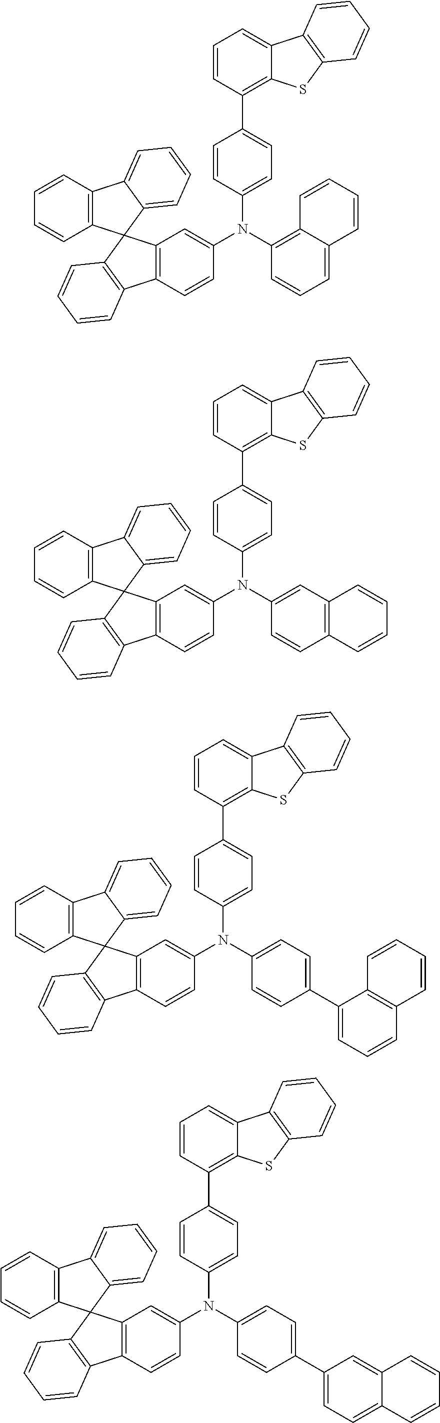

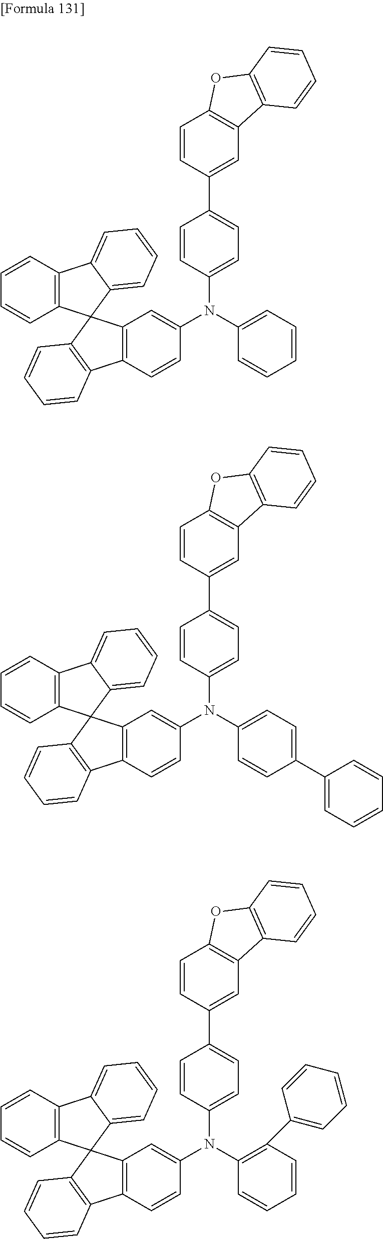 [SMILES: c1ccc(N(c2ccc(-c3ccc4oc5ccccc5c4c3)cc2)c2ccc3c(c2)C2(c4ccccc4-c4ccccc42)c2ccccc2-3)cc1 ; c1ccc(-c2ccc(N(c3ccc(-c4ccc5oc6ccccc6c5c4)cc3)c3ccc4c(c3)C3(c5ccccc5-c5ccccc53)c3ccccc3-4)cc2)cc1 ; c1ccc(-c2ccccc2N(c2ccc(-c3ccc4oc5ccccc5c4c3)cc2)c2ccc3c(c2)C2(c4ccccc4-c4ccccc42)c2ccccc2-3)cc1]

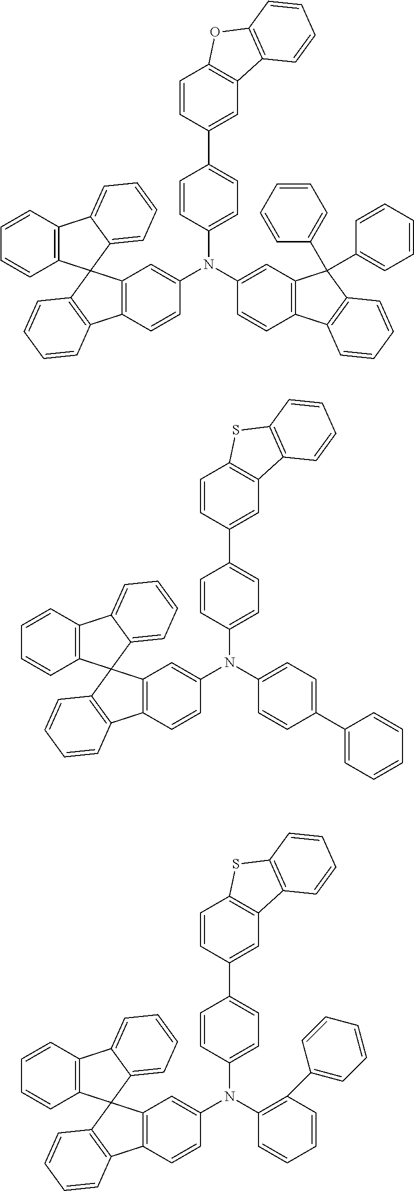 [SMILES: c1ccc(C2(c3ccccc3)c3ccccc3-c3ccc(N(c4ccc(-c5ccc6oc7ccccc7c6c5)cc4)c4ccc5c(c4)C4(c6ccccc6-c6ccccc64)c4ccccc4-5)cc32)cc1 ; c1ccc(-c2ccc(N(c3ccc(-c4ccc5sc6ccccc6c5c4)cc3)c3ccc4c(c3)C3(c5ccccc5-c5ccccc53)c3ccccc3-4)cc2)cc1 ; c1ccc(-c2ccccc2N(c2ccc(-c3ccc4sc5ccccc5c4c3)cc2)c2ccc3c(c2)C2(c4ccccc4-c4ccccc42)c2ccccc2-3)cc1]

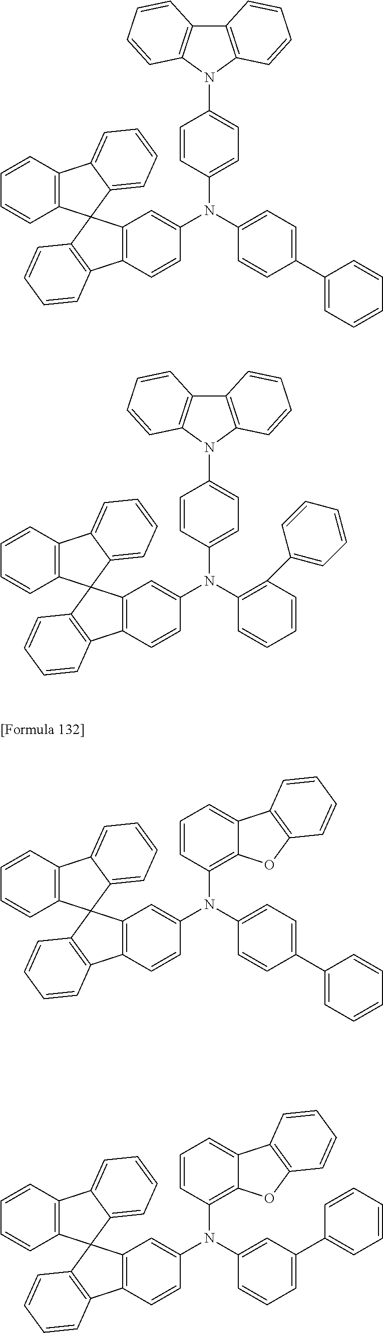 [SMILES: c1ccc(-c2ccc(N(c3ccc(-n4c5ccccc5c5ccccc54)cc3)c3ccc4c(c3)C3(c5ccccc5-c5ccccc53)c3ccccc3-4)cc2)cc1 ; c1ccc(-c2ccccc2N(c2ccc(-n3c4ccccc4c4ccccc43)cc2)c2ccc3c(c2)C2(c4ccccc4-c4ccccc42)c2ccccc2-3)cc1 ; c1ccc(-c2ccc(N(c3ccc4c(c3)C3(c5ccccc5-c5ccccc53)c3ccccc3-4)c3cccc4c3oc3ccccc34)cc2)cc1 ; c1ccc(-c2cccc(N(c3ccc4c(c3)C3(c5ccccc5-c5ccccc53)c3ccccc3-4)c3cccc4c3oc3ccccc34)c2)cc1]

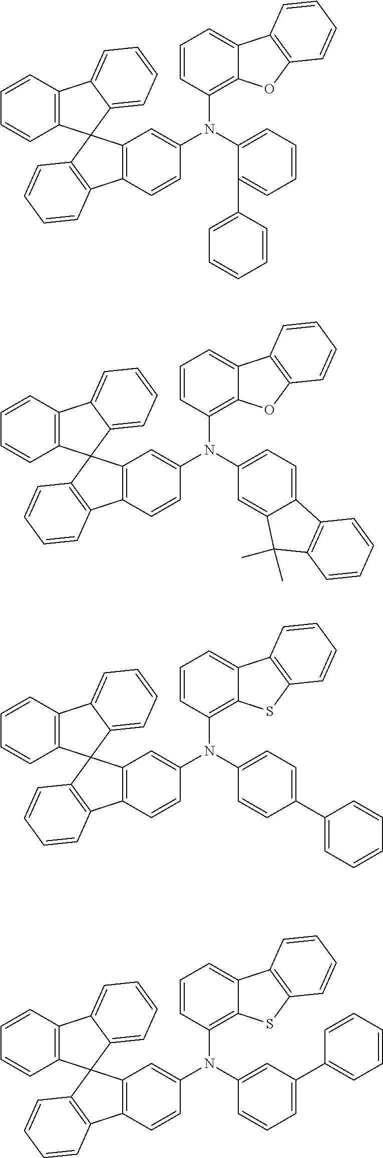

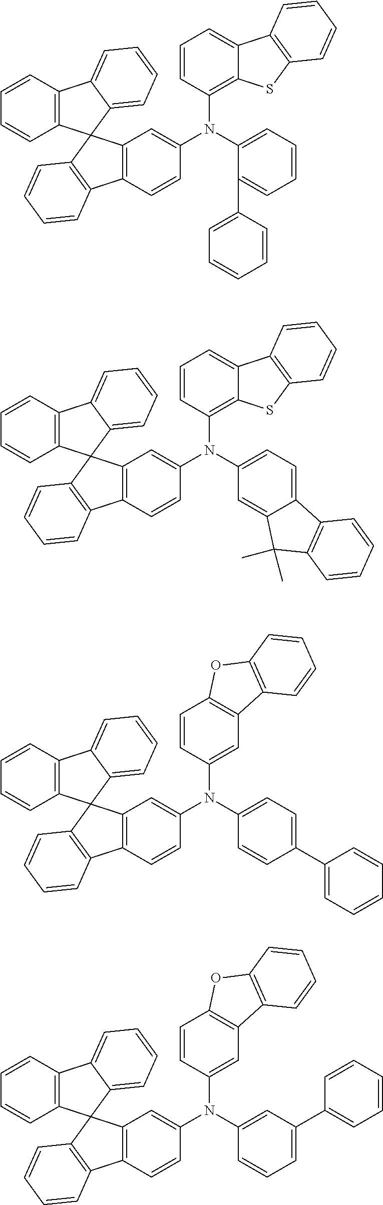 [SMILES: c1ccc(-c2ccccc2N(c2ccc3c(c2)C2(c4ccccc4-c4ccccc42)c2ccccc2-3)c2cccc3c2sc2ccccc23)cc1 ; CC1(C)c2ccccc2-c2ccc(N(c3ccc4c(c3)C3(c5ccccc5-c5ccccc53)c3ccccc3-4)c3cccc4c3sc3ccccc34)cc21 ; c1ccc(-c2ccc(N(c3ccc4c(c3)C3(c5ccccc5-c5ccccc53)c3ccccc3-4)c3ccc4oc5ccccc5c4c3)cc2)cc1 ; c1ccc(-c2cccc(N(c3ccc4c(c3)C3(c5ccccc5-c5ccccc53)c3ccccc3-4)c3ccc4oc5ccccc5c4c3)c2)cc1]

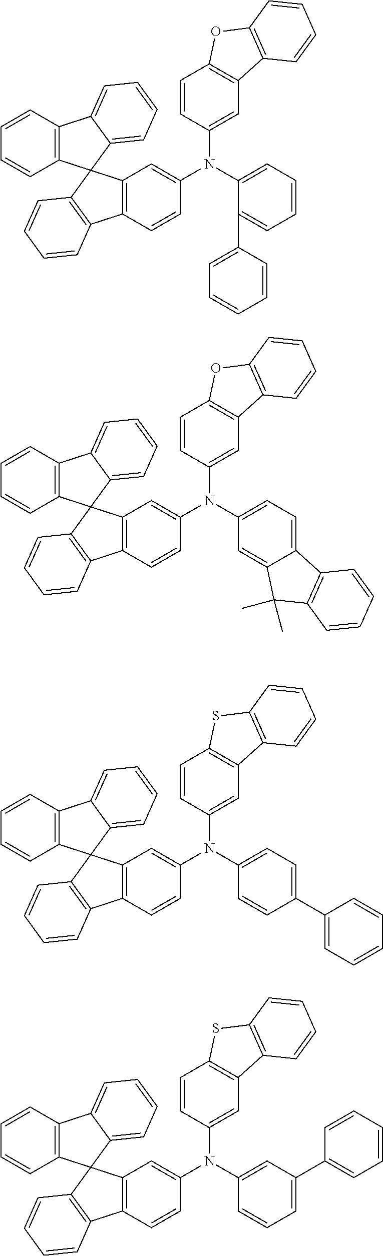

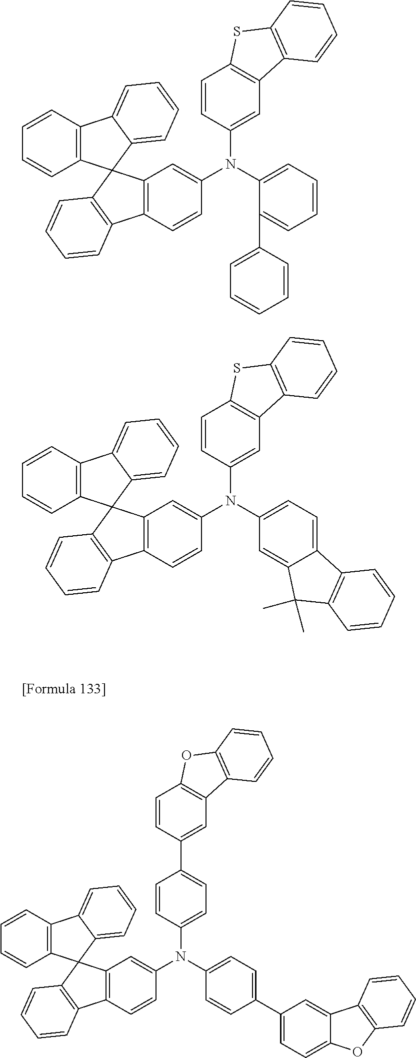

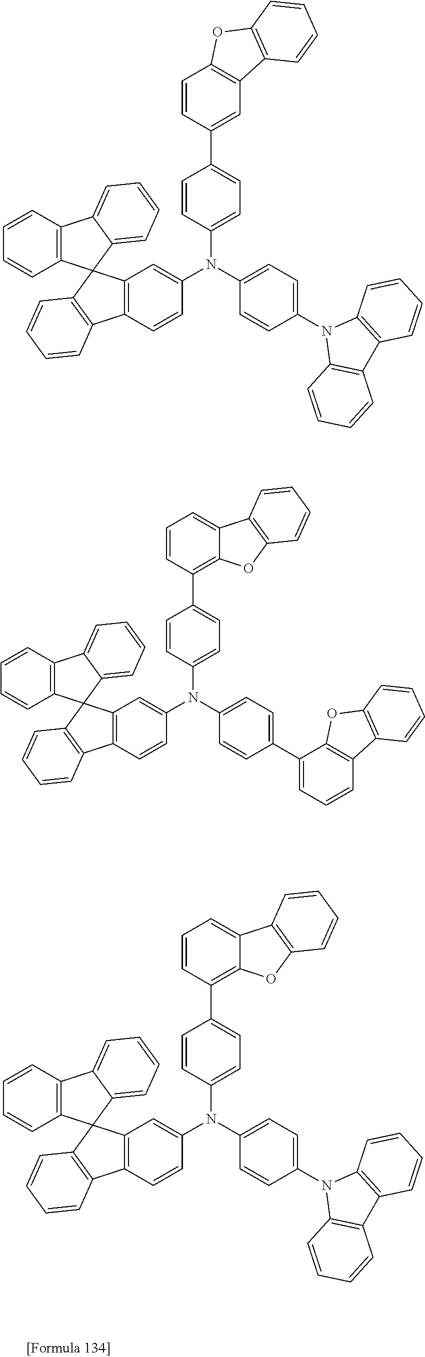 [SMILES: c1ccc2c(c1)-c1ccccc1C21c2ccccc2-c2ccc(N(c3ccc(-c4ccc5oc6ccccc6c5c4)cc3)c3ccc(-n4c5ccccc5c5ccccc54)cc3)cc21 ; c1ccc2c(c1)-c1ccccc1C21c2ccccc2-c2ccc(N(c3ccc(-c4cccc5c4oc4ccccc45)cc3)c3ccc(-c4cccc5c4oc4ccccc45)cc3)cc21 ; c1ccc2c(c1)-c1ccccc1C21c2ccccc2-c2ccc(N(c3ccc(-c4cccc5c4oc4ccccc45)cc3)c3ccc(-n4c5ccccc5c5ccccc54)cc3)cc21]

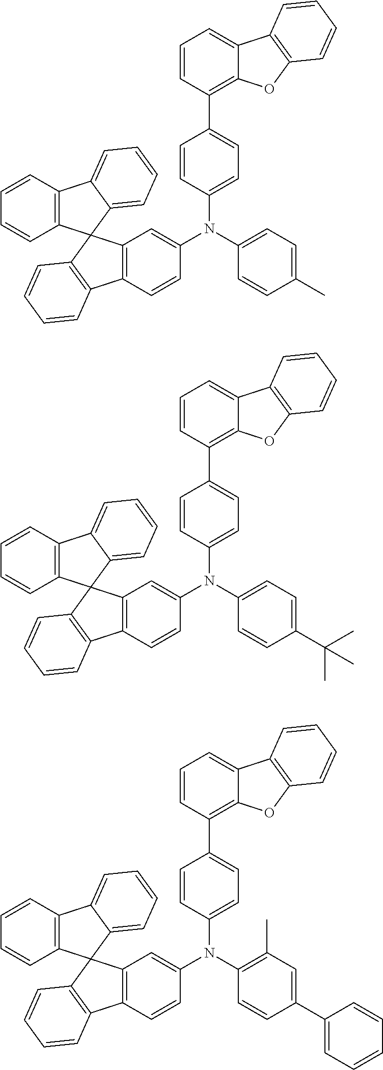

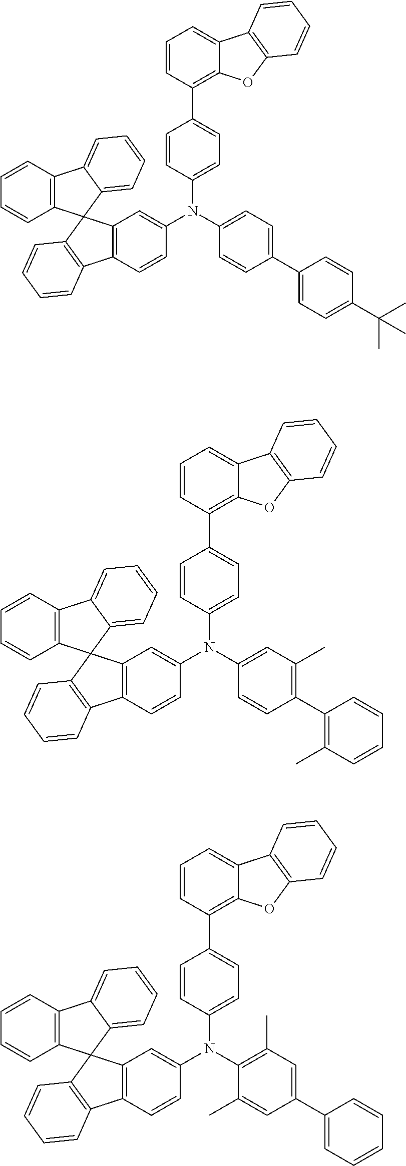 [SMILES: CC(C)(C)c1ccc(-c2ccc(N(c3ccc(-c4cccc5c4oc4ccccc45)cc3)c3ccc4c(c3)C3(c5ccccc5-c5ccccc53)c3ccccc3-4)cc2)cc1 ; Cc1ccccc1-c1ccc(N(c2ccc(-c3cccc4c3oc3ccccc34)cc2)c2ccc3c(c2)C2(c4ccccc4-c4ccccc42)c2ccccc2-3)cc1C ; Cc1cc(-c2ccccc2)cc(C)c1N(c1ccc(-c2cccc3c2oc2ccccc23)cc1)c1ccc2c(c1)C1(c3ccccc3-c3ccccc31)c1ccccc1-2]

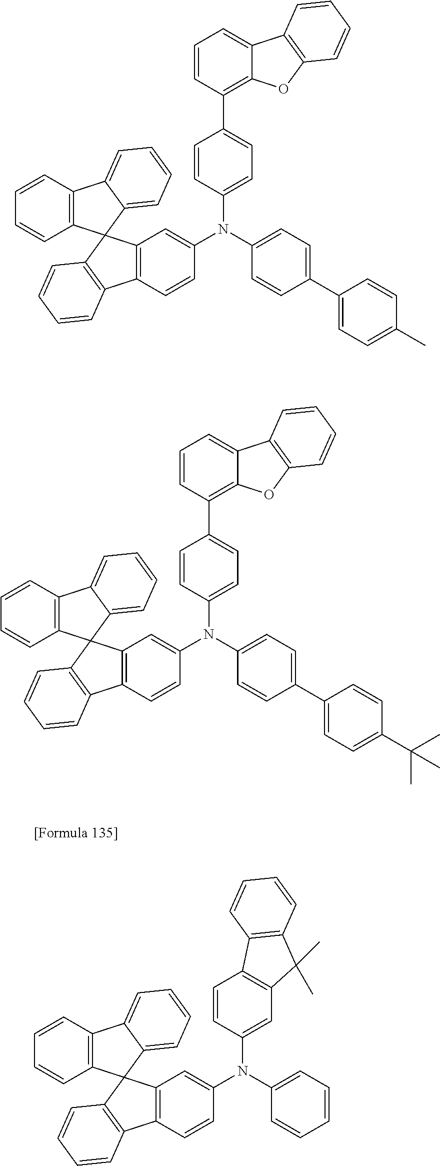 [SMILES: Cc1ccc(-c2ccc(N(c3ccc(-c4cccc5c4oc4ccccc45)cc3)c3ccc4c(c3)C3(c5ccccc5-c5ccccc53)c3ccccc3-4)cc2)cc1 ; CC(C)(C)c1ccc(-c2ccc(N(c3ccc(-c4cccc5c4oc4ccccc45)cc3)c3ccc4c(c3)C3(c5ccccc5-c5ccccc53)c3ccccc3-4)cc2)cc1 ; CC1(C)c2ccccc2-c2ccc(N(c3ccccc3)c3ccc4c(c3)C3(c5ccccc5-c5ccccc53)c3ccccc3-4)cc21]

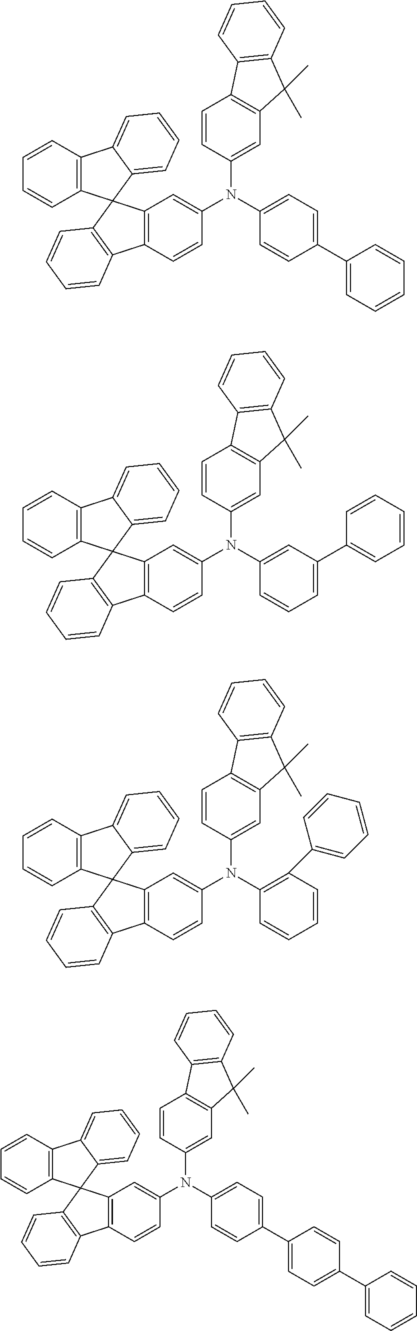 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3cccc(-c4ccccc4)c3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc(-c4ccc(-c5ccccc5)cc4)cc3)c3ccc4c(c3)C3(c5ccccc5-c5ccccc53)c3ccccc3-4)cc21]

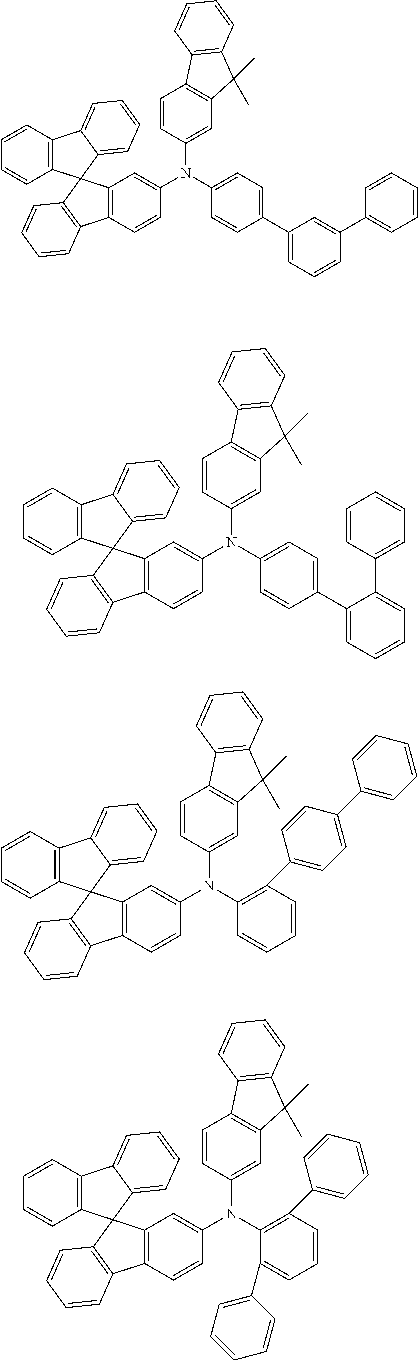 [SMILES: CC1(C)c2ccccc2-c2ccc(N(c3ccc(-c4cccc(-c5ccccc5)c4)cc3)c3ccc4c(c3)C3(c5ccccc5-c5ccccc53)c3ccccc3-4)cc21 ; CC1(C)c2ccccc2-c2ccc(N(c3ccc(-c4ccccc4-c4ccccc4)cc3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccc(-c4ccccc4)cc3)cc21 ; CC1(C)c2ccccc2-c2ccc(N(c3ccc4c(c3)C3(c5ccccc5-c5ccccc53)c3ccccc3-4)c3c(-c4ccccc4)cccc3-c3ccccc3)cc21]

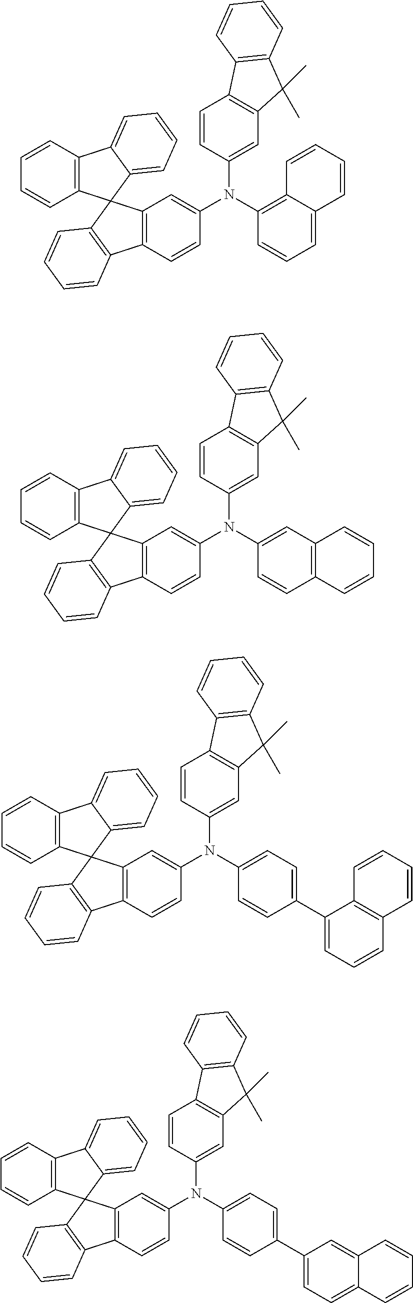 [SMILES: CC1(C)c2ccccc2-c2ccc(N(c3ccc4c(c3)C3(c5ccccc5-c5ccccc53)c3ccccc3-4)c3cccc4ccccc34)cc21 ; CC1(C)c2ccccc2-c2ccc(N(c3ccc4c(c3)C3(c5ccccc5-c5ccccc53)c3ccccc3-4)c3ccc4ccccc4c3)cc21 ; CC1(C)c2ccccc2-c2ccc(N(c3ccc(-c4cccc5ccccc45)cc3)c3ccc4c(c3)C3(c5ccccc5-c5ccccc53)c3ccccc3-4)cc21 ; CC1(C)c2ccccc2-c2ccc(N(c3ccc(-c4ccc5ccccc5c4)cc3)c3ccc4c(c3)C3(c5ccccc5-c5ccccc53)c3ccccc3-4)cc21]

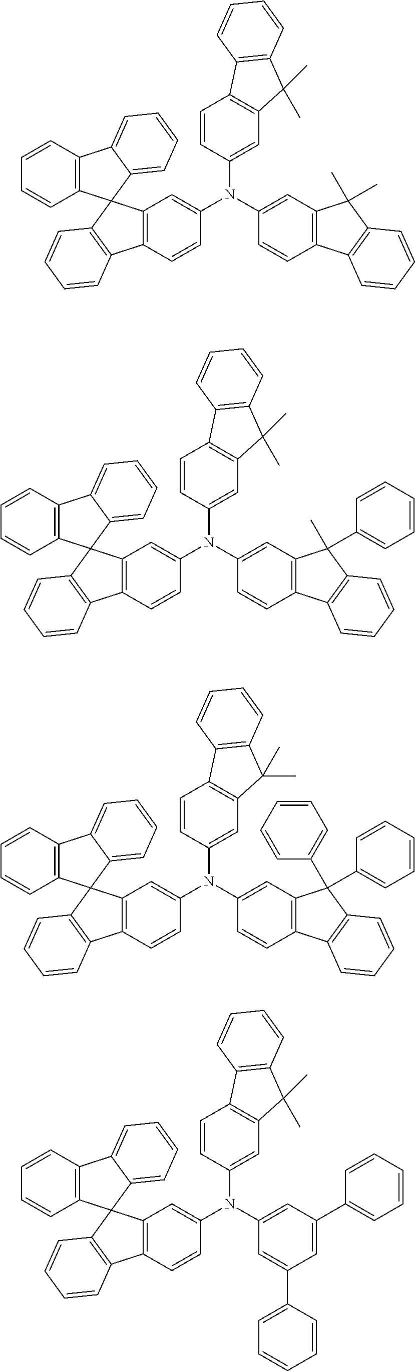 [SMILES: CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(c3ccccc3)c3ccccc3-4)c3ccc4c(c3)C3(c5ccccc5-c5ccccc53)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc21 ; CC1(C)c2ccccc2-c2ccc(N(c3cc(-c4ccccc4)cc(-c4ccccc4)c3)c3ccc4c(c3)C3(c5ccccc5-c5ccccc53)c3ccccc3-4)cc21]

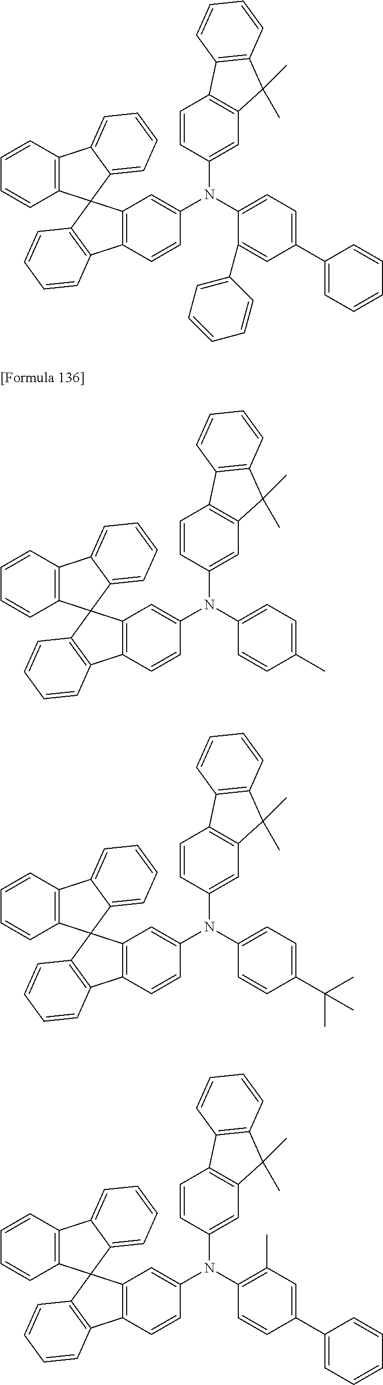 [SMILES: CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21 ; Cc1ccc(N(c2ccc3c(c2)C(C)(C)c2ccccc2-3)c2ccc3c(c2)C2(c4ccccc4-c4ccccc42)c2ccccc2-3)cc1 ; CC(C)(C)c1ccc(N(c2ccc3c(c2)C(C)(C)c2ccccc2-3)c2ccc3c(c2)C2(c4ccccc4-c4ccccc42)c2ccccc2-3)cc1 ; Cc1cc(-c2ccccc2)ccc1N(c1ccc2c(c1)C(C)(C)c1ccccc1-2)c1ccc2c(c1)C1(c3ccccc3-c3ccccc31)c1ccccc1-2]

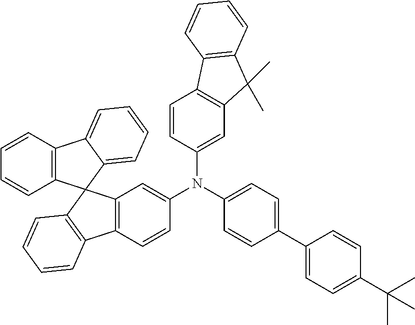 [SMILES: CC(C)(C)c1ccc(-c2ccc(N(c3ccc4c(c3)C(C)(C)c3ccccc3-4)c3ccc4c(c3)C3(c5ccccc5-c5ccccc53)c3ccccc3-4)cc2)cc1]

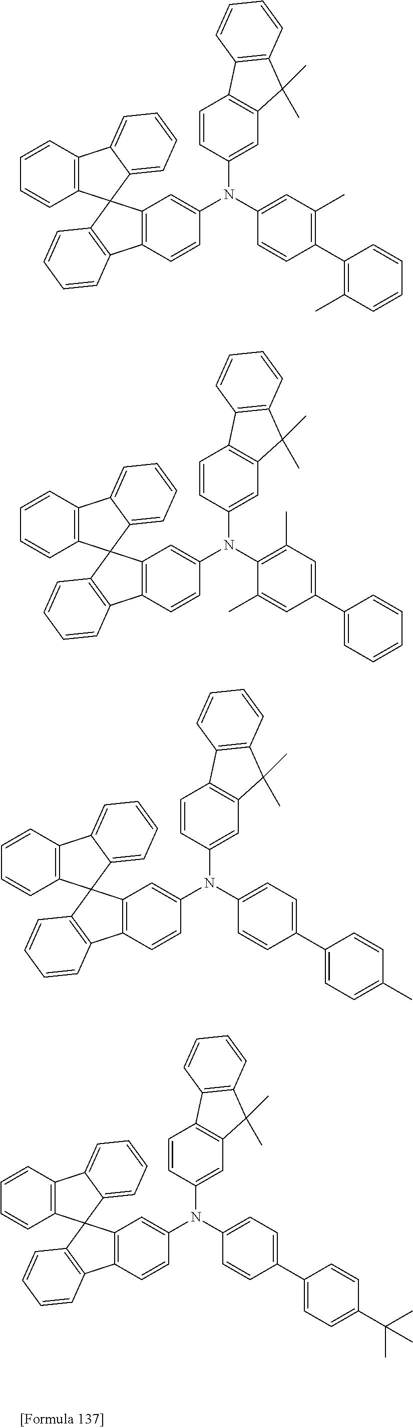 [SMILES: Cc1ccccc1-c1ccc(N(c2ccc3c(c2)C(C)(C)c2ccccc2-3)c2ccc3c(c2)C2(c4ccccc4-c4ccccc42)c2ccccc2-3)cc1C ; Cc1cc(-c2ccccc2)cc(C)c1N(c1ccc2c(c1)C(C)(C)c1ccccc1-2)c1ccc2c(c1)C1(c3ccccc3-c3ccccc31)c1ccccc1-2 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; CC(C)(C)c1ccc(-c2ccc(N(c3ccc4c(c3)C(C)(C)c3ccccc3-4)c3ccc4c(c3)C3(c5ccccc5-c5ccccc53)c3ccccc3-4)cc2)cc1]

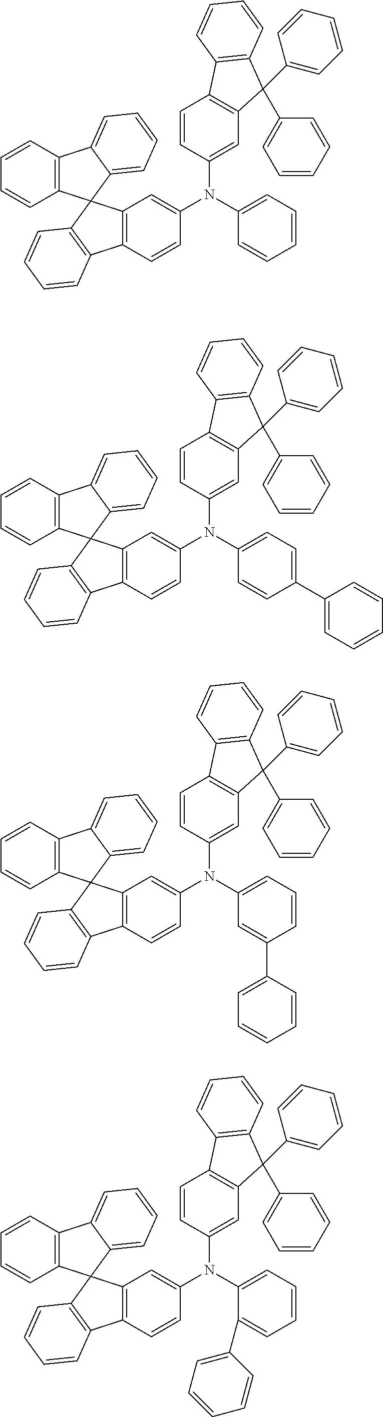

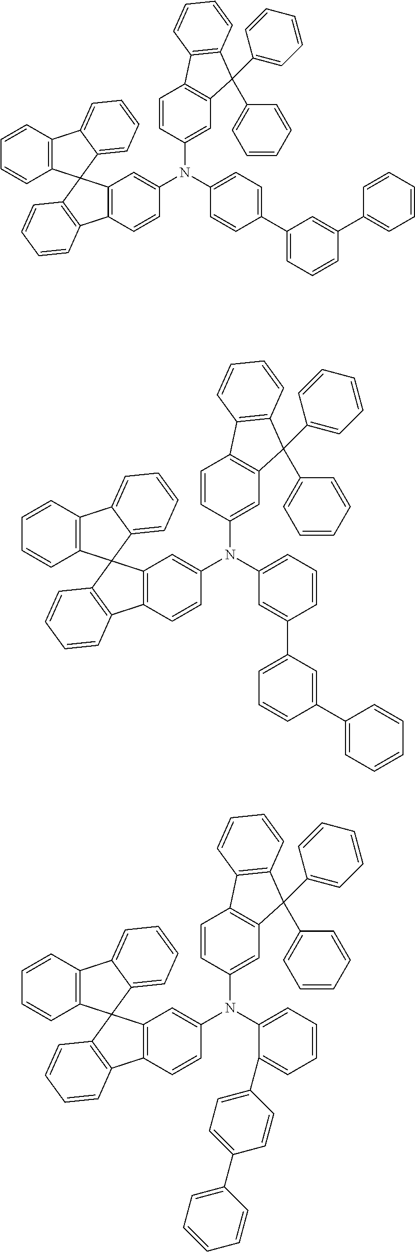 [SMILES: c1ccc(-c2cccc(-c3ccc(N(c4ccc5c(c4)C(c4ccccc4)(c4ccccc4)c4ccccc4-5)c4ccc5c(c4)C4(c6ccccc6-c6ccccc64)c4ccccc4-5)cc3)c2)cc1 ; c1ccc(-c2cccc(-c3cccc(N(c4ccc5c(c4)C(c4ccccc4)(c4ccccc4)c4ccccc4-5)c4ccc5c(c4)C4(c6ccccc6-c6ccccc64)c4ccccc4-5)c3)c2)cc1 ; c1ccc(-c2ccc(-c3ccccc3N(c3ccc4c(c3)C(c3ccccc3)(c3ccccc3)c3ccccc3-4)c3ccc4c(c3)C3(c5ccccc5-c5ccccc53)c3ccccc3-4)cc2)cc1]

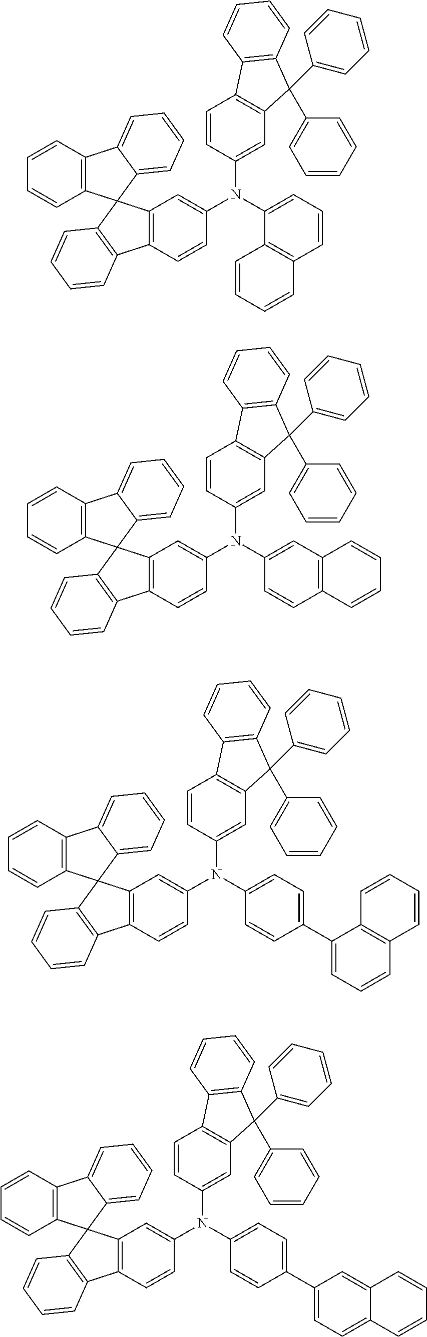

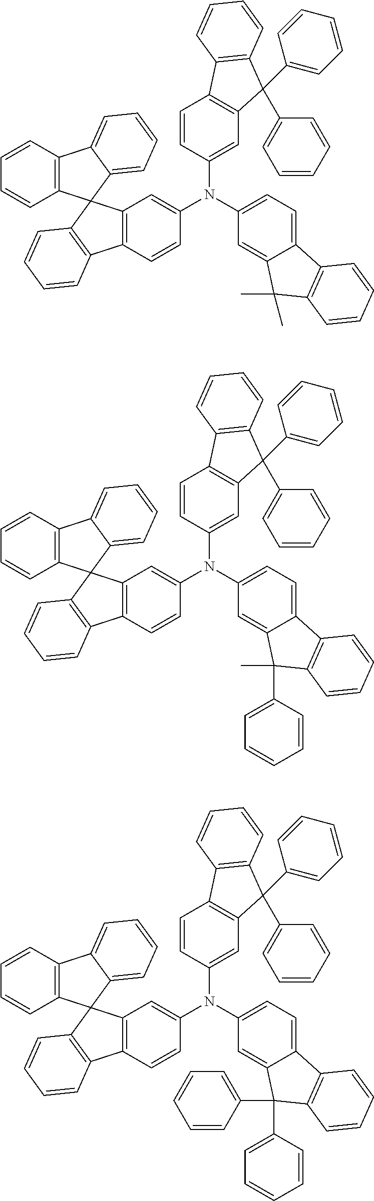 [SMILES: CC1(C)c2ccccc2-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc21 ; CC1(c2ccccc2)c2ccccc2-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc21 ; c1ccc(C2(c3ccccc3)c3ccccc3-c3ccc(N(c4ccc5c(c4)C(c4ccccc4)(c4ccccc4)c4ccccc4-5)c4ccc5c(c4)C4(c6ccccc6-c6ccccc64)c4ccccc4-5)cc32)cc1]

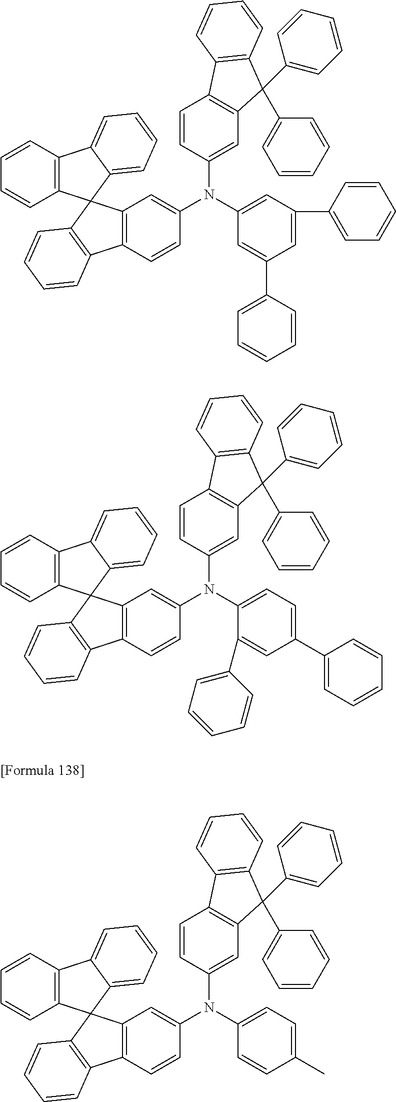

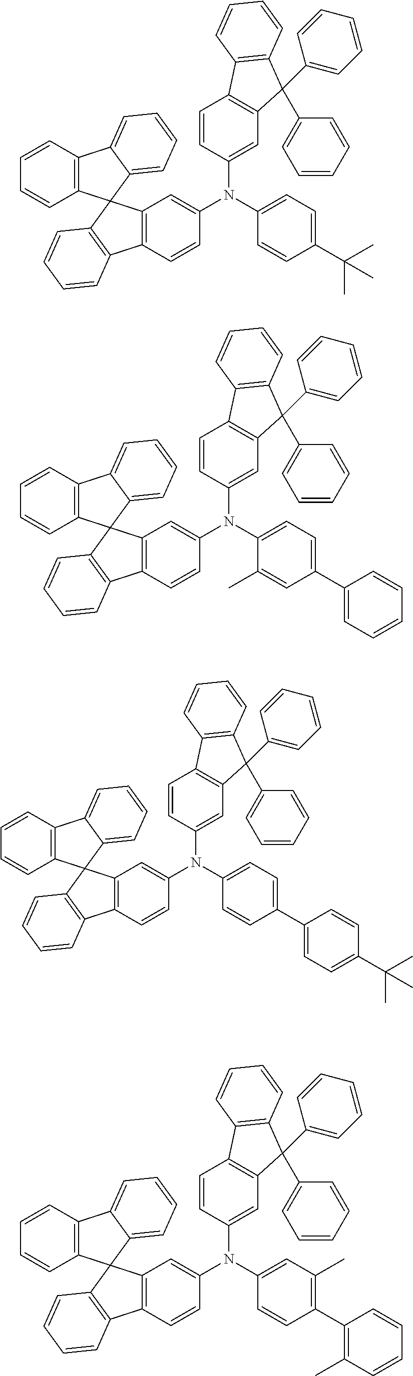 [SMILES: CC(C)(C)c1ccc(N(c2ccc3c(c2)C(c2ccccc2)(c2ccccc2)c2ccccc2-3)c2ccc3c(c2)C2(c4ccccc4-c4ccccc42)c2ccccc2-3)cc1 ; Cc1cc(-c2ccccc2)ccc1N(c1ccc2c(c1)C(c1ccccc1)(c1ccccc1)c1ccccc1-2)c1ccc2c(c1)C1(c3ccccc3-c3ccccc31)c1ccccc1-2 ; CC(C)(C)c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; Cc1ccccc1-c1ccc(N(c2ccc3c(c2)C(c2ccccc2)(c2ccccc2)c2ccccc2-3)c2ccc3c(c2)C2(c4ccccc4-c4ccccc42)c2ccccc2-3)cc1C]

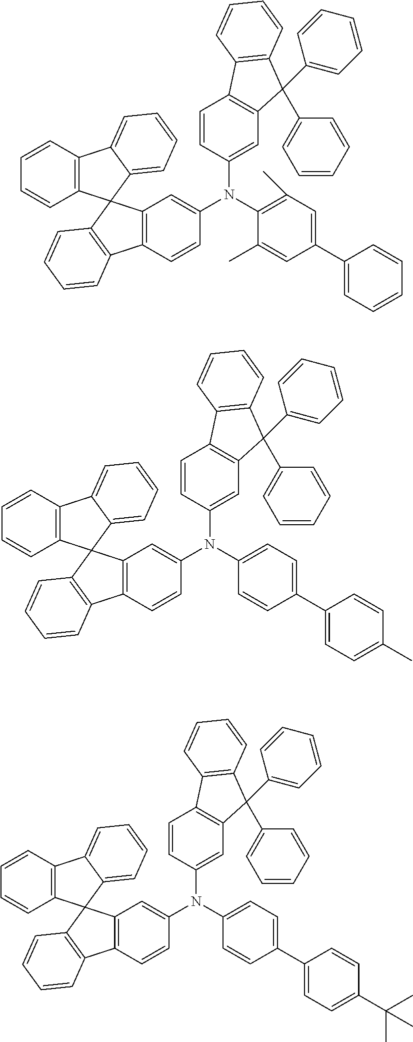 [SMILES: Cc1cc(-c2ccccc2)cc(C)c1N(c1ccc2c(c1)C(c1ccccc1)(c1ccccc1)c1ccccc1-2)c1ccc2c(c1)C1(c3ccccc3-c3ccccc31)c1ccccc1-2 ; Cc1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; CC(C)(C)c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1]

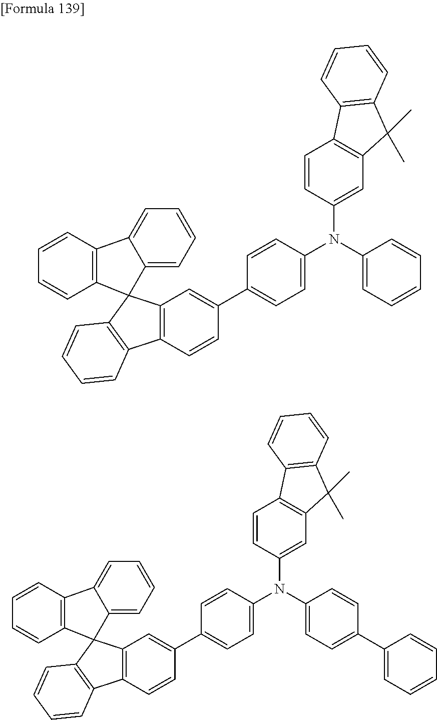 [SMILES: CC1(C)c2ccccc2-c2ccc(N(c3ccccc3)c3ccc(-c4ccc5c(c4)C4(c6ccccc6-c6ccccc64)c4ccccc4-5)cc3)cc21 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21]

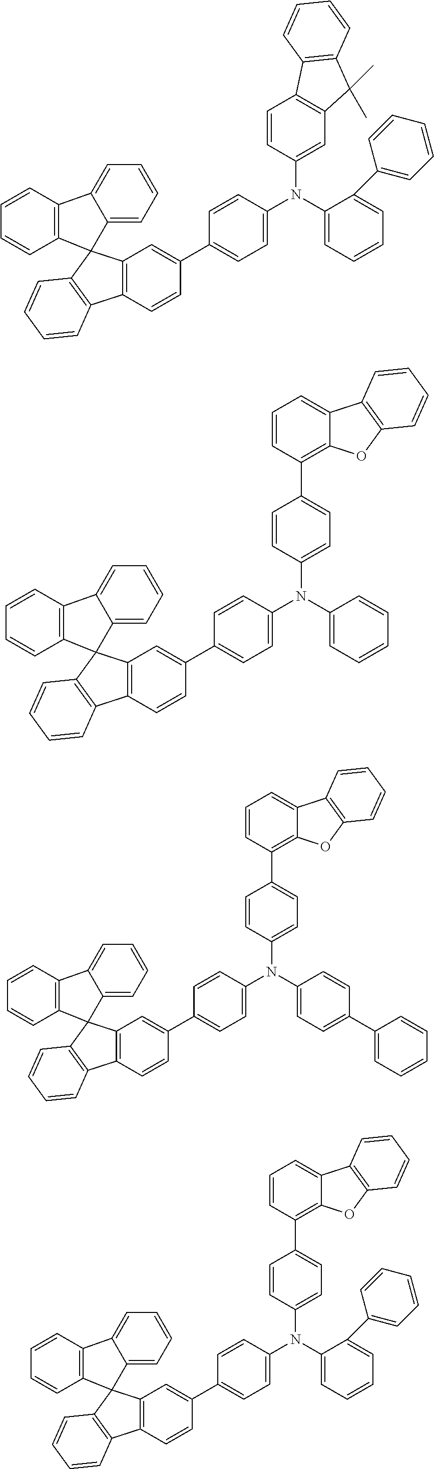 [SMILES: CC1(C)c2ccccc2-c2ccc(N(c3ccc(-c4ccc5c(c4)C4(c6ccccc6-c6ccccc64)c4ccccc4-5)cc3)c3ccccc3-c3ccccc3)cc21 ; c1ccc(N(c2ccc(-c3ccc4c(c3)C3(c5ccccc5-c5ccccc53)c3ccccc3-4)cc2)c2ccc(-c3cccc4c3oc3ccccc34)cc2)cc1 ; c1ccc(-c2ccc(N(c3ccc(-c4ccc5c(c4)C4(c6ccccc6-c6ccccc64)c4ccccc4-5)cc3)c3ccc(-c4cccc5c4oc4ccccc45)cc3)cc2)cc1 ; c1ccc(-c2ccccc2N(c2ccc(-c3ccc4c(c3)C3(c5ccccc5-c5ccccc53)c3ccccc3-4)cc2)c2ccc(-c3cccc4c3oc3ccccc34)cc2)cc1]

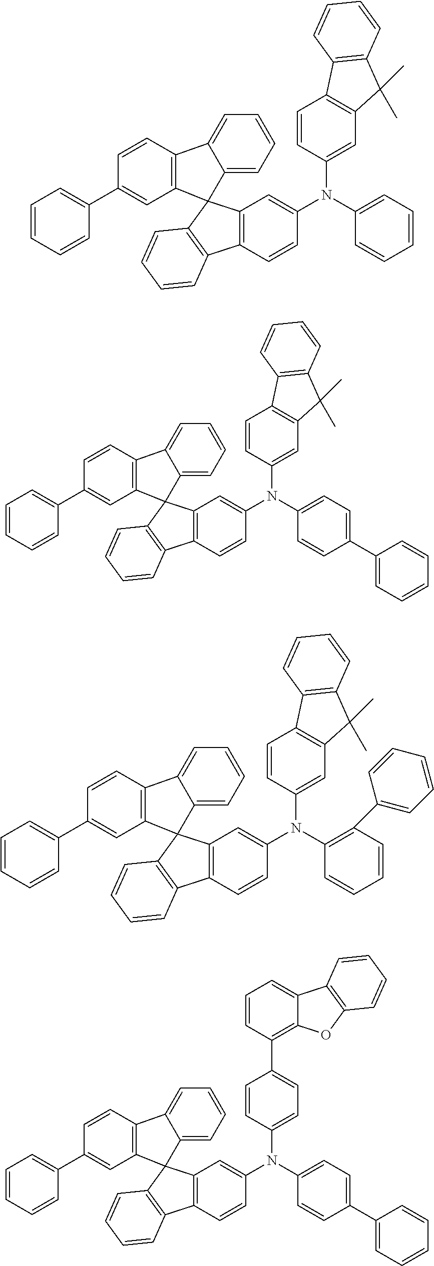 [SMILES: CC1(C)c2ccccc2-c2ccc(N(c3ccccc3)c3ccc4c(c3)C3(c5ccccc5-c5ccc(-c6ccccc6)cc53)c3ccccc3-4)cc21 ; CC1(C)c2ccccc2-c2ccc(N(c3ccc(-c4ccccc4)cc3)c3ccc4c(c3)C3(c5ccccc5-c5ccc(-c6ccccc6)cc53)c3ccccc3-4)cc21 ; CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21 ; c1ccc(-c2ccc(N(c3ccc(-c4cccc5c4oc4ccccc45)cc3)c3ccc4c(c3)C3(c5ccccc5-c5ccc(-c6ccccc6)cc53)c3ccccc3-4)cc2)cc1]

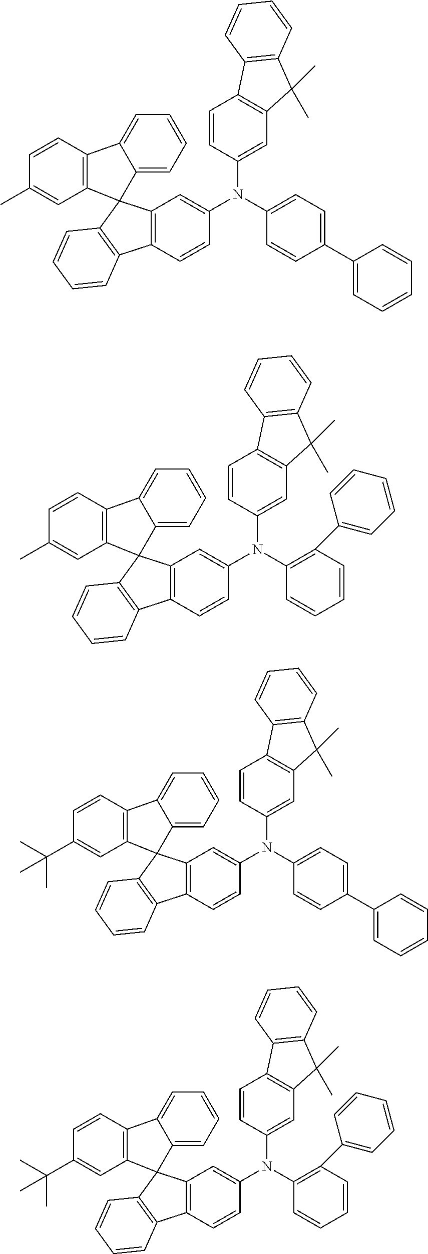 [SMILES: Cc1ccc2c(c1)C1(c3ccccc3-2)c2ccccc2-c2ccc(N(c3ccc(-c4ccccc4)cc3)c3ccc4c(c3)C(C)(C)c3ccccc3-4)cc21 ; Cc1ccc2c(c1)C1(c3ccccc3-2)c2ccccc2-c2ccc(N(c3ccc4c(c3)C(C)(C)c3ccccc3-4)c3ccccc3-c3ccccc3)cc21 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1ccccc1-2 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1ccccc1-2]

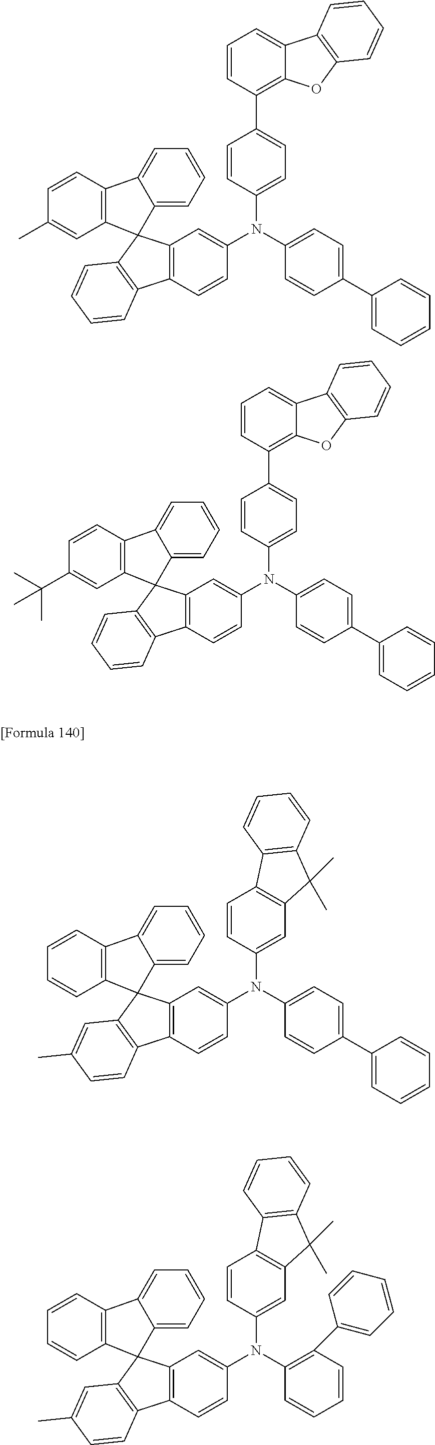

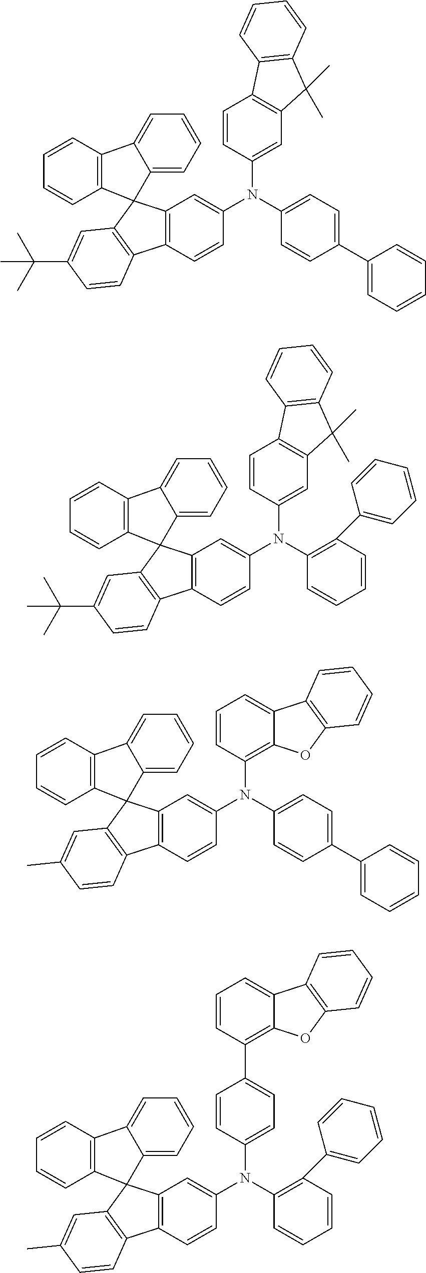 [SMILES: CC(C)(C)c1ccc2c(c1)C1(c3ccccc3-c3ccccc31)c1cc(N(c3ccc(-c4ccccc4)cc3)c3ccc4c(c3)C(C)(C)c3ccccc3-4)ccc1-2 ; CC(C)(C)c1ccc2c(c1)C1(c3ccccc3-c3ccccc31)c1cc(N(c3ccc4c(c3)C(C)(C)c3ccccc3-4)c3ccccc3-c3ccccc3)ccc1-2 ; Cc1ccc2c(c1)C1(c3ccccc3-c3ccccc31)c1cc(N(c3ccc(-c4ccccc4)cc3)c3cccc4c3oc3ccccc34)ccc1-2 ; Cc1ccc2c(c1)C1(c3ccccc3-c3ccccc31)c1cc(N(c3ccc(-c4cccc5c4oc4ccccc45)cc3)c3ccccc3-c3ccccc3)ccc1-2]

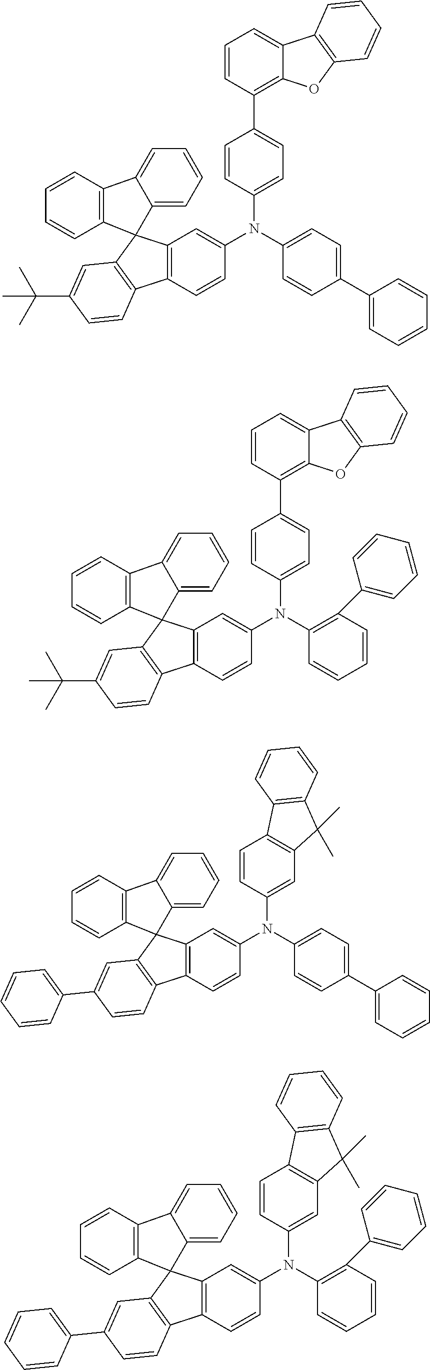

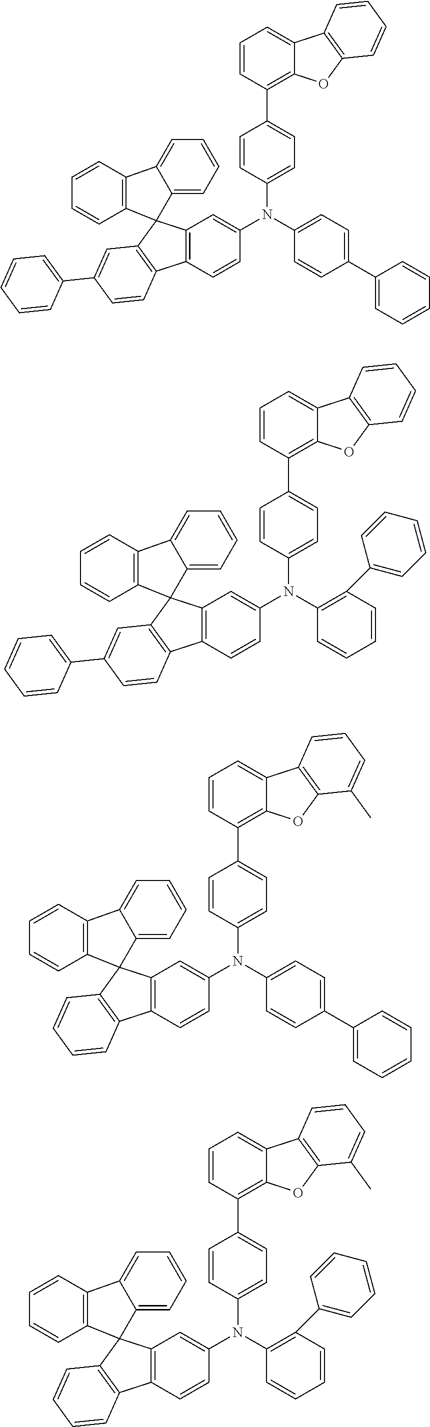

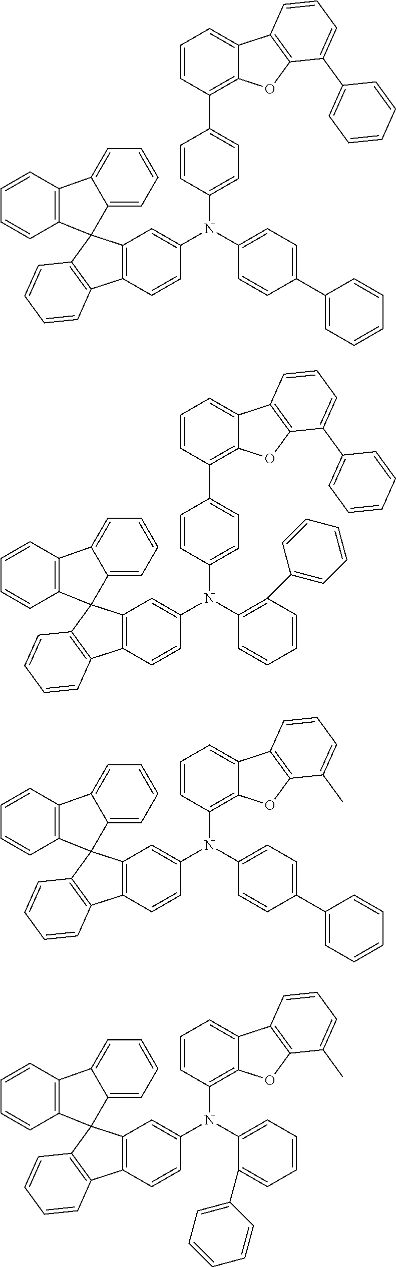

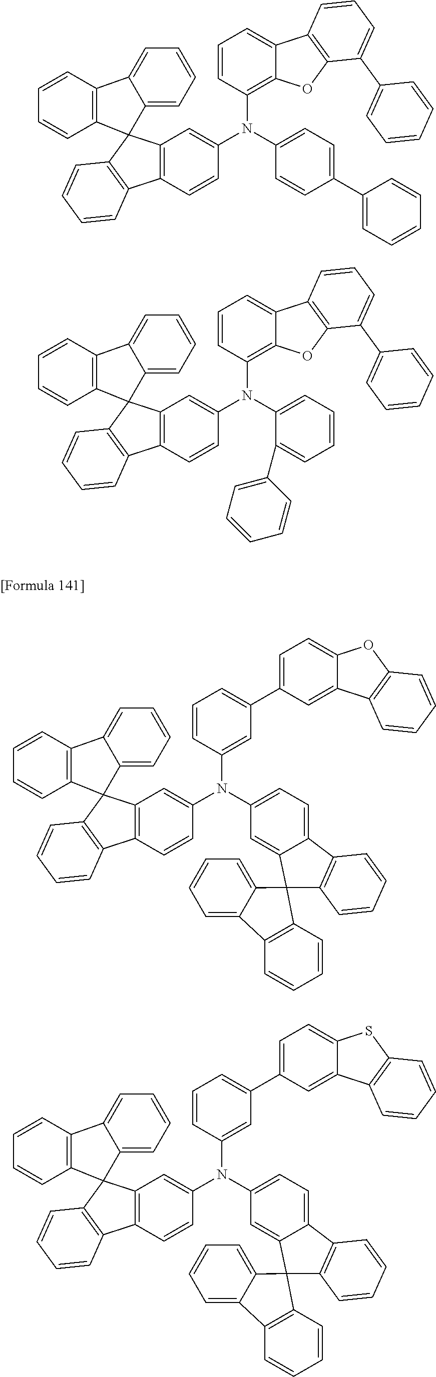

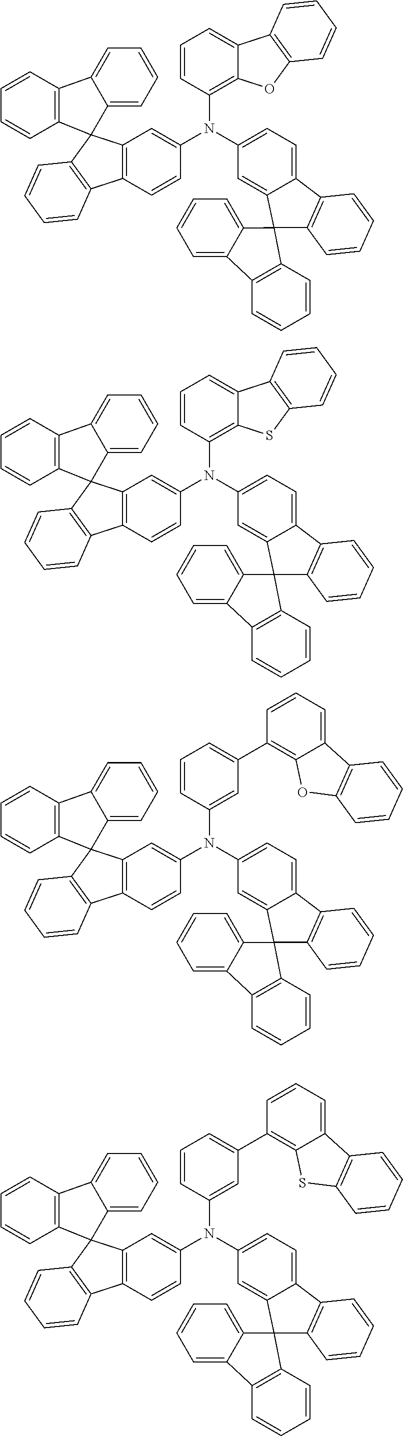

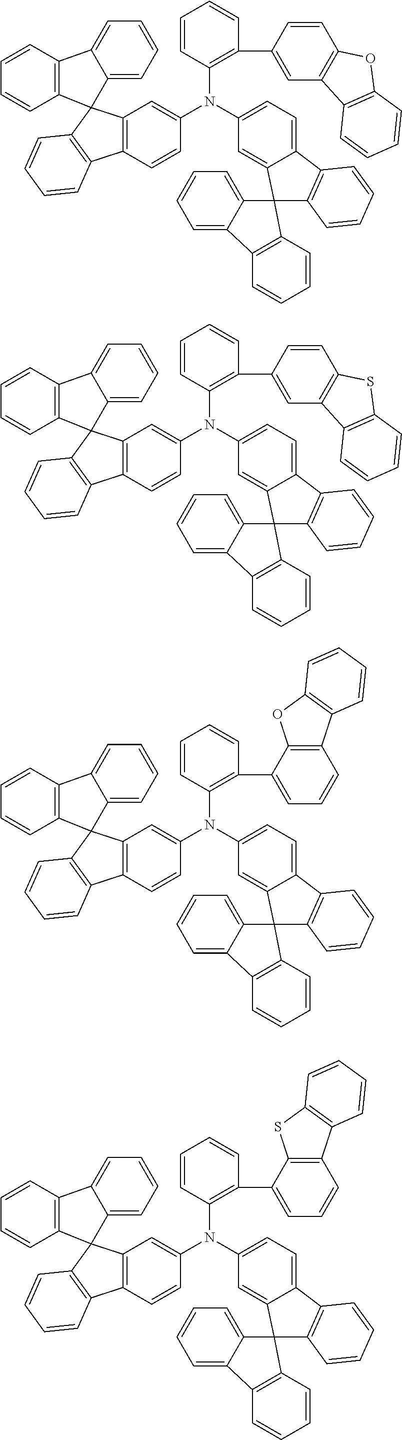

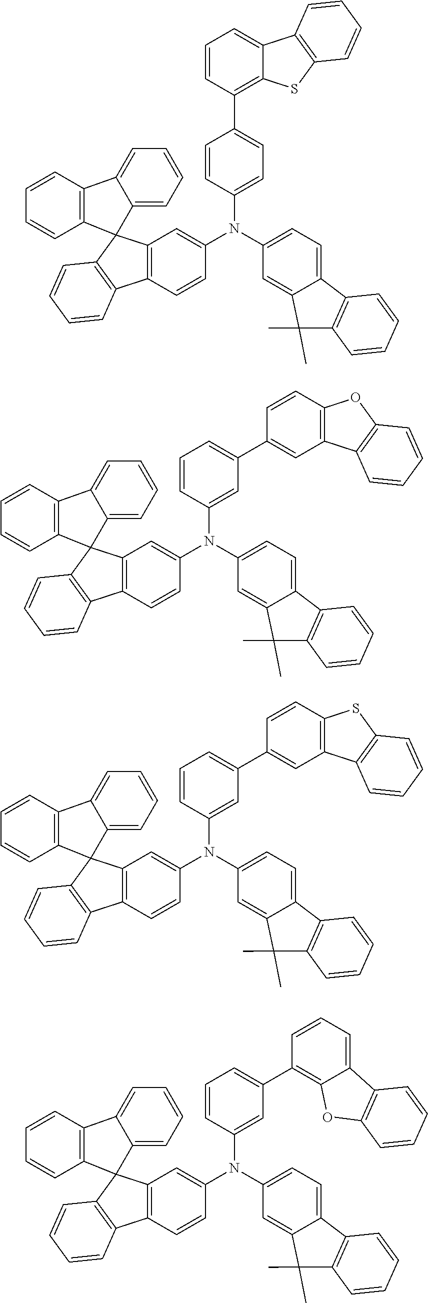

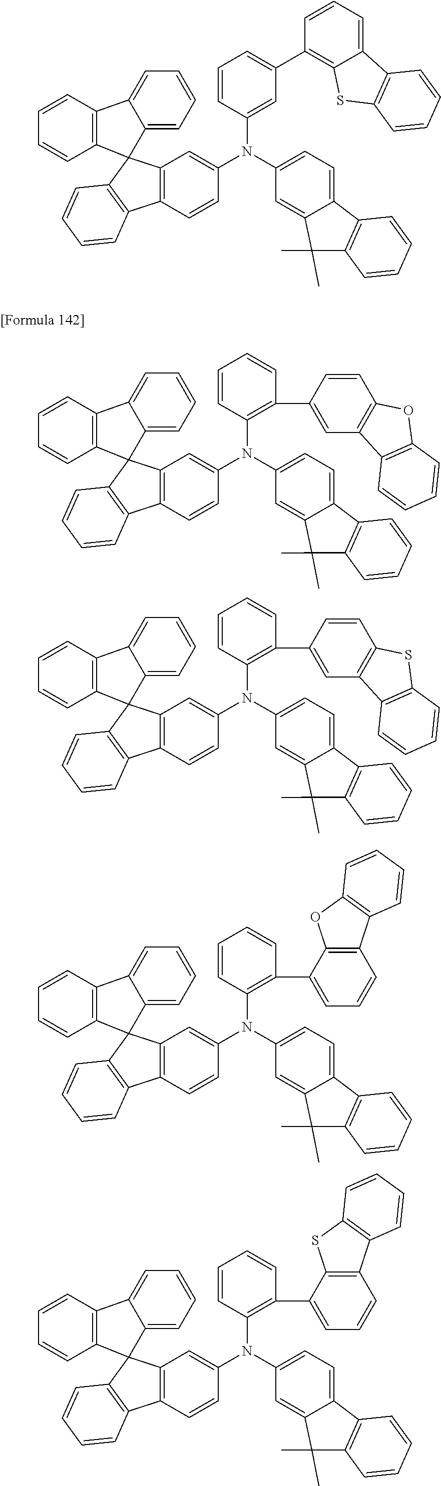

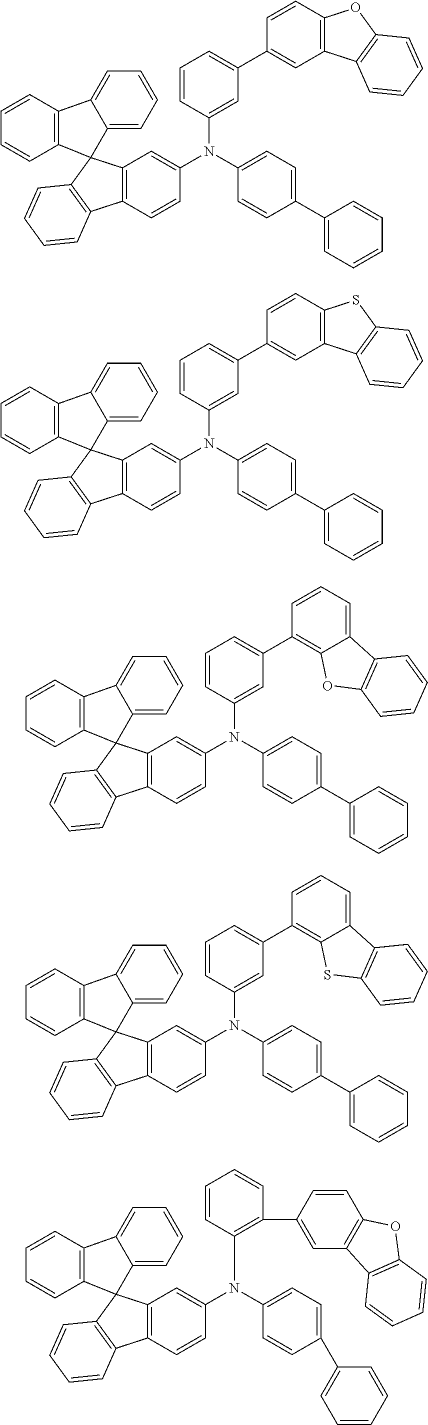

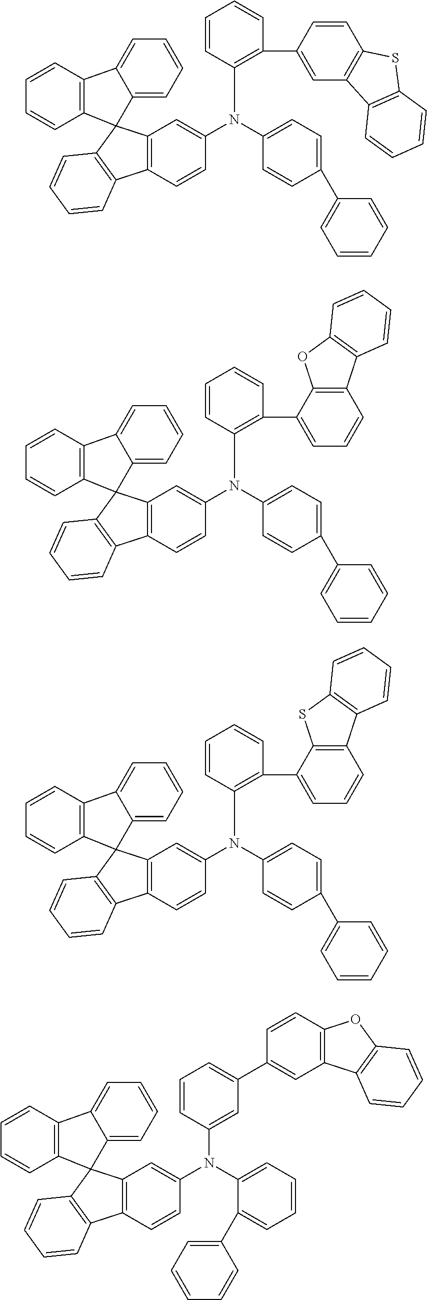

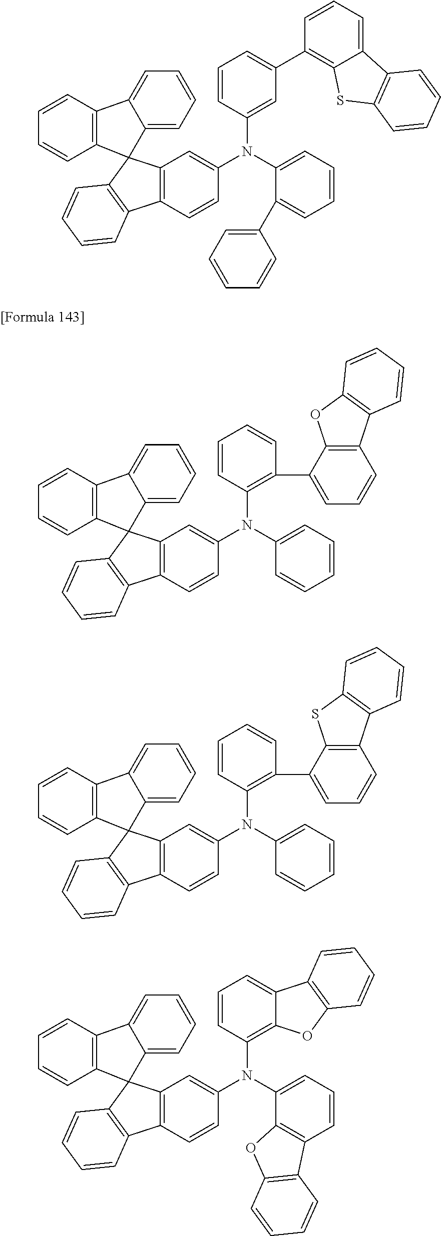 [SMILES: c1ccc(-c2ccccc2N(c2cccc(-c3cccc4c3sc3ccccc34)c2)c2ccc3c(c2)C2(c4ccccc4-c4ccccc42)c2ccccc2-3)cc1 ; c1ccc(N(c2ccc3c(c2)C2(c4ccccc4-c4ccccc42)c2ccccc2-3)c2ccccc2-c2cccc3c2oc2ccccc23)cc1 ; c1ccc(N(c2ccc3c(c2)C2(c4ccccc4-c4ccccc42)c2ccccc2-3)c2ccccc2-c2cccc3c2sc2ccccc23)cc1 ; c1ccc2c(c1)-c1ccccc1C21c2ccccc2-c2ccc(N(c3cccc4c3oc3ccccc34)c3cccc4c3oc3ccccc34)cc21]

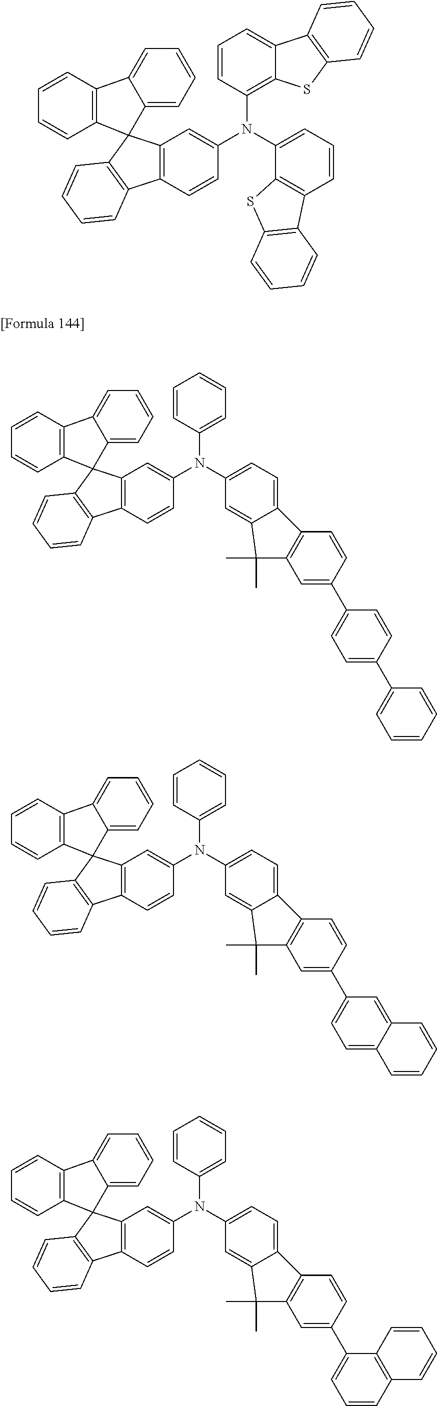 [SMILES: c1ccc2c(c1)-c1ccccc1C21c2ccccc2-c2ccc(N(c3cccc4c3sc3ccccc34)c3cccc4c3sc3ccccc34)cc21 ; CC1(C)c2cc(-c3ccc(-c4ccccc4)cc3)ccc2-c2ccc(N(c3ccccc3)c3ccc4c(c3)C3(c5ccccc5-c5ccccc53)c3ccccc3-4)cc21 ; CC1(C)c2cc(-c3ccc4ccccc4c3)ccc2-c2ccc(N(c3ccccc3)c3ccc4c(c3)C3(c5ccccc5-c5ccccc53)c3ccccc3-4)cc21 ; CC1(C)c2cc(-c3cccc4ccccc34)ccc2-c2ccc(N(c3ccccc3)c3ccc4c(c3)C3(c5ccccc5-c5ccccc53)c3ccccc3-4)cc21]

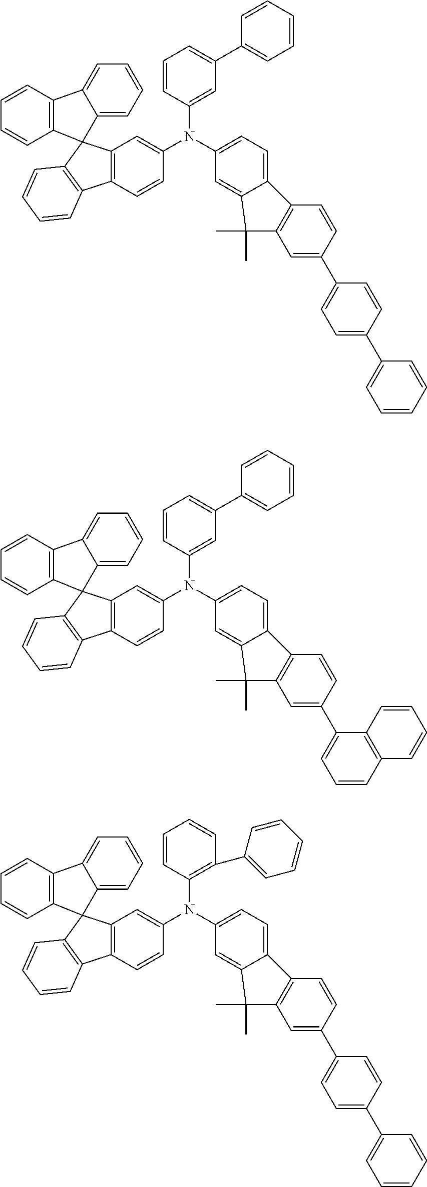 [SMILES: CC1(C)c2cc(-c3ccc(-c4ccccc4)cc3)ccc2-c2ccc(N(c3cccc(-c4ccccc4)c3)c3ccc4c(c3)C3(c5ccccc5-c5ccccc53)c3ccccc3-4)cc21 ; CC1(C)c2cc(-c3cccc4ccccc34)ccc2-c2ccc(N(c3cccc(-c4ccccc4)c3)c3ccc4c(c3)C3(c5ccccc5-c5ccccc53)c3ccccc3-4)cc21 ; CC1(C)c2cc(-c3ccc(-c4ccccc4)cc3)ccc2-c2ccc(N(c3ccc4c(c3)C3(c5ccccc5-c5ccccc53)c3ccccc3-4)c3ccccc3-c3ccccc3)cc21]

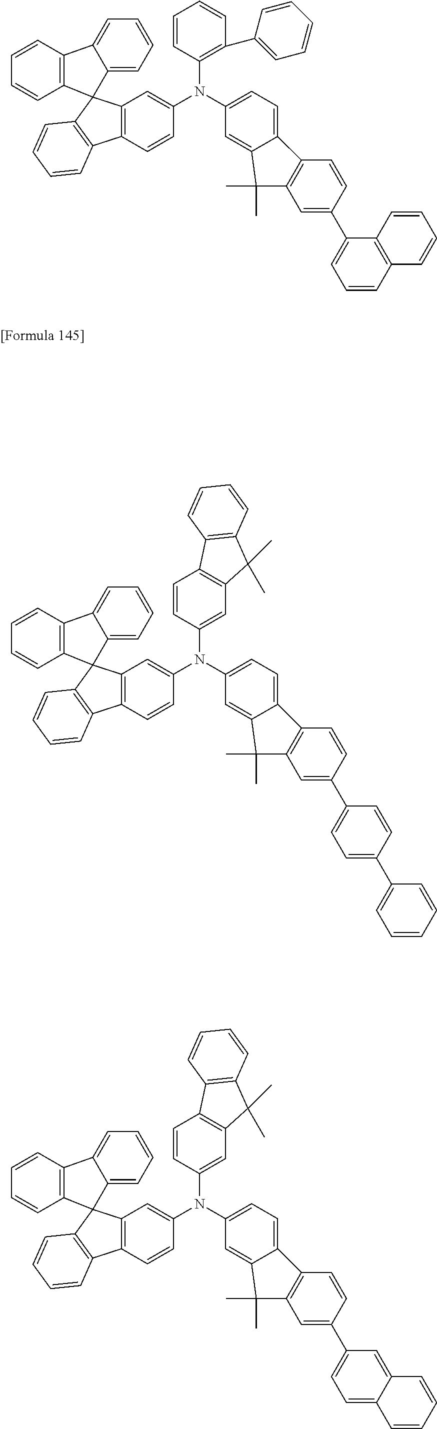 [SMILES: CC1(C)c2cc(-c3cccc4ccccc34)ccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc4c(c3)C(C)(C)c3cc(-c5ccc(-c6ccccc6)cc5)ccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(C)c3cc(-c5ccc6ccccc6c5)ccc3-4)c3ccc4c(c3)C3(c5ccccc5-c5ccccc53)c3ccccc3-4)cc21]

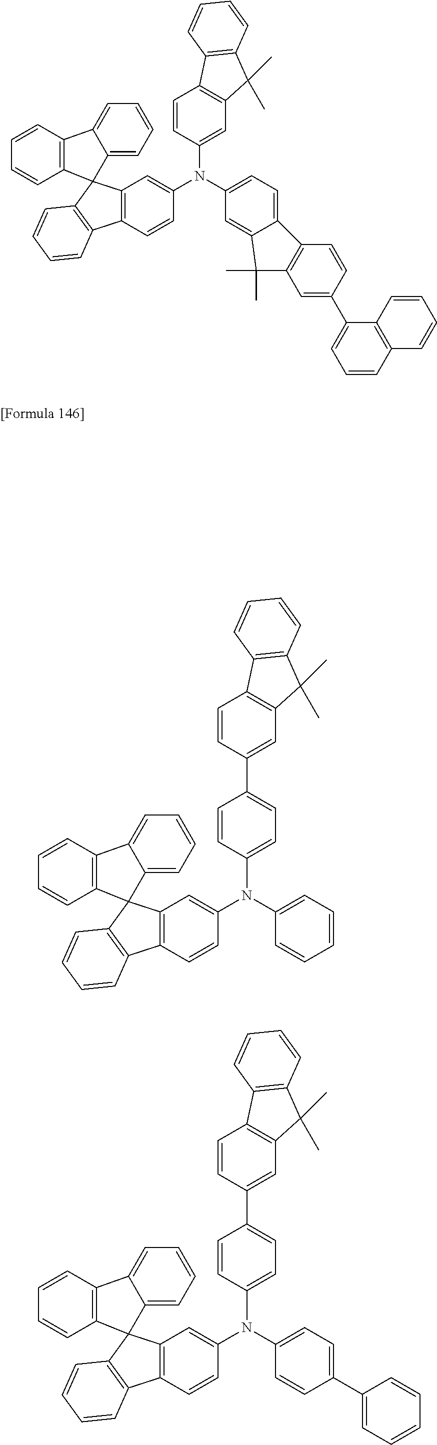 [SMILES: CC1(C)c2ccccc2-c2ccc(N(c3ccc4c(c3)C(C)(C)c3cc(-c5cccc6ccccc56)ccc3-4)c3ccc4c(c3)C3(c5ccccc5-c5ccccc53)c3ccccc3-4)cc21 ; CC1(C)c2ccccc2-c2ccc(-c3ccc(N(c4ccccc4)c4ccc5c(c4)C4(c6ccccc6-c6ccccc64)c4ccccc4-5)cc3)cc21 ; CC1(C)c2ccccc2-c2ccc(-c3ccc(N(c4ccc(-c5ccccc5)cc4)c4ccc5c(c4)C4(c6ccccc6-c6ccccc64)c4ccccc4-5)cc3)cc21]

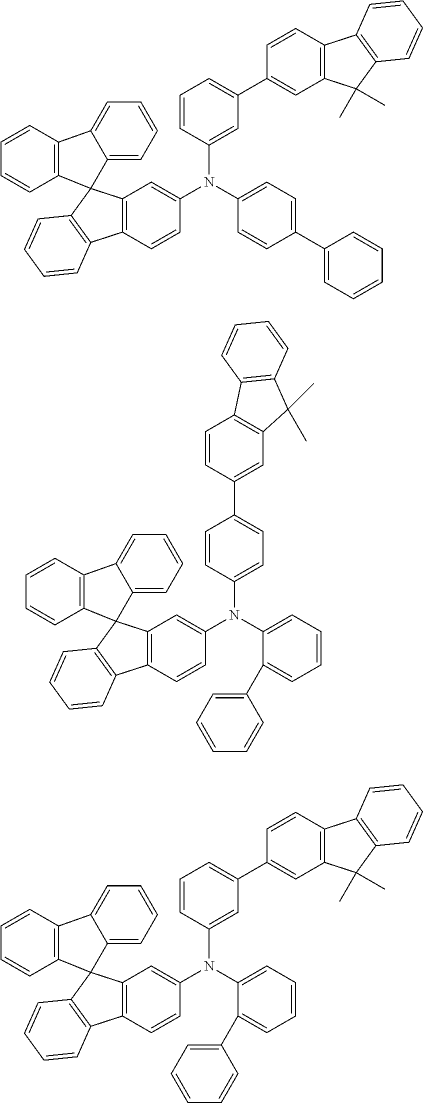 [SMILES: CC1(C)c2ccccc2-c2ccc(-c3cccc(N(c4ccc(-c5ccccc5)cc4)c4ccc5c(c4)C4(c6ccccc6-c6ccccc64)c4ccccc4-5)c3)cc21 ; CC1(C)c2ccccc2-c2ccc(-c3ccc(N(c4ccc5c(c4)C4(c6ccccc6-c6ccccc64)c4ccccc4-5)c4ccccc4-c4ccccc4)cc3)cc21 ; CC1(C)c2ccccc2-c2ccc(-c3cccc(N(c4ccc5c(c4)C4(c6ccccc6-c6ccccc64)c4ccccc4-5)c4ccccc4-c4ccccc4)c3)cc21]

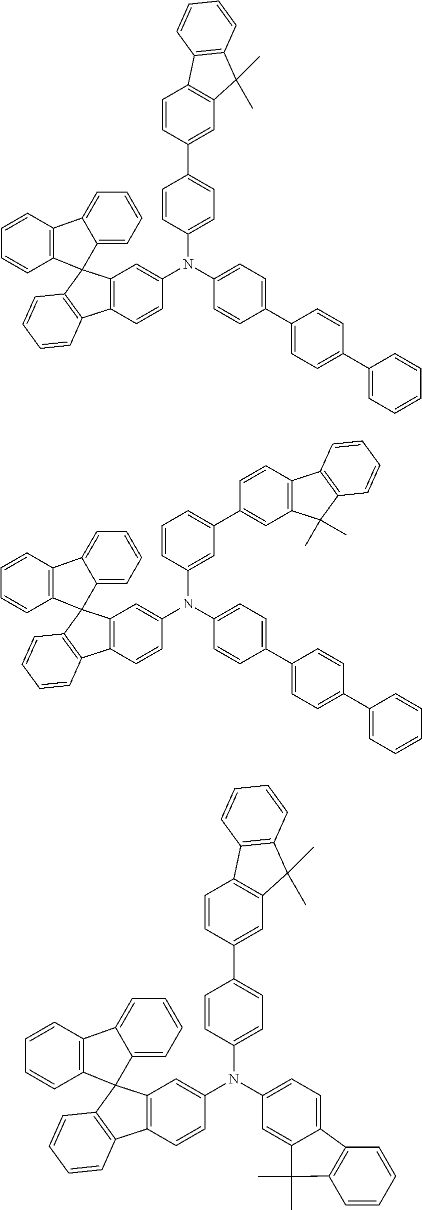 [SMILES: CC1(C)c2ccccc2-c2ccc(-c3ccc(N(c4ccc(-c5ccc(-c6ccccc6)cc5)cc4)c4ccc5c(c4)C4(c6ccccc6-c6ccccc64)c4ccccc4-5)cc3)cc21 ; CC1(C)c2ccccc2-c2ccc(-c3cccc(N(c4ccc(-c5ccc(-c6ccccc6)cc5)cc4)c4ccc5c(c4)C4(c6ccccc6-c6ccccc64)c4ccccc4-5)c3)cc21 ; CC1(C)c2ccccc2-c2ccc(-c3ccc(N(c4ccc5c(c4)C(C)(C)c4ccccc4-5)c4ccc5c(c4)C4(c6ccccc6-c6ccccc64)c4ccccc4-5)cc3)cc21]

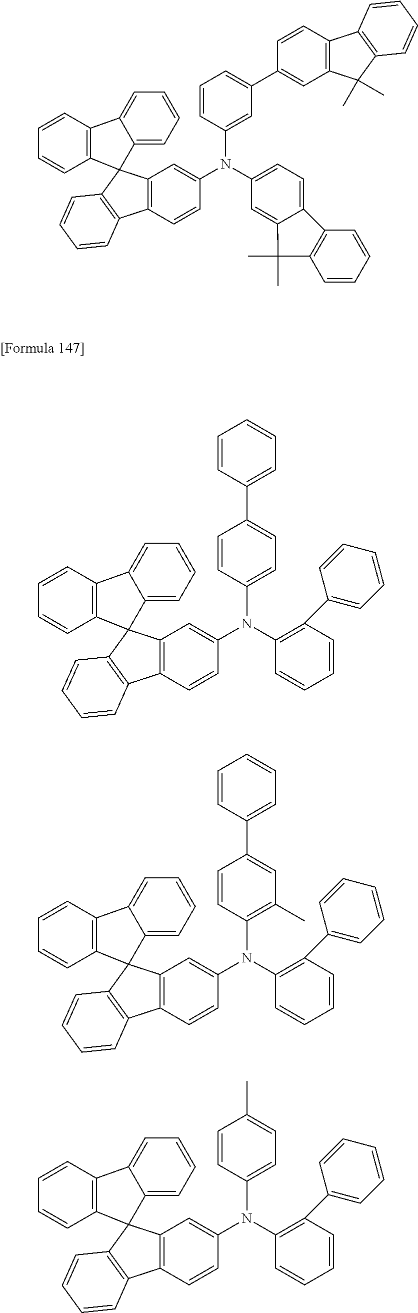 [SMILES: CC1(C)c2ccccc2-c2ccc(-c3cccc(N(c4ccc5c(c4)C(C)(C)c4ccccc4-5)c4ccc5c(c4)C4(c6ccccc6-c6ccccc64)c4ccccc4-5)c3)cc21 ; c1ccc(-c2ccc(N(c3ccc4c(c3)C3(c5ccccc5-c5ccccc53)c3ccccc3-4)c3ccccc3-c3ccccc3)cc2)cc1 ; Cc1cc(-c2ccccc2)ccc1N(c1ccc2c(c1)C1(c3ccccc3-c3ccccc31)c1ccccc1-2)c1ccccc1-c1ccccc1 ; Cc1ccc(N(c2ccc3c(c2)C2(c4ccccc4-c4ccccc42)c2ccccc2-3)c2ccccc2-c2ccccc2)cc1]

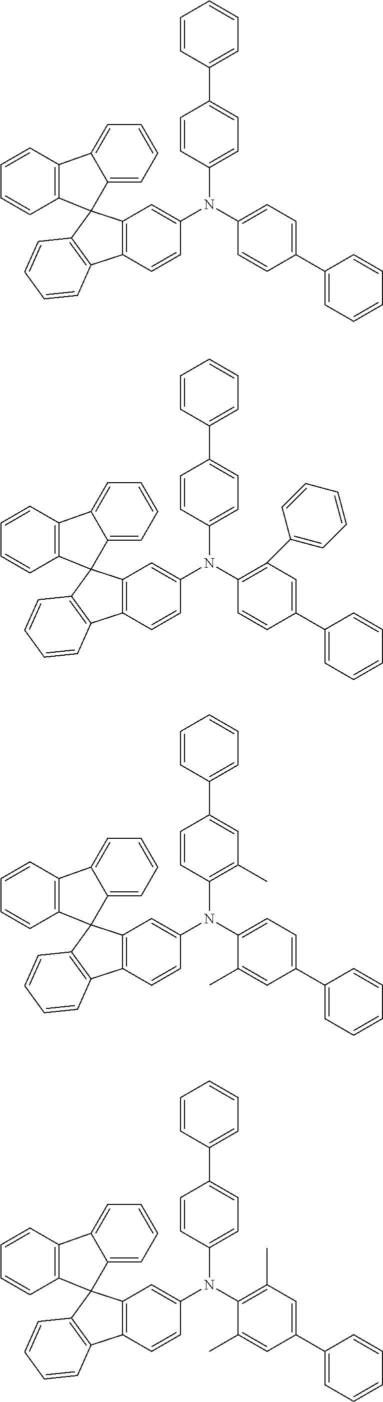 [SMILES: c1ccc(-c2ccc(N(c3ccc(-c4ccccc4)cc3)c3ccc4c(c3)C3(c5ccccc5-c5ccccc53)c3ccccc3-4)cc2)cc1 ; c1ccc(-c2ccc(N(c3ccc4c(c3)C3(c5ccccc5-c5ccccc53)c3ccccc3-4)c3ccc(-c4ccccc4)cc3-c3ccccc3)cc2)cc1 ; Cc1cc(-c2ccccc2)ccc1N(c1ccc2c(c1)C1(c3ccccc3-c3ccccc31)c1ccccc1-2)c1ccc(-c2ccccc2)cc1C ; Cc1cc(-c2ccccc2)cc(C)c1N(c1ccc(-c2ccccc2)cc1)c1ccc2c(c1)C1(c3ccccc3-c3ccccc31)c1ccccc1-2]

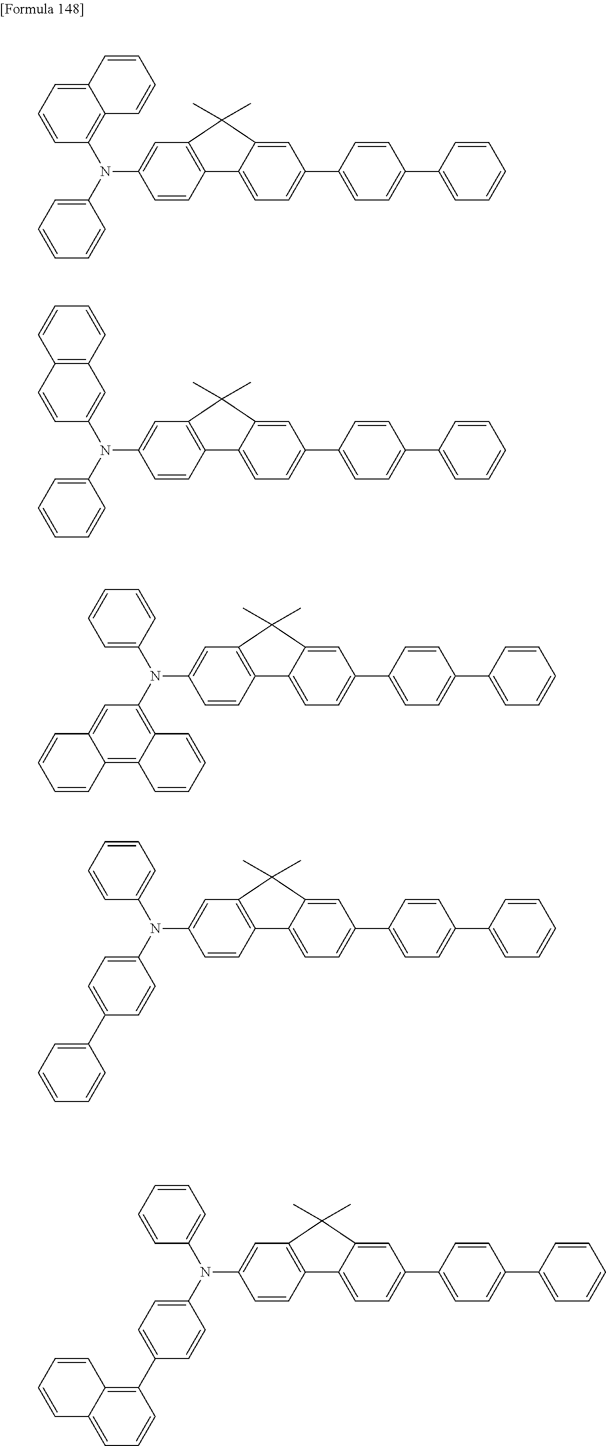 [SMILES: CC1(C)c2cc(-c3ccc(-c4ccccc4)cc3)ccc2-c2ccc(N(c3ccccc3)c3cccc4ccccc34)cc21 ; CC1(C)c2cc(-c3ccc(-c4ccccc4)cc3)ccc2-c2ccc(N(c3ccccc3)c3ccc4ccccc4c3)cc21 ; CC1(C)c2cc(-c3ccc(-c4ccccc4)cc3)ccc2-c2ccc(N(c3ccccc3)c3cc4ccccc4c4ccccc34)cc21 ; CC1(C)c2cc(-c3ccc(-c4ccccc4)cc3)ccc2-c2ccc(N(c3ccccc3)c3ccc(-c4ccccc4)cc3)cc21 ; CC1(C)c2cc(-c3ccc(-c4ccccc4)cc3)ccc2-c2ccc(N(c3ccccc3)c3ccc(-c4cccc5ccccc45)cc3)cc21]

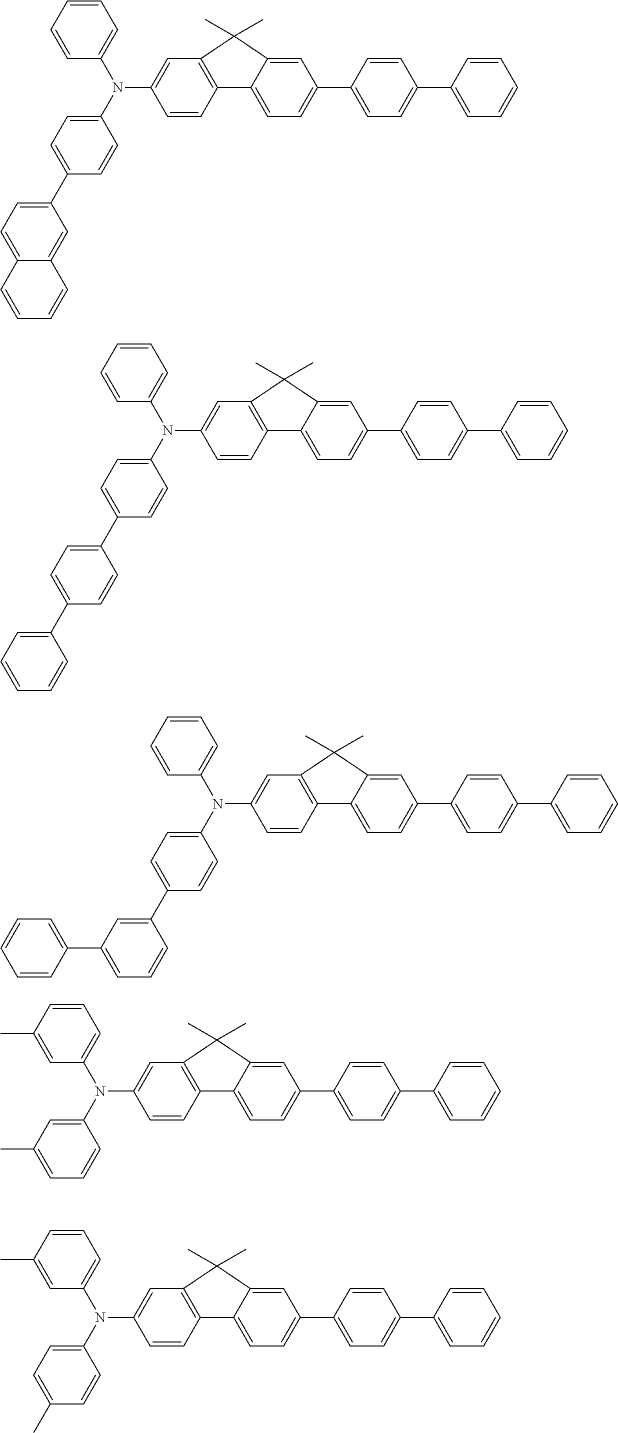

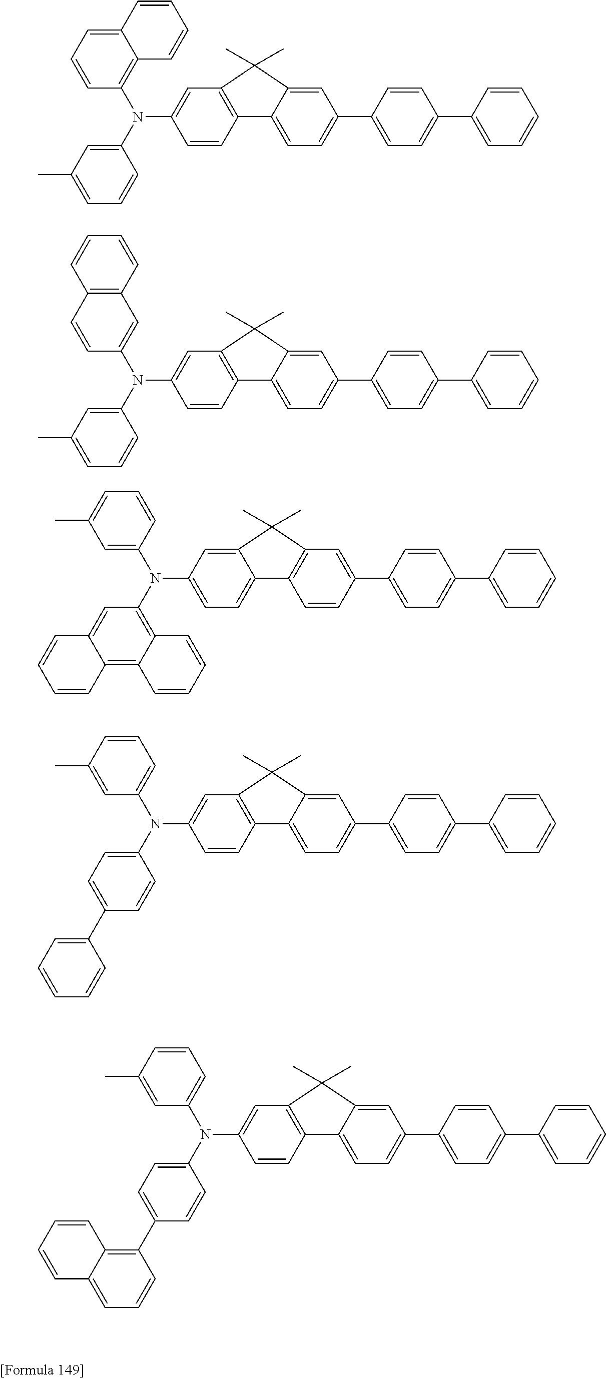

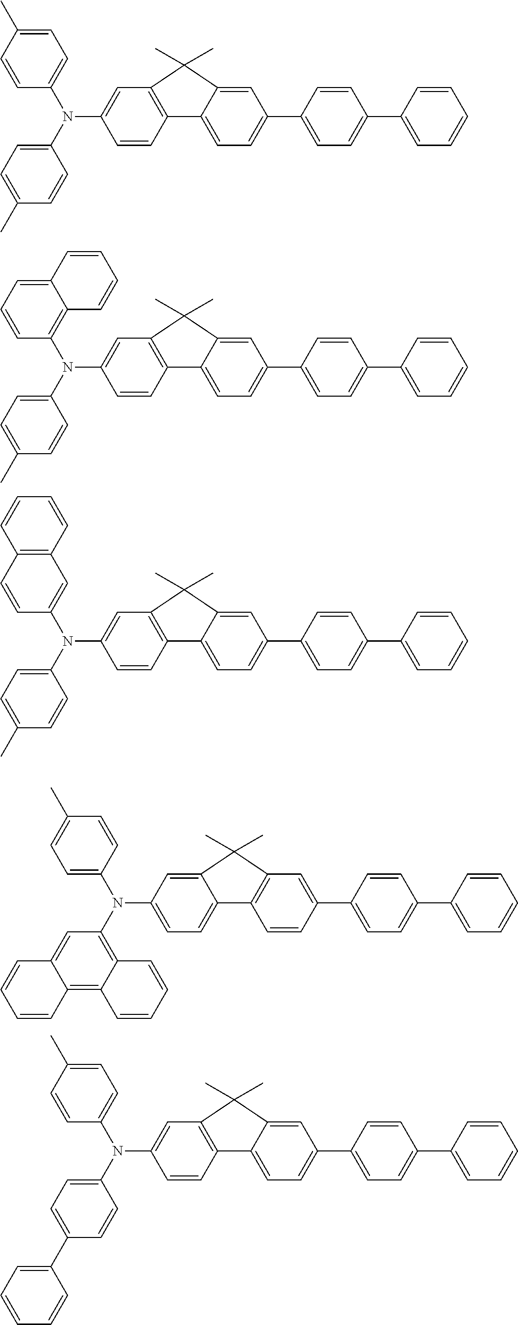

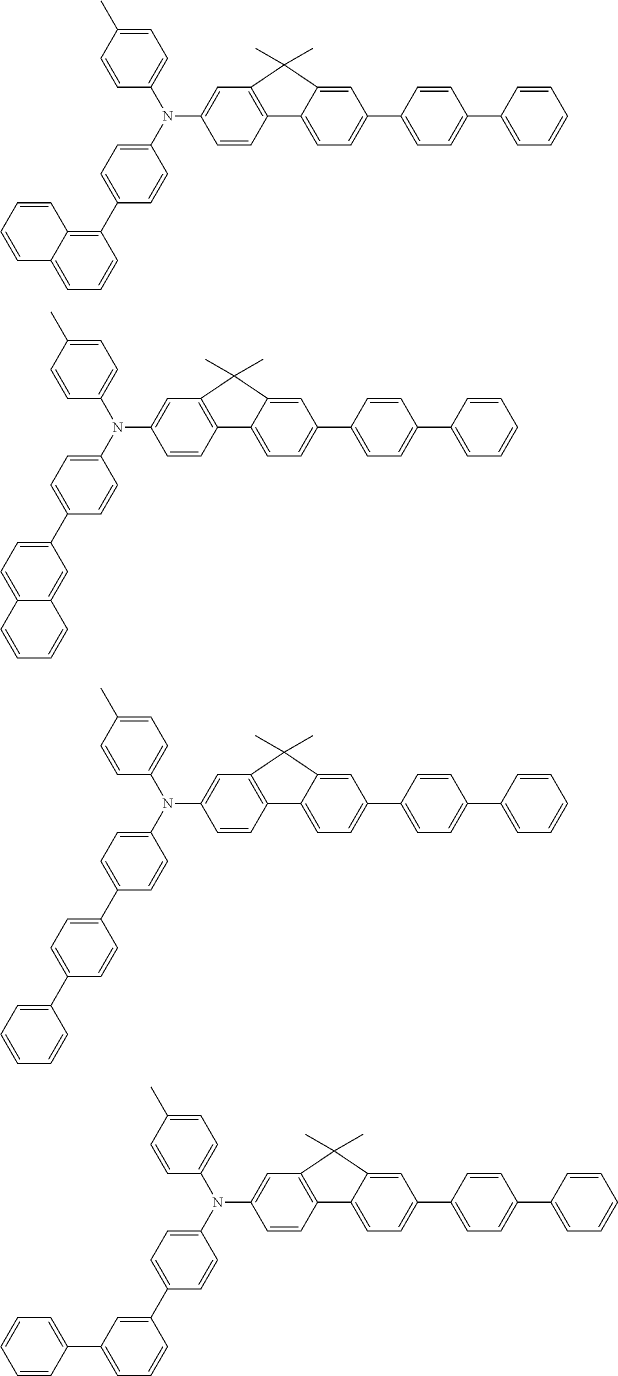

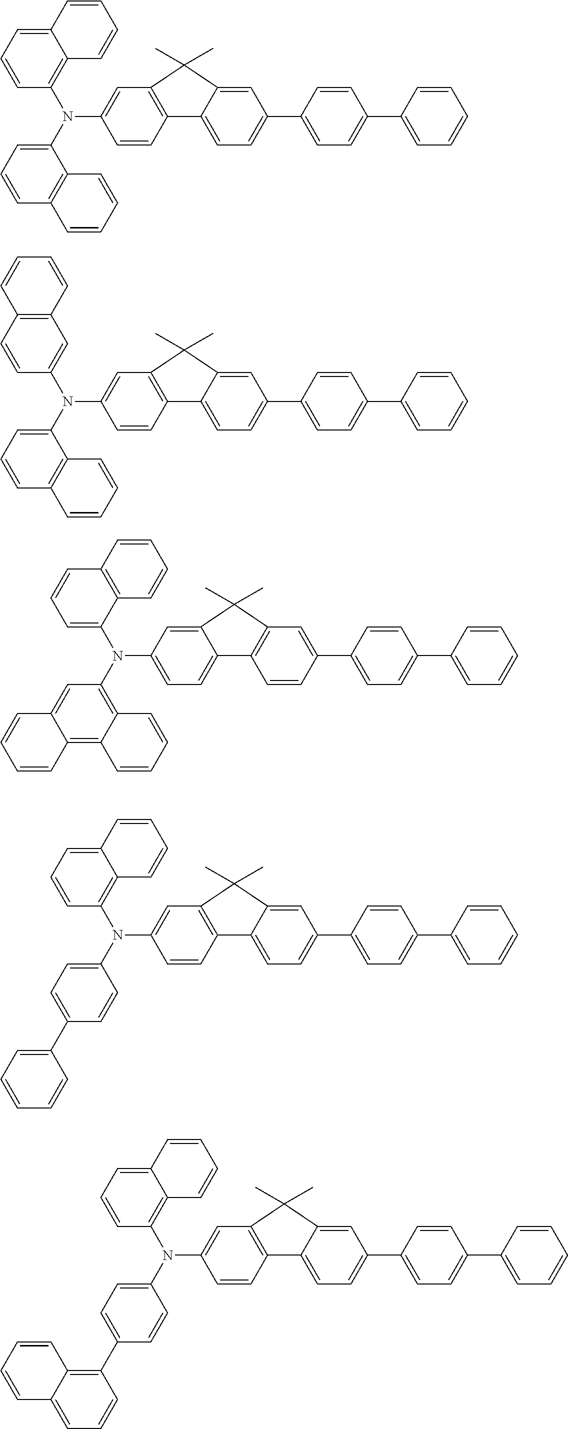

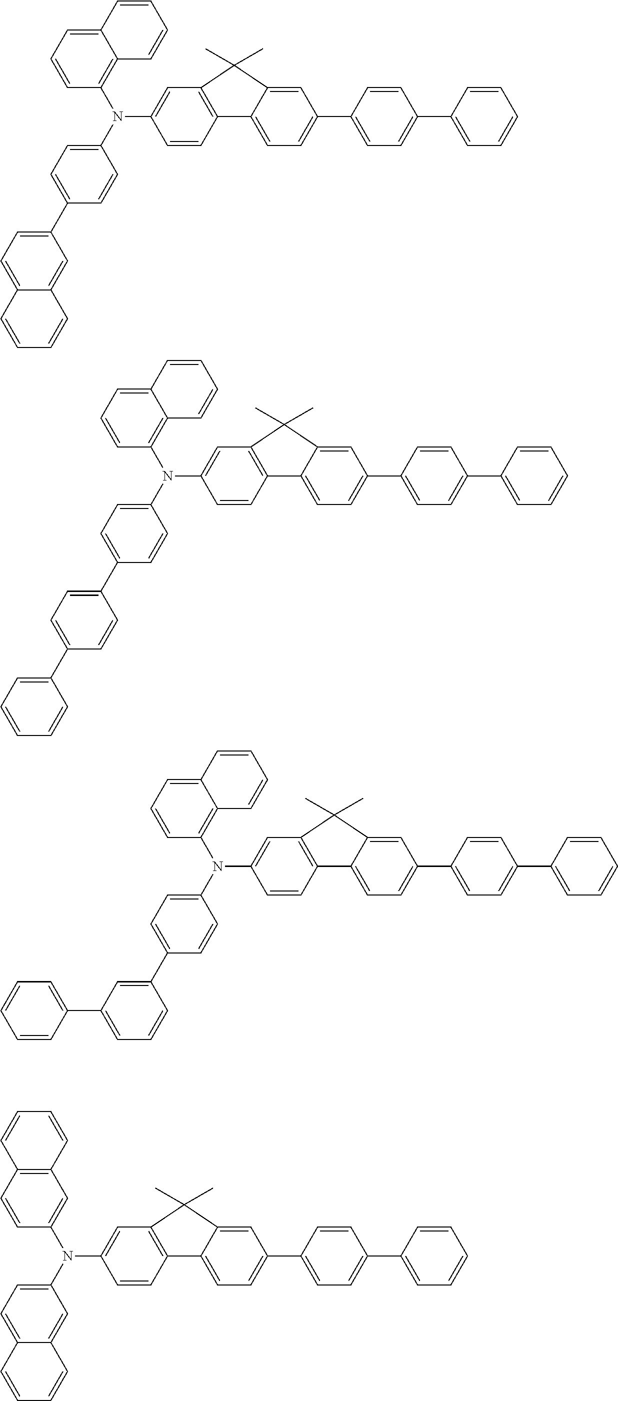 [SMILES: CC1(C)c2cc(-c3ccc(-c4ccccc4)cc3)ccc2-c2ccc(N(c3ccc(-c4ccc5ccccc5c4)cc3)c3cccc4ccccc34)cc21 ; CC1(C)c2cc(-c3ccc(-c4ccccc4)cc3)ccc2-c2ccc(N(c3ccc(-c4ccc(-c5ccccc5)cc4)cc3)c3cccc4ccccc34)cc21 ; CC1(C)c2cc(-c3ccc(-c4ccccc4)cc3)ccc2-c2ccc(N(c3ccc(-c4cccc(-c5ccccc5)c4)cc3)c3cccc4ccccc34)cc21 ; CC1(C)c2cc(-c3ccc(-c4ccccc4)cc3)ccc2-c2ccc(N(c3ccc4ccccc4c3)c3ccc4ccccc4c3)cc21]

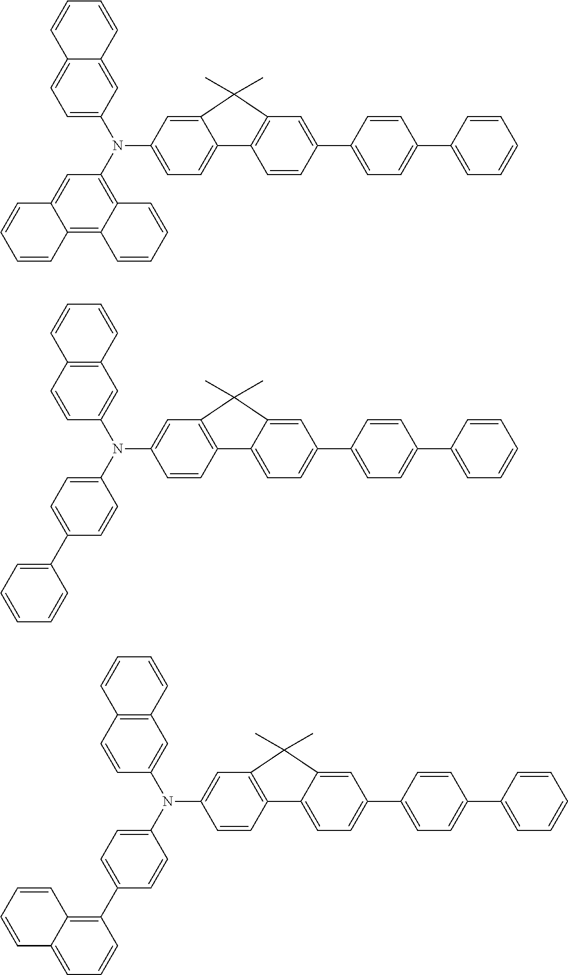

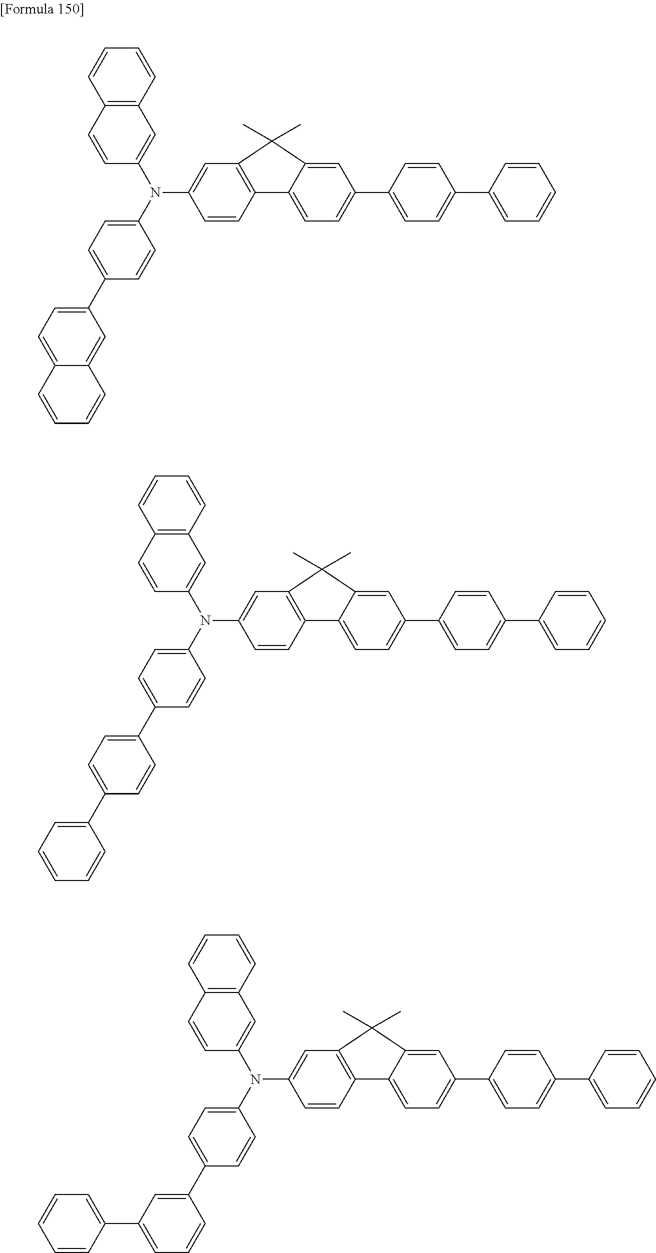 [SMILES: CC1(C)c2cc(-c3ccc(-c4ccccc4)cc3)ccc2-c2ccc(N(c3ccc(-c4ccc5ccccc5c4)cc3)c3ccc4ccccc4c3)cc21 ; CC1(C)c2cc(-c3ccc(-c4ccccc4)cc3)ccc2-c2ccc(N(c3ccc(-c4ccc(-c5ccccc5)cc4)cc3)c3ccc4ccccc4c3)cc21 ; CC1(C)c2cc(-c3ccc(-c4ccccc4)cc3)ccc2-c2ccc(N(c3ccc(-c4cccc(-c5ccccc5)c4)cc3)c3ccc4ccccc4c3)cc21]

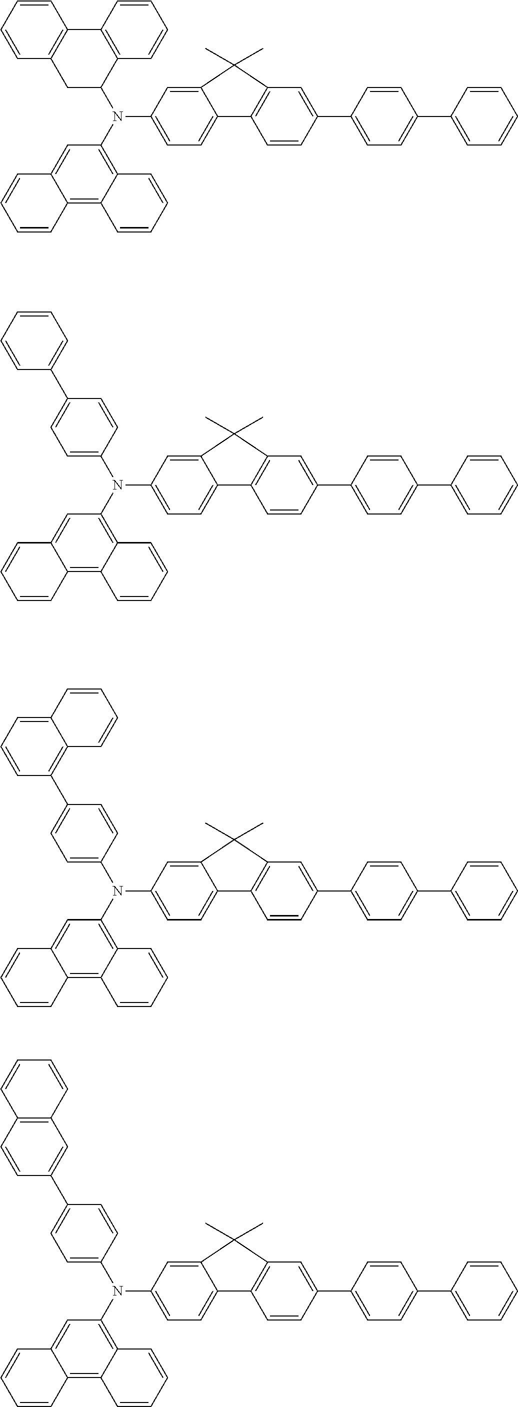 [SMILES: CC1(C)c2cc(-c3ccc(-c4ccccc4)cc3)ccc2-c2ccc(N(c3cc4ccccc4c4ccccc34)C3Cc4ccccc4-c4ccccc43)cc21 ; CC1(C)c2cc(-c3ccc(-c4ccccc4)cc3)ccc2-c2ccc(N(c3ccc(-c4ccccc4)cc3)c3cc4ccccc4c4ccccc34)cc21 ; CC1(C)c2cc(-c3ccc(-c4ccccc4)cc3)ccc2-c2ccc(N(c3ccc(-c4cccc5ccccc45)cc3)c3cc4ccccc4c4ccccc34)cc21 ; CC1(C)c2cc(-c3ccc(-c4ccccc4)cc3)ccc2-c2ccc(N(c3ccc(-c4ccc5ccccc5c4)cc3)c3cc4ccccc4c4ccccc34)cc21]

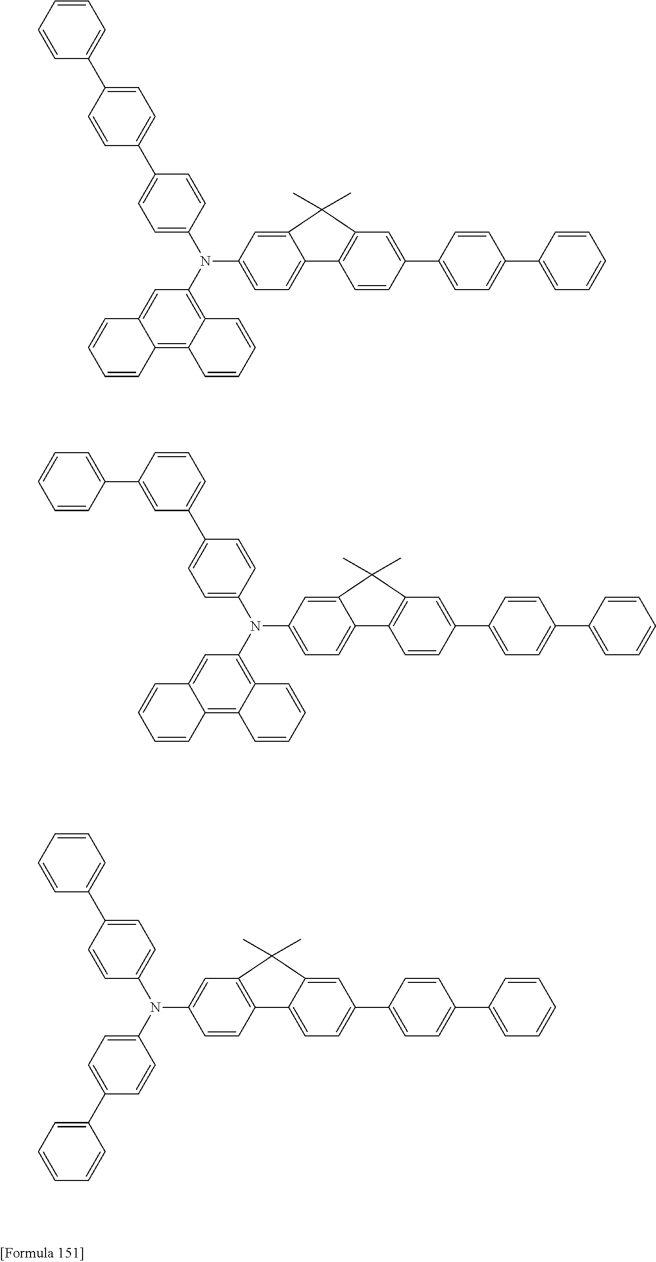 [SMILES: CC1(C)c2cc(-c3ccc(-c4ccccc4)cc3)ccc2-c2ccc(N(c3ccc(-c4ccc(-c5ccccc5)cc4)cc3)c3cc4ccccc4c4ccccc34)cc21 ; CC1(C)c2cc(-c3ccc(-c4ccccc4)cc3)ccc2-c2ccc(N(c3ccc(-c4cccc(-c5ccccc5)c4)cc3)c3cc4ccccc4c4ccccc34)cc21 ; CC1(C)c2cc(-c3ccc(-c4ccccc4)cc3)ccc2-c2ccc(N(c3ccc(-c4ccccc4)cc3)c3ccc(-c4ccccc4)cc3)cc21]

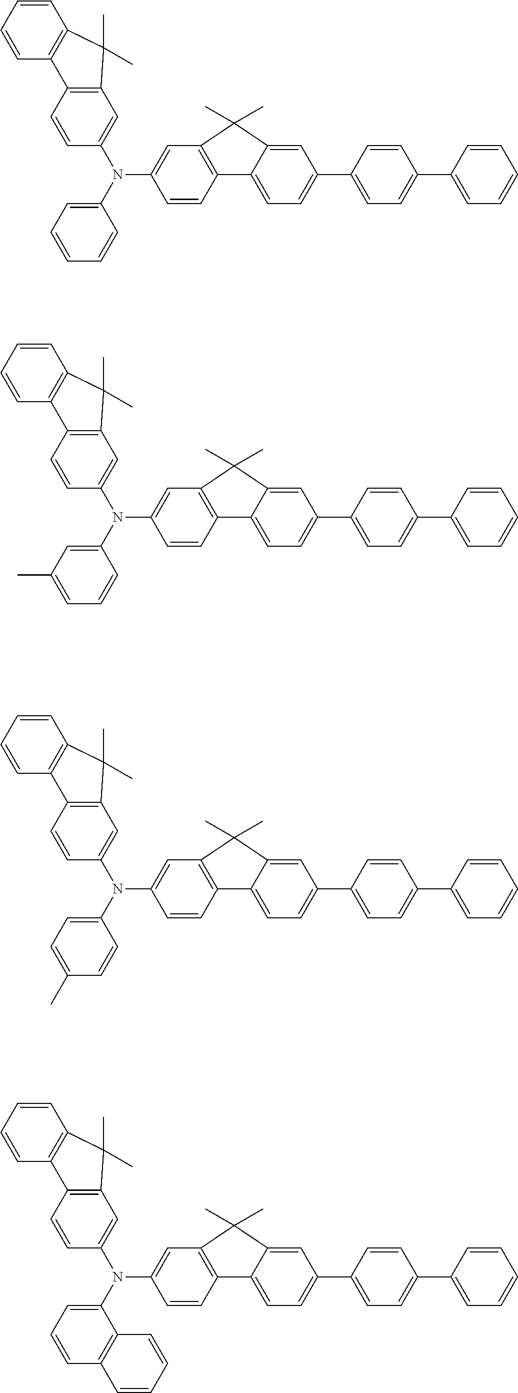 [SMILES: CC1(C)c2ccccc2-c2ccc(N(c3ccccc3)c3ccc4c(c3)C(C)(C)c3cc(-c5ccc(-c6ccccc6)cc5)ccc3-4)cc21 ; Cc1cccc(N(c2ccc3c(c2)C(C)(C)c2ccccc2-3)c2ccc3c(c2)C(C)(C)c2cc(-c4ccc(-c5ccccc5)cc4)ccc2-3)c1 ; Cc1ccc(N(c2ccc3c(c2)C(C)(C)c2ccccc2-3)c2ccc3c(c2)C(C)(C)c2cc(-c4ccc(-c5ccccc5)cc4)ccc2-3)cc1 ; CC1(C)c2ccccc2-c2ccc(N(c3ccc4c(c3)C(C)(C)c3cc(-c5ccc(-c6ccccc6)cc5)ccc3-4)c3cccc4ccccc34)cc21]

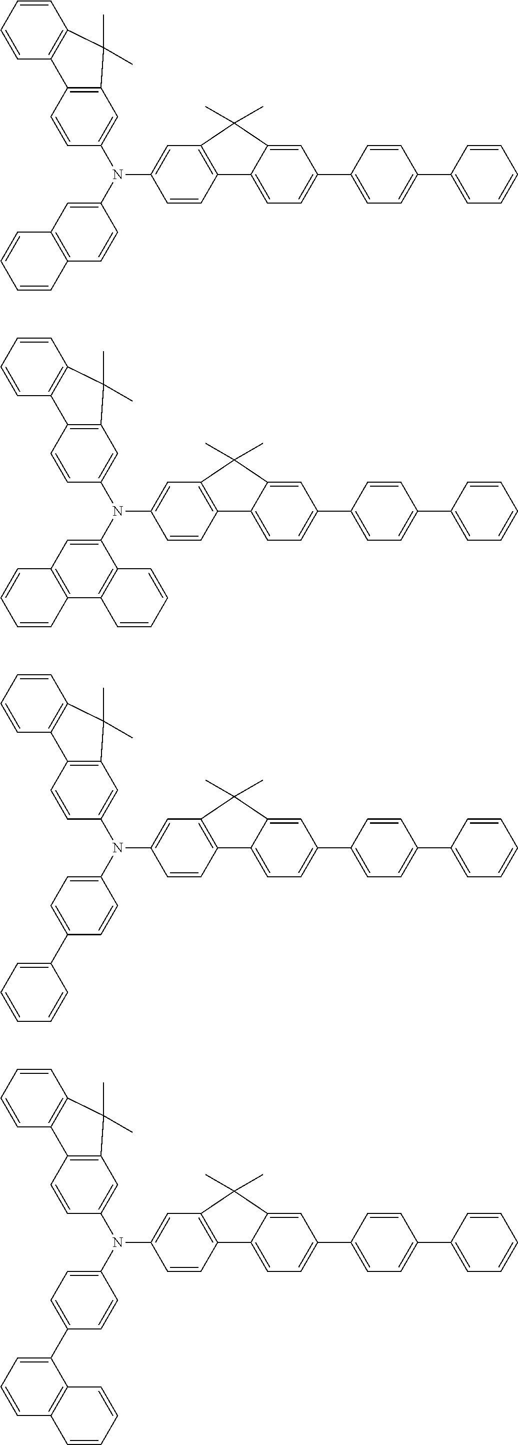 [SMILES: CC1(C)c2ccccc2-c2ccc(N(c3ccc4c(c3)C(C)(C)c3cc(-c5ccc(-c6ccccc6)cc5)ccc3-4)c3ccc4ccccc4c3)cc21 ; CC1(C)c2ccccc2-c2ccc(N(c3ccc4c(c3)C(C)(C)c3cc(-c5ccc(-c6ccccc6)cc5)ccc3-4)c3cc4ccccc4c4ccccc34)cc21 ; CC1(C)c2ccccc2-c2ccc(N(c3ccc(-c4ccccc4)cc3)c3ccc4c(c3)C(C)(C)c3cc(-c5ccc(-c6ccccc6)cc5)ccc3-4)cc21 ; CC1(C)c2ccccc2-c2ccc(N(c3ccc(-c4cccc5ccccc45)cc3)c3ccc4c(c3)C(C)(C)c3cc(-c5ccc(-c6ccccc6)cc5)ccc3-4)cc21]

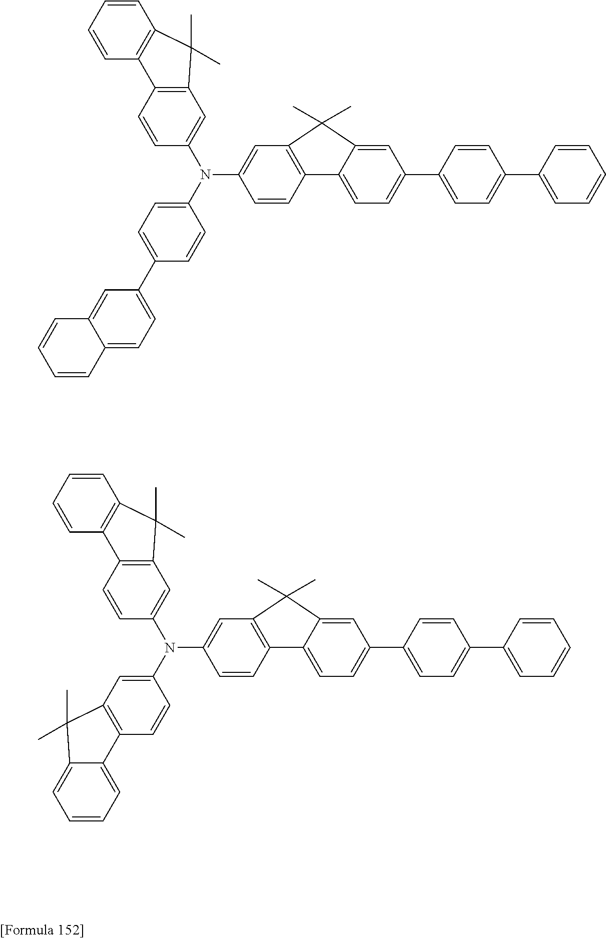 [SMILES: CC1(C)c2ccccc2-c2ccc(N(c3ccc(-c4ccc5ccccc5c4)cc3)c3ccc4c(c3)C(C)(C)c3cc(-c5ccc(-c6ccccc6)cc5)ccc3-4)cc21 ; CC1(C)c2ccccc2-c2ccc(N(c3ccc4c(c3)C(C)(C)c3ccccc3-4)c3ccc4c(c3)C(C)(C)c3cc(-c5ccc(-c6ccccc6)cc5)ccc3-4)cc21]

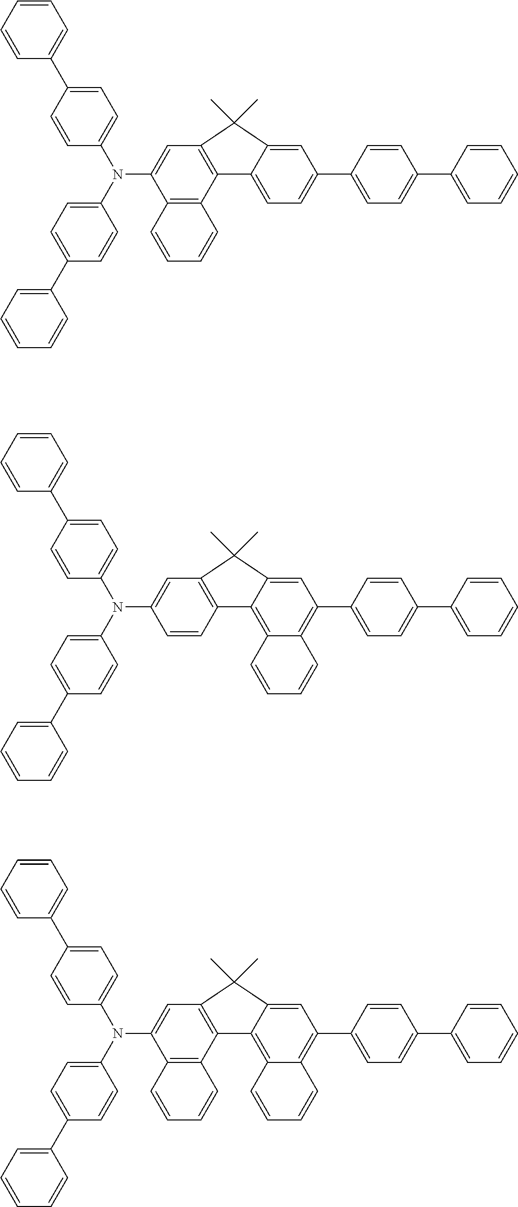 [SMILES: CC1(C)c2cc(-c3ccc(-c4ccccc4)cc3)ccc2-c2c1cc(N(c1ccc(-c3ccccc3)cc1)c1ccc(-c3ccccc3)cc1)c1ccccc21 ; CC1(C)c2cc(N(c3ccc(-c4ccccc4)cc3)c3ccc(-c4ccccc4)cc3)ccc2-c2c1cc(-c1ccc(-c3ccccc3)cc1)c1ccccc21 ; CC1(C)c2cc(-c3ccc(-c4ccccc4)cc3)c3ccccc3c2-c2c1cc(N(c1ccc(-c3ccccc3)cc1)c1ccc(-c3ccccc3)cc1)c1ccccc21]

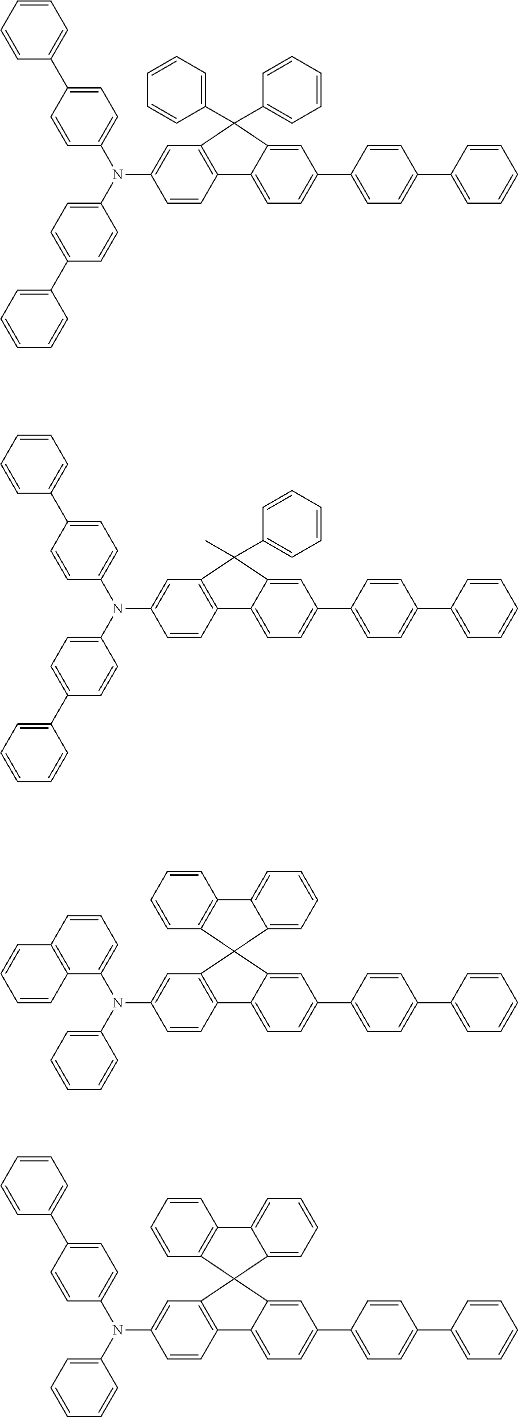 [SMILES: c1ccc(-c2ccc(-c3ccc4c(c3)C(c3ccccc3)(c3ccccc3)c3cc(N(c5ccc(-c6ccccc6)cc5)c5ccc(-c6ccccc6)cc5)ccc3-4)cc2)cc1 ; CC1(c2ccccc2)c2cc(-c3ccc(-c4ccccc4)cc3)ccc2-c2ccc(N(c3ccc(-c4ccccc4)cc3)c3ccc(-c4ccccc4)cc3)cc21 ; c1ccc(-c2ccc(-c3ccc4c(c3)C3(c5ccccc5-c5ccccc53)c3cc(N(c5ccccc5)c5cccc6ccccc56)ccc3-4)cc2)cc1 ; c1ccc(-c2ccc(-c3ccc4c(c3)C3(c5ccccc5-c5ccccc53)c3cc(N(c5ccccc5)c5ccc(-c6ccccc6)cc5)ccc3-4)cc2)cc1]

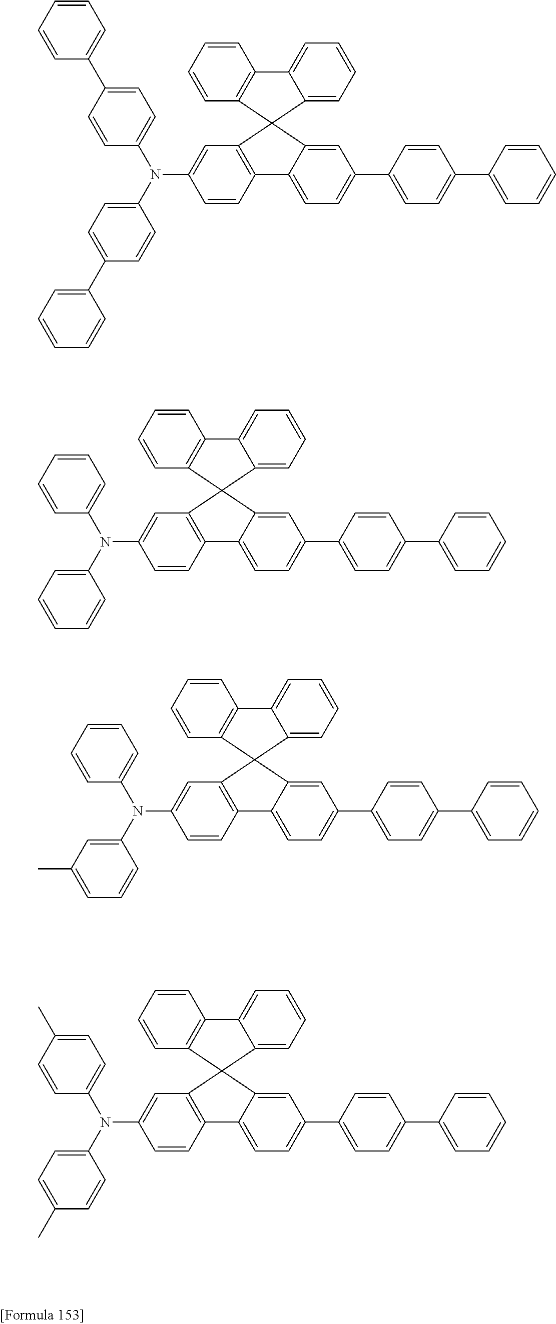 [SMILES: c1ccc(-c2ccc(-c3ccc4c(c3)C3(c5ccccc5-c5ccccc53)c3cc(N(c5ccc(-c6ccccc6)cc5)c5ccc(-c6ccccc6)cc5)ccc3-4)cc2)cc1 ; c1ccc(-c2ccc(-c3ccc4c(c3)C3(c5ccccc5-c5ccccc53)c3cc(N(c5ccccc5)c5ccccc5)ccc3-4)cc2)cc1 ; Cc1cccc(N(c2ccccc2)c2ccc3c(c2)C2(c4ccccc4-c4ccccc42)c2cc(-c4ccc(-c5ccccc5)cc4)ccc2-3)c1 ; Cc1ccc(N(c2ccc(C)cc2)c2ccc3c(c2)C2(c4ccccc4-c4ccccc42)c2cc(-c4ccc(-c5ccccc5)cc4)ccc2-3)cc1]

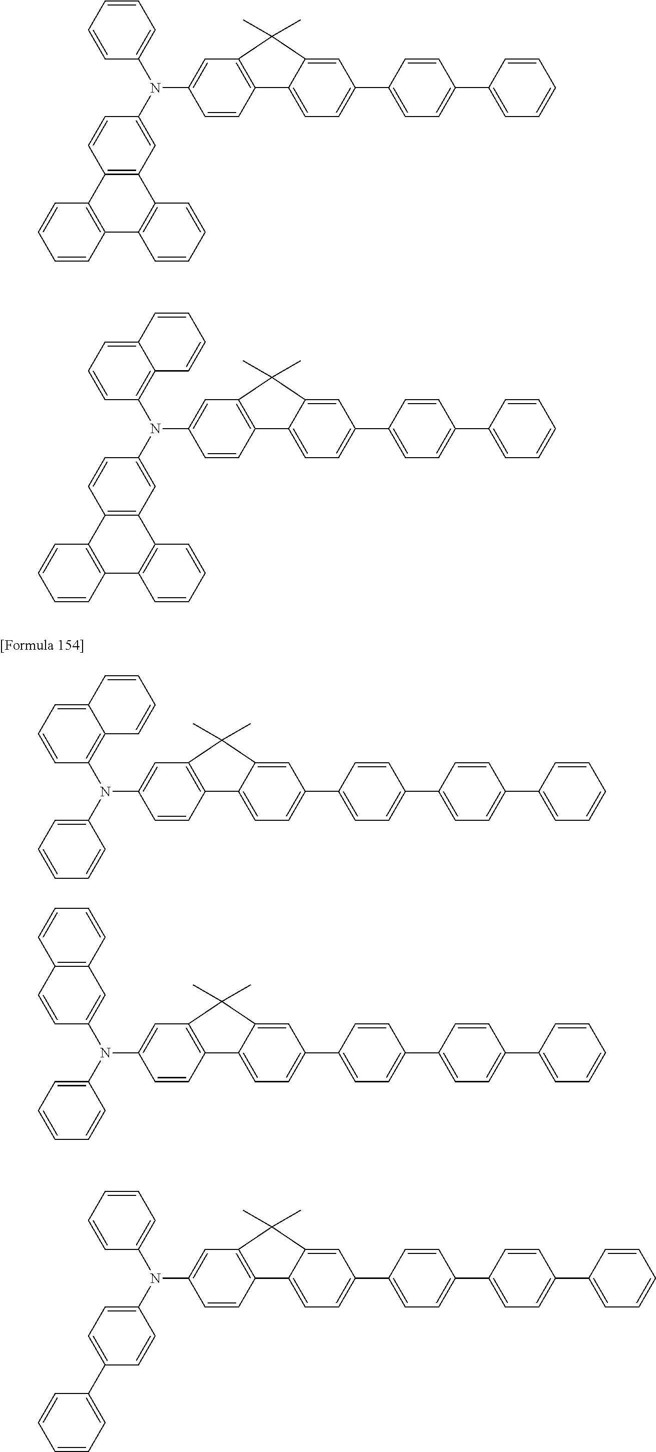

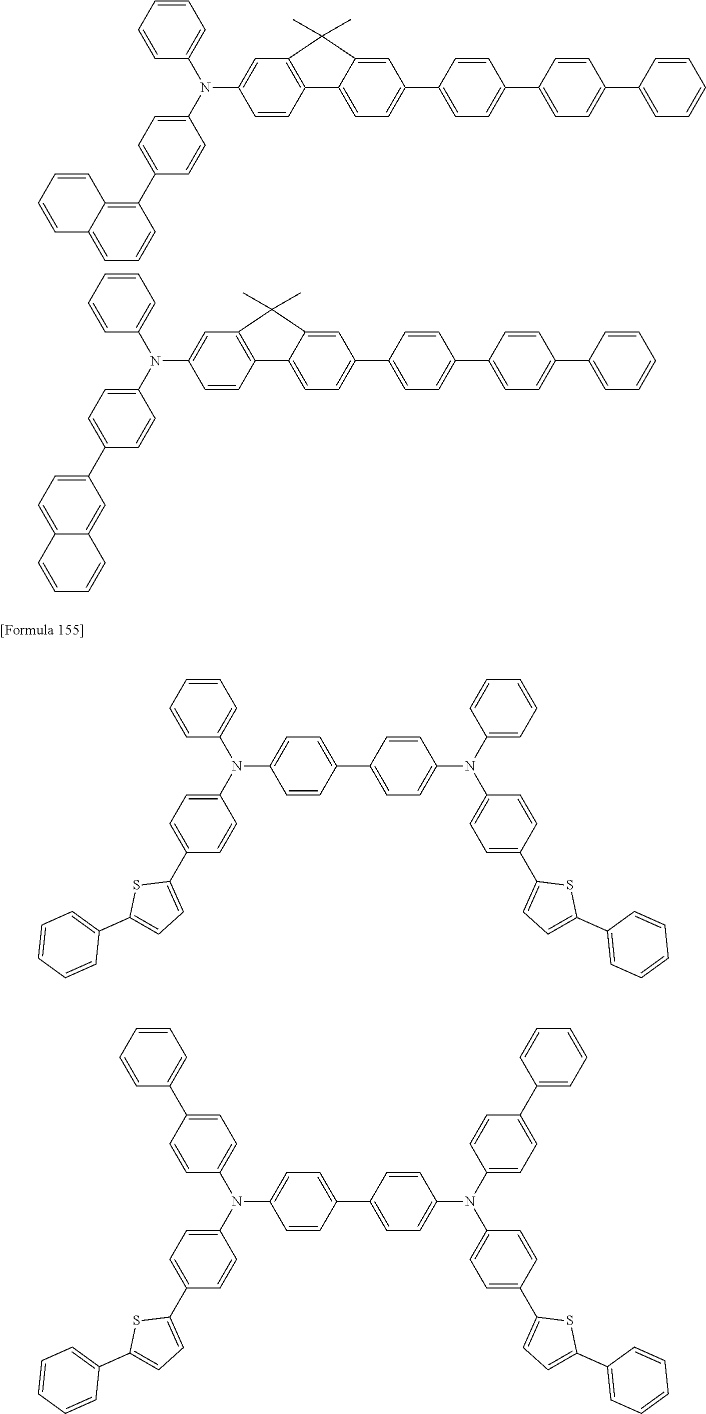

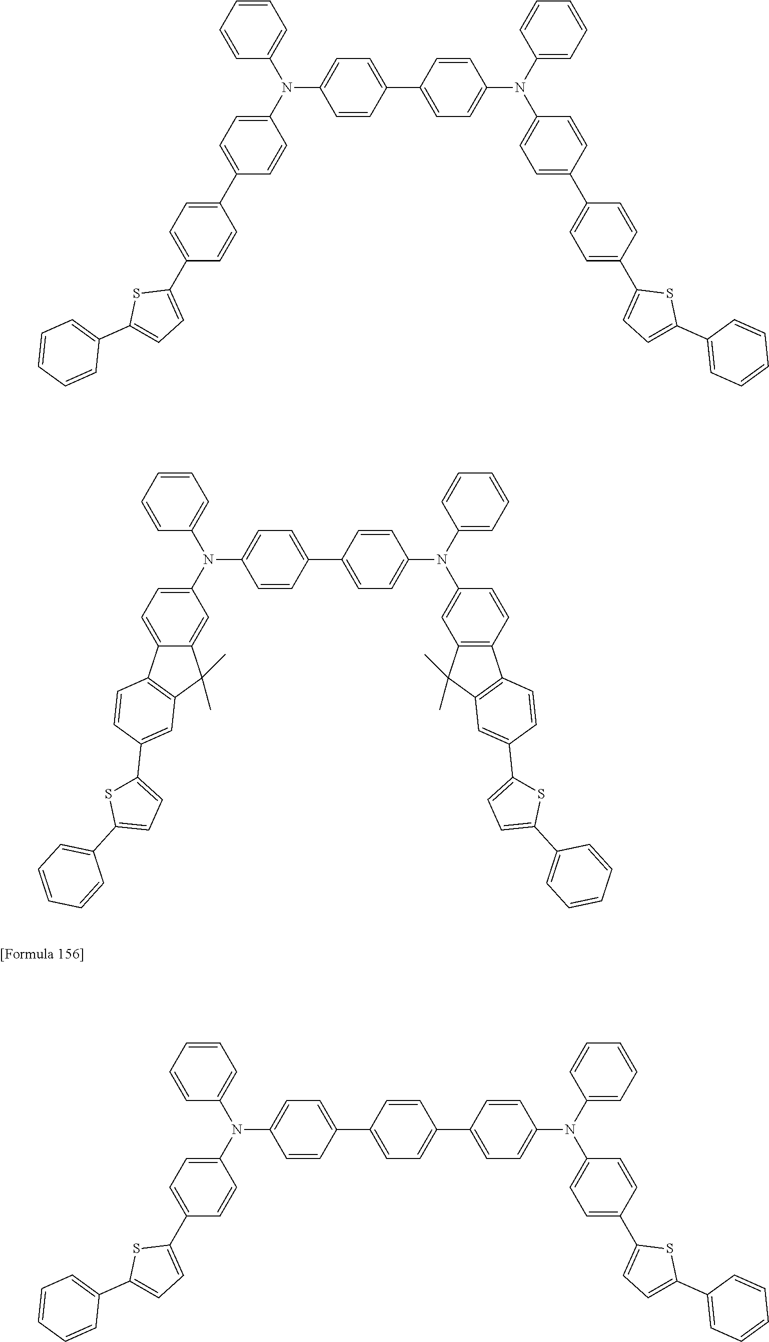 [SMILES: c1ccc(-c2ccc(-c3ccc(-c4ccc(N(c5ccccc5)c5ccc(-c6ccc(N(c7ccccc7)c7ccc(-c8ccc(-c9ccc(-c%10ccccc%10)s9)cc8)cc7)cc6)cc5)cc4)cc3)s2)cc1 ; CC1(C)c2cc(-c3ccc(-c4ccccc4)s3)ccc2-c2ccc(N(c3ccccc3)c3ccc(-c4ccc(N(c5ccccc5)c5ccc6c(c5)C(C)(C)c5cc(-c7ccc(-c8ccccc8)s7)ccc5-6)cc4)cc3)cc21 ; c1ccc(-c2ccc(-c3ccc(N(c4ccccc4)c4ccc(-c5ccc(-c6ccc(N(c7ccccc7)c7ccc(-c8ccc(-c9ccccc9)s8)cc7)cc6)cc5)cc4)cc3)s2)cc1]

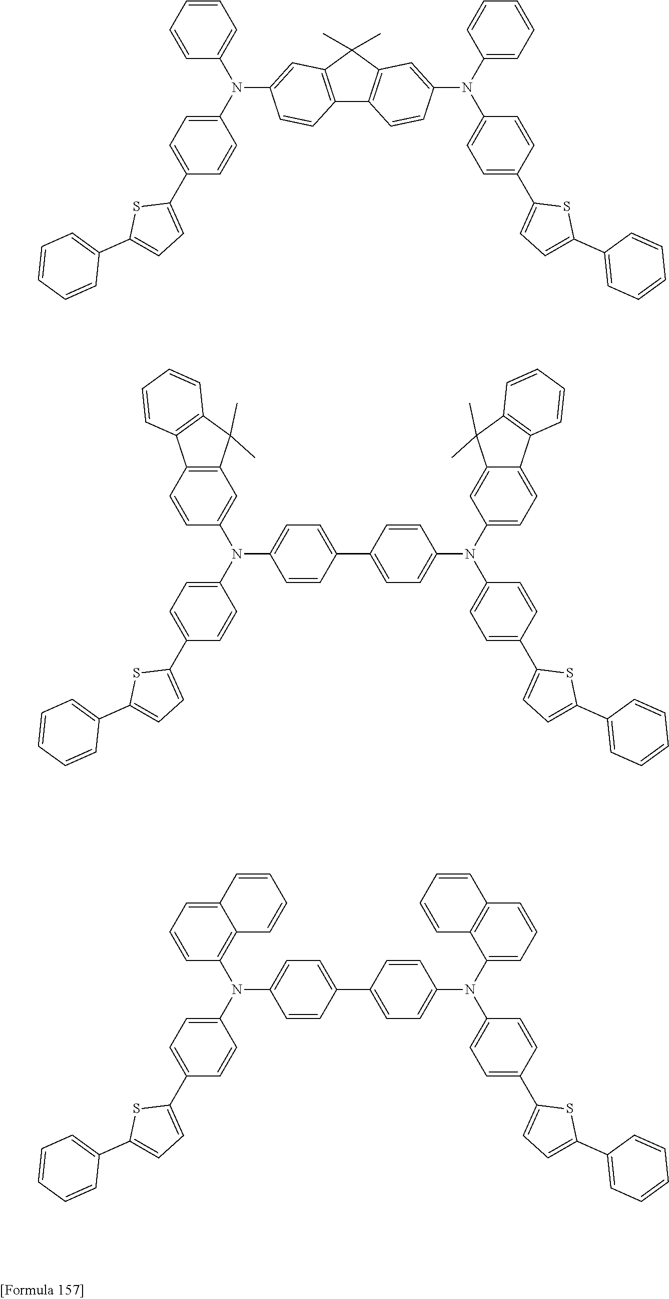 [SMILES: CC1(C)c2cc(N(c3ccccc3)c3ccc(-c4ccc(-c5ccccc5)s4)cc3)ccc2-c2ccc(N(c3ccccc3)c3ccc(-c4ccc(-c5ccccc5)s4)cc3)cc21 ; CC1(C)c2ccccc2-c2ccc(N(c3ccc(-c4ccc(N(c5ccc(-c6ccc(-c7ccccc7)s6)cc5)c5ccc6c(c5)C(C)(C)c5ccccc5-6)cc4)cc3)c3ccc(-c4ccc(-c5ccccc5)s4)cc3)cc21 ; c1ccc(-c2ccc(-c3ccc(N(c4ccc(-c5ccc(N(c6ccc(-c7ccc(-c8ccccc8)s7)cc6)c6cccc7ccccc67)cc5)cc4)c4cccc5ccccc45)cc3)s2)cc1]

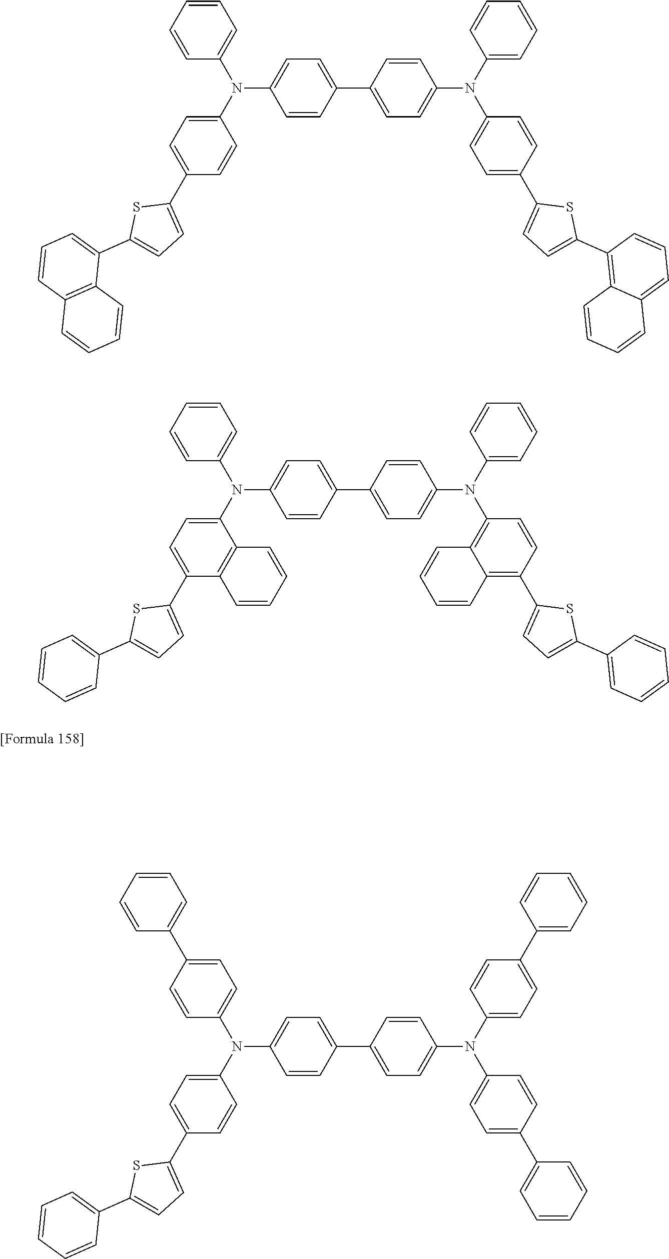 [SMILES: c1ccc(N(c2ccc(-c3ccc(N(c4ccccc4)c4ccc(-c5ccc(-c6cccc7ccccc67)s5)cc4)cc3)cc2)c2ccc(-c3ccc(-c4cccc5ccccc45)s3)cc2)cc1 ; c1ccc(-c2ccc(-c3ccc(N(c4ccccc4)c4ccc(-c5ccc(N(c6ccccc6)c6ccc(-c7ccc(-c8ccccc8)s7)c7ccccc67)cc5)cc4)c4ccccc34)s2)cc1 ; c1ccc(-c2ccc(N(c3ccc(-c4ccccc4)cc3)c3ccc(-c4ccc(N(c5ccc(-c6ccccc6)cc5)c5ccc(-c6ccc(-c7ccccc7)s6)cc5)cc4)cc3)cc2)cc1]

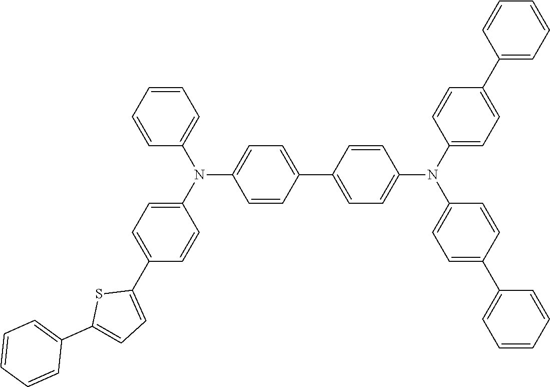 [SMILES: c1ccc(-c2ccc(N(c3ccc(-c4ccccc4)cc3)c3ccc(-c4ccc(N(c5ccccc5)c5ccc(-c6ccc(-c7ccccc7)s6)cc5)cc4)cc3)cc2)cc1]

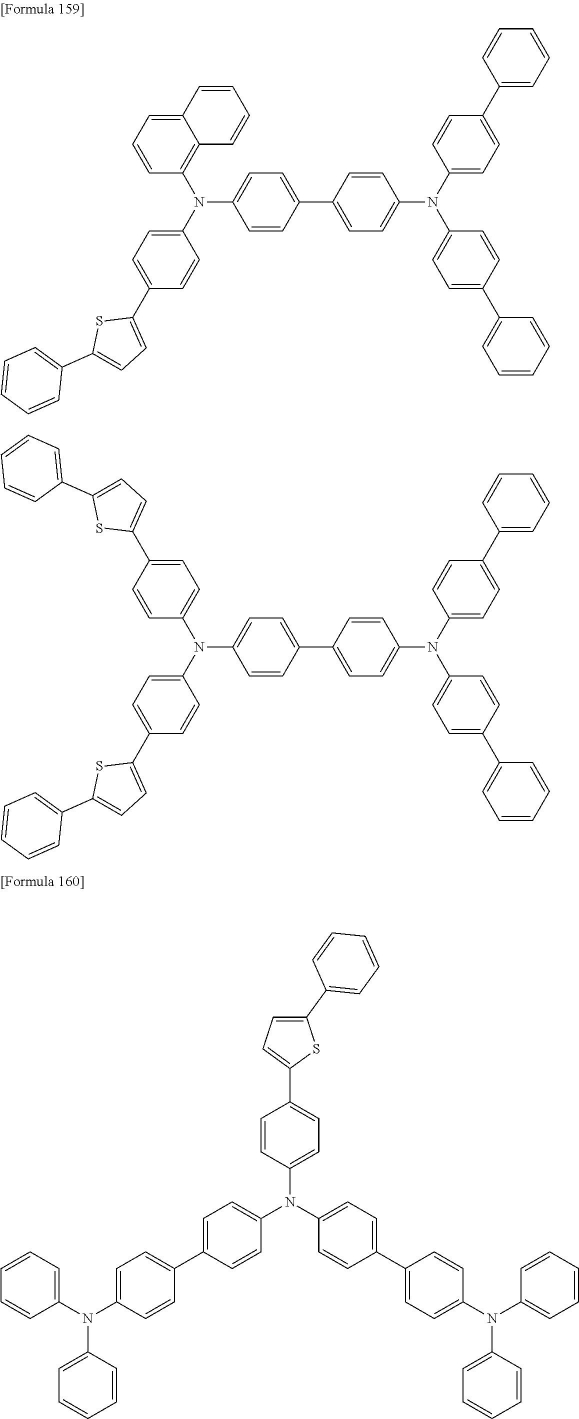

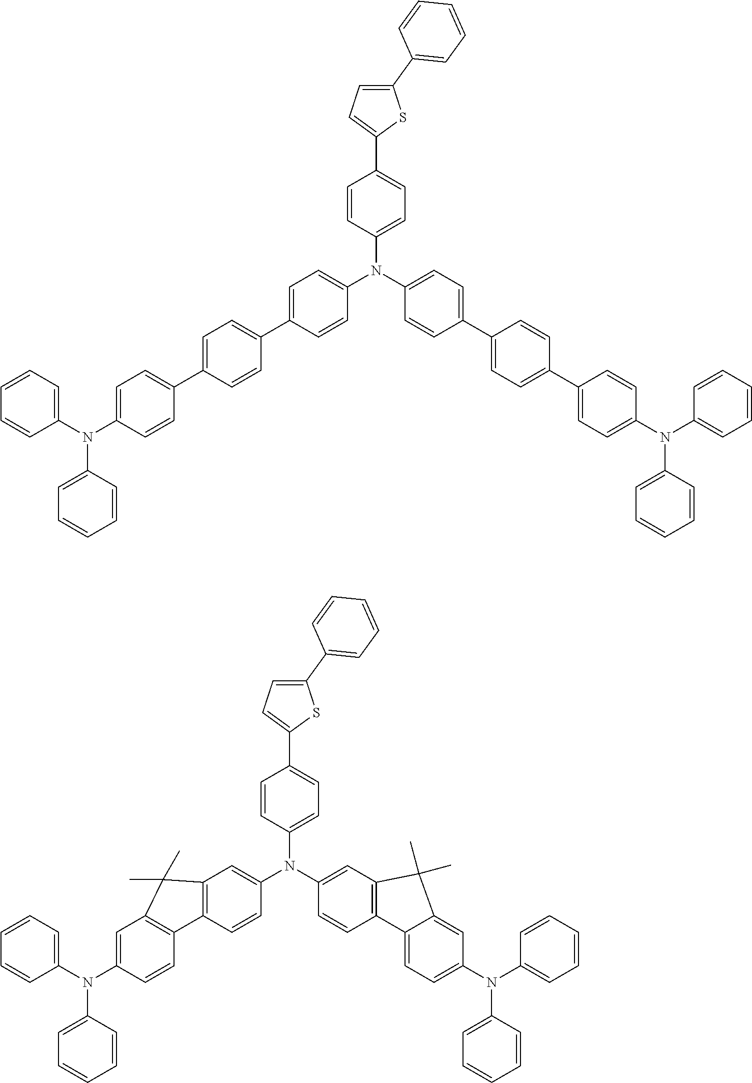 [SMILES: c1ccc(-c2ccc(-c3ccc(N(c4ccc(-c5ccc(-c6ccc(N(c7ccccc7)c7ccccc7)cc6)cc5)cc4)c4ccc(-c5ccc(-c6ccc(N(c7ccccc7)c7ccccc7)cc6)cc5)cc4)cc3)s2)cc1 ; CC1(C)c2cc(N(c3ccccc3)c3ccccc3)ccc2-c2ccc(N(c3ccc(-c4ccc(-c5ccccc5)s4)cc3)c3ccc4c(c3)C(C)(C)c3cc(N(c5ccccc5)c5ccccc5)ccc3-4)cc21]

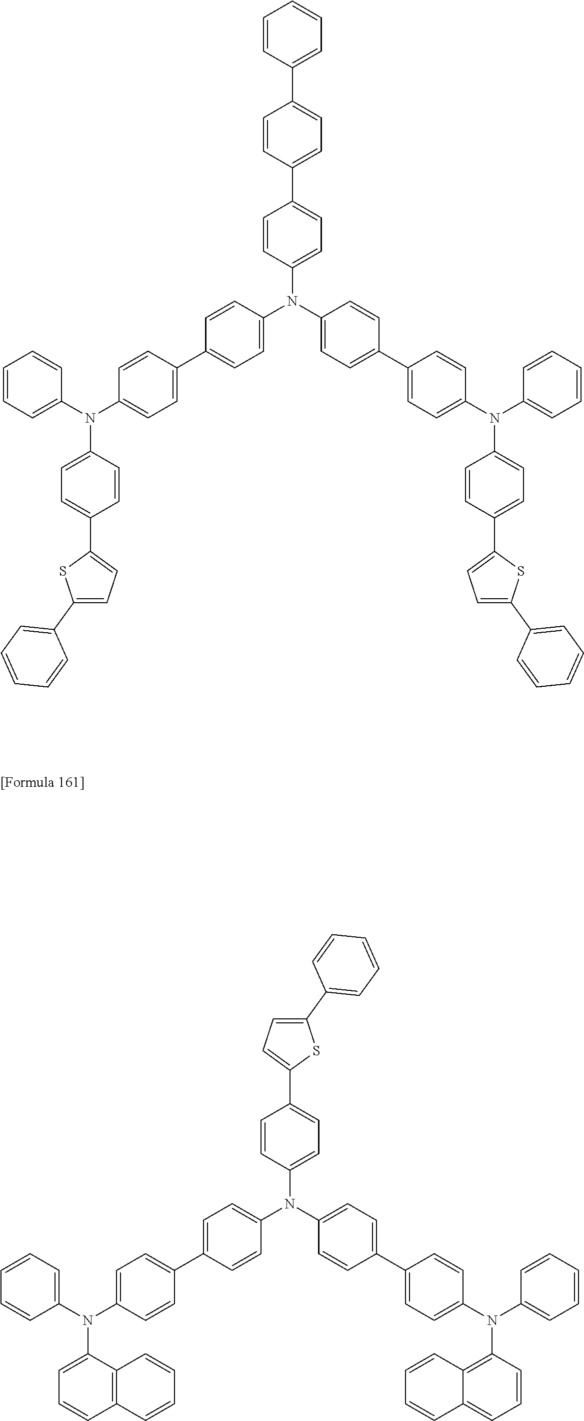 [SMILES: c1ccc(-c2ccc(-c3ccc(N(c4ccc(-c5ccc(N(c6ccccc6)c6ccc(-c7ccc(-c8ccccc8)s7)cc6)cc5)cc4)c4ccc(-c5ccc(N(c6ccccc6)c6ccc(-c7ccc(-c8ccccc8)s7)cc6)cc5)cc4)cc3)cc2)cc1 ; c1ccc(-c2ccc(-c3ccc(N(c4ccc(-c5ccc(N(c6ccccc6)c6cccc7ccccc67)cc5)cc4)c4ccc(-c5ccc(N(c6ccccc6)c6cccc7ccccc67)cc5)cc4)cc3)s2)cc1]

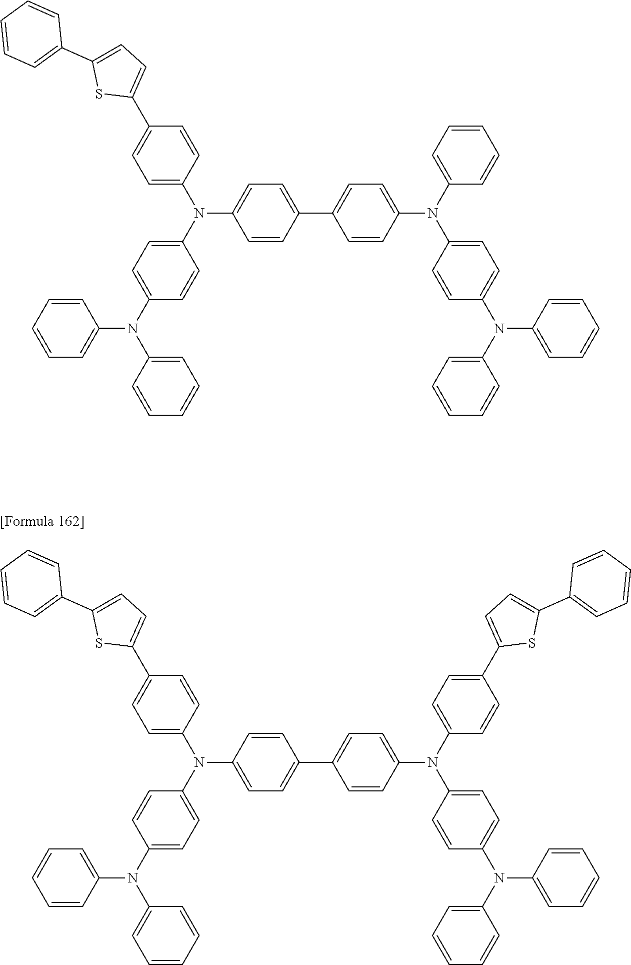 [SMILES: c1ccc(-c2ccc(-c3ccc(N(c4ccc(-c5ccc(N(c6ccccc6)c6ccc(N(c7ccccc7)c7ccccc7)cc6)cc5)cc4)c4ccc(N(c5ccccc5)c5ccccc5)cc4)cc3)s2)cc1 ; c1ccc(-c2ccc(-c3ccc(N(c4ccc(-c5ccc(N(c6ccc(-c7ccc(-c8ccccc8)s7)cc6)c6ccc(N(c7ccccc7)c7ccccc7)cc6)cc5)cc4)c4ccc(N(c5ccccc5)c5ccccc5)cc4)cc3)s2)cc1]

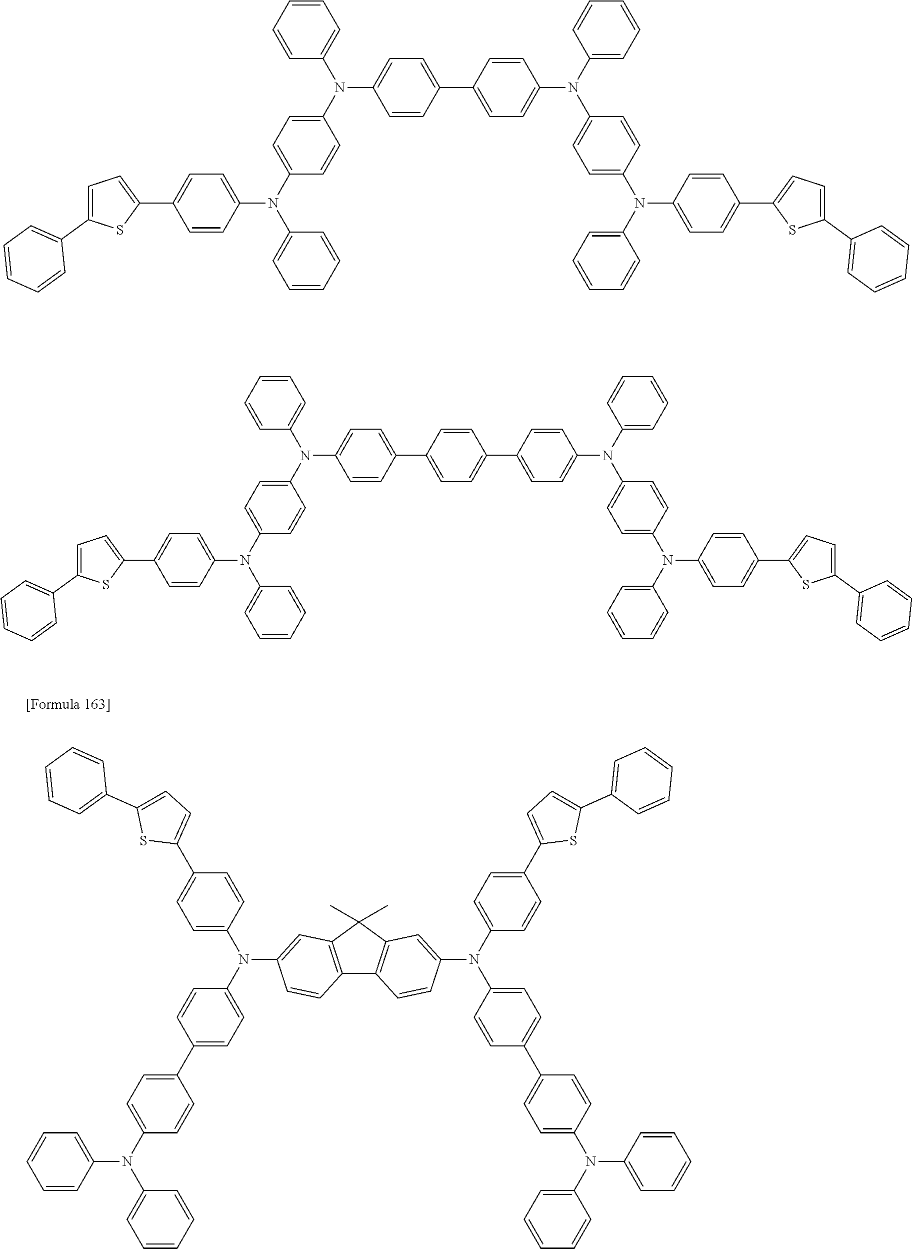 [SMILES: c1ccc(-c2ccc(-c3ccc(N(c4ccccc4)c4ccc(N(c5ccccc5)c5ccc(-c6ccc(N(c7ccccc7)c7ccc(N(c8ccccc8)c8ccc(-c9ccc(-c%10ccccc%10)s9)cc8)cc7)cc6)cc5)cc4)cc3)s2)cc1 ; c1ccc(-c2ccc(-c3ccc(N(c4ccccc4)c4ccc(N(c5ccccc5)c5ccc(-c6ccc(-c7ccc(N(c8ccccc8)c8ccc(N(c9ccccc9)c9ccc(-c%10ccc(-c%11ccccc%11)s%10)cc9)cc8)cc7)cc6)cc5)cc4)cc3)s2)cc1 ; CC1(C)c2cc(N(c3ccc(-c4ccc(N(c5ccccc5)c5ccccc5)cc4)cc3)c3ccc(-c4ccc(-c5ccccc5)s4)cc3)ccc2-c2ccc(N(c3ccc(-c4ccc(N(c5ccccc5)c5ccccc5)cc4)cc3)c3ccc(-c4ccc(-c5ccccc5)s4)cc3)cc21]

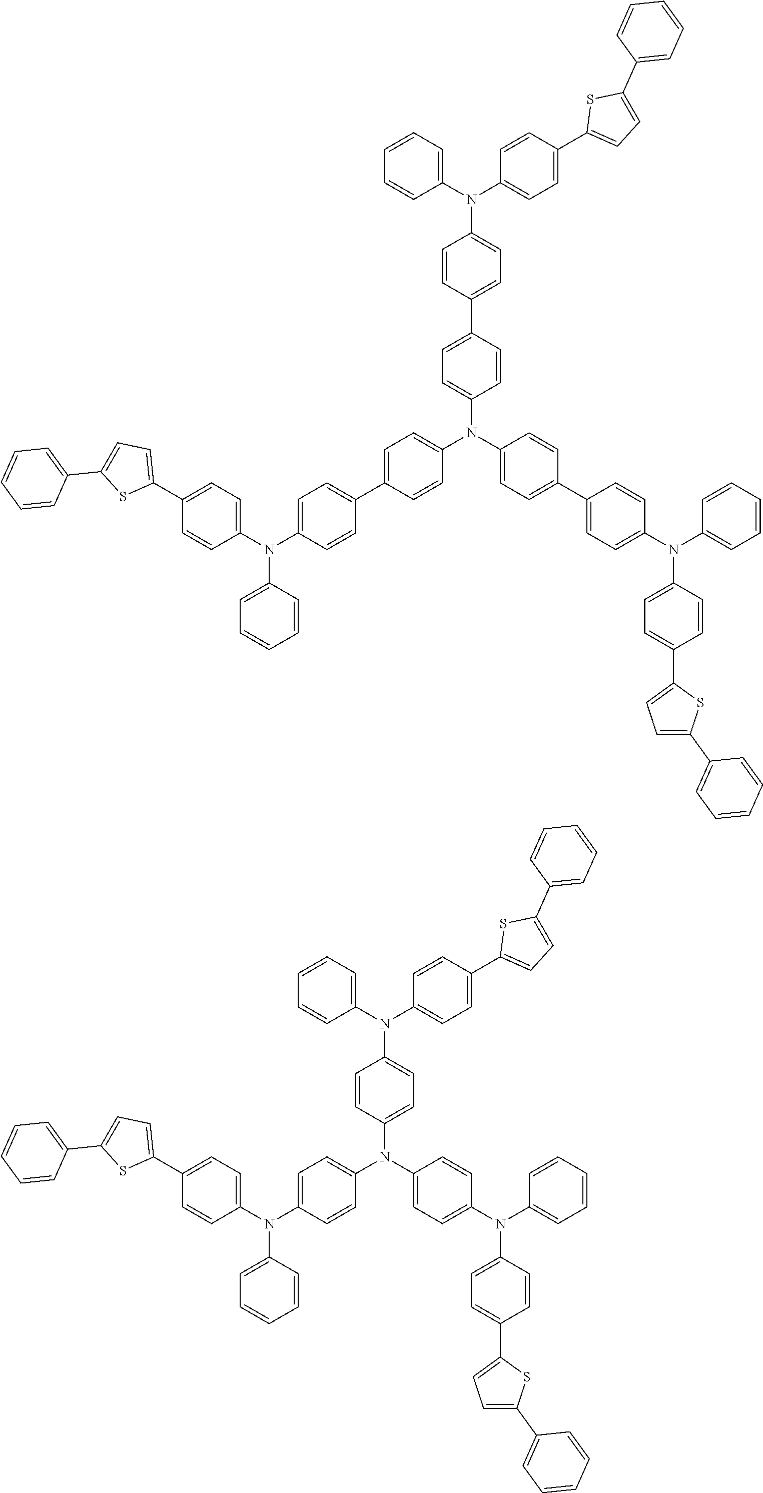 [SMILES: c1ccc(-c2ccc(-c3ccc(N(c4ccccc4)c4ccc(-c5ccc(N(c6ccc(-c7ccc(N(c8ccccc8)c8ccc(-c9ccc(-c%10ccccc%10)s9)cc8)cc7)cc6)c6ccc(-c7ccc(N(c8ccccc8)c8ccc(-c9ccc(-c%10ccccc%10)s9)cc8)cc7)cc6)cc5)cc4)cc3)s2)cc1 ; c1ccc(-c2ccc(-c3ccc(N(c4ccccc4)c4ccc(N(c5ccc(N(c6ccccc6)c6ccc(-c7ccc(-c8ccccc8)s7)cc6)cc5)c5ccc(N(c6ccccc6)c6ccc(-c7ccc(-c8ccccc8)s7)cc6)cc5)cc4)cc3)s2)cc1]

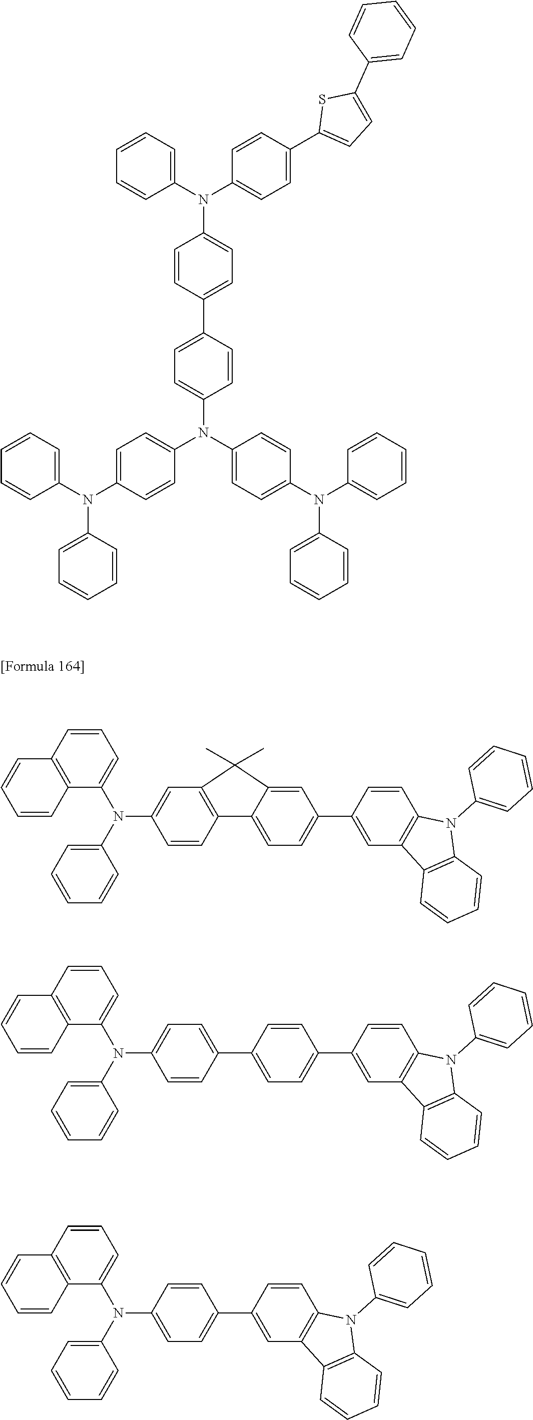 [SMILES: c1ccc(-c2ccc(-c3ccc(N(c4ccccc4)c4ccc(-c5ccc(N(c6ccc(N(c7ccccc7)c7ccccc7)cc6)c6ccc(N(c7ccccc7)c7ccccc7)cc6)cc5)cc4)cc3)s2)cc1 ; CC1(C)c2cc(-c3ccc4c(c3)c3ccccc3n4-c3ccccc3)ccc2-c2ccc(N(c3ccccc3)c3cccc4ccccc34)cc21 ; c1ccc(N(c2ccc(-c3ccc(-c4ccc5c(c4)c4ccccc4n5-c4ccccc4)cc3)cc2)c2cccc3ccccc23)cc1 ; c1ccc(N(c2ccc(-c3ccc4c(c3)c3ccccc3n4-c3ccccc3)cc2)c2cccc3ccccc23)cc1]

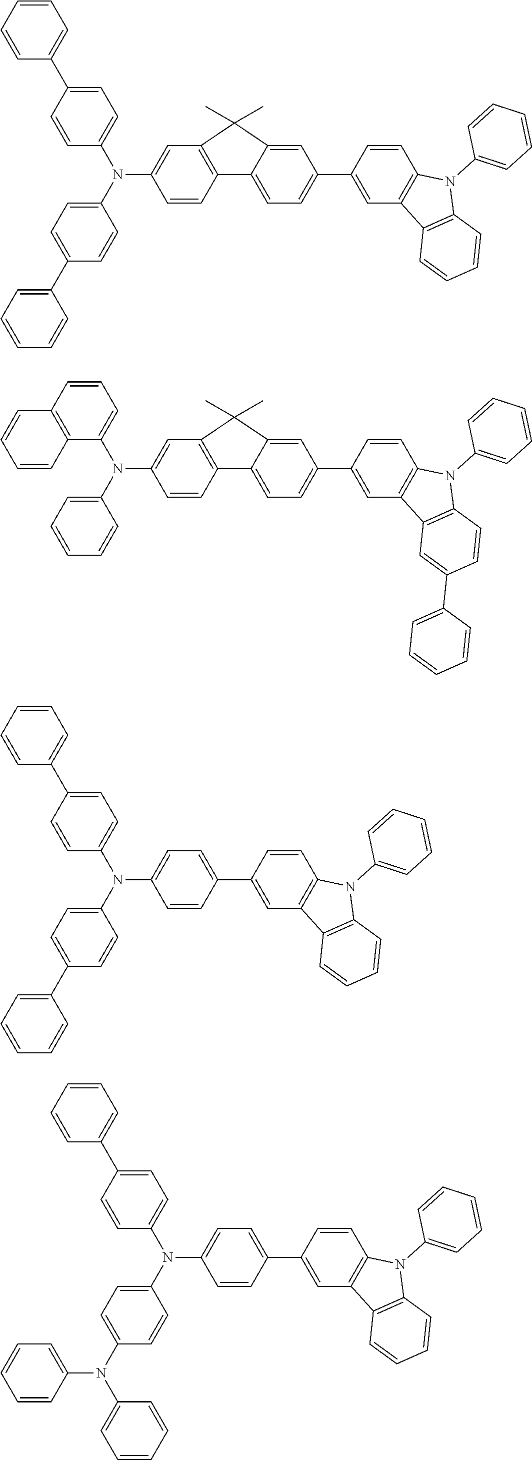

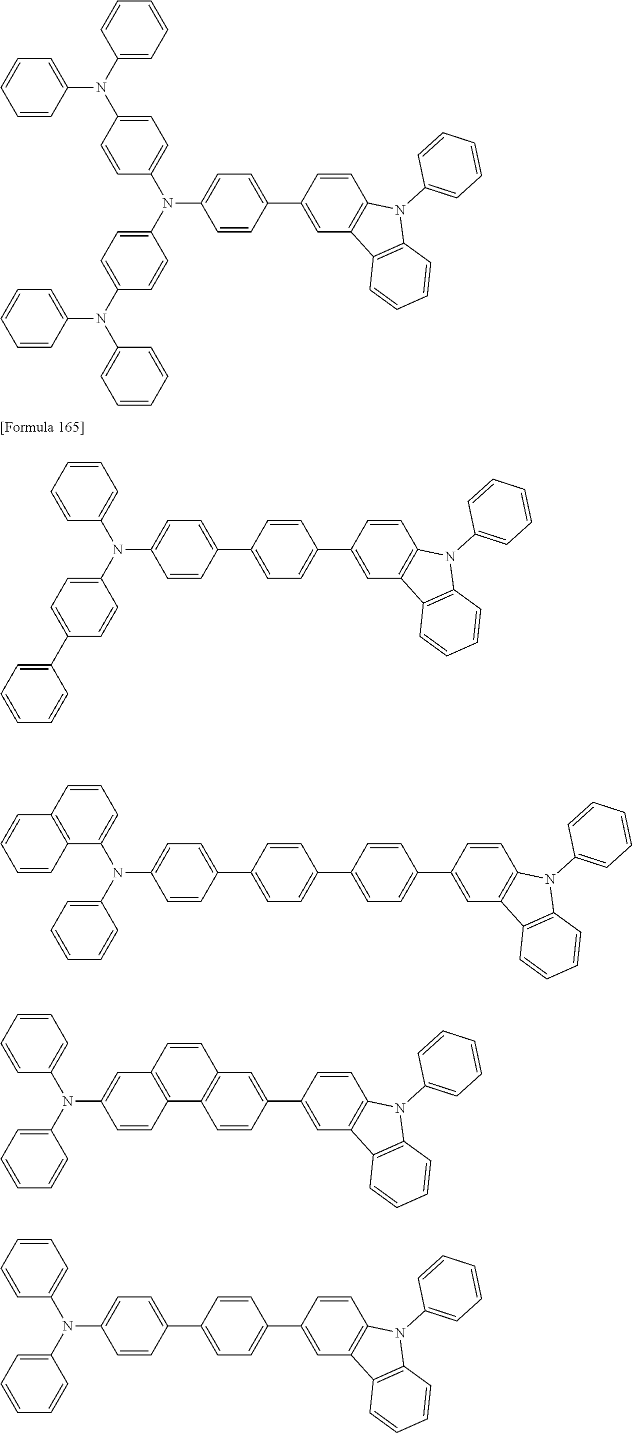 [SMILES: c1ccc(N(c2ccccc2)c2ccc(N(c3ccc(-c4ccc5c(c4)c4ccccc4n5-c4ccccc4)cc3)c3ccc(N(c4ccccc4)c4ccccc4)cc3)cc2)cc1 ; c1ccc(-c2ccc(N(c3ccccc3)c3ccc(-c4ccc(-c5ccc6c(c5)c5ccccc5n6-c5ccccc5)cc4)cc3)cc2)cc1 ; c1ccc(N(c2ccc(-c3ccc(-c4ccc(-c5ccc6c(c5)c5ccccc5n6-c5ccccc5)cc4)cc3)cc2)c2cccc3ccccc23)cc1 ; c1ccc(N(c2ccccc2)c2ccc3c(ccc4cc(-c5ccc6c(c5)c5ccccc5n6-c5ccccc5)ccc43)c2)cc1 ; c1ccc(N(c2ccccc2)c2ccc(-c3ccc(-c4ccc5c(c4)c4ccccc4n5-c4ccccc4)cc3)cc2)cc1]

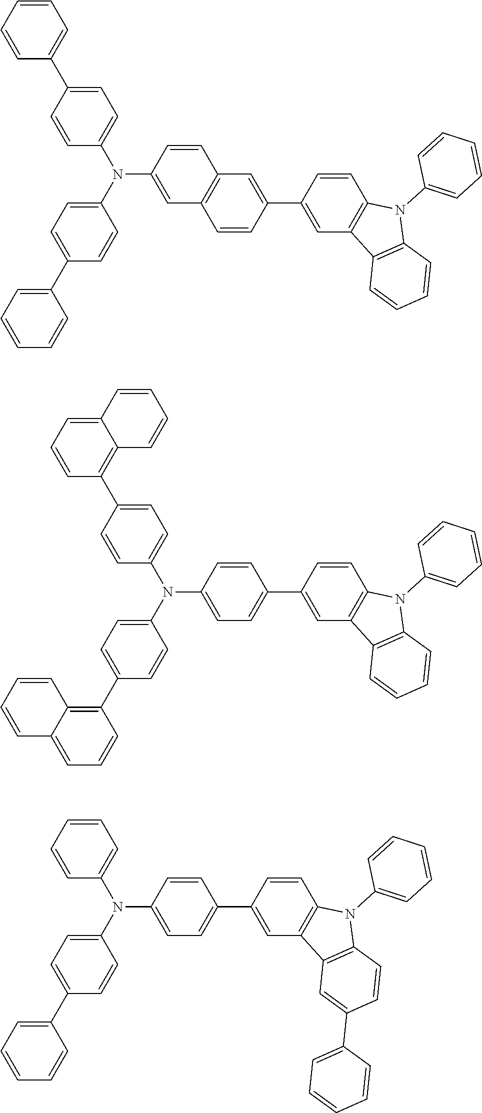 [SMILES: c1ccc(-c2ccc(N(c3ccc(-c4ccccc4)cc3)c3ccc4cc(-c5ccc6c(c5)c5ccccc5n6-c5ccccc5)ccc4c3)cc2)cc1 ; c1ccc(-n2c3ccccc3c3cc(-c4ccc(N(c5ccc(-c6cccc7ccccc67)cc5)c5ccc(-c6cccc7ccccc67)cc5)cc4)ccc32)cc1 ; c1ccc(-c2ccc(N(c3ccccc3)c3ccc(-c4ccc5c(c4)c4cc(-c6ccccc6)ccc4n5-c4ccccc4)cc3)cc2)cc1]

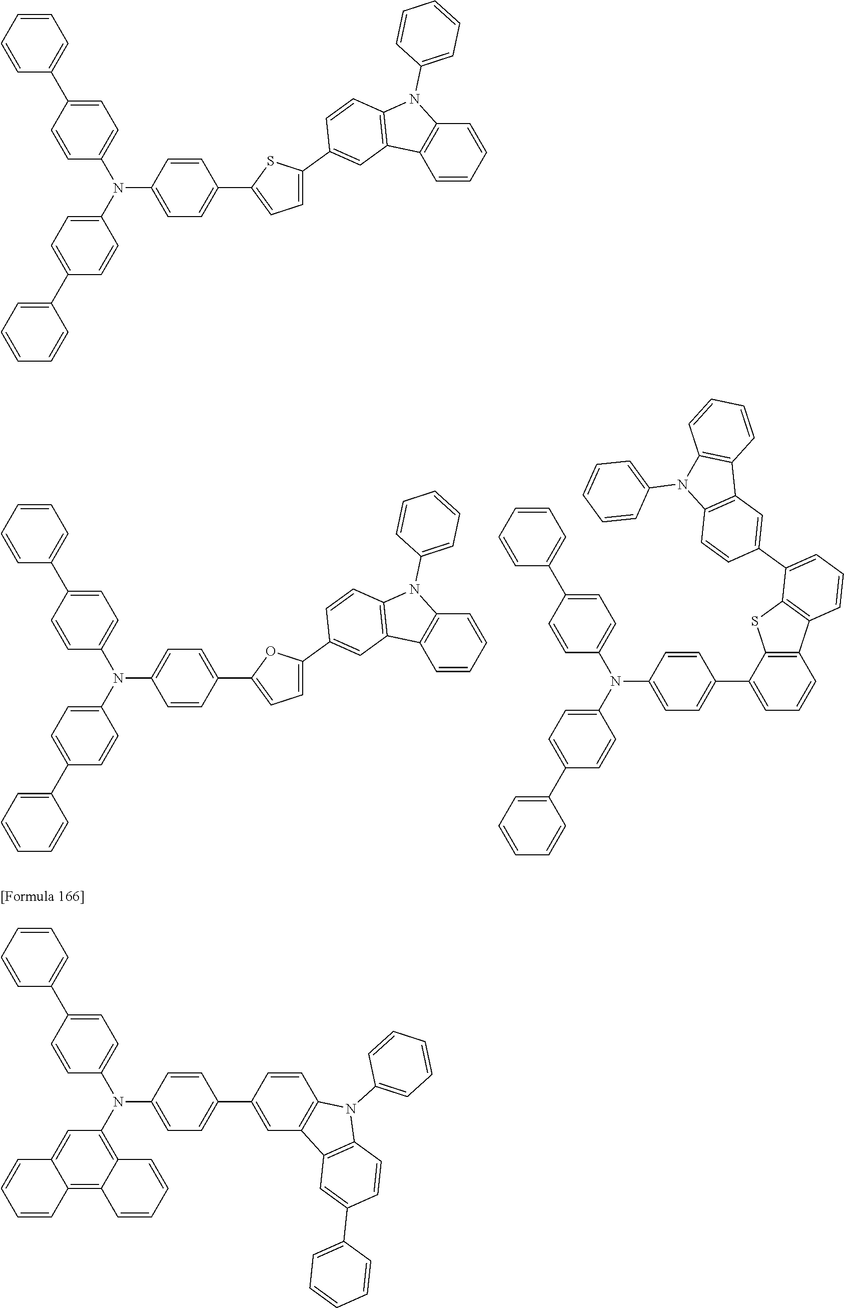

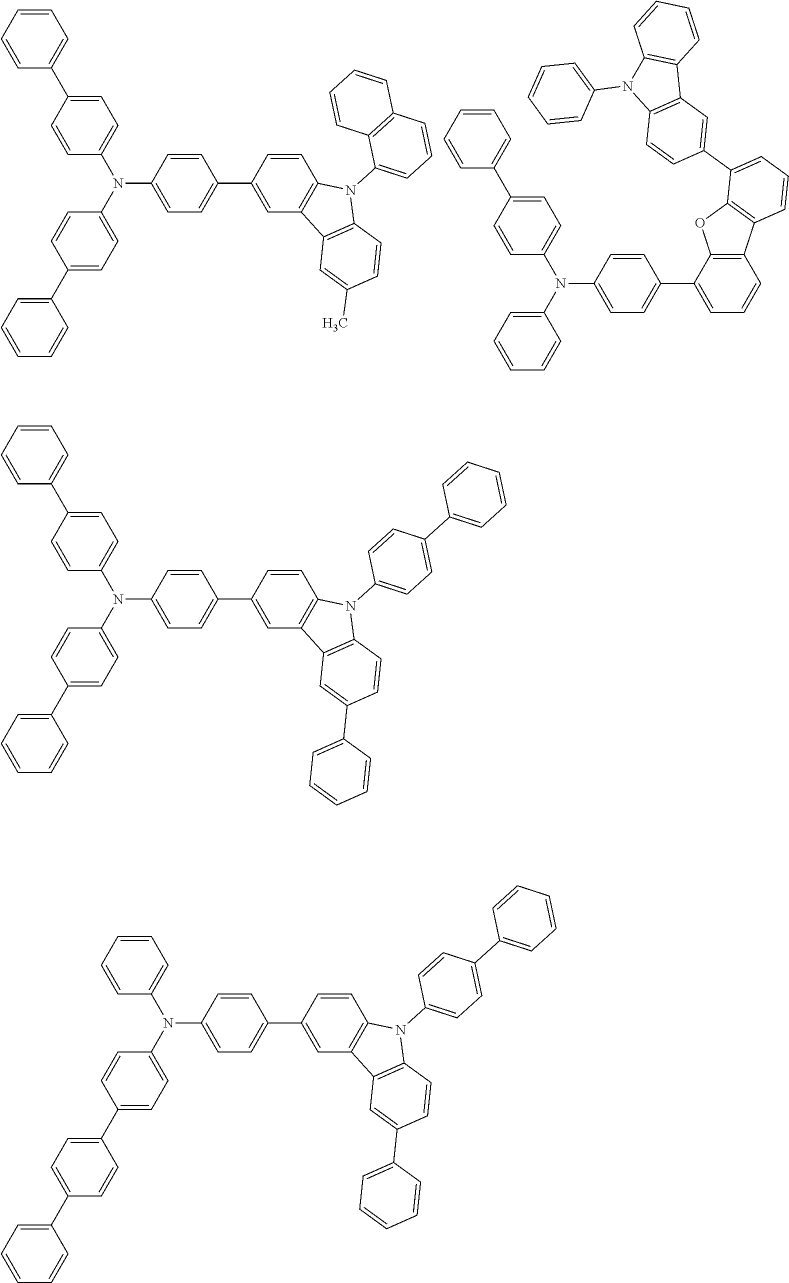

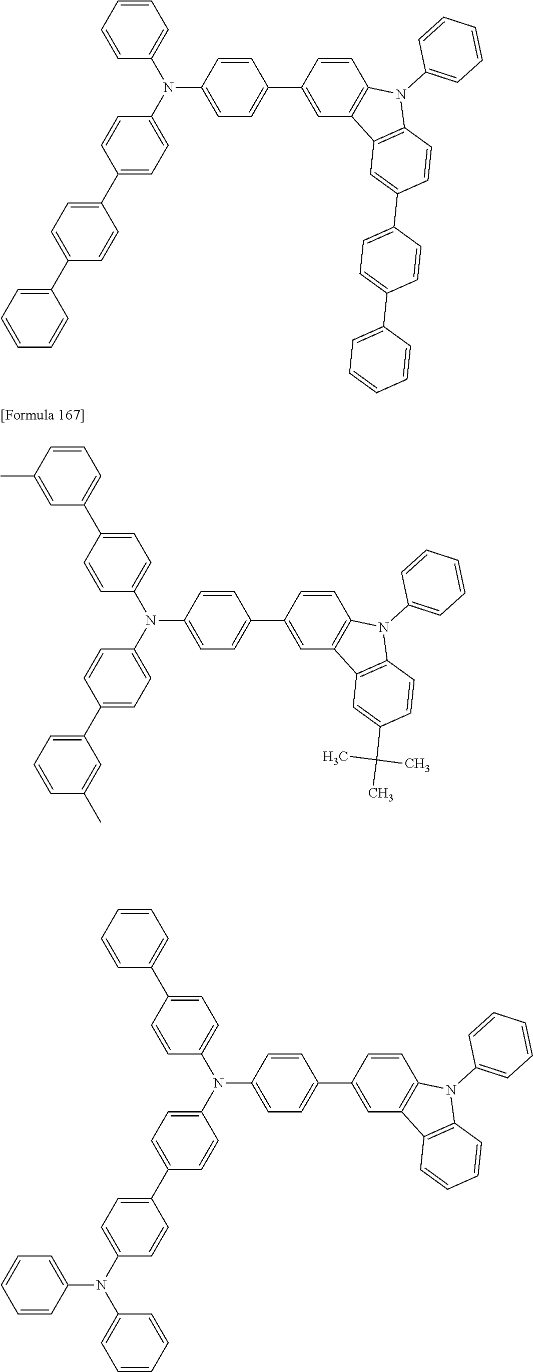 [SMILES: c1ccc(-c2ccc(-c3ccc(N(c4ccccc4)c4ccc(-c5ccc6c(c5)c5cc(-c7ccc(-c8ccccc8)cc7)ccc5n6-c5ccccc5)cc4)cc3)cc2)cc1 ; Cc1cccc(-c2ccc(N(c3ccc(-c4cccc(C)c4)cc3)c3ccc(-c4ccc5c(c4)c4cc(C(C)(C)C)ccc4n5-c4ccccc4)cc3)cc2)c1 ; c1ccc(-c2ccc(N(c3ccc(-c4ccc(N(c5ccccc5)c5ccccc5)cc4)cc3)c3ccc(-c4ccc5c(c4)c4ccccc4n5-c4ccccc4)cc3)cc2)cc1]

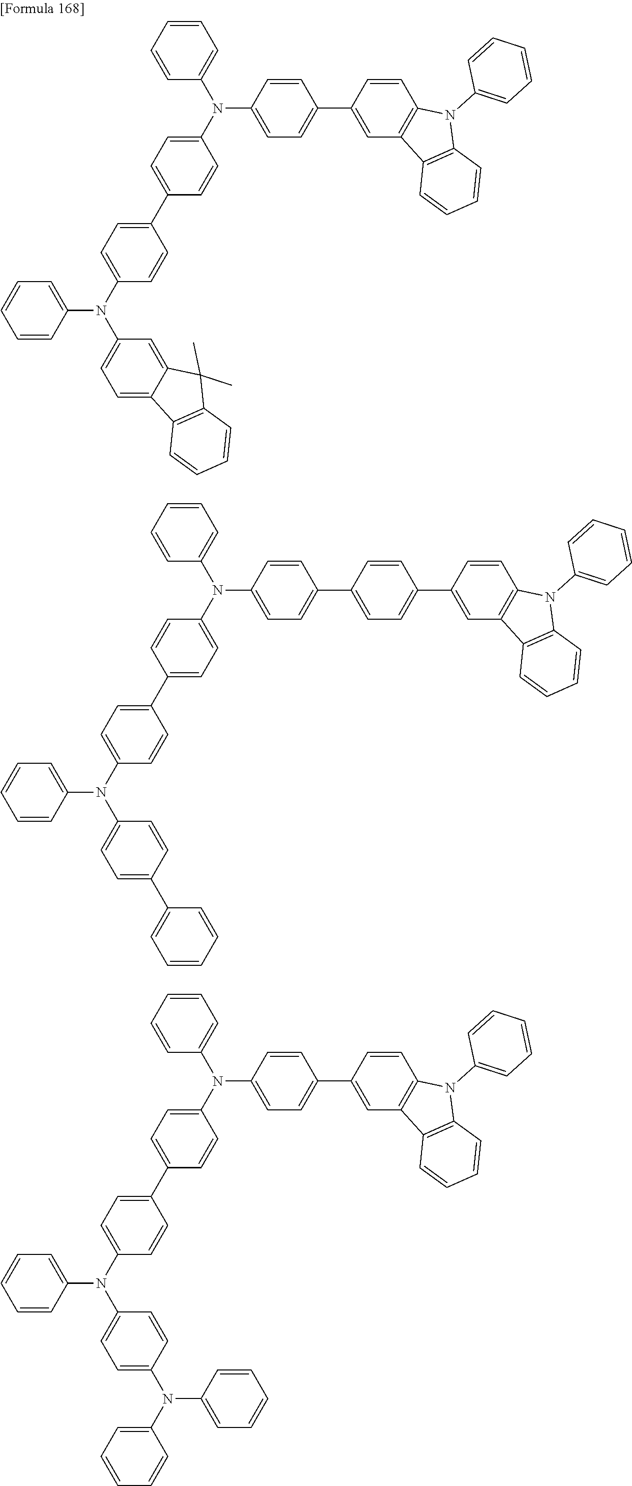

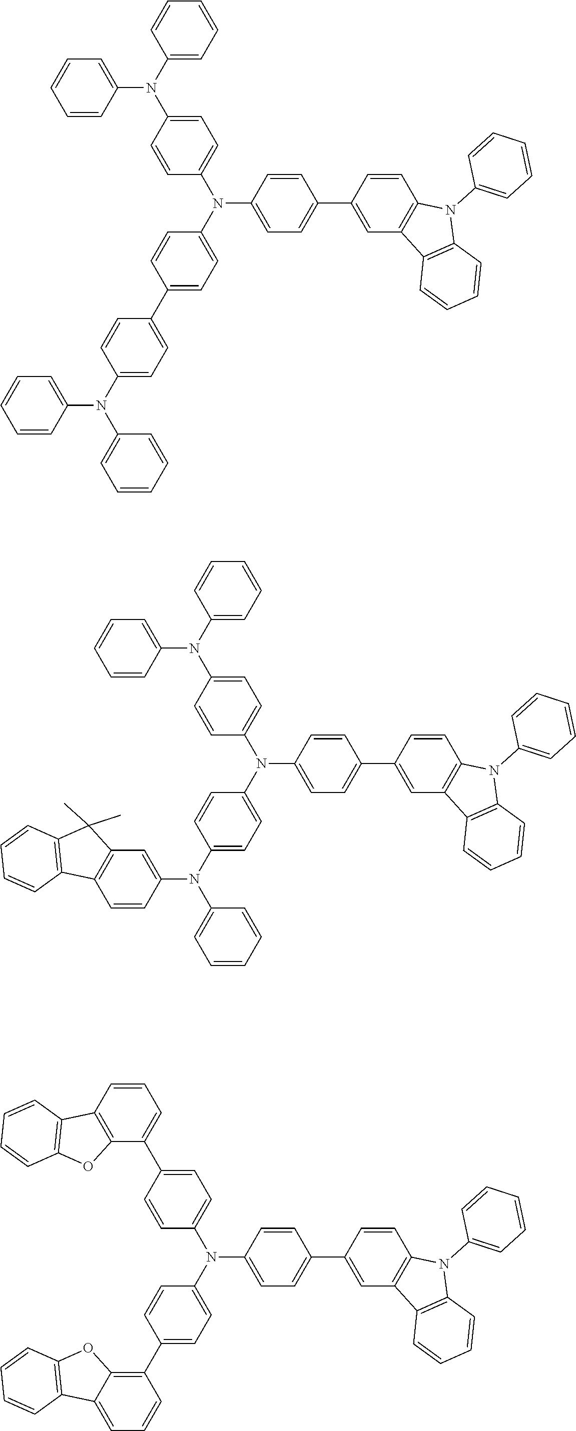 [SMILES: c1ccc(N(c2ccccc2)c2ccc(-c3ccc(N(c4ccc(-c5ccc6c(c5)c5ccccc5n6-c5ccccc5)cc4)c4ccc(N(c5ccccc5)c5ccccc5)cc4)cc3)cc2)cc1 ; CC1(C)c2ccccc2-c2ccc(N(c3ccccc3)c3ccc(N(c4ccc(-c5ccc6c(c5)c5ccccc5n6-c5ccccc5)cc4)c4ccc(N(c5ccccc5)c5ccccc5)cc4)cc3)cc21 ; c1ccc(-n2c3ccccc3c3cc(-c4ccc(N(c5ccc(-c6cccc7c6oc6ccccc67)cc5)c5ccc(-c6cccc7c6oc6ccccc67)cc5)cc4)ccc32)cc1]

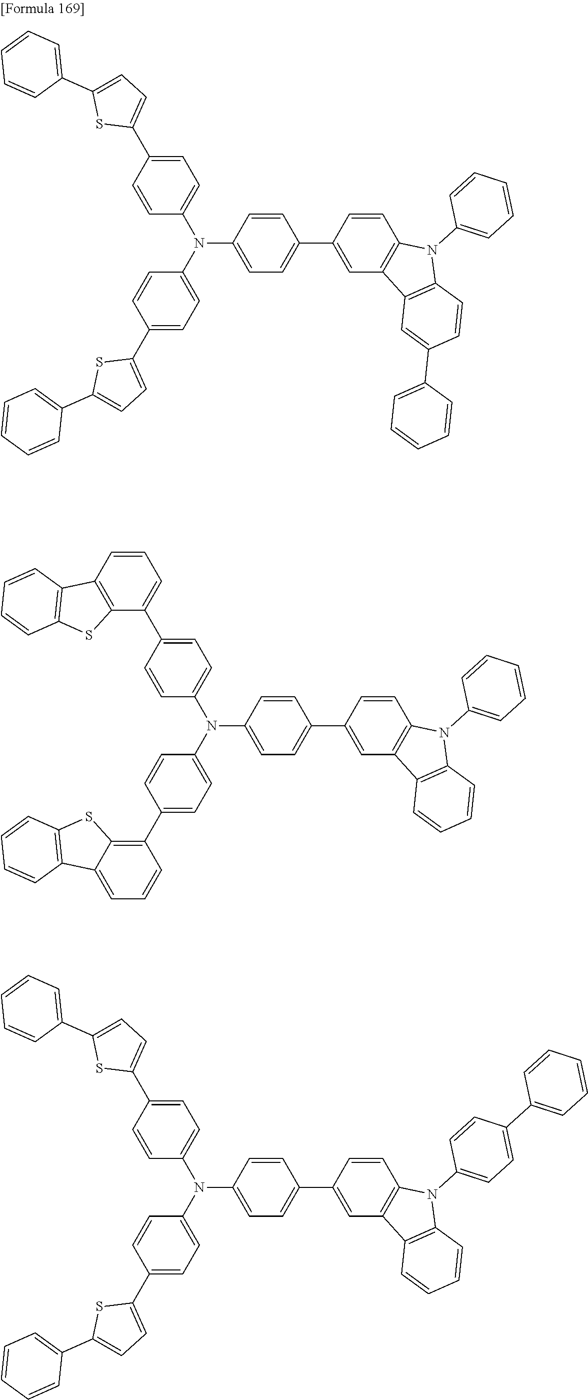 [SMILES: c1ccc(-c2ccc3c(c2)c2cc(-c4ccc(N(c5ccc(-c6ccc(-c7ccccc7)s6)cc5)c5ccc(-c6ccc(-c7ccccc7)s6)cc5)cc4)ccc2n3-c2ccccc2)cc1 ; c1ccc(-n2c3ccccc3c3cc(-c4ccc(N(c5ccc(-c6cccc7c6sc6ccccc67)cc5)c5ccc(-c6cccc7c6sc6ccccc67)cc5)cc4)ccc32)cc1 ; c1ccc(-c2ccc(-n3c4ccccc4c4cc(-c5ccc(N(c6ccc(-c7ccc(-c8ccccc8)s7)cc6)c6ccc(-c7ccc(-c8ccccc8)s7)cc6)cc5)ccc43)cc2)cc1]

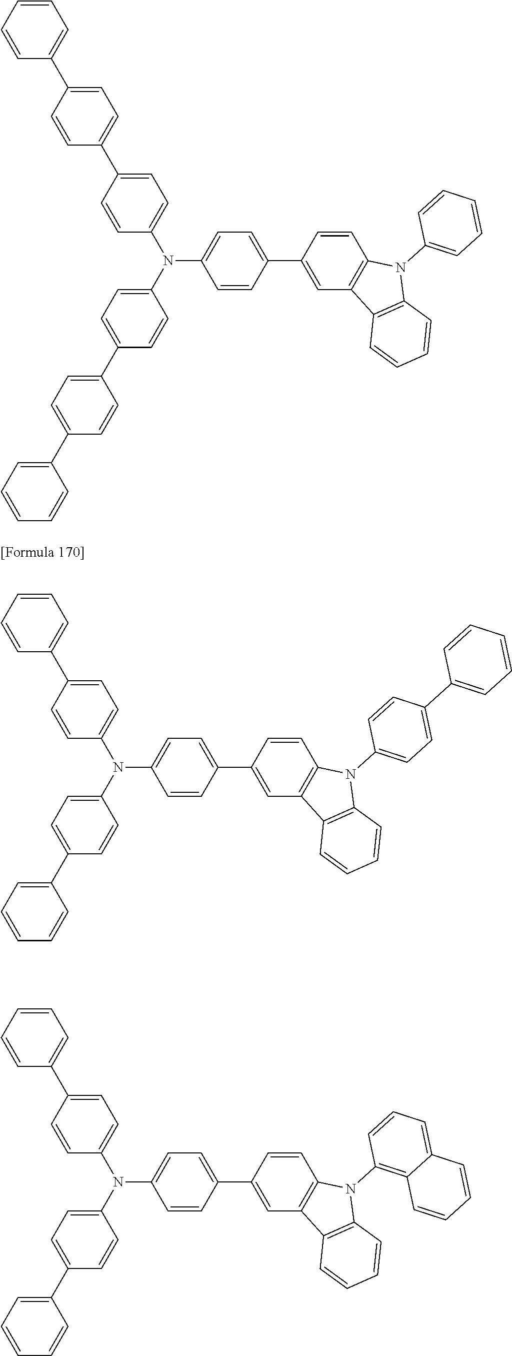 [SMILES: c1ccc(-c2ccc(-c3ccc(N(c4ccc(-c5ccc(-c6ccccc6)cc5)cc4)c4ccc(-c5ccc6c(c5)c5ccccc5n6-c5ccccc5)cc4)cc3)cc2)cc1 ; c1ccc(-c2ccc(N(c3ccc(-c4ccccc4)cc3)c3ccc(-c4ccc5c(c4)c4ccccc4n5-c4ccc(-c5ccccc5)cc4)cc3)cc2)cc1 ; c1ccc(-c2ccc(N(c3ccc(-c4ccccc4)cc3)c3ccc(-c4ccc5c(c4)c4ccccc4n5-c4cccc5ccccc45)cc3)cc2)cc1]

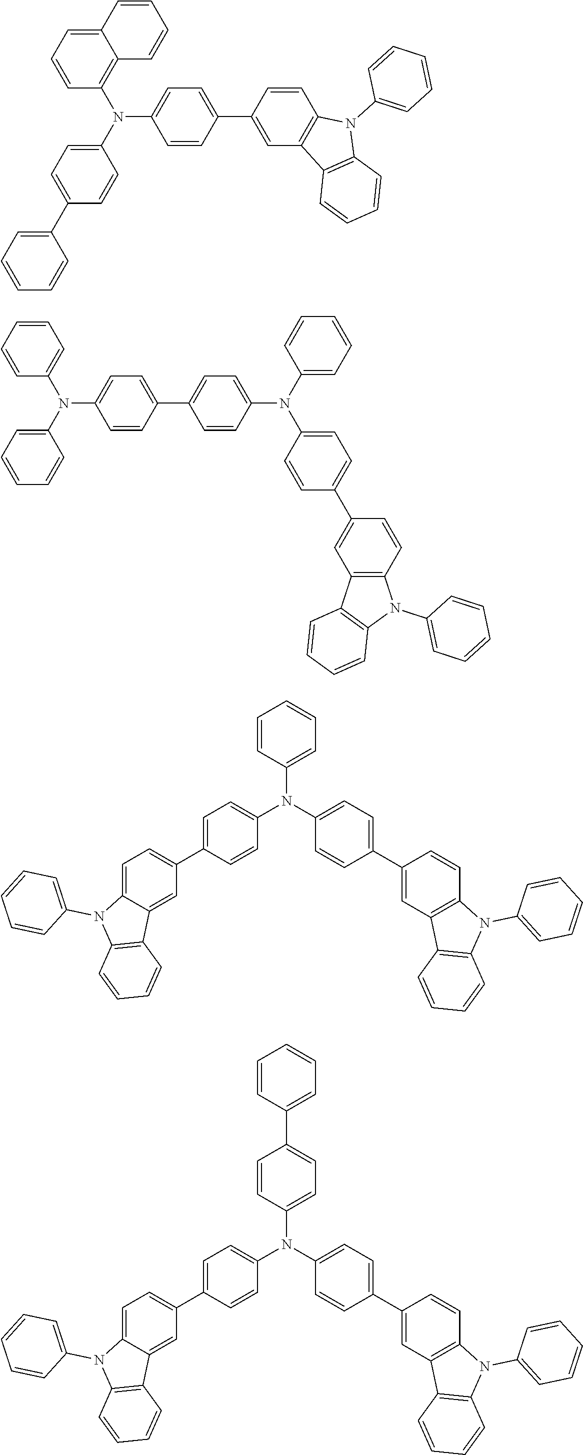

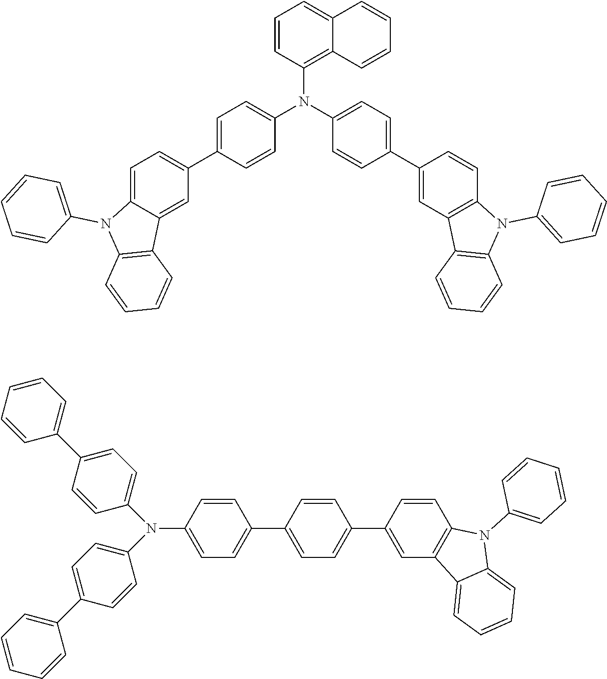 [SMILES: c1ccc(-n2c3ccccc3c3cc(-c4ccc(N(c5ccc(-c6ccc7c(c6)c6ccccc6n7-c6ccccc6)cc5)c5cccc6ccccc56)cc4)ccc32)cc1 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

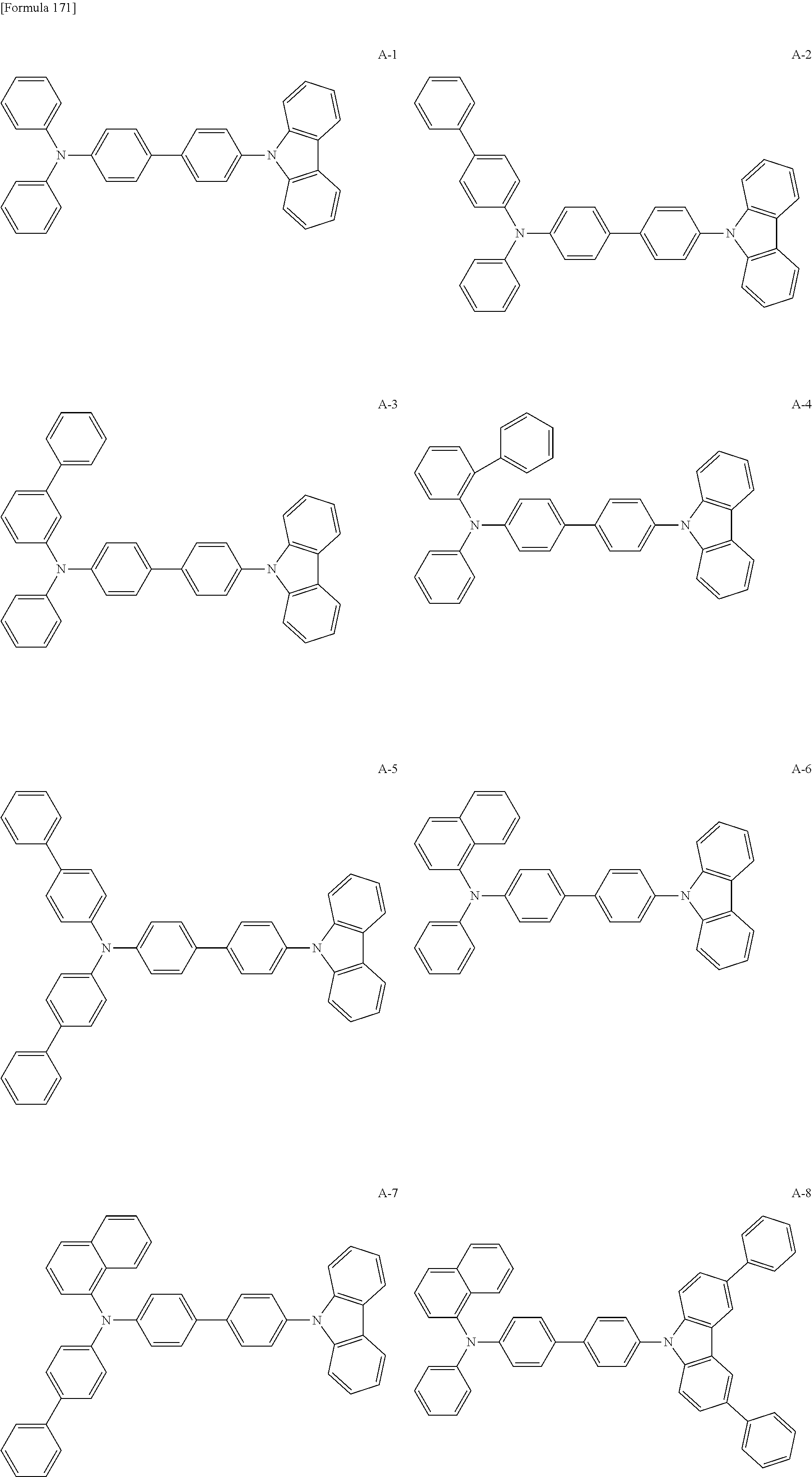

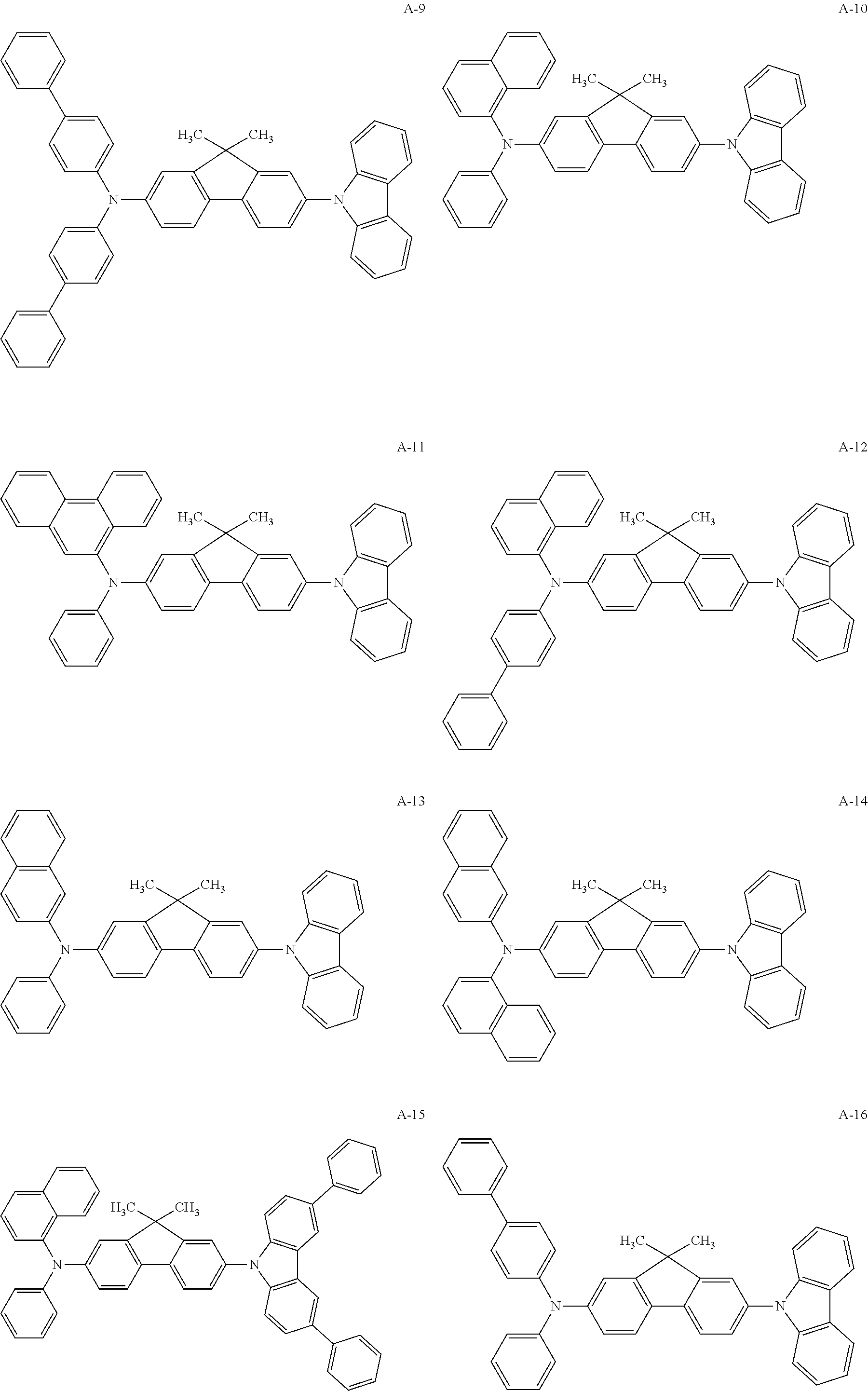

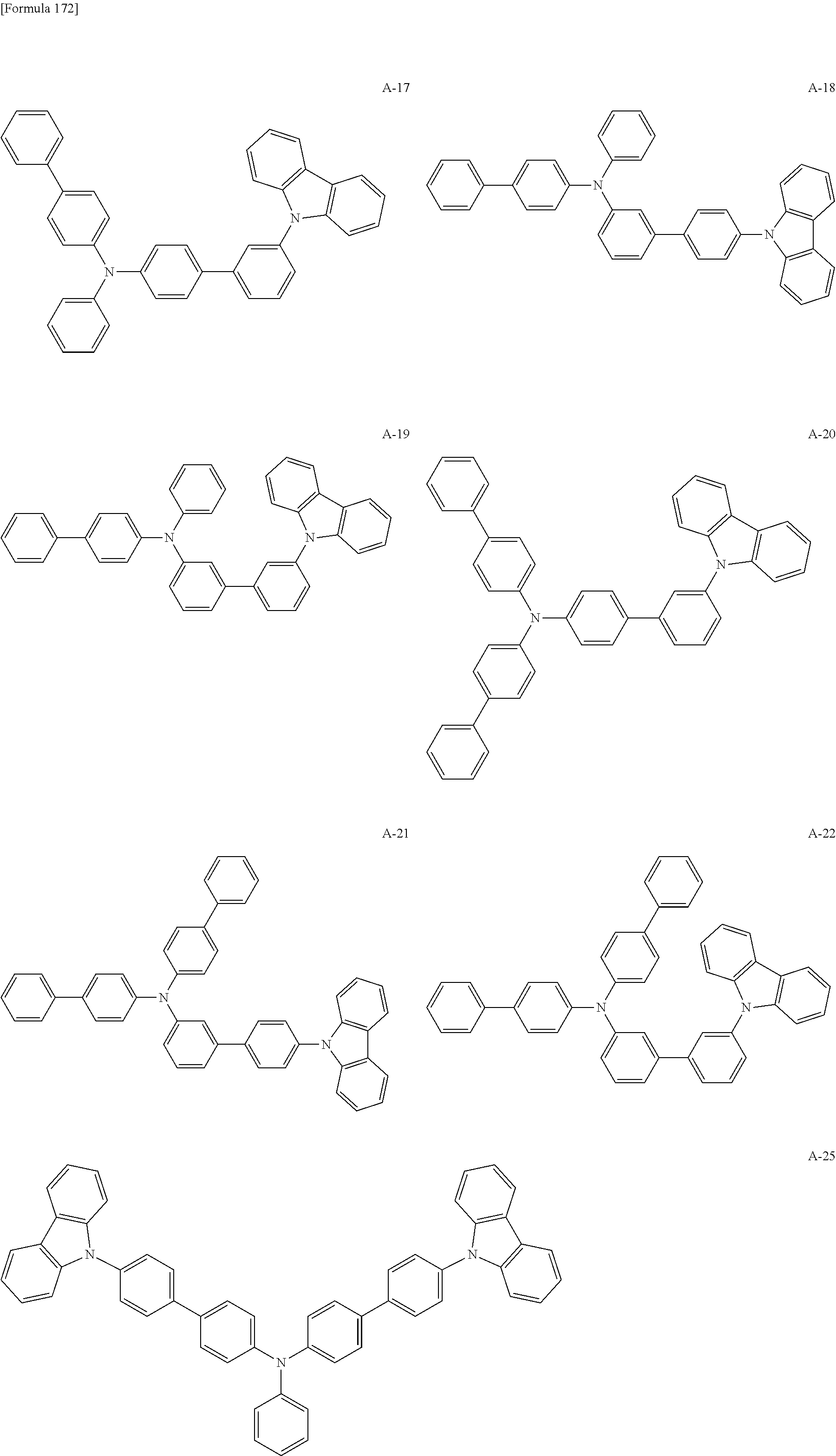

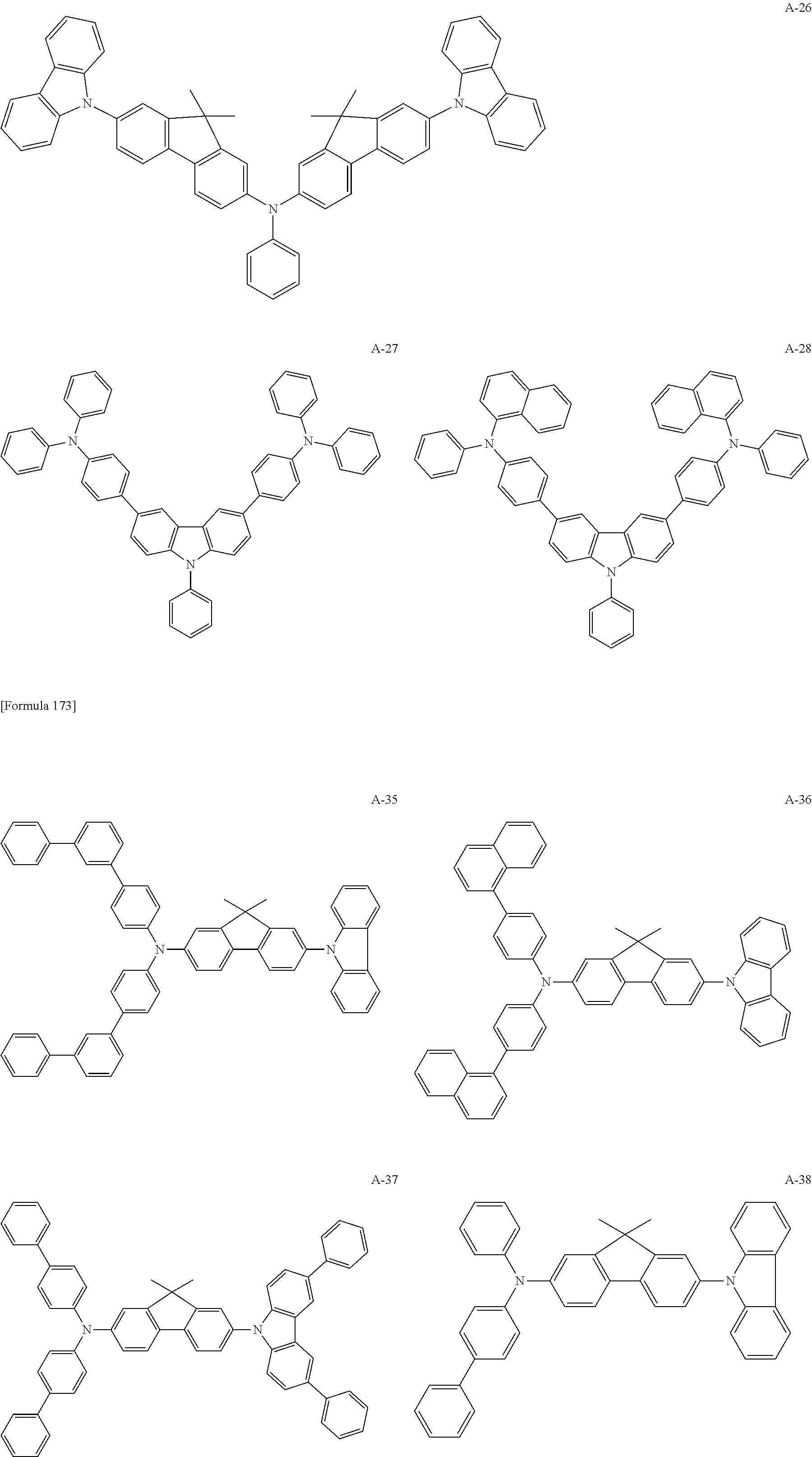

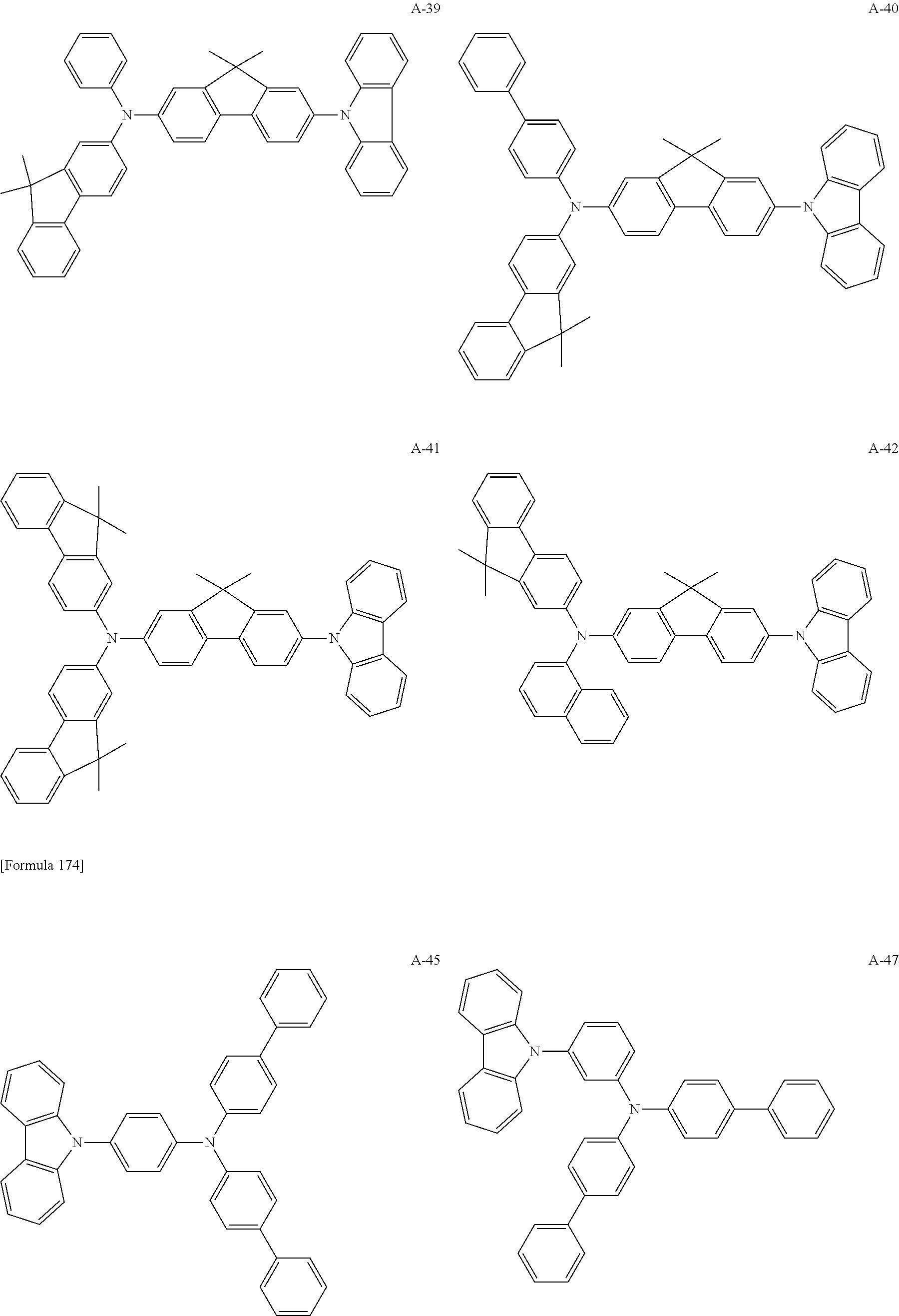

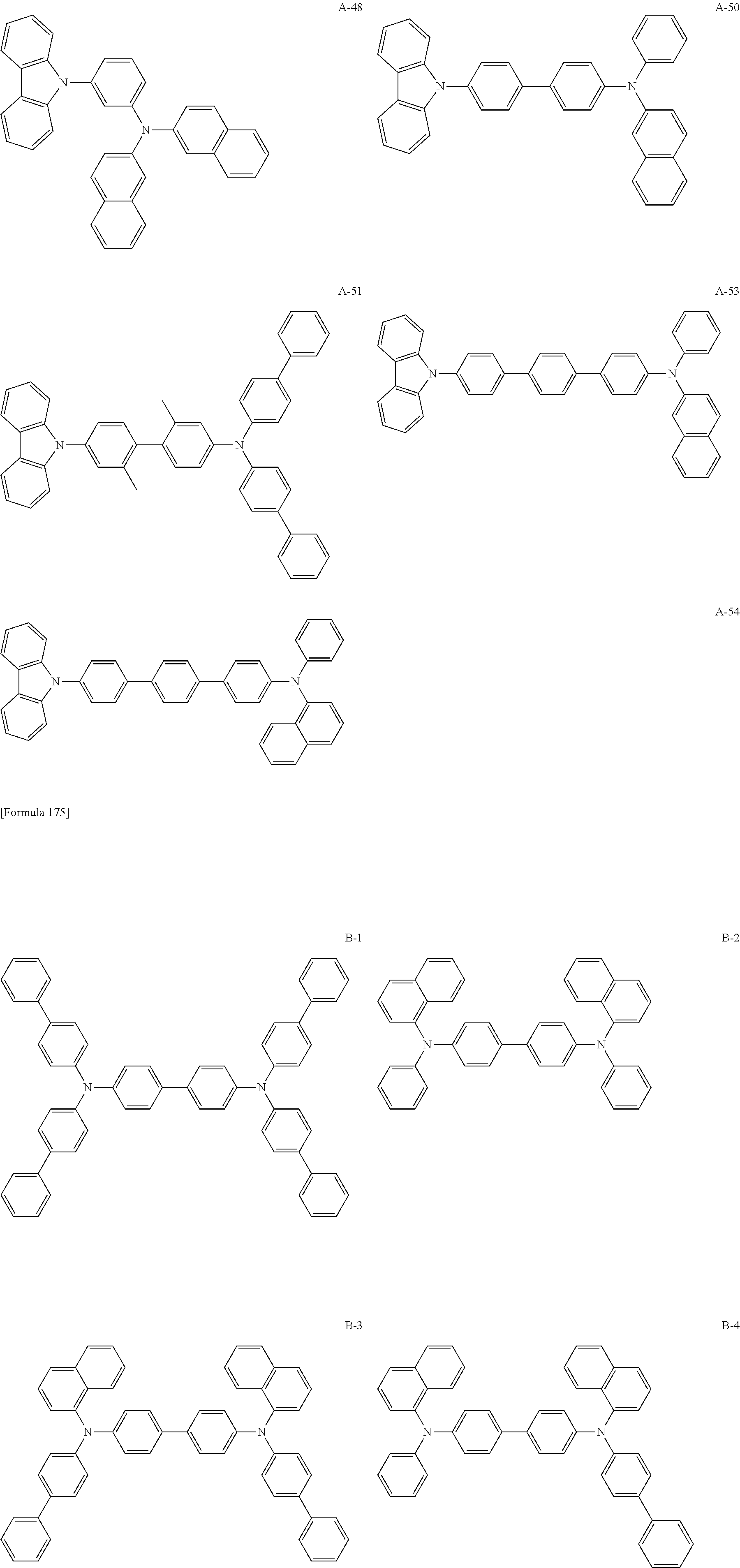

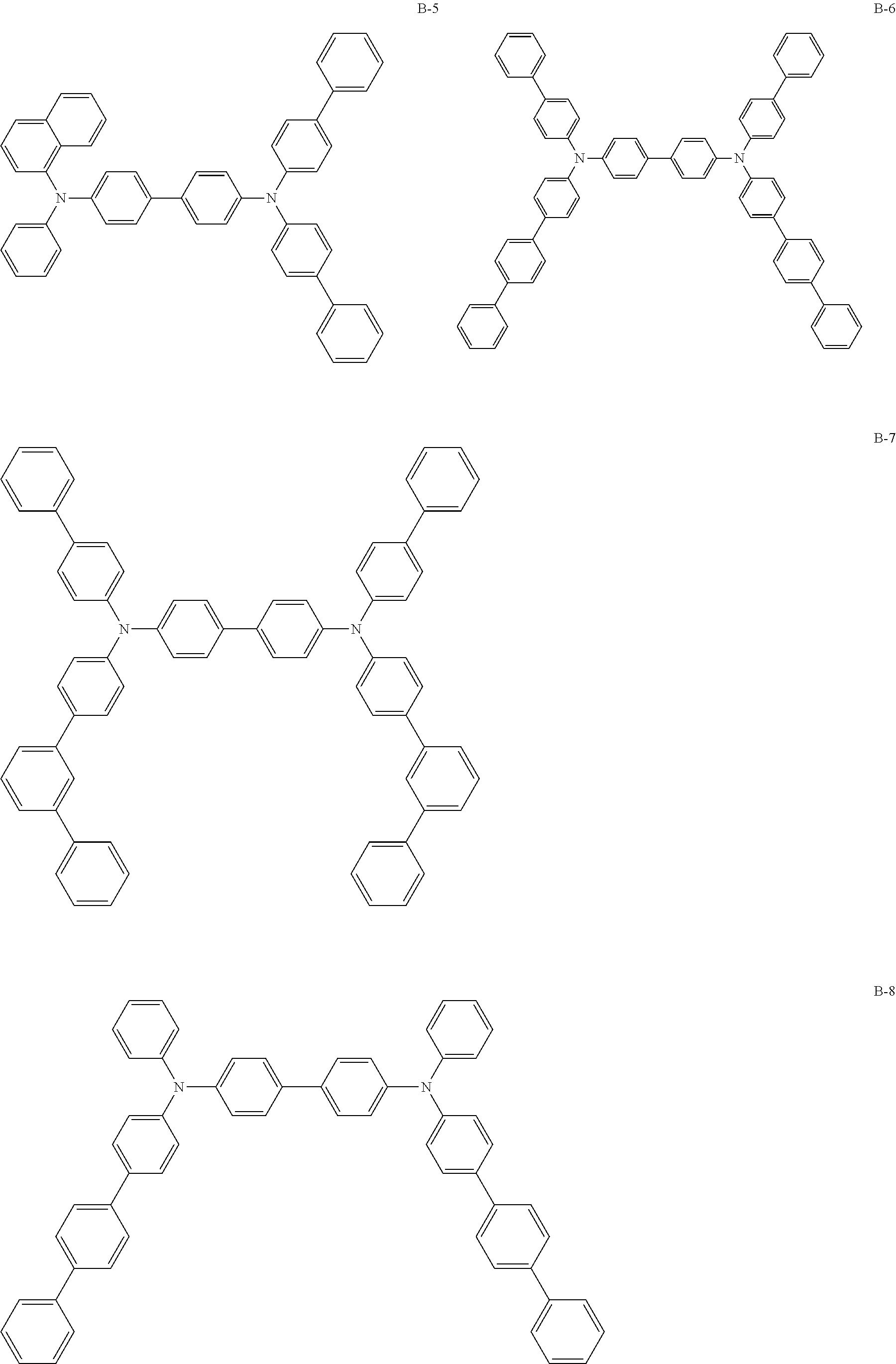 [SMILES: c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-c2ccc(-c3ccc(N(c4ccc(-c5ccccc5)cc4)c4ccc(-c5ccc(N(c6ccc(-c7ccccc7)cc6)c6ccc(-c7ccc(-c8ccccc8)cc7)cc6)cc5)cc4)cc3)cc2)cc1 ; c1ccc(-c2ccc(N(c3ccc(-c4ccc(N(c5ccc(-c6ccccc6)cc5)c5ccc(-c6cccc(-c7ccccc7)c6)cc5)cc4)cc3)c3ccc(-c4cccc(-c5ccccc5)c4)cc3)cc2)cc1 ; c1ccc(-c2ccc(-c3ccc(N(c4ccccc4)c4ccc(-c5ccc(N(c6ccccc6)c6ccc(-c7ccc(-c8ccccc8)cc7)cc6)cc5)cc4)cc3)cc2)cc1]

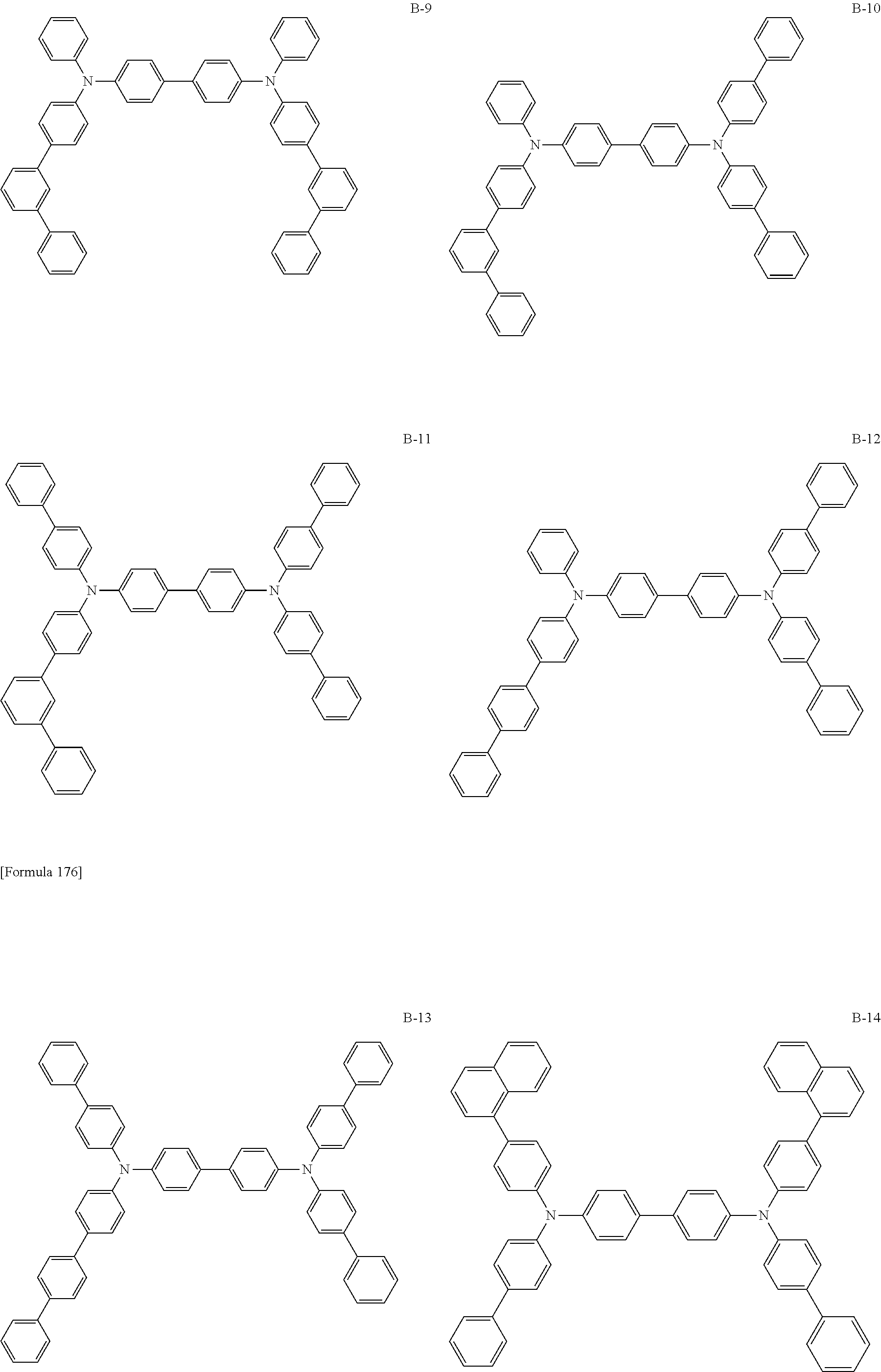

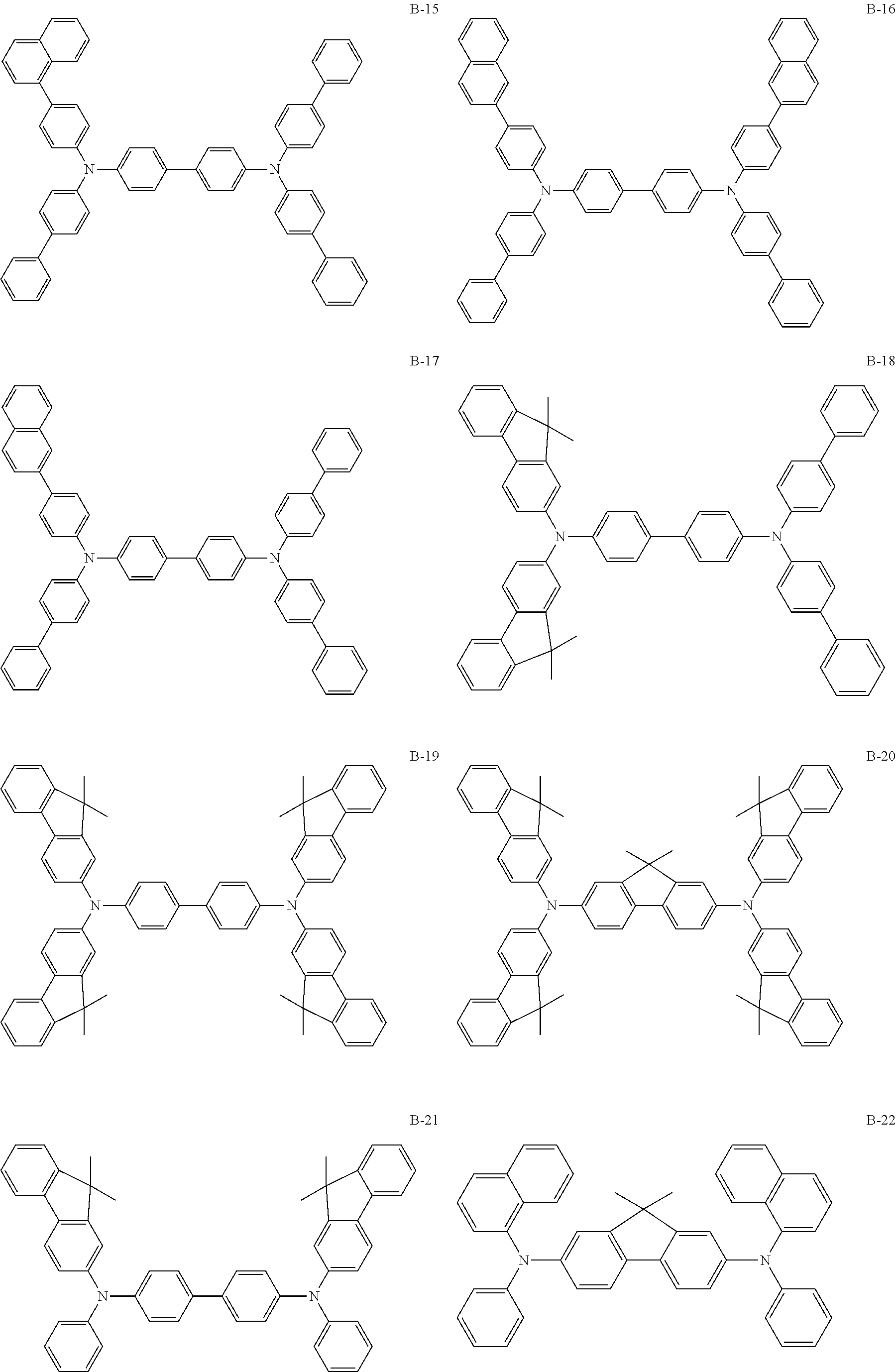

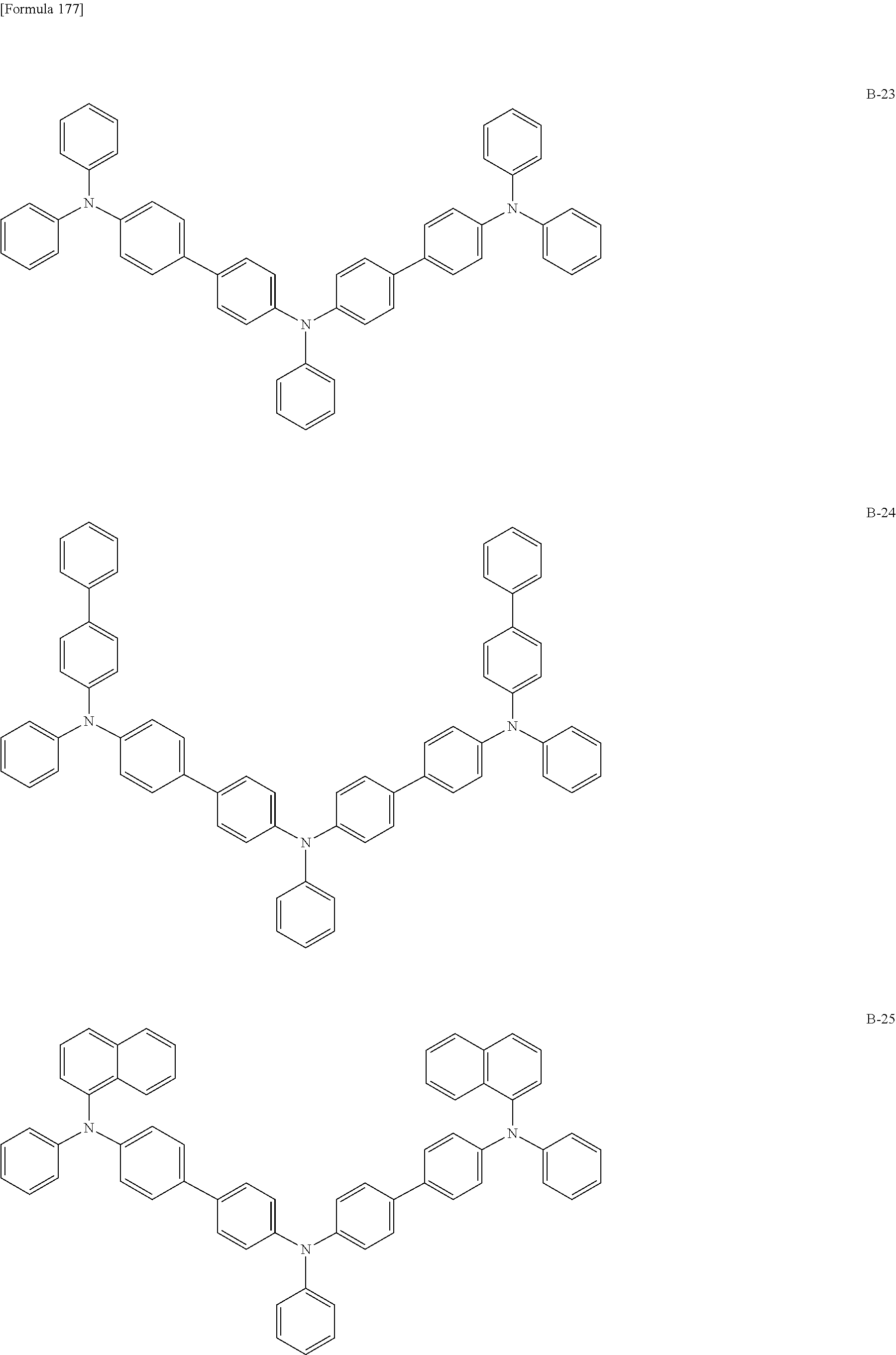 [SMILES: c1ccc(N(c2ccccc2)c2ccc(-c3ccc(N(c4ccccc4)c4ccc(-c5ccc(N(c6ccccc6)c6ccccc6)cc5)cc4)cc3)cc2)cc1 ; c1ccc(-c2ccc(N(c3ccccc3)c3ccc(-c4ccc(N(c5ccccc5)c5ccc(-c6ccc(N(c7ccccc7)c7ccc(-c8ccccc8)cc7)cc6)cc5)cc4)cc3)cc2)cc1 ; c1ccc(N(c2ccc(-c3ccc(N(c4ccccc4)c4cccc5ccccc45)cc3)cc2)c2ccc(-c3ccc(N(c4ccccc4)c4cccc5ccccc45)cc3)cc2)cc1]

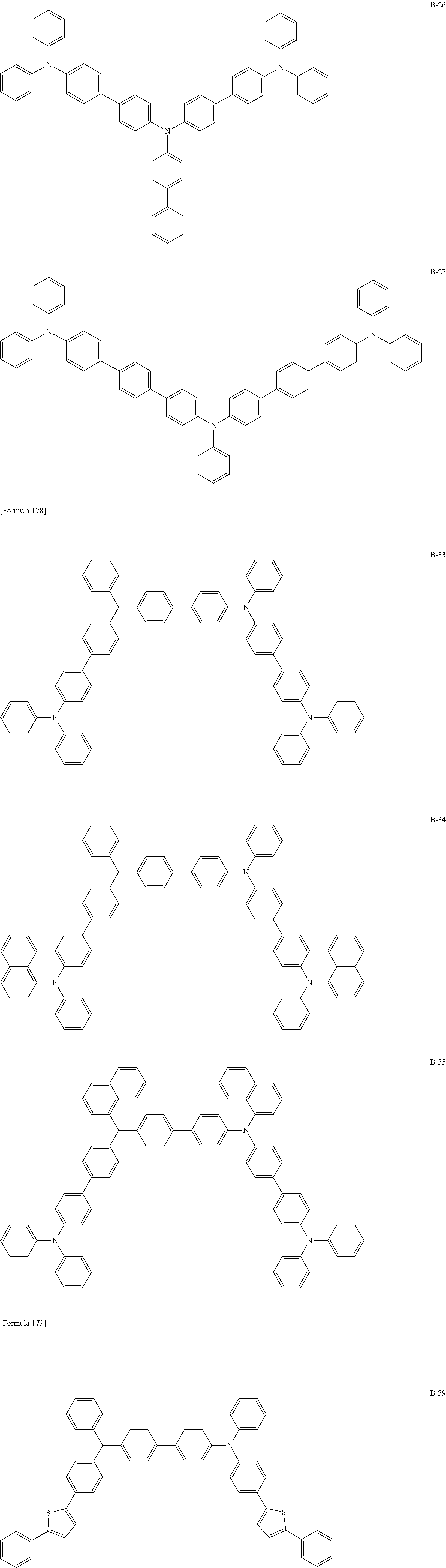

[chemical structure]

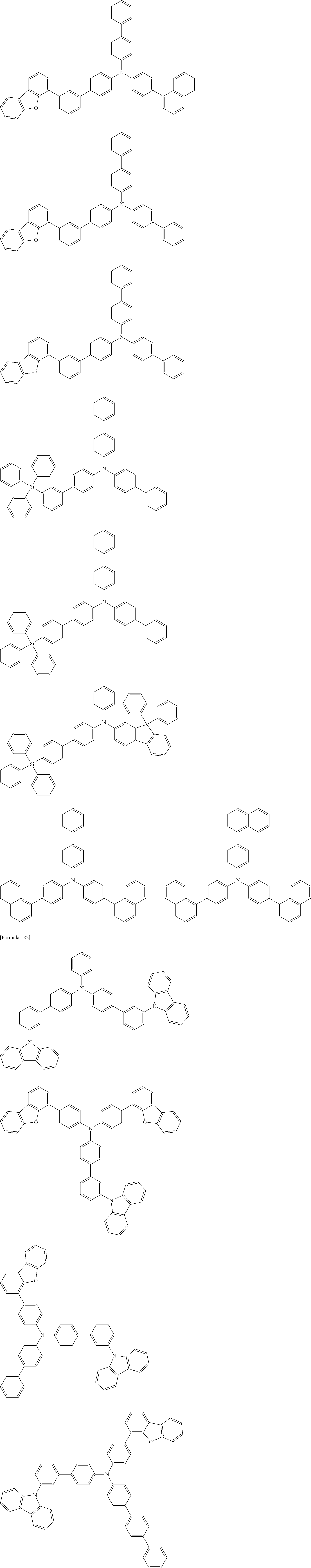

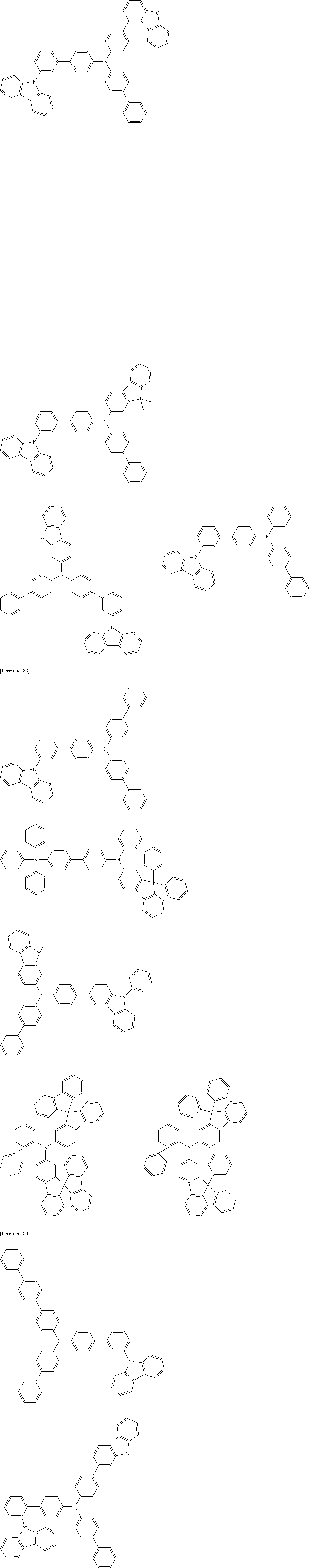

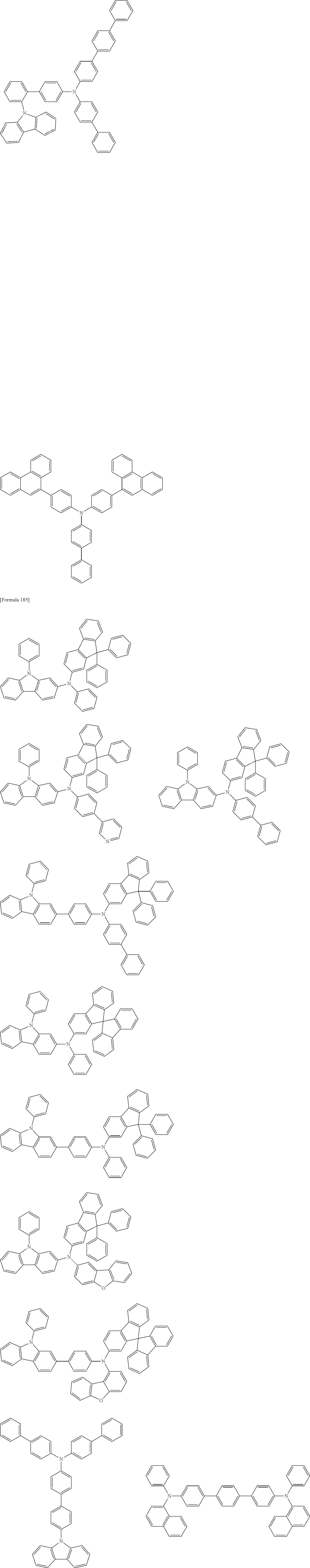

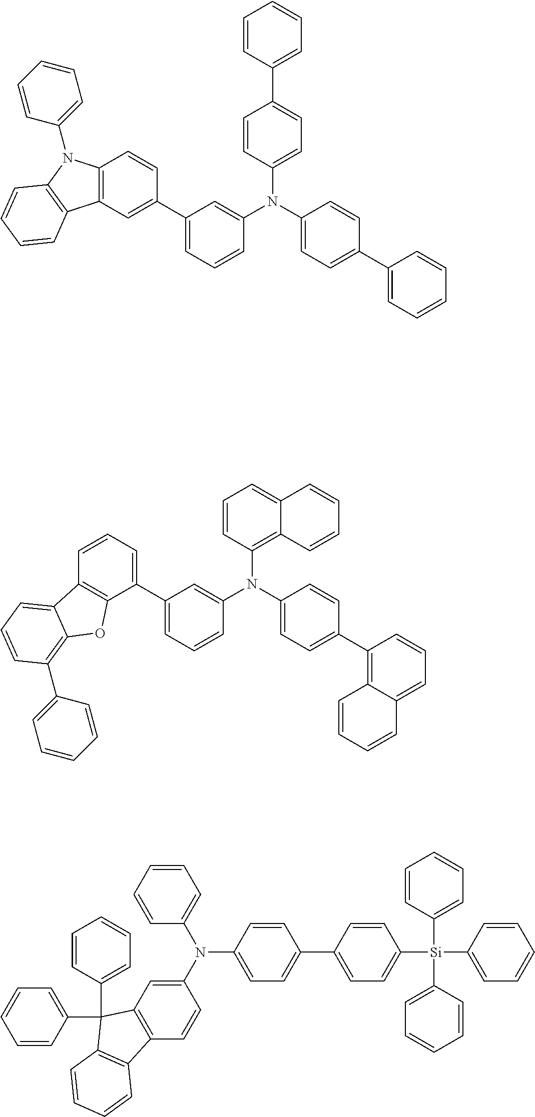 [SMILES: c1ccc(-c2ccc(N(c3ccc(-c4ccccc4)cc3)c3cccc(-c4ccc5c(c4)c4ccccc4n5-c4ccccc4)c3)cc2)cc1 ; c1ccc(-c2cccc3c2oc2c(-c4cccc(N(c5ccc(-c6cccc7ccccc67)cc5)c5cccc6ccccc56)c4)cccc23)cc1 ; c1ccc(N(c2ccc(-c3ccc([Si](c4ccccc4)(c4ccccc4)c4ccccc4)cc3)cc2)c2ccc3c(c2)C(c2ccccc2)(c2ccccc2)c2ccccc2-3)cc1]

In an exemplary arrangement of the organic EL device of the exemplary embodiment, the second organic material contained in the first anode side organic layer is preferably at least one compound selected from compounds listed below.

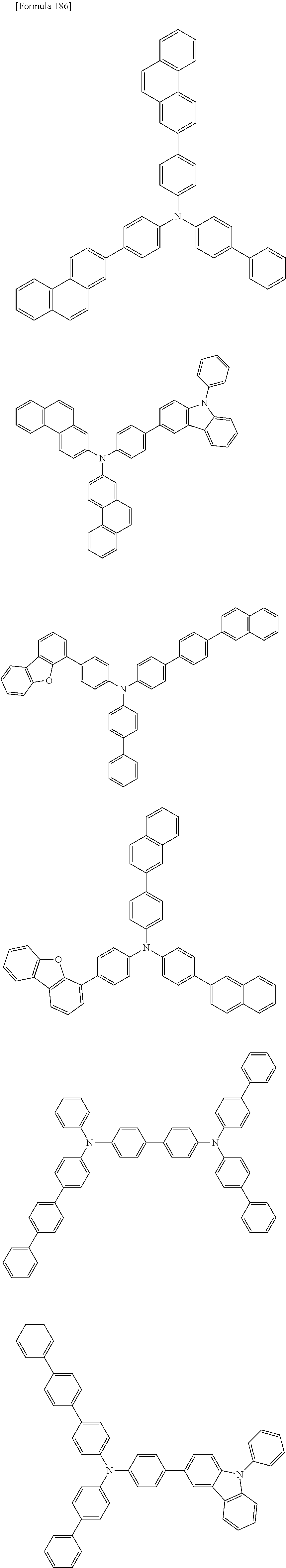

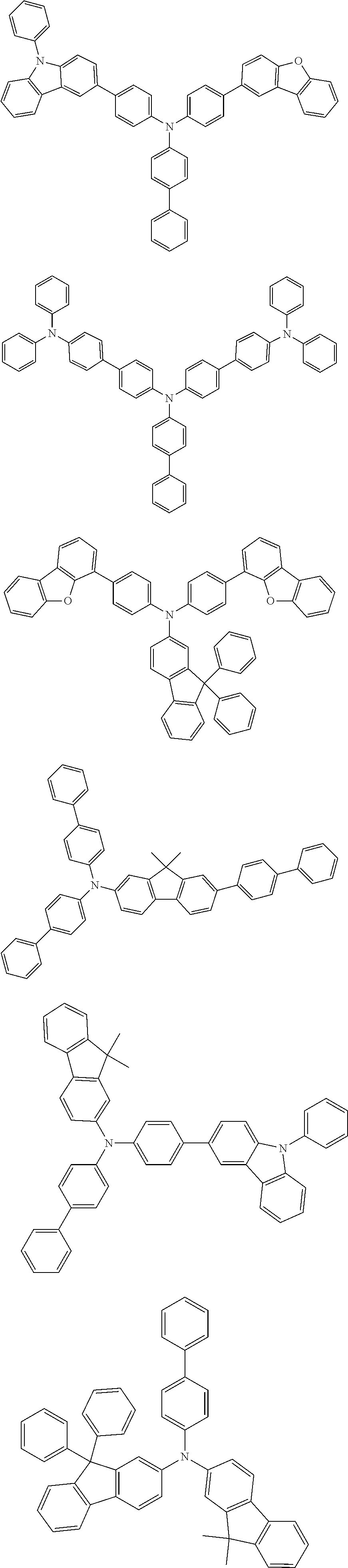

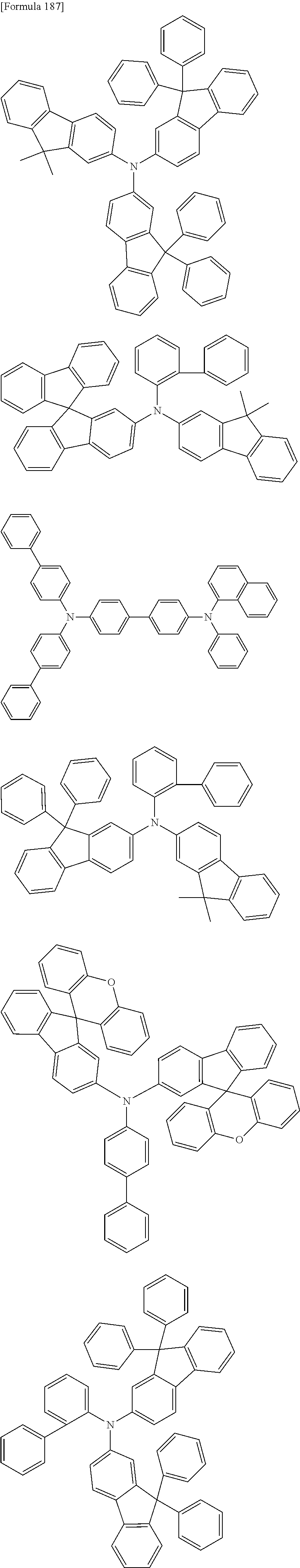

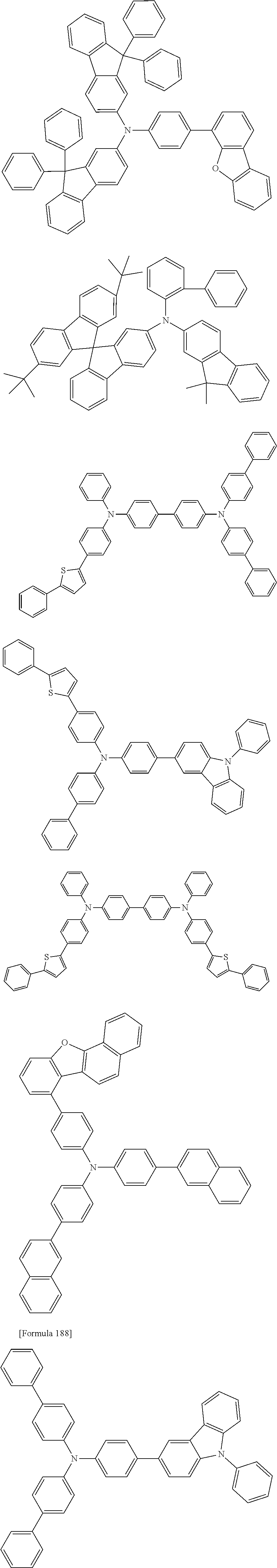

In an exemplary arrangement of the organic EL device of the exemplary embodiment, the compound (second hole transporting zone material) contained in the second anode side organic layer is preferably at least one compound selected from compounds listed below.

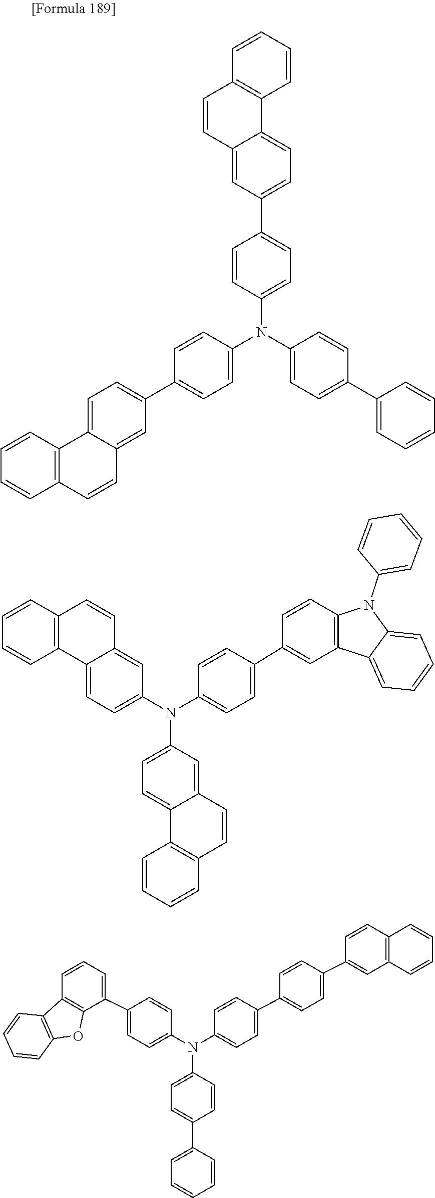 [SMILES: c1ccc(-c2ccc(N(c3ccc(-c4ccc5c(ccc6ccccc65)c4)cc3)c3ccc(-c4ccc5c(ccc6ccccc65)c4)cc3)cc2)cc1 ; c1ccc(-n2c3ccccc3c3cc(-c4ccc(N(c5ccc6c(ccc7ccccc76)c5)c5ccc6c(ccc7ccccc76)c5)cc4)ccc32)cc1 ; c1ccc(-c2ccc(N(c3ccc(-c4ccc(-c5ccc6ccccc6c5)cc4)cc3)c3ccc(-c4cccc5c4oc4ccccc45)cc3)cc2)cc1]

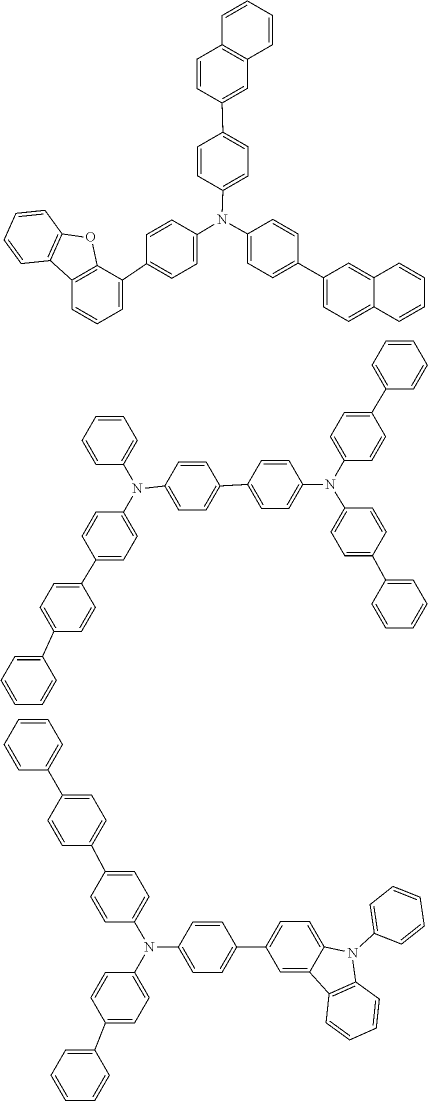

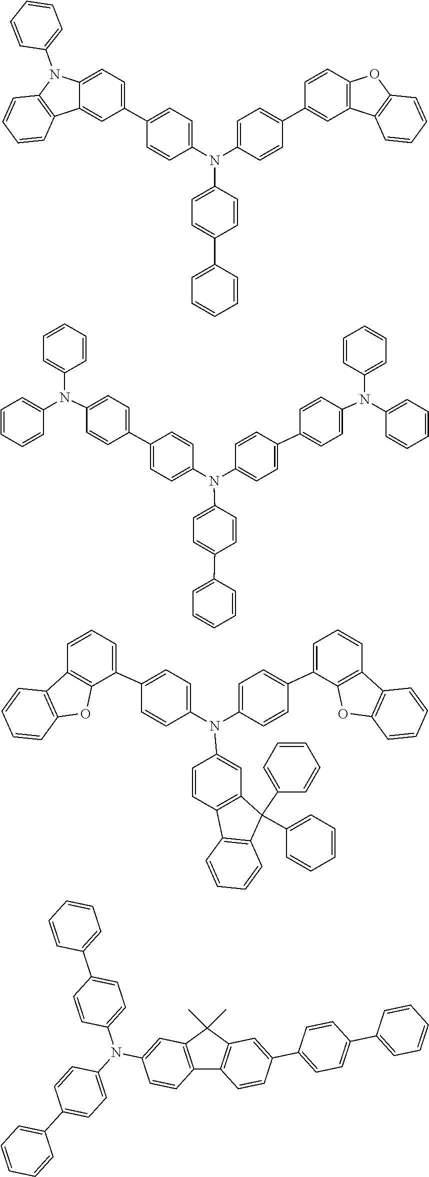 [SMILES: c1ccc(-c2ccc(N(c3ccc(-c4ccc5oc6ccccc6c5c4)cc3)c3ccc(-c4ccc5c(c4)c4ccccc4n5-c4ccccc4)cc3)cc2)cc1 ; c1ccc(-c2ccc(N(c3ccc(-c4ccc(N(c5ccccc5)c5ccccc5)cc4)cc3)c3ccc(-c4ccc(N(c5ccccc5)c5ccccc5)cc4)cc3)cc2)cc1 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1 ; CC1(C)c2cc(-c3ccc(-c4ccccc4)cc3)ccc2-c2ccc(N(c3ccc(-c4ccccc4)cc3)c3ccc(-c4ccccc4)cc3)cc21]

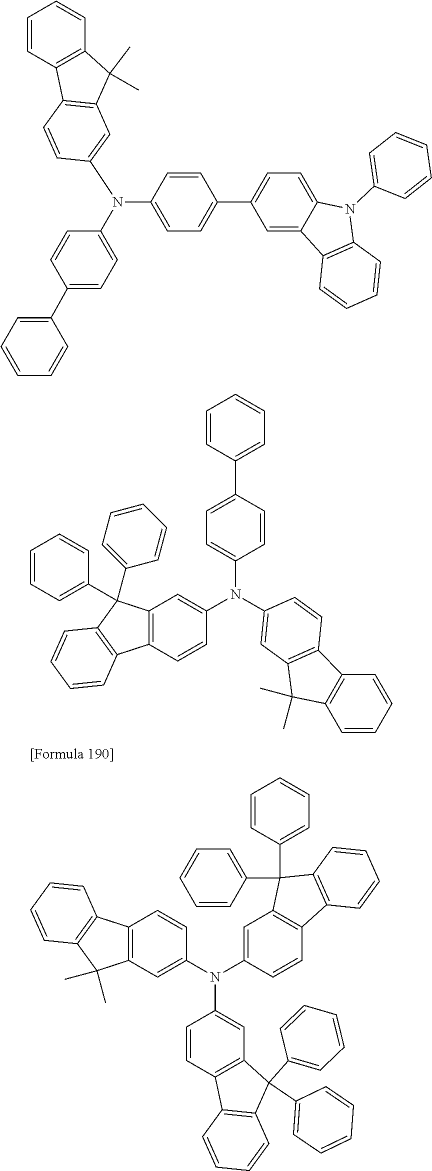 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21]

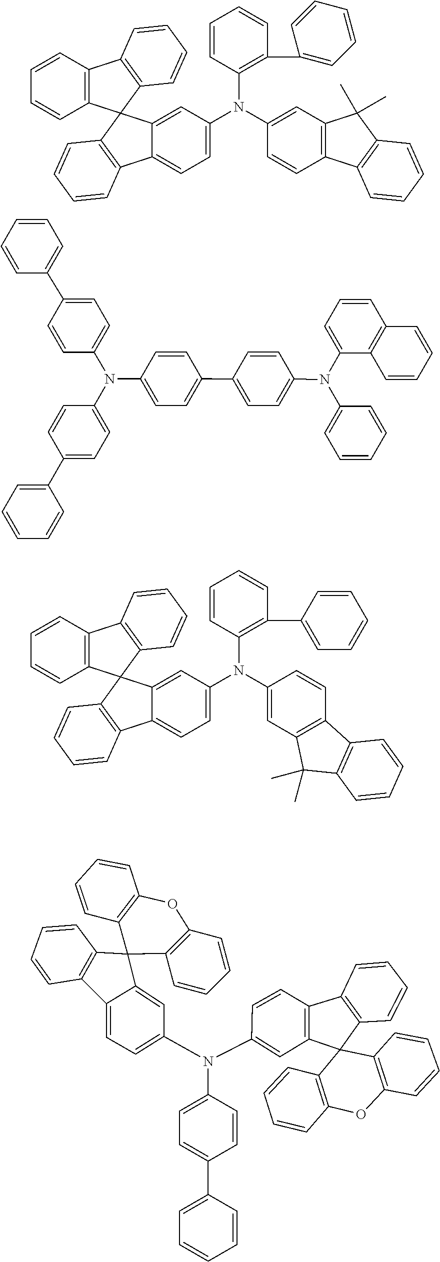

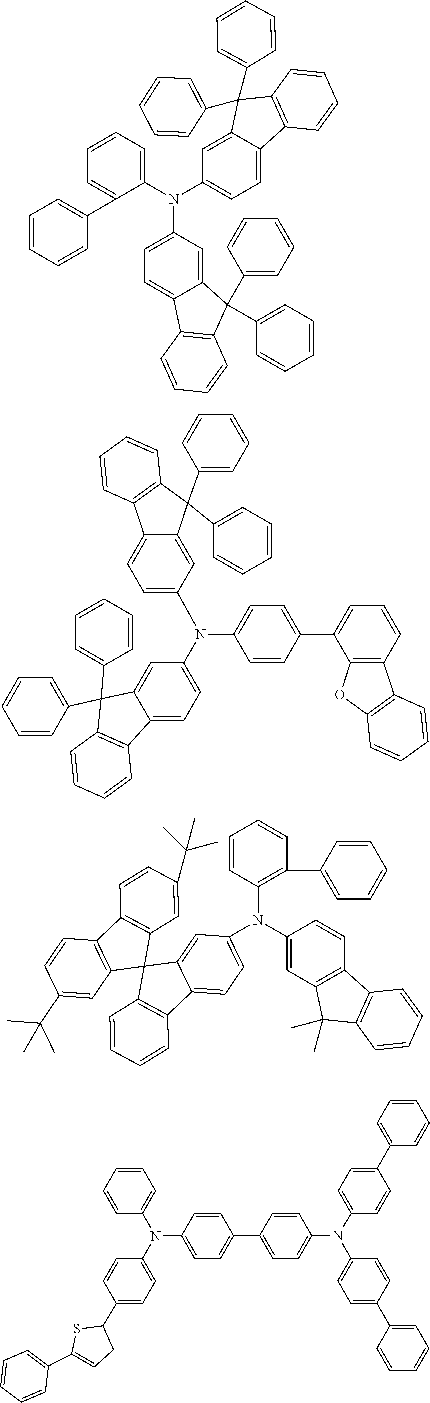

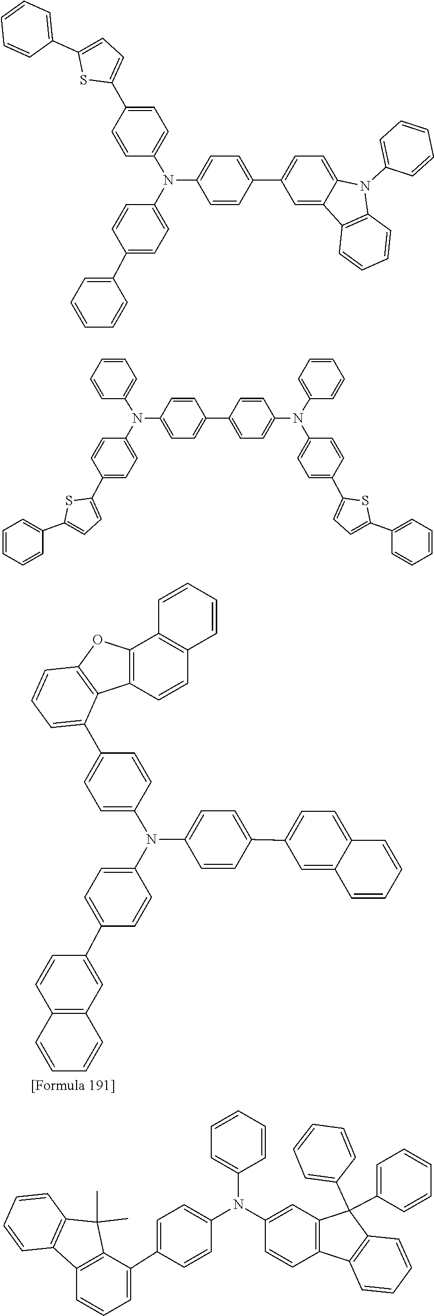

In an exemplary arrangement of the organic EL device of the exemplary embodiment, the compound (third hole transporting zone material) contained in the third anode side organic layer is preferably at least one compound selected from compounds listed below.

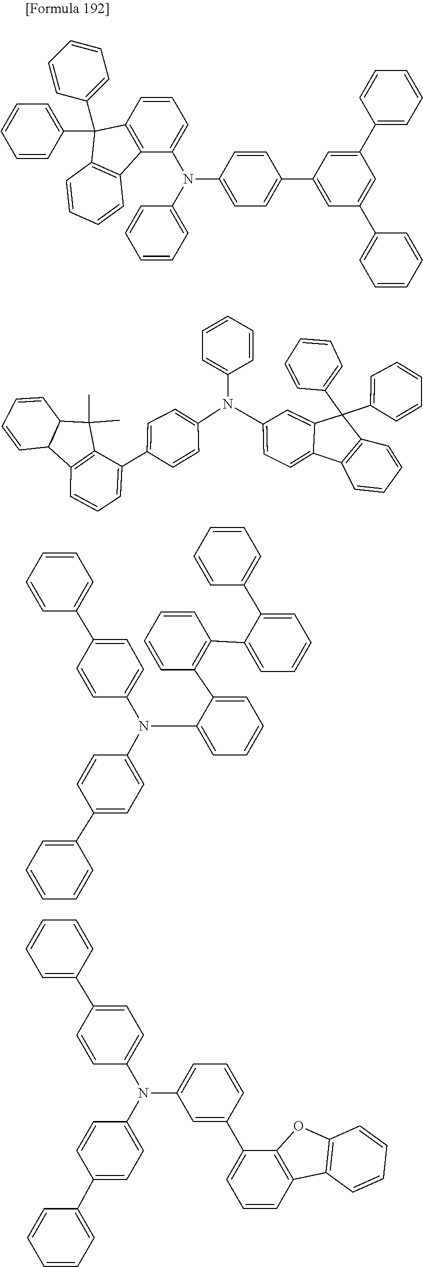

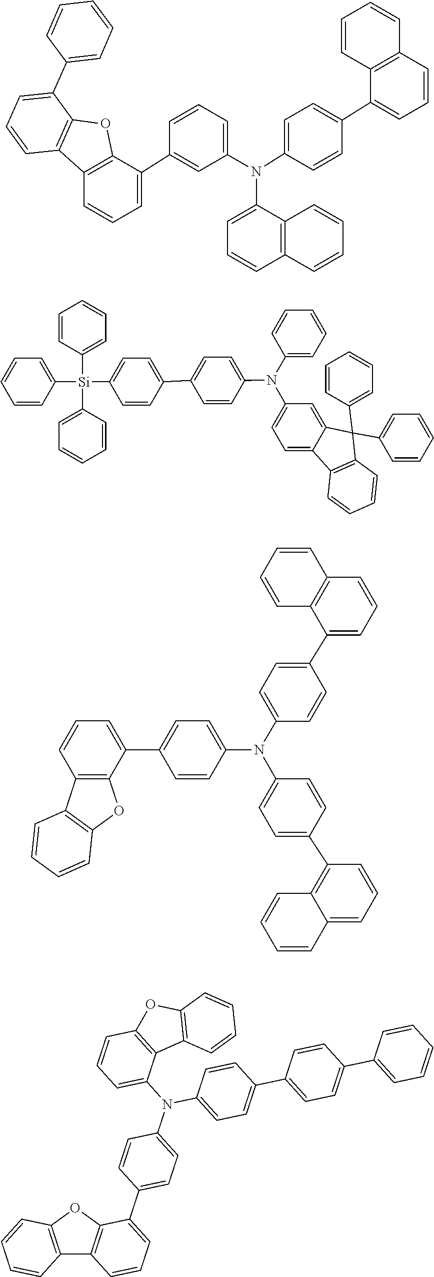

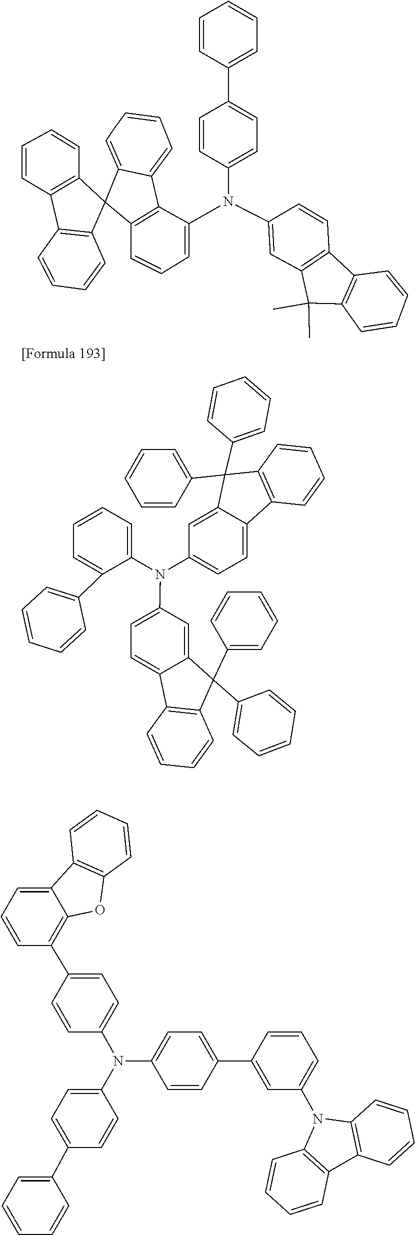 [SMILES: CC1(C)c2ccccc2-c2ccc(N(c3ccc(-c4ccccc4)cc3)c3cccc4c3C3=CC=CCC=C3C43c4ccccc4-c4ccccc43)cc21 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

The compounds exemplified as the compound contained in any one of the first anode side organic layer, the second anode side organic layer, and the third anode side organic layer sometimes overlap with examples of compounds for other layers. In the exemplary embodiment, different compounds can be appropriately selected from the listed compounds as the compounds usable for the first anode side organic layer, the second anode side organic layer, and the third anode organic layer.

### Emitting Region

### First Emitting Layer

In an exemplary arrangement of the organic EL device according to the exemplary embodiment, the first emitting layer contains the first host material. The first host material, which is not particularly limited, may be, for instance, a compound selected from the group consisting of a compound represented by a formula (H1) described later and a first compound described later.

In an exemplary arrangement of the organic EL device according to the exemplary embodiment, the first emitting layer contains a first emitting compound. The first emitting layer, which is not particularly limited, may be, for instance, a compound selected from the group consisting of a compound represented by a formula (6), a third compound, and a fourth compound which are described later.

In an exemplary arrangement of the organic EL device according to the exemplary embodiment, the first emitting layer contains the first host material and the first emitting compound.

The first emitting compound preferably emits light having a maximum peak wavelength of 500 nm or less, more preferably emits light having a maximum peak wavelength in a range from 430 nm to 480 nm. The first emitting compound is preferably a fluorescent compound that emits fluorescence having a maximum peak wavelength of 500 nm or less, more preferably a fluorescent compound that emits fluorescence having a maximum peak wavelength in a range from 430 nm to 480 nm. In an exemplary arrangement of the organic EL device according to the exemplary embodiment, the first emitting layer contains the first host material and the first emitting compound that emits light having the maximum peak wavelength of 500 nm or less.

In an exemplary arrangement of the organic EL device of the exemplary embodiment, the first emitting compound has a full width at half maximum in a range from 1 nm to 30 nm at a maximum peak.

In an exemplary arrangement of the organic EL device of the exemplary embodiment, the first emitting compound is a compound containing no azine ring structure in a molecule.

In an exemplary arrangement of the organic EL device according to the exemplary embodiment, the first emitting compound is preferably not a boron-containing complex, more preferably not a complex.

For instance, examples of a fluorescent compound that emits blue fluorescence and is usable for the first emitting layer include a pyrene derivative, styrylamine derivative, chrysene derivative, fluoranthene derivative, fluorene derivative, diamine derivative, and triarylamine derivative.

Herein, the blue light emission refers to light emission in which a maximum peak wavelength of emission spectrum is in a range from 430 nm to 500 nm.

In an exemplary arrangement of the organic EL device of the exemplary embodiment, when the emitting region includes two or more emitting layers, the two or more emitting layers are each a fluorescent emitting layer.

In other words, in an exemplary arrangement of the organic EL device of the exemplary embodiment, the emitting layers contained in the emitting region are each a fluorescent emitting layer.

In an exemplary arrangement of the organic EL device according to the exemplary embodiment, the first emitting layer does not contain a metal complex. Moreover, in an exemplary arrangement of the organic EL device according to the exemplary embodiment, the first emitting layer does not contain a boron-containing complex.

In an exemplary arrangement of the organic EL device according to the exemplary embodiment, the first emitting layer not contain a phosphorescent material (dopant material).

In an exemplary arrangement of the organic EL device according to the exemplary embodiment, the first emitting layer not contain a heavy metal complex and a phosphorescent rare-earth metal complex. Examples of the heavy-metal complex herein include iridium complex, osmium complex, and platinum complex.

A measurement method of the maximum peak wavelength of the compound is as follows. A toluene solution of a measurement target compound at a concentration of 5 μmol/L is prepared and put in a quartz cell. An emission spectrum (ordinate axis: luminous intensity, abscissa axis: wavelength) of each of the samples is measured at a normal temperature (300K). The emission spectrum can be measured using a spectrophotometer (machine name: F-7000) produced by Hitachi High-Tech Science Corporation. It should be noted that the apparatus for measuring the emission spectrum is not limited to the apparatus used herein.

A peak wavelength of the emission spectrum exhibiting the maximum luminous intensity is defined as the maximum peak wavelength. Herein, the maximum peak wavelength of fluorescence is occasionally referred to as a maximum fluorescence peak wavelength (FL-peak).

In an emission spectrum of the first emitting compound, where a peak exhibiting a maximum luminous intensity is defined as a maximum peak and a height of the maximum peak is defined as 1, heights of other peaks appearing in the emission spectrum are preferably less than 0.6. It should be noted that the peaks in the emission spectrum are defined as local maximum values.

Moreover, in the emission spectrum of the first emitting compound, the number of peaks is preferably less than three.

In an exemplary arrangement of the organic EL device according to the exemplary embodiment, the first emitting layer preferably contains 0.5 mass % or more of the first emitting compound with respect to the total mass of the first emitting layer.

The first emitting layer contains the first emitting compound preferably at 10 mass % or less, more preferably at 7 mass % or less, and still more preferably at 5 mass % less with respect to the total mass of the first emitting layer.

Herein, the “host material” refers to, for instance, a material that accounts for “50 mass % or more of the layer.”

In an exemplary arrangement of the organic EL device according to the above exemplary embodiment, the first emitting layer contains the first host material preferably at 60 mass % or more, more preferably at 70 mass % or more, still more preferably at 80 mass % or more, still further more preferably at 90 mass % or more, and yet still further more preferably at 95 mass % or more, with respect to the total mass of the first emitting layer.

The first emitting layer preferably contains the first host material at 99.5 mass % or less with respect to the total mass of the first emitting layer.

When the first emitting layer contains the first host material and the first emitting compound, the upper limit of a total of the content ratios of the first host material and the first emitting compound is 100 mass %.

In the organic EL device according to the above exemplary embodiment, the first emitting layer may further contain any other material than the first host material and the first emitting compound.

The first emitting layer may contain a single type of the first host material or may contain two or more types of the first host material. The first emitting layer may contain a single type of the first emitting compound or may contain two or more types of the first emitting compound.

### First Host Material

In an exemplary arrangement of the organic EL device of the exemplary embodiment, the first host material has at least one deuterium atom.

In an exemplary arrangement of the organic EL device of the exemplary embodiment, the first host material has no deuterium atom.

### Compound Represented by Formula (H1)

In an exemplary arrangement of the organic EL device of the exemplary embodiment, the first host material is a compound represented by a formula (H1) below.

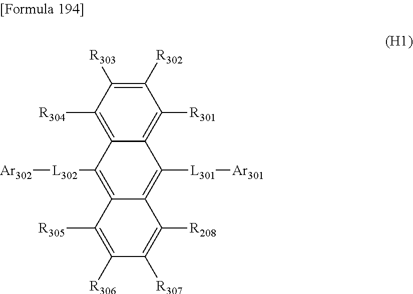

In the formula (H1): R₃₀₁ to R₃₀₈ are each independently a hydrogen atom, or a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, L₃₀₁ and L₃₀₂ are each independently a single bond, a substituted or unsubstituted arylene group having 6 to 50 ring carbon atoms, or a substituted or unsubstituted divalent heterocyclic group having 5 to 50 ring atoms; and

Ar₃₀₁ and Ar₃₀₂ are each independently a substituted or unsubstituted aryl group having 6 to 50 ring carbon atoms, a substituted or unsubstituted heterocyclic group having 5 to 50 ring atoms.

In a compound represented by the formula (H1), R₉₀₁, R₉₀₂, R₉₀₃, R₉₀₄, R₉₀₅, R₉₀₆, R₉₀₇, R₈₀₁ and R₈₀₂ are each independently a hydrogen atom, or a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary arrangement of the organic EL device of the exemplary embodiment, Ar₃₀₁ and Ar₃₀₂ are each independently a phenyl group, naphthyl group, phenanthryl group, biphenyl group, terphenyl group, diphenylfluorenyl group, dimethylfluorenyl group, benzodiphenylfluorenyl group, benzodimethylfluorenyl group, dibenzofuranyl group, dibenzothienyl group, naphthobenzofuranyl group, or naphthobenzothienyl group.

In an exemplary arrangement of the organic EL device of the exemplary embodiment, L₃₀₁ is a single bond, or an unsubstituted arylene group having 6 to 22 ring carbon atoms; and Ar₃₀₁ is a substituted or unsubstituted aryl group having 6 to 22 ring carbon atoms.

In an exemplary arrangement of the organic EL device of the exemplary embodiment, R₃₀₁ to R₃₀₈ are each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

In an exemplary arrangement of the organic EL device of the exemplary embodiment, R₃₀₁ to R₃₀₈ are each a hydrogen atom.

In an exemplary arrangement of the organic EL device of the exemplary embodiment, L₃₀₂ is a single bond and Ar₃₀₂ is an unsubstituted phenyl group.

In an exemplary arrangement of the organic EL device of the exemplary embodiment, L₃₀₂ is a single bond and Ar₃₀₂ is an unsubstituted 2-naphthyl group.

In an exemplary arrangement of the organic EL device of the exemplary embodiment, L₃₀₂ is a single bond and Ar₃₀₂ is an unsubstituted 1-naphthyl group.

In an exemplary arrangement of the organic EL device of the exemplary embodiment, L₃₀₂ is an unsubstituted p-phenylene group and Ar₃₀₂ is an unsubstituted phenyl group.

In an exemplary arrangement of the organic EL device of the exemplary embodiment, L₃₀₂ is an unsubstituted m-phenylene group and Ar₃₀₂ is an unsubstituted phenyl group.

In an exemplary arrangement of the organic EL device of the exemplary embodiment, L₃₀₂ is an unsubstituted o-phenylene group and Ar₃₀₂ is an unsubstituted phenyl group.

In an exemplary arrangement of the organic EL device of the exemplary embodiment, L₃₀₂ is an unsubstituted p-phenylene group and Ar₃₀₂ is an unsubstituted 1-naphthyl group.

In an exemplary arrangement of the organic EL device of the exemplary embodiment, L₃₀₂ is an unsubstituted p-phenylene group and Ar₃₀₂ is an unsubstituted 2-naphthyl group.

In an exemplary arrangement of the organic EL device of the exemplary embodiment, L₃₀₂ is an unsubstituted 1.4-naphthalenediyl group and Ar₃O₂ is an unsubstituted phenyl group.

In an exemplary arrangement of the organic EL device of the exemplary embodiment, L₃₀₂ is an unsubstituted m-phenylene group and Ar₃O₂ is an unsubstituted 2-naphthyl group.

In an exemplary arrangement of the organic EL device of the exemplary embodiment, R₃₀₁ to R₃₀₈ each independently have at least one deuterium atom. In an exemplary arrangement of the organic EL device of the exemplary embodiment, L₃₀₁, L₃₀₂, Ar₃₀₁, and Ar₃₀₂ each independently have at least one deuterium atom.

In an exemplary arrangement of the organic EL device of the exemplary embodiment, the first host material is a compound represented by a formula (H10) below.

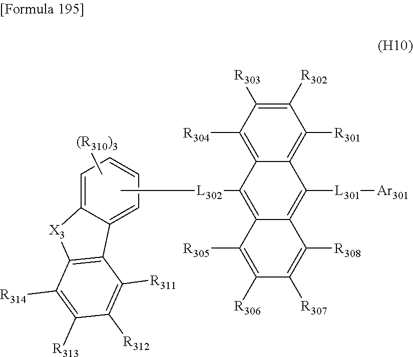

In the formula (H10): Ar₃₀₁, R₃₀₁ to R₃₀₈, L₃₀₁, and L₃₀₂ each independently represent the same as Ar₃₀₁, R₃₀₁ to R₃₀₈, L₃₀₁, and L₃₀₂ in the formula (H1);
X₃ is an oxygen atom or a sulfur atom;
at least one combination of adjacent two or more of a plurality of R₃₁₀ are mutually bonded to form a substituted or unsubstituted monocyclic ring, mutually bonded to form a substituted or unsubstituted fused ring, or not mutually bonded;
at least one combination of adjacent two or more of R₃₁₁ to R₃₁₄ are mutually bonded to form a substituted or unsubstituted monocyclic ring, or mutually bonded to form a substituted or unsubstituted fused ring; and
R₃₁₀ to R₃₁₄ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms. In the compound represented by the formula (H10), R₉₀₁, R₉₀₂, R₉₀₃, R₉₀₄, R₉₀₅, R₉₀₆, and R₉₀₇ each independently represent the same as R₉₀₁, R₉₀₂, R₉₀₃, R₉₀₄, R₉₀₅, R₉₀₆, and R₉₀₇ in the formula (H1).

In an exemplary arrangement of the organic EL device of the exemplary embodiment, at least one combination of adjacent two or more of R₃₁₁ to R₃₁₄ in the formula (H10) are bonded to each other to form a substituted or unsubstituted benzene ring.

In an exemplary arrangement of the organic EL device of the exemplary embodiment, R₃₀₁ to R₃₀₈ each independently have at least one deuterium atom. In an exemplary arrangement of the organic EL device of the exemplary embodiment, L₃₀₁, L₃₀₂, Ar₃₀₁, and R₃₁₁ to R₃₁₄ each independently have at least one deuterium atom.

In an exemplary arrangement of the organic EL device of the exemplary embodiment, the first host material is a compound represented by a formula (H31), (H32) or (H33) below.

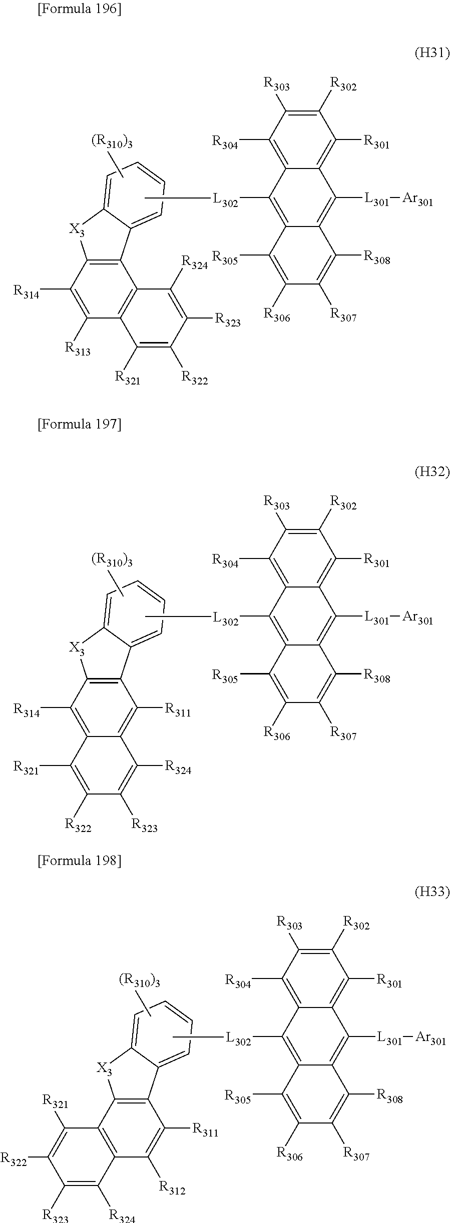

In the formulae (H31), (H32), and (H33): X₃, R₃₀₁ to R₃₀₈, R₃₁₀ to R₃₁₄, L₃₀₁, L₃₀₂, and Ar₃₀₁ each independently represent the same as X₃, R₃₀₁ to R₃₀₈, R₃₁₀ to R₃₁₄, L₃₀₁, L₃₀₂, and Ar₃₀₁ in the formula (H10); and
R₃₂₁ to R₃₂₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In an exemplary arrangement of the organic EL device of the exemplary embodiment, the first host material is a compound represented by a formula (H301) or (H302) below.

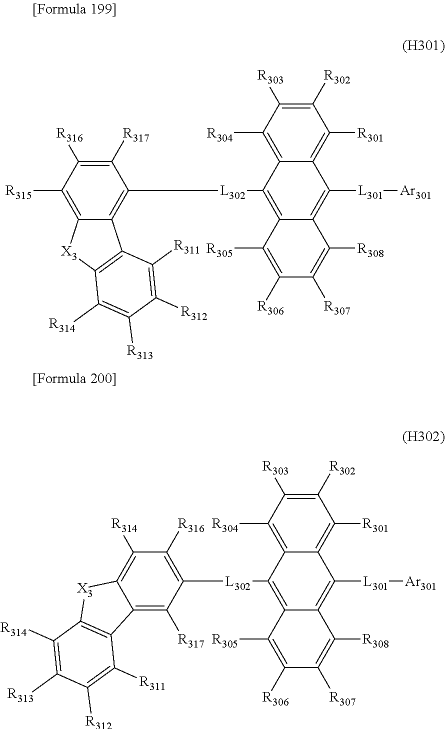

In the formulae (H301) and (H302): X₃, R₃₀₁ to R₃₀₈, R₃₁₁ to R₃₁₄, L₃₀₁, L₃₀₂, and Ar₃₀₁ each independently represent the same as X₃, R₃₀₁ to R₃₀₈, R₃₁₁ to R₃₁₄, L₃₀₁, L₃₀₂, and Ar₃₀₁ in the formula (H10);
at least one combination of adjacent two or more of R₃₁₅ to R₃₁₇ are mutually bonded to form a substituted or unsubstituted monocyclic ring, mutually bonded to form a substituted or unsubstituted fused ring, or not mutually bonded; and
R₃₁₅ to R₃₁₇ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In an exemplary arrangement of the organic EL device of the exemplary embodiment, the first host material is a compound represented by a formula (H311), (H312), (H321), (H322), (H331), or (H332) below.

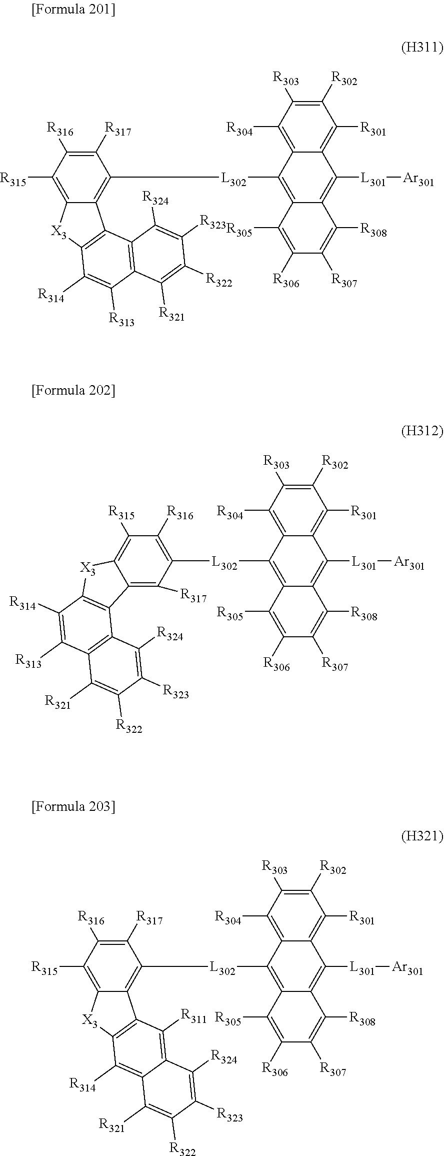

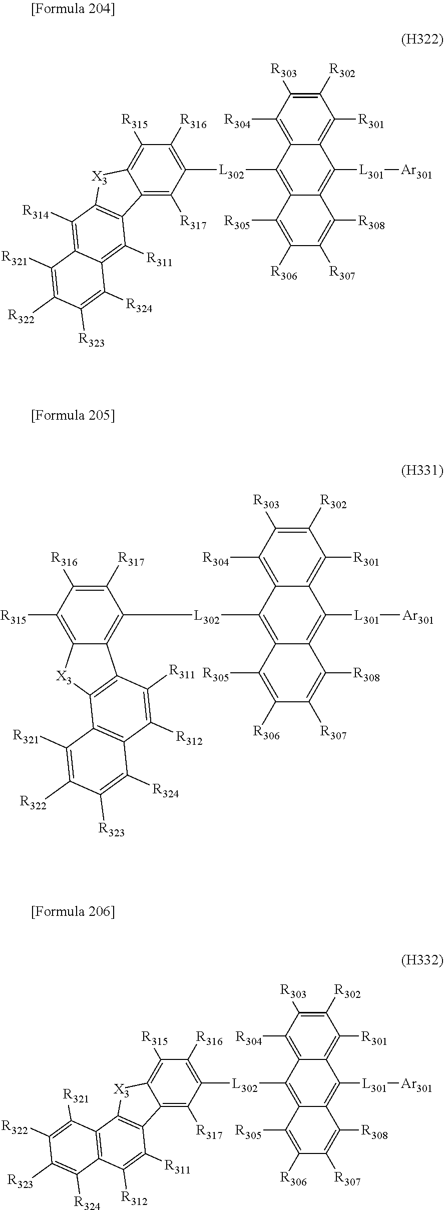

In the formulae (H311), (H312), (H321), (H322), (H331), and (H332): X₃, R₃₀₁ to R₃₀₈, L₃₀₁, L₃₀₂, and Ar₃₀₁ each independently represent the same as X₃, R₃₀₁ to R₃₀₈, L₃₀₁, L₃₀₂, and Ar₃O₁ in the formula (H10); and
R₃₁₁ to R₃₁₇ and R₃₂₁ to R₃₂₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In an exemplary arrangement of the organic EL device of the exemplary embodiment, L₃₀₁ and L₃₀₂ of the first host material are each independently a single bond or a substituted or unsubstituted arylene group having 6 to 14 ring carbon atoms.

In an exemplary arrangement of the organic EL device of the exemplary embodiment, L₃₀₁ and L₃₀₂ of the first host material are each independently a single bond, a substituted or unsubstituted phenylene group, or a substituted or unsubstituted naphthylene group.

In an exemplary arrangement of the organic EL device of the exemplary embodiment, L₃₀₁ and L₃₀₂ of the first host material are each a single bond.

In an exemplary arrangement of the organic EL device of the exemplary embodiment, the first host material is a compound represented by a formula (H313), (H314), (H323), (H324), (H333), or (H334) below.

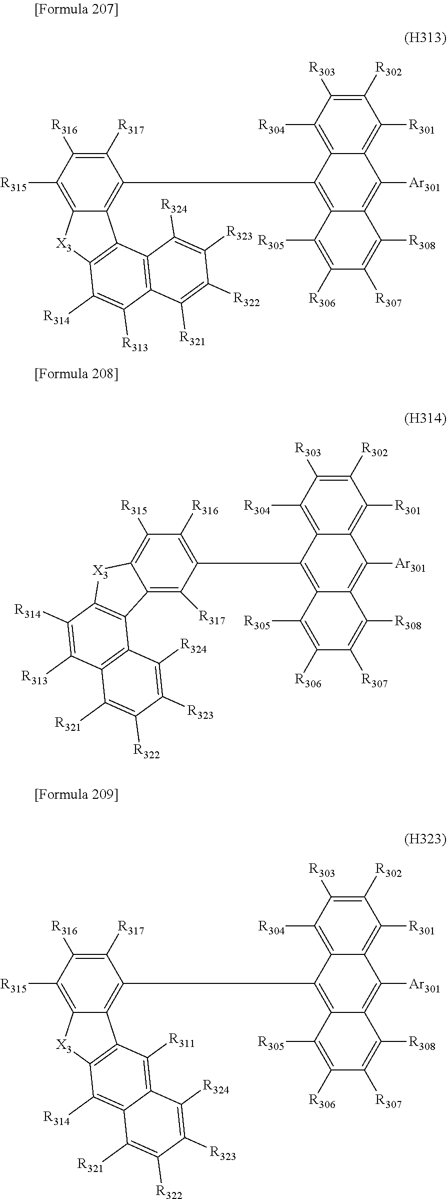

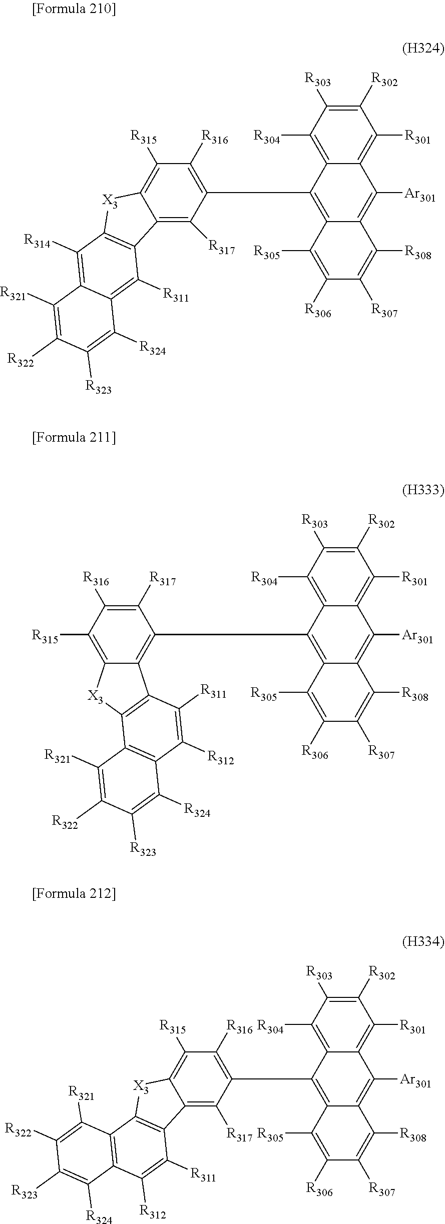

In the formulae (H313), (H314), (H323), (H324), (H333), and (H334): X₃, R₃₀₁ to R₃₀₈, and Ar₃₀₁ each independently represent the same as X₃, R₃₀₁ to R₃₀₈, and Ar₃₀₁ in the formula (H10); and
R₃₁₁ to R₃₁₇ and R₃₂₁ to R₃₂₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In an exemplary arrangement of the organic EL Device of the exemplary embodiment, R₃₁₁ to R₃₁₇ and R₃₂₁ to R₃₂₄ of the first host material are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In an exemplary arrangement of the organic EL Device of the exemplary embodiment, R₃₁₁ to R₃₁₇ and R₃₂₁ to R₃₂₄ of the first host material are each independently a hydrogen atom, a substituted or unsubstituted alkyl group having 1 to 50 carbon atoms, or a substituted or unsubstituted aryl group having 6 to 50 ring carbon atoms.

In an exemplary arrangement of the organic EL device of the exemplary embodiment, Ar₃₀₁ of the first host material is a substituted or unsubstituted aryl group having 6 to 50 ring carbon atoms.

In an exemplary arrangement of the organic EL device of the exemplary embodiment, Ar₃₀₁ of the first host material is a compound represented by a formula (a1), (a2), (a3), or (a4) below.

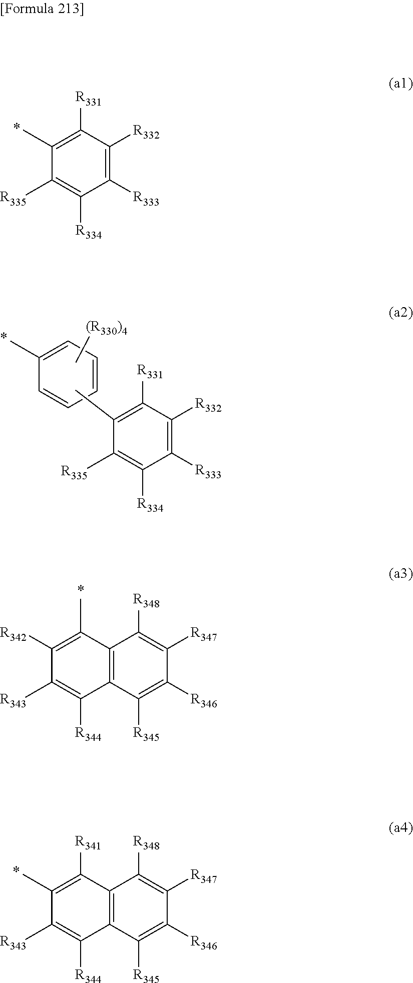

In the formulae (a1), (a2), (a3), and (a4):
at least one combination of adjacent two or more of R₃₃₀ to R₃₃₅ are mutually bonded to form a substituted or unsubstituted monocyclic ring, mutually bonded to form a substituted or unsubstituted fused ring, or not mutually bonded;
at least one combination of adjacent two or more of R₃₄₁ to R₃₄₈ are mutually bonded to form a substituted or unsubstituted monocyclic ring, mutually bonded to form a substituted or unsubstituted fused ring, or not mutually bonded;
R₃₃₀ to R₃₃₅ and R₃₄₁ to R₃₄₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
a plurality of R₃₃₀ are mutually the same or different; and
represents a bonding position to L₃₀₁.

In an exemplary arrangement of the organic EL device of the exemplary embodiment, Ar₃₀₁ of the first host material is a group represented by the formula (a1) or (a2).

In an exemplary embodiment of the organic EL device of the exemplary embodiment, R₃₃₀ to R₃₃₅ and R₃₄₁ to R₃₄₈ of the first host material are each a hydrogen atom.

In an exemplary arrangement of the organic EL device of the exemplary embodiment, X₃ of the first host material is an oxygen atom.

In an exemplary arrangement of the organic EL device of the exemplary embodiment, R₃₀₁ to R₃₀₈ of the first host material are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms.

In an exemplary arrangement of the organic EL device of the exemplary embodiment, R₃₀₁ to R₃₀₈ of the first host material are each independently a hydrogen atom, a substituted or unsubstituted alkyl group having 1 to 50 carbon atoms, or a substituted or unsubstituted aryl group having 6 to 50 ring carbon atoms.

In an exemplary arrangement of the organic EL device of the exemplary embodiment, R₃₀₁ to R₃₀₈ of the first host material are each a hydrogen atom.

### Compound Represented by Formula (H20)

In an exemplary arrangement of the organic EL device of the exemplary embodiment, the first host material is a compound represented by a formula (H20) below.

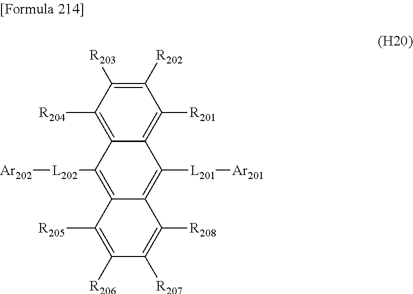

In the formula (H20): R₂₀₁ to R₂₀₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a group represented by a formula (H21) below.

[Formula 215]

-L₂₀₃-Ar₂₀₃ (H21)

In the formulae (H20) to (H21):
L₂₀₁, L₂₀₂, and L₂₀₃ are each independently a single bond, or a substituted or unsubstituted arylene group having 6 to 50 ring carbon atoms; and
Ar₂₀₁, Ar₂₀₂, and Ar₂₀₃ are each independently a substituted or unsubstituted aryl group having 6 to 50 ring carbon atoms.

In the formula (H20), R₉₀₁, R₉₀₂, R₉₀₃, R₉₀₄, R₉₀₅, R₉₀₆, and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of the organic EL device of the exemplary embodiment, Ar₂₀₁, Ar₂₀₂, and Ar₂₀₃ are each independently a phenyl group, naphthyl group, phenanthryl group, biphenyl group, terphenyl group, diphenylfluorenyl group, dimethylfluorenyl group, benzodiphenylfluorenyl group, benzodimethylfluorenyl group, dibenzofuranyl group, dibenzothienyl group, naphthobenzofuranyl group, or naphthobenzothienyl group.

In an exemplary arrangement of the organic EL device of the exemplary embodiment, R₂₀₁ to R₂₀₈ each independently have at least one deuterium atom.

In an exemplary arrangement of the organic EL device of the exemplary embodiment, L₂₀₁, L₂₀₂, L₂₀₃, Ar₂₀₁, Ar₂₀₂, and Ar₂₀₃ each independently have at least one deuterium atom.

In the organic EL device according to the exemplary embodiment, the compound represented by the formula (H20) is preferably a compound represented by a formula (201), a formula (202), a formula (203), a formula (204), a formula (205), a formula (206), a formula (207), a formula (208), or a formula (209) below.

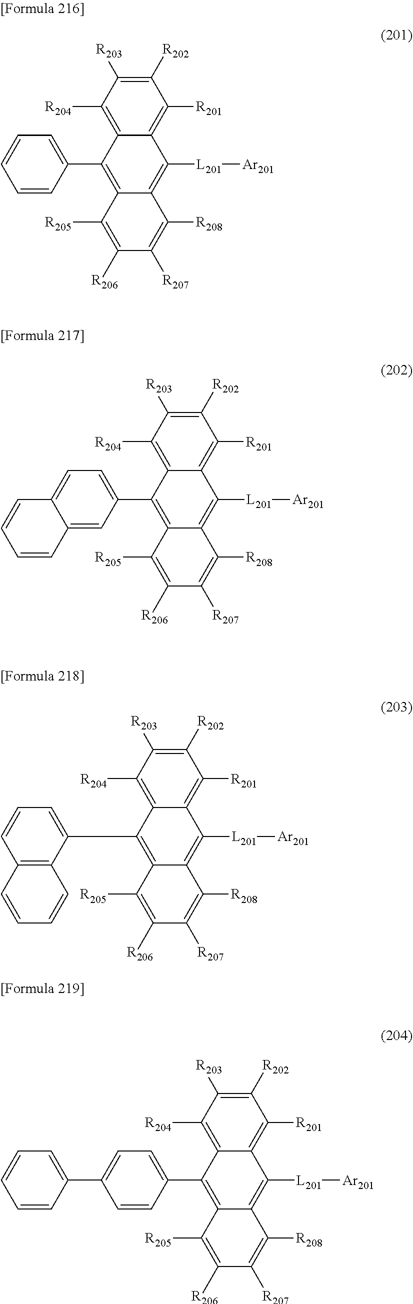

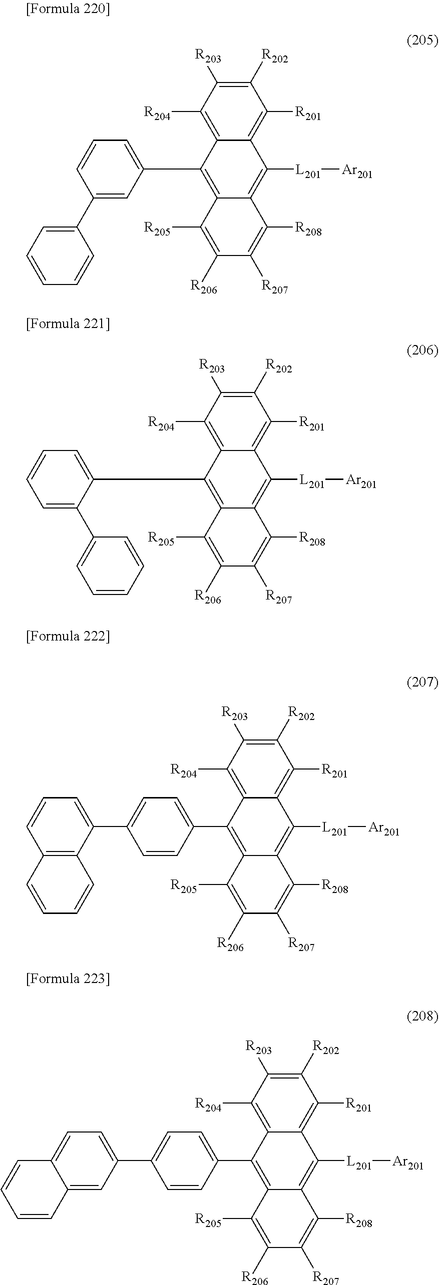

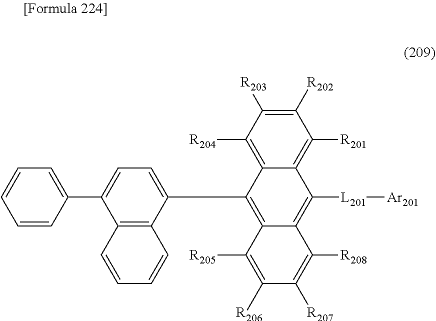

In the formulae (201) to (209): L₂₀₁ and Ar₂₀₁ respectively represent the same as L₂₀₁ and Ar₂₀₁ in the formula (H20); and R₂₀₁ to R₂₀₈ each independently represent the same as R₂₀₁ to R₂₀₈ in the formula (H20).

In the organic EL device according to the exemplary embodiment, the compound represented by the formula (H20) is preferably a compound represented by a formula (221), a formula (222), a formula (223), a formula (224), a formula (225), a formula (226), a formula (227), a formula (228), or a formula (229) below.

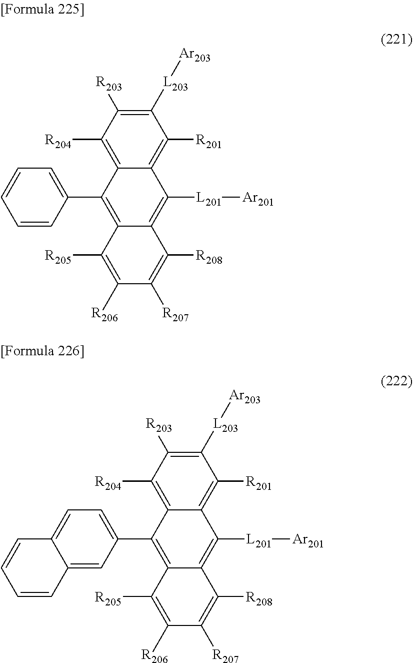

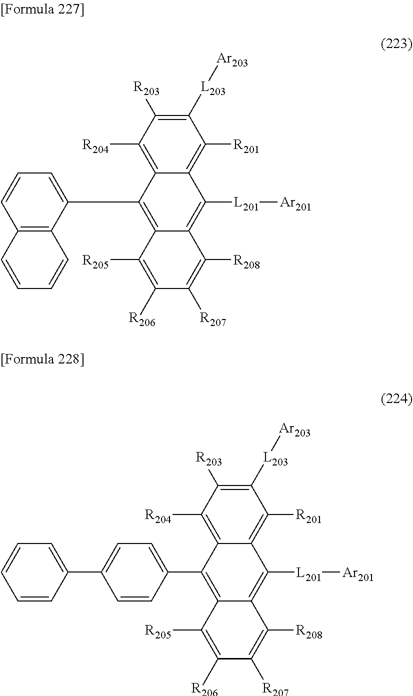

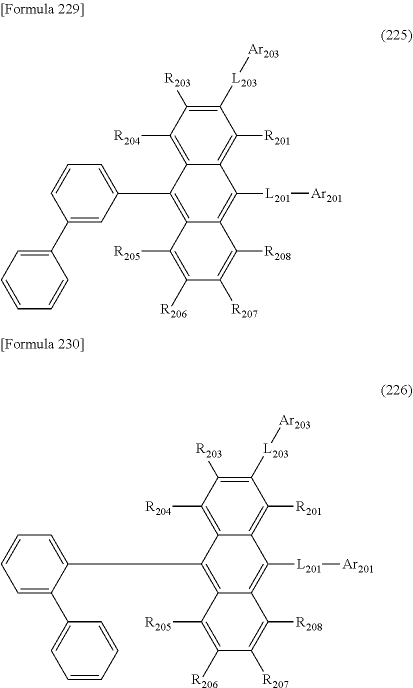

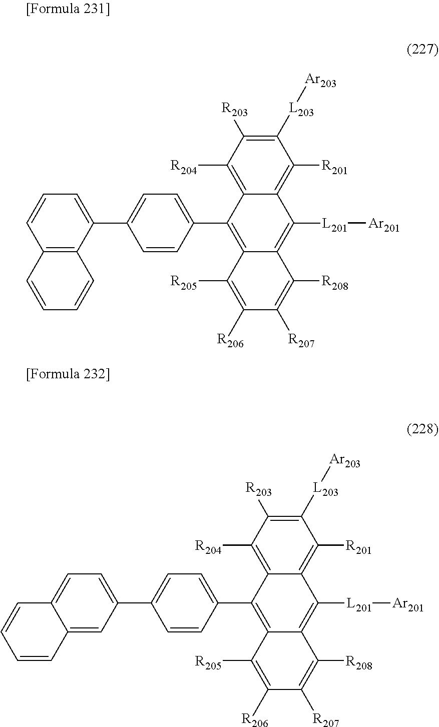

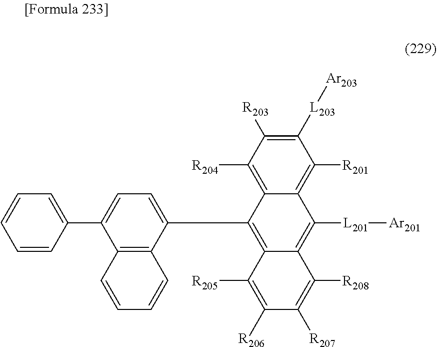

In the formulae (221), (222), (223), (224), (225), (226), (227), (228) and (229):
R₂₀₁ and R₂₀₃ to R₂₀₈ each independently represent the same as R₂₀₁ and R₂₀₃ to R₂₀₈ in the formula (H20);
L₂₀₁ and Ar₂₀₁ respectively represent the same as L₂₀₁ and Ar₂₀₁ in the formula (H20);
L₂₀₃ represents the same as L₂₀₃ in the formula (H21);
L₂₀₃ and L₂₀₁ are mutually the same or different;
Ar₂₀₃ represents the same as Ar₂₀₃ in the formula (H21); and
Ar₂₀₃ and Ar₂₀₁ are mutually the same or different.

In the organic EL device according to the exemplary embodiment, the compound represented by the formula (H20) is preferably a compound represented by a formula (241), a formula (242), a formula (243), a formula (244), a formula (245), a formula (246), a formula (247), a formula (248), or a formula (249) below.

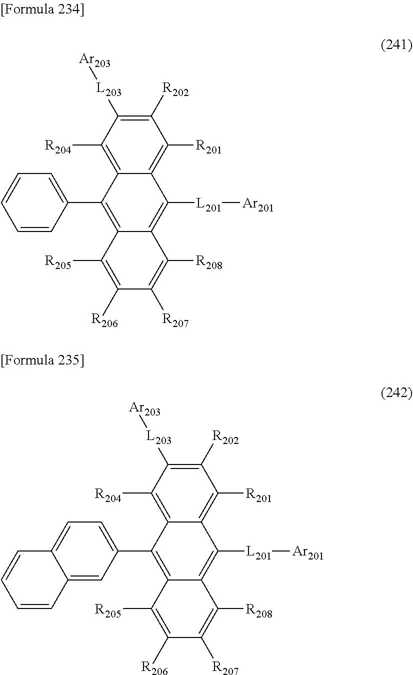

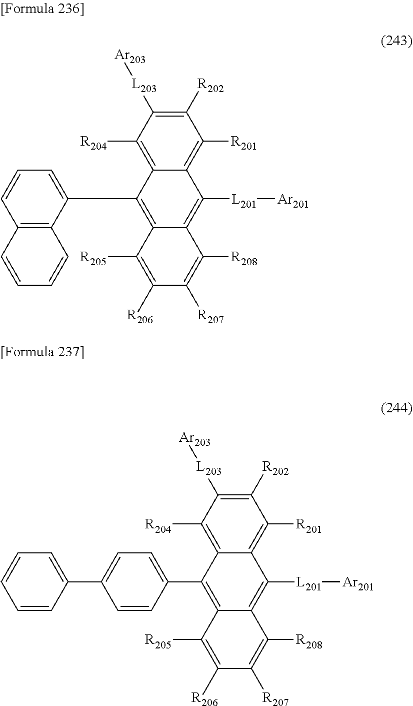

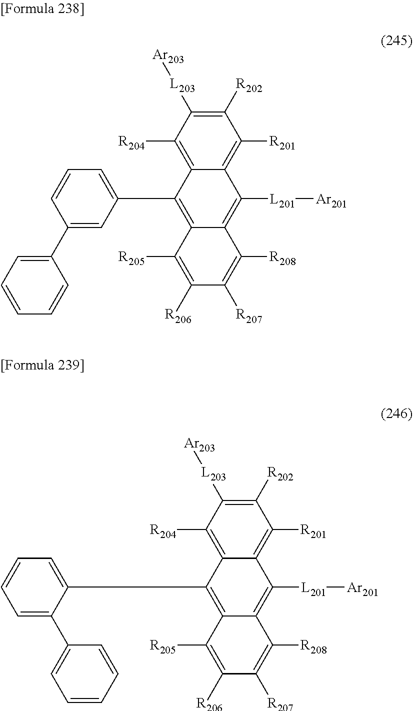

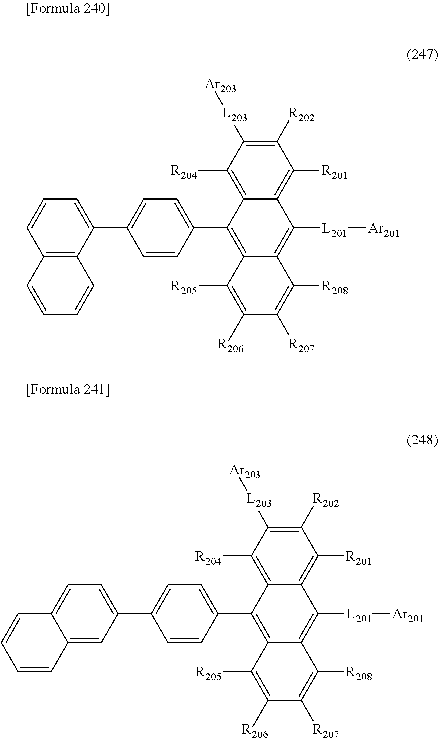

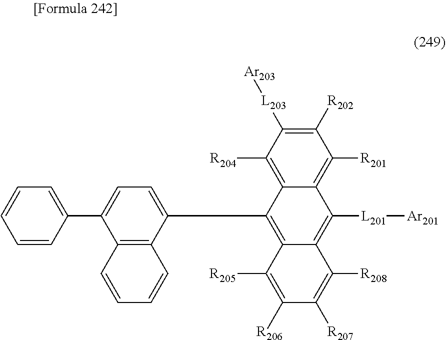

In the formulae (241), (242), (243), (244), (245), (246), (247), (248) and (249):
R₂₀₁, R₂₀₂ and R₂₀₄ to R₂₀₈ each independently represent the same as R₂₀₁, R₂₀₂ and R₂₀₄ to R₂₀₈ in the formula (H20);
L₂₀₁ and Ar₂₀₁ respectively represent the same as L₂₀₁ and Ar₂₀₁ in the formula (H20);
L₂₀₃ represents the same as L₂₀₃ in the formula (H21);
L₂₀₃ and L₂₀₁ are mutually the same or different;
Ar₂₀₃ represents the same as Ar₂₀₃ in the formula (H21); and
Ar₂₀₃ and Ar₂₀₁ are mutually the same or different.

In an exemplary arrangement of the organic EL device of the exemplary embodiment, R₂₀₁ to R₂₀₈ in the formula (H20) are each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

In an exemplary arrangement of the organic EL device of the exemplary embodiment, in the formula (H20), L₁₀₁ is a single bond or an unsubstituted arylene group having 6 to 22 ring carbon atoms and Ar₁₀₁ is a substituted or unsubstituted aryl group having 6 to 22 ring carbon atoms.

In an exemplary arrangement of the organic EL device of the exemplary embodiment, R₂₀₁ to R₂₀₈ that are substituents of an anthracene skeleton in the formula (H20) are preferably hydrogen atoms in terms of preventing inhibition of intermolecular interaction and inhibiting decrease in electron mobility. However, R₂₀₁ to R₂₀₈ may be a substituted or unsubstituted aryl group having 6 to 50 ring carbon atoms or a substituted or unsubstituted heterocyclic group having 5 to 50 ring atoms.

In an exemplary arrangement of the organic EL device of the exemplary embodiment, when the emitting region at least includes the first emitting layer containing the first host material and the second emitting layer containing the second host material, R₃₀₁ to R₃₀₈ that are substituents of an anthracene skeleton in the compound represented by the formula (H1) are preferably hydrogen atoms in terms of preventing inhibition of intermolecular interaction and inhibiting decrease in electron mobility. However, R₃₀₁ to R₃₀₈ may be a substituted or unsubstituted aryl group having 6 to 50 ring carbon atoms or a substituted or unsubstituted heterocyclic group having 5 to 50 ring atoms.

An exemplary arrangement of the organic EL device of the exemplary embodiment may include the anode, the first emitting layer, the second emitting layer, and the cathode in this order. However, the order of the first emitting layer and the second emitting layer may be inversed.

For instance, in a case where the second emitting layer and the first emitting layer are layered in this order from a side close to the anode and the first host material contained in the first emitting layer is a compound represented by the formula (H1), the following phenomenon may occur. Therefore, R₃₀₁ to R₃₀₈ in the formula (H1) are each preferably not a bulky substituent.

Assuming that R₃₀₁ to R₃₀₈ each are a bulky substituent such as an alkyl group and a cycloalkyl group, intermolecular interaction may be inhibited to decrease the electron mobility relative to that of the second host material, so that the relationship of μe(H1)>μe(H2) shown by a later-described numerical formula (Numerical Formula 3) may not be satisfied. In a case where a compound represented by the formula (H1) is used as the first host material in the first emitting layer, it can be expected that satisfying the relationship of μe(H1)>μe(H2) inhibits a decrease in a recombination ability between holes and electrons in the second emitting layer and a decrease in luminous efficiency. It should be noted that substituents, namely, a haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group are likely to be bulky, and an alkyl group and cycloalkyl group are likely to be further bulky.

In the compound represented by the formula (H1), R₃₀₁ to R₃₀₈, which are the substituents on the anthracene skeleton, are each preferably not a bulky substituent and preferably not an alkyl group and cycloalkyl group. More preferably, R₃₀₁ to R₃₀₈ are each not an alkyl group and cycloalkyl group. Still more preferably, R₃₀₁ to R₃₀₈ are each not an alkyl group, cycloalkyl group haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group.

In the formula (H1), examples of the substituent for the “substituted or unsubstituted” group on R₃₀₁ to R₃₀₈ also preferably do not include the above-described substituents that are likely to be bulky, especially a substituted or unsubstituted alkyl group and a substituted or unsubstituted cycloalkyl group. When examples of the substituent for the “substituted or unsubstituted” group on R₃₀₁ to R₃₀₈ do not include a substituted or unsubstituted alkyl group and a substituted or unsubstituted cycloalkyl group, inhibition of intermolecular interaction to be caused by presence of a bulky substituent such as an alkyl group and a cycloalkyl group can be prevented, thereby preventing a decrease in the electron mobility. Moreover, when the compound described above is used as the first host material in the first emitting layer, a decrease in a recombination ability between holes and electrons in the second emitting layer and a decrease in the luminous efficiency can be inhibited.

Further preferably, R₃₀₁ to R₃₀₈ that are the substituents on the anthracene skeleton are not bulky substituents and R₃₀₁ to R₃₀₈ as substituents are unsubstituted. Assuming that R₃₀₁ to R₃₀₈ that are the substituents on the anthracene skeleton are not bulky substituents and substituents are bonded to R₃₀₁ to R₃₀₈ that are not bulky substituents, the substituents bonded to R₃₀₁ to R₃₀₈ are preferably not bulky substituents; and the substituents bonded to R₂₀₁ to R₂₀₈ serving as substituents are preferably not an alkyl group and cycloalkyl group, more preferably not an alkyl group, cycloalkyl group, haloalkyl group, alkenyl group, alkynyl group, group represented by —Si(R₉₀₁)(R₉₀₂)(R₉₀₃), group represented by —O—(R₉₀₄), group represented by —S—(R₉₀₅), group represented by —N(R₉₀₆)(R₉₀₇), aralkyl group, group represented by —C(═O)R₈₀₁, group represented by —COOR₈₀₂, halogen atom, cyano group, and nitro group.

In the first host material, the groups specified to be “substituted or unsubstituted” are each preferably an “unsubstituted” group.

In an exemplary arrangement of the organic EL device of the exemplary embodiment, the first emitting layer contains the compound represented by the formula (H10). The compound represented by the formula (H10) has at least one deuterium atom or does not have.

In an exemplary arrangement of the organic EL device of the exemplary embodiment, the first emitting layer contains the compound represented by the formula (H20). The compound represented by the formula (H20) has at least one deuterium atom or does not have.

In an exemplary arrangement of the organic EL device of the exemplary embodiment, the first emitting layer contains the compound represented by the formula (H10) and the compound represented by the formula (H20) as the first host material. In this arrangement, at least one of the compound represented by the formula (H10) or the compound represented by the formula (H20) preferably has at least one deuterium atom.

In an exemplary arrangement of the organic EL device of the exemplary embodiment, when the first emitting layer contains the compound represented by the formula (H10) and the compound represented by the formula (H20) as the first host material, the compound represented by the formula (H10) does not substantially contain a deuterium atom and the compound represented by the formula (H20) contains at least one deuterium atom.

In an exemplary arrangement of the organic EL device of the exemplary embodiment, when the first emitting layer contains the compound represented by the formula (H10) and the compound represented by the formula (H20) as the first host material, the compound represented by the formula (H20) does not substantially contain a deuterium atom and the compound represented by the formula (H10) does not contain at least one deuterium atom.

Here, that “the compound does not substantially contain a compound having a deuterium atom” means that the compound does not contain a deuterium atom at all or the compound is allowed to contain a deuterium atom in a natural abundance. For instance, the natural abundance of a deuterium atom is 0.015% or less.

### Production Method of First Host Material

The first host material can be produced by a known method. The first host material can also be produced based on a known method through a known alternative reaction using a known material(s) tailored for the target compound.

### Specific Examples of First Host Material

Specific examples of the first host material include the following compounds. It should however be noted that the invention is not limited to the specific examples of the first host material.

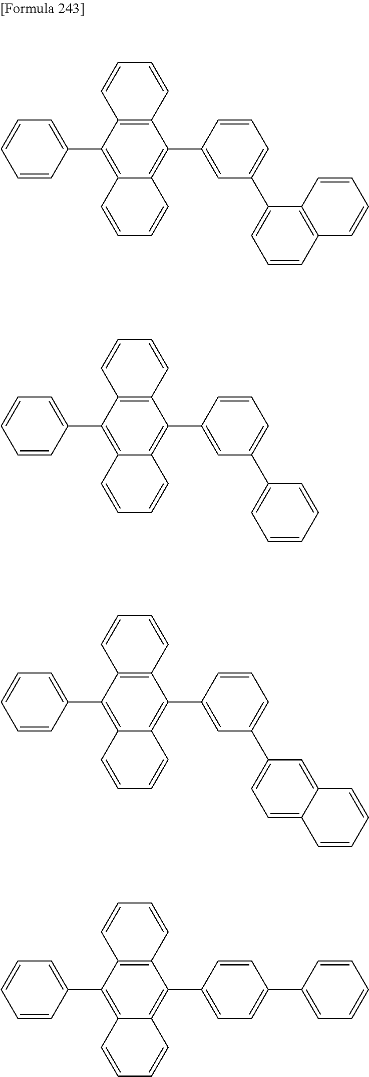

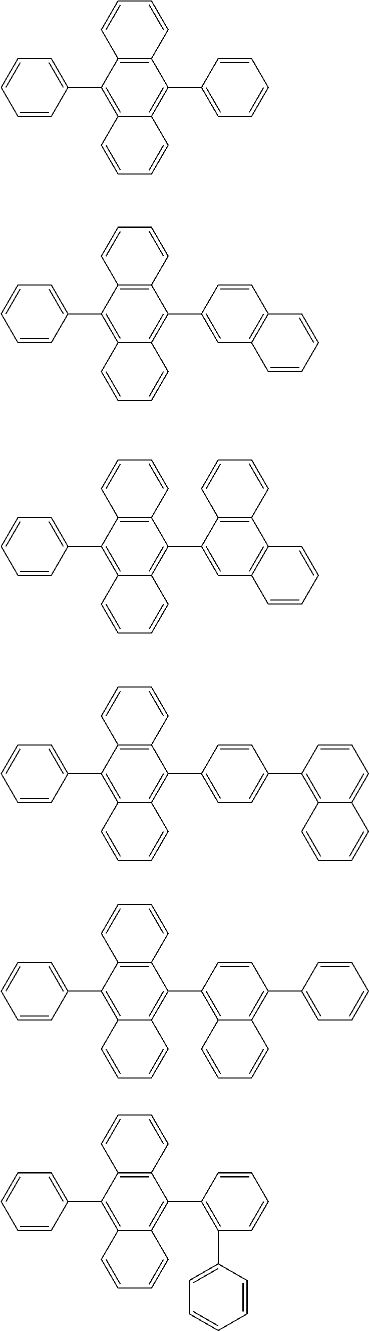

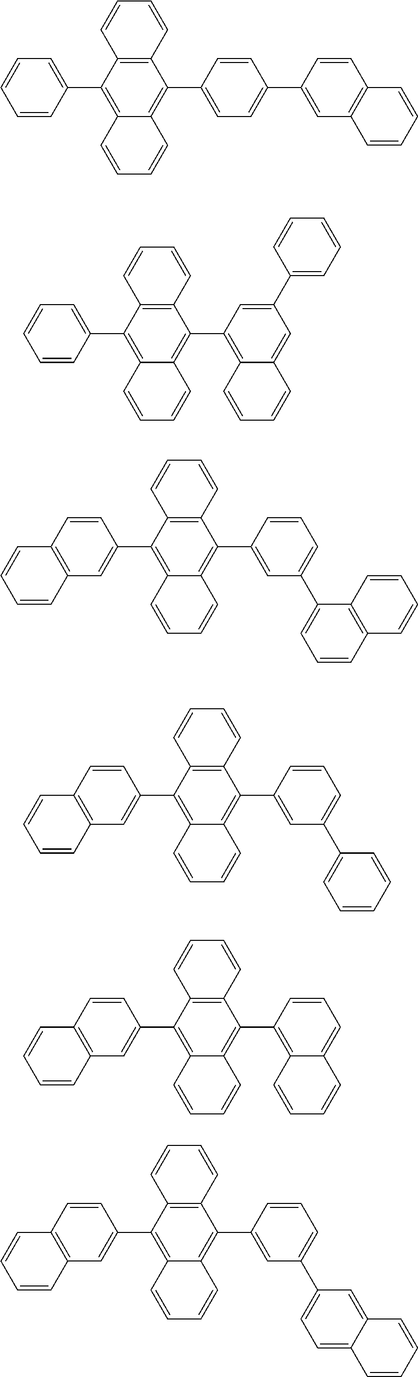

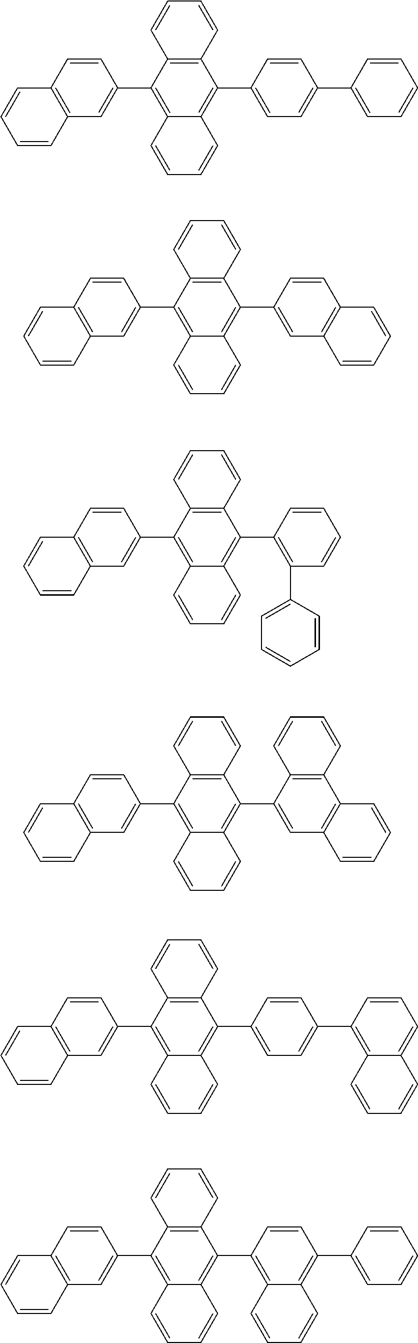

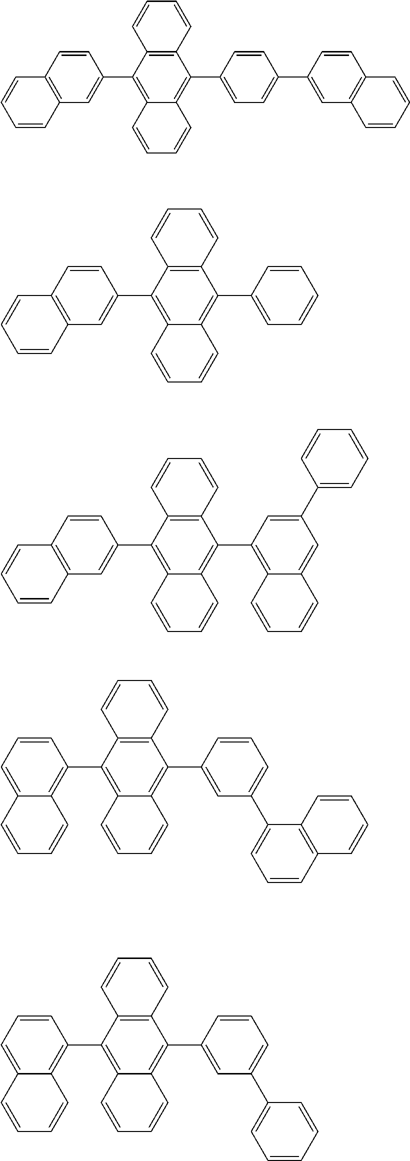

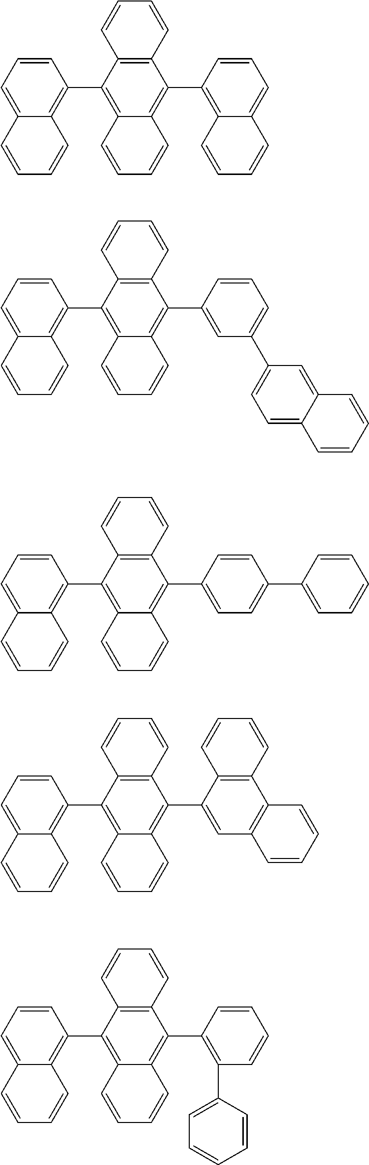

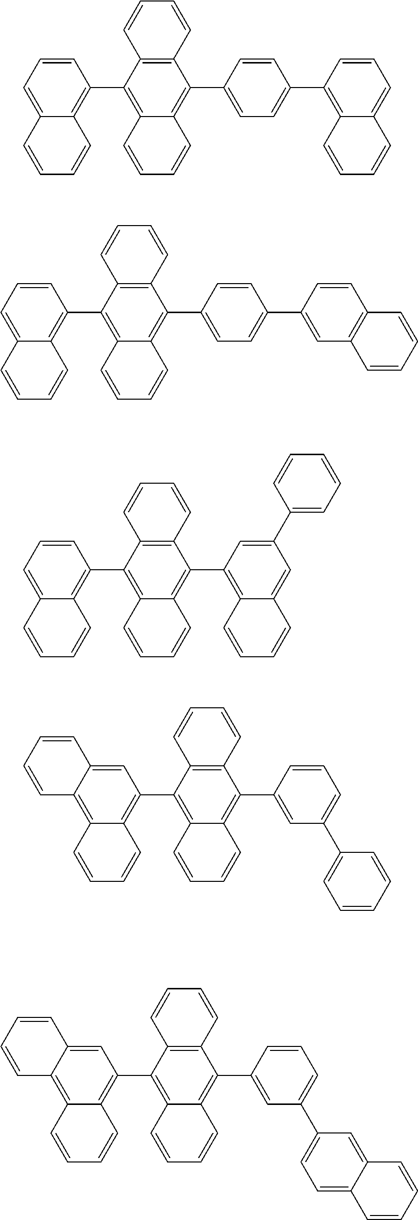

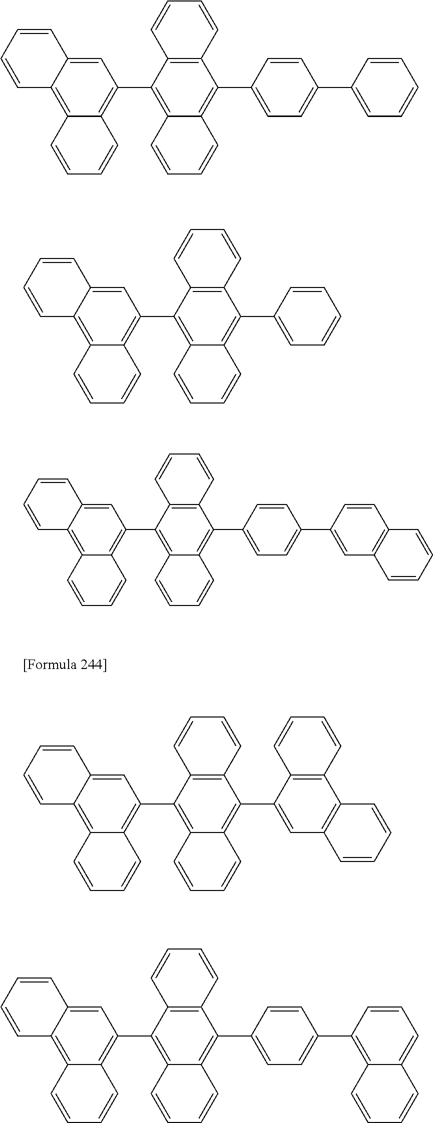

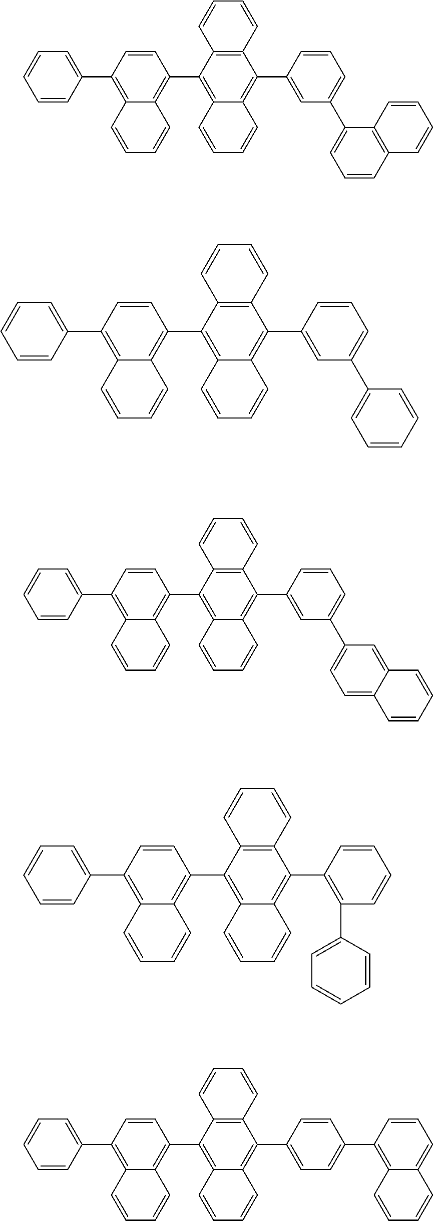

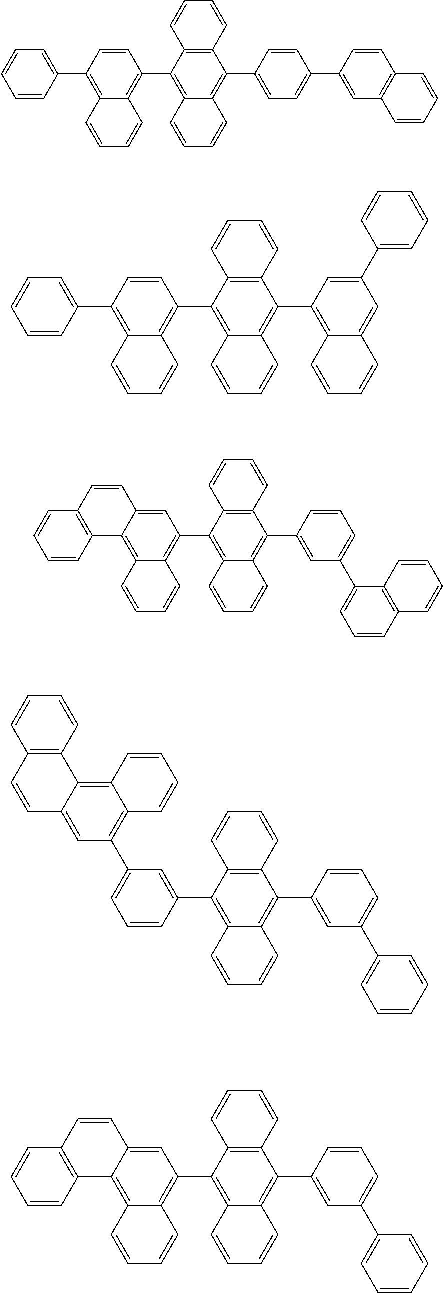

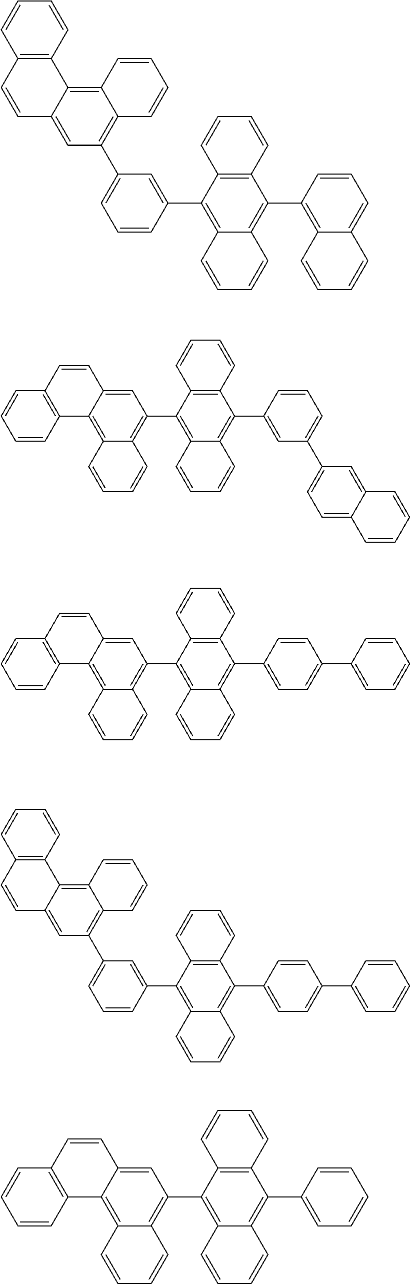

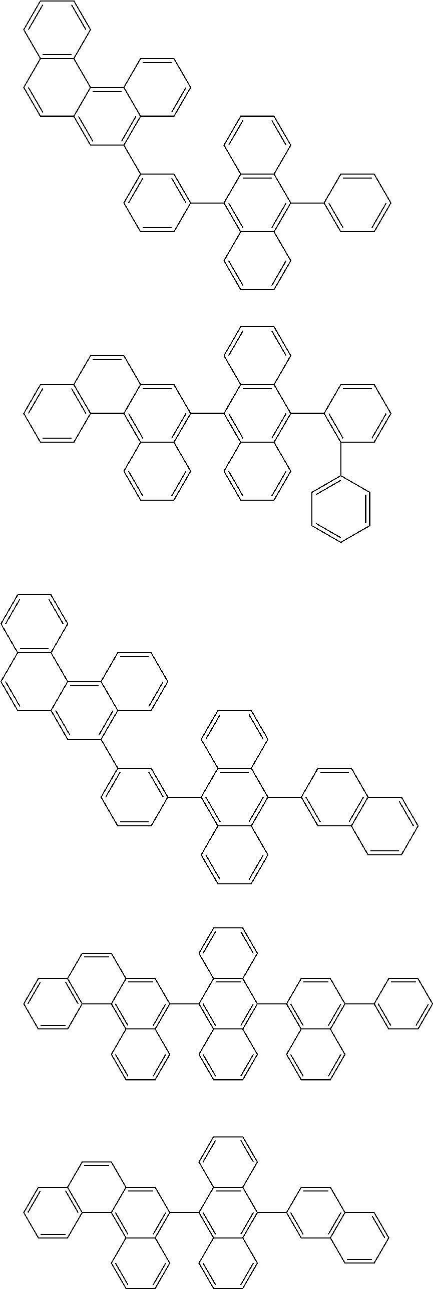

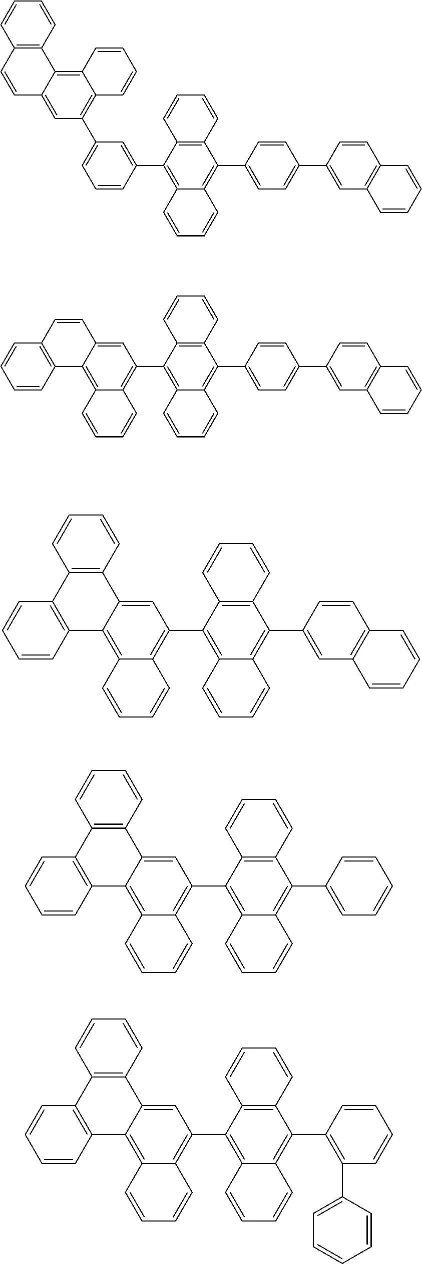

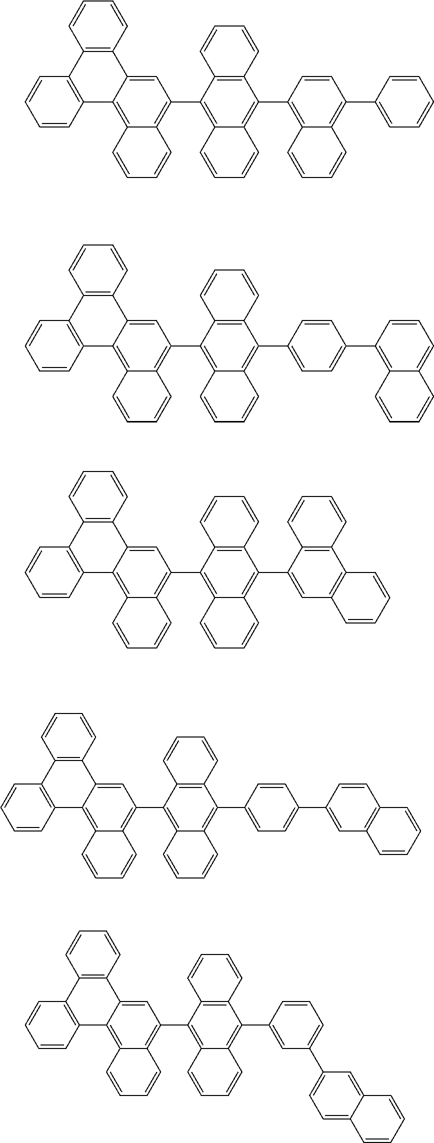

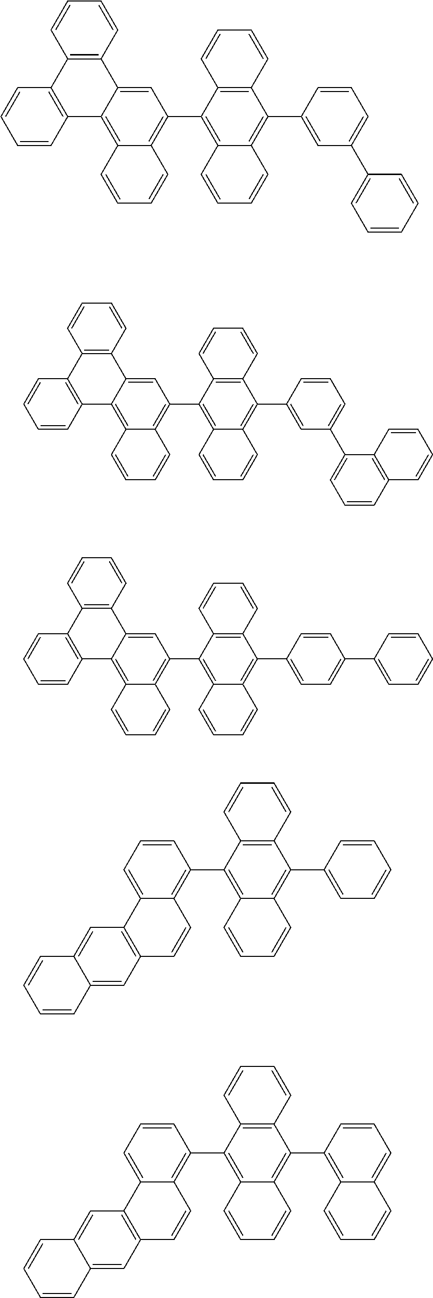

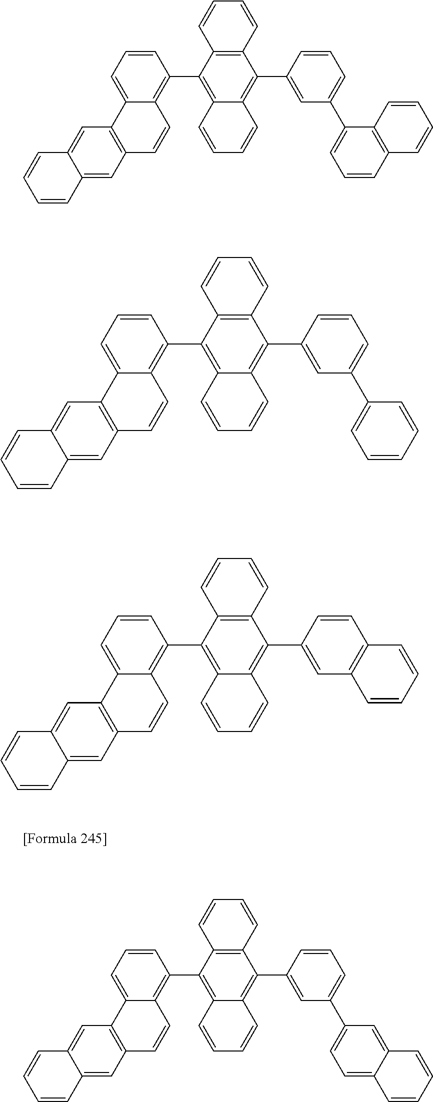

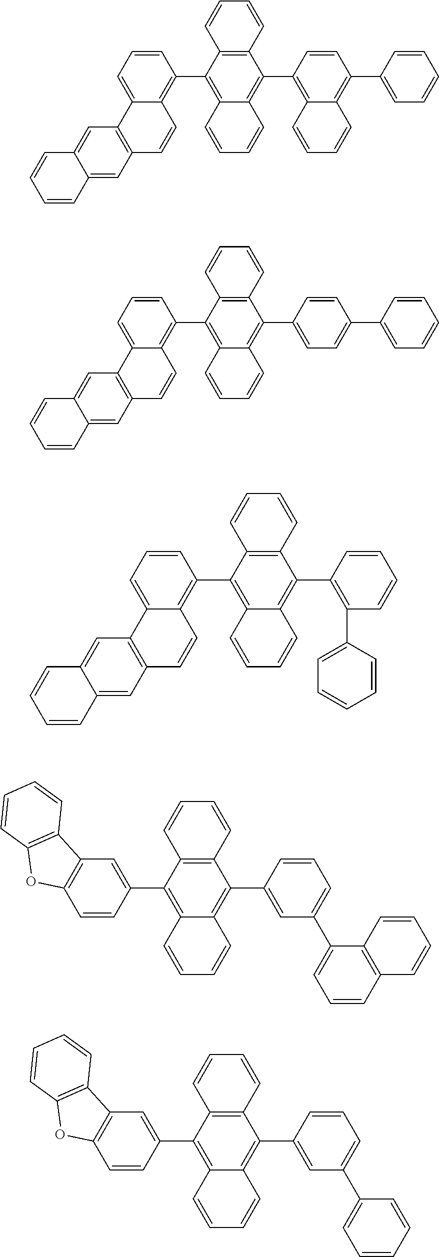

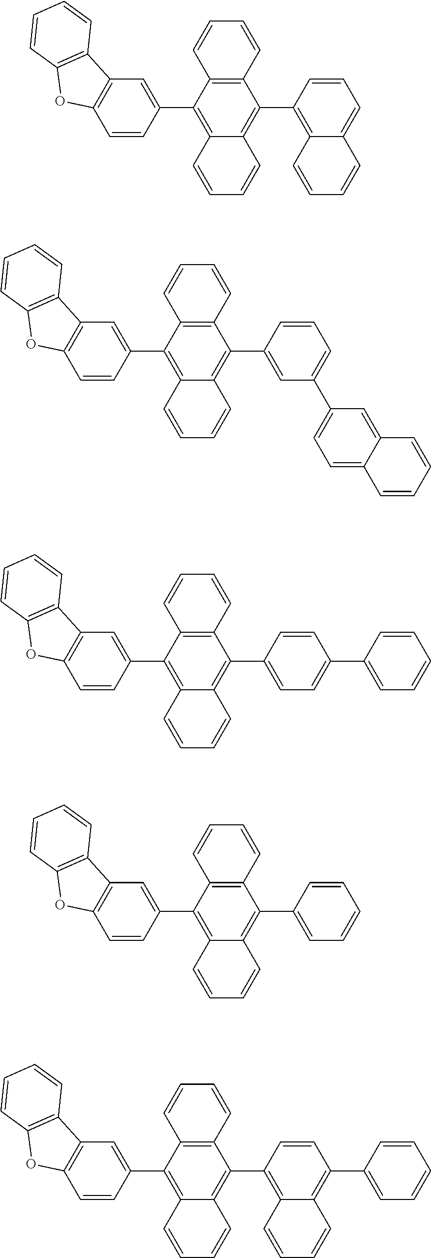 [SMILES: c1ccc2c(-c3c4ccccc4c(-c4ccc5oc6ccccc6c5c4)c4ccccc34)cccc2c1 ; c1cc(-c2ccc3ccccc3c2)cc(-c2c3ccccc3c(-c3ccc4oc5ccccc5c4c3)c3ccccc23)c1 ; c1ccc(-c2ccc(-c3c4ccccc4c(-c4ccc5oc6ccccc6c5c4)c4ccccc34)cc2)cc1 ; c1ccc(-c2c3ccccc3c(-c3ccc4oc5ccccc5c4c3)c3ccccc23)cc1 ; c1ccc(-c2ccc(-c3c4ccccc4c(-c4ccc5oc6ccccc6c5c4)c4ccccc34)c3ccccc23)cc1]

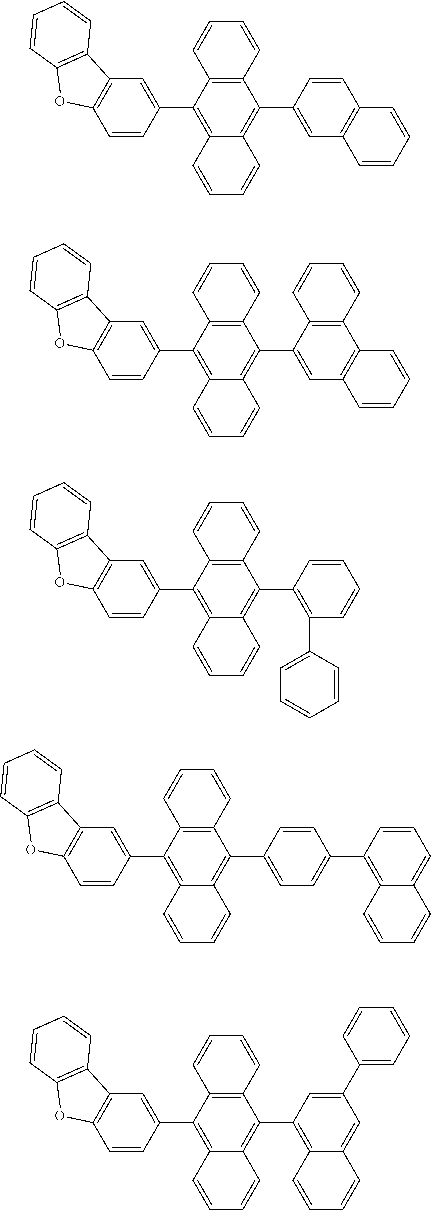 [SMILES: c1ccc2cc(-c3c4ccccc4c(-c4ccc5oc6ccccc6c5c4)c4ccccc34)ccc2c1 ; c1ccc2c(c1)cc(-c1c3ccccc3c(-c3ccc4oc5ccccc5c4c3)c3ccccc13)c1ccccc12 ; c1ccc(-c2ccccc2-c2c3ccccc3c(-c3ccc4oc5ccccc5c4c3)c3ccccc23)cc1 ; c1ccc2c(-c3ccc(-c4c5ccccc5c(-c5ccc6oc7ccccc7c6c5)c5ccccc45)cc3)cccc2c1 ; c1ccc(-c2cc(-c3c4ccccc4c(-c4ccc5oc6ccccc6c5c4)c4ccccc34)c3ccccc3c2)cc1]

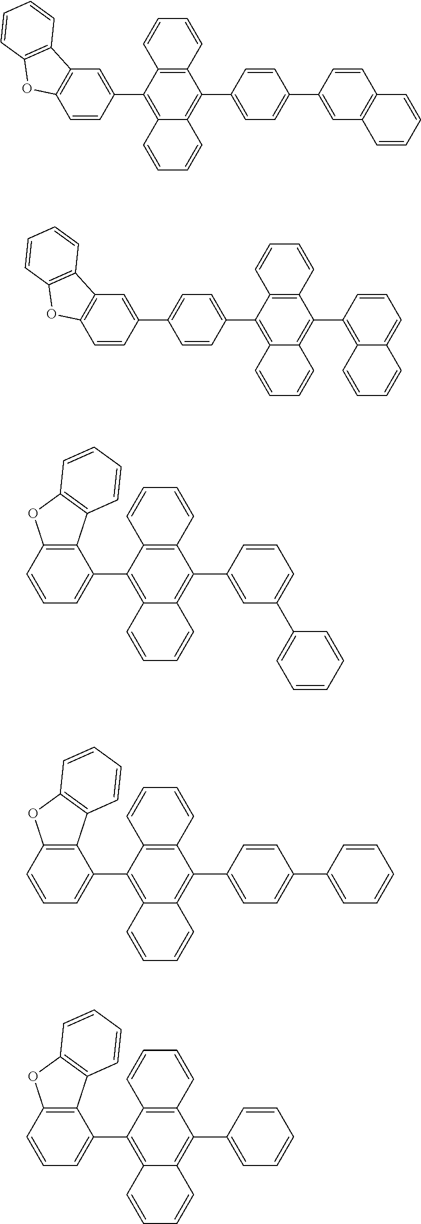

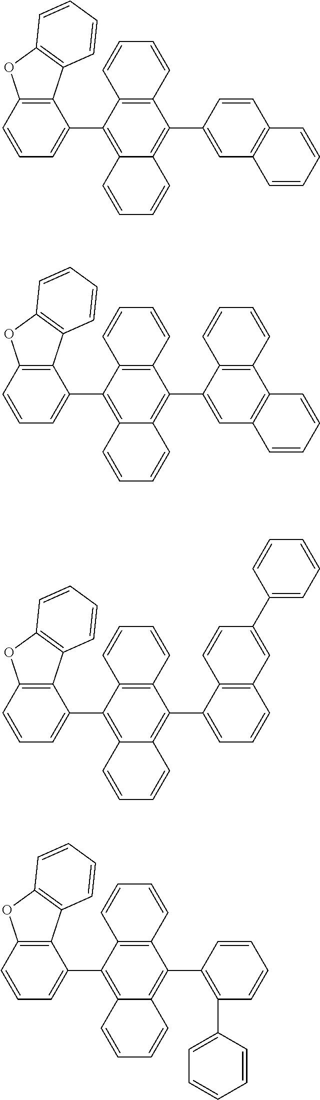

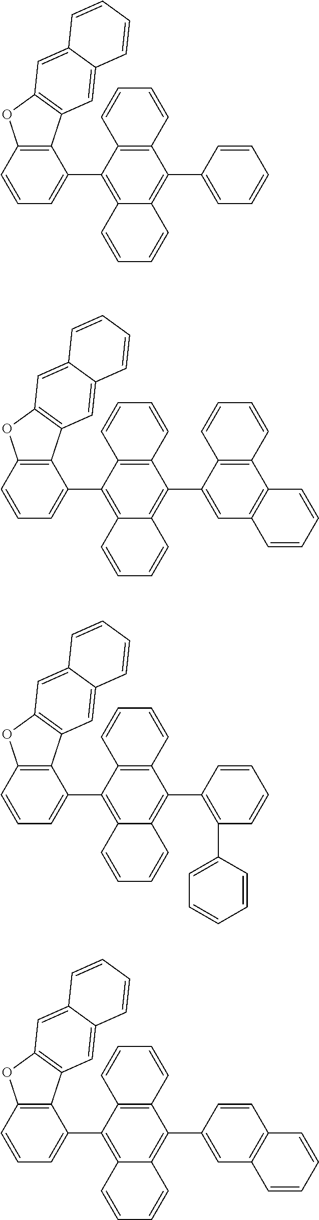 [SMILES: c1ccc(-c2c3ccccc3c(-c3cccc4oc5cc6ccccc6cc5c34)c3ccccc23)cc1 ; c1ccc2cc3c(cc2c1)oc1cccc(-c2c4ccccc4c(-c4cc5ccccc5c5ccccc45)c4ccccc24)c13 ; c1ccc(-c2ccccc2-c2c3ccccc3c(-c3cccc4oc5cc6ccccc6cc5c34)c3ccccc23)cc1 ; c1ccc2cc(-c3c4ccccc4c(-c4cccc5oc6cc7ccccc7cc6c45)c4ccccc34)ccc2c1]

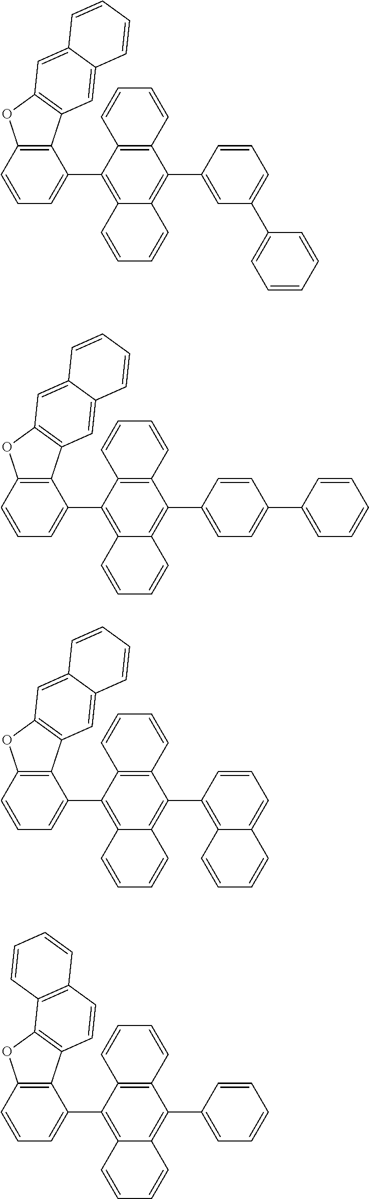

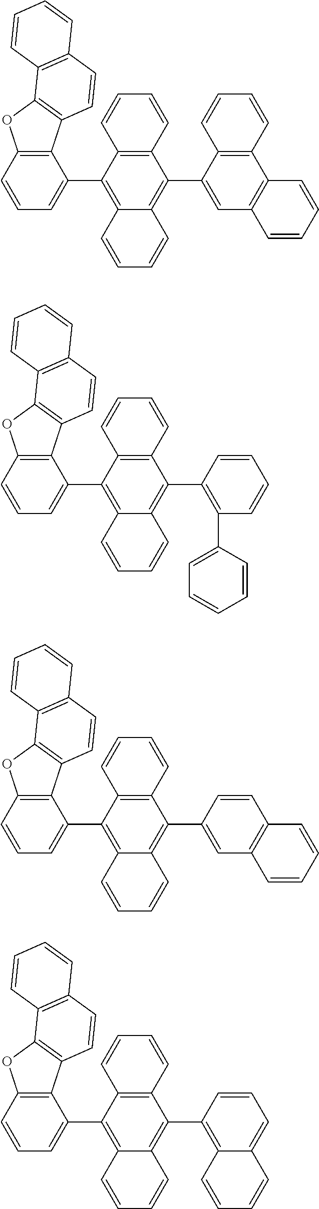 [SMILES: c1ccc2c(c1)cc(-c1c3ccccc3c(-c3cccc4oc5c6ccccc6ccc5c34)c3ccccc13)c1ccccc12 ; c1ccc(-c2ccccc2-c2c3ccccc3c(-c3cccc4oc5c6ccccc6ccc5c34)c3ccccc23)cc1 ; c1ccc2cc(-c3c4ccccc4c(-c4cccc5oc6c7ccccc7ccc6c45)c4ccccc34)ccc2c1 ; c1ccc2c(-c3c4ccccc4c(-c4cccc5oc6c7ccccc7ccc6c45)c4ccccc34)cccc2c1]

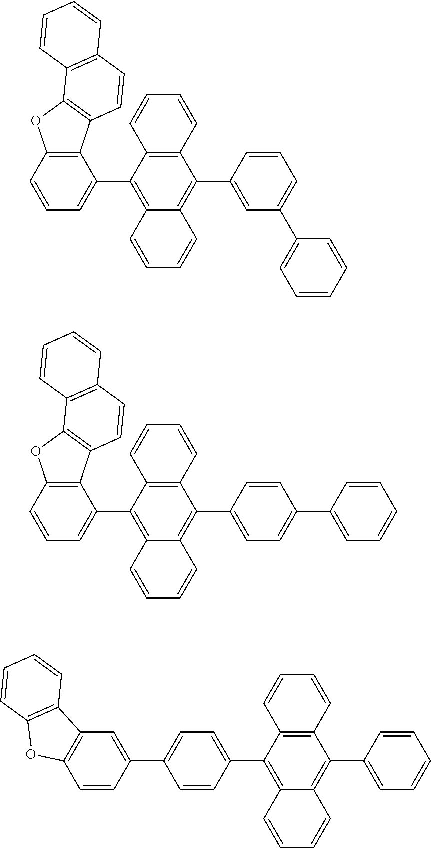 [SMILES: c1ccc(-c2cccc(-c3c4ccccc4c(-c4cccc5oc6c7ccccc7ccc6c45)c4ccccc34)c2)cc1 ; c1ccc(-c2ccc(-c3c4ccccc4c(-c4cccc5oc6c7ccccc7ccc6c45)c4ccccc34)cc2)cc1 ; c1ccc(-c2c3ccccc3c(-c3ccc(-c4ccc5oc6ccccc6c5c4)cc3)c3ccccc23)cc1]

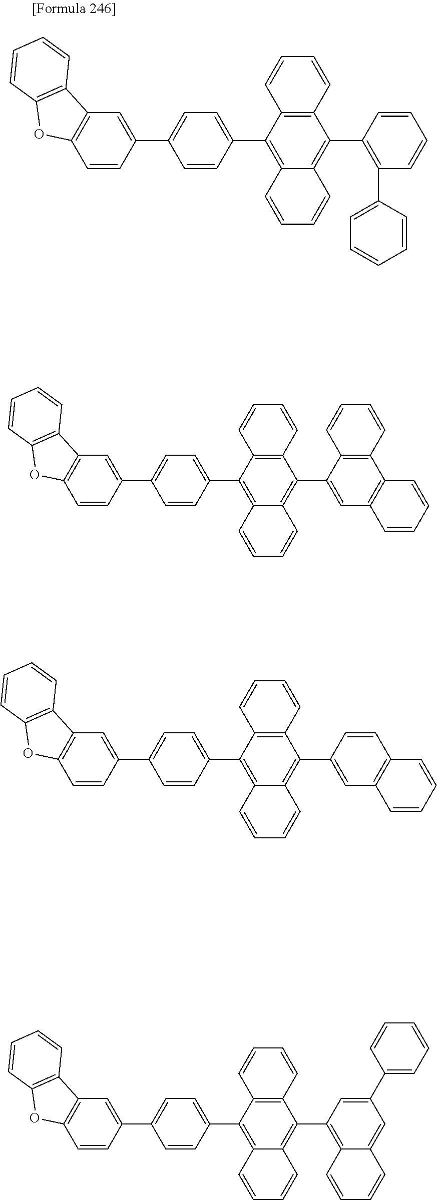 [SMILES: c1ccc(-c2ccccc2-c2c3ccccc3c(-c3ccc(-c4ccc5oc6ccccc6c5c4)cc3)c3ccccc23)cc1 ; c1ccc2c(c1)cc(-c1c3ccccc3c(-c3ccc(-c4ccc5oc6ccccc6c5c4)cc3)c3ccccc13)c1ccccc12 ; c1ccc2cc(-c3c4ccccc4c(-c4ccc(-c5ccc6oc7ccccc7c6c5)cc4)c4ccccc34)ccc2c1 ; c1ccc(-c2cc(-c3c4ccccc4c(-c4ccc(-c5ccc6oc7ccccc7c6c5)cc4)c4ccccc34)c3ccccc3c2)cc1]

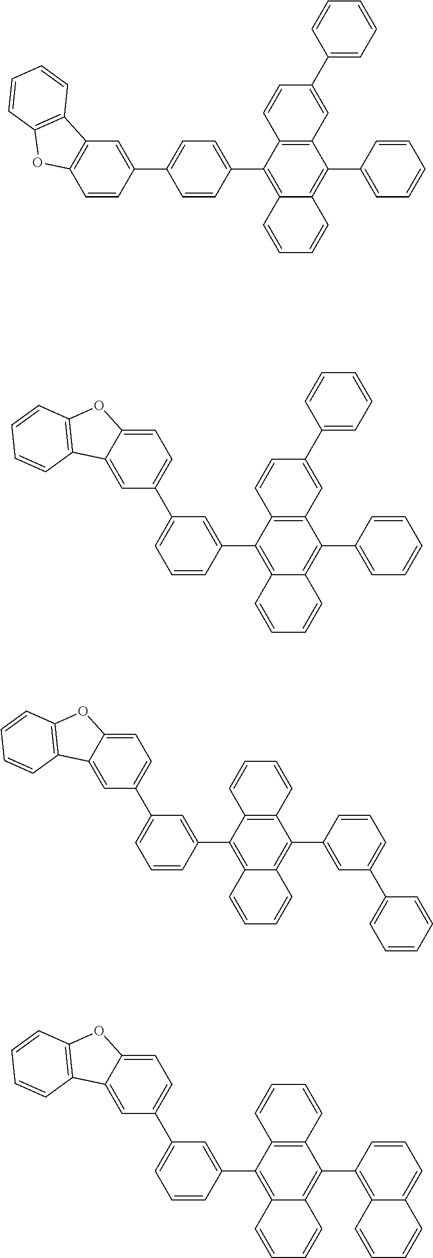 [SMILES: c1ccc(-c2ccc3c(-c4ccc(-c5ccc6oc7ccccc7c6c5)cc4)c4ccccc4c(-c4ccccc4)c3c2)cc1 ; c1ccc(-c2ccc3c(-c4cccc(-c5ccc6oc7ccccc7c6c5)c4)c4ccccc4c(-c4ccccc4)c3c2)cc1 ; c1ccc(-c2cccc(-c3c4ccccc4c(-c4cccc(-c5ccc6oc7ccccc7c6c5)c4)c4ccccc34)c2)cc1 ; c1cc(-c2ccc3oc4ccccc4c3c2)cc(-c2c3ccccc3c(-c3cccc4ccccc34)c3ccccc23)c1]

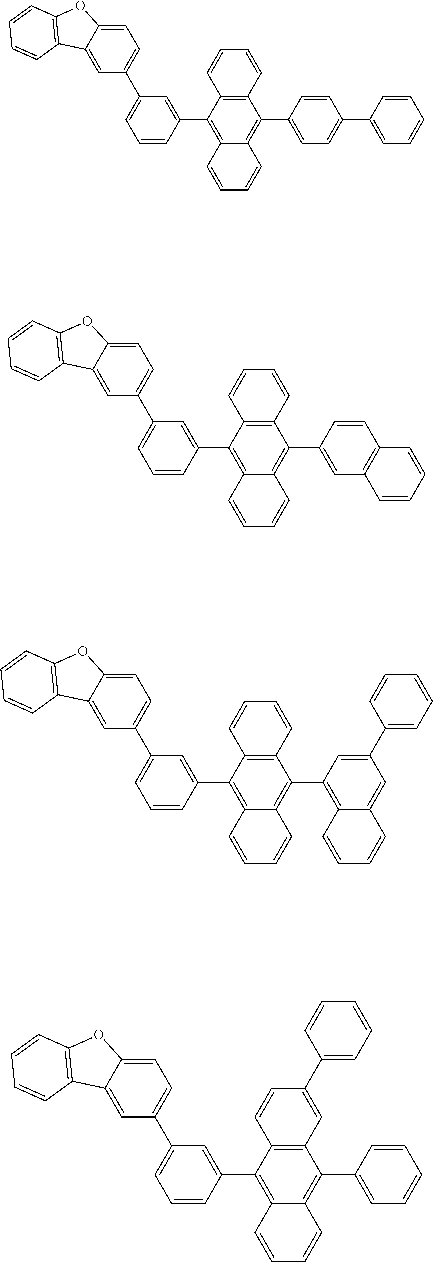 [SMILES: c1ccc(-c2ccc(-c3c4ccccc4c(-c4cccc(-c5ccc6oc7ccccc7c6c5)c4)c4ccccc34)cc2)cc1 ; c1cc(-c2ccc3oc4ccccc4c3c2)cc(-c2c3ccccc3c(-c3ccc4ccccc4c3)c3ccccc23)c1 ; c1ccc(-c2cc(-c3c4ccccc4c(-c4cccc(-c5ccc6oc7ccccc7c6c5)c4)c4ccccc34)c3ccccc3c2)cc1 ; c1ccc(-c2ccc3c(-c4cccc(-c5ccc6oc7ccccc7c6c5)c4)c4ccccc4c(-c4ccccc4)c3c2)cc1]

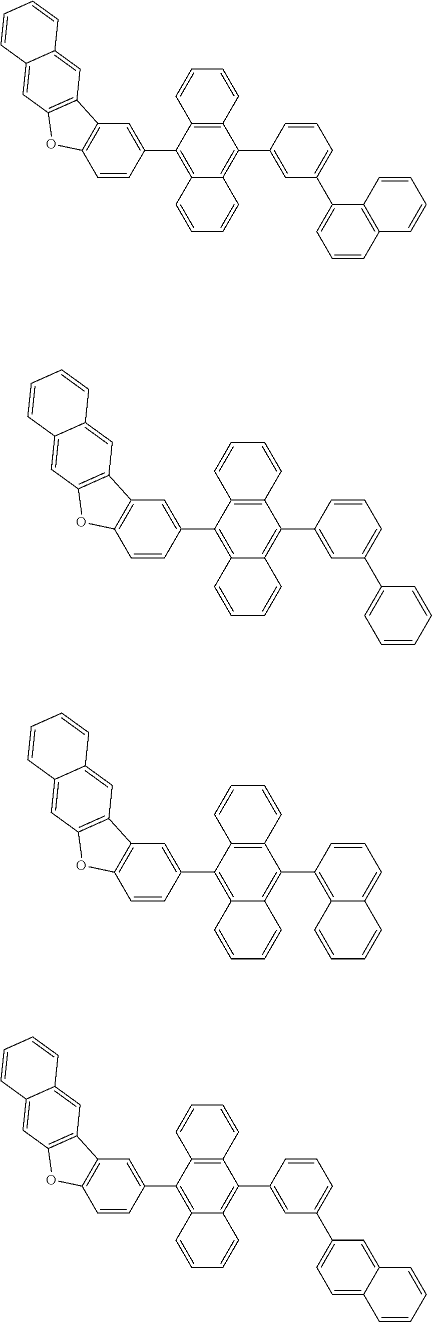 [SMILES: c1cc(-c2cccc3ccccc23)cc(-c2c3ccccc3c(-c3ccc4oc5cc6ccccc6cc5c4c3)c3ccccc23)c1 ; c1ccc(-c2cccc(-c3c4ccccc4c(-c4ccc5oc6cc7ccccc7cc6c5c4)c4ccccc34)c2)cc1 ; c1ccc2cc3c(cc2c1)oc1ccc(-c2c4ccccc4c(-c4cccc5ccccc45)c4ccccc24)cc13 ; c1cc(-c2ccc3ccccc3c2)cc(-c2c3ccccc3c(-c3ccc4oc5cc6ccccc6cc5c4c3)c3ccccc23)c1]

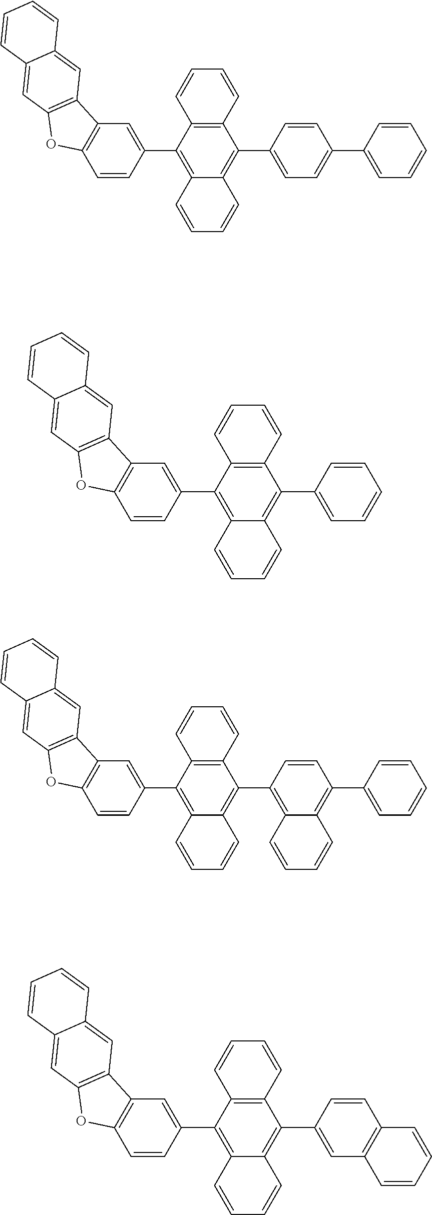 [SMILES: c1ccc(-c2ccc(-c3c4ccccc4c(-c4ccc5oc6cc7ccccc7cc6c5c4)c4ccccc34)cc2)cc1 ; c1ccc(-c2c3ccccc3c(-c3ccc4oc5cc6ccccc6cc5c4c3)c3ccccc23)cc1 ; c1ccc(-c2ccc(-c3c4ccccc4c(-c4ccc5oc6cc7ccccc7cc6c5c4)c4ccccc34)c3ccccc23)cc1 ; c1ccc2cc(-c3c4ccccc4c(-c4ccc5oc6cc7ccccc7cc6c5c4)c4ccccc34)ccc2c1]

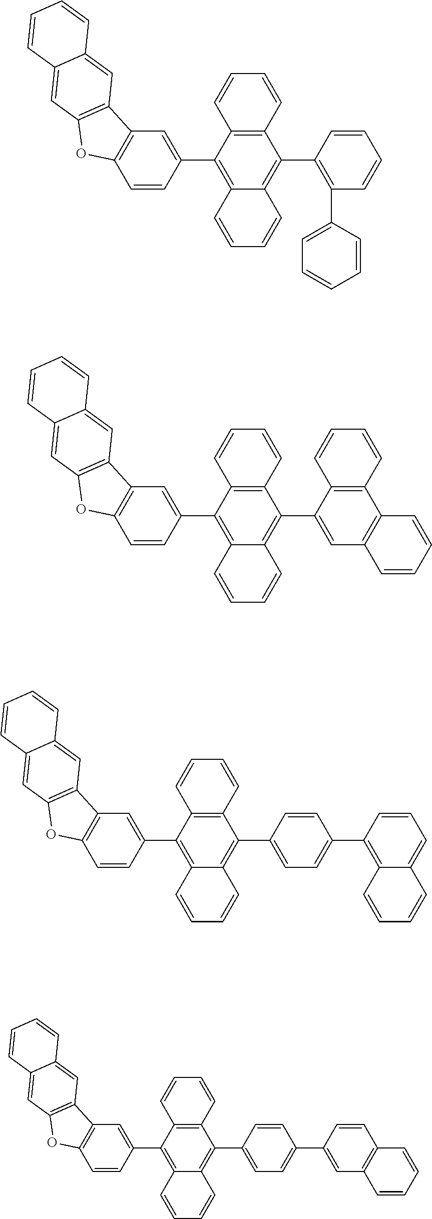 [SMILES: c1ccc(-c2ccccc2-c2c3ccccc3c(-c3ccc4oc5cc6ccccc6cc5c4c3)c3ccccc23)cc1 ; c1ccc2cc3c(cc2c1)oc1ccc(-c2c4ccccc4c(-c4cc5ccccc5c5ccccc45)c4ccccc24)cc13 ; c1ccc2cc3c(cc2c1)oc1ccc(-c2c4ccccc4c(-c4ccc(-c5cccc6ccccc56)cc4)c4ccccc24)cc13 ; c1ccc2cc(-c3ccc(-c4c5ccccc5c(-c5ccc6oc7cc8ccccc8cc7c6c5)c5ccccc45)cc3)ccc2c1]

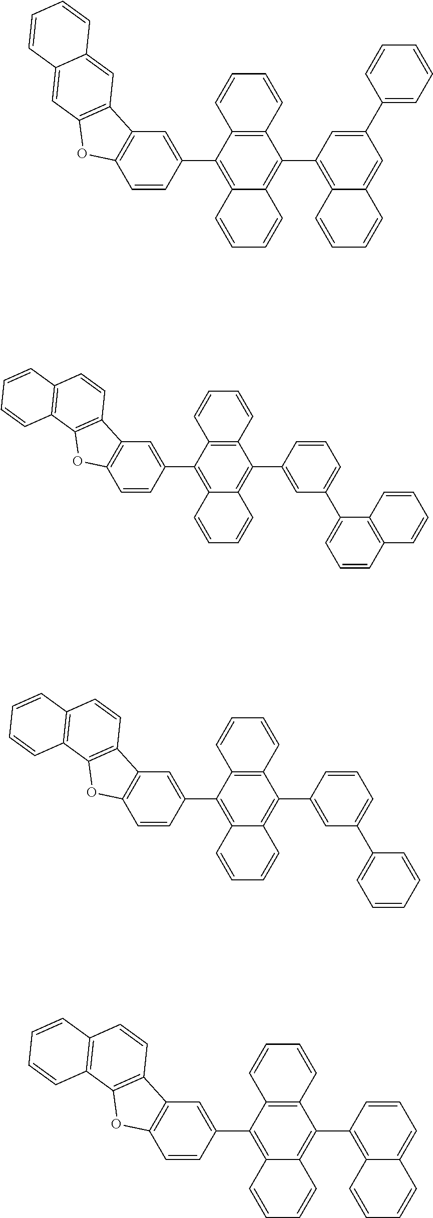 [SMILES: c1ccc(-c2cc(-c3c4ccccc4c(-c4ccc5oc6cc7ccccc7cc6c5c4)c4ccccc34)c3ccccc3c2)cc1 ; c1cc(-c2cccc3ccccc23)cc(-c2c3ccccc3c(-c3ccc4oc5c6ccccc6ccc5c4c3)c3ccccc23)c1 ; c1ccc(-c2cccc(-c3c4ccccc4c(-c4ccc5oc6c7ccccc7ccc6c5c4)c4ccccc34)c2)cc1 ; c1ccc2c(-c3c4ccccc4c(-c4ccc5oc6c7ccccc7ccc6c5c4)c4ccccc34)cccc2c1]

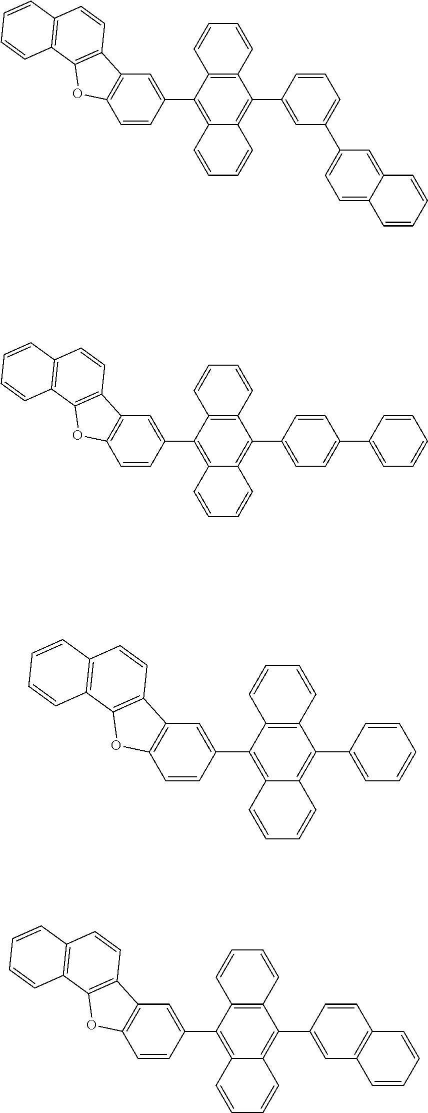 [SMILES: c1cc(-c2ccc3ccccc3c2)cc(-c2c3ccccc3c(-c3ccc4oc5c6ccccc6ccc5c4c3)c3ccccc23)c1 ; c1ccc(-c2ccc(-c3c4ccccc4c(-c4ccc5oc6c7ccccc7ccc6c5c4)c4ccccc34)cc2)cc1 ; c1ccc(-c2c3ccccc3c(-c3ccc4oc5c6ccccc6ccc5c4c3)c3ccccc23)cc1 ; c1ccc2cc(-c3c4ccccc4c(-c4ccc5oc6c7ccccc7ccc6c5c4)c4ccccc34)ccc2c1]

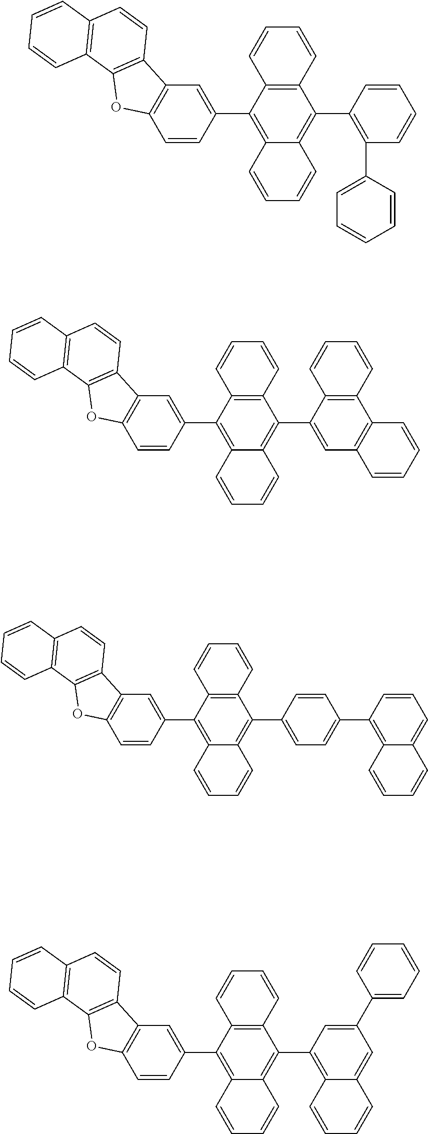 [SMILES: c1ccc(-c2ccccc2-c2c3ccccc3c(-c3ccc4oc5c6ccccc6ccc5c4c3)c3ccccc23)cc1 ; c1ccc2c(c1)cc(-c1c3ccccc3c(-c3ccc4oc5c6ccccc6ccc5c4c3)c3ccccc13)c1ccccc12 ; c1ccc2c(-c3ccc(-c4c5ccccc5c(-c5ccc6oc7c8ccccc8ccc7c6c5)c5ccccc45)cc3)cccc2c1 ; c1ccc(-c2cc(-c3c4ccccc4c(-c4ccc5oc6c7ccccc7ccc6c5c4)c4ccccc34)c3ccccc3c2)cc1]

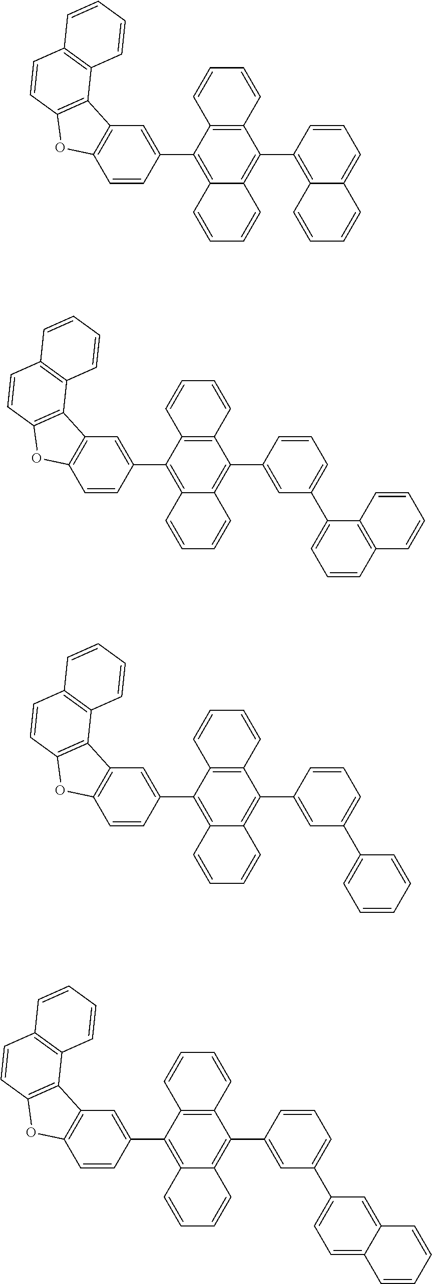 [SMILES: c1ccc2c(-c3c4ccccc4c(-c4ccc5oc6ccc7ccccc7c6c5c4)c4ccccc34)cccc2c1 ; c1cc(-c2cccc3ccccc23)cc(-c2c3ccccc3c(-c3ccc4oc5ccc6ccccc6c5c4c3)c3ccccc23)c1 ; c1ccc(-c2cccc(-c3c4ccccc4c(-c4ccc5oc6ccc7ccccc7c6c5c4)c4ccccc34)c2)cc1 ; c1cc(-c2ccc3ccccc3c2)cc(-c2c3ccccc3c(-c3ccc4oc5ccc6ccccc6c5c4c3)c3ccccc23)c1]

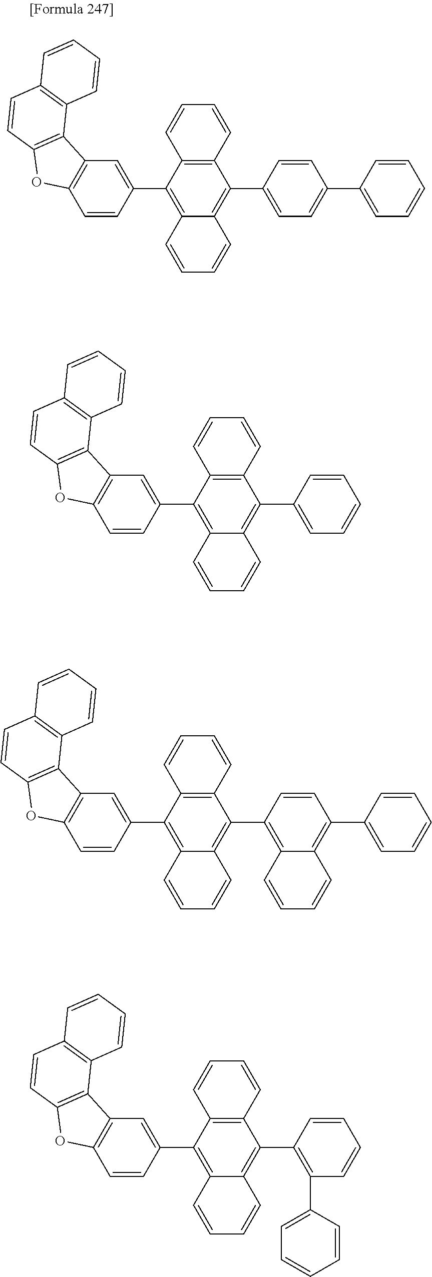 [SMILES: c1ccc(-c2ccc(-c3c4ccccc4c(-c4ccc5oc6ccc7ccccc7c6c5c4)c4ccccc34)cc2)cc1 ; c1ccc(-c2c3ccccc3c(-c3ccc4oc5ccc6ccccc6c5c4c3)c3ccccc23)cc1 ; c1ccc(-c2ccc(-c3c4ccccc4c(-c4ccc5oc6ccc7ccccc7c6c5c4)c4ccccc34)c3ccccc23)cc1 ; c1ccc(-c2ccccc2-c2c3ccccc3c(-c3ccc4oc5ccc6ccccc6c5c4c3)c3ccccc23)cc1]

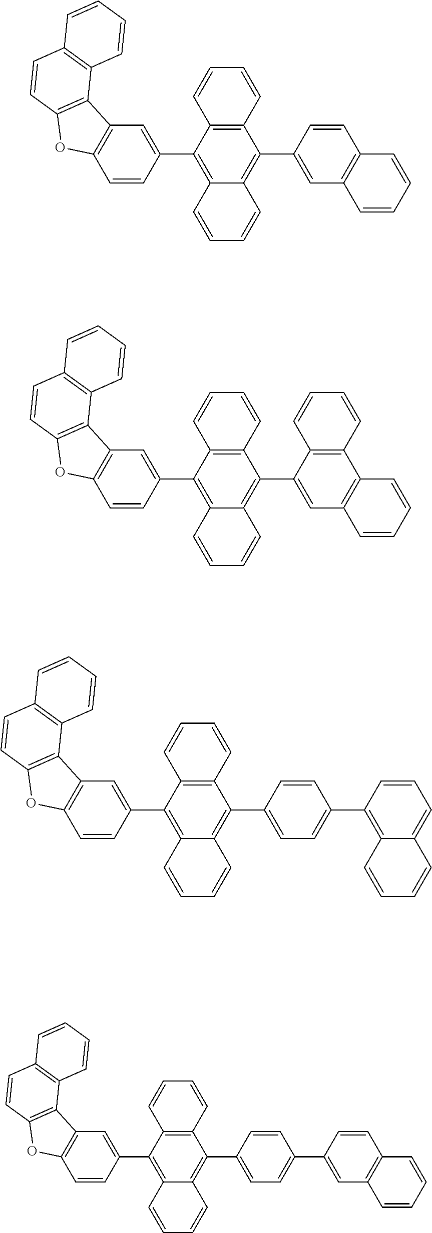 [SMILES: c1ccc2cc(-c3c4ccccc4c(-c4ccc5oc6ccc7ccccc7c6c5c4)c4ccccc34)ccc2c1 ; c1ccc2c(c1)cc(-c1c3ccccc3c(-c3ccc4oc5ccc6ccccc6c5c4c3)c3ccccc13)c1ccccc12 ; c1ccc2c(-c3ccc(-c4c5ccccc5c(-c5ccc6oc7ccc8ccccc8c7c6c5)c5ccccc45)cc3)cccc2c1 ; c1ccc2cc(-c3ccc(-c4c5ccccc5c(-c5ccc6oc7ccc8ccccc8c7c6c5)c5ccccc45)cc3)ccc2c1]

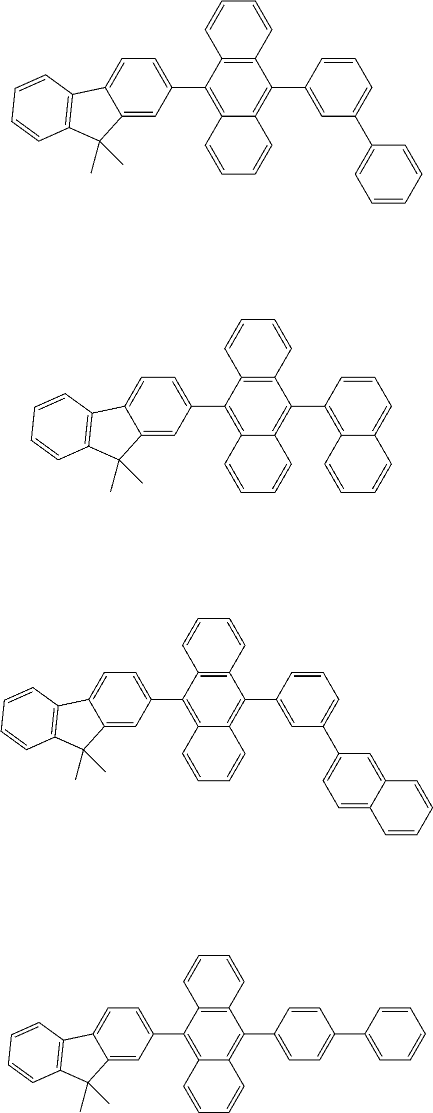

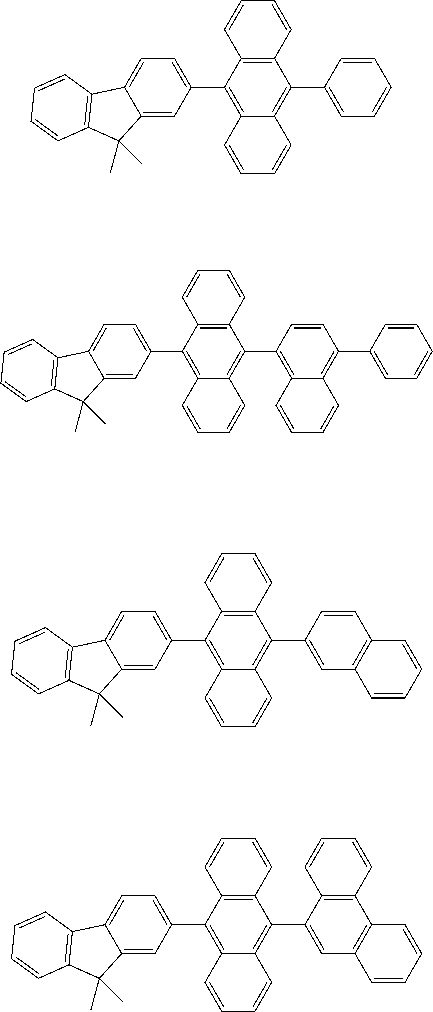

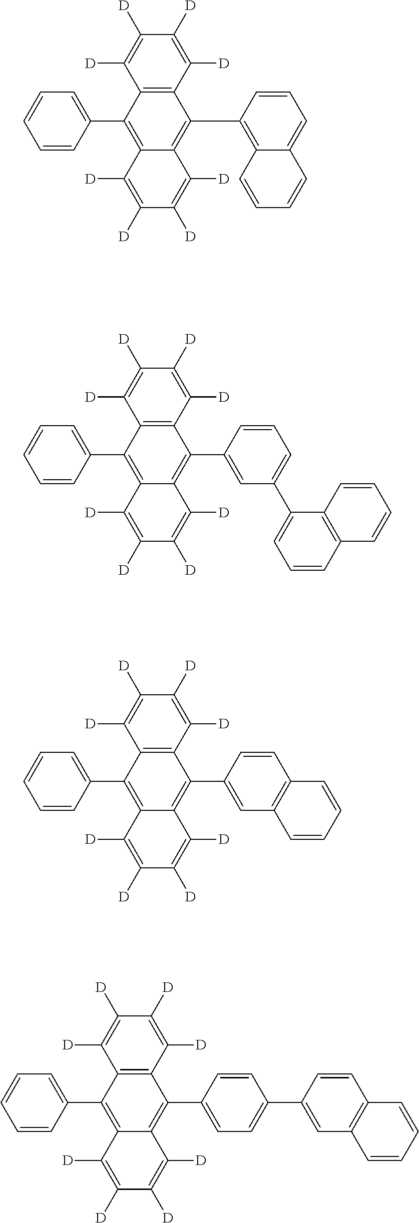 [SMILES: [2H]c1c([2H])c([2H])c2c(-c3cccc4ccccc34)c3c([2H])c([2H])c([2H])c([2H])c3c(-c3ccccc3)c2c1[2H] ; [2H]c1c([2H])c([2H])c2c(-c3cccc(-c4cccc5ccccc45)c3)c3c([2H])c([2H])c([2H])c([2H])c3c(-c3ccccc3)c2c1[2H] ; [2H]c1c([2H])c([2H])c2c(-c3ccc4ccccc4c3)c3c([2H])c([2H])c([2H])c([2H])c3c(-c3ccccc3)c2c1[2H] ; [2H]c1c([2H])c([2H])c2c(-c3ccc(-c4ccc5ccccc5c4)cc3)c3c([2H])c([2H])c([2H])c([2H])c3c(-c3ccccc3)c2c1[2H]]

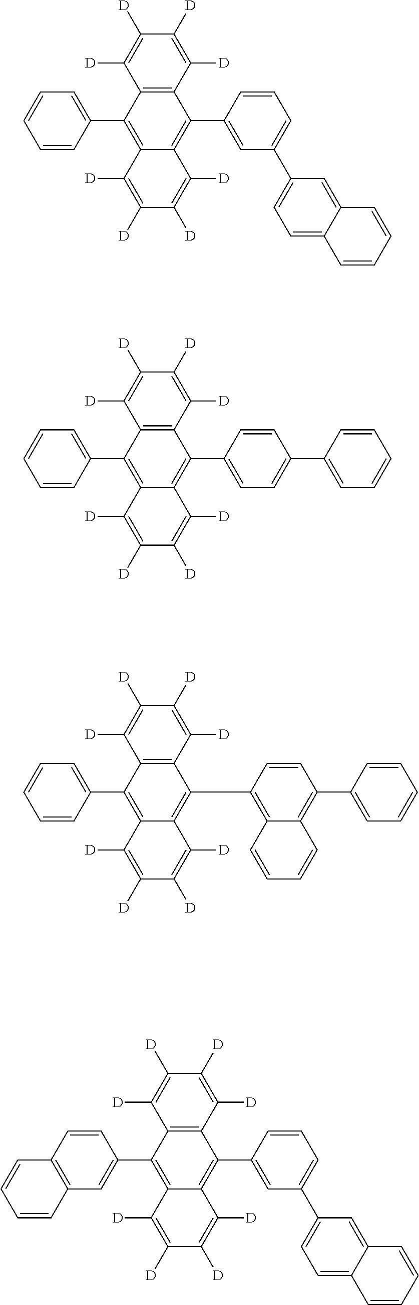 [SMILES: [2H]c1c([2H])c([2H])c2c(-c3cccc(-c4ccc5ccccc5c4)c3)c3c([2H])c([2H])c([2H])c([2H])c3c(-c3ccccc3)c2c1[2H] ; [2H]c1c([2H])c([2H])c2c(-c3ccc(-c4ccccc4)cc3)c3c([2H])c([2H])c([2H])c([2H])c3c(-c3ccccc3)c2c1[2H] ; [2H]c1c([2H])c([2H])c2c(-c3ccc(-c4ccccc4)c4ccccc34)c3c([2H])c([2H])c([2H])c([2H])c3c(-c3ccccc3)c2c1[2H] ; [2H]c1c([2H])c([2H])c2c(-c3ccc4ccccc4c3)c3c([2H])c([2H])c([2H])c([2H])c3c(-c3cccc(-c4ccc5ccccc5c4)c3)c2c1[2H]]

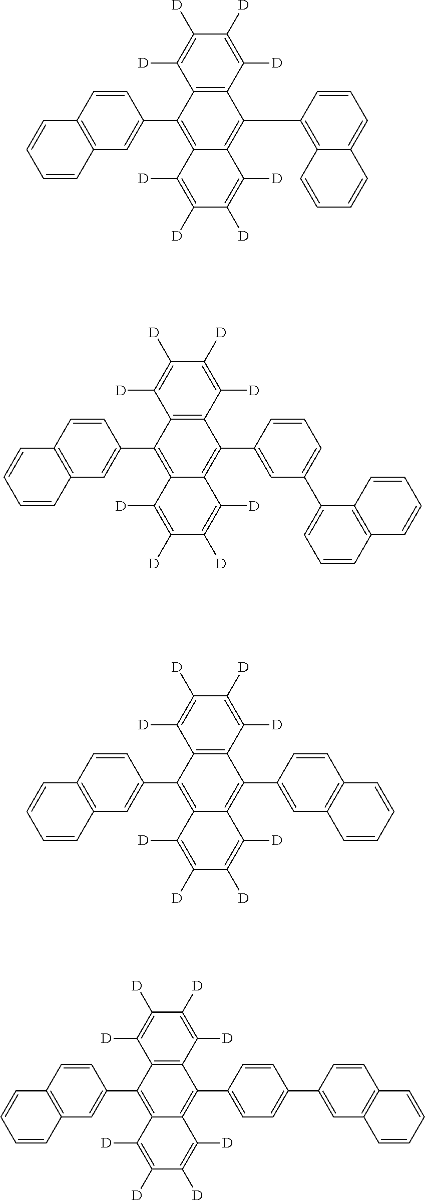 [SMILES: [2H]c1c([2H])c([2H])c2c(-c3cccc4ccccc34)c3c([2H])c([2H])c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3cccc(-c4cccc5ccccc45)c3)c2c1[2H] ; [2H]c1c([2H])c([2H])c2c(-c3ccc4ccccc4c3)c3c([2H])c([2H])c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3ccc(-c4ccc5ccccc5c4)cc3)c2c1[2H]]

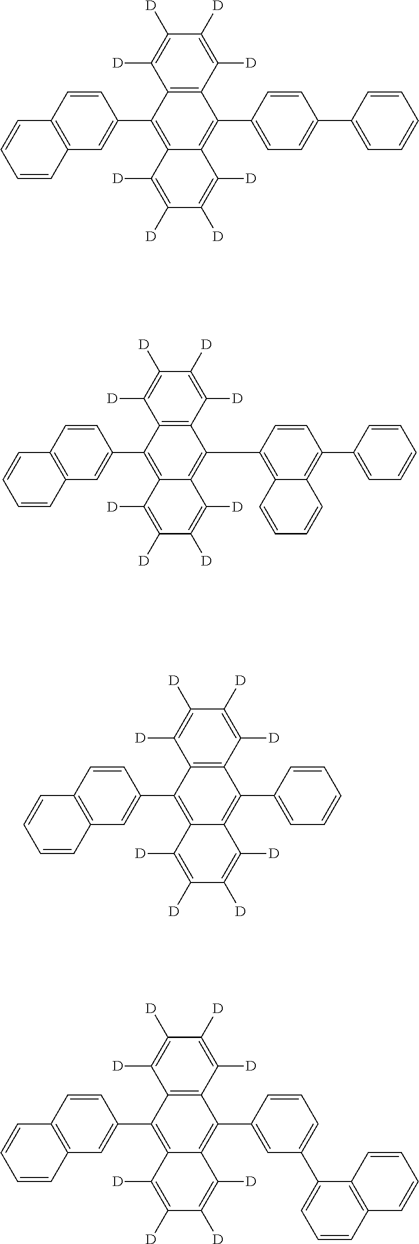 [SMILES: [2H]c1c([2H])c([2H])c2c(-c3ccc4ccccc4c3)c3c([2H])c([2H])c([2H])c([2H])c3c(-c3ccc(-c4ccccc4)cc3)c2c1[2H] ; [2H]c1c([2H])c([2H])c2c(-c3ccc(-c4ccccc4)c4ccccc34)c3c([2H])c([2H])c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3ccccc3)c2c1[2H] ; [2H]c1c([2H])c([2H])c2c(-c3ccc4ccccc4c3)c3c([2H])c([2H])c([2H])c([2H])c3c(-c3cccc(-c4cccc5ccccc45)c3)c2c1[2H]]

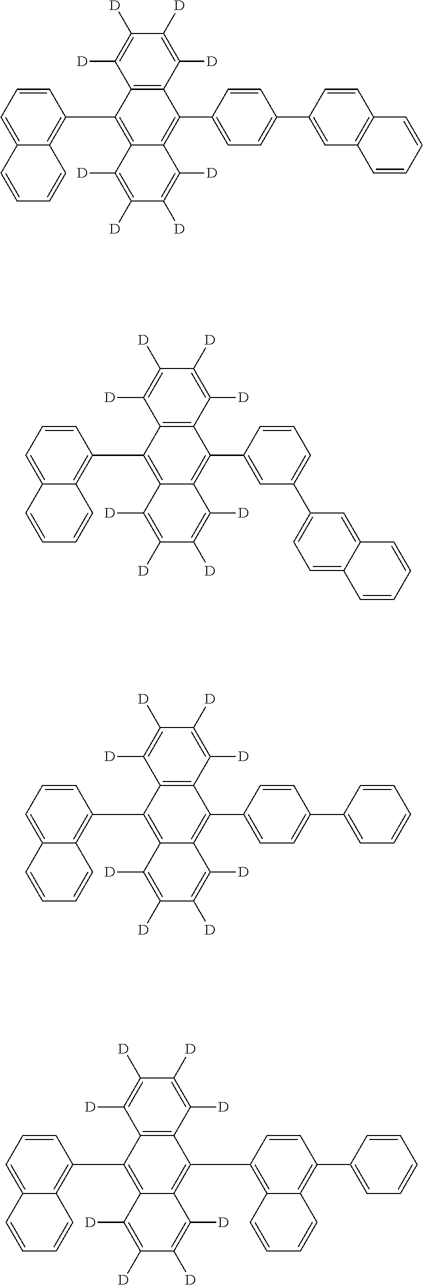 [SMILES: [2H]c1c([2H])c([2H])c2c(-c3cccc4ccccc34)c3c([2H])c([2H])c([2H])c([2H])c3c(-c3ccc(-c4ccc5ccccc5c4)cc3)c2c1[2H] ; [2H]c1c([2H])c([2H])c2c(-c3cccc4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3cccc4ccccc34)c3c([2H])c([2H])c([2H])c([2H])c3c(-c3ccc(-c4ccccc4)cc3)c2c1[2H] ; [2H]c1c([2H])c([2H])c2c(-c3ccc(-c4ccccc4)c4ccccc34)c3c([2H])c([2H])c([2H])c([2H])c3c(-c3cccc4ccccc34)c2c1[2H]]

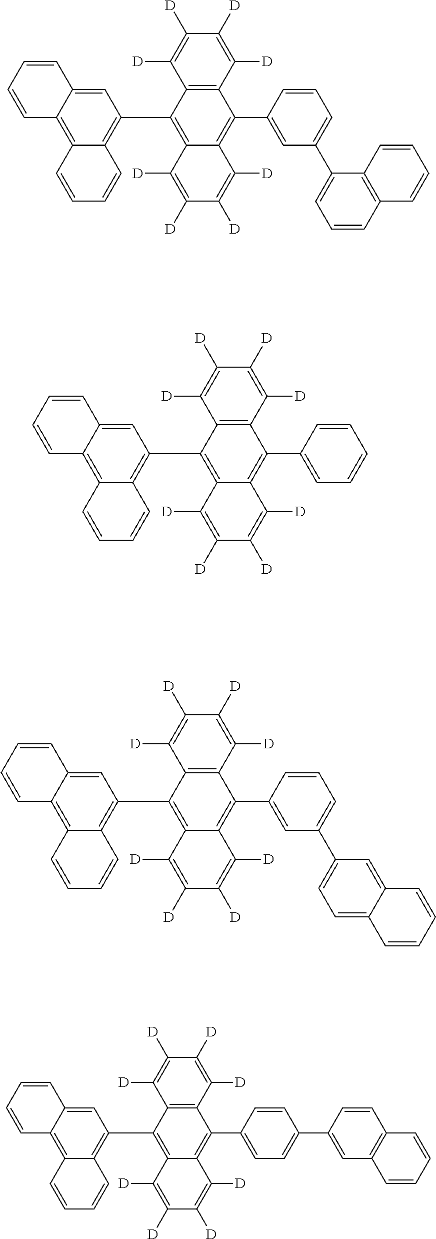 [SMILES: [2H]c1c([2H])c([2H])c2c(-c3cc4ccccc4c4ccccc34)c3c([2H])c([2H])c([2H])c([2H])c3c(-c3cccc(-c4cccc5ccccc45)c3)c2c1[2H] ; [2H]c1c([2H])c([2H])c2c(-c3cc4ccccc4c4ccccc34)c3c([2H])c([2H])c([2H])c([2H])c3c(-c3ccccc3)c2c1[2H] ; [2H]c1c([2H])c([2H])c2c(-c3cc4ccccc4c4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3cc4ccccc4c4ccccc34)c3c([2H])c([2H])c([2H])c([2H])c3c(-c3ccc(-c4ccc5ccccc5c4)cc3)c2c1[2H]]

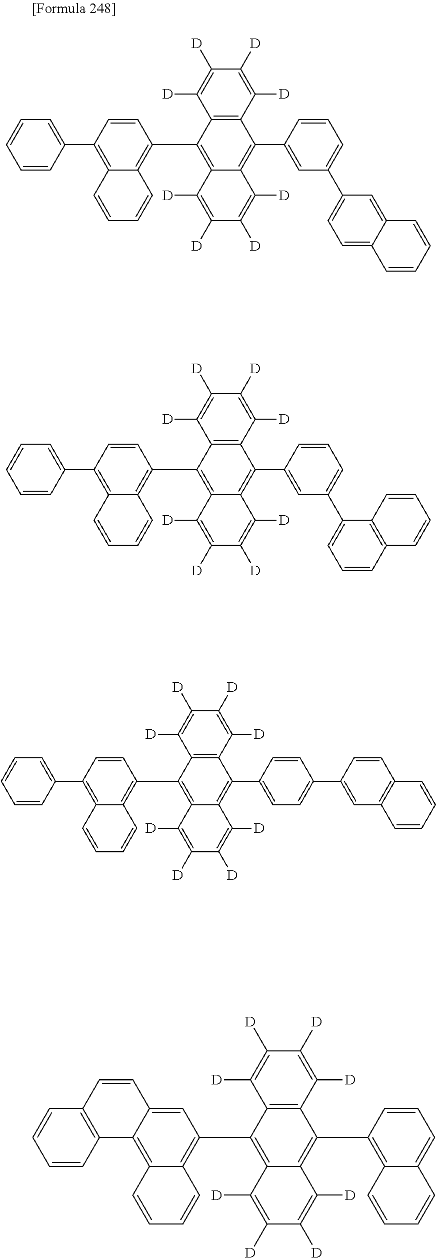 [SMILES: [2H]c1c([2H])c([2H])c2c(-c3ccc(-c4ccccc4)c4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3ccc(-c4ccccc4)c4ccccc34)c3c([2H])c([2H])c([2H])c([2H])c3c(-c3cccc(-c4cccc5ccccc45)c3)c2c1[2H] ; [2H]c1c([2H])c([2H])c2c(-c3ccc(-c4ccccc4)c4ccccc34)c3c([2H])c([2H])c([2H])c([2H])c3c(-c3ccc(-c4ccc5ccccc5c4)cc3)c2c1[2H] ; [2H]c1c([2H])c([2H])c2c(-c3cc4ccc5ccccc5c4c4ccccc34)c3c([2H])c([2H])c([2H])c([2H])c3c(-c3cccc4ccccc34)c2c1[2H]]

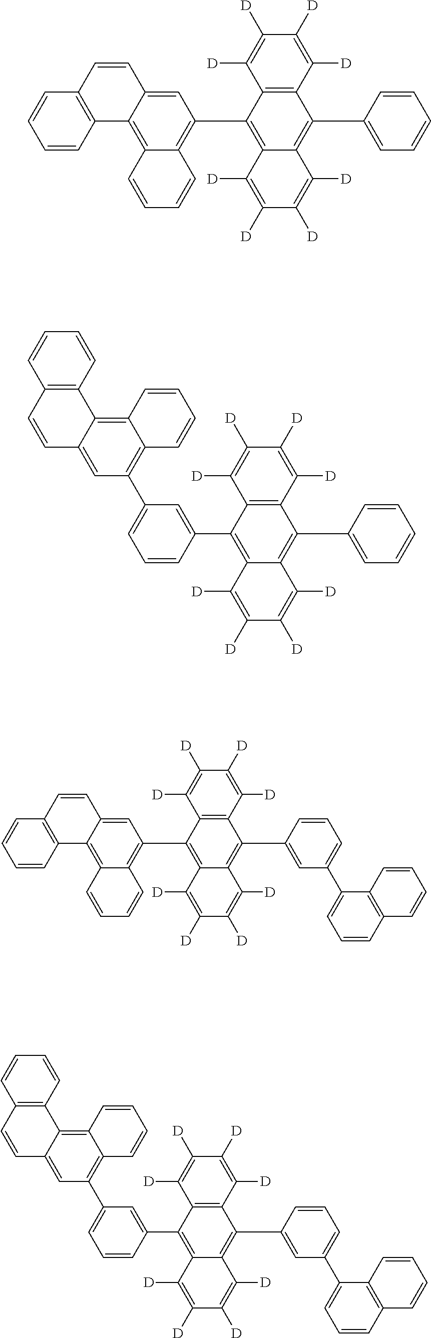 [SMILES: [2H]c1c([2H])c([2H])c2c(-c3cc4ccc5ccccc5c4c4ccccc34)c3c([2H])c([2H])c([2H])c([2H])c3c(-c3ccccc3)c2c1[2H] ; [2H]c1c([2H])c([2H])c2c(-c3cccc(-c4cc5ccc6ccccc6c5c5ccccc45)c3)c3c([2H])c([2H])c([2H])c([2H])c3c(-c3ccccc3)c2c1[2H] ; [2H]c1c([2H])c([2H])c2c(-c3cc4ccc5ccccc5c4c4ccccc34)c3c([2H])c([2H])c([2H])c([2H])c3c(-c3cccc(-c4cccc5ccccc45)c3)c2c1[2H] ; [2H]c1c([2H])c([2H])c2c(-c3cccc(-c4cc5ccc6ccccc6c5c5ccccc45)c3)c3c([2H])c([2H])c([2H])c([2H])c3c(-c3cccc(-c4cccc5ccccc45)c3)c2c1[2H]]

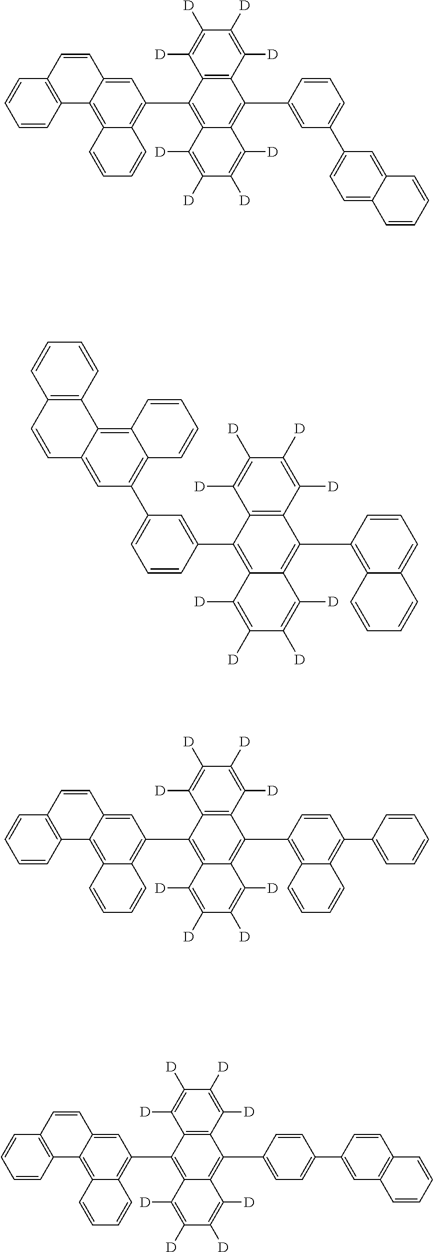 [SMILES: [2H]c1c([2H])c([2H])c2c(-c3cc4ccc5ccccc5c4c4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3cccc4ccccc34)c3c([2H])c([2H])c([2H])c([2H])c3c(-c3cccc(-c4cc5ccc6ccccc6c5c5ccccc45)c3)c2c1[2H] ; [2H]c1c([2H])c([2H])c2c(-c3cc4ccc5ccccc5c4c4ccccc34)c3c([2H])c([2H])c([2H])c([2H])c3c(-c3ccc(-c4ccccc4)c4ccccc34)c2c1[2H] ; [2H]c1c([2H])c([2H])c2c(-c3cc4ccc5ccccc5c4c4ccccc34)c3c([2H])c([2H])c([2H])c([2H])c3c(-c3ccc(-c4ccc5ccccc5c4)cc3)c2c1[2H]]

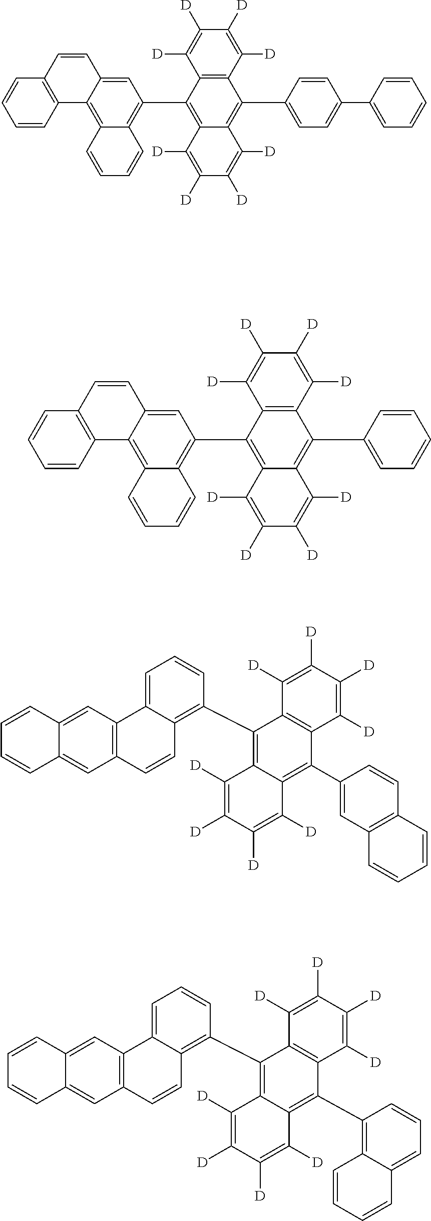 [SMILES: [2H]c1c([2H])c([2H])c2c(-c3cc4ccc5ccccc5c4c4ccccc34)c3c([2H])c([2H])c([2H])c([2H])c3c(-c3ccc(-c4ccccc4)cc3)c2c1[2H] ; [2H]c1c([2H])c([2H])c2c(-c3cc4ccc5ccccc5c4c4ccccc34)c3c([2H])c([2H])c([2H])c([2H])c3c(-c3ccccc3)c2c1[2H] ; [2H]c1c([2H])c([2H])c2c(-c3cccc4c3ccc3cc5ccccc5cc34)c3c([2H])c([2H])c([2H])c([2H])c3c(-c3ccc4ccccc4c3)c2c1[2H] ; [2H]c1c([2H])c([2H])c2c(-c3cccc4c3ccc3cc5ccccc5cc34)c3c([2H])c([2H])c([2H])c([2H])c3c(-c3cccc4ccccc34)c2c1[2H]]

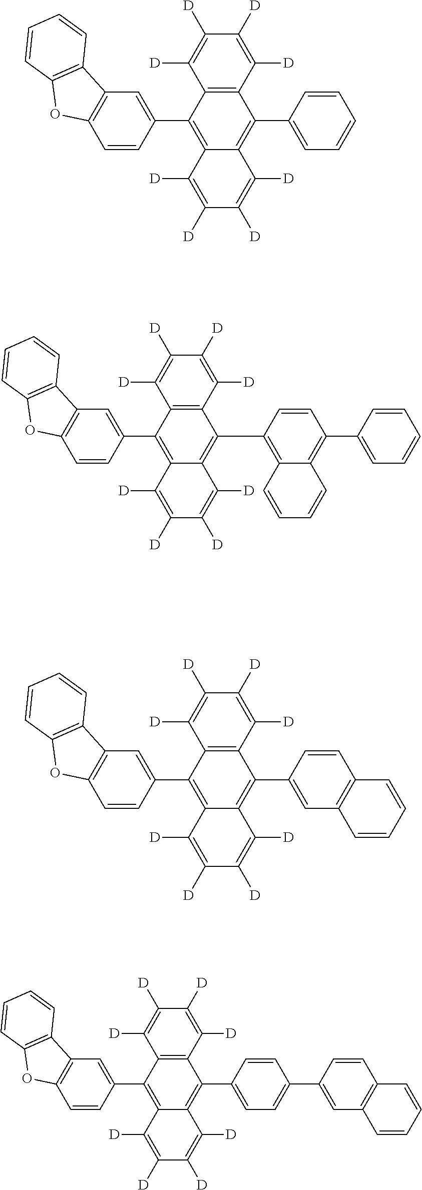 [SMILES: [2H]c1c([2H])c([2H])c2c(-c3ccc4oc5ccccc5c4c3)c3c([2H])c([2H])c([2H])c([2H])c3c(-c3ccccc3)c2c1[2H] ; [2H]c1c([2H])c([2H])c2c(-c3ccc(-c4ccccc4)c4ccccc34)c3c([2H])c([2H])c([2H])c([2H])c3c(-c3ccc4oc5ccccc5c4c3)c2c1[2H] ; [2H]c1c([2H])c([2H])c2c(-c3ccc4oc5ccccc5c4c3)c3c([2H])c([2H])c([2H])c([2H])c3c(-c3ccc4ccccc4c3)c2c1[2H] ; [2H]c1c([2H])c([2H])c2c(-c3ccc4oc5ccccc5c4c3)c3c([2H])c([2H])c([2H])c([2H])c3c(-c3ccc(-c4ccc5ccccc5c4)cc3)c2c1[2H]]

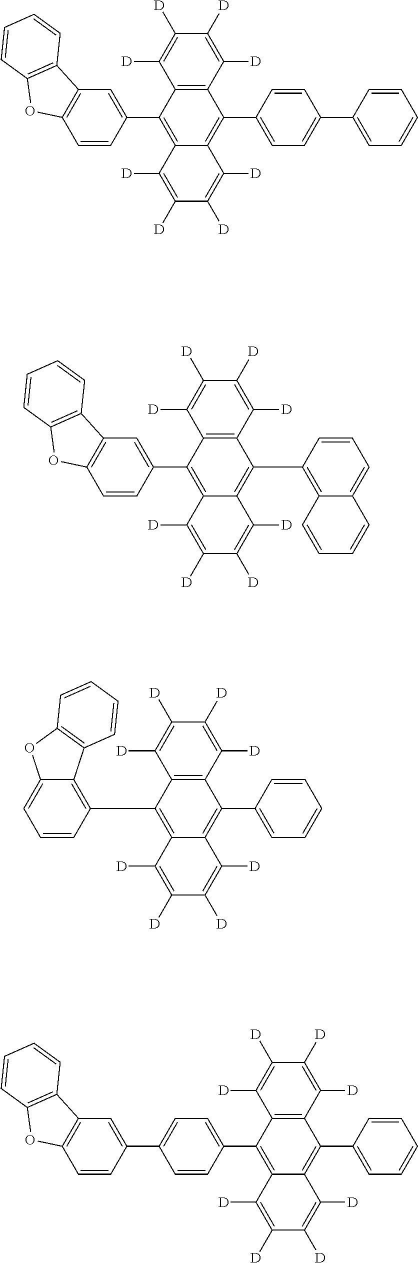 [SMILES: [2H]c1c([2H])c([2H])c2c(-c3ccc4oc5ccccc5c4c3)c3c([2H])c([2H])c([2H])c([2H])c3c(-c3ccc(-c4ccccc4)cc3)c2c1[2H] ; [2H]c1c([2H])c([2H])c2c(-c3cccc4ccccc34)c3c([2H])c([2H])c([2H])c([2H])c3c(-c3ccc4oc5ccccc5c4c3)c2c1[2H] ; [2H]c1c([2H])c([2H])c2c(-c3cccc4oc5ccccc5c34)c3c([2H])c([2H])c([2H])c([2H])c3c(-c3ccccc3)c2c1[2H] ; [2H]c1c([2H])c([2H])c2c(-c3ccc(-c4ccc5oc6ccccc6c5c4)cc3)c3c([2H])c([2H])c([2H])c([2H])c3c(-c3ccccc3)c2c1[2H]]

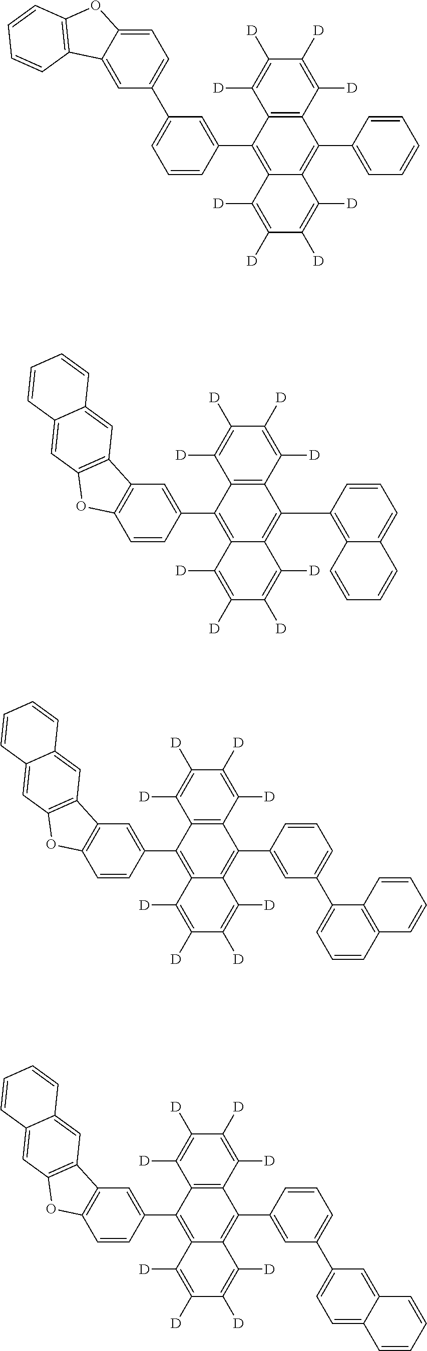 [SMILES: [2H]c1c([2H])c([2H])c2c(-c3cccc(-c4ccc5oc6ccccc6c5c4)c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5cc6ccccc6cc5c4c3)c2c1[2H] ; [2H]c1c([2H])c([2H])c2c(-c3ccc4oc5cc6ccccc6cc5c4c3)c3c([2H])c([2H])c([2H])c([2H])c3c(-c3cccc(-c4cccc5ccccc45)c3)c2c1[2H] ; [2H]c1c([2H])c([2H])c2c(-c3ccc4oc5cc6ccccc6cc5c4c3)c3c([2H])c([2H])c([2H])c([2H])c3c(-c3cccc(-c4ccc5ccccc5c4)c3)c2c1[2H]]

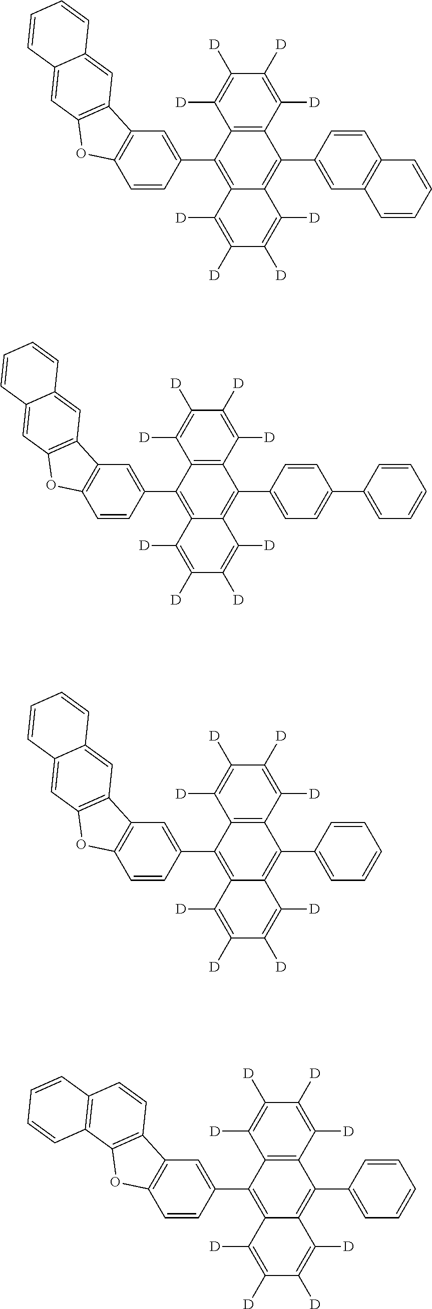 [SMILES: [2H]c1c([2H])c([2H])c2c(-c3ccc4oc5cc6ccccc6cc5c4c3)c3c([2H])c([2H])c([2H])c([2H])c3c(-c3ccc4ccccc4c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc(-c4ccccc4)cc3)c2c1[2H] ; [2H]c1c([2H])c([2H])c2c(-c3ccc4oc5cc6ccccc6cc5c4c3)c3c([2H])c([2H])c([2H])c([2H])c3c(-c3ccccc3)c2c1[2H] ; [2H]c1c([2H])c([2H])c2c(-c3ccc4oc5c6ccccc6ccc5c4c3)c3c([2H])c([2H])c([2H])c([2H])c3c(-c3ccccc3)c2c1[2H]]

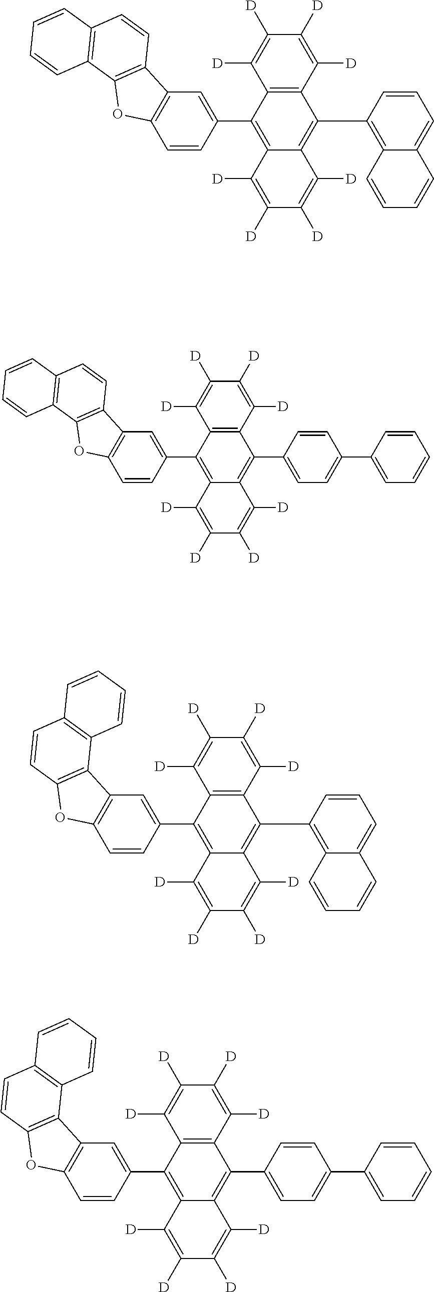 [SMILES: [2H]c1c([2H])c([2H])c2c(-c3cccc4ccccc34)c3c([2H])c([2H])c([2H])c([2H])c3c(-c3ccc4oc5c6ccccc6ccc5c4c3)c2c1[2H] ; [2H]c1c([2H])c([2H])c2c(-c3ccc4oc5c6ccccc6ccc5c4c3)c3c([2H])c([2H])c([2H])c([2H])c3c(-c3ccc(-c4ccccc4)cc3)c2c1[2H] ; [2H]c1c([2H])c([2H])c2c(-c3cccc4ccccc34)c3c([2H])c([2H])c([2H])c([2H])c3c(-c3ccc4oc5ccc6ccccc6c5c4c3)c2c1[2H] ; [2H]c1c([2H])c([2H])c2c(-c3ccc4oc5ccc6ccccc6c5c4c3)c3c([2H])c([2H])c([2H])c([2H])c3c(-c3ccc(-c4ccccc4)cc3)c2c1[2H]]

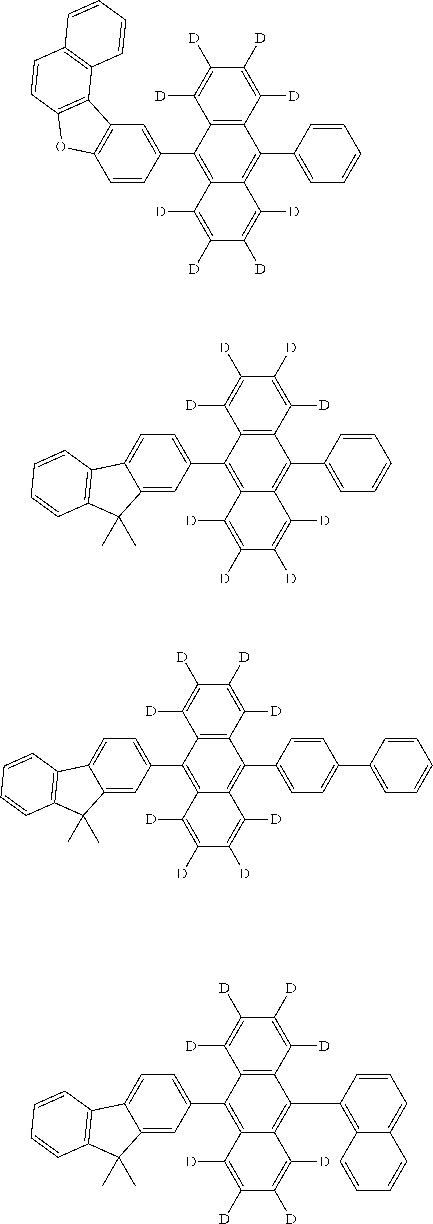 [SMILES: [2H]c1c([2H])c([2H])c2c(-c3ccc4oc5ccc6ccccc6c5c4c3)c3c([2H])c([2H])c([2H])c([2H])c3c(-c3ccccc3)c2c1[2H] ; [2H]c1c([2H])c([2H])c2c(-c3ccc4c(c3)C(C)(C)c3ccccc3-4)c3c([2H])c([2H])c([2H])c([2H])c3c(-c3ccccc3)c2c1[2H] ; [2H]c1c([2H])c([2H])c2c(-c3ccc4c(c3)C(C)(C)c3ccccc3-4)c3c([2H])c([2H])c([2H])c([2H])c3c(-c3ccc(-c4ccccc4)cc3)c2c1[2H] ; [2H]c1c([2H])c([2H])c2c(-c3cccc4ccccc34)c3c([2H])c([2H])c([2H])c([2H])c3c(-c3ccc4c(c3)C(C)(C)c3ccccc3-4)c2c1[2H]]

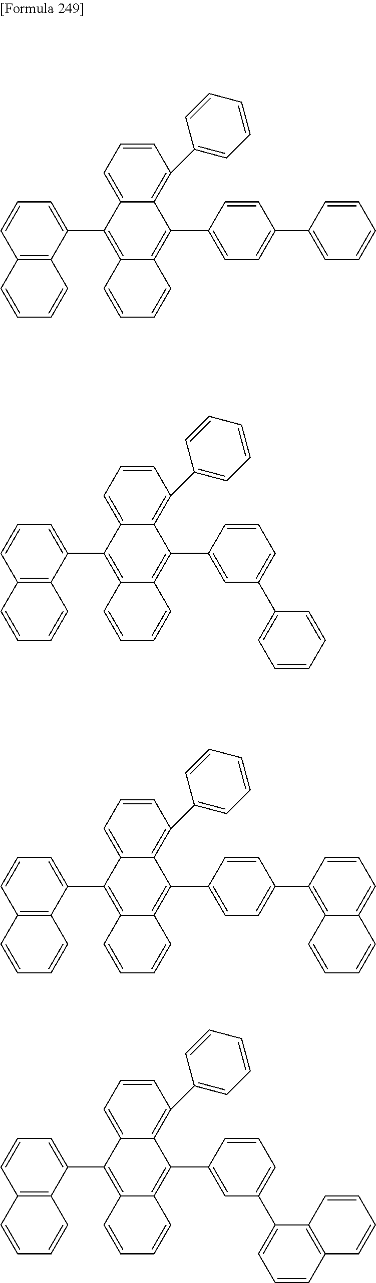

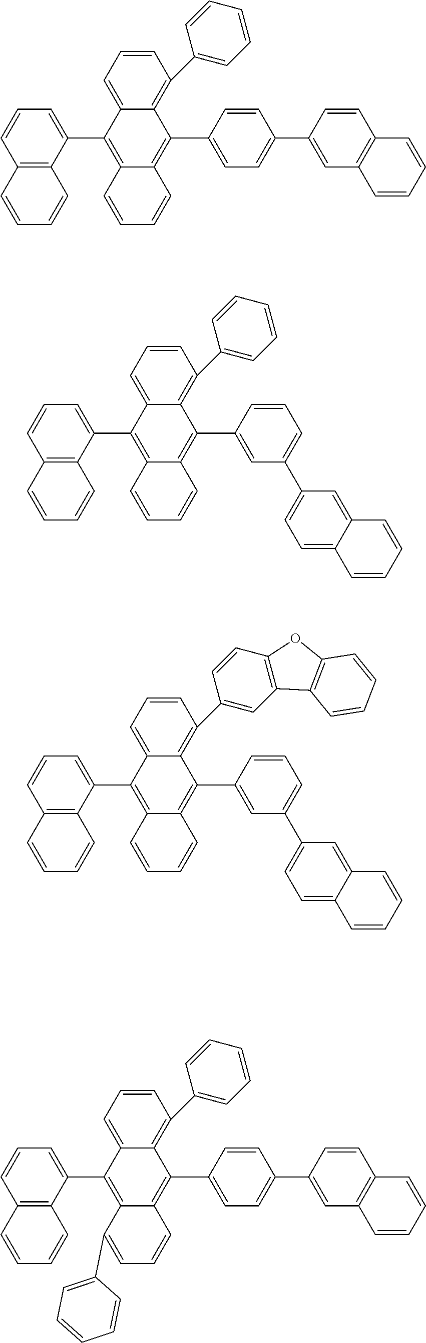

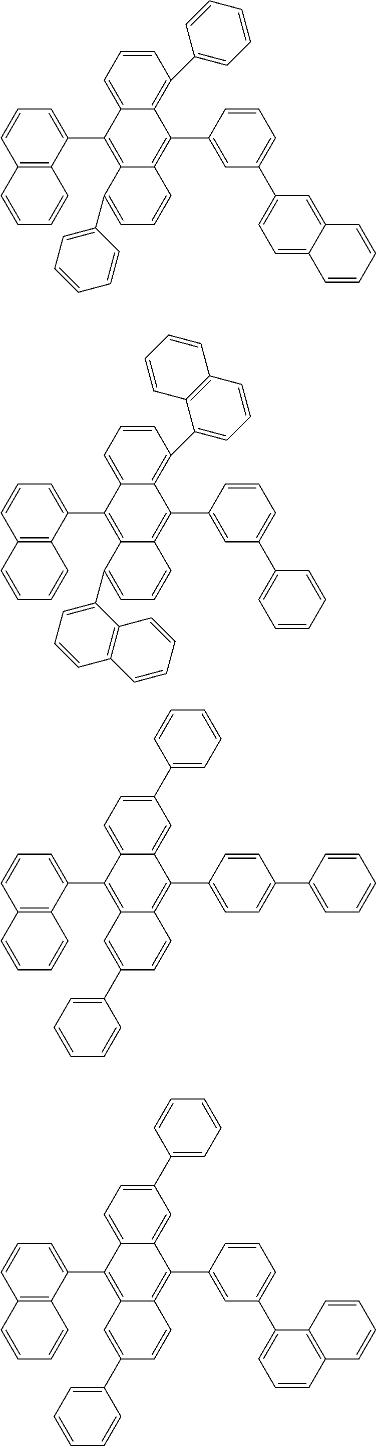

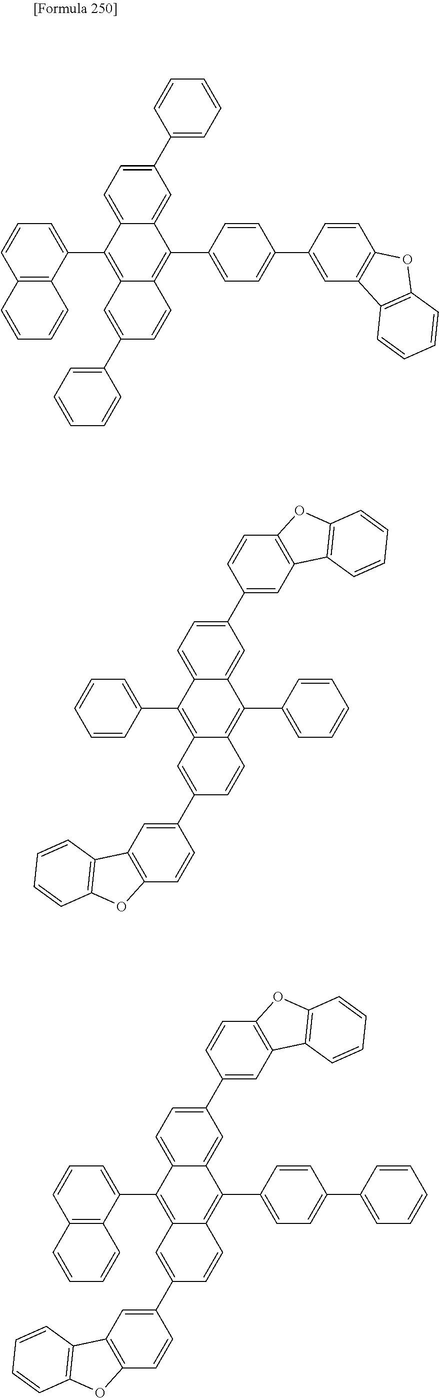 [SMILES: c1ccc(-c2ccc3c(-c4cccc5ccccc45)c4cc(-c5ccccc5)ccc4c(-c4ccc(-c5ccc6oc7ccccc7c6c5)cc4)c3c2)cc1 ; c1ccc(-c2c3ccc(-c4ccc5oc6ccccc6c5c4)cc3c(-c3ccccc3)c3ccc(-c4ccc5oc6ccccc6c5c4)cc23)cc1 ; c1ccc(-c2ccc(-c3c4cc(-c5ccc6oc7ccccc7c6c5)ccc4c(-c4cccc5ccccc45)c4cc(-c5ccc6oc7ccccc7c6c5)ccc34)cc2)cc1]

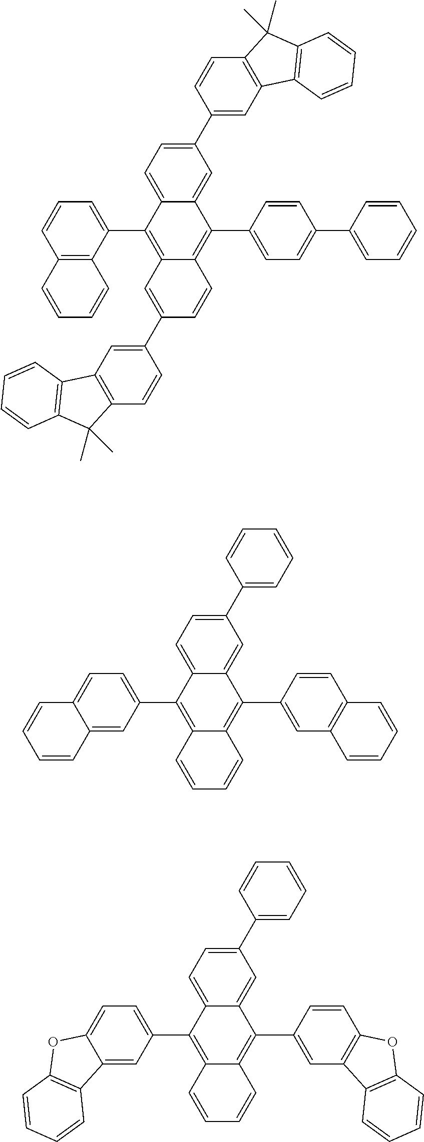

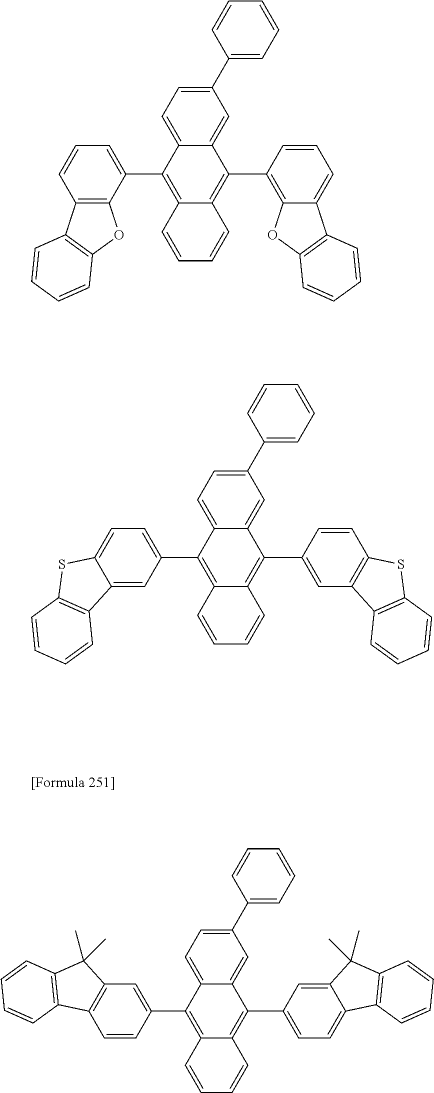

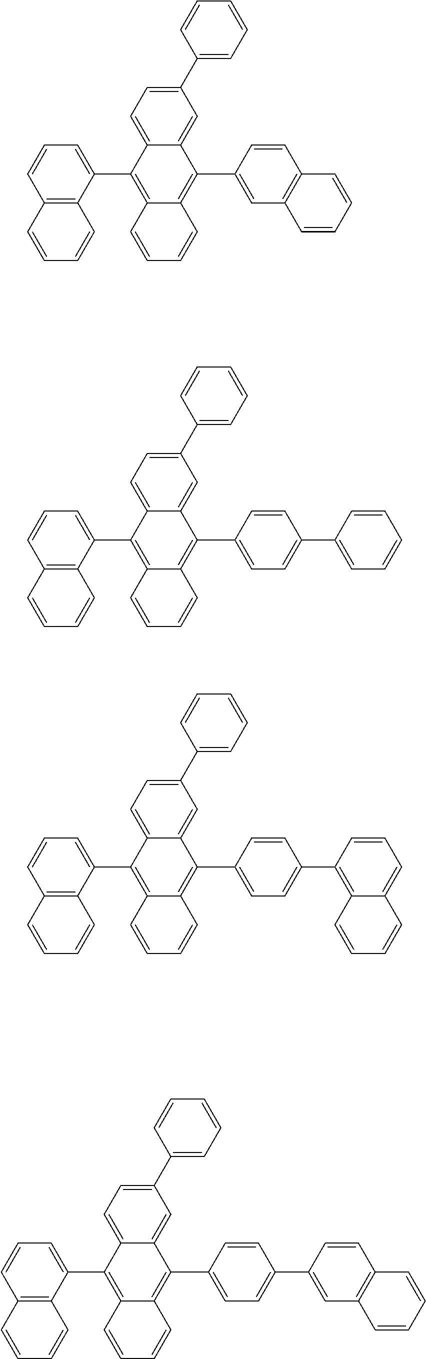

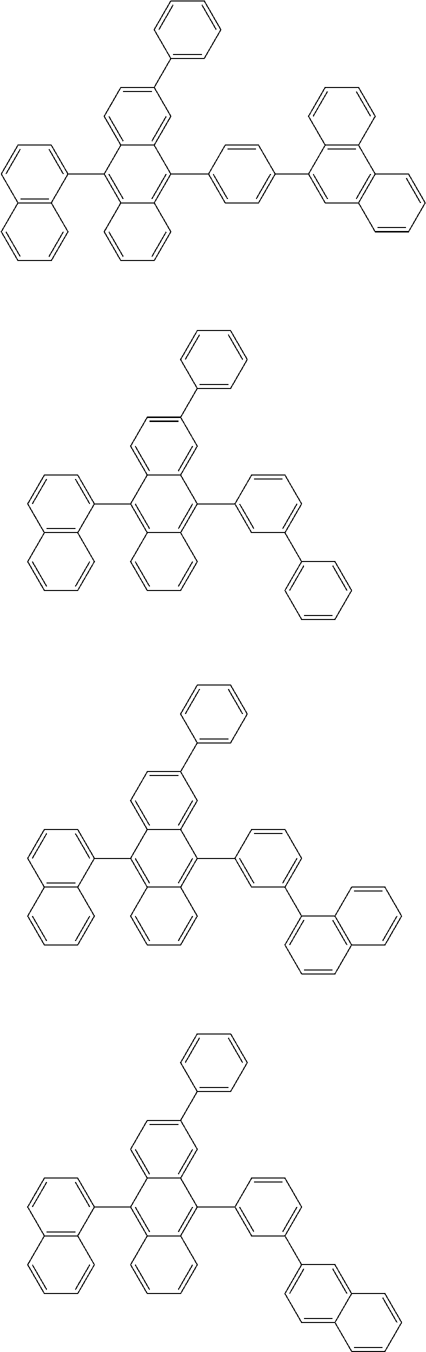

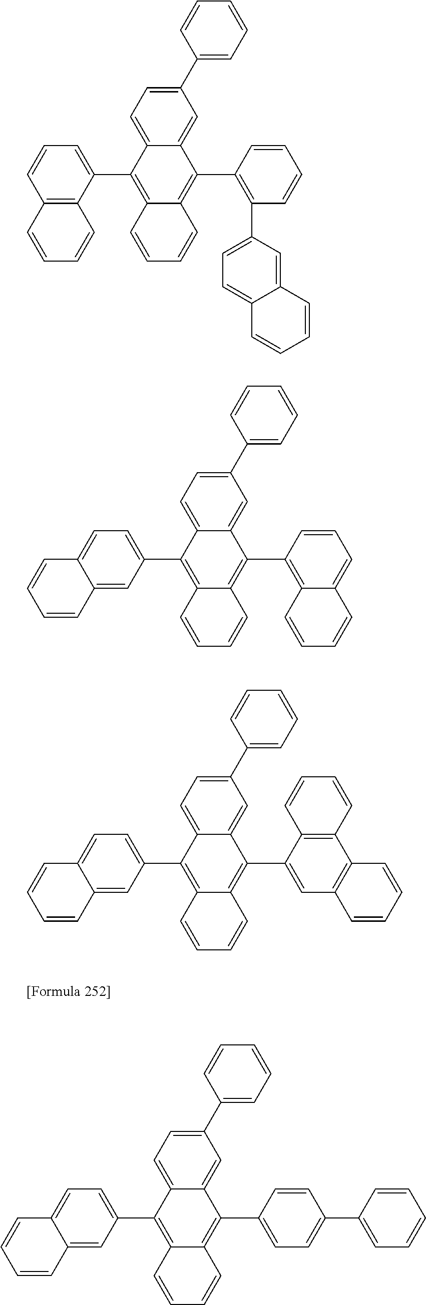

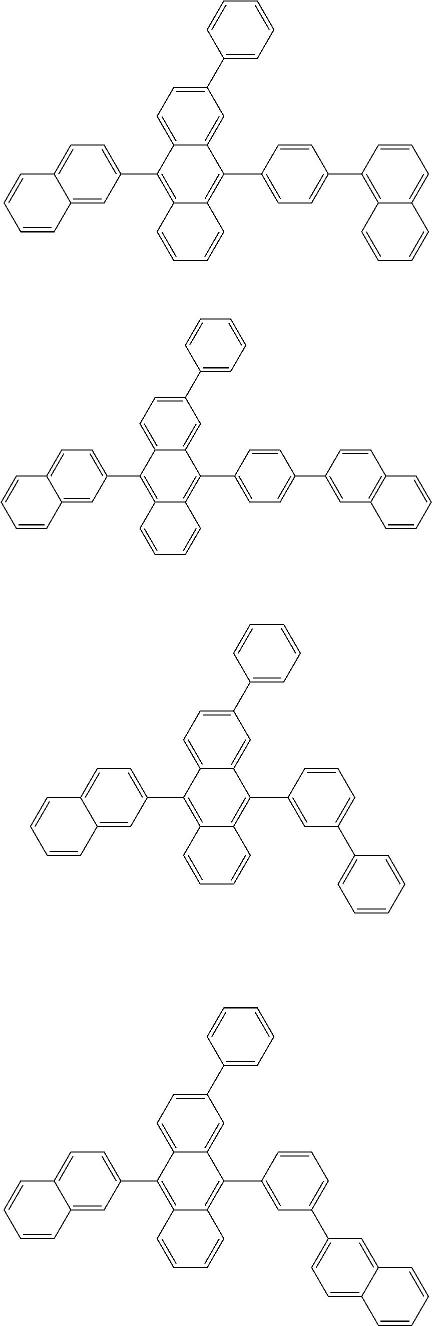

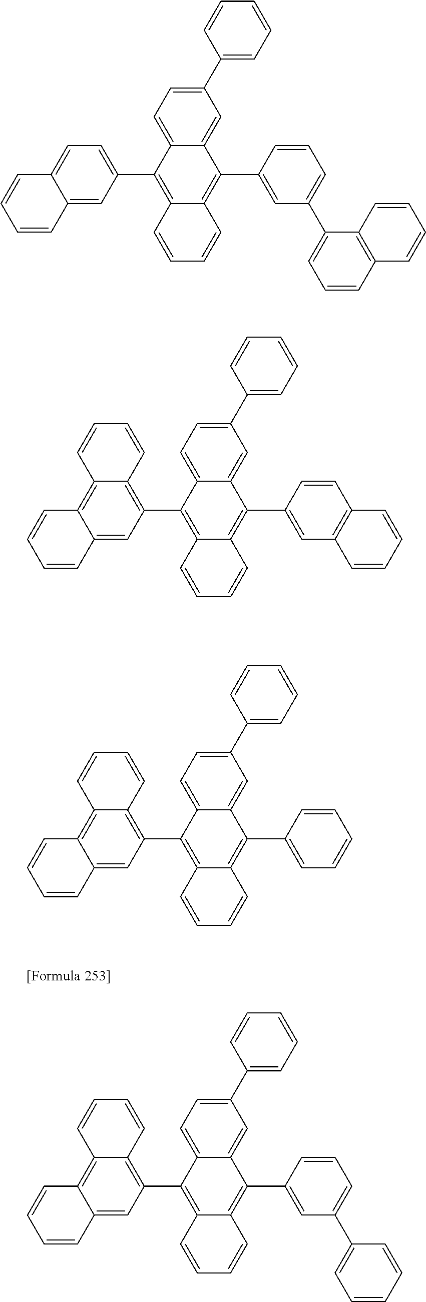

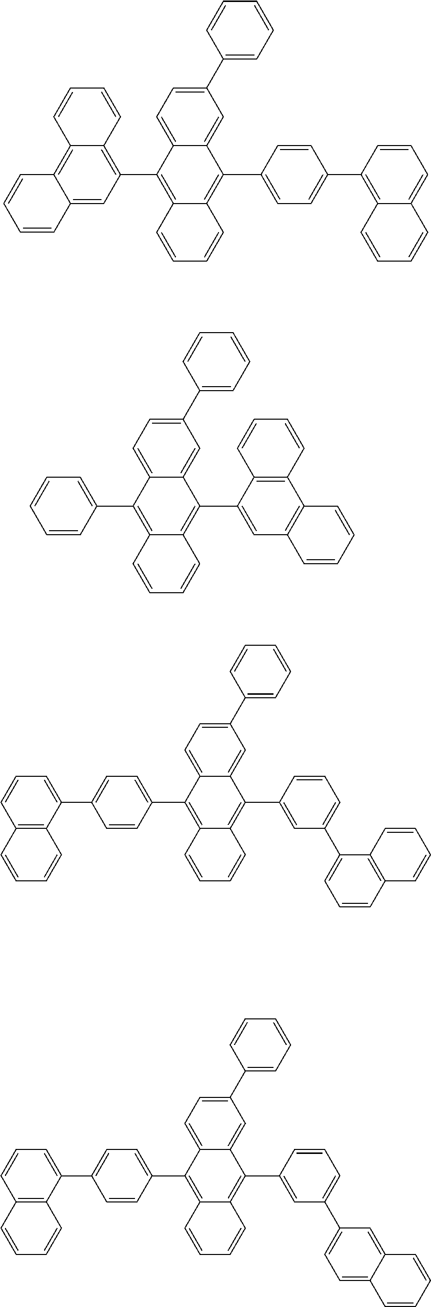

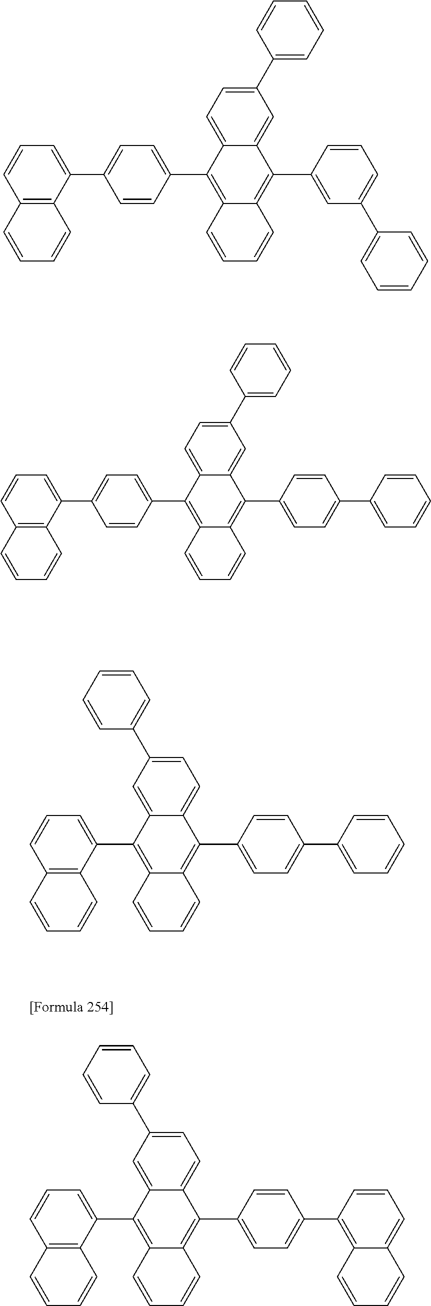

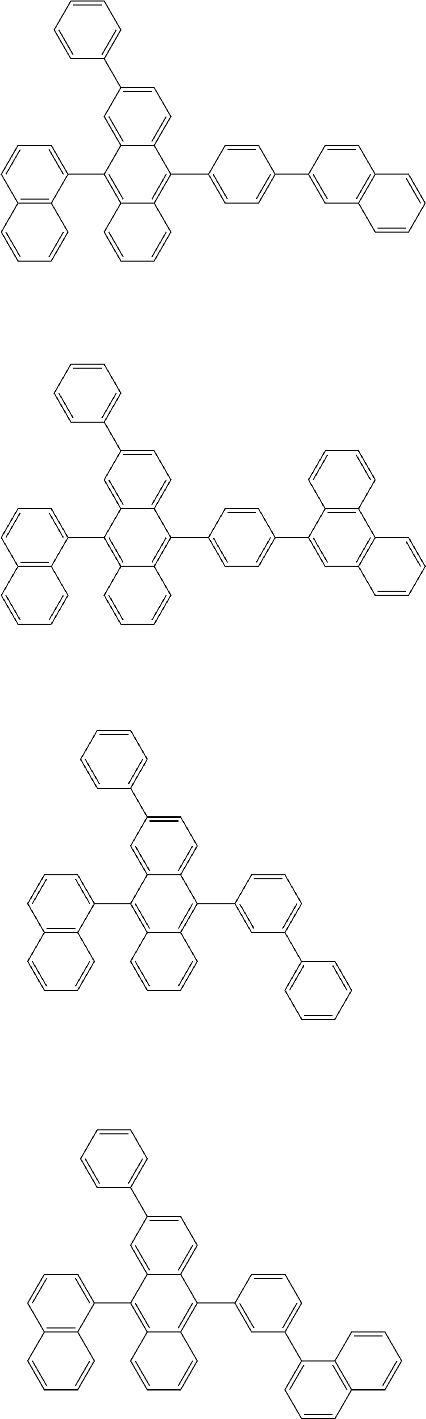

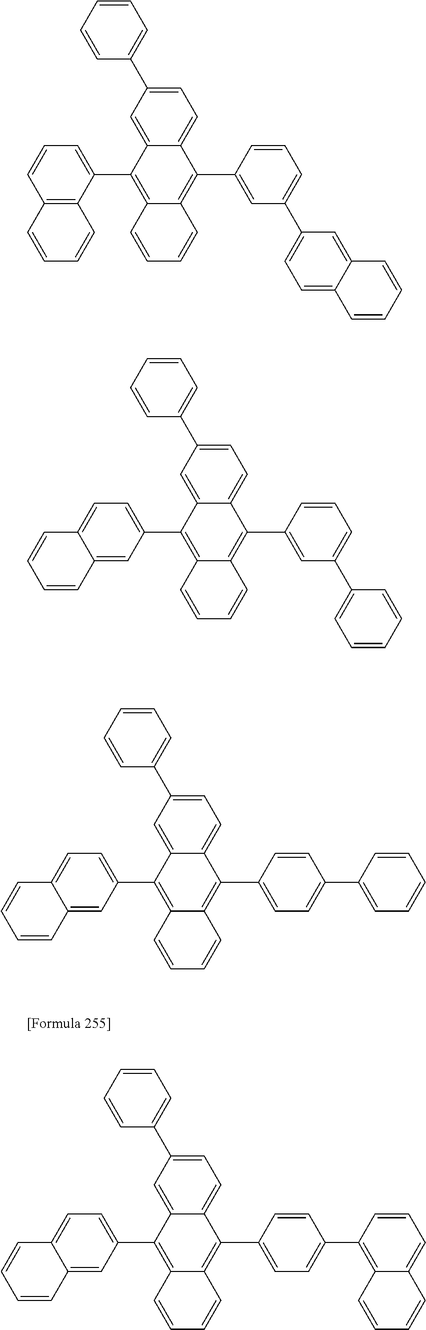

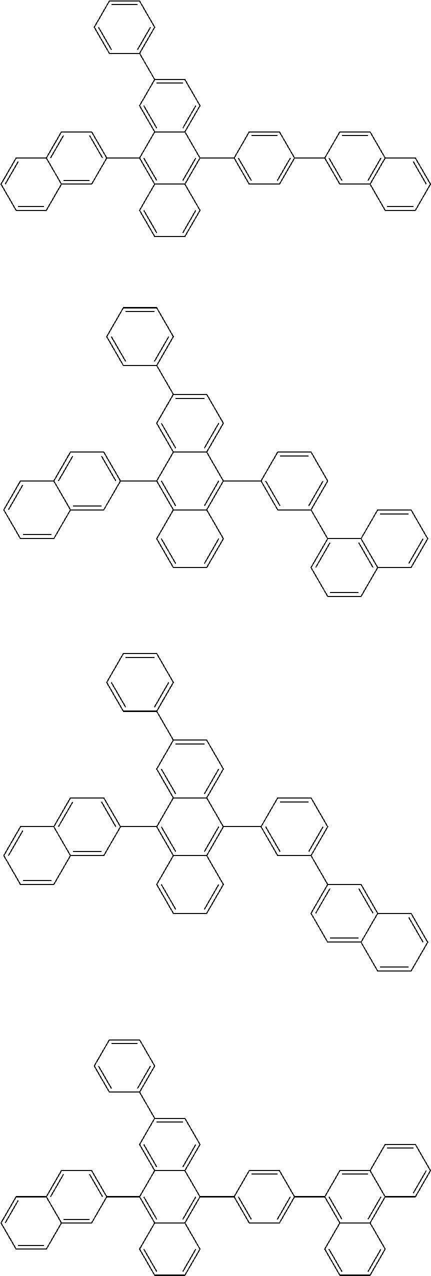

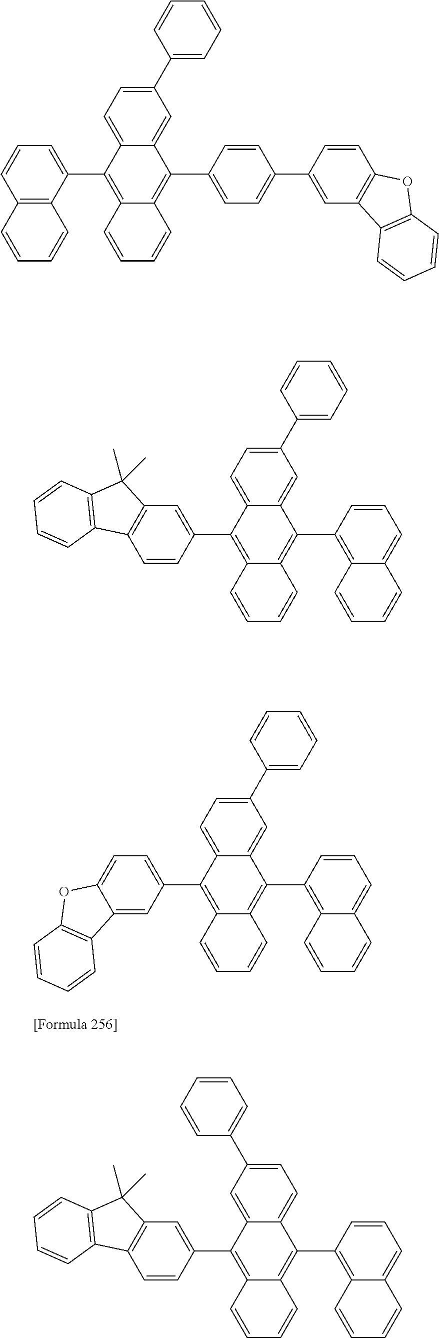

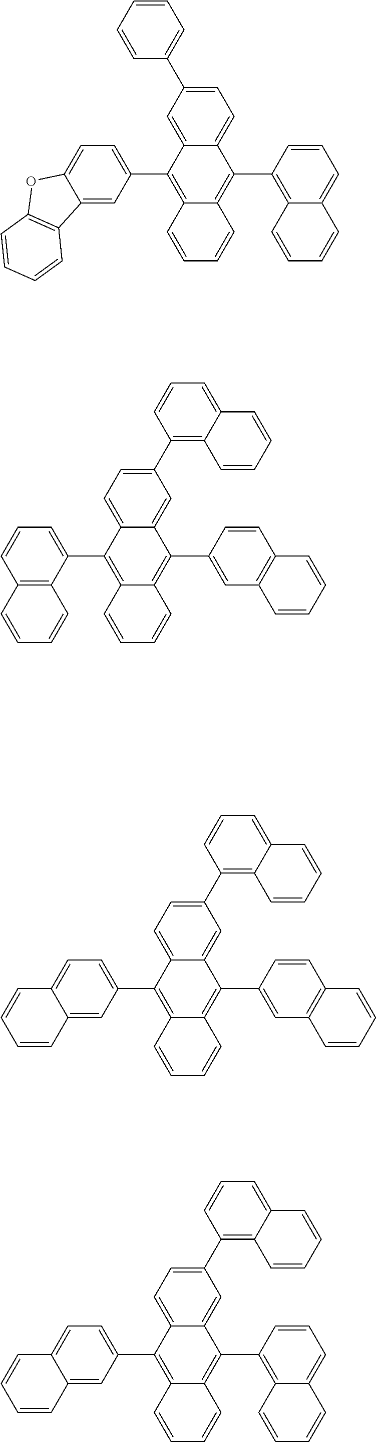

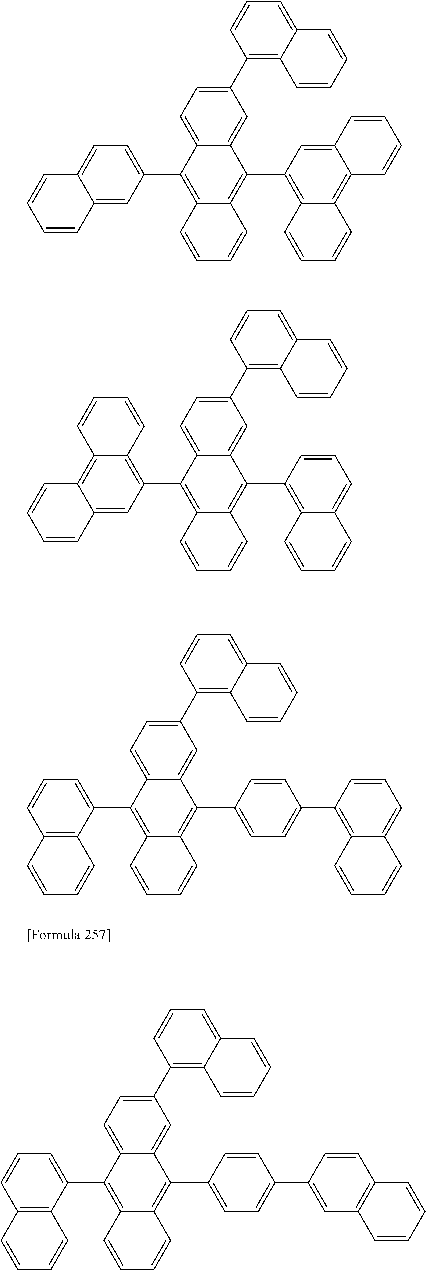

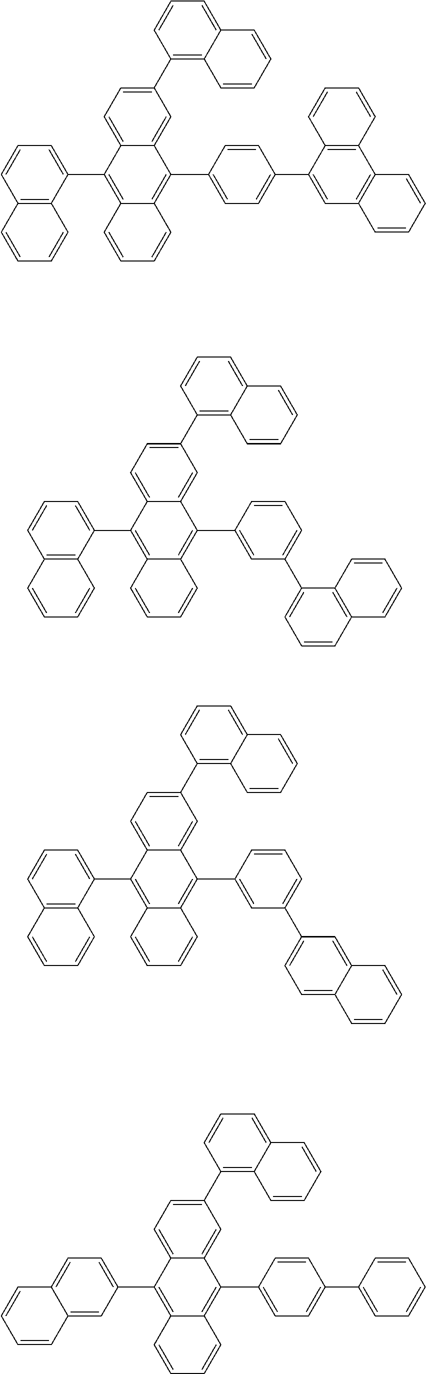

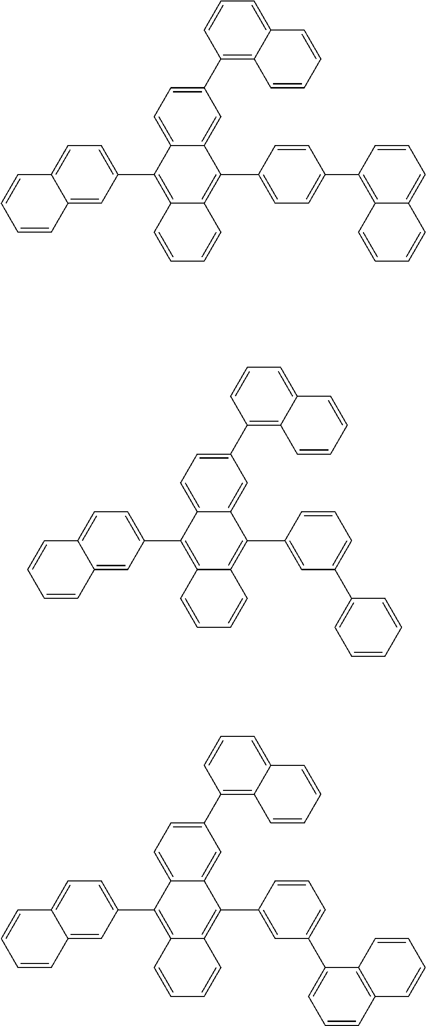

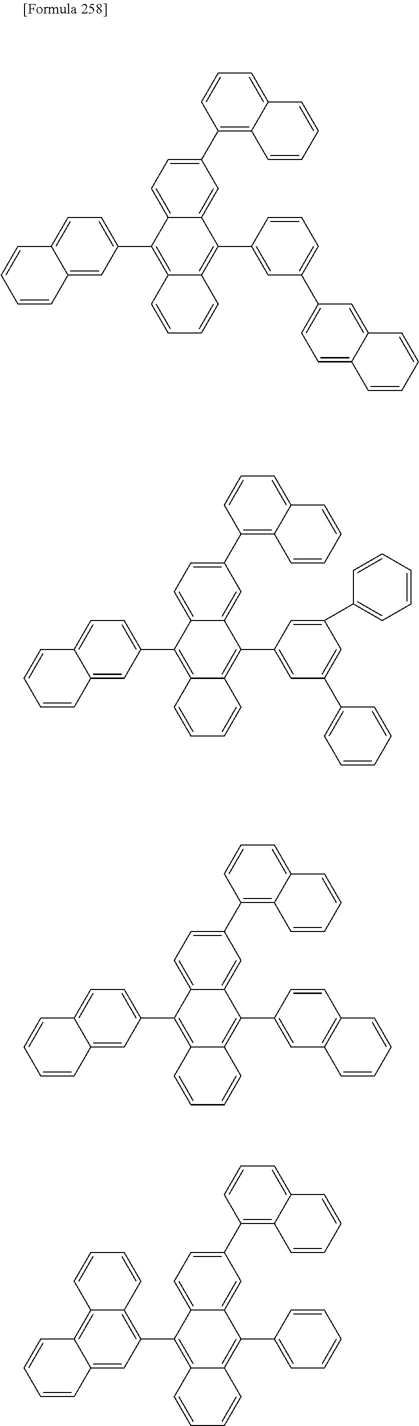

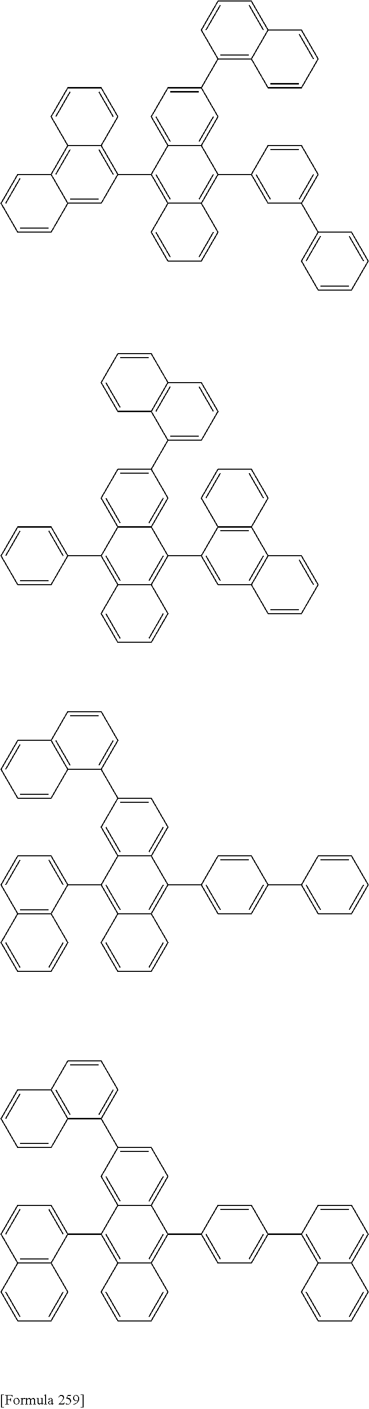

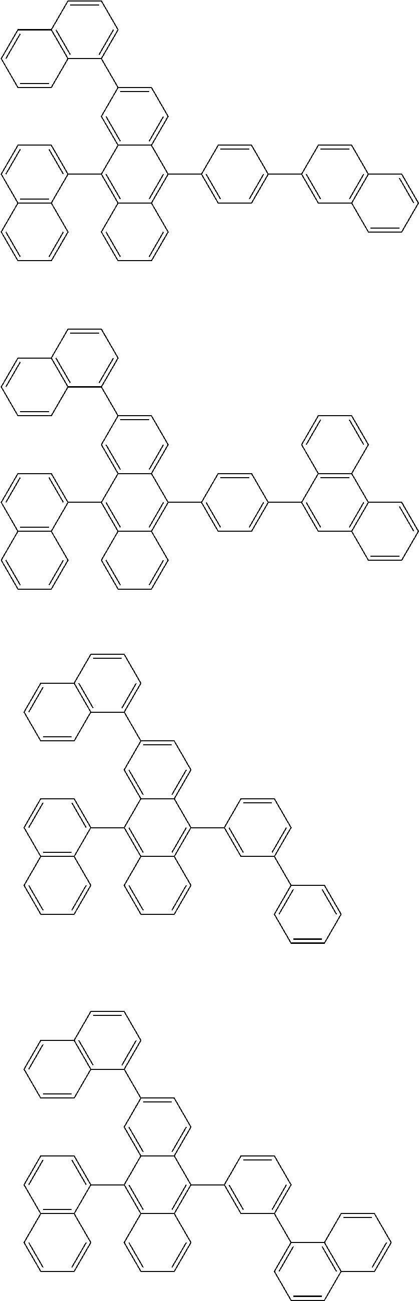

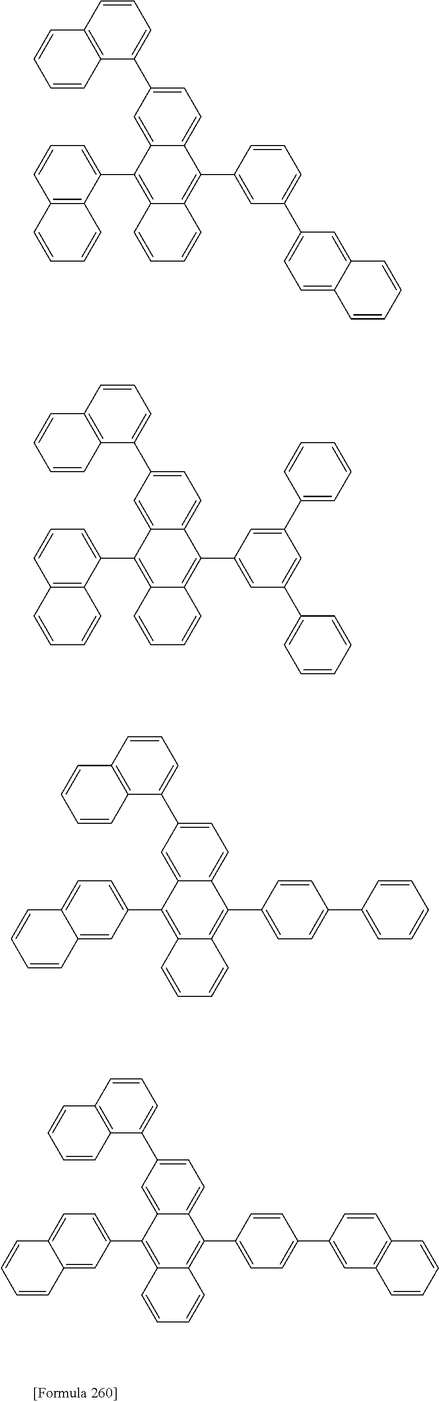

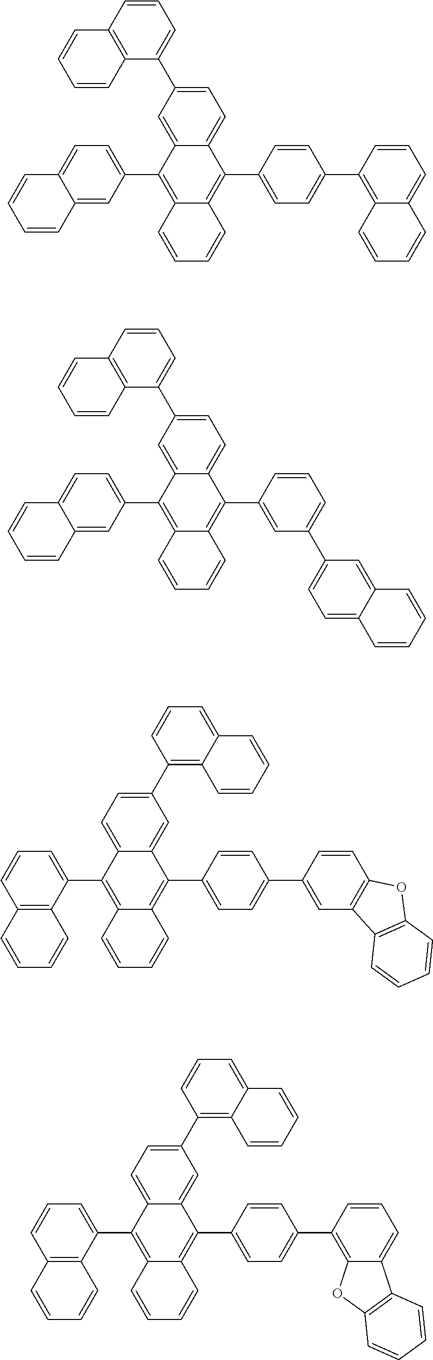

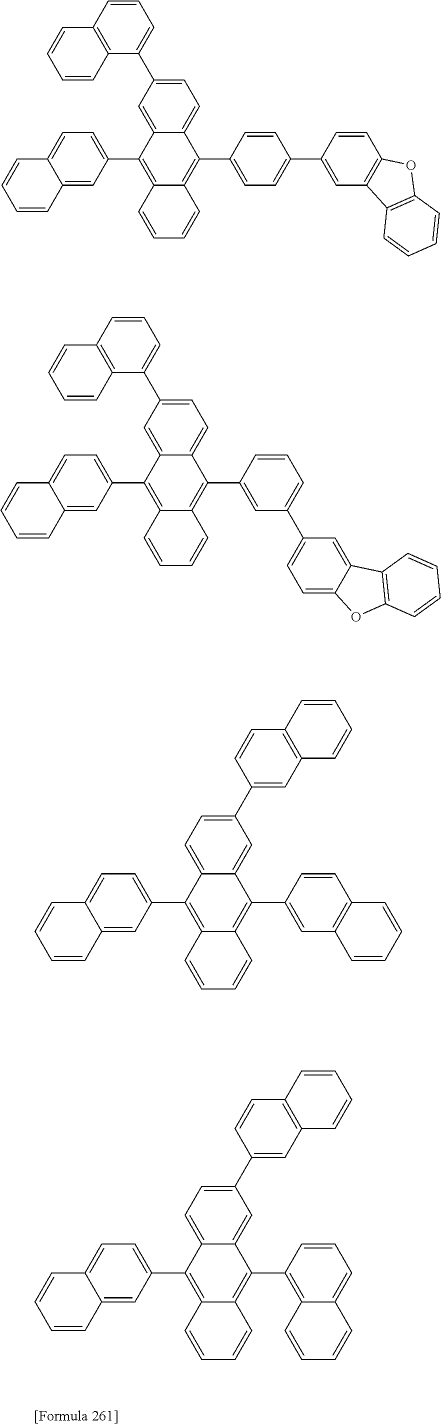

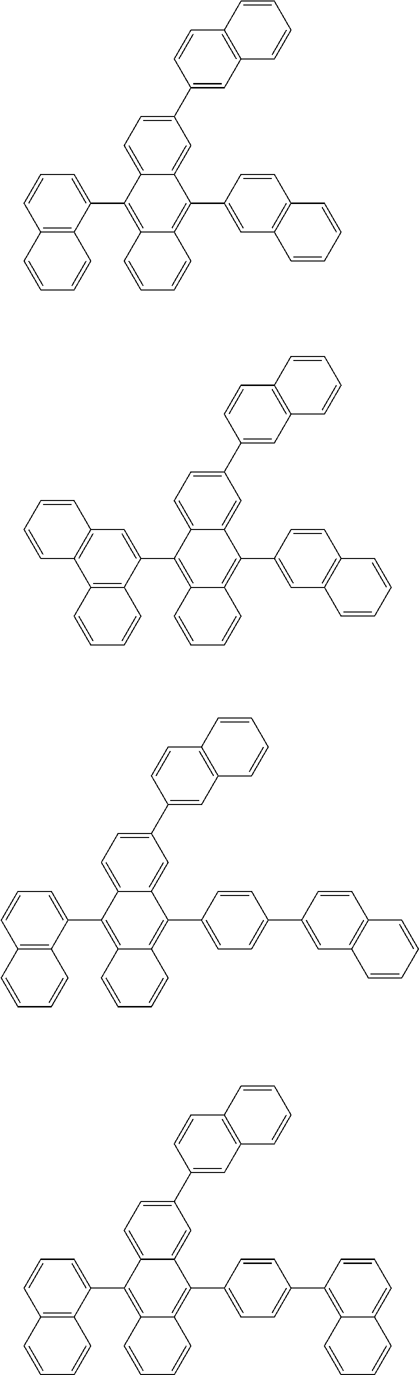

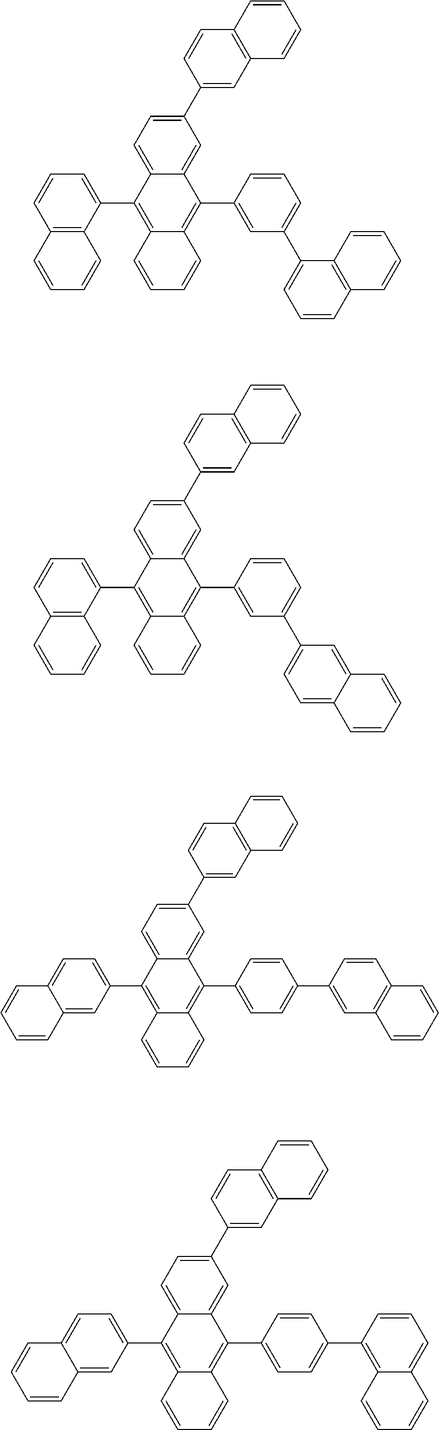

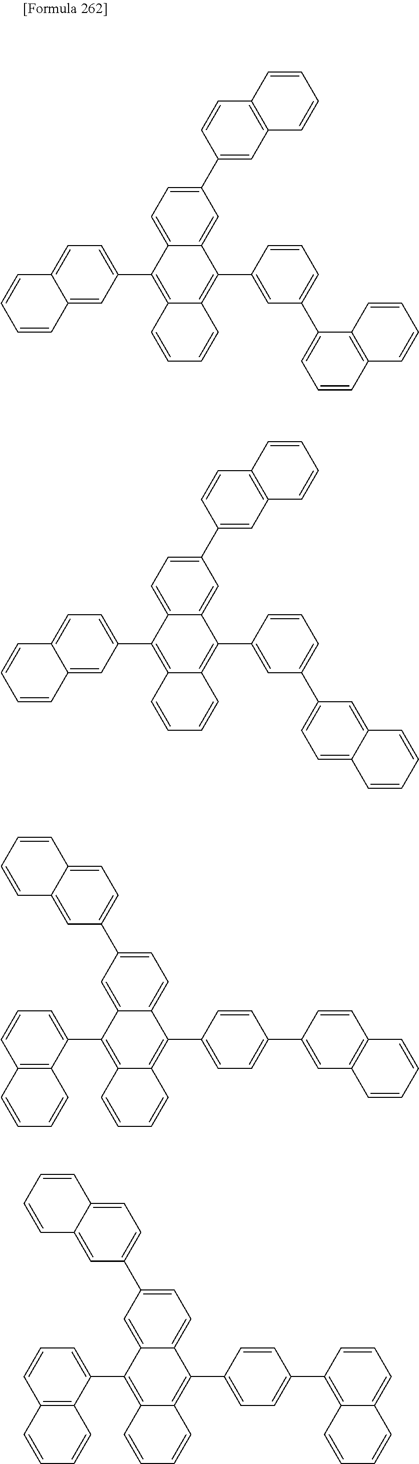

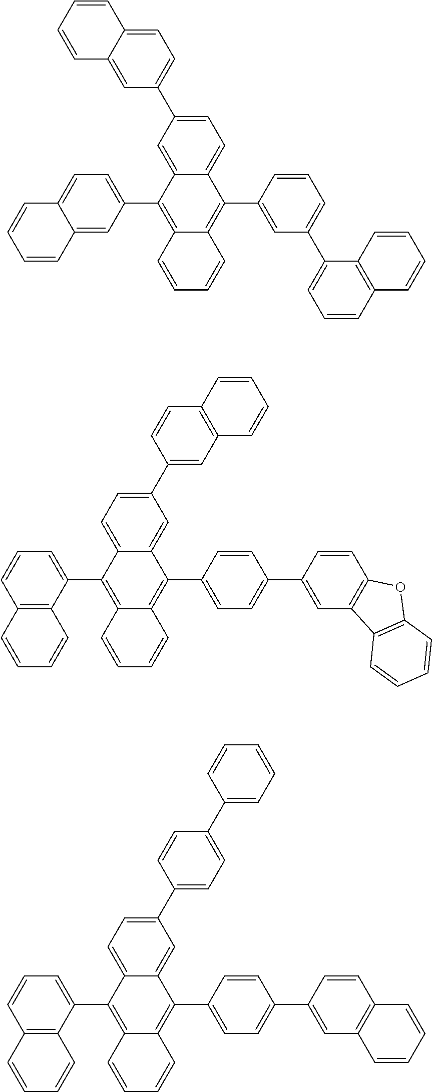

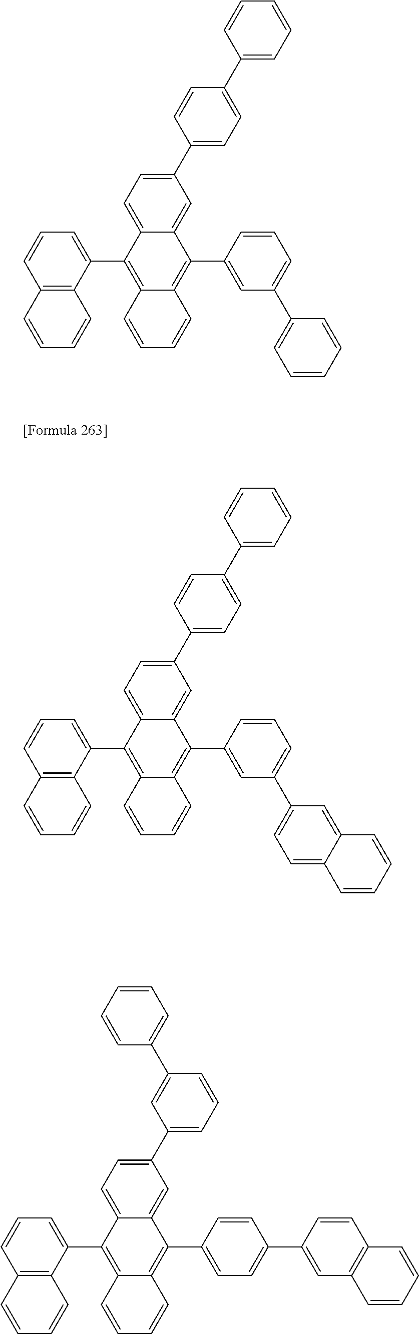

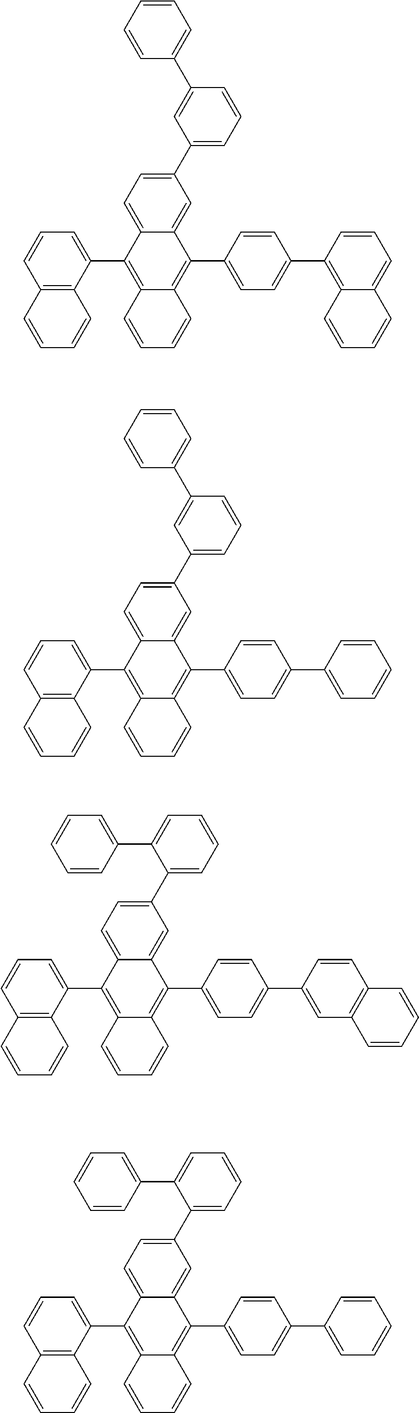

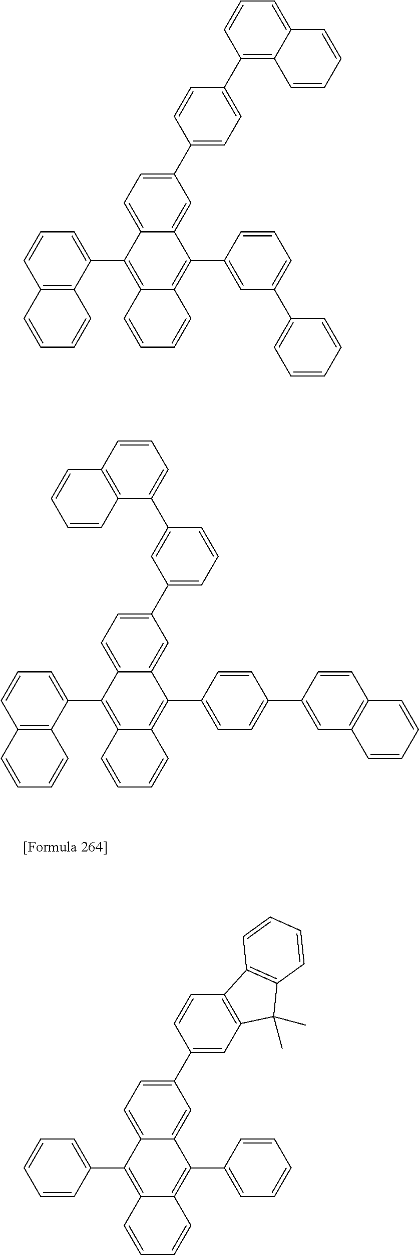

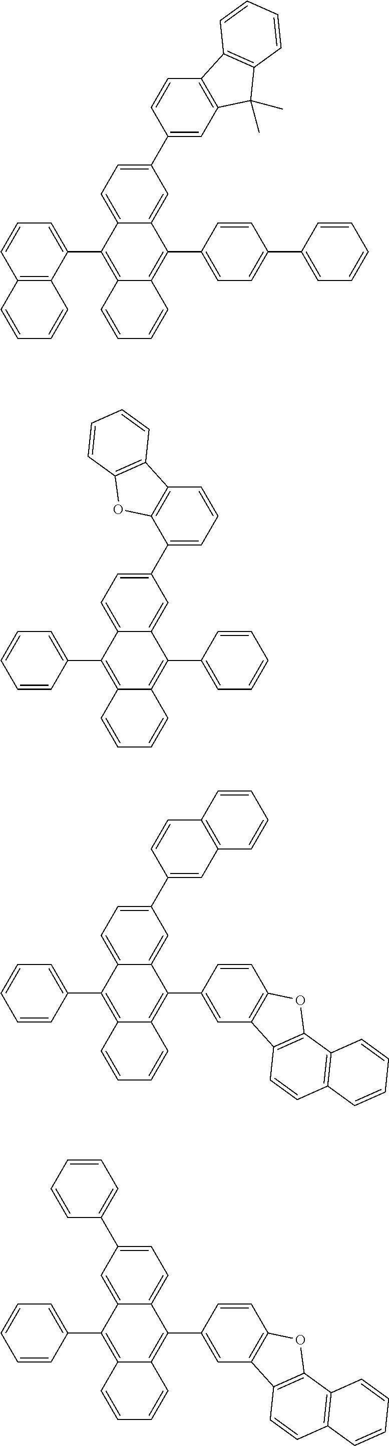

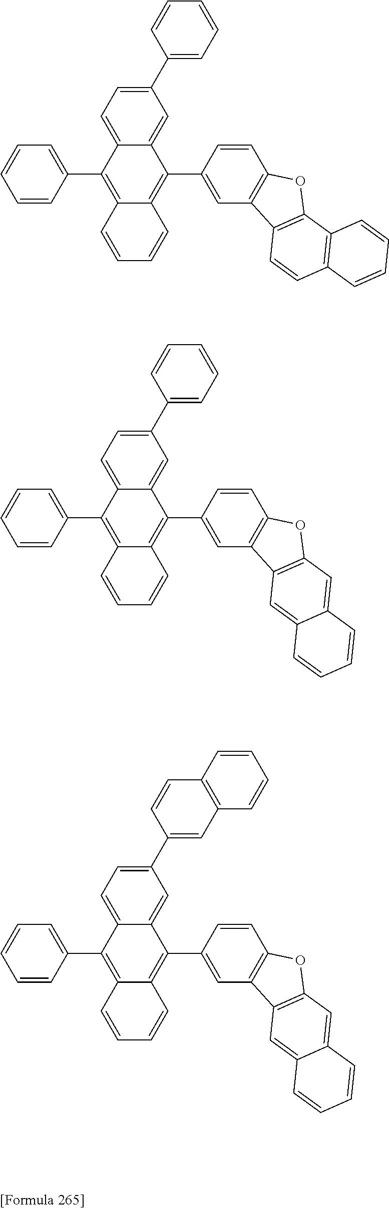 [SMILES: c1ccc(-c2ccc3c(-c4ccccc4)c4ccccc4c(-c4ccc5oc6c7ccccc7ccc6c5c4)c3c2)cc1 ; c1ccc(-c2ccc3c(-c4ccccc4)c4ccccc4c(-c4ccc5oc6cc7ccccc7cc6c5c4)c3c2)cc1 ; c1ccc(-c2c3ccccc3c(-c3ccc4oc5cc6ccccc6cc5c4c3)c3cc(-c4ccc5ccccc5c4)ccc23)cc1]

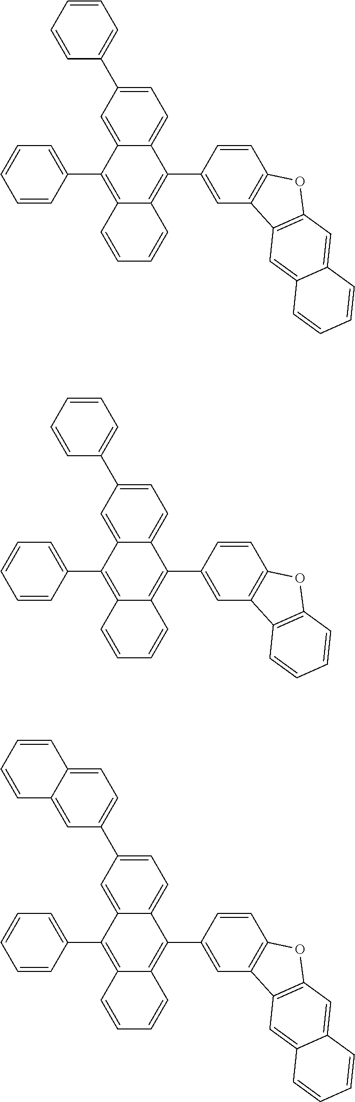 [SMILES: c1ccc(-c2ccc3c(-c4ccc5oc6cc7ccccc7cc6c5c4)c4ccccc4c(-c4ccccc4)c3c2)cc1 ; c1ccc(-c2ccc3c(-c4ccc5oc6ccccc6c5c4)c4ccccc4c(-c4ccccc4)c3c2)cc1 ; c1ccc(-c2c3ccccc3c(-c3ccc4oc5cc6ccccc6cc5c4c3)c3ccc(-c4ccc5ccccc5c4)cc23)cc1]

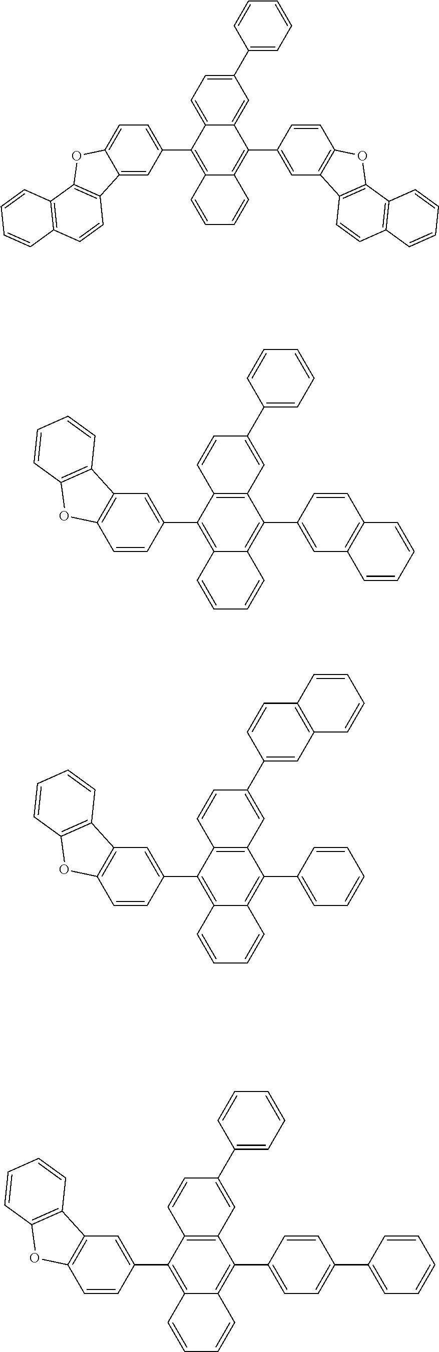 [SMILES: c1ccc(-c2ccc3c(-c4ccc5oc6c7ccccc7ccc6c5c4)c4ccccc4c(-c4ccc5oc6c7ccccc7ccc6c5c4)c3c2)cc1 ; c1ccc(-c2ccc3c(-c4ccc5oc6ccccc6c5c4)c4ccccc4c(-c4ccc5ccccc5c4)c3c2)cc1 ; c1ccc(-c2c3ccccc3c(-c3ccc4oc5ccccc5c4c3)c3ccc(-c4ccc5ccccc5c4)cc23)cc1 ; c1ccc(-c2ccc(-c3c4ccccc4c(-c4ccc5oc6ccccc6c5c4)c4ccc(-c5ccccc5)cc34)cc2)cc1]

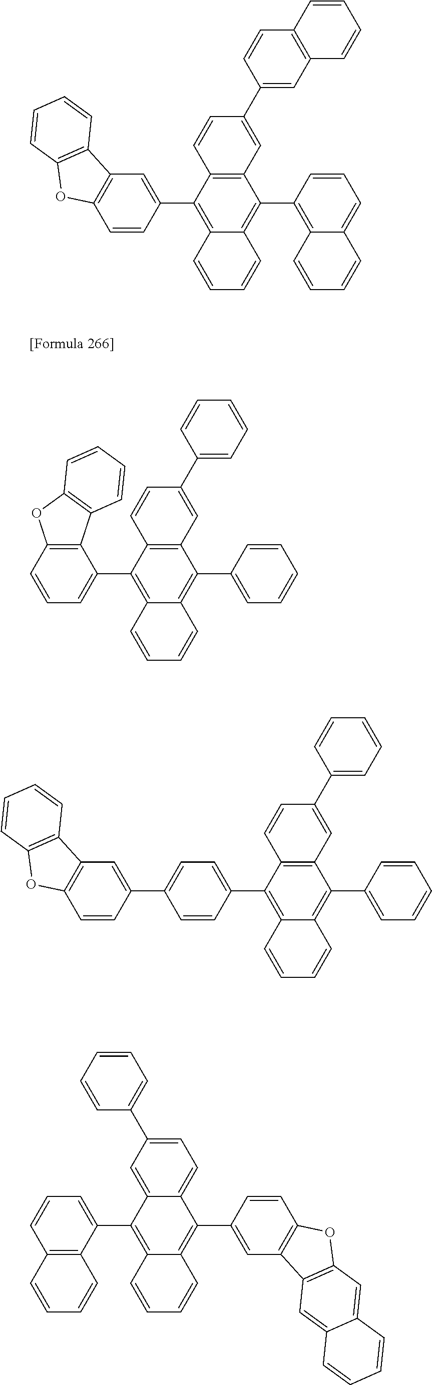 [SMILES: c1ccc2cc(-c3ccc4c(-c5ccc6oc7ccccc7c6c5)c5ccccc5c(-c5cccc6ccccc56)c4c3)ccc2c1 ; c1ccc(-c2ccc3c(-c4cccc5oc6ccccc6c45)c4ccccc4c(-c4ccccc4)c3c2)cc1 ; c1ccc(-c2ccc3c(-c4ccc(-c5ccc6oc7ccccc7c6c5)cc4)c4ccccc4c(-c4ccccc4)c3c2)cc1 ; c1ccc(-c2ccc3c(-c4ccc5oc6cc7ccccc7cc6c5c4)c4ccccc4c(-c4cccc5ccccc45)c3c2)cc1]

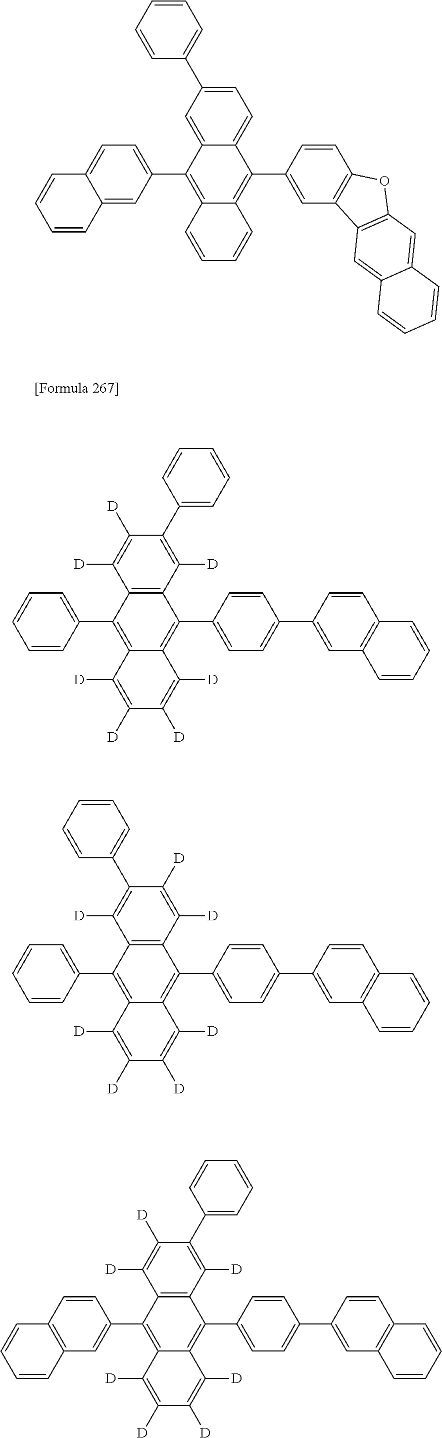 [SMILES: c1ccc(-c2ccc3c(-c4ccc5oc6cc7ccccc7cc6c5c4)c4ccccc4c(-c4ccc5ccccc5c4)c3c2)cc1 ; [2H]c1c([2H])c([2H])c2c(-c3ccc(-c4ccc5ccccc5c4)cc3)c3c([2H])c(-c4ccccc4)c([2H])c([2H])c3c(-c3ccccc3)c2c1[2H] ; [2H]c1c([2H])c([2H])c2c(-c3ccccc3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4ccccc4c3)c2c1[2H]]

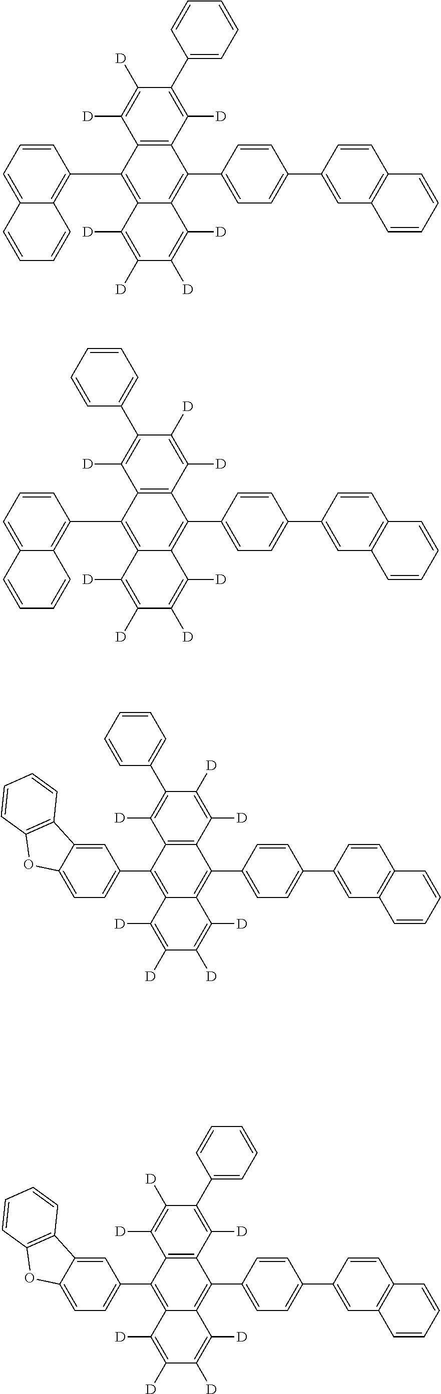 [SMILES: [2H]c1c([2H])c([2H])c2c(-c3cccc4ccccc34)c3c([2H])c([2H])c(-c4ccccc4)c([2H])c3c(-c3ccc(-c4ccc5ccccc5c4)cc3)c2c1[2H] ; [2H]c1c([2H])c([2H])c2c(-c3cccc4ccccc34)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc4oc5ccccc5c4c3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5ccccc5c4c3)c2c1[2H]]

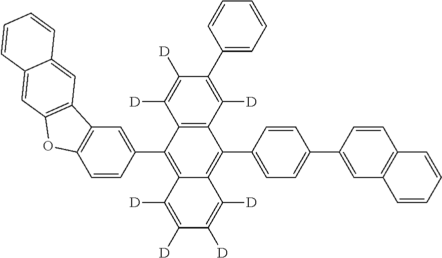 [SMILES: [2H]c1c([2H])c([2H])c2c(-c3ccc(-c4ccc5ccccc5c4)cc3)c3c([2H])c(-c4ccccc4)c([2H])c([2H])c3c(-c3ccc4oc5cc6ccccc6cc5c4c3)c2c1[2H]]

### First Emitting Compound

In an exemplary arrangement of the organic EL device of the exemplary embodiment, the first emitting compound is a compound represented by a formula (6) below.

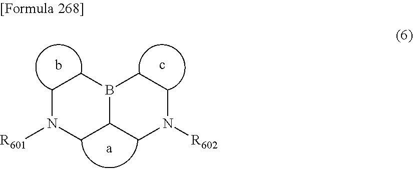

In the formula (6):
a ring a, a ring b and a ring c are each independently a substituted or unsubstituted aromatic hydrocarbon ring having 6 to 50 ring carbon atoms, or a substituted or unsubstituted heterocyclic ring having 5 to 50 ring atoms;
R₆₀₁ and R₆₀₂ are each independently bonded to the ring a, ring b or ring c to form a substituted or unsubstituted heterocycle, or not bonded thereto to form no substituted or unsubstituted heterocycle; and
R₆₀₁ and R₆₀₂ not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In an exemplary arrangement of the organic EL device of the exemplary embodiment, the ring a, ring b and ring c are each a ring (a substituted or unsubstituted aromatic hydrocarbon ring having 6 to 50 ring carbon atoms, or a substituted or unsubstituted heterocycle having 5 to 50 ring atoms) fused with a fused bicyclic structure formed of a boron atom and two nitrogen atoms at the center of the formula (6).

The “aromatic hydrocarbon ring” for the rings a, b, and c has the same structure as a compound formed by introducing a hydrogen atom to an “aryl group”.

Ring atoms of the “aromatic hydrocarbon ring” for the ring a include three carbon atoms on the fused bicyclic structure at the center of the formula (6).

Ring atoms of the “aromatic hydrocarbon ring” for the rings b and c include two carbon atoms on the fused bicyclic structure at the center of the formula (6).

Specific examples of the “substituted or unsubstituted aromatic hydrocarbon ring having 6 to 50 ring carbon atoms” include a compound formed by introducing a hydrogen atom to the “aryl group” described in the specific example group G1.

The “heterocycle” for the rings a, b, and c has the same structure as a compound formed by introducing a hydrogen atom to the “heterocyclic group” described above.

Ring atoms of the “heterocycle” for the ring a include three carbon atoms on the fused bicyclic structure at the center of the formula (6). Ring atoms of the “heterocycle” for the rings b and c include two carbon atoms on the fused bicyclic structure at the center of the formula (6). Specific examples of the “substituted or unsubstituted heterocycle having 5 to 50 ring atoms” include a compound formed by introducing a hydrogen atom to the “heterocyclic group” described in the specific example group G2.

R₆₀₁ and R₆₀₂ may be each independently bonded with the ring a, ring b, or ring c to form a substituted or unsubstituted heterocycle. The “heterocycle” in this arrangement includes a nitrogen atom on the fused bicyclic structure at the center of the formula (6). The heterocycle in the above arrangement optionally includes a hetero atom other than the nitrogen atom. R₆₀₁ and R₆₀₂ being bonded with the ring a, ring b, or ring c specifically means that atoms forming R₆₀₁ and R₆₀₂ are bonded with atoms forming the ring a, ring b, or ring c. For instance, R₆₀₁ may be bonded with the ring a to form a bicyclic (or tri-or-more cyclic) fused nitrogen-containing heterocycle, in which the ring including R₆₀₁ and the ring a are fused. Specific examples of the nitrogen-containing heterocycle include a compound corresponding to the nitrogen-containing bi(or-more)cyclic fused heterocyclic group in the specific example group G2.

The same applies to R₆₀₁ bonded with the ring b, R₆₀₂ bonded with the ring a, and R₆₀₂ bonded with the ring c.

R₆₀₁ and R₆₀₂ may be each independently not bonded with the ring a, ring b, or ring c.

In an exemplary embodiment, the ring a, ring b and ring c in the formula (6) are each independently a substituted or unsubstituted aromatic hydrocarbon ring having 6 to 50 ring carbon atoms.

In an exemplary embodiment, the ring a, ring b and ring c in the formula (6) are each independently a substituted or unsubstituted benzene ring or a substituted or unsubstituted naphthalene ring.

In an exemplary embodiment, R₆₀₁ and R₆₀₂ in the formula (6) are each independently a substituted or unsubstituted aryl group having 6 to 50 ring carbon atoms, or a substituted or unsubstituted heterocyclic group having 5 to 50 ring atoms, preferably a substituted or unsubstituted aryl group having 6 to 50 ring carbon atoms.

In an exemplary embodiment, the compound represented by the formula (6) is a compound represented by a formula (62) below.

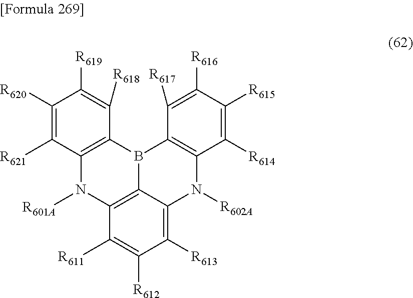

In the formula (62):
R_{601A} is bonded with at least one of R₆₁₁ or R₆₂₁ to form a substituted or unsubstituted heterocycle, or not bonded therewith to form no substituted or unsubstituted heterocycle;
R_{602A} is bonded with at least one of R₆₁₃ or R₆₁₄ to form a substituted or unsubstituted heterocycle, or not bonded therewith to form no substituted or unsubstituted heterocycle;
R_{601A} and R_{602A} not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
at least one combination of adjacent two or more of R₆₁₁ to R₆₂₁ are mutually bonded to form a substituted or unsubstituted monocyclic ring, mutually bonded to form a substituted or unsubstituted fused ring, or not mutually bonded;
R₆₁₁ to R₆₂₁ not forming the substituted or unsubstituted heterocycle, not forming the monocyclic ring, and not forming the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms. In the formula (62), R₉₀₁, R₉₀₂, R₉₀₃, R₉₀₄, R₉₀₅, R₉₀₆, and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.
R_{601A} and R_{602A} in the formula (62) are groups corresponding to R₆₀₁ and R₆₀₂ in the formula (6), respectively.

For instance, R_{601A} and R₆₁₁ are optionally bonded with each other to form a bicyclic (or tri-or-more cyclic) fused nitrogen-containing heterocycle, in which the ring including R_{601A} and R₆₁₁ and a benzene ring corresponding to the ring a are fused. Specific examples of the nitrogen-containing heterocycle include a compound corresponding to the nitrogen-containing bi(or-more)cyclic fused heterocyclic group in the specific example group G2. The same applies to R_{601A} bonded with R₆₂₁, R_{602A} bonded with R₆₁₃, and R_{602A} bonded with R₆₁₄.

At least one combination of adjacent two or more of R₆₁₁ to R₆₂₁ are mutually bonded to form a substituted or unsubstituted monocyclic ring, or mutually bonded to form a substituted or unsubstituted fused ring.

For instance, R₆₁₁ and R₆₁₂ are optionally mutually bonded to form a structure in which a benzene ring, indole ring, pyrrole ring, benzofuran ring, benzothiophene ring or the like is fused to the six-membered ring bonded with R₆₁₁ and R₆₁₂, the resultant fused ring forming a naphthalene ring, carbazole ring, indole ring, dibenzofuran ring, or dibenzothiophene ring, respectively.

In an exemplary embodiment, R₆₁₁ to R₆₂₁ not contributing to ring formation are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In an exemplary embodiment, R₆₁₁ to R₆₂₁ not contributing to ring formation are each independently a hydrogen atom, a substituted or unsubstituted aryl group having 6 to 50 ring carbon atoms, or a substituted or unsubstituted heterocyclic group having 5 to 50 ring atoms.

In an exemplary embodiment, R₆₁₁ to R₆₂₁ not contributing to ring formation are each independently a hydrogen atom, or a substituted or unsubstituted alkyl group having 1 to 50 carbon atoms.

In an exemplary embodiment, R₆₁₁ to R₆₂₁ not contributing to ring formation are each independently a hydrogen atom, or a substituted or unsubstituted alkyl group having 1 to 50 carbon atoms; and at least one of R₆₁₁ to R₆₂₁ is a substituted or unsubstituted alkyl group having 1 to 50 carbon atoms.

In an exemplary embodiment, the compound represented by the formula (62) is a compound represented by a formula (63) below.

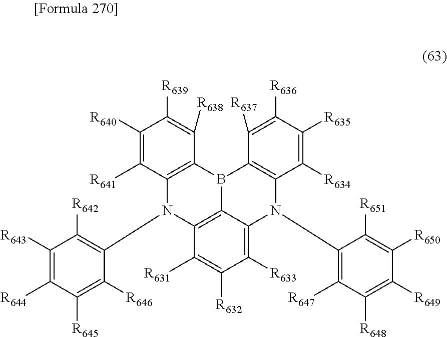

In the formula (63):
R₆₃₁ is bonded with R₆₄₆ to form a substituted or unsubstituted heterocycle, or not bonded therewith to form no substituted or unsubstituted heterocycle;
R₆₃₃ is bonded with R₆₄₇ to form a substituted or unsubstituted heterocycle, or not bonded therewith to form no substituted or unsubstituted heterocycle;
R₆₃₄ is bonded with R₆₅₁ to form a substituted or unsubstituted heterocycle, or not bonded therewith to form no substituted or unsubstituted heterocycle;
R₆₄₁ is bonded with R₆₄₂ to form a substituted or unsubstituted heterocycle, or not bonded therewith to form no substituted or unsubstituted heterocycle; at least one combination of adjacent two or more of R₆₃₁ to R₆₅₁ are mutually bonded to form a substituted or unsubstituted monocyclic ring, mutually bonded to form a substituted or unsubstituted fused ring, or not mutually bonded; and
R₆₃₁ to R₆₅₁ not forming the substituted or unsubstituted heterocycle, not forming the monocyclic ring, and not forming the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.
R₆₃₁ is optionally bonded with R₆₄₆ to form a substituted or unsubstituted heterocycle. For instance, R₆₃₁ and R₆₄₆ are optionally bonded with each other to form a tri-or-more cyclic fused nitrogen-containing heterocycle, in which a benzene ring bonded with R₆₄₆, a ring including a nitrogen atom, and a benzene ring corresponding to the ring a are fused. Specific examples of the nitrogen-containing heterocycle include a compound corresponding to a nitrogen-containing tri(-or-more)cyclic fused heterocyclic group in the specific example group G2. The same applies to R₆₃₃ bonded with R₆₄₇, R₆₃₄ bonded with R₆₅₁, and R₆₄₁ bonded with R₆₄₂.

In an exemplary embodiment, R₆₃₁ to R₆₅₁ not contributing to ring formation are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In an exemplary embodiment, R₆₃₁ to R₆₅₁ not contributing to ring formation are each independently a hydrogen atom, a substituted or unsubstituted aryl group having 6 to 50 ring carbon atoms, or a substituted or unsubstituted heterocyclic group having 5 to 50 ring atoms.

In an exemplary embodiment, R₆₃₁ to R₆₅₁ not contributing to ring formation are each independently a hydrogen atom, or a substituted or unsubstituted alkyl group having 1 to 50 carbon atoms.

In an exemplary embodiment, R₆₃₁ to R₆₅₁ not contributing to ring formation are each independently a hydrogen atom, or a substituted or unsubstituted alkyl group having 1 to 50 carbon atoms; and
at least one of R₆₃₁ to R₆₅₁ is a substituted or unsubstituted alkyl group having 1 to 50 carbon atoms.

In an exemplary embodiment, the compound represented by the formula (63) is a compound represented by a formula (63A) below.

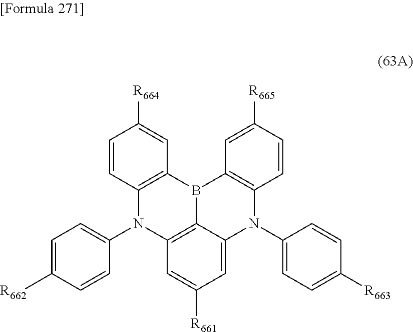

In the formula (63A):
R₆₆₁ is a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms, and
R₆₆₂ to R₆₆₅ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms.

In an exemplary embodiment, R₆₆₁ to R₆₆₅ are each independently a substituted or unsubstituted alkyl group having 1 to 50 carbon atoms, or a substituted or unsubstituted aryl group having 6 to 50 ring carbon atoms.

In an exemplary embodiment, R₆₆₁ to R₆₆₅ are each independently a substituted or unsubstituted alkyl group having 1 to 50 carbon atoms.

In an exemplary embodiment, the compound represented by the formula (63) is a compound represented by a formula (63B) below.

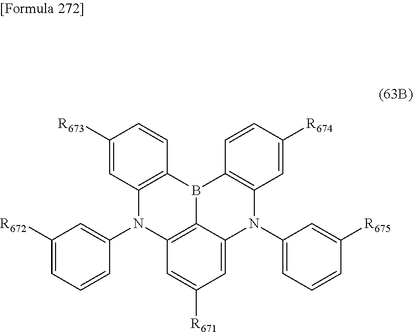

In the formula (63B):
R₆₇₁ and R₆₇₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), or a substituted or unsubstituted aryl group having 6 to 50 ring carbon atoms; and
R₆₇₃ to R₆₇₅ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), or a substituted or unsubstituted aryl group having 6 to 50 ring carbon atoms.

In an exemplary embodiment, the compound represented by the formula (63) is a compound represented by a formula (63B′) below.

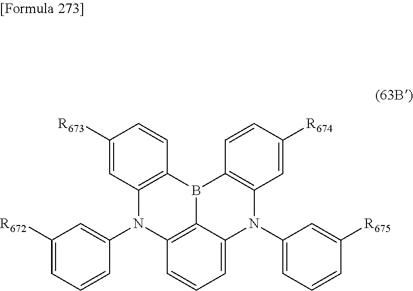

In the formula (63B′), R₆₇₂ to R₆₇₅ each independently represent the same as R₆₇₂ to R₆₇₅ in the formula (63B).

In an exemplary embodiment, at least one of R₆₇₁ to R₆₇₅ is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), or a substituted or unsubstituted aryl group having 6 to 50 ring carbon atoms.

In an exemplary embodiment: R₆₇₂ is a hydrogen atom, a substituted or unsubstituted alkyl group having 1 to 50 carbon atoms, a group represented by —N(R₉₀₆)(R₉₀₇), or a substituted or unsubstituted aryl group having 6 to 50 ring carbon atoms; and R₆₇₁ and R₆₇₃ to R₆₇₅ are each independently a substituted or unsubstituted alkyl group having 1 to 50 carbon atoms, a group represented by —N(R₉₀₆)(R₉₀₇), or a substituted or unsubstituted aryl group having 6 to 50 ring carbon atoms.

In an exemplary embodiment, the compound represented by the formula (63) is a compound represented by a formula (63C) below.

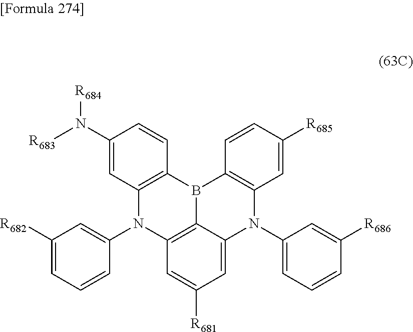

In the formula (63C):
R₆₈₁ and R₆₈₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms; and
R₆₈₃ to R₆₈₆ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, or a substituted or unsubstituted aryl group having 6 to 50 ring carbon atoms.

In an exemplary embodiment, the compound represented by the formula (63) is a compound represented by a formula (63C′) below.

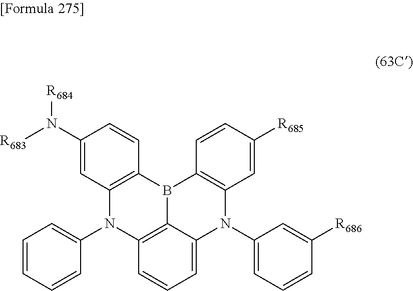

In the formula (63C′), R₆₈₃ to R₆₈₆ each independently represent the same as R₆₈₃ to R₆₈₆ in the formula (63C).

In an exemplary embodiment, R₆₈₁ to R₆₈₆ are each independently a substituted or unsubstituted alkyl group having 1 to 50 carbon atoms, or a substituted or unsubstituted aryl group having 6 to 50 ring carbon atoms.

In an exemplary embodiment, R₆₈₁ to R₆₈₆ are each independently a substituted or unsubstituted alkyl group having 6 to 50 carbon atoms.

The compound represented by the formula (6) is producible by initially bonding the ring a, ring b and ring c with linking groups (a group including N—R₆₀₁ and a group including N—R₆₀₂) to form an intermediate (first reaction), and bonding the ring a, ring b and ring c with a linking group (a group including a boron atom) to form a final product (second reaction). In the first reaction, an amination reaction (e.g. Buchwald-Hartwig reaction) is applicable. In the second reaction, Tandem Hetero-Friedel-Crafts Reactions or the like is applicable.

In an exemplary embodiment, the compound represented by the formula (6) is a compound represented by a formula (42-2) below.

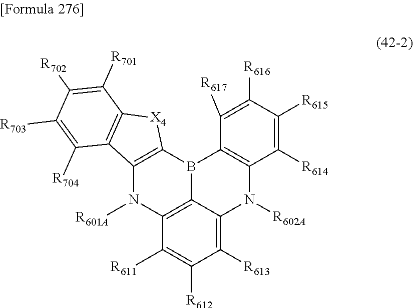

In the formula (42-2):
R₆₁₁ to R₆₁₇, R_{601A} to R_{602A} each independently represent the same as R₆₁₁ to R₆₁₇, R_{601A} to R_{602A} in the formula (62);
X₄ is an oxygen atom or a sulfur atom;
at least one combination of adjacent two or more of R₇₀₁ to R₇₀₄ are mutually bonded to form a substituted or unsubstituted monocyclic ring, mutually bonded to form a substituted or unsubstituted fused ring, or not mutually bonded; and
R₇₀₁ to R₇₀₄ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms. In the formula (42-2), R₉₀₁, R₉₀₂, R₉₀₃, R₉₀₄, R₉₀₅, R₉₀₆, and R₉₀₇ each independently represent the same as R₉₀₁, R₉₀₂, R₉₀₃, R₉₀₄, R₉₀₅, R₉₀₆, and R₉₀₇ in the formula (62).

### Specific Examples of Compound Represented by Formula (6)

Specific examples of the compound represented by the formula (6) are shown below. It should however be noted that these specific examples are merely exemplary and do not limit the compound represented by the formula (6).

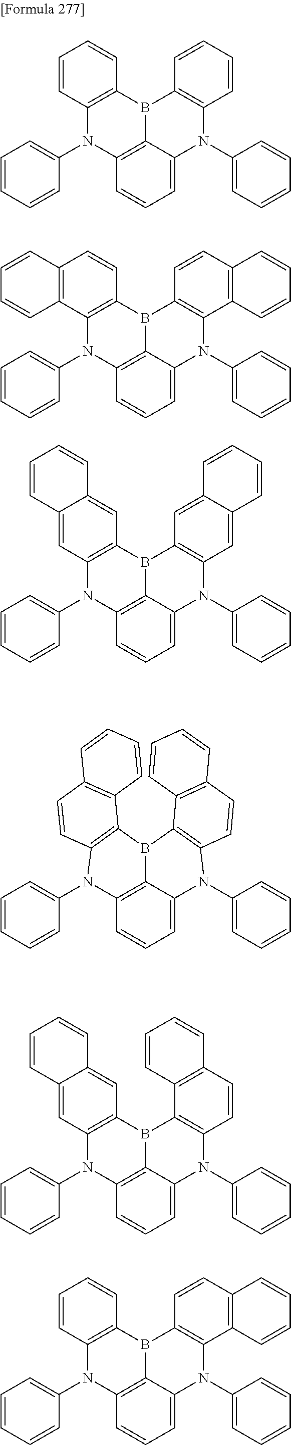

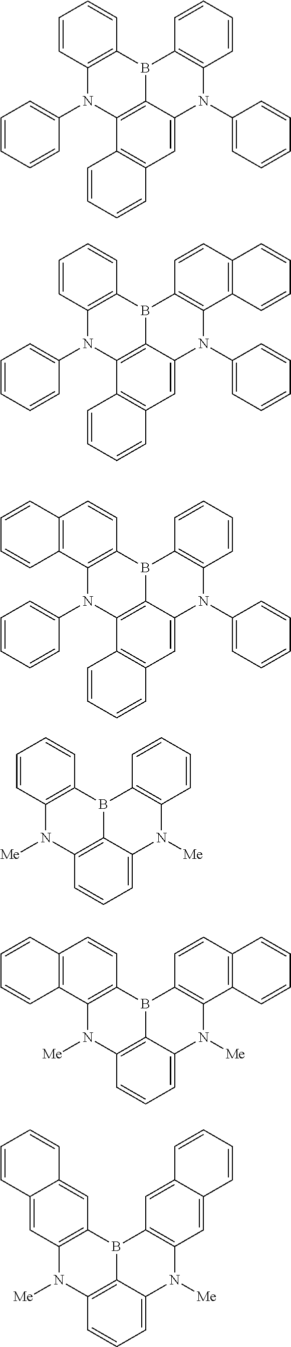

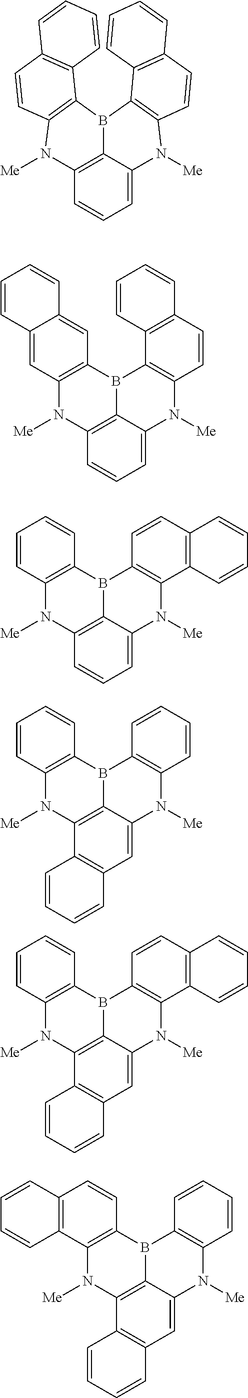

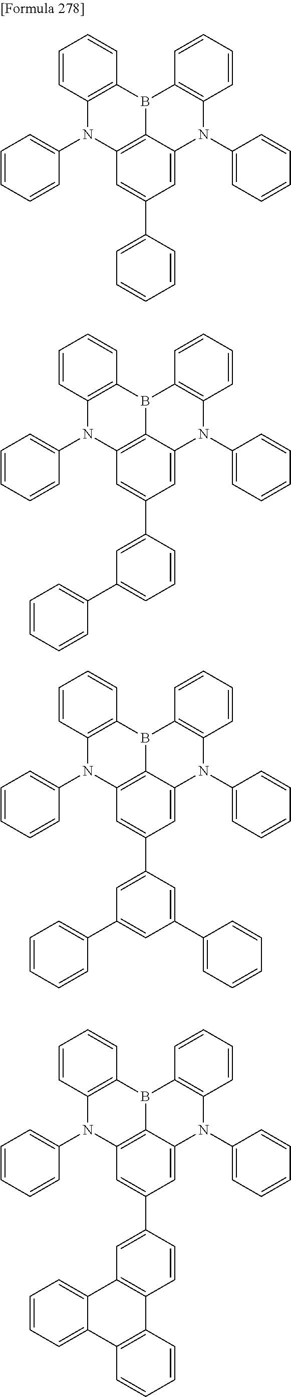

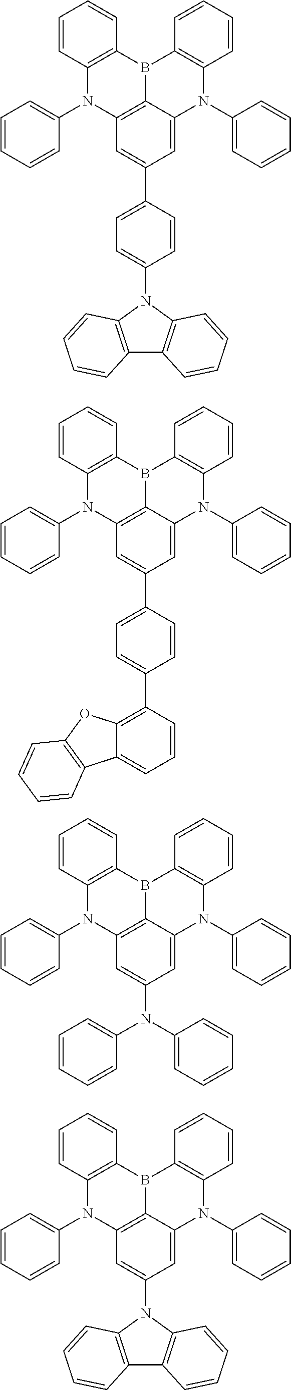

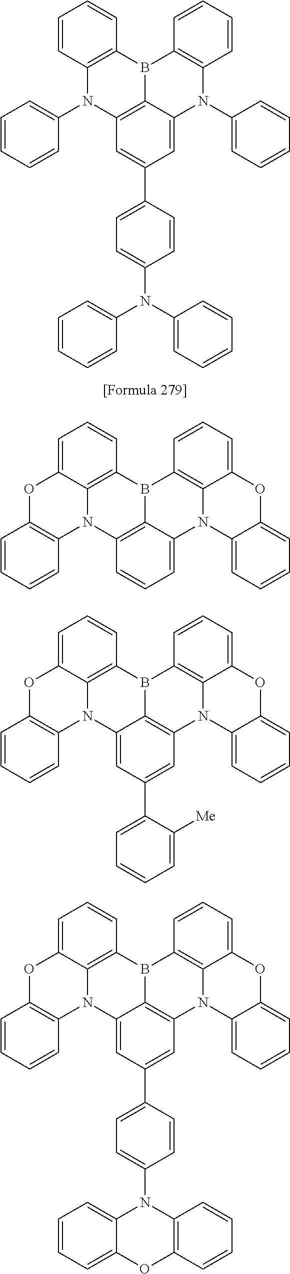

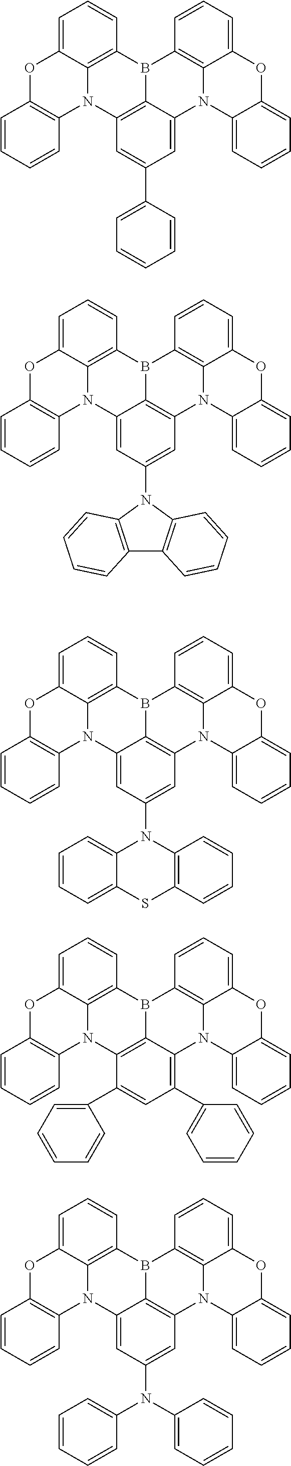

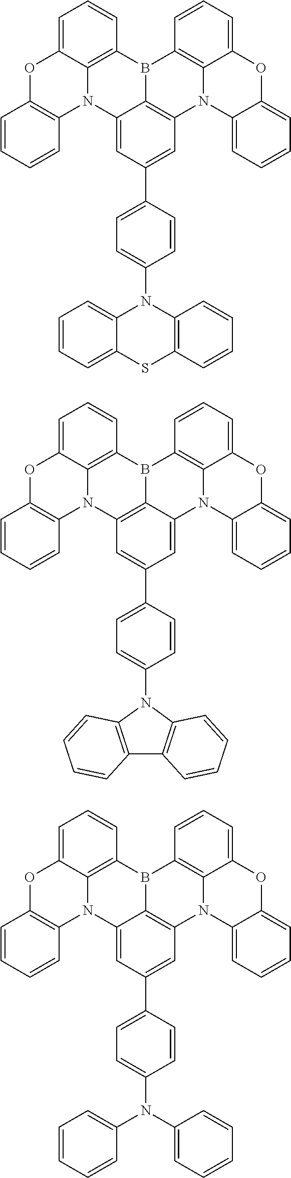

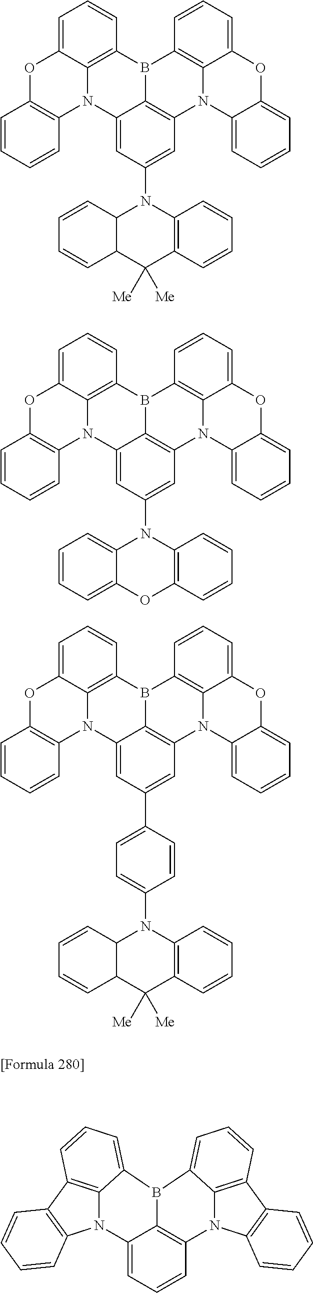

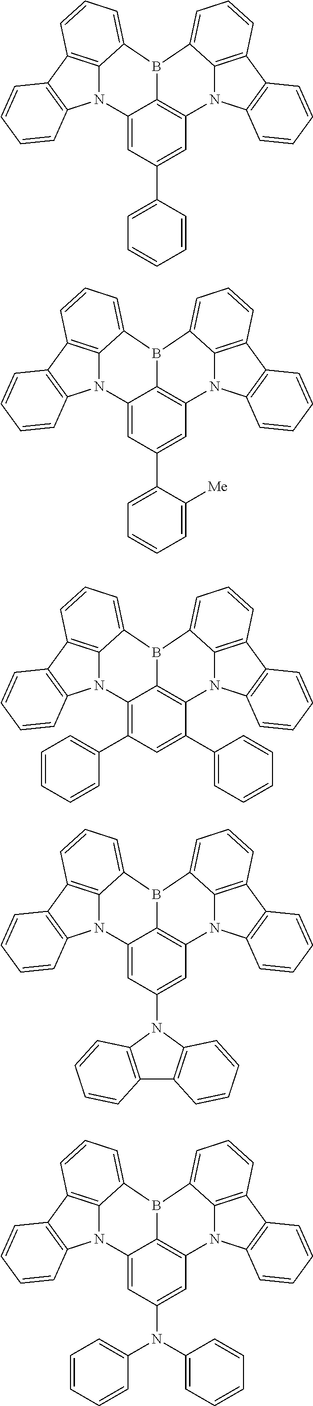

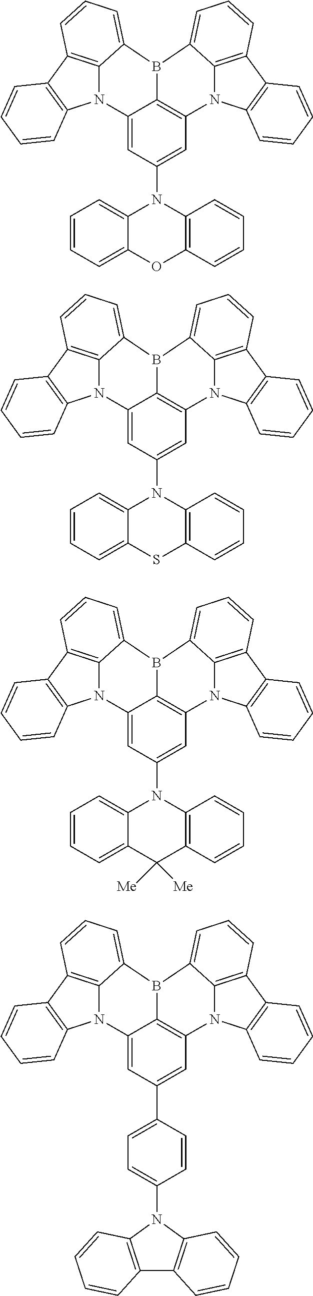

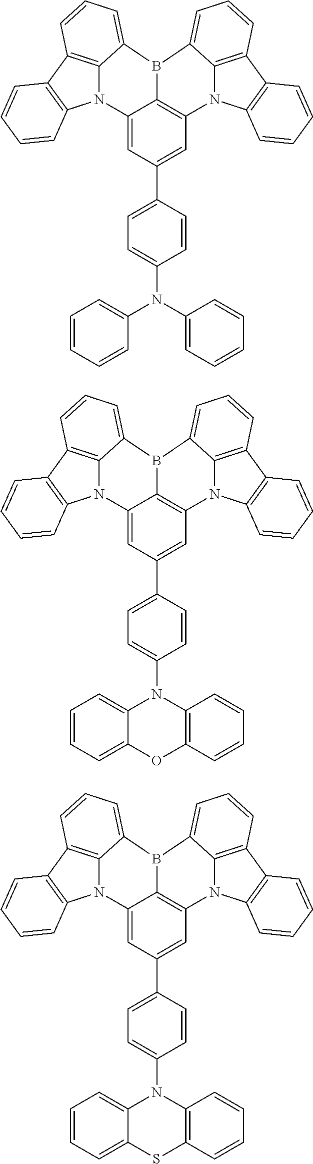

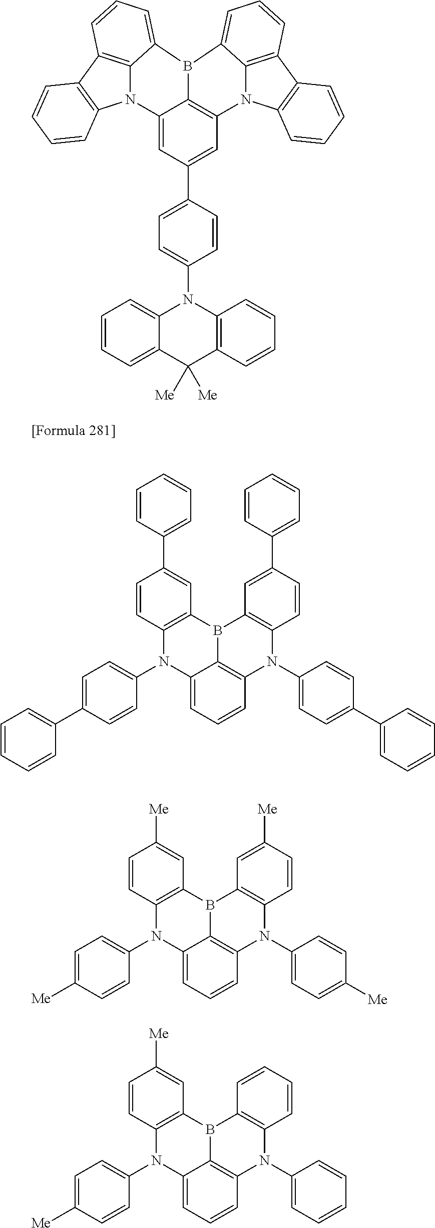 [SMILES: CC1(C)c2ccccc2N(c2ccc(-c3cc4c5c(c3)-n3c6ccccc6c6cccc(c63)B5c3cccc5c6ccccc6n-4c35)cc2)c2ccccc21 ; c1ccc(-c2ccc(N3c4ccc(-c5ccccc5)cc4B4c5cc(-c6ccccc6)ccc5N(c5ccc(-c6ccccc6)cc5)c5cccc3c54)cc2)cc1 ; Cc1ccc(N2c3ccc(C)cc3B3c4cc(C)ccc4N(c4ccc(C)cc4)c4cccc2c43)cc1 ; Cc1ccc(N2c3ccc(C)cc3B3c4ccccc4N(c4ccccc4)c4cccc2c43)cc1]

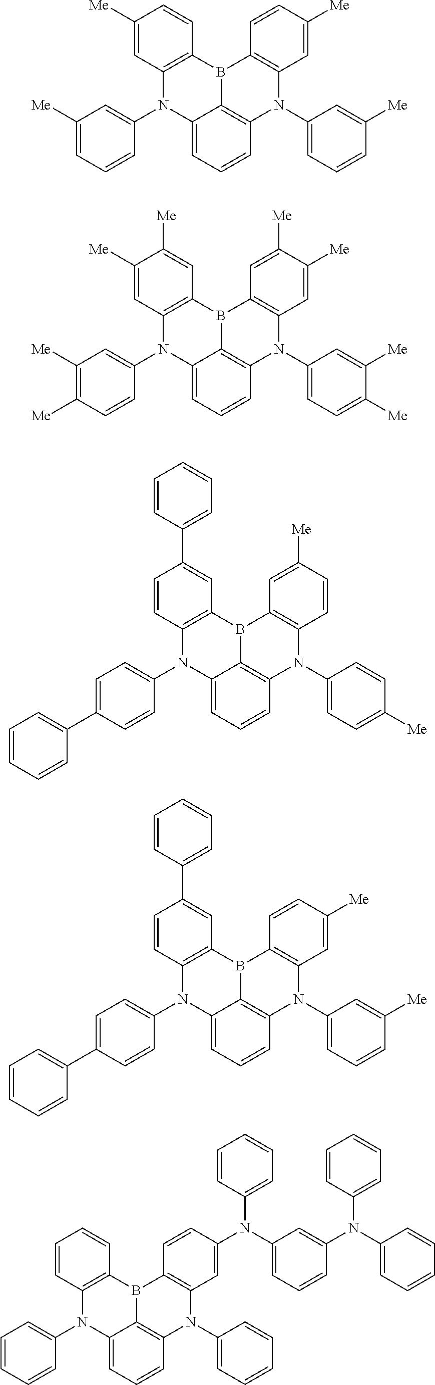 [SMILES: Cc1cccc(N2c3cc(C)ccc3B3c4ccc(C)cc4N(c4cccc(C)c4)c4cccc2c43)c1 ; Cc1ccc(N2c3cc(C)c(C)cc3B3c4cc(C)c(C)cc4N(c4ccc(C)c(C)c4)c4cccc2c43)cc1C ; Cc1ccc(N2c3ccc(C)cc3B3c4cc(-c5ccccc5)ccc4N(c4ccc(-c5ccccc5)cc4)c4cccc2c43)cc1 ; Cc1cccc(N2c3cc(C)ccc3B3c4cc(-c5ccccc5)ccc4N(c4ccc(-c5ccccc5)cc4)c4cccc2c43)c1 ; c1ccc(N(c2ccccc2)c2cccc(N(c3ccccc3)c3ccc4c(c3)N(c3ccccc3)c3cccc5c3B4c3ccccc3N5c3ccccc3)c2)cc1]

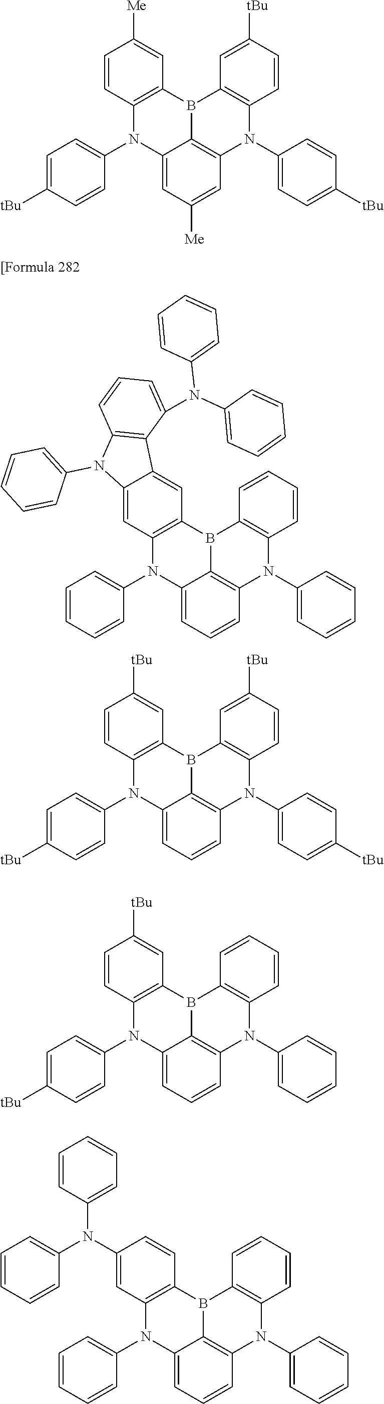

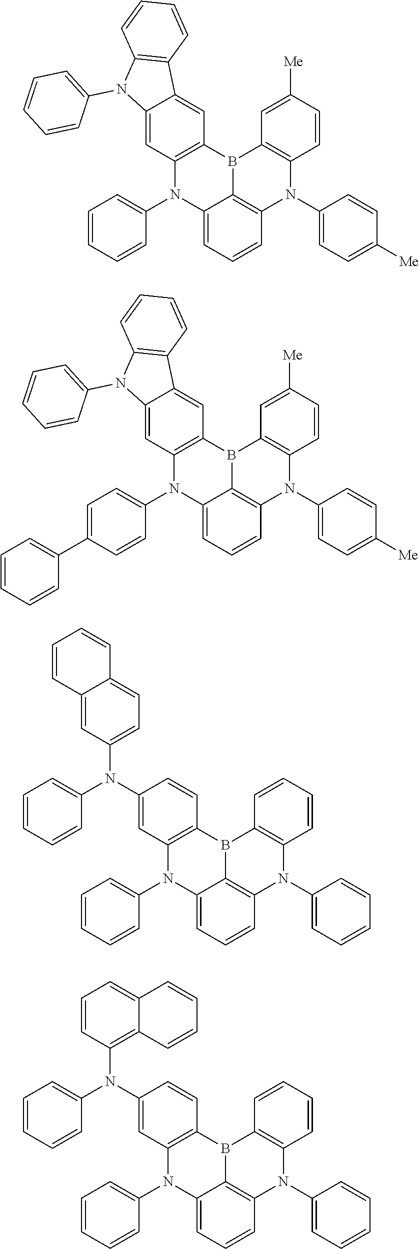

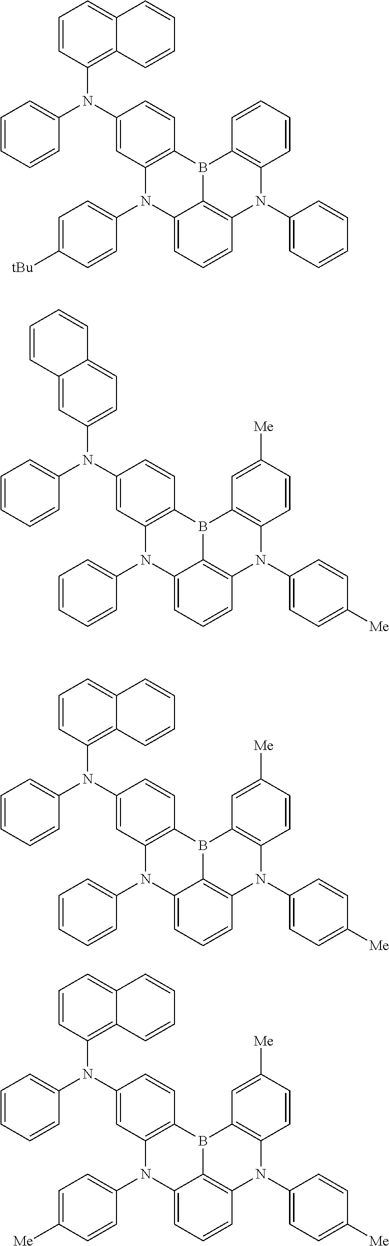

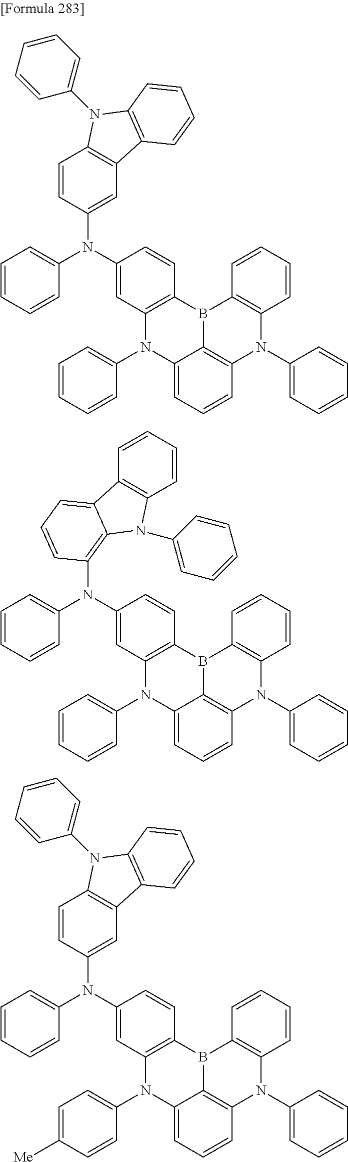

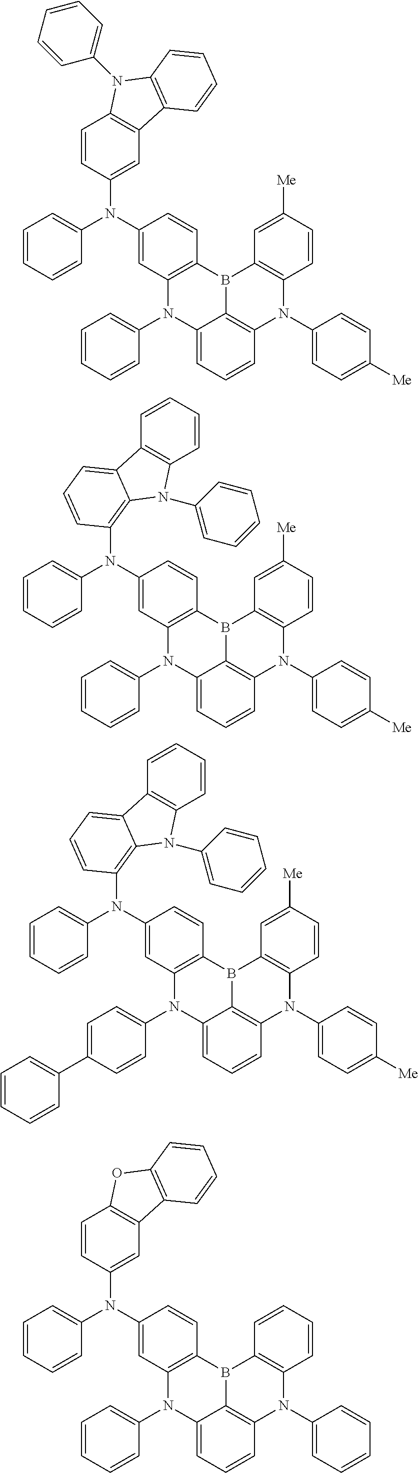

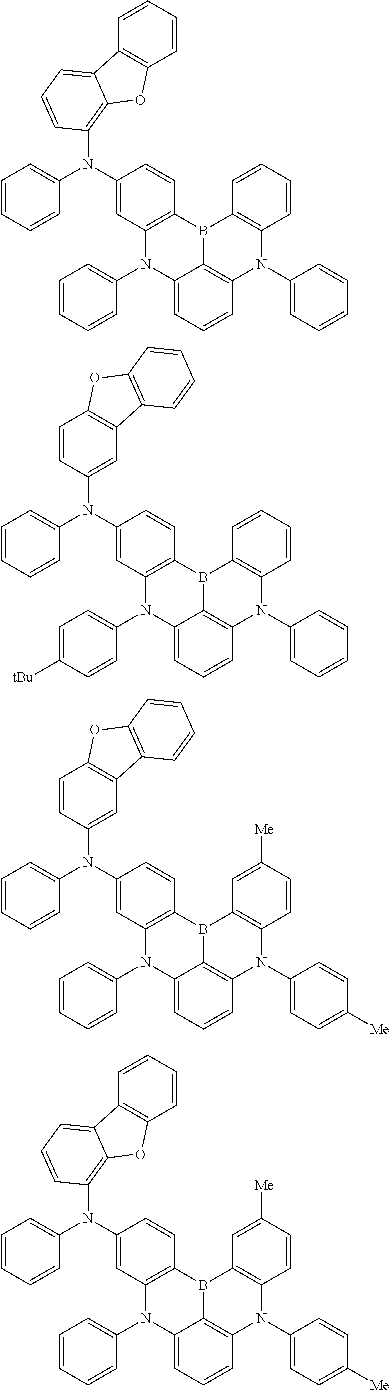

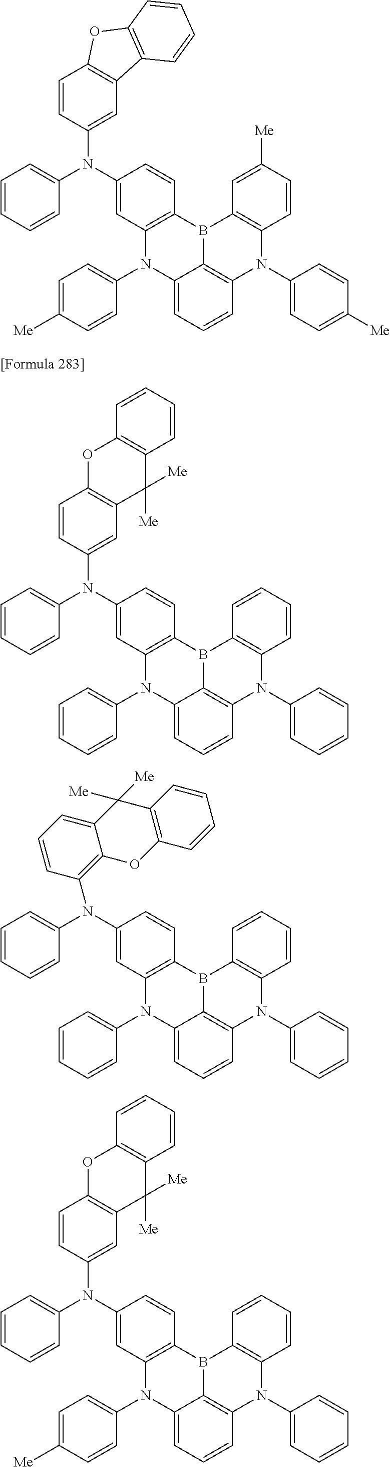

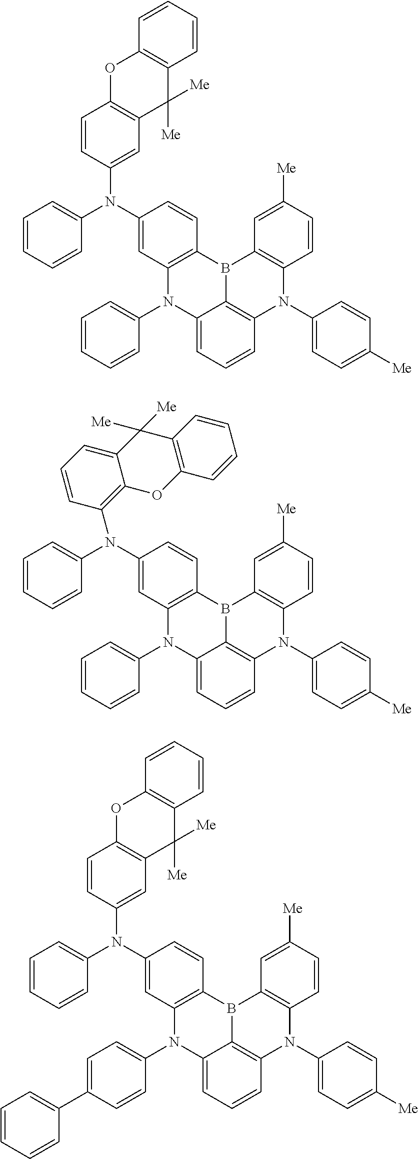 [SMILES: Cc1ccc(N2c3ccc(C)cc3B3c4ccc(N(c5ccccc5)c5ccc6c(c5)C(C)(C)c5ccccc5O6)cc4N(c4ccccc4)c4cccc2c43)cc1 ; Cc1ccc(N2c3ccc(C)cc3B3c4ccc(N(c5ccccc5)c5cccc6c5Oc5ccccc5C6(C)C)cc4N(c4ccccc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccc(-c5ccccc5)cc4)c4cccc2c43)cc1]

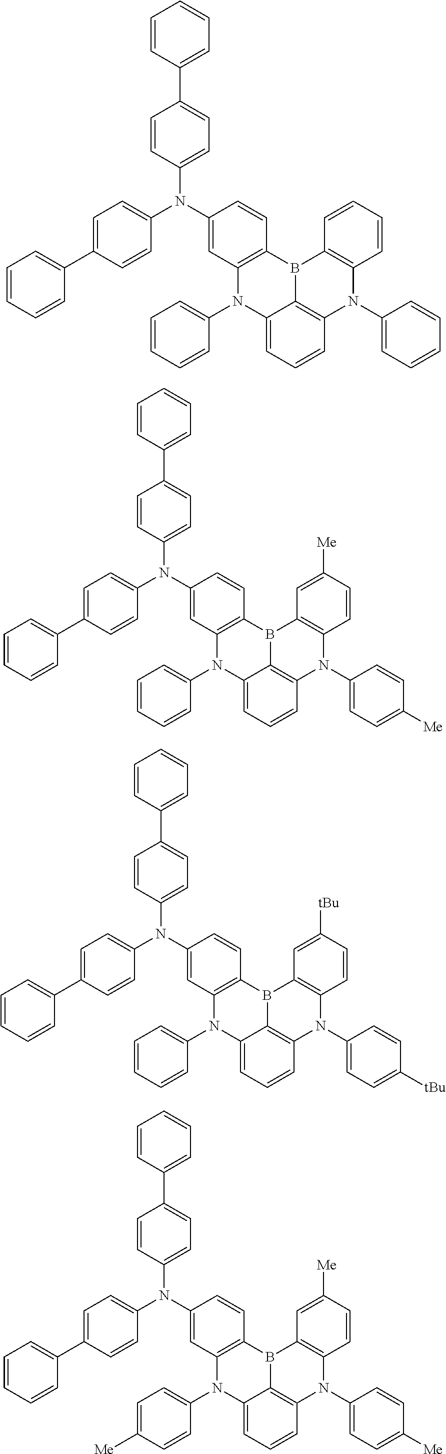

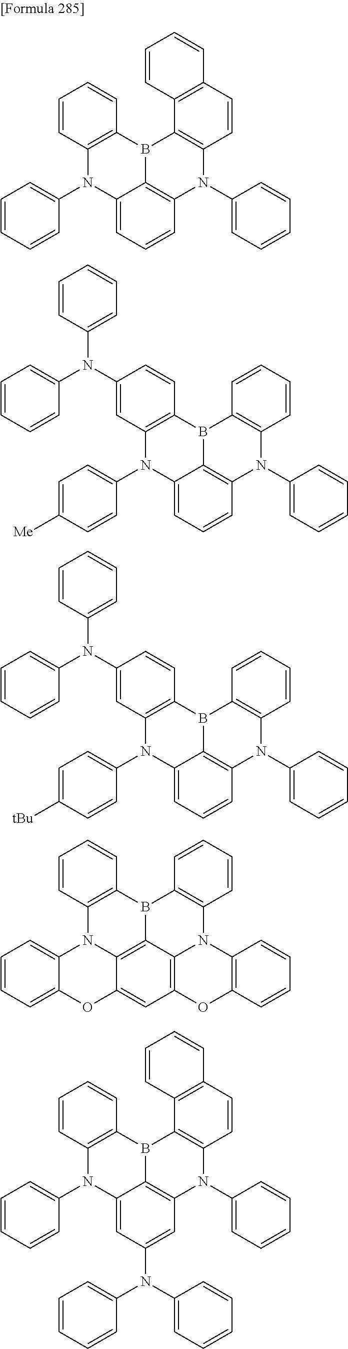

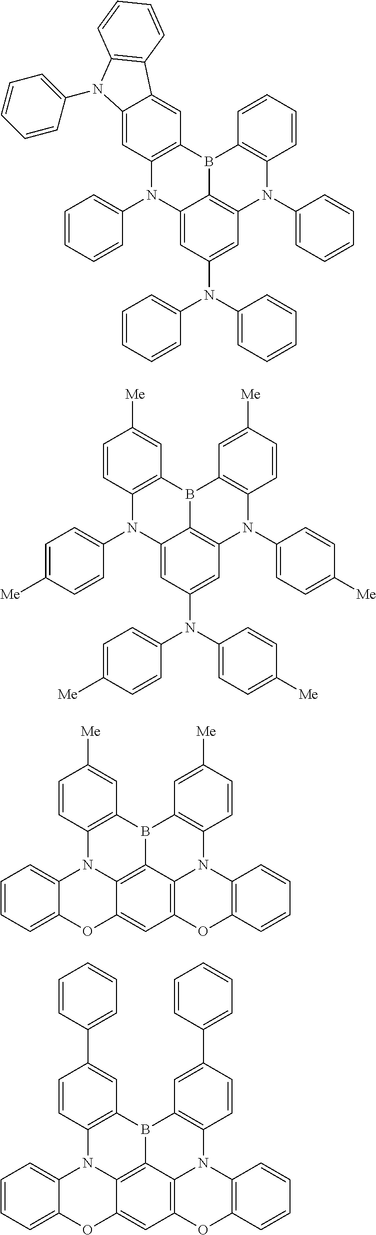

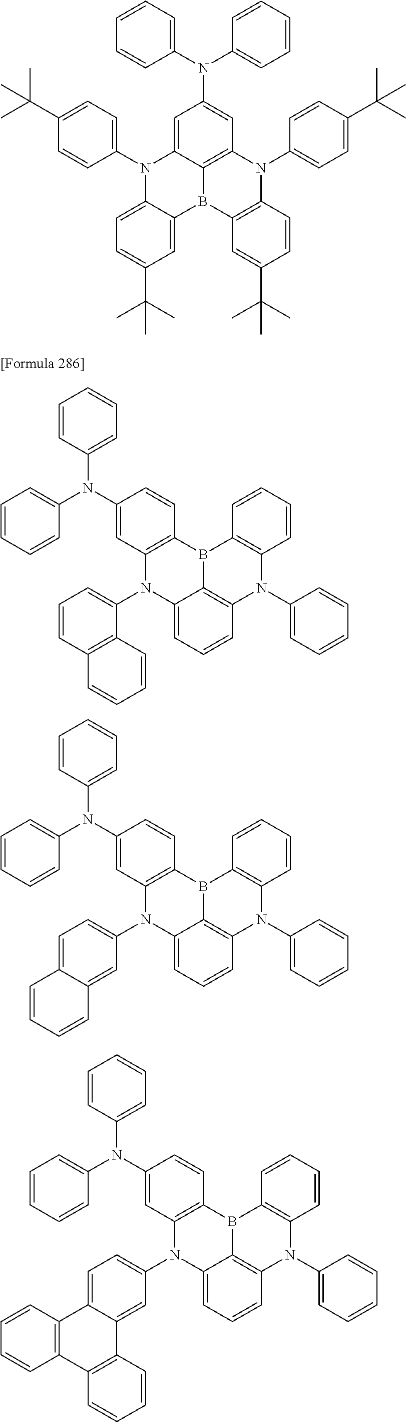

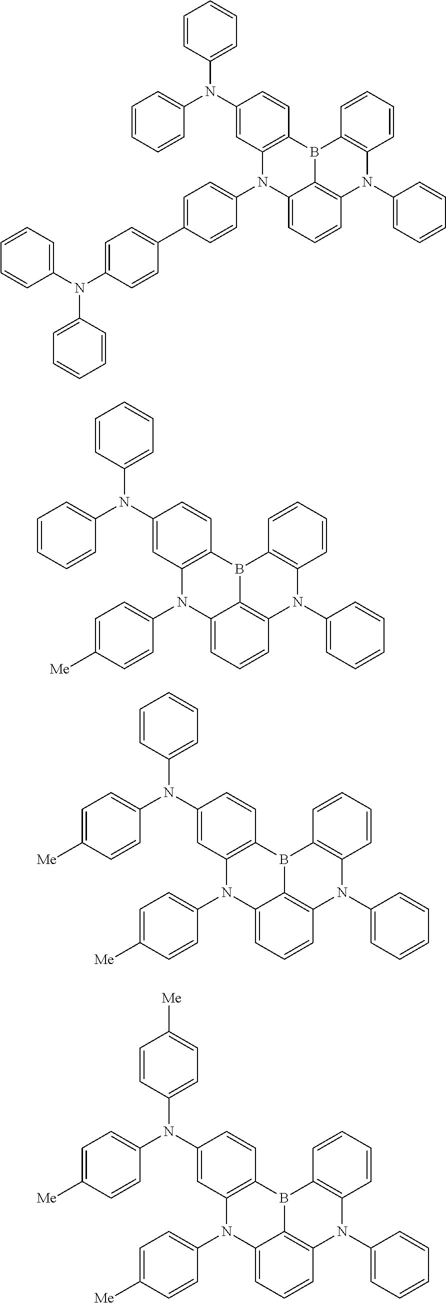

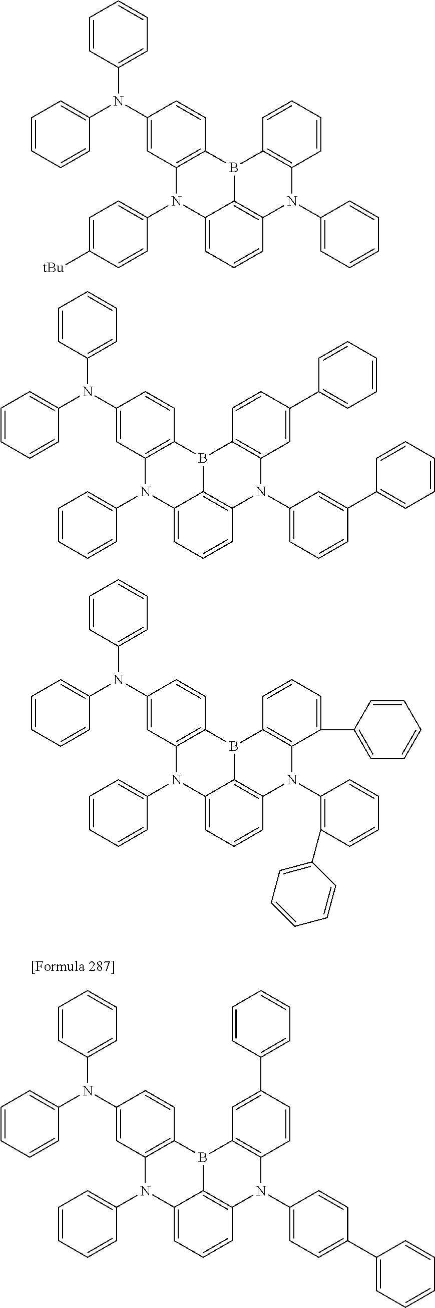

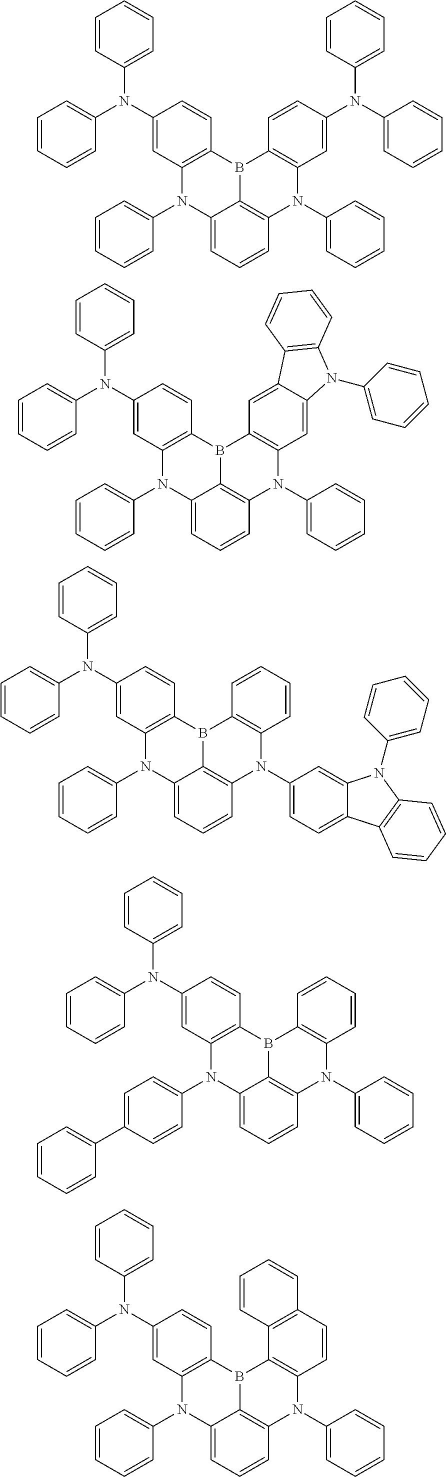

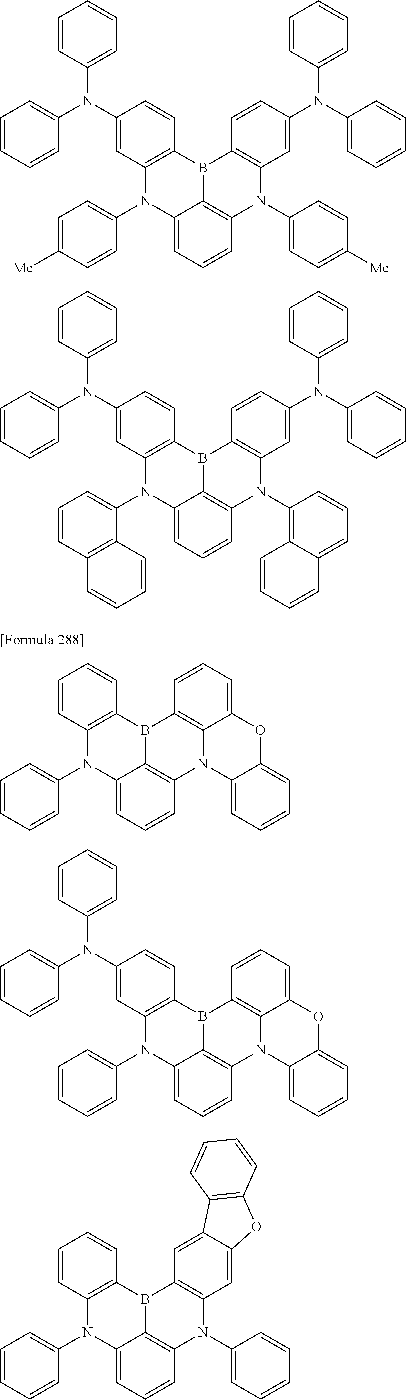

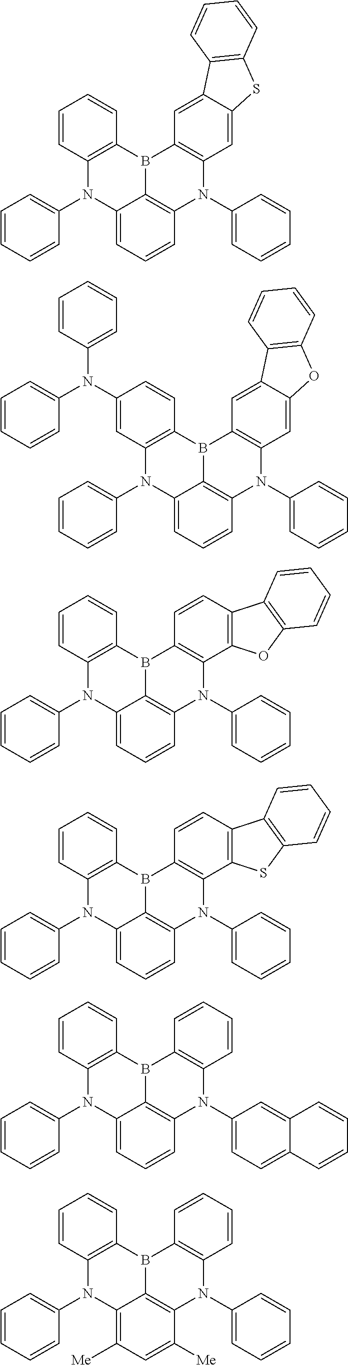

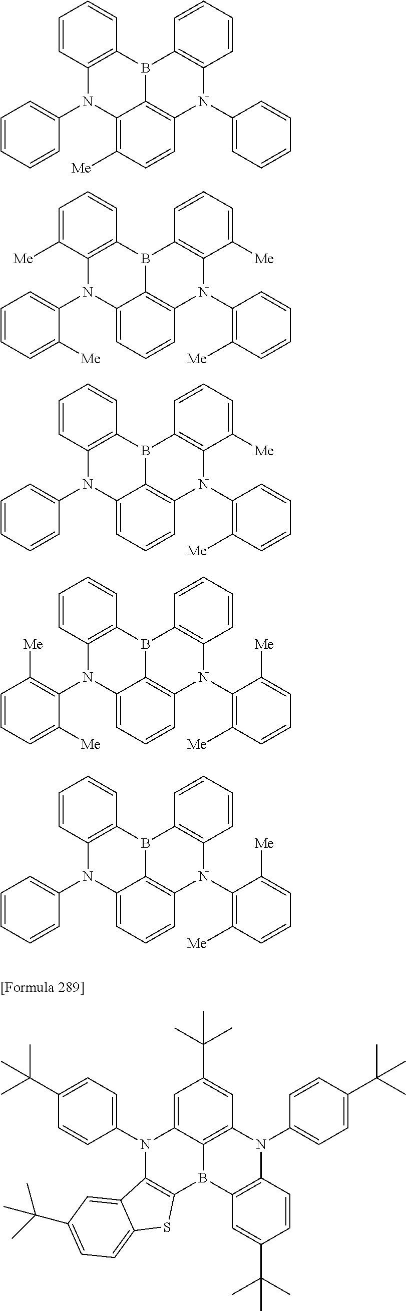

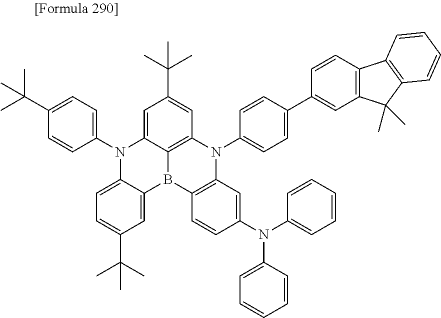 [SMILES: CC(C)(C)c1ccc(N2c3ccc(C(C)(C)C)cc3B3c4ccc(N(c5ccccc5)c5ccccc5)cc4N(c4ccc(-c5ccc6c(c5)C(C)(C)c5ccccc5-6)cc4)c4cc(C(C)(C)C)cc2c43)cc1]

In an exemplary arrangement of the organic EL device of the exemplary embodiment, the emitting region consists of the first emitting layer.

In an exemplary arrangement of the organic EL device according to the exemplary embodiment, the emitting region further includes the second emitting layer in addition to the first emitting layer.

In an exemplary arrangement of the organic EL device of the exemplary embodiment, the emitting region consists of the first emitting layer and the second emitting layer.

In an exemplary arrangement of the organic EL device according to the exemplary embodiment, the emitting region at least includes the first emitting layer containing the first host material and the second emitting layer containing the second host material. The first host material and the second host material are mutually different.

When the emitting region at least includes the first emitting layer and the second emitting layer, luminous efficiency is improvable by using Triplet-Triplet-Annihilation (sometimes referred to as TTA).

TTA is a mechanism in which triplet excitons collide with one another to generate singlet excitons. The TTA mechanism is sometimes also referred to as a TTF mechanism as described in International Publication No. WO2010/134350.

The TTF phenomenon will be described. Holes injected from an anode and electrons injected from a cathode are recombined in an emitting layer to generate excitons. As for the spin state, as is conventionally known, singlet excitons account for 25% and triplet excitons account for 75%. In a conventionally known fluorescent device, light is emitted when singlet excitons of 25% are relaxed to the ground state. The remaining triplet excitons of 75% are returned to the ground state without emitting light through a thermal deactivation process. Accordingly, the theoretical limit value of the internal quantum efficiency of the conventional fluorescent device is believed to be 25%.

The behavior of triplet excitons generated within an organic substance has been theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as ³A*) collide with one another with an increase in density thereof, whereby a reaction shown by the following formula occurs. In the formula, ¹A represents the ground state and ¹A* represents the lowest singlet excitons.

³A*+³A*→(4/9)¹A+(1/9)¹A*+(13/9)³A*

In other words, 5³A*→* 4¹A+1A* is satisfied, and it is expected that, among triplet excitons initially generated, which account for 75%, one fifth thereof (i.e., 20%) is changed to singlet excitons. Accordingly, the amount of singlet excitons which contribute to emission is 40%, which is a value obtained by adding 15% (75%×(1/5)=15%) to 25%, which is the amount ratio of initially generated singlet excitons. At this time, a ratio of luminous intensity derived from TTF (TTF ratio) relative to the total luminous intensity is 15/40, i.e., 37.5%. Assuming that singlet excitons are generated by collision of initially generated triplet excitons accounting for 75% (i.e., one singlet exciton is generated from two triplet excitons), a significantly high internal quantum efficiency of 62.5% is obtained, which is a value obtained by adding 37.5% (75%×(½)=37.5%) to 25% (the amount ratio of initially generated singlet excitons). At this time, the TTF ratio is 37.5/62.5=60%.

In an exemplary arrangement of the organic EL device of the exemplary embodiment, the triplet energy of the first host material T₁(H1) and the triplet energy of the second host material T₁(H2) preferably satisfy a relationship of a numerical formula (Numerical Formula 1) below, more preferably satisfy a relationship of a numerical formula (Numerical Formula 2) below.

T₁(H2)>T₁(H1) (Numerical Formula 1)

T₁(H2)−T₁(H1)>0.03 eV (Numerical Formula 2)

When an exemplary arrangement of the organic EL device of the exemplary embodiment includes the first emitting layer and the second emitting layer satisfying the numerical formula (Numerical Formula 1), the luminous efficiency of the device is improvable.

In an exemplary arrangement of the organic EL device according to the first exemplary embodiment, it is considered that since the relationship of the numerical formula (Numerical Formula 1) is satisfied, triplet excitons generated by recombination of holes and electrons in the second emitting layer and present on an interface between the second emitting layer and organic layer(s) in direct contact therewith are not likely to be quenched even under the presence of excessive carriers on the interface between the second emitting layer and the organic layer(s). For instance, the presence of a recombination region locally on an interface between the second emitting layer and a hole transporting layer or an electron blocking layer is considered to cause quenching by excessive electrons. Meanwhile, the presence of a recombination region locally on an interface between the second emitting layer and an electron transporting layer or a hole blocking layer is considered to cause quenching by excessive holes.

In an exemplary arrangement of the organic EL device according to the exemplary embodiment, by including the first emitting layer and the second emitting layer so as to satisfy the relationship of the numerical formula (Numerical Formula 1), triplet excitons generated in the second emitting layer can transfer to the first emitting layer without being quenched by excessive carriers and be inhibited from back-transferring from the first emitting layer to the second emitting layer. Consequently, the first emitting layer exhibits the TTF mechanism to effectively generate singlet excitons, thereby improving the luminous efficiency.

Accordingly, the organic EL device includes, as different regions, the second emitting layer mainly generating triplet excitons and the first emitting layer mainly exhibiting the TTF mechanism using triplet excitons having transferred from the second emitting layer, and has a difference in triplet energy provided by using a compound having a smaller triplet energy than that of the second host material in the second emitting layer as the first host material in the first emitting layer. The luminous efficiency is thus improved.

In an exemplary arrangement of the organic EL device according to the exemplary embodiment, the first emitting layer and the second emitting layer are in direct contact with each other.

Herein, a layer arrangement in which “the first emitting layer and the second emitting layer are in direct contact with each other” may include, for instance, one of embodiments (LS1), (LS2), and (LS3) below.

(LS1) An embodiment in which a region containing both the first host material and the second host material is generated in a process of vapor-depositing the compound of the first emitting layer and vapor-depositing the compound of the second emitting layer, and is present on the interface between the first emitting layer and the second emitting layer.

(LS2) An embodiment in which in a case of containing an emitting compound in the first emitting layer and the second emitting layer, a region containing the first host material, the second host material and the emitting compound is generated in a process of vapor-depositing the compound of the first emitting layer and vapor-depositing the compound of the second emitting layer, and is present on the interface between the first emitting layer and the second emitting layer.

(LS3) An embodiment in which in a case of containing an emitting compound in the first emitting layer and the second emitting layer, a region containing the emitting compound, a region containing the first host material or a region containing the second host material is generated in a process of vapor-depositing the compound of the first emitting layer and vapor-depositing the compound of the second emitting layer, and is present on the interface between the first emitting layer and the second emitting layer.

### Second Emitting Layer

In an exemplary arrangement of the organic EL device according to the exemplary embodiment, the second emitting layer contains the second host material. The second host material, which is not particularly limited, may be, for instance, a compound selected from the group consisting of a first compound described later and a compound represented by the formula (H1).

In an exemplary arrangement of the organic EL device according to the exemplary embodiment, the second emitting layer contains a second emitting compound. The second emitting layer, which is not particularly limited, may be, for instance, a compound selected from the group consisting of a compound represented by the formula (6), a third compound and a fourth compound which are described later.

In an exemplary arrangement of the organic EL device according to the exemplary embodiment, the second emitting layer contains the second host material and the second emitting compound.

In an exemplary arrangement of the organic EL device of the exemplary embodiment, the second emitting compound is the same as or different from the first emitting compound contained in the first emitting layer.

In an exemplary arrangement of the organic EL device of the exemplary embodiment, the second host material is a compound different from the first host material contained in the first emitting layer.

The second emitting compound preferably emits light having a maximum peak wavelength of 500 nm or less, more preferably emits light having a maximum peak wavelength in a range from 430 nm to 480 nm. The second emitting compound is preferably a fluorescent compound that emits fluorescence having a maximum peak wavelength of 500 nm or less, more preferably a fluorescent compound that emits fluorescence having a maximum peak wavelength in a range from 430 nm to 480 nm.

In an exemplary arrangement of the organic EL device according to the exemplary embodiment, the second emitting layer contains the second host material and the second emitting compound that emits light having the maximum peak wavelength of 500 nm or less.

In an exemplary arrangement of the organic EL device of the exemplary embodiment, the second emitting compound has a full width at half maximum in a range from 1 nm to 30 nm at a maximum peak.

A method of measuring a maximum peak wavelength of a compound is as follows.

In an exemplary arrangement of the organic EL device according to the exemplary embodiment, a triplet energy of the second emitting compound T₁(D1) and the triplet energy of the first host material T₁(H1) preferably satisfy a relationship of a numerical formula (Numerical Formula 4A) below.

T₁(D1)>T₁(H1) (Numerical Formula 4A)

In an exemplary arrangement of the organic EL device according to the exemplary embodiment, when the first emitting compound and the first host material satisfy the relationship of the numerical formula (Numerical Formula 4A), in transfer of triplet excitons generated in the second emitting layer to the first emitting layer, the triplet excitons energy-transfer not onto the first emitting compound having higher triplet energy but onto molecules of the first host material. In addition, triplet excitons generated by recombination of holes and electrons on the first host material do not transfer to the first emitting compound having higher triplet energy. Triplet excitons generated by recombination on molecules of the first emitting compound quickly energy-transfer to molecules of the first host material.

Triplet excitons in the first host material do not transfer to the first emitting compound but efficiently collide with one another on the first host material to generate singlet excitons by the TTF phenomenon.

In an exemplary arrangement of the organic EL device according to the exemplary embodiment, a singlet energy of the first host material S₁(H1) and a singlet energy of the first emitting compound S₁(D1) preferably satisfy a relationship of a numerical formula (Numerical Formula 4) below.

S₁(H1)>S₁(D1) (Numerical Formula 4)

In an exemplary arrangement of the organic EL device according to the exemplary embodiment, when the first emitting compound and the first host material satisfy the relationship of the numerical formula (Numerical formula 4), due to the singlet energy of the first emitting compound being smaller than the singlet energy of the first host material, singlet excitons generated by the TTF phenomenon energy-transfer from the first host material to the first emitting compound, thereby contributing to emission (preferably fluorescence) of the first emitting compound.

In an exemplary arrangement of the organic EL device according to the exemplary embodiment, when the first emitting layer and the second emitting layer are layered in this order from a side on which the anode is provided, the electron mobility of the second host material μe(H2) and the electron mobility of the first host material μe(H1) preferably satisfy a formula (Numerical Formula 3) below. When the first host material and the second host material satisfy a relationship of the numerical formula (Numerical Formula 3), a recombination ability between holes and electrons in the second emitting layer is improved.

μe(H1)>μe(H2) (Numerical Formula 3)

In an exemplary arrangement of the organic EL device according to the exemplary embodiment, when the second emitting layer and the first emitting layer are layered in this order from a side on which the anode is provided, the hole mobility of the second host material μh(H2) and the hole mobility of the first host material μh(H1) preferably satisfy a formula (Numerical Formula 31) below.

μh(H2)>μh(H1) (Numerical Formula 31)

In an exemplary arrangement of the organic EL device according to the exemplary embodiment, when the second emitting layer and the first emitting layer are layered in this order from a side on which the anode is provided, the hole mobility of the second host material μh(H2), the electron mobility of the second host material μe(H2), the hole mobility of the first host material μh(H1), and the electron mobility of the first host material μe(H1) preferably satisfy a formula (Numerical Formula 32) below.

(μe(H1)/μh(H1))>(μe(H2)/μh(H2)) (Numerical Formula 32)

In an exemplary arrangement of the organic EL device according to the exemplary embodiment, a singlet energy of the second host material S₁(H2) and a singlet energy of the second emitting compound S₁(D2) preferably satisfy a relationship of a numerical formula (Numerical Formula 20) below.

S₁(H2)>S₁(D2) (Numerical Formula 20)

When the second host material and the second emitting compound satisfy the relationship of the numerical formula (Numerical Formula 20), singlet excitons generated on the second host material easily transfer from the second host material to the second dopant material, thereby contributing to emission (preferably fluorescence) of the second emitting compound.

In the organic EL device according to the second exemplary embodiment, the triplet energy of the second host material T₁(H2) and the triplet energy of the second emitting compound T₁(D2) preferably satisfy a relationship of a numerical formula (Numerical Formula 20A) below.

T₁(D2)>T₁(H2) (Numerical Formula 20A)

When the second host material and the second emitting compound satisfy the relationship of the numerical formula (Numerical Formula 20A), triplet excitons generated in the second emitting layer transfer not onto the second emitting compound having higher triplet energy but onto the second host material, thereby easily transferring to the first emitting layer.

A measurement method of triplet energy T₁, singlet energy Si, hole mobility, and electron mobility will be described later.

In an exemplary arrangement of the organic EL device of the exemplary embodiment, the second emitting compound is a compound containing no azine ring structure in a molecule.

In an exemplary arrangement of the organic EL device of the exemplary embodiment, the second emitting compound is preferably not a boron-containing complex, more preferably not a complex.

For instance, examples of a compound that emits blue fluorescence and is usable for the second emitting layer include a pyrene derivative, styrylamine derivative, chrysene derivative, fluoranthene derivative, fluorene derivative, diamine derivative, and triarylamine derivative.

In an exemplary arrangement of the organic EL device according to the exemplary embodiment, the second emitting layer does not contain a metal complex. Moreover, in an exemplary arrangement of the organic EL device according to the exemplary embodiment, the second emitting layer does not contain a boron-containing complex.

In an exemplary arrangement of the organic EL device according to the exemplary embodiment, the second emitting layer not contain a phosphorescent material (dopant material).

In an exemplary arrangement of the organic EL device according to the exemplary embodiment, the second emitting layer not contain a heavy metal complex and a phosphorescent rare-earth metal complex.

In an exemplary arrangement of the organic EL device according to the exemplary embodiment, the second emitting layer contains 0.5 mass % or more of the emitting compound with respect to the total mass of the second emitting layer. The second emitting layer contains the emitting compound preferably at 10 mass % or less, more preferably at 7 mass % or less, and still more preferably at 5 mass % less with respect to the total mass of the second emitting layer.

In an exemplary arrangement of the organic EL device according to the exemplary embodiment, the second emitting layer contains the second host material preferably at 60 mass % or more, more preferably at 70 mass % or more, still more preferably at 80 mass % or more, still further more preferably at 90 mass % or more, and yet still further more preferably at 95 mass % or more, with respect to the total mass of the first emitting layer.

The second emitting layer preferably contains the second host material at 99.5 mass % or less with respect to the total mass of the second emitting layer. When the second emitting layer contains the second host material and the second emitting compound, the upper limit of a total of the content ratios of the second host material and the second emitting compound is 100 mass %.

In the organic EL device according to the above exemplary embodiment, the second emitting layer may further contain any other material than the second host material and the second emitting compound.

The second emitting layer may contain a single type of the second host material or may contain two or more types of the second host material. The second emitting layer may contain a single type of the second emitting compound or may contain two or more types of the second emitting compound.

In an exemplary arrangement of the organic EL device of the exemplary embodiment, a film thickness of the first emitting layer is preferably 5 nm or more, more preferably 15 nm or more. When the film thickness of the first emitting layer is 5 nm or more, when the emitting region includes the second emitting layer, it is easy to inhibit triplet excitons having transferred from the second emitting layer to the first emitting layer from returning to the second emitting layer. Further, when the film thickness of the first emitting layer is 5 nm or more, triplet excitons can be sufficiently separated from the recombination portion in the second emitting layer.

In an exemplary arrangement of the organic EL device according to the exemplary embodiment, the film thickness of the third layer is preferably 20 nm or less. With the film thickness of the first emitting layer of 20 nm or less, a density of triplet excitons in the first emitting layer is improvable to further facilitate occurrence of the TTF phenomenon.

In an exemplary arrangement of the organic EL device of the exemplary embodiment, the film thickness of the first emitting layer is preferably in a range from 5 nm to 20 nm.

In an exemplary arrangement of the organic EL device of the exemplary embodiment, the film thickness of the second emitting layer is preferably 3 nm or more, more preferably 5 nm or more. The film thickness of the second emitting layer of 3 nm or more is sufficient for causing recombination of holes and electrons in the second emitting layer.

In an exemplary arrangement of the organic EL device of the exemplary embodiment, the film thickness of the second emitting layer is preferably 15 nm or less, more preferably 10 nm or less. The film thickness of the second emitting layer of 15 nm or less is thin enough for transfer of triplet excitons to the first emitting layer. In an exemplary arrangement of the organic EL device of the exemplary embodiment, the film thickness of the second emitting layer is preferably in a range from 3 nm to 15 nm.

### First Host Material and Second Host Material

In an exemplary arrangement of the organic EL device according to the exemplary embodiment, in addition to the above-listed compounds (e.g., the compound represented by the formula (H1)) as the first host material, the first host material is also preferably a compound selected from the group consisting of first compounds represented by formulae (1), (1X), (12X), (13X), (14X), (15X), (16X), (1000B), (16X), (17X-1), (17X-2), (17X-3), and (18) below.

In an exemplary arrangement of the organic EL device of the exemplary embodiment, the second host material is also preferably a compound selected from the group consisting of the first compounds represented by the formulae (1), (1X), (12X), (13X), (14X), (15X), (16X), (1000B), (16X), (17X-1), (17X-2), (17X-3), and (18) below and the compound represented by the formula (H1).

Moreover, the first compound is also usable as the first host material and the second host material.

### Compound Represented by Formula (1)

In an exemplary arrangement of the organic EL device of the exemplary embodiment, the first compound is a compound represented by the formula (1) below. The first compound represented by the formula (1) includes at least one group represented by a formula (11) below.

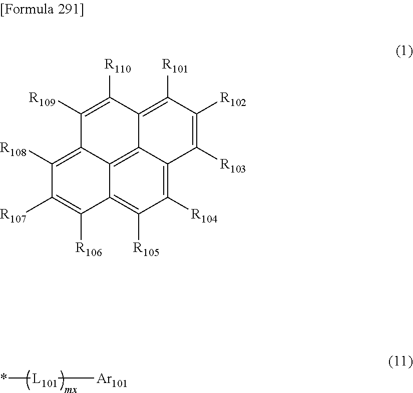

In the formula (1):
R₁₀₁ to R₁₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (11);
at least one of R₁₀₁ to R₁₁₀ is a group represented by the formula (11);
when a plurality of groups represented by the formula (11) are present, the plurality of groups represented by the formula (11) are mutually the same or different;
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 0, 1, 2, 3, 4, or 5;
when two or more L₁₀₁ are present, the two or more L₁₀₁ are mutually the same or different;
when two or more Ar₁₀₁ are present, the two or more Ar₁₀₁ are mutually the same or different; and
in the formula (11) represents a bonding position to a pyrene ring in the formula (1).

In the first compound represented by the formula (1), R₉₀₁, R₉₀₂, R₉₀₃, R₉₀₄, R₉₀₅, R₉₀₆, R₉₀₇, R₈₀₁ and R$₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary embodiment, Ar₁₀₁ is preferably a substituted or unsubstituted aryl group having 6 to 50 ring carbon atoms.

In an exemplary embodiment: Ar₁₀₁ is preferably a substituted or unsubstituted phenyl group, a substituted or unsubstituted naphthyl group, a substituted or unsubstituted biphenyl group, a substituted or unsubstituted terphenyl group, a substituted or unsubstituted pyrenyl group, a substituted or unsubstituted phenanthryl group, or a substituted or unsubstituted fluorenyl group.

In an exemplary embodiment: the first compound is preferably represented by a formula (101) below.

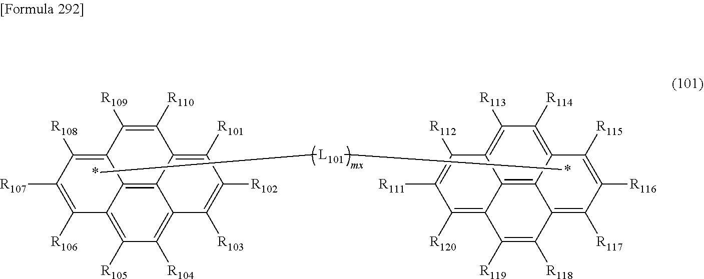

In the formula (101):
R₁₀₁ to R₁₂₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
one of R₁₀₁ to R₁₁₀ represents a bonding position to L₁₀₁, and one of R₁₁₁ to R₁₂₀ represents a bonding position to L₁₀₁;
L₁₀₁ is a single bond, a substituted or unsubstituted arylene group having 6 to 50 ring carbon atoms, or a substituted or unsubstituted divalent heterocyclic group having 5 to 50 ring atoms;
mx is 0, 1, 2, 3, 4, or 5; and
when two or more L₁₀₁ are present, the two or more L₁₀₁ are mutually the same or different.

In an exemplary embodiment: L₁₀₁ is preferably a single bond or a substituted or unsubstituted arylene group having 6 to 50 ring carbon atoms.

In an exemplary embodiment: it is preferable that two or more of R₁₀₁ to R₁₁₀ are each a group represented by the formula (11).

In an exemplary embodiment: it is preferable that two or more of R₁₀₁ to R₁₁₀ are each a group represented by the formula (11) and Ar₁₀₁ is a substituted or unsubstituted aryl group having 6 to 50 ring carbon atoms.

In an exemplary embodiment: Ar₁₀₁ is not a substituted or unsubstituted pyrenyl group, L₁₀₁ is not a substituted or unsubstituted pyrenylene group, and the substituted or unsubstituted aryl group having 6 to 50 ring carbon atoms for R₁₀₁ to R₁₁₀ not being the group represented by the formula (11) is not a substituted or unsubstituted pyrenyl group.

In an exemplary embodiment: R₁₀₁ to R₁₁₀ not being the group represented by the formula (11) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In an exemplary embodiment: R₁₀₁ to R₁₁₀ not being the group represented by the formula (11) are each independently a hydrogen atom, a substituted or unsubstituted alkyl group having 1 to 50 carbon atoms, or a substituted or unsubstituted cycloalkyl group having 3 to 50 ring carbon atoms.

In an exemplary embodiment, R₁₀₁ to R₁₁₀ not being the group represented by the formula (11) are each preferably a hydrogen atom.

### Compound Represented by Formula (1X)

In an exemplary arrangement of the organic EL device of the exemplary embodiment, the first compound is a compound represented by the formula (1X) below.

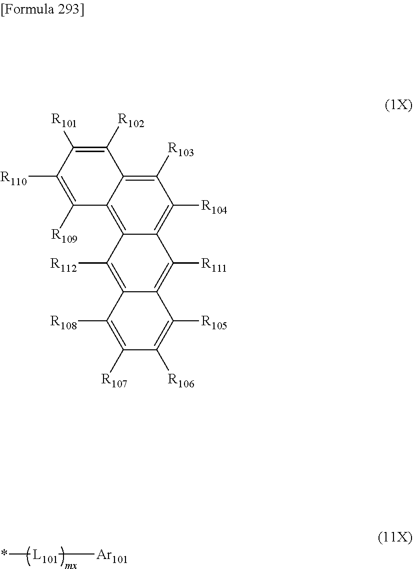

In the formula (1X):
R₁₀₁ to R₁₁₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (11X);
at least one of R₁₀₁ to R₁₁₂ is a group represented by the formula (11X);
when a plurality of groups represented by the formula (11X) are present, the plurality of groups represented by the formula (11X) are mutually the same or different;
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 1, 2, 3, 4, or 5;
when two or more L₁₀₁ are present, the two or more L₁₀₁ are mutually the same or different;
when two or more Ar₁₀₁ are present, the two or more Ar₁₀₁ are mutually the same or different; and
in the formula (11X) represents a bonding position to a benz[a]anthracene ring in the formula (1X).

In an exemplary arrangement of the organic EL device of the exemplary embodiment, the group represented by the formula (11X) is a group represented by a formula (111X) below.

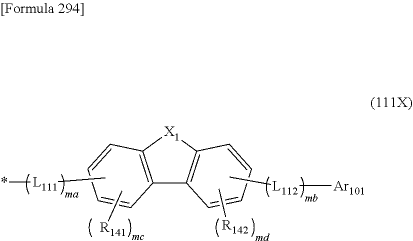

In the formula (111X):
X₁ is CR₁₄₃R₁₄₄, an oxygen atom, a sulfur atom, or NR₁₄₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
m is 1, 2, 3 or 4;
mb is 1, 2, 3 or 4;
ma+mb is 2, 3, or 4;
Ar₁₀₁ represents the same as Ar₁₀₁ in the formula (11);
R₁₄₁, R₁₄₂, R₁₄₃, R₁₄₄ and R₁₄₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₁₄₁ are mutually the same or different;
md is 3; and
three R₁₄₂ are mutually the same or different.

Among positions *1 to *8 of carbon atoms in a cyclic structure represented by a formula (111aX) below in the group represented by the formula (111X), L₁₁₁ is bonded to one of the positions *1 to *4, R₁₄₁ is bonded to each of three positions of the rest of *1 to *4, L₁₁₂ is bonded to one of the positions *5 to *8, and R₁₄₂ is bonded to each of three positions of the rest of *5 to *8.

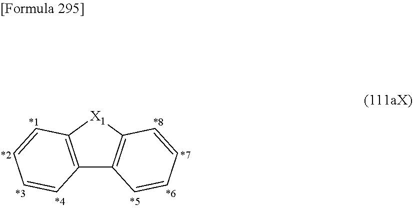

For instance, in the group represented by the formula (111X), when L111 is bonded to a carbon atom at *2 in the cyclic structure represented by the formula (111 aX) and L₁₁₂ is bonded to a carbon atom at *7 in the cyclic structure represented by the formula (111aX), the group represented by the formula (111X) is represented by a formula (111bX) below.

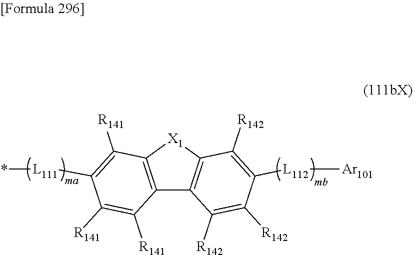

In the formula (111 bX):
X₁, L₁₁₁, L₁₁₂, ma, mb, Ar₁₀₁, R₁₄₁, R₁₄₂, R₁₄₃, R₁₄₄ and R₁₄₅ each independently represent the same as X₁, L₁₁₁, L₁₁₂, ma, mb, Ar₁₀₁, R₁₄₁, R₁₄₂, R₁₄₃, R₁₄₄ and R₁₄₅ in the formula (111X);
a plurality of R₁₄₁ are mutually the same or different; and a plurality of R₁₄₂ are mutually the same or different.

In the organic EL device according to the exemplary embodiment, the group represented by the formula (111X) is preferably a group represented by the formula (111bX).

In the compound represented by the formula (1X), preferably, ma is 1 or 2 and mb is 1 or 2.

In the compound represented by the formula (1X), preferably, ma is 1 and mb is 1.

In the compound represented by the formula (1X), Ar₁₀₁ is preferably a substituted or unsubstituted aryl group having 6 to 50 ring carbon atoms.

In the compound represented by the formula (1X), Ar₁₀₁ is preferably a substituted or unsubstituted phenyl group, a substituted or unsubstituted naphthyl group, a substituted or unsubstituted biphenyl group, a substituted or unsubstituted terphenyl group, a substituted or unsubstituted benz[a]anthryl group; a substituted or unsubstituted pyrenyl group, a substituted or unsubstituted phenanthryl group, or a substituted or unsubstituted fluorenyl group.

The compound represented by the formula (1X) is also preferably represented by a formula (101X) below.

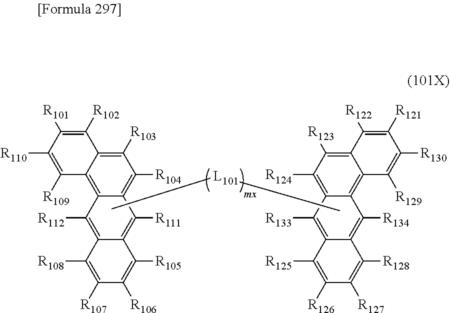

In the formula (101X):
one of R₁₁₁ and R₁₁₂ represents a bonding position to L₁₀₁ and one of R₁₃₃ and R₁₃₄ represents a bonding position to L₁₀₁;
R₁₀₁ to R₁₁₀, R₁₂₁ to R₁₃₀, R₁₁₁ or R₁₁₂ not being the bonding position to L₁₀₁, and R₁₃₃ or R₁₃₄ not being the bonding position to L₁₀₁ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₁₀₁ is a single bond, a substituted or unsubstituted arylene group having 6 to 50 ring carbon atoms, or a substituted or unsubstituted divalent heterocyclic group having 5 to 50 ring atoms;
mx is 1, 2, 3, 4, or 5; and
when two or more L₁₀₁ are present, the two or more L₁₀₁ are mutually the same or different.

In the compound represented by the formula (1X), L₁₀₁ is preferably a single bond, or a substituted or unsubstituted arylene group having 6 to 50 ring carbon atoms.

The compound represented by the formula (1X) is also preferably represented by a formula (102X) below.

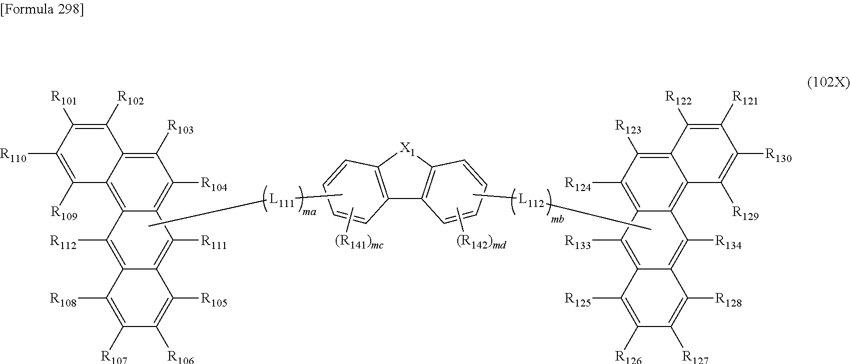

In the formula (102X):
one of R₁₁₁ and R₁₁₂ represents a bonding position to L₁₁₁ and one of R₁₃₃ and R₁₃₄ represents a bonding position to L₁₁₂;
R₁₀₁ to R₁₁₀, R₁₂₁ to R₁₃₀, R₁₁₁ or R₁₁₂ not being the bonding position to L₁₁₁, and R₁₃₃ or R₁₃₄ not being the bonding position to L₁₁₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
X₁ is CR₁₄₃R₁₄₄, an oxygen atom, a sulfur atom, or NR₁₄₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
m is 1, 2, 3 or 4;
mb is 1, 2, 3 or 4;
ma+mb is 2, 3, 4, or 5;
R₁₄₁, R₁₄₂, R₁₄₃, R₁₄₄ and R₁₄₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₁₄₁ are mutually the same or different;
md is 3; and three R₁₄₂ are mutually the same or different.

In the compound represented by the formula (1X), preferably, ma is 1 or 2 and mb is 1 or 2 in the formula (102X).

In the compound represented by the formula (1X), preferably, ma is 1 and mb is 1 in the formula (102X).

In the compound represented by the formula (1X), the group represented by the formula (11X) is also preferably a group represented by a formula (11AX) or a group represented by a formula (11BX) below.

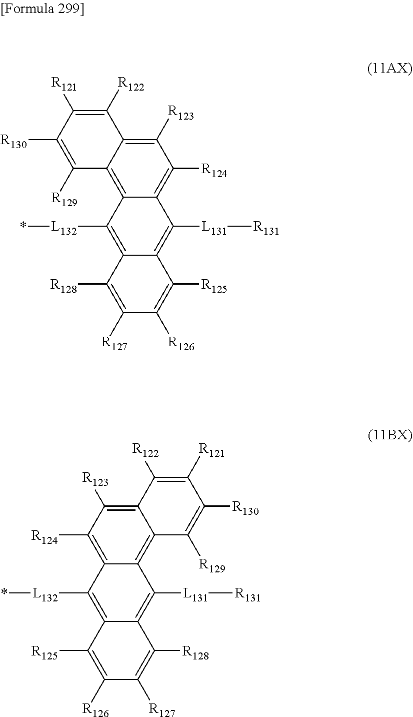

In the formulae (11AX) and (11BX):
R₁₂₁ to R₁₃₁ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by—C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
when a plurality of groups represented by the formula (11AX) are present, the plurality of groups represented by the formula (11AX) are mutually the same or different;
when a plurality of groups represented by the formula (11BX) are present, the plurality of groups represented by the formula (11BX) are mutually the same or different;
L₁₃₁ and L₁₃₂ are each independently a single bond, a substituted or unsubstituted arylene group having 6 to 50 ring carbon atoms, or a substituted or unsubstituted divalent heterocyclic group having 5 to 50 ring atoms; and
in each of the formulae (11AX) and (11BX) represents a bonding position to a benz[a]anthracene ring in the formula (1X).

The compound represented by the formula (1X) is also preferably represented by a formula (103X) below.

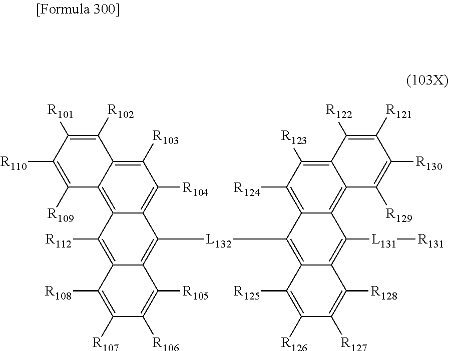

In the formula (103X):
R₁₀₁ to R₁₁₀ and R₁₁₂ respectively represent the same as R₁₀₁ to R₁₁₀ and R₁₁₂ in the formula (1X); and
R₁₂₁ to R₁₃₁, L₁₃₁, and L₁₃₂ respectively represent the same as R₁₂₁ to R₁₃₁, L₁₃₁, and L₁₃₂ in the formula (11BX).

In the compound represented by the formula (1X), L₁₃₁ is also preferably a substituted or unsubstituted arylene group having 6 to 50 ring carbon atoms.

In the compound represented by the formula (1X), L₁₃₂ is also preferably a substituted or unsubstituted arylene group having 6 to 50 ring carbon atoms.

In the compound represented by the formula (1X), two or more of R₁₀₁ to R₁₁₂ are each also preferably a group represented by the formula (11X).

In the compound represented by the formula (1X), it is preferable that two or more of R₁₀₁ to R₁₁₂ are each a group represented by the formula (11X) and Ar₁₀₁ in the formula (11X) is a substituted or unsubstituted aryl group having 6 to 50 ring carbon atoms.

In the compound represented by the formula (1X), it is preferable that Ar₁₀₁ is not a substituted or unsubstituted benz[a]anthryl group, L₁₀₁ is not a substituted or unsubstituted benz[a]anthrylene group, and, the substituted or unsubstituted aryl group having 6 to 50 ring carbon atoms for R₁₀₁ to R₁₁₀ not being the group represented by the formula (11X) is also preferably not a substituted or unsubstituted benz[a]anthryl group.

In the compound represented by the formula (1X), R₁₀₁ to R₁₁₂ not being the group represented by the formula (11X) are preferably each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the compound represented by the formula (1X), R₁₀₁ to R₁₁₂ not being the group represented by the formula (11X) are each preferably a hydrogen atom, a substituted or unsubstituted alkyl group having 1 to 50 carbon atoms, or a substituted or unsubstituted cycloalkyl group having 3 to 50 ring carbon atoms.

In the compound represented by the formula (1X), R₁₀₁ to R₁₁₂ not being the group represented by the formula (11X) are each preferably a hydrogen atom.

### Compound Represented by Formula (12X)

In an exemplary arrangement of the organic EL device of the exemplary embodiment, the first compound is a compound represented by the formula (12X) below.

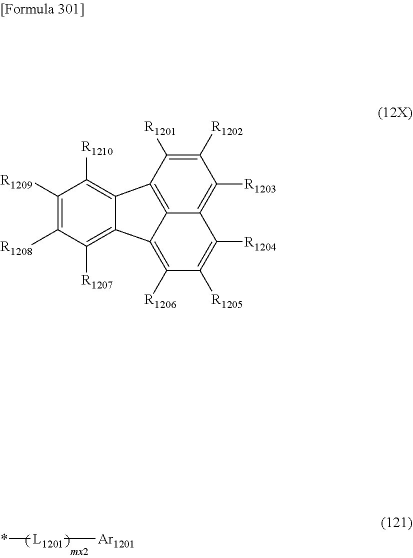

In the formula (12X):
at least one combination of adjacent two or more of R₁₂₀₁ to R₁₂₁₀ are mutually bonded to form a substituted or unsubstituted monocyclic ring, or mutually bonded to form a substituted or unsubstituted fused ring;
R₁₂₀₁ to R₁₂₁₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (121);
at least one of a substituent, if present, for the substituted or unsubstituted monocyclic ring, a substituent, if present, for the substituted or unsubstituted fused ring, or R₁₂₀₁ to R₁₂₁₀ is a group represented by the formula (121);
when a plurality of groups represented by the formula (121) are present, the plurality of groups represented by the formula (121) are mutually the same or different;
L₁₂₀₁ is a single bond, a substituted or unsubstituted arylene group having 6 to 50 ring carbon atoms, or a substituted or unsubstituted divalent heterocyclic group having 5 to 50 ring atoms;
Ar₁₂₀₁ is a substituted or unsubstituted aryl group having 6 to 50 ring carbon atoms, or a substituted or unsubstituted heterocyclic group having 5 to 50 ring atoms;
mx2 is 0, 1, 2, 3, 4, or 5;
when two or more L₁₂₀₁ are present, the two or more L₁₂₀₁ are mutually the same or different;
when two or more Ar₁₂₀₁ are present, the two or more Ar₁₂₀₁ are mutually the same or different; and
in the formula (121) represents a bonding position to a ring represented by the formula (12X).

In the formula (12X), combinations of adjacent two of R₁₂₀₁ to R₁₂₁₀ refer to a combination of R₁₂₀₁ and R₁₂₀₂, a combination of R₁₂₀₂ and R₁₂₀₃, a combination of R₁₂₀₃ and R₁₂₀₄, a combination of R₁₂₀₄ and R₁₂₀₅, a combination of R₁₂₀₅ and R₁₂₀₆, a combination of R₁₂₀₇ and R₁₂₀₈, a combination of R₁₂₀₈ and R₁₂₀₉, and a combination of R₁₂₀₉ and R₁₂₁₀.

### Compound Represented by Formula (13X)

In an exemplary arrangement of the organic EL device of the exemplary embodiment, the first compound is a compound represented by the formula (13X) below.

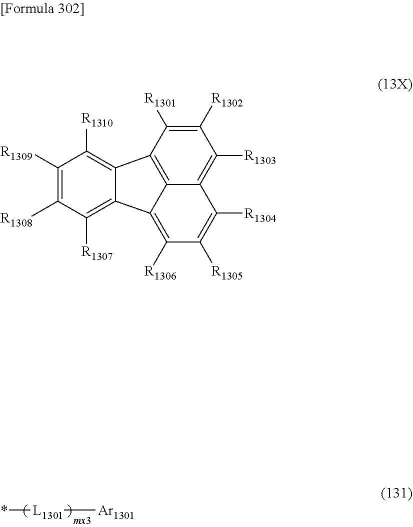

In the formula (13X):
R₁₃₀₁ to R₁₃₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (131);
at least one of R₁₃₀₁ to R₁₃₁₀ is a group represented by the formula (131);
when a plurality of groups represented by the formula (131) are present, the plurality of groups represented by the formula (131) are mutually the same or different;
L₁₃₀₁ is a single bond, a substituted or unsubstituted arylene group having 6 to 50 ring carbon atoms, or a substituted or unsubstituted divalent heterocyclic group having 5 to 50 ring atoms;
Ar₁₃₀₁ is a substituted or unsubstituted aryl group having 6 to 50 ring carbon atoms, or a substituted or unsubstituted heterocyclic group having 5 to 50 ring atoms;
mx3 is 0, 1, 2, 3, 4, or 5;
when two or more L₁₃₀₁ are present, the two or more L₁₃₀₁ are mutually the same or different;
when two or more Ar₁₃₀₁ are present, the two or more Ar₁₃₀₁ are mutually the same or different; and
in the formula (131) represents a bonding position to a fluoranthene ring represented by the formula (13X).

In the organic EL device of the exemplary embodiment, none of combinations of adjacent two or more of R₁₃₀₁ to R₁₃₁₀ not being the group represented by the formula (131) are bonded to each other. Combinations of adjacent two of R₁₃₀₁ to R₁₃₁₀ in the formula (13X) refer to a combination of R₁₃₀₁ and R₁₃₀₂, a combination of R₁₃₀₂ and R₁₃₀₃, a combination of R₁₃₀₃ and R₁₃₀₄, a combination of R₁₃₀₄ and R₁₃₀₅, a combination of R₁₃₀₅ and R₁₃₀₆, a combination of R₁₃₀₇ and R₁₃₀₈, a combination of R₁₃₀₈ and R₁₃₀₉, and a combination of R₁₃₀₉ and R₁₃₁₀.

### Compound Represented by Formula (14X)

In an exemplary arrangement of the organic EL device of the exemplary embodiment, the first compound is a compound represented by the formula (14X) below.

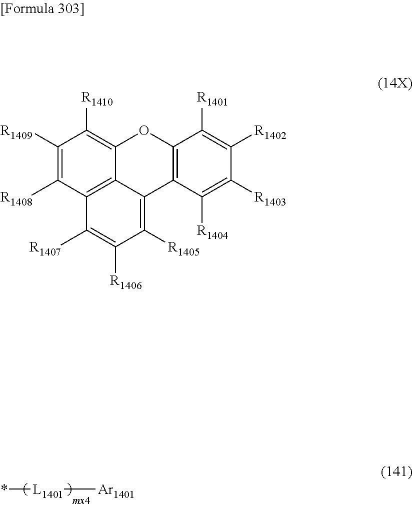

In the formula (14X):
R₁₄₀₁ to R₁₄₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (141);
at least one of R₁₄₀₁ to R₁₄₁₀ is a group represented by the formula (141);
when a plurality of groups represented by the formula (141) are present, the plurality of groups represented by the formula (141) are mutually the same or different;
L₁₄₀₁ is a single bond, a substituted or unsubstituted arylene group having 6 to 50 ring carbon atoms, or a substituted or unsubstituted divalent heterocyclic group having 5 to 50 ring atoms;
Ar₁₄₀₁ is a substituted or unsubstituted aryl group having 6 to 50 ring carbon atoms, or a substituted or unsubstituted heterocyclic group having 5 to 50 ring atoms;
mx4 is 0, 1, 2, 3, 4, or 5;
when two or more L₁₄₀₁ are present, the two or more L₁₄₀₁ are mutually the same or different;
when two or more Ar₁₄₀₁ are present, the two or more Ar₁₄₀₁ are mutually the same or different; and
in the formula (141) represents a bonding position to a ring represented by the formula (14X).

### Compound Represented by Formula (15X)

In an exemplary arrangement of the organic EL device of the exemplary embodiment, the first compound is a compound represented by the formula (15X) below.

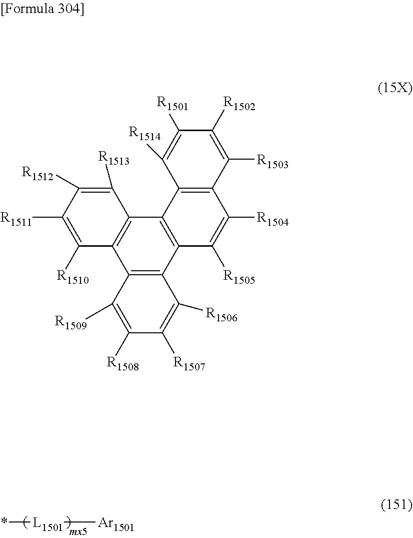

In the formula (15X):
R₁₅₀₁ to R₁₅₁₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (151);
at least one of R₁₅₀₁ to R₁₅₁₄ is a group represented by the formula (151);
when a plurality of groups represented by the formula (151) are present, the plurality of groups represented by the formula (151) are mutually the same or different;
L₁₅₀₁ is a single bond, a substituted or unsubstituted arylene group having 6 to 50 ring carbon atoms, or a substituted or unsubstituted divalent heterocyclic group having 5 to 50 ring atoms;
Ar₁₅₀₁ is a substituted or unsubstituted aryl group having 6 to 50 ring carbon atoms, or a substituted or unsubstituted heterocyclic group having 5 to 50 ring atoms;
mx5 is 0, 1, 2, 3, 4, or 5;
when two or more L₁₅₀₁ are present, the two or more L₁₅₀₁ are mutually the same or different;
when two or more Ar₁₅₀₁ are present, the two or more Ar₁₅₀₁ are mutually the same or different; and
in the formula (151) represents a bonding position to a ring represented by the formula (15X).

### Compound Represented by Formula (16X)

In an exemplary arrangement of the organic EL device of the exemplary embodiment, the first compound is a compound represented by the formula (16X) below.

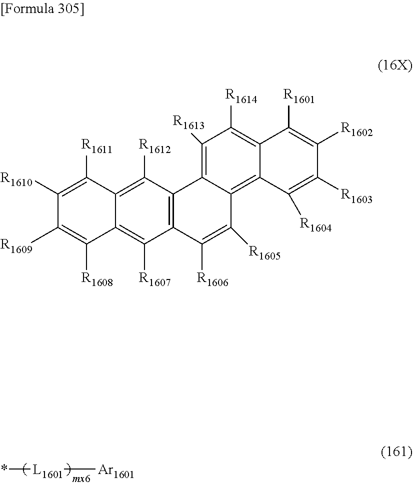

In the formula (16X):
R₁₆₀₁ to R₁₆₁₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (161);
at least one of R₁₆₀₁ to R₁₆₁₄ is a group represented by the formula (161);
when a plurality of groups represented by the formula (161) are present, the plurality of groups represented by the formula (161) are mutually the same or different;
L₁₆₀₁ is a single bond, a substituted or unsubstituted arylene group having 6 to 50 ring carbon atoms, or a substituted or unsubstituted divalent heterocyclic group having 5 to 50 ring atoms;
Ar₁₆₀₁ is a substituted or unsubstituted aryl group having 6 to 50 ring carbon atoms, or a substituted or unsubstituted heterocyclic group having 5 to 50 ring atoms;
mx6 is 0, 1, 2, 3, 4, or 5;
when two or more L₁₆₀₁ are present, the two or more L₁₆₀₁ are mutually the same or different;
when two or more Ar₁₆₀₁ are present, the two or more Ar₁₆₀₁ are mutually the same or different; and
in the formula (161) represents a bonding position to a ring represented by the formula (16X).

### Compound Represented by Formula (1000B)

In an exemplary arrangement of the organic EL device of the exemplary embodiment, the first compound is a compound represented by the formula (1000B) below.

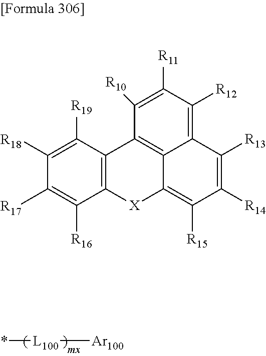

In the formula (1000B):
X is an oxygen atom or a sulfur atom;
at least one combination of adjacent two or more of R₁₀ to R₁₉ are mutually bonded to form a substituted or unsubstituted monocyclic ring, mutually bonded to form a substituted or unsubstituted fused ring, or not mutually bonded;
R₁₀ to R₁₁ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a nitro group, a substituted or unsubstituted aryl group having 6 to 50 ring carbon atoms, a substituted or unsubstituted heterocyclic group having 5 to 50 ring atoms, or a group represented by the formula (110);
at least one of R₁₀ to R₁₉ is a group represented by the formula (110);
when a plurality of groups represented by the formula (110) are present, the plurality of groups represented by the formula (110) are mutually the same or different; L₁₀₀ is a single bond, a substituted or unsubstituted arylene group having 6 to 50 ring carbon atoms, or a substituted or unsubstituted divalent heterocyclic group having 5 to 50 ring atoms;
mx is 1, 2, or 3;
when two or more L₁₀₀ are present, the two or more L₁₀₀ are mutually the same or different;
Ar₁₀₀ is a substituted or unsubstituted aryl group having three or more rings, or a substituted or unsubstituted heterocyclic group having two or more aromatic rings and one or more heterocycles;
Ar₁₀₀ does not include an anthracene ring;
when two or more Ar₁₀₀ are present, the two or more Ar₁₀₀ are mutually the same or different;
* in the formula (110) represents a bonding position;
in the first compound represented by the formula (1000B), R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In the formula (1000B), X is preferably an oxygen atom.

The compound represented by the formula (1000B) is preferably a compound represented by a formula (100) below and having at least one group represented by the formula (110).

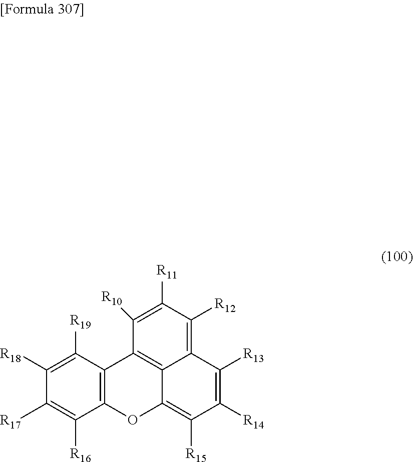

In the formula (100): R₁₀ to R₁₉ each independently represent the same as R₁₀ to R₁₉ in the formula (1000B); and Ar₁₀₀, L₁₀₀, and mx respectively represent the same as Ar₁₀₀, L₁₀₀, and mx in the formula (110).

A compound represented by the formula (1000B) is also preferably a compound represented by a formula (101) or (102) below.

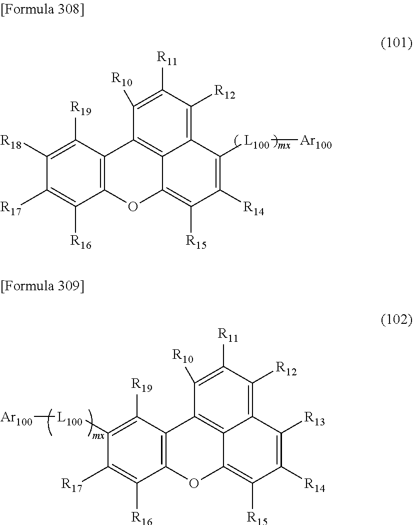

In the formulae (101) and (102): R₁₀ to R₁₉ each independently represent the same as R₁₀ to R₁₉ in the formula (1000B); and Ar₁₀₀, L₁₀₀, and mx respectively represent the same as Ar₁₀₀, L₁₀₀, and mx in the formula (110).

In the formula (1000B), R₁₀ to R₁₉ not being a group represented by the formula (110) are preferably each independently a hydrogen atom, a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms.

In the formula (1000B), R₁₀ to R₁₉ not being the group represented by the formula (110) are each preferably a hydrogen atom.

In the formula (1000B), L₁₀₀ is preferably a single bond or a substituted or unsubstituted arylene group having three or less benzene rings.

In the formula (1000B), L₁₀₀ is preferably not a substituted or unsubstituted anthrylene group.

In the formula (1000B), L₁₀₀ is also preferably a single bond.

In the formula (1000B), a group represented by -(L₁₀₀)ₘₓ- in the formula (110) is also preferably a group represented by one of formulae (111) to (120) below.

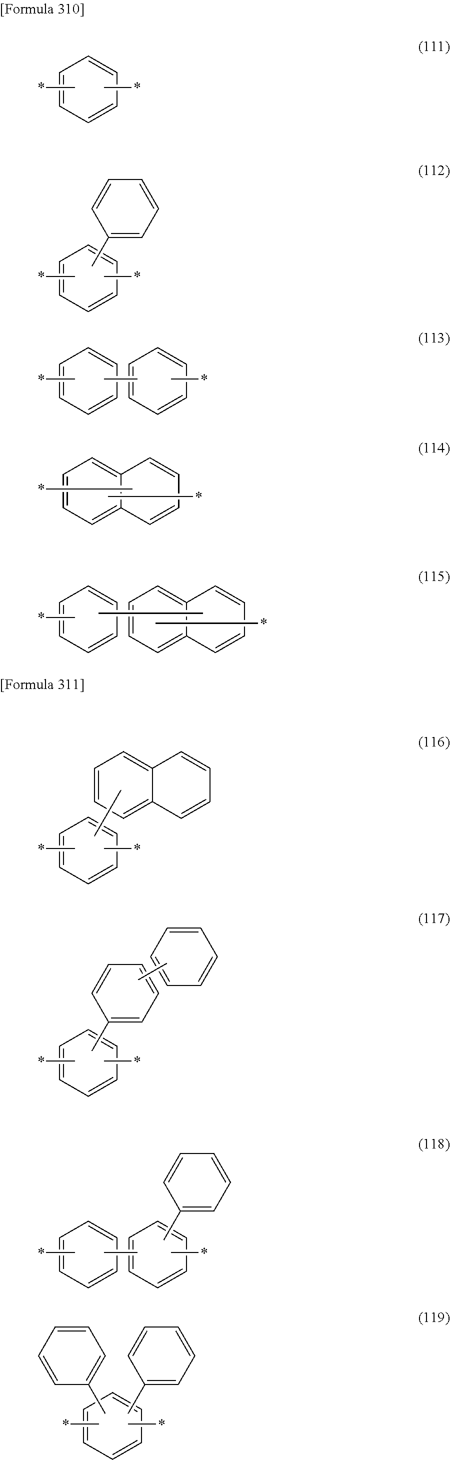

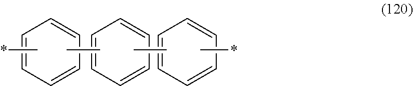

Each * in the formulae (111) to (120) represents a bonding position.

A group represented by -(L₁₀₀)ₘₓ- in the formula (110) is preferably a group represented by a formula (111) or (112) below.

In the formula (1000B), Ar₁₀₀ is preferably an aryl group in which four or more substituted or unsubstituted benzene rings are fused.

In the formula (1000B), Ar₁₀₀ is preferably an aryl group in which four substituted or unsubstituted benzene rings are fused or an aryl group in which five substituted or unsubstituted benzene rings are fused.

In the formula (1000B): Ar₁₀₀ is preferably a group represented by a formula (1100), (1200), (1300), (1400), (1500), (1600), (1700), or (1800) below.

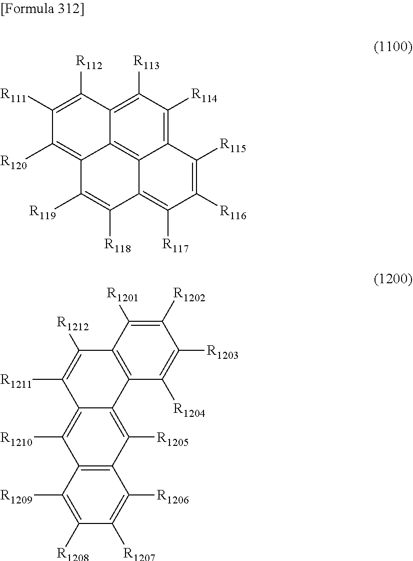

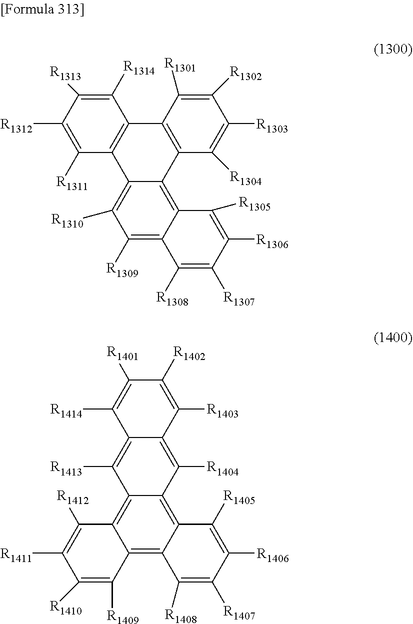

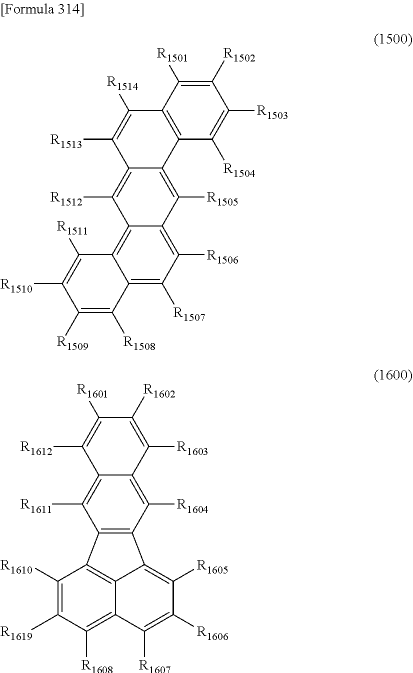

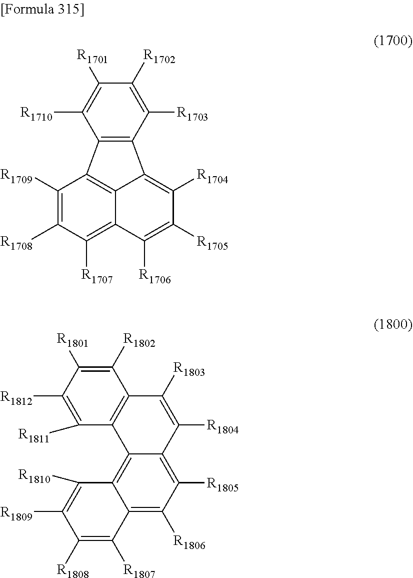

In the formula (1100), one of R₁₁₁ to R₁₂₀ is a bond.
In the formula (1200), one of R₁₂₀₁ to R₁₂₁₂ is a bond.
In the formula (1300), one of R₁₃₀₁ to R₁₃₁₄ is a bond.
In the formula (1400), one of R₁₄₀₁ to R₁₄₁₄ is a bond.
In the formula (1500), one of R₁₅₀₁ to R₁₅₁₄ is a bond.
In the formula (1600), one of R₁₆₀₁ to R₁₆₁₂ is a bond.
In the formula (1700), one of R₁₇₀₁ to R₁₇₁₀ is a bond.
In the formula (1800), one of R₁₈₀₁ to R₁₈₁₂ is a bond.
R₁₁₁ to R₁₂₀ not being a bond, R₁₂₀₁ to R₁₂₁₂ not being a bond, R₁₃₀₁ to R₁₃₁₄ not being a bond, R₁₄₀₁ to R₁₄₁₄ not being a bond, R₁₅₀₁ to R₁₅₁₄ not being a bond, R₁₆₀₁ to R₁₆₁₂ not being a bond, R₁₇₀₁ to R₁₇₁₀ not being a bond, and R₁₈₀₁ to R₁₈₁₂ not being a bond are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a nitro group, a substituted or unsubstituted aryl group having 6 to 50 ring carbon atoms, or a substituted or unsubstituted heterocyclic group having 5 to 50 ring atoms.

The group represented by the formula (1100) in which R₁₁₁ is a bond is a group represented by a formula (1112) below. The group represented by the formula (1100) in which R₁₂₀ is a bond is a group represented by a formula (1113) below. The group represented by the formula (1100) in which R₁₁₁ is a bond is a group represented by a formula (1114) below.

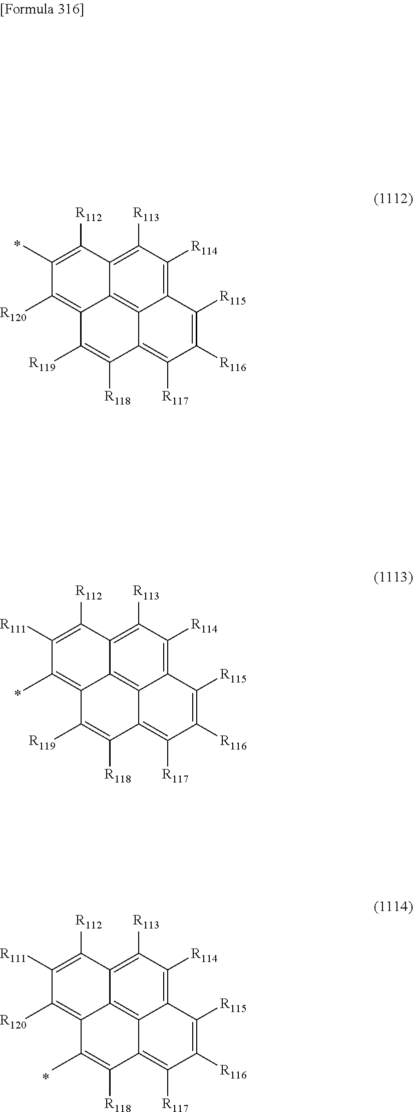

In the formulae (1112), (1113), and (1114):
R₁₁₁ to R₁₂₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a nitro group, a substituted or unsubstituted aryl group having 6 to 50 ring carbon atoms, or a substituted or unsubstituted heterocyclic group having 5 to 50 ring atoms; and
each * in the formulae (1112) to (1114) represents a bonding position.

In the formulae (1100), (1200), (1300), (1400), (1500), (1600), (1700), and (1800), R₁₁₁ to R₁₂₀ not being a bond, R₁₂₀₁ to R₁₂₁₂ not being a bond, R₁₃₀₁ to R₁₃₁₄ not being a bond, R₁₄₀₁ to R₁₄₁₄ not being a bond, R₁₅₀₁ to R₁₅₁₄ not being a bond, R₁₆₀₁ to R₁₆₁₂ not being a bond, R₁₇₀₁ to R₁₇₁₀ not being a bond, and R₁₈₀₁ to R₁₈₁₂ not being a bond are preferably each independently a hydrogen atom, a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms.

In the formulae (1100), (1200), (1300), (1400), (1500), (1600), (1700), and (1800), R₁₁₁ to R₁₂₀ not being a bond, R₁₂₀₁ to R₁₂₁₂ not being a bond, R₁₃₀₁ to R₁₃₁₄ not being a bond, R₁₄₀₁ to R₁₄₁₄ not being a bond, R₁₅₀₁ to R₁₅₁₄ not being a bond, R₁₆₀₁ to R₁₆₁₂ not being a bond, R₁₇₀₁ to R₁₇₁₀ not being a bond, and R₁₈₀₁ to R₁₈₁₂ not being a bond are preferably each a hydrogen atom.

A compound represented by the formula (1000B) preferably includes a benzoxanthene ring in a molecule.

In a compound represented by each of the formulae (100), (101), and (102), a benzoxanthene ring is also preferably replaced with a benzothioxanthene ring.

### Compound Represented by Formula (17X-1)

In an exemplary arrangement of the organic EL device of the exemplary embodiment, the first compound is a compound represented by the formula (17X-1) below.

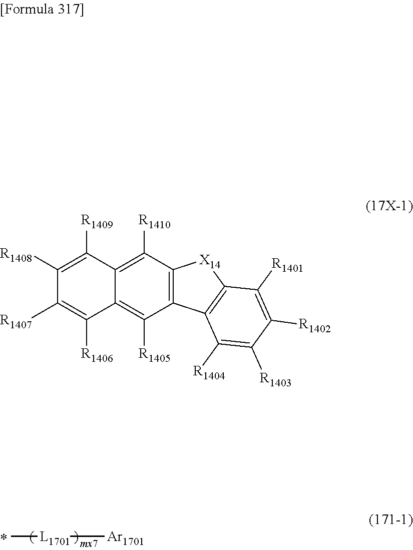

In the formula (17X-1):
X₁₄ is an oxygen atom or a sulfur atom;
at least one combination of adjacent two or more of R₁₄₀₁ to R₁₄₀₄ are mutually bonded to form a substituted or unsubstituted monocyclic ring, mutually bonded to form a substituted or unsubstituted fused ring, or not mutually bonded;
at least one combination of adjacent two or more of R₁₄₀₅ to R₁₄₁₀ are mutually bonded to form a substituted or unsubstituted monocyclic ring, mutually bonded to form a substituted or unsubstituted fused ring, or not mutually bonded;
at least one of R₁₄₀₁ to R₁₄₁₀ is a group represented by the formula (171-1);
R₁₄₀₁ to R₁₄₁₀ forming neither the monocyclic ring nor the fused ring and not being a group represented by the formula (171-1) are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (171-1);
at least one of R₁₄₀₁ to R₁₄₁₀ is a group represented by the formula (171-1);
when a plurality of groups represented by the formula (171-1) are present, the plurality of groups represented by the formula (171-1) are mutually the same or different;
L₁₇₀₁ is a single bond, a substituted or unsubstituted arylene group having 6 to 50 ring carbon atoms, or a substituted or unsubstituted divalent heterocyclic group having 5 to 50 ring atoms;
Ar₁₇₀₁ is a substituted or unsubstituted aryl group having 6 to 50 ring carbon atoms, or a substituted or unsubstituted heterocyclic group having 5 to 50 ring atoms;
mx7 is 0, 1, 2, 3, 4, or 5;
when two or more L₁₇₀₁ are present, the two or more L₁₇₀₁ are mutually the same or different;
when two or more Ar₁₇₀₁ are present, the two or more Ar₁₇₀₁ are mutually the same or different;
X₉₀₁ to X₉₀₅, R₈₀₁, and R₈₀₂ each independently represent the same as X₉₀₁ to X₉₀₅, R₈₀₁, and R₈₀₂ in the formula (1000B); and
in the formula (171-1) represents a bonding position to a ring represented by the formula (17X-1).

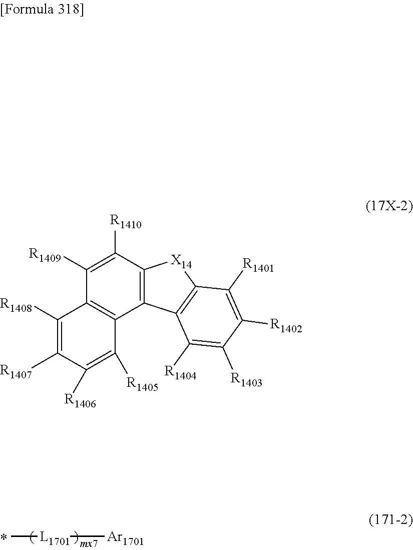

In the formula (17X-2), R₁₄₀₁ to R₁₄₁₀ and X₁₄ each independently represent the same as R₁₄₀₁ to R₁₄₁₀ and X₁₄ in the formula (17X-1).

A group represented by the formula (171-2) represent the same as a group represented by the formula (171-1). In the formula (171-2), L₁₇₀₁, Ar₁₇₀₁, and mx7 each independently represent the same as L₁₇₀₁, Ar₁₇₀₁, and mx7 in the formula (171-1).

When a plurality of groups represented by the formula (171-2) are present, the plurality of groups represented by the formula (171-2) are mutually the same or different.
in the formula (171-2) represents a bonding position to a ring represented by the formula (17X-2).

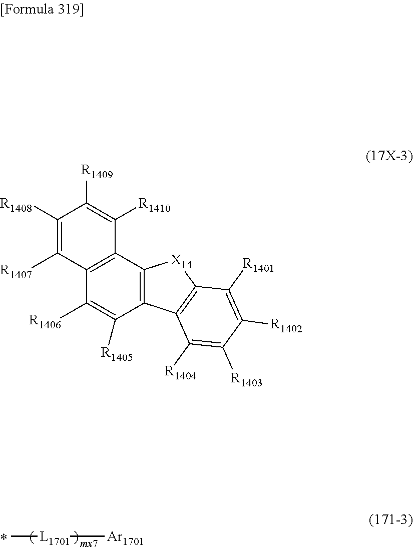

In the formula (17X-3), R₁₄₀₁ to R₁₄₁₀ and X₁₄ each independently represent the same as R₁₄₀₁ to R₁₄₁₀ and X₁₄ in the formula (17X-1).

A group represented by the formula (171-3) represent the same as a group represented by the formula (171-1). In the formula (171-3), L₁₇₀₁, Ar₁₇₀₁, and mx7 each independently represent the same as L₁₇₀₁, Ar₁₇₀₁, and mx7 in the formula (171-1).

When a plurality of groups represented by the formula (171-3) are present, the plurality of groups represented by the formula (171-3) are mutually the same or different.
in the formula (171-3) represents a bonding position to a ring represented by the formula (17X-3).

In the formulae (17X-1), (17X-2), and (17X-3), X₁₄ is preferably an oxygen atom.

### Compound Represented by Formula (18)

In an exemplary arrangement of the organic EL device of the exemplary embodiment, the first compound is a compound represented by the formula (18) below.

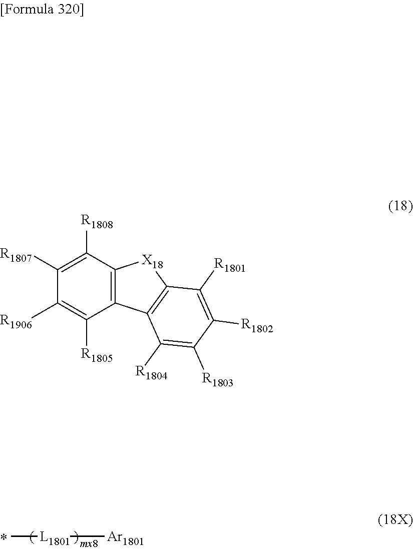

In the formula (18):
X₁₈ is an oxygen atom or a sulfur atom;
at least one combination of adjacent two or more of R₁₈₀₁ to R₁₈₀₄ are mutually bonded to form a substituted or unsubstituted monocyclic ring, mutually bonded to form a substituted or unsubstituted fused ring, or not mutually bonded;
at least one combination of adjacent two or more of R₁₈₀₅ to R₁₈₀₈ are mutually bonded to form a substituted or unsubstituted monocyclic ring, mutually bonded to form a substituted or unsubstituted fused ring, or not mutually bonded;
at least one of R₁₈₀₁ to R₁₈₀₈ is a group represented by the formula (18X);
R₁₈₀₁ to R₁₈₀₈ forming neither the monocyclic ring nor the fused ring and not being a group represented by the formula (18X) are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (18X);
at least one of R₁₈₀₁ to R₁₈₀₈ is a group represented by the formula (18X);
when a plurality of groups represented by the formula (18X) are present, the plurality of groups represented by the formula (18X) are mutually the same or different;
L₁₈₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx8 is 0, 1, 2, 3, 4, or 5;
when two or more L₁₈₀₁ are present, the two or more L₁₈₀₁ are mutually the same or different;
when two or more Ar₁₈₀₁ are present, the two or more Ar₁₈₀₁ are mutually the same or different;
X₉₀₁ to X₉₀₅, R₈₀₁, and R$₀₂ each independently represent the same as X₉₀₁ to X₉₀₅, R₈₀₁, and R₈₀₂ in the formula (1000B); and
in the formula (18X) represents a bonding position to a ring represented by the formula (18).

In the formula (18), X₁, is preferably an oxygen atom.

In first compound, the groups specified to be “substituted or unsubstituted” are each preferably an “unsubstituted” group.

In the organic EL device according to the exemplary embodiment, also preferably, the second host material has, in a molecule, a linking structure including a benzene ring and a naphthalene ring linked to each other with a single bond, in which the benzene ring and the naphthalene ring in the linking structure are each independently fused or not fused with a further monocyclic ring or fused ring, and the benzene ring and the naphthalene ring in the linking structure are further linked to each other by cross-linking at at least one site other than the single bond.

When the second host material has the linking structure including such cross-linking, deterioration in the chromaticity of the organic EL device is expected to be inhibited.

The second host material in the above case is only required to have a linking structure as the minimum unit in a molecule, the linking structure including a benzene ring and a naphthalene ring linked to each other with a single bond (occasionally referred to as a benzene-naphthalene linking structure), the linking structure being as represented by a formula (X1) or a formula (X2) below. Further, the benzene ring may be fused with a monocyclic ring or fused ring, and the naphthalene ring may be fused with a monocyclic ring or fused ring. For instance, also in a case where the second host material has, in a molecule, a linking structure including a naphthalene ring and a naphthalene ring linked to each other with a single bond (occasionally referred to as a naphthalene-naphthalene linking structure) and being as represented by a formula (X3), a formula (X4), or a formula (X5) below, the naphthalene-naphthalene linking structure is regarded as including the benzene-naphthalene linking structure since one of the naphthalene rings includes a benzene ring.

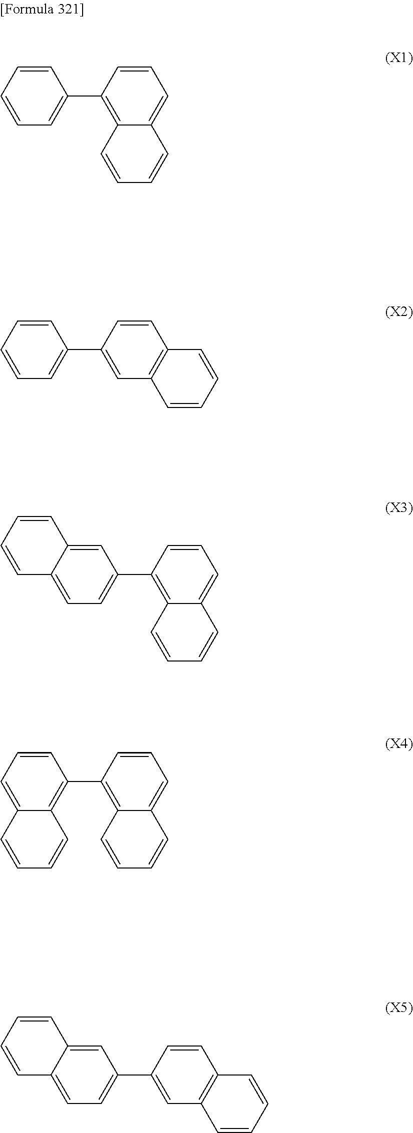

In the organic EL device according to the exemplary, the cross-linking also preferably includes a double bond. Specifically, the first host material also preferably has a structure in which the benzene ring and the naphthalene ring are further linked to each other at any other site than the single bond by the cross-linking structure including a double bond.

Assuming that the benzene ring and the naphthalene ring in the benzene-naphthalene linking structure are further linked to each other at at least one site other than the single bond by cross-linking, for instance, a linking structure (fused ring) represented by a formula (X11) below is obtained in a case of the formula (X1), and a linking structure (fused ring) represented by a formula (X31) below is obtained in a case of the formula (X3).

Assuming that the benzene ring and the naphthalene ring in the benzene-naphthalene linking structure are further linked to each other at any other site than the single bond by cross-linking including a double bond, for instance, a linking structure (fused ring) represented by a formula (X12) below is obtained in a case of the formula (X1), a linking structure (fused ring) represented by a formula (X21) or formula (X22) below is obtained in a case of the formula (X2), a linking structure (fused ring) represented by a formula (X41) below is obtained in a case of the formula (X4), and a linking structure (fused ring) represented by a formula (X51) below is obtained in a case of the formula (X5).

Assuming that the benzene ring and the naphthalene ring in the benzene-naphthalene linking structure are further linked to each other at at least one site other than the single bond by cross-linking including a hetero atom (e.g., an oxygen atom), for instance, a linking structure (fused ring) represented by a formula (X13) below is obtained in a case of the formula (X1).

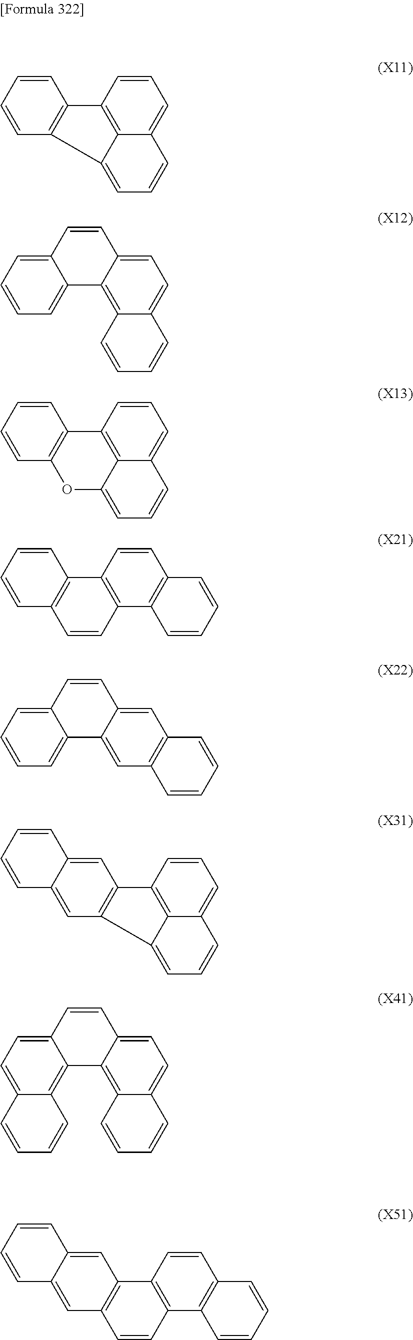

In the organic EL device according to the exemplary embodiment, also preferably, the second host material has, in a molecule, a biphenyl structure including a first benzene ring and a second benzene ring linked to each other with a single bond, and the first benzene ring and the second benzene ring in the biphenyl structure are further linked to each other by cross-linking at at least one site other than the single bond.

In the organic EL device according to the exemplary embodiment, also preferably, the first benzene ring and the second benzene ring in the biphenyl structure are further linked to each other by the cross-linking at one site other than the single bond. When the second host material has the biphenyl structure including such cross-linking, deterioration in the chromaticity of the organic EL device is expected to be inhibited.

In the organic EL device according to the exemplary, the cross-linking also preferably includes a double bond.

In the organic EL device according to the exemplary embodiment, the cross-linking also preferably includes no double bond.

Also preferably, the first benzene ring and the second benzene ring in the biphenyl structure are further linked to each other by the cross-linking at two sites other than the single bond.

In the organic EL device according to the exemplary embodiment, also preferably, the first benzene ring and the second benzene ring in the biphenyl structure are further linked to each other by the cross-linking at two sites other than the single bond, and the cross-linking includes no double bond. When the second host material has the biphenyl structure including such cross-linking, deterioration in the chromaticity of the organic EL device is expected to be inhibited.

For instance, assuming that the first benzene ring and the second benzene ring in the biphenyl structure represented by a formula (BP1) below are further linked to each other by cross-linking at at least one site other than the single bond, the biphenyl structure is exemplified by linking structures (fused rings) represented by formulae (BP11) to (BP15) below.

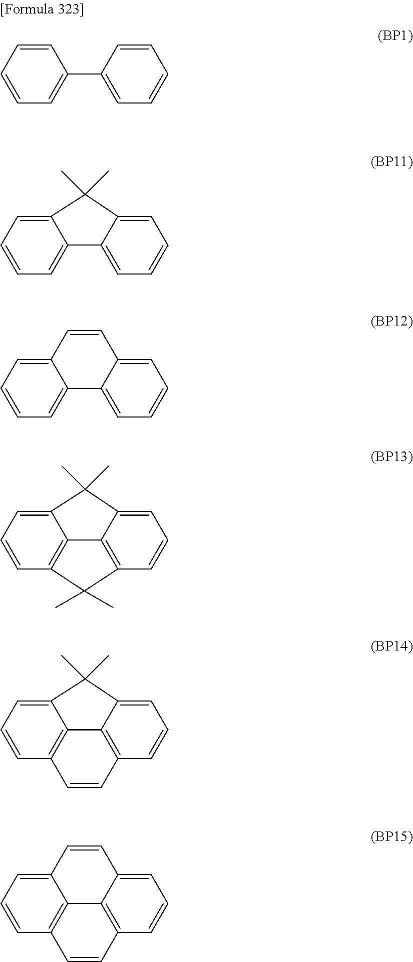

The formula (BP11) represents a linking structure in which the first benzene ring and the second benzene ring are linked to each other at one site other than the single bond by cross-linking including no double bond.

The formula (BP12) represents a linking structure in which the first benzene ring and the second benzene ring are linked to each other at one site other than the single bond by cross-linking including a double bond.

The formula (BP13) represents a linking structure in which the first benzene ring and the second benzene ring are linked to each other at two sites other than the single bond by cross-linking including no double bond.

The formula (BP14) represents a linking structure in which the first benzene ring and the second benzene ring are linked to each other by cross-linking including no double bond at one of two sites other than the single bond, and the first benzene ring and the second benzene ring are linked to each other by cross-linking including a double bond at the other of the two sites other than the single bond.

The formula (BP15) represents a linking structure in which the first benzene ring and the second benzene ring are linked to each other at two sites other than the single bond by cross-linking including a double bond.

In first compound, the groups specified to be “substituted or unsubstituted” are each preferably an “unsubstituted” group.

### Method of Producing First Compound

The first compound usable for the organic EL device according to the exemplary embodiment can be produced by a known method. The first compound can also be produced based on a known method through a known alternative reaction using a known material(s) tailored for the target compound.

### Specific Examples of First Compound

Specific examples of the first compound usable for the organic EL device according to the exemplary embodiment include compounds below. It should however be noted that the invention is not limited to the specific examples of the first compound.

In the specific examples of the compound herein, D represents a deuterium atom, Me represents a methyl group, and tBu represents a tert-butyl group.

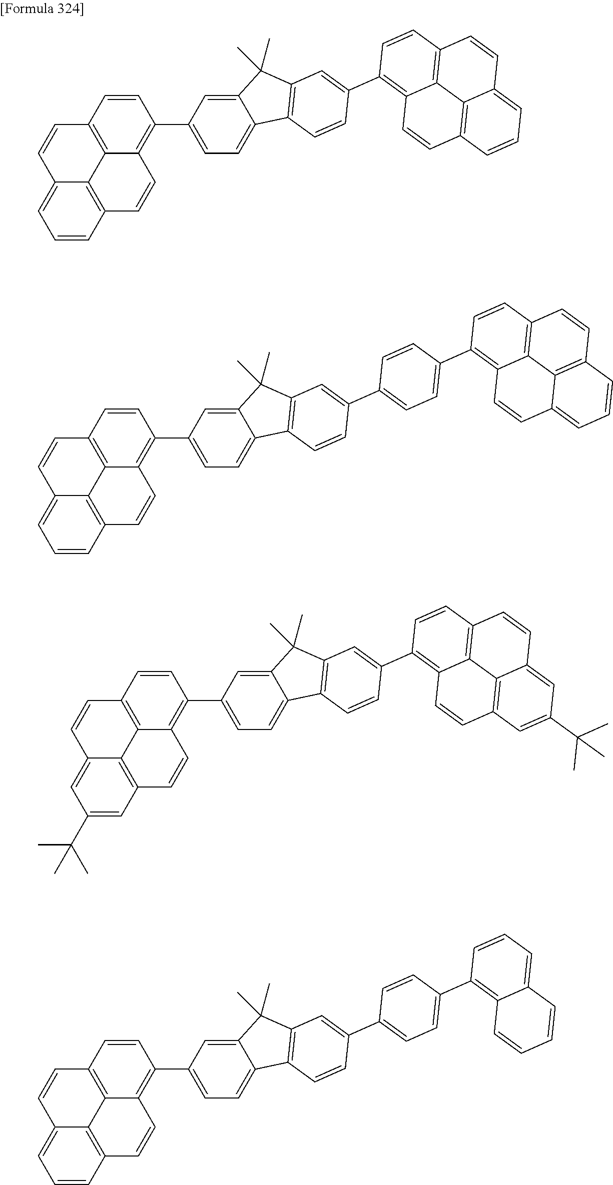

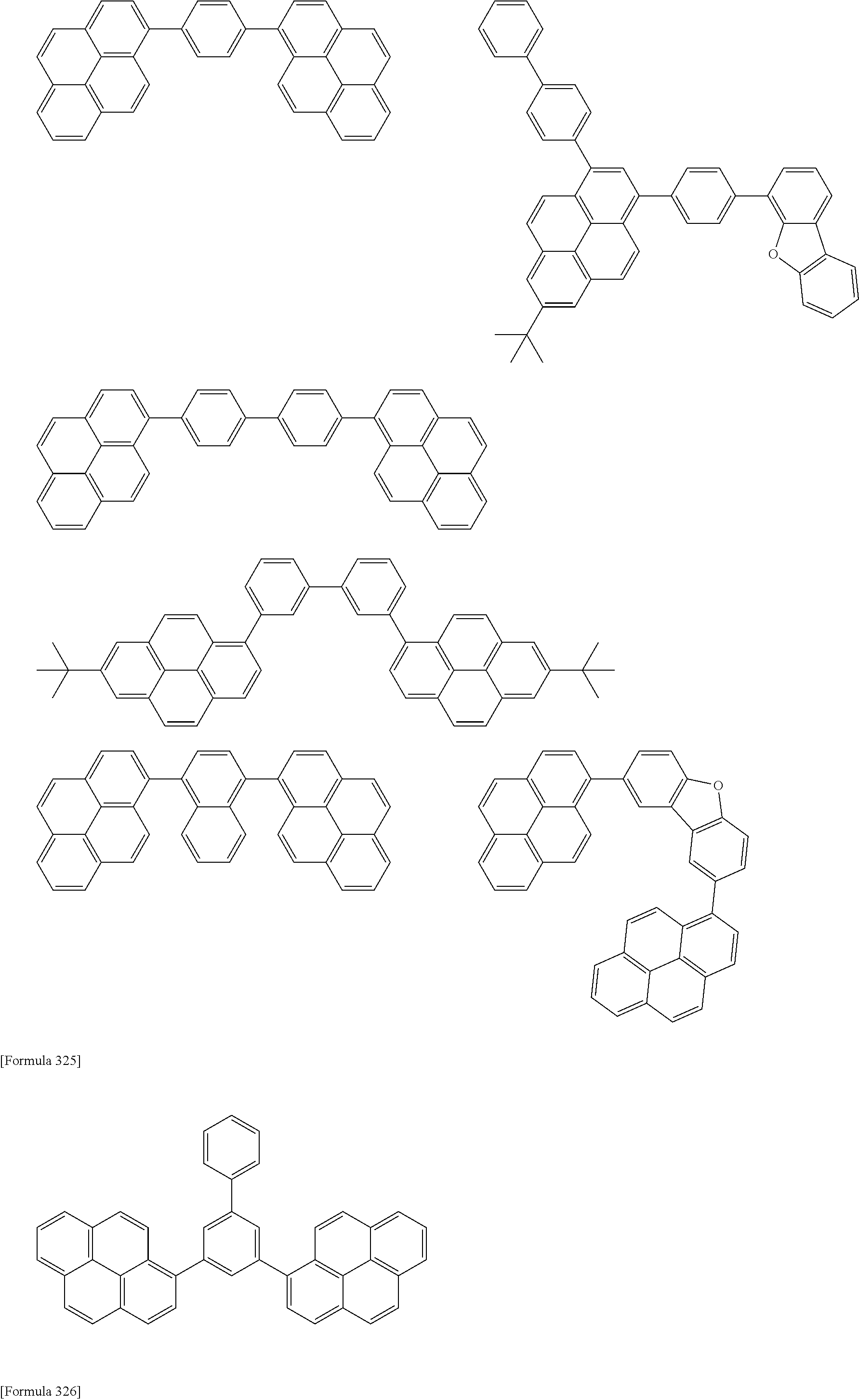

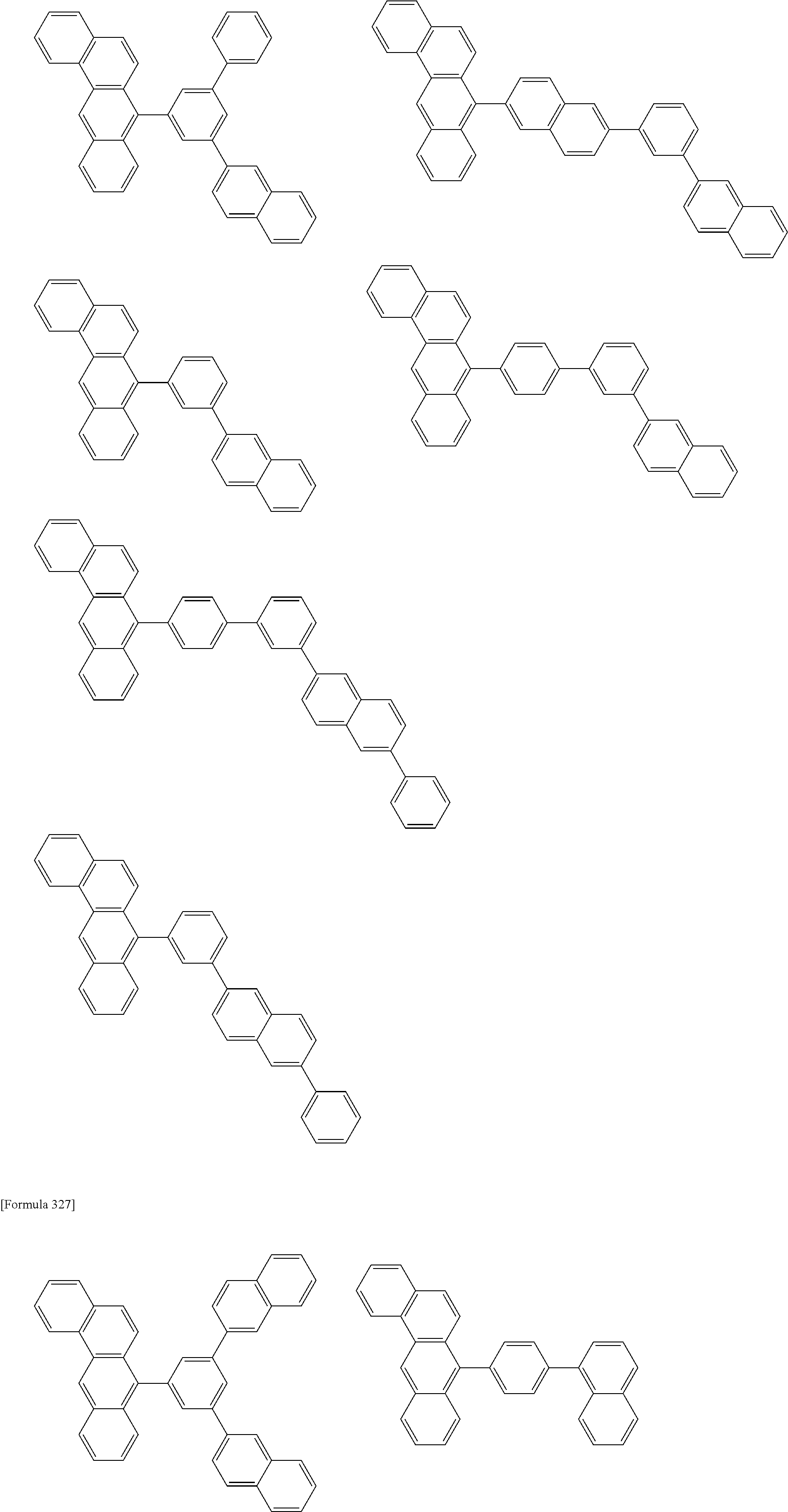

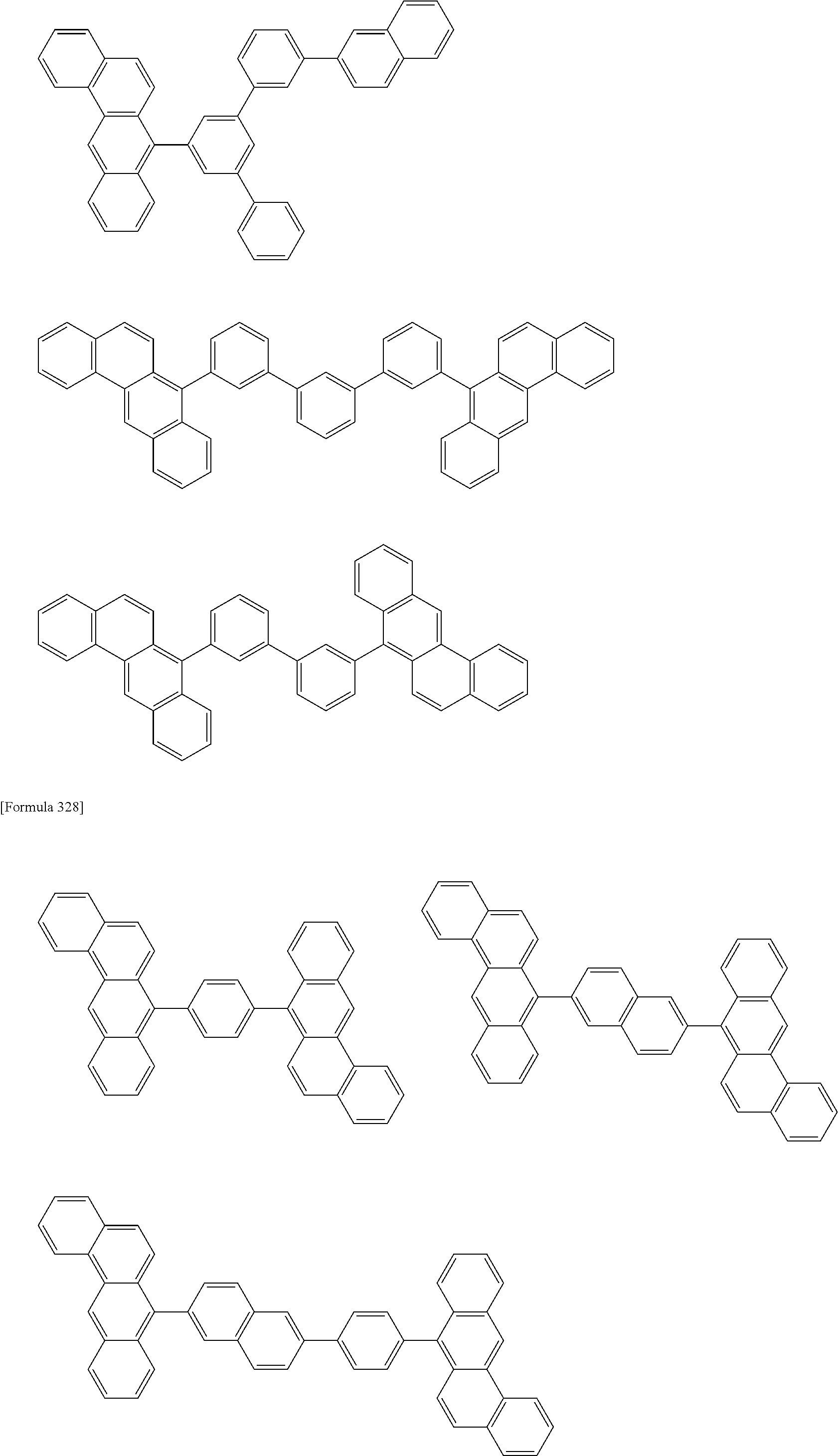

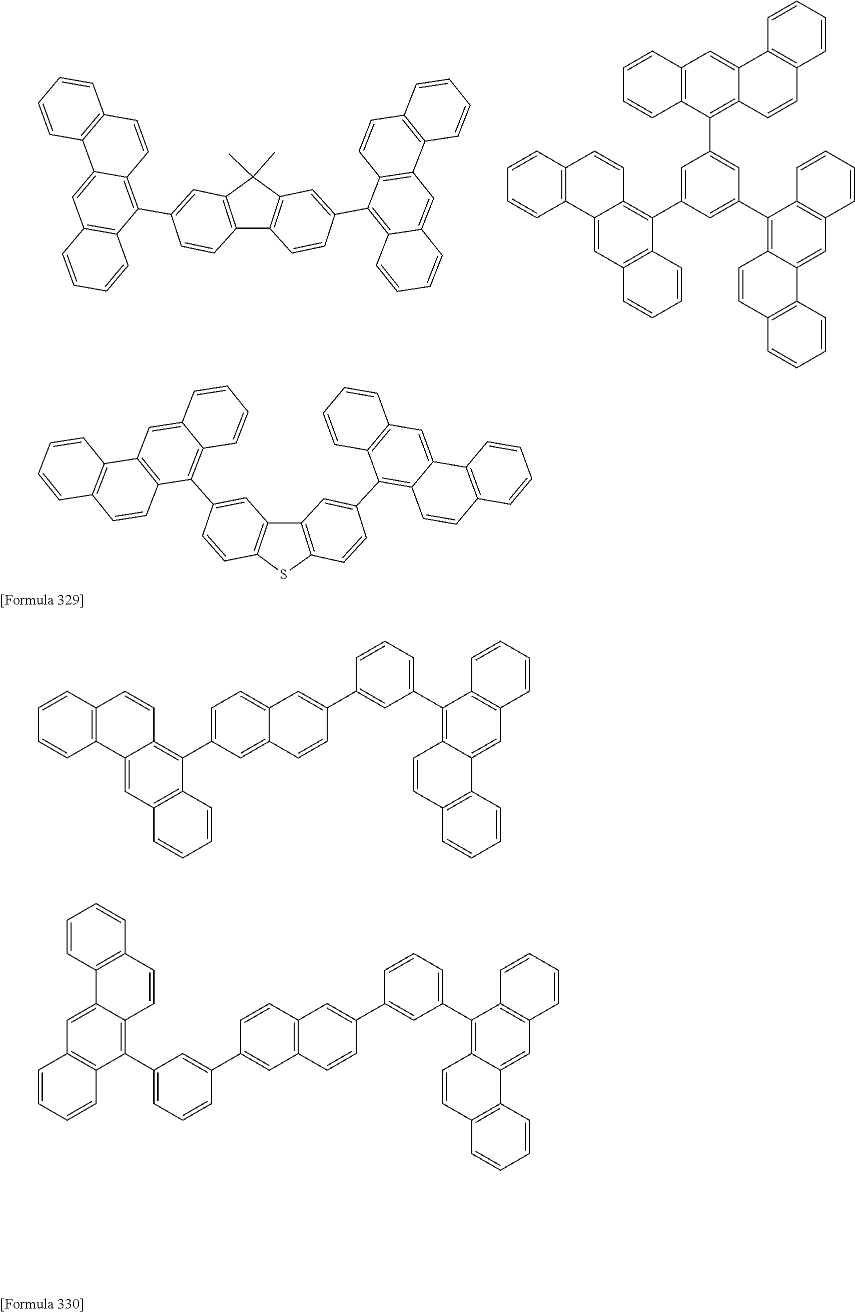

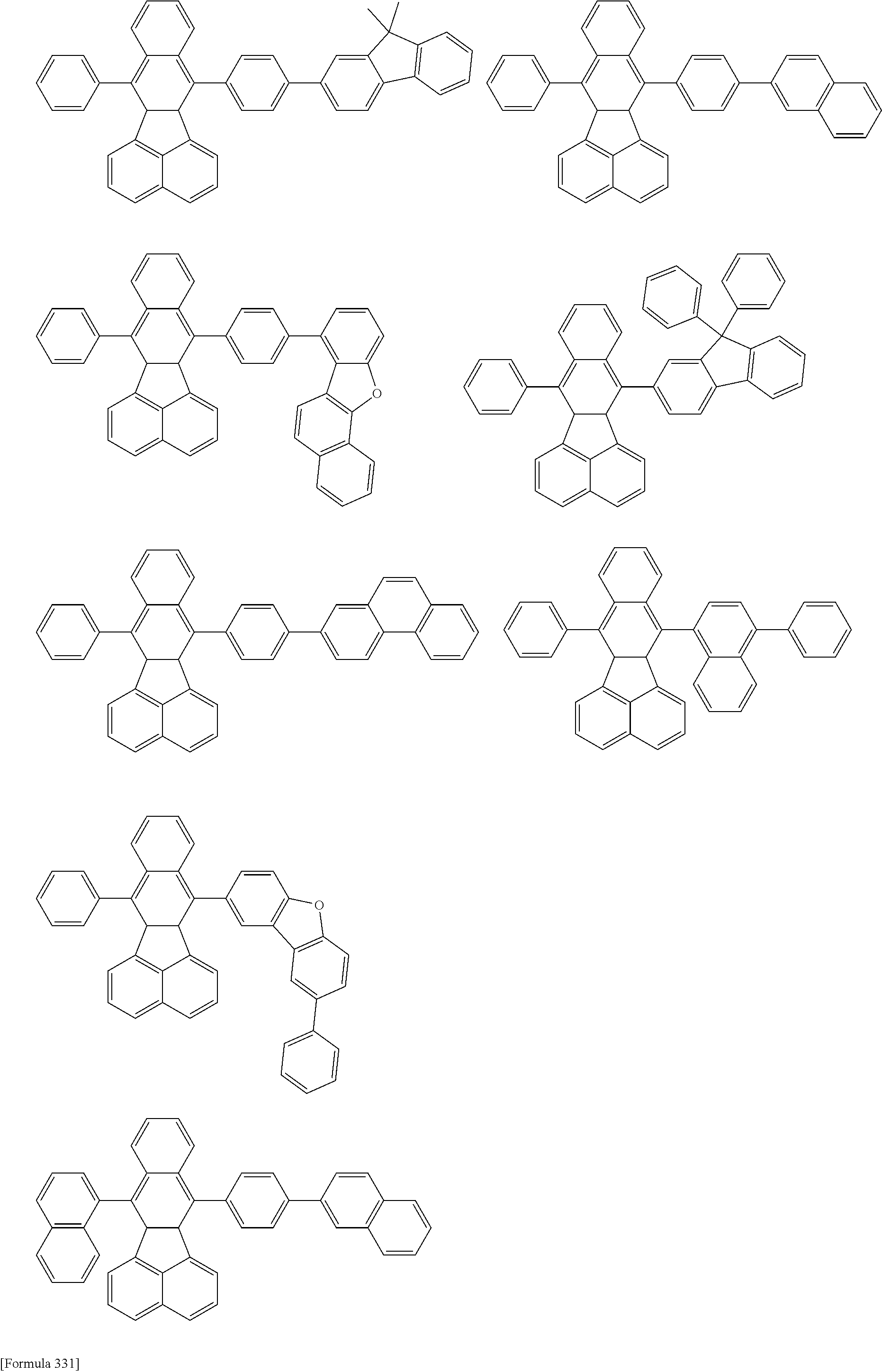

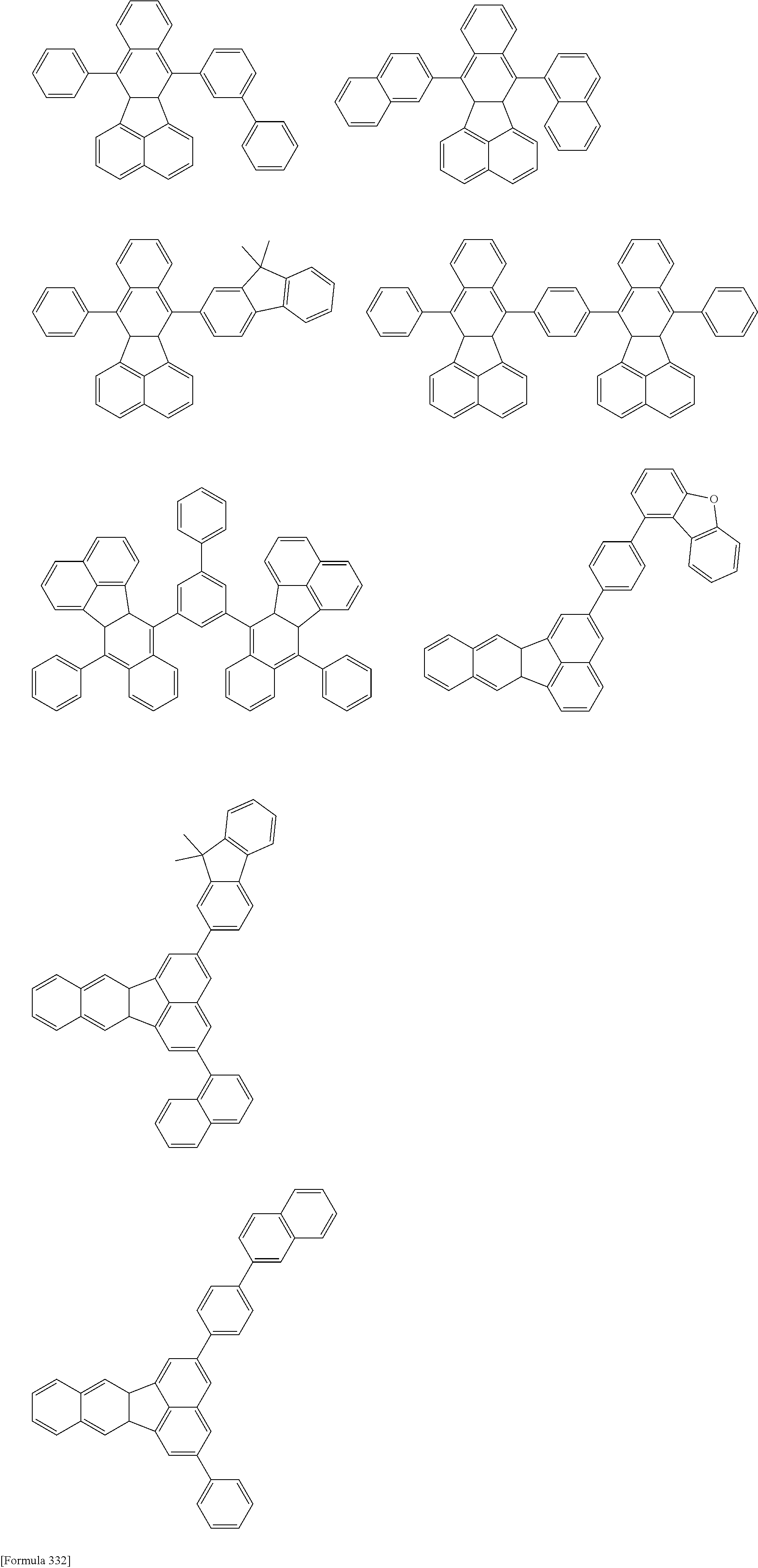

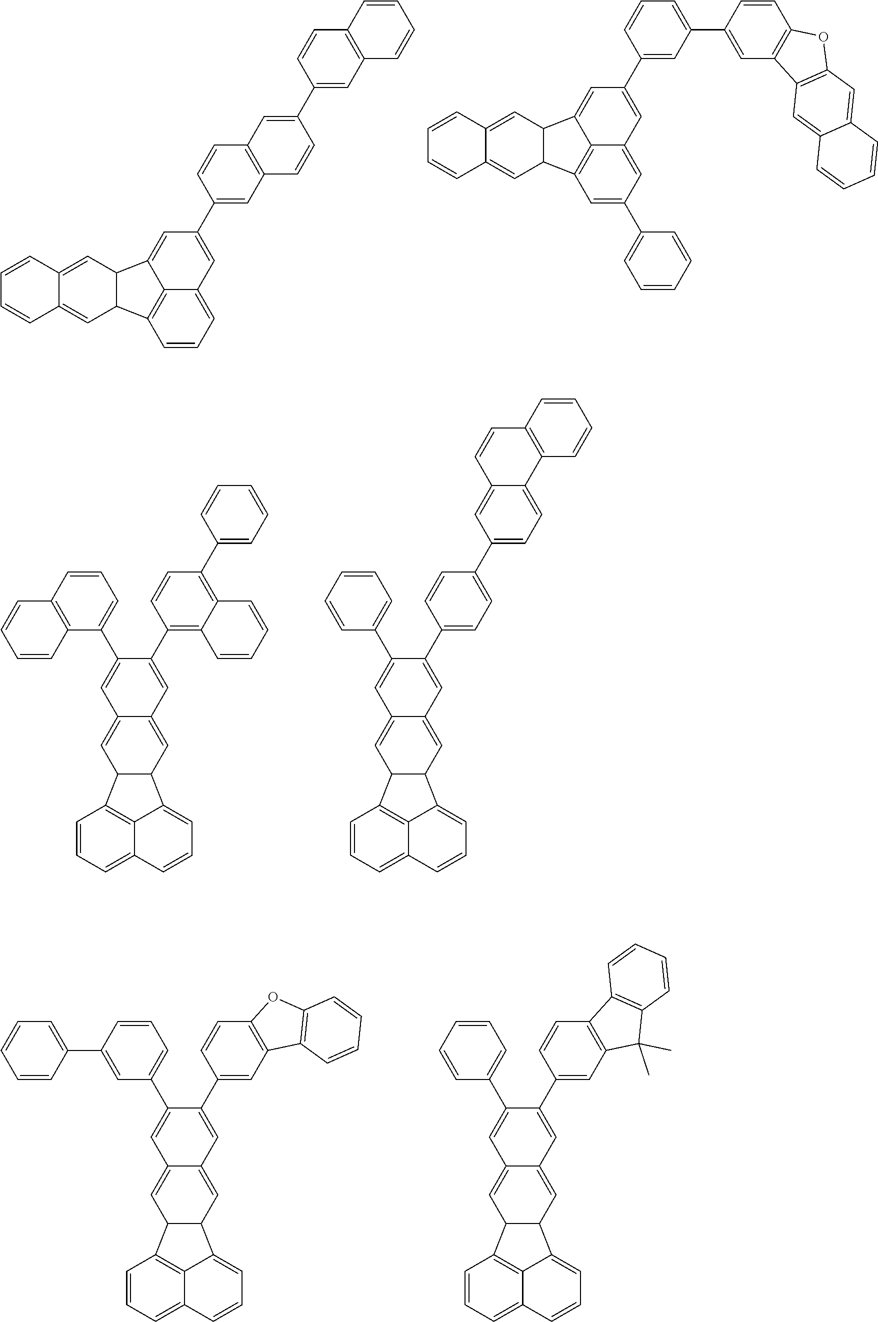

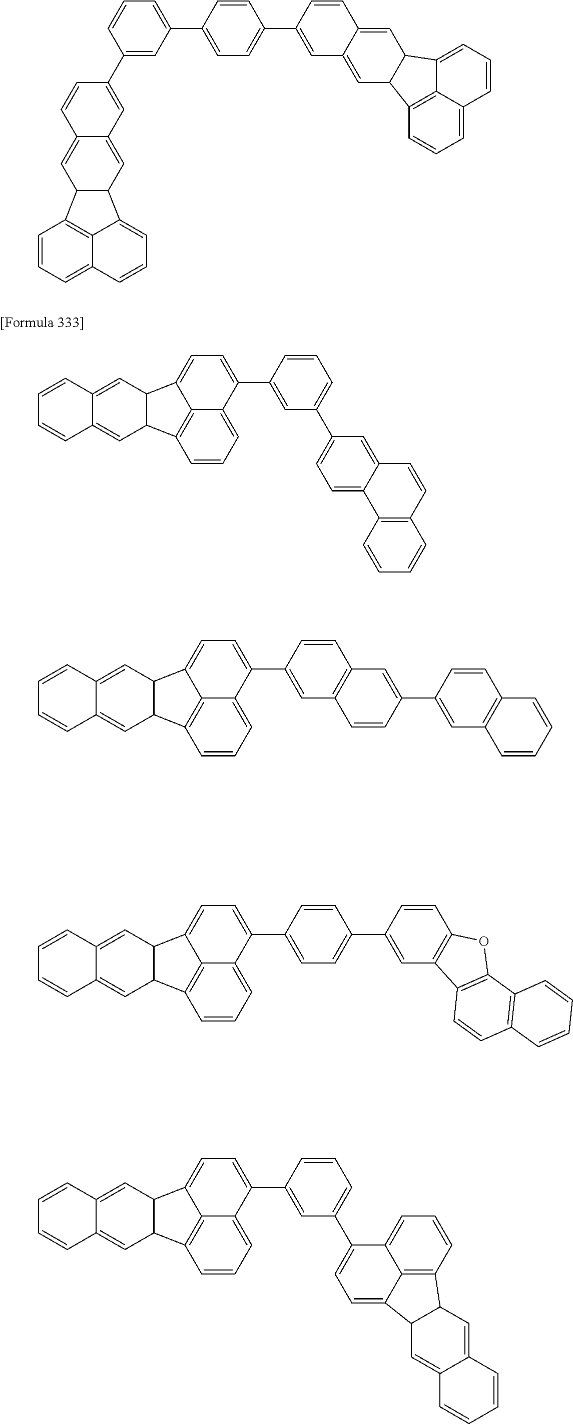

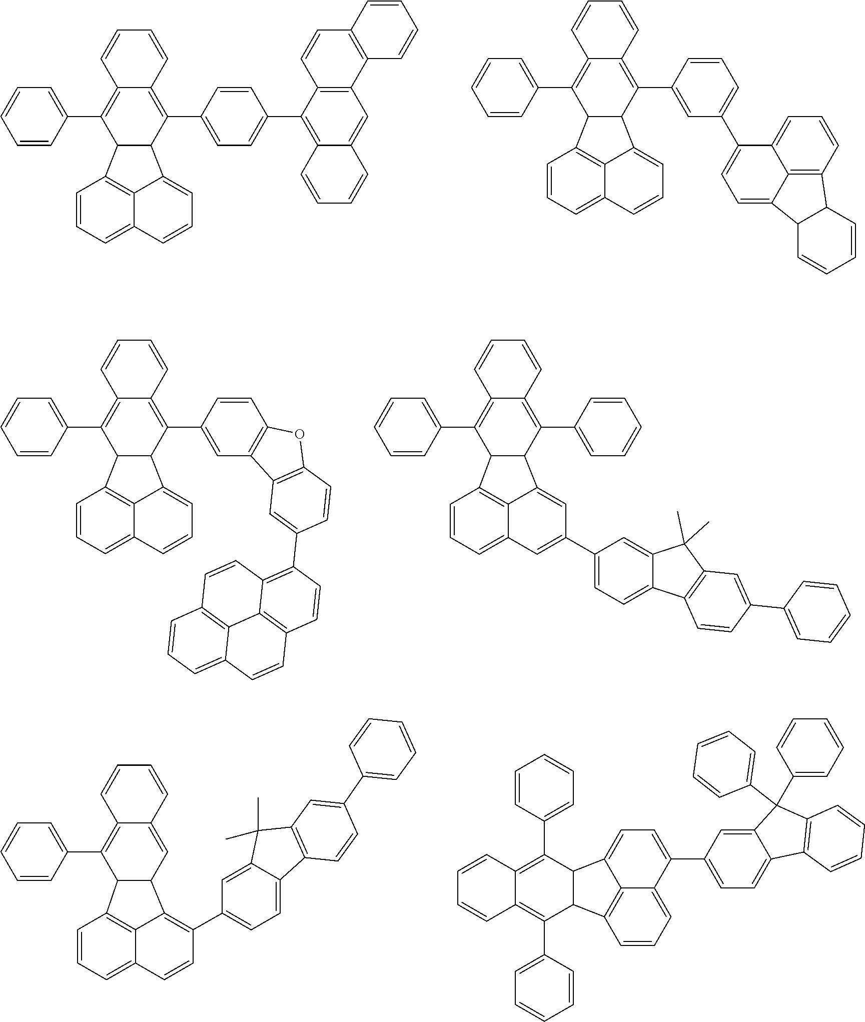

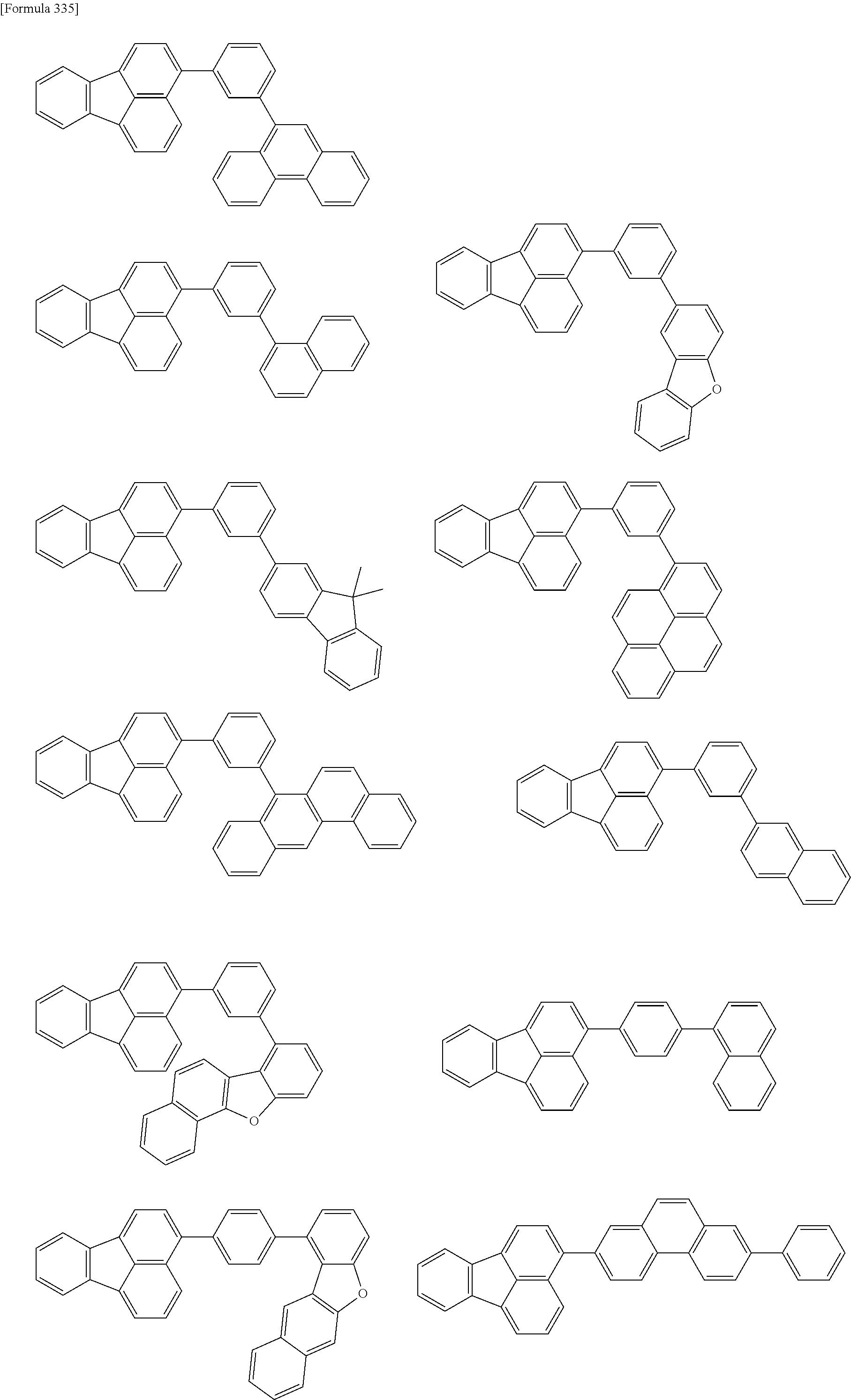

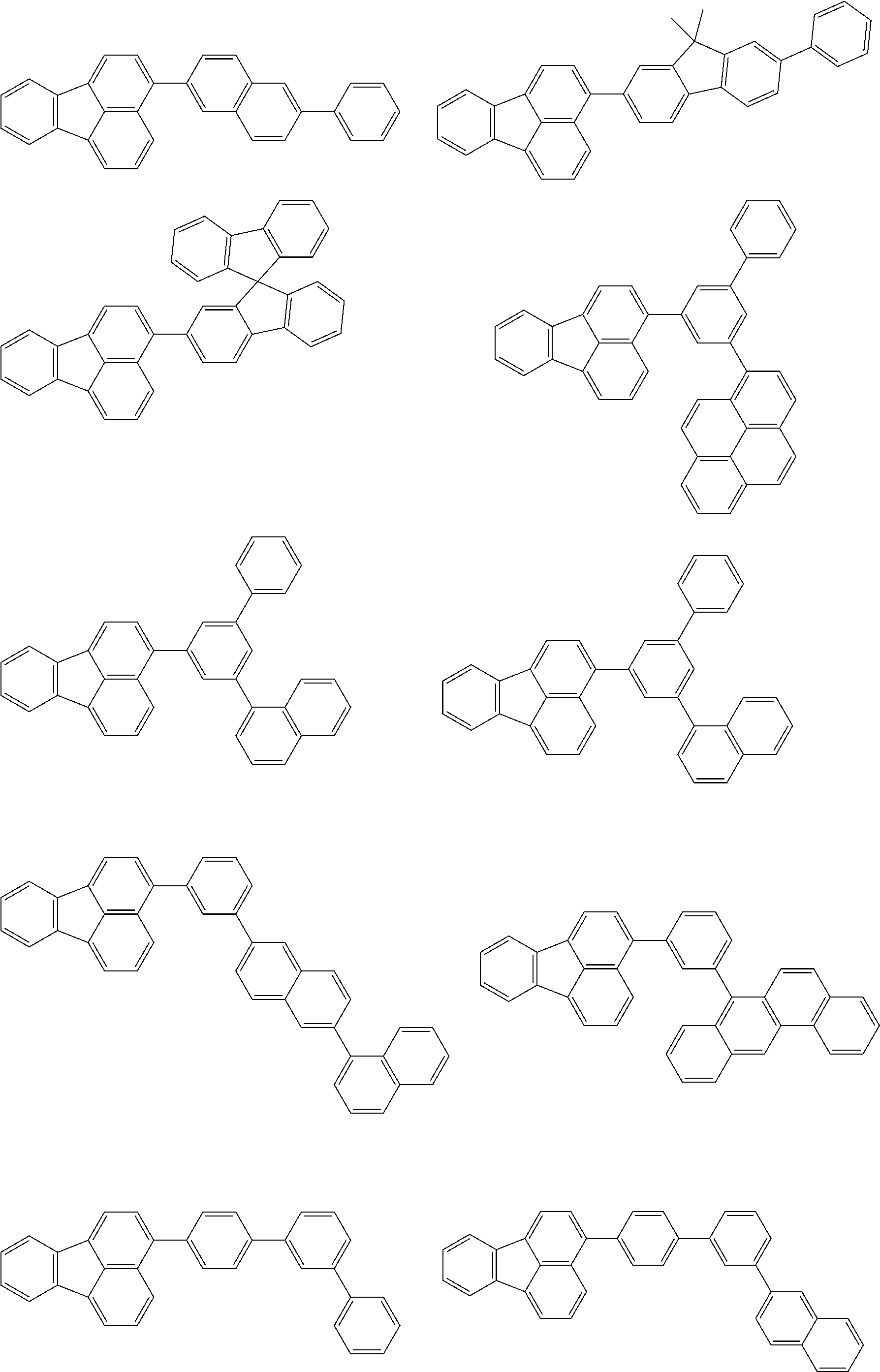

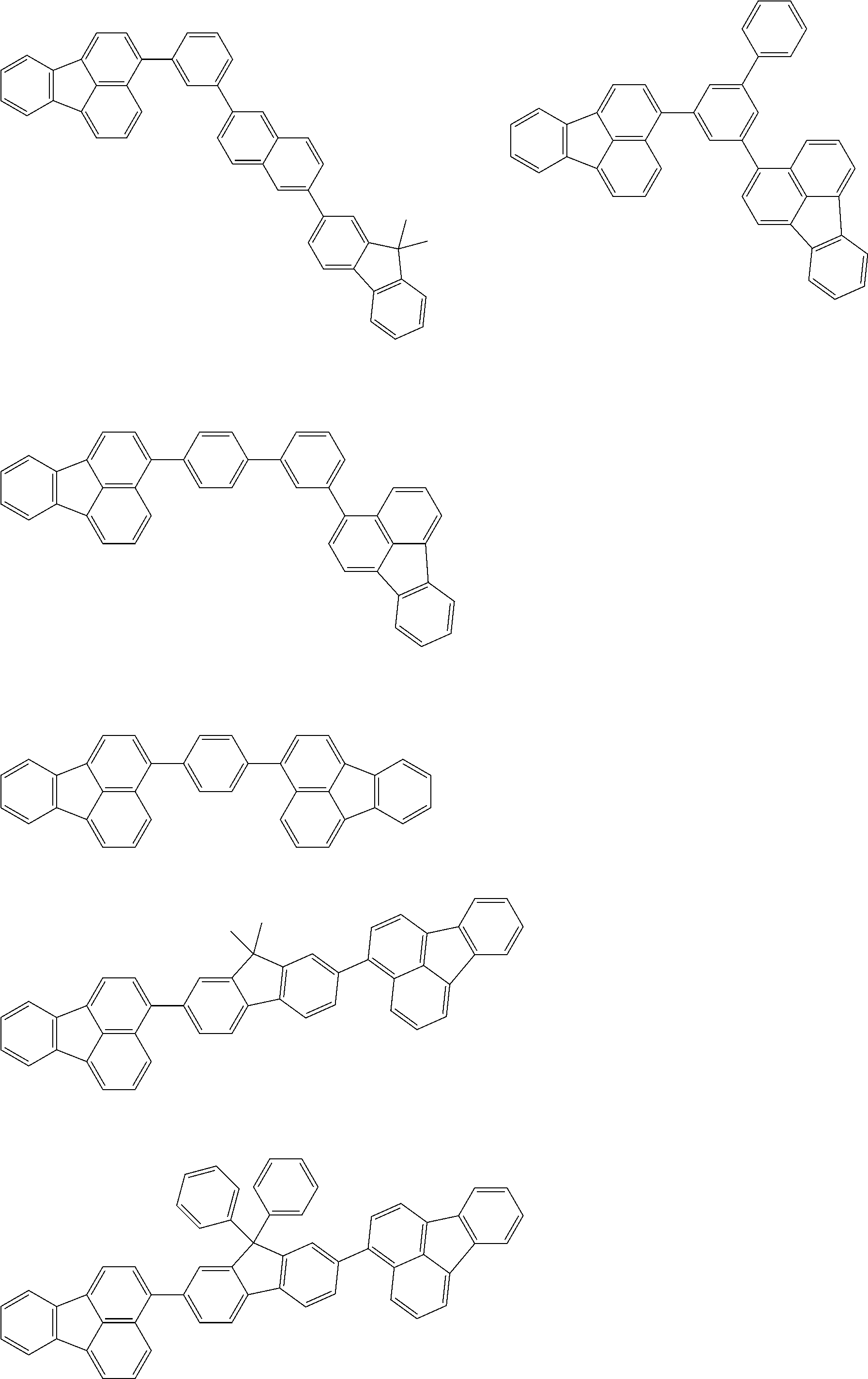

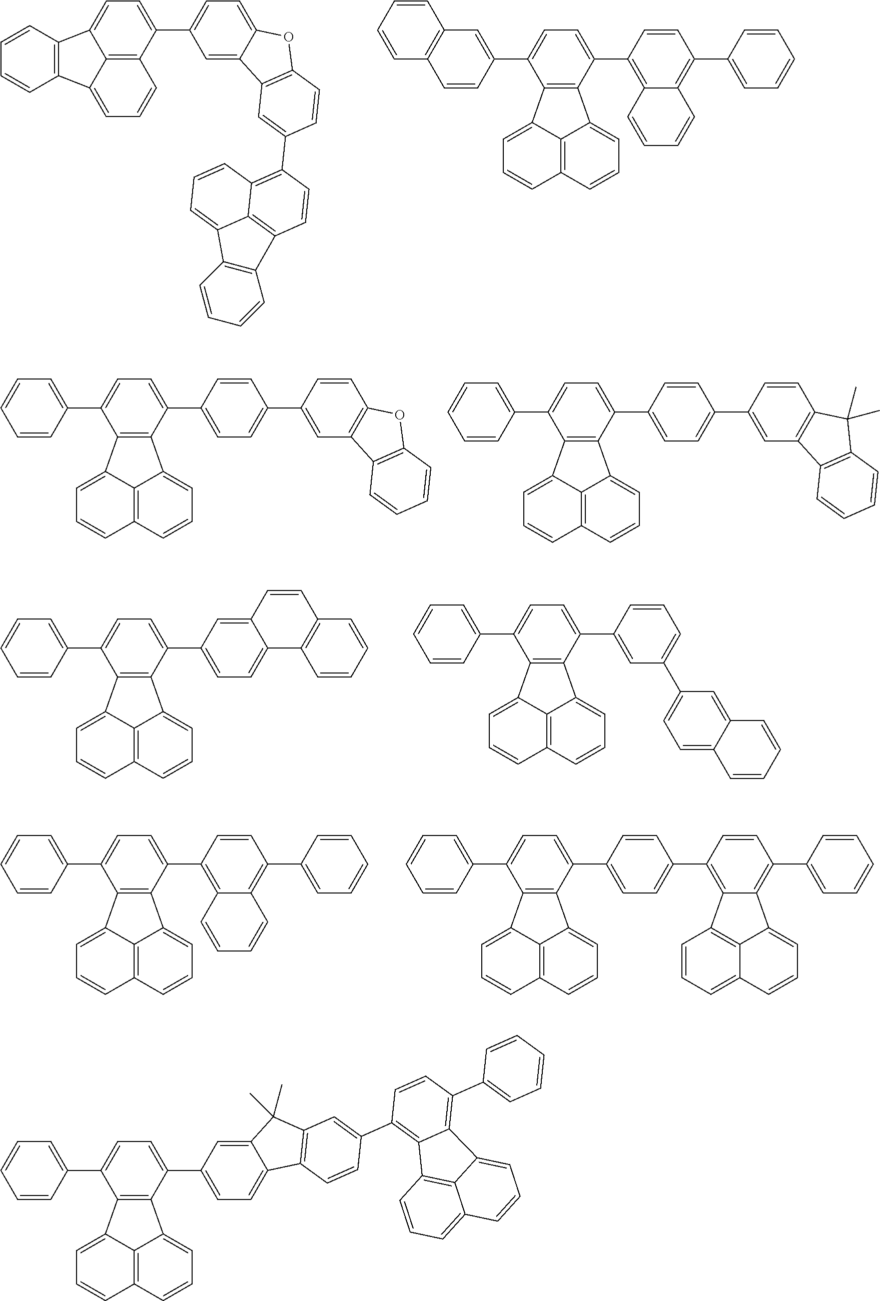

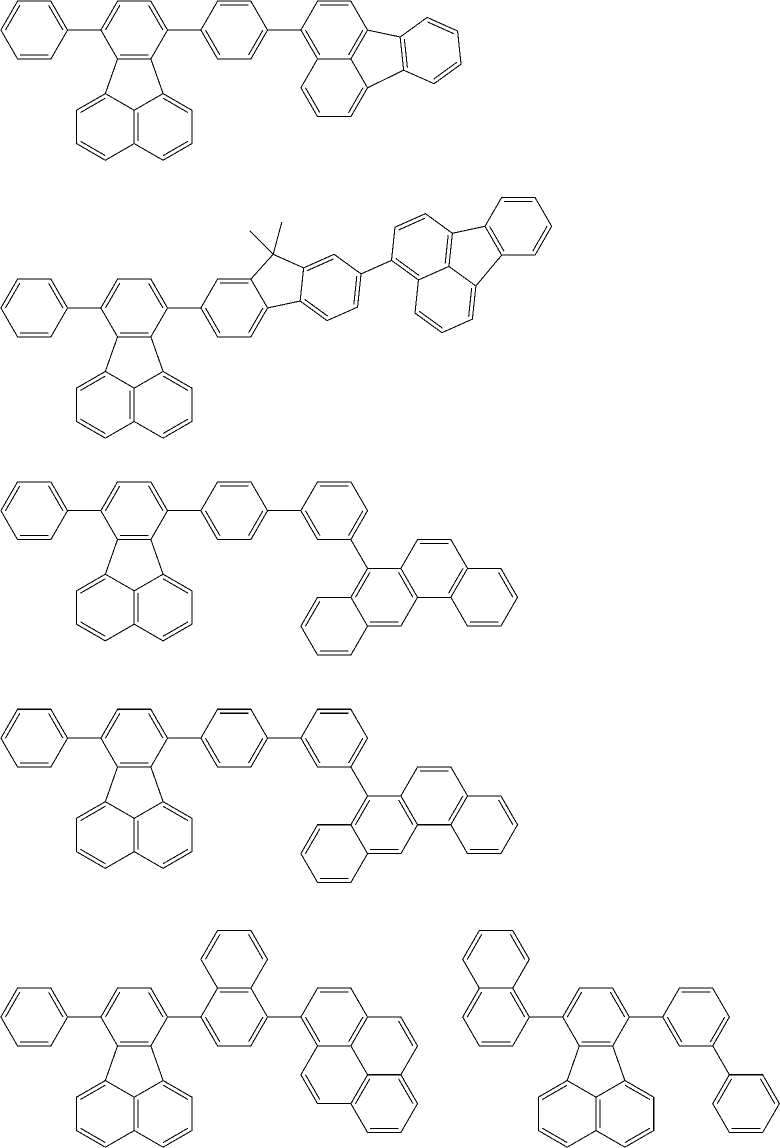

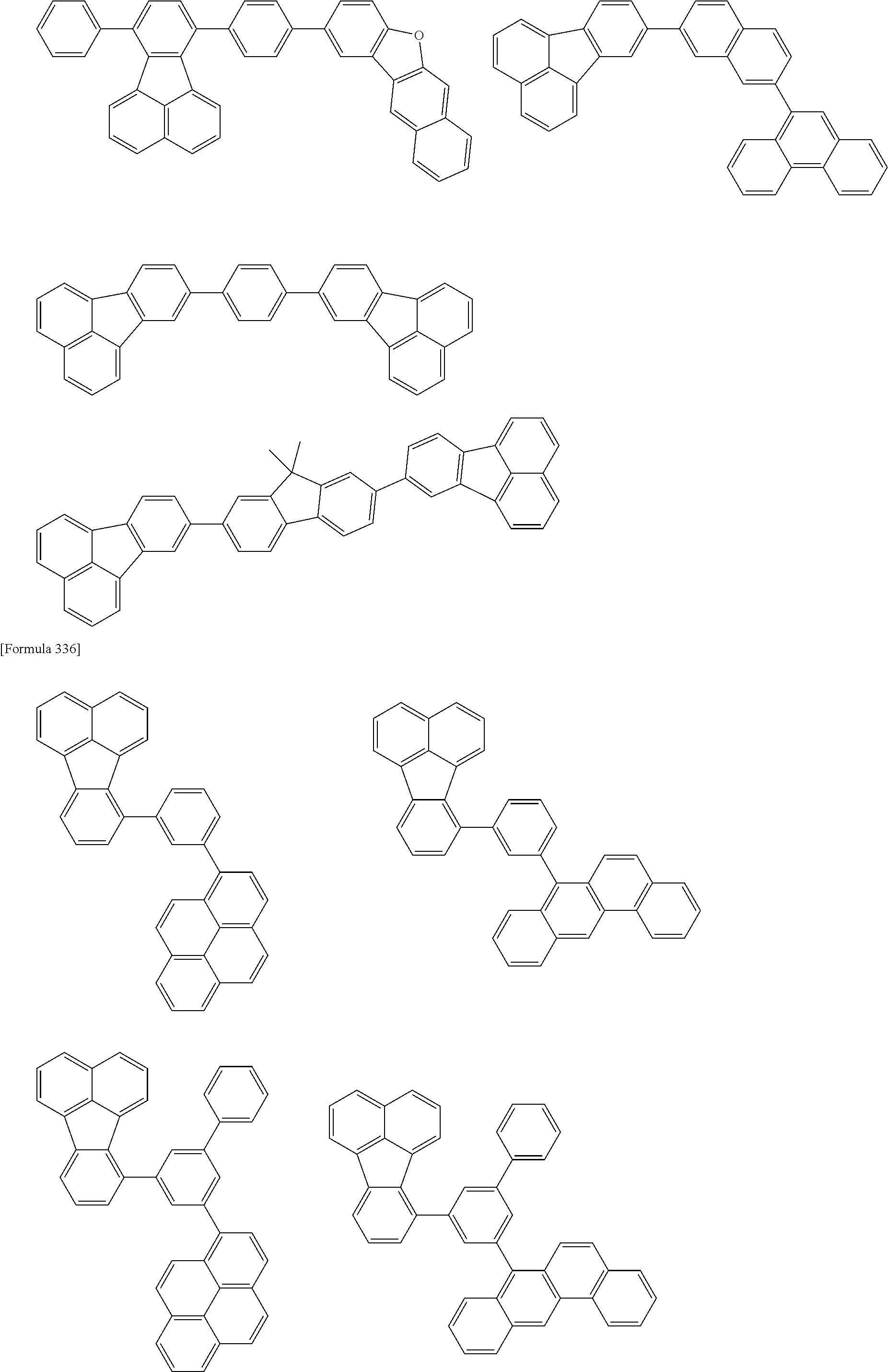

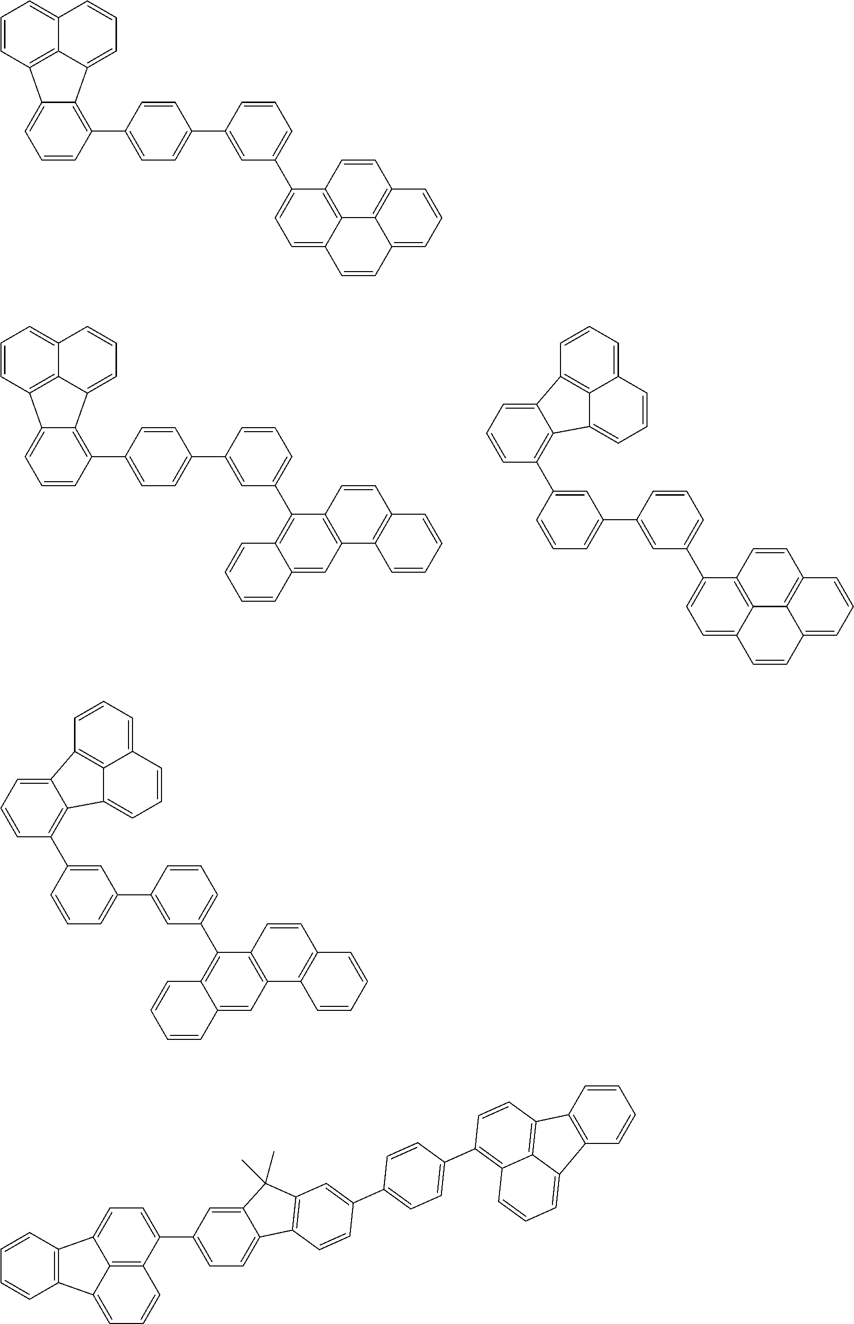

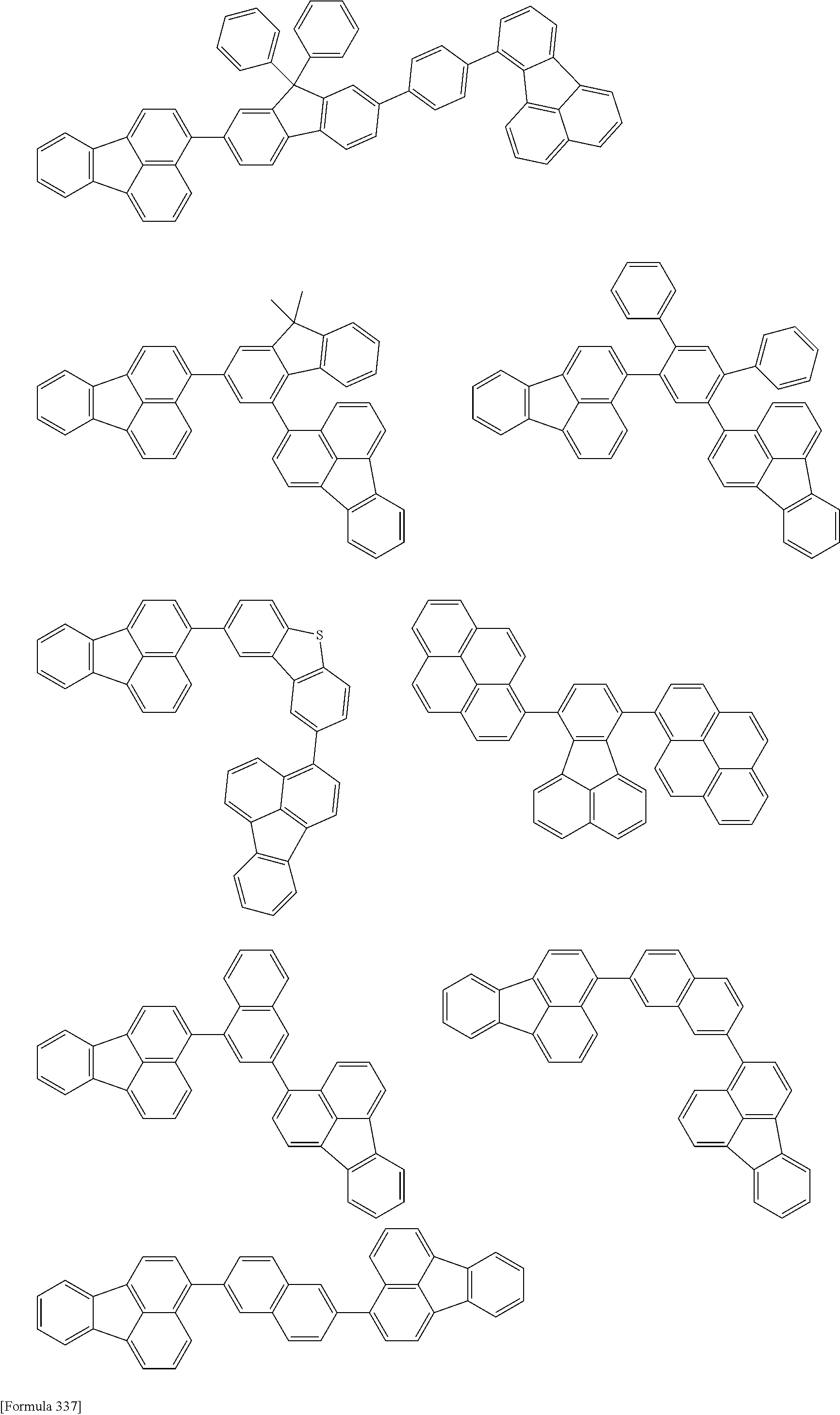

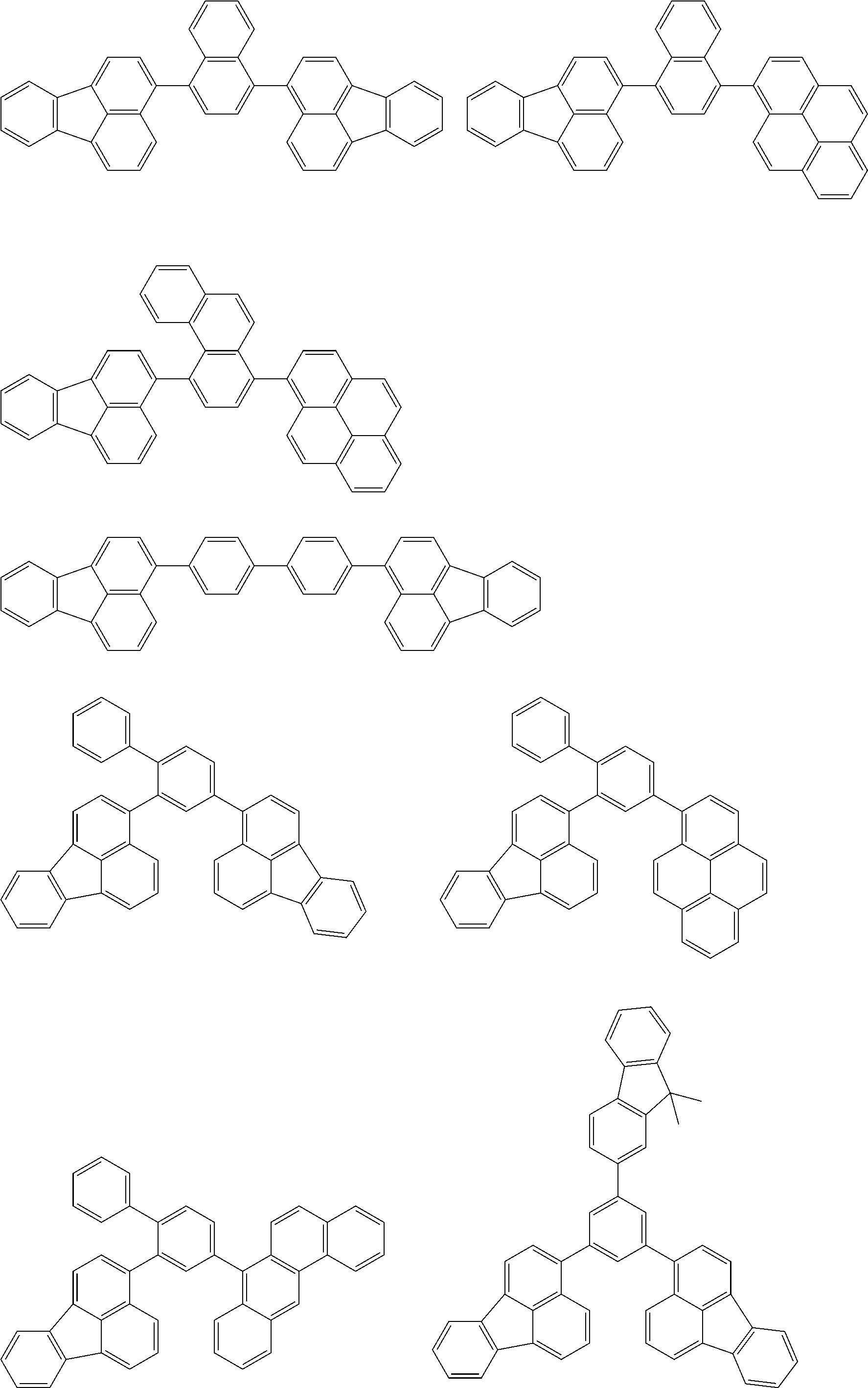

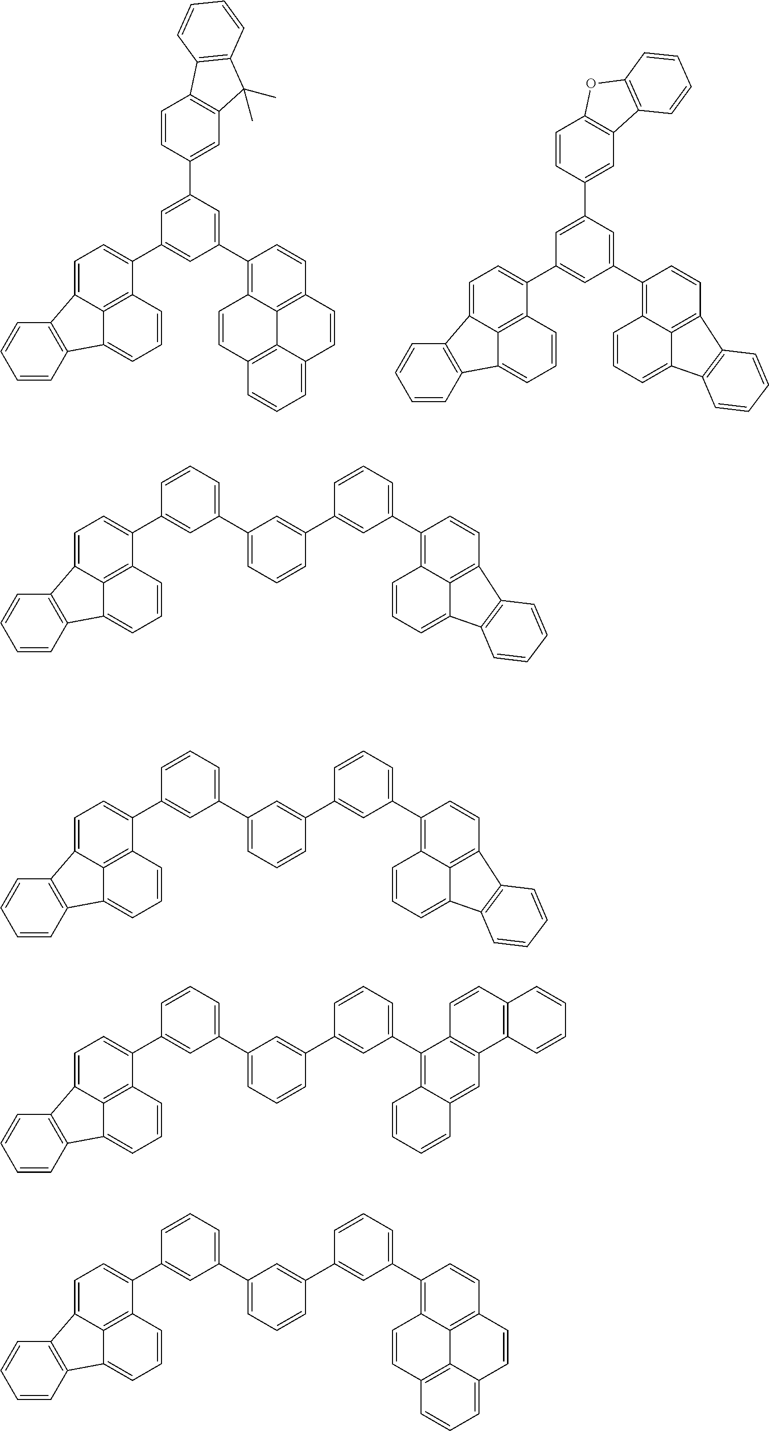

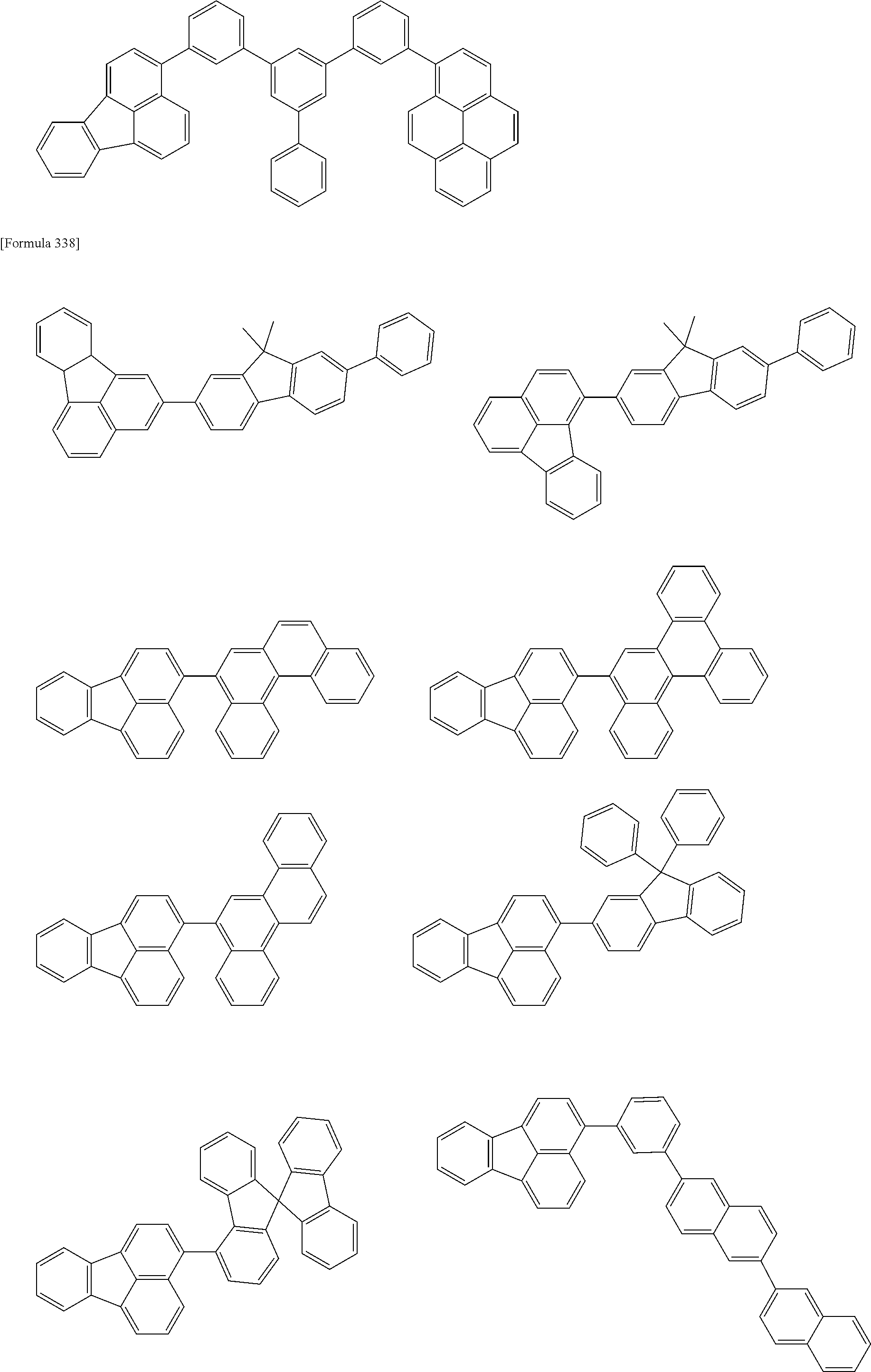

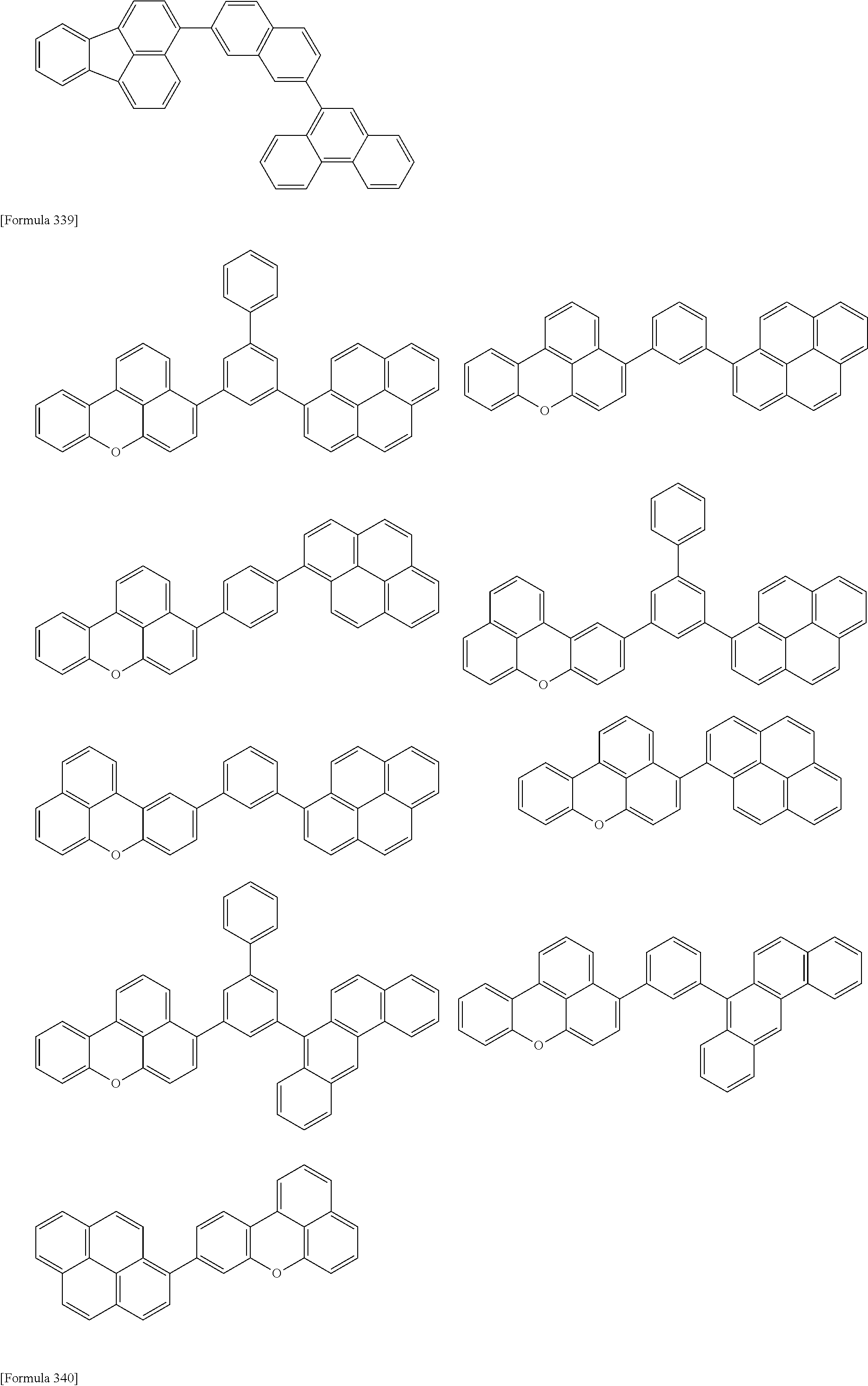

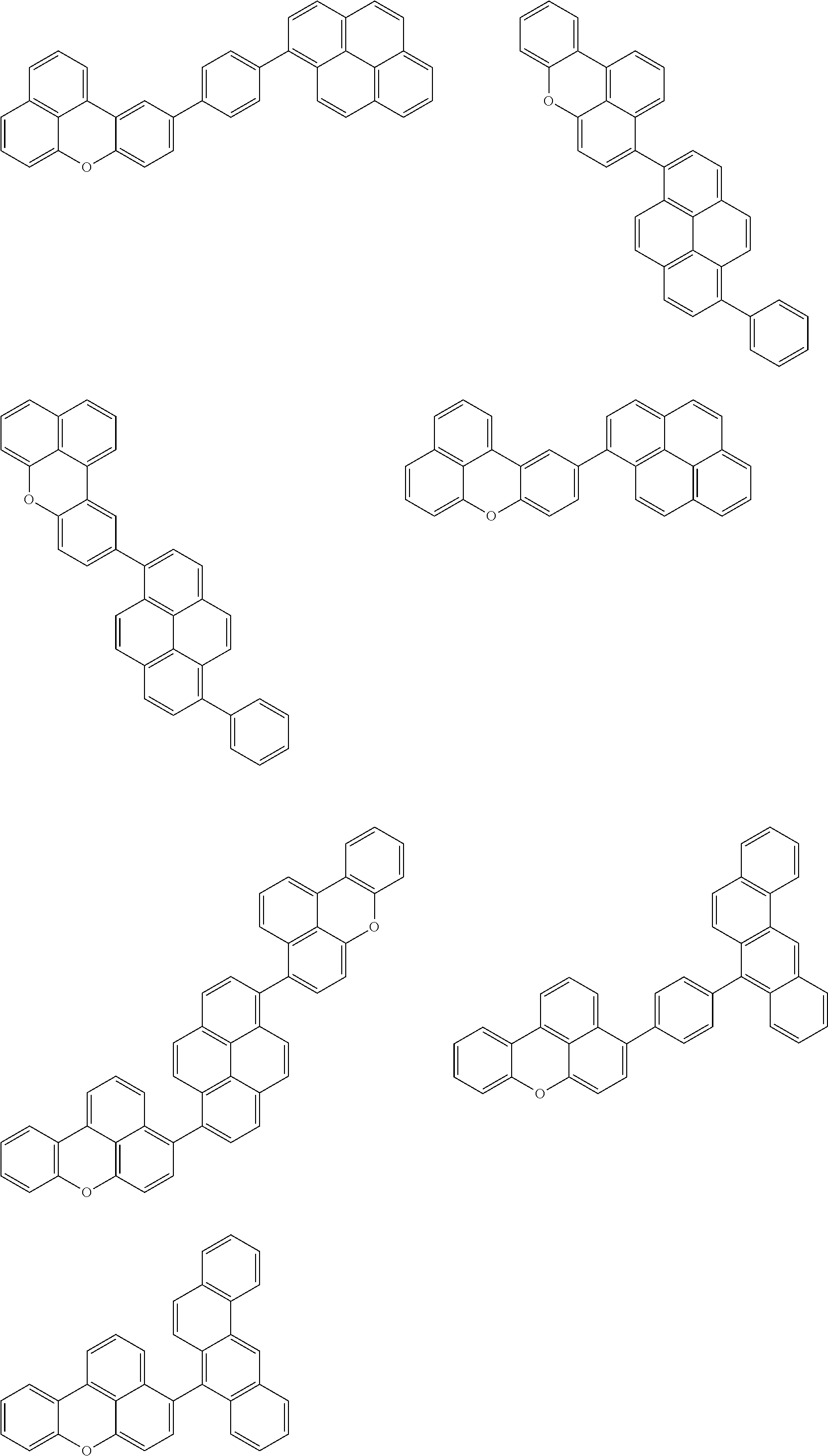

The third compound and the fourth compound are each independently at least one compound selected from the group consisting of a compound represented by a formula (3) below, a compound represented by a formula (4) below, a compound represented by a formula (5) below, a compound represented by a formula (7) below, a compound represented by a formula (8) below, a compound represented by a formula (9) below, and a compound represented by a formula (10) below.

### Compound Represented by Formula (3)

The compound represented by the formula (3) will be described below.

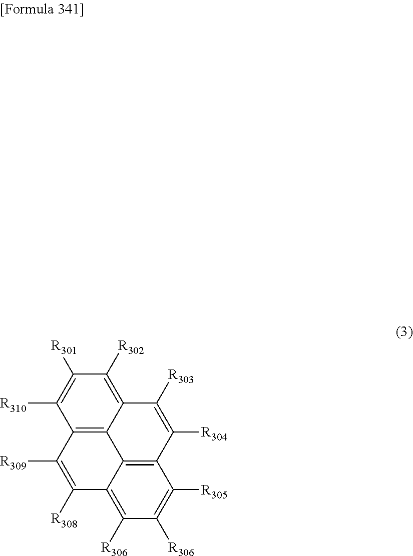

In the formula (3):
at least one combination of adjacent two or more of R₃₀₁ to R₃₁₀ are mutually bonded to form a substituted or unsubstituted monocyclic ring, mutually bonded to form a substituted or unsubstituted fused ring, or not mutually bonded;
at least one of R₃₀₁ to R₃₁₀ is a monovalent group represented by a formula (31) below; and
R₃₀₁ to R₃₁₀ forming neither the monocyclic ring nor the fused ring and not being the monovalent group represented by the formula (31) are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

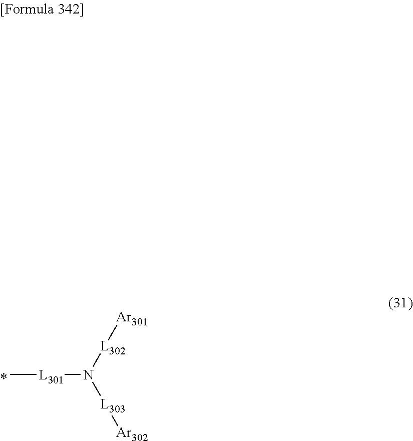

In the formula (31):
Ar₃₀₁ and Ar₃₀₂ are each independently a substituted or unsubstituted aryl group having 6 to 50 ring carbon atoms, or a substituted or unsubstituted heterocyclic group having 5 to 50 ring atoms;
L₃₀₁ to L₃₀₃ are each independently a single bond, a substituted or unsubstituted arylene group having 6 to 30 ring carbon atoms, or a substituted or unsubstituted divalent heterocyclic group having 5 to 30 ring atoms; and
represents a bonding position to a pyrene ring in the formula (3).

In the third and fourth compounds, R₉₀₁, R₉₀₂, R₉₀₃, R₉₀₄, R₉₀₅, R₉₀₆, and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms, a substituted or unsubstituted alkyl group having 1 to 50 carbon atoms, or a substituted or unsubstituted aryl group having 6 to 50 ring carbon atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In the formula (3), two of R₃₀₁ to R₃₁₀ are each preferably a group represented by the formula (31).

In an exemplary embodiment, the compound represented by the formula (3) is a compound represented by a formula (33) below.

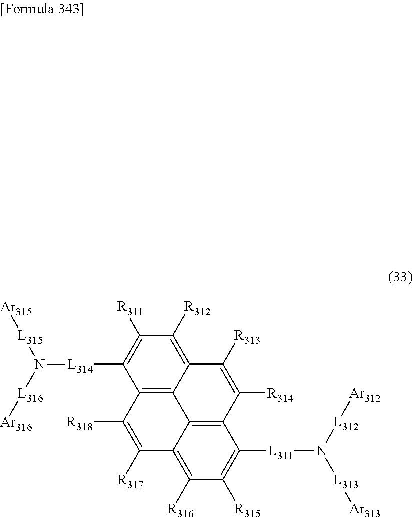

In the formula (33):
R₃₁₁ to R₃₁₈ each independently represent the same as R₃₀₁ to R₃₁₀ in the formula (3) that are not a monovalent group represented by the formula (31);
L₃₁₁ to L₃₁₆ are each independently a single bond, a substituted or unsubstituted arylene group having 6 to 30 ring carbon atoms, or a substituted or unsubstituted divalent heterocyclic group having 5 to 30 ring atoms; and
Ar₃₁₂, Ar₃₁₃, Ar₃₁₅, and Ar₃₁₆ are each independently a substituted or unsubstituted aryl group having 6 to 50 ring carbon atoms, or a substituted or unsubstituted heterocyclic group having 5 to 50 ring atoms.

In the formula (31), L₃₀₁ is preferably a single bond, and L₃₀₂ and L₃₀₃ are each preferably a single bond.

In an exemplary embodiment, the compound represented by the formula (3) is represented by a formula (34) or a formula (35) below.

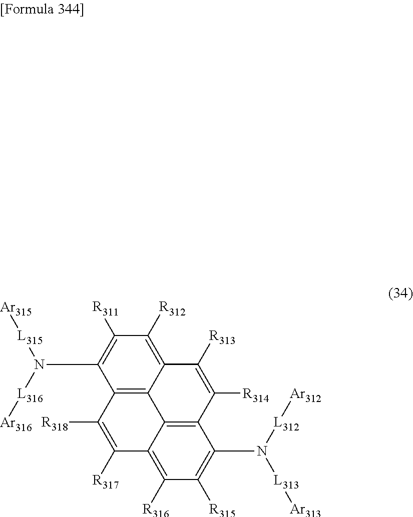

In the formula (34):
R₃₁₁ to R₃₁₈ each independently represent the same as R₃₀₁ to R₃₁₀ in the formula (3) that are not a monovalent group represented by the formula (31);
L₃₁₂, L₃₁₃, L₃₁₅ and L₃₁₆ each independently represent the same as L₃₁₂, L₃₁₃, L₃₁₅ and L₃₁₆ in the formula (33); and
Ar₃₁₂, Ar₃₁₃, Ar₃₁₅ and Ar₃₁₆ each independently represent the same as Ar₃₁₂, Ar₃₁₃, Ar₃₁₅ and Ar₃₁₆ in the formula (33).

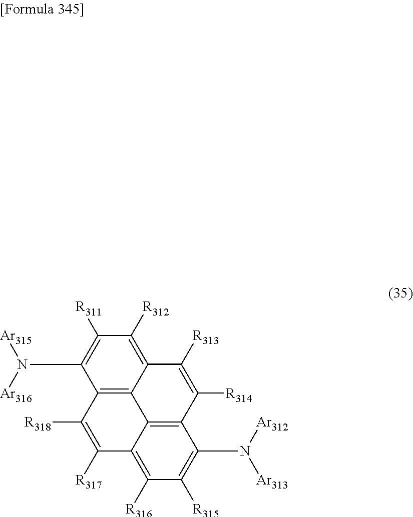

In the formula (35):
R₃₁₁ to R₃₁₈ each independently represent the same as R₃₀₁ to R₃₁₀ in the formula (3) that are not a monovalent group represented by the formula (31); and
Ar₃₁₂, Ar₃₁₃, Ar₃₁₅ and Ar₃₁₆ each independently represent the same as Ar₃₁₂, Ar₃₁₃, Ar₃₁₅ and Ar₃₁₆ in the formula (33).

In the formula (31), at least one of Ar₃₀₁ or Ar₃₀₂ is preferably a group represented by a formula (36) below.

In the formulae (33) to (35), at least one of Ar₃₁₂ or Ar₃₁₃ is preferably a group represented by the formula (36).

In the formulae (33) to (35), at least one of Ar₃₁₅ or Ar₃₁₆ is preferably a group represented by the formula (36).

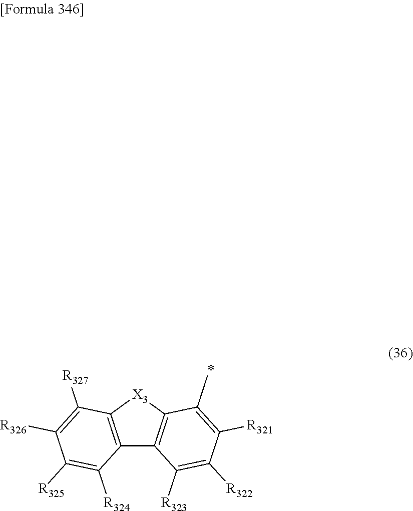

In the formula (36):
X₃ represents an oxygen atom or a sulfur atom;
at least one combination of adjacent two or more of R₃₂₁ to R₃₂₇ are mutually bonded to form a substituted or unsubstituted monocyclic ring, mutually bonded to form a substituted or unsubstituted fused ring, or not mutually bonded;
R₃₂₁ to R₃₂₇ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms; and
represents a bonding position to L₃₀₂, L₃₀₃, L₃₁₂, L₃₁₃, L₃₁₅ or L₃₁₆.
X₃ is preferably an oxygen atom.

At least one of R₃₂₁ to R₃₂₇ is preferably a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the formula (31), preferably, Ar₃₀₁ is a group represented by the formula (36) and Ar₃₀₂ is a substituted or unsubstituted aryl group having 6 to 50 ring carbon atoms.

In the formulae (33) to (35), preferably, Ar₃₁₂ is a group represented by the formula (36) and Ar₃₁₃ is a substituted or unsubstituted aryl group having 6 to 50 ring carbon atoms.

In the formulae (33) to (35), preferably, Ar₃₁₅ is a group represented by the formula (36) and Ar₃₁₆ is a substituted or unsubstituted aryl group having 6 to 50 ring carbon atoms.

In an exemplary embodiment, the compound represented by the formula (3) is represented by a formula (37) below.

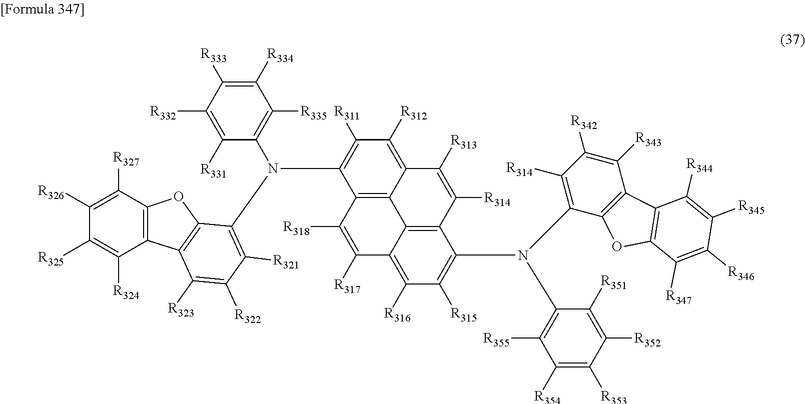

In the formula (37):
R₃₁₁ to R₃₁₈ each independently represent the same as R₃₀₁ to R₃₁₀ in the formula (3) that are not a monovalent group represented by the formula (31);
at least one combination of adjacent two or more of R₃₂₁ to R₃₂₇ are mutually bonded to form a substituted or unsubstituted monocyclic ring, mutually bonded to form a substituted or unsubstituted fused ring, or not mutually bonded;
at least one combination of adjacent two or more of R₃₄₁ to R₃₄₇ are mutually bonded to form a substituted or unsubstituted monocyclic ring, mutually bonded to form a substituted or unsubstituted fused ring, or not mutually bonded;
R₃₂₁ to R₃₂₇ and R₃₄₁ to R₃₄₇ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms; and
R₃₃₁ to R₃₃₅ and R₃₅₁ to R₃₃₅ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

### Specific Examples of Compound Represented by Formula (3)

Specific examples of the compound represented by the formula (3) include compounds shown below.

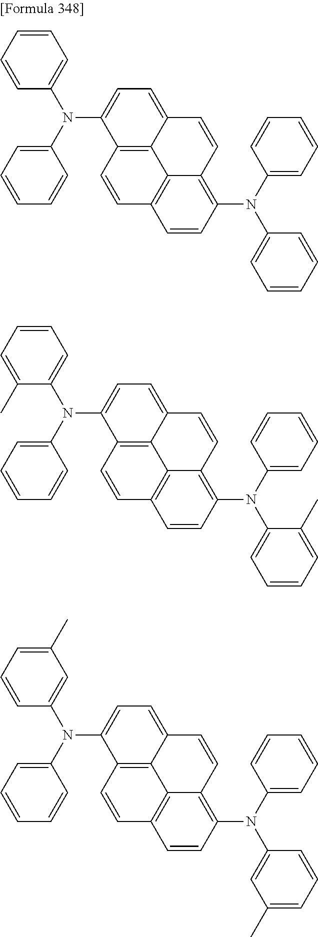 [SMILES: c1ccc(N(c2ccccc2)c2ccc3ccc4c(N(c5ccccc5)c5ccccc5)ccc5ccc2c3c54)cc1 ; Cc1ccccc1N(c1ccccc1)c1ccc2ccc3c(N(c4ccccc4)c4ccccc4C)ccc4ccc1c2c43 ; Cc1cccc(N(c2ccccc2)c2ccc3ccc4c(N(c5ccccc5)c5cccc(C)c5)ccc5ccc2c3c54)c1]

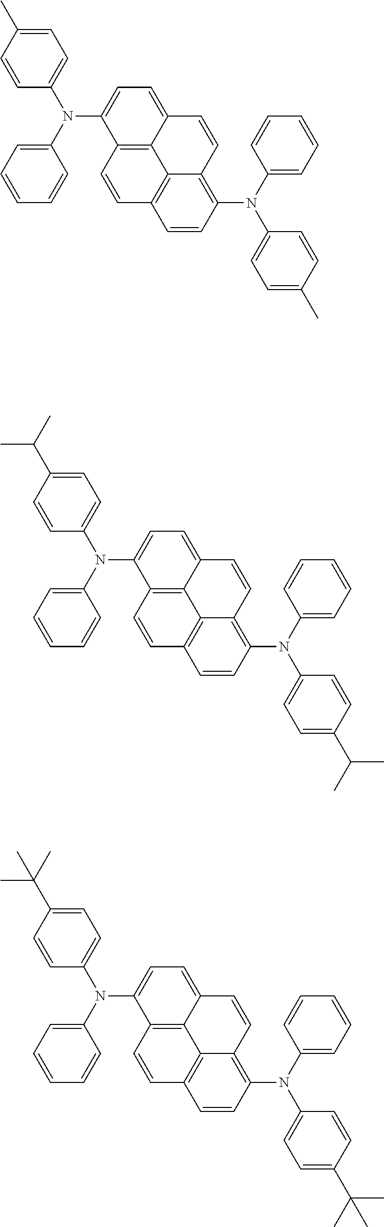

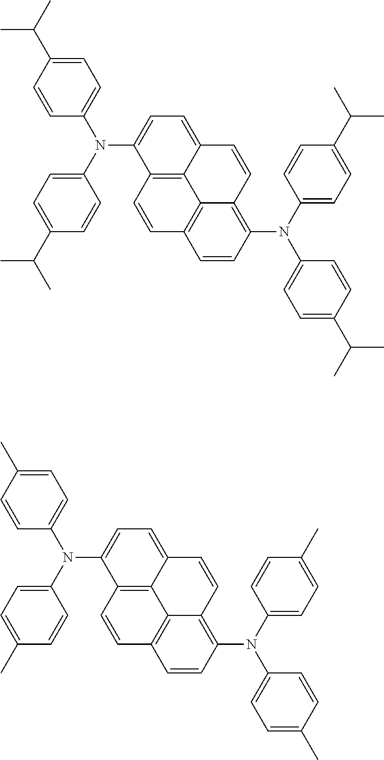 [SMILES: CC(C)c1ccc(N(c2ccc(C(C)C)cc2)c2ccc3ccc4c(N(c5ccc(C(C)C)cc5)c5ccc(C(C)C)cc5)ccc5ccc2c3c54)cc1 ; Cc1ccc(N(c2ccc(C)cc2)c2ccc3ccc4c(N(c5ccc(C)cc5)c5ccc(C)cc5)ccc5ccc2c3c54)cc1]

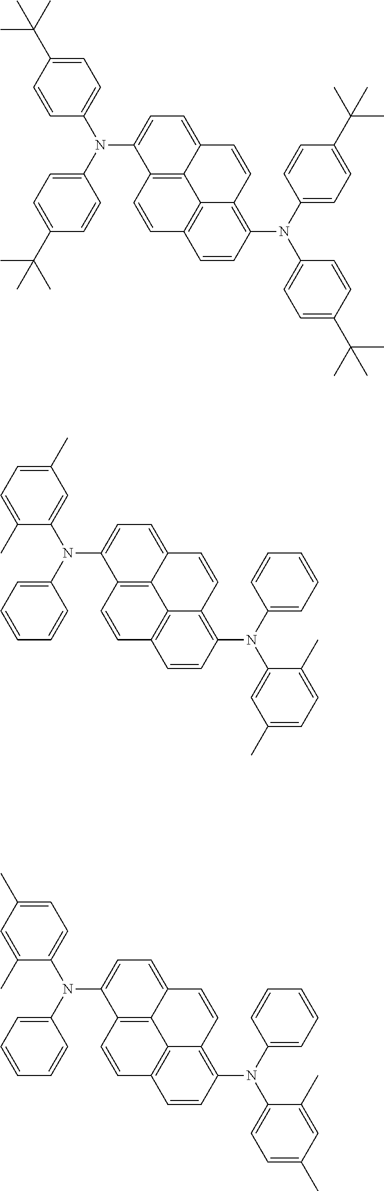 [SMILES: CC(C)(C)c1ccc(N(c2ccc(C(C)(C)C)cc2)c2ccc3ccc4c(N(c5ccc(C(C)(C)C)cc5)c5ccc(C(C)(C)C)cc5)ccc5ccc2c3c54)cc1 ; Cc1ccc(C)c(N(c2ccccc2)c2ccc3ccc4c(N(c5ccccc5)c5cc(C)ccc5C)ccc5ccc2c3c54)c1 ; Cc1ccc(N(c2ccccc2)c2ccc3ccc4c(N(c5ccccc5)c5ccc(C)cc5C)ccc5ccc2c3c54)c(C)c1]

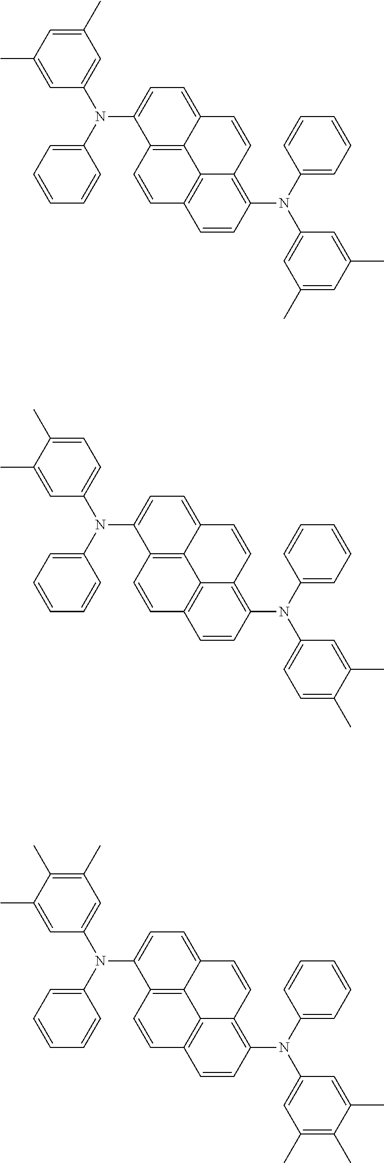

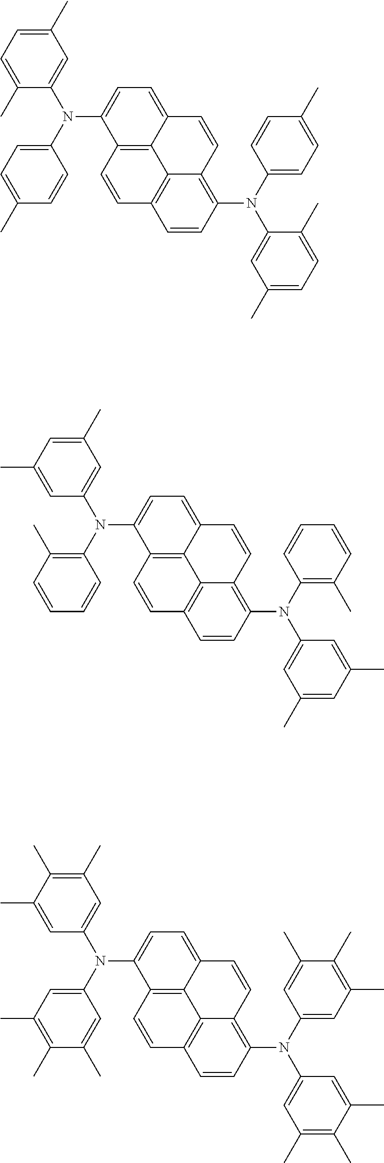

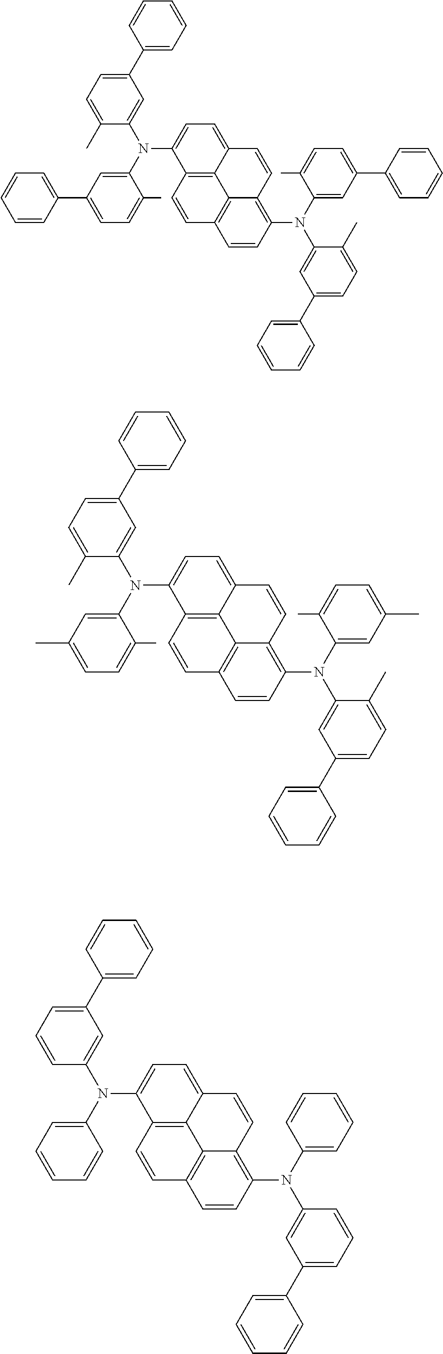

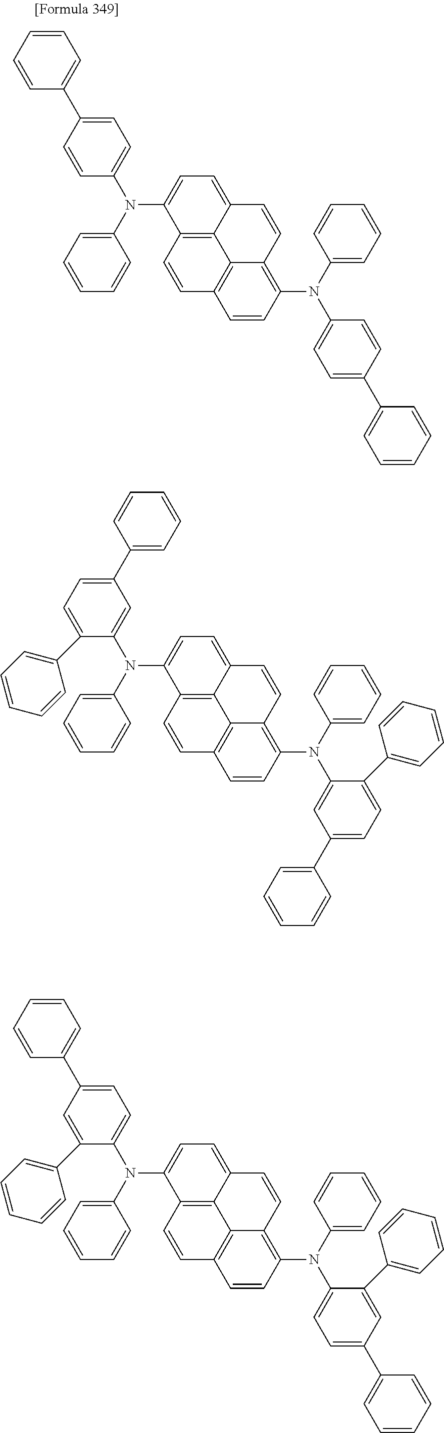 [SMILES: c1ccc(-c2ccc(N(c3ccccc3)c3ccc4ccc5c(N(c6ccccc6)c6ccc(-c7ccccc7)cc6)ccc6ccc3c4c65)cc2)cc1 ; c1ccc(-c2ccc(-c3ccccc3)c(N(c3ccccc3)c3ccc4ccc5c(N(c6ccccc6)c6cc(-c7ccccc7)ccc6-c6ccccc6)ccc6ccc3c4c65)c2)cc1 ; c1ccc(-c2ccc(N(c3ccccc3)c3ccc4ccc5c(N(c6ccccc6)c6ccc(-c7ccccc7)cc6-c6ccccc6)ccc6ccc3c4c65)c(-c3ccccc3)c2)cc1]

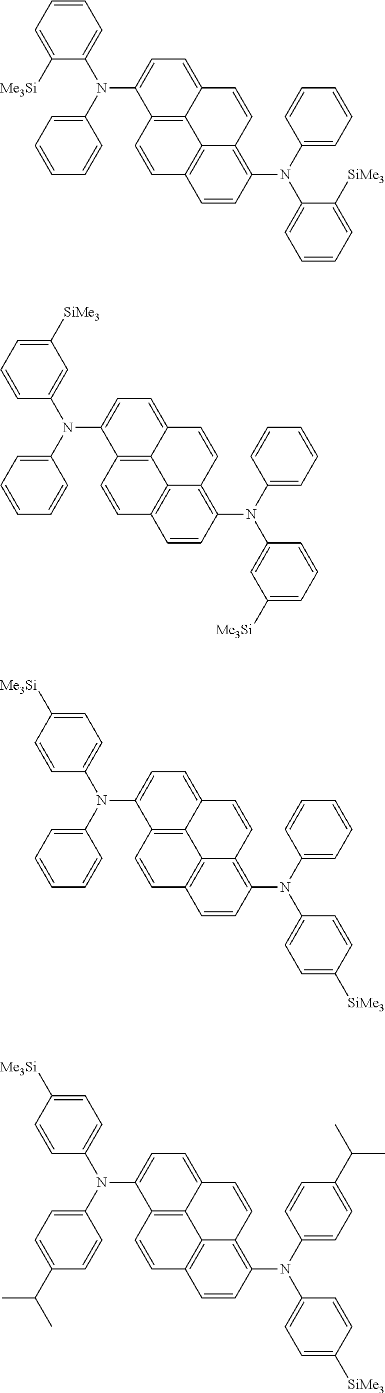 [SMILES: C[Si](C)(C)c1ccccc1N(c1ccccc1)c1ccc2ccc3c(N(c4ccccc4)c4ccccc4[Si](C)(C)C)ccc4ccc1c2c43 ; C[Si](C)(C)c1cccc(N(c2ccccc2)c2ccc3ccc4c(N(c5ccccc5)c5cccc([Si](C)(C)C)c5)ccc5ccc2c3c54)c1 ; C[Si](C)(C)c1ccc(N(c2ccccc2)c2ccc3ccc4c(N(c5ccccc5)c5ccc([Si](C)(C)C)cc5)ccc5ccc2c3c54)cc1 ; CC(C)c1ccc(N(c2ccc([Si](C)(C)C)cc2)c2ccc3ccc4c(N(c5ccc(C(C)C)cc5)c5ccc([Si](C)(C)C)cc5)ccc5ccc2c3c54)cc1]

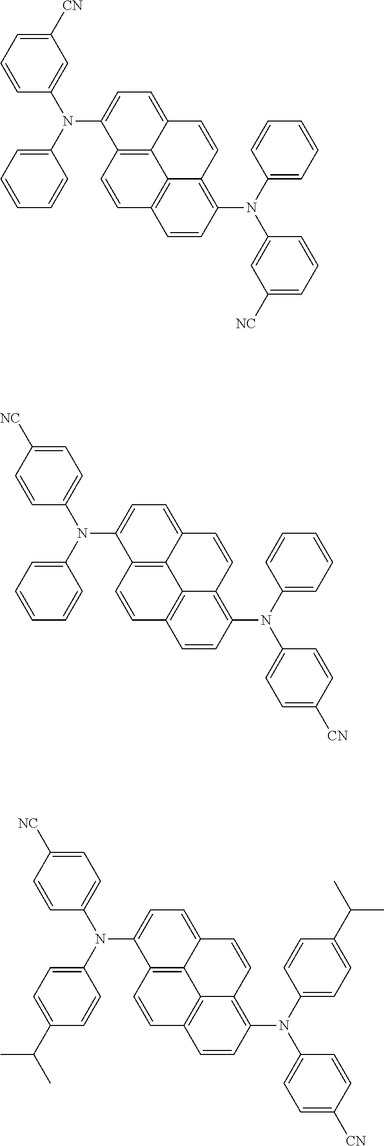 [SMILES: N#Cc1cccc(N(c2ccccc2)c2ccc3ccc4c(N(c5ccccc5)c5cccc(C#N)c5)ccc5ccc2c3c54)c1 ; N#Cc1ccc(N(c2ccccc2)c2ccc3ccc4c(N(c5ccccc5)c5ccc(C#N)cc5)ccc5ccc2c3c54)cc1 ; CC(C)c1ccc(N(c2ccc(C#N)cc2)c2ccc3ccc4c(N(c5ccc(C#N)cc5)c5ccc(C(C)C)cc5)ccc5ccc2c3c54)cc1]

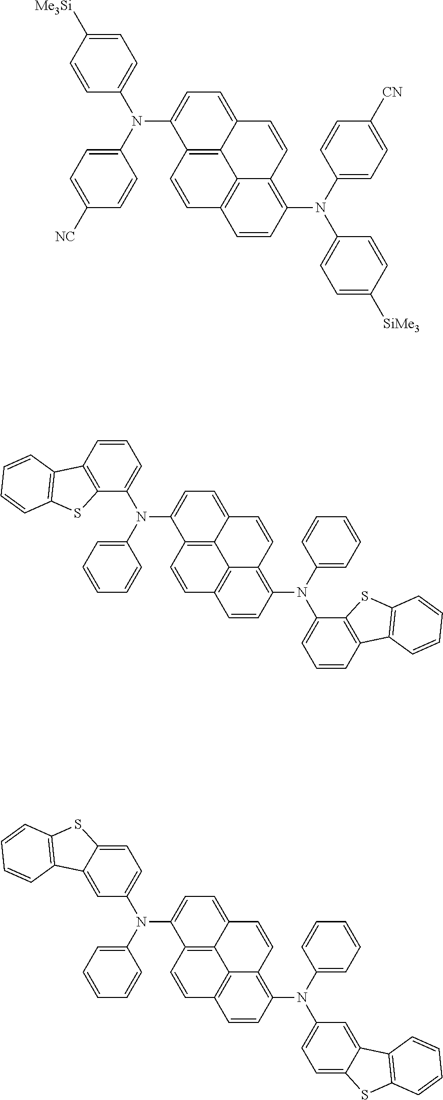 [SMILES: C[Si](C)(C)c1ccc(N(c2ccc(C#N)cc2)c2ccc3ccc4c(N(c5ccc(C#N)cc5)c5ccc([Si](C)(C)C)cc5)ccc5ccc2c3c54)cc1 ; c1ccc(N(c2ccc3ccc4c(N(c5ccccc5)c5cccc6c5sc5ccccc56)ccc5ccc2c3c54)c2cccc3c2sc2ccccc23)cc1 ; c1ccc(N(c2ccc3sc4ccccc4c3c2)c2ccc3ccc4c(N(c5ccccc5)c5ccc6sc7ccccc7c6c5)ccc5ccc2c3c54)cc1]

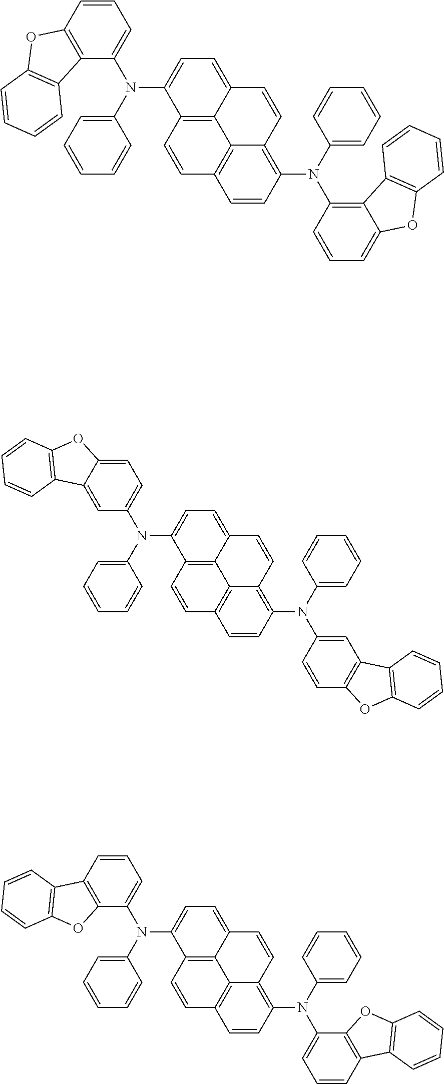 [SMILES: c1ccc(N(c2ccc3ccc4c(N(c5ccccc5)c5cccc6oc7ccccc7c56)ccc5ccc2c3c54)c2cccc3oc4ccccc4c23)cc1 ; c1ccc(N(c2ccc3oc4ccccc4c3c2)c2ccc3ccc4c(N(c5ccccc5)c5ccc6oc7ccccc7c6c5)ccc5ccc2c3c54)cc1 ; c1ccc(N(c2ccc3ccc4c(N(c5ccccc5)c5cccc6c5oc5ccccc56)ccc5ccc2c3c54)c2cccc3c2oc2ccccc23)cc1]

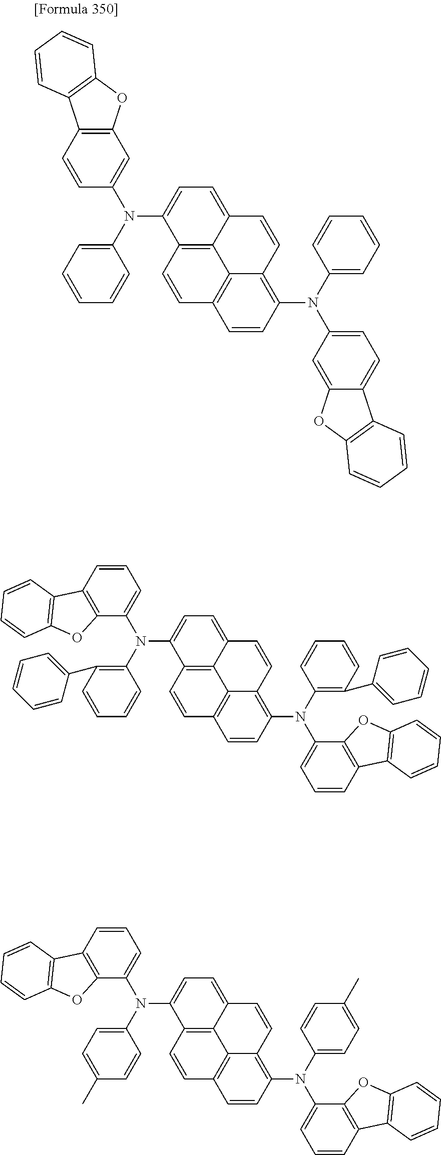 [SMILES: c1ccc(N(c2ccc3c(c2)oc2ccccc23)c2ccc3ccc4c(N(c5ccccc5)c5ccc6c(c5)oc5ccccc56)ccc5ccc2c3c54)cc1 ; c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1 ; Cc1ccc(N(c2ccc3ccc4c(N(c5ccc(C)cc5)c5cccc6c5oc5ccccc56)ccc5ccc2c3c54)c2cccc3c2oc2ccccc23)cc1]

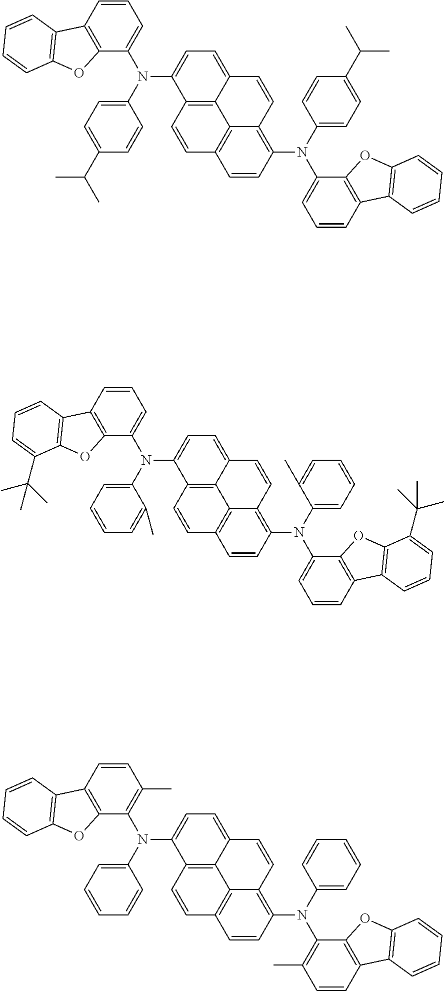 [SMILES: CC(C)c1ccc(N(c2ccc3ccc4c(N(c5ccc(C(C)C)cc5)c5cccc6c5oc5ccccc56)ccc5ccc2c3c54)c2cccc3c2oc2ccccc23)cc1 ; Cc1ccccc1N(c1ccc2ccc3c(N(c4ccccc4C)c4cccc5c4oc4c(C(C)(C)C)cccc45)ccc4ccc1c2c43)c1cccc2c1oc1c(C(C)(C)C)cccc12 ; Cc1ccc2c(oc3ccccc32)c1N(c1ccccc1)c1ccc2ccc3c(N(c4ccccc4)c4c(C)ccc5c4oc4ccccc45)ccc4ccc1c2c43]

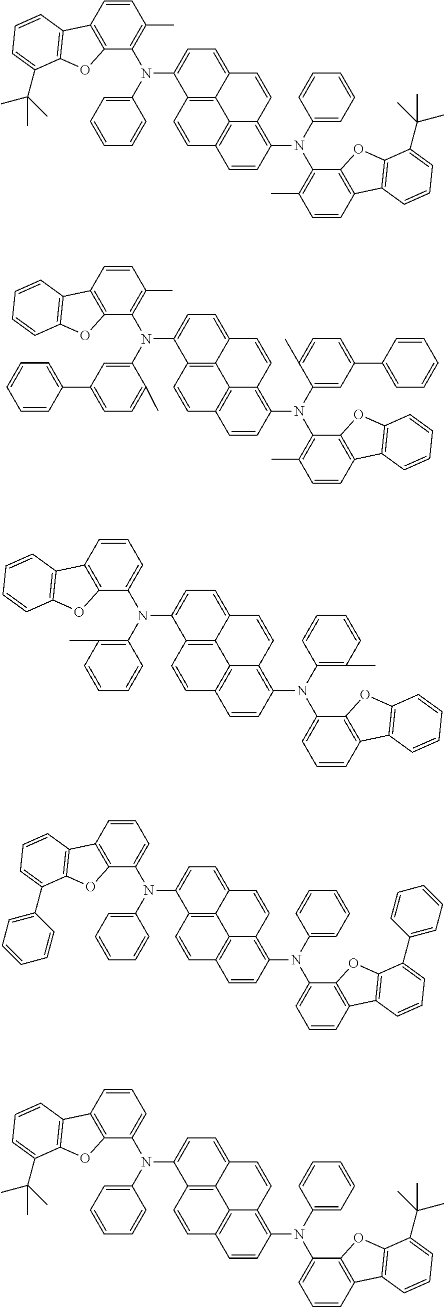

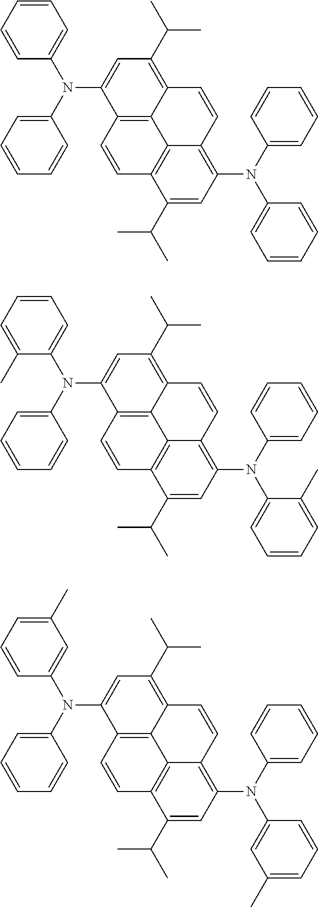

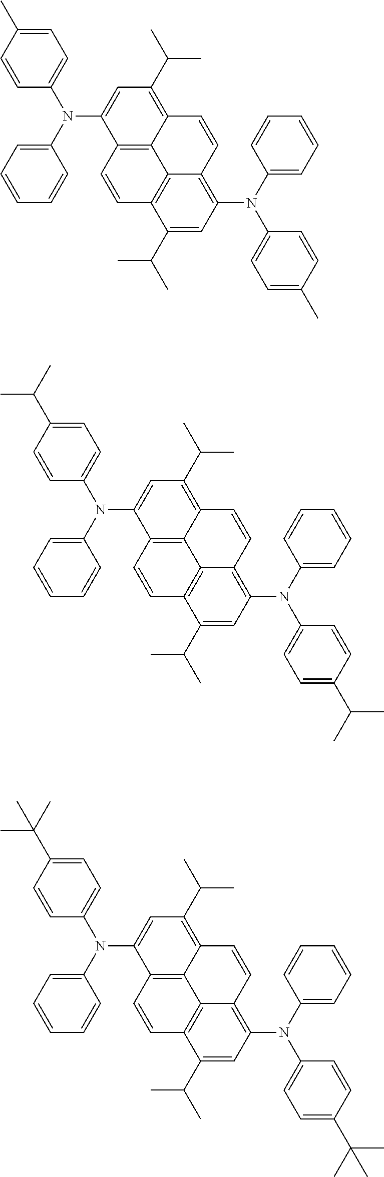

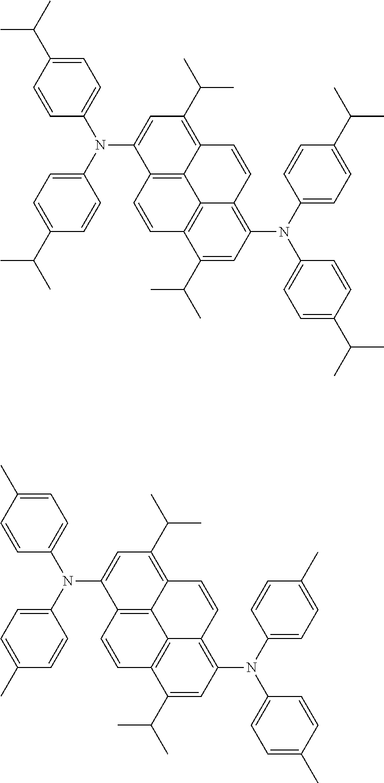 [SMILES: CC(C)c1ccc(N(c2ccc(C(C)C)cc2)c2cc(C(C)C)c3ccc4c(N(c5ccc(C(C)C)cc5)c5ccc(C(C)C)cc5)cc(C(C)C)c5ccc2c3c54)cc1 ; Cc1ccc(N(c2ccc(C)cc2)c2cc(C(C)C)c3ccc4c(N(c5ccc(C)cc5)c5ccc(C)cc5)cc(C(C)C)c5ccc2c3c54)cc1]

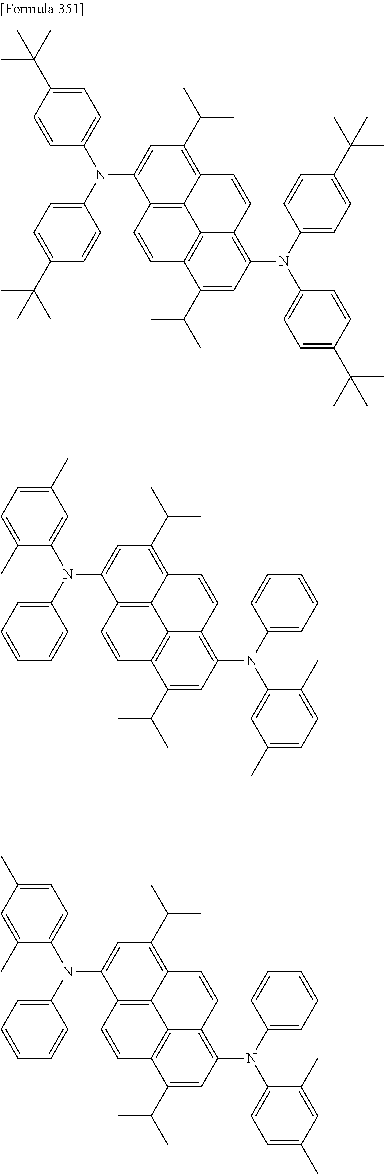 [SMILES: CC(C)c1cc(N(c2ccc(C(C)(C)C)cc2)c2ccc(C(C)(C)C)cc2)c2ccc3c(C(C)C)cc(N(c4ccc(C(C)(C)C)cc4)c4ccc(C(C)(C)C)cc4)c4ccc1c2c34 ; Cc1ccc(C)c(N(c2ccccc2)c2cc(C(C)C)c3ccc4c(N(c5ccccc5)c5cc(C)ccc5C)cc(C(C)C)c5ccc2c3c54)c1 ; Cc1ccc(N(c2ccccc2)c2cc(C(C)C)c3ccc4c(N(c5ccccc5)c5ccc(C)cc5C)cc(C(C)C)c5ccc2c3c54)c(C)c1]

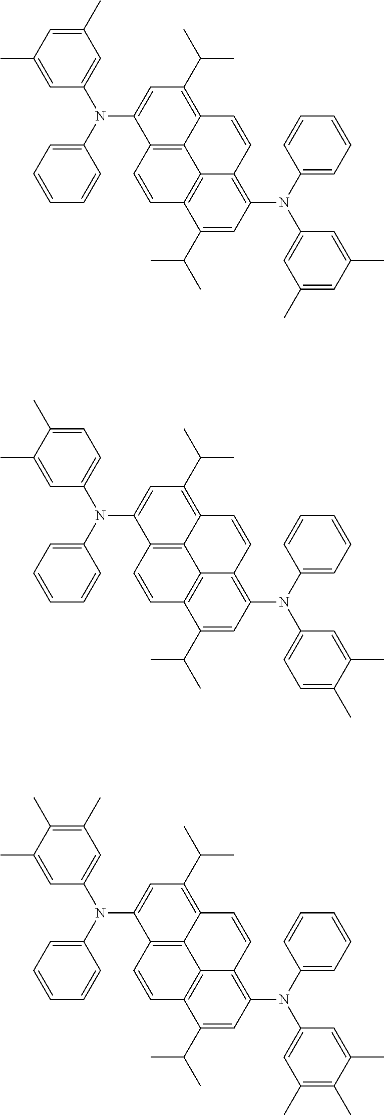

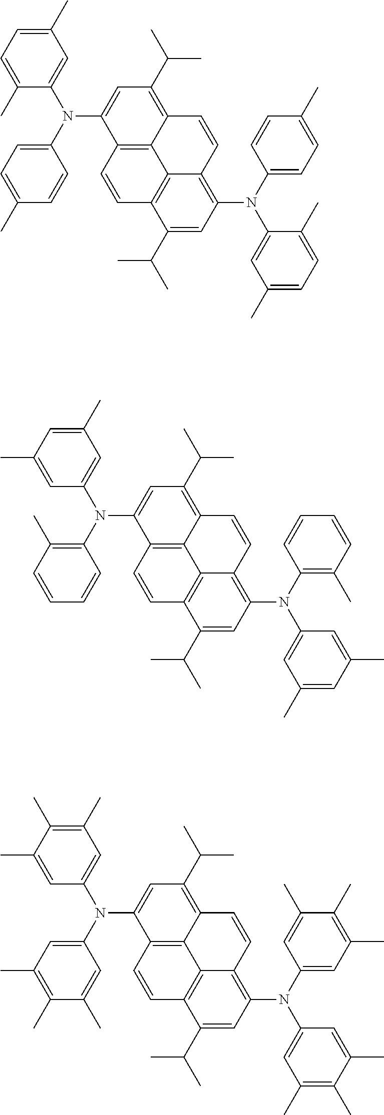

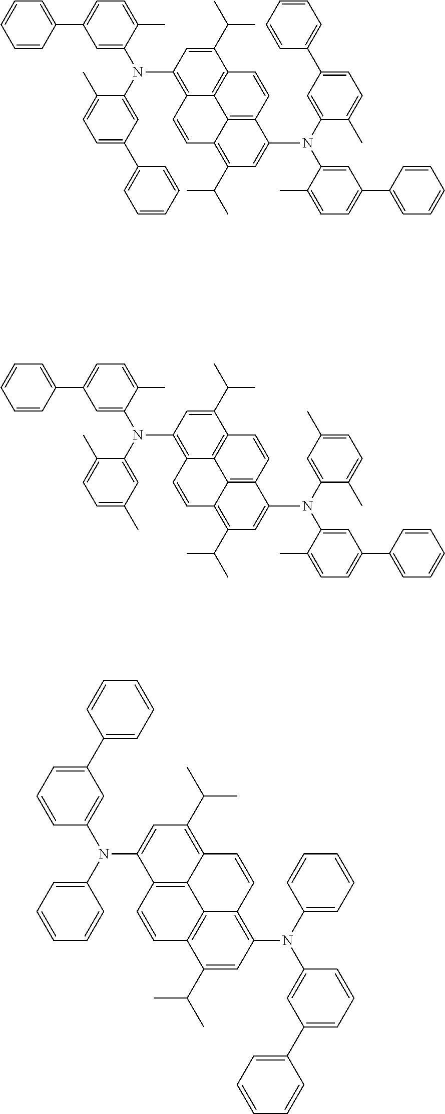 [SMILES: Cc1ccc(-c2ccccc2)cc1N(c1cc(-c2ccccc2)ccc1C)c1cc(C(C)C)c2ccc3c(N(c4cc(-c5ccccc5)ccc4C)c4cc(-c5ccccc5)ccc4C)cc(C(C)C)c4ccc1c2c43 ; Cc1ccc(C)c(N(c2cc(-c3ccccc3)ccc2C)c2cc(C(C)C)c3ccc4c(N(c5cc(C)ccc5C)c5cc(-c6ccccc6)ccc5C)cc(C(C)C)c5ccc2c3c54)c1 ; CC(C)c1cc(N(c2ccccc2)c2cccc(-c3ccccc3)c2)c2ccc3c(C(C)C)cc(N(c4ccccc4)c4cccc(-c5ccccc5)c4)c4ccc1c2c34]

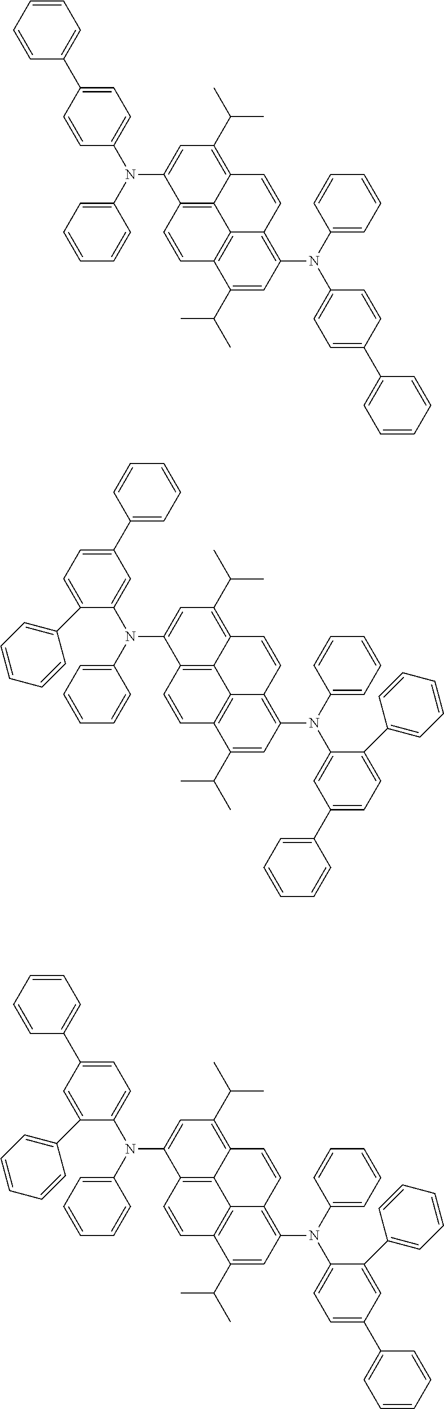 [SMILES: CC(C)c1cc(N(c2ccccc2)c2ccc(-c3ccccc3)cc2)c2ccc3c(C(C)C)cc(N(c4ccccc4)c4ccc(-c5ccccc5)cc4)c4ccc1c2c34 ; CC(C)c1cc(N(c2ccccc2)c2cc(-c3ccccc3)ccc2-c2ccccc2)c2ccc3c(C(C)C)cc(N(c4ccccc4)c4cc(-c5ccccc5)ccc4-c4ccccc4)c4ccc1c2c34 ; CC(C)c1cc(N(c2ccccc2)c2ccc(-c3ccccc3)cc2-c2ccccc2)c2ccc3c(C(C)C)cc(N(c4ccccc4)c4ccc(-c5ccccc5)cc4-c4ccccc4)c4ccc1c2c34]

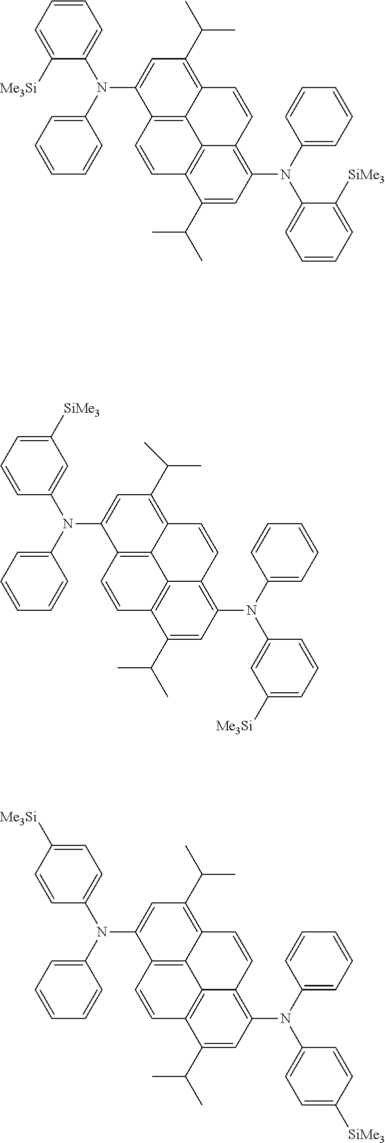 [SMILES: CC(C)c1cc(N(c2ccccc2)c2ccccc2[Si](C)(C)C)c2ccc3c(C(C)C)cc(N(c4ccccc4)c4ccccc4[Si](C)(C)C)c4ccc1c2c34 ; CC(C)c1cc(N(c2ccccc2)c2cccc([Si](C)(C)C)c2)c2ccc3c(C(C)C)cc(N(c4ccccc4)c4cccc([Si](C)(C)C)c4)c4ccc1c2c34 ; CC(C)c1cc(N(c2ccccc2)c2ccc([Si](C)(C)C)cc2)c2ccc3c(C(C)C)cc(N(c4ccccc4)c4ccc([Si](C)(C)C)cc4)c4ccc1c2c34]

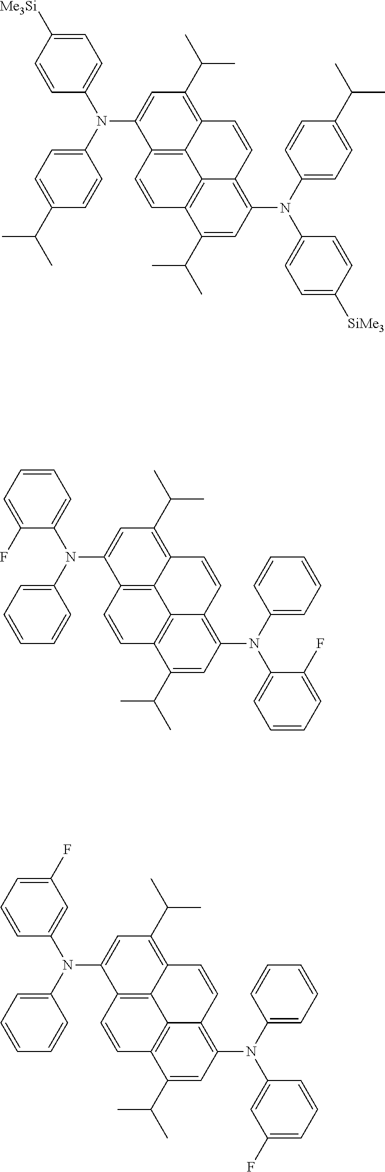 [SMILES: CC(C)c1ccc(N(c2ccc([Si](C)(C)C)cc2)c2cc(C(C)C)c3ccc4c(N(c5ccc(C(C)C)cc5)c5ccc([Si](C)(C)C)cc5)cc(C(C)C)c5ccc2c3c54)cc1 ; CC(C)c1cc(N(c2ccccc2)c2ccccc2F)c2ccc3c(C(C)C)cc(N(c4ccccc4)c4ccccc4F)c4ccc1c2c34 ; CC(C)c1cc(N(c2ccccc2)c2cccc(F)c2)c2ccc3c(C(C)C)cc(N(c4ccccc4)c4cccc(F)c4)c4ccc1c2c34]

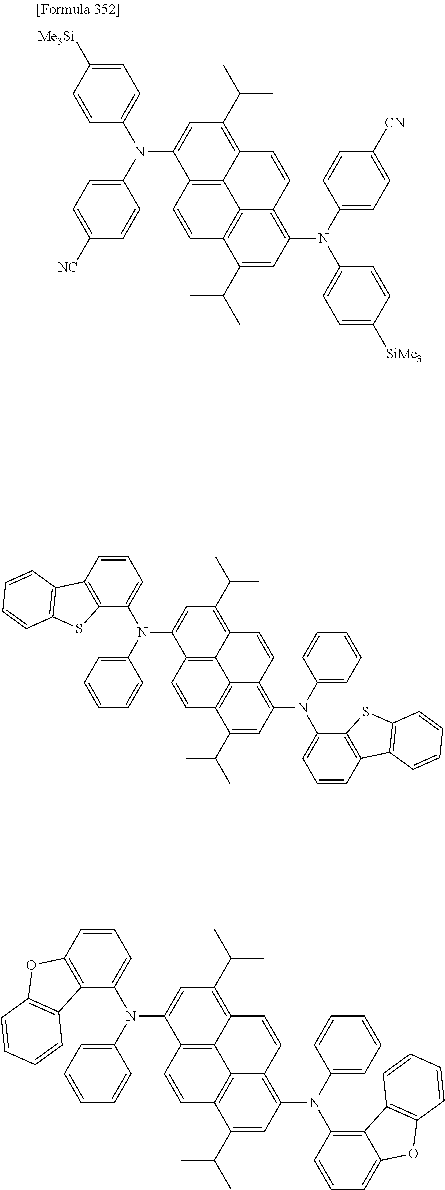 [SMILES: CC(C)c1cc(N(c2ccc(C#N)cc2)c2ccc([Si](C)(C)C)cc2)c2ccc3c(C(C)C)cc(N(c4ccc(C#N)cc4)c4ccc([Si](C)(C)C)cc4)c4ccc1c2c34 ; CC(C)c1cc(N(c2ccccc2)c2cccc3c2sc2ccccc23)c2ccc3c(C(C)C)cc(N(c4ccccc4)c4cccc5c4sc4ccccc45)c4ccc1c2c34 ; CC(C)c1cc(N(c2ccccc2)c2cccc3oc4ccccc4c23)c2ccc3c(C(C)C)cc(N(c4ccccc4)c4cccc5oc6ccccc6c45)c4ccc1c2c34]

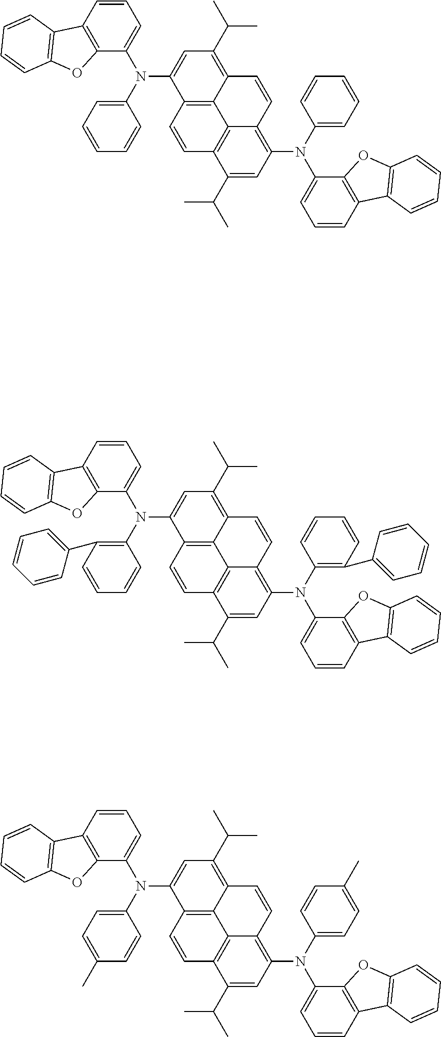 [SMILES: CC(C)c1cc(N(c2ccccc2)c2cccc3c2oc2ccccc23)c2ccc3c(C(C)C)cc(N(c4ccccc4)c4cccc5c4oc4ccccc45)c4ccc1c2c34 ; CC(C)c1cc(N(c2ccccc2-c2ccccc2)c2cccc3c2oc2ccccc23)c2ccc3c(C(C)C)cc(N(c4ccccc4-c4ccccc4)c4cccc5c4oc4ccccc45)c4ccc1c2c34 ; Cc1ccc(N(c2cc(C(C)C)c3ccc4c(N(c5ccc(C)cc5)c5cccc6c5oc5ccccc56)cc(C(C)C)c5ccc2c3c54)c2cccc3c2oc2ccccc23)cc1]

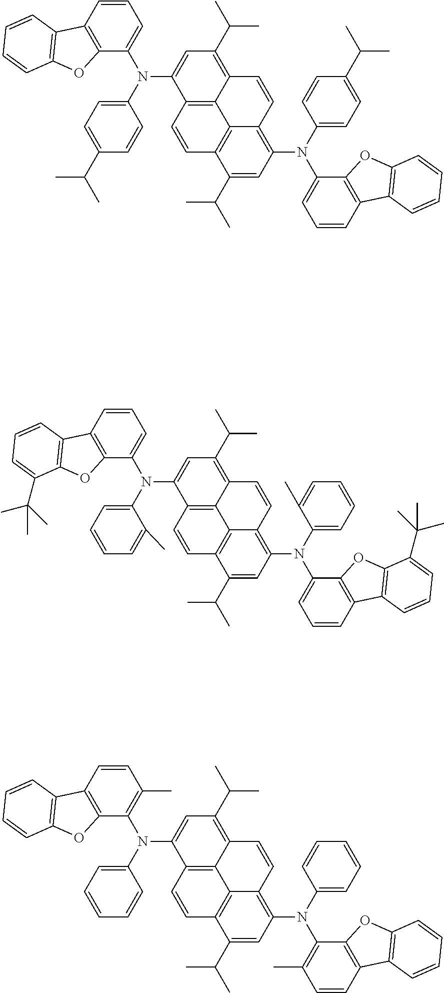 [SMILES: CC(C)c1ccc(N(c2cc(C(C)C)c3ccc4c(N(c5ccc(C(C)C)cc5)c5cccc6c5oc5ccccc56)cc(C(C)C)c5ccc2c3c54)c2cccc3c2oc2ccccc23)cc1 ; Cc1ccccc1N(c1cc(C(C)C)c2ccc3c(N(c4ccccc4C)c4cccc5c4oc4c(C(C)(C)C)cccc45)cc(C(C)C)c4ccc1c2c43)c1cccc2c1oc1c(C(C)(C)C)cccc12 ; Cc1ccc2c(oc3ccccc32)c1N(c1ccccc1)c1cc(C(C)C)c2ccc3c(N(c4ccccc4)c4c(C)ccc5c4oc4ccccc45)cc(C(C)C)c4ccc1c2c43]

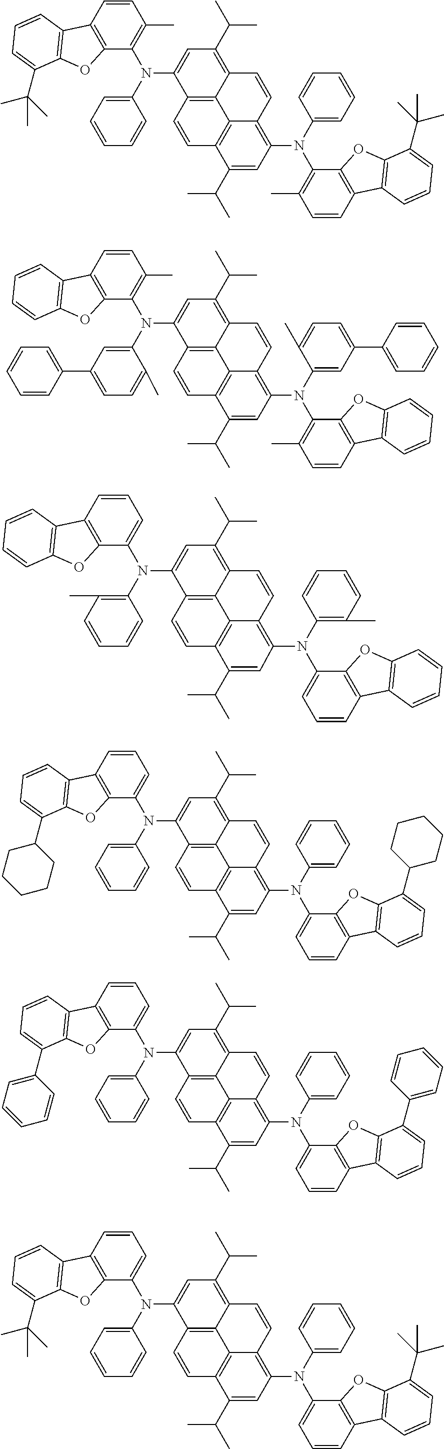

### Compound Represented by Formula (4)

The compound represented by the formula (4) will be described below.

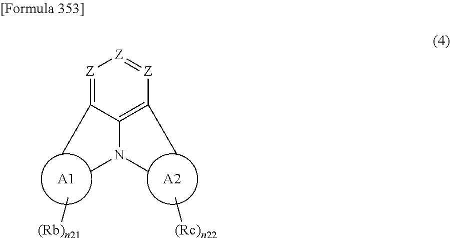

In the formula (4):
Z are each independently CRa or a nitrogen atom;
A1 ring and A2 ring are each independently a substituted or unsubstituted aromatic hydrocarbon ring having 6 to 50 ring carbon atoms, or a substituted or unsubstituted heterocyclic ring having 5 to 50 ring atoms;
when a plurality of Ra are present, at least one combination of adjacent two or more of the plurality of Ra are mutually bonded to form a substituted or unsubstituted monocyclic ring, mutually bonded to form a substituted or unsubstituted fused ring, or not mutually bonded;
n21 and n22 are each independently 0, 1, 2, 3 or 4;
when a plurality of Rb are present, at least one combination of adjacent two or more of the plurality of Rb are mutually bonded to form a substituted or unsubstituted monocyclic ring, mutually bonded to form a substituted or unsubstituted fused ring, or not mutually bonded;
when a plurality of Rc are present, at least one combination of adjacent two or more of the plurality of Rc are mutually bonded to form a substituted or unsubstituted monocyclic ring, mutually bonded to form a substituted or unsubstituted fused ring, or not mutually bonded; and
Ra, Rb, and Rc forming neither the monocyclic ring nor the fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

The “aromatic hydrocarbon ring” for the A1 ring and A2 ring has the same structure as a compound formed by introducing a hydrogen atom to the “aryl group” described above.

Ring atoms of the “aromatic hydrocarbon ring” for the A1 ring and A2 ring include two carbon atoms on a fused bicyclic structure at the center of the formula (4).

Specific examples of the “substituted or unsubstituted aromatic hydrocarbon ring having 6 to 50 ring carbon atoms” include a compound formed by introducing a hydrogen atom to the “aryl group” described in the specific example group G1.

The “heterocycle” for the A1 ring and A2 ring has the same structure as a compound formed by introducing a hydrogen atom to the “heterocyclic group” described above.

Ring atoms of the “heterocycle” for the A1 ring and A2 ring include two carbon atoms on a fused bicyclic structure at the center of the formula (4).

Specific examples of the “substituted or unsubstituted heterocycle having 5 to 50 ring atoms” include a compound formed by introducing a hydrogen atom to the “heterocyclic group” described in the specific example group G2.

Rb is bonded to any one of carbon atoms forming the aromatic hydrocarbon ring as the A1 ring or any one of atoms forming the heterocycle as the A1 ring.

Rc is bonded to any one of carbon atoms forming the aromatic hydrocarbon ring as the A2 ring or any one of atoms forming the heterocycle as the A2 ring.

At least one of Ra, Rb, or Rc is preferably a group represented by a formula (4a) below. More preferably, at least two of Ra, Rb, or Rc are each a group represented by the formula (4a).

[Formula 354]

*-L₄₀₁-Ar₄₀₁ (4a)

In the formula (4a):
L₄₀₁ is a single bond, a substituted or unsubstituted arylene group having 6 to 30 ring carbon atoms, or a substituted or unsubstituted divalent heterocyclic group having 5 to 30 ring atoms; and
Ar₄₀₁ is a substituted or unsubstituted aryl group having 6 to 50 ring carbon atoms, a substituted or unsubstituted heterocyclic group having 5 to 50 ring atoms, or a group represented by a formula (4b) below.

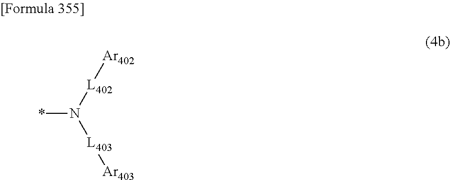

In the formula (4b):
L₄₀₂ and L₄₀₃ are each independently a single bond, a substituted or unsubstituted arylene group having 6 to 30 ring carbon atoms, or a substituted or unsubstituted divalent heterocyclic group having 5 to 30 ring atoms;
a combination of Ar₄₀₂ and Ar₄₀₃ are mutually bonded to form a substituted or unsubstituted monocyclic ring, mutually bonded to form a substituted or unsubstituted fused ring, or not mutually bonded; and
Ar₄₀₂ and Ar₄₀₃ forming neither the monocyclic ring nor the fused ring are each independently a substituted or unsubstituted aryl group having 6 to 50 ring carbon atoms, or a substituted or unsubstituted heterocyclic group having 5 to 50 ring atoms.

In an exemplary embodiment, the compound represented by the formula (4) is represented by a formula (42) below.

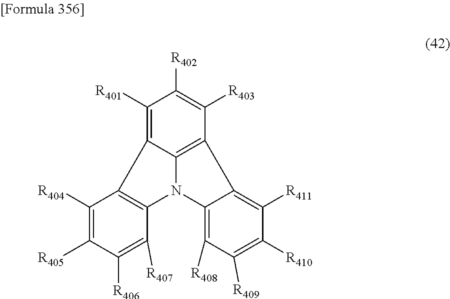

In the formula (42):
at least one combination of adjacent two or more of R₄₀₁ to R₄₁₁ are mutually bonded to form a substituted or unsubstituted monocyclic ring, mutually bonded to form a substituted or unsubstituted fused ring, or not mutually bonded; and
R₄₀₁ to R₄₁₁ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

At least one of R₄₀₁ to R₄₁₁ is preferably a group represented by the formula (4a). More preferably, at least two of R₄₀₁ to R₄₁₁ are each a group represented by the formula (4a).
R₄₀₄ and R₄₁₁ are each preferably a group represented by the formula (4a).

In an exemplary embodiment, the compound represented by the formula (4) is a compound formed by bonding a moiety represented by a formula (4-1) or a formula (4-2) below to the A1 ring.

Further, in an exemplary embodiment, the compound represented by the formula (42) is a compound formed by bonding the moiety represented by the formula (4-1) or the formula (4-2) to a ring bonded to R₄₀₄ to R₄₀₇.

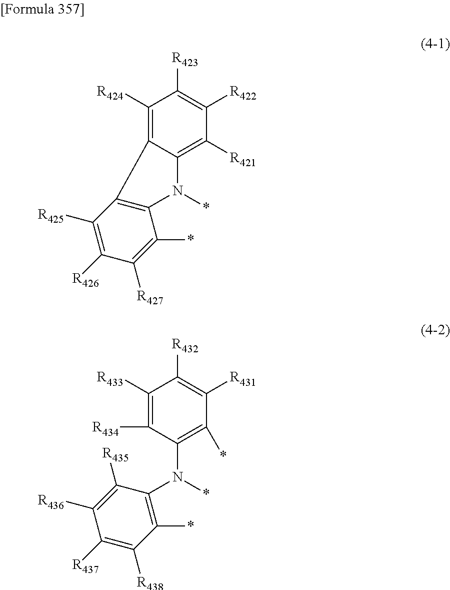

In the formula (4-1), two bonds * are each independently bonded to a ring-forming carbon atom of the aromatic hydrocarbon ring or a ring atom of the heterocycle as the A1 ring in the formula (4) or bonded to one of R₄₀₄ to R₄₀₇ in the formula (42).

In the formula (4-2): three bonds * are each independently bonded to a ring-forming carbon atom of the aromatic hydrocarbon ring or a ring atom of the heterocycle as the A1 ring in the formula (4) or bonded to one of R₄₀₄ to R₄₀₇ in the formula (42);
at least one combination of adjacent two or more of R₄₂₁ to R₄₂₇ are mutually bonded to form a substituted or unsubstituted monocyclic ring, mutually bonded to form a substituted or unsubstituted fused ring, or not mutually bonded;
at least one combination of adjacent two or more of R₄₃₁ to R₄₃₈ are mutually bonded to form a substituted or unsubstituted monocyclic ring, mutually bonded to form a substituted or unsubstituted fused ring, or not mutually bonded; and
R₄₂₁ to R₄₂₇ and R₄₃₁ to R₄₃₈ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In an exemplary embodiment, the compound represented by the formula (4) is a compound represented by a formula (41-3), a formula (41-4) or a formula (41-5) below.

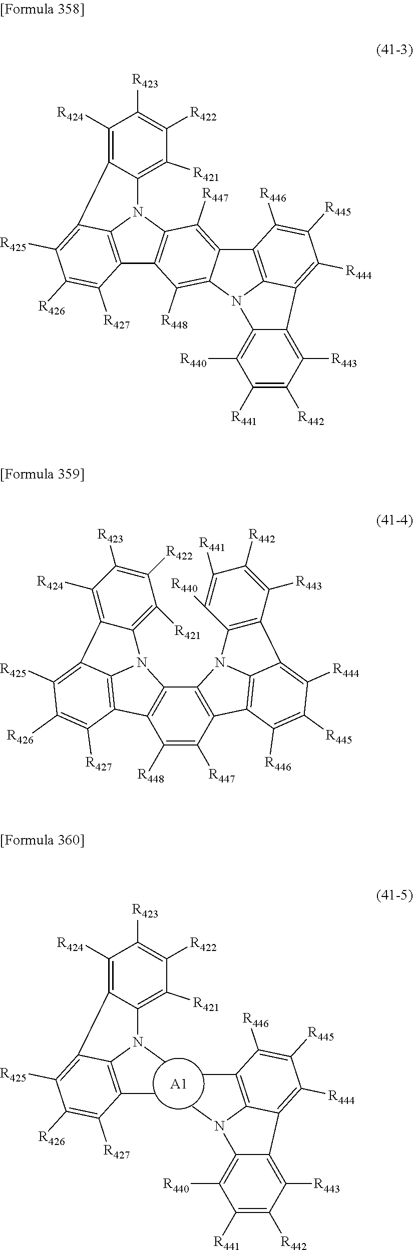

In the formulae (41-3), (41-4), and (41-5):
A1 ring is as defined in the formula (4);
R₄₂₁ to R₄₂₇ each independently represent the same as R₄₂₁ to R₄₂₇ in the formula (4-1); and
R₄₄₀ to R₄₄₈ each independently represent the same as R₄₀₁ to R₄₁₁ in the formula (42).

In an exemplary embodiment, a substituted or unsubstituted aromatic hydrocarbon ring having 6 to 50 ring carbon atoms as the A1 ring in the formula (41-5) is a substituted or unsubstituted naphthalene ring, or a substituted or unsubstituted fluorene ring.

In an exemplary embodiment, a substituted or unsubstituted heterocycle having 5 to 50 ring atoms as the A1 ring in the formula (41-5) is a substituted or unsubstituted dibenzofuran ring, a substituted or unsubstituted carbazole ring, or a substituted or unsubstituted dibenzothiophene ring.

In an exemplary embodiment, the compound represented by the formula (4) or the formula (42) is selected from the group consisting of compounds represented by formulae (461) to (467) below.

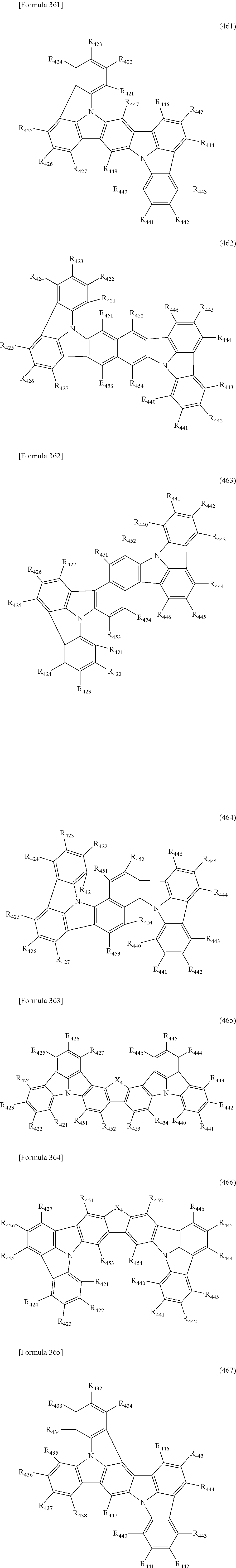

In the formulae (461), (462), (463), (464), (465), (466), and (467):
R₄₂₁ to R₄₂₇ each independently represent the same as R₄₂₁ to R₄₂₇ in the formula (4-1);
R₄₃₁ to R₄₃₈ each independently represent the same as R₄₃₁ to R₄₃₈ in the formula (4-2);
R₄₄₀ to R₄₄₈ and R₄₅₁ to R₄₅₄ each independently represent the same as R₄₀₁ to R₄₁₁ in the formula (42);
X₄ is an oxygen atom, NR₈₀₁, or C(R₈₀₂)(R₈₀₃);
R₈₀₁, R₈₀₂, and R₈₀₃ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
a substituted or unsubstituted alkyl group having 1 to 50 carbon atoms, or a substituted or unsubstituted aryl group having 6 to 50 ring carbon atoms;
when a plurality of R₈₀₁ are present, the plurality of R₈₀₁ are mutually the same or different;
when a plurality of R₈₀₂ are present, the plurality of R₈₀₂ are mutually the same or different; and
when a plurality of R₈₀₃ are present, the plurality of R₈₀₃ are mutually the same or different.

In an exemplary embodiment, at least one combination of adjacent two or more of R₄₀₁ to R₄₁₁ in the compound represented by the formula (42) are mutually bonded to form a substituted or unsubstituted monocyclic ring, or mutually bonded to form a substituted or unsubstituted fused ring. This exemplary embodiment will be described in detail below as a compound represented by a formula (45) below.

### Compound Represented by Formula (45)

The compound represented by the formula (45) will be described below.

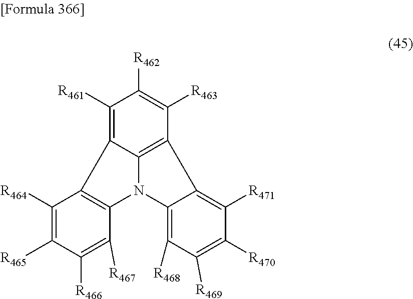

In the formula (45):
two or more of combinations selected from the group consisting of a combination of R₄₆₁ and R₄₆₂, a combination of R₄₆₂ and R₄₆₃, a combination of R₄₆₄ and R₄₆₅, a combination of R₄₆₅ and R₄₆₆, a combination of R₄₆₆ and R₄₆₇, a combination of R₄₆₈ and R₄₆₉, a combination of R₄₆₉ and R₄₇₀, and a combination of R₄₇₀ and R₄₇₁ are mutually bonded to form a substituted or unsubstituted monocyclic ring or mutually bonded to form a substituted or unsubstituted fused ring;
the combination of R₄₆₁ and R₄₆₂ and the combination of R₄₆₂ and R₄₆₃; the combination of R₄₆₄ and R₄₆₅ and the combination of R₄₆₅ and R₄₆₆; the combination of R₄₆₅ and R₄₆₆ and the combination of R₄₆₆ and R₄₆₇; the combination of R₄₆₈ and R₄₆₉ and the combination of R₄₆₉ and R₄₇₀; and the combination of R₄₆₉ and R₄₇₀ and the combination of R₄₇₀ and R₄₇₁ do not form a ring at the same time;
the two or more rings formed by R₄₆₁ to R₄₇₁ are mutually the same or different; and
R₄₆₁ to R₄₇₁ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the formula (45), Rₙ and Rₙ₊₁ (n being an integer selected from 461, 462, 464 to 466, and 468 to 470) are mutually bonded to form a substituted or unsubstituted monocyclic ring or fused ring together with two ring-forming carbon atoms bonded to Rₙ and Rₙ₊₁. The ring is preferably formed of atoms selected from the group consisting of a carbon atom, an oxygen atom, a sulfur atom, and a nitrogen atom, and is made of preferably 3 to 7 atoms, more preferably 5 or 6 atoms.

The number of the above cyclic structures in the compound represented by the formula (45) is, for instance, 2, 3, or 4. The two or more of the cyclic structures may be present on the same benzene ring on the basic skeleton represented by the formula (45) or may be present on different benzene rings. For instance, when three cyclic structures are present, each of the cyclic structures may be present on the corresponding one of the three benzene rings of the formula (45).

Examples of the above cyclic structures in the compound represented by the formula (45) include structures represented by formulae (451) to (460) below.

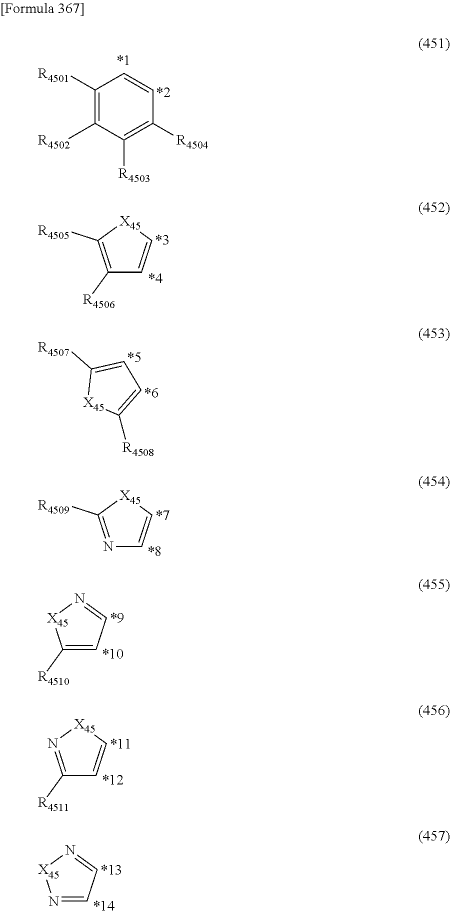

In the formulae (451) to (457):
each combination of *1 and *2, *3 and *4, *5 and *6, *7 and *8, *9 and *10, *11 and *12, and *13 and *14 represents the two ring-forming carbon atoms bonded to Rₙ and Rₙ₊₁;
the ring-forming carbon atom bonded to Rₙ may be any one of the two ring-forming carbon atoms represented by *1 and *2, *3 and *4, *5 and *6, *7 and *8, *9 and *10, *11 and *12, and *13 and *14;
X₄₅ is C(R₄₅₁₂)(R₄₅₁₃), NR₄₅₁₄, an oxygen atom, or a sulfur atom;
at least one combination of adjacent two or more of R₄₅₀₁ to R₄₅₀₆ and R₄₅₁₂ to R₄₅₁₃ are mutually bonded to form a substituted or unsubstituted monocyclic ring, mutually bonded to form a substituted or unsubstituted fused ring, or not mutually bonded; and
R₄₅₀₁ to R₄₅₁₄ forming neither the monocyclic ring nor the fused ring each independently represent the same as R₄₆₁ to R₄₇₁ in the formula (45).

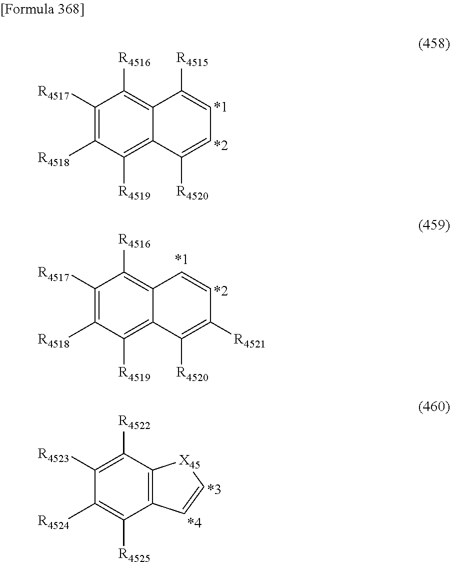

In the formulae (458) to (460):
each combination of *1 and *2, and *3 and *4 represents the two ring-forming carbon atoms bonded to Rₙ and Rₙ₊₁;
the ring-forming carbon atom bonded to Rₙ may be any one of the two ring-forming carbon atoms represented by *1 and *2, or *3 and *4;
X₄₅ is C(R₄₅₁₂)(R₄₅₁₃), NR₄₅₁₄, an oxygen atom, or a sulfur atom;
at least one combination of adjacent two or more of R₄₅₁₂ to R₄₅₁₃ and R₄₅₁₅ to R₄₅₂₅ are mutually bonded to form a substituted or unsubstituted monocyclic ring, mutually bonded to form a substituted or unsubstituted fused ring, or not mutually bonded; and
R₄₅₁₂ to R₄₅₁₃, R₄₅₁₅ to R₄₅₂₁ and R₄₅₂₂ to R₄₅₂₅ forming neither the monocyclic ring nor the fused ring, and R₄₅₁₄ each independently represent the same as R₄₆₁ to R₄₇₁ in the formula (45).

In the formula (45), preferably, at least one of R₄₆₂, R₄₆₄, R₄₆₅, R₄₇₀ or R₄₇₁ (preferably, at least one of R₄₆₂, R₄₆₅ or R₄₇₀, more preferably R₄₆₂) is a group forming no cyclic structure.

(i) A substituent, if present, for a cyclic structure formed by Rₙ and Rₙ₊₁ in the formula (45), (ii) R₄₆₁ to R₄₇₁ forming no cyclic structure in the formula (45), and (iii) R₄₅₀₁ to R₄₅₁₄, R₄₅₁₅ to R₄₅₂₅ in the formulae (451) to (460) are preferably each independently any one of groups selected from the group consisting of a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —N(R₉₀₆)(R₉₀₇), a substituted or unsubstituted aryl group having 6 to 50 ring carbon atoms, a substituted or unsubstituted heterocyclic group having 5 to 50 ring atoms, or groups represented by formulae (461) to (464) below.

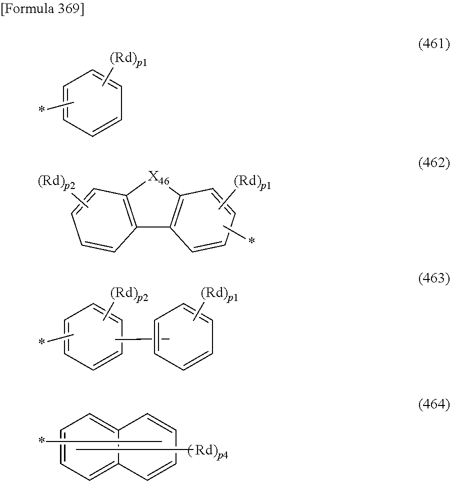

In the formulae (461) to (464):
R_{d} is each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
X₄₆ is C(R₈₀₁)(R₈₀₂), NR₈₀₃, an oxygen atom, or a sulfur atom;
R₈₀₁, R₈₀₂, and R₈₀₃ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
a substituted or unsubstituted alkyl group having 1 to 50 carbon atoms, or a substituted or unsubstituted aryl group having 6 to 50 ring carbon atoms;
when a plurality of R₈₀₁ are present, the plurality of R₈₀₁ are mutually the same or different;
when a plurality of R₈₀₂ are present, the plurality of R₈₀₂ are mutually the same or different;
when a plurality of R₈₀₃ are present, the plurality of R₈₀₃ are mutually the same or different;
p1 is 5;
p2 is 4;
p3 is 3;
p4 is 7; and
in the formulae (461) to (464) each independently represent a bonding position to a cyclic structure.
R₉₀₁ to R₉₀₇ in the third compound and the fourth compound are as defined above.

In an exemplary embodiment, the compound represented by the formula (45) is represented by one of formulae (45-1) to (45-6) below.

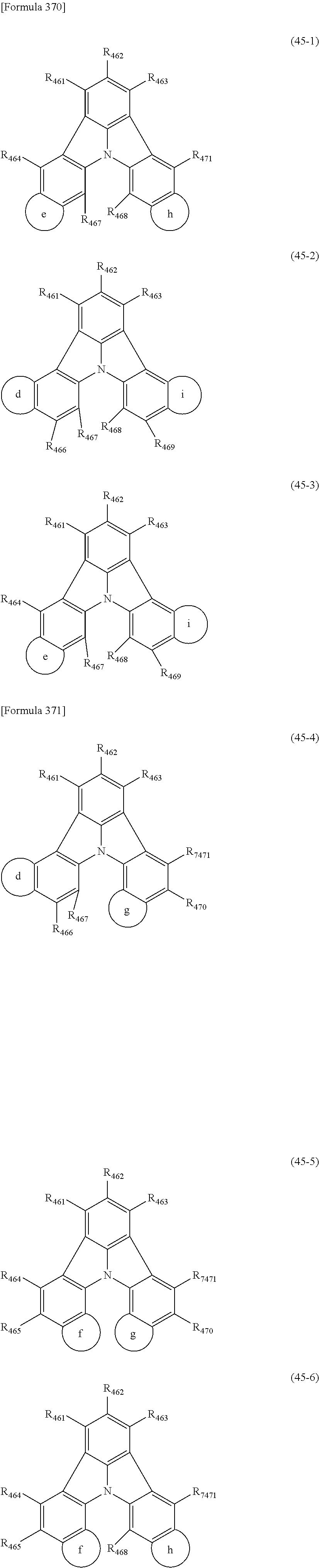

In the formulae (45-1) to (45-6):
rings d to i are each independently a substituted or unsubstituted monocyclic ring or a substituted or unsubstituted fused ring; and
R₄₆₁ to R₄₇₁ each independently represent the same as R₄₆₁ to R₄₇₁ in the formula (45).

In an exemplary embodiment, the compound represented by the formula (45) is represented by one of formulae (45-7) to (45-12) below.

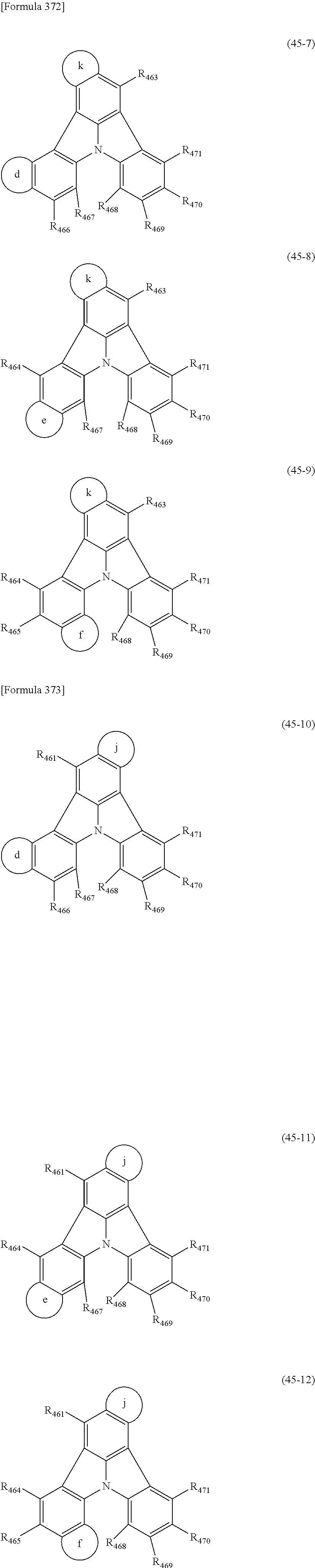

In the formulae (45-7) to (45-12):
rings d to f, k and j are each independently a substituted or unsubstituted monocyclic ring or a substituted or unsubstituted fused ring; and
R₄₆₁ to R₄₇₁ each independently represent the same as R₄₆₁ to R₄₇₁ in the formula (45).

In an exemplary embodiment, the compound represented by the formula (45) is represented by one of formulae (45-13) to (45-21) below.

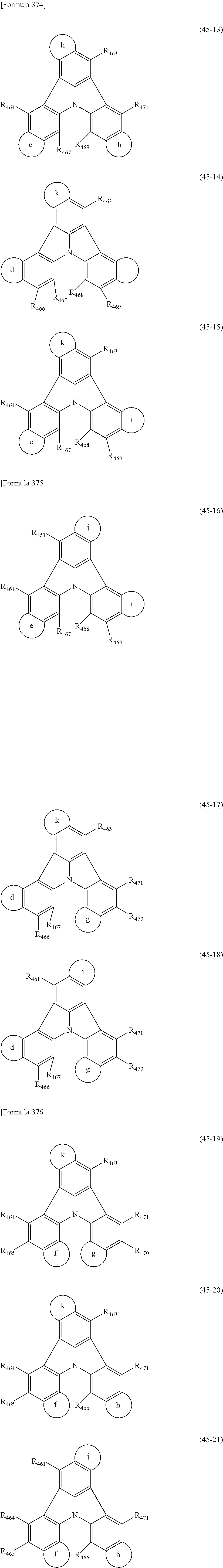

In the formulae (45-13) to (45-21):
rings d to k are each independently a substituted or unsubstituted monocyclic ring or a substituted or unsubstituted fused ring; and R₄₆₁ to R₄₇₁ each independently represent the same as R₄₆₁ to R₄₇₁ in the formula (45).

When the ring g or the ring h further has a substituent, examples of the substituent include a substituted or unsubstituted alkyl group having 1 to 50 carbon atoms, a substituted or unsubstituted aryl group having 6 to 50 ring carbon atoms, a group represented by the formula (461), a group represented by the formula (463), and a group represented by the formula (464).

In an exemplary embodiment, the compound represented by the formula (45) is represented by one of formulae (45-22) to (45-25) below.

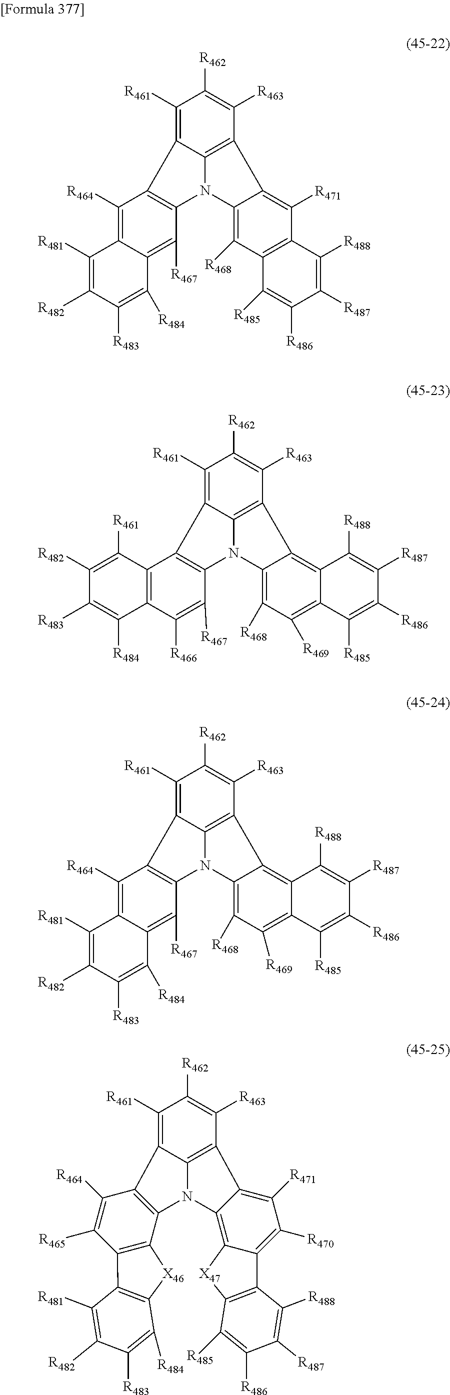

In the formulae (45-22) to (45-25):
X₄₆ and X₄₇ are each independently C(R₈₀₁)(R₈₀₂), NR₈₀₃, an oxygen atom, or a sulfur atom;
R₄₆₁ to R₄₇₁ and R₄₈₁ to R₄₈₈ each independently represent the same as R₄₆₁ to R₄₇₁ in the formula (45);
R₈₀₁, R₈₀₂, and R₈₀₃ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
a substituted or unsubstituted alkyl group having 1 to 50 carbon atoms, or a substituted or unsubstituted aryl group having 6 to 50 ring carbon atoms;
when a plurality of R₈₀₁ are present, the plurality of R₈₀₁ are mutually the same or different;
when a plurality of R₈₀₂ are present, the plurality of R₈₀₂ are mutually the same or different; and
when a plurality of R₈₀₃ are present, the plurality of R₈₀₃ are mutually the same or different.

In an exemplary embodiment, the compound represented by the formula (45) is represented by a formula (45-26) below.

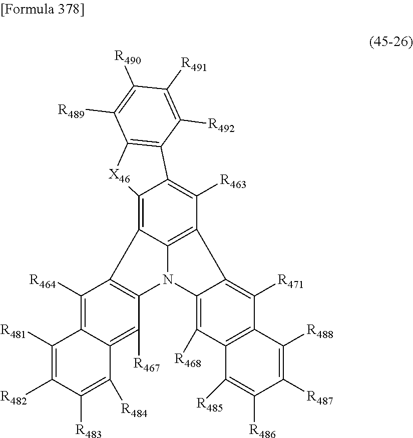

In the formula (45-26):
X₄₆ is C(R₈₀₁)(R₈₀₂), NR₈₀₃, an oxygen atom, or a sulfur atom;
R₄₆₃, R₄₆₄, R₄₆₇, R₄₆₈, R₄₇₁, and R₄₈₁ to R₄₉₂ each independently represent the same as R₄₆₁ to R₄₇₁ in the formula (45);
R₈₀₁, R₈₀₂, and R₈₀₃ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms, a substituted or unsubstituted alkyl group having 1 to 50 carbon atoms, or a substituted or unsubstituted aryl group having 6 to 50 ring carbon atoms;
when a plurality of R₈₀₁ are present, the plurality of R₈₀₁ are mutually the same or different;
when a plurality of R₈₀₂ are present, the plurality of R₈₀₂ are mutually the same or different; and
when a plurality of R₈₀₃ are present, the plurality of R₈₀₃ are mutually the same or different.

### Specific Examples of Compound Represented by Formula (4)

Specific examples of the compound represented by the formula (4) include compounds shown below. In the specific examples below, Ph represents a phenyl group, and D represents a deuterium atom.

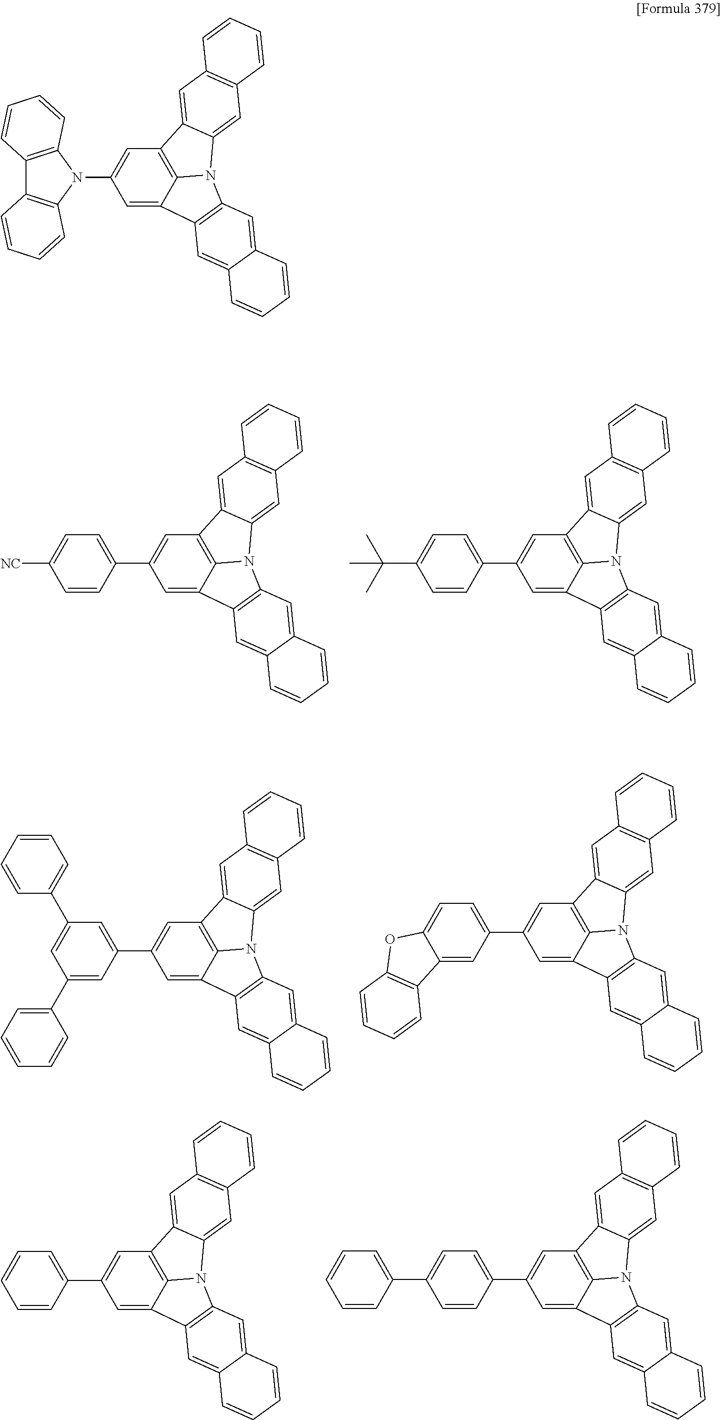

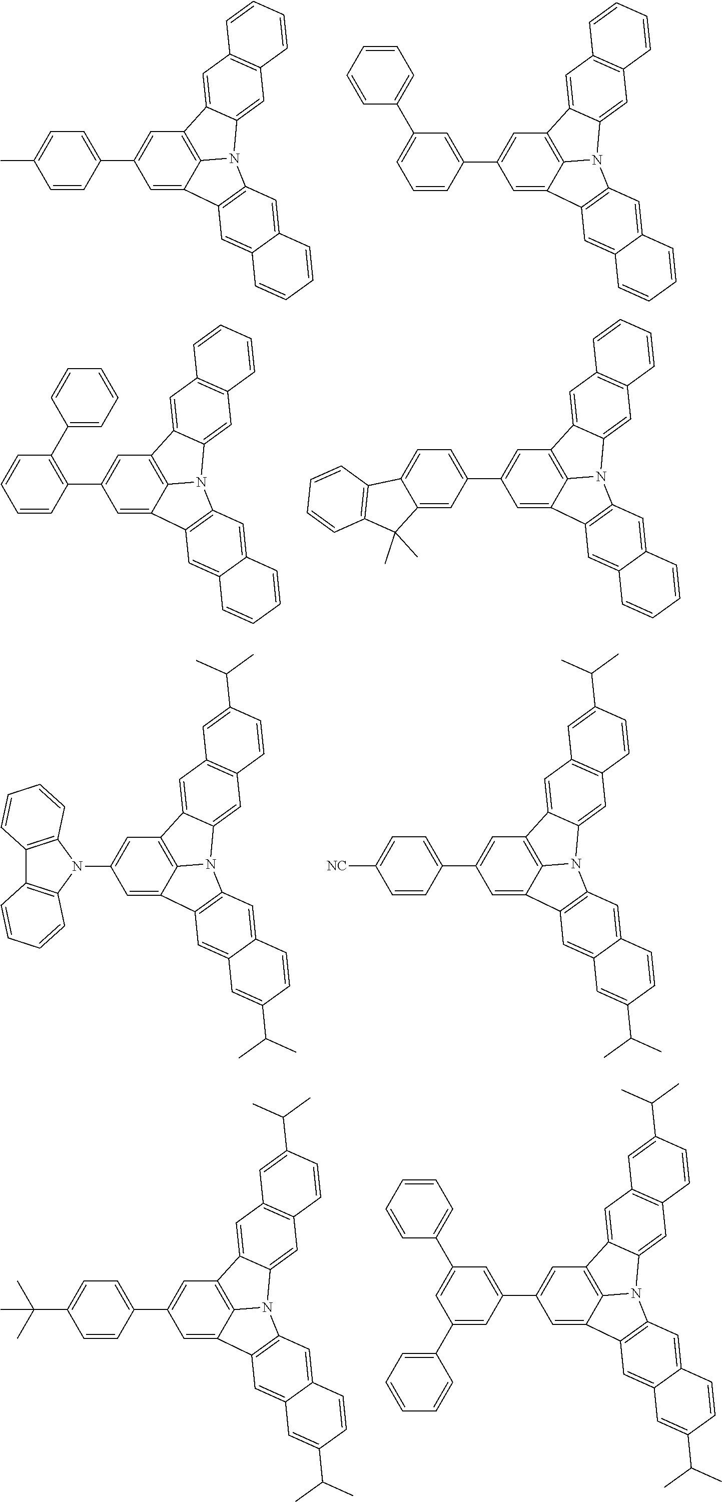

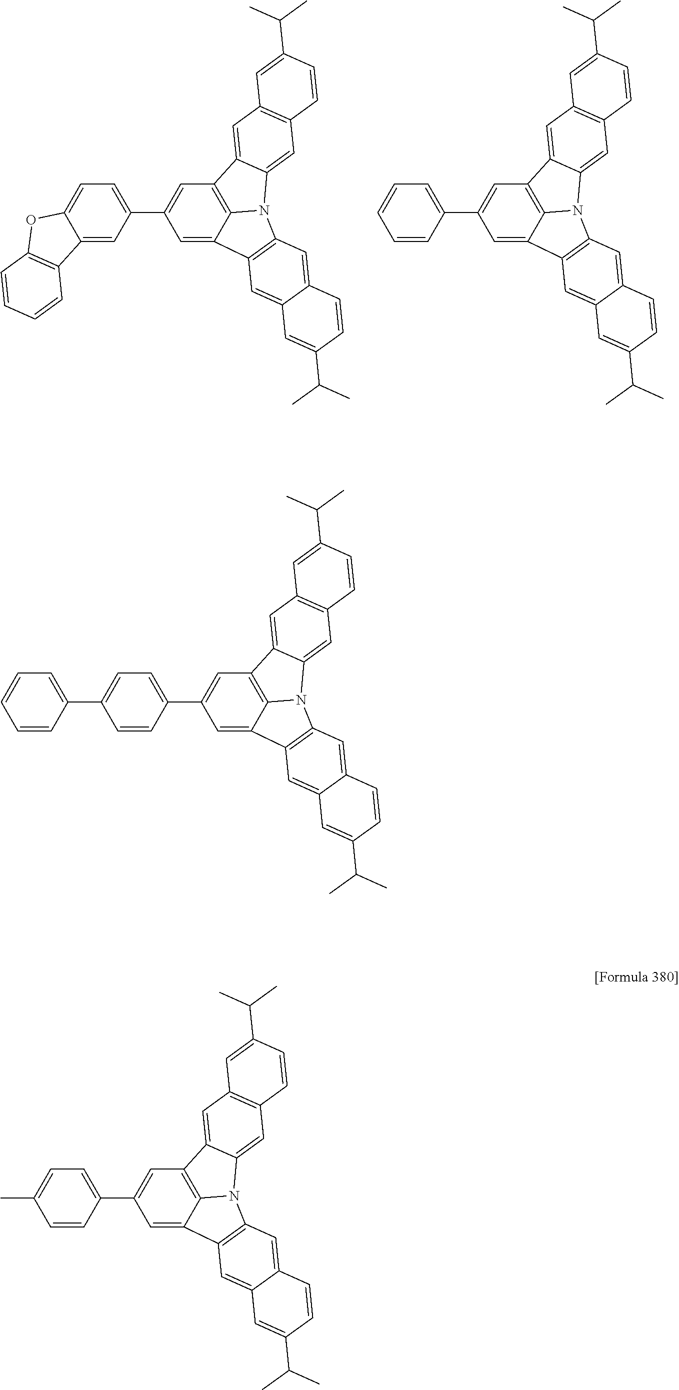 [SMILES: CC(C)c1ccc2cc3c(cc2c1)c1cc(-c2ccc4oc5ccccc5c4c2)cc2c4cc5cc(C(C)C)ccc5cc4n3c12 ; CC(C)c1ccc2cc3c(cc2c1)c1cc(-c2ccccc2)cc2c4cc5cc(C(C)C)ccc5cc4n3c12 ; CC(C)c1ccc2cc3c(cc2c1)c1cc(-c2ccc(-c4ccccc4)cc2)cc2c4cc5cc(C(C)C)ccc5cc4n3c12 ; Cc1ccc(-c2cc3c4cc5cc(C(C)C)ccc5cc4n4c5cc6ccc(C(C)C)cc6cc5c(c2)c34)cc1]

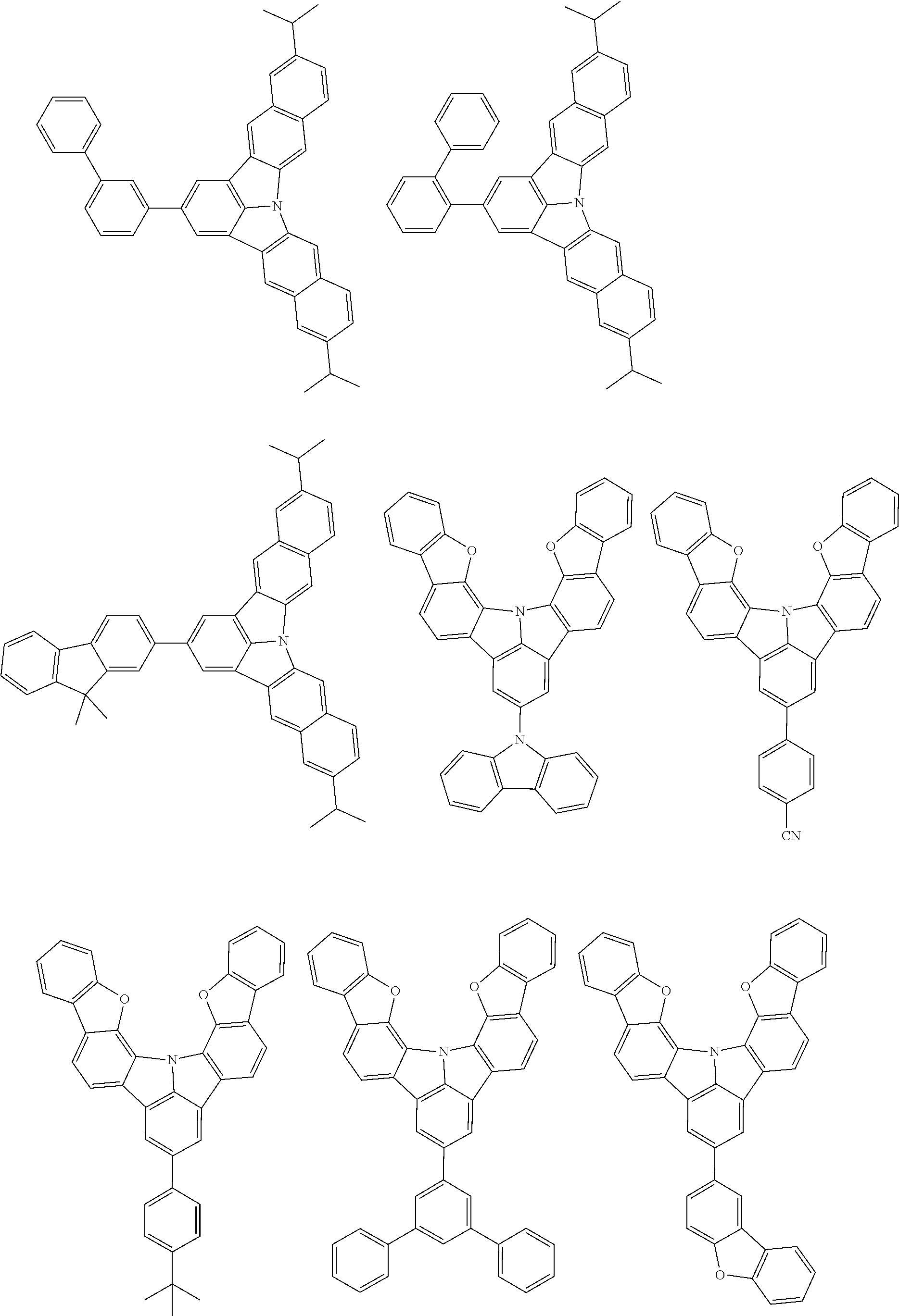

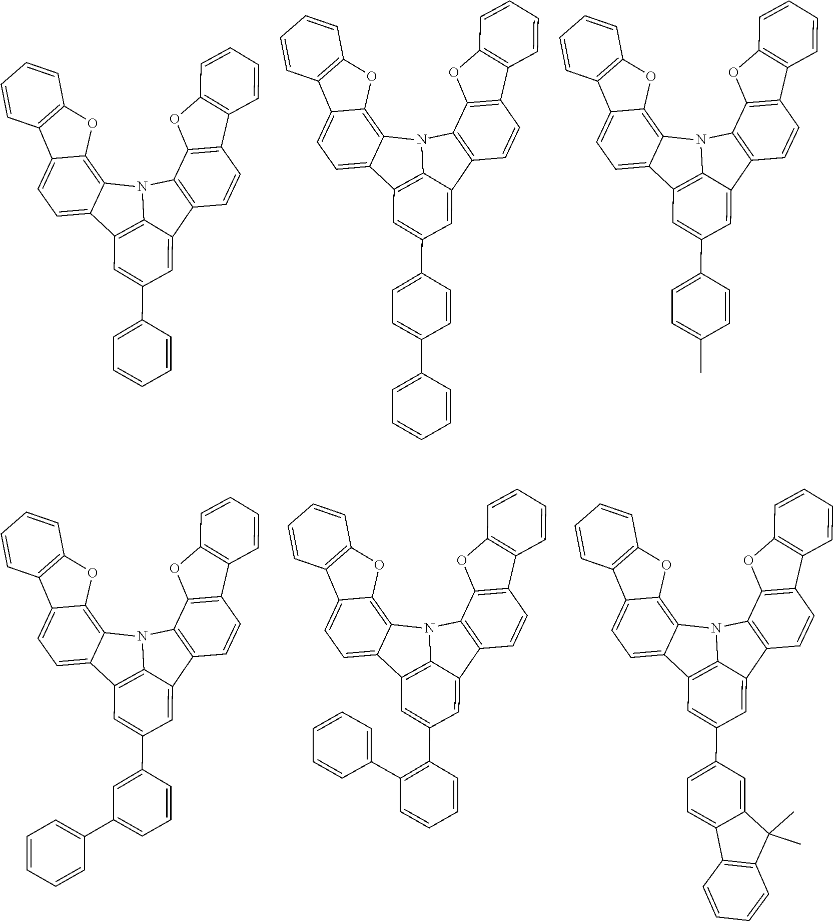

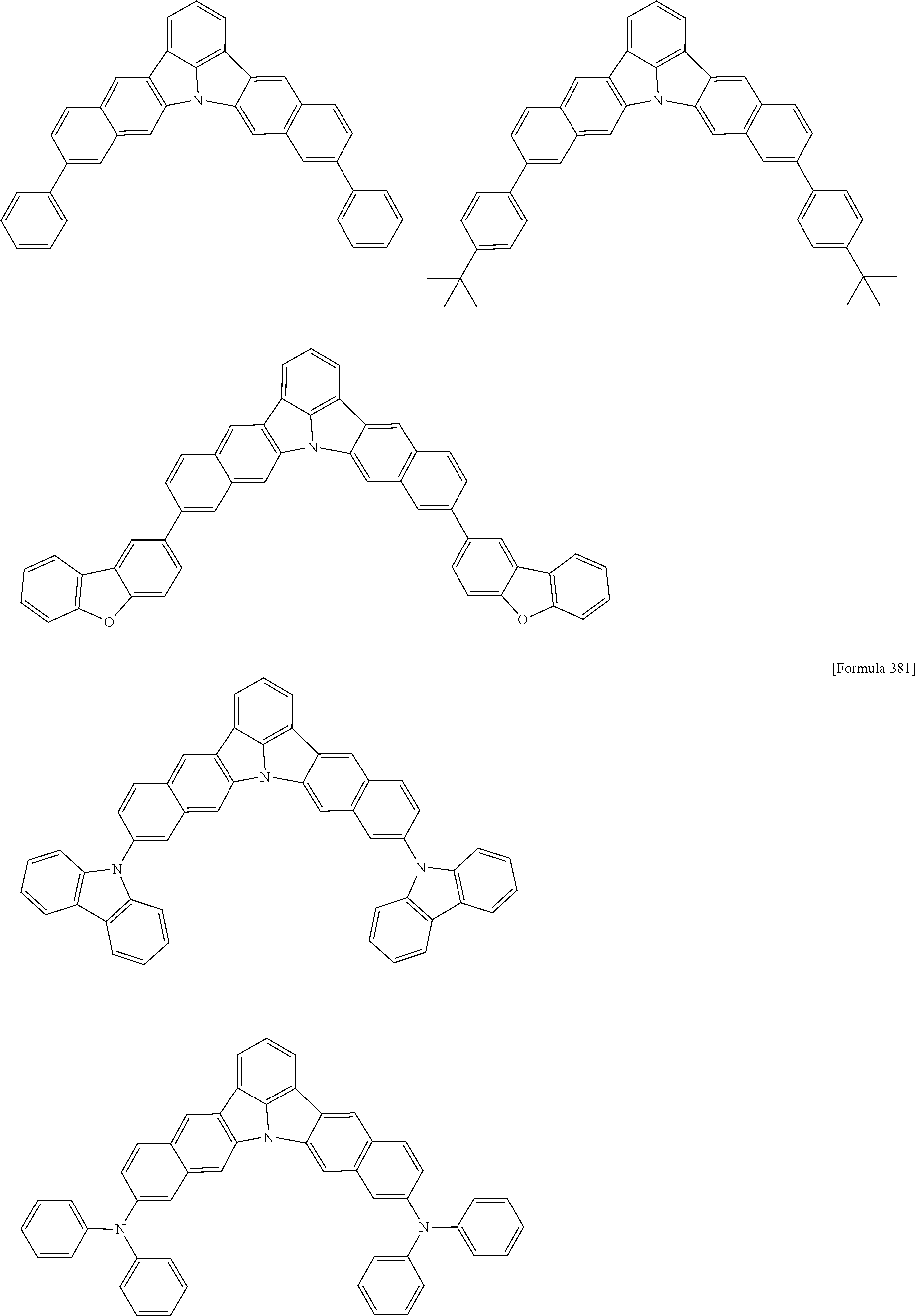 [SMILES: c1ccc(-c2ccc3cc4c5cccc6c7cc8ccc(-c9ccccc9)cc8cc7n(c4cc3c2)c56)cc1 ; CC(C)(C)c1ccc(-c2ccc3cc4c5cccc6c7cc8ccc(-c9ccc(C(C)(C)C)cc9)cc8cc7n(c4cc3c2)c56)cc1 ; c1ccc2c(c1)oc1ccc(-c3ccc4cc5c6cccc7c8cc9ccc(-c%10ccc%11oc%12ccccc%12c%11c%10)cc9cc8n(c5cc4c3)c67)cc12 ; c1ccc2c(c1)c1ccccc1n2-c1ccc2cc3c4cccc5c6cc7ccc(-n8c9ccccc9c9ccccc98)cc7cc6n(c3cc2c1)c45 ; c1ccc(N(c2ccccc2)c2ccc3cc4c5cccc6c7cc8ccc(N(c9ccccc9)c9ccccc9)cc8cc7n(c4cc3c2)c56)cc1]

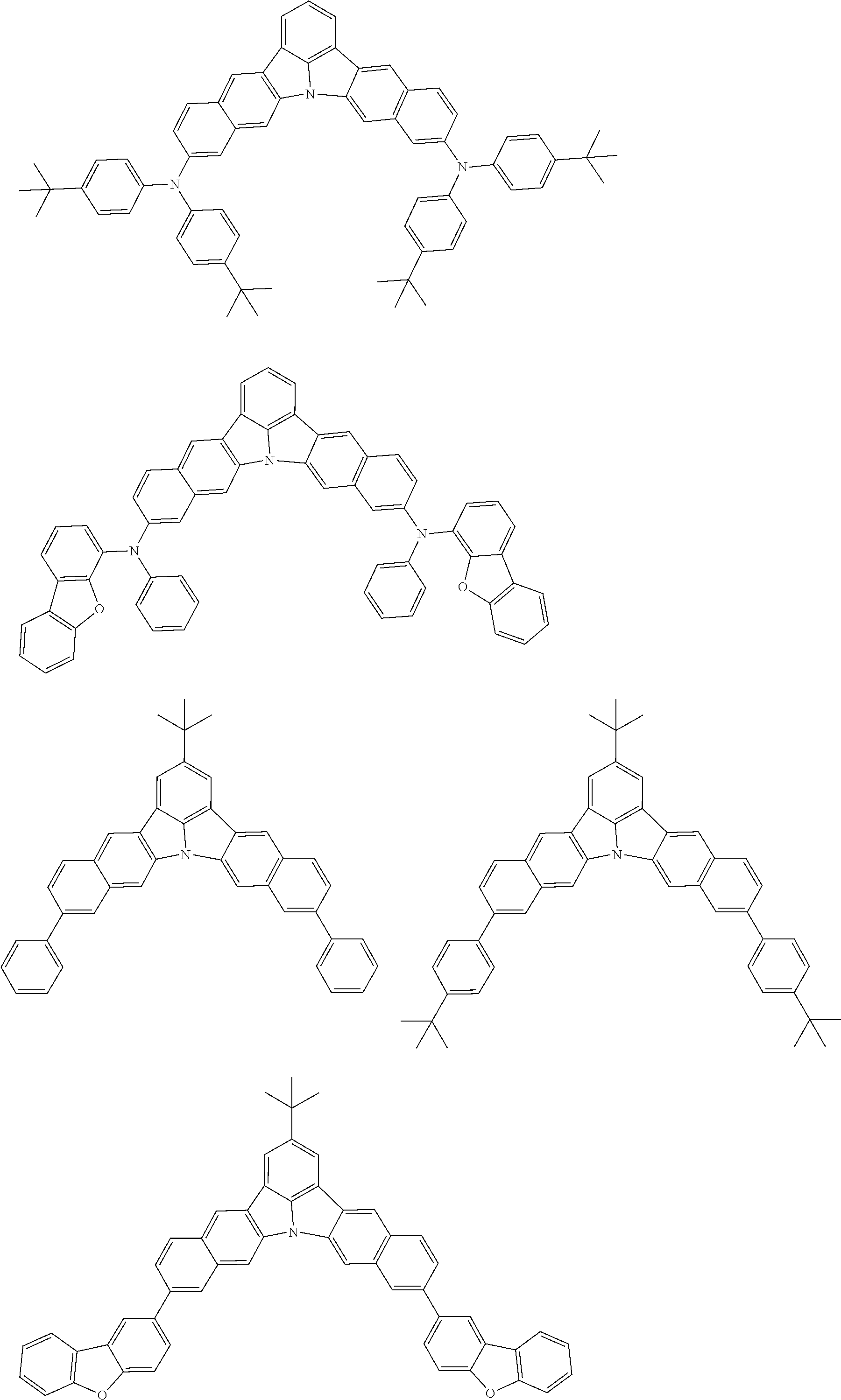

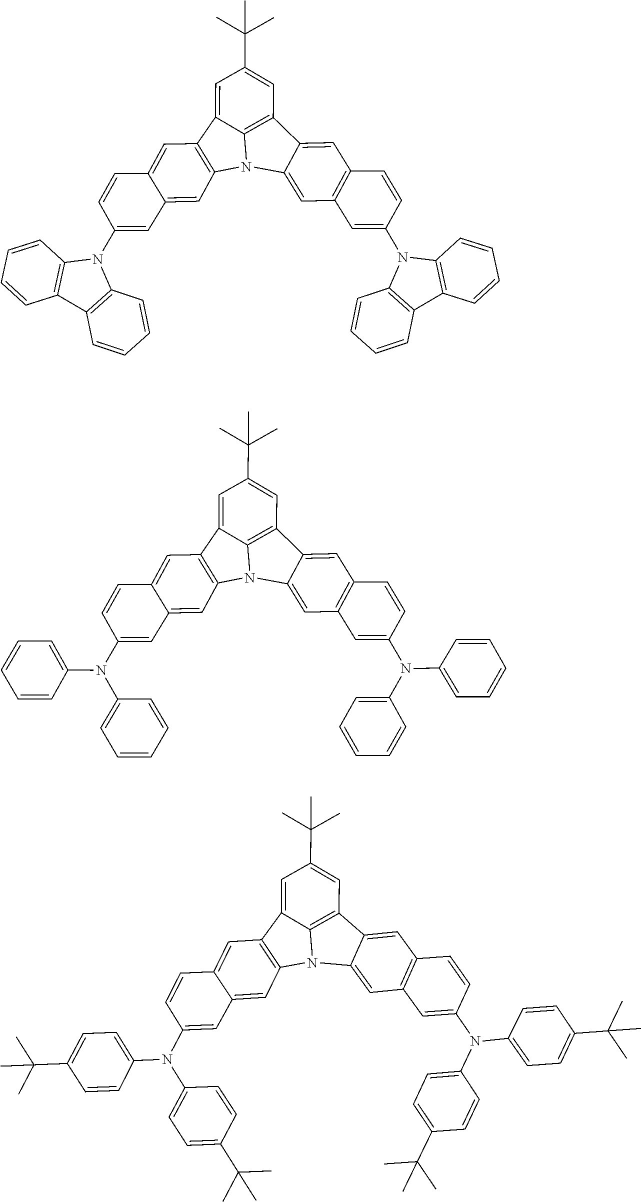 [SMILES: CC(C)(C)c1cc2c3cc4ccc(-n5c6ccccc6c6ccccc65)cc4cc3n3c4cc5cc(-n6c7ccccc7c7ccccc76)ccc5cc4c(c1)c23 ; CC(C)(C)c1cc2c3cc4ccc(N(c5ccccc5)c5ccccc5)cc4cc3n3c4cc5cc(N(c6ccccc6)c6ccccc6)ccc5cc4c(c1)c23 ; CC(C)(C)c1ccc(N(c2ccc(C(C)(C)C)cc2)c2ccc3cc4c5cc(C(C)(C)C)cc6c7cc8ccc(N(c9ccc(C(C)(C)C)cc9)c9ccc(C(C)(C)C)cc9)cc8cc7n(c4cc3c2)c56)cc1]

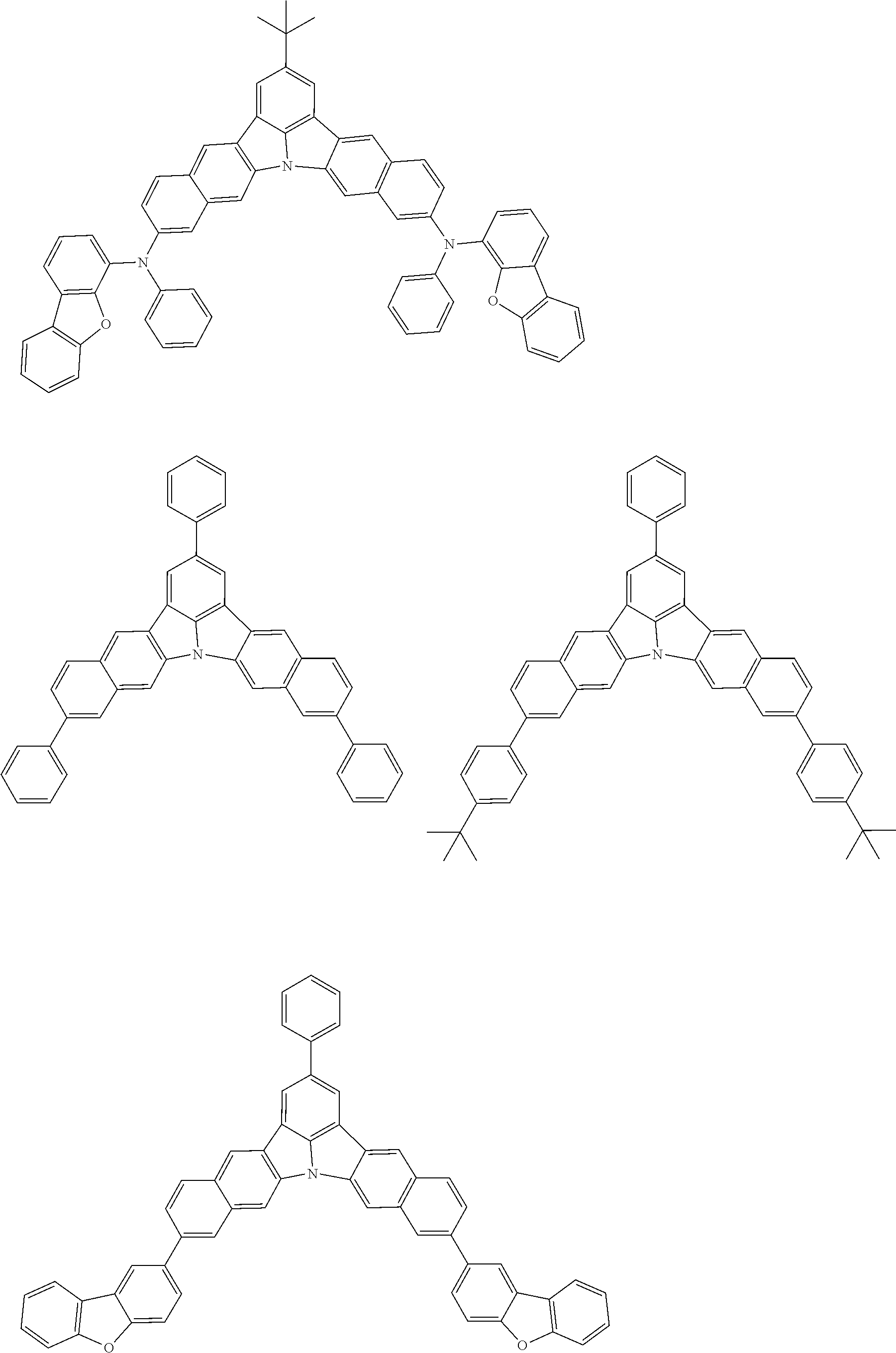 [SMILES: CC(C)(C)c1cc2c3cc4ccc(N(c5ccccc5)c5cccc6c5oc5ccccc56)cc4cc3n3c4cc5cc(N(c6ccccc6)c6cccc7c6oc6ccccc67)ccc5cc4c(c1)c23 ; c1ccc(-c2ccc3cc4c5cc(-c6ccccc6)cc6c7cc8ccc(-c9ccccc9)cc8cc7n(c4cc3c2)c56)cc1 ; CC(C)(C)c1ccc(-c2ccc3cc4c5cc(-c6ccccc6)cc6c7cc8ccc(-c9ccc(C(C)(C)C)cc9)cc8cc7n(c4cc3c2)c56)cc1 ; c1ccc(-c2cc3c4cc5ccc(-c6ccc7oc8ccccc8c7c6)cc5cc4n4c5cc6cc(-c7ccc8oc9ccccc9c8c7)ccc6cc5c(c2)c34)cc1]

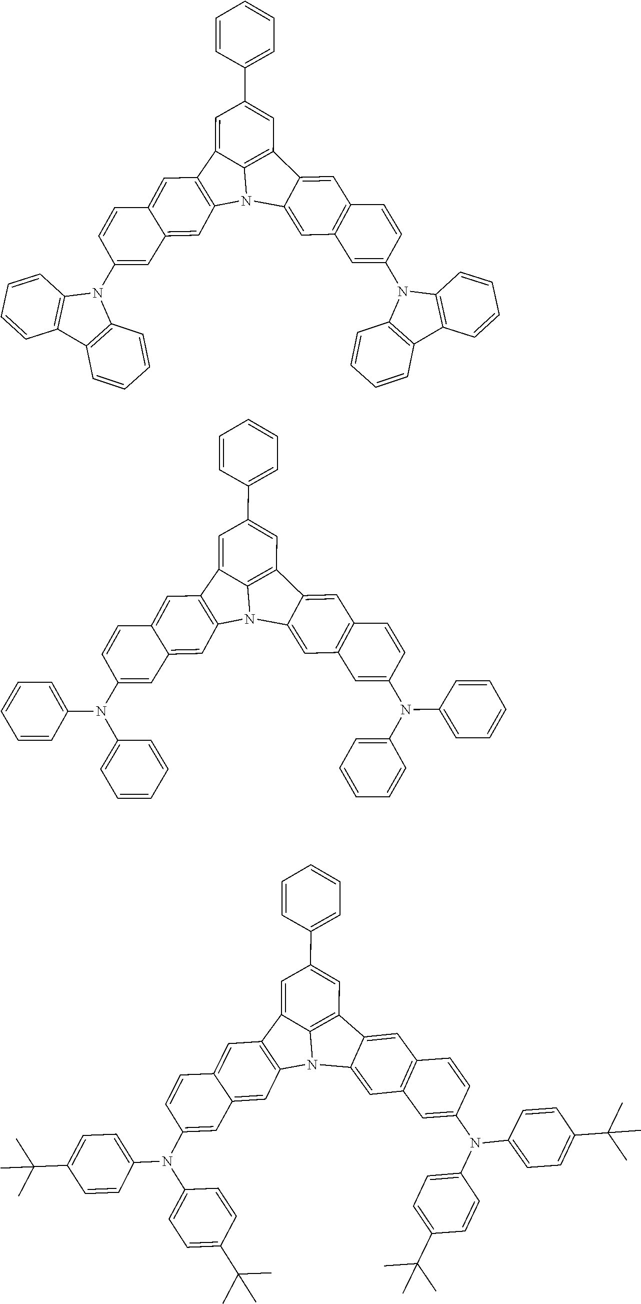 [SMILES: c1ccc(-c2cc3c4cc5ccc(-n6c7ccccc7c7ccccc76)cc5cc4n4c5cc6cc(-n7c8ccccc8c8ccccc87)ccc6cc5c(c2)c34)cc1 ; c1ccc(-c2cc3c4cc5ccc(N(c6ccccc6)c6ccccc6)cc5cc4n4c5cc6cc(N(c7ccccc7)c7ccccc7)ccc6cc5c(c2)c34)cc1 ; CC(C)(C)c1ccc(N(c2ccc(C(C)(C)C)cc2)c2ccc3cc4c5cc(-c6ccccc6)cc6c7cc8ccc(N(c9ccc(C(C)(C)C)cc9)c9ccc(C(C)(C)C)cc9)cc8cc7n(c4cc3c2)c56)cc1]

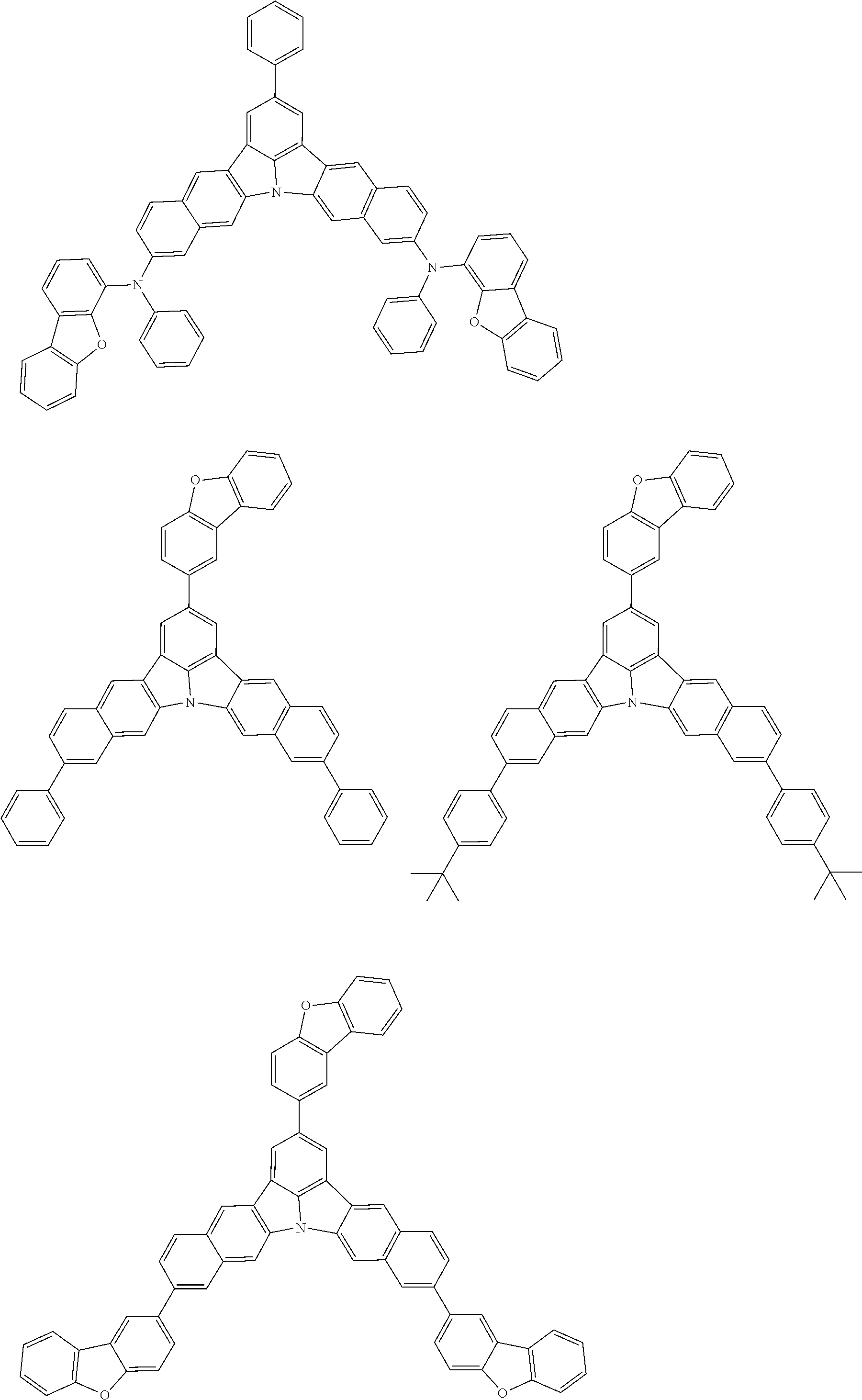 [SMILES: c1ccc(-c2cc3c4cc5ccc(N(c6ccccc6)c6cccc7c6oc6ccccc67)cc5cc4n4c5cc6cc(N(c7ccccc7)c7cccc8c7oc7ccccc78)ccc6cc5c(c2)c34)cc1 ; c1ccc(-c2ccc3cc4c5cc(-c6ccc7oc8ccccc8c7c6)cc6c7cc8ccc(-c9ccccc9)cc8cc7n(c4cc3c2)c56)cc1 ; CC(C)(C)c1ccc(-c2ccc3cc4c5cc(-c6ccc7oc8ccccc8c7c6)cc6c7cc8ccc(-c9ccc(C(C)(C)C)cc9)cc8cc7n(c4cc3c2)c56)cc1 ; c1ccc2c(c1)oc1ccc(-c3ccc4cc5c6cc(-c7ccc8oc9ccccc9c8c7)cc7c8cc9ccc(-c%10ccc%11oc%12ccccc%12c%11c%10)cc9cc8n(c5cc4c3)c67)cc12]

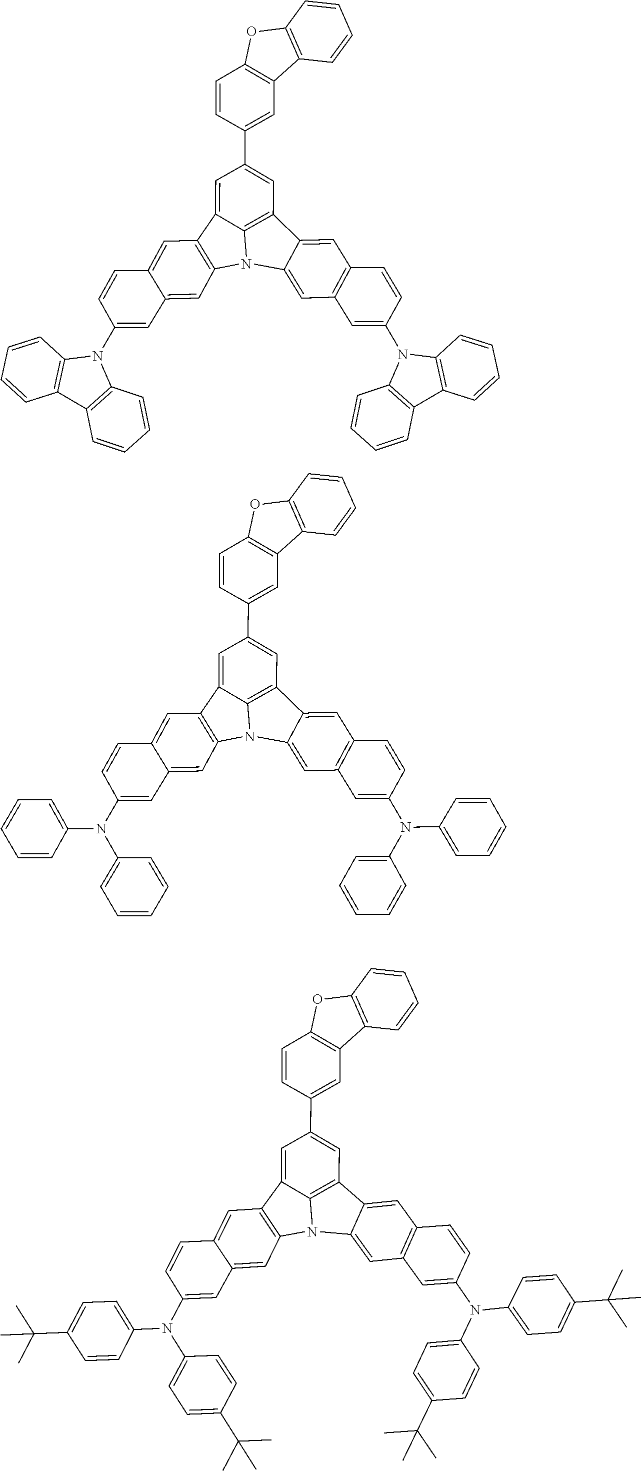

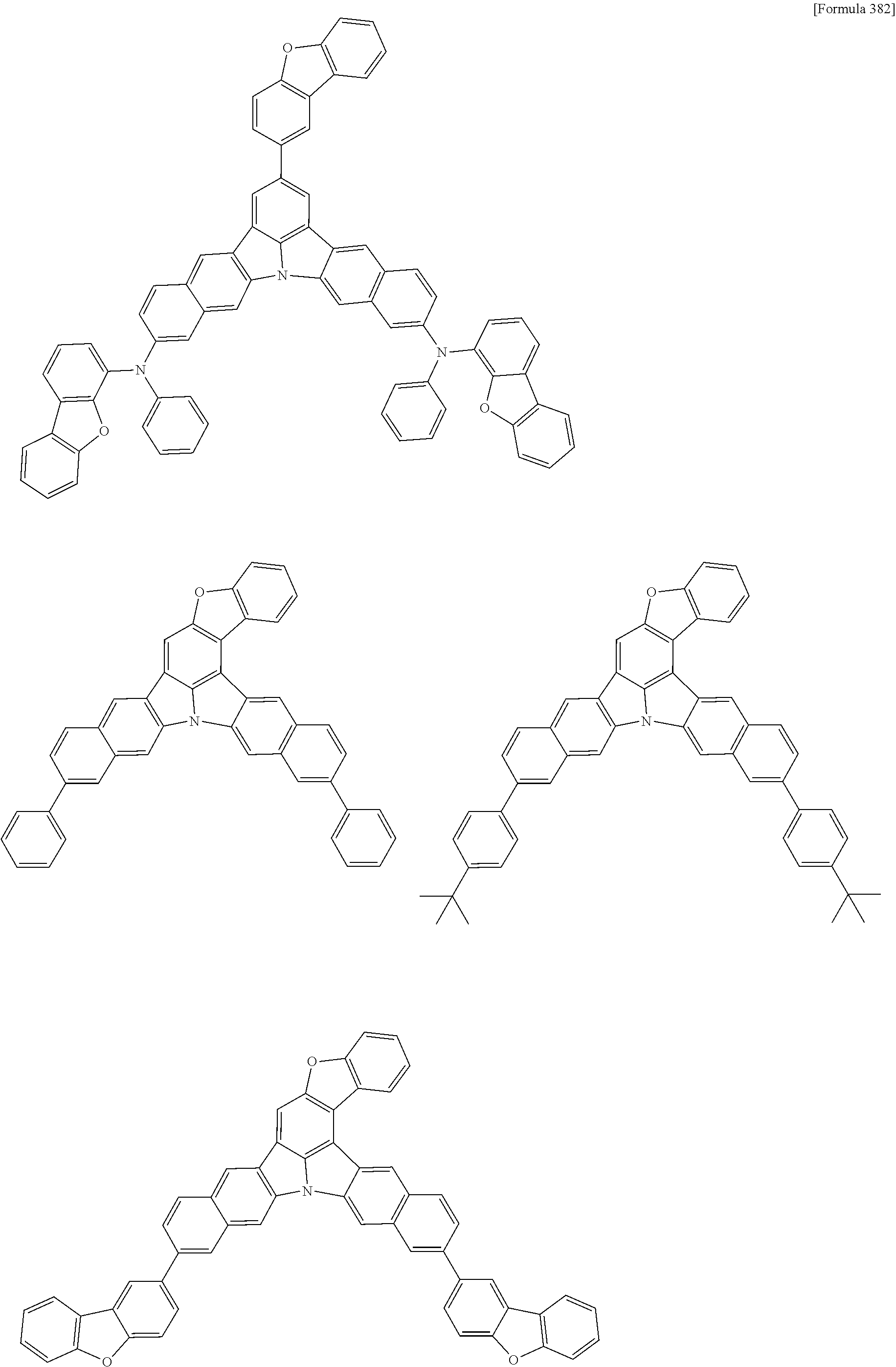 [SMILES: c1ccc(N(c2ccc3cc4c5cc(-c6ccc7oc8ccccc8c7c6)cc6c7cc8ccc(N(c9ccccc9)c9cccc%10c9oc9ccccc9%10)cc8cc7n(c4cc3c2)c56)c2cccc3c2oc2ccccc23)cc1 ; c1ccc(-c2ccc3cc4c5cc6oc7ccccc7c6c6c7cc8ccc(-c9ccccc9)cc8cc7n(c4cc3c2)c56)cc1 ; CC(C)(C)c1ccc(-c2ccc3cc4c5cc6oc7ccccc7c6c6c7cc8ccc(-c9ccc(C(C)(C)C)cc9)cc8cc7n(c4cc3c2)c56)cc1 ; c1ccc2c(c1)oc1ccc(-c3ccc4cc5c6cc7oc8ccccc8c7c7c8cc9ccc(-c%10ccc%11oc%12ccccc%12c%11c%10)cc9cc8n(c5cc4c3)c67)cc12]

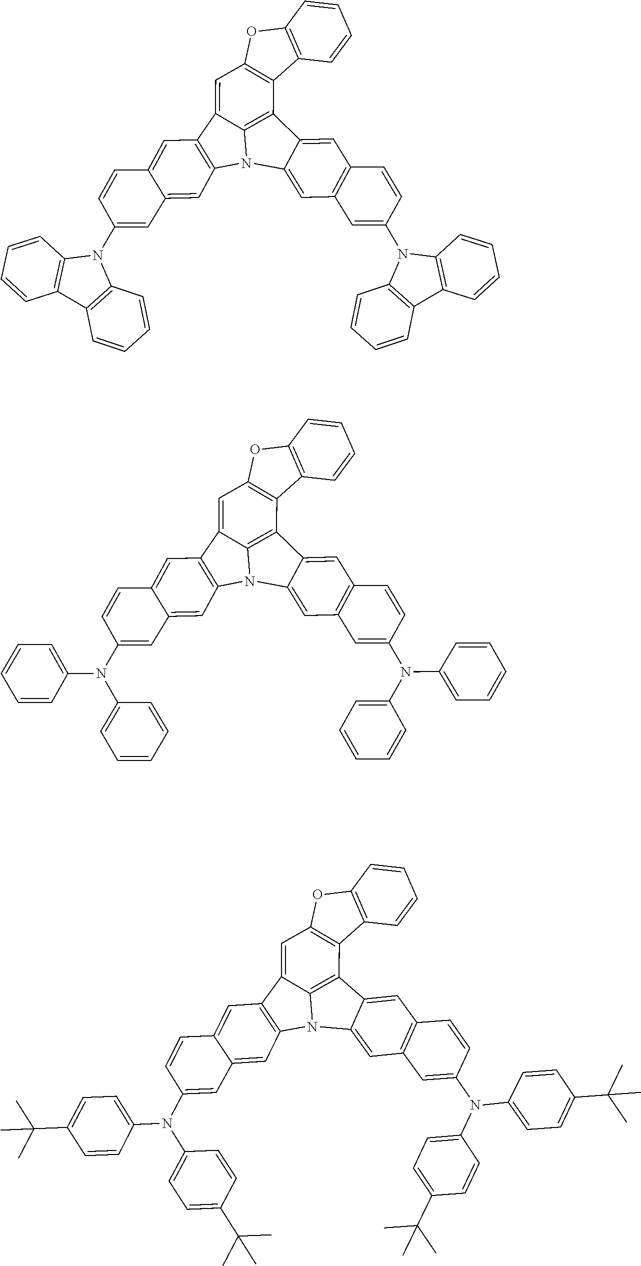 [SMILES: c1ccc2c(c1)oc1cc3c4cc5ccc(-n6c7ccccc7c7ccccc76)cc5cc4n4c5cc6cc(-n7c8ccccc8c8ccccc87)ccc6cc5c(c12)c34 ; c1ccc(N(c2ccccc2)c2ccc3cc4c5cc6oc7ccccc7c6c6c7cc8ccc(N(c9ccccc9)c9ccccc9)cc8cc7n(c4cc3c2)c56)cc1 ; CC(C)(C)c1ccc(N(c2ccc(C(C)(C)C)cc2)c2ccc3cc4c5cc6oc7ccccc7c6c6c7cc8ccc(N(c9ccc(C(C)(C)C)cc9)c9ccc(C(C)(C)C)cc9)cc8cc7n(c4cc3c2)c56)cc1]

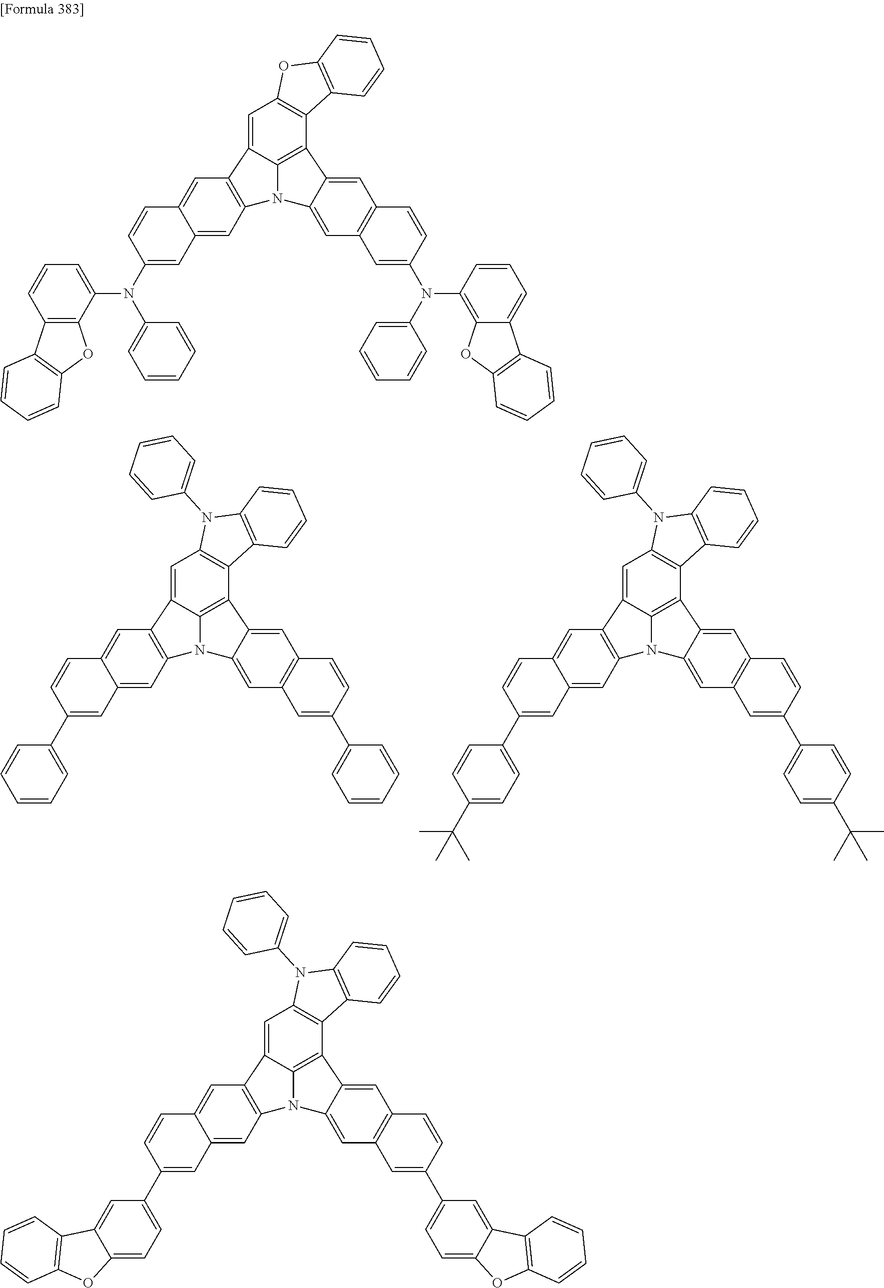 [SMILES: c1ccc(N(c2ccc3cc4c5cc6oc7ccccc7c6c6c7cc8ccc(N(c9ccccc9)c9cccc%10c9oc9ccccc9%10)cc8cc7n(c4cc3c2)c56)c2cccc3c2oc2ccccc23)cc1 ; c1ccc(-c2ccc3cc4c5cc6c(c7ccccc7n6-c6ccccc6)c6c7cc8ccc(-c9ccccc9)cc8cc7n(c4cc3c2)c56)cc1 ; CC(C)(C)c1ccc(-c2ccc3cc4c5cc6c(c7ccccc7n6-c6ccccc6)c6c7cc8ccc(-c9ccc(C(C)(C)C)cc9)cc8cc7n(c4cc3c2)c56)cc1 ; c1ccc(-n2c3ccccc3c3c4c5cc6ccc(-c7ccc8oc9ccccc9c8c7)cc6cc5n5c6cc7cc(-c8ccc9oc%10ccccc%10c9c8)ccc7cc6c(cc32)c45)cc1]

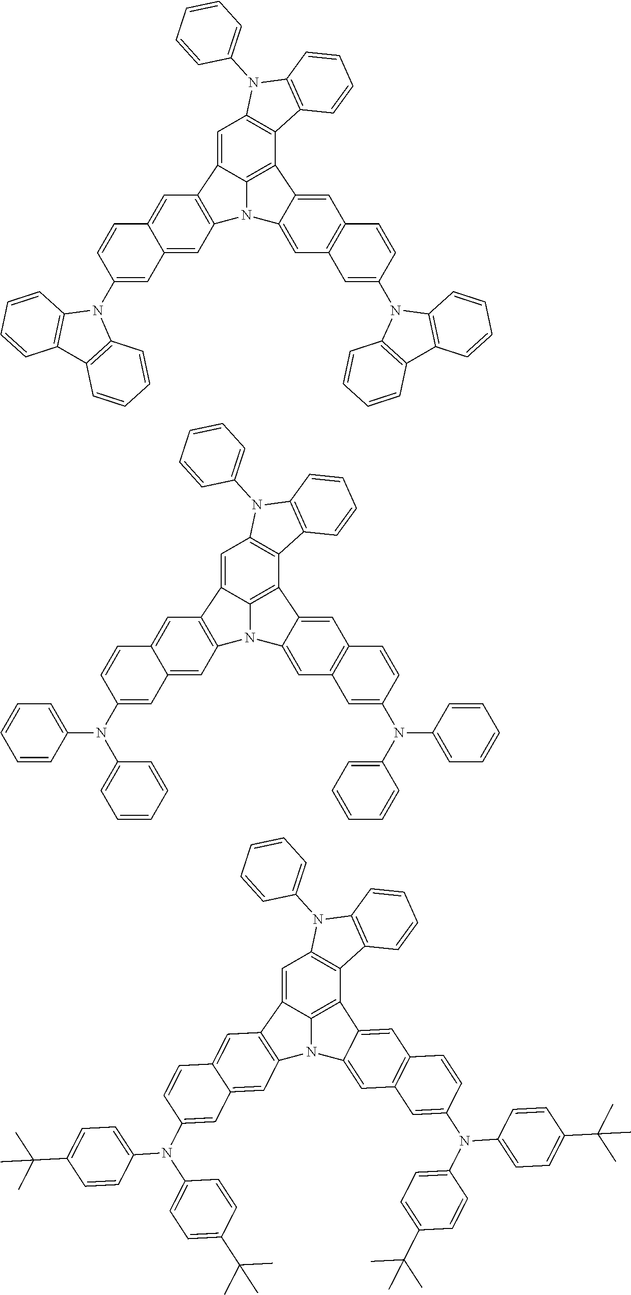 [SMILES: c1ccc(-n2c3ccccc3c3c4c5cc6ccc(-n7c8ccccc8c8ccccc87)cc6cc5n5c6cc7cc(-n8c9ccccc9c9ccccc98)ccc7cc6c(cc32)c45)cc1 ; c1ccc(N(c2ccccc2)c2ccc3cc4c5cc6c(c7ccccc7n6-c6ccccc6)c6c7cc8ccc(N(c9ccccc9)c9ccccc9)cc8cc7n(c4cc3c2)c56)cc1 ; CC(C)(C)c1ccc(N(c2ccc(C(C)(C)C)cc2)c2ccc3cc4c5cc6c(c7ccccc7n6-c6ccccc6)c6c7cc8ccc(N(c9ccc(C(C)(C)C)cc9)c9ccc(C(C)(C)C)cc9)cc8cc7n(c4cc3c2)c56)cc1]

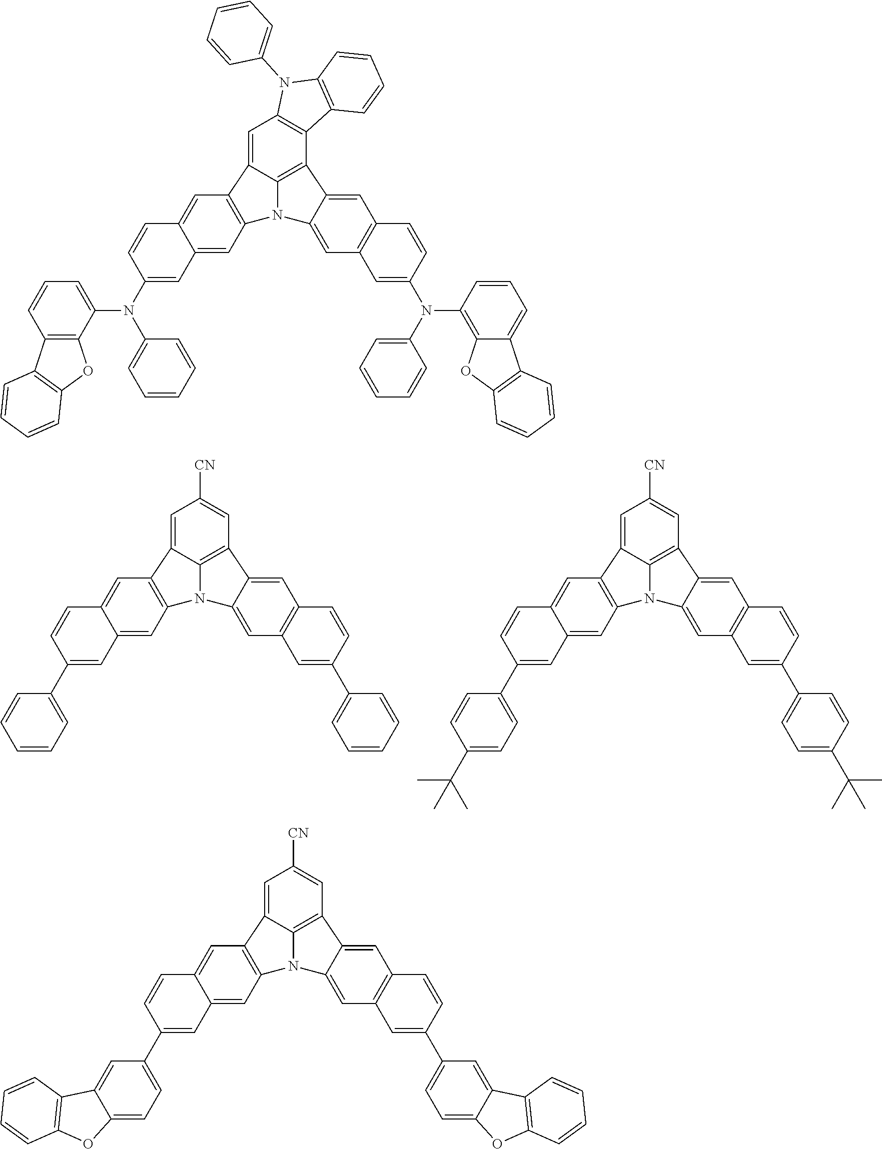

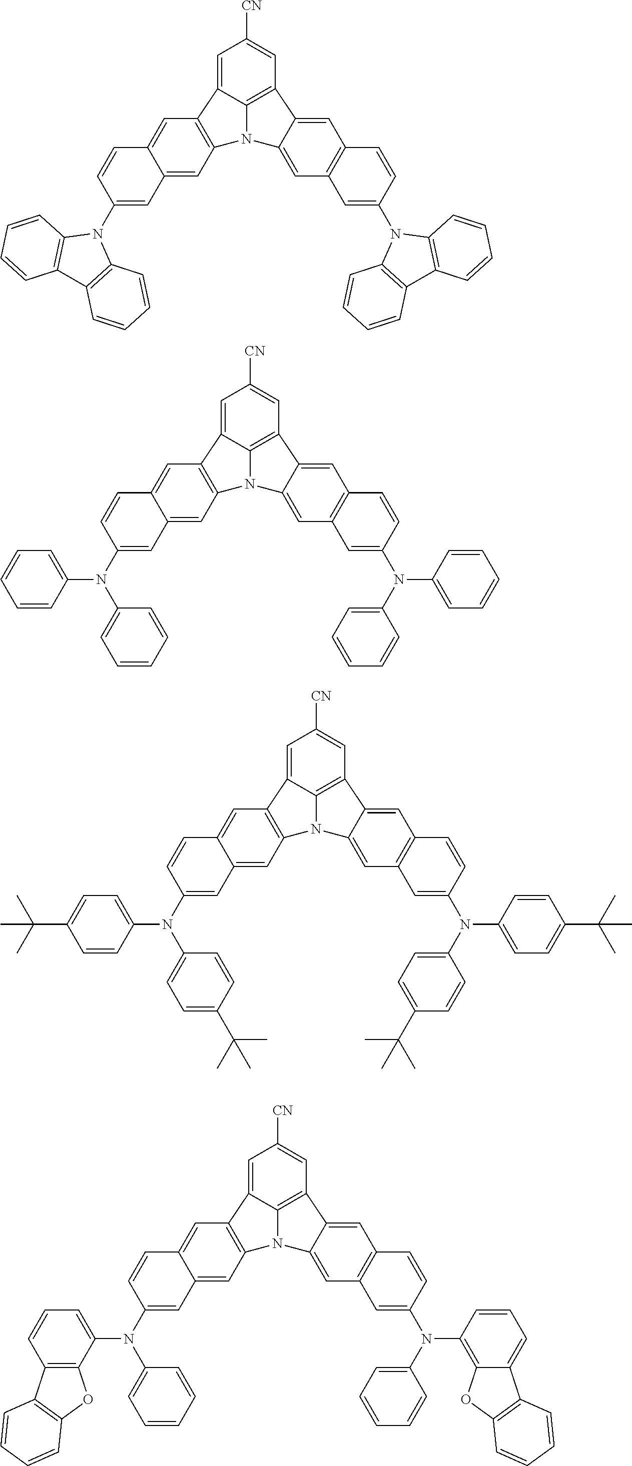

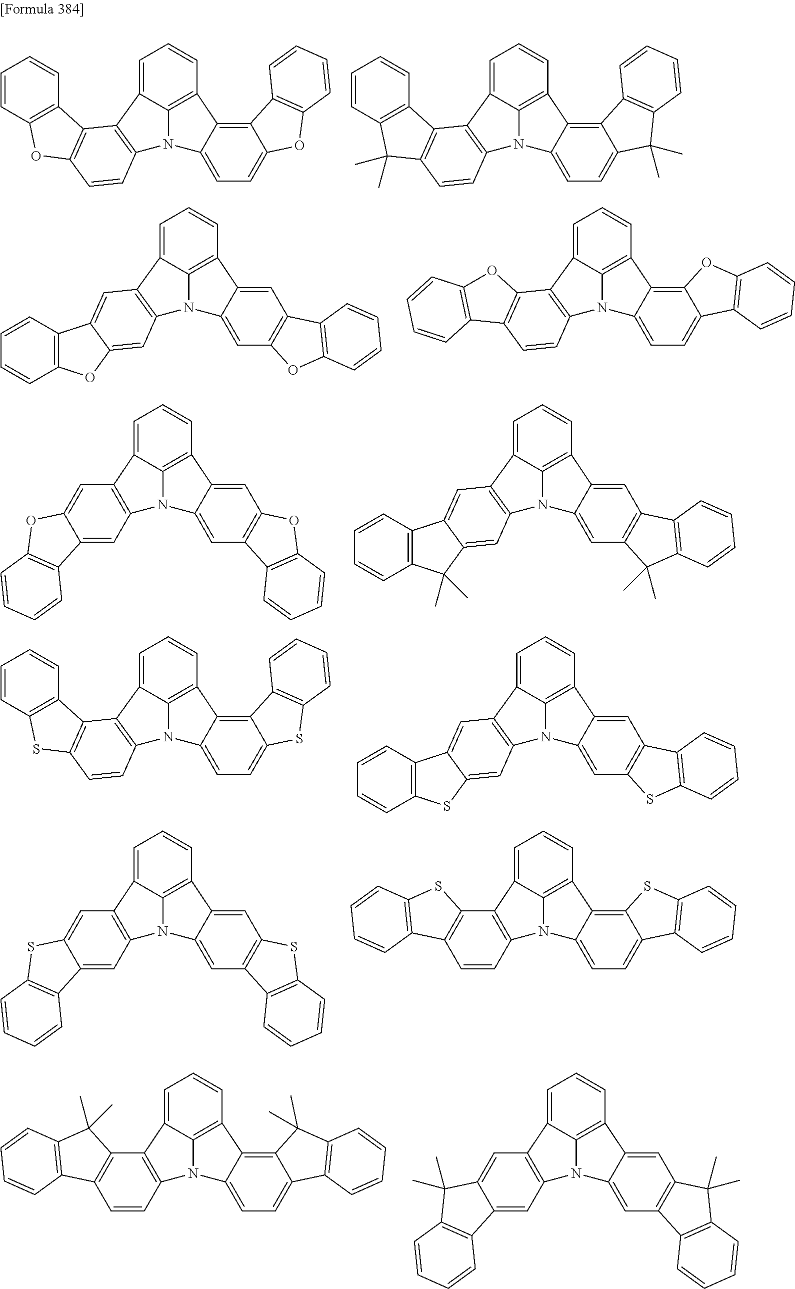

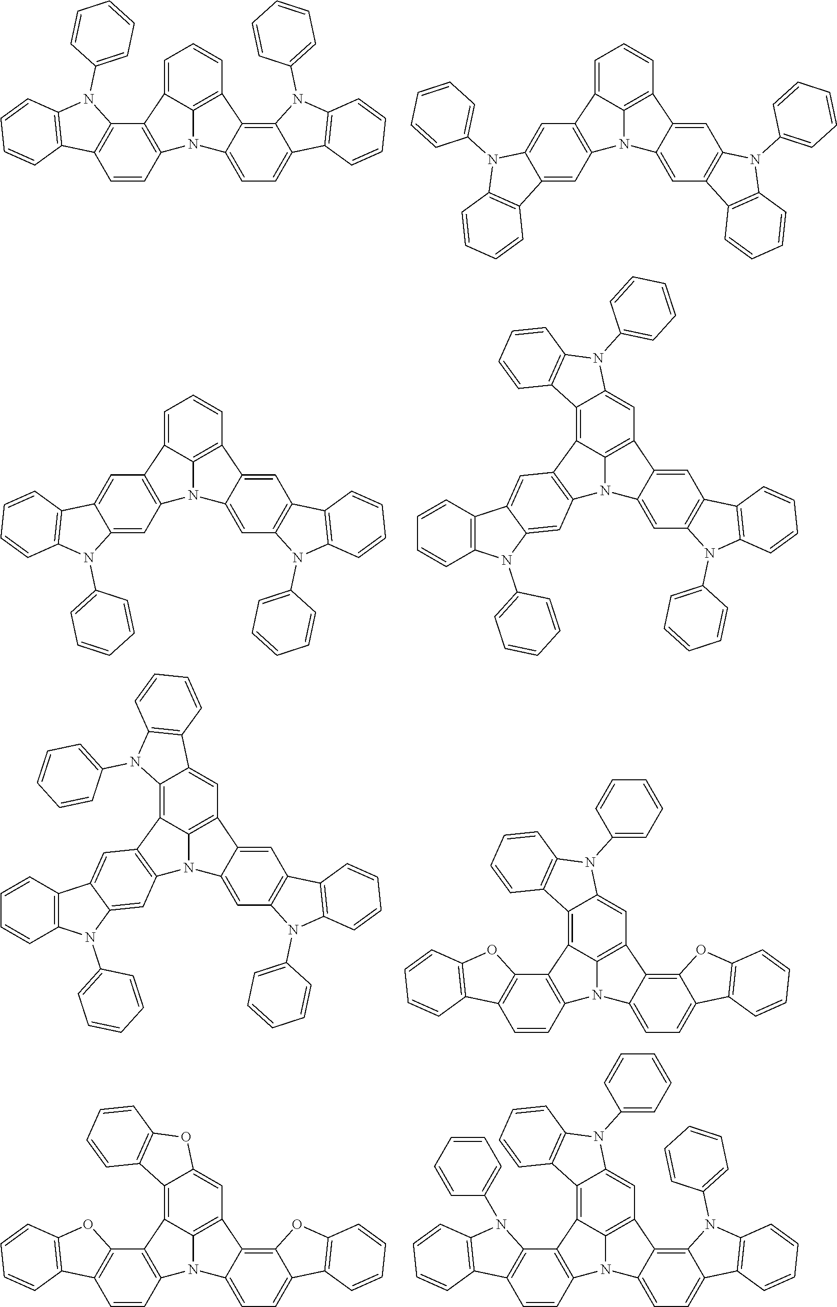

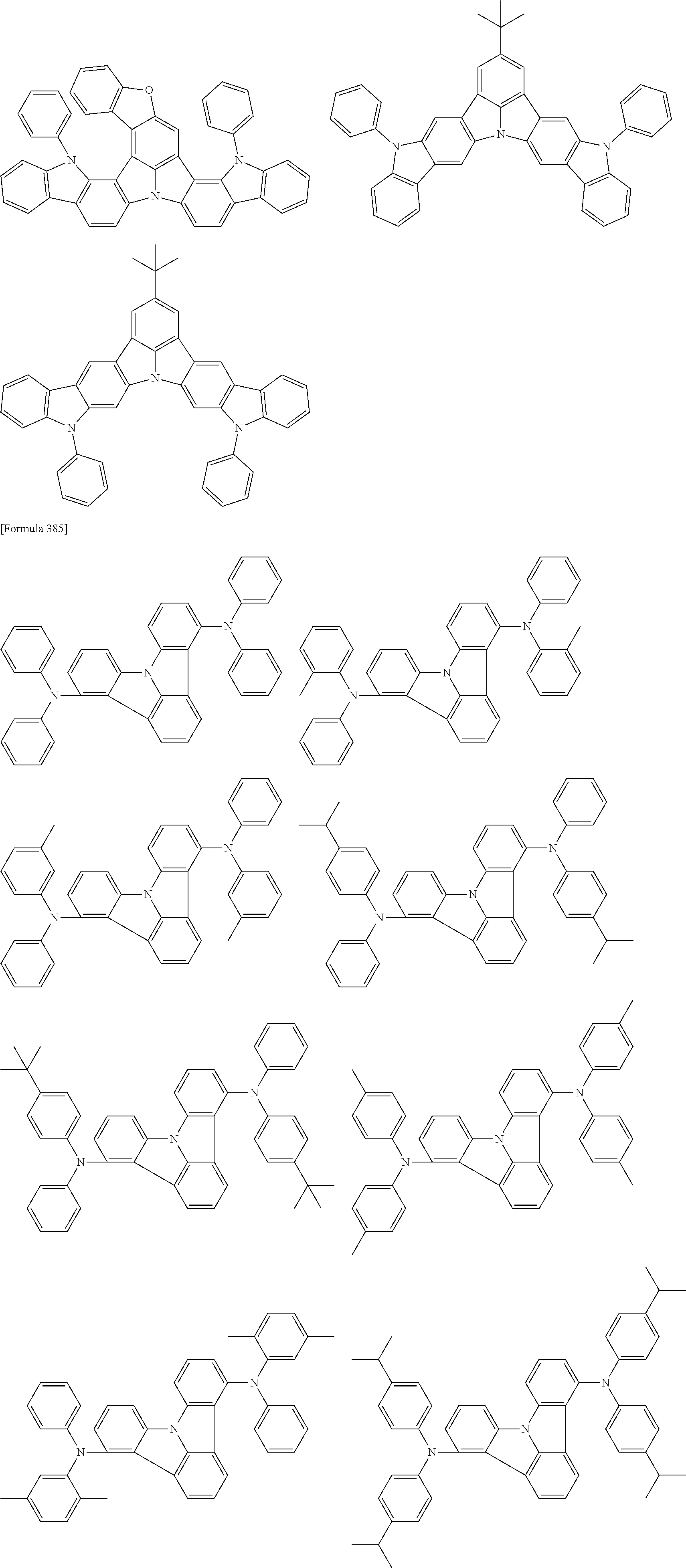

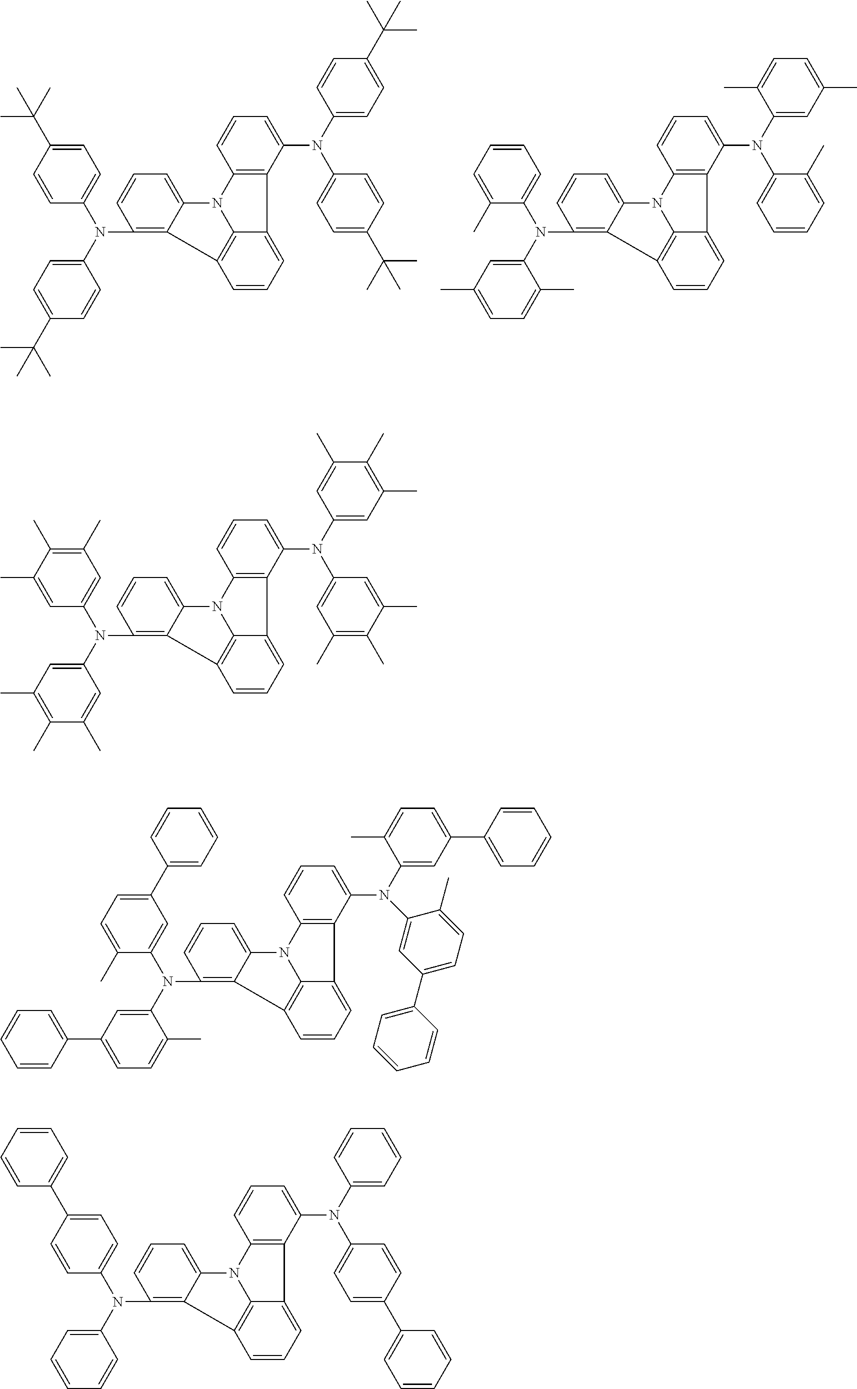

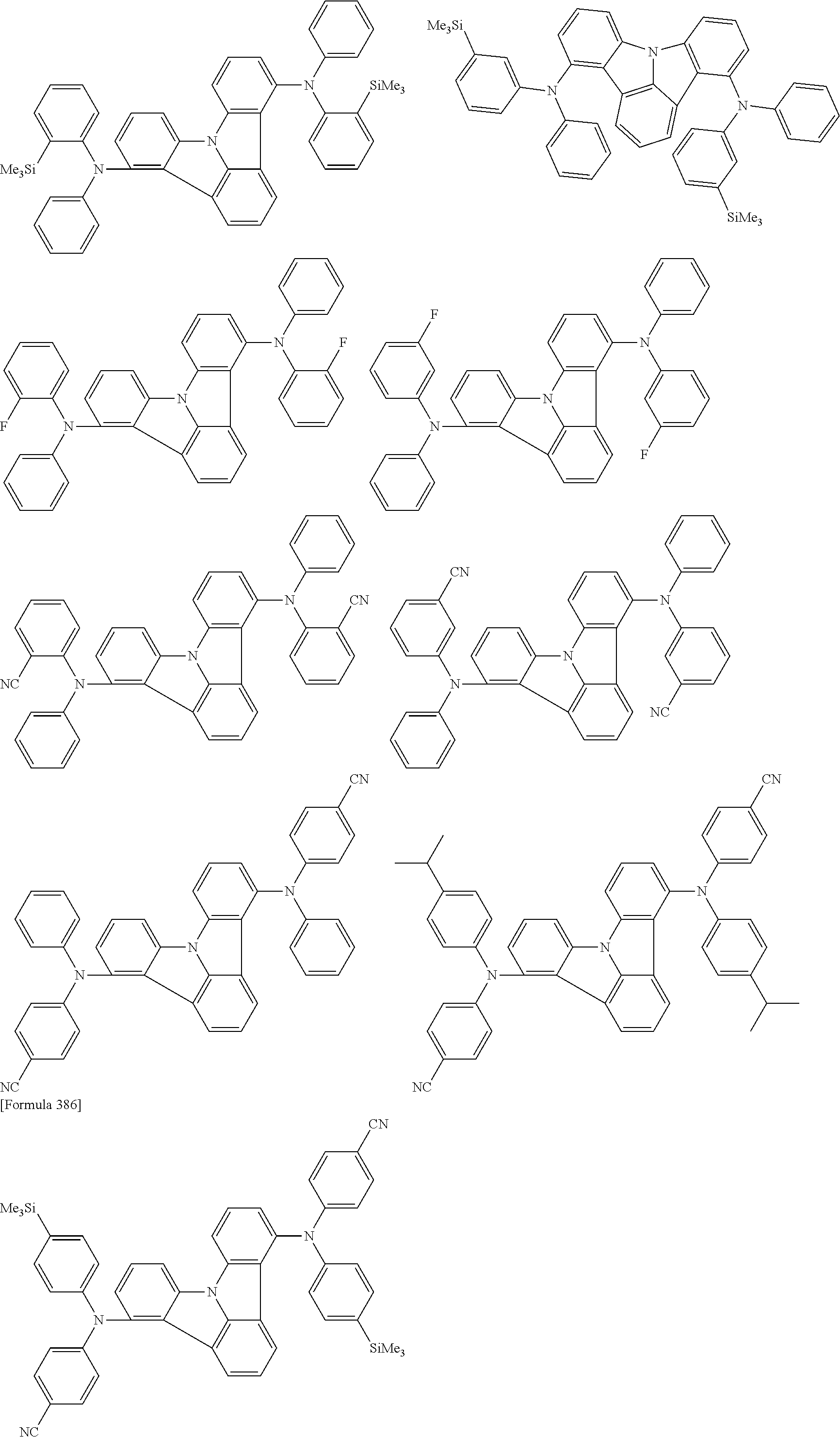

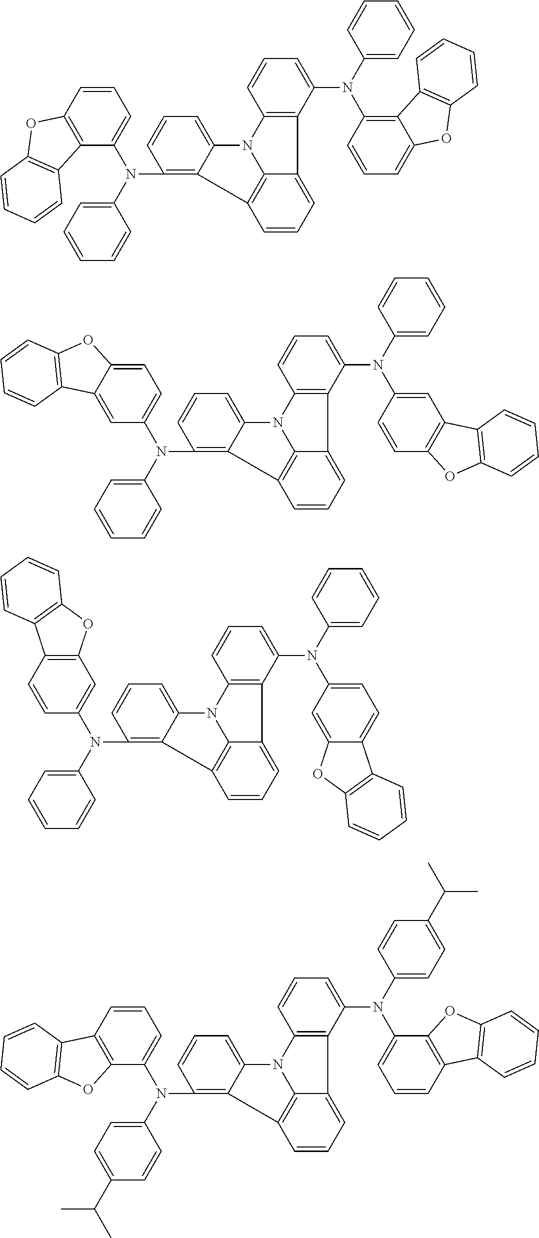 [SMILES: c1ccc(N(c2cccc3oc4ccccc4c23)c2cccc3c2c2cccc4c5c(N(c6ccccc6)c6cccc7oc8ccccc8c67)cccc5n3c24)cc1 ; c1ccc(N(c2ccc3oc4ccccc4c3c2)c2cccc3c2c2cccc4c5c(N(c6ccccc6)c6ccc7oc8ccccc8c7c6)cccc5n3c24)cc1 ; c1ccc(N(c2ccc3c(c2)oc2ccccc23)c2cccc3c2c2cccc4c5c(N(c6ccccc6)c6ccc7c(c6)oc6ccccc67)cccc5n3c24)cc1 ; CC(C)c1ccc(N(c2cccc3c2oc2ccccc23)c2cccc3c2c2cccc4c5c(N(c6ccc(C(C)C)cc6)c6cccc7c6oc6ccccc67)cccc5n3c24)cc1]

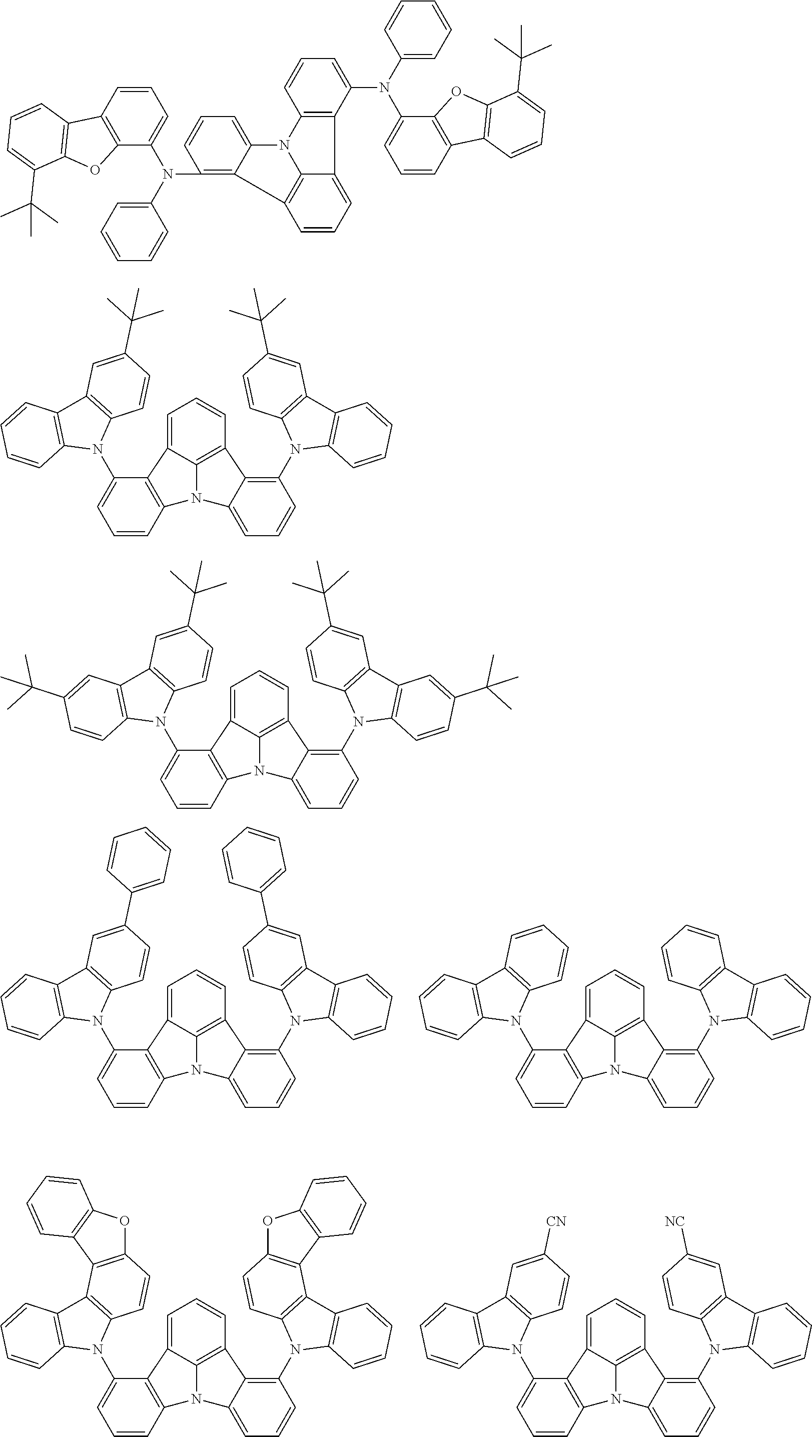

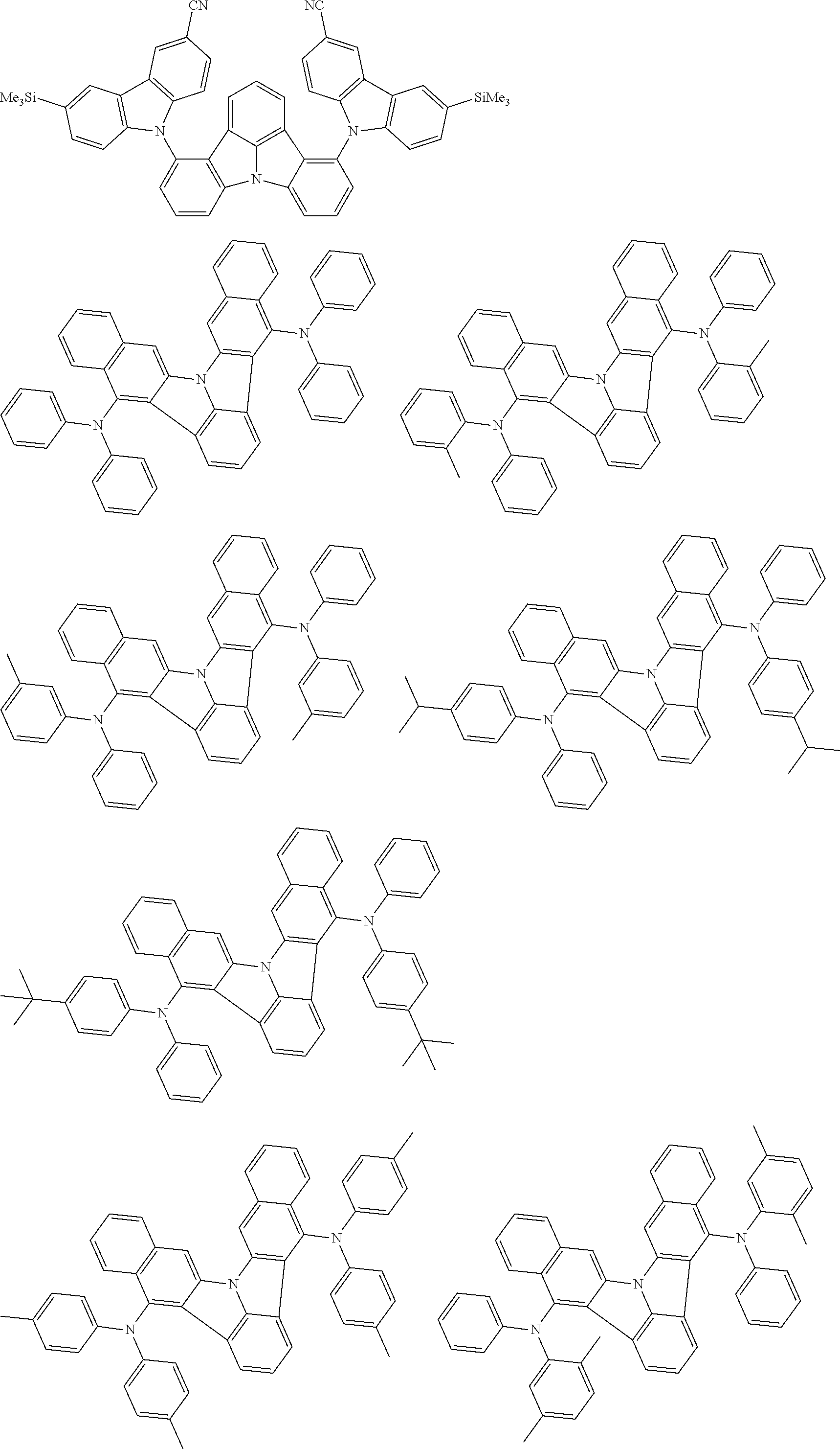

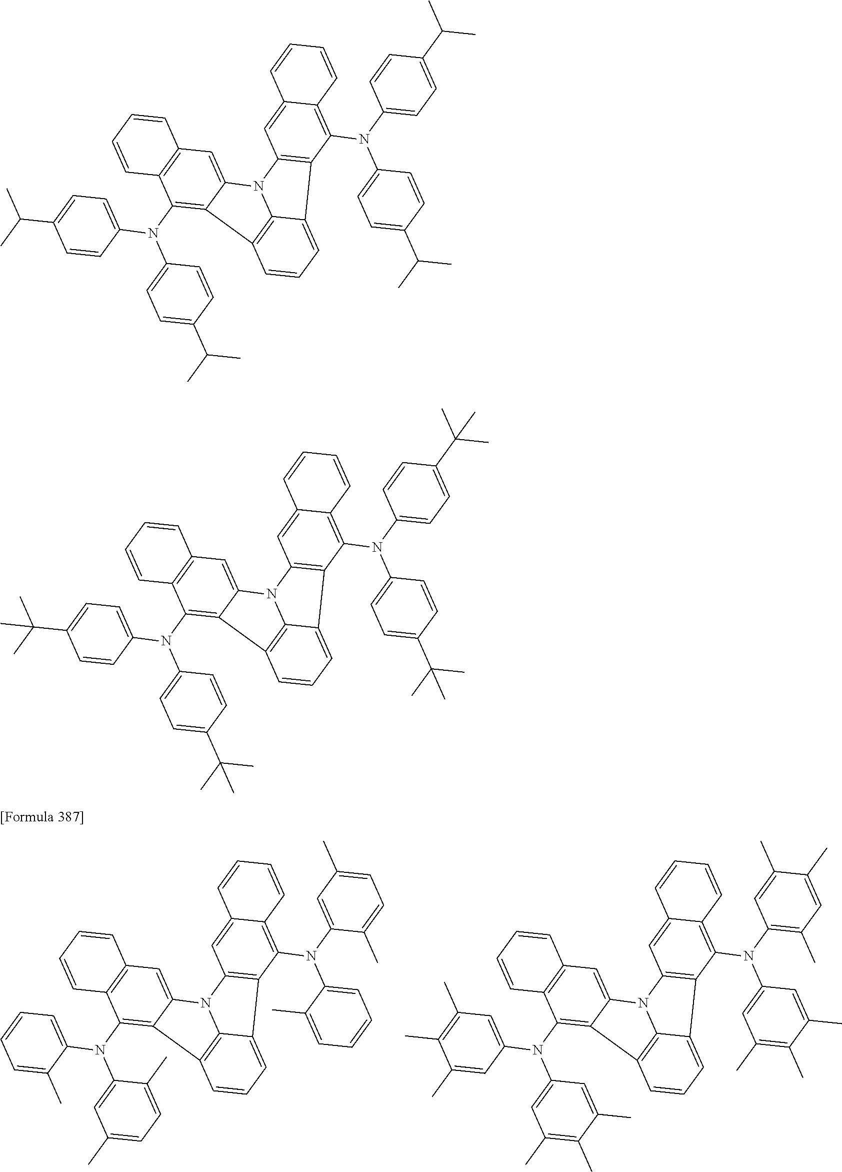

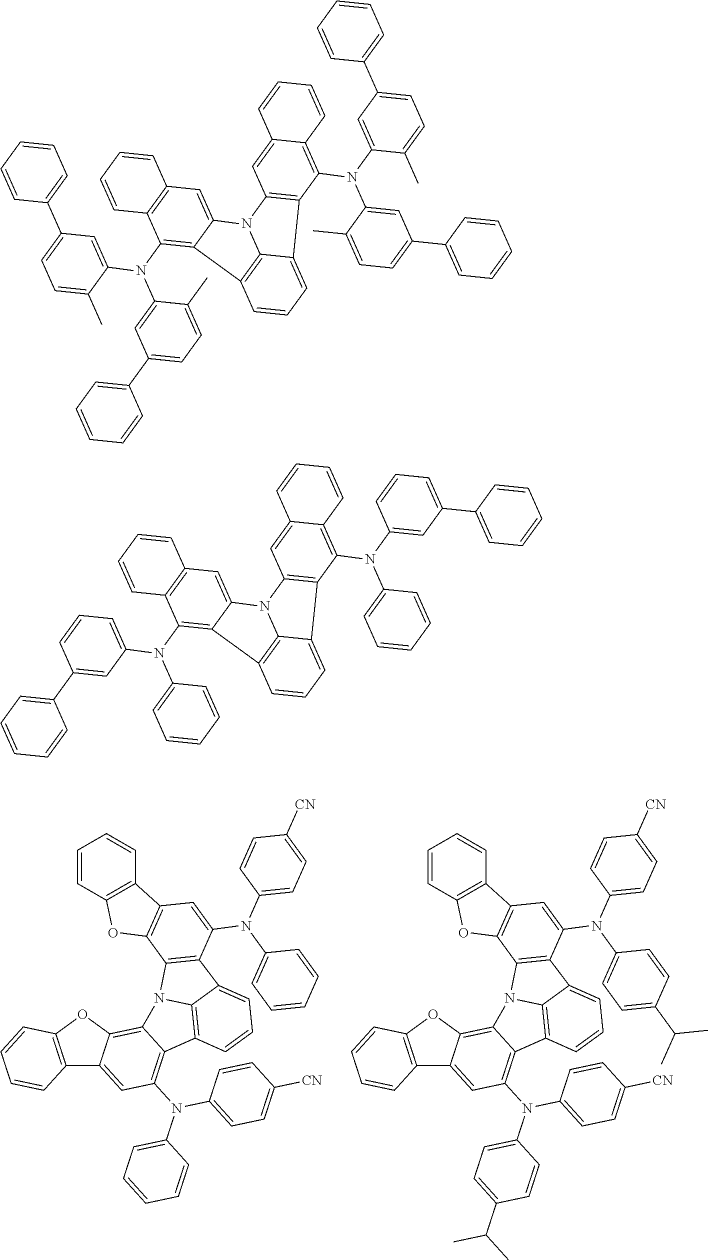 [SMILES: Cc1ccc(-c2ccccc2)cc1N(c1cc(-c2ccccc2)ccc1C)c1c2ccccc2cc2c1c1cccc3c4c(N(c5cc(-c6ccccc6)ccc5C)c5cc(-c6ccccc6)ccc5C)c5ccccc5cc4n2c13 ; c1ccc(-c2cccc(N(c3ccccc3)c3c4ccccc4cc4c3c3cccc5c6c(N(c7ccccc7)c7cccc(-c8ccccc8)c7)c7ccccc7cc6n4c35)c2)cc1 ; N#Cc1ccc(N(c2ccccc2)c2cc3c4ccccc4oc3c3c2c2cccc4c5c(N(c6ccccc6)c6ccc(C#N)cc6)cc6c7ccccc7oc6c5n3c24)cc1 ; CC(C)c1ccc(N(c2ccc(C#N)cc2)c2cc3c4ccccc4oc3c3c2c2cccc4c5c(N(c6ccc(C#N)cc6)c6ccc(C(C)C)cc6)cc6c7ccccc7oc6c5n3c24)cc1]

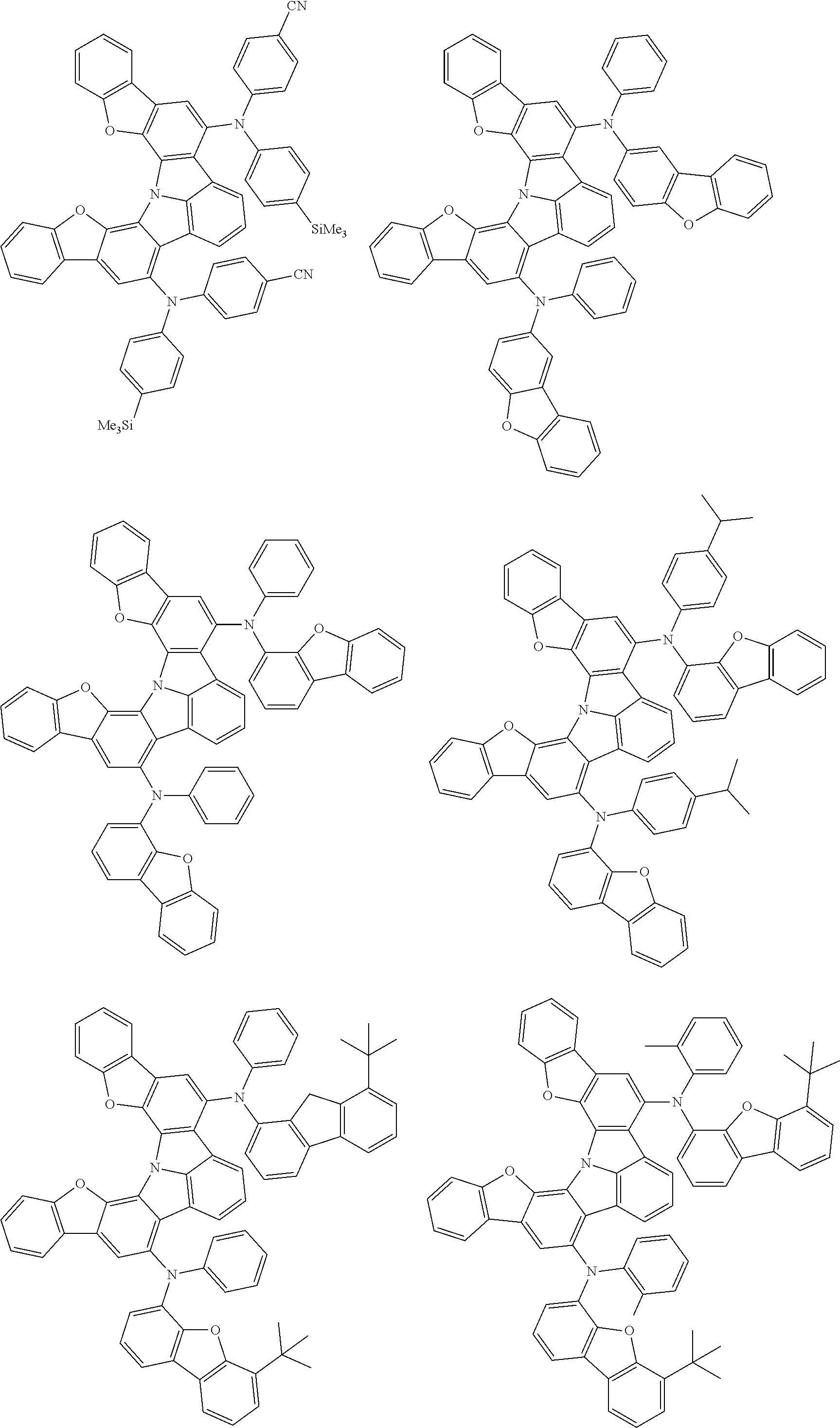

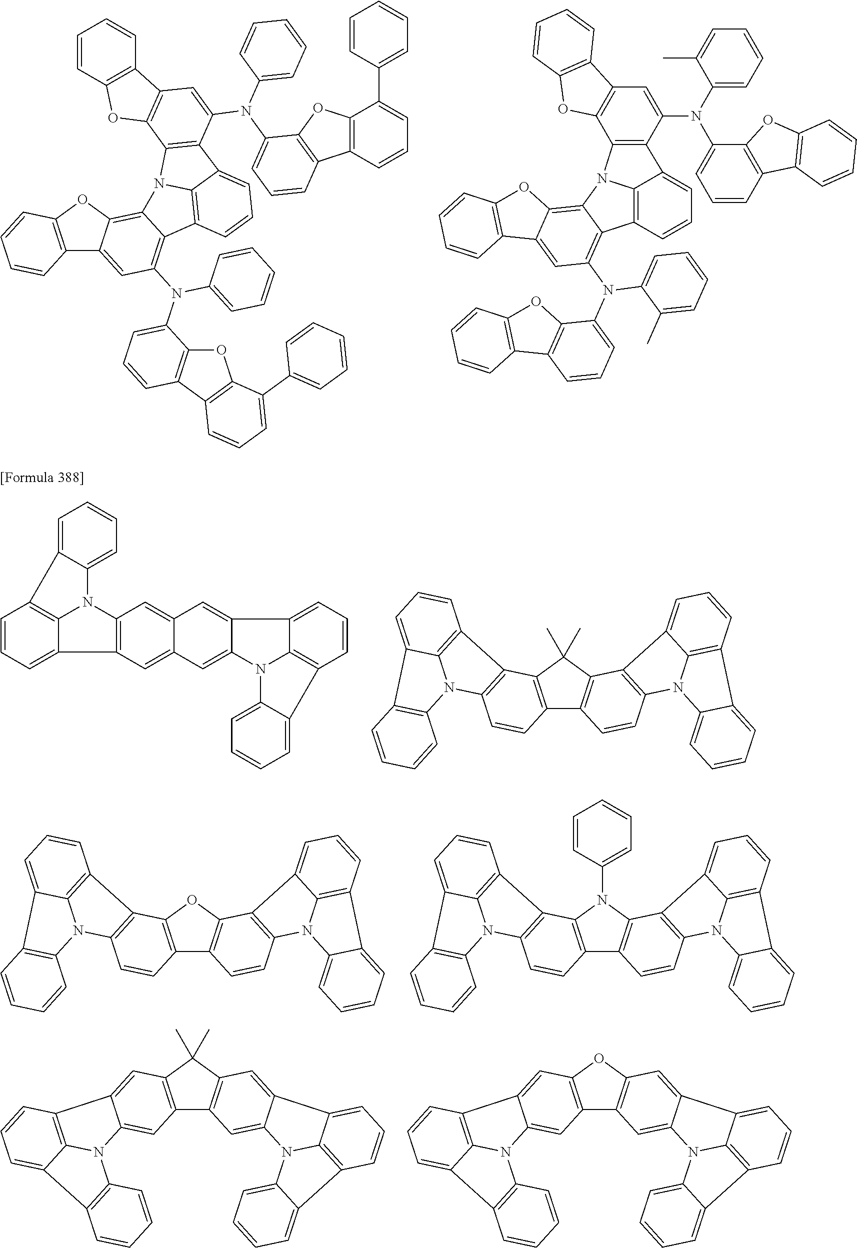

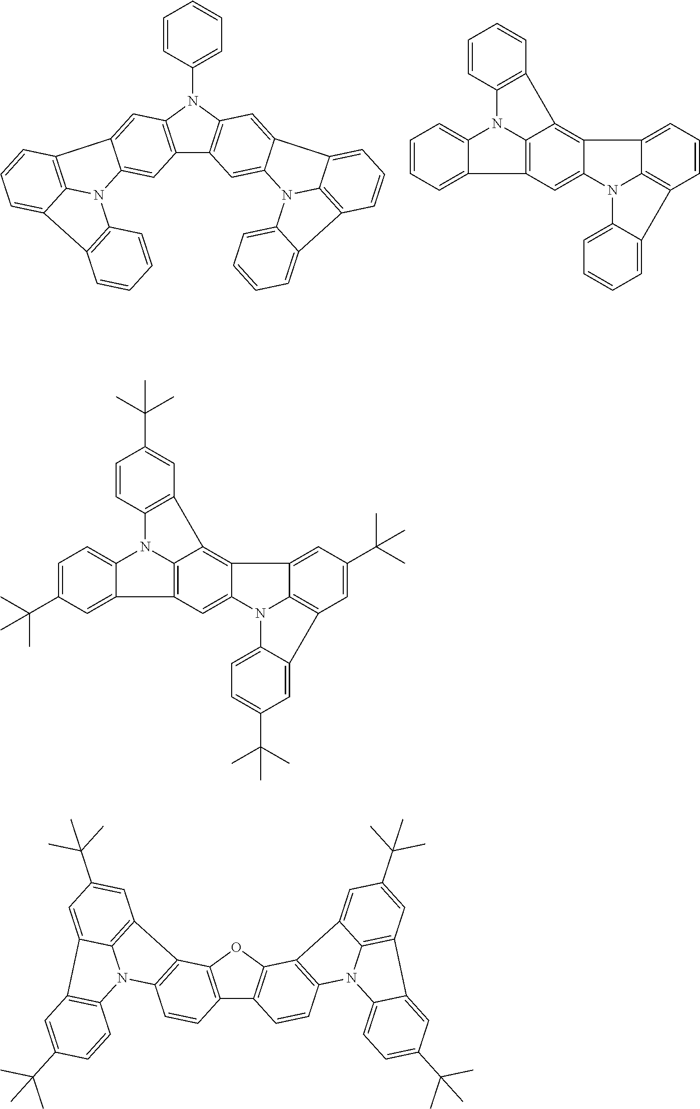

### Compound Represented by Formula (5)

The compound represented by the formula (5) will be described below. The compound represented by the formula (5) corresponds to a compound represented by the formula (41-3).

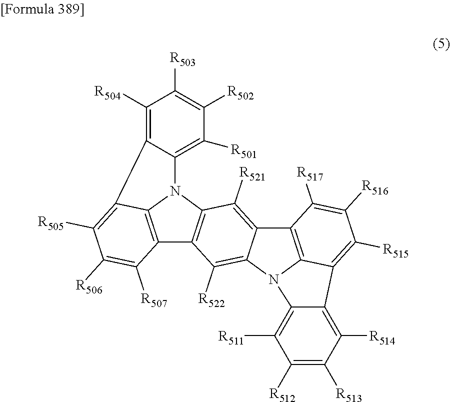

In the formula (5):
at least one combination of adjacent two or more of R₅₀₁ to R₅₀₇ and R₅₁₁ to R₅₁₇ are mutually bonded to form a substituted or unsubstituted monocyclic ring, mutually bonded to form a substituted or unsubstituted fused ring, or not mutually bonded;
R₅₀₁ to R₅₀₇ and R₅₁₁ to R₅₁₇ forming neither the monocyclic ring nor the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms; and
R₅₂₁ and R₅₂₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

“A combination of adjacent two or more of R₅₀₁ to R₅₀₇ and R₅₁₁ to R₅₁₇” refers to, for instance, a combination of R₅₀₁ and R₅₀₂, a combination of R₅₀₂ and R₅₀₃, a combination of R₅₀₃ and R₅₀₄, a combination of R₅₀₅ and R₅₀₆, a combination of R₅₀₆ and R₅₀₇, and a combination of R₅₀₁, R₅₀₂, and R₅₀₃.

In an exemplary embodiment, at least one, preferably two of R₅₀₁ to R₅₀₇ or R₅₁₁ to R₅₁₇ are each a group represented by —N(R₉₀₆)(R₉₀₇).

In an exemplary embodiment, R₅₀₁ to R₅₀₇ and R₅₁₁ to R₅₁₇ are each independently a hydrogen atom, a substituted or unsubstituted aryl group having 6 to 50 ring carbon atoms, or a substituted or unsubstituted heterocyclic group having 5 to 50 ring atoms.

In an exemplary embodiment, the compound represented by the formula (5) is a compound represented by a formula (52) below.

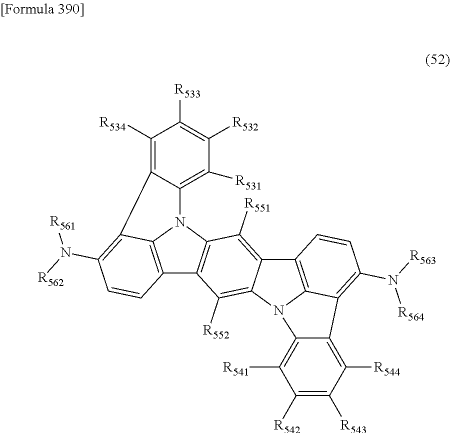

In the formula (52):
at least one combination of adjacent two or more of R₅₃₁ to R₅₃₄ and R₅₄₁ to R₅₄₄ are mutually bonded to form a substituted or unsubstituted monocyclic ring, mutually bonded to form a substituted or unsubstituted fused ring, or not mutually bonded;
R₅₃₁ to R₅₃₄, R₅₄₁ to R₅₄₄ forming neither the monocyclic ring nor the fused ring, and R₅₅₁ and R₅₅₂ are each independently a hydrogen atom, a substituted or unsubstituted aryl group having 6 to 50 ring carbon atoms, or a substituted or unsubstituted heterocyclic group having 5 to 50 ring atoms; and
R₅₆₁ to R₅₆₄ are each independently a substituted or unsubstituted aryl group having 6 to 50 ring carbon atoms, or a substituted or unsubstituted heterocyclic group having 5 to 50 ring atoms.

In an exemplary embodiment, the compound represented by the formula (5) is a compound represented by a formula (53) below.

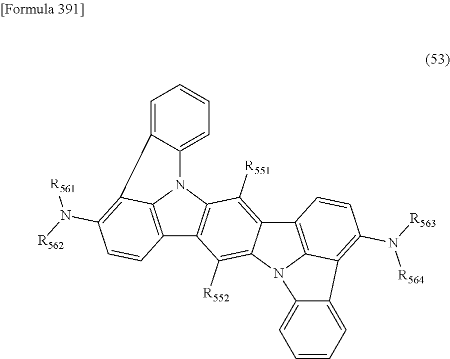

In the formula (53), R₅₅₁, R₅₅₂ and R₅₆₁ to R₅₆₄ each independently represent the same as R₅₅₁, R₅₅₂ and R₅₆₁ to R₅₆₄ in the formula (52).

In an exemplary embodiment, R₅₆₁ to R₅₆₄ in the formulae (52) and (53) are each independently a substituted or unsubstituted aryl group having 6 to 50 ring carbon atoms (preferably a phenyl group).

In an exemplary embodiment, R₅₂₁ and R₅₂₂ in the formula (5) and R₅₅₁ and R₅₅₂ in the formulae (52) and (53) are each a hydrogen atom.

In an exemplary embodiment, the substituent for the “substituted or unsubstituted” group in the formulae (5), (52) and (53) is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

### Specific Examples of Compound Represented by Formula (5)

Specific examples of the compound represented by the formula (5) include compounds shown below.

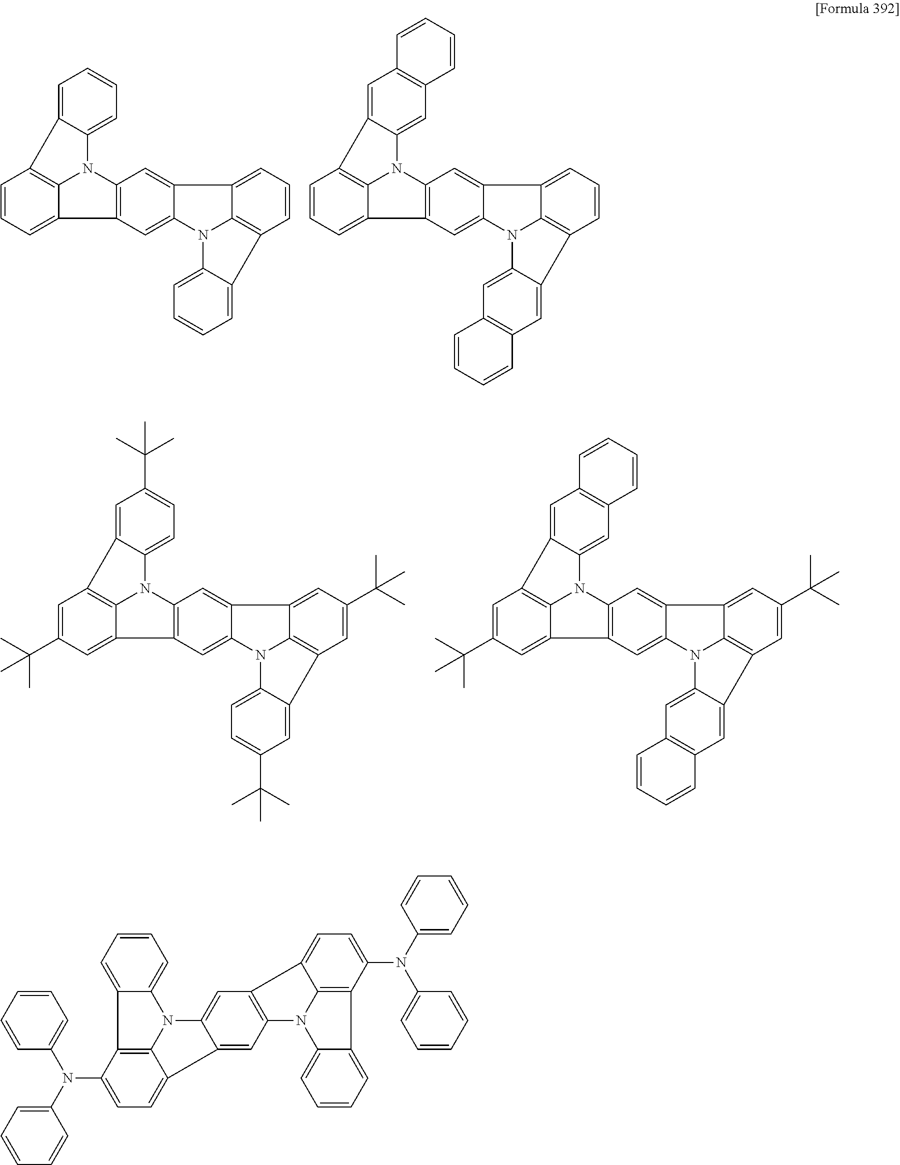

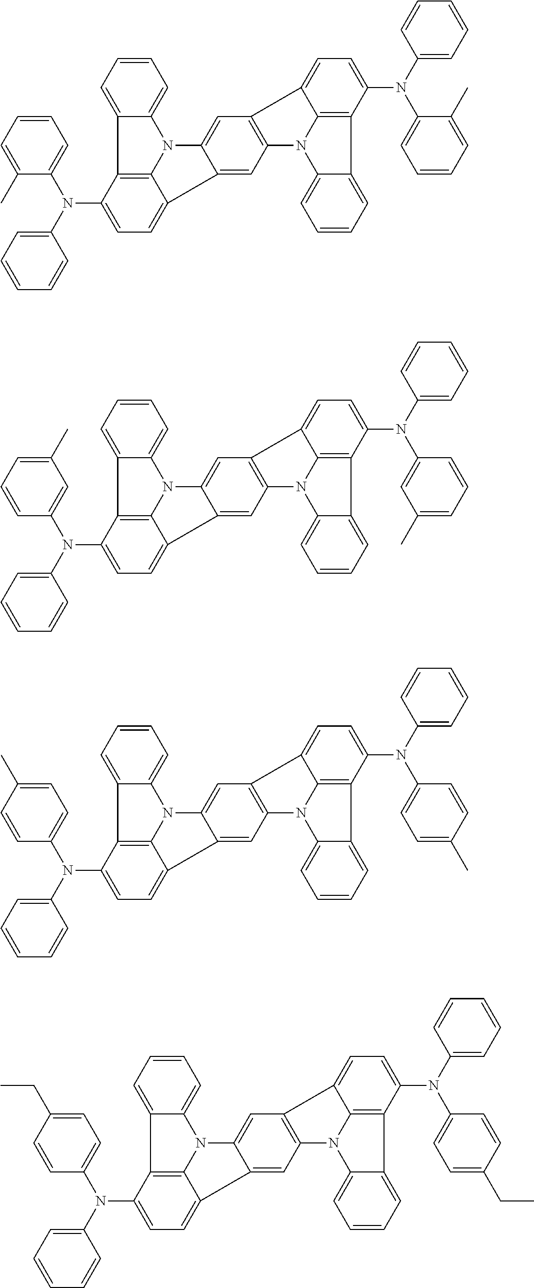

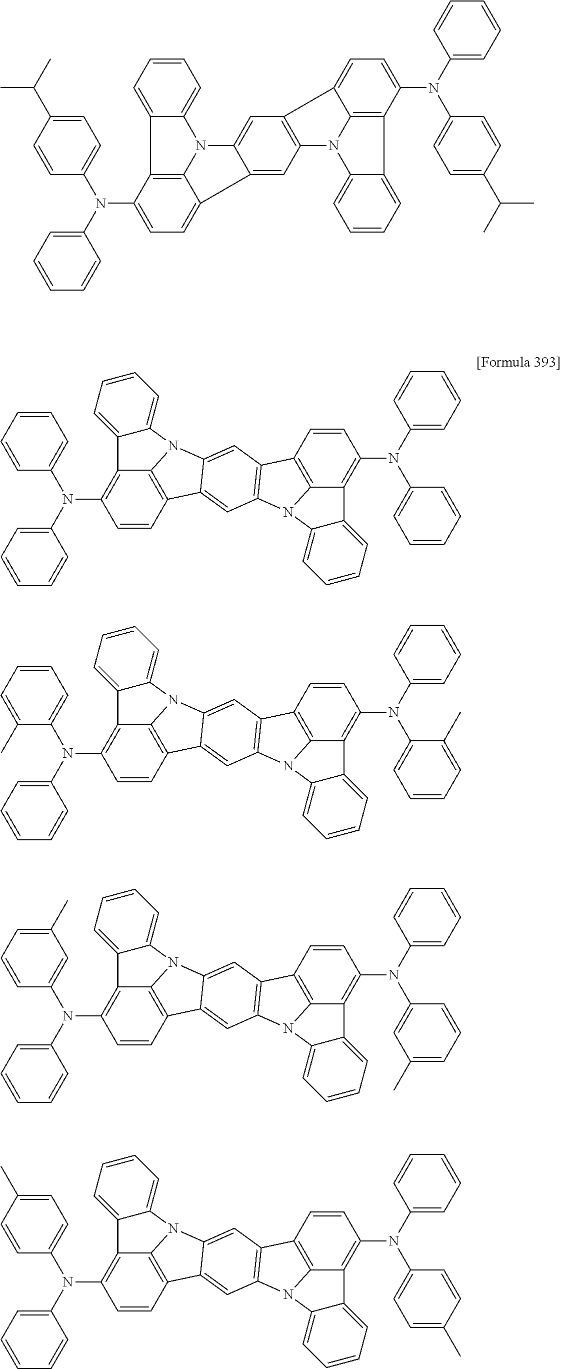

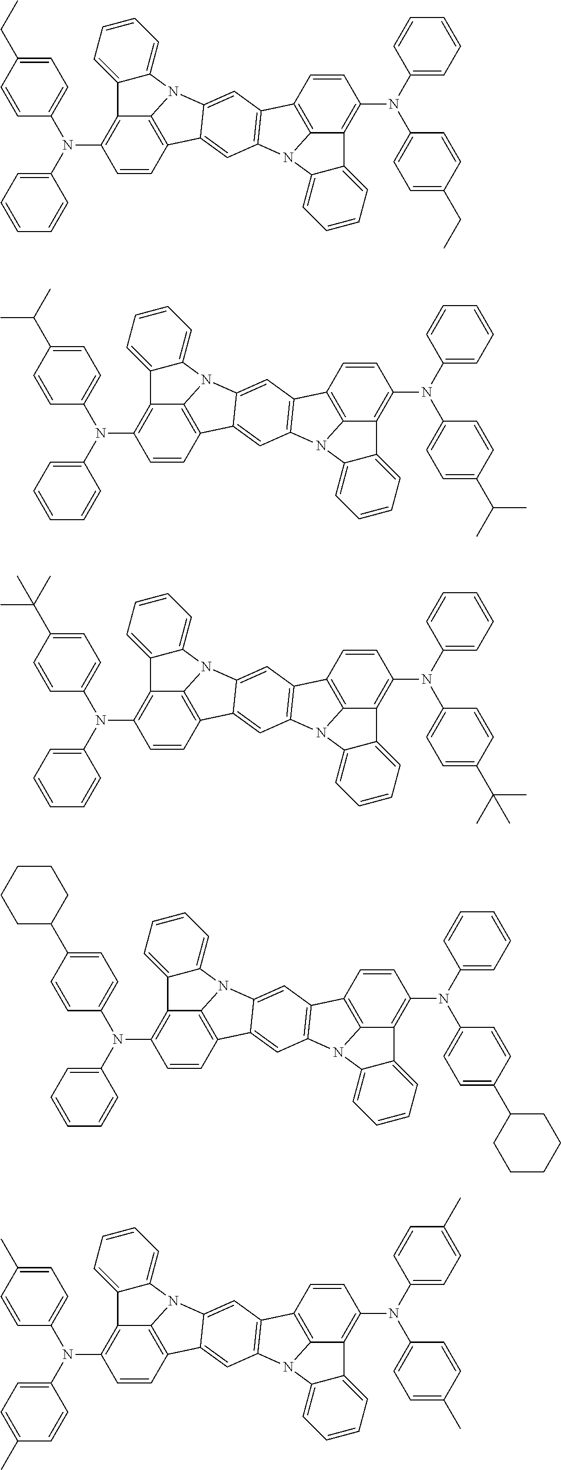

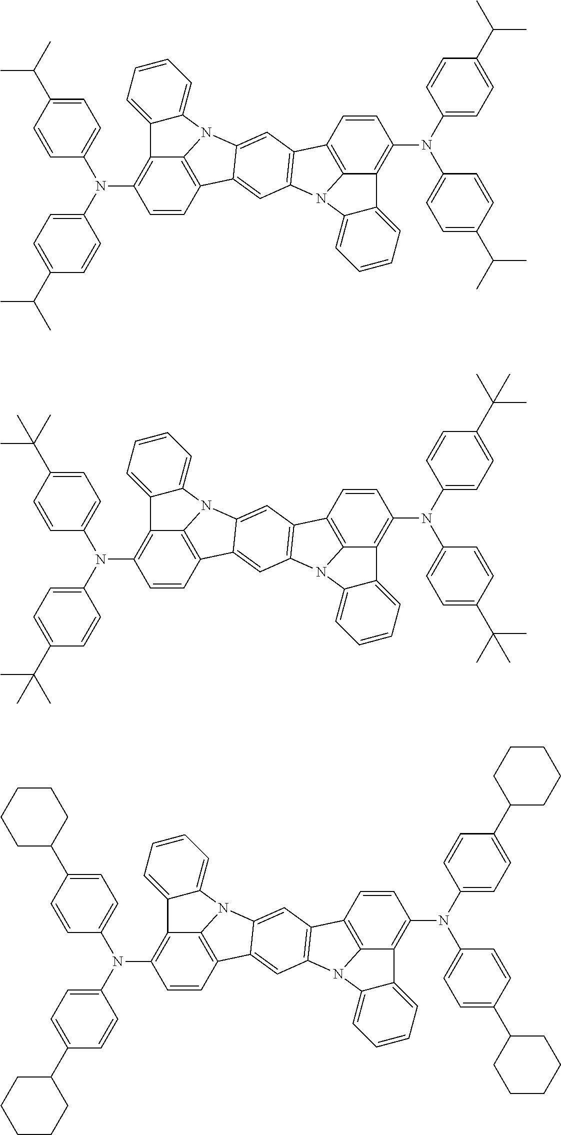

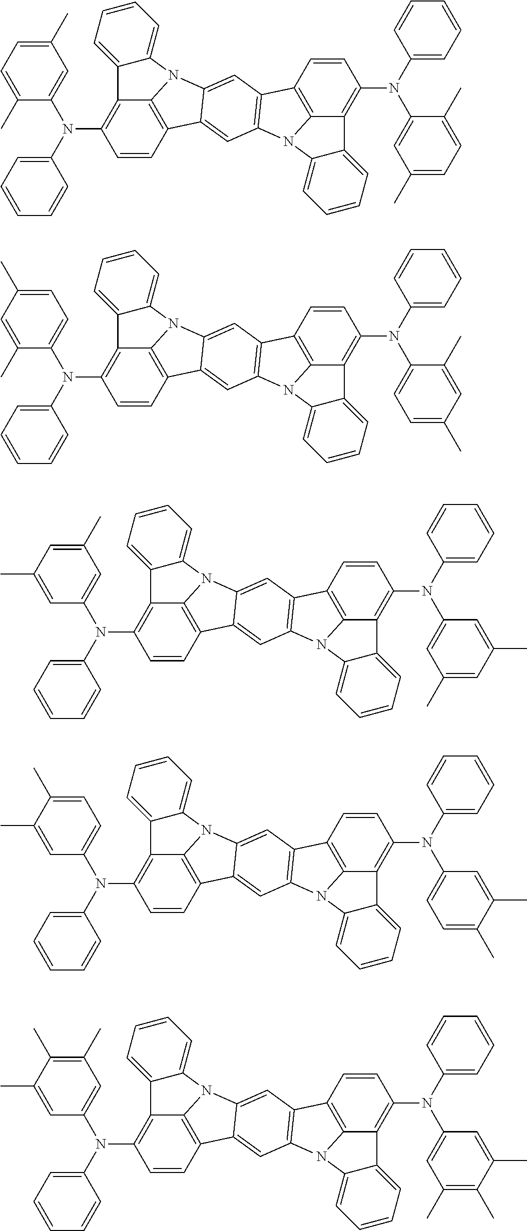

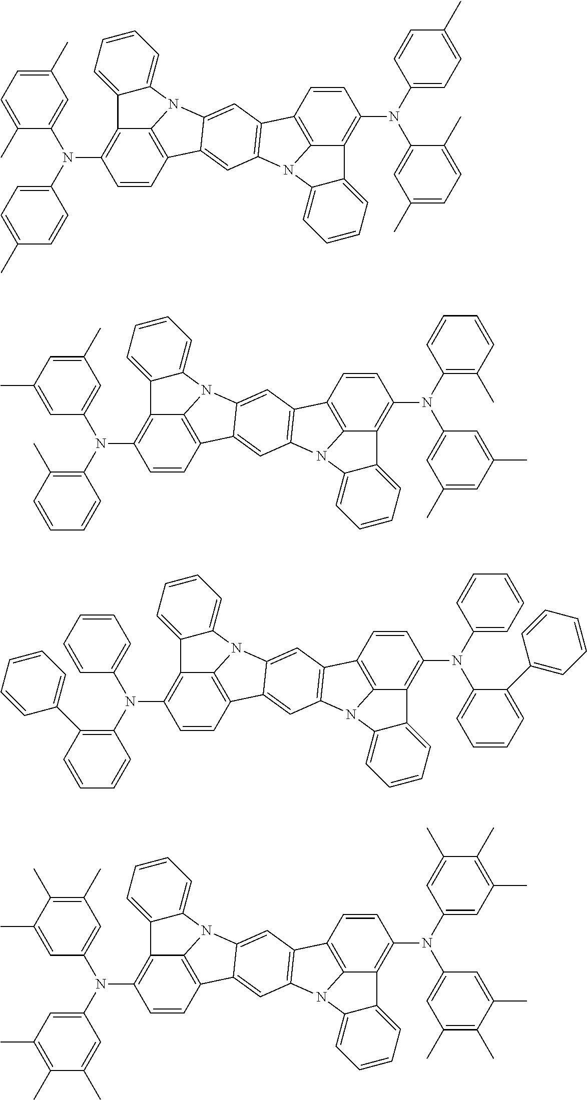

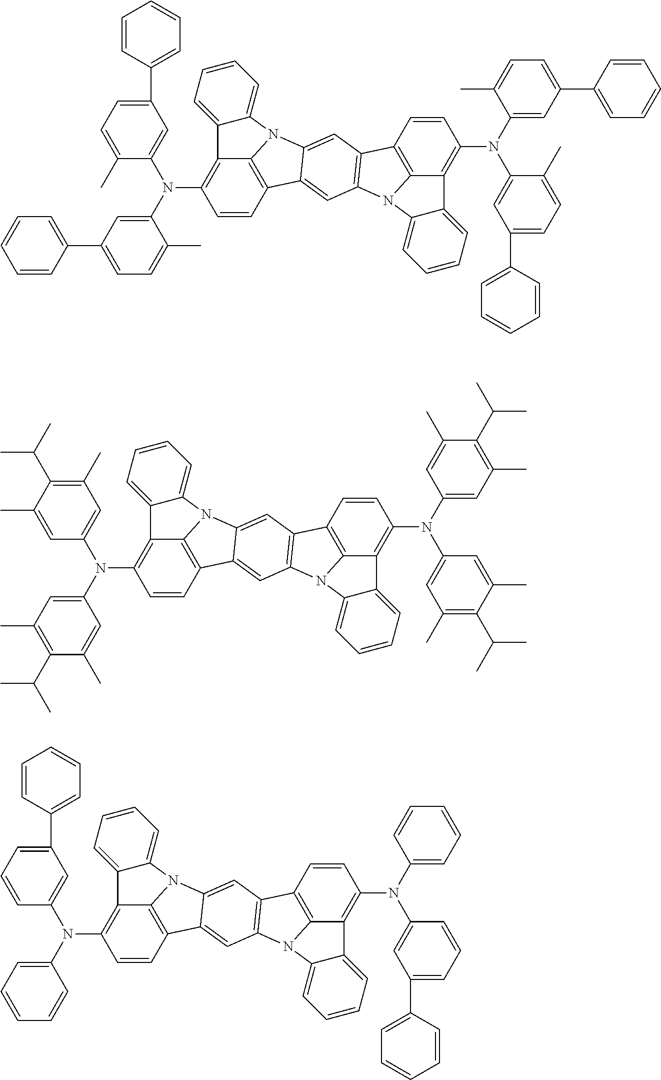

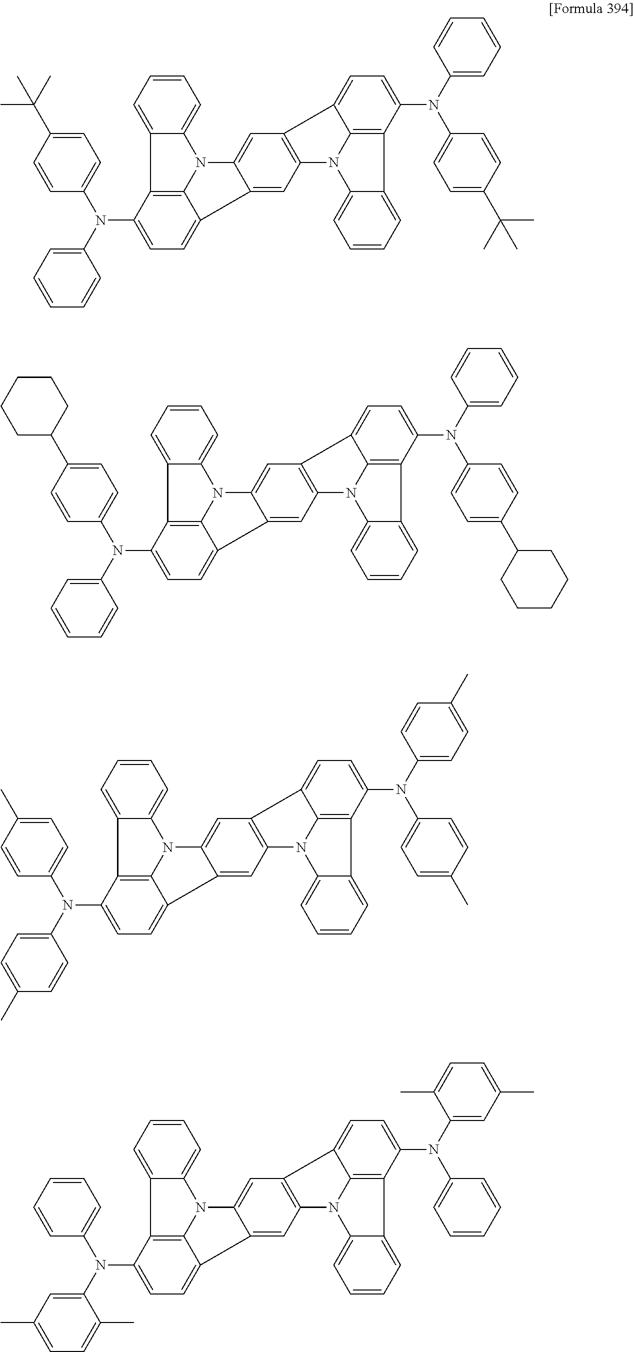

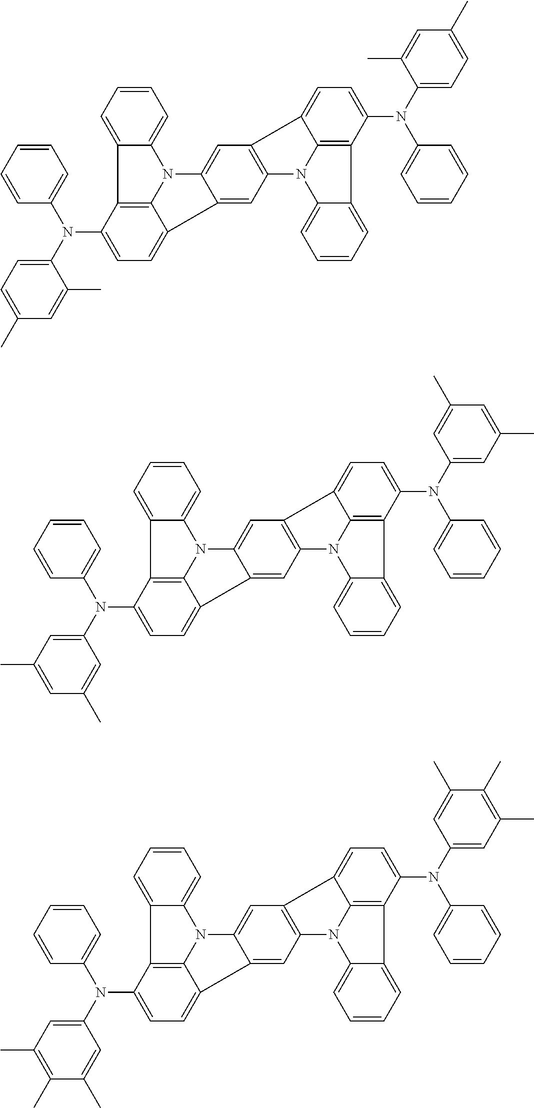

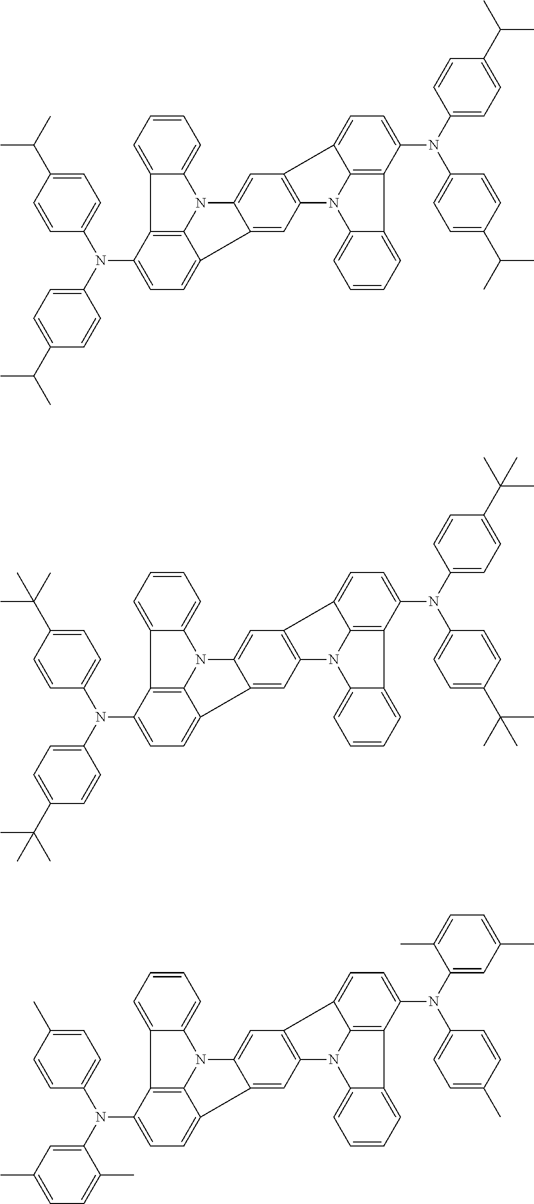

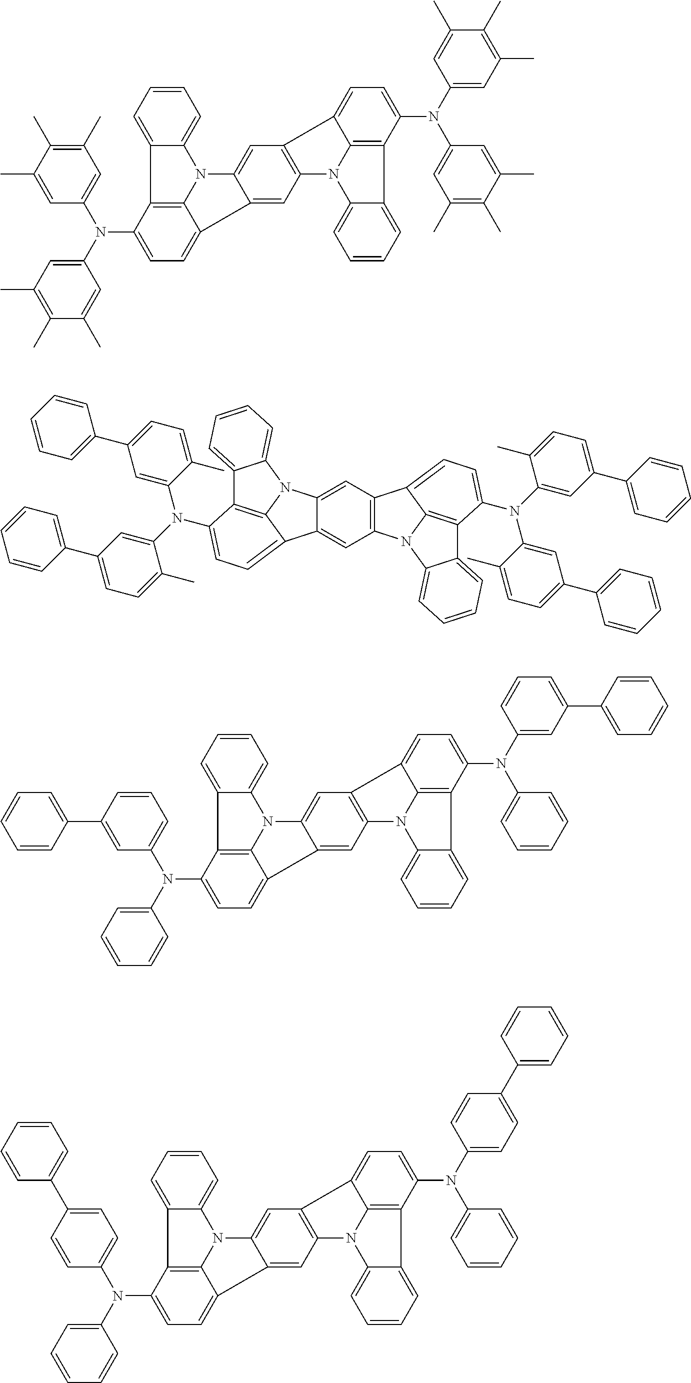

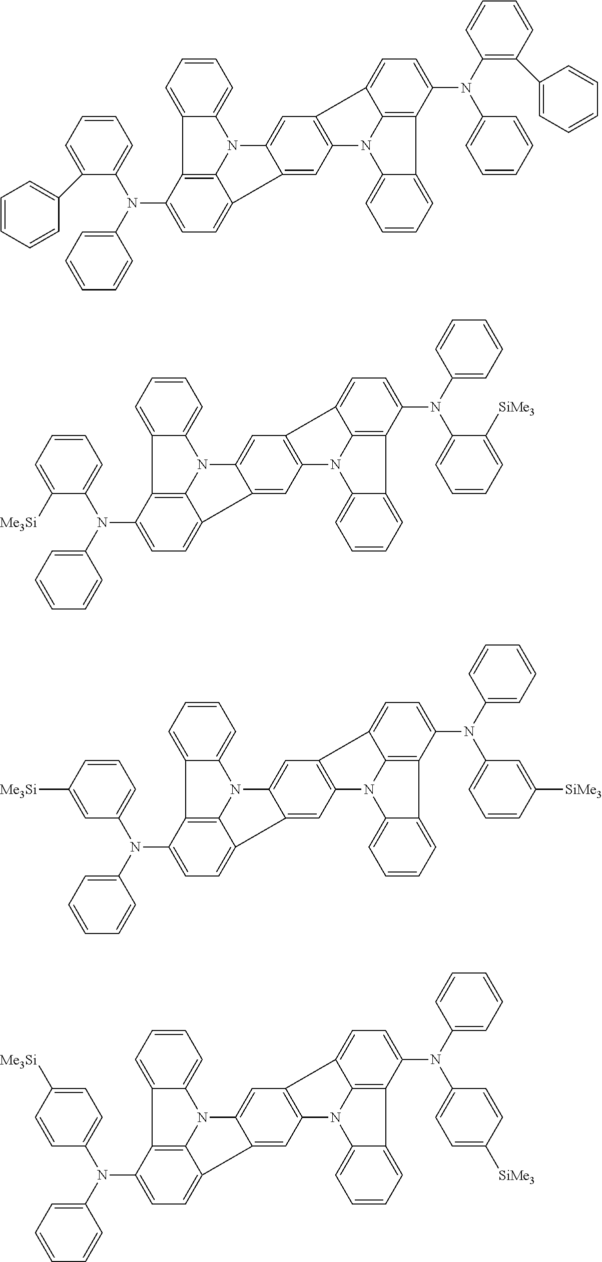 [SMILES: c1ccc(-c2ccccc2N(c2ccccc2)c2ccc3c4cc5c(cc4n4c6ccccc6c2c34)c2ccc(N(c3ccccc3)c3ccccc3-c3ccccc3)c3c4ccccc4n5c23)cc1 ; C[Si](C)(C)c1ccccc1N(c1ccccc1)c1ccc2c3cc4c(cc3n3c5ccccc5c1c23)c1ccc(N(c2ccccc2)c2ccccc2[Si](C)(C)C)c2c3ccccc3n4c12 ; C[Si](C)(C)c1cccc(N(c2ccccc2)c2ccc3c4cc5c(cc4n4c6ccccc6c2c34)c2ccc(N(c3ccccc3)c3cccc([Si](C)(C)C)c3)c3c4ccccc4n5c23)c1 ; C[Si](C)(C)c1ccc(N(c2ccccc2)c2ccc3c4cc5c(cc4n4c6ccccc6c2c34)c2ccc(N(c3ccccc3)c3ccc([Si](C)(C)C)cc3)c3c4ccccc4n5c23)cc1]

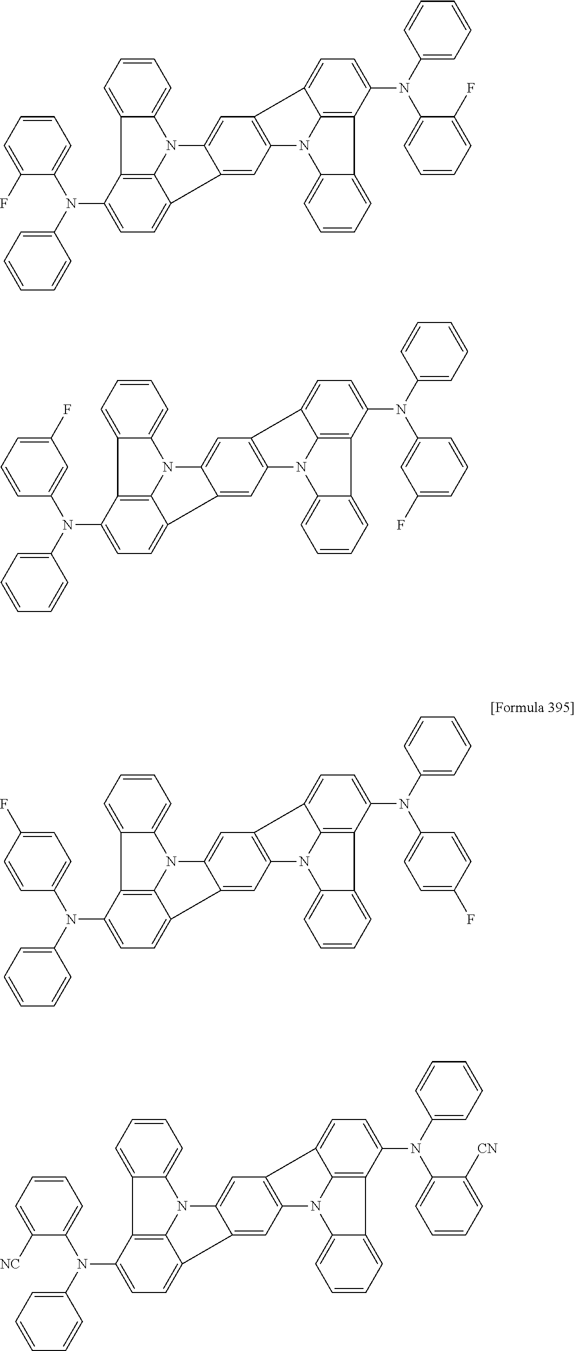 [SMILES: Fc1ccccc1N(c1ccccc1)c1ccc2c3cc4c(cc3n3c5ccccc5c1c23)c1ccc(N(c2ccccc2)c2ccccc2F)c2c3ccccc3n4c12 ; Fc1cccc(N(c2ccccc2)c2ccc3c4cc5c(cc4n4c6ccccc6c2c34)c2ccc(N(c3ccccc3)c3cccc(F)c3)c3c4ccccc4n5c23)c1 ; Fc1ccc(N(c2ccccc2)c2ccc3c4cc5c(cc4n4c6ccccc6c2c34)c2ccc(N(c3ccccc3)c3ccc(F)cc3)c3c4ccccc4n5c23)cc1 ; N#Cc1ccccc1N(c1ccccc1)c1ccc2c3cc4c(cc3n3c5ccccc5c1c23)c1ccc(N(c2ccccc2)c2ccccc2C#N)c2c3ccccc3n4c12]

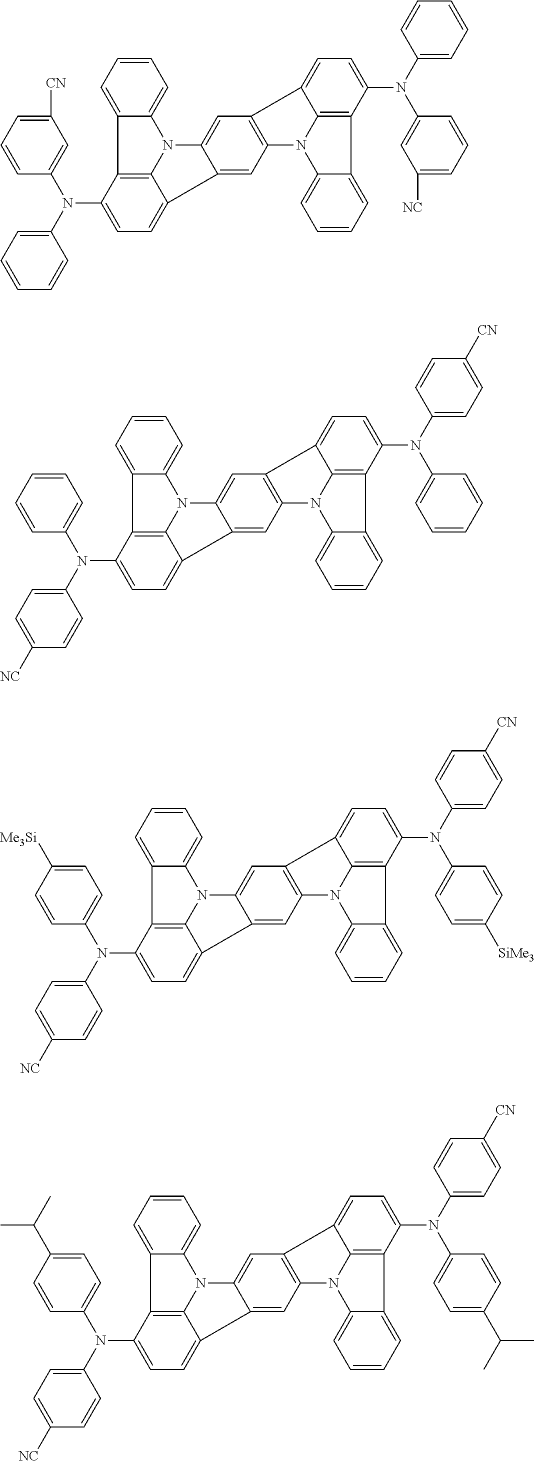 [SMILES: N#Cc1cccc(N(c2ccccc2)c2ccc3c4cc5c(cc4n4c6ccccc6c2c34)c2ccc(N(c3ccccc3)c3cccc(C#N)c3)c3c4ccccc4n5c23)c1 ; N#Cc1ccc(N(c2ccccc2)c2ccc3c4cc5c(cc4n4c6ccccc6c2c34)c2ccc(N(c3ccccc3)c3ccc(C#N)cc3)c3c4ccccc4n5c23)cc1 ; C[Si](C)(C)c1ccc(N(c2ccc(C#N)cc2)c2ccc3c4cc5c(cc4n4c6ccccc6c2c34)c2ccc(N(c3ccc(C#N)cc3)c3ccc([Si](C)(C)C)cc3)c3c4ccccc4n5c23)cc1 ; CC(C)c1ccc(N(c2ccc(C#N)cc2)c2ccc3c4cc5c(cc4n4c6ccccc6c2c34)c2ccc(N(c3ccc(C#N)cc3)c3ccc(C(C)C)cc3)c3c4ccccc4n5c23)cc1]

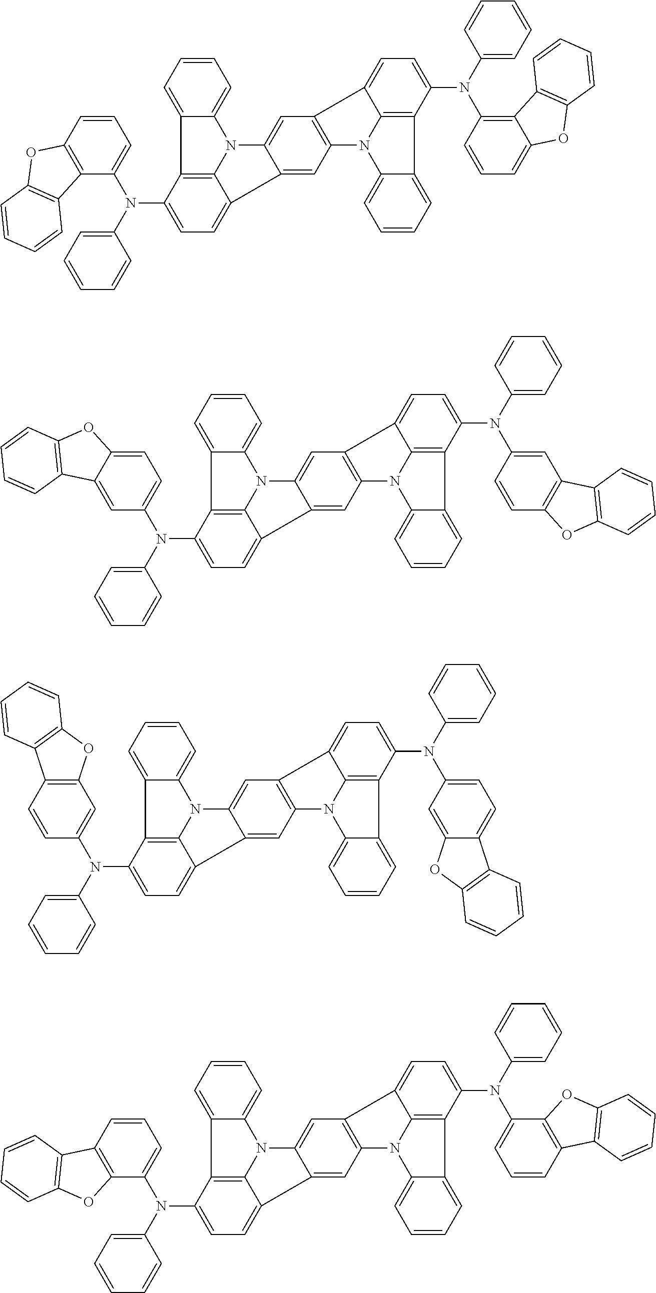 [SMILES: c1ccc(N(c2cccc3oc4ccccc4c23)c2ccc3c4cc5c(cc4n4c6ccccc6c2c34)c2ccc(N(c3ccccc3)c3cccc4oc6ccccc6c34)c3c4ccccc4n5c23)cc1 ; c1ccc(N(c2ccc3oc4ccccc4c3c2)c2ccc3c4cc5c(cc4n4c6ccccc6c2c34)c2ccc(N(c3ccccc3)c3ccc4oc6ccccc6c4c3)c3c4ccccc4n5c23)cc1 ; c1ccc(N(c2ccc3c(c2)oc2ccccc23)c2ccc3c4cc5c(cc4n4c6ccccc6c2c34)c2ccc(N(c3ccccc3)c3ccc4c(c3)oc3ccccc34)c3c4ccccc4n5c23)cc1 ; c1ccc(N(c2cccc3c2oc2ccccc23)c2ccc3c4cc5c(cc4n4c6ccccc6c2c34)c2ccc(N(c3ccccc3)c3cccc4c3oc3ccccc34)c3c4ccccc4n5c23)cc1]

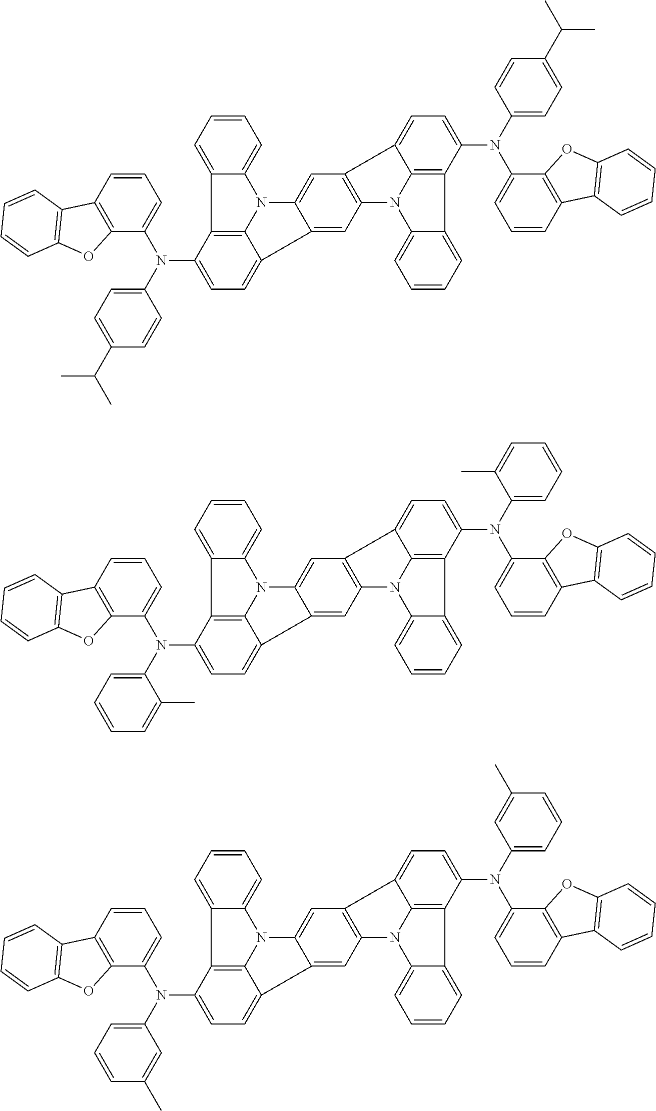 [SMILES: CC(C)c1ccc(N(c2cccc3c2oc2ccccc23)c2ccc3c4cc5c(cc4n4c6ccccc6c2c34)c2ccc(N(c3ccc(C(C)C)cc3)c3cccc4c3oc3ccccc34)c3c4ccccc4n5c23)cc1 ; Cc1ccccc1N(c1cccc2c1oc1ccccc12)c1ccc2c3cc4c(cc3n3c5ccccc5c1c23)c1ccc(N(c2ccccc2C)c2cccc3c2oc2ccccc23)c2c3ccccc3n4c12 ; Cc1cccc(N(c2cccc3c2oc2ccccc23)c2ccc3c4cc5c(cc4n4c6ccccc6c2c34)c2ccc(N(c3cccc(C)c3)c3cccc4c3oc3ccccc34)c3c4ccccc4n5c23)c1]

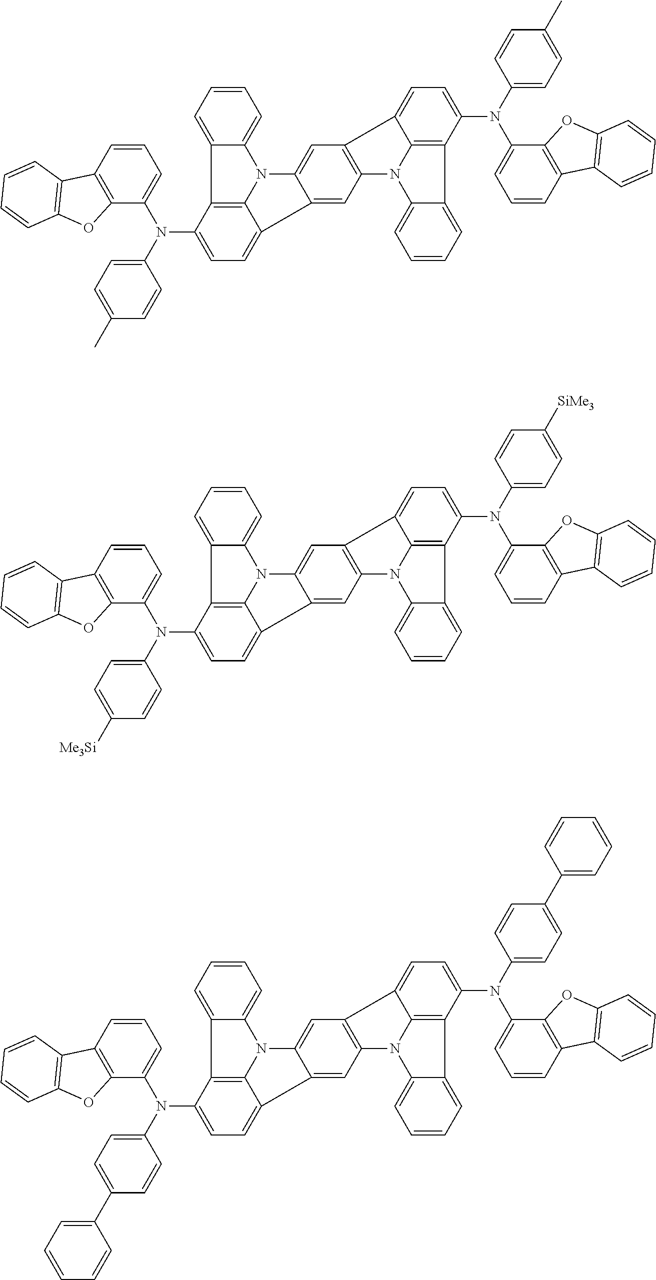 [SMILES: Cc1ccc(N(c2cccc3c2oc2ccccc23)c2ccc3c4cc5c(cc4n4c6ccccc6c2c34)c2ccc(N(c3ccc(C)cc3)c3cccc4c3oc3ccccc34)c3c4ccccc4n5c23)cc1 ; C[Si](C)(C)c1ccc(N(c2cccc3c2oc2ccccc23)c2ccc3c4cc5c(cc4n4c6ccccc6c2c34)c2ccc(N(c3ccc([Si](C)(C)C)cc3)c3cccc4c3oc3ccccc34)c3c4ccccc4n5c23)cc1 ; c1ccc(-c2ccc(N(c3cccc4c3oc3ccccc34)c3ccc4c5cc6c(cc5n5c7ccccc7c3c45)c3ccc(N(c4ccc(-c5ccccc5)cc4)c4cccc5c4oc4ccccc45)c4c5ccccc5n6c34)cc2)cc1]

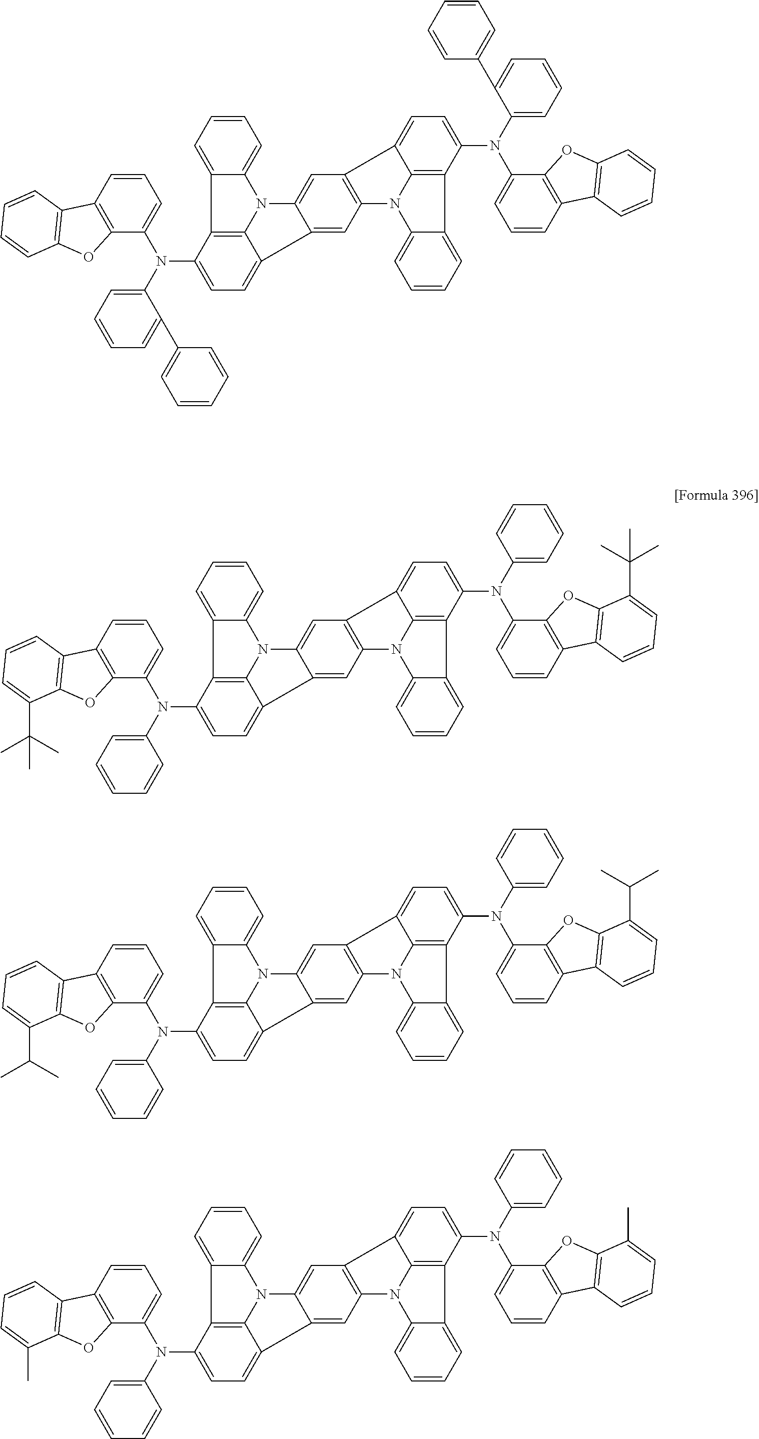

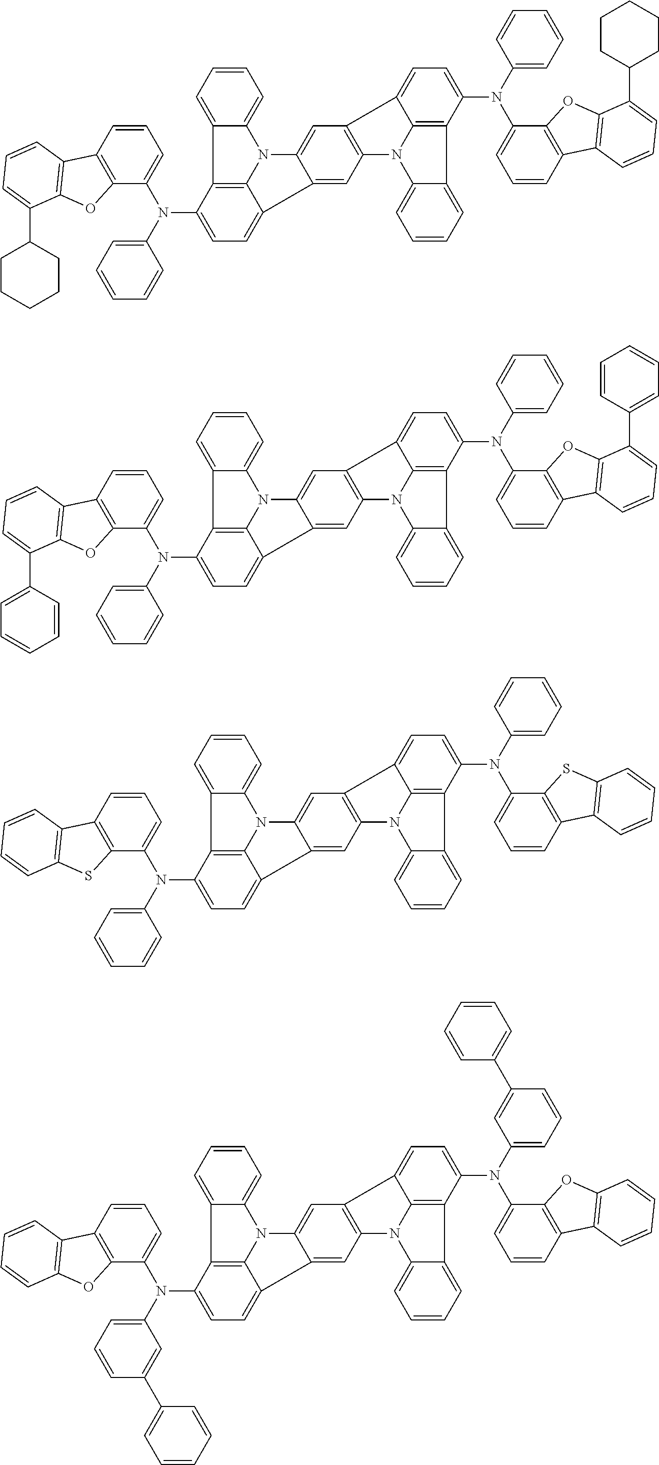

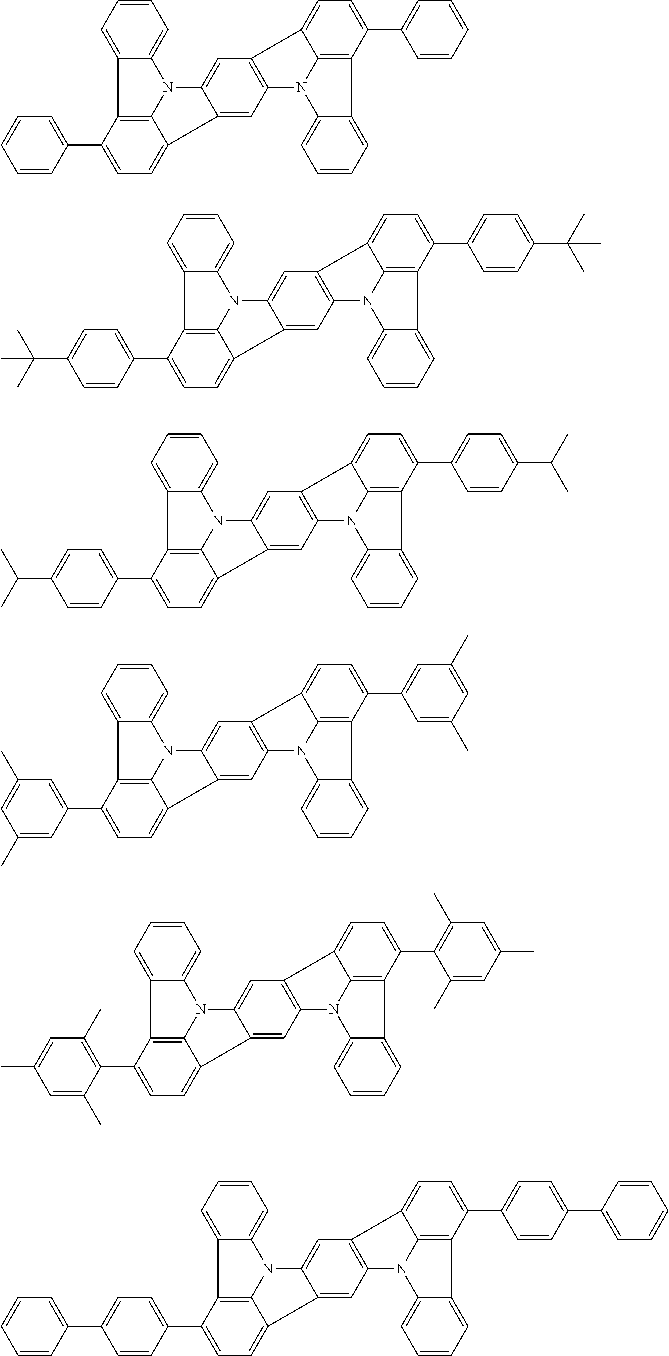

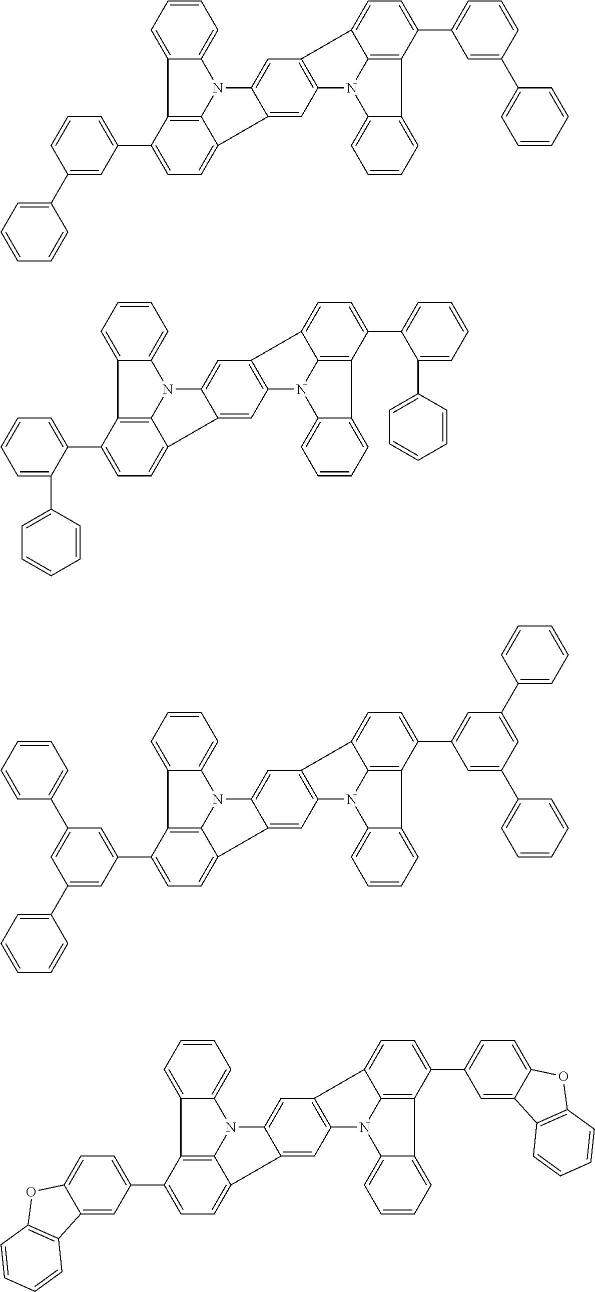 [SMILES: c1ccc(-c2cccc(-c3ccc4c5cc6c(cc5n5c7ccccc7c3c45)c3ccc(-c4cccc(-c5ccccc5)c4)c4c5ccccc5n6c34)c2)cc1 ; c1ccc(-c2ccccc2-c2ccc3c4cc5c(cc4n4c6ccccc6c2c34)c2ccc(-c3ccccc3-c3ccccc3)c3c4ccccc4n5c23)cc1 ; c1ccc(-c2cc(-c3ccccc3)cc(-c3ccc4c5cc6c(cc5n5c7ccccc7c3c45)c3ccc(-c4cc(-c5ccccc5)cc(-c5ccccc5)c4)c4c5ccccc5n6c34)c2)cc1 ; c1ccc2c(c1)oc1ccc(-c3ccc4c5cc6c(cc5n5c7ccccc7c3c45)c3ccc(-c4ccc5oc7ccccc7c5c4)c4c5ccccc5n6c34)cc12]

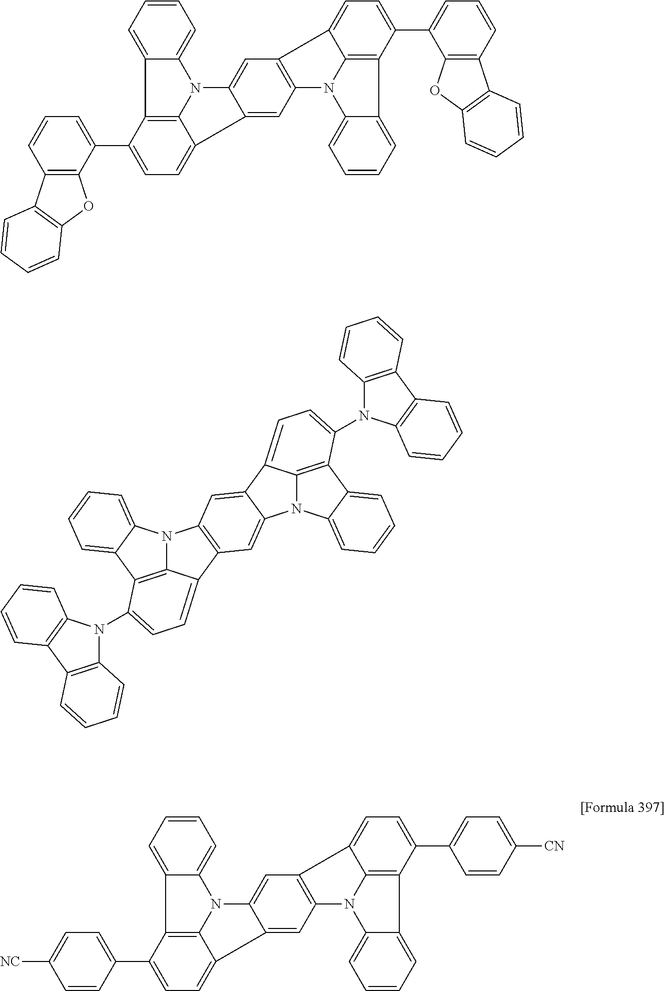 [SMILES: c1ccc2c(c1)oc1c(-c3ccc4c5cc6c(cc5n5c7ccccc7c3c45)c3ccc(-c4cccc5c4oc4ccccc45)c4c5ccccc5n6c34)cccc12 ; c1ccc2c(c1)c1ccccc1n2-c1ccc2c3cc4c(cc3n3c5ccccc5c1c23)c1ccc(-n2c3ccccc3c3ccccc32)c2c3ccccc3n4c12 ; N#Cc1ccc(-c2ccc3c4cc5c(cc4n4c6ccccc6c2c34)c2ccc(-c3ccc(C#N)cc3)c3c4ccccc4n5c23)cc1]

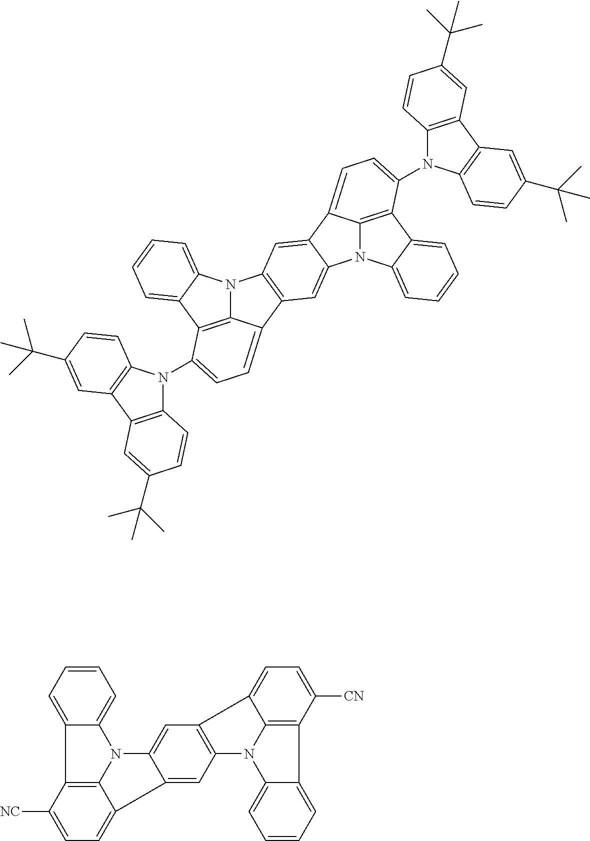 [SMILES: CC(C)(C)c1ccc2c(c1)c1cc(C(C)(C)C)ccc1n2-c1ccc2c3cc4c(cc3n3c5ccccc5c1c23)c1ccc(-n2c3ccc(C(C)(C)C)cc3c3cc(C(C)(C)C)ccc32)c2c3ccccc3n4c12 ; N#Cc1ccc2c3cc4c(cc3n3c5ccccc5c1c23)c1ccc(C#N)c2c3ccccc3n4c12]

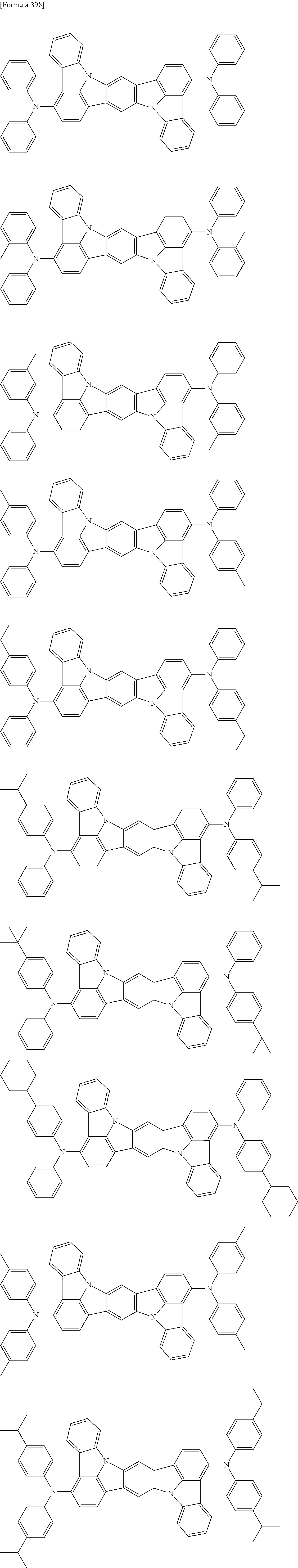

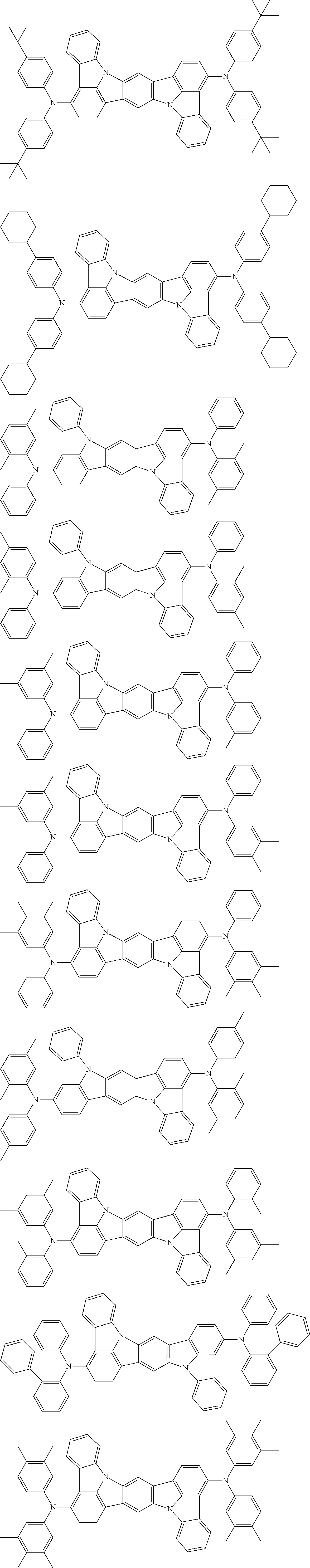

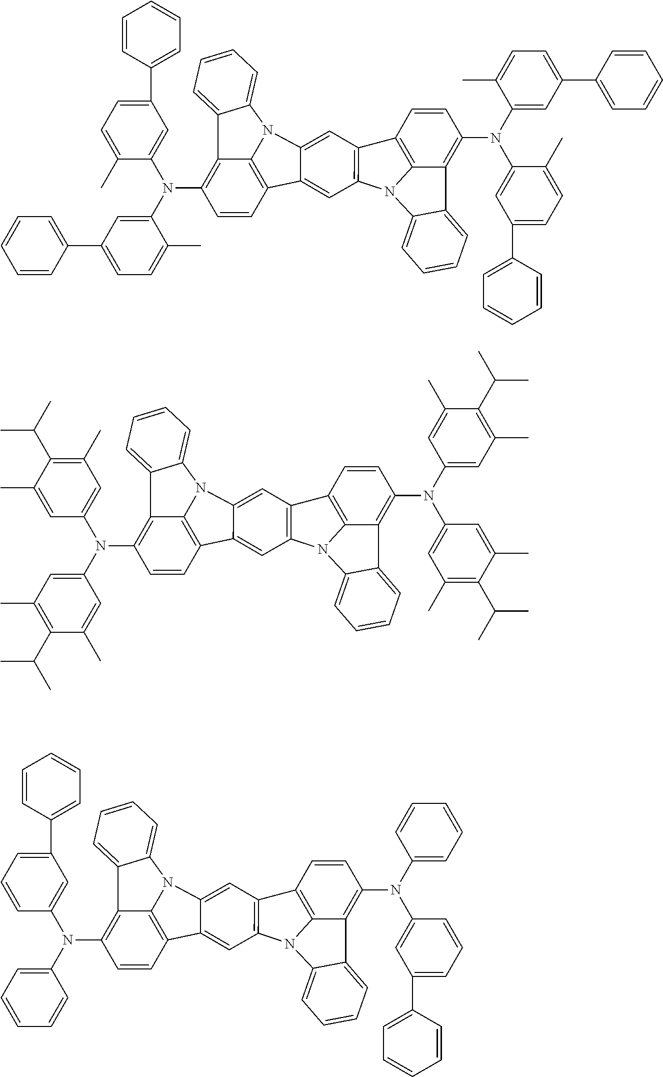

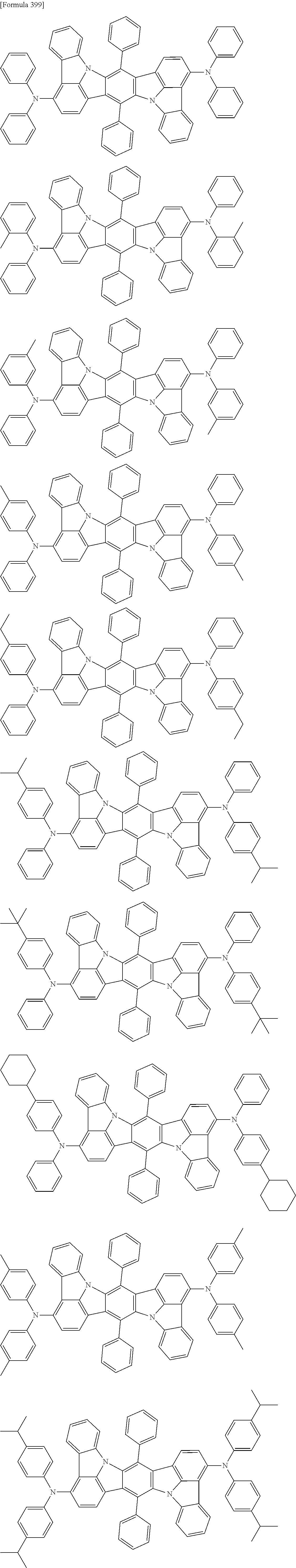

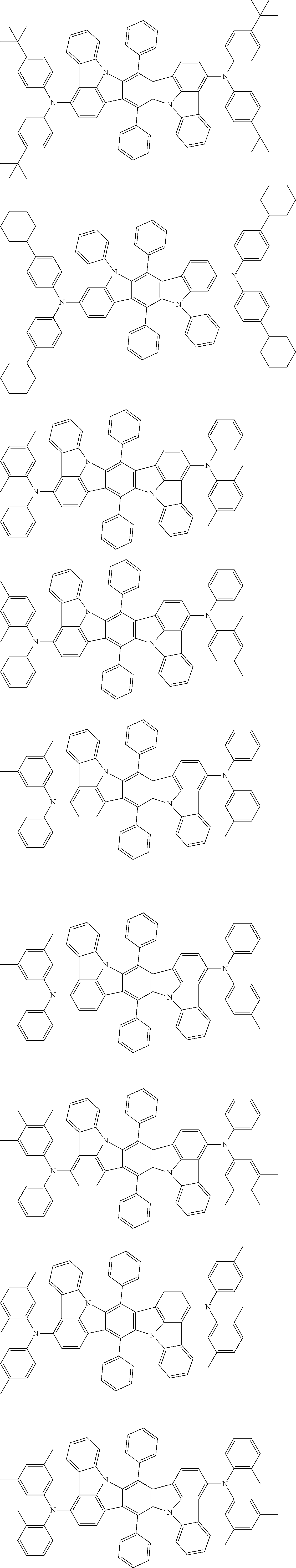

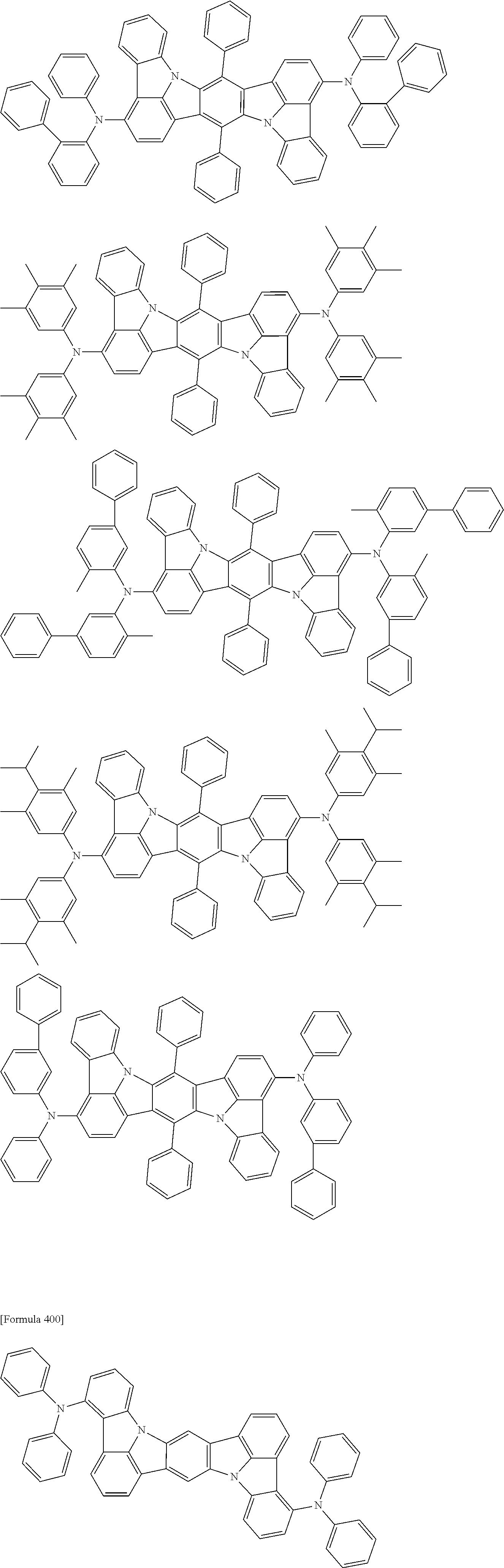

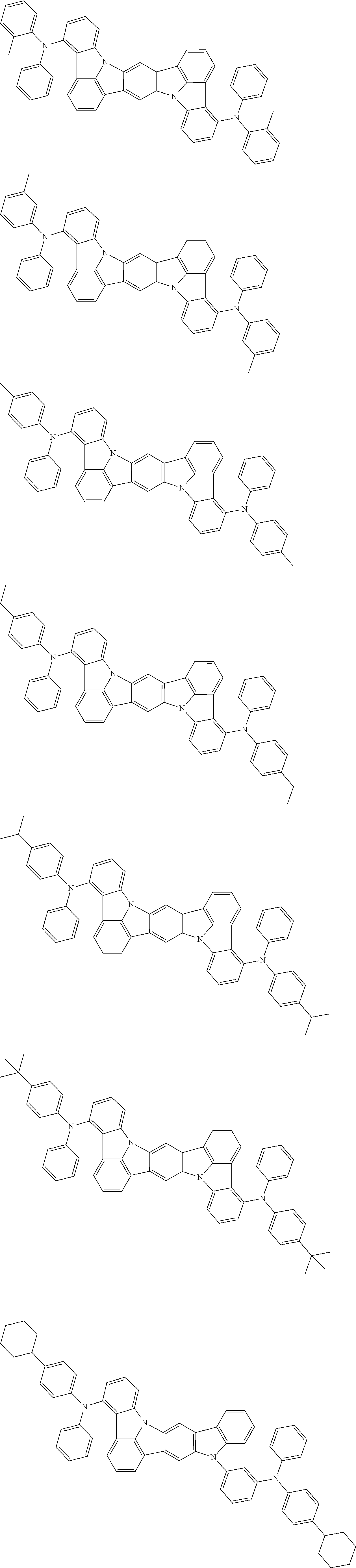

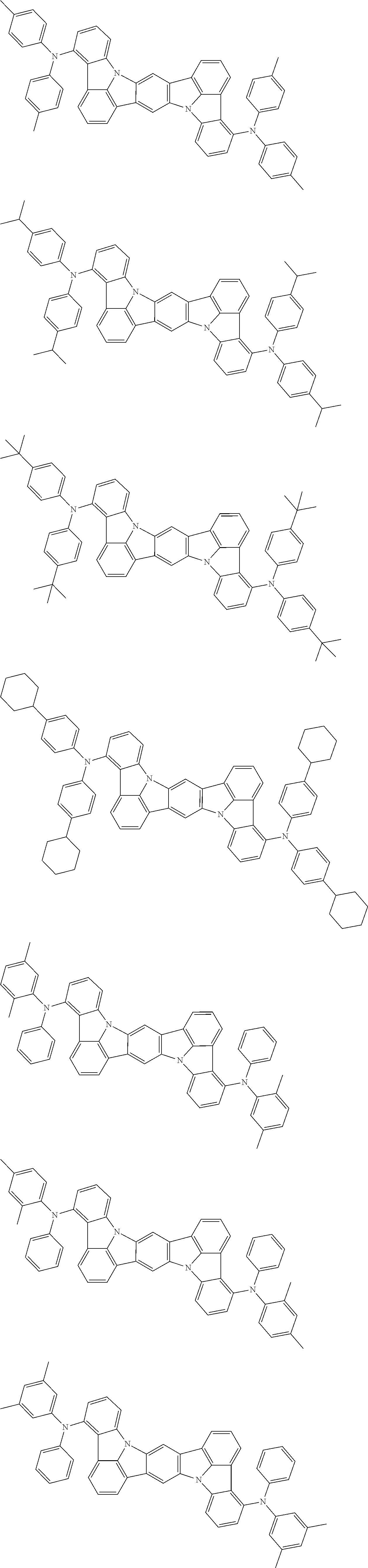

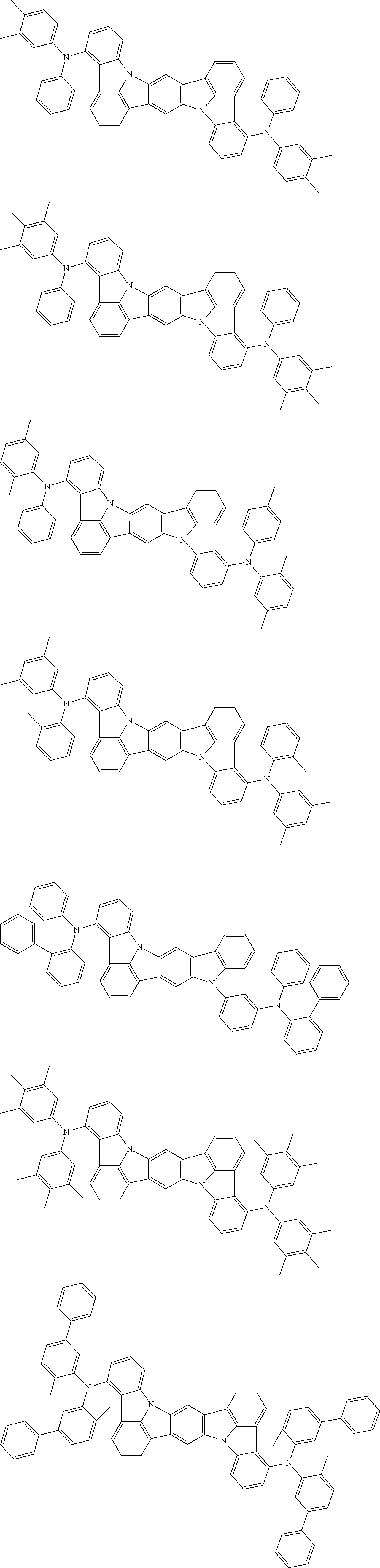

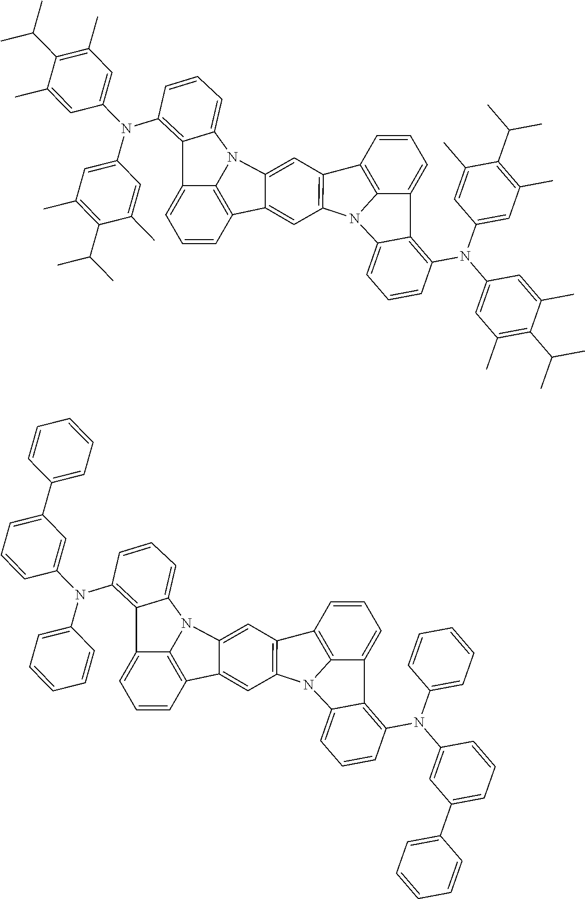 [SMILES: Cc1cc(N(c2cc(C)c(C(C)C)c(C)c2)c2cccc3c2c2cccc4c5cc6c(cc5n3c42)c2cccc3c4c(N(c5cc(C)c(C(C)C)c(C)c5)c5cc(C)c(C(C)C)c(C)c5)cccc4n6c23)cc(C)c1C(C)C ; c1ccc(-c2cccc(N(c3ccccc3)c3cccc4c3c3cccc5c6cc7c(cc6n4c53)c3cccc4c5c(N(c6ccccc6)c6cccc(-c8ccccc8)c6)cccc5n7c34)c2)cc1]

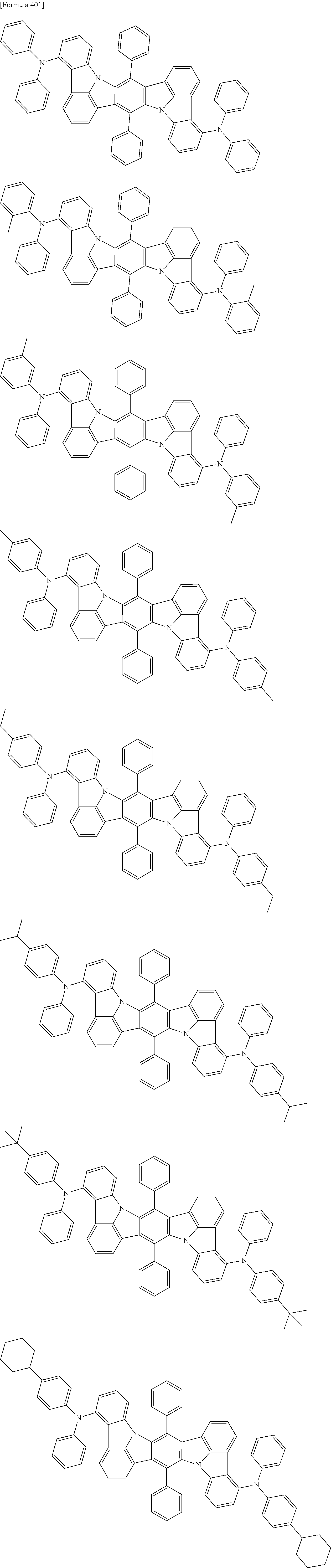

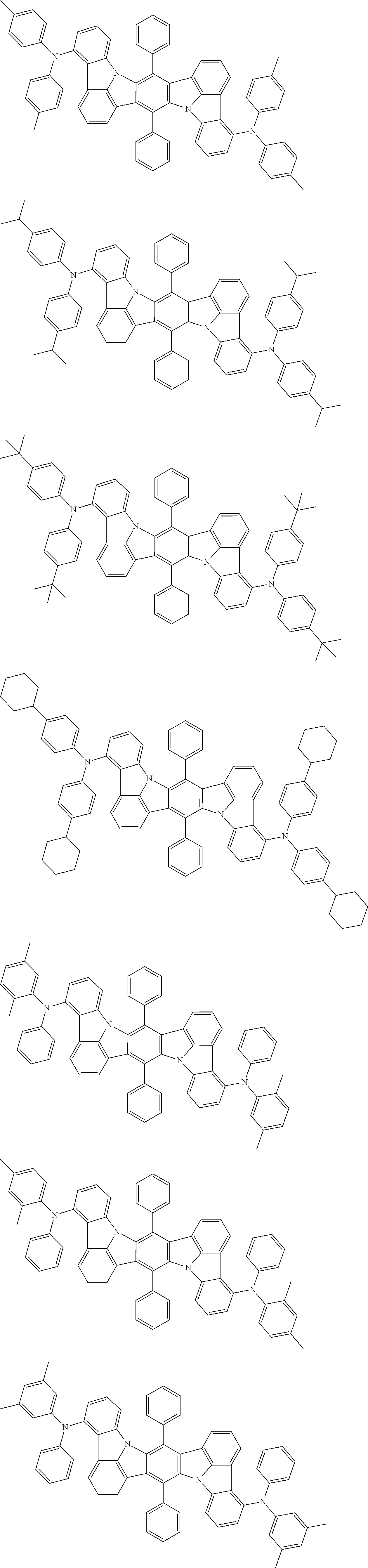

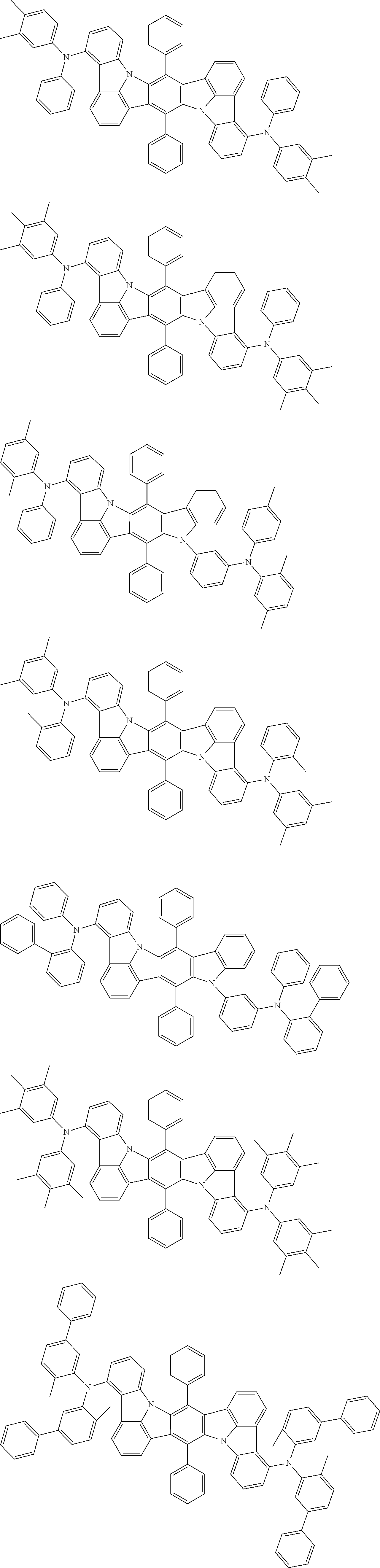

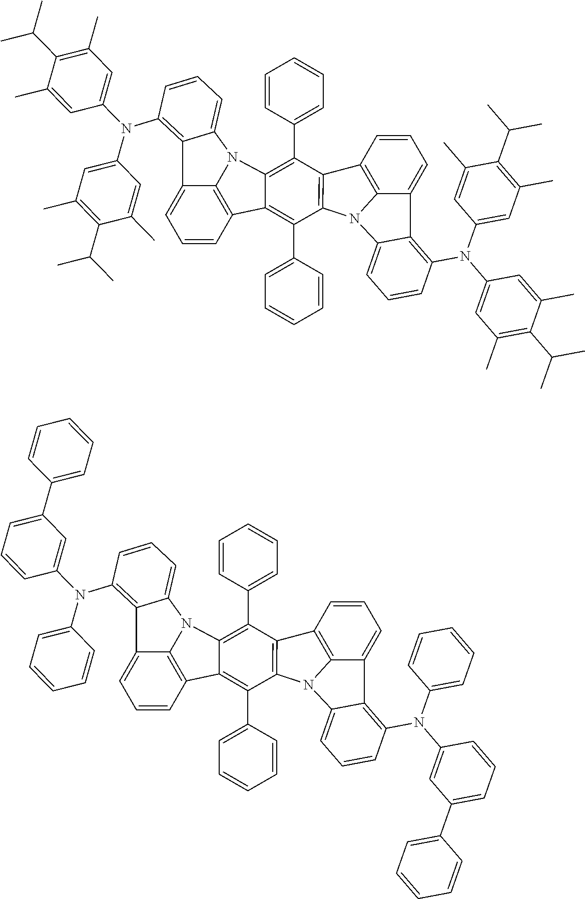 [SMILES: Cc1cc(N(c2cc(C)c(C(C)C)c(C)c2)c2cccc3c2c2cccc4c5c(-c6ccccc6)c6c(c(-c7ccccc7)c5n3c24)c2cccc3c4c(N(c5cc(C)c(C(C)C)c(C)c5)c5cc(C)c(C(C)C)c(C)c5)cccc4n6c32)cc(C)c1C(C)C ; c1ccc(-c2cccc(N(c3ccccc3)c3cccc4c3c3cccc5c6c(-c7ccccc7)c7c(c(-c8ccccc8)c6n4c35)c3cccc4c5c(N(c6ccccc6)c6cccc(-c8ccccc8)c6)cccc5n7c43)c2)cc1]

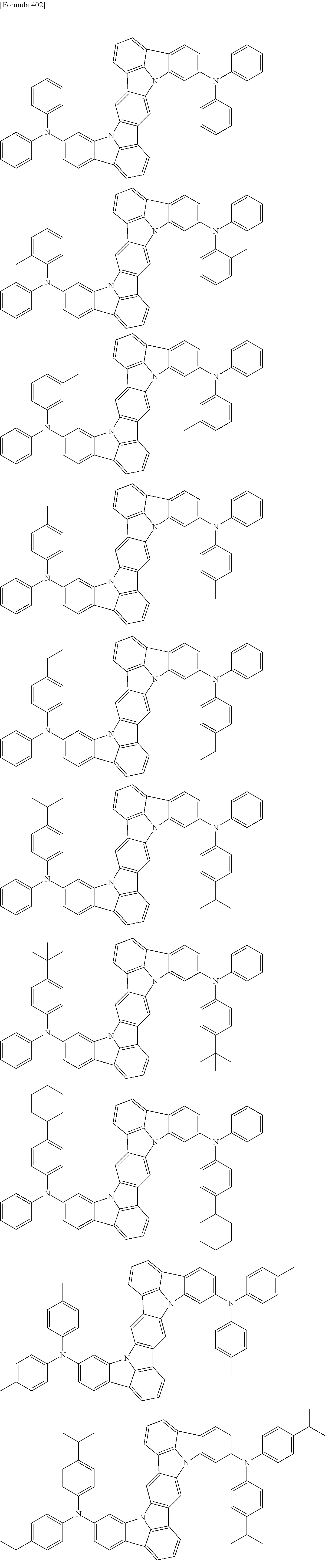

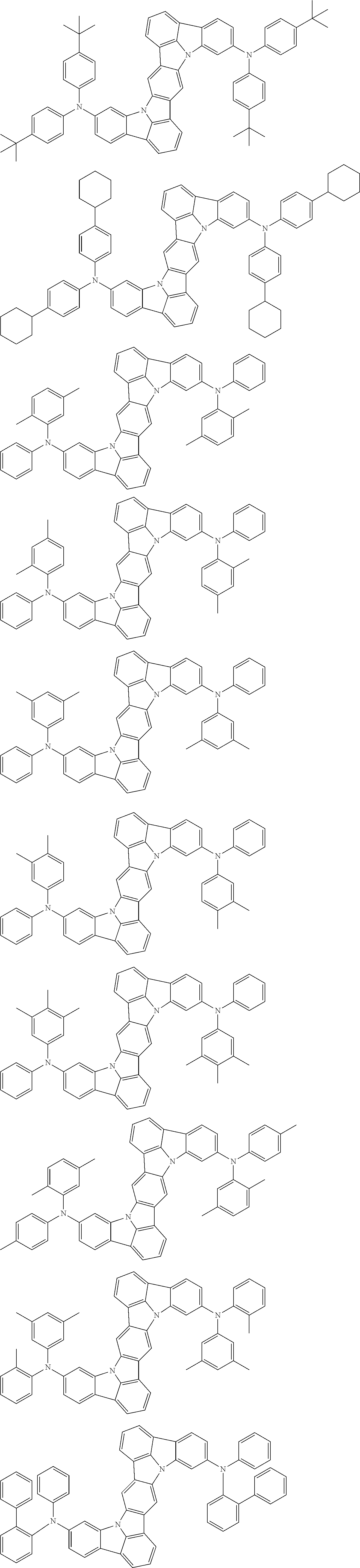

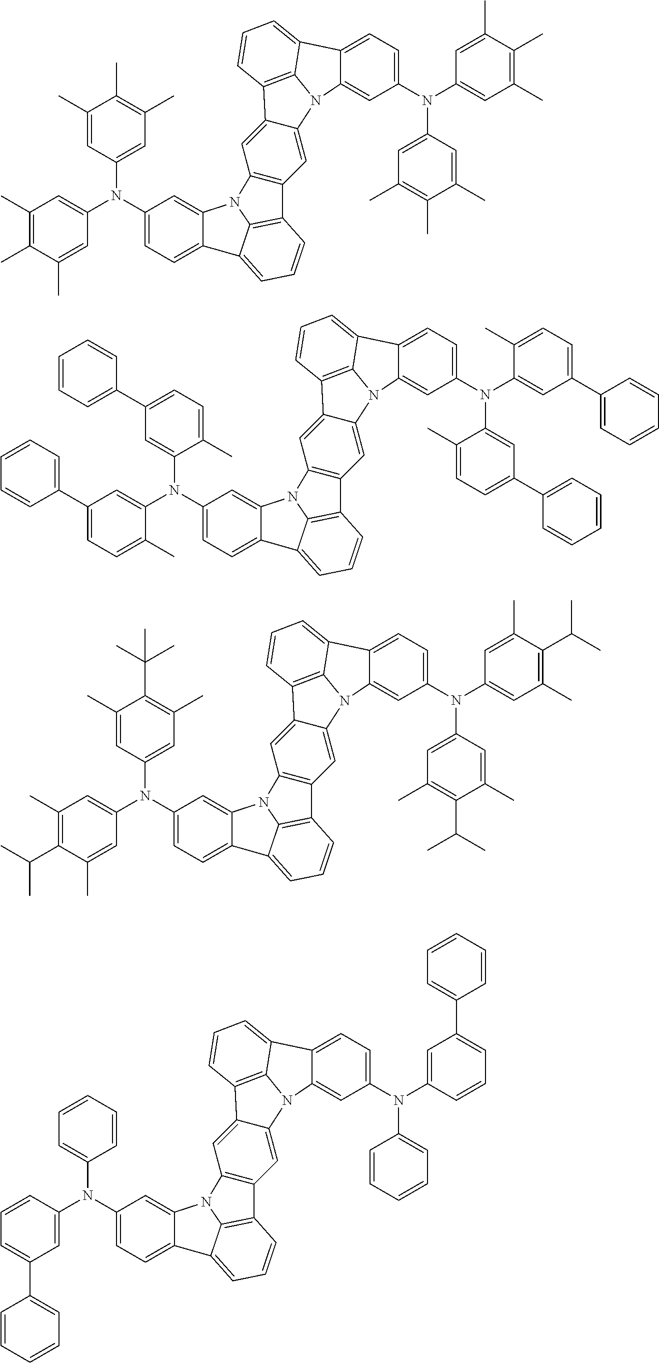

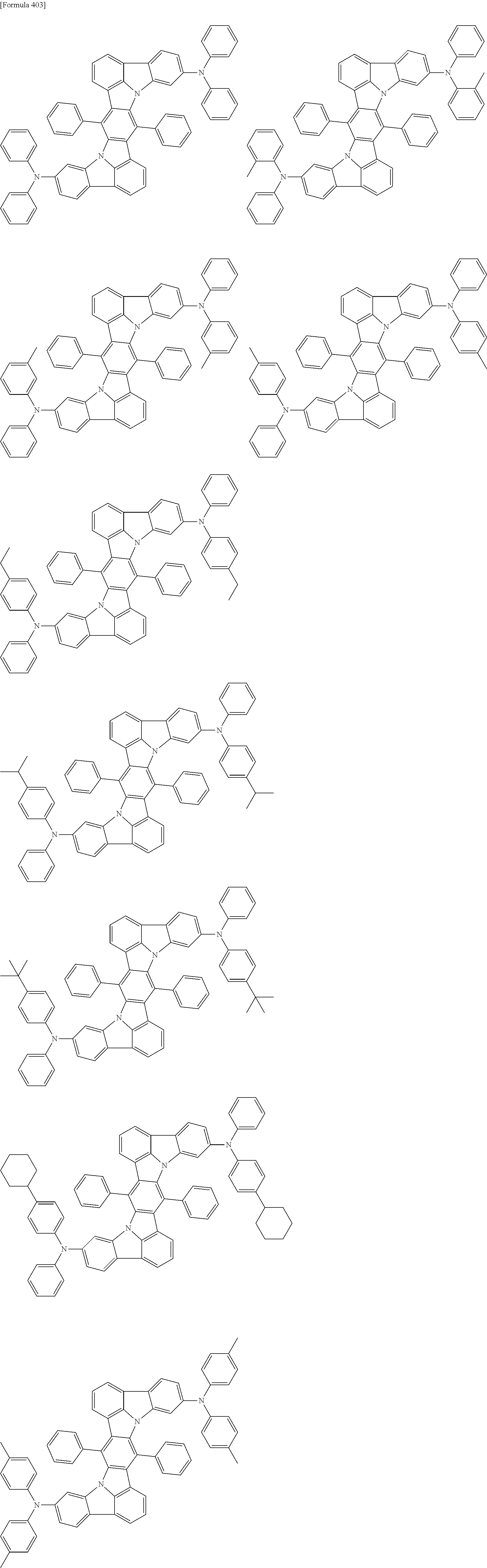

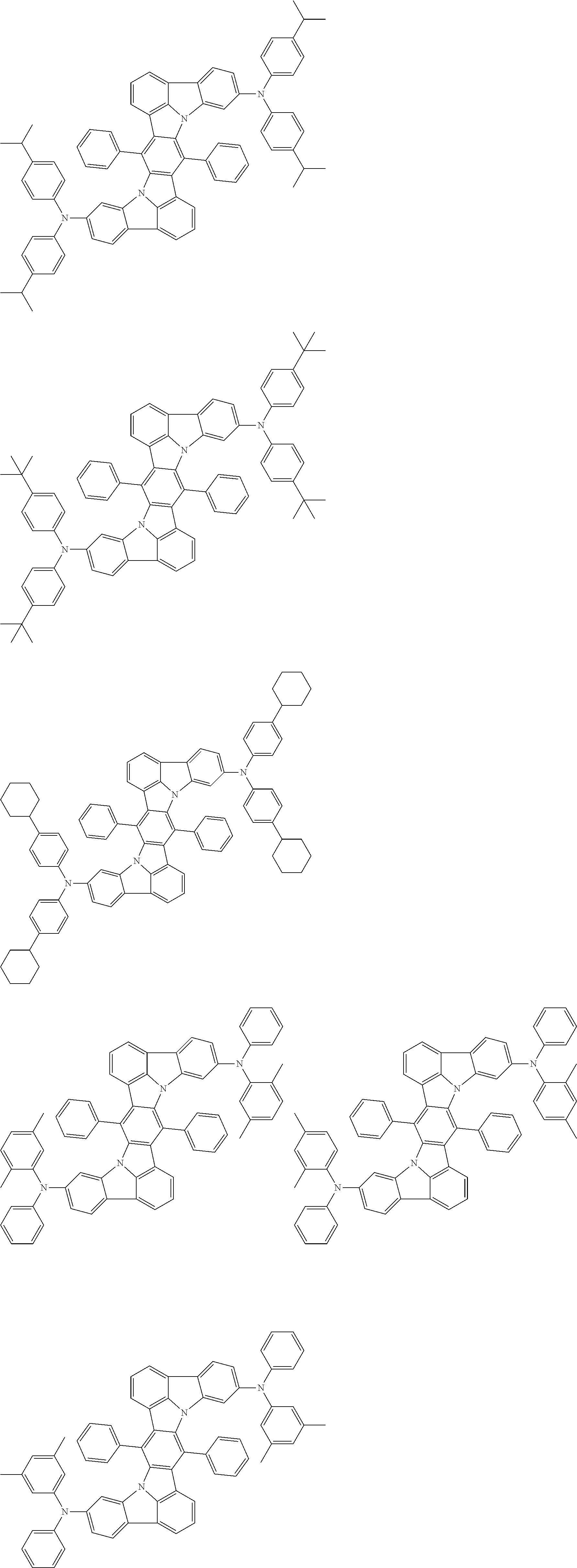

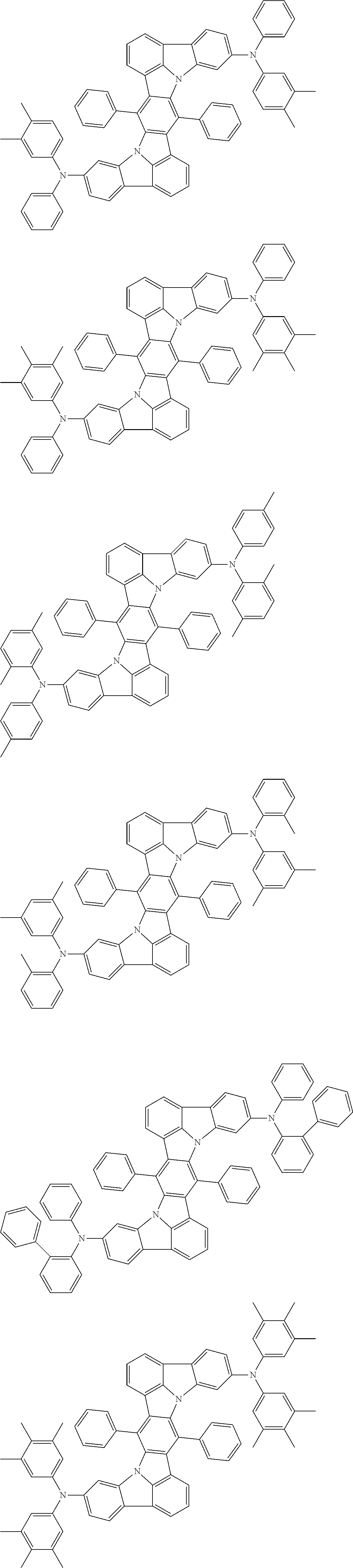

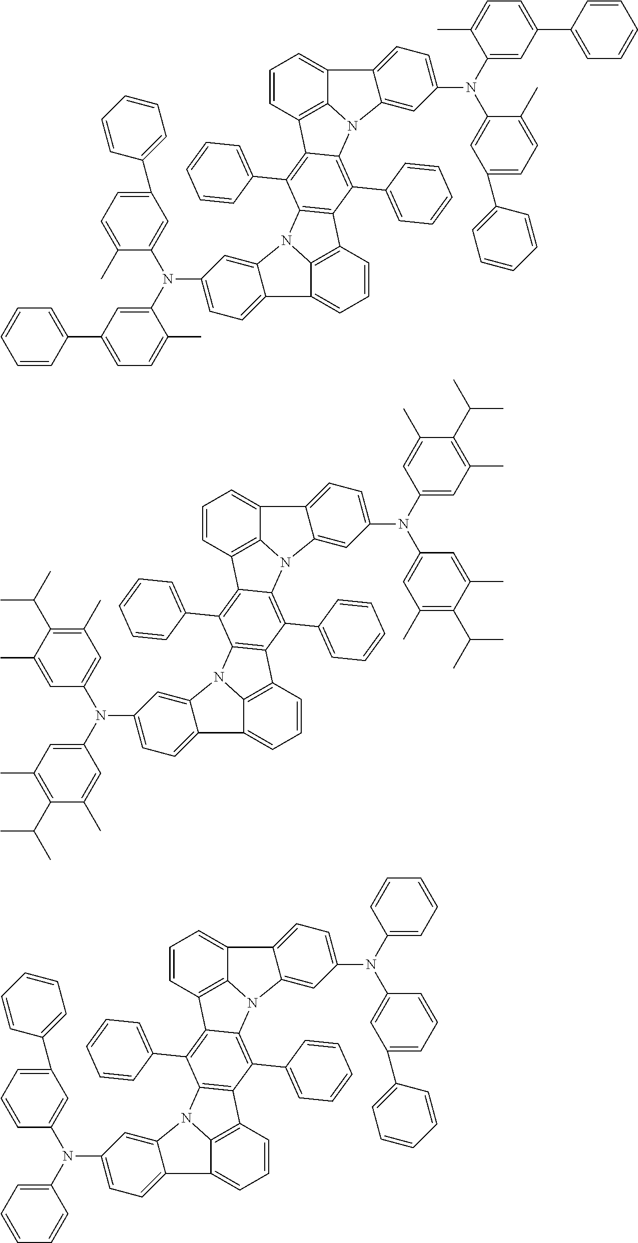 [SMILES: Cc1ccc(-c2ccccc2)cc1N(c1ccc2c3cccc4c5c(-c6ccccc6)c6c(c(-c7ccccc7)c5n(c2c1)c34)c1cccc2c3ccc(N(c4cc(-c5ccccc5)ccc4C)c4cc(-c5ccccc5)ccc4C)cc3n6c21)c1cc(-c2ccccc2)ccc1C ; Cc1cc(N(c2cc(C)c(C(C)C)c(C)c2)c2ccc3c4cccc5c6c(-c7ccccc7)c7c(c(-c8ccccc8)c6n(c3c2)c45)c2cccc3c4ccc(N(c5cc(C)c(C(C)C)c(C)c5)c5cc(C)c(C(C)C)c(C)c5)cc4n7c32)cc(C)c1C(C)C ; c1ccc(-c2cccc(N(c3ccccc3)c3ccc4c5cccc6c7c(-c8ccccc8)c8c(c(-c9ccccc9)c7n(c4c3)c56)c3cccc4c5ccc(N(c6ccccc6)c6cccc(-c7ccccc7)c6)cc5n8c43)c2)cc1]

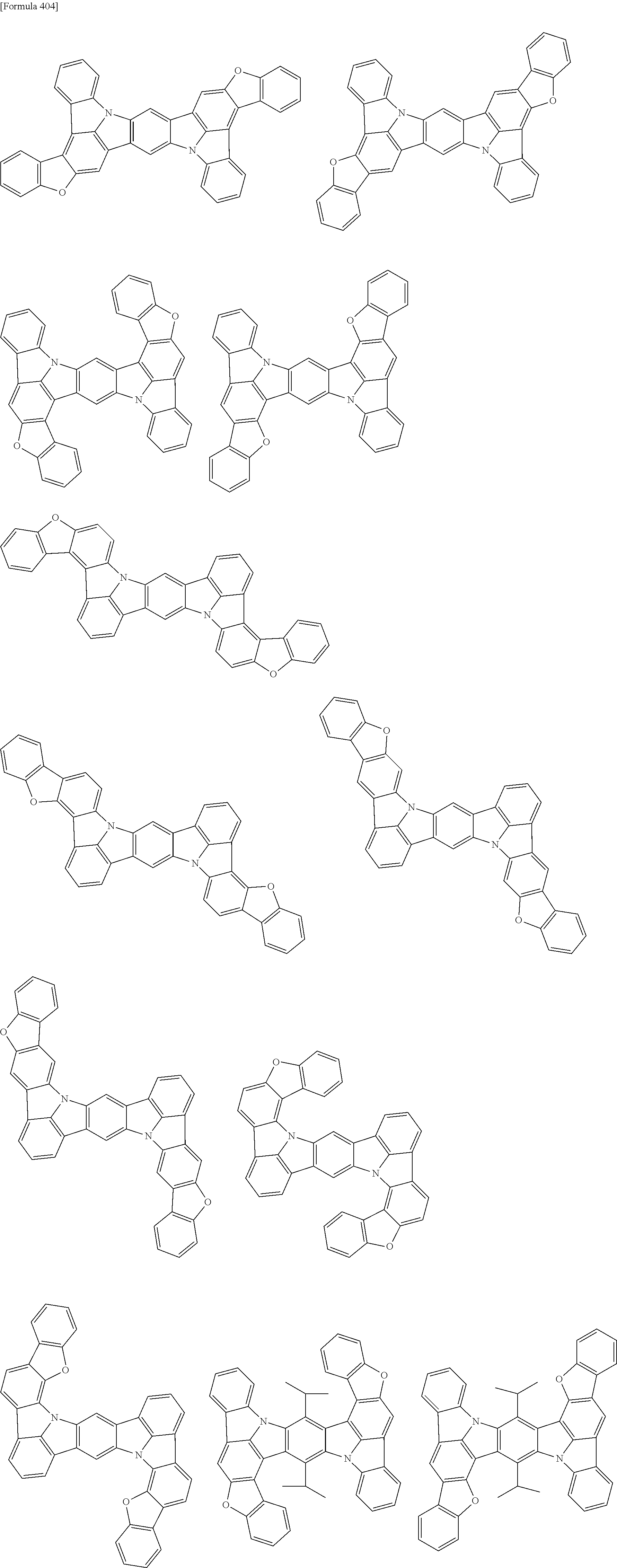

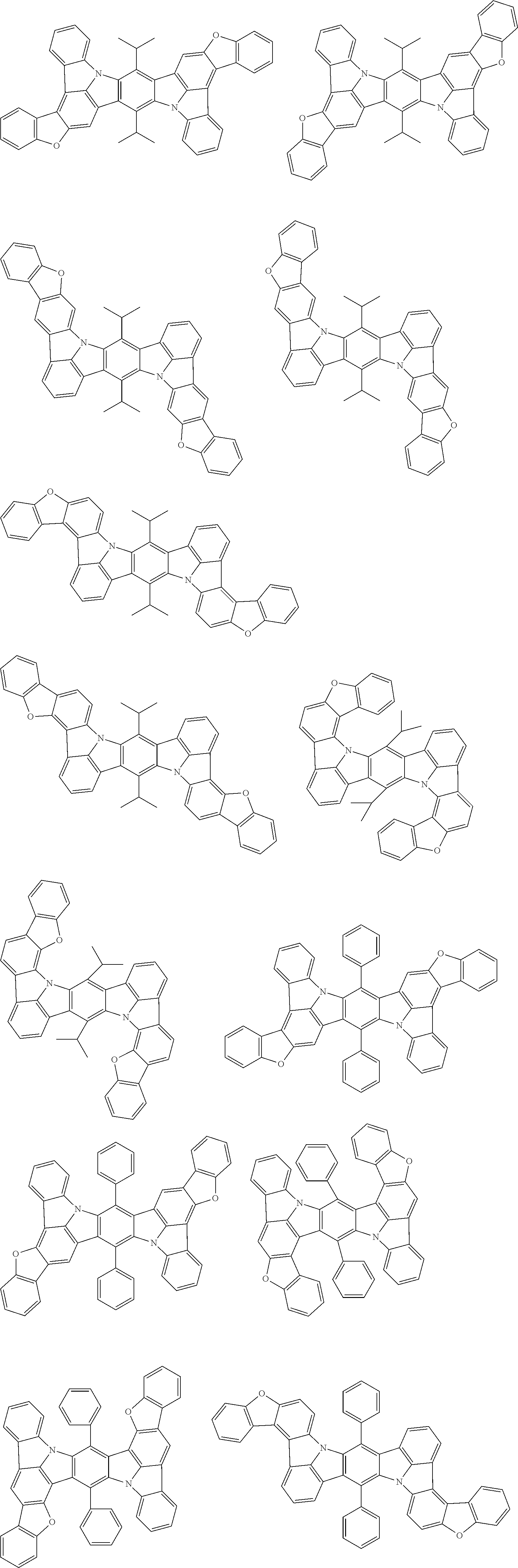

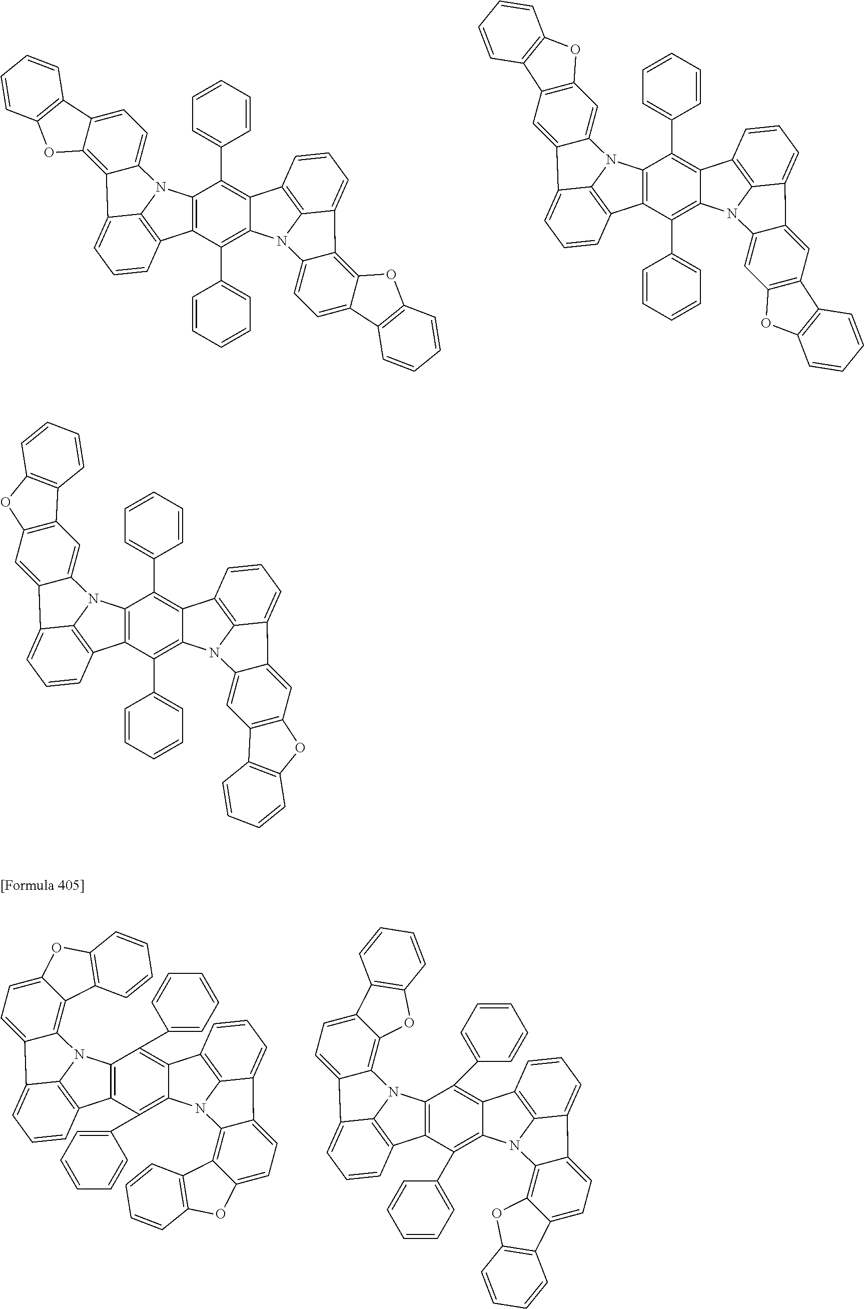

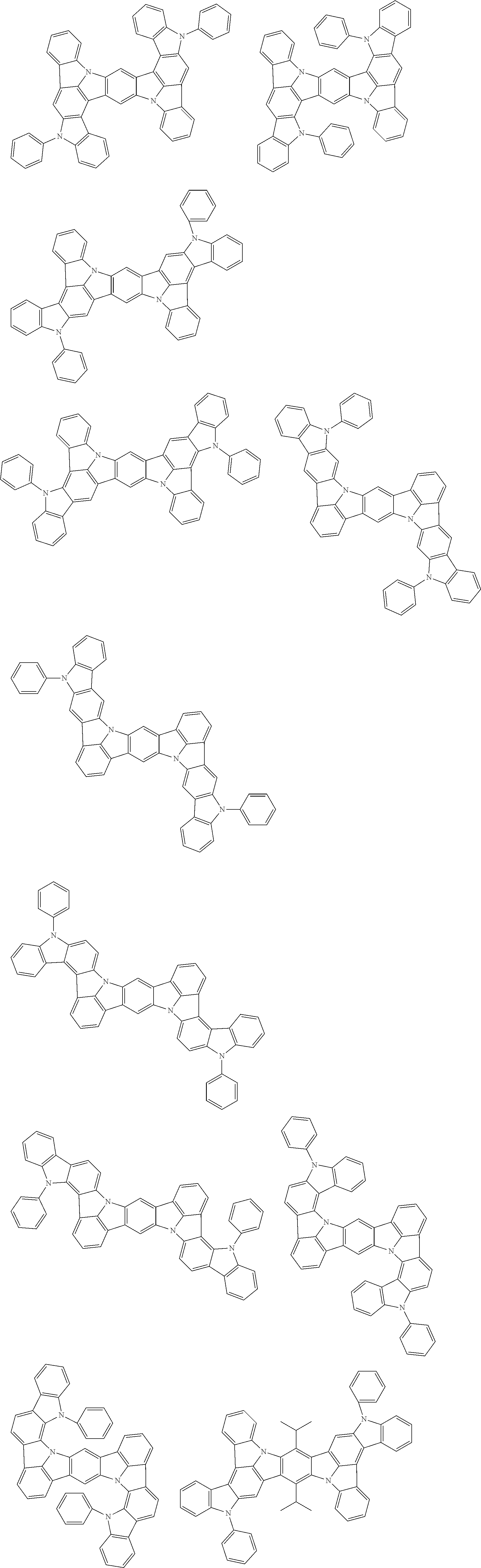

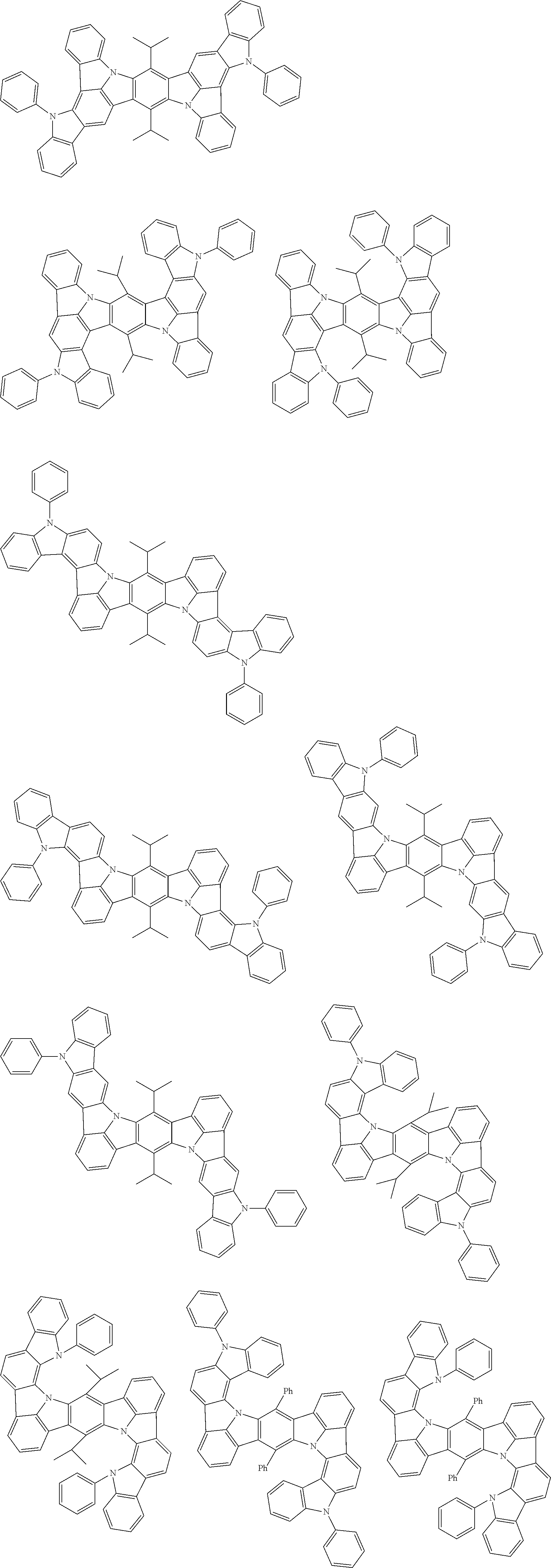

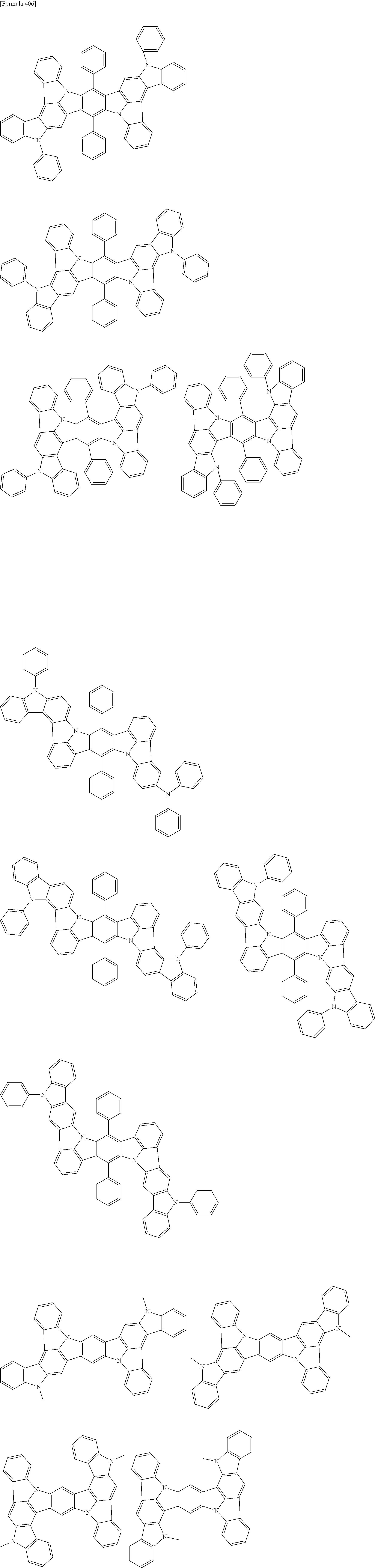

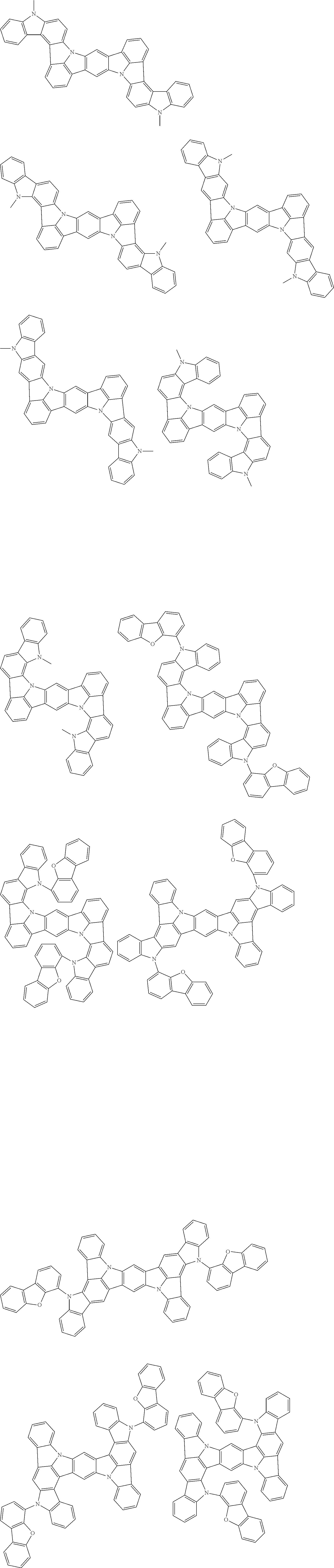

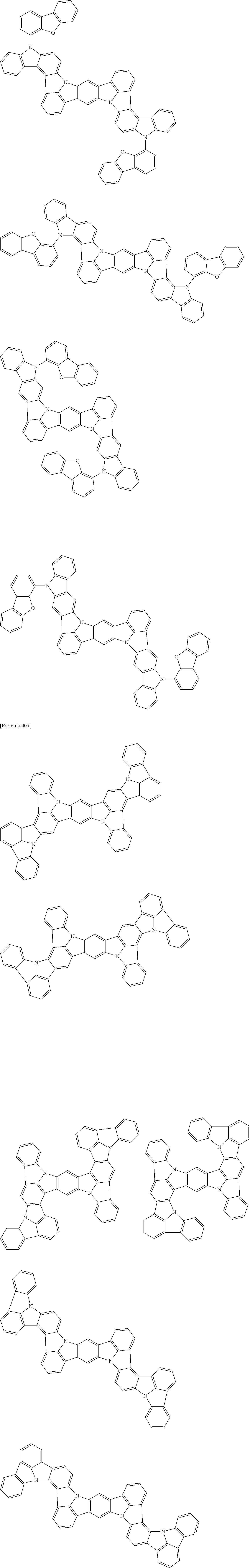

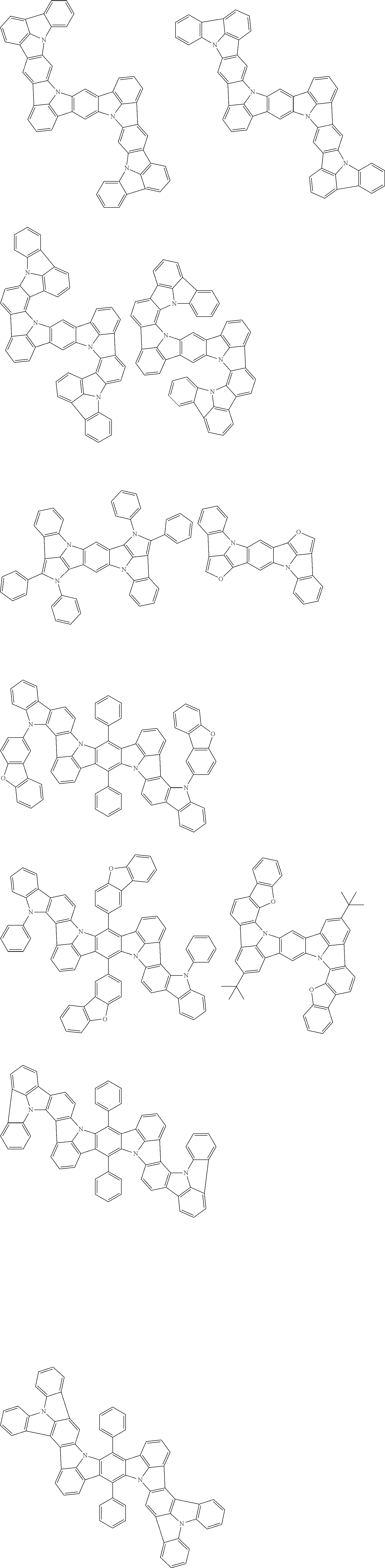

### Compound Represented by Formula (7)

The compound represented by the formula (7) will be described below.

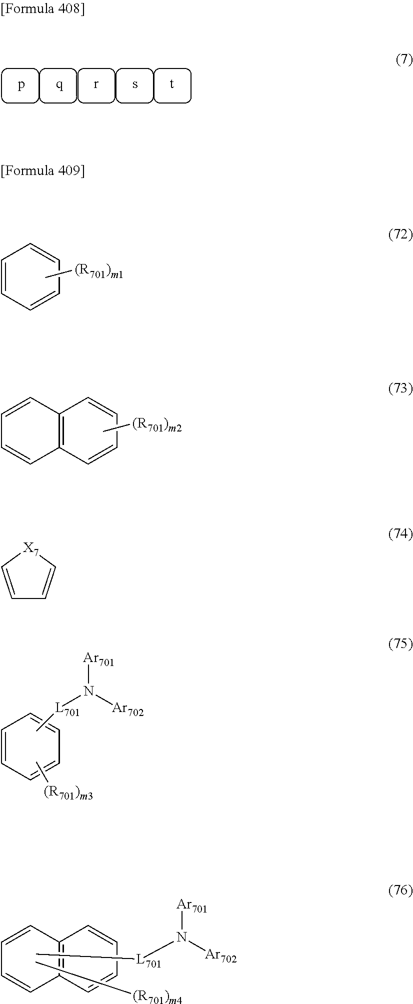

In the formula (7):
r ring is a ring represented by the formula (72) or the formula (73), the r ring being fused with adjacent ring(s) at any position(s);
q ring and s ring are each independently a ring represented by the formula (74) and fused with adjacent ring(s) at any position(s);
p ring and t ring are each independently a structure represented by the formula (75) or the formula (76) and fused with adjacent ring(s) at any position(s);
X₇ is an oxygen atom, a sulfur atom, or NR₇₀₂;
when a plurality of R₇₀₁ are present, adjacent ones of the plurality of R₇₀₁ are mutually bonded to form a substituted or unsubstituted monocyclic ring, mutually bonded to form a substituted or unsubstituted fused ring, or not mutually bonded;
R₇₀₁ and R₇₀₂ forming neither the monocyclic ring nor the fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
Ar₇₀₁ and Ar₇₀₂ are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
L₇₀₁ is a substituted or unsubstituted alkylene group having 1 to 50 carbon atoms, a substituted or unsubstituted alkenylene group having 2 to 50 carbon atoms, a substituted or unsubstituted alkynylene group having 2 to 50 carbon atoms, a substituted or unsubstituted cycloalkylene group having 3 to 50 ring carbon atoms, a substituted or unsubstituted arylene group having 6 to 50 ring carbon atoms, or a substituted or unsubstituted divalent heterocyclic group having 5 to 50 ring atoms;
m1 is 0, 1, or 2;
m2 is 0, 1, 2, 3, or 4;
m3 is each independently 0, 1, 2, or 3;
m4 is each independently 0, 1, 2, 3, 4, or 5;
when a plurality of R₇₀₁ are present, the plurality of R₇₀₁ are mutually the same or different;
when a plurality of X₇ are present, the plurality of X₇ are mutually the same or different;
when a plurality of R₇₀₂ are present, the plurality of R₇₀₂ are mutually the same or different;
when a plurality of Ar₇₀₁ are present, the plurality of Ar₇₀₁ are mutually the same or different;
when a plurality of Ar₇₀₂ are present, the plurality of Ar₇₀₂ are mutually the same or different; and
when a plurality of L₇₀₁ are present, the plurality of L₇₀₁ are mutually the same or different.

In the formula (7), each of the p ring, q ring, r ring, s ring, and t ring is fused with an adjacent ring(s) sharing two carbon atoms. The fused position and orientation are not limited but may be defined as required.

In an exemplary embodiment, in the formula (72) or the formula (73) representing the r ring, m1=0 or m2=0 is satisfied.

In an exemplary embodiment, the compound represented by the formula (7) is represented by any one of formulae (71-1) to (71-6) below.

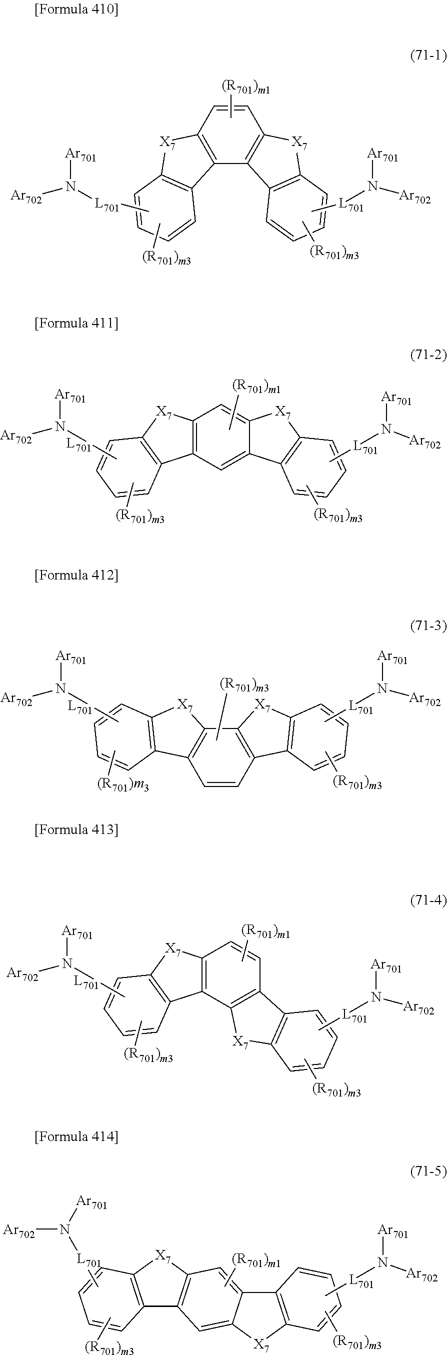

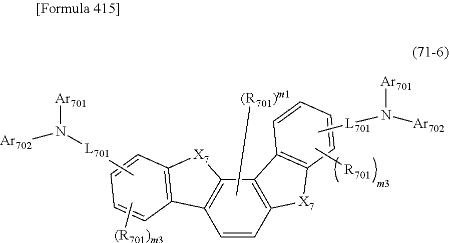

In the formulae (71-1) to (71-6), R₇₀₁, X₇, Ar₇₀₁, Ar₇₀₂, L₇₀₁, m1 and m3 respectively represent the same as R₇₀₁, X₇, Ar₇₀₁, Ar₇₀₂, L₇₀₁, m1 and m3 in the formula (7).

In an exemplary embodiment, the compound represented by the formula (7) is represented by any one of formulae (71-11) to (71-13) below.

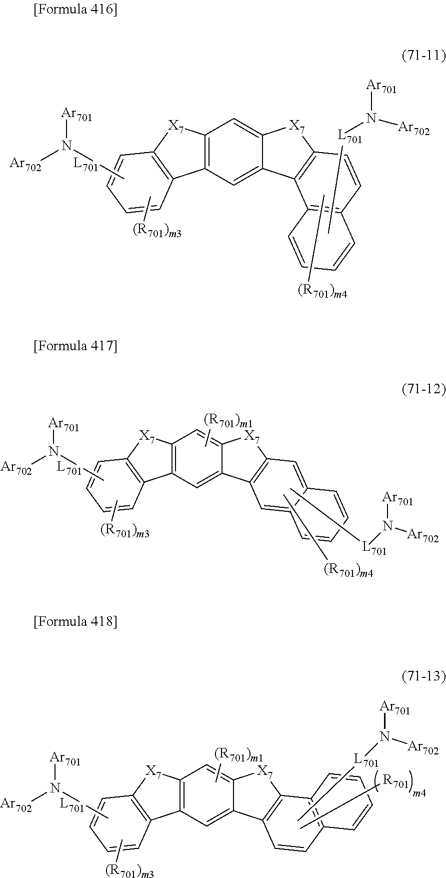

In the formulae (71-11) to (71-13), R₇₀₁, X₇, Ar₇₀₁, Ar₇₀₂, L₇₀₁, m1, m3 and m4 respectively represent the same as R₇₀₁, X₇, Ar₇₀₁, Ar₇₀₂, L₇₀₁, m1, m3 and m4 in the formula (7).

In an exemplary embodiment, the compound represented by the formula (7) is represented by any one of formulae (71-21) to (71-25) below.

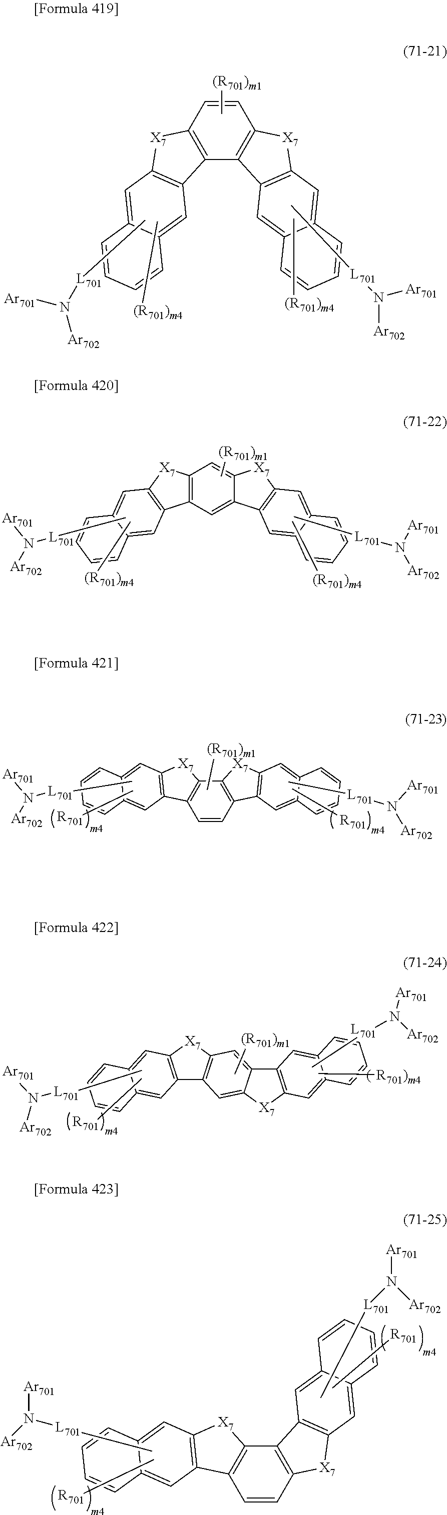

In the formulae (71-21) to (71-25), R₇₀₁, X₇, Ar₇₀₁, Ar₇₀₂, L₇₀₁, m1 and m4 respectively represent the same as R₇₀₁, X₇, Ar₇₀₁, Ar₇₀₂, L₇₀₁, m1 and m4 in the formula (7).

In an exemplary embodiment, the compound represented by the formula (7) is represented by any one of formulae (71-31) to (71-33) below.

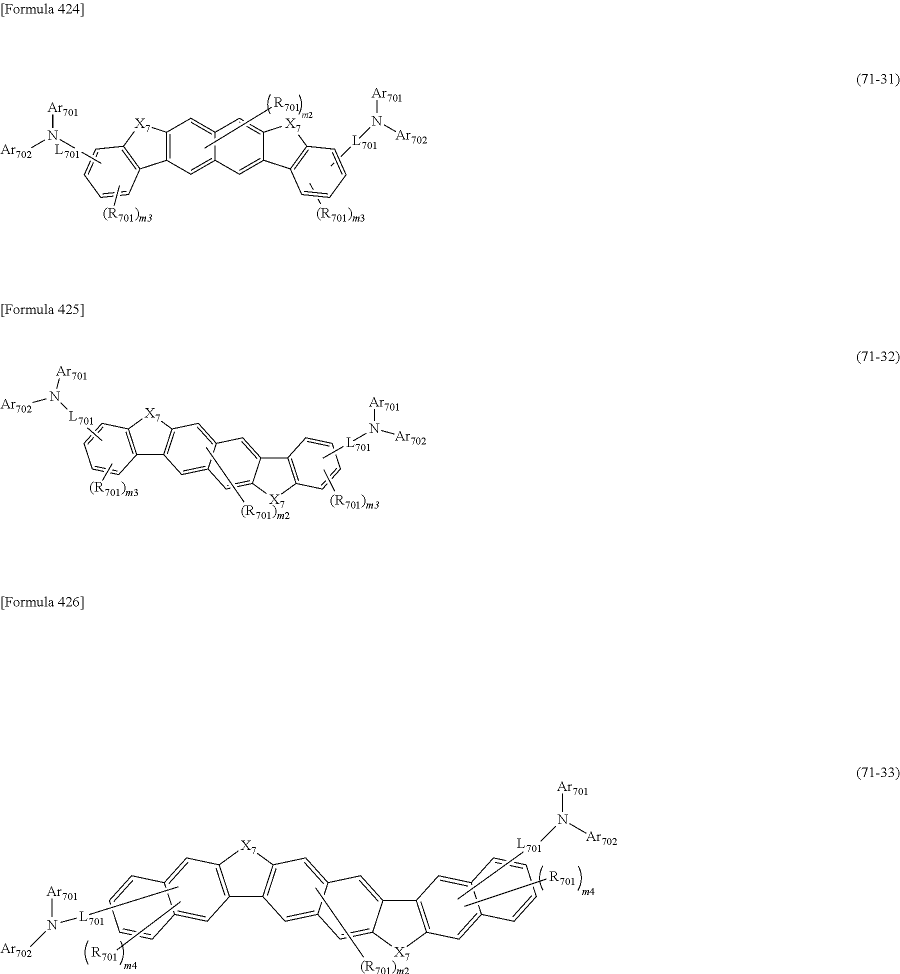

In the formulae (71-31) to (71-33), R₇₀₁, X₇, Ar₇₀₁, Ar₇₀₂, L₇₀₁, and m2 to m4 respectively represent the same as R₇₀₁, X₇, Ar₇₀₁, Ar₇₀₂, L₇₀₁, and m2 to m4 in the formula (7).

In an exemplary embodiment, Ar₇₀₁ and Ar₇₀₂ are each independently a substituted or unsubstituted aryl group having 6 to 50 ring carbon atoms.

In an exemplary embodiment, one of Ar₇₀₁ and Ar₇₀₂ is a substituted or unsubstituted aryl group having 6 to 50 ring carbon atoms, and the other of Ar₇₀₁ and Ar₇₀₂ is a substituted or unsubstituted heterocyclic group having 5 to 50 ring atoms.

### Specific Examples of Compound Represented by Formula (7)

Specific examples of the compound represented by the formula (7) include compounds shown below.

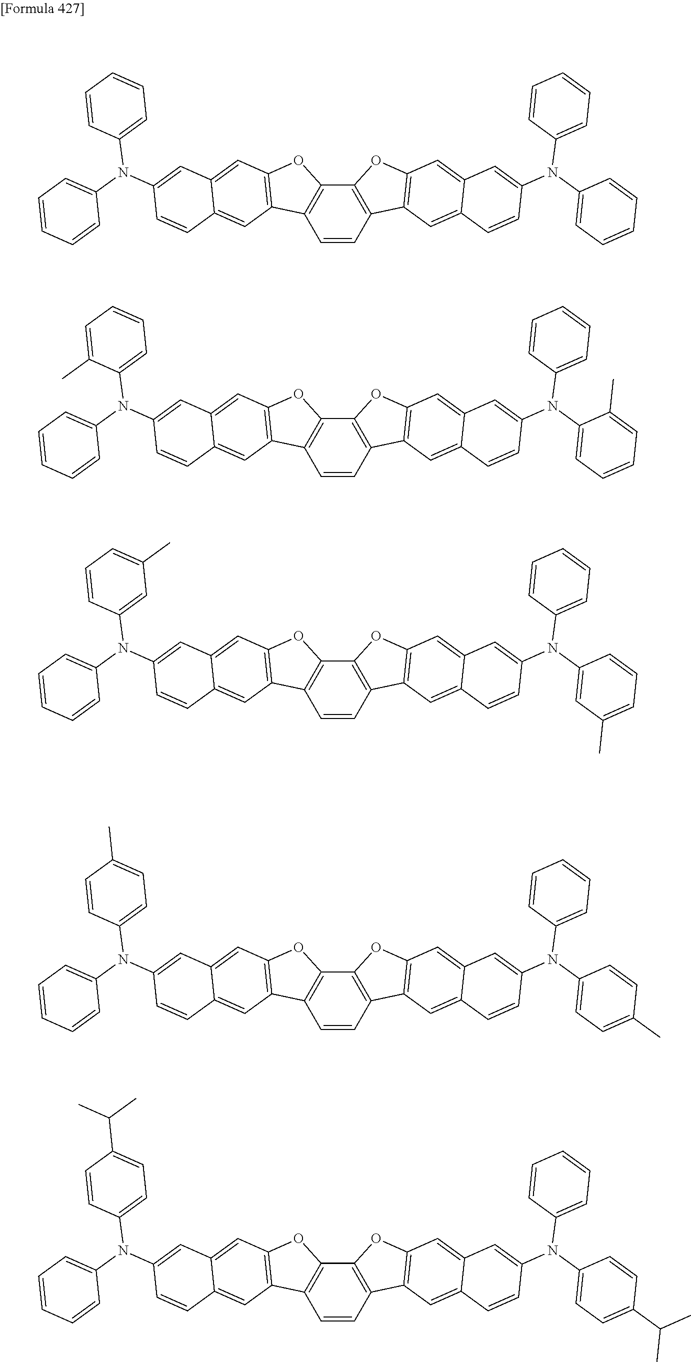 [SMILES: c1ccc(N(c2ccccc2)c2ccc3cc4c(cc3c2)oc2c4ccc3c4cc5ccc(N(c6ccccc6)c6ccccc6)cc5cc4oc32)cc1 ; Cc1ccccc1N(c1ccccc1)c1ccc2cc3c(cc2c1)oc1c3ccc2c3cc4ccc(N(c5ccccc5)c5ccccc5C)cc4cc3oc21 ; Cc1cccc(N(c2ccccc2)c2ccc3cc4c(cc3c2)oc2c4ccc3c4cc5ccc(N(c6ccccc6)c6cccc(C)c6)cc5cc4oc32)c1 ; Cc1ccc(N(c2ccccc2)c2ccc3cc4c(cc3c2)oc2c4ccc3c4cc5ccc(N(c6ccccc6)c6ccc(C)cc6)cc5cc4oc32)cc1 ; CC(C)c1ccc(N(c2ccccc2)c2ccc3cc4c(cc3c2)oc2c4ccc3c4cc5ccc(N(c6ccccc6)c6ccc(C(C)C)cc6)cc5cc4oc32)cc1]

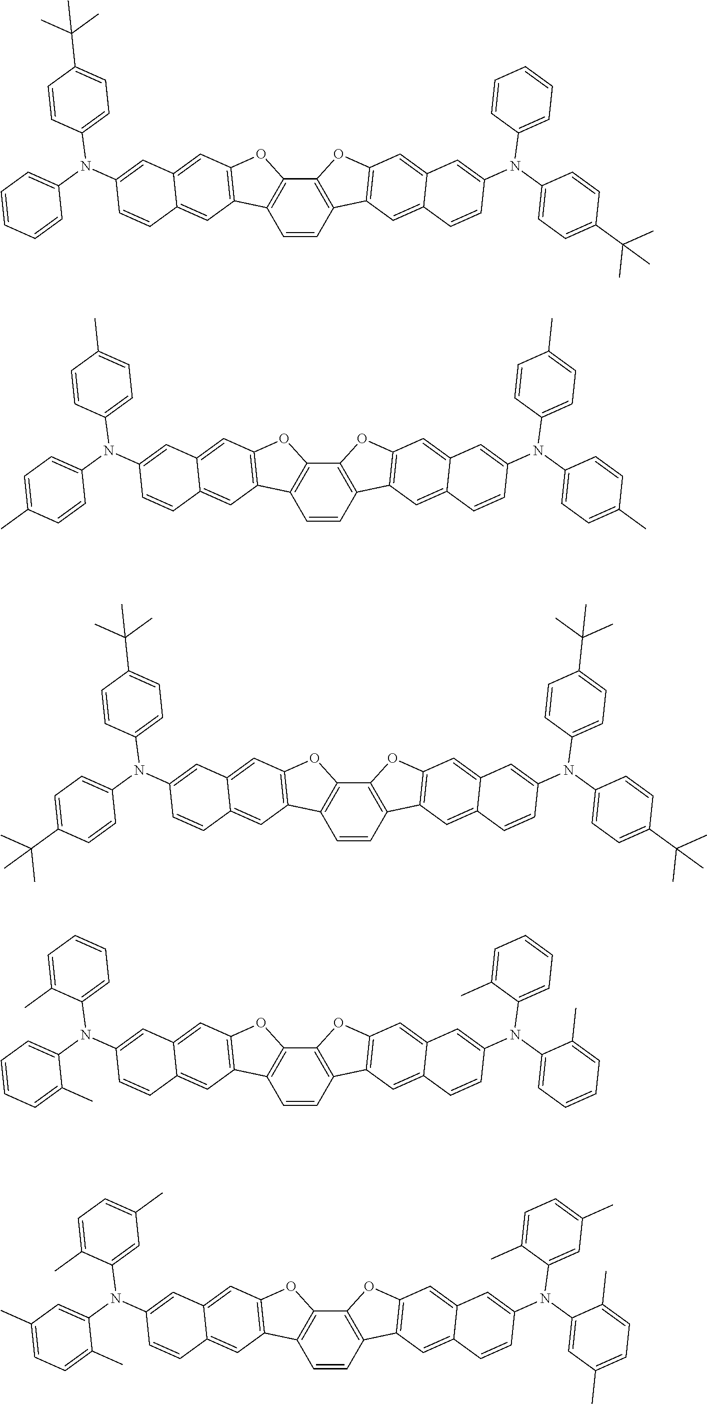

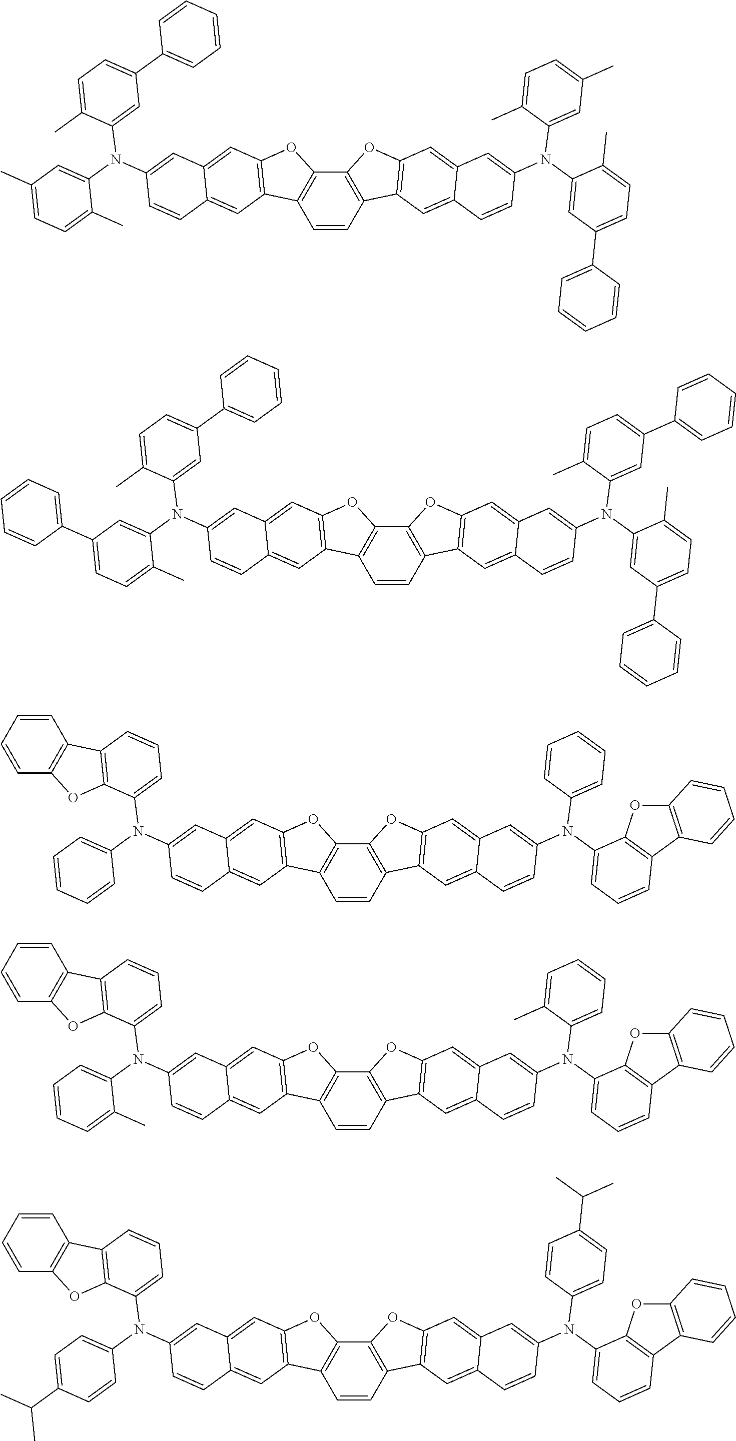

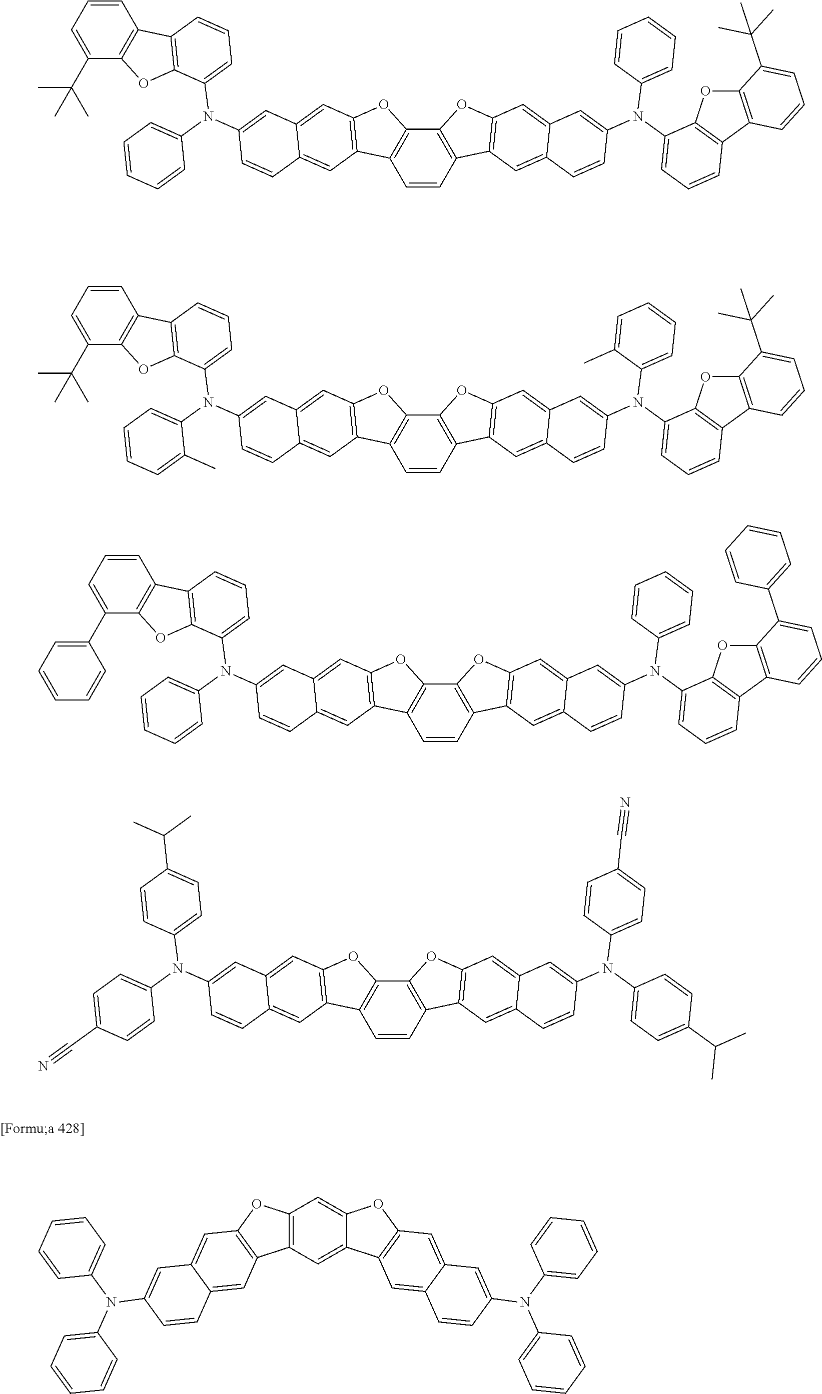

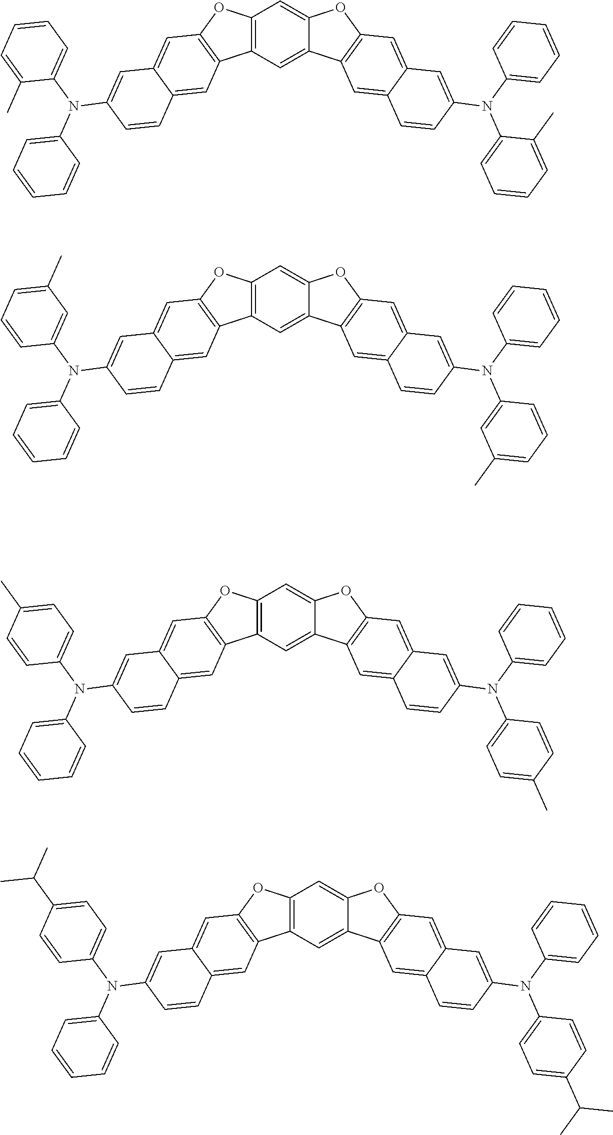 [SMILES: Cc1ccccc1N(c1ccccc1)c1ccc2cc3c(cc2c1)oc1cc2oc4cc5cc(N(c6ccccc6)c6ccccc6C)ccc5cc4c2cc13 ; Cc1cccc(N(c2ccccc2)c2ccc3cc4c(cc3c2)oc2cc3oc5cc6cc(N(c7ccccc7)c7cccc(C)c7)ccc6cc5c3cc24)c1 ; Cc1ccc(N(c2ccccc2)c2ccc3cc4c(cc3c2)oc2cc3oc5cc6cc(N(c7ccccc7)c7ccc(C)cc7)ccc6cc5c3cc24)cc1 ; CC(C)c1ccc(N(c2ccccc2)c2ccc3cc4c(cc3c2)oc2cc3oc5cc6cc(N(c7ccccc7)c7ccc(C(C)C)cc7)ccc6cc5c3cc24)cc1]

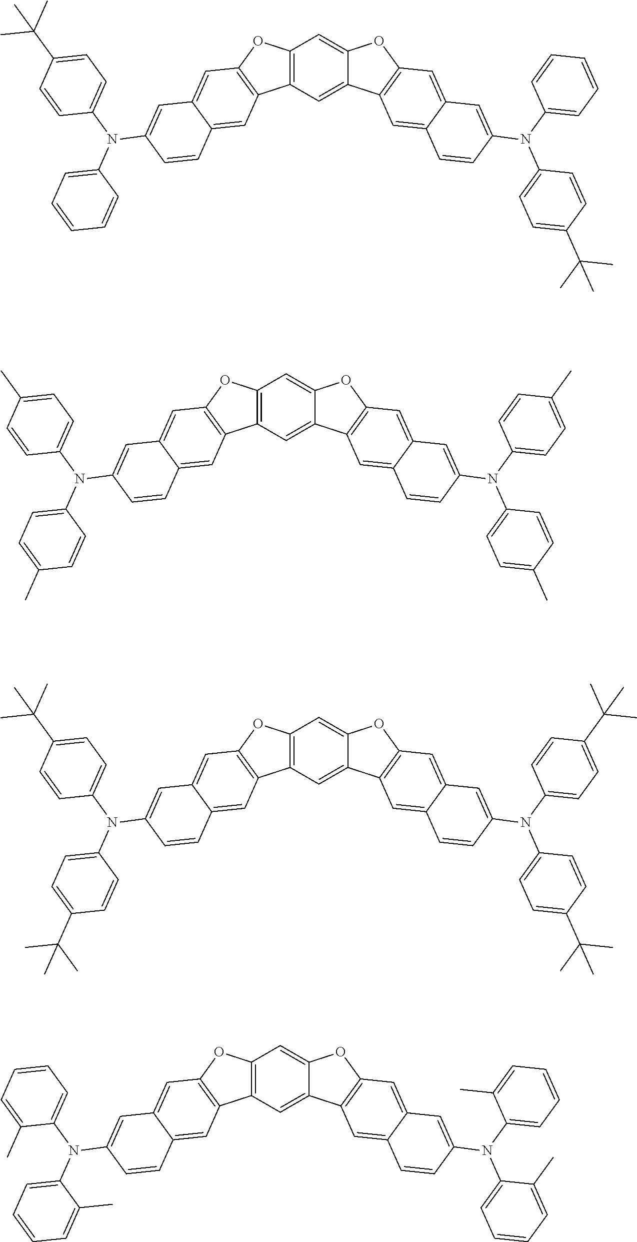

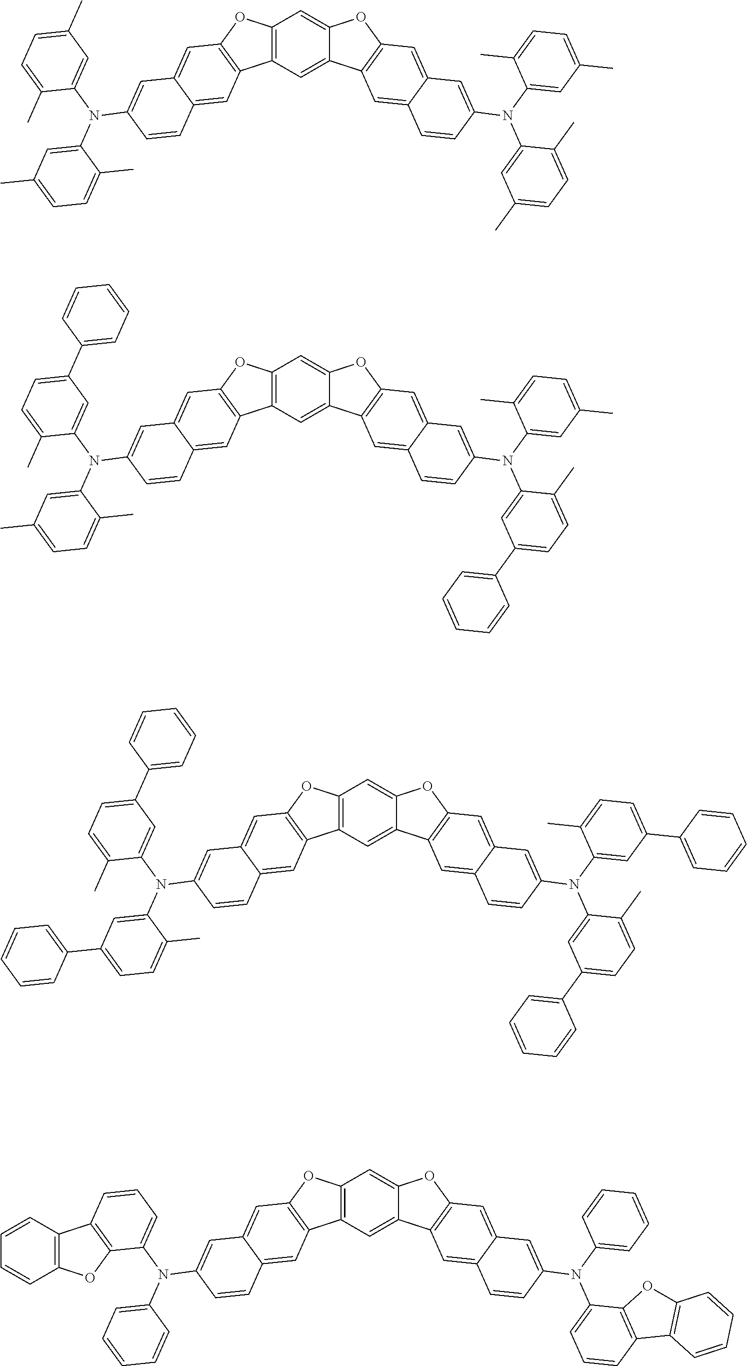

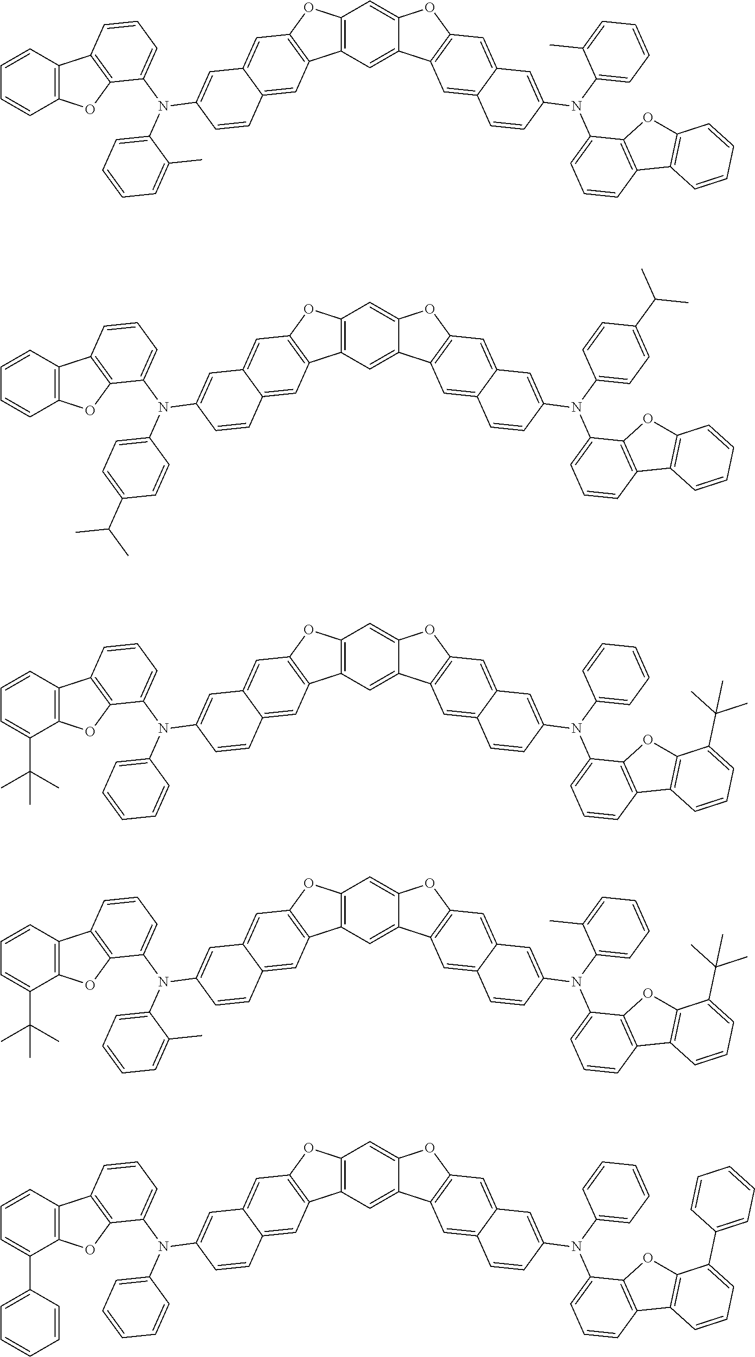

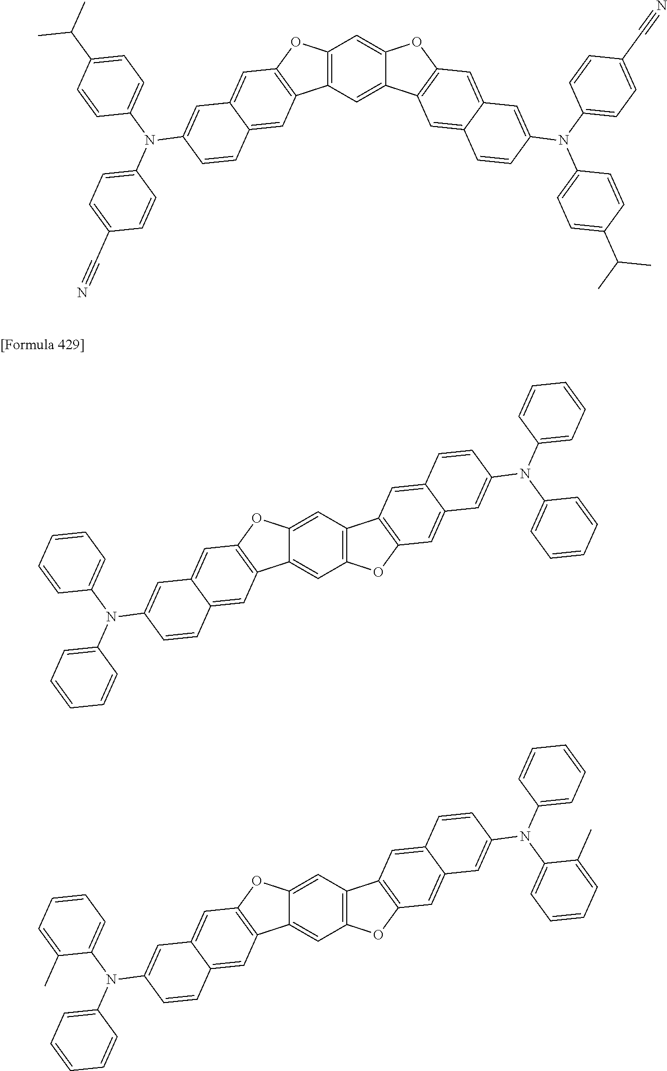 [SMILES: CC(C)c1ccc(N(c2ccc(C#N)cc2)c2ccc3cc4c(cc3c2)oc2cc3oc5cc6cc(N(c7ccc(C#N)cc7)c7ccc(C(C)C)cc7)ccc6cc5c3cc24)cc1 ; c1ccc(N(c2ccccc2)c2ccc3cc4c(cc3c2)oc2cc3c(cc24)oc2cc4cc(N(c5ccccc5)c5ccccc5)ccc4cc23)cc1 ; Cc1ccccc1N(c1ccccc1)c1ccc2cc3c(cc2c1)oc1cc2c(cc13)oc1cc3cc(N(c4ccccc4)c4ccccc4C)ccc3cc12]

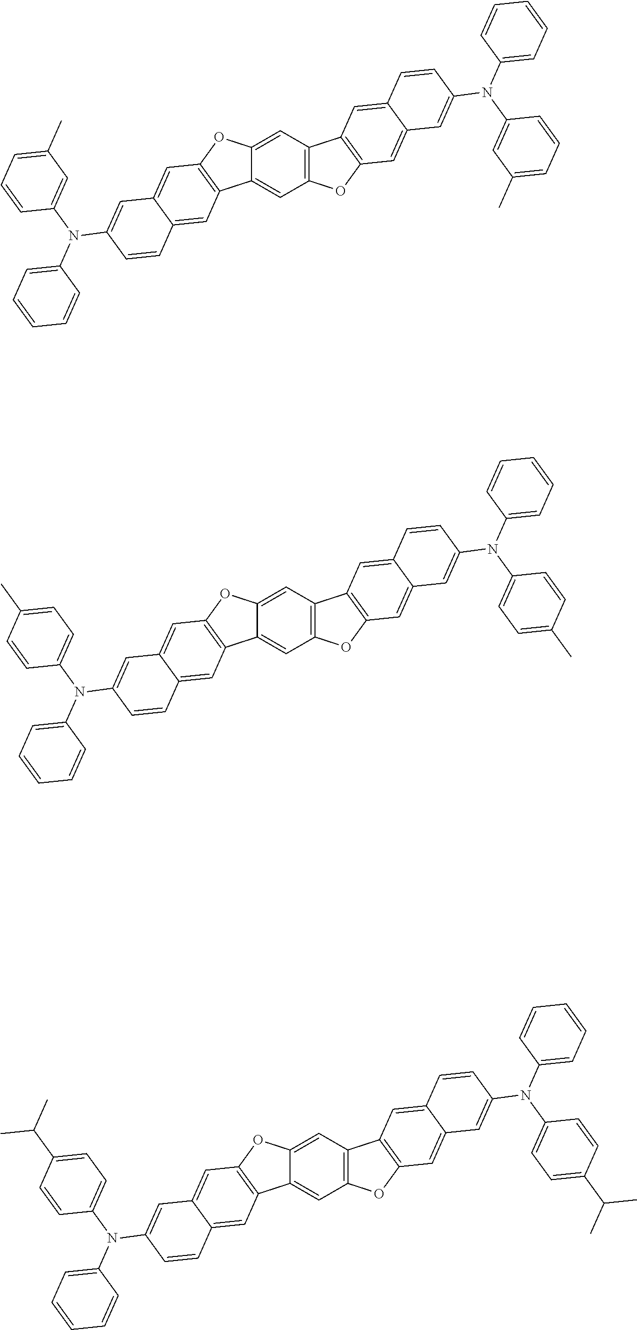

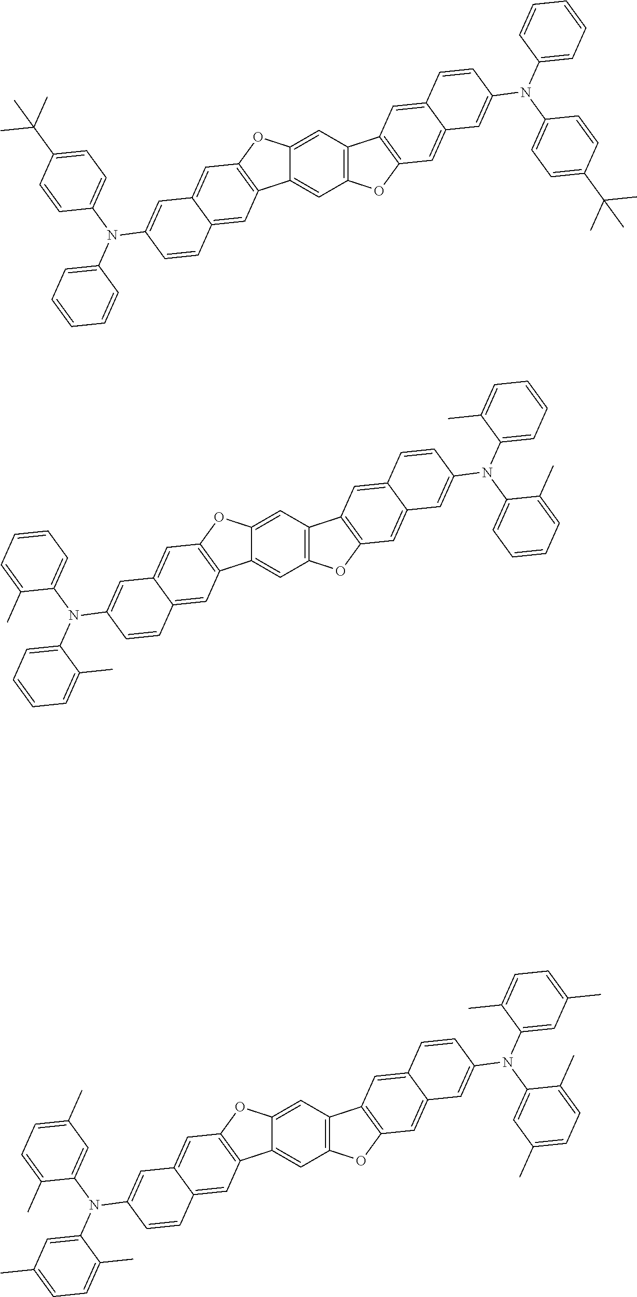

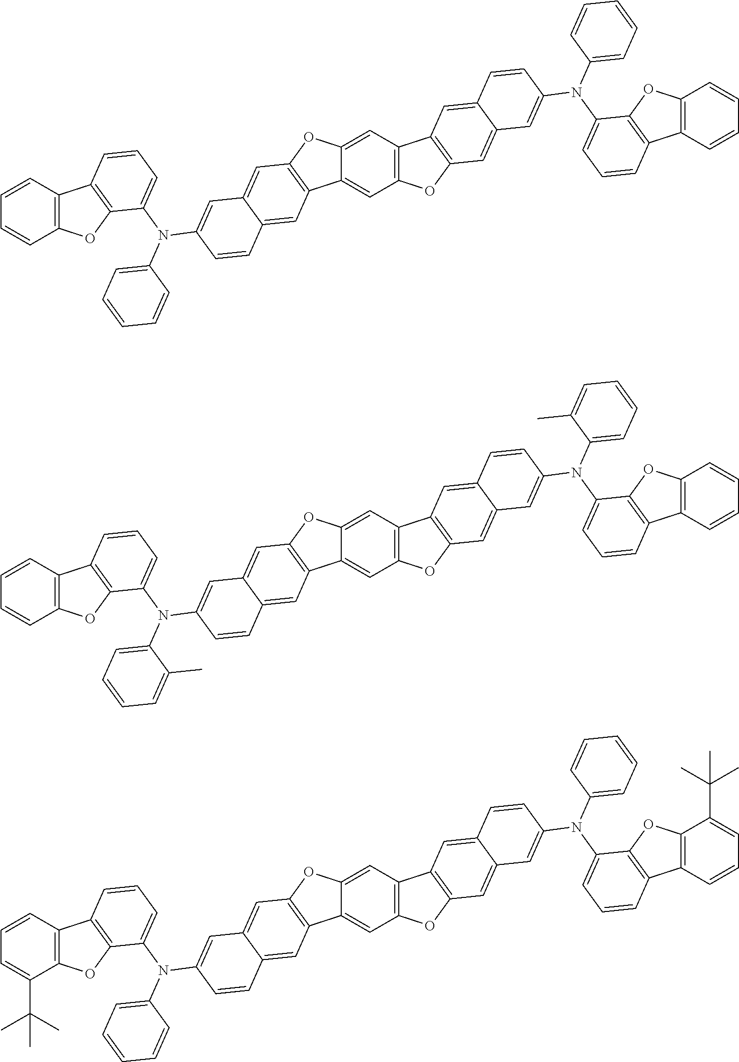 [SMILES: c1ccc(N(c2ccc3cc4c(cc3c2)oc2cc3c(cc24)oc2cc4cc(N(c5ccccc5)c5cccc6c5oc5ccccc56)ccc4cc23)c2cccc3c2oc2ccccc23)cc1 ; Cc1ccccc1N(c1ccc2cc3c(cc2c1)oc1cc2c(cc13)oc1cc3cc(N(c4ccccc4C)c4cccc5c4oc4ccccc45)ccc3cc12)c1cccc2c1oc1ccccc12 ; CC(C)(C)c1cccc2c1oc1c(N(c3ccccc3)c3ccc4cc5c(cc4c3)oc3cc4c(cc35)oc3cc5cc(N(c6ccccc6)c6cccc7c6oc6c(C(C)(C)C)cccc67)ccc5cc34)cccc12]

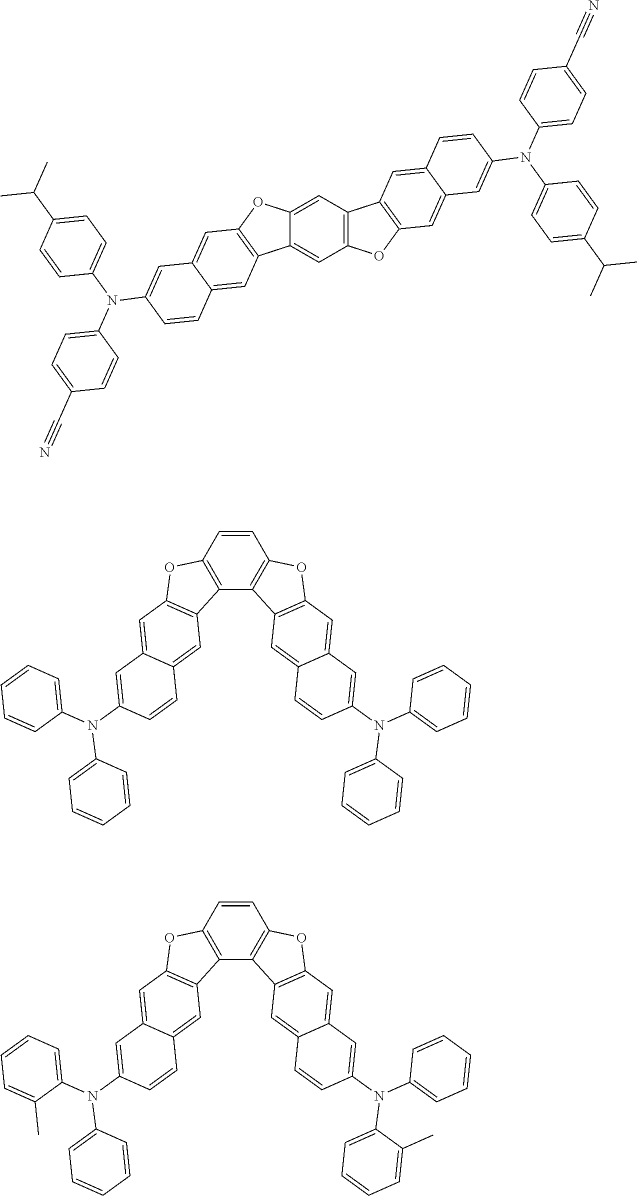 [SMILES: CC(C)c1ccc(N(c2ccc(C#N)cc2)c2ccc3cc4c(cc3c2)oc2cc3c(cc24)oc2cc4cc(N(c5ccc(C#N)cc5)c5ccc(C(C)C)cc5)ccc4cc23)cc1 ; c1ccc(N(c2ccccc2)c2ccc3cc4c(cc3c2)oc2ccc3oc5cc6cc(N(c7ccccc7)c7ccccc7)ccc6cc5c3c24)cc1 ; Cc1ccccc1N(c1ccccc1)c1ccc2cc3c(cc2c1)oc1ccc2oc4cc5cc(N(c6ccccc6)c6ccccc6C)ccc5cc4c2c13]

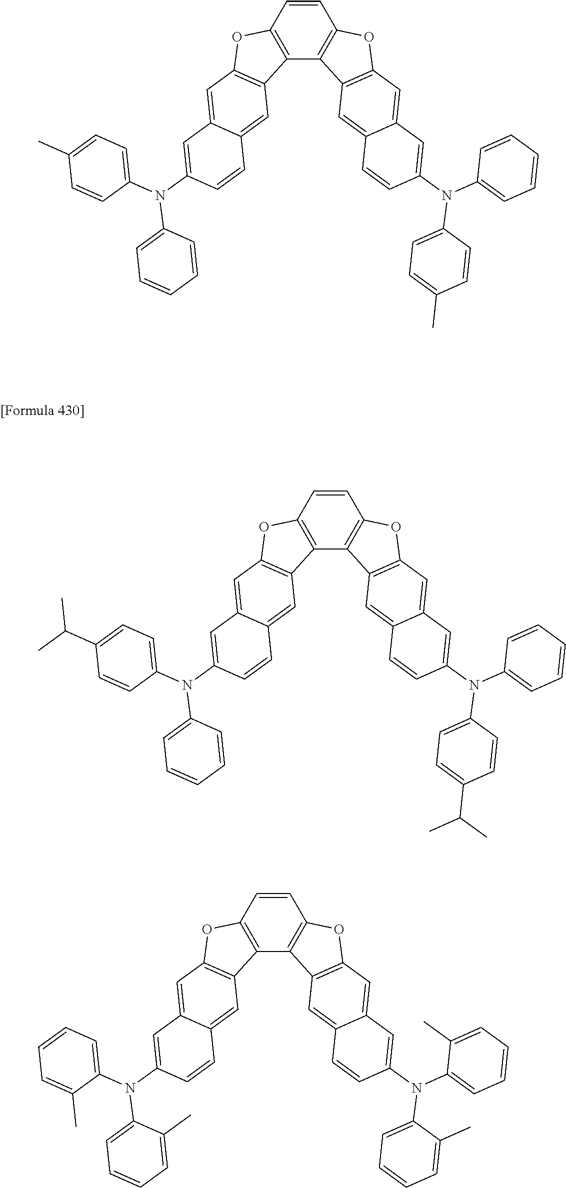 [SMILES: Cc1ccc(N(c2ccccc2)c2ccc3cc4c(cc3c2)oc2ccc3oc5cc6cc(N(c7ccccc7)c7ccc(C)cc7)ccc6cc5c3c24)cc1 ; CC(C)c1ccc(N(c2ccccc2)c2ccc3cc4c(cc3c2)oc2ccc3oc5cc6cc(N(c7ccccc7)c7ccc(C(C)C)cc7)ccc6cc5c3c24)cc1 ; Cc1ccccc1N(c1ccc2cc3c(cc2c1)oc1ccc2oc4cc5cc(N(c6ccccc6C)c6ccccc6C)ccc5cc4c2c13)c1ccccc1C]

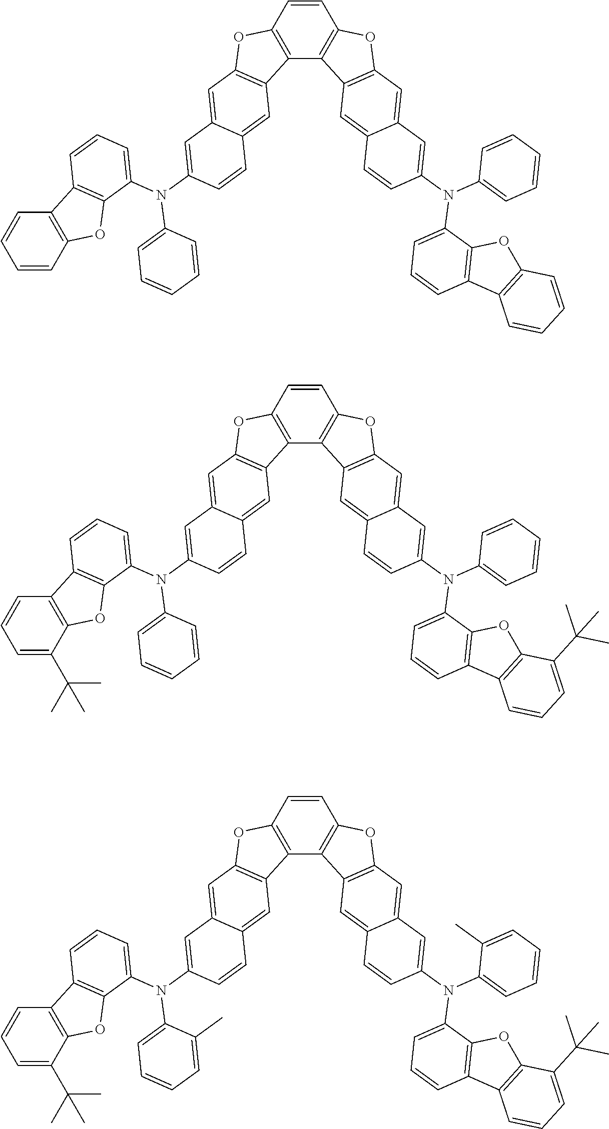 [SMILES: c1ccc(N(c2ccc3cc4c(cc3c2)oc2ccc3oc5cc6cc(N(c7ccccc7)c7cccc8c7oc7ccccc78)ccc6cc5c3c24)c2cccc3c2oc2ccccc23)cc1 ; CC(C)(C)c1cccc2c1oc1c(N(c3ccccc3)c3ccc4cc5c(cc4c3)oc3ccc4oc6cc7cc(N(c8ccccc8)c8cccc9c8oc8c(C(C)(C)C)cccc89)ccc7cc6c4c35)cccc12 ; Cc1ccccc1N(c1ccc2cc3c(cc2c1)oc1ccc2oc4cc5cc(N(c6ccccc6C)c6cccc7c6oc6c(C(C)(C)C)cccc67)ccc5cc4c2c13)c1cccc2c1oc1c(C(C)(C)C)cccc12]

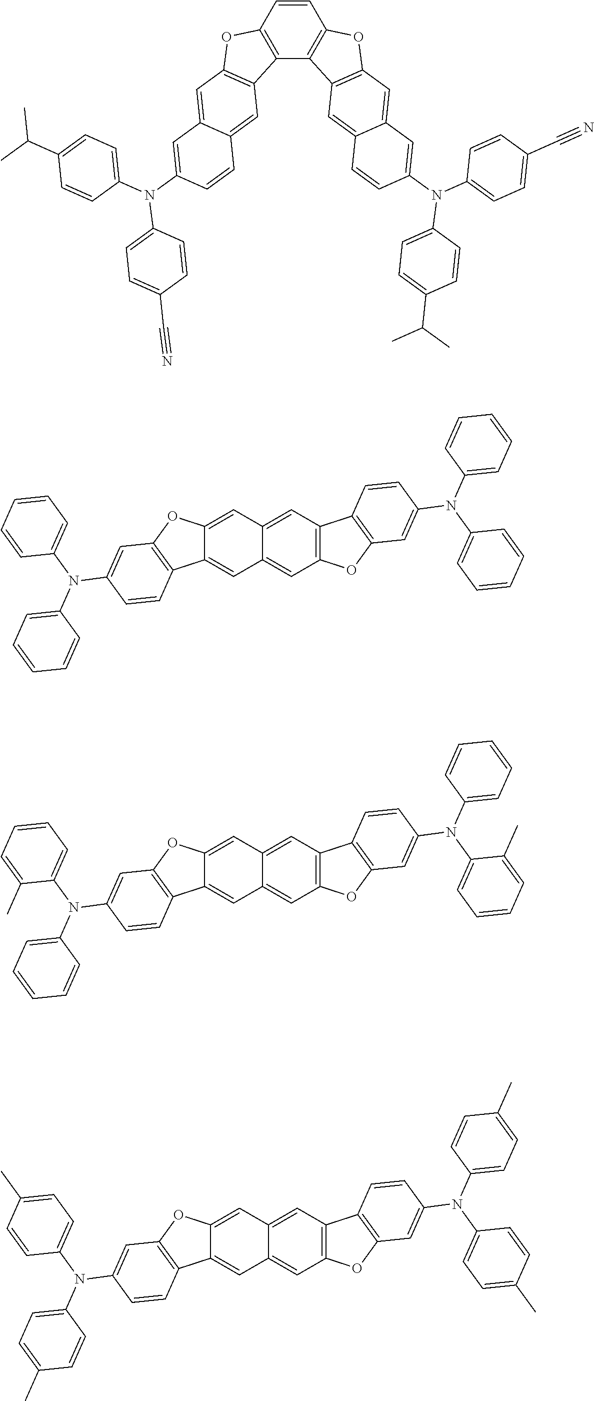

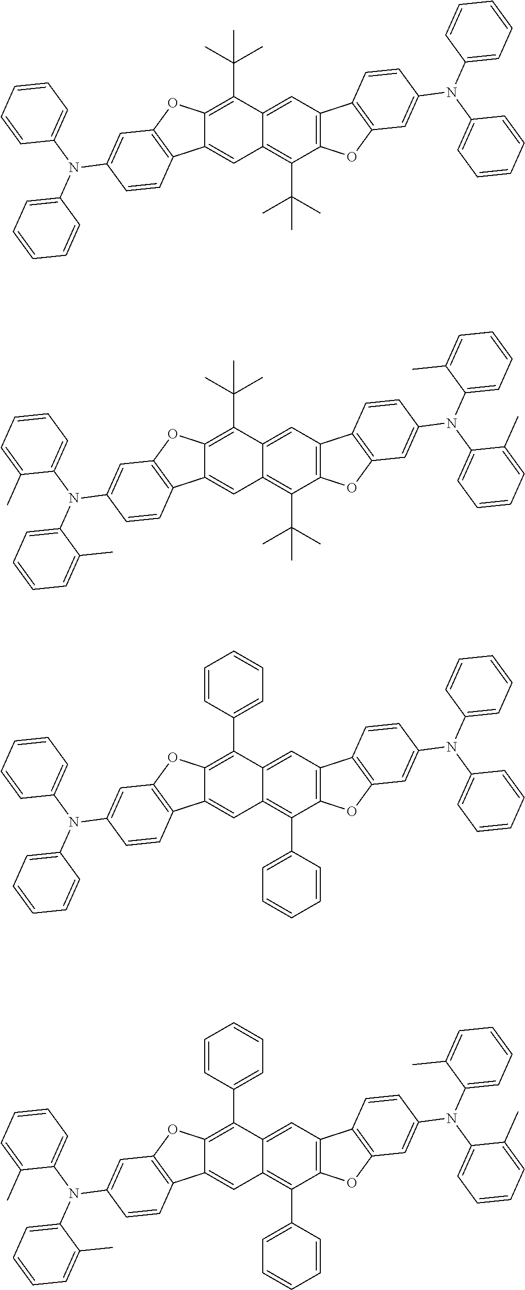 [SMILES: CC(C)(C)c1c2cc3c(oc4cc(N(c5ccccc5)c5ccccc5)ccc43)c(C(C)(C)C)c2cc2c1oc1cc(N(c3ccccc3)c3ccccc3)ccc12 ; Cc1ccccc1N(c1ccc2c(c1)oc1c(C(C)(C)C)c3cc4c(oc5cc(N(c6ccccc6C)c6ccccc6C)ccc54)c(C(C)(C)C)c3cc12)c1ccccc1C ; c1ccc(-c2c3cc4c(oc5cc(N(c6ccccc6)c6ccccc6)ccc54)c(-c4ccccc4)c3cc3c2oc2cc(N(c4ccccc4)c4ccccc4)ccc23)cc1 ; Cc1ccccc1N(c1ccc2c(c1)oc1c(-c3ccccc3)c3cc4c(oc5cc(N(c6ccccc6C)c6ccccc6C)ccc54)c(-c4ccccc4)c3cc12)c1ccccc1C]

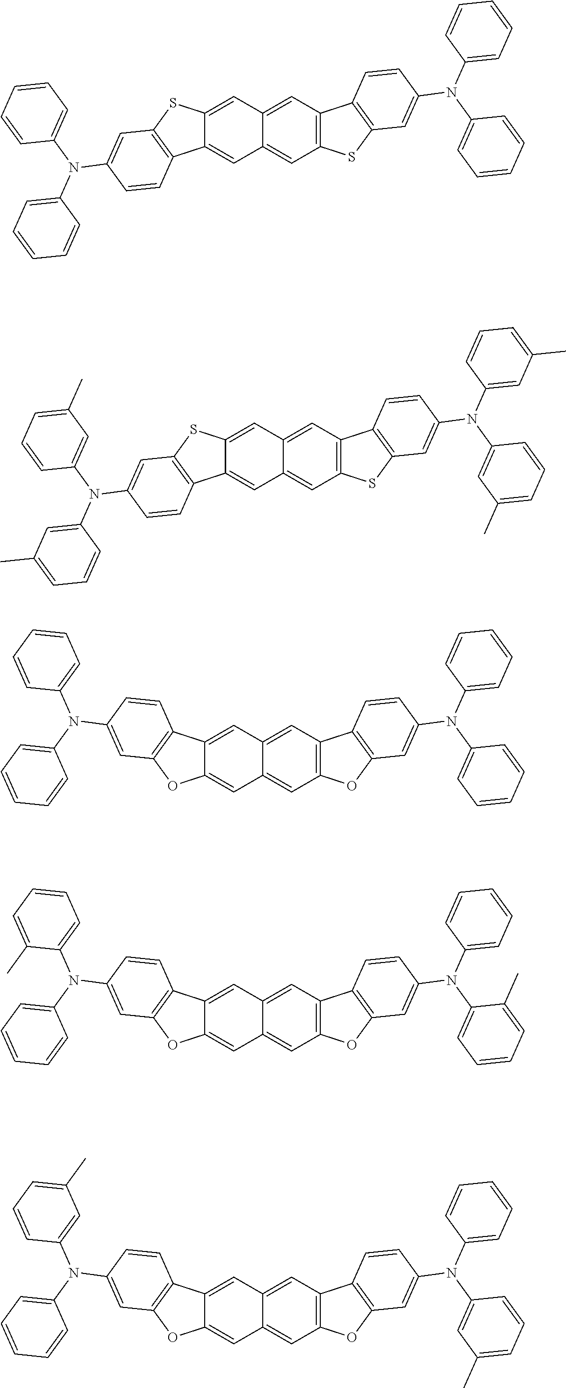

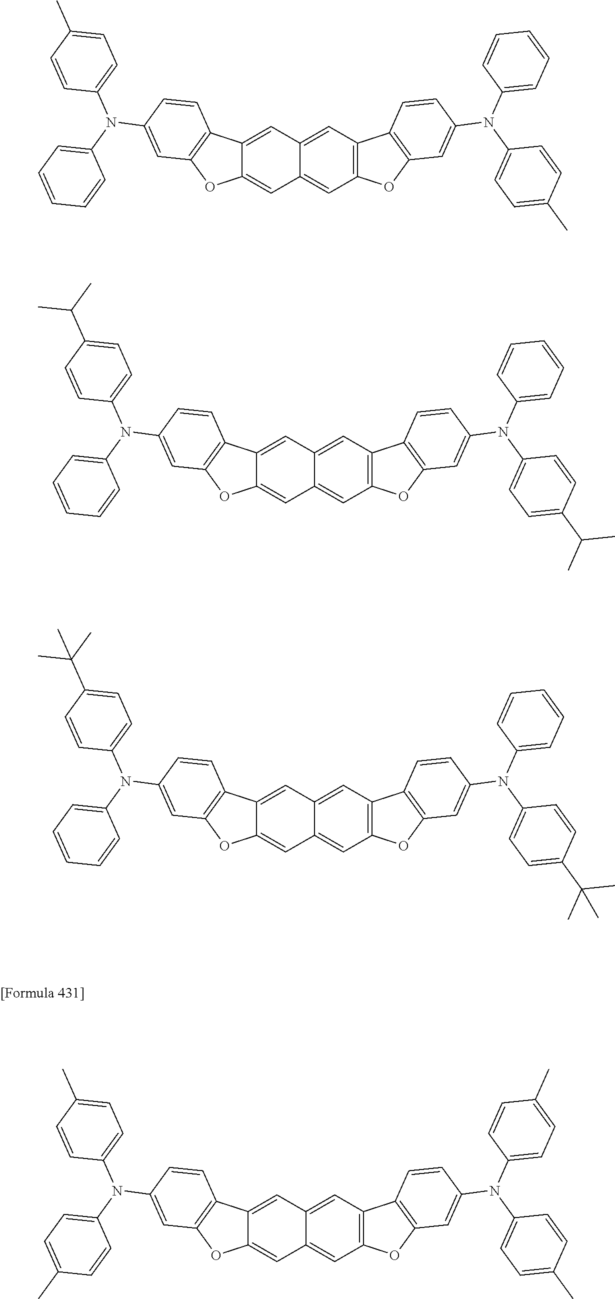

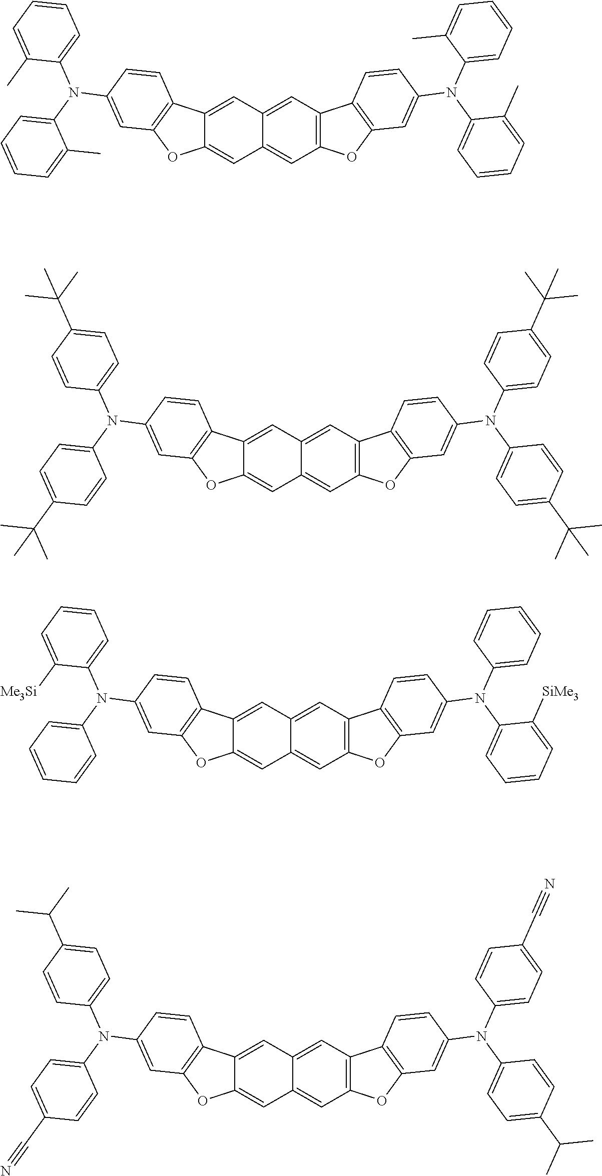 [SMILES: Cc1ccccc1N(c1ccc2c(c1)oc1cc3cc4oc5cc(N(c6ccccc6C)c6ccccc6C)ccc5c4cc3cc12)c1ccccc1C ; CC(C)(C)c1ccc(N(c2ccc(C(C)(C)C)cc2)c2ccc3c(c2)oc2cc4cc5oc6cc(N(c7ccc(C(C)(C)C)cc7)c7ccc(C(C)(C)C)cc7)ccc6c5cc4cc23)cc1 ; C[Si](C)(C)c1ccccc1N(c1ccccc1)c1ccc2c(c1)oc1cc3cc4oc5cc(N(c6ccccc6)c6ccccc6[Si](C)(C)C)ccc5c4cc3cc12 ; CC(C)c1ccc(N(c2ccc(C#N)cc2)c2ccc3c(c2)oc2cc4cc5oc6cc(N(c7ccc(C#N)cc7)c7ccc(C(C)C)cc7)ccc6c5cc4cc23)cc1]

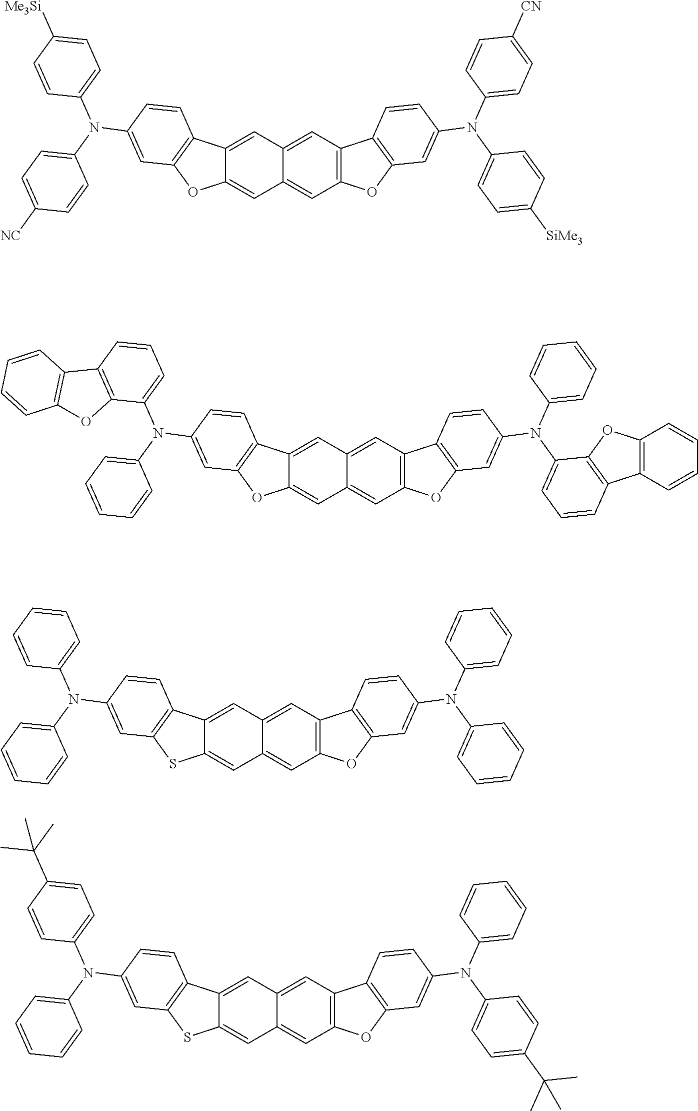

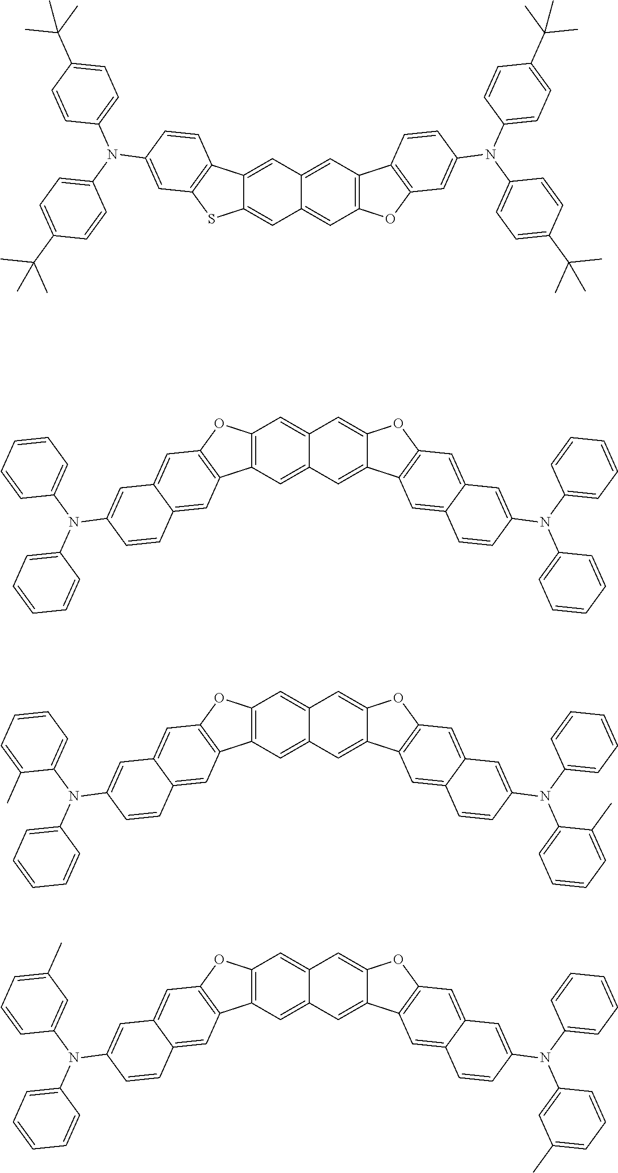 [SMILES: CC(C)(C)c1ccc(N(c2ccc(C(C)(C)C)cc2)c2ccc3c(c2)oc2cc4cc5sc6cc(N(c7ccc(C(C)(C)C)cc7)c7ccc(C(C)(C)C)cc7)ccc6c5cc4cc23)cc1 ; c1ccc(N(c2ccccc2)c2ccc3cc4c(cc3c2)oc2cc3cc5oc6cc7cc(N(c8ccccc8)c8ccccc8)ccc7cc6c5cc3cc24)cc1 ; Cc1ccccc1N(c1ccccc1)c1ccc2cc3c(cc2c1)oc1cc2cc4oc5cc6cc(N(c7ccccc7)c7ccccc7C)ccc6cc5c4cc2cc13 ; Cc1cccc(N(c2ccccc2)c2ccc3cc4c(cc3c2)oc2cc3cc5oc6cc7cc(N(c8ccccc8)c8cccc(C)c8)ccc7cc6c5cc3cc24)c1]

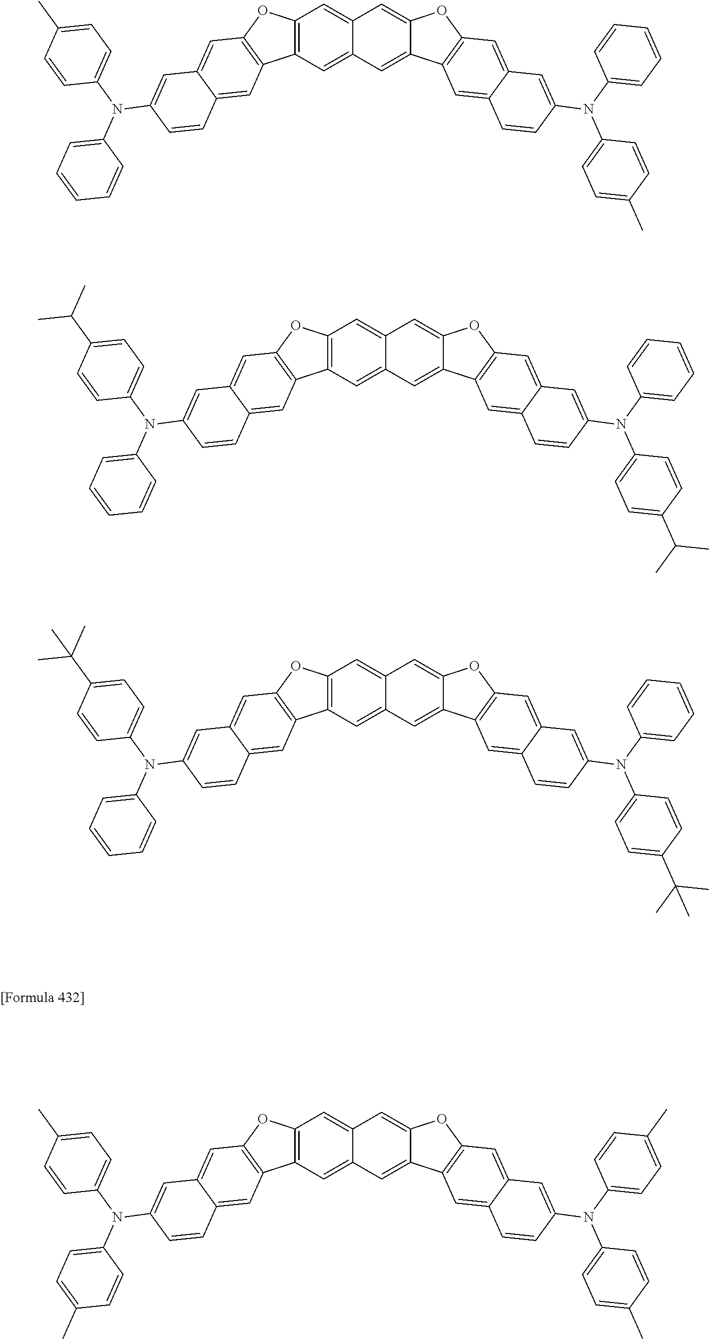

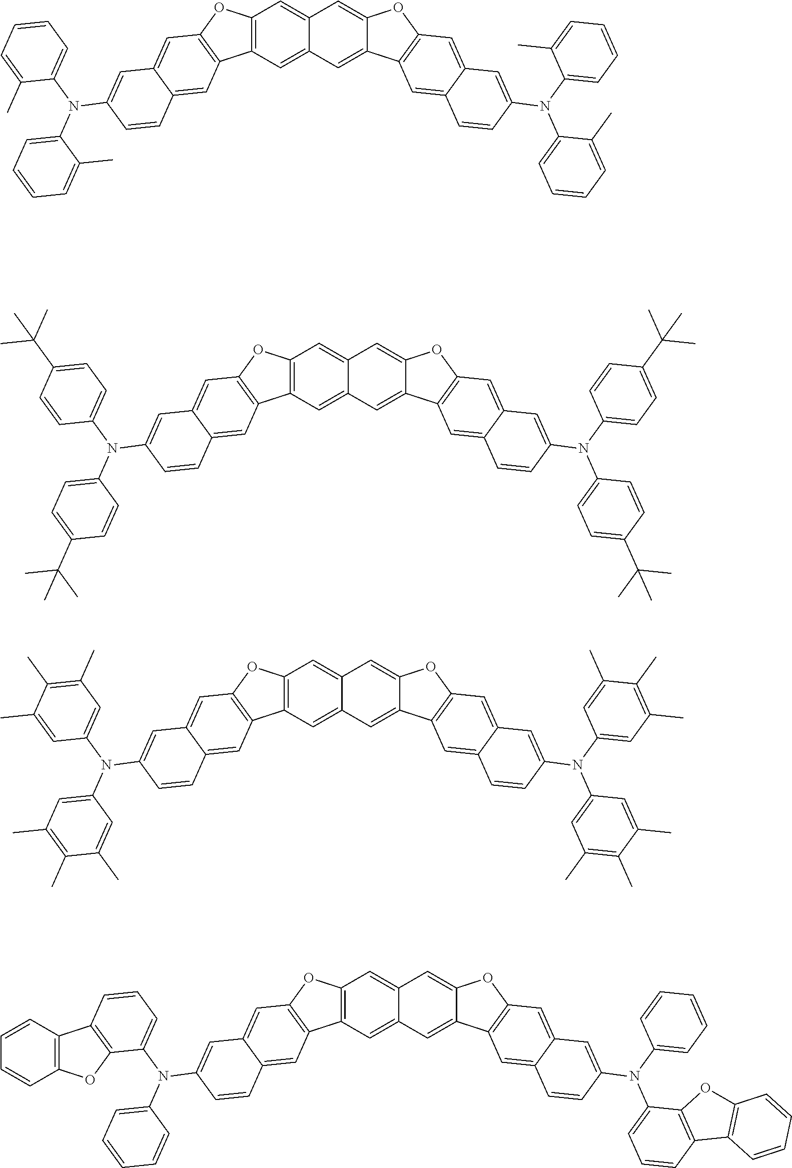

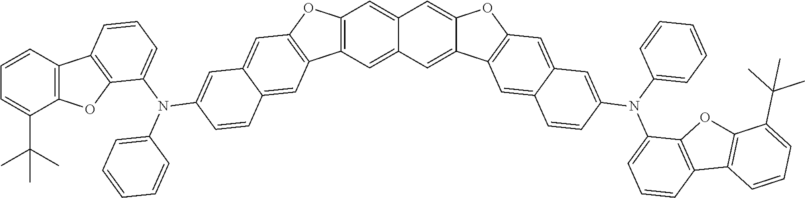 [SMILES: CC(C)(C)c1cccc2c1oc1c(N(c3ccccc3)c3ccc4cc5c(cc4c3)oc3cc4cc6oc7cc8cc(N(c9ccccc9)c9cccc%10c9oc9c(C(C)(C)C)cccc9%10)ccc8cc7c6cc4cc35)cccc12]

### Compound Represented by Formula (8)

The compound represented by the formula (8) will be described below.

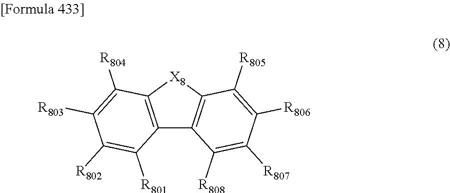

In the formula (8): at least one combination of R₈₀₁ and R₈₀₂, R₈₀₂ and R₈₀₃, or R₈₀₃ and R₈₀₄ are mutually bonded to form a divalent group represented by a formula (82) below, and at least one combination of R₈₀₅ and R₈₀₆, R₈₀₆ and R₈₀₈, or R₈₀₇ and R₈₀₈ are mutually bonded to form a divalent group represented by a formula (83) below.

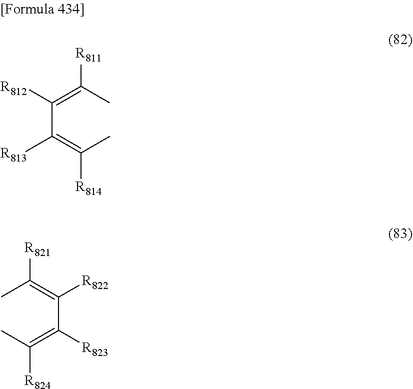

At least one of R₈₀₁ to R₈₀₄ not forming the divalent group represented by the formula (82) or R₁₁ to R₈₁₄ is a monovalent group represented by a formula (84) below;
at least one of R₈₀₅ to R₈₀₈ not forming the divalent group represented by the formula (83) or R₈₂₁ to R₈₂₄ is a monovalent group represented by a formula (84) below;
X₈ is an oxygen atom, a sulfur atom, or NR₈₀₉; and
R₈₀₁ to R₈₀₈ not forming the divalent group represented by the formula (82) or (83) and not being the monovalent group represented by the formula (84), R₈₁₁ to R₈₁₄ and R₈₂₁ to R₈₂₄ not being the monovalent group represented by the formula (84), and R₈₀₉ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

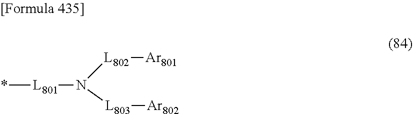

In the formula (84):
Ar₈₀₁ and Ar₈₀₂ are each independently a substituted or unsubstituted aryl group having 6 to 50 ring carbon atoms, or a substituted or unsubstituted heterocyclic group having 5 to 50 ring atoms;
L₈₀₁ to L₈₀₃ are each independently a single bond, a substituted or unsubstituted arylene group having 6 to 30 ring carbon atoms, a substituted or unsubstituted divalent heterocyclic group having 5 to 30 ring atoms, or a divalent linking group formed by bonding two, three or four groups selected from the group consisting of a substituted or unsubstituted arylene group having 6 to 30 ring carbon atoms and a substituted or unsubstituted divalent heterocyclic group having 5 to 30 ring atoms; and
in the formula (84) represents a bonding position to a cyclic structure represented by the formula (8) or a bonding position to a group represented by the formula (82) or (83).

In the formula (8), the positions for the divalent group represented by the formula (82) and the divalent group represented by the formula (83) to be formed are not specifically limited but the divalent groups may be formed at any possible positions on R₈₀₁ to R₈₀₈.

In an exemplary embodiment, the compound represented by the formula (8) is represented by any one of formulae (81-1) to (81-6) below.

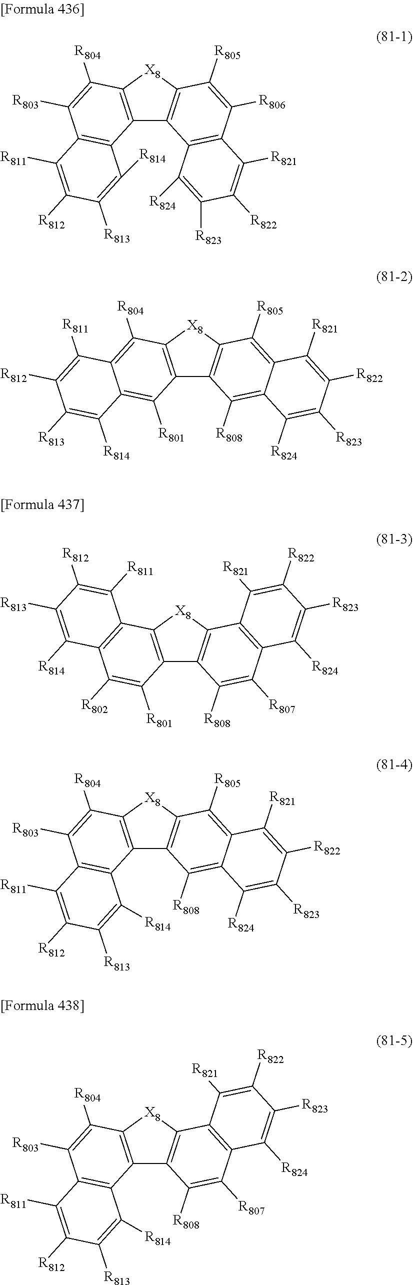

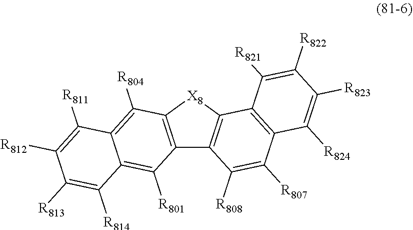

In the formulae (81-1) to (81-6):
X₈ represents the same as X₈ in the formula (8);
at least two of R₈₀₁ to R₈₂₄ are each a monovalent group represented by the formula (84); and
R₈₀₁ to R₈₂₄ not being the monovalent group represented by the formula (84) are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In an exemplary embodiment, the compound represented by the formula (8) is represented by any one of formulae (81-7) to (81-18) below.

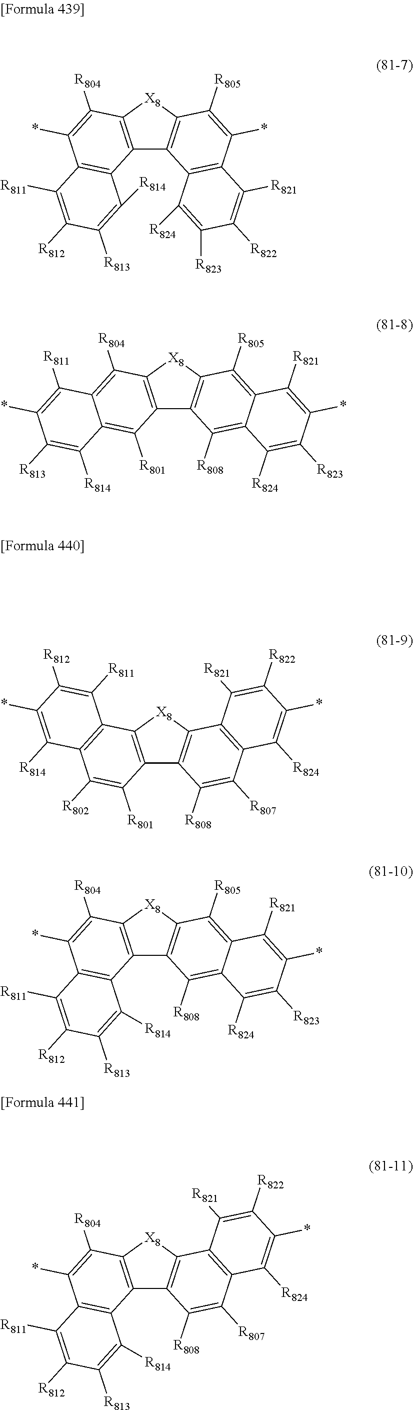

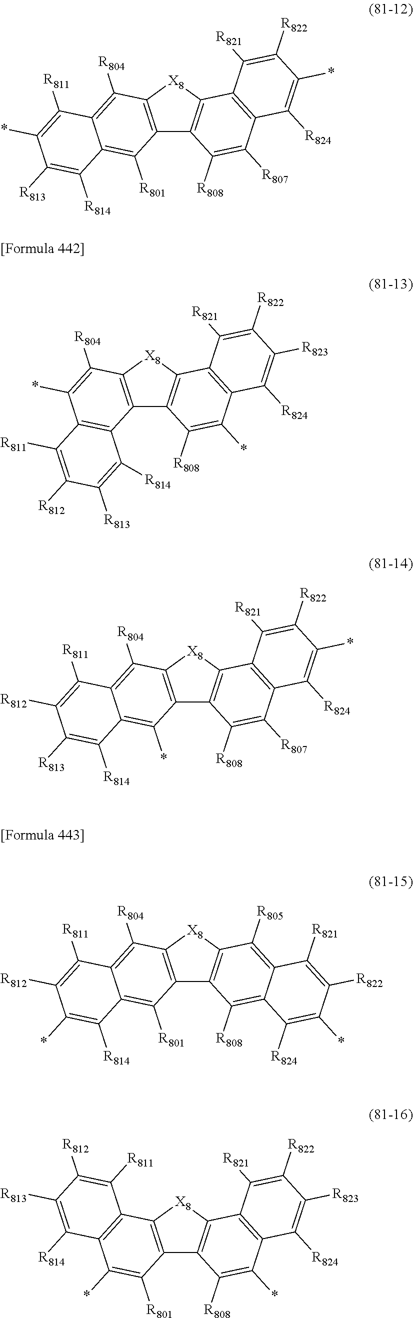

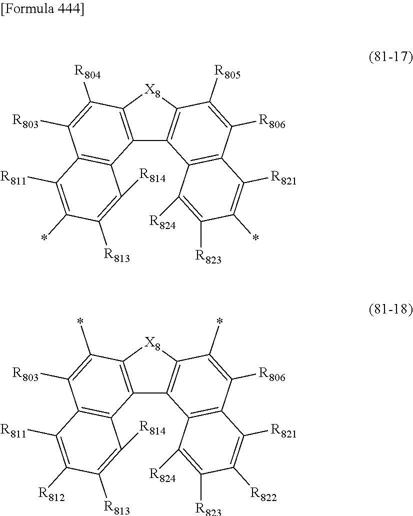

In the formulae (81-7) to (81-18):
X₈ represents the same as X₈ in the formula (8);
is a single bond bonded to a monovalent group represented by the formula (84); and
R₈₀₁ to R₈₂₄ each independently represent the same as R₈₀₁ to R₈₂₄ in the formulae (81-1) to (81-6) that are not the monovalent group represented by the formula (84).
R₈₀₁ to R₈₀₈ not forming the divalent group represented by the formula (82) or (83) and not being the monovalent group represented by the formula (84), and R₈₁₁ to R₈₁₄ and R₈₂₁ to R₈₂₄ not being the monovalent group represented by the formula (84) are preferably each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

The monovalent group represented by the formula (84) is preferably represented by a formula (85) or (86) below.

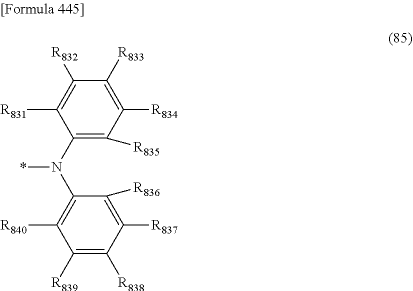

In the formula (85): R₈₃₁ to R₈₄₀ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms, * in the formula (85) represents the same as * in the formula (84).

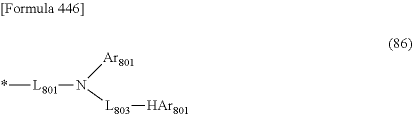

In the formula (86): Ar₈₀₁, L₈₀₁, and L₈₀₃ represent the same as Ar₈₀₁, L₈₀₁, and L₈₀₃ in the formula (84); and HAr₈₀₁ is a structure represented by a formula (87) below.

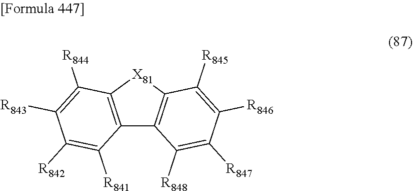

In the formula (87): X₈₁ is an oxygen atom or a sulfur atom; one of R₈₄₁ to R₈₄₈ is a single bond with L₈₀₃; and R₈₄₁ to R₈₄₈ not being the single bond are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

### Specific Examples of Compound Represented by Formula (8)

Specific examples of the compound represented by the formula (8) include compounds shown below as well as the compounds disclosed in WO 2014/104144.

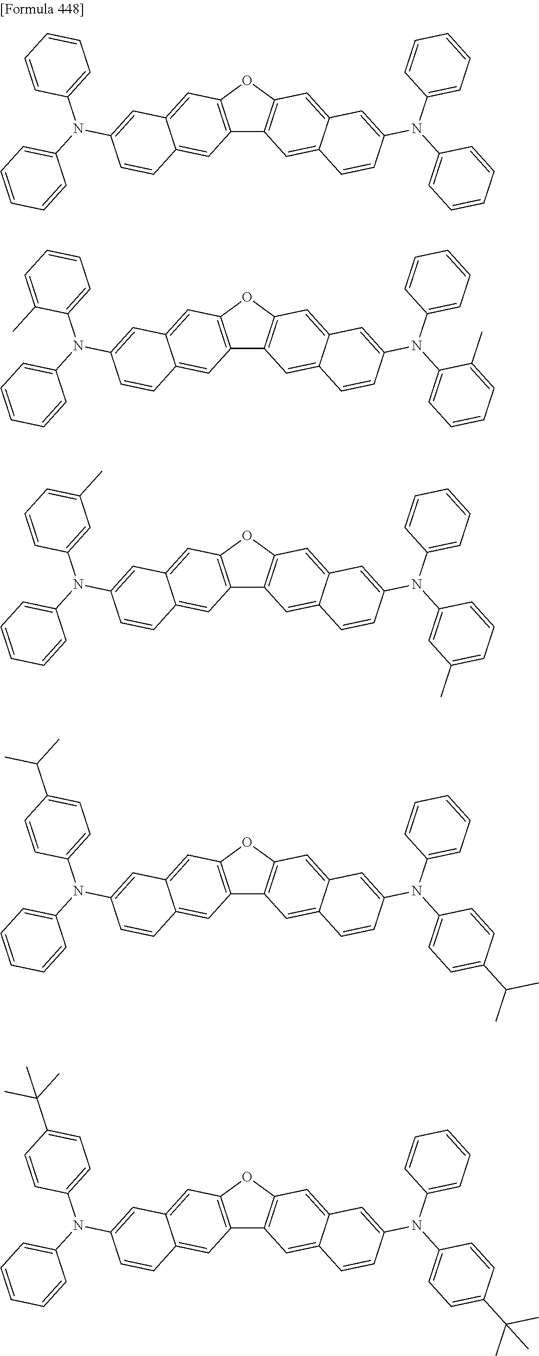

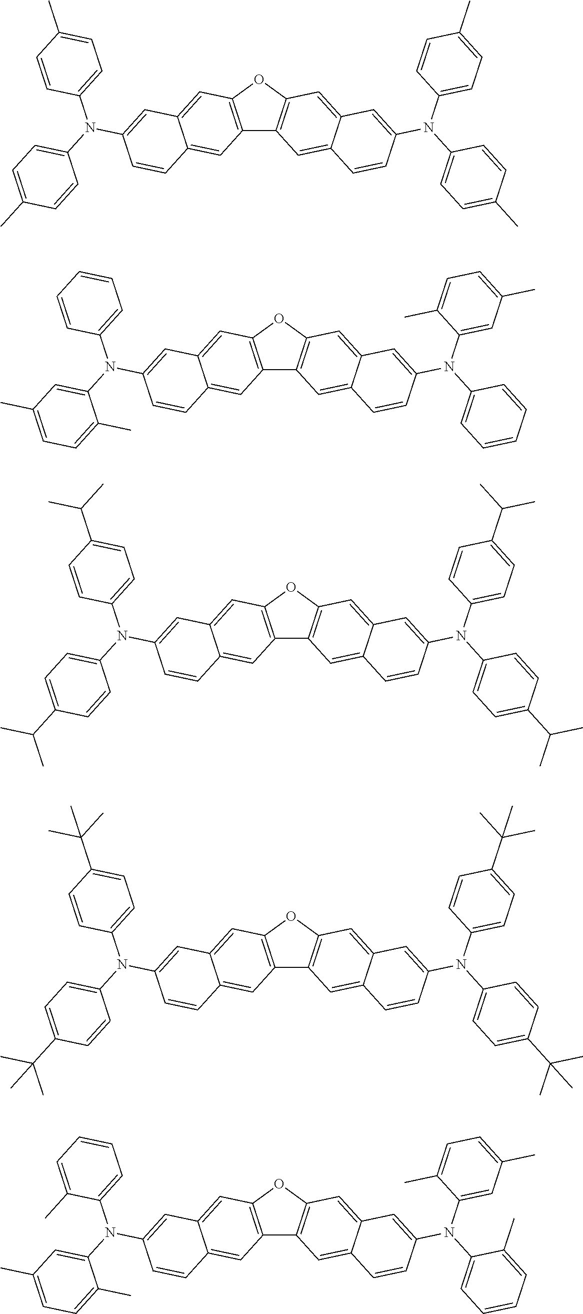

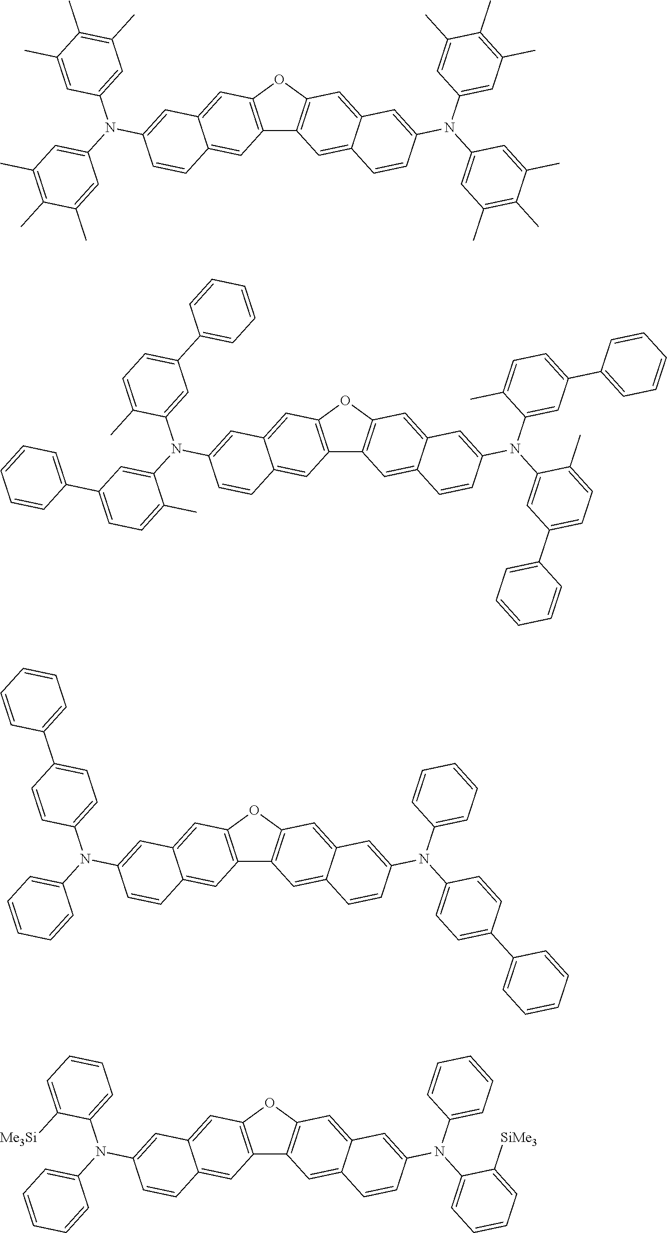

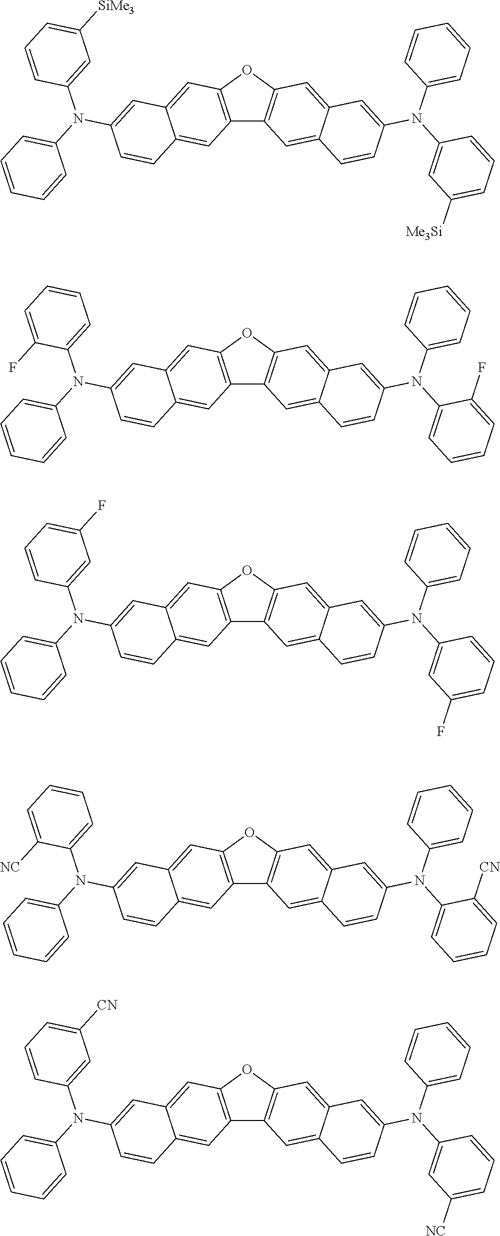 [SMILES: C[Si](C)(C)c1cccc(N(c2ccccc2)c2ccc3cc4c(cc3c2)oc2cc3cc(N(c5ccccc5)c5cccc([Si](C)(C)C)c5)ccc3cc24)c1 ; Fc1ccccc1N(c1ccccc1)c1ccc2cc3c(cc2c1)oc1cc2cc(N(c4ccccc4)c4ccccc4F)ccc2cc13 ; Fc1cccc(N(c2ccccc2)c2ccc3cc4c(cc3c2)oc2cc3cc(N(c5ccccc5)c5cccc(F)c5)ccc3cc24)c1 ; N#Cc1ccccc1N(c1ccccc1)c1ccc2cc3c(cc2c1)oc1cc2cc(N(c4ccccc4)c4ccccc4C#N)ccc2cc13 ; N#Cc1cccc(N(c2ccccc2)c2ccc3cc4c(cc3c2)oc2cc3cc(N(c5ccccc5)c5cccc(C#N)c5)ccc3cc24)c1]

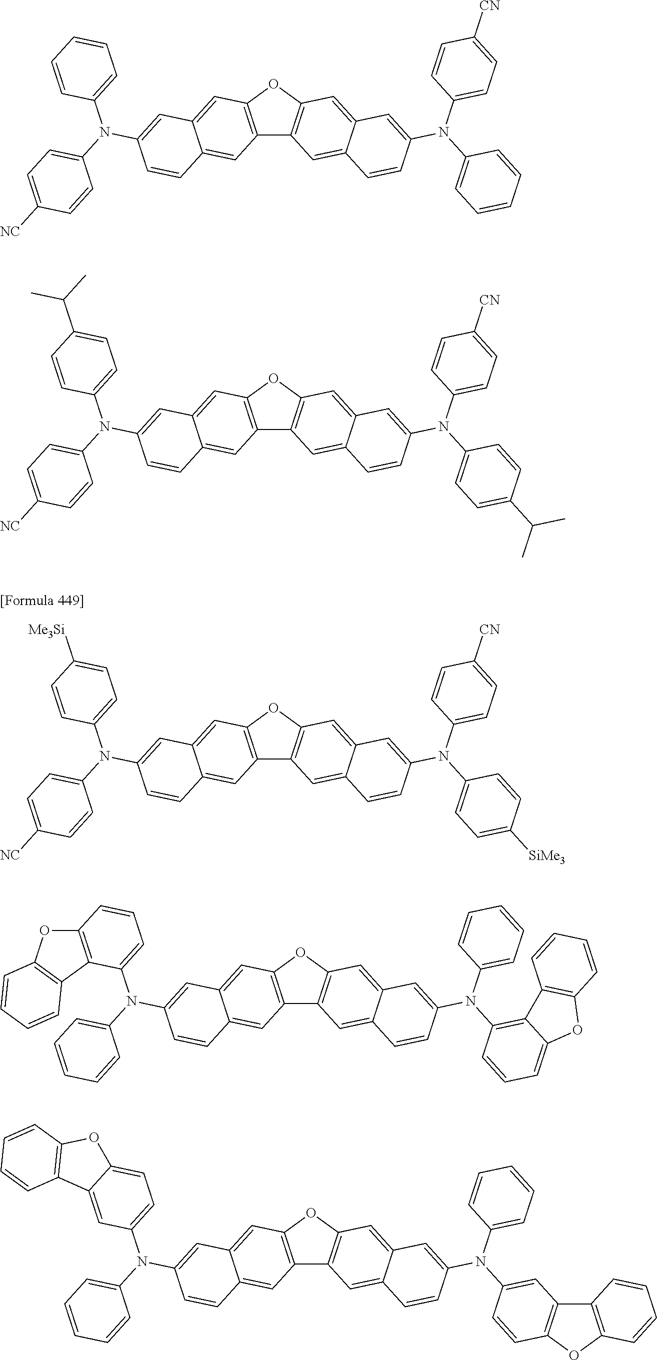 [SMILES: N#Cc1ccc(N(c2ccccc2)c2ccc3cc4c(cc3c2)oc2cc3cc(N(c5ccccc5)c5ccc(C#N)cc5)ccc3cc24)cc1 ; CC(C)c1ccc(N(c2ccc(C#N)cc2)c2ccc3cc4c(cc3c2)oc2cc3cc(N(c5ccc(C#N)cc5)c5ccc(C(C)C)cc5)ccc3cc24)cc1 ; C[Si](C)(C)c1ccc(N(c2ccc(C#N)cc2)c2ccc3cc4c(cc3c2)oc2cc3cc(N(c5ccc(C#N)cc5)c5ccc([Si](C)(C)C)cc5)ccc3cc24)cc1 ; c1ccc(N(c2ccc3cc4c(cc3c2)oc2cc3cc(N(c5ccccc5)c5cccc6oc7ccccc7c56)ccc3cc24)c2cccc3oc4ccccc4c23)cc1 ; c1ccc(N(c2ccc3cc4c(cc3c2)oc2cc3cc(N(c5ccccc5)c5ccc6oc7ccccc7c6c5)ccc3cc24)c2ccc3oc4ccccc4c3c2)cc1]

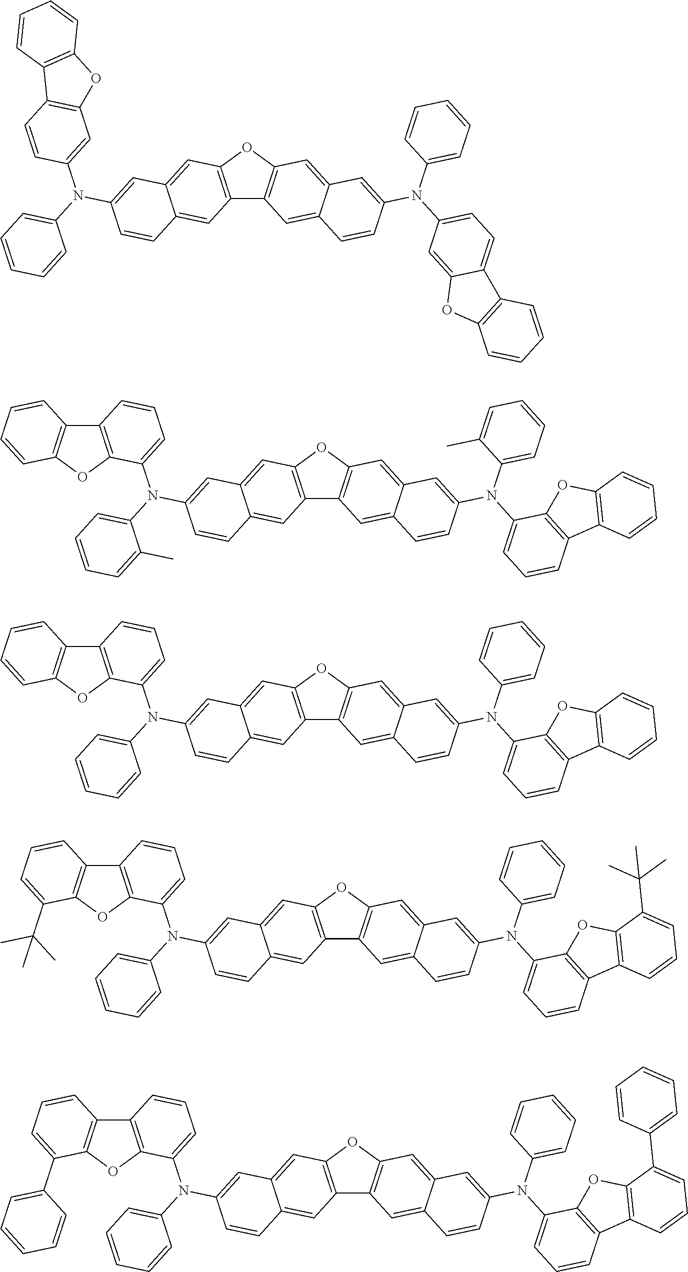

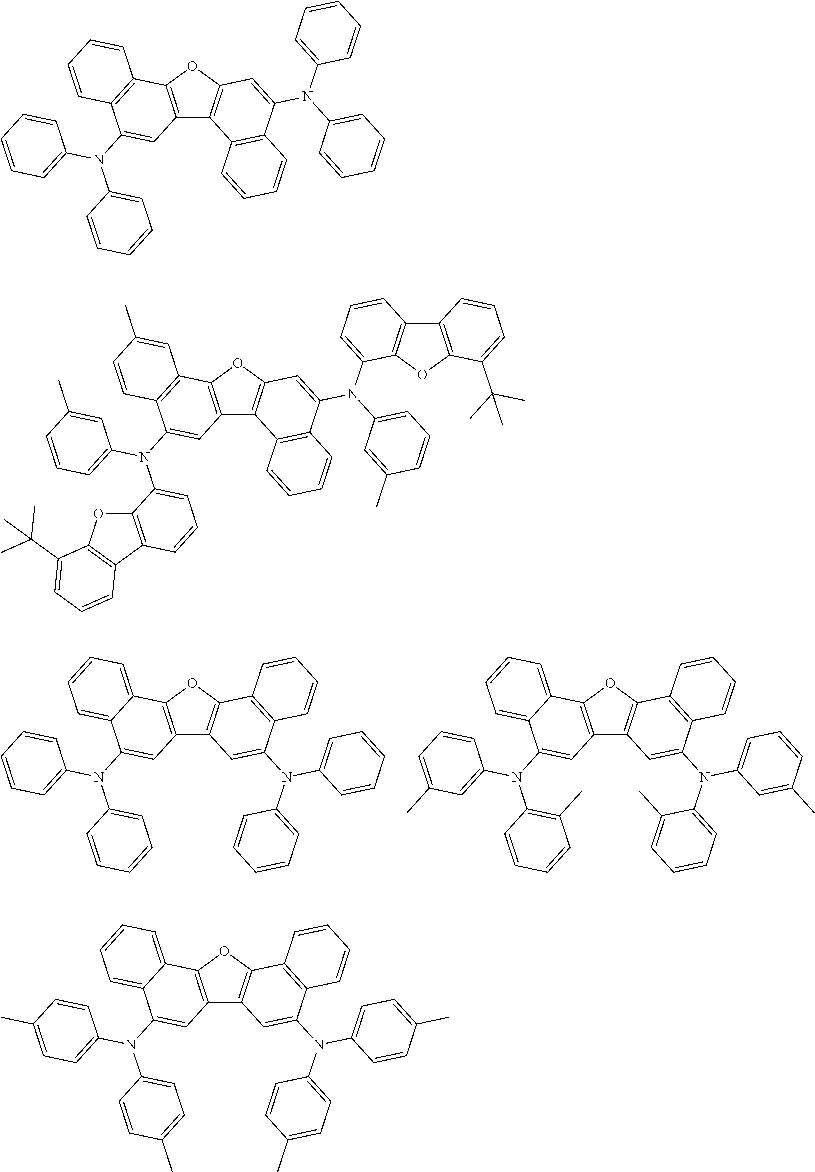

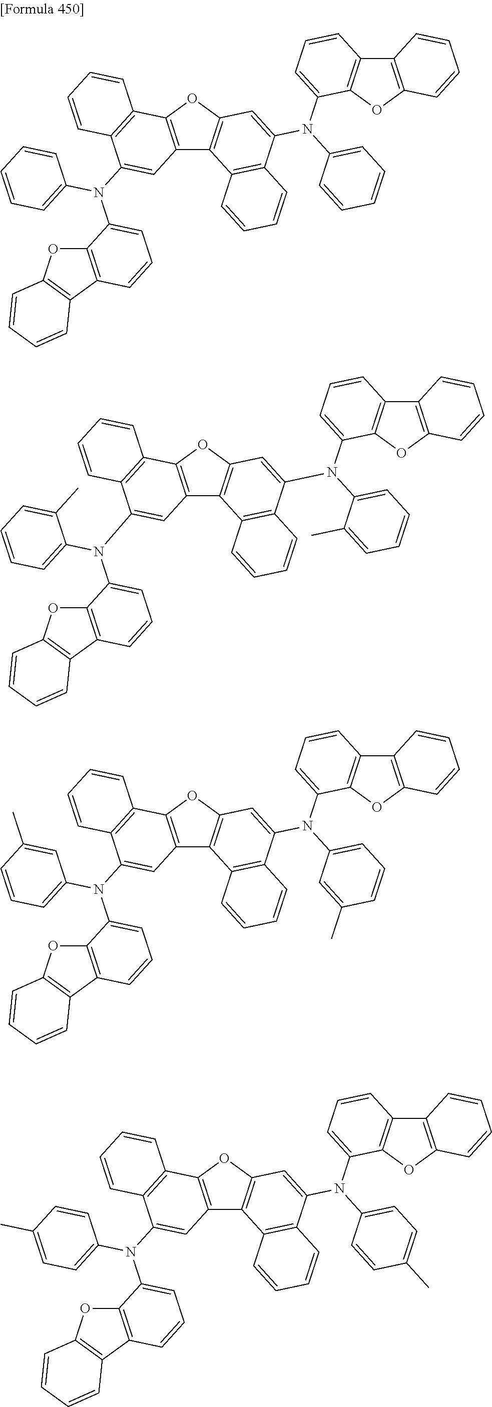 [SMILES: c1ccc(N(c2cc3c(oc4cc(N(c5ccccc5)c5cccc6c5oc5ccccc56)c5ccccc5c43)c3ccccc23)c2cccc3c2oc2ccccc23)cc1 ; Cc1ccccc1N(c1cc2c(oc3cc(N(c4ccccc4C)c4cccc5c4oc4ccccc45)c4ccccc4c32)c2ccccc12)c1cccc2c1oc1ccccc12 ; Cc1cccc(N(c2cc3c(oc4cc(N(c5cccc(C)c5)c5cccc6c5oc5ccccc56)c5ccccc5c43)c3ccccc23)c2cccc3c2oc2ccccc23)c1 ; Cc1ccc(N(c2cc3c(oc4cc(N(c5ccc(C)cc5)c5cccc6c5oc5ccccc56)c5ccccc5c43)c3ccccc23)c2cccc3c2oc2ccccc23)cc1]

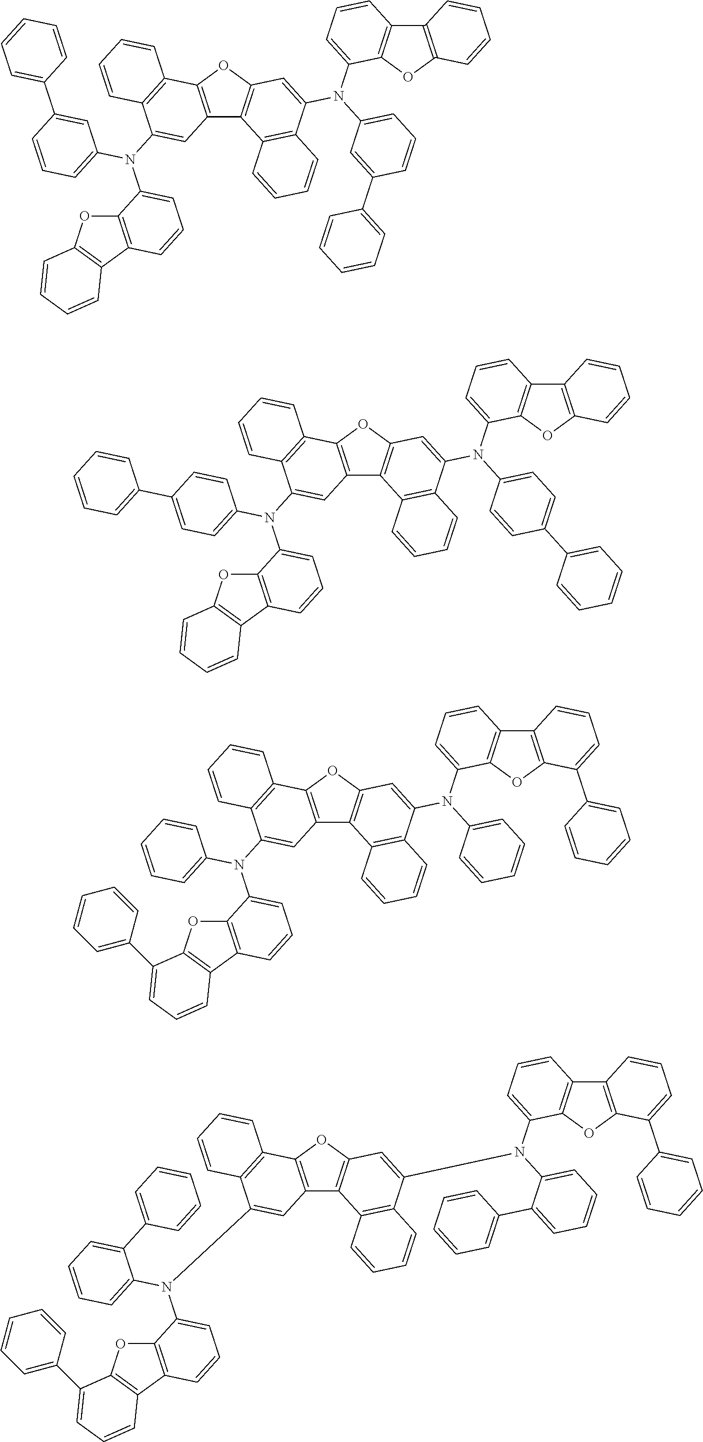

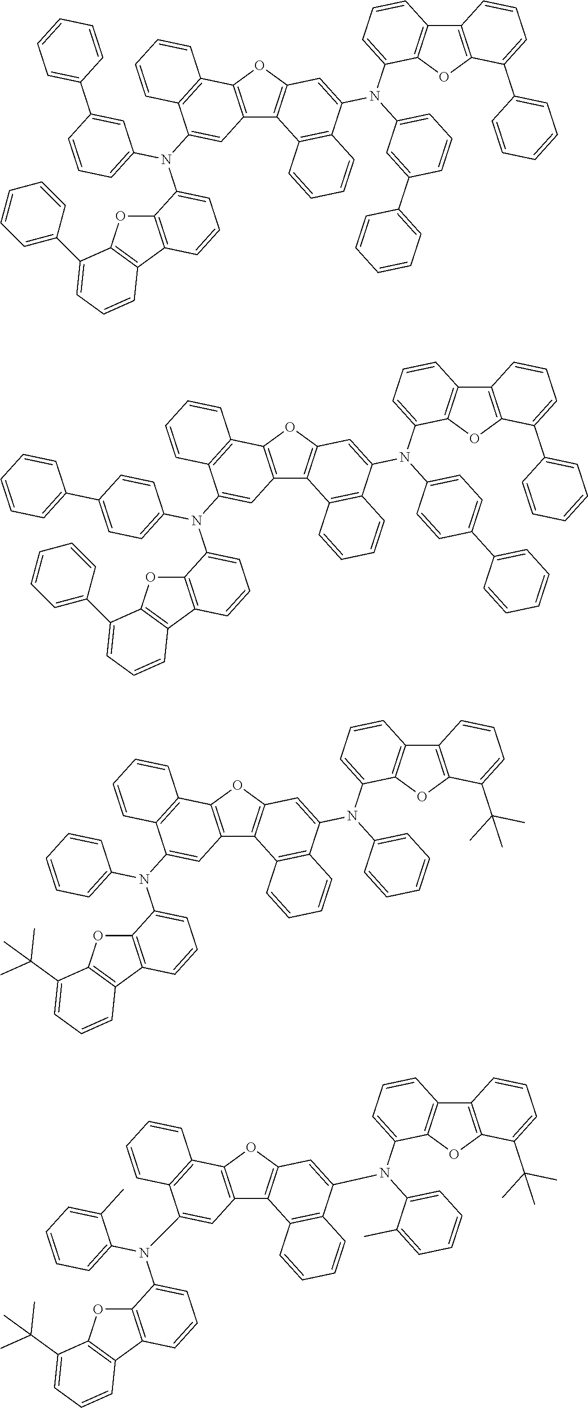

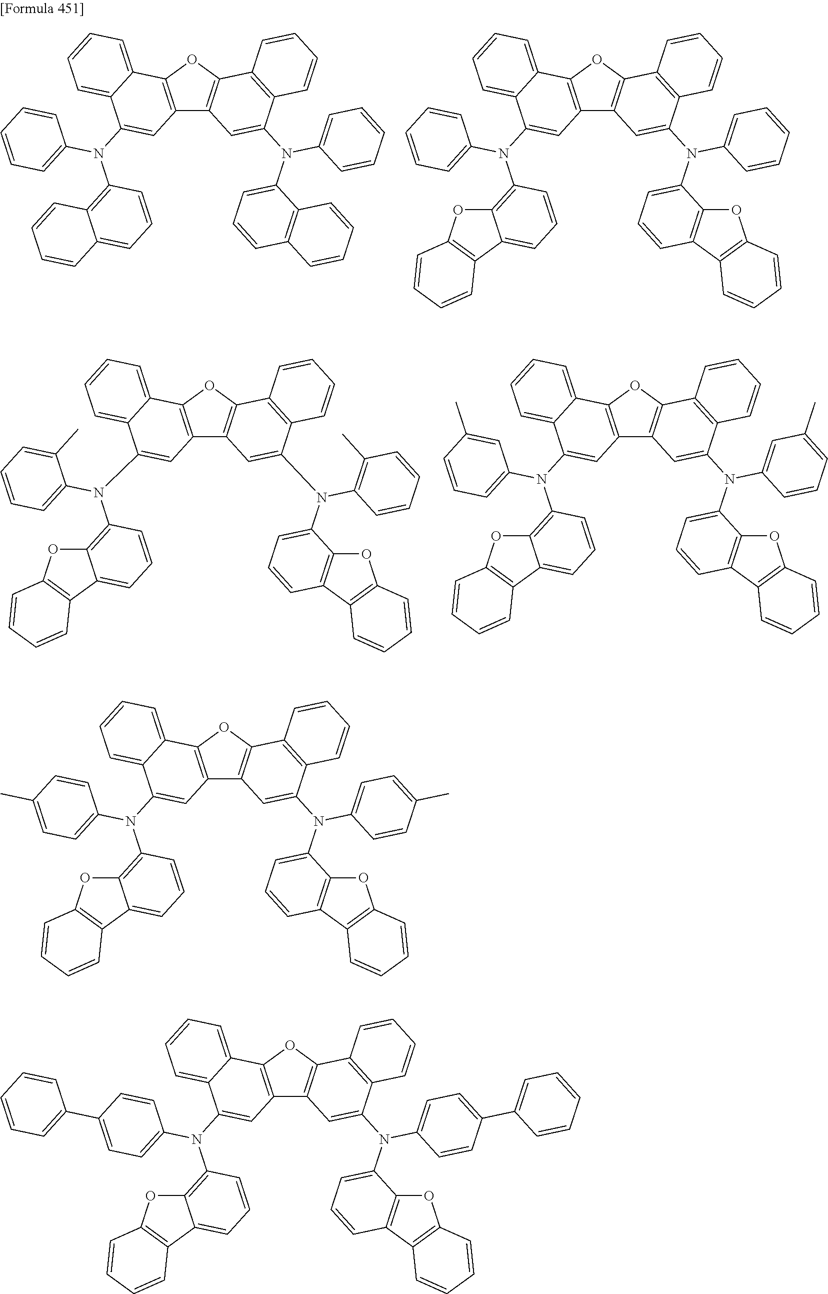

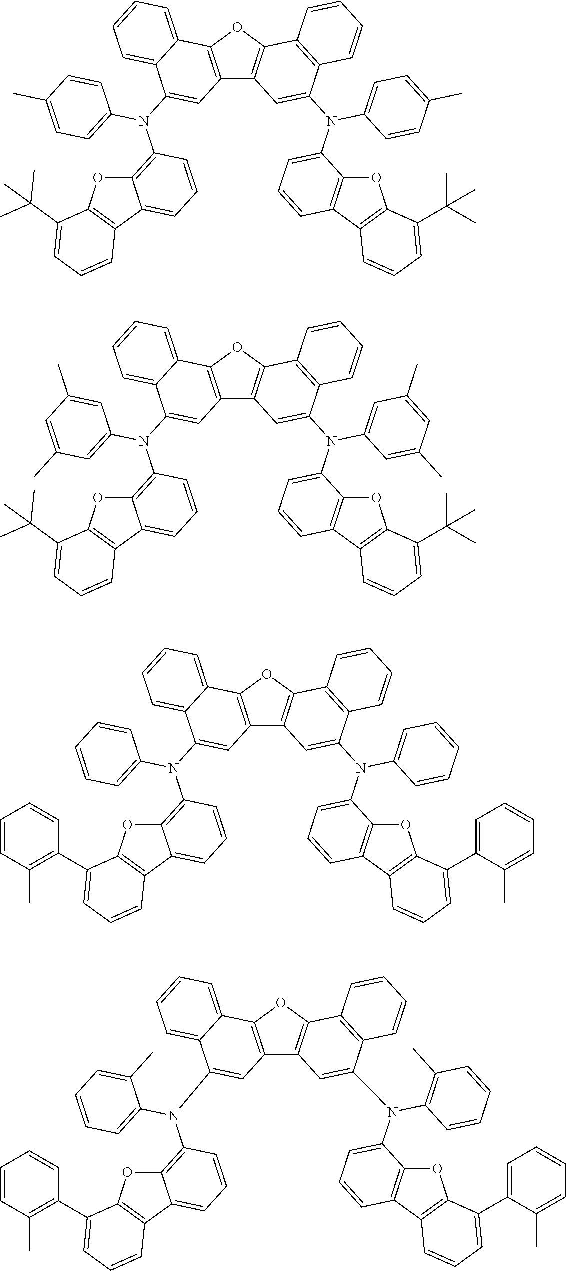

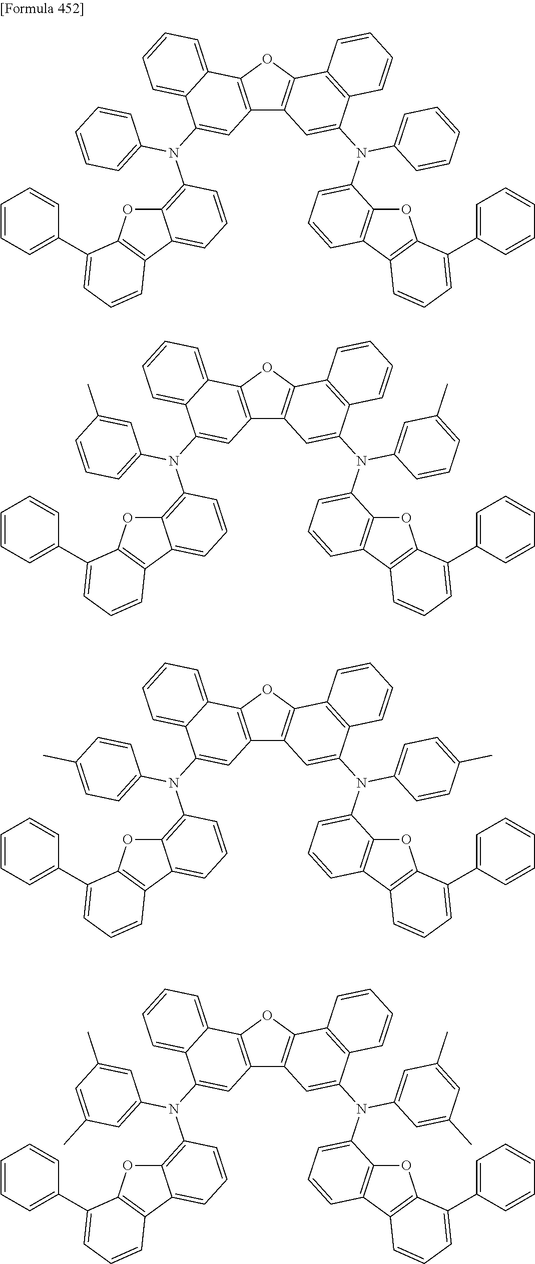 [SMILES: c1ccc(-c2cccc3c2oc2c(N(c4ccccc4)c4cc5c6cc(N(c7ccccc7)c7cccc8c7oc7c(-c9ccccc9)cccc78)c7ccccc7c6oc5c5ccccc45)cccc23)cc1 ; Cc1cccc(N(c2cc3c4cc(N(c5cccc(C)c5)c5cccc6c5oc5c(-c7ccccc7)cccc56)c5ccccc5c4oc3c3ccccc23)c2cccc3c2oc2c(-c4ccccc4)cccc23)c1 ; Cc1ccc(N(c2cc3c4cc(N(c5ccc(C)cc5)c5cccc6c5oc5c(-c7ccccc7)cccc56)c5ccccc5c4oc3c3ccccc23)c2cccc3c2oc2c(-c4ccccc4)cccc23)cc1 ; Cc1cc(C)cc(N(c2cc3c4cc(N(c5cc(C)cc(C)c5)c5cccc6c5oc5c(-c7ccccc7)cccc56)c5ccccc5c4oc3c3ccccc23)c2cccc3c2oc2c(-c4ccccc4)cccc23)c1]

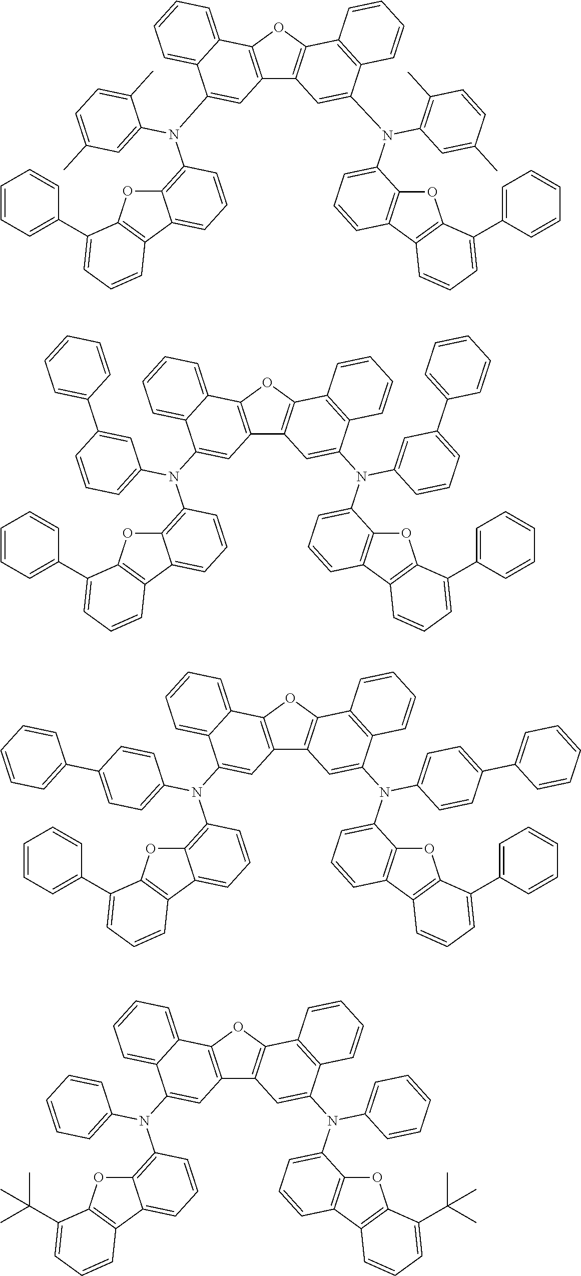

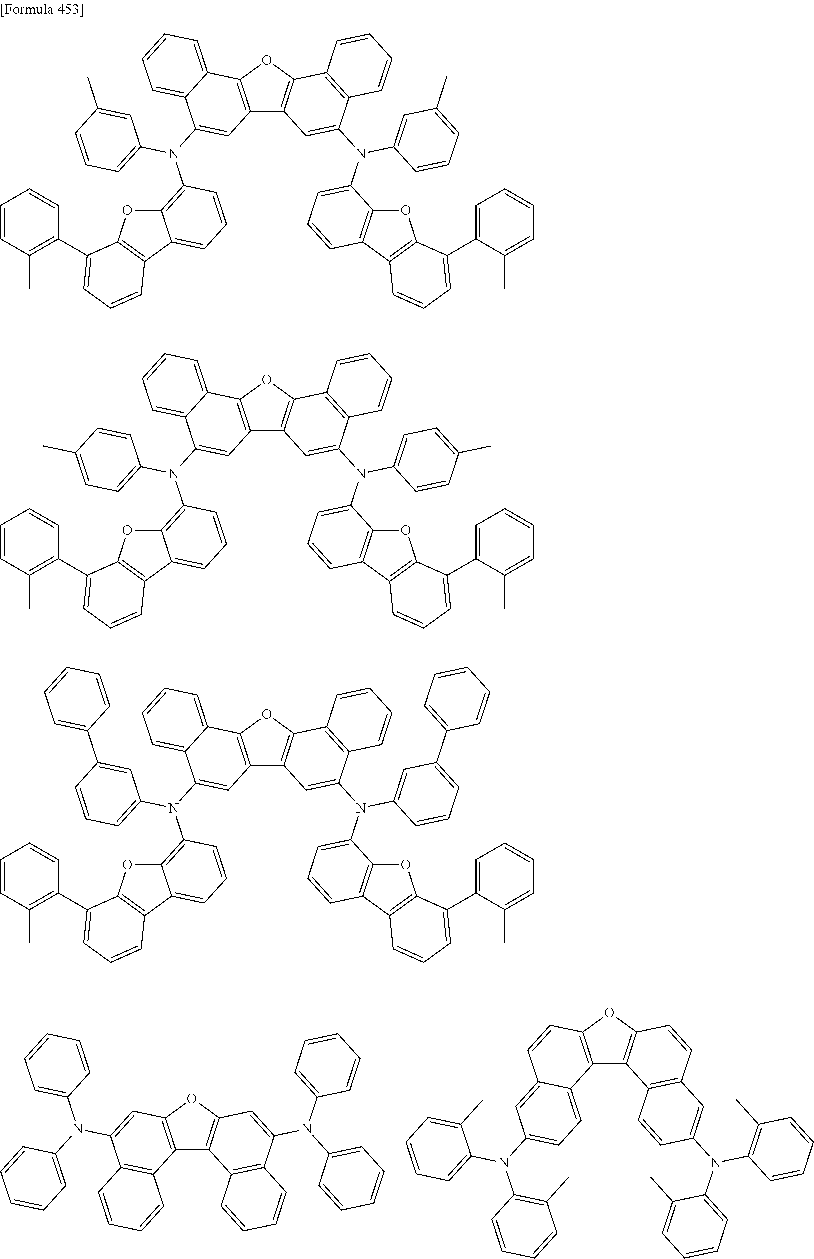

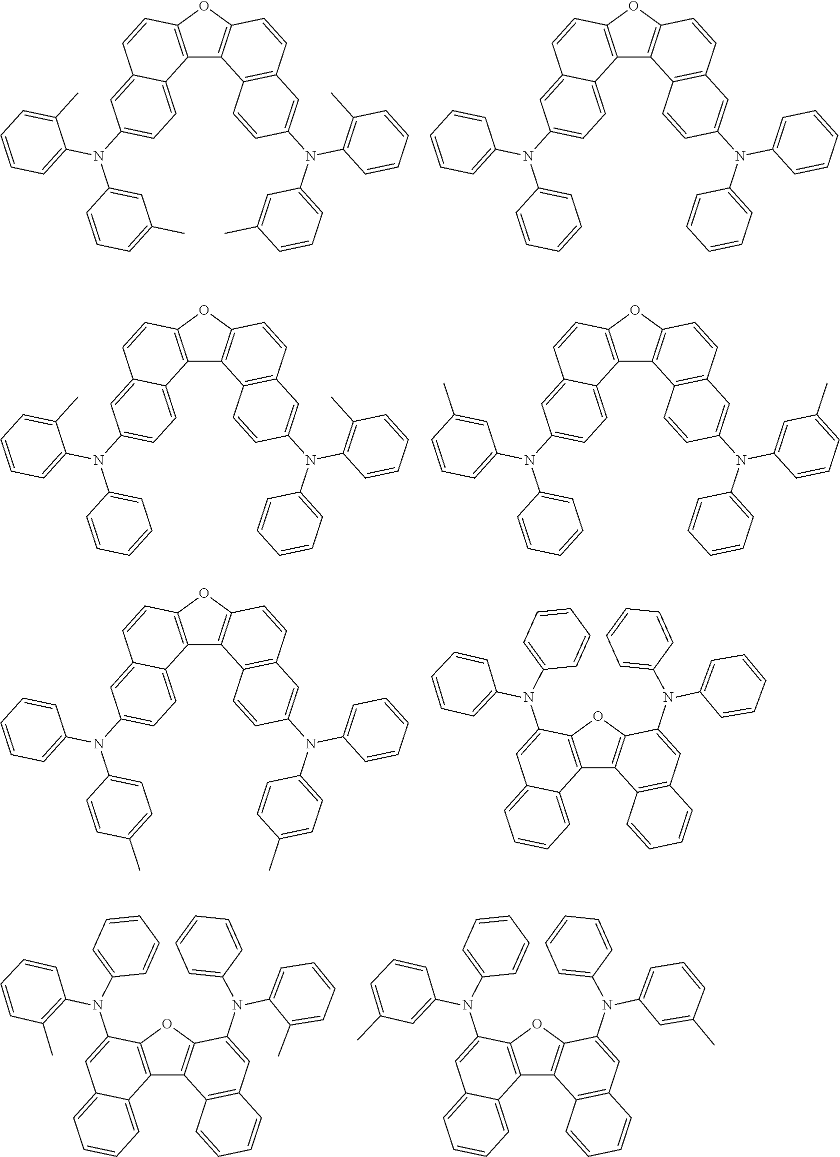

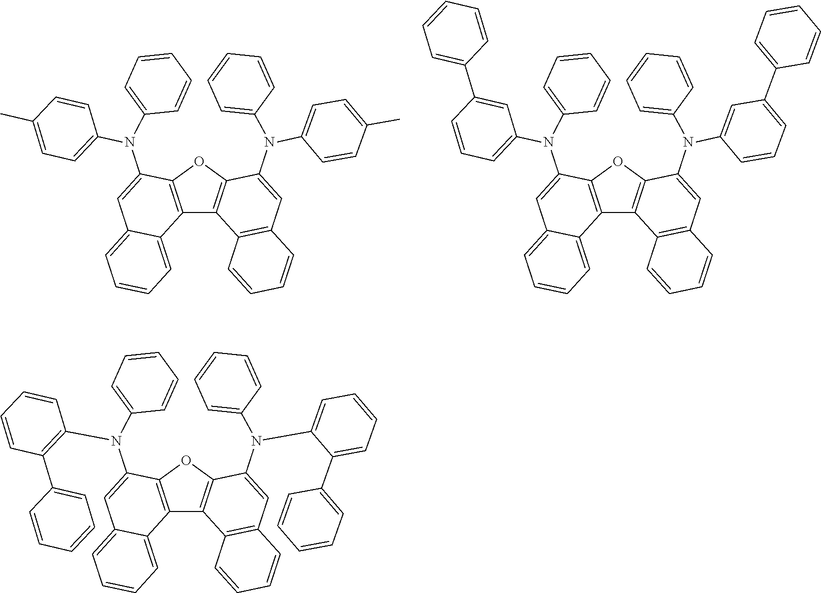

### Compound Represented by Formula (9)

The compound represented by the formula (9) will be described below.

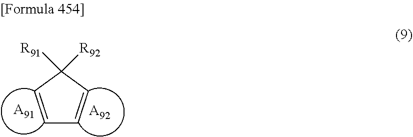

In the formula (9): And ring and A92 ring are each independently a substituted or unsubstituted aromatic hydrocarbon ring having 6 to 50 ring carbon atoms, or a substituted or unsubstituted heterocyclic ring having 5 to 50 ring atoms; and at least one ring selected from the group consisting of A₉₁ ring and A₉₂ ring is bonded with * in a structure represented by a formula (92) below.

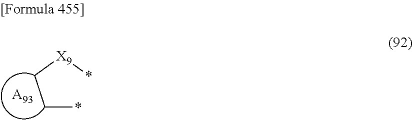

In the formula (92):
A₉₃ is a substituted or unsubstituted aromatic hydrocarbon ring having 6 to 50 ring carbon atoms, or a substituted or unsubstituted heterocyclic ring having 5 to 50 ring atoms;
X₉ is NR₉₃, C(R₉₄)(R₉₅), Si(R₉₆)(R₉₇), Ge(R₉₈)(R₉₉), an oxygen atom, a sulfur atom, or a selenium atom;
R₉₁ and R₉₂ are mutually bonded to form a substituted or unsubstituted monocyclic ring, mutually bonded to form a substituted or unsubstituted fused ring, or not mutually bonded; and
R₉₁ and R₉₂ not forming the monocyclic ring and not forming the fused ring, and R₉₃ to R₉₉ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

At least one of A₉₁ ring or A₉₂ ring is bonded to a bond * of a structure represented by the formula (92). In other words, the ring-forming carbon atoms of the aromatic hydrocarbon ring or the ring atoms of the heterocycle of the A₉₁ ring in an exemplary embodiment are bonded to the bonds * in a structure represented by the formula (92). Further, the ring-forming carbon atoms of the aromatic hydrocarbon ring or the ring atoms of the heterocycle of the A₉₂ ring in an exemplary embodiment are bonded to the bonds * in a structure represented by the formula (92).

In an exemplary embodiment, a group represented by a formula (93) below is bonded to one or both of the A₉₁ ring and A₉₂ ring.

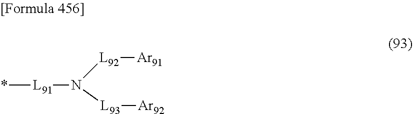

In the formula (93):
Ar₉₁ and Ar₉₂ are each independently a substituted or unsubstituted aryl group having 6 to 50 ring carbon atoms, or a substituted or unsubstituted heterocyclic group having 5 to 50 ring atoms;
L₉₁ to L₉₃ are each independently a single bond, a substituted or unsubstituted arylene group having 6 to 30 ring carbon atoms, a substituted or unsubstituted divalent heterocyclic group having 5 to 30 ring atoms, or a divalent linking group formed by bonding two, three or four groups selected from the group consisting of a substituted or unsubstituted arylene group having 6 to 30 ring carbon atoms and a substituted or unsubstituted divalent heterocyclic group having 5 to 30 ring atoms; and
in the formula (93) represents a bonding position to one of A₉₁ ring and A₉₂ ring.

In an exemplary embodiment, in addition to the A₉₁ ring, the ring-forming carbon atoms of the aromatic hydrocarbon ring or the ring atoms of the heterocycle of the A₉₂ ring are bonded to * in a structure represented by the formula (92). In this case, the structures represented by the formula (92) may be mutually the same or different.

In an exemplary embodiment, R₉₁ and R₉₂ are each independently a substituted or unsubstituted aryl group having 6 to 50 ring carbon atoms.

In an exemplary embodiment, R₉₁ and R₉₂ are mutually bonded to form a fluorene structure.

In an exemplary embodiment, the rings A₉₁ and A₉₂ are each independently a substituted or unsubstituted aromatic hydrocarbon ring having 6 to 50 ring carbon atoms, example of which is a substituted or unsubstituted benzene ring.

In an exemplary embodiment, the ring A₉₃ is a substituted or unsubstituted aromatic hydrocarbon ring having 6 to 50 ring carbon atoms, example of which is a substituted or unsubstituted benzene ring.

In an exemplary embodiment, X₉ is an oxygen atom or a sulfur atom.

### Specific Examples of Compound Represented by Formula (9)

Specific examples of the compound represented by the formula (9) include compounds shown below.

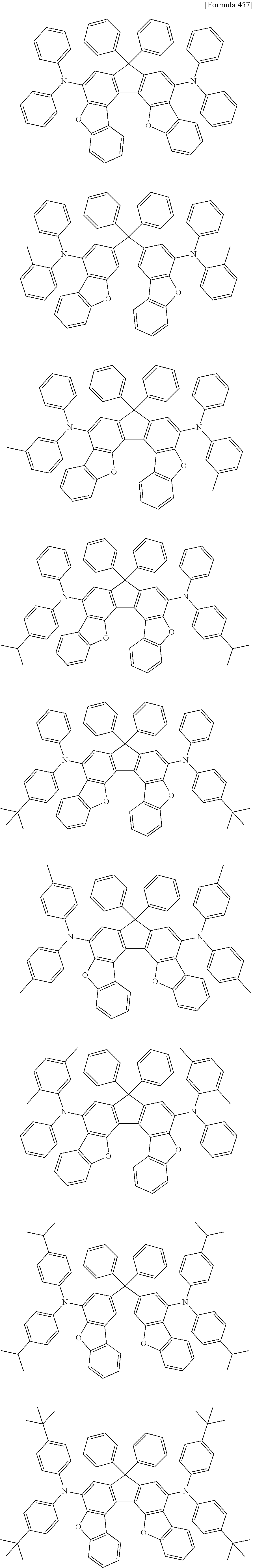

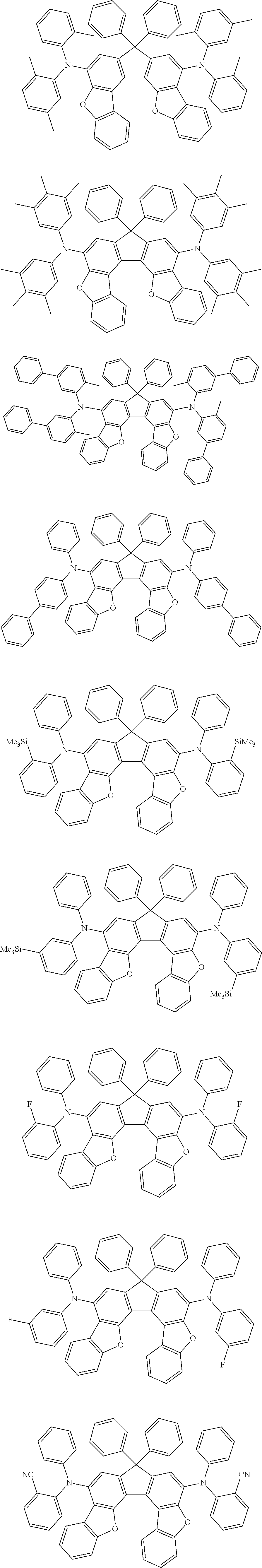

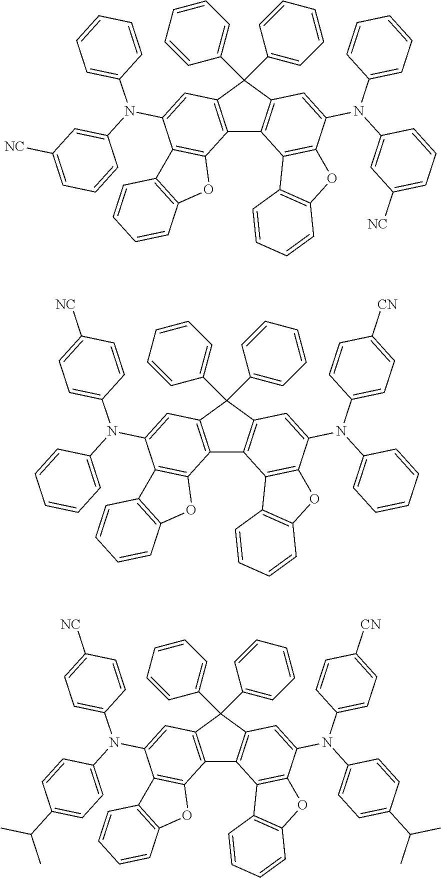 [SMILES: N#Cc1cccc(N(c2ccccc2)c2cc3c(c4c2oc2ccccc24)-c2c(cc(N(c4ccccc4)c4cccc(C#N)c4)c4c2oc2ccccc24)C3(c2ccccc2)c2ccccc2)c1 ; N#Cc1ccc(N(c2ccccc2)c2cc3c(c4c2oc2ccccc24)-c2c(cc(N(c4ccccc4)c4ccc(C#N)cc4)c4c2oc2ccccc24)C3(c2ccccc2)c2ccccc2)cc1 ; CC(C)c1ccc(N(c2ccc(C#N)cc2)c2cc3c(c4c2oc2ccccc24)-c2c(cc(N(c4ccc(C#N)cc4)c4ccc(C(C)C)cc4)c4c2oc2ccccc24)C3(c2ccccc2)c2ccccc2)cc1]

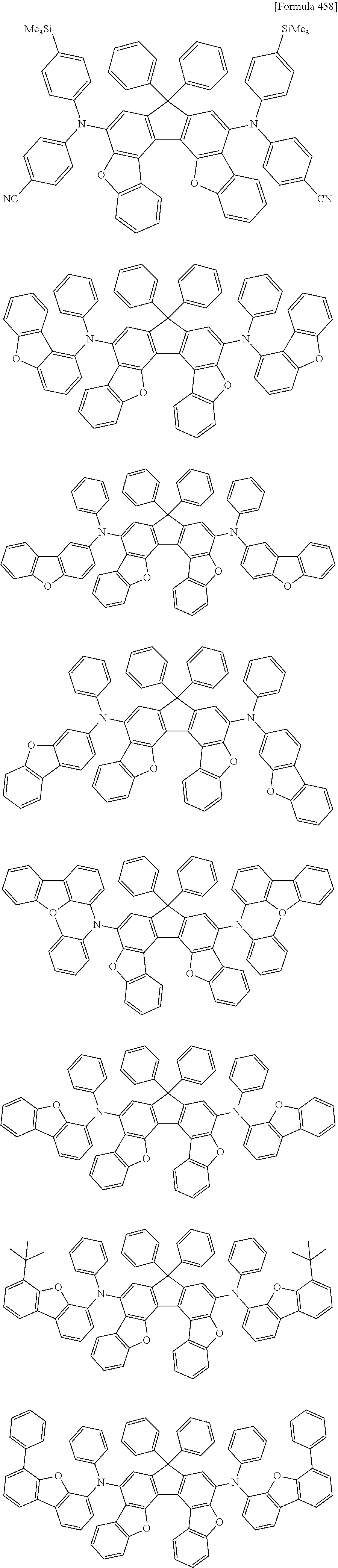

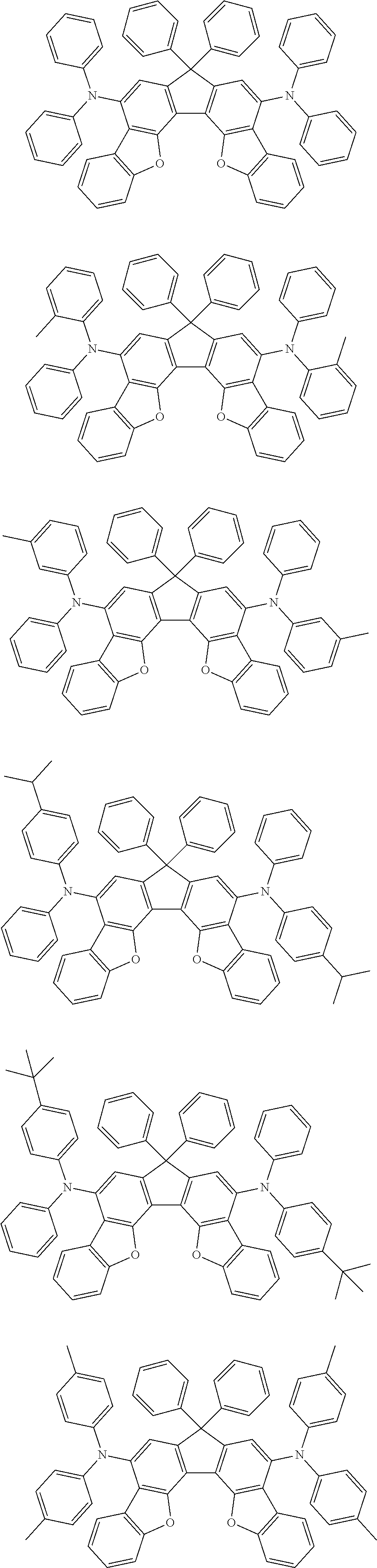

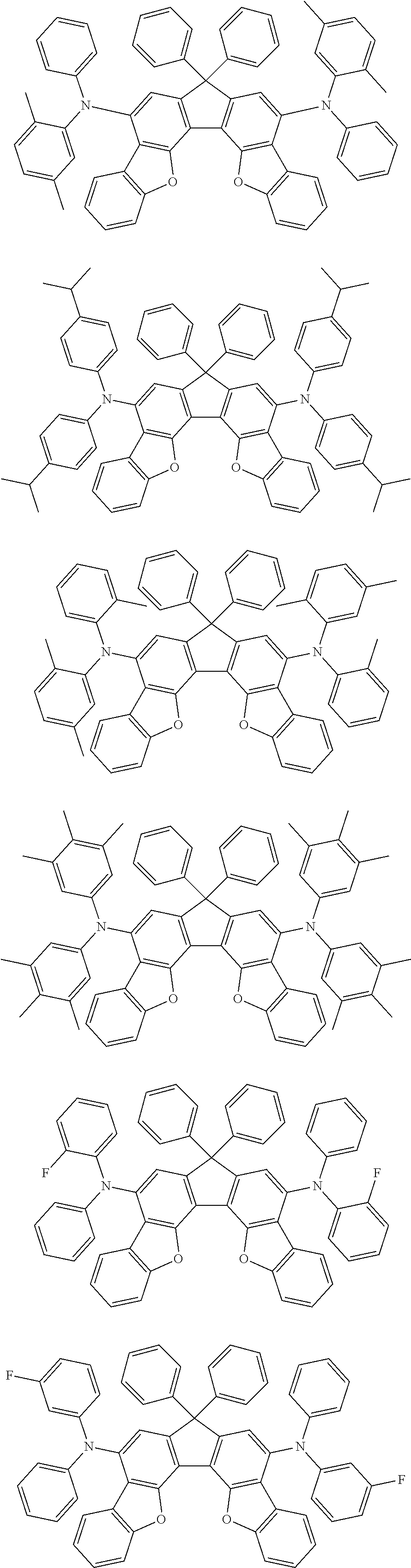

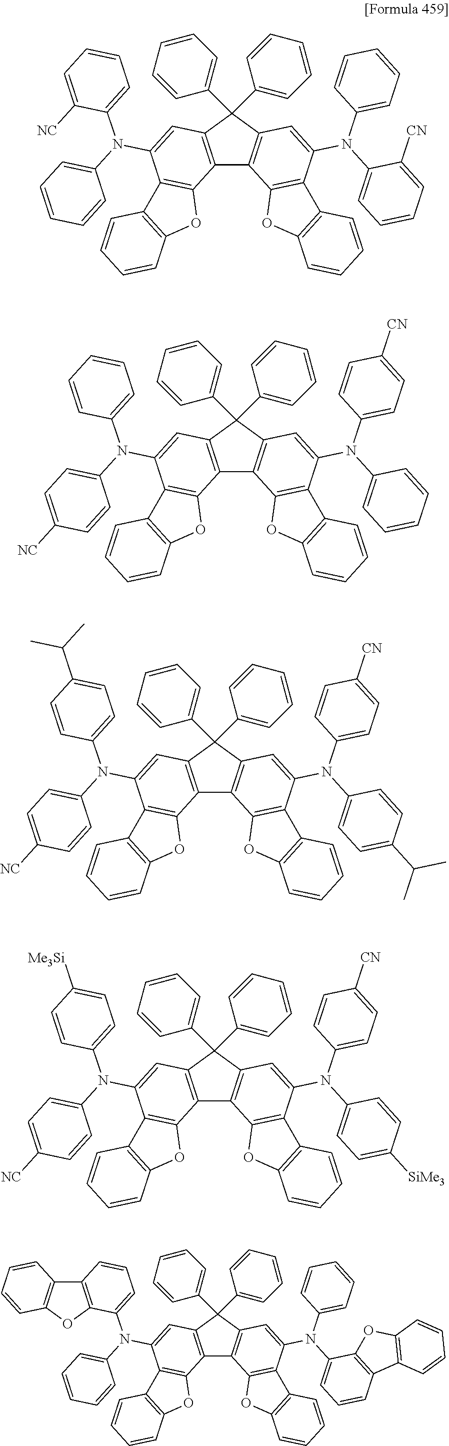

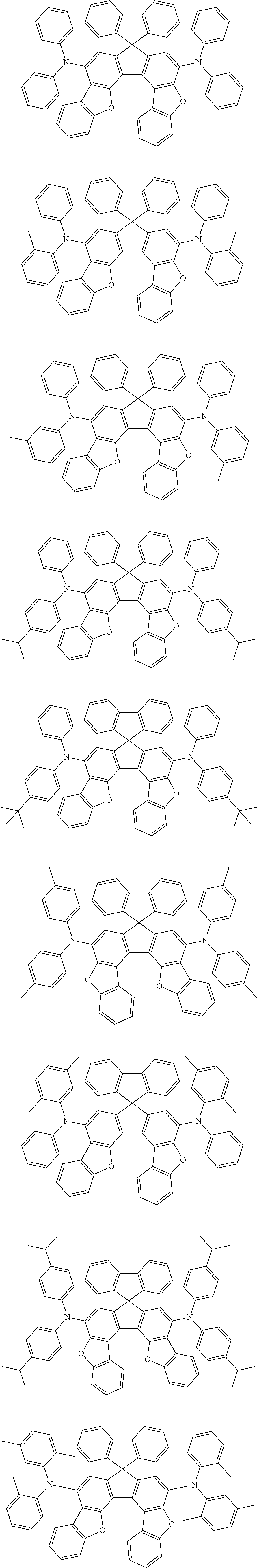

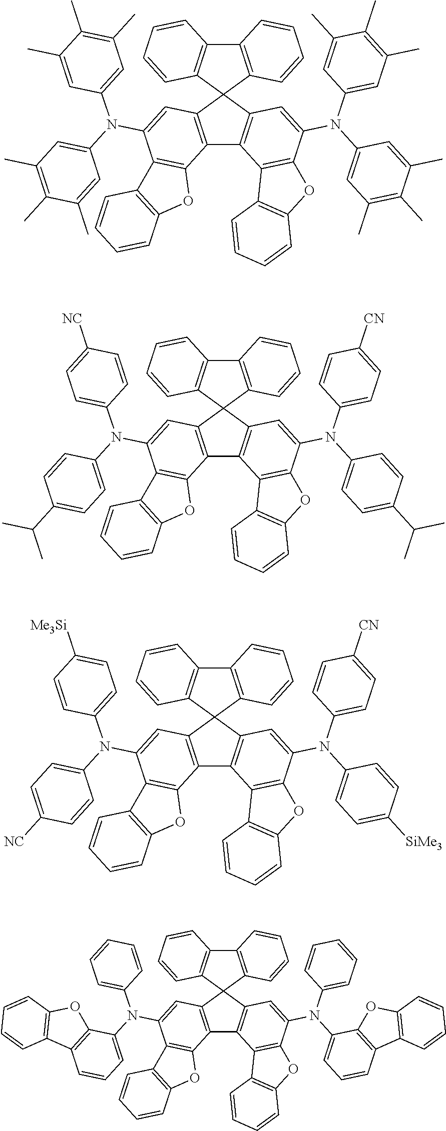

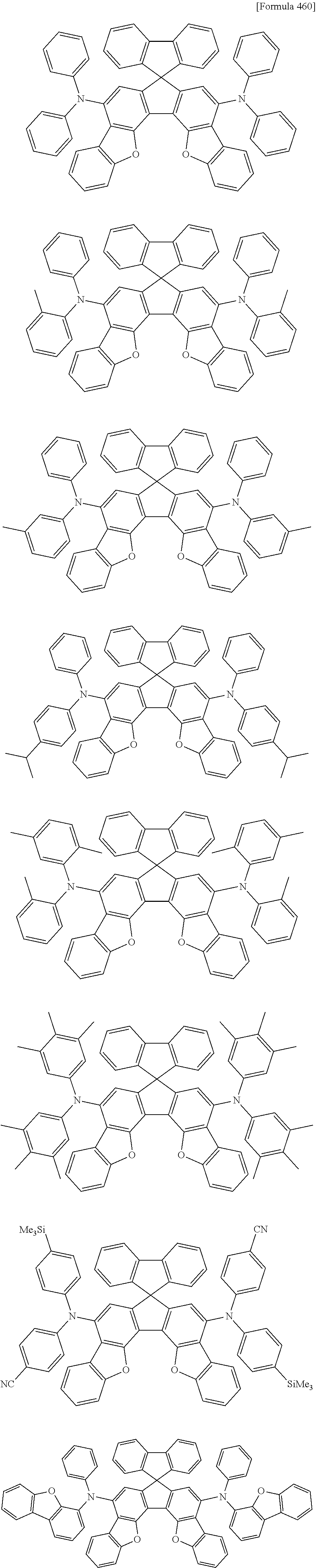

### Compound Represented by Formula (10)

The compound represented by the formula (10) will be described below.

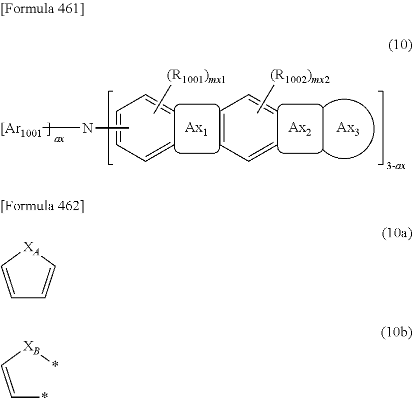

In the formula (10):
Ax₁ ring is a ring represented by the formula (10a) that is fused with adjacent ring(s) at any position(s);
Ax₂ ring is a ring represented by the formula (10b) that is fused with adjacent ring(s) at any position(s);
two * in the formula (10b) are bonded to Ax₃ ring at any position(s);
X_{A} and X_{B} are each independently C(R₁₀₀₃)(R₁₀₀₄), Si(R₁₀₀₅)(R₁₀₀₆), an oxygen atom or a sulfur atom;
Ax₃ ring is a substituted or unsubstituted aromatic hydrocarbon ring having 6 to 50 ring carbon atoms, or a substituted or unsubstituted heterocyclic ring having 5 to 50 ring atoms;
A₁₀₀₁ is a substituted or unsubstituted aryl group having 6 to 50 ring carbon atoms, or a substituted or unsubstituted heterocyclic group having 5 to 50 ring atoms;
R₁₀₀₁ to R₁₀₀₆ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
mx1 is 3, and mx2 is 2;
a plurality of R₁₀₀₁ are mutually the same or different;
a plurality of R₁₀₀₂ are mutually the same or different;
ax is 0, 1, or 2;
when ax is 0 or 1, the structures enclosed by brackets indicated by “3-ax” are mutually the same or different; and
when ax is 2, a plurality of Ar₁₀₀₁ are mutually the same or different.

In an exemplary embodiment, Ar₁₀₀₁ is a substituted or unsubstituted aryl group having 6 to 50 ring carbon atoms.

In an exemplary embodiment, Ax₃ ring is a substituted or unsubstituted aromatic hydrocarbon ring having 6 to 50 ring carbon atoms, example of which is a substituted or unsubstituted benzene ring, a substituted or unsubstituted naphthalene ring, or a substituted or unsubstituted anthracene ring.

In an exemplary embodiment, R₁₀₀₃ and R₁₀₀₄ are each independently a substituted or unsubstituted alkyl group having 1 to 50 carbon atoms.

In an exemplary embodiment, ax is 1.

### Specific Examples of Compound Represented by Formula (10)

Specific examples of the compound represented by the formula (10) include compounds shown below.

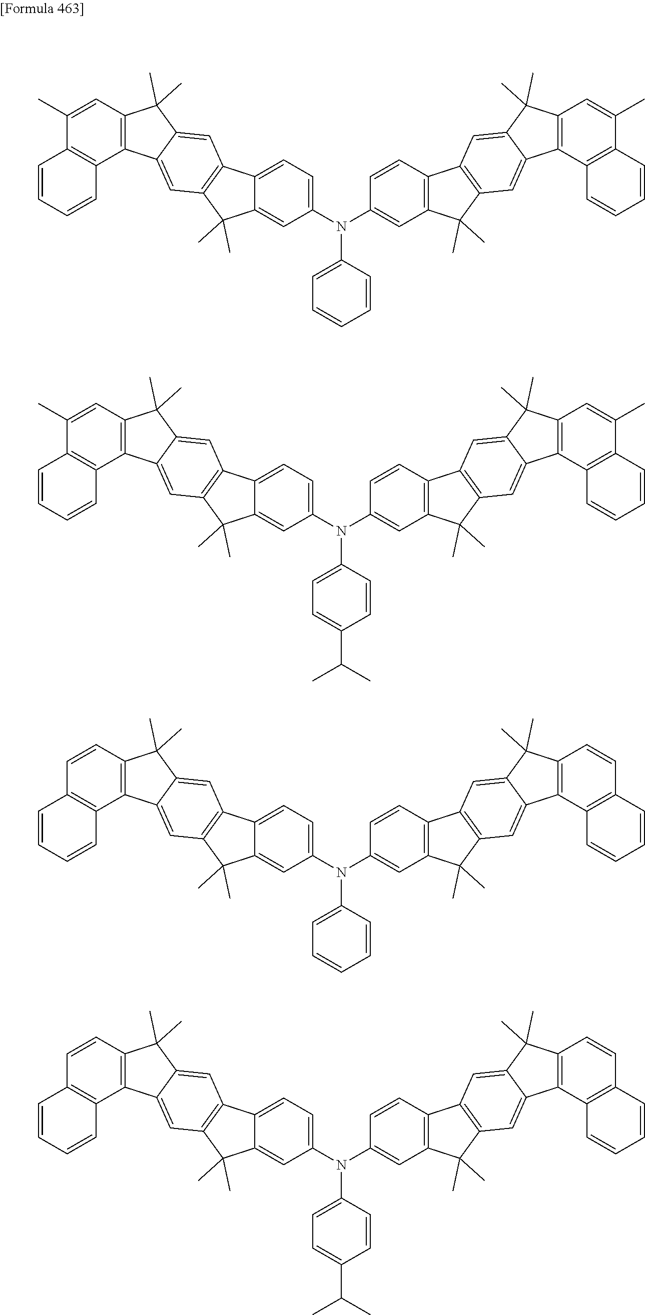

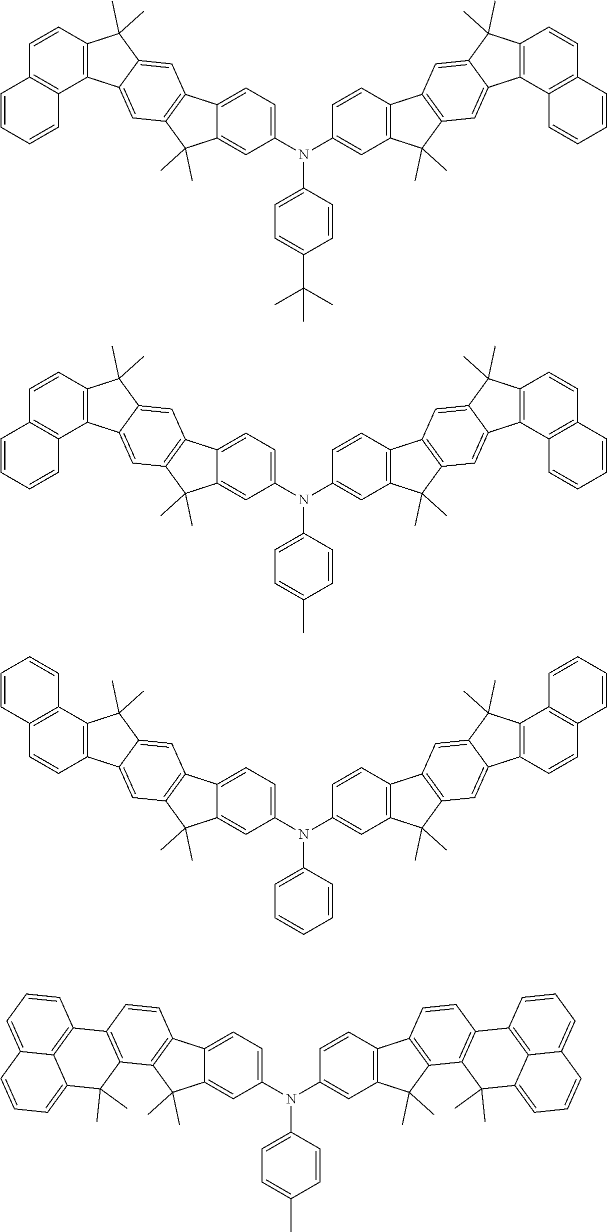 [SMILES: CC(C)(C)c1ccc(N(c2ccc3c(c2)C(C)(C)c2cc4c(cc2-3)C(C)(C)c2ccc3ccccc3c2-4)c2ccc3c(c2)C(C)(C)c2cc4c(cc2-3)C(C)(C)c2ccc3ccccc3c2-4)cc1 ; Cc1ccc(N(c2ccc3c(c2)C(C)(C)c2cc4c(cc2-3)C(C)(C)c2ccc3ccccc3c2-4)c2ccc3c(c2)C(C)(C)c2cc4c(cc2-3)C(C)(C)c2ccc3ccccc3c2-4)cc1 ; CC1(C)c2cc(N(c3ccccc3)c3ccc4c(c3)C(C)(C)c3cc5c(cc3-4)C(C)(C)c3c-5ccc4ccccc34)ccc2-c2cc3c(cc21)-c1ccc2ccccc2c1C3(C)C ; Cc1ccc(N(c2ccc3c(c2)C(C)(C)c2c-3ccc3c2C(C)(C)c2cccc4cccc-3c24)c2ccc3c(c2)C(C)(C)c2c-3ccc3c2C(C)(C)c2cccc4cccc-3c24)cc1]

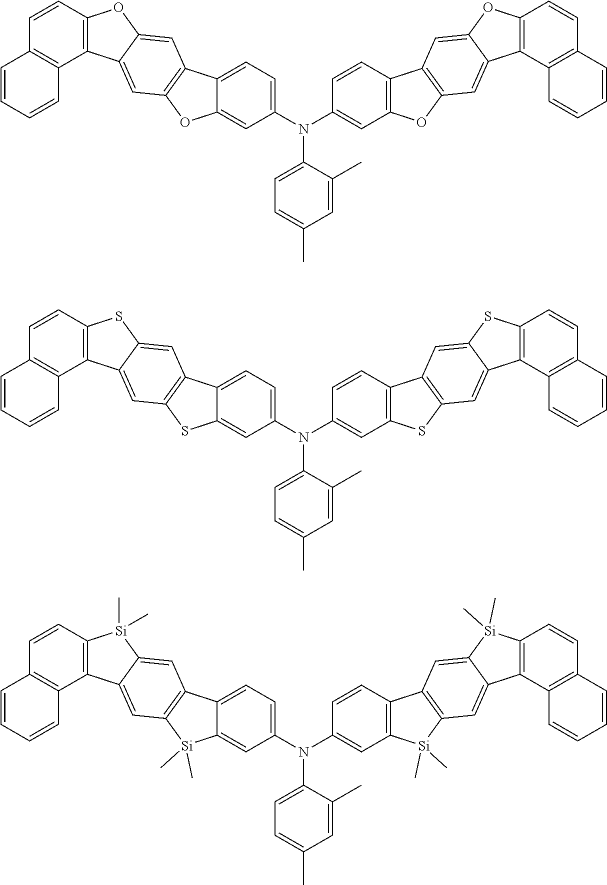 [SMILES: Cc1ccc(N(c2ccc3c(c2)oc2cc4c(cc23)oc2ccc3ccccc3c24)c2ccc3c(c2)oc2cc4c(cc23)oc2ccc3ccccc3c24)c(C)c1 ; Cc1ccc(N(c2ccc3c(c2)sc2cc4c(cc23)sc2ccc3ccccc3c24)c2ccc3c(c2)sc2cc4c(cc23)sc2ccc3ccccc3c24)c(C)c1 ; Cc1ccc(N(c2ccc3c(c2)[Si](C)(C)c2cc4c(cc2-3)[Si](C)(C)c2ccc3ccccc3c2-4)c2ccc3c(c2)[Si](C)(C)c2cc4c(cc2-3)[Si](C)(C)c2ccc3ccccc3c2-4)c(C)c1]

In an exemplary embodiment, the substituent for “the substituted or unsubstituted” group in each of the formulae is an unsubstituted alkyl group having 1 to 50 carbon atoms, an unsubstituted aryl group having 6 to 50 ring carbon atoms, or an unsubstituted heterocyclic group having 5 to 50 ring atoms.

In an exemplary embodiment, the substituent for “the substituted or unsubstituted” group in each of the formulae is an unsubstituted alkyl group having 1 to 18 carbon atoms, an unsubstituted aryl group having 6 to 18 ring carbon atoms, or an unsubstituted heterocyclic group having 5 to 18 ring atoms.

### Electron Transporting Zone

An exemplary arrangement of the organic EL device according to the exemplary embodiment further includes an electron transporting zone between the cathode and the emitting region, in which the electron transporting zone includes at least one electron transporting layer. The at least one electron transporting layer in the electron transporting zone contains a nitrogen-containing compound having at least one of a five-membered ring having a nitrogen atom or a six-membered ring having a nitrogen atom.

In an exemplary arrangement of the organic EL device according to the exemplary embodiment, at least one electron transporting layer in the electron transporting zone contains, as a nitrogen-containing compound, at least one compound selected from the group consisting of an imidazole derivative, benzimidazole derivative, azine derivative, carbazole derivative, and phenanthroline derivative.

### Phenanthroline Derivative

In an exemplary arrangement of the organic EL device according to the exemplary embodiment, at least one electron transporting layer in the electron transporting zone contains a phenanthroline derivative as a nitrogen-containing compound.

In an exemplary arrangement of the organic EL device of the exemplary embodiment, the phenanthroline derivative (phenanthroline compound) contained in the electron transporting layer is a compound represented by a formula (20) below and having at least one group represented by a formula (21) below.

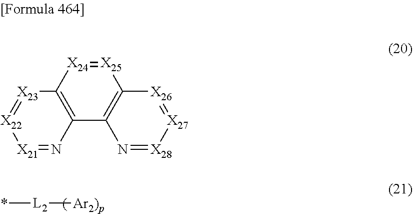

In the formula (20):
X₂₁ to X₂₈ are each independently a nitrogen atom, CR₂₁ or a carbon atom bonded to a group represented by the formula (21);
at least one of X₂₁ to X₂₈ is a carbon atom bonded to a group represented by the formula (21);
when a plurality of groups represented by the formula (21) are present, the plurality of groups represented by the formula (21) are mutually the same or different;
at least one combination of adjacent two or more of a plurality of R₂₁ are mutually bonded to form a substituted or unsubstituted monocyclic ring, mutually bonded to form a substituted or unsubstituted fused ring, or not mutually bonded; and
R₂₁ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₃₁, a group represented by —COOR₉₃₂, a group represented by —S(═O)₂R₉₃₃, a group represented by —B(R₉₃₄)(R₉₃₅), a group represented by —P(═O)(R₉₃₆)(R₉₃₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the formula (21):
Ar₂ is a substituted or unsubstituted aryl group having 6 to 50 ring carbon atoms, or a substituted or unsubstituted heterocyclic group having 5 to 50 ring atoms;
p is 1, 2, 3, 4, or 5;
when two or more Ar₂ are present, the two or more Ar₂ are mutually the same or different;
L₂ is a single bond or a linking group;
L₂ as a linking group is a substituted or unsubstituted polyvalent linear, branched or cyclic aliphatic hydrocarbon group having 1 to 50 carbon atoms, a substituted or unsubstituted polyvalent aromatic hydrocarbon group having 6 to 50 ring carbon atoms, a substituted or unsubstituted polyvalent heterocyclic group having 5 to 50 ring atoms, or a polyvalent multiple linking group obtained by bonding two or three groups selected from the polyvalent aromatic hydrocarbon ring group and the polyvalent heterocyclic group;
the aromatic hydrocarbon ring group and the heterocyclic group forming L₂ as the multiple linking group are mutually the same or different, and adjacent ones of the aromatic hydrocarbon ring group and the heterocyclic group are mutually bonded to form a ring, or not mutually bonded;
Ar₂ and L₂ as a linking group are mutually bonded to form a ring, or not mutually bonded;
L₂ as a linking group and a carbon atom or R₂₁ of CR₂₁ in one of X₂₁ to X₂₈ adjacent to a carbon atom bonded to L₂ are mutually bonded to form a ring, or not mutually bonded; and
in the formula (21) represents a bonding position to a ring represented by the formula (20).

In the phenanthroline compound, R₉₀₁, R₉₀₂, R₉₀₃, R₉₀₄, R₉₀₅, R₉₀₆, R₉₀₇, R₉₃₁, R₉₃₂, R₉₃₃, R₉₃₄, R₉₃₅, R₉₃₆, and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

A group represented by —O—(R₉₀₄) herein in which R₉₀₄ is a hydrogen atom is a hydroxy group.

A group represented by —S—(R₉₀₅) herein in which R₉₀₅ is a hydrogen atom is a thiol group.

A group represented by —S(═O)₂R₉₃₃ herein in which R₉₃₃ is a substituent is a substituted sulfo group.

A group represented by —B(R₉₃₄)(R₉₃₅) herein in which R₉₃₄ and R₉₃₅ are each a substituent is a substituted boryl group.

A group represented by —P(═O)(R₉₃₆)(R₉₃₇) herein is a substituted phosphine oxide group when R₉₃₆ and R₉₃₇ are each a substituent, and an aryl phosphoryl group when R₉₃₆ and R₉₃₇ are each an aryl group.

An “unsubstituted polyvalent linear, branched or cyclic aliphatic hydrocarbon group” mentioned herein has, unless otherwise specified herein, 1 to 50, preferably 1 to 20, more preferably 1 to 6 carbon atoms.

An “unsubstituted polyvalent aromatic hydrocarbon group” mentioned herein has, unless otherwise specified herein, 6 to 50, preferably 6 to 30, more preferably 6 to 18 ring carbon atoms.

An “unsubstituted polyvalent heterocyclic group” mentioned herein has, unless otherwise specified, 5 to 50, preferably 5 to 30, more preferably 5 to 18 ring atoms.

In an exemplary embodiment, a heterocyclic group having 5 to 50 ring atoms as Ar₂ in the formula (21) includes a substituted or unsubstituted group derived from the cyclic structure represented by the formula (20).

In an exemplary embodiment, X₂₁ and X₂₈ in the formula (20) are each a carbon atom bonded to a group represented by the formula (21).

In an exemplary embodiment, one of X₂₁ and X₂₈ in the formula (20) is a carbon atom bonded to a group represented by the formula (21) and the other of X₂₁ and X₂₈ is a carbon atom bonded to a hydrogen atom.

In an exemplary embodiment, X₂₁ to X₂₈ in the formula (20) are each independently CR₂₁ or a carbon atom bonded to a group represented by the formula (21).

In an exemplary embodiment, the rest of X₂₁ to X₂₈ in the formula (20), except for a carbon atom bonded to a group represented by the formula (21), are CR₂₁. Specifically, in an exemplary embodiment, the compound represented by the formula (20) is a 1,10-phenanthroline derivative.

In an exemplary embodiment, Ar₂ in the formula (21) is a substituted or unsubstituted fused aromatic hydrocarbon group having 8 to 20 ring carbon atoms.

In an exemplary embodiment, a fused aromatic hydrocarbon group having 8 to 20 ring carbon atoms is a group derived from any aromatic hydrocarbon selected from the group consisting of, for instance, naphthalene, anthracene, acephenanthrylene, aceanthrylene, benzanthracene, triphenylene, pyrene, chrysene, naphthacene, fluorene, phenanthrene, fluoranthene, and benzofluoranthene.

In an exemplary embodiment, Ar₂ in the formula (21) is a substituted or unsubstituted anthryl group.

In an exemplary embodiment, Ar₂ in the formula (21) is a substituted or unsubstituted heterocyclic group having 5 to 40 ring carbon atoms.

In an exemplary embodiment, Ar₂ in the formula (21) is a substituted or unsubstituted group derived from the cyclic structure represented by the formula (20).

In an exemplary embodiment, Ar₂ in the formula (21) is a group represented by a formula (23) below.

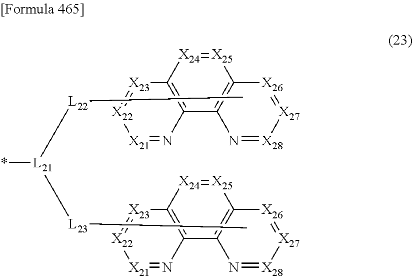

In the formula (23):
X₂₁ to X₂₈ are each independently a nitrogen atom, CR₂₁, a group represented by the formula (21), a carbon atom bonded to a group represented by the formula (21), or a carbon atom bonded to L₂₂ or L₂₃;
L₂₁ is a linking group, and L₂₁ as the linking group is a substituted or unsubstituted trivalent linear, branched or cyclic aliphatic hydrocarbon group having 1 to 50 carbon atoms, a substituted or unsubstituted trivalent aromatic hydrocarbon group having 6 to 50 ring carbon atoms, or a substituted or unsubstituted trivalent heterocyclic group having 5 to 50 ring atoms; and
L₂₂ and L₂₃ are each independently a single bond or a linking group, and L₂₂ and L₂₃ as the linking group are each independently a substituted or unsubstituted divalent linear, branched or cyclic aliphatic hydrocarbon group having 1 to 50 carbon atoms, a substituted or unsubstituted arylene group having 6 to 50 ring carbon atoms, or a substituted or unsubstituted divalent heterocyclic group having 5 to 50 ring atoms.

In a formula representing a phenanthroline compound:
when a plurality of X₂₁ are present, the plurality of X₂₁ are mutually the same or different;
when a plurality of X₂₂ are present, the plurality of X₂₂ are mutually the same or different;
when a plurality of X₂₃ are present, the plurality of X₂₃ are mutually the same or different;
when a plurality of X₂₄ are present, the plurality of X₂₄ are mutually the same or different;
when a plurality of X₂₅ are present, the plurality of X₂₅ are mutually the same or different;
when a plurality of X₂₆ are present, the plurality of X₂₆ are mutually the same or different;
when a plurality of X₂₇ are present, the plurality of X₂₇ are mutually the same or different; and
when a plurality of X₂₈ are present, the plurality of X₂₈ are mutually the same or different.

In an exemplary embodiment, X₂₁ to X₂₈ in the formula (23) are preferably each independently a nitrogen atom, CR₂₁, or a carbon atom bonded to L₂₂ or L₂₃, more preferably CR₂₁, or a carbon atom bonded to L₂₂ or L₂₃.

In an exemplary embodiment, the phenanthroline compound is a compound represented by a formula (24) below.

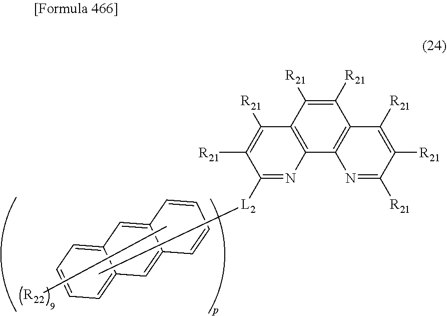

In the formula (24):
a plurality of R₂₁ each independently represent the same as R₂₁ in the formula (20);
a plurality of R₂₂ each independently represent the same as R₂₁ in the formula (20);
L₂ represents the same as L₂ in the formula (21);
p is 1, 2, 3, 4, or 5; and
the plurality of R₂₂ and L₂ are bonded to respective ones of carbon atoms at positions 1 to 10 of an anthracene ring.

In an exemplary embodiment, the phenanthroline compound is a compound represented by a formula (24A) below.

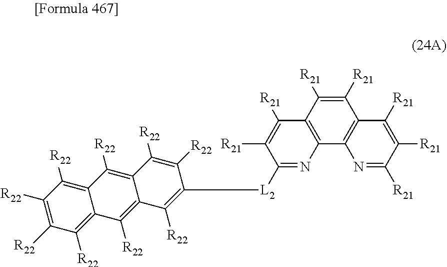

In the formula (24A): a plurality of R₂₁ each independently represent the same as R₂₁ in the formula (20); a plurality of R₂₂ each independently represent the same as R₂₁ in the formula (20); and L₂ represents the same as L₂ in the formula (21).

In an exemplary embodiment, the phenanthroline compound is a compound represented by a formula (24B) below.

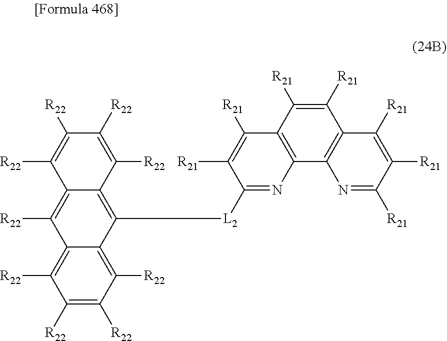

In the formula (24B): a plurality of R₂₁ each independently represent the same as R₂₁ in the formula (20); a plurality of R₂₂ each independently represent the same as R₂₁ in the formula (20); and L₂ represents the same as L₂ in the formula (21).

In an exemplary embodiment, the phenanthroline compound is a compound represented by a formula (25) below.

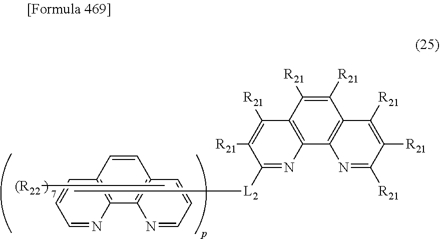

In the formula (25):
a plurality of R₂₁ each independently represent the same as R₂₁ in the formula (20);
a plurality of R₂₂ each independently represent the same as R₂₁ in the formula (20);
L₂ represents the same as L₂ in the formula (21);
p is 1, 2, 3, 4, or 5; and
the plurality of R₂₂ and L₂ are bonded to respective ones of carbon atoms at positions 2 to 9 of a phenanthroline ring.

In an exemplary embodiment, the phenanthroline compound is a compound represented by a formula (25A) below.

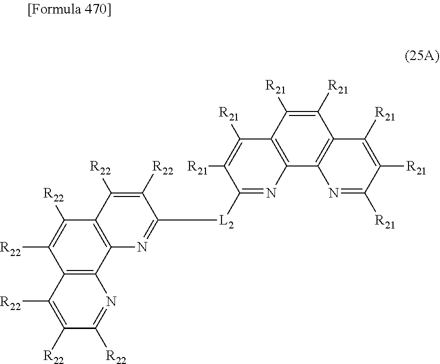

In the formula (25A): a plurality of R₂₁ each independently represent the same as R₂₁ in the formula (20); a plurality of R₂₂ each independently represent the same as R₂₁ in the formula (20); and L2 represents the same as L2 in the formula (21).

In an exemplary embodiment, L₂ in the formulae (24), (24A), (24B), (25) and (25A) is a single bond, a substituted or unsubstituted arylene group having 6 to 50 ring carbon atoms, or a substituted or unsubstituted divalent heterocyclic group having 5 to 50 ring atoms.

In an exemplary embodiment, the phenanthroline compound is a compound represented by a formula (25B) below.

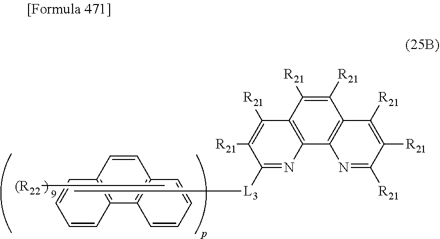

In the formula (25B):
a plurality of R₂₁ each independently represent the same as R₂₁ in the formula (20);
a plurality of R₂₂ each independently represent the same as R₂₁ in the formula (20);
L₃ is a linking group, and L₃ as the linking group is a substituted or unsubstituted polyvalent linear, branched or cyclic aliphatic hydrocarbon group having 1 to 50 carbon atoms, a substituted or unsubstituted polyvalent amino group, a substituted or unsubstituted polyvalent aromatic hydrocarbon group having 6 to 50 ring carbon atoms, a substituted or unsubstituted polyvalent heterocyclic group having 5 to 50 ring atoms, or a polyvalent multiple linking group obtained by bonding two or three groups selected from the polyvalent aromatic hydrocarbon ring group and the polyvalent heterocyclic group;
the aromatic hydrocarbon ring group and the heterocyclic group forming L₃ as the multiple linking group are mutually the same or different, and adjacent ones of the aromatic hydrocarbon ring group and the heterocyclic group are mutually bonded to form a ring, or not mutually bonded;
p is 1, 2, 3, 4, or 5; and
the plurality of R₂₂ and L₂ are bonded to respective ones of carbon atoms at positions 1 to 10 of a phenanthroline ring.

In an exemplary embodiment, the phenanthroline compound is a compound represented by a formula (25C) below.

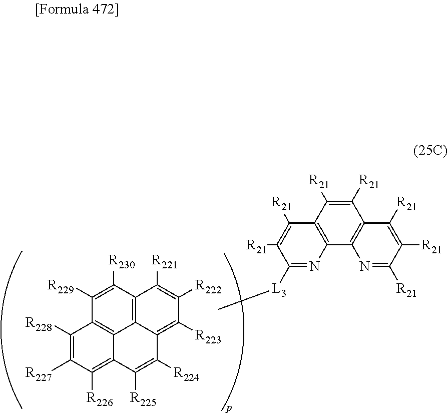

In the formula (25C):
a plurality of R₂₁ each independently represent the same as R₂₁ in the formula (20);
one of R₂₂₁ to R₂₃₀ is a single bond bonded to L₃, and R₂₂₁ to R₂₃₀ not being the single bond bonded to L₃ each independently represent the same as R₂₁ in the formula (20);
L₃ is a linking group, and L₃ as the linking group represents the same as L₃ as the linking group in the formula (25B); and
p is 1, 2, 3, 4, or 5.

In an exemplary embodiment, the phenanthroline compound is a compound represented by a formula (25D) below.

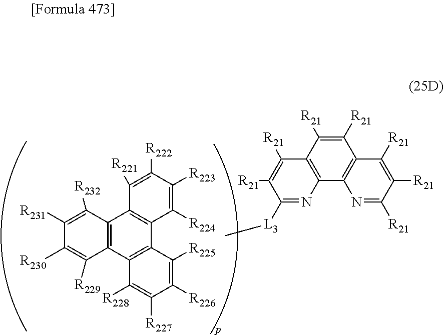

In the formula (25D):
a plurality of R₂₁ each independently represent the same as R₂₁ in the formula (20);
one of R₂₂₁ to R₂₃₂ is a single bond bonded to L₃, and R₂₂₁ to R₂₃₂ not being the single bond bonded to L₃ each independently represent the same as R₂₁ in the formula (20);
L₃ is a linking group, and L₃ as the linking group represents the same as L₃ as the linking group in the formula (25B); and
p is 1, 2, 3, 4, or 5.

In an exemplary embodiment, the phenanthroline compound is a compound represented by a formula (25E) below.

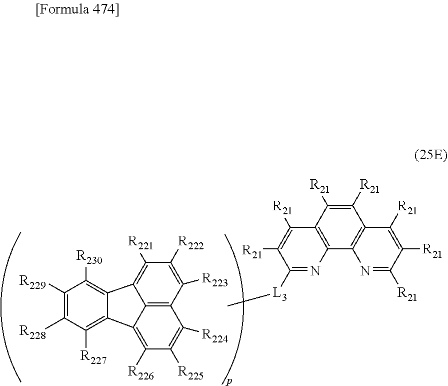

In the formula (25E):
a plurality of R₂₁ each independently represent the same as R₂₁ in the formula (20);
one of R₂₂₁ to R₂₃₀ is a single bond bonded to L₃, and R₂₂₁ to R₂₃₀ not being the single bond bonded to L₃ each independently represent the same as R₂₁ in the formula (20);
L₃ is a linking group, and L₃ as the linking group represents the same as L₃ as the linking group in the formula (25B); and
p is 1, 2, 3, 4, or 5.
L₃ in the formulae (25B), (25C), (25D) and (25E) is also preferably a substituted or unsubstituted arylene group having 6 to 50 ring carbon atoms, or a substituted or unsubstituted divalent heterocyclic group having 5 to 50 ring atoms.

### Producing Method of Phenanthroline Compound

The phenanthroline compound can be produced by a known method. The phenanthroline compound can also be produced based on a known method through a known alternative reaction using a known material(s) tailored for the target compound.

### Azine Derivative

In an exemplary arrangement of the organic EL device according to the exemplary embodiment, at least one electron transporting layer in the electron transporting zone contains an azine derivative as a nitrogen-containing compound.

In an exemplary arrangement of the organic EL device of the exemplary embodiment, the azine derivative contained in the electron transporting layer is a compound represented by a formula (E42) below.

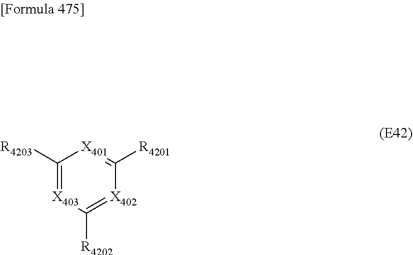

In the formula (E42):
X₄₀₁ to X₄₀₃ are each independently CR₄₂₀₄ or a nitrogen atom;
at least one of X₄₀₁ to X₄₀₃ is a nitrogen atom;
when two or more R₄₂₀₄ are present, the two or more R₄₂₀₄ are mutually the same or different;
R₄₂₀₁ to R₄₂₀₄ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms; R₉₀₁ to R₉₀₇ in the azine derivative are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of the organic EL device of the exemplary embodiment, the azine derivative contained in the electron transporting layer is a compound represented by a formula (E421) below.

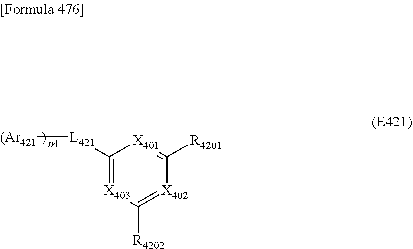

In the formula (E421):
X₄₀₁ to X₄₀₃, R₄₂₀₁, and R₄₂₀₂ each independently represent the same as X₄₀₁ to X₄₀₃, R₄₂₀₁, and R₄₂₀₂;
n4 is 1, 2, or 3;
L₄₂₁ is a single bond, a substituted or unsubstituted arylene group having 6 to 50 ring carbon atoms, a trivalent or tetravalent group derived from the arylene group, a substituted or unsubstituted divalent heterocyclic group having 5 to 50 ring atoms, a trivalent or tetravalent group derived from the divalent heterocyclic group, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms, or a trivalent or tetravalent group derived from the divalent group;
Ar₄₂₁ is a substituted or unsubstituted aryl group having 6 to 50 ring carbon atoms, or a substituted or unsubstituted heterocyclic group having 5 to 50 ring atoms;
when n4 is 2 or 3, Ar₄₂₁ are mutually the same or different; and
when n4 is 2 or 3, L₄₂₁ is not a single bond.

In an exemplary arrangement of the organic EL device of the exemplary embodiment, the azine derivative contained in the electron transporting layer is a compound represented by each of a formula (E422) and a formula (E423) below.

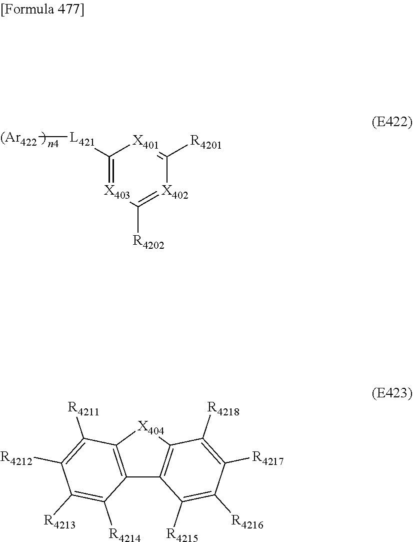

In the formula (E422):
n4, X₄₀₁ to X₄₀₃, R₄₂₀₁, and R₄₂₀₂ respectively independently represent the same as X₄₀₁ to X₄₀₃, R₄₂₀₁, and R₄₂₀₂;
L₄₂₁ represents the same as L₄₂₁ in the formula (E421); and
Ar₄₂₂ is a group represented by the formula (E423).

In the formula (E423):
X₄O₄ is an oxygen atom, a sulfur atom, N(R₄₂₂₁), or C(R₄₂₂₂)(R₄₂₂₃);
one of R₄₂₁₁ to R₄₂₁₈ and R₄₂₂₁ to R₄₂₂₃ is a single bond with L₄₂₁;
at least one combination of adjacent two or more of R₄₂₁₁ to R₄₂₁₈ not being a single bond with L₄₂₁ are mutually bonded to form a substituted or unsubstituted monocyclic ring, mutually bonded to form a substituted or unsubstituted fused ring, or not mutually bonded;
a combination of R₄₂₂₂ and R₄₂₂₃ not being a single bond with L₄₂₁ are mutually bonded to form a substituted or unsubstituted monocyclic ring, mutually bonded to form a substituted or unsubstituted fused ring, or not mutually bonded;
R₄₂₁₁ to R₄₂₁₈ not being a single bond with L₄₂₁ and forming neither the substituted or unsubstituted monocyclic ring nor the substituted or unsubstituted fused ring; R₄₂₂₁; and R₄₂₂₂ and R₄₂₂₃ not being a single bond with L₄₂₁ and forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
when n4 is 2 or 3,
a plurality of R₄₀₄ are mutually the same or different,
a plurality of R₄₂₁₁ are mutually the same or different,
a plurality of R₄₂₁₂ are mutually the same or different,
a plurality of R₄₂₁₃ are mutually the same or different,
a plurality of R₄₂₁₄ are mutually the same or different,
a plurality of R₄₂₁₅ are mutually the same or different,
a plurality of R₄₂₁₆ are mutually the same or different,
a plurality of R₄₂₁₇ are mutually the same or different, and
a plurality of R₄₂₁₈ are mutually the same or different.

In the formulae (E422) and (E423), R₉₀₁ to R₉₀₇ each independently represent the same as R₉₀₁ to R₉₀₇ in the azine derivative.

For instance, in the formula (E421), when n4 is 1, a group represented by (Ar₄₂₁)ₙ₄-L₄₂₁-* is represented by a formula (E421-1) below. In this arrangement, L₄₂₁ is a divalent linking group. * represents a bonding position to a six-membered ring in the formula (E421).

In the formula (E421), when n4 is 2, a group represented by (Ar₄₂₁)n4-L421-* is represented by a formula (E421-2) below. Ar₄₂₁ are mutually the same or different. In this arrangement, L₄₂₁ is a trivalent linking group.

In the formula (E421), when n4 is 3, a group represented by (Ar₄₂₁)n4-L421-* is represented by a formula (E421-3) below. Ar₄₂₁ are mutually the same or different. In this arrangement, L₄₂₁ is a tetravalent linking group.

The same applies for a group represented by (Ar₄₂₂)ₙ₄-L₄₂₁-* in the formula (E422).

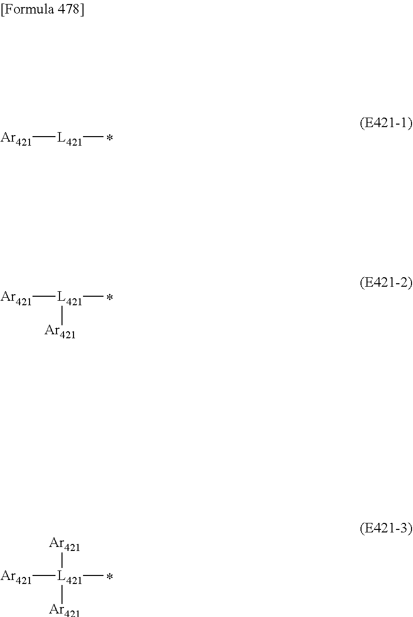

Each * in the formulae (E421-1), (E421-2), and (E421-3) represents a bonding position to a six-membered ring in the formula (E421).

In the formulae (E421) to (E422), L₄₂₁ as a linking group is preferably a divalent or trivalent group derived from any one of benzene, biphenyl, terphenyl, naphthalene, and phenanthrene.

In an exemplary arrangement of the organic EL device according to the exemplary embodiment, a substituent for “a substituted or unsubstituted” group in the azine derivative is at least one group selected from the group consisting of an alkyl group having 1 to 18 carbon atoms, aryl group having 6 to 18 ring carbon atoms, and heterocyclic group having 5 to 18 ring atoms.

In an exemplary arrangement of the organic EL device according to the exemplary embodiment, a substituent for “the substituted or unsubstituted” group in the azine derivative is an alkyl group having 1 to 5 carbon atoms.

In an exemplary arrangement of the organic EL device according to the exemplary embodiment, the groups specified to be “substituted or unsubstituted” in the azine derivative are each an “unsubstituted” group.

### Benzimidazole Derivative

In an exemplary arrangement of the organic EL device according to the exemplary embodiment, at least one electron transporting layer in the electron transporting zone contains a benzimidazole derivative.

In an exemplary arrangement of the organic EL device of the exemplary embodiment, the benzimidazole derivative contained in the electron transporting layer is a compound represented by a formula (E41) below.

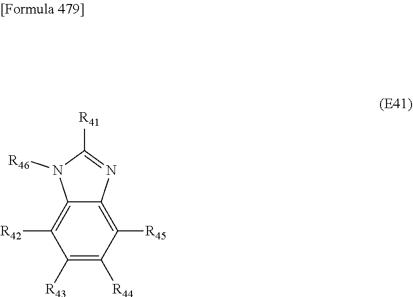

In the formula (E41):
at least one combination of adjacent two or more of R₄₁ to R₄₆ are mutually bonded to form a substituted or unsubstituted monocyclic ring, mutually bonded to form a substituted or unsubstituted fused ring, or not mutually bonded; and
R₄₁ to R₄₆ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the formula (E41): R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of the organic EL device of the exemplary embodiment, the benzimidazole derivative contained in the electron transporting layer is a compound represented by a formula (E41A), (E41B), (E41C), (E41D), or (E41 E) below.

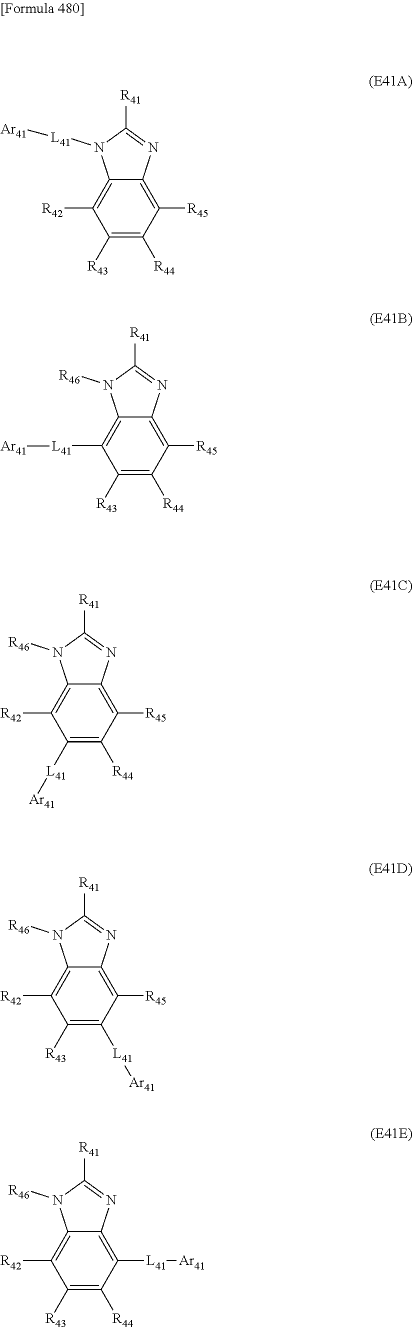

In the formulae (E41A), (E41 B), (E41 C), (E41 D), and (E41 E):
R₄₁ to R₄₆ each independently represent the same as R₄₁ to R₄₆ in the formula (E41);
L₄₁ is a single bond, a substituted or unsubstituted arylene group having 6 to 50 ring carbon atoms, or a substituted or unsubstituted divalent heterocyclic group having 5 to 50 ring atoms; and
Ar₄₁ is a substituted or unsubstituted alkyl group having 1 to 50 carbon atoms, a group represented by —O—(R₉₀₄), a substituted or unsubstituted aryl group having 6 to 50 ring carbon atoms, or a substituted or unsubstituted heterocyclic group having 5 to 50 ring atoms; and R₉₀₄ represents the same as R₉₀₄ in the benzimidazole derivative.

In an exemplary arrangement of the organic EL device of the exemplary embodiment, Ar₄₁ in the formulae (E41A), (E41B), (E41C), (E41D), and (E41E) is a group represented by a formula (E412) below.

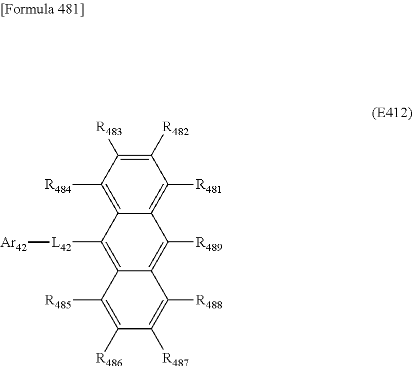

In the formula (E412):
one of R₄₈₁ to R₄₈₉ is a single bond with L₄₁;
at least one combination of adjacent two or more of R₄₈₁ to R₄₈₉ not being a single bond with L₄₁ are mutually bonded to form a substituted or unsubstituted monocyclic ring, mutually bonded to form a substituted or unsubstituted fused ring, or not mutually bonded;
R₄₈₁ to R₄₈₉ not being a single bond with L₄₁ and forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
L₄₂ is each independently a single bond, a substituted or unsubstituted arylene group having 6 to 50 ring carbon atoms, or a substituted or unsubstituted divalent heterocyclic group having 5 to 50 ring atoms; and
Ar₄₂ is each independently a substituted or unsubstituted aryl group having 6 to 50 ring carbon atoms, or a substituted or unsubstituted heterocyclic group having 5 to 50 ring atoms.

In the formula (E412), R₉₀₁ to R₉₀₇ each independently represent the same as R₉₀₁ to R₉₀₇ in the benzimidazole derivative.

In the formulae (E41A), (E41B), (E41C), (E41D), and (E41E), L₄₁ is preferably a substituted or unsubstituted phenylene group, a substituted or unsubstituted biphenylene group, a substituted or unsubstituted naphthylene group, a substituted or unsubstituted pyridinylene group, or a substituted or unsubstituted 9,9′-spirobifluorenylene group.

In the formulae (E41A), (E41B), (E41C), (E41D), and (E41E), L₄₁ is more preferably an unsubstituted phenyl group, an unsubstituted biphenylene group, an unsubstituted naphthylene group, an unsubstituted pyridinylene group, or an unsubstituted 9,9′-spirobifluorenylene group.

In the formulae (E41A), (E41B), (E41C), (E41D), and (E41E), Ar₄₁ is preferably a substituted or unsubstituted phenyl group, a substituted or unsubstituted biphenyl group, a substituted or unsubstituted terphenyl group, a substituted or unsubstituted naphthyl group, a substituted or unsubstituted phenanthryl group, a substituted or unsubstituted fluoranthenyl group, a substituted or unsubstituted pyrenyl group, or a substituted or unsubstituted fluorenyl group.

In the formulae (E41A), (E41B), (E41C), (E41D), and (E41E), Ar₄₁ is more preferably an unsubstituted phenyl group, an unsubstituted biphenyl group, an unsubstituted terphenyl group, an unsubstituted naphthyl group, an unsubstituted phenanthryl group, an unsubstituted fluoranthenyl group, an unsubstituted pyrenyl group, or an unsubstituted 9,9-dimethylfluorenyl group.

In an exemplary arrangement of the organic EL device of the exemplary embodiment is a compound represented by the formula (E413) below.

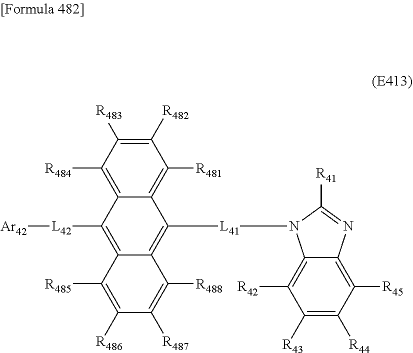

In the formula (E413): R₄₁ to R₄₅ and L₄₁ each independently represent the same as R₄₁ to R₄₅ and L₄₁ in the formula (E41A); and R₄₈₁ to R₄₈₈, L₄₂, and Ar₄₂ each independently represent the same as R₄₈₁ to R₄₈₈, L₄₂, and Ar₄₂ in the formula (E412).

In an exemplary arrangement of the organic EL device according to the exemplary embodiment, the groups specified to be “substituted or unsubstituted” in the benzimidazole derivative are each an “unsubstituted” group.

### Specific Examples of Nitrogen-containing Compound

Specific examples of the nitrogen-containing compound include the following compounds. It should however be noted that the invention is not limited to the specific examples of the nitrogen-containing compound.

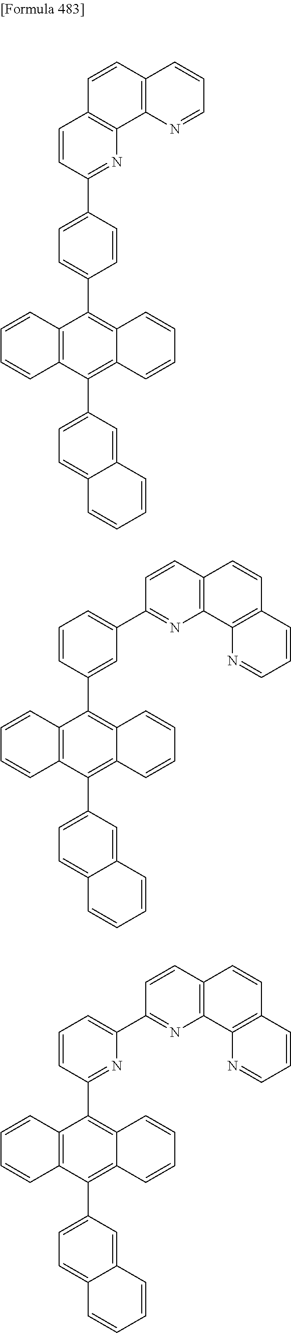 [SMILES: c1ccc2cc(-c3c4ccccc4c(-c4ccc(-c5ccc6ccc7cccnc7c6n5)cc4)c4ccccc34)ccc2c1 ; c1cc(-c2ccc3ccc4cccnc4c3n2)cc(-c2c3ccccc3c(-c3ccc4ccccc4c3)c3ccccc23)c1 ; c1cc(-c2ccc3ccc4cccnc4c3n2)nc(-c2c3ccccc3c(-c3ccc4ccccc4c3)c3ccccc23)c1]

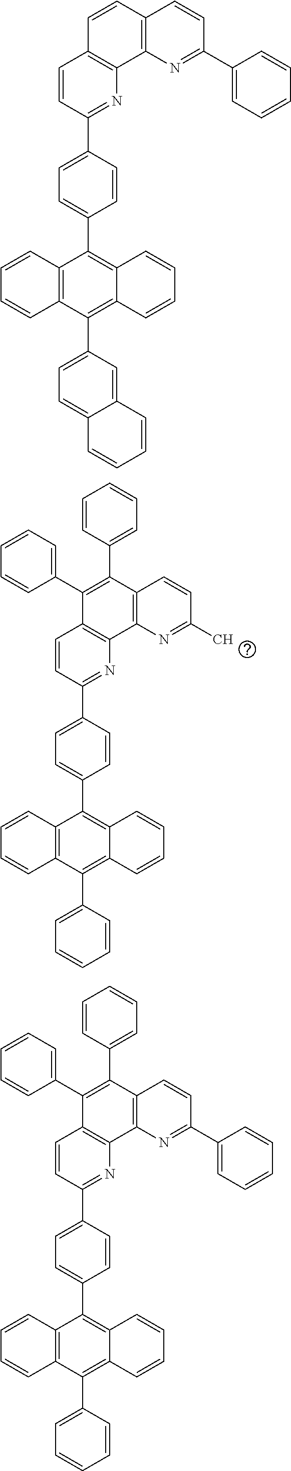

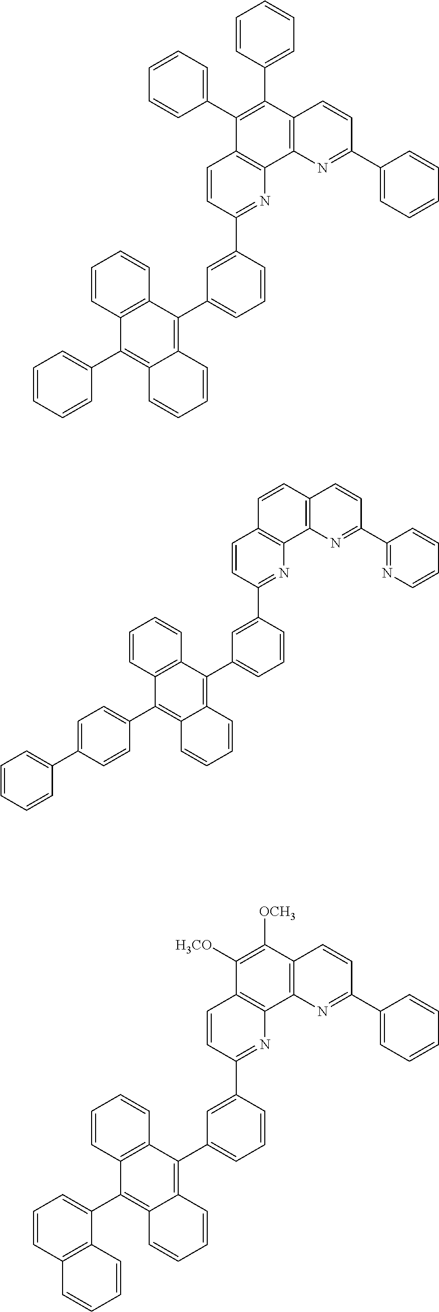 [SMILES: c1ccc(-c2ccc3c(-c4ccccc4)c(-c4ccccc4)c4ccc(-c5cccc(-c6c7ccccc7c(-c7ccccc7)c7ccccc67)c5)nc4c3n2)cc1 ; c1ccc(-c2ccc(-c3c4ccccc4c(-c4cccc(-c5ccc6ccc7ccc(-c8ccccn8)nc7c6n5)c4)c4ccccc34)cc2)cc1 ; COc1c(OC)c2ccc(-c3cccc(-c4c5ccccc5c(-c5cccc6ccccc56)c5ccccc45)c3)nc2c2nc(-c3ccccc3)ccc12]

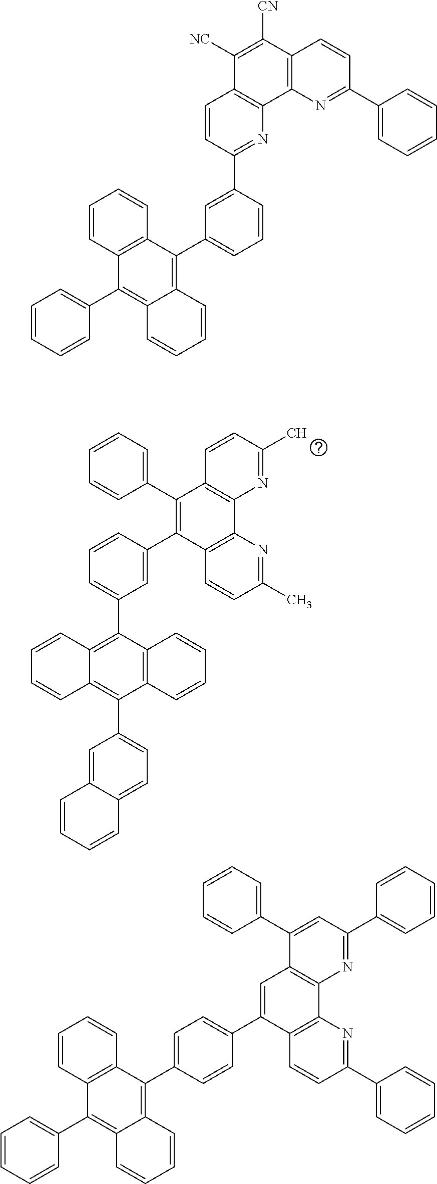 [SMILES: N#Cc1c(C#N)c2ccc(-c3cccc(-c4c5ccccc5c(-c5ccccc5)c5ccccc45)c3)nc2c2nc(-c3ccccc3)ccc12 ; Cc1ccc2c(-c3ccccc3)c(-c3cccc(-c4c5ccccc5c(-c5ccc6ccccc6c5)c5ccccc45)c3)c3ccc(C)nc3c2n1 ; c1ccc(-c2ccc3c(-c4ccc(-c5c6ccccc6c(-c6ccccc6)c6ccccc56)cc4)cc4c(-c5ccccc5)cc(-c5ccccc5)nc4c3n2)cc1]

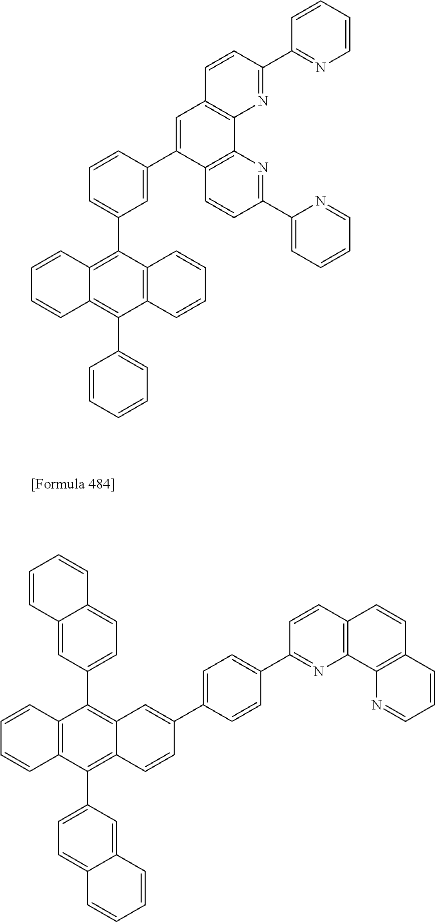 [SMILES: c1ccc(-c2c3ccccc3c(-c3cccc(-c4cc5ccc(-c6ccccn6)nc5c5nc(-c6ccccn6)ccc45)c3)c3ccccc23)cc1 ; c1ccc2cc(-c3c4ccccc4c(-c4ccc5ccccc5c4)c4cc(-c5ccc(-c6ccc7ccc8cccnc8c7n6)cc5)ccc34)ccc2c1]

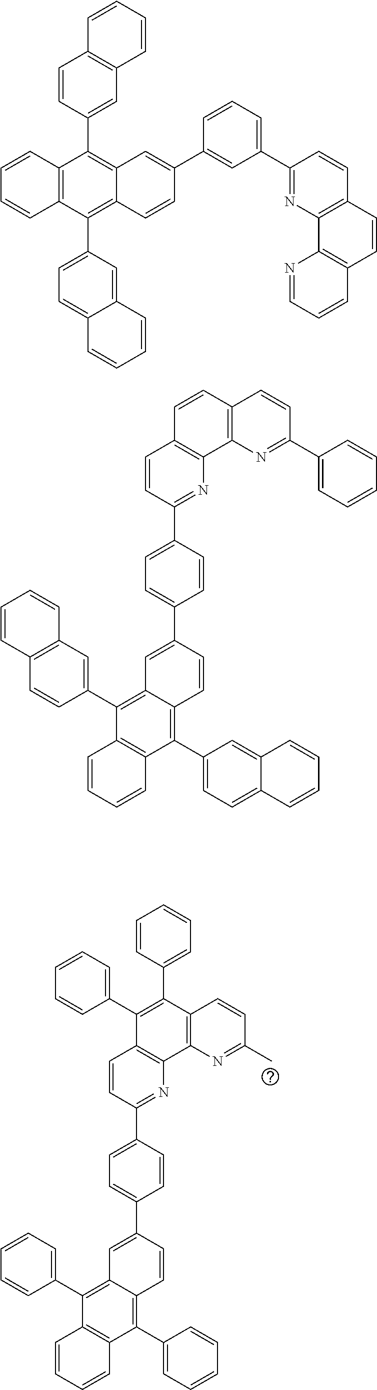 [SMILES: c1cc(-c2ccc3c(-c4ccc5ccccc5c4)c4ccccc4c(-c4ccc5ccccc5c4)c3c2)cc(-c2ccc3ccc4cccnc4c3n2)c1 ; c1ccc(-c2ccc3ccc4ccc(-c5ccc(-c6ccc7c(-c8ccc9ccccc9c8)c8ccccc8c(-c8ccc9ccccc9c8)c7c6)cc5)nc4c3n2)cc1 ; Cc1ccc2c(-c3ccccc3)c(-c3ccccc3)c3ccc(-c4ccc(-c5ccc6c(-c7ccccc7)c7ccccc7c(-c7ccccc7)c6c5)cc4)nc3c2n1]

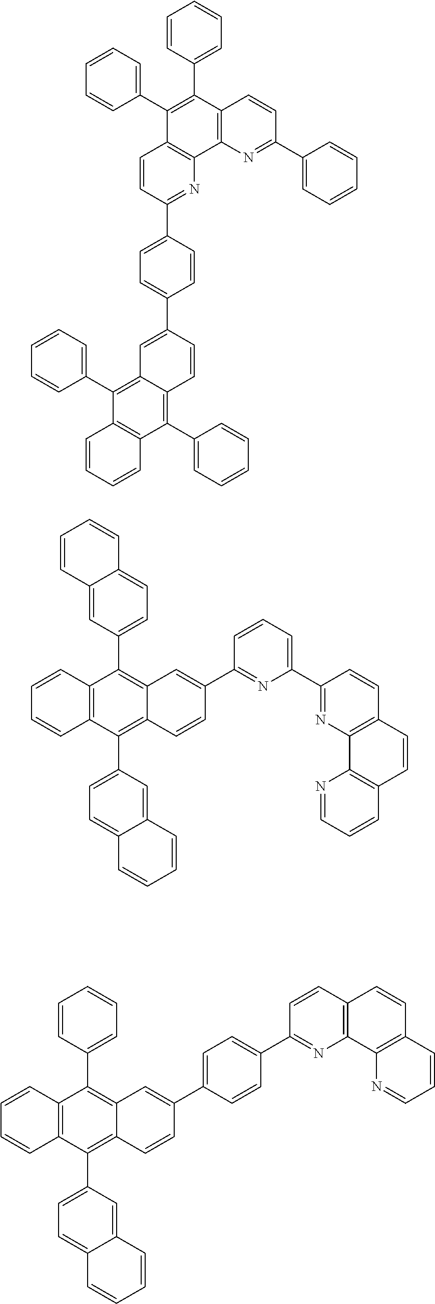

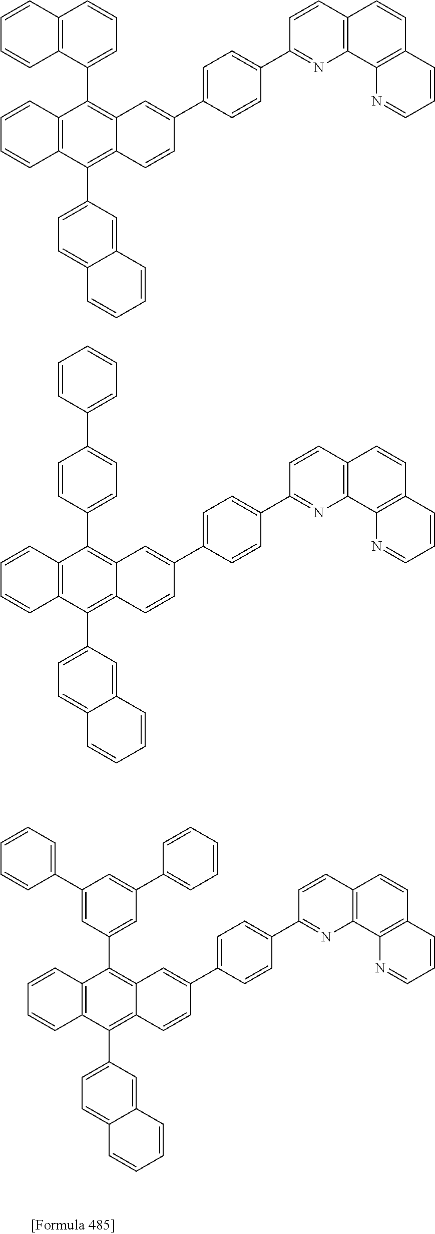

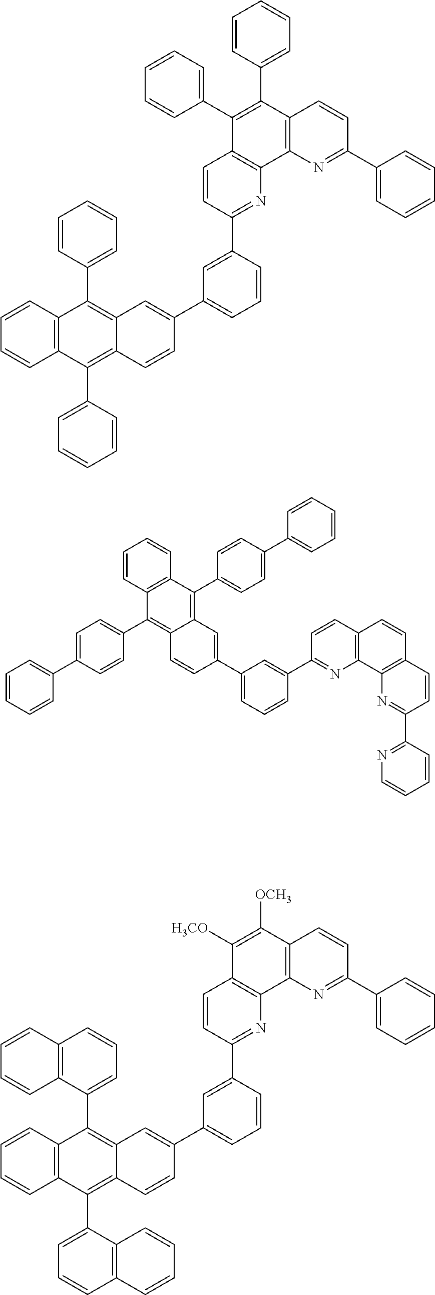 [SMILES: c1ccc(-c2ccc3c(-c4ccccc4)c(-c4ccccc4)c4ccc(-c5cccc(-c6ccc7c(-c8ccccc8)c8ccccc8c(-c8ccccc8)c7c6)c5)nc4c3n2)cc1 ; c1ccc(-c2ccc(-c3c4ccccc4c(-c4ccc(-c5ccccc5)cc4)c4cc(-c5cccc(-c6ccc7ccc8ccc(-c9ccccn9)nc8c7n6)c5)ccc34)cc2)cc1 ; COc1c(OC)c2ccc(-c3cccc(-c4ccc5c(-c6cccc7ccccc67)c6ccccc6c(-c6cccc7ccccc67)c5c4)c3)nc2c2nc(-c3ccccc3)ccc12]

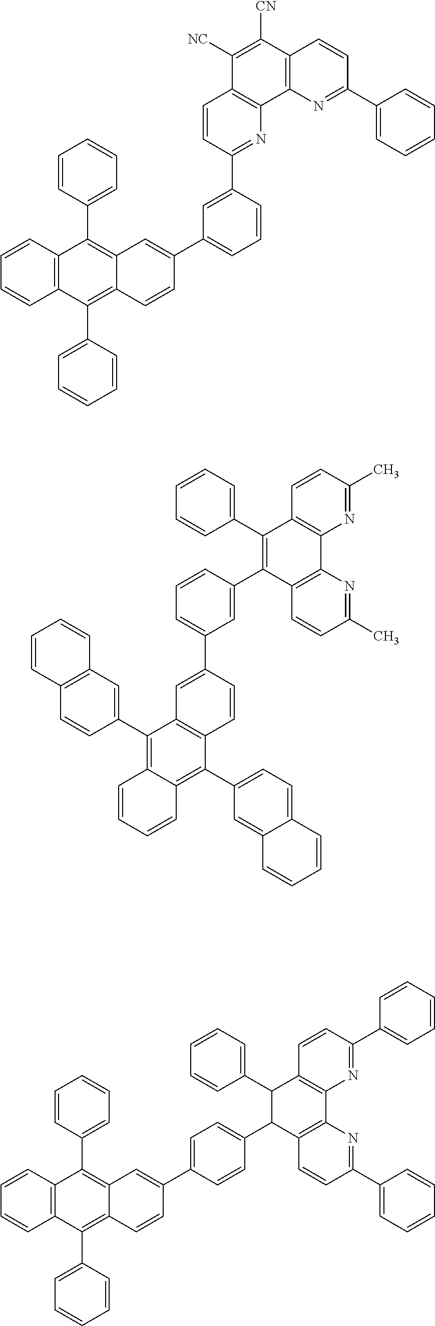 [SMILES: N#Cc1c(C#N)c2ccc(-c3cccc(-c4ccc5c(-c6ccccc6)c6ccccc6c(-c6ccccc6)c5c4)c3)nc2c2nc(-c3ccccc3)ccc12 ; Cc1ccc2c(-c3ccccc3)c(-c3cccc(-c4ccc5c(-c6ccc7ccccc7c6)c6ccccc6c(-c6ccc7ccccc7c6)c5c4)c3)c3ccc(C)nc3c2n1 ; c1ccc(-c2ccc3c(n2)-c2nc(-c4ccccc4)ccc2C(c2ccc(-c4ccc5c(-c6ccccc6)c6ccccc6c(-c6ccccc6)c5c4)cc2)C3c2ccccc2)cc1]

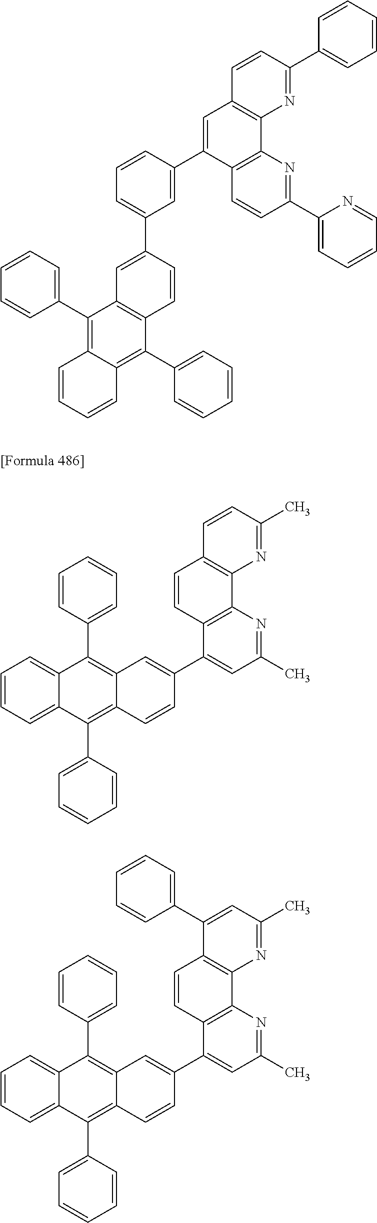 [SMILES: c1ccc(-c2ccc3cc(-c4cccc(-c5ccc6c(-c7ccccc7)c7ccccc7c(-c7ccccc7)c6c5)c4)c4ccc(-c5ccccn5)nc4c3n2)cc1 ; Cc1ccc2ccc3c(-c4ccc5c(-c6ccccc6)c6ccccc6c(-c6ccccc6)c5c4)cc(C)nc3c2n1 ; Cc1cc(-c2ccccc2)c2ccc3c(-c4ccc5c(-c6ccccc6)c6ccccc6c(-c6ccccc6)c5c4)cc(C)nc3c2n1]

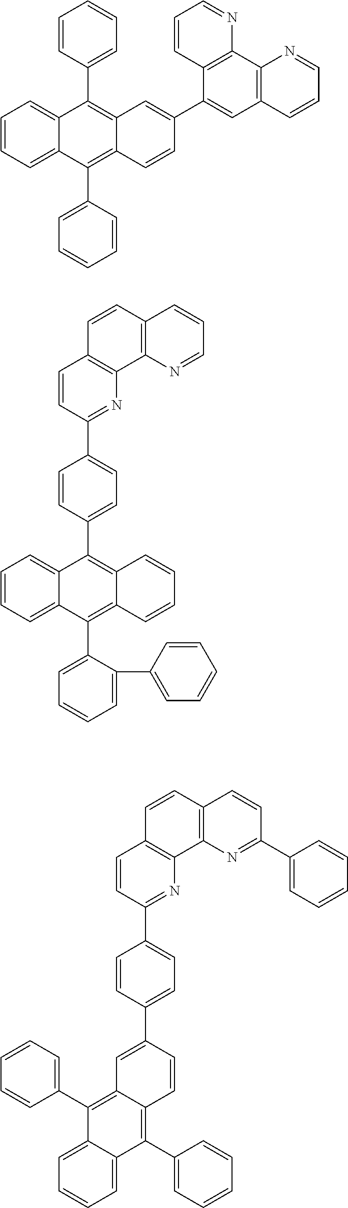 [SMILES: c1ccc(-c2c3ccccc3c(-c3ccccc3)c3cc(-c4cc5cccnc5c5ncccc45)ccc23)cc1 ; c1ccc(-c2ccccc2-c2c3ccccc3c(-c3ccc(-c4ccc5ccc6cccnc6c5n4)cc3)c3ccccc23)cc1 ; c1ccc(-c2ccc3ccc4ccc(-c5ccc(-c6ccc7c(-c8ccccc8)c8ccccc8c(-c8ccccc8)c7c6)cc5)nc4c3n2)cc1]

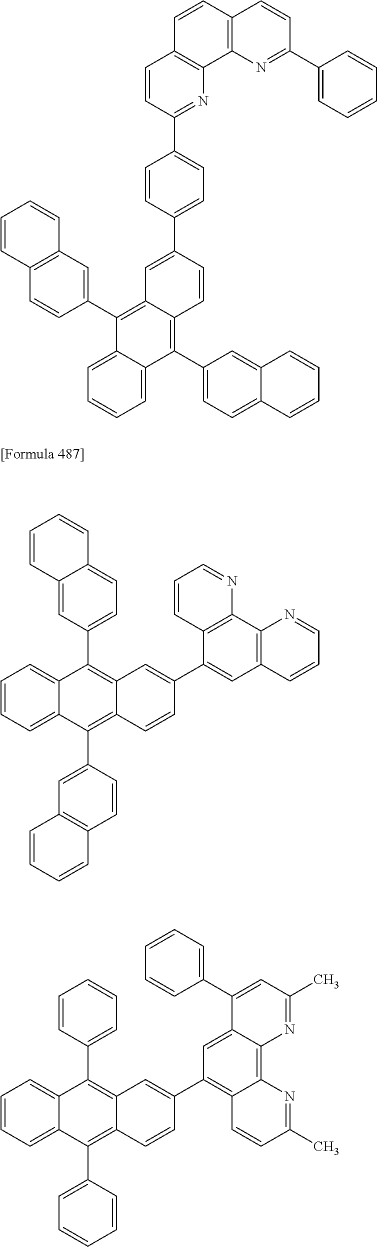 [SMILES: c1ccc(-c2ccc3ccc4ccc(-c5ccc(-c6ccc7c(-c8ccc9ccccc9c8)c8ccccc8c(-c8ccc9ccccc9c8)c7c6)cc5)nc4c3n2)cc1 ; c1ccc2cc(-c3c4ccccc4c(-c4ccc5ccccc5c4)c4cc(-c5cc6cccnc6c6ncccc56)ccc34)ccc2c1 ; Cc1ccc2c(-c3ccc4c(-c5ccccc5)c5ccccc5c(-c5ccccc5)c4c3)cc3c(-c4ccccc4)cc(C)nc3c2n1]

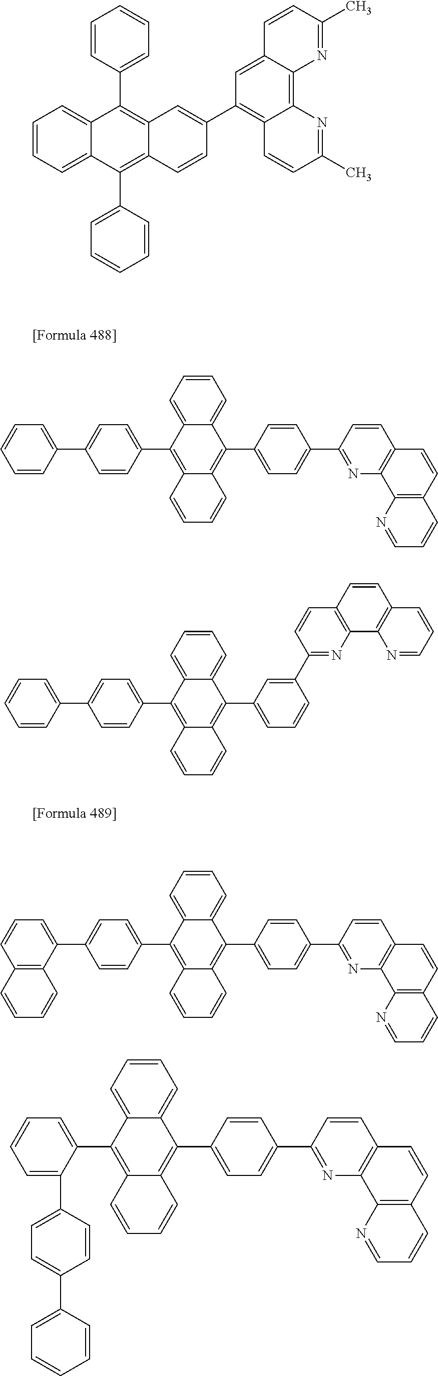 [SMILES: Cc1ccc2cc(-c3ccc4c(-c5ccccc5)c5ccccc5c(-c5ccccc5)c4c3)c3ccc(C)nc3c2n1 ; c1ccc(-c2ccc(-c3c4ccccc4c(-c4ccc(-c5ccc6ccc7cccnc7c6n5)cc4)c4ccccc34)cc2)cc1 ; c1ccc(-c2ccc(-c3c4ccccc4c(-c4cccc(-c5ccc6ccc7cccnc7c6n5)c4)c4ccccc34)cc2)cc1 ; c1ccc2c(-c3ccc(-c4c5ccccc5c(-c5ccc(-c6ccc7ccc8cccnc8c7n6)cc5)c5ccccc45)cc3)cccc2c1 ; c1ccc(-c2ccc(-c3ccccc3-c3c4ccccc4c(-c4ccc(-c5ccc6ccc7cccnc7c6n5)cc4)c4ccccc34)cc2)cc1]

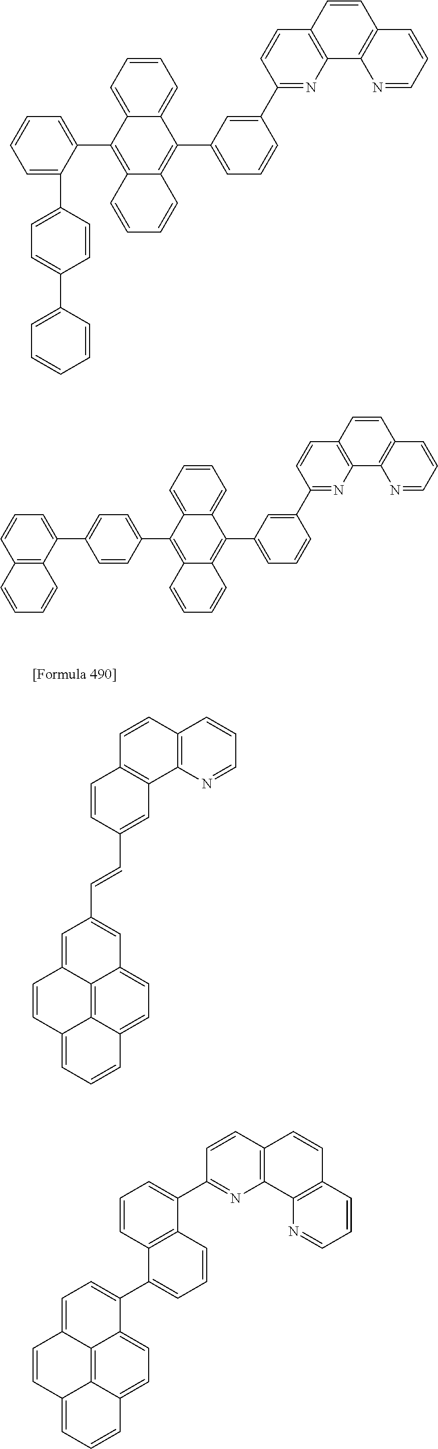 [SMILES: c1ccc(-c2ccc(-c3ccccc3-c3c4ccccc4c(-c4cccc(-c5ccc6ccc7cccnc7c6n5)c4)c4ccccc34)cc2)cc1 ; c1cc(-c2ccc3ccc4cccnc4c3n2)cc(-c2c3ccccc3c(-c3ccc(-c4cccc5ccccc45)cc3)c3ccccc23)c1 ; C(=C\c1ccc2ccc3cccnc3c2c1)/c1cc2ccc3cccc4ccc(c1)c2c34 ; c1cnc2c(c1)ccc1ccc(-c3cccc4c(-c5ccc6ccc7cccc8ccc5c6c78)cccc34)nc12]

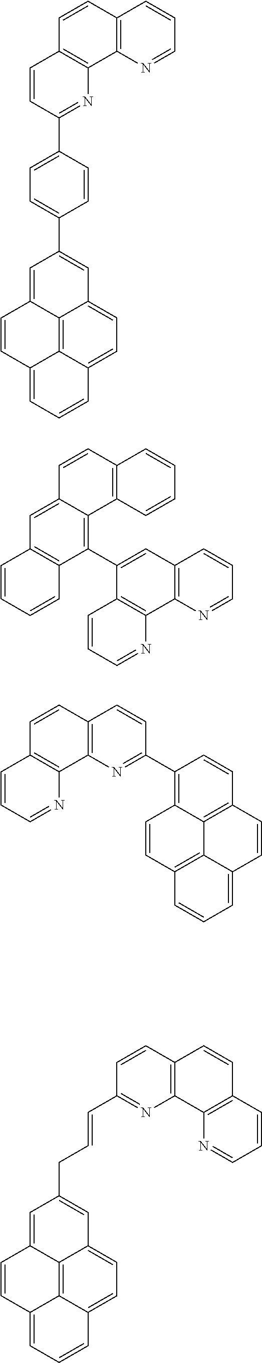

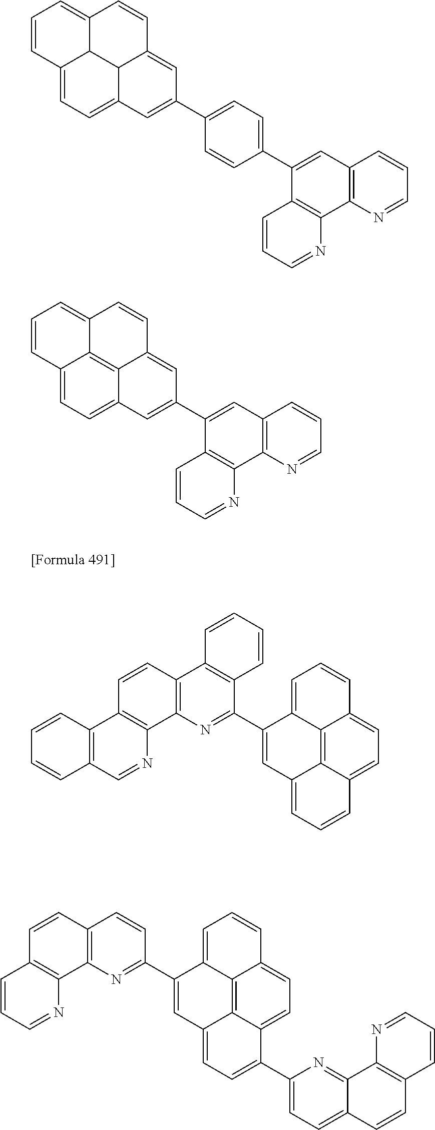 [SMILES: C1=CC2=CC=C3C=C(c4ccc(-c5cc6cccnc6c6ncccc56)cc4)C=C4C=CC(=C1)C2C34 ; c1cnc2c(c1)cc(-c1cc3ccc4cccc5ccc(c1)c3c45)c1cccnc12 ; c1ccc2c(c1)cnc1c2ccc2c3ccccc3c(-c3cc4cccc5ccc6cccc3c6c54)nc21 ; c1cnc2c(c1)ccc1ccc(-c3cc4ccc(-c5ccc6ccc7cccnc7c6n5)c5ccc6cccc3c6c45)nc12]

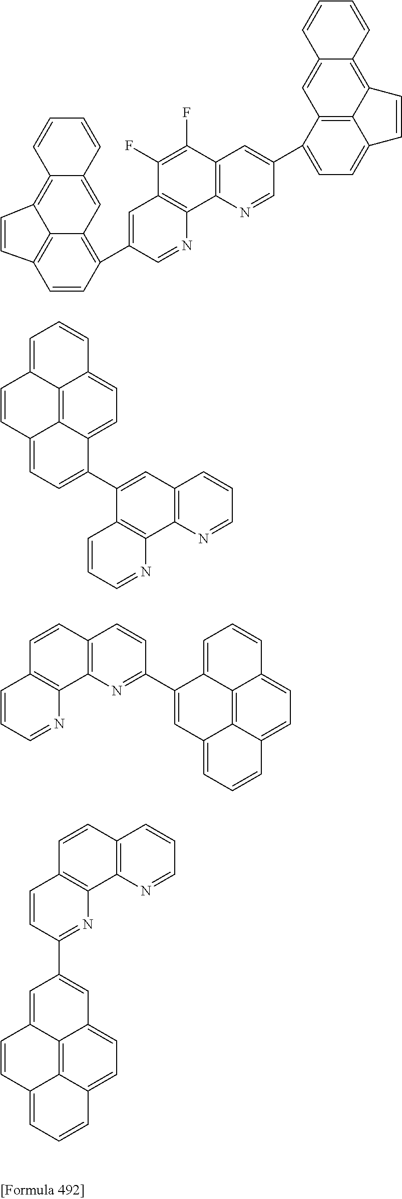

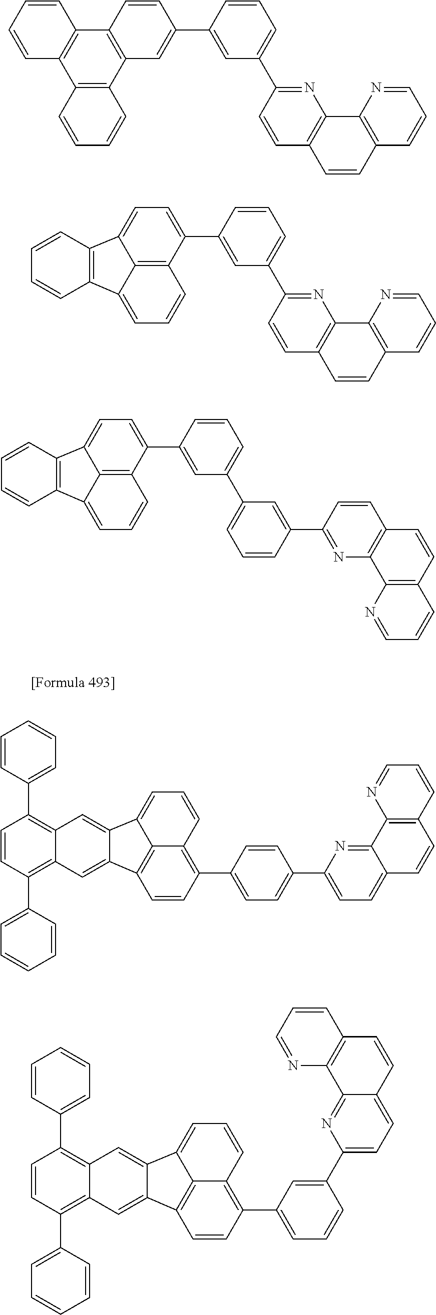 [SMILES: c1cc(-c2ccc3c4ccccc4c4ccccc4c3c2)cc(-c2ccc3ccc4cccnc4c3n2)c1 ; c1cc(-c2ccc3ccc4cccnc4c3n2)cc(-c2ccc3c4c(cccc24)-c2ccccc2-3)c1 ; c1cc(-c2cccc(-c3ccc4c5c(cccc35)-c3ccccc3-4)c2)cc(-c2ccc3ccc4cccnc4c3n2)c1 ; c1ccc(-c2ccc(-c3ccccc3)c3cc4c(cc23)-c2cccc3c(-c5ccc(-c6ccc7ccc8cccnc8c7n6)cc5)ccc-4c23)cc1 ; c1ccc(-c2ccc(-c3ccccc3)c3cc4c(cc23)-c2cccc3c(-c5cccc(-c6ccc7ccc8cccnc8c7n6)c5)ccc-4c23)cc1]

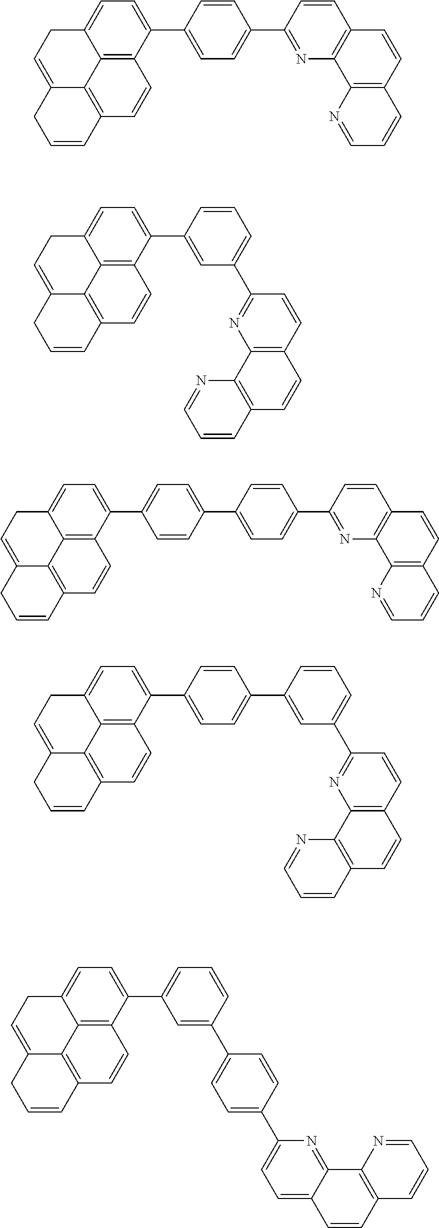 [SMILES: C1=Cc2ccc3c(-c4ccc(-c5ccc6ccc7cccnc7c6n5)cc4)ccc4c3c2C(=CC4)C1 ; C1=Cc2ccc3c(-c4cccc(-c5ccc6ccc7cccnc7c6n5)c4)ccc4c3c2C(=CC4)C1 ; C1=Cc2ccc3c(-c4ccc(-c5ccc(-c6ccc7ccc8cccnc8c7n6)cc5)cc4)ccc4c3c2C(=CC4)C1 ; C1=Cc2ccc3c(-c4ccc(-c5cccc(-c6ccc7ccc8cccnc8c7n6)c5)cc4)ccc4c3c2C(=CC4)C1 ; C1=Cc2ccc3c(-c4cccc(-c5ccc(-c6ccc7ccc8cccnc8c7n6)cc5)c4)ccc4c3c2C(=CC4)C1]

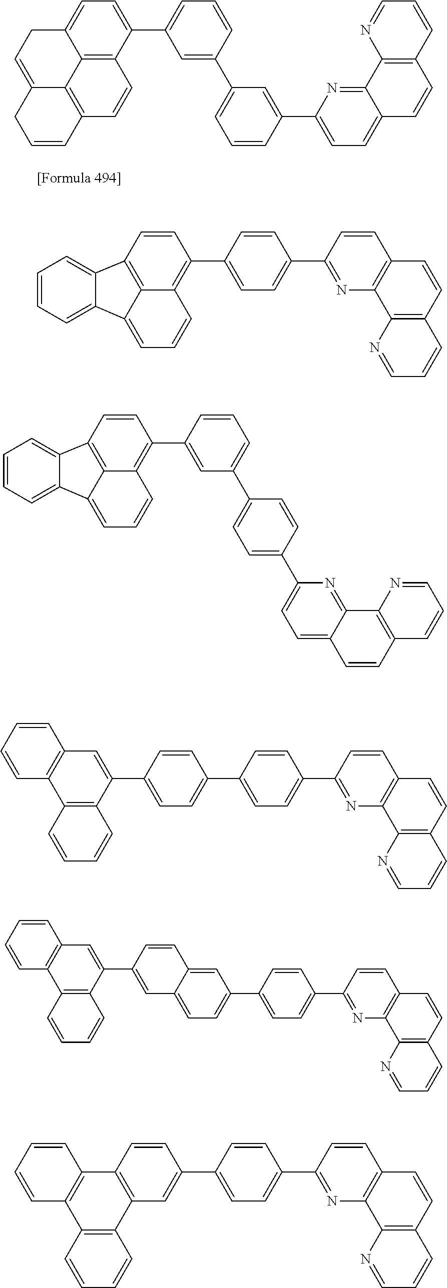 [SMILES: C1=Cc2ccc3c(-c4cccc(-c5cccc(-c6ccc7ccc8cccnc8c7n6)c5)c4)ccc4c3c2C(=CC4)C1 ; c1ccc2c(c1)-c1cccc3c(-c4ccc(-c5ccc6ccc7cccnc7c6n5)cc4)ccc-2c13 ; c1cc(-c2ccc(-c3ccc4ccc5cccnc5c4n3)cc2)cc(-c2ccc3c4c(cccc24)-c2ccccc2-3)c1 ; c1ccc2c(c1)cc(-c1ccc(-c3ccc(-c4ccc5ccc6cccnc6c5n4)cc3)cc1)c1ccccc12 ; c1ccc2c(c1)cc(-c1ccc3cc(-c4ccc(-c5ccc6ccc7cccnc7c6n5)cc4)ccc3c1)c1ccccc12 ; c1cnc2c(c1)ccc1ccc(-c3ccc(-c4ccc5c6ccccc6c6ccccc6c5c4)cc3)nc12]

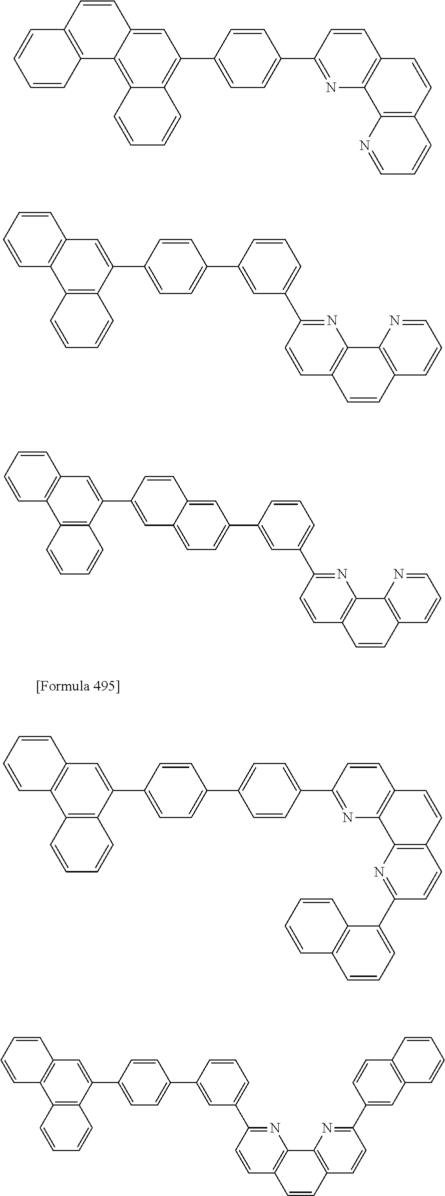 [SMILES: c1ccc2c(c1)ccc1cc(-c3ccc(-c4ccc5ccc6cccnc6c5n4)cc3)c3ccccc3c12 ; c1cc(-c2ccc(-c3cc4ccccc4c4ccccc34)cc2)cc(-c2ccc3ccc4cccnc4c3n2)c1 ; c1cc(-c2ccc3cc(-c4cc5ccccc5c5ccccc45)ccc3c2)cc(-c2ccc3ccc4cccnc4c3n2)c1 ; c1ccc2c(-c3ccc4ccc5ccc(-c6ccc(-c7ccc(-c8cc9ccccc9c9ccccc89)cc7)cc6)nc5c4n3)cccc2c1 ; c1cc(-c2ccc(-c3cc4ccccc4c4ccccc34)cc2)cc(-c2ccc3ccc4ccc(-c5ccc6ccccc6c5)nc4c3n2)c1]

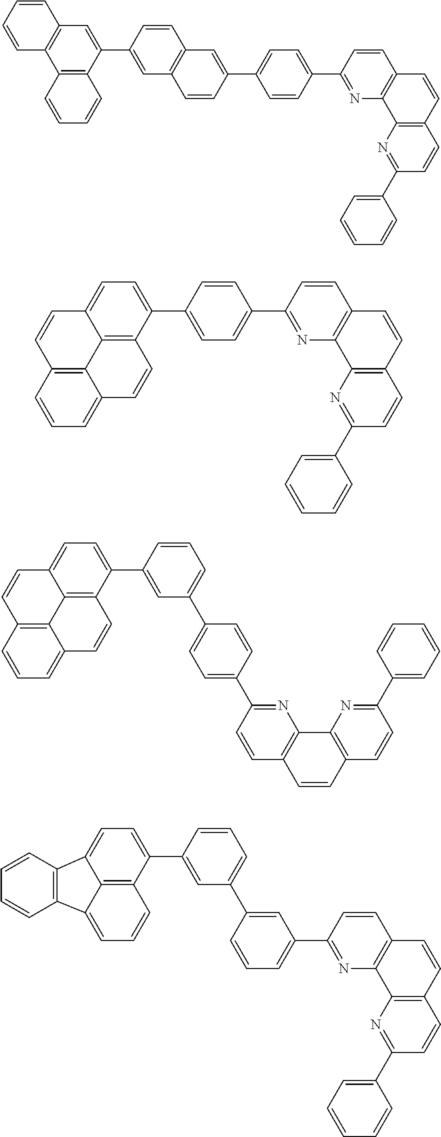

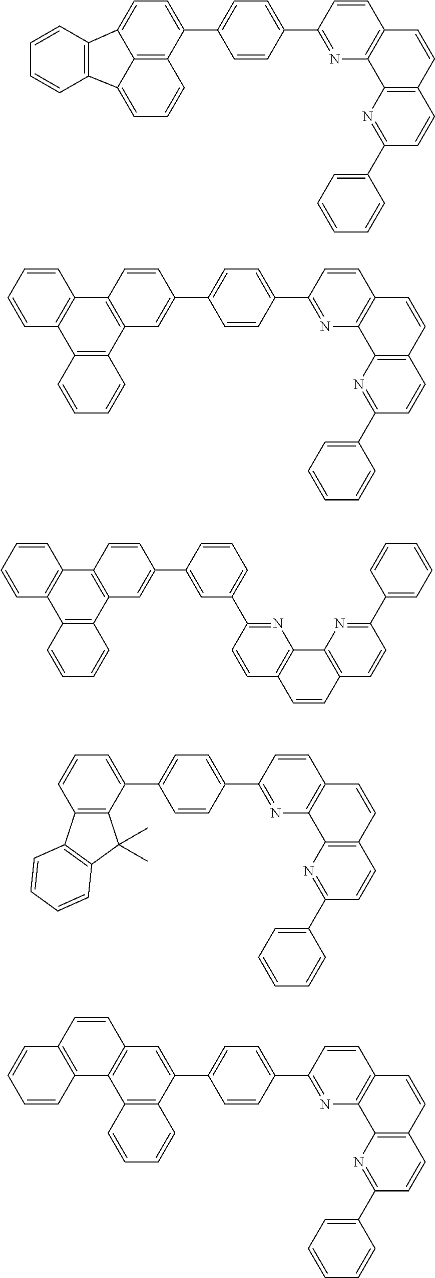

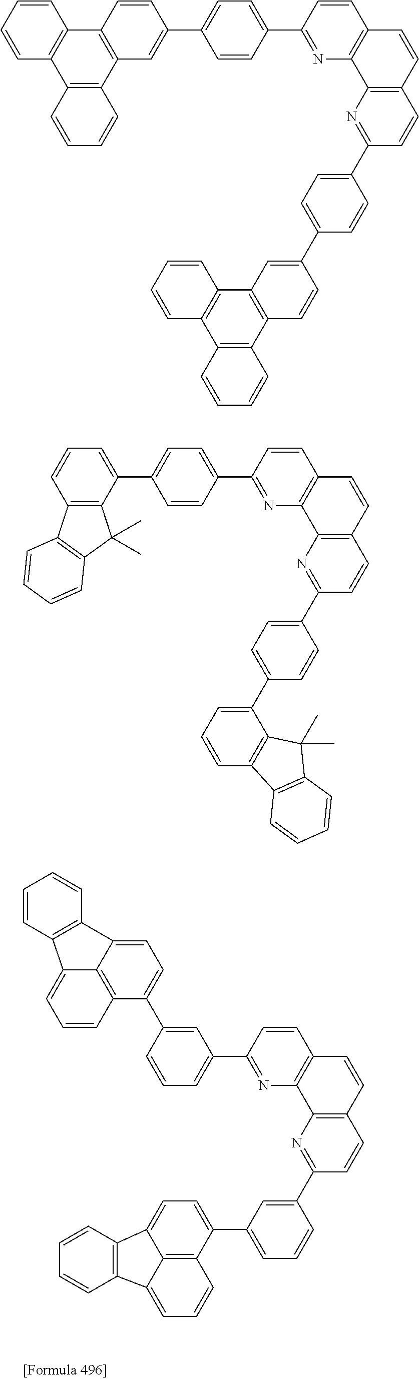

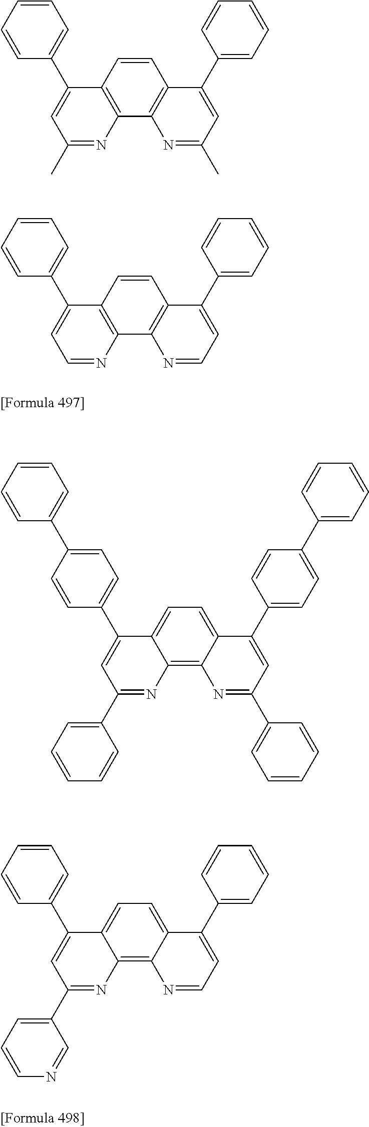

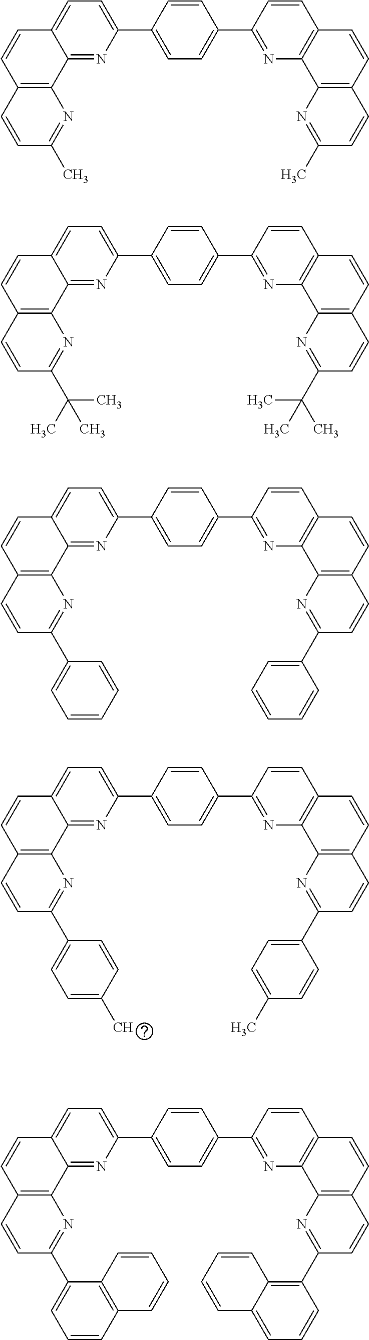 [SMILES: Cc1ccc2ccc3ccc(-c4ccc(-c5ccc6ccc7ccc(C)nc7c6n5)cc4)nc3c2n1 ; CC(C)(C)c1ccc2ccc3ccc(-c4ccc(-c5ccc6ccc7ccc(C(C)(C)C)nc7c6n5)cc4)nc3c2n1 ; c1ccc(-c2ccc3ccc4ccc(-c5ccc(-c6ccc7ccc8ccc(-c9ccccc9)nc8c7n6)cc5)nc4c3n2)cc1 ; Cc1ccc(-c2ccc3ccc4ccc(-c5ccc(-c6ccc7ccc8ccc(-c9ccc(C)cc9)nc8c7n6)cc5)nc4c3n2)cc1 ; c1ccc2c(-c3ccc4ccc5ccc(-c6ccc(-c7ccc8ccc9ccc(-c%10cccc%11ccccc%10%11)nc9c8n7)cc6)nc5c4n3)cccc2c1]

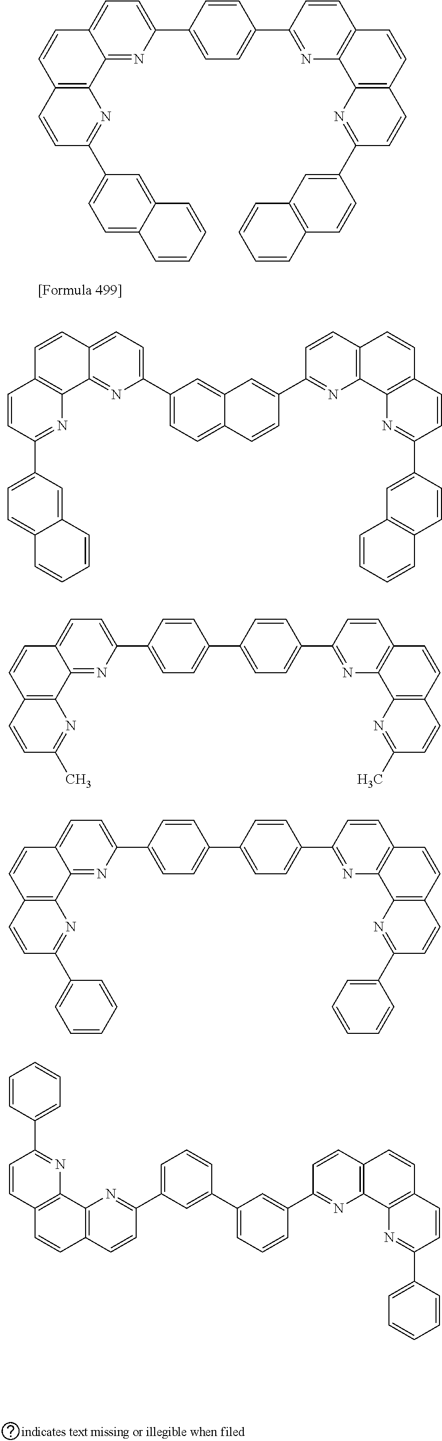

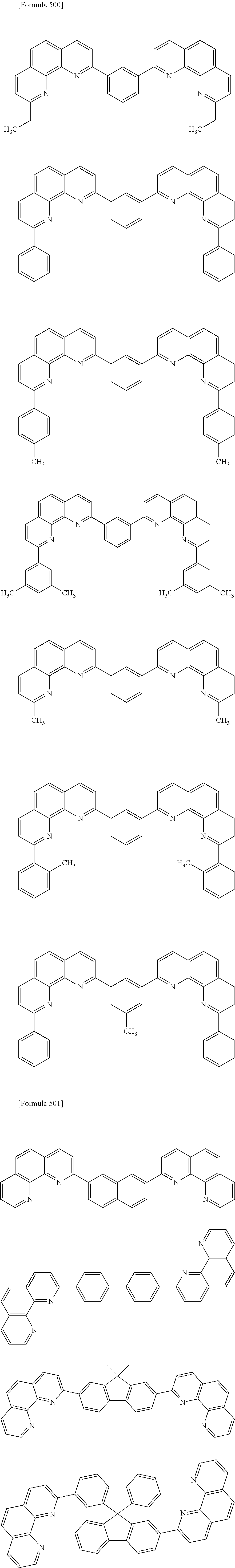

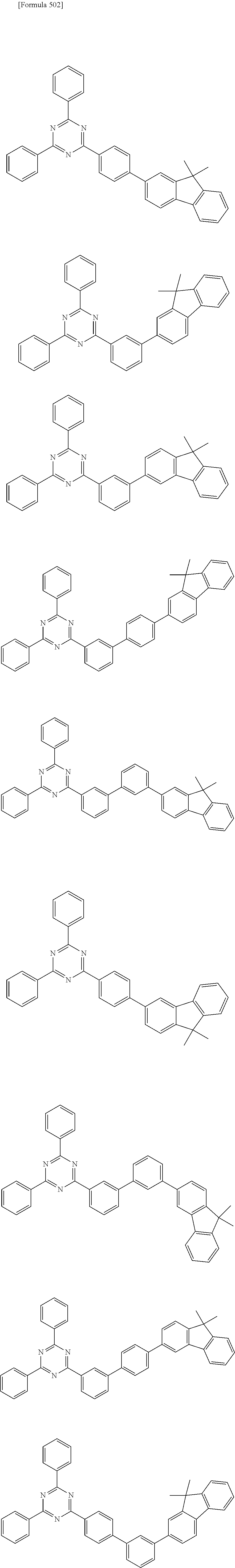

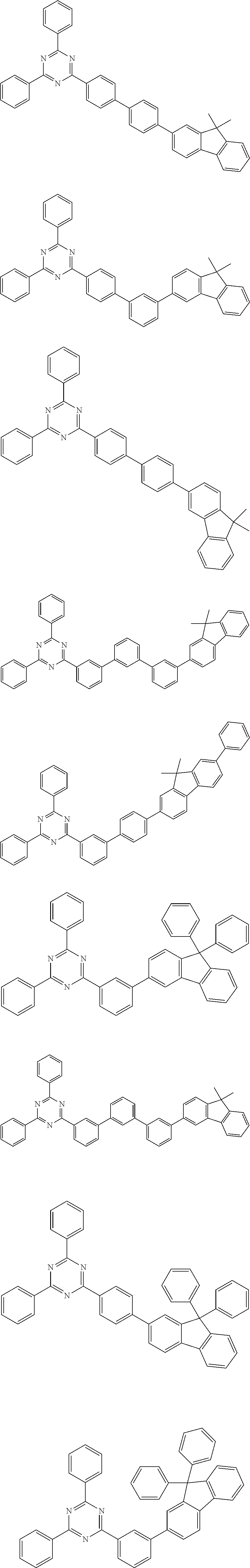

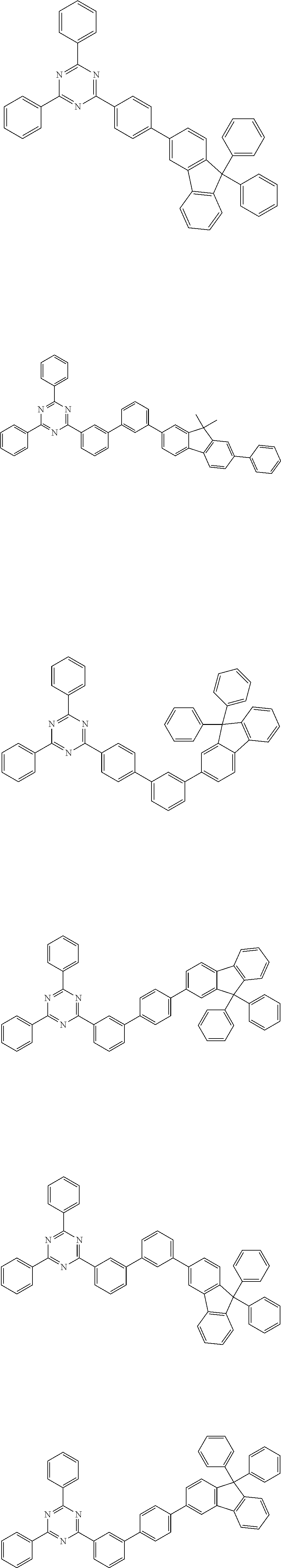

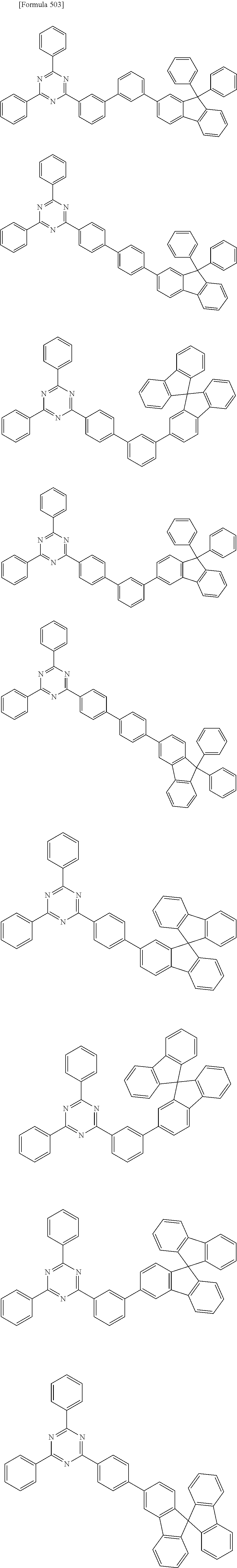

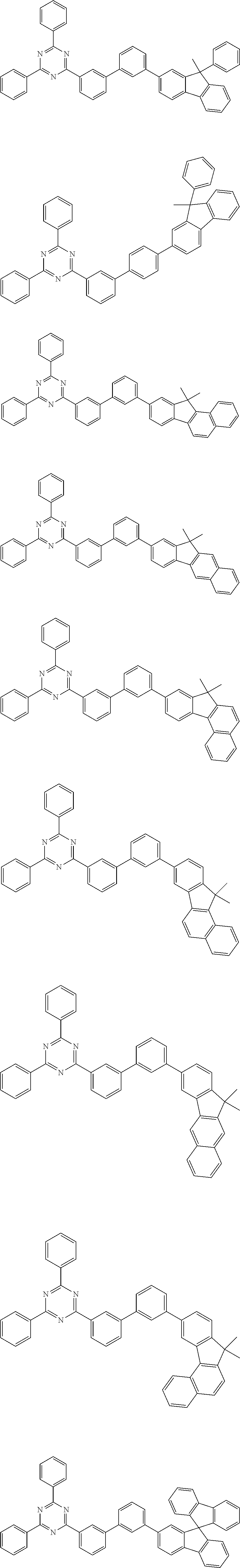

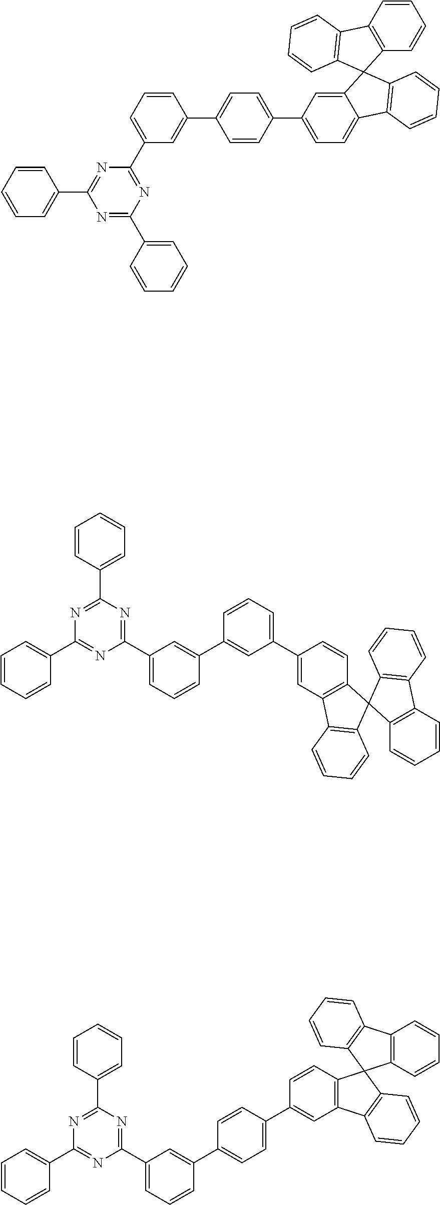 [SMILES: c1ccc(-c2nc(-c3ccccc3)nc(-c3cccc(-c4ccc(-c5ccc6c(c5)C5(c7ccccc7-c7ccccc75)c5ccccc5-6)cc4)c3)n2)cc1 ; c1ccc(-c2nc(-c3ccccc3)nc(-c3cccc(-c4cccc(-c5ccc6c(c5)-c5ccccc5C65c6ccccc6-c6ccccc65)c4)c3)n2)cc1 ; c1ccc(-c2nc(-c3ccccc3)nc(-c3cccc(-c4ccc(-c5ccc6c(c5)-c5ccccc5C65c6ccccc6-c6ccccc65)cc4)c3)n2)cc1]

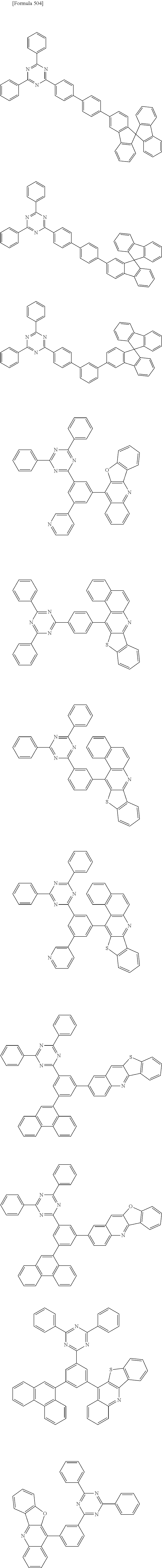

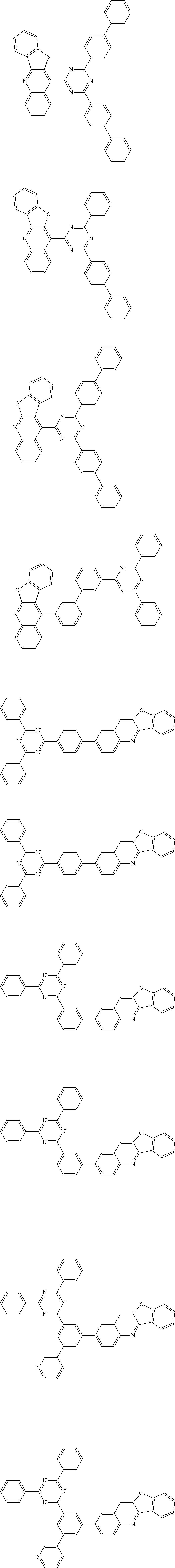

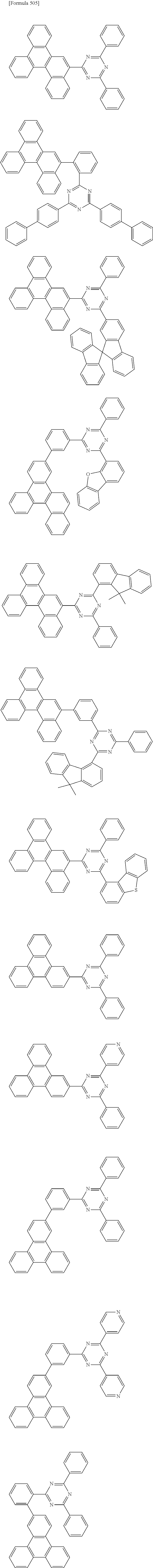

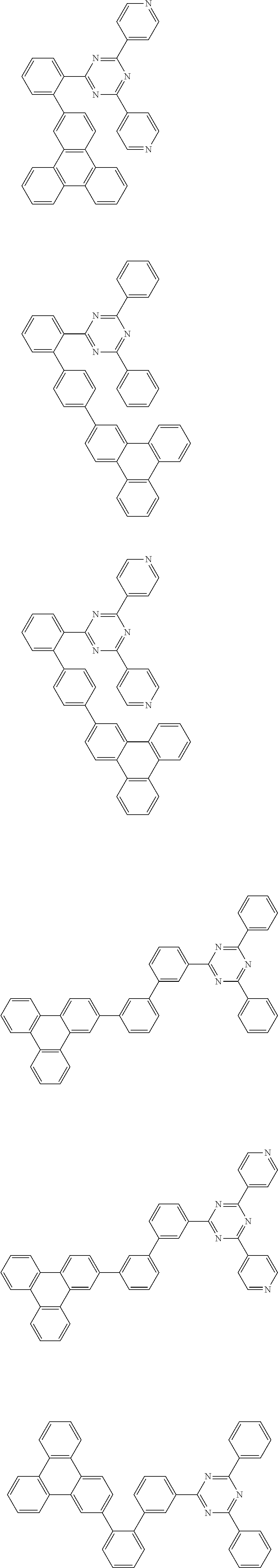 [SMILES: c1ccc(-c2nc(-c3ccncc3)nc(-c3ccncc3)n2)c(-c2ccc3c4ccccc4c4ccccc4c3c2)c1 ; c1ccc(-c2nc(-c3ccccc3)nc(-c3ccccc3-c3ccc(-c4ccc5c6ccccc6c6ccccc6c5c4)cc3)n2)cc1 ; c1ccc(-c2nc(-c3ccncc3)nc(-c3ccncc3)n2)c(-c2ccc(-c3ccc4c5ccccc5c5ccccc5c4c3)cc2)c1 ; c1ccc(-c2nc(-c3ccccc3)nc(-c3cccc(-c4cccc(-c5ccc6c7ccccc7c7ccccc7c6c5)c4)c3)n2)cc1 ; c1cc(-c2cccc(-c3nc(-c4ccncc4)nc(-c4ccncc4)n3)c2)cc(-c2ccc3c4ccccc4c4ccccc4c3c2)c1 ; c1ccc(-c2nc(-c3ccccc3)nc(-c3cccc(-c4ccccc4-c4ccc5c6ccccc6c6ccccc6c5c4)c3)n2)cc1]

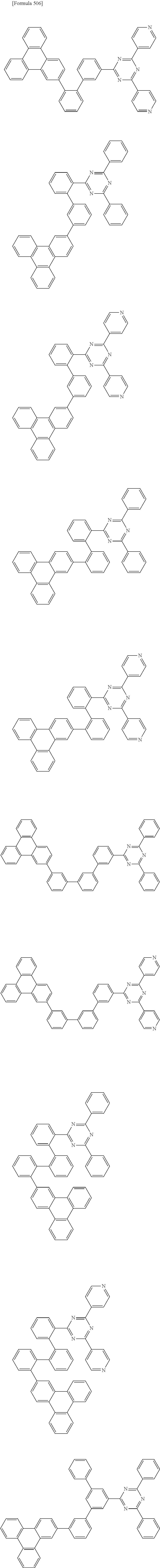

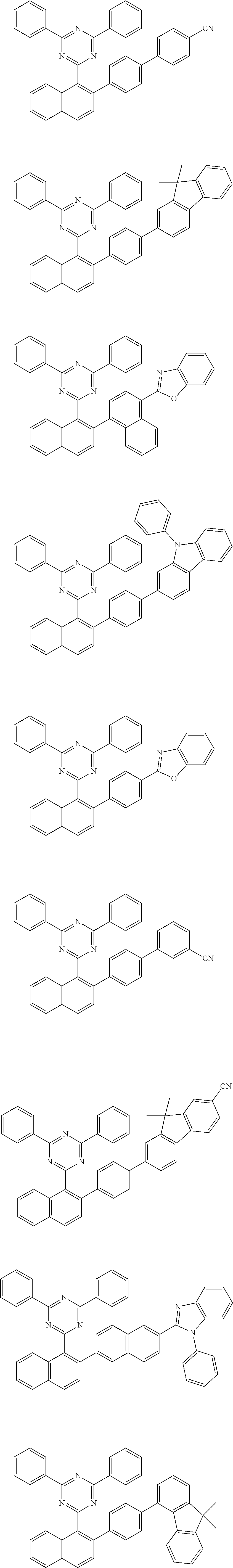

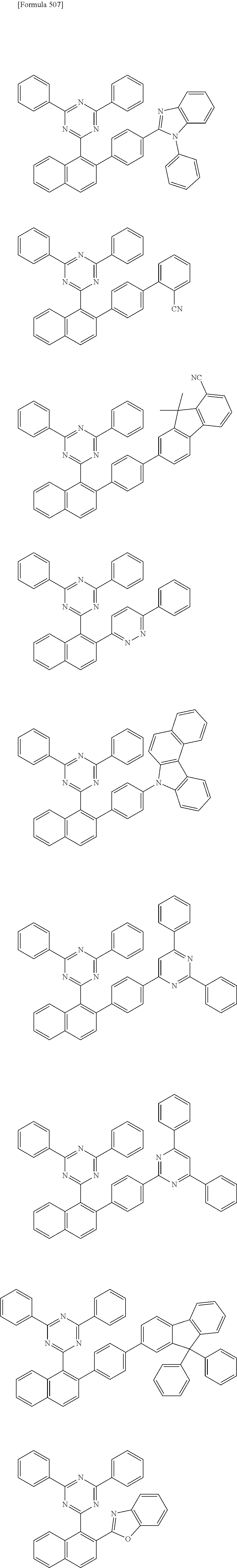

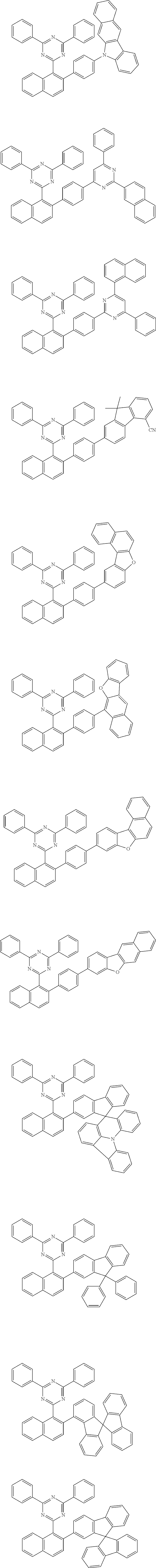

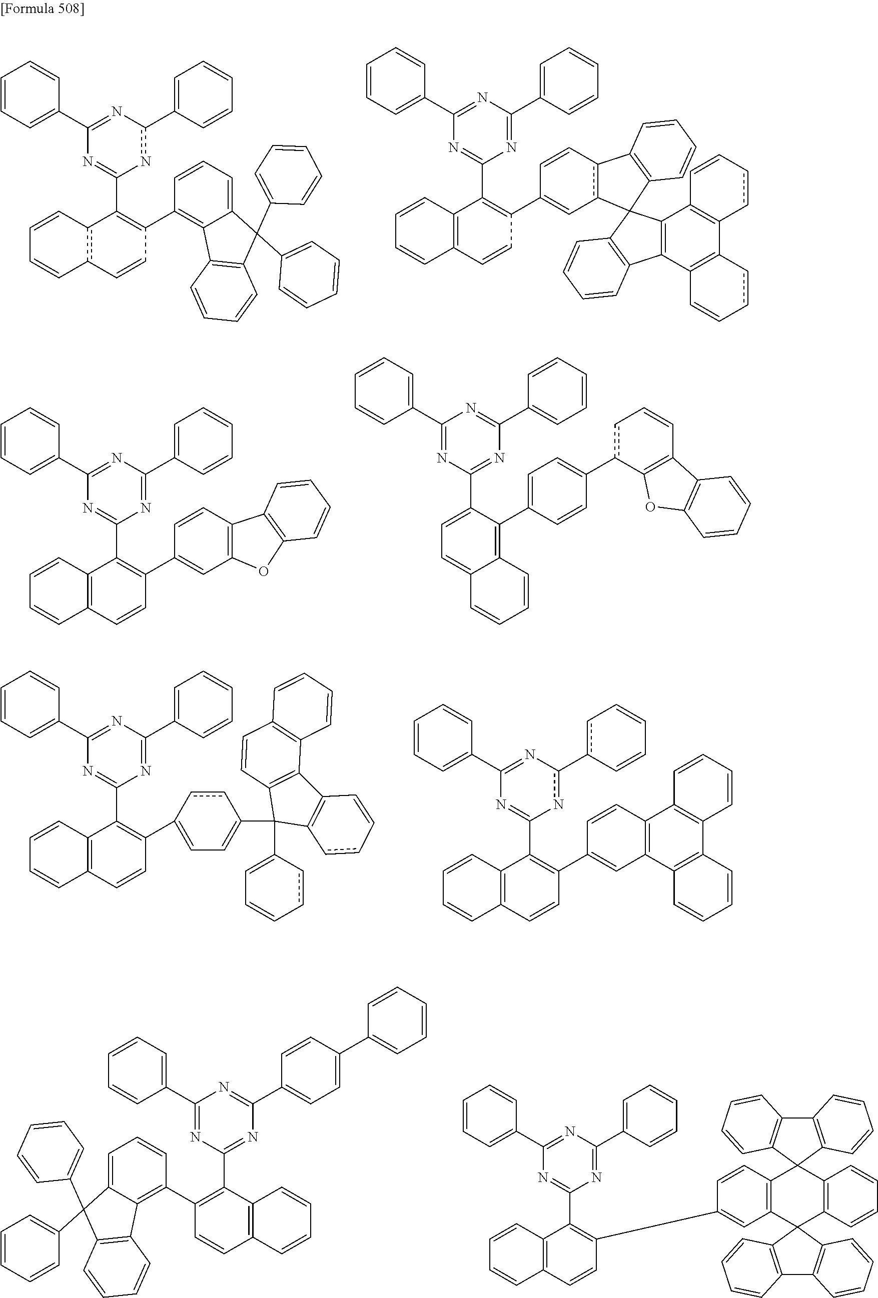

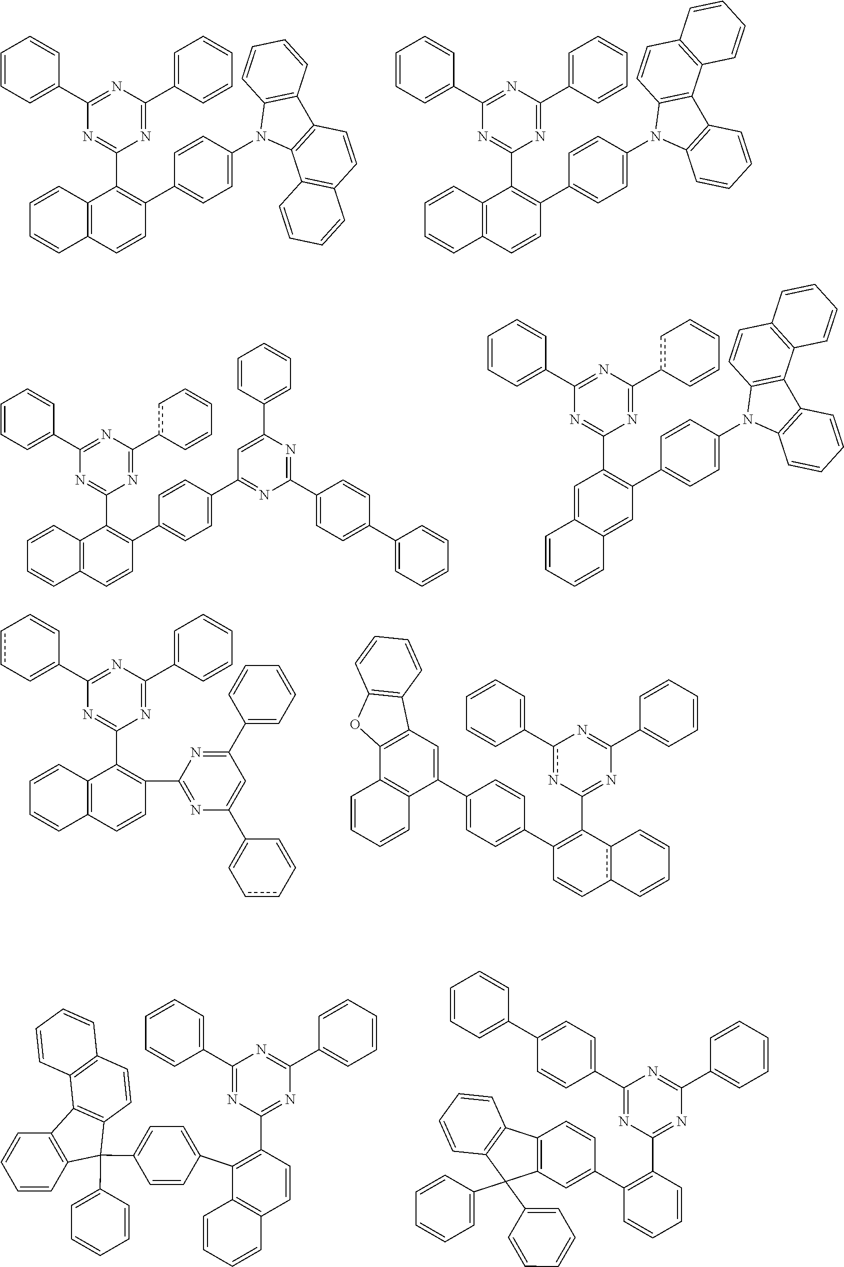

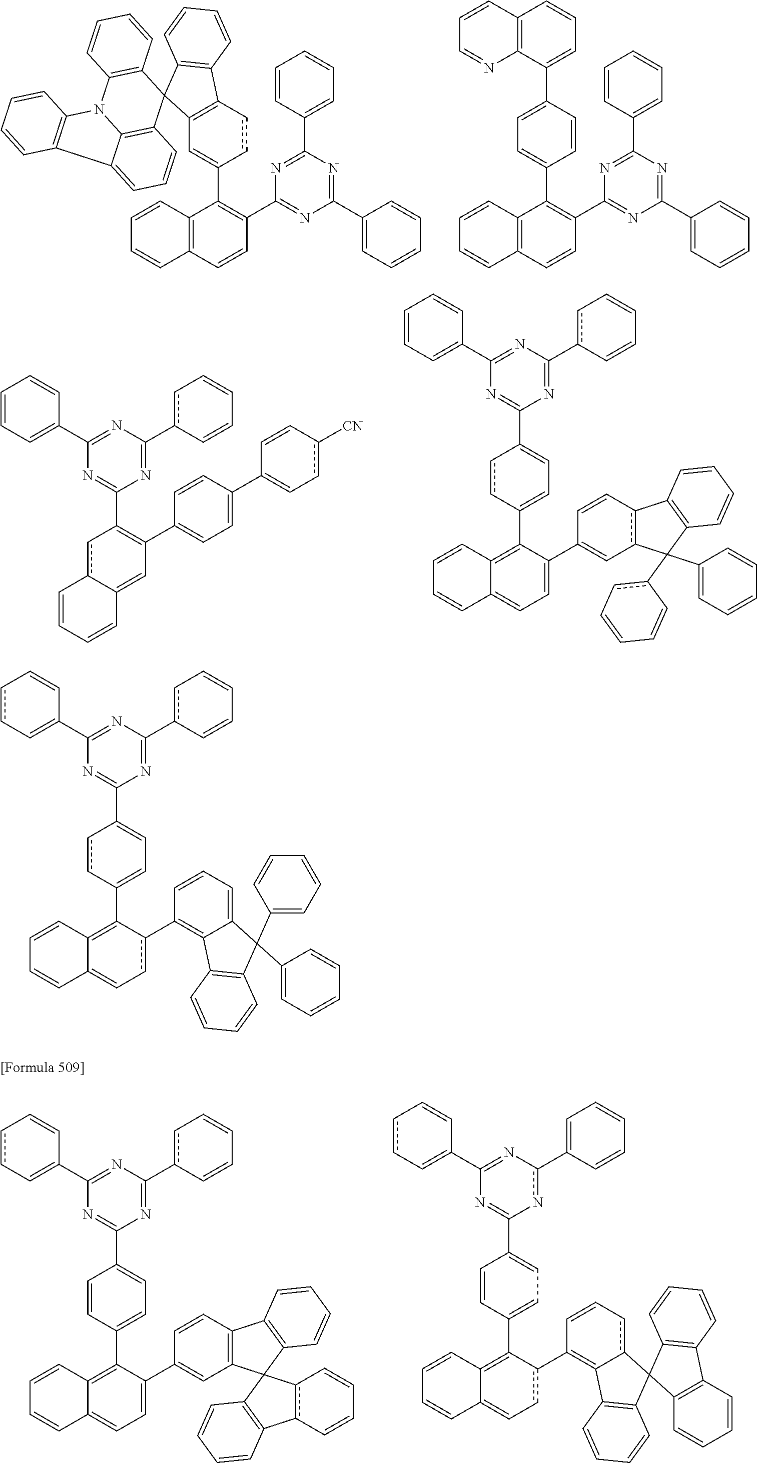

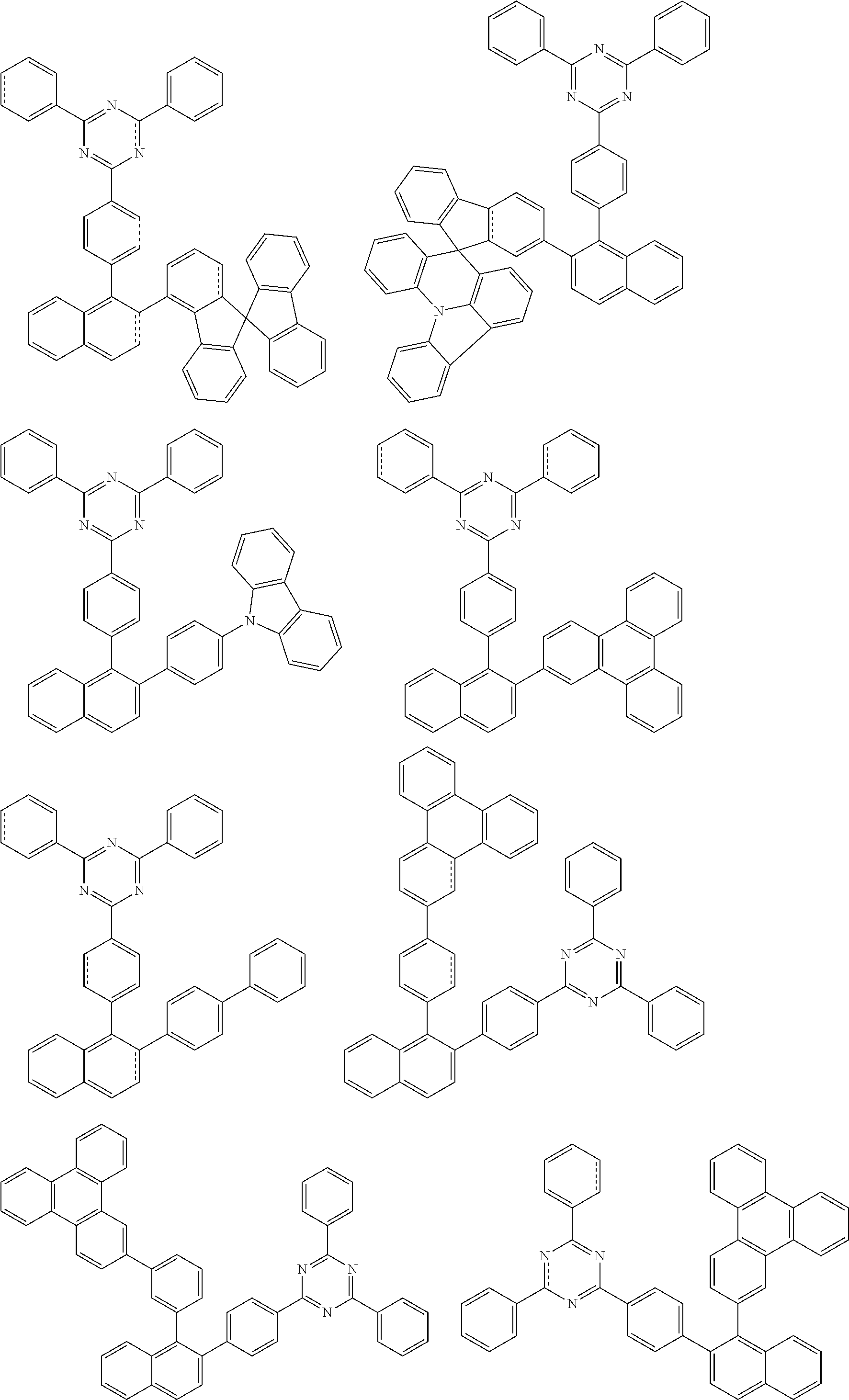

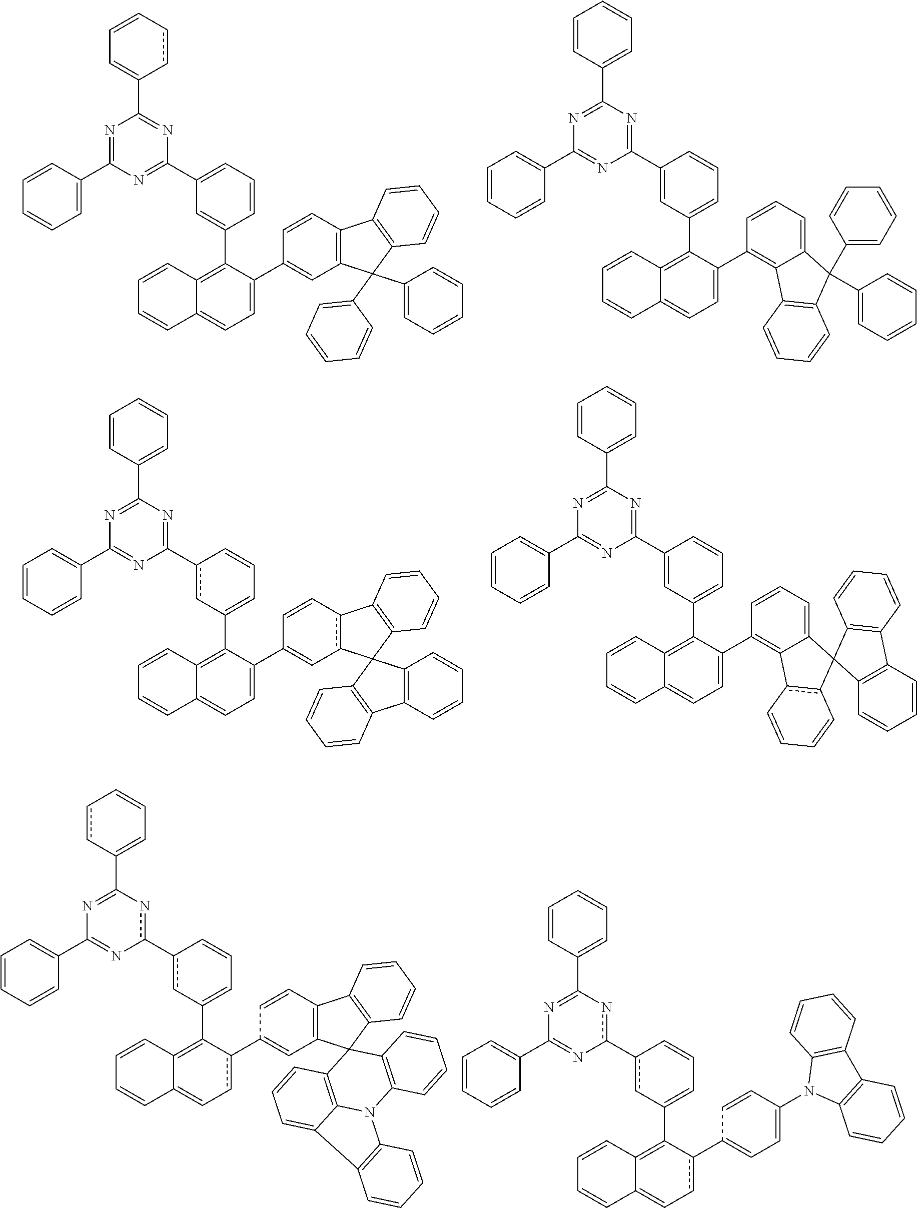

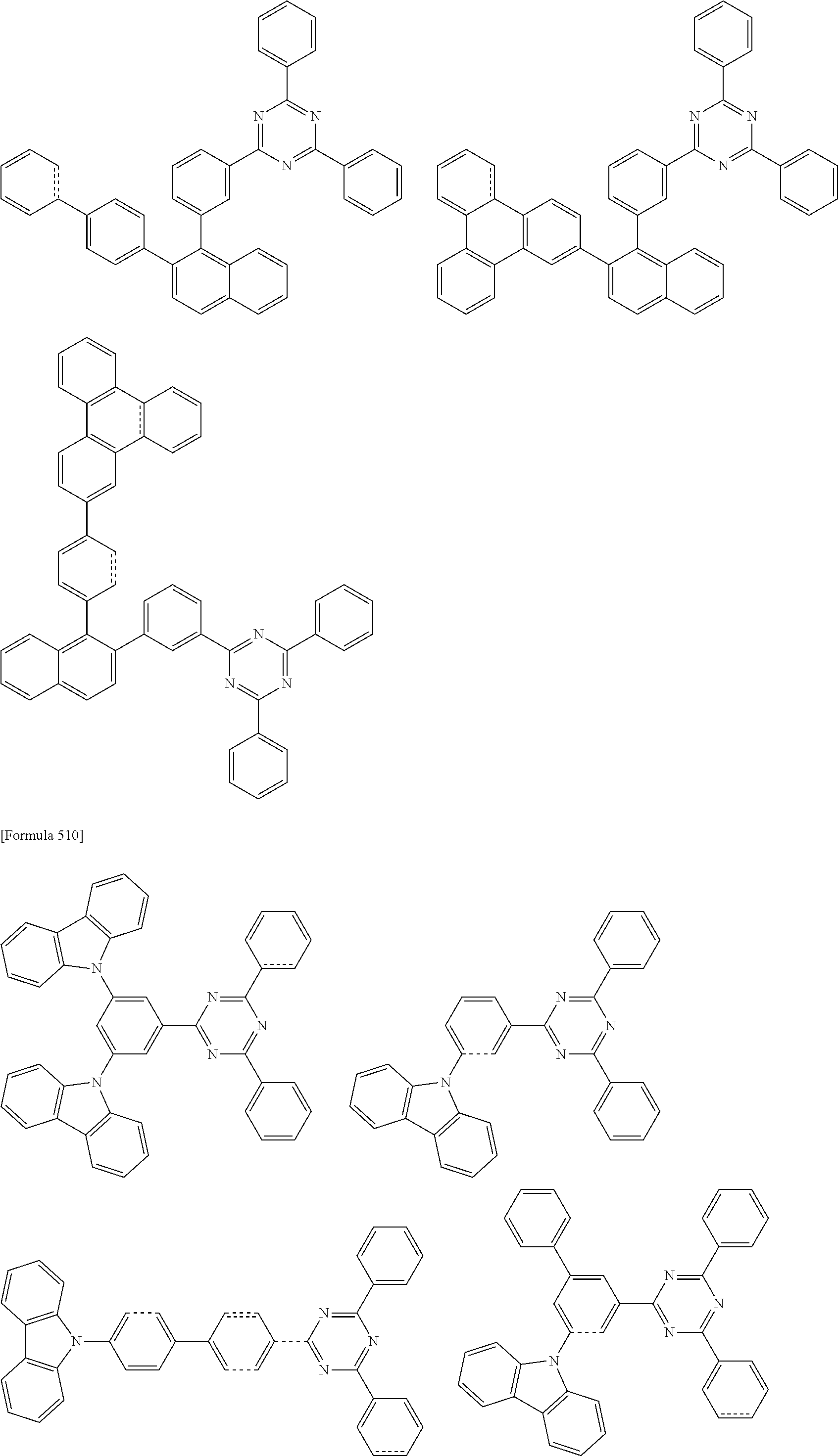

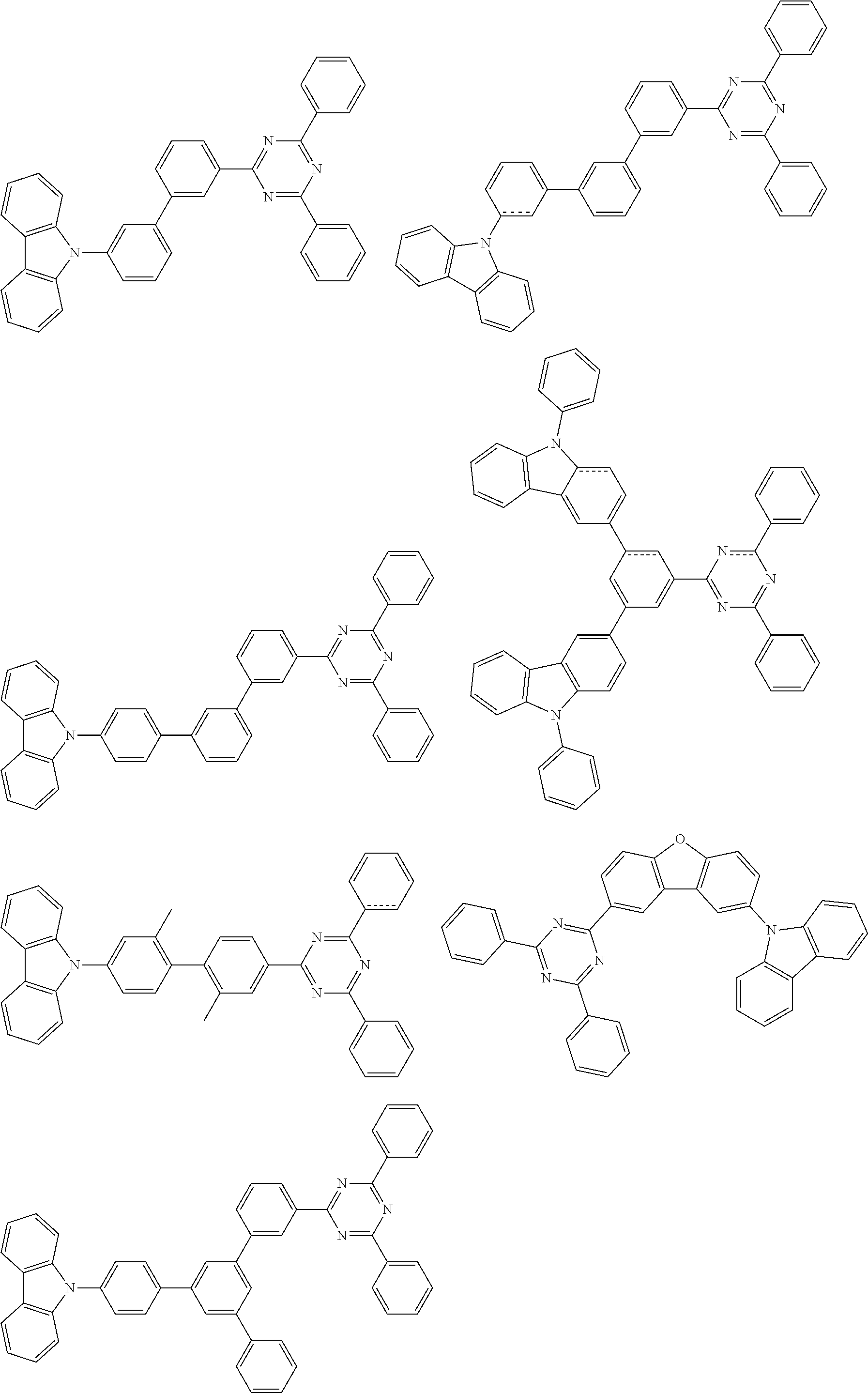

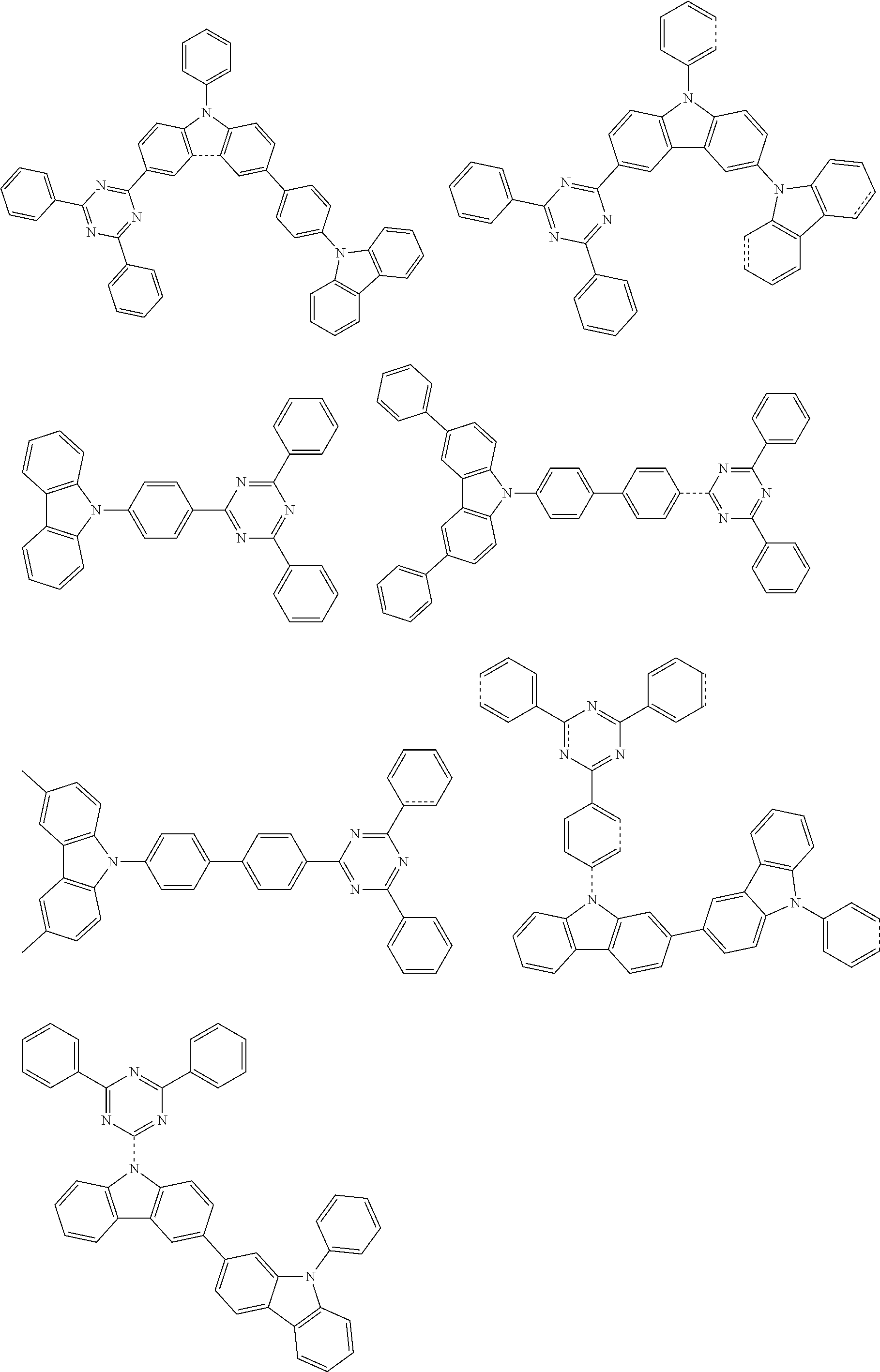

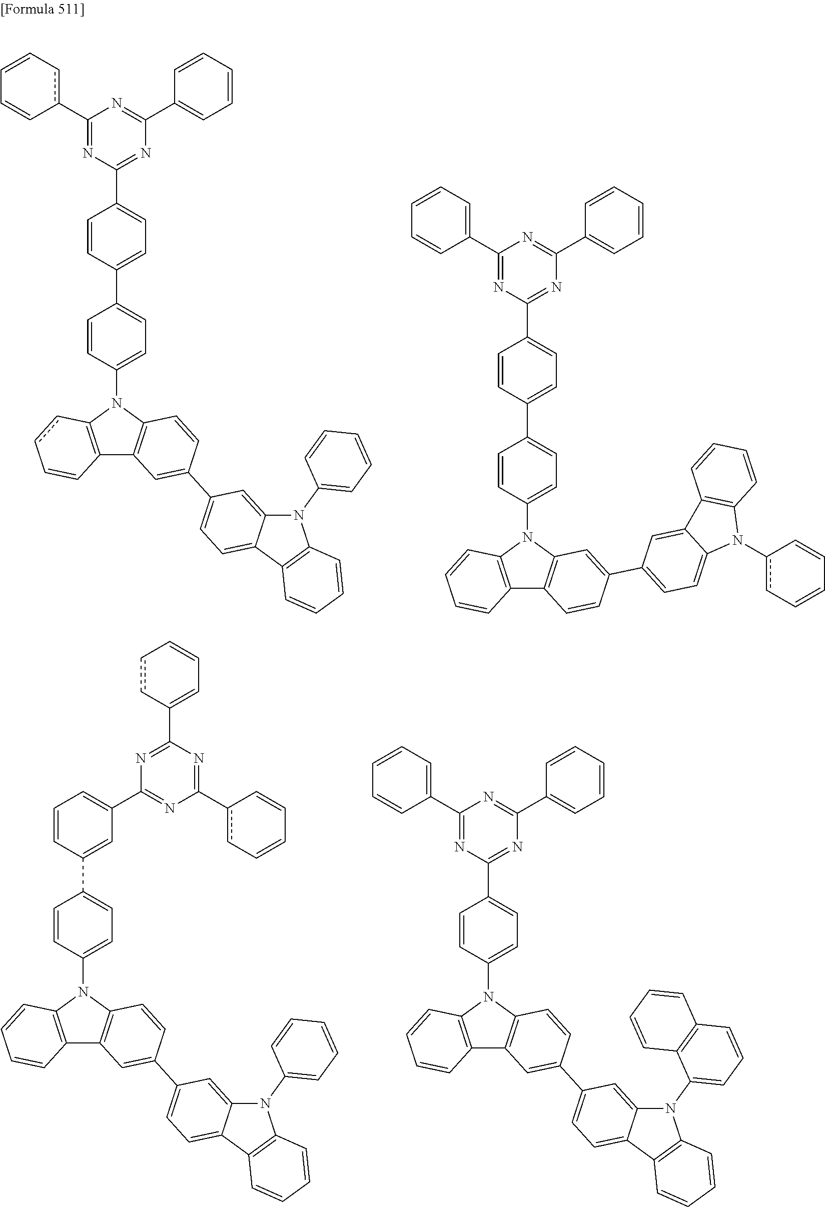

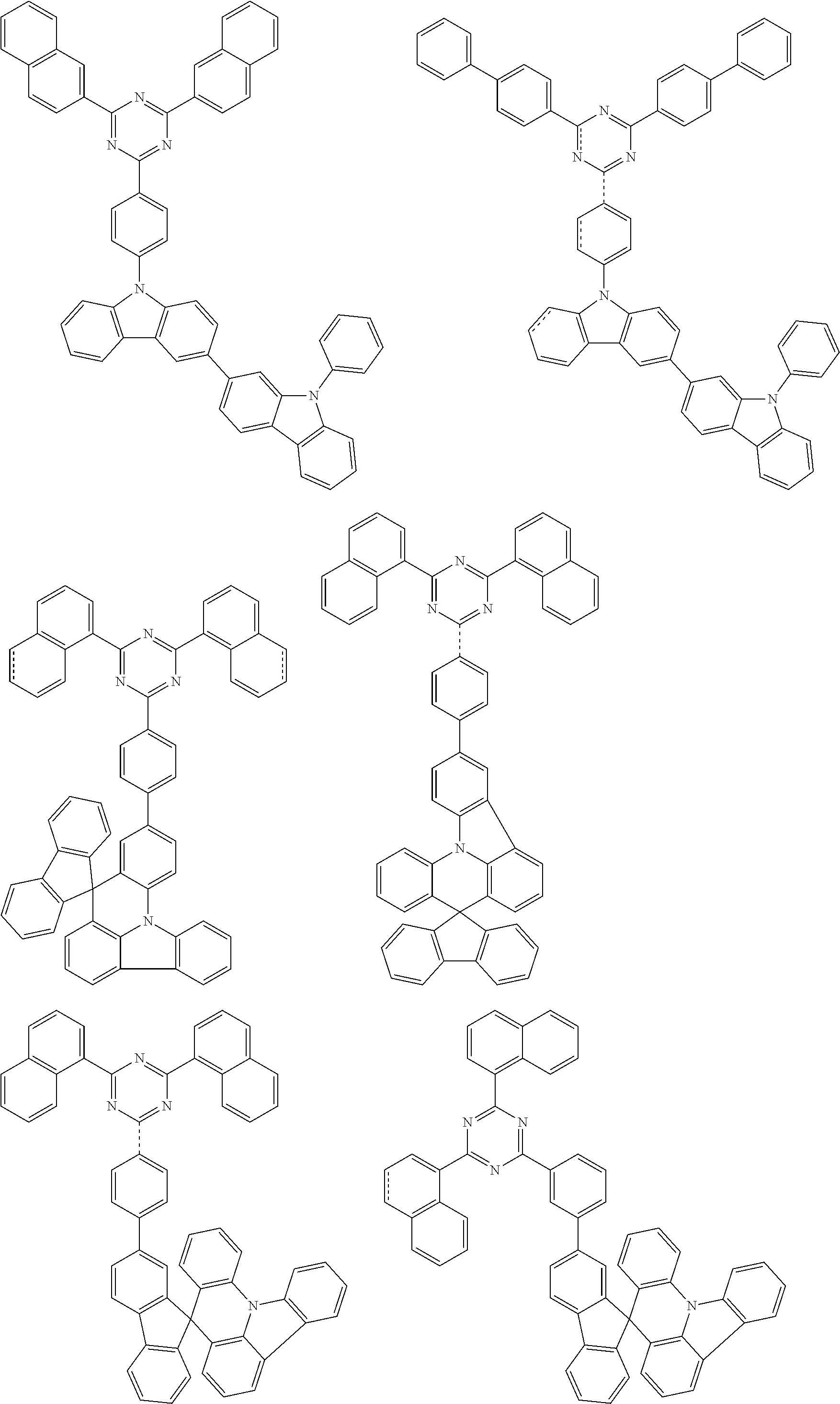

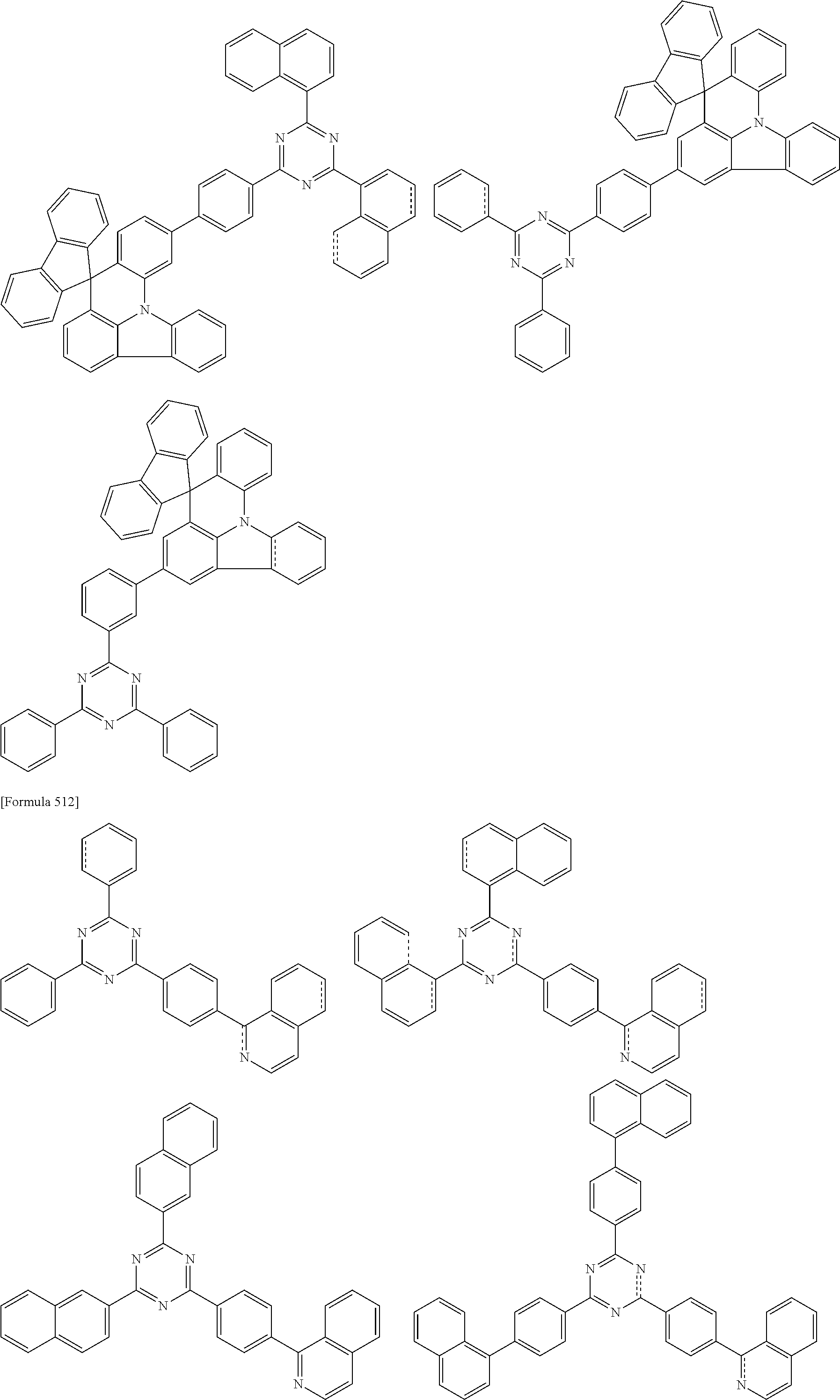

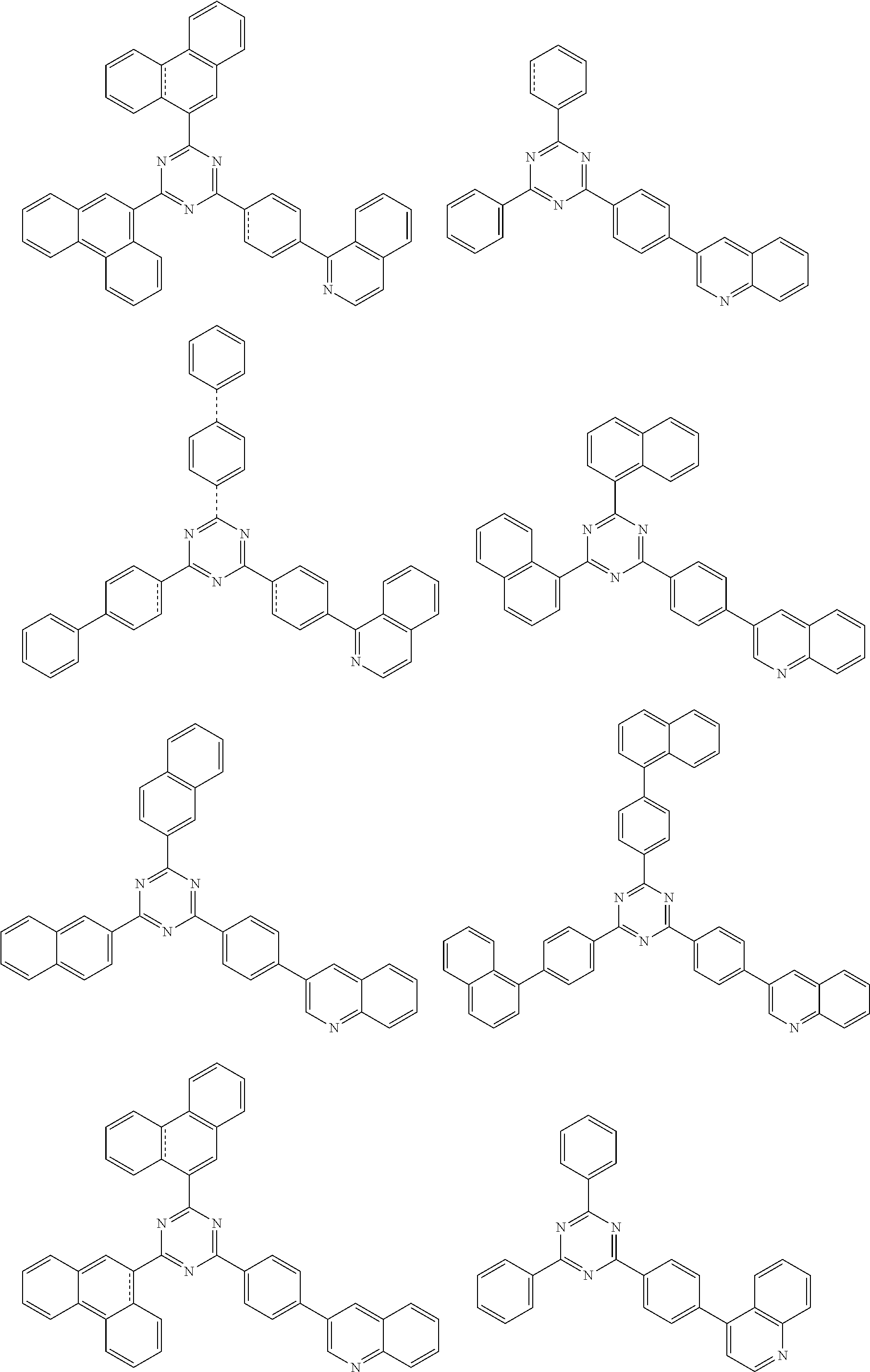

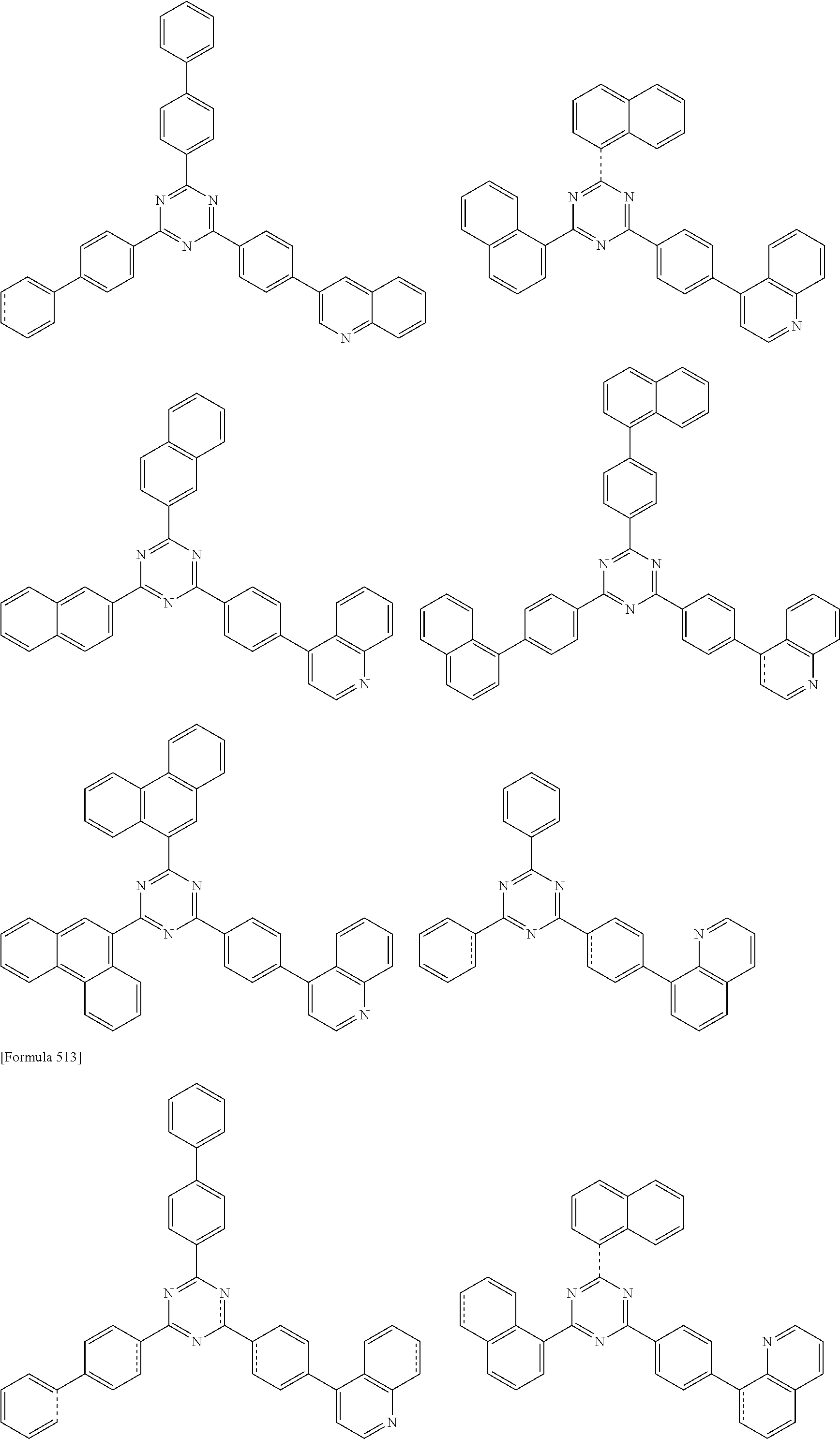

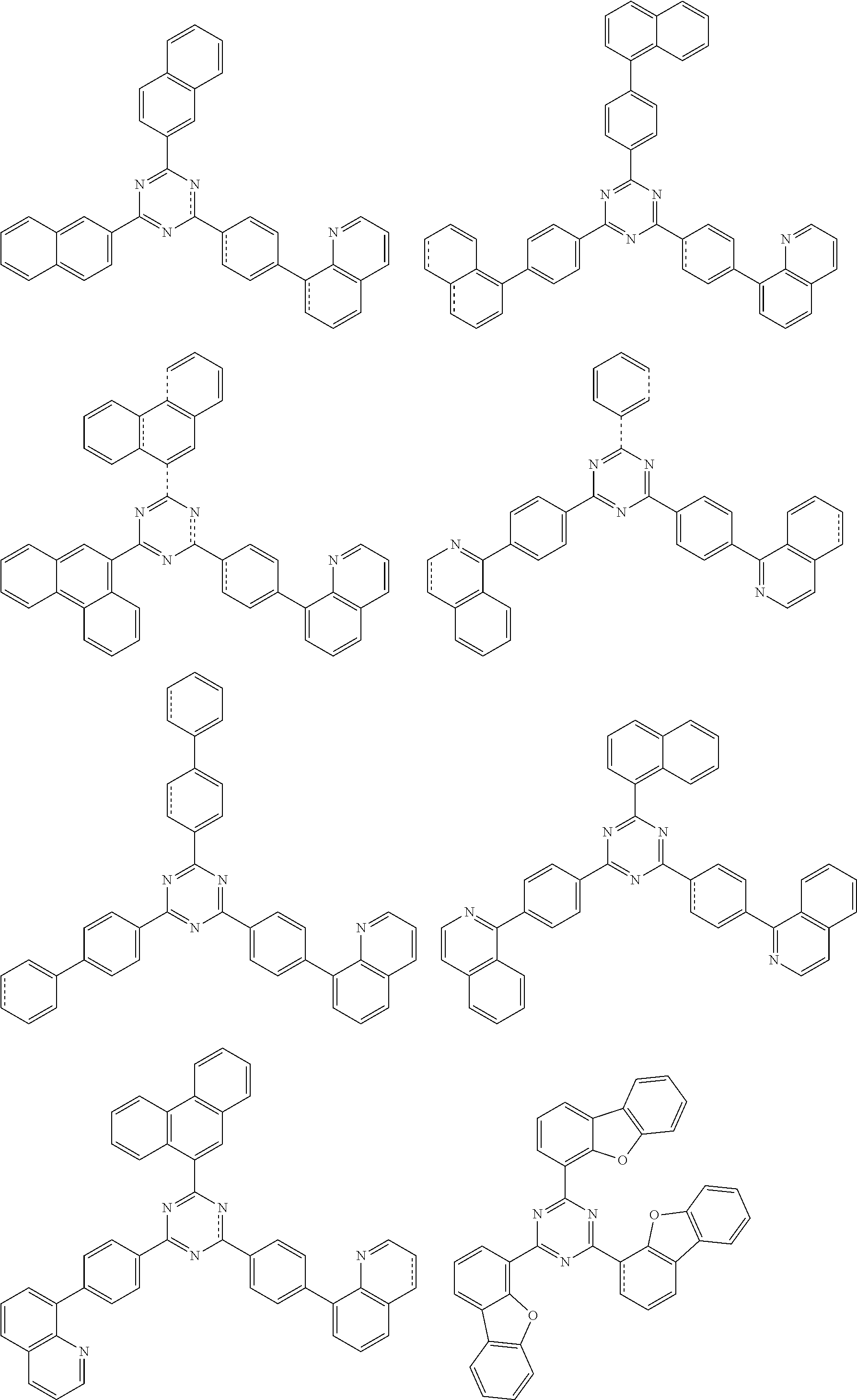

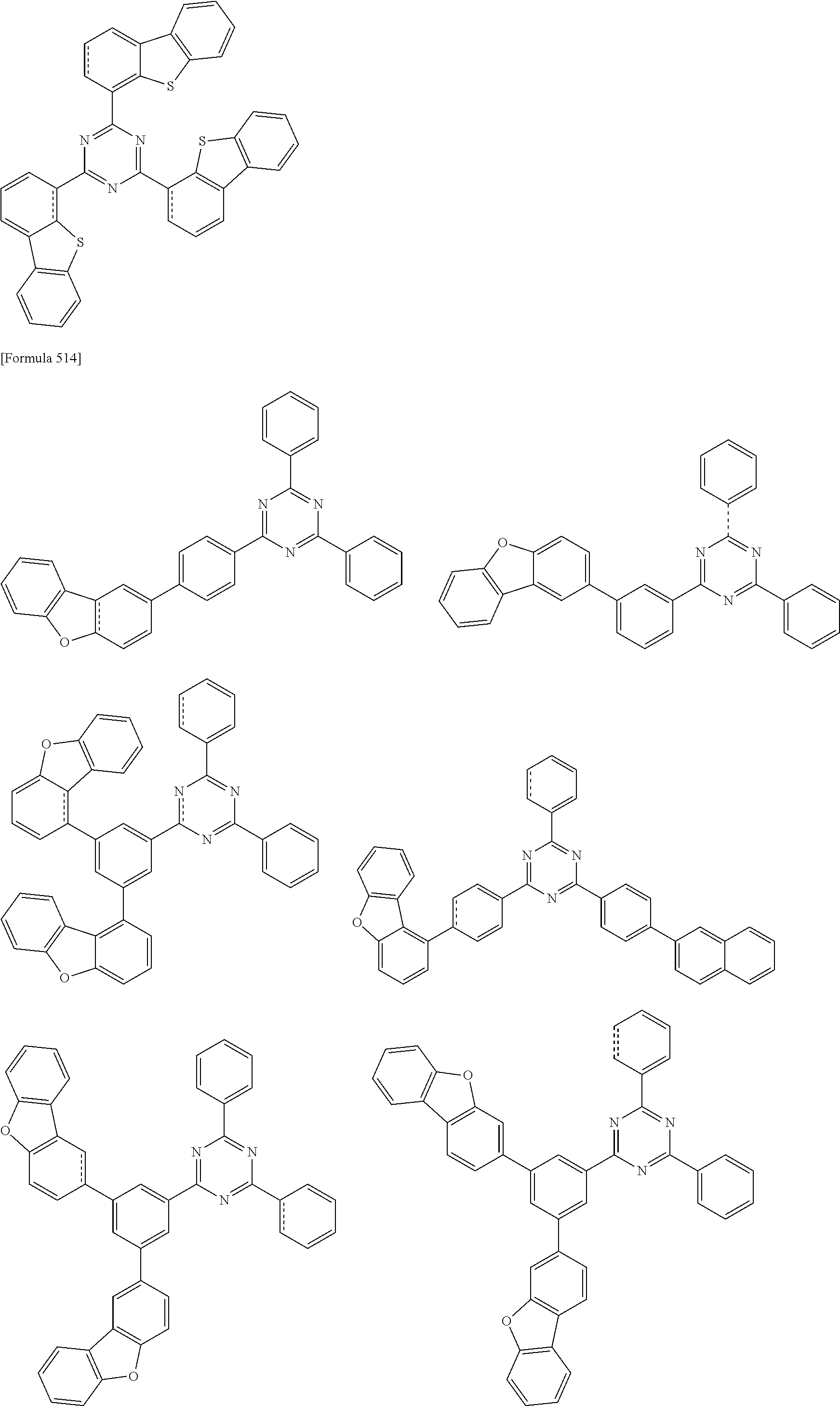

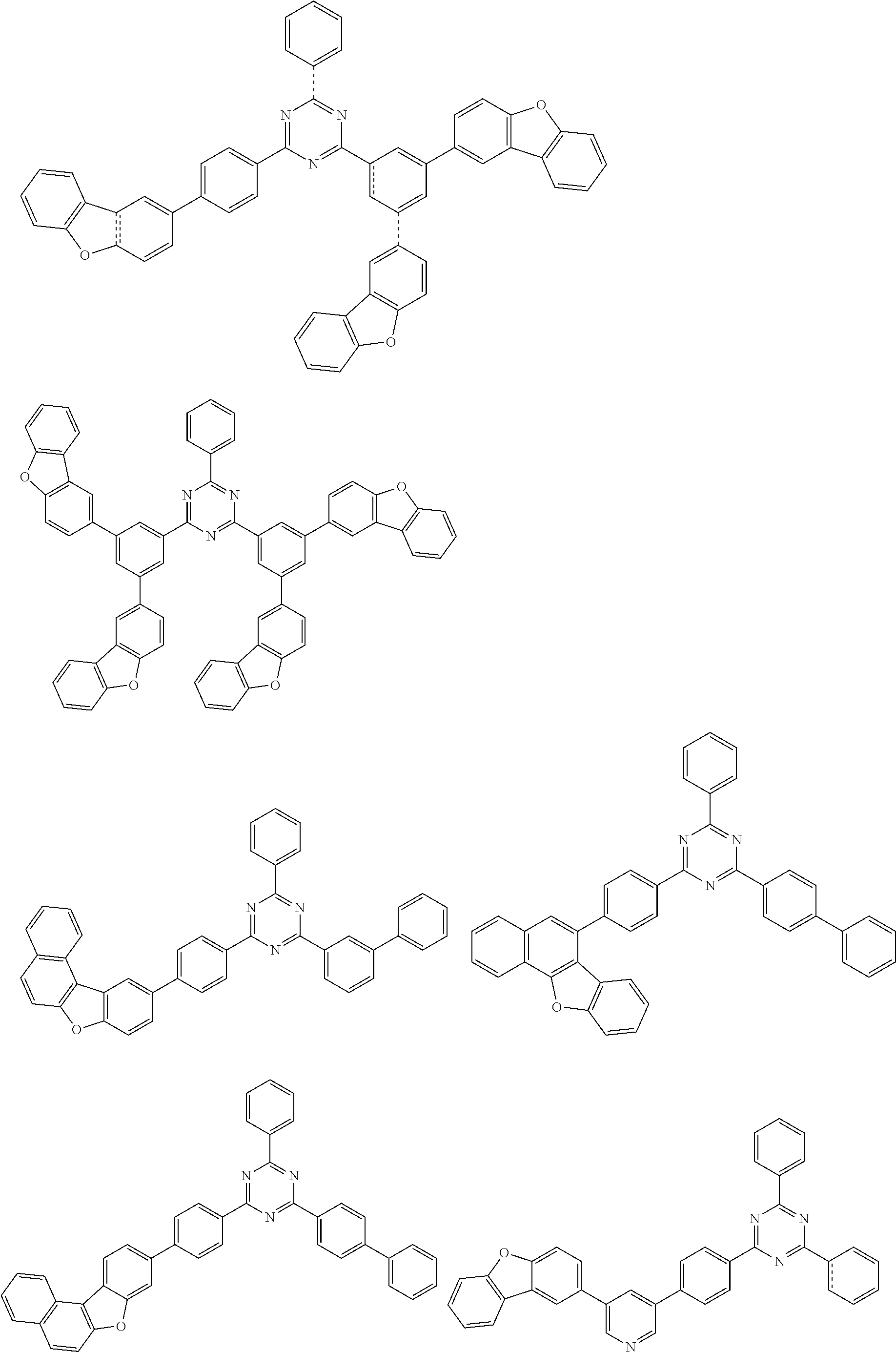

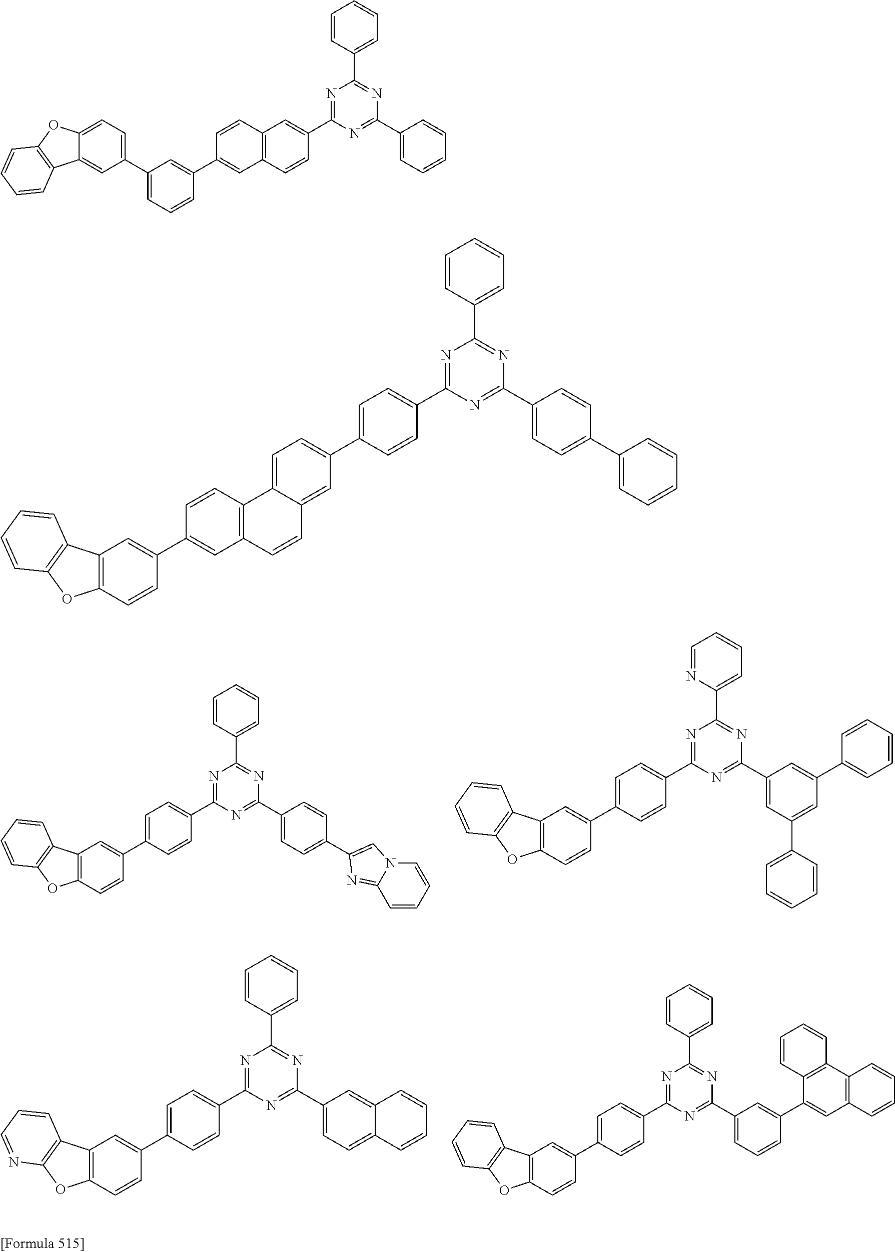

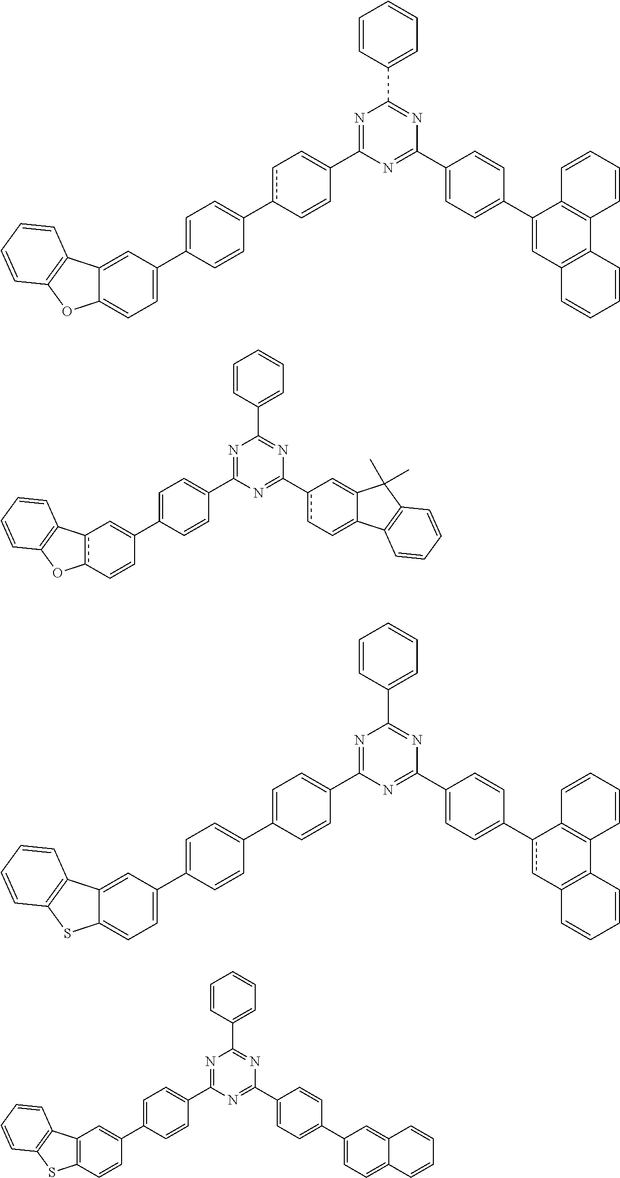

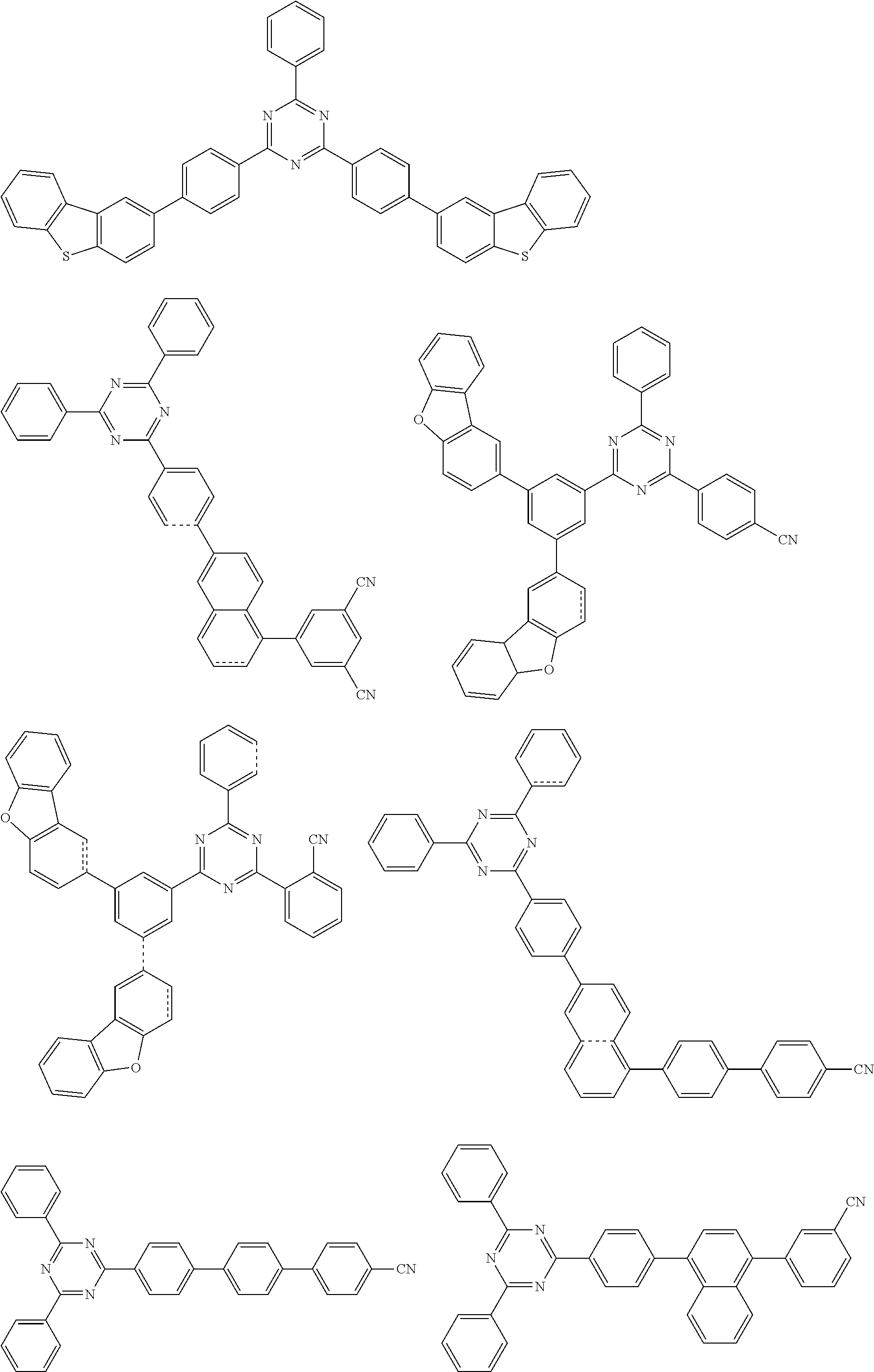

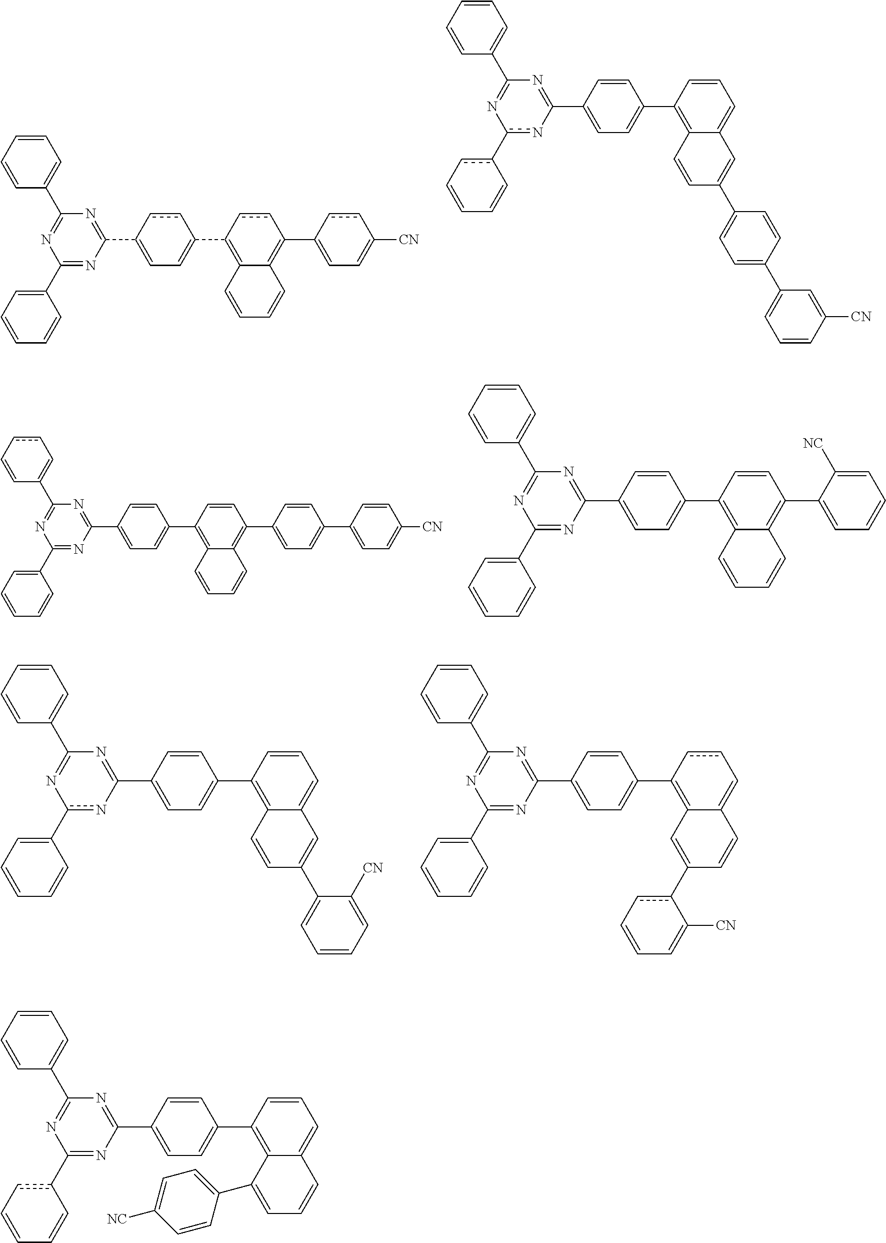

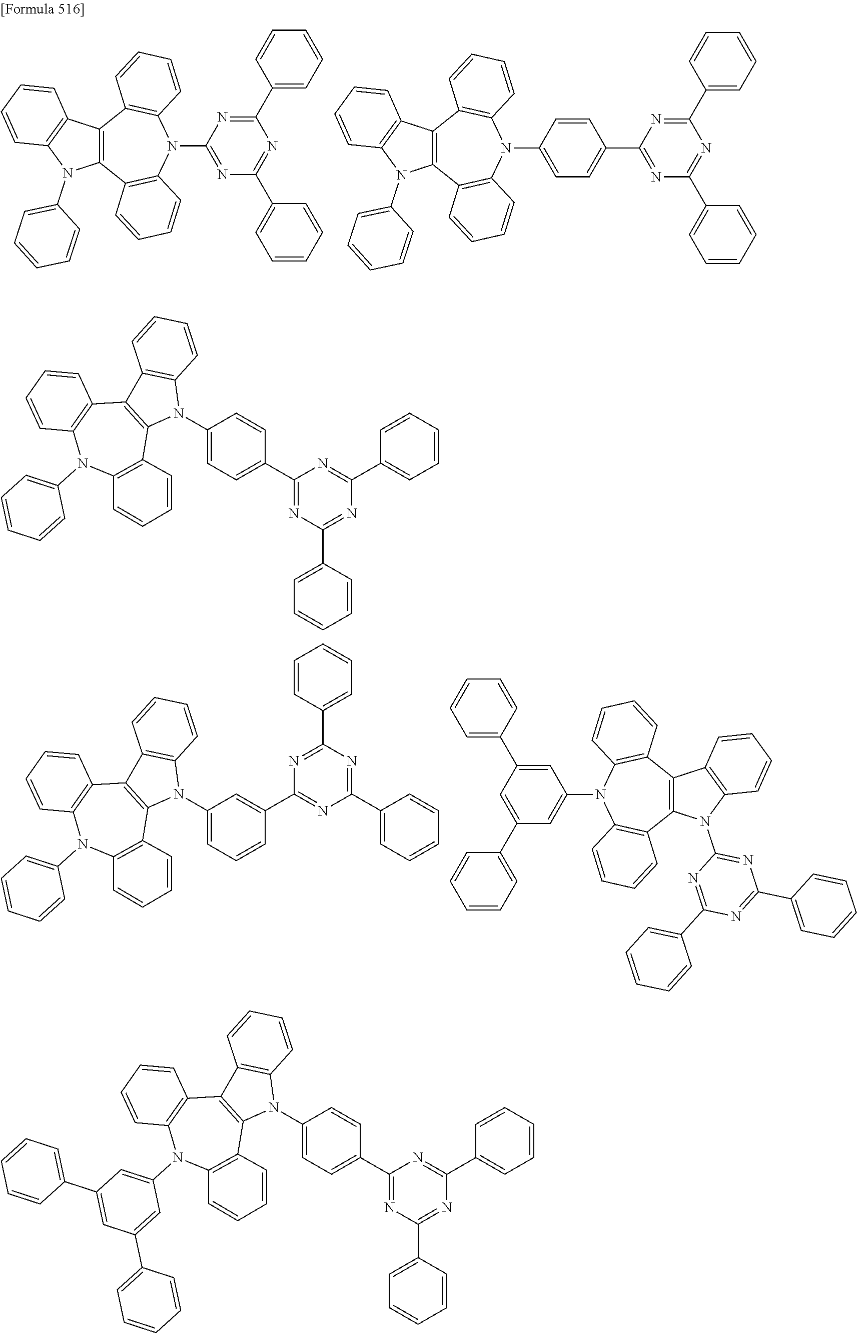

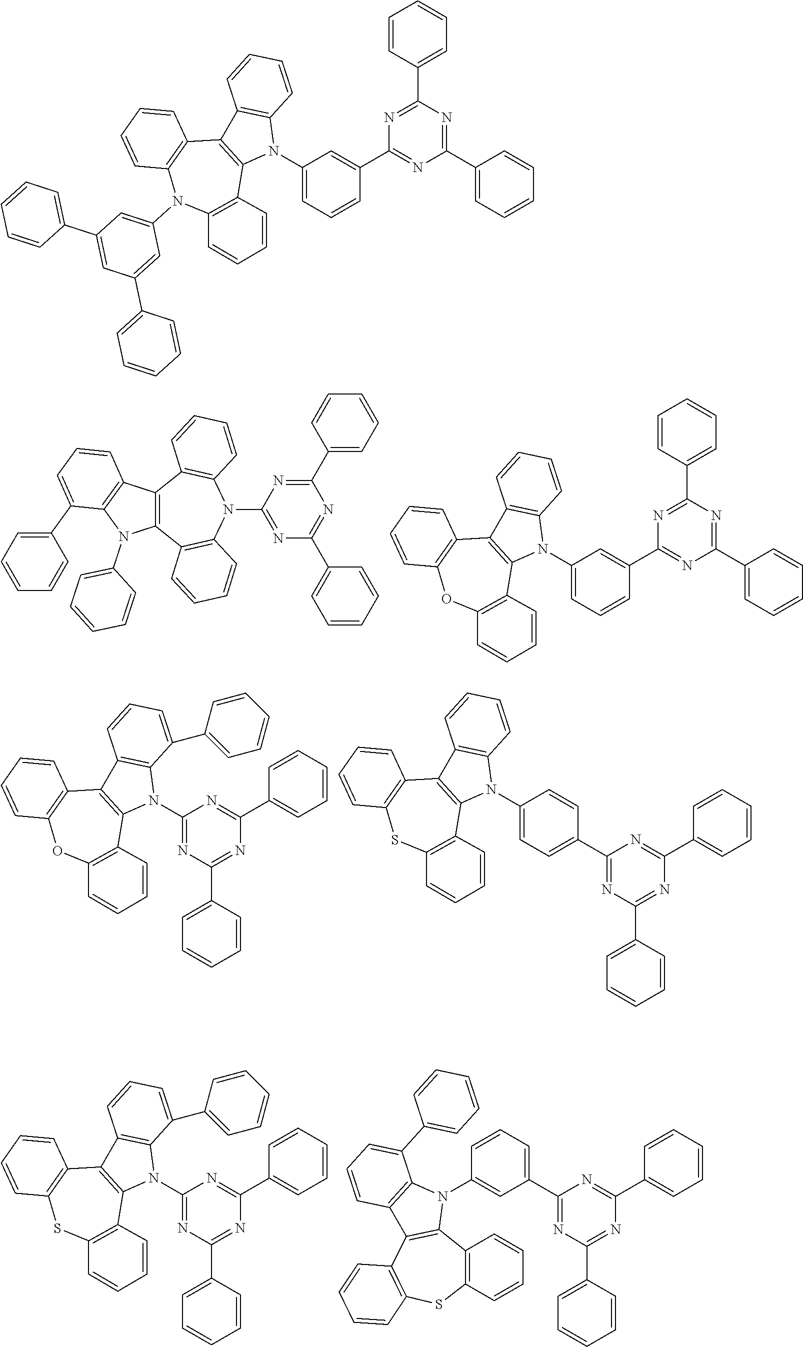

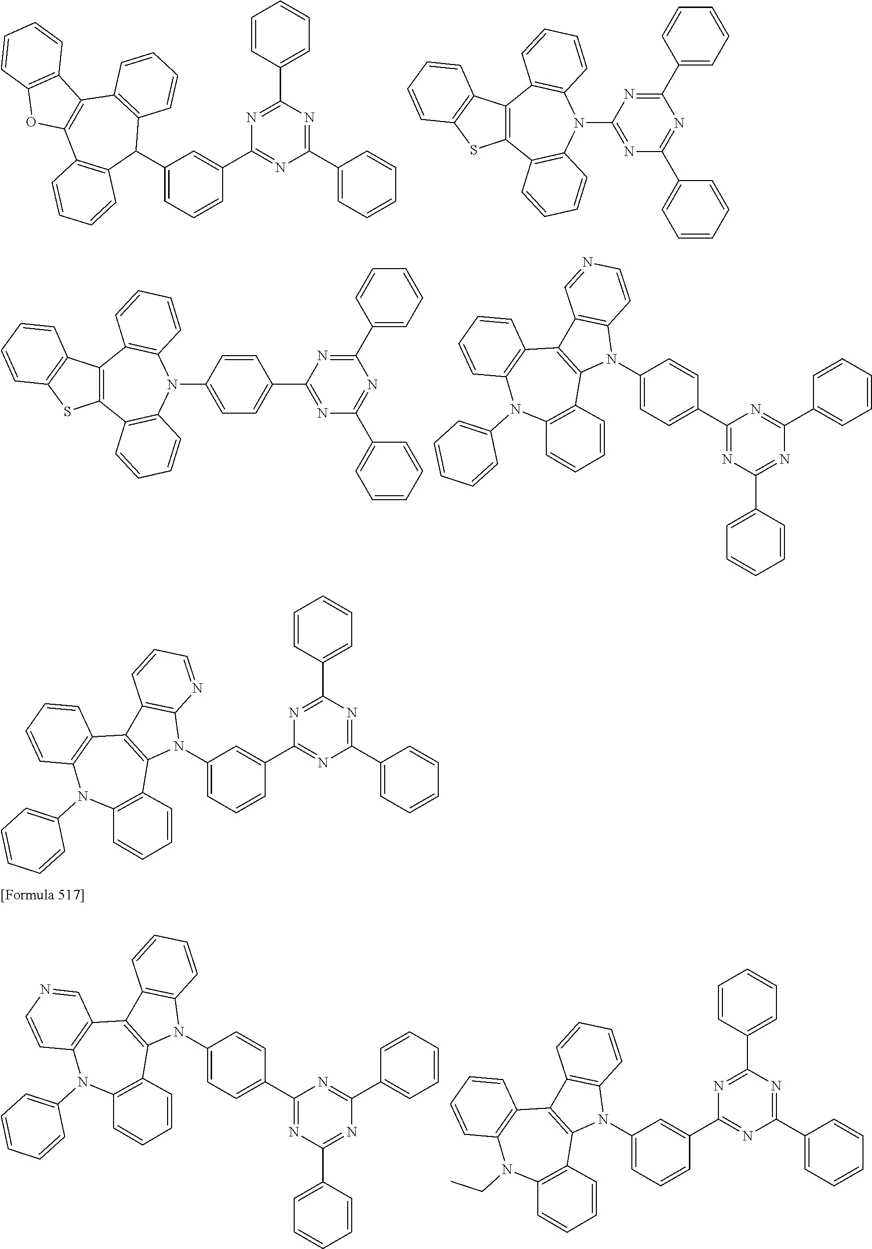

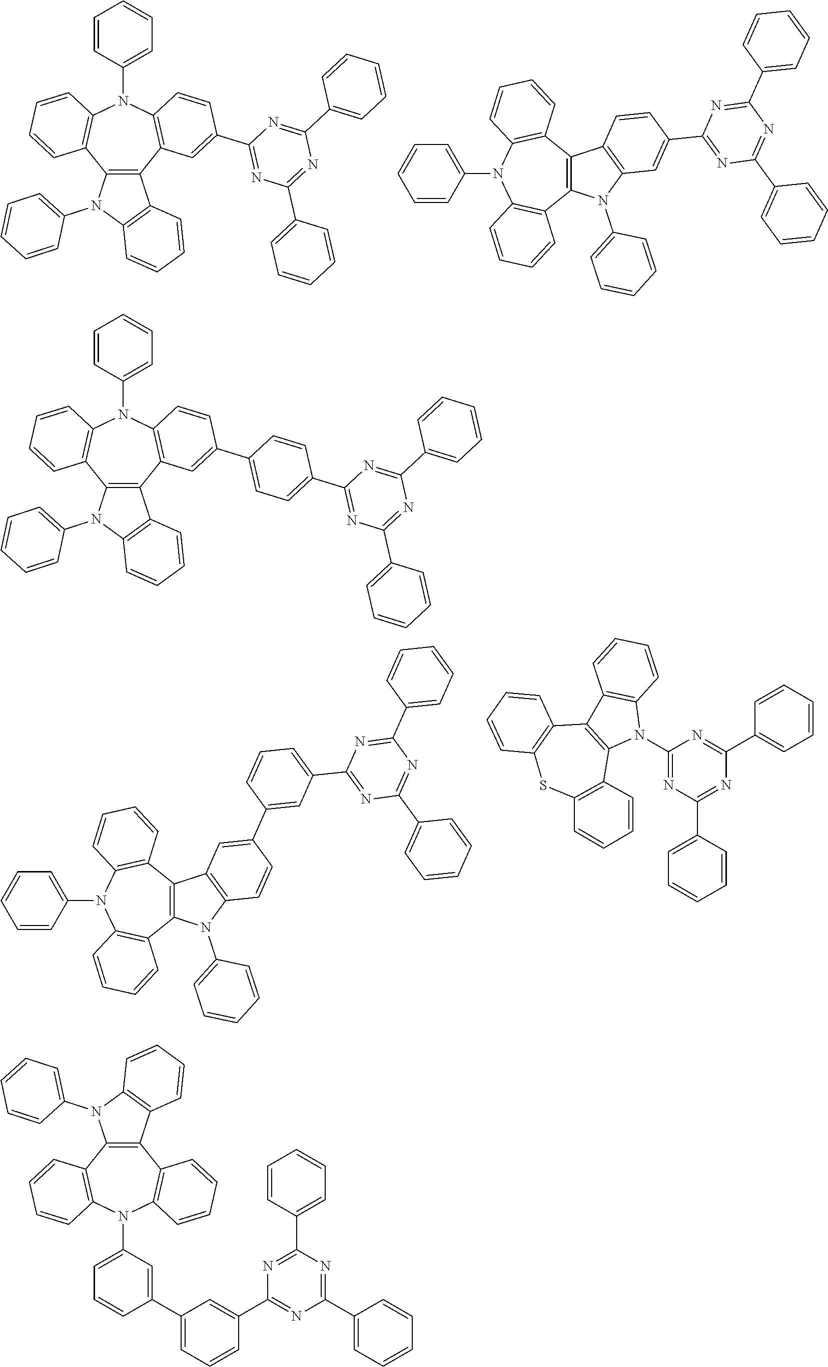

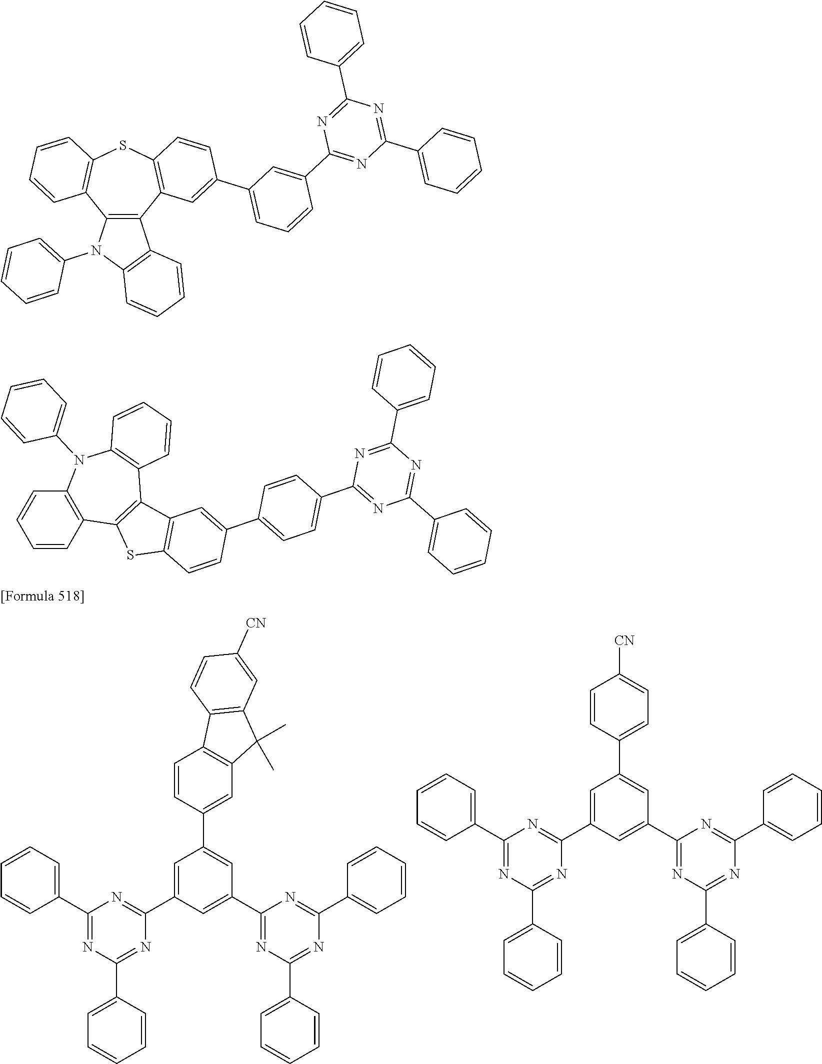

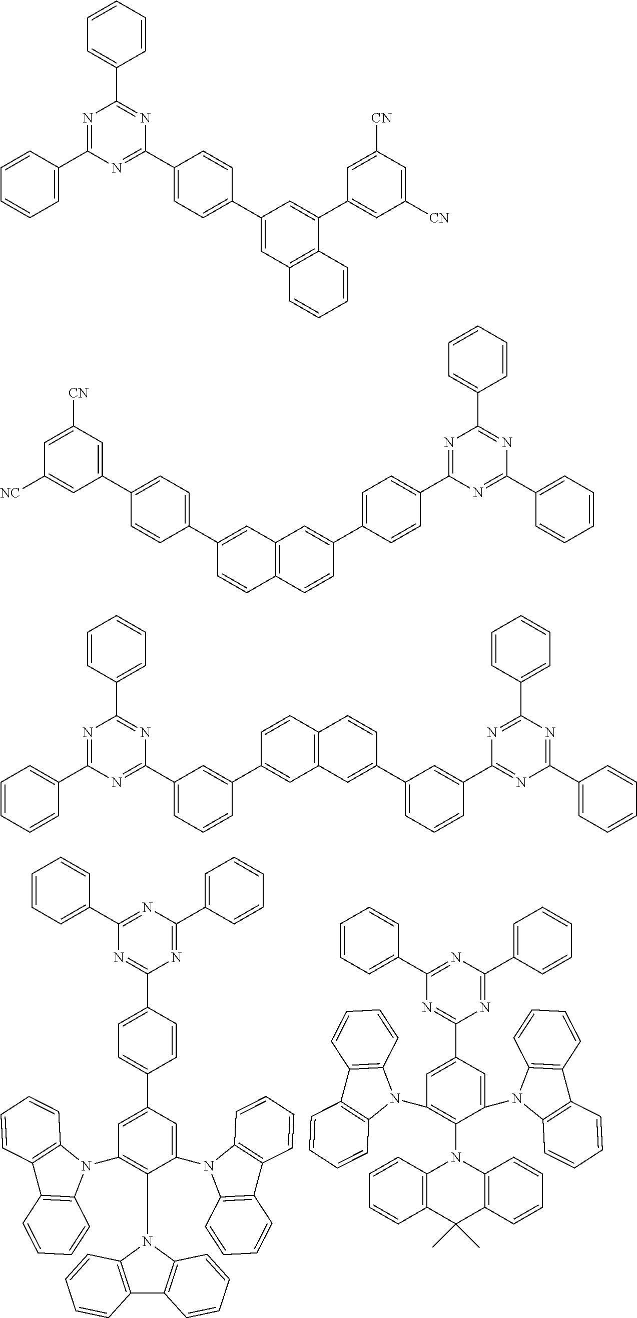

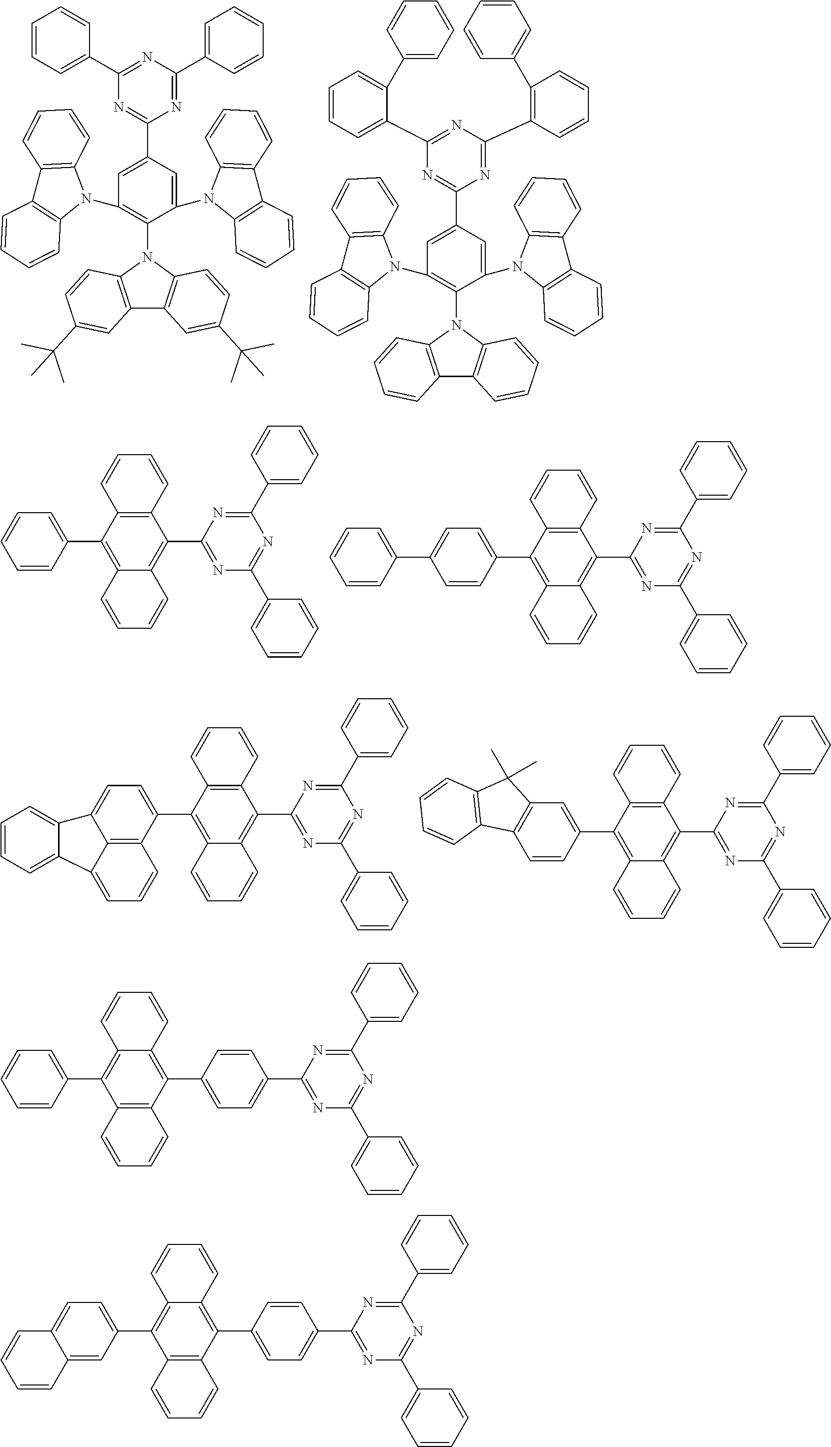

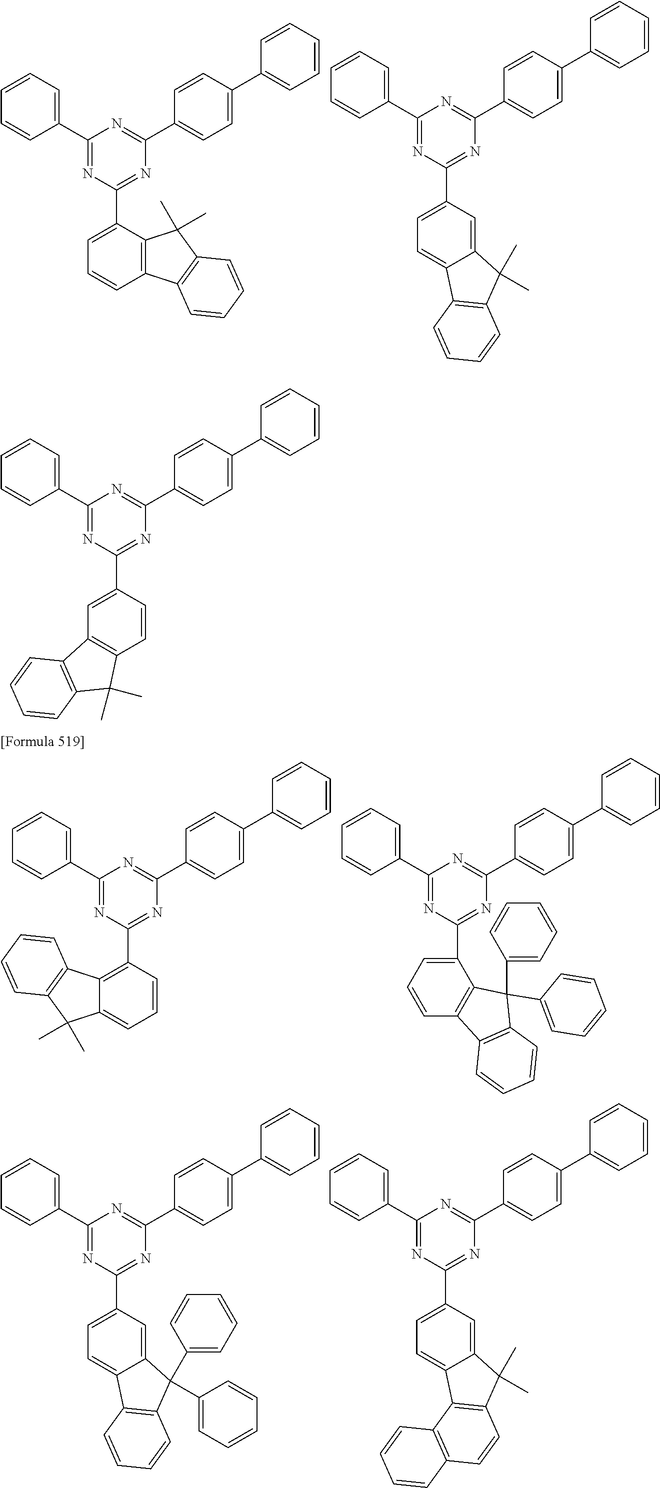

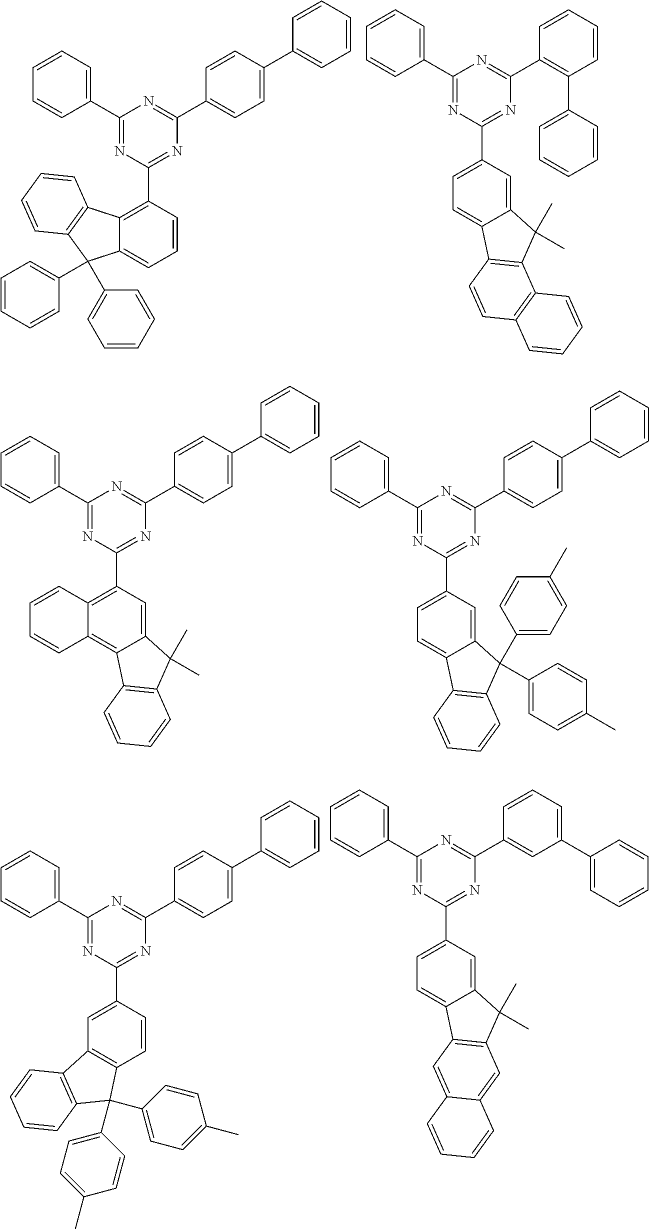

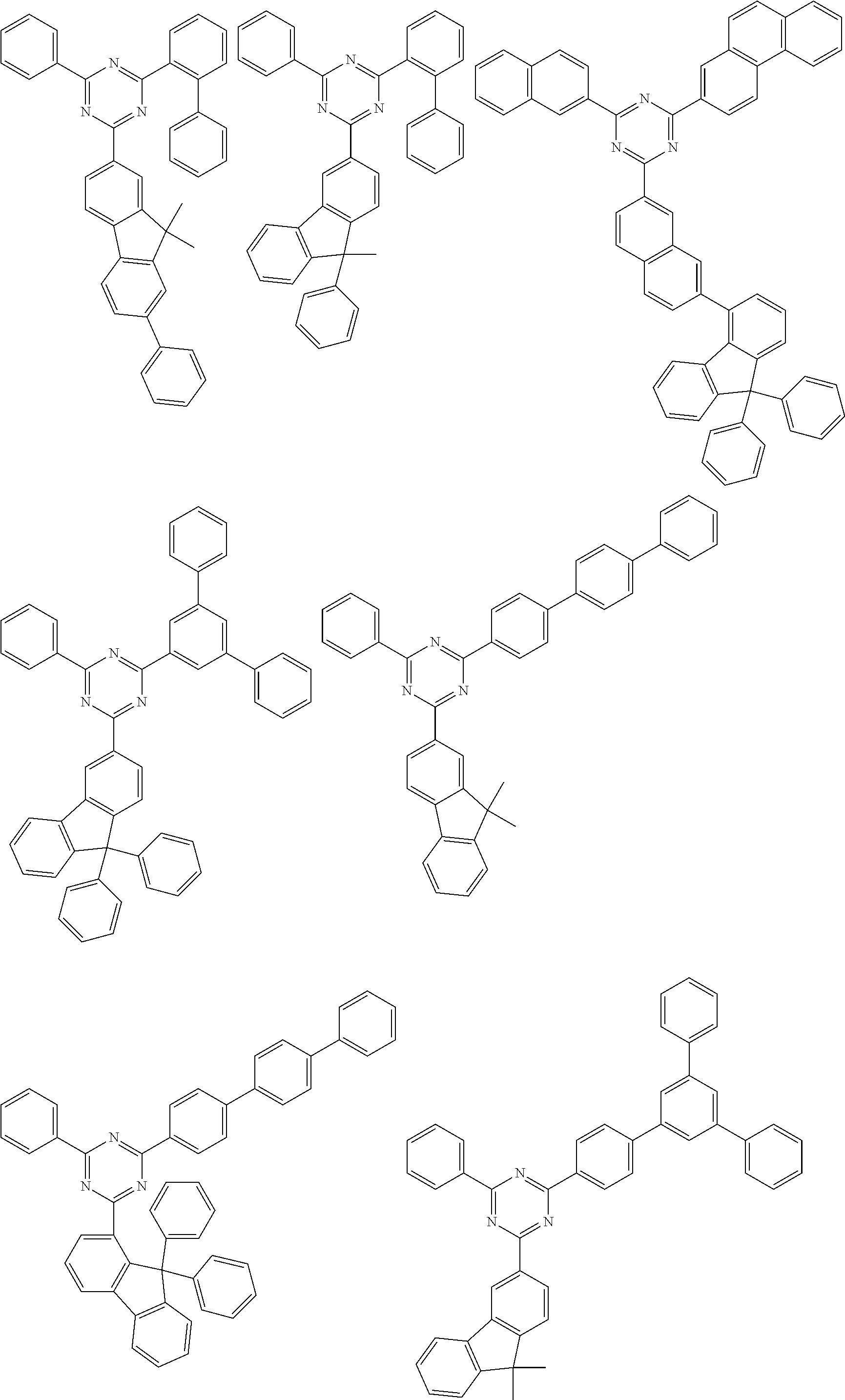

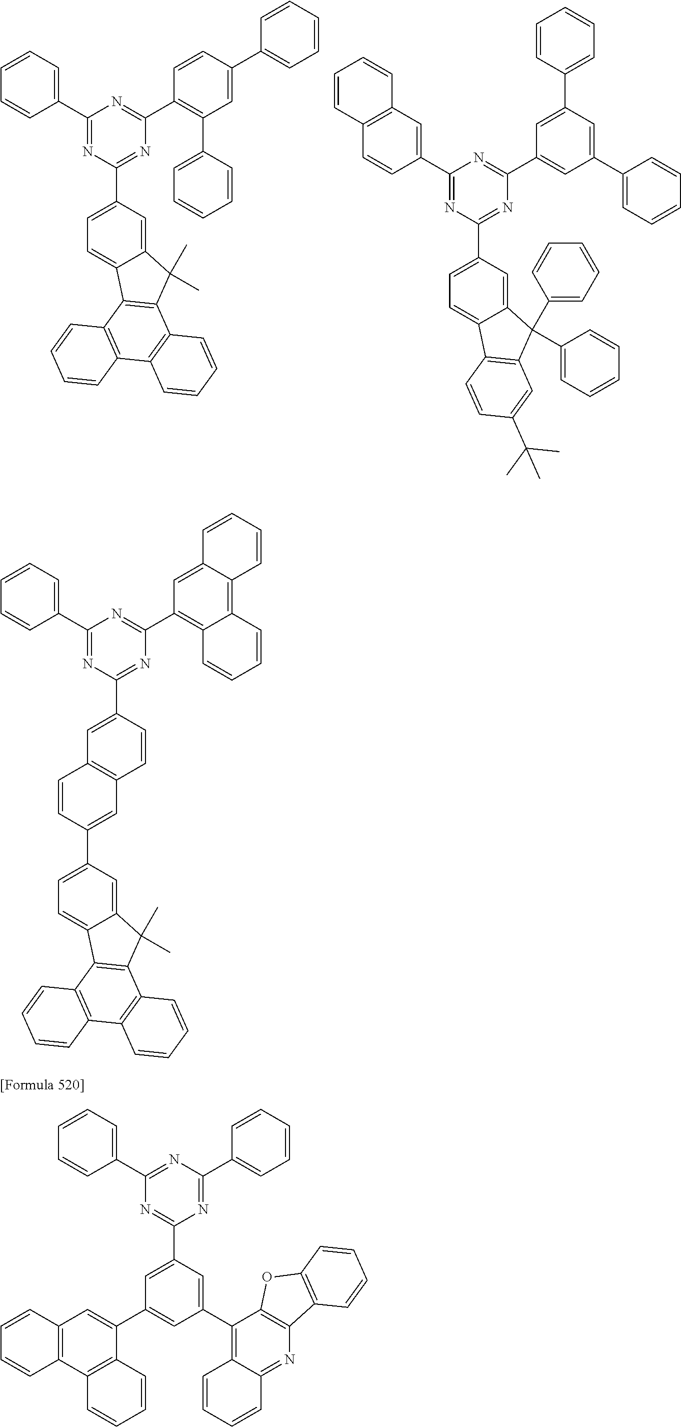

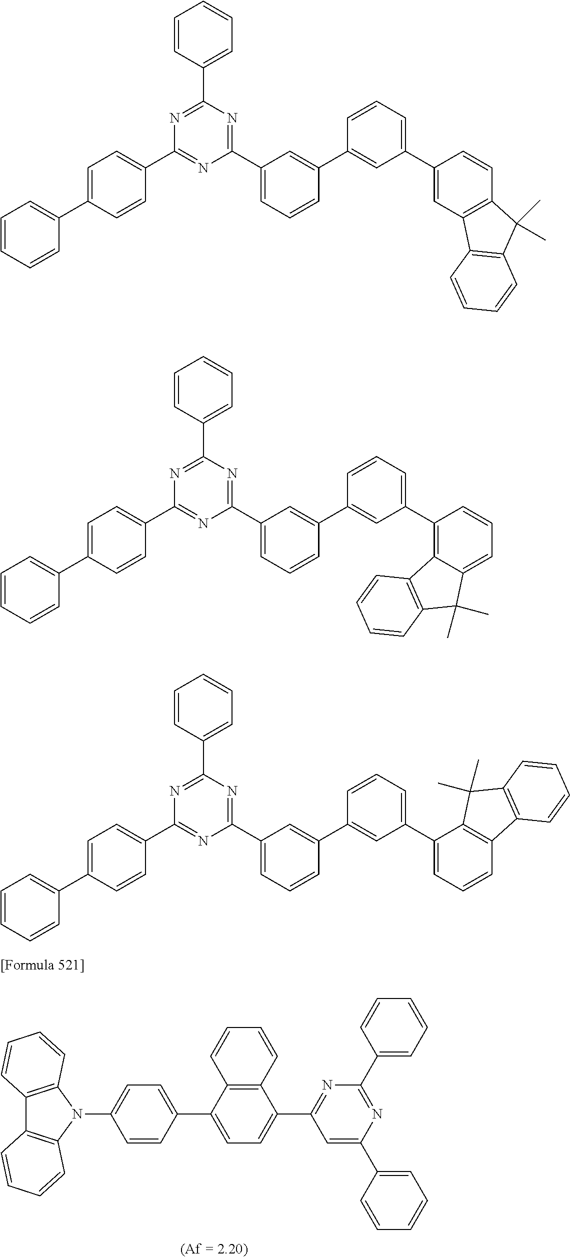 [SMILES: CC1(C)c2ccccc2-c2cc(-c3cccc(-c4cccc(-c5nc(-c6ccccc6)nc(-c6ccc(-c7ccccc7)cc6)n5)c4)c3)ccc21 ; CC1(C)c2ccccc2-c2c(-c3cccc(-c4cccc(-c5nc(-c6ccccc6)nc(-c6ccc(-c7ccccc7)cc6)n5)c4)c3)cccc21 ; CC1(C)c2ccccc2-c2cccc(-c3cccc(-c4cccc(-c5nc(-c6ccccc6)nc(-c6ccc(-c7ccccc7)cc6)n5)c4)c3)c21 ; c1ccc(-c2cc(-c3ccc(-c4ccc(-n5c6ccccc6c6ccccc65)cc4)c4ccccc34)nc(-c3ccccc3)n2)cc1]

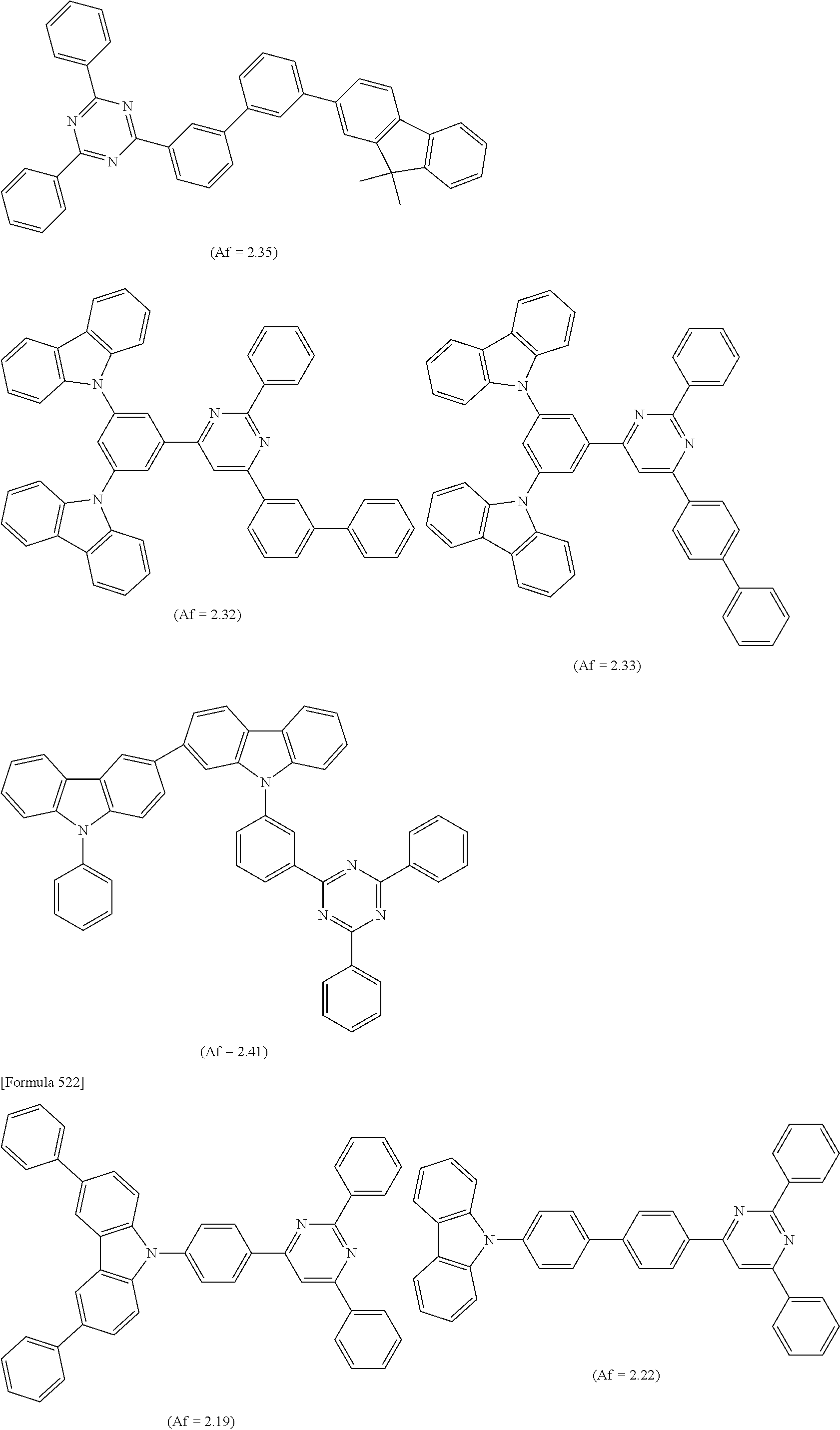

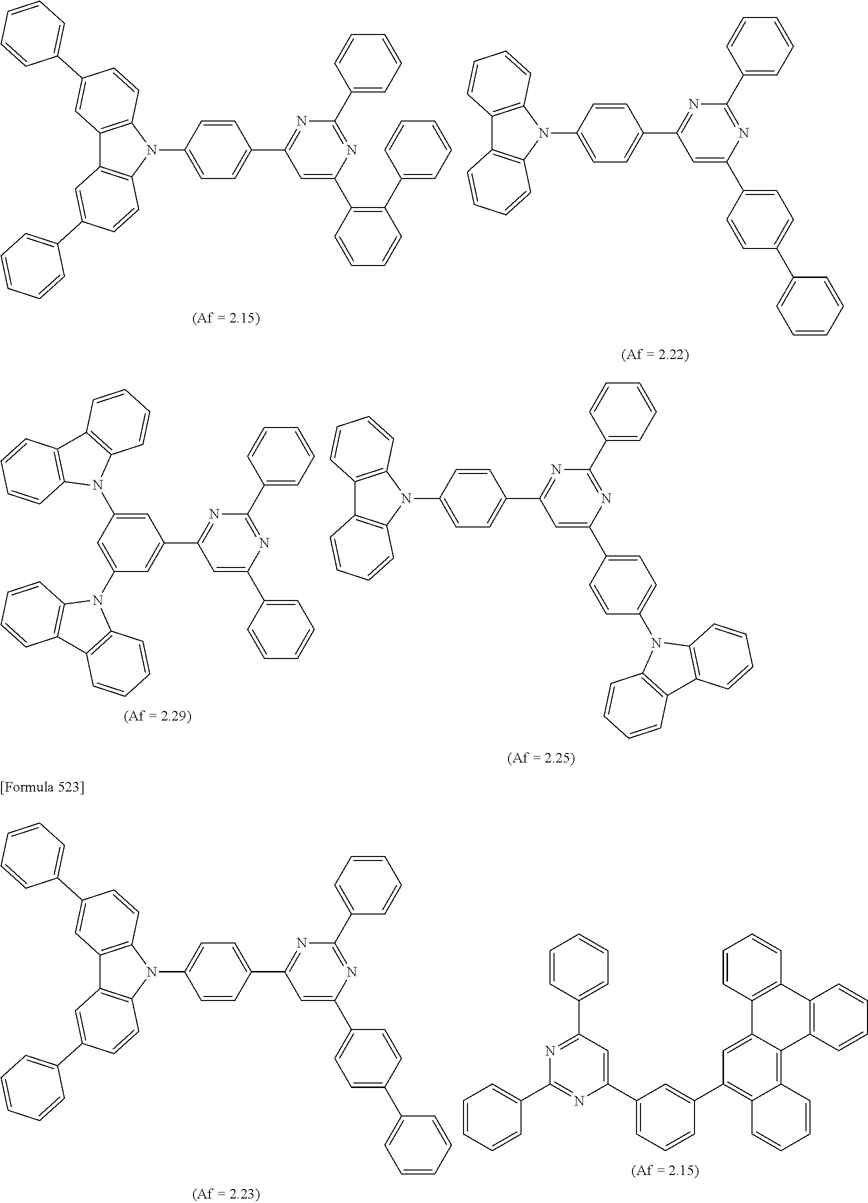

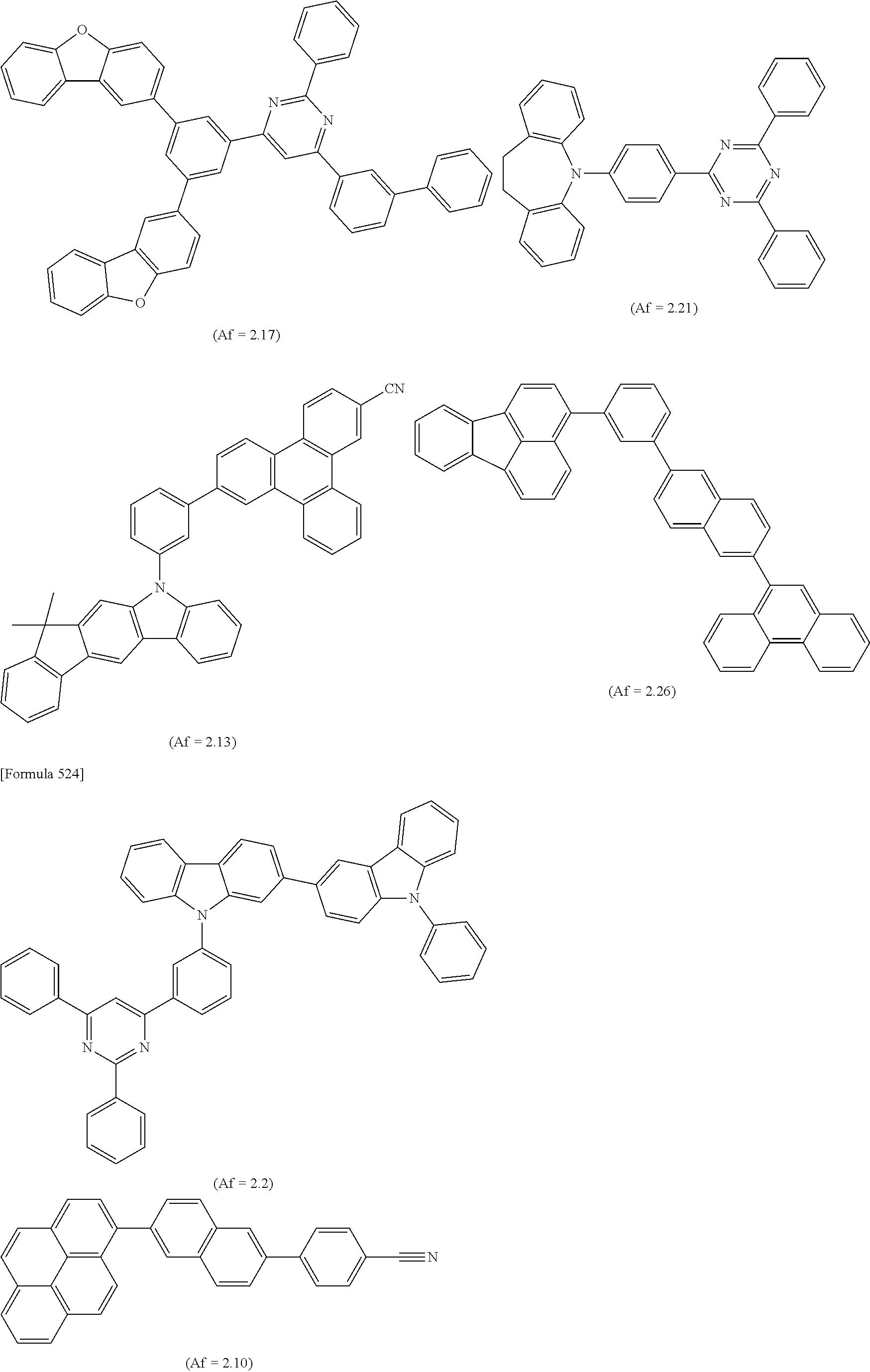

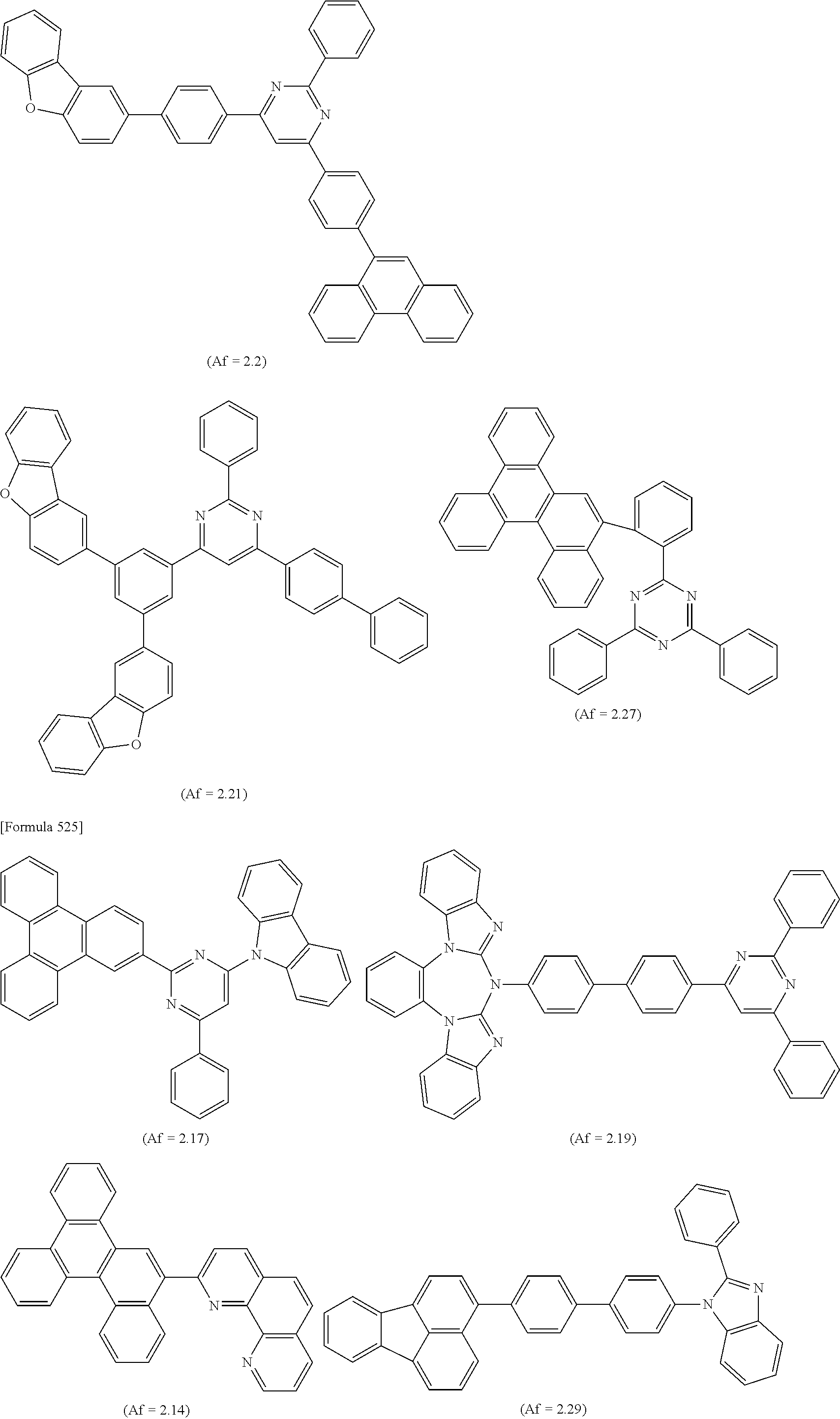

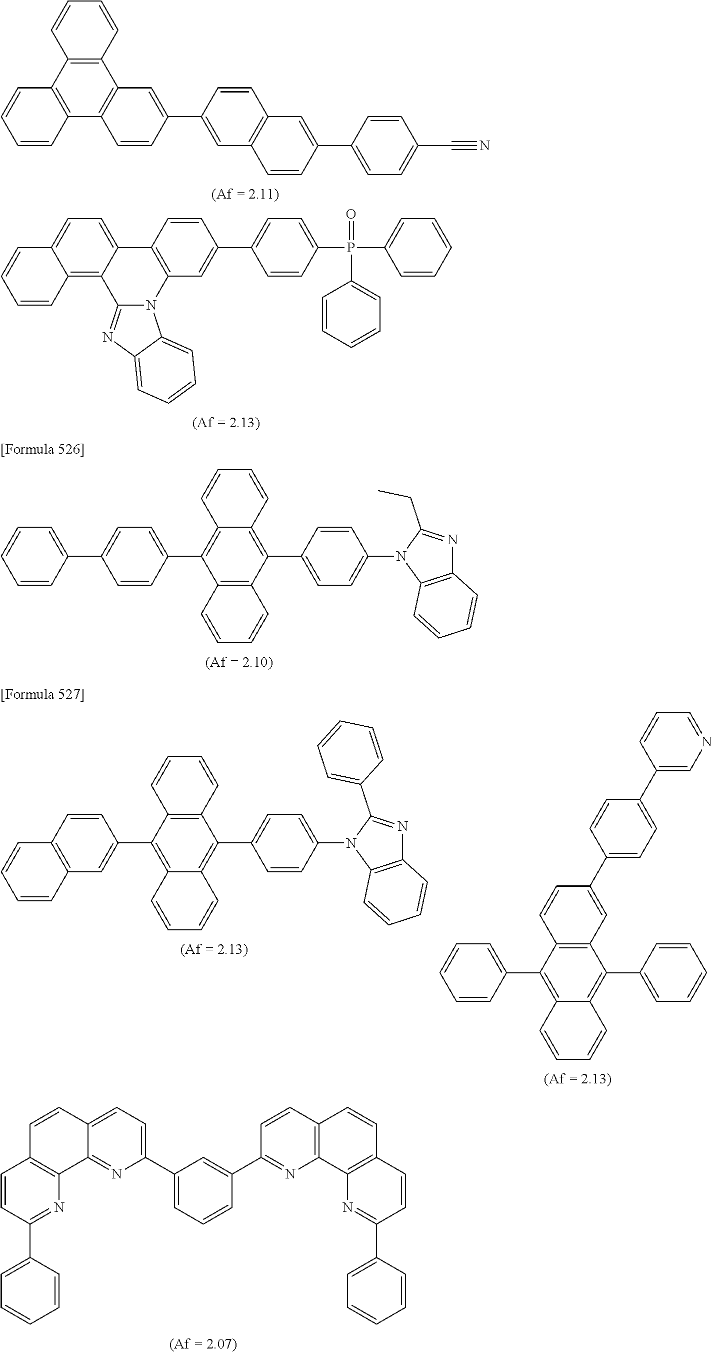

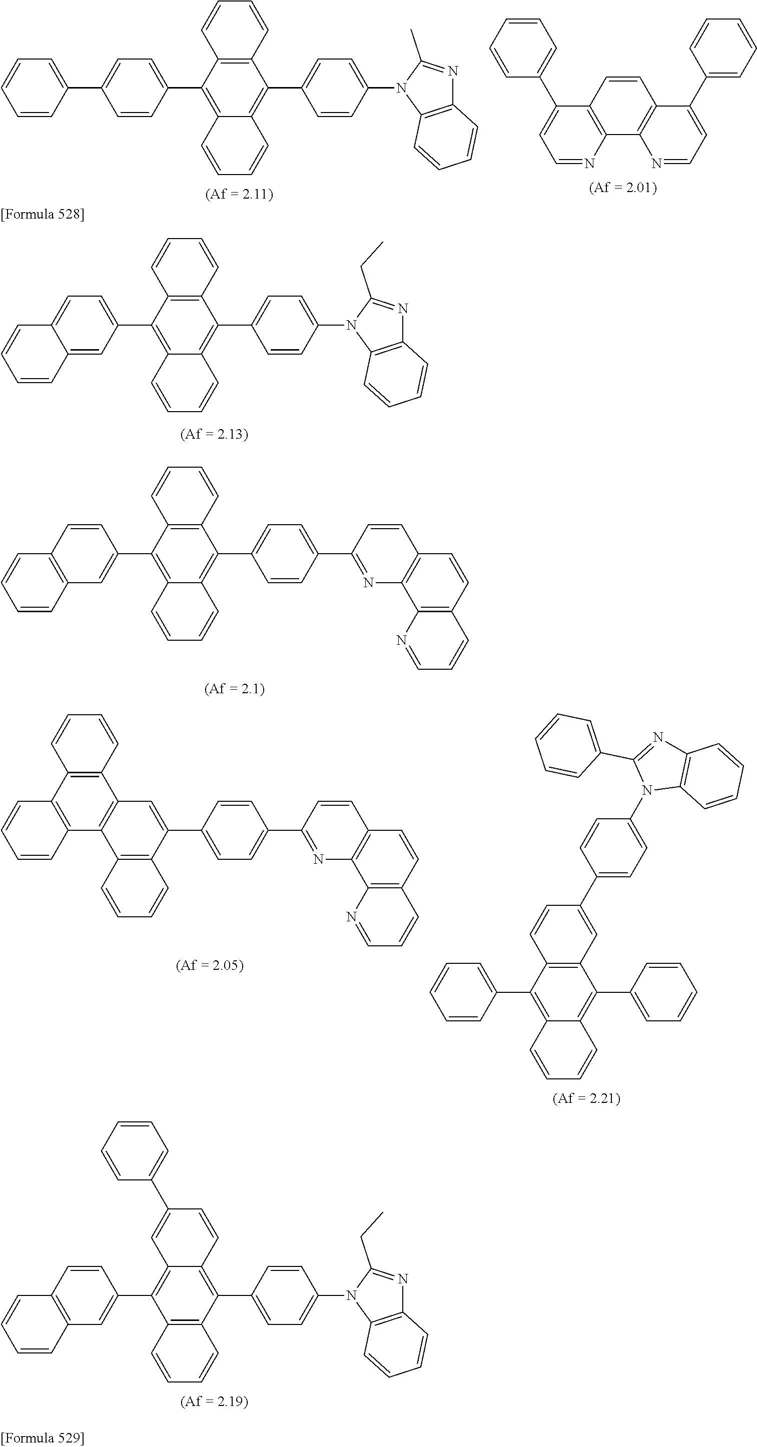

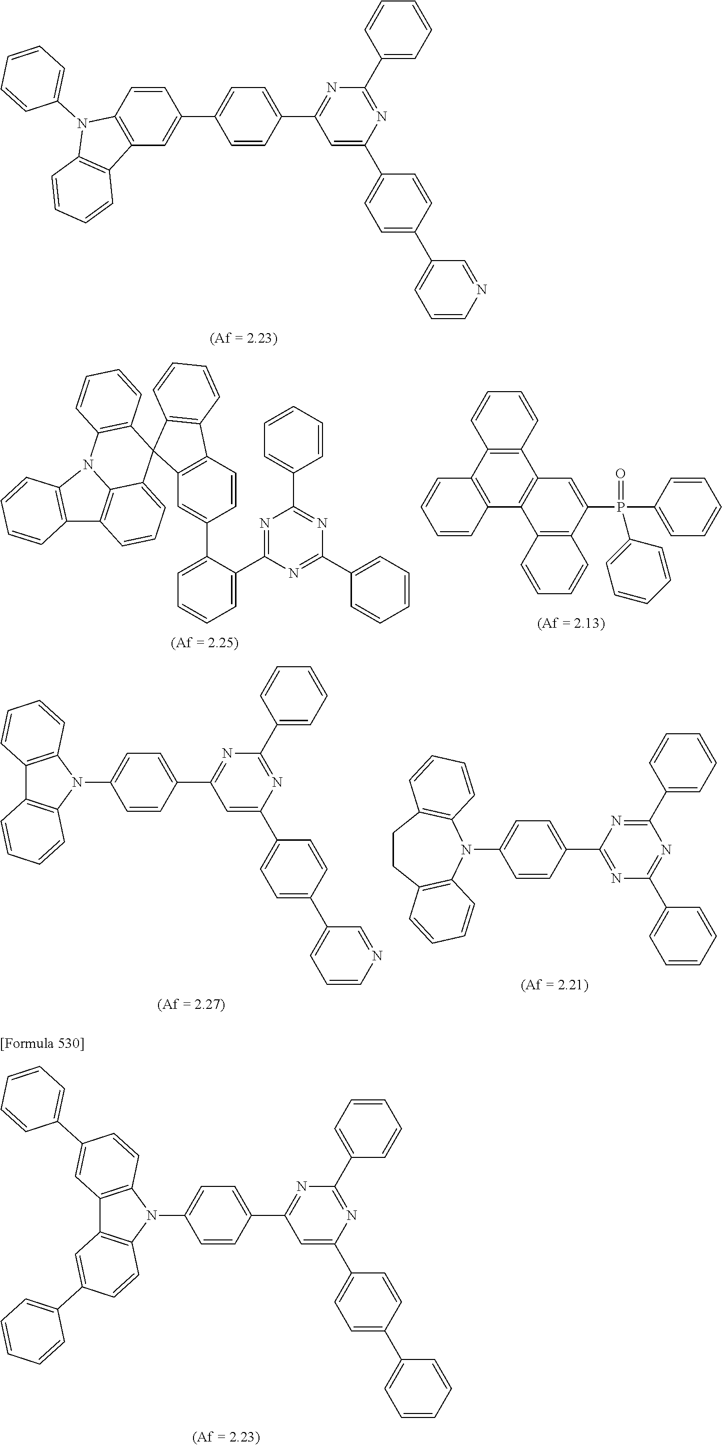 [SMILES: c1ccc(-c2nc(-c3ccc(-c4cccnc4)cc3)cc(-c3ccc(-c4ccc5c(c4)c4ccccc4n5-c4ccccc4)cc3)n2)cc1 ; c1ccc(-c2nc(-c3ccccc3)nc(-c3ccccc3-c3ccc4c(c3)C3(c5ccccc5-4)c4ccccc4-n4c5ccccc5c5cccc3c54)n2)cc1 ; O=P(c1ccccc1)(c1ccccc1)c1cc2c3ccccc3c3ccccc3c2c2ccccc12 ; c1ccc(-c2nc(-c3ccc(-c4cccnc4)cc3)cc(-c3ccc(-n4c5ccccc5c5ccccc54)cc3)n2)cc1 ; c1ccc(-c2nc(-c3ccccc3)nc(-c3ccc(N4c5ccccc5CCc5ccccc54)cc3)n2)cc1 ; c1ccc(-c2ccc(-c3cc(-c4ccc(-n5c6ccc(-c7ccccc7)cc6c6cc(-c7ccccc7)ccc65)cc4)nc(-c4ccccc4)n3)cc2)cc1]

A second exemplary embodiment and a third exemplary embodiment will be described below.

An organic EL device of each of the second exemplary embodiment and the third exemplary embodiment is an exemplary arrangement of the organic EL device of the first exemplary embodiment.

Accordingly, constituent elements that can be contained in the organic EL device of the second exemplary embodiment are the same as constituent elements that can be contained in the organic EL device described in the first exemplary embodiment.

Further, constituent elements that can be contained in the organic EL device of the third exemplary embodiment are the same as constituent elements that can be contained in the organic EL device described in the first exemplary embodiment.

### Second Exemplary Embodiment

The organic EL device according to the second exemplary embodiment includes a cathode; an anode;
an emitting region provided between the cathode and the anode; and
a hole transporting zone provided between the anode and the emitting region; and an electron transporting zone provided between the cathode and the emitting region, in which the emitting region includes at least one emitting layer,
the at least one emitting layer includes a first emitting layer,
the hole transporting zone includes a first anode side organic layer, a second anode side organic layer, and a third anode side organic layer,
the first anode side organic layer is in direct contact with the second anode side organic layer and the second anode side organic layer is in direct contact with the third anode side organic layer,
the first anode side organic layer, the second anode side organic layer, and the third anode side organic layer are arranged in this order from a side close to the anode between the anode and the emitting region,
the second anode side organic layer contains a second hole transporting zone material,
the second hole transporting zone material is a monoamine compound having one substituted or unsubstituted amino group in a molecule or a diamine compound having two substituted or unsubstituted amino groups in a molecule,
the third anode side organic layer contains a third hole transporting zone material,
the third hole transporting zone material is a monoamine compound having one substituted or unsubstituted amino group in a molecule or a diamine compound having two substituted or unsubstituted amino groups in a molecule,
the third anode side organic layer has a film thickness of 20 nm or more,
the second hole transporting zone material and the third hole transporting zone material are mutually the same or different,
the second anode side organic layer comprises at least one compound different from the compound comprised in the third anode side organic layer,
at least one electron transporting layer in the electron transporting zone contains a phenanthroline compound having a phenanthroline skeleton,
the phenanthroline compound is a compound represented by the formula (20) and having at least one group represented by the formula (21),
the first emitting layer is a fluorescent emitting layer, and
a refractive index NM₂ of a constituent material contained in the second anode side organic layer and a refractive index NM₃ of a constituent material contained in the third anode side organic layer satisfy a relationship of a numerical formula (Numerical Formula NM) below.

NM₂>NM₃ (Numerical Formula NM)

According the second exemplary embodiment, the device performance of the organic EL device is improvable. In an exemplary arrangement of the second exemplary embodiment, the organic EL device has an improved luminous efficiency. In an exemplary arrangement of the second exemplary embodiment, the organic EL device has a longer lifetime.

### Third Exemplary Embodiment

The organic EL device according to the third exemplary embodiment includes a cathode; an anode;
an emitting region provided between the cathode and the anode; and
a hole transporting zone provided between the anode and the emitting region; in which the emitting region includes at least one emitting layer,
the at least one emitting layer includes a first emitting layer,
the first emitting layer contains a first host material and a first emitting compound,
the first host material is a compound represented by a formula (H1) below,
the compound represented by the formula (H1) has at least one deuterium atom,
the hole transporting zone includes a first anode side organic layer, a second anode side organic layer, and a third anode side organic layer,
the first anode side organic layer is in direct contact with the second anode side organic layer and the second anode side organic layer is in direct contact with the third anode side organic layer,
the first anode side organic layer, the second anode side organic layer, and the third anode side organic layer are arranged in this order from a side close to the anode between the anode and the emitting region,
the second anode side organic layer contains a second hole transporting zone material,
the second hole transporting zone material is a monoamine compound having one substituted or unsubstituted amino group in a molecule or a diamine compound having two substituted or unsubstituted amino groups in a molecule,
the third anode side organic layer contains a third hole transporting zone material,
the third hole transporting zone material is a monoamine compound having one substituted or unsubstituted amino group in a molecule or a diamine compound having two substituted or unsubstituted amino groups in a molecule,
the third anode side organic layer has a film thickness of 20 nm or more,
the second hole transporting zone material and the third hole transporting zone material are mutually the same or different,
the second anode side organic layer contains at least one compound different from the compound comprised in the third anode side organic layer,
the first emitting layer is a fluorescent emitting layer, and
a refractive index NM₂ of a constituent material contained in the second anode side organic layer and a refractive index NM₃ of a constituent material contained in the third anode side organic layer satisfy a relationship of a numerical formula (Numerical Formula NM) below.

NM₂>NM₃ (Numerical Formula NM)

According the third exemplary embodiment, the device performance of the organic EL device is improvable. In an exemplary arrangement of the third exemplary embodiment, the organic EL device has an improved luminous efficiency. In an exemplary arrangement of the third exemplary embodiment, the organic EL device has a longer lifetime.

### Additional Layers of Organic EL Device

The organic EL device according to each of the first to third exemplary embodiments may include one or more organic layer(s) in addition to the first anode side organic layer, the second anode side organic layer, the third anode side organic layer, and the first emitting layer. Examples of the organic layer include, for instance, at least one layer selected from the group consisting of the above-described fourth anode side organic layer, the second emitting layer, the electron transporting layer, an electron injecting layer, a hole blocking layer, and an electron blocking layer.

The organic layers of the organic EL device according to each of the first to third exemplary embodiments may consist of the first anode side organic layer, the second anode side organic layer, the third anode side organic layer, and the emitting layer in the emitting region, alternatively, may further include, for instance, at least one layer selected from the group consisting of the fourth anode side organic layer, the second emitting layer, the electron injecting layer, the electron transporting layer, and the hole blocking layer.

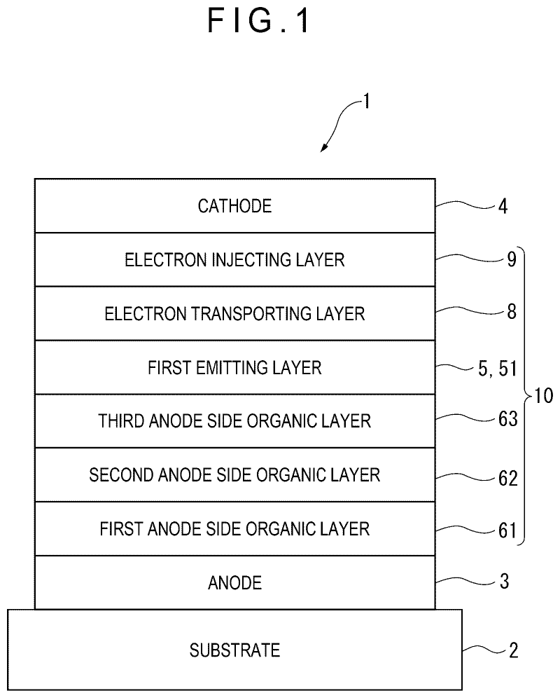

FIG. 1 schematically illustrates an exemplary arrangement of an organic EL device according to the first exemplary embodiment.

An organic EL device 1 includes a substrate 2, an anode 3, a cathode 4, and organic layers 10 provided between the anode 3 and the cathode 4. The organic layers 10 include a first anode side organic layer 61, a second anode side organic layer 62, a third anode side organic layer 63, a first emitting layer 51, an electron transporting layer 8, and an electron injecting layer 9, which are sequentially layered on the anode 3.

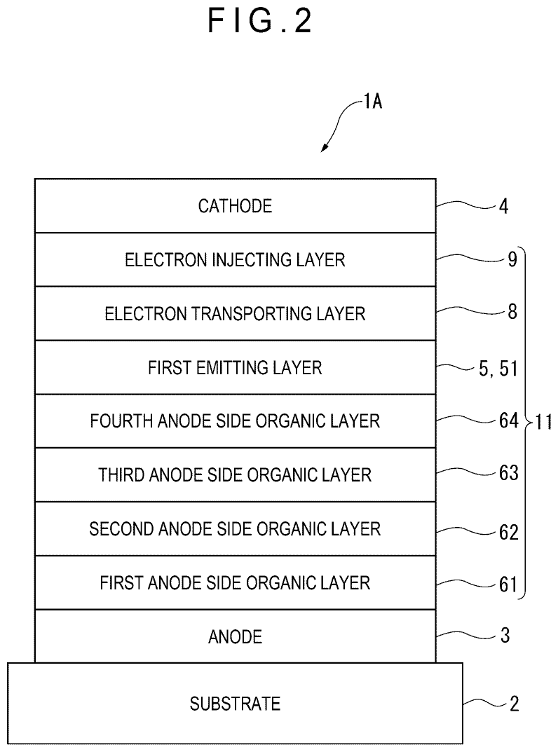

FIG. 2 schematically illustrates an exemplary arrangement of an organic EL device according to the first exemplary embodiment.

An organic EL device 1A includes the substrate 2, the anode 3, the cathode 4, and organic layers 11 provided between the anode 3 and the cathode 4. The organic layers 11 include the first anode side organic layer 61, the second anode side organic layer 62, the third anode side organic layer 63, a fourth anode side organic layer 64, the first emitting layer 51, the electron transporting layer 8, and the electron injecting layer 9, which are sequentially layered on the anode 3.

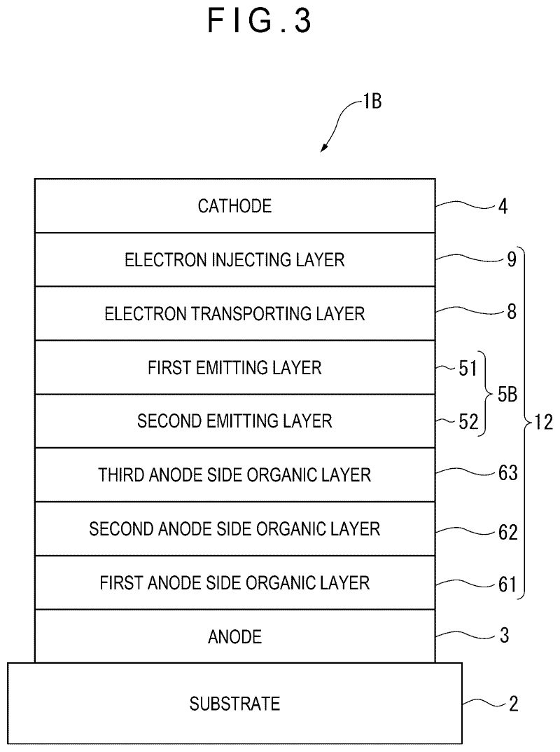

FIG. 3 schematically illustrates an exemplary arrangement of an organic EL device according to the first exemplary embodiment.

An organic EL device 1B includes the substrate 2, the anode 3, the cathode 4, and organic layers 12 provided between the anode 3 and the cathode 4. The organic layers 12 include the first anode side organic layer 61, the second anode side organic layer 62, the third anode side organic layer 63, a second emitting layer 52, the first emitting layer 51, the electron transporting layer 8, and the electron injecting layer 9, which are sequentially layered on the anode 3.

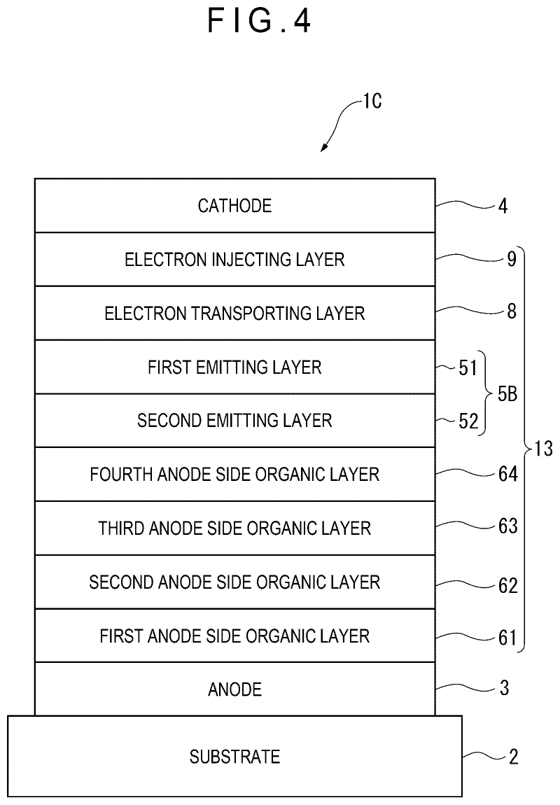

FIG. 4 schematically illustrates an exemplary arrangement of an organic EL device according to the first exemplary embodiment.

An organic EL device 1C includes the substrate 2, the anode 3, the cathode 4, and organic layers 13 provided between the anode 3 and the cathode 4. The organic layers 13 include the first anode side organic layer 61, the second anode side organic layer 62, the third anode side organic layer 63, the fourth anode side organic layer 64, the second emitting layer 52, the first emitting layer 51, the electron transporting layer 8, and the electron injecting layer 9, which are sequentially layered on the anode 3.

In the organic EL device 1 of FIG. 1 and the organic EL device 1A of FIG. 2, the emitting region 5 includes the first emitting layer 51.

In the organic EL device 1B of FIG. 3 and the organic EL device 1C of FIG. 4, an emitting region 5B includes the first emitting layer 51 and the second emitting layer 52.

In the organic EL device 1 of FIG. 1 and the organic EL device 1B of FIG. 3, the hole transporting zone includes the first anode side organic layer 61, the second anode side organic layer 62, and the third anode side organic layer 63.

In the organic EL device 1A of FIG. 2 and the organic EL device 1C of FIG. 4, the hole transporting zone includes the first anode side organic layer 61, the second anode side organic layer 62, the third anode side organic layer 63, and the fourth anode side organic layer 64.

The arrangements of the organic EL devices illustrated in FIGS. 1 to 4 are applicable to the organic EL devices of the second or third exemplary embodiment.

The invention is not limited to the exemplary arrangements of the organic EL devices illustrated in FIGS. 1 to 4. The organic EL device with any other arrangement is exemplified by an organic EL device in which the first emitting layer and the second emitting layer in the emitting region are layered in this order from a side close to the anode.

### Interposed Layer

In an exemplary arrangement of the organic EL device according to the exemplary embodiment, the emitting region when including the first emitting layer and the second emitting layer may include an interposed layer as an organic layer disposed between the first emitting layer and the second emitting layer.

In an exemplary embodiment, in order to inhibit an overlap between a Singlet emitting region and a TTF emitting region, the interposed layer contains no emitting compound or may contain an emitting compound in an insubstantial amount provided that the overlap can be inhibited.

For instance, the interposed layer contains 0 mass % of an emitting compound. Alternatively, for instance, the interposed layer may contain an emitting compound provided that the emitting compound contained is a component accidentally mixed in a producing process or a component contained as impurities in a material.

For instance, when the interposed layer consists of a material A, a material B, and a material C, the content ratios of the materials A, B, and C in the interposed layer are each 10 mass % or more, and the total of the content ratios of the materials A, B, and C is 100 mass %.

In the following, the interposed layer is occasionally referred to as a “non-doped layer”. A layer containing an emitting compound is occasionally referred to as a “doped layer”.

It is considered that luminous efficiency is improvable in an arrangement including layered emitting layers because the Singlet emitting region and the TTF emitting region are typically likely to be separated from each other.

In an exemplary arrangement of the organic EL device of the exemplary embodiment, when the interposed layer (non-doped layer) is disposed between the first emitting layer and the second emitting layer in the emitting region, it is expected that a region where the Singlet emitting region and the TTF emitting region overlap with each other is reduced to inhibit a decrease in TTF efficiency which may otherwise be caused by collision between triplet excitons and carriers. That is, it is considered that providing the interposed layer (non-doped layer) between the emitting layers contributes to the improvement in TTF emission efficiency.

The interposed layer is the non-doped layer.

The interposed layer contains no metal atom. The interposed layer thus contains no metal complex.

The interposed layer contains an interposed layer material. The interposed layer material is not an emitting compound.

The interposed layer material may be any material except for the emitting compound.

Examples of the interposed layer material include: 1) a heterocyclic compound such as an oxadiazole derivative, benzimidazole derivative, or phenanthroline derivative; 2) a fused aromatic compound such as a carbazole derivative, anthracene derivative, phenanthrene derivative, pyrene derivative or chrysene derivative; and 3) an aromatic amine compound such as a triarylamine derivative or a fused polycyclic aromatic amine derivative.

One or both of the first host material and the second host material may be used as the interposed layer material. The interposed layer material may be any material provided that the Singlet emitting region and the TTF emitting region are separated from each other and the Singlet emission and the TTF emission are not hindered.

In an exemplary arrangement of the organic EL device according to the exemplary embodiment, the respective content ratios of all the materials forming the interposed layer in the interposed layer are 10 mass % or more.

The interposed layer contains the interposed layer material as a material forming the interposed layer.

The interposed layer preferably contains 60 mass % or more of the interposed layer material, more preferably contains 70 mass % or more of the interposed layer material, still more preferably contains 80 mass % or more of the interposed layer material, still further more preferably 90 mass % or more of the interposed layer material, and yet still further more preferably 95 mass % or more of the interposed layer material, with respect to the total mass of the interposed layer.

The interposed layer may contain a single type of the interposed layer material or may contain two or more types of the interposed layer material.

When the interposed layer contains two or more types of the interposed layer material, the upper limit of the total of the content ratios of the two or more types of the interposed layer material is 100 mass %.

It should be noted that the interposed layer of the exemplary embodiment may further contain any other material than the interposed layer material.

The interposed layer may be provided in the form of a single layer or a laminate of two or more layers.

As long as the overlap between the Singlet emitting region and the TTF emitting region is inhibited, the film thickness of the interposed layer is not particularly limited, but each layer in the interposed layer is preferably in a range from 3 nm to 15 nm, more preferably in a range from 5 nm to 10 nm.

The interposed layer having a film thickness of 3 nm or more easily separates the Singlet emitting region from the emitting region derived from TTF.

The interposed layer having a film thickness of 15 nm or less easily inhibits a phenomenon in which the host material of the interposed layer emits light.

It is preferable that the interposed layer contains the interposed layer material as a material forming the interposed layer and the triplet energy of the first host material T₁(H1), the triplet energy of the second host material T₁(H2), and a triplet energy of at least one interposed layer material T₁(M_{mid}) satisfy a relationship of a numerical formula (Numerical Formula 21) below.

T₁(H2)≥T₁(M_{mid})≥T₁(H1) (Numerical Formula 21)

When the interposed layer contains two or more interposed layer materials as a material forming the interposed layer, the triplet energy of the first host material T₁(H1), the triplet energy of the second host material T₁(H2), and a triplet energy of each interposed layer material T₁(M_{EA}) more preferably satisfy a relationship of a numerical formula (Numerical Formula 21A) below.

T₁(H2)≥T₁(M_{EA})≥T₁(H1) (Numerical Formula 21A)

An exemplary arrangement of the organic EL device according to the exemplary embodiment may further include a diffusion layer.

When the exemplary arrangement of the organic EL device according to the exemplary embodiment includes the diffusion layer, the diffusion layer is preferably disposed between the first emitting layer and the second emitting layer.

The arrangement of the organic EL device will be further described below. It should be noted that the reference numerals are occasionally omitted below.

### Substrate

The substrate is used as a support for the organic EL device. For instance, glass, quartz, plastics and the like are usable for the substrate. A flexible substrate is also usable. The flexible substrate is a bendable substrate, which is exemplified by a plastic substrate. Examples of the material for the plastic substrate include polycarbonate, polyarylate, polyethersulfone, polypropylene, polyester, polyvinyl fluoride, polyvinyl chloride, polyimide, and polyethylene naphthalate. Further, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include ITO (Indium Tin Oxide), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the organic layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), alloys including the rare earth metal are also usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

### Cathode

It is preferable to use metal, an alloy, an electroconductive compound, a mixture thereof, or the like having a small work function (specifically, 3.8 eV or less) for the cathode. Examples of the material for the cathode include elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

### Electron Transporting Layer

In an exemplary arrangement of the organic EL device of the exemplary embodiment, the electron transporting layer is provided between the emitting region and the cathode.

The electron transporting layer is a layer containing a highly electron-transporting substance. For the electron transporting layer, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinato)aluminum (abbreviation: Almq₃), bis(10-hydroxybenzo[h]quinolinato)beryllium (abbreviation: BeBq₂), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In an exemplary arrangement of the exemplary embodiment, a nitrogen-containing compound (preferably benzimidazole compound) is usable. The above-described substances mostly have an electron mobility of 10⁻⁶ cm²/Vs or more. It should be noted that any other substance than the above substance may be used for the electron transporting layer as long as the substance exhibits a higher electron transportability than the hole transportability. The electron transporting layer may be provided in the form of a single layer or a laminate of two or more layers of the above substance(s).

Further, a high polymer compound is usable for the electron transporting layer. For instance, poly[(9,9-dihexylfluorene-2,7-diyl)-co-(pyridine-3,5-diyl)](abbreviation: PF-Py), poly[(9,9-dioctylfluorene-2,7-diyl)-co-(2,2′-bipyridine-6,6′-diyl)](abbreviation: PF-BPy) and the like are usable.

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

### Fourth Exemplary Embodiment

An organic electroluminescence display device (hereinafter also referred to as an organic EL display device) according to a fourth exemplary embodiment will be described below. In the description of the second exemplary embodiment, the same components as those in the first exemplary embodiment are denoted by the same reference signs and names to simplify or omit an explanation of the components. In the second exemplary embodiment, the same materials and compounds as described in the first exemplary embodiment are usable, unless otherwise specified.

### Organic Electroluminescence Display Device

An organic electroluminescence display device of the exemplary embodiment includes an anode and a cathode arranged opposite each other;
a first organic electroluminescence device as a first pixel and a second organic electroluminescence device as a second pixel;
the first pixel includes the organic electroluminescence device of the first exemplary embodiment as the first organic electroluminescence device;
the first organic electroluminescence device includes a first emitting region as the emitting region, and a first hole transporting zone as the hole transporting zone provided between the first emitting region and the anode;
the first anode side organic layer, the second anode side organic layer, and the third anode side organic layer are provided in a shared manner across the second organic electroluminescence device;
the first emitting layer of the first emitting region contains the first emitting compound;
the second organic electroluminescence device includes a second emitting region provided between the anode and the cathode, and a second hole transporting zone provided between the second emitting region and the anode;
the second hole transporting zone includes the first anode side organic layer, the second anode side organic layer, and the third anode side organic layer;
in the second hole transporting zone, the first anode side organic layer is in direct contact with the second anode side organic layer and the second anode side organic layer is in direct contact with the third anode side organic layer;
the first anode side organic layer, the second anode side organic layer, and the third anode side organic layer are arranged in this order from a side close to the anode between the anode and the second emitting region;
the second emitting region includes at least one emitting layer;
the at least one emitting layer of the second emitting region includes a third emitting layer;
the third emitting layer of the second emitting region contains a third emitting compound;
a maximum peak wavelength of the first emitting compound contained in the first emitting layer and a maximum peak wavelength of the third emitting compound contained in the third emitting layer are mutually the same or different; and
a refractive index NM₁ of a constituent material contained in the first anode side organic layer and a refractive index NM₂ of a constituent material contained in the second anode side organic layer satisfy a relationship of a numerical formula (Numerical Formula L1) below.

NM₁>NM₂ (Numerical Formula 1)

According to the organic EL display device of the exemplary embodiment, since the first pixel includes the organic EL display device of the first exemplary embodiment as the first organic EL device, the luminous efficiency of the first organic EL device is improved. As a result, the performance of the organic EL display device is improved.

In an exemplary arrangement of the organic EL display device of the exemplary embodiment, the maximum peak wavelength of the first emitting compound is different from the maximum peak wavelength of the third emitting compound.

In an exemplary arrangement of the organic EL display device of the exemplary embodiment, the maximum peak wavelength of the emitting compound contained in the emitting layer of the first emitting region is different from the maximum peak wavelength of the emitting compound contained in the emitting layer of the second emitting region.

In an exemplary arrangement of the organic EL display device of the exemplary embodiment, the maximum peak wavelength of the first emitting compound is shorter than the maximum peak wavelength of the third emitting compound.

In an exemplary arrangement of the organic EL display device of the exemplary embodiment, the maximum peak wavelength of the emitting compound contained in the emitting layer of the first emitting region is shorter than the maximum peak wavelength of the emitting compound contained in the emitting layer of the second emitting region.

An exemplary arrangement of the organic EL display device of the exemplary embodiment includes a fourth anode side organic layer between the third anode side organic layer and the first emitting layer in the first pixel.

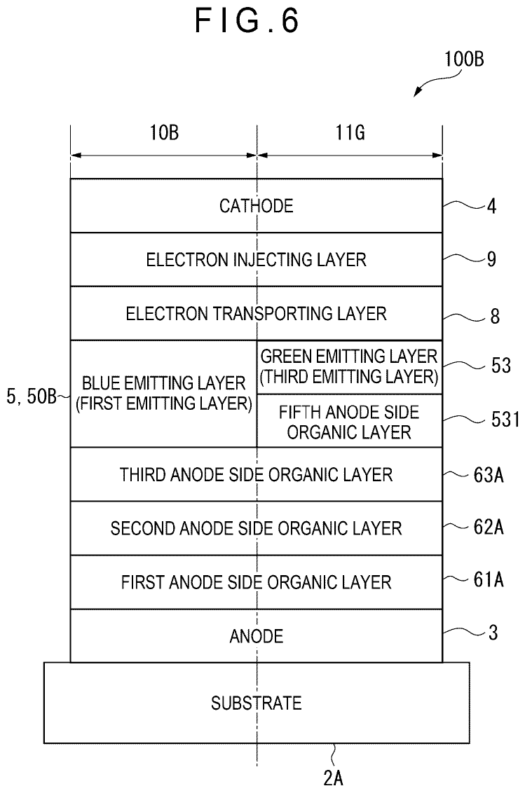

An exemplary arrangement of the organic EL display device of the exemplary embodiment includes a fifth anode side organic layer between the third anode side organic layer and the third emitting layer in the second pixel. For instance, in later-described cases illustrated in FIGS. 6 to 10, the fifth anode side organic layer is a layer corresponding to a fifth anode side organic layer 531.

In an exemplary arrangement of the organic EL display device of the exemplary embodiment, the first pixel and the second pixel are each independently a blue pixel, a green pixel or a red pixel.

In an exemplary arrangement of the organic EL display device of the exemplary embodiment, the first pixel is a blue pixel and the second pixel is a green pixel.

In an exemplary arrangement of the organic EL display device of the exemplary embodiment, the first pixel is a blue pixel and the second pixel is a red pixel.

For instance, when the first pixel is a blue pixel, the first organic EL device contained in the first pixel may be referred to as a blue-emitting organic EL device, the first emitting region contained in the blue-emitting organic EL device may be referred to as a blue emitting region, and the first emitting layer contained in the blue emitting region may be referred to as a blue emitting layer.

For instance, when the second pixel is a green pixel, the second organic EL device contained in the second pixel may be referred to as a green-emitting organic EL device, the second emitting region contained in the green-emitting organic EL device may be referred to as a green emitting region, and the third emitting layer contained in the green emitting region may be referred to as a green emitting layer.

### Organic EL Display Device of First Arrangement

In an organic EL display device of a first arrangement of the exemplary embodiment, the first pixel is a blue pixel and the second pixel is a green pixel.

For instance, the organic EL display device of the first arrangement of the exemplary embodiment includes an anode and a cathode arranged opposite each other;
a blue-emitting organic EL device as a blue pixel and a green-emitting organic EL device as a green pixel; and
the blue pixel includes the organic EL device of the first exemplary embodiment as the blue-emitting organic EL device, in which
the blue-emitting organic EL device includes a blue emitting region as a first emitting region, and a first hole transporting zone provided between the blue emitting region and the anode;
the first anode side organic layer, the second anode side organic layer, and the third anode side organic layer are provided in a shared manner across the green-emitting organic electroluminescence device;
a blue emitting layer as the first emitting layer of the blue emitting region contains the first emitting compound;
the green-emitting organic EL device includes a green emitting region as a second emitting region provided between the anode and the cathode, and a second hole transporting zone provided between the green emitting region and the anode;
the second hole transporting zone includes the first anode side organic layer, the second anode side organic layer, and the third anode side organic layer;
in the second hole transporting zone, the first anode side organic layer is in direct contact with the second anode side organic layer and the second anode side organic layer is in direct contact with the third anode side organic layer;
the first anode side organic layer, the second anode side organic layer, and the third anode side organic layer are arranged in this order from a side close to the anode between the anode and the green emitting region;
the green emitting region includes at least one emitting layer;
the at least one emitting layer in the green emitting region includes a green emitting layer as a third emitting layer;
the green emitting layer as the third emitting layer of the green emitting region contains the third emitting compound;
the maximum peak wavelength of the first emitting compound contained in the first emitting layer and the maximum peak wavelength of the third emitting compound contained in the third emitting layer are different; and
the refractive index NM₁ of the constituent material contained in the first anode side organic layer and the refractive index NM₂ of the constituent material contained in the second anode side organic layer satisfy the relationship of the numerical formula (Numerical Formula L1).

### Organic EL Display Device of Second Arrangement

In an organic EL display device of a second arrangement of the exemplary embodiment, the first pixel is a blue pixel and the second pixel is a red pixel.

For instance, the organic EL display device of the second arrangement of the exemplary embodiment includes an anode and a cathode arranged opposite each other, and a blue-emitting organic EL device as a blue pixel and a red-emitting organic EL device as a red pixel; and
the blue pixel includes the organic EL device of the first exemplary embodiment as the blue-emitting organic EL device, in which
the blue-emitting organic EL device includes a blue emitting region as a first emitting region, and a first hole transporting zone provided between the blue emitting region and the anode;
the first anode side organic layer, the second anode side organic layer, and the third anode side organic layer are provided in a shared manner across red-emitting organic electroluminescence device;
a blue emitting layer as the first emitting layer of the blue emitting region contains the first emitting compound;
the red-emitting organic EL device includes a red emitting region as a second emitting region provided between the anode and the cathode, and a second hole transporting zone provided between the red emitting region and the anode;
the second hole transporting zone includes the first anode side organic layer, the second anode side organic layer, and the third anode side organic layer;
in the second hole transporting zone, the first anode side organic layer is in direct contact with the second anode side organic layer and the second anode side organic layer is in direct contact with the third anode side organic layer;
the first anode side organic layer, the second anode side organic layer, and the third anode side organic layer are arranged in this order from a side close to the anode between the anode and the red emitting region;
the red emitting region includes at least one emitting layer;
the at least one emitting layer in the red emitting region includes a red emitting layer as a third emitting layer;
the red emitting layer as the third emitting layer in the red emitting region contains a third emitting compound;
the maximum peak wavelength of the first emitting compound contained in the blue emitting layer and the maximum peak wavelength of the third emitting compound contained in the red emitting layer are mutually different; and
the refractive index NM₁ of the constituent material contained in the first anode side organic layer and the refractive index NM₂ of the constituent material contained in the second anode side organic layer satisfy the relationship of the numerical formula (Numerical Formula L1).

An exemplary arrangement of the organic EL display device according to the exemplary embodiment further includes a third pixel. The third pixel is, for instance, a blue pixel, a green pixel or a red pixel.

For instance, when the third pixel is a red pixel, the third organic EL device contained in the third pixel may be referred to as a red-emitting organic EL device, the third emitting region contained in the red-emitting organic EL device may be referred to as a red emitting region, and a fourth emitting layer contained in the red emitting region may be referred to as a red emitting layer.

### Organic EL Display Device of Third Arrangement

In an organic EL display device of a third arrangement of the exemplary embodiment, the first pixel is a blue pixel, the second pixel is a green pixel, and the third pixel is a red pixel.

For instance, in the organic EL display device of the third arrangement of the exemplary embodiment,
the blue-emitting organic EL device as the first organic EL device represents the same as the blue-emitting organic EL device of the first arrangement, and
the green-emitting organic EL device as the second organic EL device represents the same as the green-emitting organic EL device of the first arrangement.

The red-emitting organic EL device as the third organic EL device includes a red emitting region as the third emitting region provided between the anode and the cathode, and a third hole transporting zone provided between the red emitting region and the anode;
the third hole transporting zone includes the first anode side organic layer, the second anode side organic layer, and the third anode side organic layer;
in the third hole transporting zone, the first anode side organic layer is in direct contact with the second anode side organic layer and the second anode side organic layer is in direct contact with the third anode side organic layer;
the first anode side organic layer, the second anode side organic layer, and the third anode side organic layer are arranged in this order from a side close to the anode between the anode and the red emitting region;
the red emitting region includes at least one emitting layer;
the at least one emitting layer in the red emitting region includes a red emitting layer as a fourth emitting layer;
the red emitting layer as the fourth emitting layer in the red emitting region contains a fourth emitting compound;
the maximum peak wavelength of the first emitting compound contained in the blue emitting layer and the maximum peak wavelength of the third emitting compound contained in the green emitting layer are same or different; and
the refractive index NM₁ of the constituent material contained in the first anode side organic layer and the refractive index NM₂ of the constituent material contained in the second anode side organic layer satisfy the relationship of the numerical formula (Numerical Formula L1).

The organic EL display device according to the first, second or third arrangement of the exemplary embodiment includes a fourth anode side organic layer between the third anode side organic layer and the blue emitting layer in the blue pixel. Thus, the blue-emitting organic EL device of the blue pixel has a longer lifetime.

The organic EL display device according to the first or third arrangement of the exemplary embodiment includes a fifth anode side organic layer between the third anode side organic layer and the green emitting layer in the green pixel. In later-described cases illustrated in FIGS. 6 to 10, the fifth anode side organic layer is a layer corresponding to the fifth anode side organic layer 531.

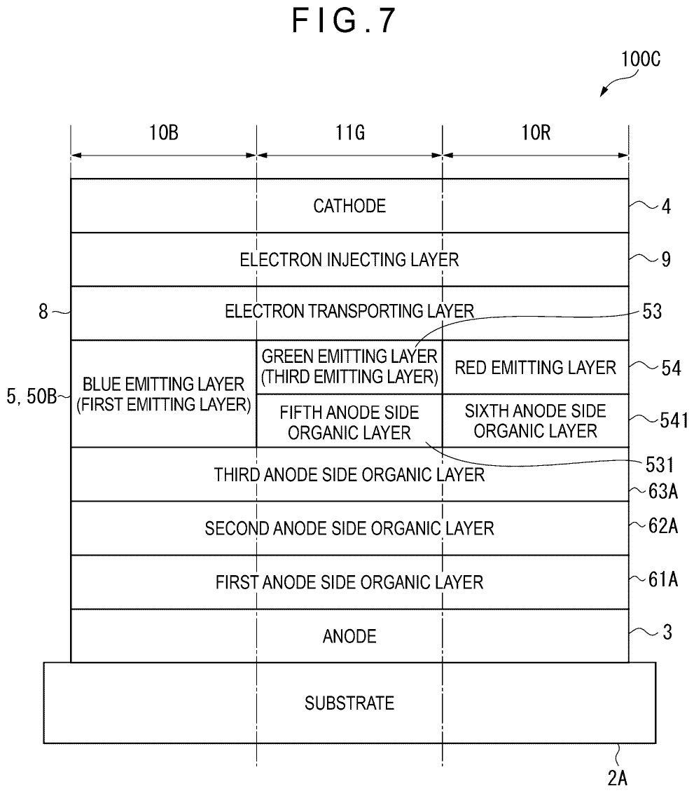

The organic EL display device according to the second or third arrangement of the exemplary embodiment includes a sixth anode side organic layer between the third anode side organic layer and the red emitting layer in the red pixel. In later-described cases illustrated in FIGS. 7 to 10, the sixth anode side organic layer is a layer corresponding to the sixth anode side organic layer 541.

The organic EL display device according to the first, second or third arrangement of the exemplary embodiment includes, as the blue-emitting organic EL device, the organic EL device according to an exemplary embodiment of the first exemplary embodiment, thereby improving the luminous efficiency of the blue-emitting organic EL device. As a result, the performance of the organic EL display device is improved.

Herein, a layer provided in a shared manner across a plurality of devices is occasionally referred to as a common layer. Herein, a layer not provided in a shared manner across a plurality of devices is occasionally referred to as a non-common layer.

Herein, a zone provided in a shared manner across a plurality of devices is occasionally referred to as a common zone. The hole transporting zone, which is provided between the anode and the blue emitting region of the blue-emitting organic EL device, the green emitting layer of the green-emitting organic EL device, and the red emitting layer of the red-emitting organic EL device in a shared manner across the blue-emitting organic EL device, the green-emitting organic EL device, and the red-emitting organic EL device, is a common zone.

Herein, “blue”, “green”, or “red” used for each element, such as “pixel”, “emitting layer”, or “material”, is used to distinguish one from another. Although “blue”, “green”, or “red” may represent a color of light emitted from “pixel”, “emitting layer”, or “material”, “blue”, “green”, or “red” does not mean the color of appearance of each element.

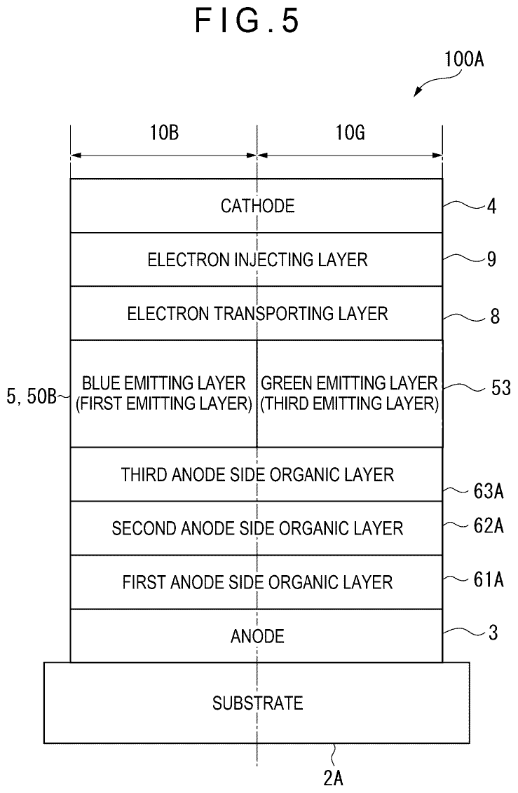

Referring to FIG. 5, explanation is made about an exemplary arrangement of the organic EL display device according to the fourth exemplary embodiment.

FIG. 5 illustrates an organic EL display device 100A according to an exemplary embodiment.

The organic EL display device 100A includes electrodes and organic layers supported by a substrate 2A.

The organic EL display device 100A includes the anode 3 and the cathode 4 arranged opposite each other.

The organic EL display device 100A includes a blue-emitting organic EL device 10B as a blue pixel, and a green organic EL device 10G as a green pixel.

It should be noted that FIG. 5 schematically illustrates the organic EL display device 100A, and thus does not limit, for instance, a thickness of each layer of the device 100A and a size of the device 100A. For instance, FIG. 5 illustrates that the blue emitting layer 51 and the green emitting layer 53 have the same thickness, but does not necessarily mean that these layers in an actual organic EL display device have the same thickness. The same applies to organic EL display devices illustrated in FIGS. 6 to 10.

In the blue-emitting organic EL device 10B and the green-emitting organic EL device 10G of the organic EL display device 100A, a hole transporting zone as the common zone is provided between the anode 3 and the respective emitting regions of the blue-emitting organic EL device 10B and the green-emitting organic EL device 10G.

In the hole transporting zone of the organic EL display device 100A, a first anode side organic layer 61A, a second anode side organic layer 62A, and a third anode side organic layer 63A are layered in this order from the side close to the anode 3. In the organic EL display device 100A, the hole transporting zone is provided in a shared manner across the blue-emitting organic EL device 10B and the green-emitting organic EL device 10G.

In the organic EL display device 100A, the electron transporting layer 8 and the electron injecting layer 9 as the common layers are layered in this order between the cathode and the respective emitting regions of the blue-emitting organic EL device 10B and the green-emitting organic EL device 10G.

A blue emitting region 5 of the blue-emitting organic EL device 10B of the organic EL display device 100A is similar to the emitting region 5 according to the first exemplary embodiment. The blue emitting region 5 includes a blue emitting layer 50B. The blue emitting layer 50B corresponds to the first emitting layer 51 according to the first exemplary embodiment.

The green emitting region of the green-emitting organic EL device 10G of the organic EL display device 100A includes the green emitting layer 53 (the third emitting layer).

The anode 3 is independently provided for each of the blue-emitting organic EL device 10B and the green-emitting organic EL device 10G. Thus, the blue-emitting organic EL device 10B and the green-emitting organic EL device 10G can be individually driven in the organic EL display device 100A. The respective anodes of the organic EL devices 10B, 10G are insulated from each other by an insulation material (not depicted). The cathode 4 is common provided for each of the blue-emitting organic EL device 10B and the green-emitting organic EL device 10G.

In an exemplary embodiment, the blue-emitting organic EL device 10B and the green-emitting organic EL device 10G as pixels are arranged in parallel with each other on the substrate 2A.

FIG. 6 schematically illustrates another exemplary arrangement of the organic EL display device according to the second exemplary embodiment.

An organic EL display device 100B illustrated in FIG. 6 is configured the same as the organic EL display device 100A illustrated in FIG. 5 except for a green-emitting organic EL device 11G as a green pixel. Thus, only differences from the organic EL display device 100A are described below.

The green-emitting organic EL device 11G includes the fifth anode side organic layer 531 as a non-common layer between the green emitting layer 53 and the third anode side organic layer 63A. In a case illustrated in FIG. 6, the fifth anode side organic layer 531 is in direct contact with the green emitting layer 53 and the third anode side organic layer 63A. The fifth anode side organic layer 531 is preferably an electron blocking layer.

FIG. 7 schematically illustrates another exemplary arrangement of the organic EL display device according to the second exemplary embodiment.

An organic EL display device 100C illustrated in FIG. 7 is configured the same as the organic EL display device 100B illustrated in FIG. 6 except for including the red-emitting organic EL device 10R as a red pixel. Thus, only differences from the organic EL display device 100B are described below.

In the blue-emitting organic EL device 10B, the green-emitting organic EL device 11G, and the red-emitting organic EL device 10R of the organic EL display device 100C, a hole transporting zone as the common zone is provided between the anode 3 and the respective emitting regions of the blue-emitting organic EL device 10B, the green-emitting organic EL device 11G, and the red-emitting organic EL device 10R.

In the hole transporting zone of the organic EL display device 100C, the hole transporting zone (the first anode side organic layer 61A, the second anode side organic layer 62A, and the third anode side organic layer 63A) is provided in a shared manner across the blue-emitting organic EL device 10B, the green-emitting organic EL device 11G, and the red-emitting organic EL device 10R.

The red emitting region of the red-emitting organic EL device 10R of the organic EL display device 1000 includes the red emitting layer 54. In the red-emitting organic EL device 10R, the six anode side organic layer 541 as the non-common layer is provided between the red emitting layer 54 and the third anode side organic layer 63A.

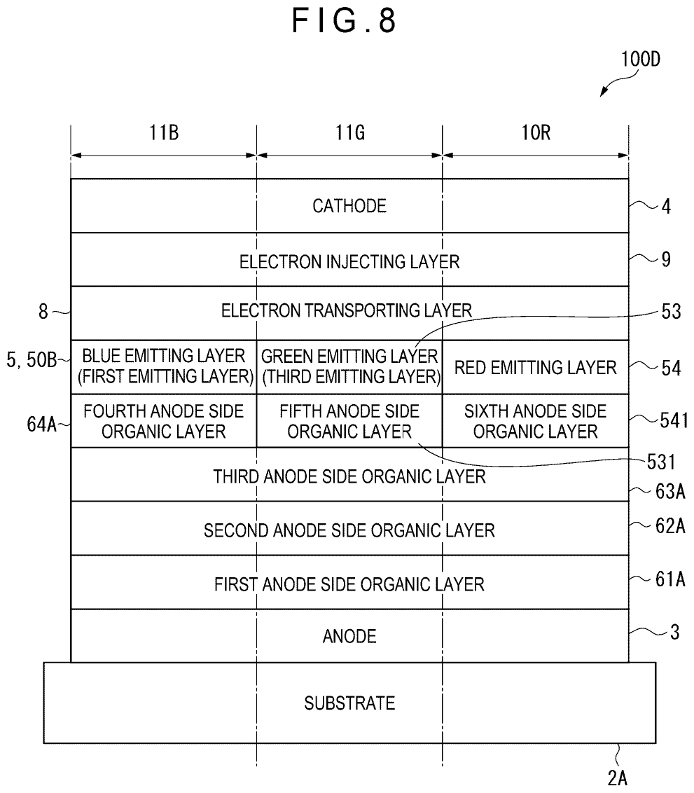

FIG. 8 schematically illustrates another exemplary arrangement of the organic EL display device according to the second exemplary embodiment.

An organic EL display device 100D illustrated in FIG. 8 is configured the same as the organic EL display device 100C illustrated in FIG. 7 except for the blue-emitting organic EL device 11B as a blue pixel. Thus, only differences from the organic EL display device 100C are described below.

The blue-emitting organic EL device 11B includes a fourth anode side organic layer 64A as the non-common layer between the blue emitting layer 50B and the third anode side organic layer 63A. In FIG. 8, the fourth anode side organic layer 64A is in direct contact with the blue emitting layer 50B and the third anode side organic layer 63A. The fourth anode side organic layer 64A is preferably an electron blocking layer.

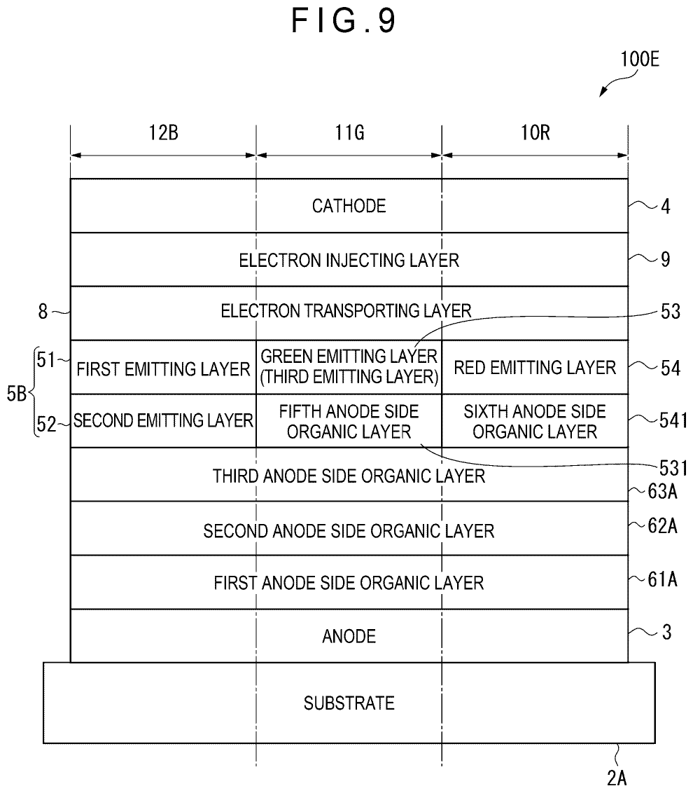

FIG. 9 schematically illustrates another exemplary arrangement of the organic EL display device according to the second exemplary embodiment.

An organic EL display device 100E illustrated in FIG. 9 is configured the same as the organic EL display device 100C illustrated in FIG. 7 except for the blue-emitting organic EL device 12B as a blue pixel. Thus, only differences from the organic EL display device 100C are described below.

A blue emitting region 5B of the blue-emitting organic EL device 12B is similar to the emitting region 5B of the first exemplary embodiment. The blue emitting region 5B includes the first emitting layer 51 and the second emitting layer 52. The second emitting layer 52 and the first emitting layer 51 are layered in this order from a side close to the anode.

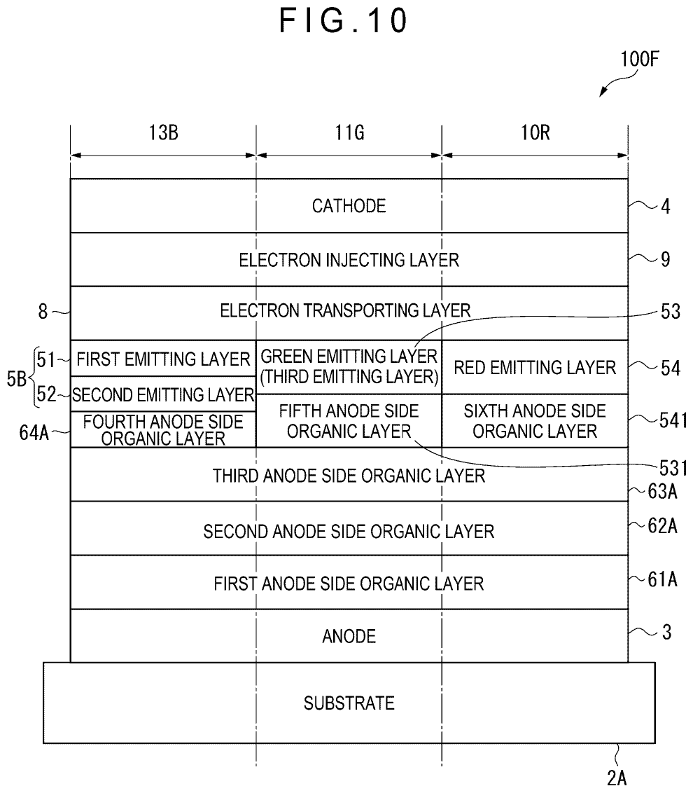

FIG. 10 schematically illustrates another exemplary arrangement of the organic EL display device according to the second exemplary embodiment.

An organic EL display device 100F illustrated in FIG. 10 is configured the same as the organic EL display device 100E illustrated in FIG. 9 except for the blue-emitting organic EL device 13B as a blue pixel. Thus, only differences from the organic EL display device 100E are described below.

The blue-emitting organic EL device 13B includes the fourth anode side organic layer 64A as the non-common layer between the second emitting layer 52 of the blue emitting region 5B and the third anode side organic layer 63A. In a case illustrated in FIG. 10, the fourth anode side organic layer 64A is in direct contact with the second emitting layer 52 and the third anode side organic layer 63A. The fourth anode side organic layer 64A is preferably an electron blocking layer.

The invention is not limited to the arrangements of the organic EL display device illustrated in FIGS. 5 to 10.

For instance, in an exemplary arrangement of the organic EL display device of the exemplary embodiment, the sixth anode side organic layer 541 is not provided between the red emitting layer 54 and the third anode side organic layer 63A, and the red emitting layer 54 is in direct contact with the third anode side organic layer 63A.

For instance, in FIG. 5, the green emitting layer as the third emitting layer may be replaced with the red emitting layer. In FIG. 6, the green emitting layer as the third emitting layer may be replaced with the red emitting layer and the fifth anode side organic layer may be replaced with the sixth anode side organic layer.

For instance, in an exemplary arrangement of the organic EL display device of the second exemplary embodiment, the blue-emitting organic EL device, the green-emitting organic EL device, and the red-emitting organic EL device may each independently further include a layer different from the layers illustrated in FIGS. 5 to 10. For instance, a hole blocking layer may be provided as the common layer between the emitting regions and the electron transporting layer.

For instance, in an exemplary arrangement of the organic EL display device of the second exemplary embodiment, the blue-emitting organic EL device, the green-emitting organic EL device, and the red-emitting organic EL device may be each independently a device that fluoresces or a device that phosphoresces. The blue-emitting organic EL device is preferably a device that fluoresces.

In an exemplary arrangement of the organic EL display device of the second exemplary embodiment, the third anode side organic layer as the common layer contains a third hole transporting zone material, and a hole mobility of the third hole transporting zone material μh(cHT3) is larger than 1.0×10⁻⁵ cm²/Vs, and an energy level of a highest occupied molecular orbital of the third hole transporting zone material HOMO(cHT3) is −5.6 eV or less. When the third anode side organic layer as the common layer contains the third hole transporting zone material having such a hole mobility and HOMO, hole injectability to the emitting regions of the blue pixel, the green pixel, and the red pixel is improved. Further, when the organic EL display device includes the fourth anode side organic layer, the fifth anode side organic layer 531, and the sixth anode side organic layer 541, the hole injectability to those layers is high.

In an exemplary arrangement of the organic EL display device of the second exemplary embodiment, the first anode side organic layer as the common layer contains the first hole transporting zone material of the first exemplary embodiment.

In an exemplary arrangement of the organic EL display device of the second exemplary embodiment, the second anode side organic layer as the common layer contains the second hole transporting zone material of the first exemplary embodiment.

In an exemplary arrangement of the organic EL display device of the exemplary embodiment, the third anode side organic layer as the common layer contains the third hole transporting zone material of the first exemplary embodiment.

In an exemplary arrangement of the organic EL display device of the second exemplary embodiment, the fourth anode side organic layer as the non-common layer contains the fourth hole transporting zone material of the first exemplary embodiment.

In an exemplary arrangement of the organic EL display device of the second exemplary embodiment, the green emitting layer contains a host material. For instance, the green emitting layer contains 50 mass % or more of the host material with respect to the total mass of the green emitting layer.

In an exemplary arrangement of the organic EL display device of the second exemplary embodiment, the green emitting layer of the green-emitting organic EL device contains a green emitting compound that emits light having a maximum peak wavelength in a range from 500 nm to 550 nm. For instance, the green emitting compound is a fluorescent compound that exhibits fluorescence having a maximum peak wavelength in a range from 500 nm to 550 nm. For instance, the green emitting compound is a phosphorescent compound that exhibits phosphorescence having a maximum peak wavelength in a range from 500 nm to 550 nm. Herein, the green light emission refers to light emission in which a maximum peak wavelength of emission spectrum is in a range from 500 nm to 550 nm.

The fluorescent compound is a compound capable of emitting in a singlet state. The phosphorescent compound is a compound capable of emitting in a triplet state.

Examples of a green fluorescent compound usable for the green emitting layer include an aromatic amine derivative. Examples of a green phosphorescent compound usable for the green emitting layer include an iridium complex.

### Maximum Phosphorescence Peak Wavelength (PH-Peak)

A maximum peak wavelength (maximum phosphorescence peak wavelength) of a phosphorescent compound is measurable by the following method. A measurement target compound is dissolved in EPA (diethylether:isopentane:ethanol=5:5:2 in volume ratio) so as to fall within a range from 10⁻⁵ mol/L to 10⁻⁴ mol/L, and the obtained EPA solution is encapsulated in a quartz cell to provide a measurement sample. A phosphorescence spectrum (ordinate axis: phosphorescent luminous intensity, abscissa axis: wavelength) of the measurement sample is measured at a low temperature (77K). The local maximum value closest to the short-wavelength region among the local maximum values of the phosphorescence spectrum is defined as the maximum phosphorescence peak wavelength. A spectrophotofluorometer F-7000 produced by Hitachi High-Tech Science Corporation can be used to measure phosphorescence. The measurement apparatus is not limited to this arrangement. A combination of a cooling unit, a low temperature container, an excitation light source and a light-receiving unit may be used for measurement. Herein, the maximum peak wavelength of phosphorescence is occasionally referred to as the maximum phosphorescence peak wavelength (PH-peak).

In an exemplary arrangement of the organic EL display device of the exemplary embodiment, the green-emitting organic EL device includes the fifth anode side organic layer between the green emitting layer and the third anode side organic layer. The fifth anode side organic layer may be in direct contact with the hole transporting zone. The fifth anode side organic layer may be in direct contact with the green emitting layer. An emission position in the green-emitting organic EL device is easily adjustable by providing the fifth anode side organic layer in the green-emitting organic EL device.

The fifth anode side organic layer contains, for instance, a green organic material. The hole transporting zone material according to the first exemplary embodiment is usable as the green organic material. Although the green organic material and the hole transporting zone material contained in the hole transporting zone may be the same compound or different compounds, the green organic material is preferably different from the hole transporting zone material. The hole mobility of the green organic material is preferably larger than the hole mobility of the hole transporting zone material contained in the hole transporting zone. The green organic material is a compound different from the host material and the green emitting compound contained in the green emitting layer.

In an exemplary arrangement of the organic EL display device of the second exemplary embodiment, the red emitting layer contains a host material. For instance, the red emitting layer contains 50 mass % or more of the host material with respect to the total mass of the red emitting layer.

In an exemplary arrangement of the organic EL display device of the second exemplary embodiment, the red emitting layer of the red organic EL device contains a red emitting compound that emits light having a maximum peak wavelength in a range from 600 nm to 640 nm. For instance, the red emitting compound is a fluorescent compound that exhibits fluorescence having a maximum peak wavelength in a range from 600 nm to 640 nm. For instance, the red emitting compound is a phosphorescent compound that exhibits phosphorescence having a maximum peak wavelength in a range from 600 nm to 640 nm. Herein, the red light emission refers to light emission in which a maximum peak wavelength of emission spectrum is in a range from 600 nm to 640 nm.

Examples of a red fluorescent compound usable for the red emitting layer include a tetracene derivative and a diamine derivative. Examples of a red phosphorescent compound usable for the red emitting layer include metal complexes such as an iridium complex, platinum complex, terbium complex, and europium complex.

In an exemplary arrangement of the organic EL display device of the exemplary embodiment, the red-emitting organic EL device preferably includes the sixth anode side organic layer between the red emitting layer and the third anode side organic layer. The sixth anode side organic layer may be in direct contact with the hole transporting zone. The sixth anode side organic layer may be in direct contact with the red emitting layer. In an exemplary arrangement of the organic EL display device of the exemplary embodiment, an emission position in the red-emitting organic EL device is easily adjustable by providing the six anode side organic layer in the red-emitting organic EL device.

The sixth anode side organic layer contains, for instance, a red organic material. The hole transporting zone material according to the first exemplary embodiment is usable as the red organic material. Although the red organic material and the hole transporting zone material contained in the hole transporting zone may be the same compound or different compounds, the red organic material is preferably different from the hole transporting zone material. The hole mobility of the red organic material is preferably larger than the hole mobility of the hole transporting zone material contained in the hole transporting zone. The red organic material is a compound different from the host material and the red emitting compound contained in the red emitting layer.

Although the red organic material contained in the sixth anode side organic layer of the red-emitting organic EL device and the green organic material contained in the fifth anode side organic layer of the green-emitting organic EL device may be the same compound or different compounds, the red organic material is preferably different from the green organic material. The hole mobility of the red organic material is preferably larger than the hole mobility of the green organic material.

In an exemplary arrangement of the organic EL display device of the exemplary embodiment, the film thickness of the sixth anode side organic layer is preferably larger than the film thickness of the fifth anode side organic layer.

In an exemplary arrangement of the organic EL display device of the second exemplary embodiment, the host material contained in the green emitting layer and the host material contained in the red emitting layer are, for instance, a compound for dispersing a highly emittable substance (dopant material) in the emitting layers. As the host material contained in the green emitting layer and the host material contained in the red emitting layer, it is possible to use, for instance, a substance having a higher Lowest Unoccupied Molecular Orbital (LUMO) level and a lower Highest Occupied Molecular Orbital (HOMO) level than the highly emittable substance.

For instance, the following compounds (1) to (4) can be each independently used as the host material contained in the green emitting layer and the host material contained in the red emitting layer.
(1) a metal complex such as an aluminum complex, beryllium complex, and zinc complex
(2) a heterocyclic compound such as an oxadiazole derivative, benzimidazole derivative, or phenanthroline derivative
(3) a fused aromatic compound such as a carbazole derivative, anthracene derivative, phenanthrene derivative, pyrene derivative or chrysene derivative
(4) an aromatic amine compound such as a triarylamine derivative or a fused polycyclic aromatic amine derivative

Referring to FIG. 6, the organic EL display device according to the second exemplary embodiment is further explained. Descriptions on the same arrangements as those of the organic EL device according to the first exemplary embodiment are simplified or omitted.

### Anode

In an exemplary embodiment, the anode 3 is arranged opposite to the cathode 4.

In an exemplary embodiment, the anode 3 is typically the non-common layer. In an exemplary embodiment, for instance, when the anode 3 is the non-common layer, the respective anodes in the blue-emitting organic EL device 10B, the green-emitting organic EL device 11G and the red-emitting organic EL device 10R are physically separated from each other, and specifically, may be insulated from each other by an insulation material (not illustrated in the drawings) or the like.

### Cathode

In an exemplary embodiment, the cathode 4 is arranged opposite to the anode 3.

In an exemplary embodiment, the cathode 4 may be the common layer or the non-common layer.

In an exemplary embodiment, the cathode 4 is preferably the common layer provided in a shared manner across the blue-emitting organic EL device 10B, the green-emitting organic EL device 11G, and the red-emitting organic EL device 10R.

In an exemplary embodiment, the cathode 4 is in direct contact with the electron injecting layer 9.

In an exemplary embodiment, when the cathode 4 is the common layer, the film thickness of the cathode 4 is constant over the blue-emitting organic EL device 10B, the green-emitting organic EL device 11G, and the red-emitting organic EL device 10R. When the cathode 4 is the common layer, the cathode 4 provided for the blue-emitting organic EL device 10B, the green-emitting organic EL device 11G, and the red-emitting organic EL device 10R can be produced without changing a mask or the like. The organic EL display device 100B thus has enhanced productivity.

### Electron Transporting Layer

In an exemplary embodiment, the electron transporting layer 8 is the common layer provided in a shared manner across the blue-emitting organic EL device 10B, the green-emitting organic EL device 11G, and the red-emitting organic EL device 10R.

In an exemplary embodiment, the electron transporting layer 8 is provided between the electron injecting layer 9 and the emitting layers of the blue-emitting organic EL device 10B, the green-emitting organic EL device 11G, and the red-emitting organic EL device 10R.

In an exemplary embodiment, the side of the electron transporting layer 8 close to the anode 3 is in direct contact with the second emitting layer 52, the green emitting layer 53, and the red emitting layer 54.

The side of the electron transporting layer 8 close to the cathode 4 is in direct contact with the electron injecting layer 9.

In an exemplary embodiment, the electron transporting layer 8 is the common layer. In this case, the film thickness of the electron transporting layer 8 is constant over the blue-emitting organic EL device 10B, the green-emitting organic EL device 11G, and the red-emitting organic EL device 10R. When the electron transporting layer 8 is the common layer, the electron transporting layer 8 provided for the blue-emitting organic EL device 10B, the green-emitting organic EL device 11G, and the red-emitting organic EL device 10R can be produced without changing a mask or the like. The organic EL display device 100A thus has enhanced productivity.

### Electron Injecting Layer

In an exemplary embodiment, the electron injecting layer 9 is the common layer provided in a shared manner across the blue-emitting organic EL device 10B, the green-emitting organic EL device 11G, and the red-emitting organic EL device 10R.

In an exemplary embodiment, the electron injecting layer 9 is disposed between the electron transporting layer 8 and the cathode 4.

In an exemplary embodiment, the electron injecting layer 9 is in direct contact with the electron transporting layer 8.

In an exemplary embodiment, the electron injecting layer 9 is the common layer. In this case, the film thickness of the electron injecting layer 9 is constant over the blue-emitting organic EL device 10B, the green-emitting organic EL device 11G, and the red-emitting organic EL device 10R. When the electron injecting layer 9 is the common layer, the electron injecting layer 9 provided for the blue-emitting organic EL device 10B, the green-emitting organic EL device 11G, and the red-emitting organic EL device 10R can be produced without changing a mask or the like. The organic EL display device 100A thus has enhanced productivity.

In an exemplary embodiment, any other layer than the emitting layer(s), the first emitting layer, the second emitting layer, the fourth anode side organic layer, the green emitting layer, the red emitting layer, the fifth anode side organic layer, and the sixth anode side organic layer is preferably provided in a shared manner across the blue-emitting organic EL device, the green-emitting organic EL device, and the red-emitting organic EL device. Reducing the number of the non-common layers in the organic EL display device improves productivity of the device.

### Method of Producing Organic EL Display Device

As an exemplary method of producing the organic EL display device of the exemplary embodiment, explanation is made about a method of producing the organic EL display device 100B illustrated in FIG. 6.

First, the anode 3 is formed on the substrate 2A.

Subsequently, the anode side organic layers as the common layers (first anode side organic layer 61A, second anode side organic layer 62A, and third anode side organic layer 63A) are sequentially formed in a shared manner across the anode 3, forming the hole transporting zone as the common zone. Respective organic layers in the hole transporting zone of the blue-emitting organic EL device 10B, the green-emitting organic EL device 11G, and the red-emitting organic EL device 10R are formed to have the same film thickness.

Subsequently, the blue emitting layer 50B is formed on the third anode side organic layer 63A in a region corresponding to the anode 3 of the blue-emitting organic EL device 10B using a predetermined film-forming mask (mask for the blue-emitting organic EL device).

Subsequently, the fifth anode side organic layer 531 is formed on the third anode side organic layer 63A in a region corresponding to the anode 3 of the green-emitting organic EL device 11G using a predetermined film-forming mask (mask for the green-emitting organic EL device). Subsequent to formation of the fifth anode side organic layer 531, the green emitting layer 53 is formed on the fifth anode side organic layer 531.

Subsequently, the sixth anode side organic layer 541 is formed on the third anode side organic layer 63A in a region corresponding to the anode 3 of the red-emitting organic EL device 10R using a predetermined film-forming mask (mask for the red-emitting organic EL device). Subsequent to formation of the sixth anode side organic layer 541, the red emitting layer 54 is formed on the sixth anode side organic layer 541.

The emitting layer 50, the green emitting layer 53, and the red emitting layer 54 are formed from mutually different materials.

After the formation of the third anode side organic layer 63A, the order of forming the non-common layers of the blue-emitting organic EL device 10B, the green-emitting organic EL device 11G, and the red-emitting organic EL device 10R is not particularly limited.

For instance, after forming the third anode side organic layer 63A, the fifth anode side organic layer 531 and the green emitting layer 53 of the green-emitting organic EL device 11G may be formed, then the anode side organic layer 541 and the red emitting layer 54 of the red-emitting organic EL device 10R may be formed, and then the blue emitting layer 50B of the blue-emitting organic EL device 10B may be formed.

Alternatively, for instance, after forming the third anode side organic layer 63A, the anode side organic layer 541 and the red emitting layer 54 of the red-emitting organic EL device 10R may be formed, then the fifth anode side organic layer 531 and the green emitting layer 53 of the green-emitting organic EL device 11G may be formed, and then the blue emitting layer 50B of the blue-emitting organic EL device 10B may be formed.

Subsequently, the electron transporting layer 8 as the common layer is formed in a shared manner across the blue emitting layer 50B, the green emitting layer 53, and the red emitting layer 54. The electron transporting layer 8 of the blue-emitting organic EL device 10B, the green-emitting organic EL device 11G, and the red-emitting organic EL device 10R is formed to have a constant film thickness using the same material.

Subsequently, the electron injecting layer 9 as the common layer is formed on the electron transporting layer 8. The electron injecting layer 9 of the blue-emitting organic EL device 10B, the green-emitting organic EL device 11G, and the red-emitting organic EL device 10R is formed to have a constant film thickness using the same material.

Subsequently, the cathode 4 as the common layer is formed on the electron injecting layer 9. The cathode 4 of the blue-emitting organic EL device 10B, the green-emitting organic EL device 11G, and the red-emitting organic EL device 10R is formed to have a constant film thickness using the same material.

The organic EL display device 100B illustrated in FIG. 6 is produced as described above.

The organic EL display device 100D illustrated in FIG. 8 is different from the organic EL display device 100B illustrated in FIG. 6 in that the organic EL display device 100D includes the fourth anode side organic layer 64A. In producing the organic EL display device 100D illustrated in FIG. 8, the fourth anode side organic layer 64A is formed on the third anode side organic layer 63A in a region corresponding to the anode 3 of the blue-emitting organic EL device 11B using a predetermined film-forming mask (mask for the blue-emitting organic EL device). Subsequently, the blue emitting layer 50B is formed on the fourth anode side organic layer 64A. Any other producing steps of the organic EL display device 100D are similar to those of the organic EL display device 100B.

The organic EL display device 100E illustrated in FIG. 9 is different from the organic EL display device 100B illustrated in FIG. 6 in that the emitting region 5B includes the first emitting layer 51 and the second emitting layer 52. In producing the organic EL display device 100E illustrated in FIG. 9, the second emitting layer 52 is formed on the third anode side organic layer 63A in a region corresponding to the anode 3 of the blue-emitting organic EL device 12B using a predetermined film-forming mask (mask for the blue-emitting organic EL device). Subsequently, the first emitting layer 51 is formed on the second emitting layer 52. After that, the electron transporting layer 8 as the common layer is formed in a shared manner across the first emitting layer 51, the green emitting layer 53, and the red emitting layer 54. Any other producing steps of the organic EL display device 100E are similar to those of the organic EL display device 100B.

The organic EL display device 100F illustrated in FIG. 10 is different from the organic EL display device 100E illustrated in FIG. 9 in that the organic EL display device 100D includes the fourth anode side organic layer 64A. In producing the organic EL display device 100F illustrated in FIG. 10, the fourth anode side organic layer 64A is formed on the third anode side organic layer 63A in a region corresponding to the anode 3 of the blue-emitting organic EL device 13B using a predetermined film-forming mask (mask for the blue-emitting organic EL device). Subsequently, the second emitting layer 52 is formed on the fourth anode side organic layer 64A. After that, the first emitting layer 51 is formed on the second emitting layer 52.

Any other producing steps of the organic EL display device 100F are similar to those of the organic EL display device 100E.

Organic electroluminescence devices according to other exemplary embodiments 1, 2 are described below. In the description of the organic EL devices according to other exemplary embodiments 1, 2, the same constituent elements as those in the first exemplary embodiment are denoted by the same reference signs and names to simplify or omit an explanation of the constituent elements. In other exemplary embodiments 1, 2, the same materials and compounds as those described in the first exemplary embodiment are usable, unless otherwise specified.

### Other Exemplary Embodiment 1

### Organic Electroluminescence Device

An organic EL device according to other exemplary embodiment 1 includes a cathode, an anode, an emitting region provided between the cathode and the anode, a first anode side organic layer, a second anode side organic layer, and a third anode side organic layer, in which the emitting region includes at least one emitting layer, the first anode side organic layer, the second anode side organic layer, and the third anode side organic layer are arranged between the anode and the emitting region in this order from a side close to the anode, the third anode side organic layer does not contain a compound contained in the second anode side organic layer, a total of a film thickness of the second anode side organic layer and a film thickness of the third anode side organic layer is in range from 30 nm to 150 nm, and a ratio of the film thickness of the third anode side organic layer to the film thickness of the second anode side organic layer satisfies a relationship of a numerical formula (Numerical Formula A1) below.

0.50<TL₃/TL₂<4.0 (Numerical Formula A1)

where TL₂ is a film thickness of the second anode side organic layer, TL₃ is a film thickness of the third anode side organic layer, and a unit of the film thickness is denoted by nm.

### Other Exemplary Embodiment 2

### Organic Electroluminescence Device

An organic EL device according to other exemplary embodiment 2 includes a cathode, an anode, an emitting region provided between the cathode and the anode, and a hole transporting zone provided between the anode and the emitting region, in which the emitting region includes at least one emitting layer, the hole transporting zone includes at least a second anode side organic layer and a third anode side organic layer, the second anode side organic layer and the third anode side organic layer are arranged between the anode and the emitting region in this order from a side close to the anode, the second anode side organic layer contains at least one compound selected from the group consisting of a compound represented by the formula (C1) and a compound represented by a formula (C3) below, the third anode side organic layer contains a compound represented by the formula (C1), here, the second anode side organic layer contains at least one compound different from the compound contained in the third anode side organic layer, a difference NM₂−NM₃ between a refractive index NM₂ of a constituent material contained in the second anode side organic layer and a refractive index NM₃ of a constituent material contained in the third anode side organic layer satisfies a relationship of a numerical formula (Numerical Formula N1) below, and a distance from an interface at a side close to the anode of the third anode side organic layer to an interface at a side close to the anode of an emitting layer disposed closest to the anode in the emitting region is 20 nm or more.

NM₂−NM₃≥0.05 (Numerical Formula N1)

The organic EL device according to other exemplary embodiment 2 has the following features.

The organic EL device according to other exemplary embodiment 2 may not include the first anode side organic layer. However, the hole transporting zone of the organic EL device according to the other exemplary embodiment 2 may include the first anode side organic layer. In this case, the first anode side organic layer is disposed between the anode and the second anode side organic layer.

In the organic EL device according to other exemplary embodiment 2, the second anode side organic layer and the third anode side organic layer contain predetermined compounds, respectively. It should be noted that the second anode side organic layer contains at least one compound different from the compound contained in the third anode side organic layer. For instance, when the second anode side organic layer contains two types of compounds (compound AA and compound AB) and the third anode side organic layer contains a single type of compound (compound AA), the compound AB is different from the compound AA contained in the third anode side organic layer. Thus, this case satisfies the condition “the second anode side organic layer contains at least one compound different from the compound contained in the third anode side organic layer”.

In the organic EL device according to other exemplary embodiment 2, the difference NM₂−NM₃ between the refractive index NM₂ of the constituent material contained in the second anode side organic layer and the refractive index NM₃ of the constituent material contained in the third anode side organic layer satisfies the relationship of the numerical formula (Numerical Formula N1) (NM₂−NM₃≥0.05).

In the organic EL device according to other exemplary embodiment 2, a distance from the interface at the side close to the anode of the third anode side organic layer to the interface at the side close to the anode of the emitting layer disposed closest to the anode in the emitting region is 20 nm or more.

Any other features of the organic EL devices according to other exemplary embodiments are the same as those of the organic EL device according to the first exemplary embodiment, and thus all the arrangements of the organic EL device described in the first exemplary embodiment are applicable to the organic EL devices according to other exemplary embodiments.

The compound represented by the formula (C1) in the organic EL device according to other exemplary embodiment 2 represents the same as the compound represented by the formula (C1) described in the first exemplary embodiment.

The compound represented by the formula (C3) in the organic EL device according to other exemplary embodiment 2 represents the same as the compound represented by the formula (C3) described in the first exemplary embodiment.

In an exemplary arrangement of the organic EL device of other exemplary embodiment 2, the second anode side organic layer contains a monoamine compound or a diamine compound, and the third anode side organic layer contains a monoamine compound and does not contain a diamine compound.

The organic EL device according to other exemplary embodiment 2 also has enhanced light-extraction efficiency when the second anode side organic layer and the third anode side organic layer satisfy the relationship of the numerical formula (Numerical Formula N1) (NM₂−NM₃≥0.05). Further, the light-extraction efficiency is readily improved by making the distance from the interface at the side close to the anode of the third anode side organic layer to the interface at the side close to the anode of the emitting layer disposed closest to the anode in the emitting region, 20 nm or more.

### Other Exemplary Embodiment 3

### Organic Electroluminescence Display Device

An organic EL display device according to other exemplary embodiment 3 includes an anode and a cathode arranged opposite each other,
a blue-emitting organic EL device as a blue pixel; a green-emitting organic EL device as a green pixel; and a red-emitting organic EL device as a red pixel, in which
the blue pixel includes the organic electroluminescence device according to other exemplary embodiment 1 or 2 as the blue-emitting organic EL device,
the green-emitting organic EL device includes a green emitting region provided between the anode and the cathode,
the red-emitting organic EL device includes a red emitting region provided between the anode and the cathode,
when the blue-emitting organic EL device includes the first anode side organic layer, the second anode side organic layer, and the third anode side organic layer, the first anode side organic layer, the second anode side organic layer, and the third anode side organic layer are provided between the anode and each of the emitting region of the blue-emitting organic EL device, the green emitting region, and the red emitting region, in a shared manner across the blue-emitting organic EL device, the green-emitting organic EL device, and the red-emitting organic EL device, and
when the blue-emitting organic EL device does not include the first anode side organic layer but includes the second anode side organic layer and the third anode side organic layer, the second anode side organic layer and the third anode side organic layer are provided between the anode and each of the emitting region of the blue-emitting organic EL device, the green emitting region, and the red emitting region, in a shared manner across the blue-emitting organic EL device, the green-emitting organic EL device, and the red-emitting organic EL device.

Since the blue pixel of the organic EL display device according to other exemplary embodiment 3 includes the organic EL device of other exemplary embodiment 1 or 2, the blue-emitting organic EL device of the blue pixel has an improved light-extraction efficiency. As a result, the performance of the organic EL display device is improved.

### Fifth Exemplary Embodiment

### Electronic Device

An electronic device according to a sixth exemplary embodiment is installed with the organic EL device according to any of the above exemplary embodiments or the organic EL display device according to any of the above exemplary embodiments. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light.

### Modification of Embodiment(s)

The scope of the invention is not limited by the above-described exemplary embodiments but includes any modification and improvement as long as such modification and improvement are compatible with the invention.

For instance, the number of emitting layers is not limited to one or two, and more than two emitting layers may be layered. For instance, the rest of the emitting layers may be a fluorescent emitting layer or a phosphorescent emitting layer with use of emission caused by electron transfer from the triplet excited state directly to the ground state. When the organic EL device includes a plurality of emitting layers, these emitting layers may be in direct contact with each other, or may form a so-called tandem organic EL device, in which a plurality of emitting units are layered via an intermediate layer (sometimes referred to as a charge generating layer or the like).

Further, for instance, a blocking layer is optionally provided adjacent to a side of the emitting layer close to the cathode. The blocking layer provided in direct contact with the side of the emitting layer close to the cathode preferably blocks at least one of holes or excitons.

For instance, when the blocking layer is provided in contact with the side of the emitting layer close to the cathode, the blocking layer permits transport of electrons, and blocks holes from reaching a layer provided closer to the cathode (e.g., the electron transporting layer) beyond the blocking layer. When the organic EL device includes the electron transporting layer, the blocking layer may be disposed between the emitting layer and the electron transporting layer.

Alternatively, the blocking layer may be provided adjacent to the emitting layer so that the excitation energy does not leak out from the emitting layer toward neighboring layer(s). The blocking layer blocks excitons generated in the emitting layer from being transferred to a layer(s) closer to the electrode(s) (e.g., the electron transporting layer and the like) beyond the blocking layer. The emitting layer is preferably in direct contact with the blocking layer.

Specific structure, shape and the like of the components in the invention may be designed in any manner as long as an object of the invention can be achieved.

The invention will be described in more detail below with reference to Examples. The scope of the invention is by no means limited to Examples.

### EXAMPLES

Compounds

Structures of compounds used for producing organic EL devices in Examples are shown below.

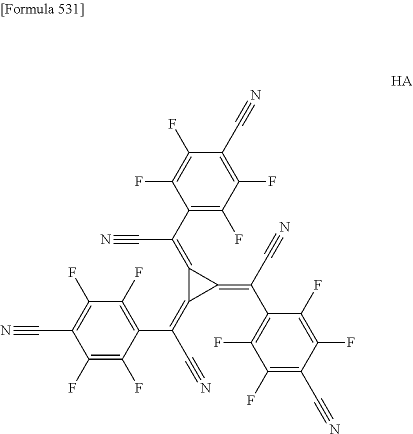 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

Structures of compounds used as the first hole transporting zone material, the second hole transporting zone material, the third hole transporting zone material, and the fourth hole transporting zone material for producing organic EL devices in Examples are shown below.

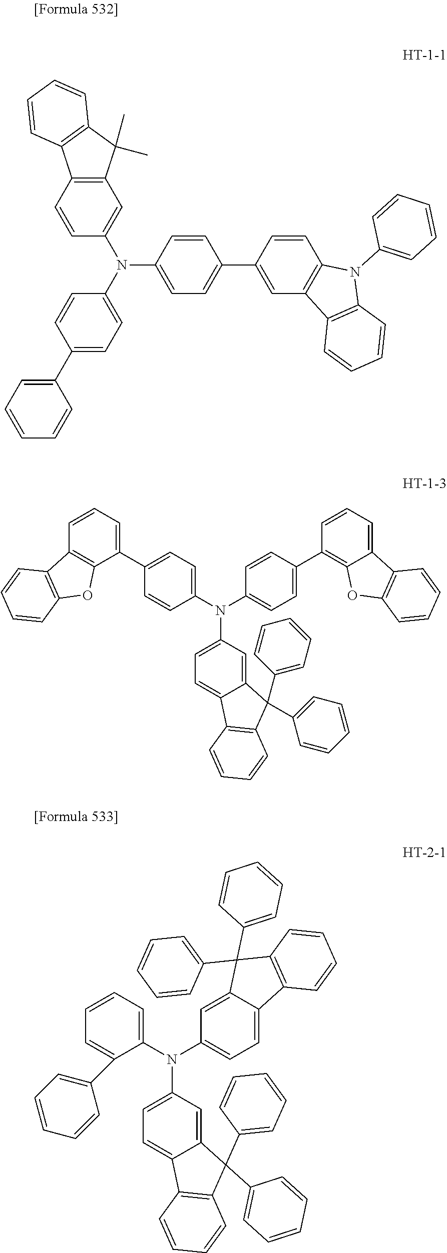 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1]

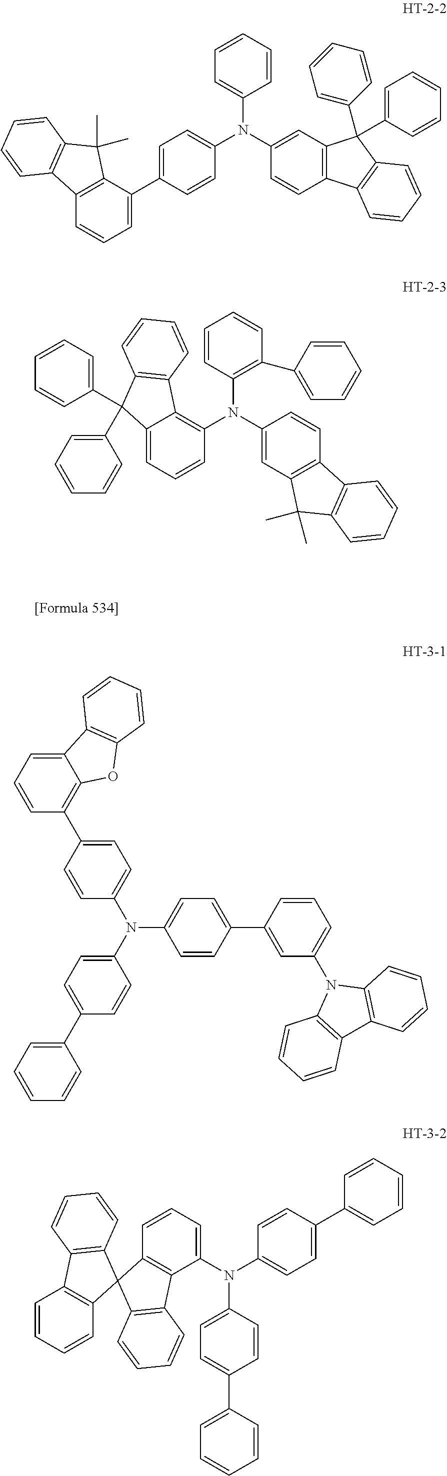 [SMILES: CC1(C)c2ccccc2-c2cccc(-c3ccc(N(c4ccccc4)c4ccc5c(c4)C(c4ccccc4)(c4ccccc4)c4ccccc4-5)cc3)c21 ; CC1(C)c2ccccc2-c2ccc(N(c3ccccc3-c3ccccc3)c3cccc4c3-c3ccccc3C4(c3ccccc3)c3ccccc3)cc21 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1 ; c1ccc(-c2ccc(N(c3ccc(-c4ccccc4)cc3)c3cccc4c3-c3ccccc3C43c4ccccc4-c4ccccc43)cc2)cc1]

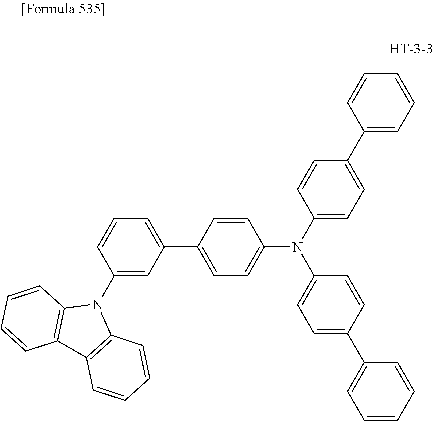 [SMILES: c1ccc(-c2ccc(N(c3ccc(-c4ccccc4)cc3)c3ccc(-c4cccc(-n5c6ccccc6c6ccccc65)c4)cc3)cc2)cc1]

Structures of other compounds used for producing organic EL devices in Examples are shown below.

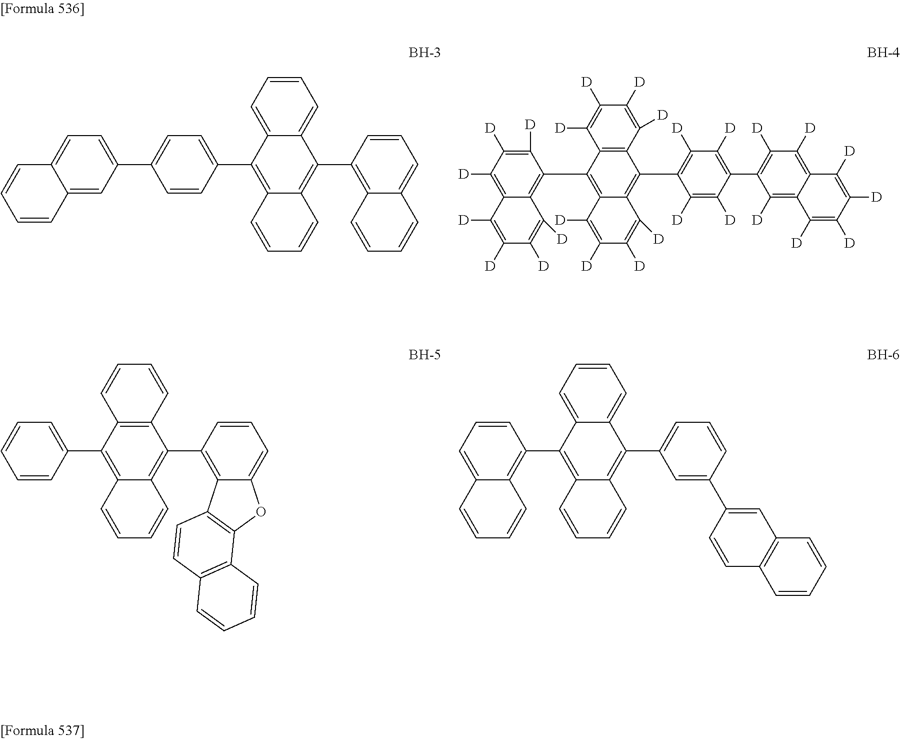

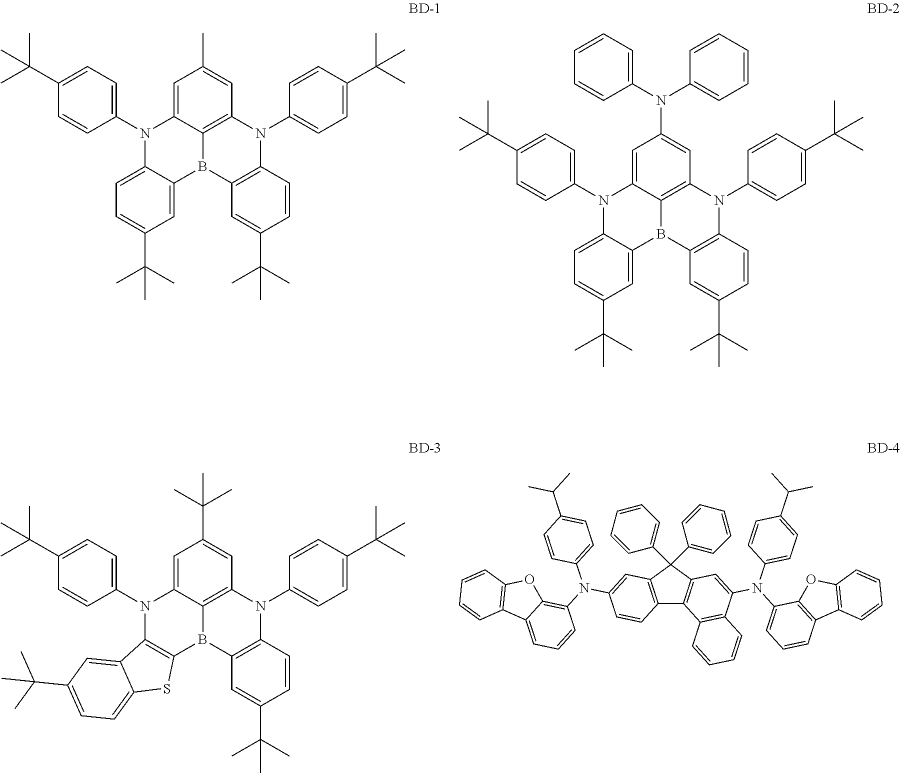 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1 ; CC(C)(C)c1ccc(N2c3ccc(C(C)(C)C)cc3B3c4sc5ccc(C(C)(C)C)cc5c4N(c4ccc(C(C)(C)C)cc4)c4cc(C(C)(C)C)cc2c43)cc1 ; CC(C)c1ccc(N(c2ccc3c(c2)C(c2ccccc2)(c2ccccc2)c2cc(N(c4ccc(C(C)C)cc4)c4cccc5c4oc4ccccc45)c4ccccc4c2-3)c2cccc3c2oc2ccccc23)cc1]

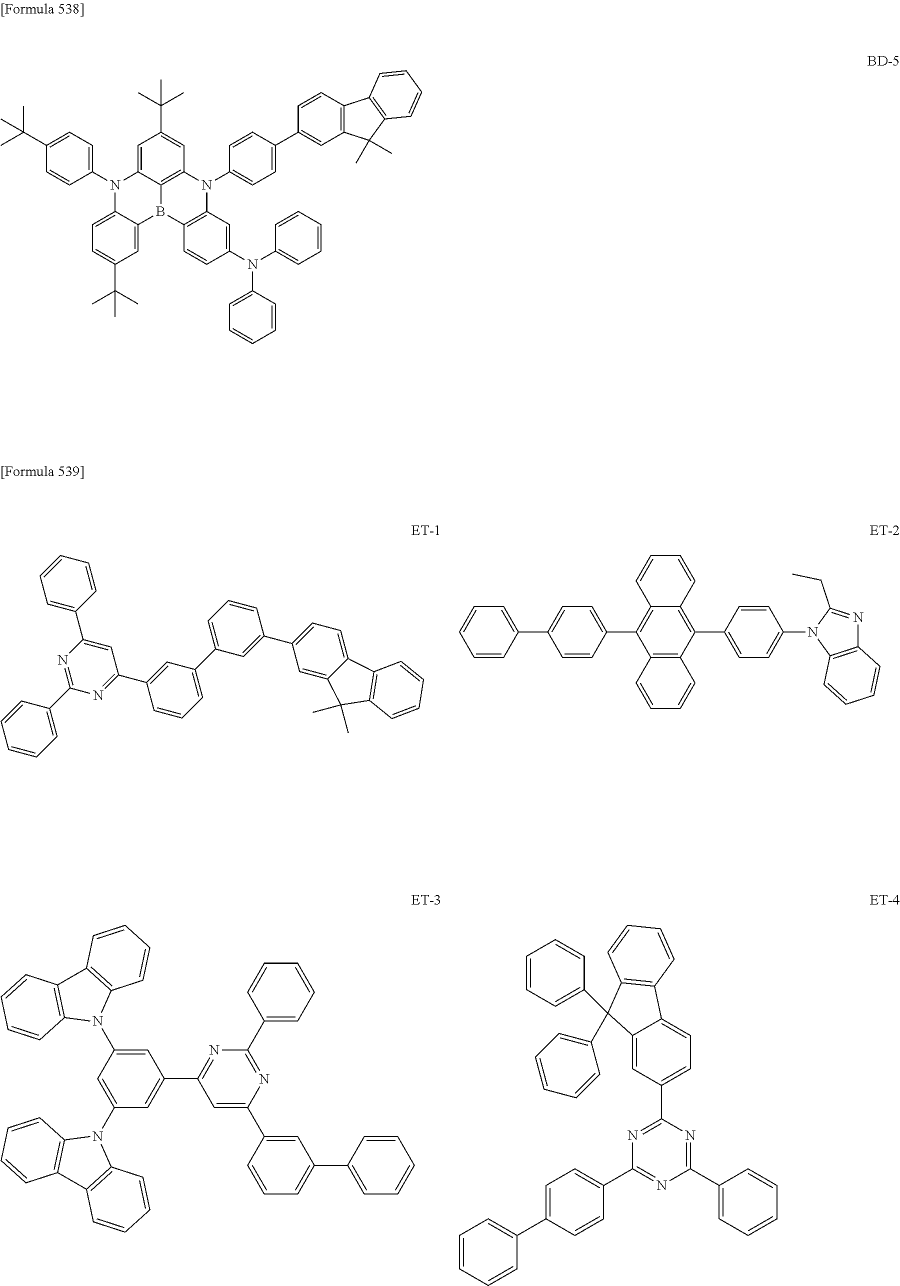 [SMILES: CC(C)(C)c1ccc(N2c3ccc(C(C)(C)C)cc3B3c4ccc(N(c5ccccc5)c5ccccc5)cc4N(c4ccc(-c5ccc6c(c5)C(C)(C)c5ccccc5-6)cc4)c4cc(C(C)(C)C)cc2c43)cc1 ; CC1(C)c2ccccc2-c2ccc(-c3cccc(-c4cccc(-c5cc(-c6ccccc6)nc(-c6ccccc6)n5)c4)c3)cc21 ; CCc1nc2ccccc2n1-c1ccc(-c2c3ccccc3c(-c3ccc(-c4ccccc4)cc3)c3ccccc23)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2ccc(-c3nc(-c4ccccc4)nc(-c4ccc5c(c4)C(c4ccccc4)(c4ccccc4)c4ccccc4-5)n3)cc2)cc1]

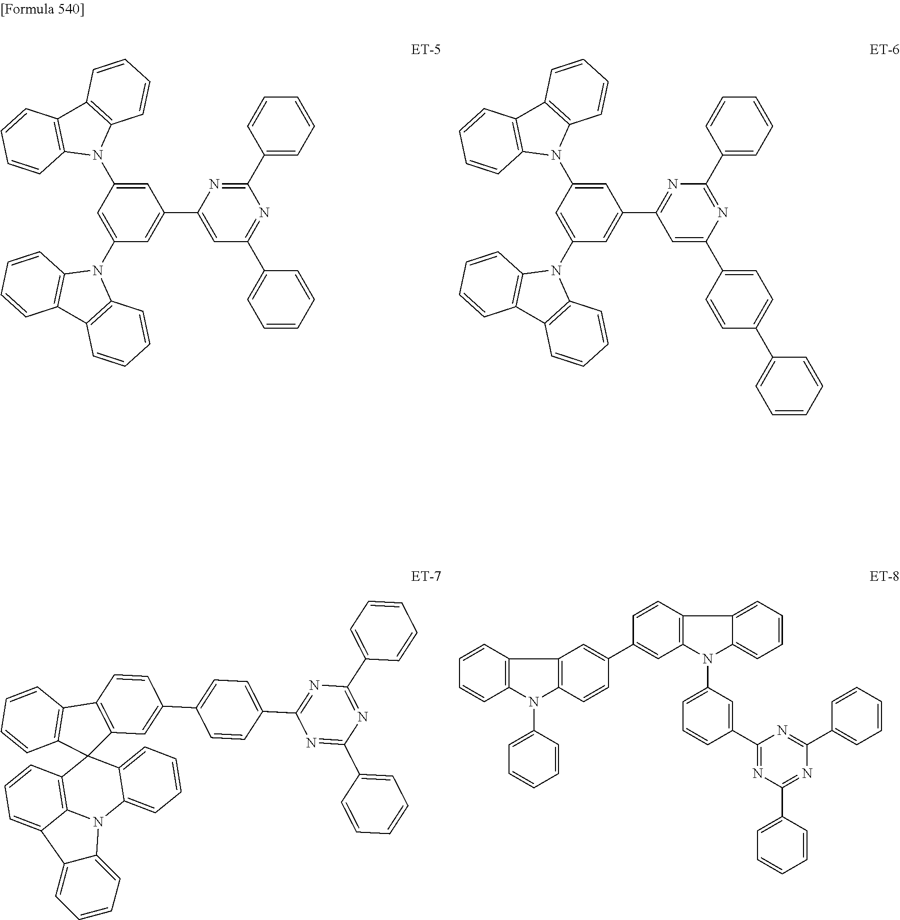 [SMILES: c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2nc(-c3ccccc3)nc(-c3ccc(-c4ccc5c(c4)C4(c6ccccc6-5)c5ccccc5-n5c6ccccc6c6cccc4c65)cc3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

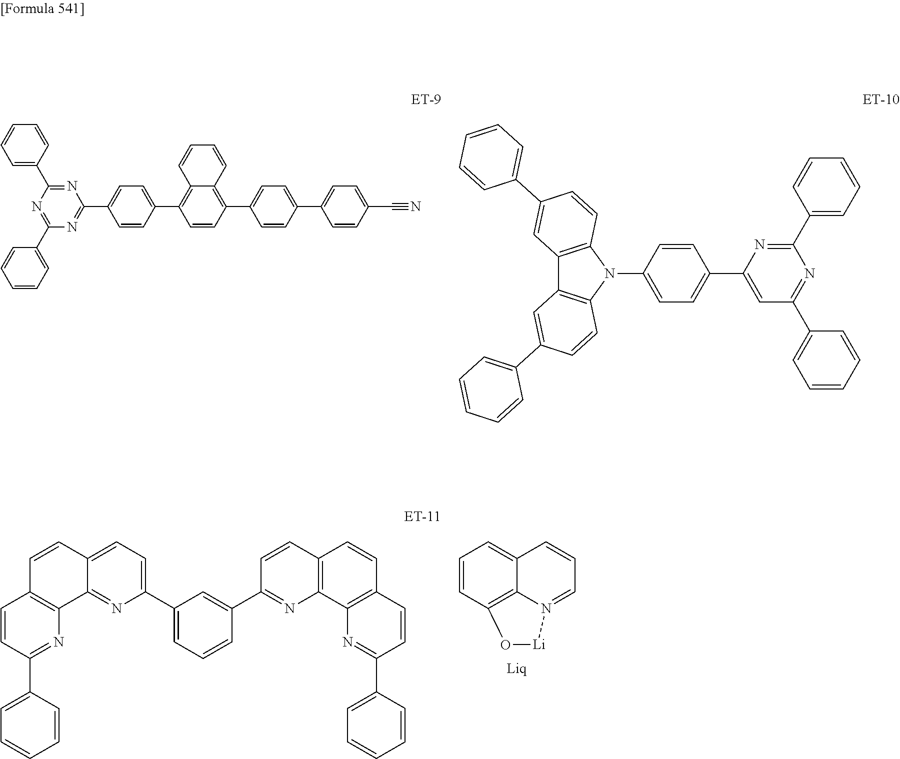

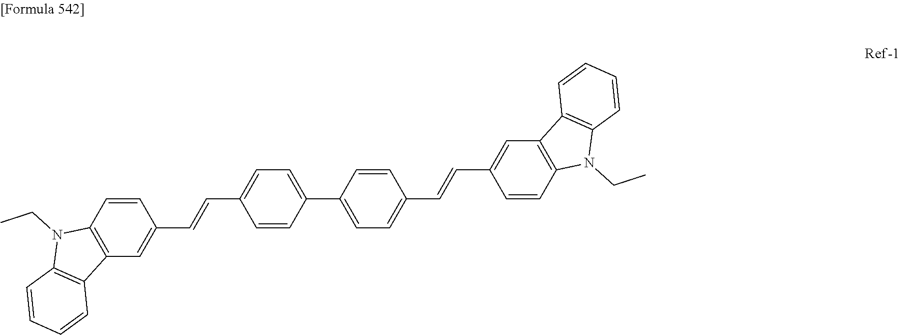 [SMILES: CCn1c2ccccc2c2cc(/C=C/c3ccc(-c4ccc(/C=C/c5ccc6c(c5)c5ccccc5n6CC)cc4)cc3)ccc21]

### Production of Organic EL Device

The organic EL devices were produced and evaluated as follows.

### Example 1-1

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, a compound HT-1-1 (second organic material) and a compound HA1 (first organic material) were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-1-1 and the compound HA in the first anode side organic layer were 97 mass % and 3 mass %, respectively.

The compound HT-1-1 (second hole transporting zone material) was vapor-deposited on the first anode side organic layer to form a 40-nm-thick second anode side organic layer (occasionally also referred to as a first hole transporting layer).

A compound HT-2-1 (third hole transporting zone material) was vapor-deposited on the second anode side organic layer to form a 40-nm-thick third anode side organic layer (occasionally also referred to as a second hole transporting layer).

A compound HT-3-1 (fourth hole transporting zone material) was vapor-deposited on the third anode side organic layer to form a 5-nm-thick fourth anode side organic layer (occasionally also referred to as a third hole transporting layer).

A compound BH-3 (first host material) and a compound BD-1 (first emitting compound) were co-deposited on the fourth anode side organic layer to form a 25-nm-thick first emitting layer. The ratios of the compound BH-3 and the compound BD-1 in the first emitting layer were 97 mass % and 3 mass %, respectively.

A compound ET-6 was vapor-deposited on the first emitting layer to form a 10-nm-thick first electron transporting layer (occasionally also referred to as a hole blocking layer (HBL)).

A compound ET-2 were-deposited on the first electron transporting layer to form a 15-nm-thick second electron transporting layer (ET).

A compound LiF was vapor-deposited on the second electron transporting layer to form a 1-nm-thick electron injecting layer.

Metal (Al) was vapor-deposited on the electron injecting layer to form an 80-nm-thick cathode.

A device arrangement of the organic EL device in Example 1-1 is roughly shown as follows.
ITO(130)/HT-1-1:HA(10,97%:3%)/HT-1-1(40)/HT-2-1(40)/HT-3-1(5)/BH-3:BD-1(25,97%:3%)/ET-6(10)/ET-2(15)/LiF(1)/Al(80)

Numerals in parentheses represent a film thickness (unit: nm).

The numerals (97%:3%) represented by percentage in the same parentheses indicate a ratio (mass %) between the compound HT-1-1 and the compound HA in the first anode side organic layer. The numerals (97%:3%) represented by percentage in the same parentheses indicate a ratio (mass %) between the first host material (compound BH-3) and the first emitting compound (compound BD-1) in the first emitting layer.

### Examples 1-2 to 1-3

The organic EL devices in Examples 1-2 to 1-3 were each produced in the same manner as in Example 1-1 except that the compound BD-1 contained in the first emitting layer was replaced with compounds shown in Table 1.

### Comparative 1-1

The organic EL device in Comparative 1-1 was produced in the same manner as the organic EL device in Example 1-1 except that the compound HT-2-1 contained in the third anode side organic layer was replaced with a compound shown in Table 1 and the compound BD-1 contained in the first emitting layer was replaced with a compound shown in Table 1.

### Comparative 1-2

The organic EL device in Comparative 1-2 was produced in the same manner as the organic EL device in Example 1-2 except that the compound HT-2-1 contained in the third anode side organic layer was replaced with a compound shown in Table 1.

### Evaluation of Organic EL Devices

The organic EL devices produced were evaluated as follows. Tables 1 to 4 show evaluation results.

### Drive Voltage

The voltage (unit: V) when electric current was applied to between the anode and the cathode so that the current density was 10 mA/cm² was measured.

### External Quantum Efficiency EQE

Voltage was applied to the organic EL devices such that a current density was 10 mA/cm², where spectral radiance spectrum was measured with a spectroradiometer CS-2000 (produced by Konica Minolta, Inc.). The external quantum efficiency EQE (unit: %) was calculated based on the obtained spectral radiance spectra, assuming that the spectra was provided under a Lambertian radiation.

### Lifetime LT95

Voltage was applied to the produced organic EL device such that a current density was 50 mA/cm², where a time (LT95 (unit: hr)) elapsed before a luminance intensity was reduced to 95% of the initial luminance intensity was measured as a lifetime. The luminance intensity was measured with a spectroradiometer CS-2000 (manufactured by Konica Minolta, Inc.).

TABLE 1

| | Hole transporting zone | | | | | | | | | | | | |
|---|---|---|---|---|---|---|---|---|---|---|---|---|---|
| | | | | | Second anode | | | Third anode side | | | Fourth anode side | | |
| | First anode side organic layer | | | | side organic layer | | | organic layer | | | organic layer | | |
| | | | | Film | Second hole | Refrac- | Film | Third hole | Refrac- | Film | Fourth hole | Film | Refractive |
| | First | Seccond | Refractive | thick- | transporting | tive | thick- | transporting | tive | thick- | transporting | thick- | index |
| | organic | organic | index | ness | zone | index | ness | zone | index | ness | zone | ness | difference |
| | material | material | NM₁ | [nm] | material | NM₂ | [nm] | material | NM₃ | [nm] | material | [nm] | NM₂-NM₃ |
| Ex. 1-1 | HA | HT-1-1 | 1.94 | 10 | HT-1-1 | 1.94 | 40 | HT-2-1 | 1.85 | 40 | HT-3-1 | 5 | 0.09 |
| Ex. 1-2 | HA | HT-1-1 | 1.94 | 10 | HT-1-1 | 1.94 | 40 | HT-2-1 | 1.85 | 40 | HT-3-1 | 5 | 0.09 |
| Ex. 1-3 | HA | HT-1-1 | 1.94 | 10 | HT-1-1 | 1.94 | 40 | HT-2-1 | 1.85 | 40 | HT-3-1 | 5 | 0.09 |
| Comp. 1-1 | HA | HT-1-1 | 1.94 | 10 | HT-1-1 | 1.94 | 40 | HT-1-1 | 1.94 | 40 | HT-3-1 | 5 | 0.00 |
| Comp. 1-2 | HA | HT-1-1 | 1.94 | 10 | HT-1-1 | 1.94 | 40 | HT-1-1 | 1.94 | 40 | HT-3-1 | 5 | 0.00 |
| | | | | Electron transporting zone | | | | | | | | | |
| | Emitting region | | | First electron | | Second electron | | | | | | | |
| | First emitting layer | | | transporting layer | | transporting layer | | | | | | | |
| | First | First | Film | | Film | | Film | | | | | | |
| | host | emitting | thick- | Com- | thick- | Com- | thick- | Device evaluation | | | | | |
| | mate- | com- | ness | pound | ness | pound | ness | Voltage | EQE | LT95 | | | |
| | rial | pound | [nm] | Name | [nm] | Name | [nm] | [V] | [%] | [hr] | | | |
| Ex. 1-1 | BH-3 | BD-1 | 25 | ET-6 | 10 | ET-2 | 15 | 4.2 | 9.3 | 60 | | | |
| Ex. 1-2 | BH-3 | BD-2 | 25 | ET-6 | 10 | ET-2 | 15 | 4.2 | 9.2 | 50 | | | |
| Ex. 1-3 | BH-3 | BD-3 | 25 | ET-6 | 10 | ET-2 | 15 | 4.2 | 9.5 | 80 | | | |
| Comp. 1-1 | BH-3 | Ref-1 | 25 | ET-6 | 10 | ET-2 | 15 | 4.1 | 6.2 | 20 | | | |
| Comp. 1-2 | BH-3 | BD-2 | 25 | ET-6 | 10 | ET-2 | 15 | 4.1 | 7.9 | 30 | | | |

The organic EL devices in Examples 1-1 to 1-3 in which a refractive index NM₂ of a constituent material contained in the second anode side organic layer and a refractive index NM₃ of a constituent material contained in the third anode side organic layer satisfied a relationship of a numerical formula (Numerical Formula NM)(NM₂>NM₃) emitted light at a higher efficiency with a longer lifetime than the organic EL devices in Comparatives 1-1 to 1-2 not satisfying the relationship of the numerical formula (Numerical Formula NM).

### Example 2-1

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, a compound HT-1-3 and a compound HA were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-1-3 and the compound HA in the first anode side organic layer were 97 mass % and 3 mass %, respectively.

The compound HT-1-3 was vapor-deposited on the first anode side organic layer to form a 40-nm-thick second anode side organic layer (occasionally also referred to as a first hole transporting layer).

A compound HT-2-3 was vapor-deposited on the second anode side organic layer to form a 40-nm-thick third anode side organic layer (occasionally also referred to as a second hole transporting layer).

A compound BH-5 (first host material), a compound BH-4 (first additional host material) and a compound BD-4 (first emitting compound) were co-deposited on the third anode side organic layer to form a 25-nm-thick first emitting layer. The ratios of the compound BH-5, the compound BH-4, and a compound BD-4 were in the first emitting layer were 50 mass %, 47 mass %, and 3 mass %, respectively.

A compound ET-3 was vapor-deposited on the first emitting layer to form a 5-nm-thick first electron transporting layer (occasionally also referred to as a hole blocking layer (HBL)).

A compound ET-2 were vapor-deposited on the first electron transporting layer to form a 20-nm-thick second electron transporting layer (ET).

A compound LiF was vapor-deposited on the second electron transporting layer to form a 1-nm-thick electron injecting layer.

Metal (Al) was vapor-deposited on the electron injecting layer to form an 80-nm-thick cathode.

A device arrangement of the organic EL device in Example 2-1 is roughly shown as follows.
ITO(130)/HT-1-3:HA(10,97%:3%)/HT-1-3(40)/HT-2-3(40)/BH-5:BH-4:BD-4(25,50%:47%:3%)/ET-3(5)/ET-2(20)/LiF(1)/Al(80)

Numerals in parentheses represent a film thickness (unit: nm).

The numerals (97%:3%) represented by percentage in the same parentheses indicate a ratio (mass %) between the compound HT-1-3 and the compound HA in the first anode side organic layer. The numerals (50%:47%:3%) represented by percentage in the same parentheses indicate a ratio (mass %) between the first host material (compound BH-5), the first additional host material (compound BH-4) and the first emitting compound (compound BD-4) in the first emitting layer.

### Example 2-2

An organic EL device in Example 2-2 was produced in the same manner as the organic EL device in Example 2-1 except that the compound BH-4 and the compound BD-4 were co-deposited on the third anode side organic layer to form the first emitting layer. The ratios of the compound BH-4 and the compound BD-4 in the first emitting layer were 97 mass % and 3 mass %, respectively.

### Example 2-3

An organic EL device in Example 2-3 was produced in the same manner as the organic EL device in Example 2-1 except that the compound BH-5 and the compound BD-4 were co-deposited on the third anode side organic layer to form the first emitting layer. The ratios of the compound BH-5 and the compound BD-4 in the first emitting layer were 97 mass % and 3 mass %, respectively.

### Comparative 2-1

An organic EL device in Comparative 2-1 was produced in the same manner as in Example 2-1 except that the compound HT-1-3 was vapor-deposited on the second anode side organic layer to form the third anode side organic layer having a film thickness of 35 nm, the compound HT-2-3 was vapor-deposited on the third anode side organic layer to form the fourth anode side organic layer having a film thickness of 5 nm, and the first emitting layer was formed on the fourth anode side organic layer.

### Comparative 2-2

An organic EL device in Comparative 2-2 was produced in the same manner as in Example 2-2 except that the compound HT-1-3 was vapor-deposited on the second anode side organic layer to form the third anode side organic layer having a film thickness of 35 nm, the compound HT-2-3 was vapor-deposited on the third anode side organic layer to form the fourth anode side organic layer having a film thickness of 5 nm, and the first emitting layer was formed on the fourth anode side organic layer.

### Comparative 2-3

An organic EL device in Comparative 2-3 was produced in the same manner as in Example 2-3 except that the compound HT-1-3 was vapor-deposited on the second anode side organic layer to form the third anode side organic layer having a film thickness of 35 nm, the compound HT-2-3 was vapor-deposited on the third anode side organic layer to form the fourth anode side organic layer having a film thickness of 5 nm, and the first emitting layer was formed on the fourth anode side organic layer.

TABLE 2

| | Hole transporting zone | | | | | | | | | | | | |
|---|---|---|---|---|---|---|---|---|---|---|---|---|---|
| | | | | | Second anode side | | | Third anode side | | | Fourth anode side | | |
| | First anode side organic layer | | | | organic layer | | | organic layer | | | organic layer | | |
| | | | Refrac- | Film | Second hole | Refrac- | Film | Third hole | Refrac- | Film | Fourth hole | Film | Refractive |
| | First | Seccond | tive | thick- | transporting | tive | thick- | transporting | tive | thick- | transporting | thick- | index |
| | organic | organic | index | ness | zone | index | ness | zone | index | ness | zone | ness | difference |
| | material | material | NM₁ | [nm] | material | NM₂ | [nm] | material | NM₃ | [nm] | material | [nm] | NM₂-NM₃ |
| Ex. 2-1 | HA | HT-1-3 | 1.94 | 10 | HT-1-3 | 1.94 | 40 | HT-2-3 | 1.78 | 40 | — | — | 0.16 |
| Comp. 2-1 | HA | HT-1-3 | 1.94 | 10 | HT-1-3 | 1.94 | 40 | HT-1-3 | 1.94 | 35 | HT-2-3 | 5 | 0.00 |
| Ex. 2-2 | HA | HT-1-3 | 1.94 | 10 | HT-1-3 | 1.94 | 40 | HT-2-3 | 1.78 | 40 | — | — | 0.16 |
| Comp. 2-2 | HA | HT-1-3 | 1.94 | 10 | HT-1-3 | 1.94 | 40 | HT-1-3 | 1.94 | 35 | HT-2-3 | 5 | 0.00 |
| Ex. 2-3 | HA | HT-1-3 | 1.94 | 10 | HT-1-3 | 1.94 | 40 | HT-2-3 | 1.78 | 40 | — | — | 0.16 |
| Comp. 2-3 | HA | HT-1-3 | 1.94 | 10 | HT-1-3 | 1.94 | 40 | HT-1-3 | 1.94 | 35 | HT-2-3 | 5 | 0.00 |
| | | | | | Electron transporting zone | | | | | | | | |
| | Emitting region | | | | First electron | | Second electron | | | | | | |
| | First emitting layer | | | | transporting layer | | transporting layer | | | | | | |
| | First | First | First | Film | | Film | | Film | | | | | |
| | host | additional | emitting | thick- | Com- | thick- | Com- | thick- | Device evaluation | | | | |
| | mate- | host | com- | ness | pound | ness | pound | ness | Voltage | EQE | LT95 | | |
| | rial | material | pound | [nm] | Name | [nm] | Name | [nm] | [V] | [%] | [hr] | | |
| Ex. 2-1 | BH-5 | BH-4 | BD-4 | 25 | ET-3 | 5 | ET-2 | 20 | 3.9 | 9.3 | 250 | | |
| Comp. 2-1 | BH-5 | BH-4 | BD-4 | 25 | ET-3 | 5 | ET-2 | 20 | 3.8 | 8.7 | 200 | | |
| Ex. 2-2 | BH-4 | — | BD-4 | 25 | ET-3 | 5 | ET-2 | 20 | 4.7 | 9.2 | 180 | | |
| Comp. 2-2 | BH-4 | — | BD-4 | 25 | ET-3 | 5 | ET-2 | 20 | 4.2 | 8.8 | 250 | | |
| Ex. 2-3 | BH-5 | — | BD-4 | 25 | ET-3 | 5 | ET-2 | 20 | 4.0 | 9.0 | 130 | | |
| Comp. 2-3 | BH-5 | — | BD-4 | 25 | ET-3 | 5 | ET-2 | 20 | 3.8 | 8.5 | 150 | | |

The organic EL devices in Example 2-1 in which the refractive index NM₂ of the constituent material contained in the second anode side organic layer and the refractive index NM₃ of the constituent material contained in the third anode side organic layer satisfied the relationship of the numerical formula (Numerical Formula NM)(NM₂>NM₃) emitted light at a higher efficiency with a longer lifetime than the organic EL device in Comparative 2-1 not satisfying the relationship of the numerical formula (Numerical Formula NM).

The organic EL devices in Example 2-2 in which the refractive index NM₂ of the constituent material contained in the second anode side organic layer and the refractive index NM₃ of the constituent material contained in the third anode side organic layer satisfied the relationship of the numerical formula (Numerical Formula NM)(NM₂>NM₃) emitted light at a higher efficiency with a longer lifetime than the organic EL device in Comparative 2-2 not satisfying the relationship of the numerical formula (Numerical Formula NM).

Similarly, the organic EL devices in Example 2-3 emitted light at a higher efficiency than the organic EL device in Comparative 2-3.

### Example 3-1

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, a compound HT-1-1 and a compound HA were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-1-1 and the compound HA in the first anode side organic layer were 97 mass % and 3 mass %, respectively.

The compound HT-1-1 was vapor-deposited on the first anode side organic layer to form a 40-nm-thick second anode side organic layer (occasionally also referred to as a first hole transporting layer).

A compound HT-2-2 was vapor-deposited on the second anode side organic layer to form a 40-nm-thick third anode side organic layer (occasionally also referred to as a second hole transporting layer).

A compound HT-3-2 was vapor-deposited on the third anode side organic layer to form a 5-nm-thick fourth anode side organic layer (occasionally also referred to as a third hole transporting layer or an electron blocking layer).

A compound BH-6 (first host material) and the compound BD-4 (first emitting compound) were co-deposited on the fourth anode side organic layer to form a 25-nm-thick first emitting layer. The ratios of the compound BH-6 and the compound BD-4 in the first emitting layer were 97 mass % and 3 mass %, respectively.

A compound ET-1 was vapor-deposited on the first emitting layer to form a 5-nm-thick first electron transporting layer (occasionally also referred to as a hole blocking layer (HBL)).

A compound ET-2 were vapor-deposited on the first electron transporting layer to form a 20-nm-thick second electron transporting layer (ET).

A compound LiF was vapor-deposited on the second electron transporting layer to form a 1-nm-thick electron injecting layer.

Metal (Al) was vapor-deposited on the electron injecting layer to form an 80-nm-thick cathode.

A device arrangement of the organic EL device in Example 3-1 is roughly shown as follows.
ITO(130)/HT-1-1:HA(10,97%:3%)/HT-1-1(40)/HT-2-2(40)/HT-3-2(5)/BH-6:BD-4(25,97%:3%)/ET-1(5)/ET-2(20)/LiF(1)/Al(80)

Numerals in parentheses represent a film thickness (unit: nm).

The numerals (97%:3%) represented by percentage in the same parentheses indicate a ratio (mass %) between the compound HT-1-1 and the compound HA in the first anode side organic layer. The numerals (97%:3%) represented by percentage in the same parentheses indicate a ratio (mass %) between the first host material (compound BH-6) and the first emitting compound (compound BD-4) in the first emitting layer.

### Examples 3-2, 3-3, 3-5, and 3-6

The organic EL devices in Examples 3-2, 3-3, 3-5, and 3-6 were produced in the same manner as the organic EL device in Example 3-1 except that the compound contained in the first electron transporting layer, the compound contained in the second electron transporting layer, the film thickness of the first electron transporting layer, and the film thickness of the second electron transporting layer were replaced with the compounds and film thicknesses shown in Table 3.

In Table 3, the numerals (70%:30%) represented by percentage indicate a ratio (mass %) between the compound ET-4 and the compound Liq in the second electron transporting layer, and the numerals (50%:50%) represented by percentage indicate a ratio (mass %) between the compound ET-6 and the compound Liq in the second electron transporting layer or a ratio (mass %) between the compound ET-9 and the compound Liq in the second electron transporting layer.

### Example 3-4

The organic EL device in Example 3-4 was produced in the same manner as the organic EL device in Example 3-1 except that the compound contained in the first electron transporting layer and the film thickness of the first electron transporting layer were replaced with the compound and film thickness shown in Table 3 and the second electron transporting layer was not formed. In Table 3, the numerals (50%:50%) represented by percentage indicate a ratio (mass %) between the compound ET-2 and the compound ET-7 in the second electron transporting layer.

### Comparative 3-1

The organic EL device in Comparative 3-1 was produced in the same manner as the organic EL device in Example 3-1 except that the third hole transporting zone material was replaced with a compound shown in Table 3, the compound contained in the first electron transporting layer and the film thickness of the first electron transporting layer were replaced with a compound and a film thickness shown in Table 3, and the second electron transporting layer was not formed. In Table 3, Alq₃ represents tris(8-quinolinolato)aluminum.

TABLE 3

| | Hole transporting zone | | | | | | | | | | | | |
|---|---|---|---|---|---|---|---|---|---|---|---|---|---|
| | | | | | Second anode side | | | Third anode side | | | Fourth anode side | | |
| | First anode side organic layer | | | | organic layer | | | organic layer | | | organic layer | | |
| | | | Refrac- | Film | Second hole | Refrac- | Film | Third hole | Refrac- | Film | Fourth hole | Film | Refractive |
| | First | Seccond | tive | thick- | transporting | tive | thick- | transporting | tive | thick- | transporting | thick- | index |
| | organic | organic | index | ness | zone | index | ness | zone | index | ness | zone | ness | difference |
| | material | material | NM₁ | [nm] | material | NM₂ | [nm] | material | NM₃ | [nm] | material | [nm] | NM₂-NM₃ |
| Ex. 3-1 | HA | HT-1-1 | 1.94 | 10 | HT-1-1 | 1.94 | 40 | HT-2-2 | 1.79 | 40 | HT-3-2 | 5 | 0.15 |
| Ex. 3-2 | HA | HT-1-1 | 1.94 | 10 | HT-1-1 | 1.94 | 40 | HT-2-2 | 1.79 | 40 | HT-3-2 | 5 | 0.15 |
| Ex. 3-3 | HA | HT-1-1 | 1.94 | 10 | HT-1-1 | 1.94 | 40 | HT-2-2 | 1.79 | 40 | HT-3-2 | 5 | 0.15 |
| Ex. 3-4 | HA | HT-1-1 | 1.94 | 10 | HT-1-1 | 1.94 | 40 | HT-2-2 | 1.79 | 40 | HT-3-2 | 5 | 0.15 |
| Ex. 3-5 | HA | HT-1-1 | 1.94 | 10 | HT-1-1 | 1.94 | 40 | HT-2-2 | 1.79 | 40 | HT-3-2 | 5 | 0.15 |
| Ex. 3-6 | HA | HT-1-1 | 1.94 | 10 | HT-1-1 | 1.94 | 40 | HT-2-2 | 1.79 | 40 | HT-3-2 | 5 | 0.15 |
| Comp. 3-1 | HA | HT-1-1 | 1.94 | 10 | HT-1-1 | 1.94 | 40 | HT-1-1 | 1.94 | 40 | HT-3-2 | 5 | 0.00 |
| | | | | Electron transporting zone | | | | | | | | | |
| | Emitting region | | | First electron | | Second electron | | | | | | | |
| | First emitting layer | | | transporting layer | | transporting layer | | | | | | | |
| | First | First | Film | | Film | | Film | | | | | | |
| | host | emitting | thick- | Com- | thick- | Com- | thick- | Device evaluation | | | | | |
| | mate- | com- | ness | pound | ness | pound | ness | Voltage | EQE | LT95 | | | |
| | rial | pound | [nm] | Name | [nm] | Name | [nm] | [V] | [%] | [hr] | | | |
| Ex. 3-1 | BH-6 | BD-4 | 25 | ET-1 | 5 | ET-2 | 20 | 3.8 | 10.2 | 150 | | | |
| Ex. 3-2 | BH-6 | BD-4 | 25 | ET-3 | 7 | ET-4, Liq | 18 | 4.0 | 9.8 | 170 | | | |
| | | | | | | (70%:30%) | | | | | | | |
| Ex. 3-3 | BH-6 | BD-4 | 25 | ET-5 | 10 | ET-6, Liq | 15 | 4.2 | 9.5 | 180 | | | |
| | | | | | | (50%:50%) | | | | | | | |
| Ex. 3-4 | BH-6 | BD-4 | 25 | ET-2,ET-7 | 25 | — | — | 3.9 | 9.9 | 160 | | | |
| | | | | (50%:50%) | | | | | | | | | |
| Ex. 3-5 | BH-6 | BD-4 | 25 | ET-8 | 3 | ET-9, Liq | 22 | 4.5 | 9.2 | 200 | | | |
| | | | | | | (50%:50%) | | | | | | | |
| Ex. 3-6 | BH-6 | BD-4 | 25 | ET-10 | 10 | ET-11 | 15 | 3.4 | 10.8 | 110 | | | |
| Comp. 3-1 | BH-6 | BD-4 | 25 | Alq 3 | 25 | — | — | 5.4 | 6.3 | 95 | | | |

The organic EL devices in Examples 3-1 to 3-6 in which the refractive index NM₂ of the constituent material contained in the second anode side organic layer and the refractive index NM₃ of the constituent material contained in the third anode side organic layer satisfied the relationship of the numerical formula (Numerical Formula NM)(NM₂>NM₃) emitted light at a higher efficiency with a longer lifetime than the organic EL device in Comparative 3-1 not satisfying the relationship of the numerical formula (Numerical Formula NM). The organic EL devices in Example 3-1 to 3-6 were driven at lower voltage than the organic EL device in Comparative 3-1.

### Example 4-1

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum evaporation apparatus. First, a compound HT-1-3 and a compound HA were co-deposited on a surface of the glass substrate, where the transparent electrode line was provided, to cover the transparent electrode, thereby forming a 10-nm-thick first anode side organic layer (occasionally also referred to as a hole injecting layer). The ratios of the compound HT-1-3 and the compound HA in the first anode side organic layer were 97 mass % and 3 mass %, respectively.

The compound HT-1-3 was vapor-deposited on the first anode side organic layer to form a 40-nm-thick second anode side organic layer (occasionally also referred to as a first hole transporting layer).

A compound HT-2-1 was vapor-deposited on the second anode side organic layer to form a 40-nm-thick third anode side organic layer (occasionally also referred to as a second hole transporting layer).

A compound HT-3-3 was vapor-deposited on the third anode side organic layer to form a 5-nm-thick fourth anode side organic layer (occasionally also referred to as a third hole transporting layer or an electron blocking layer).

A compound BH-3 (first host material) and the compound BD-5 (first emitting compound) were co-deposited on the fourth anode side organic layer to form a 25-nm-thick first emitting layer. The ratios of the compound BH-3 and the compound BD-5 in the first emitting layer were 99 mass % and 1 mass %, respectively.

A compound ET-3 was vapor-deposited on the first emitting layer to form a 10-nm-thick first electron transporting layer (occasionally also referred to as a hole blocking layer (HBL)).

A compound ET-2 were-deposited on the first electron transporting layer to form a 15-nm-thick second electron transporting layer (ET).

A compound LiF was vapor-deposited on the second electron transporting layer to form a 1-nm-thick electron injecting layer.

Metal (Al) was vapor-deposited on the electron injecting layer to form an 80-nm-thick cathode.

A device arrangement of the organic EL device in Example 4-1 is roughly shown as follows.
ITO(130)/HT-1-3:HA(10,97%:3%)/HT-1-3(40)/HT-2-1(40)/HT-3-3(5)/BH-3:BD-5(25,99%:1%)/ET-3(10)/ET-2(15)/LiF(1)/Al(80)

Numerals in parentheses represent a film thickness (unit: nm).

The numerals (97%:3%) represented by percentage in the same parentheses indicate a ratio (mass %) between the compound HT-1-3 and the compound HA in the first anode side organic layer. The numerals (99%:1%) represented by percentage in the same parentheses indicate a ratio (mass %) between the first host material (compound BH-3) and the first emitting compound (compound BD-5) in the first emitting layer.

### Comparative 4-1

The organic EL device in Comparative 4-1 was produced in the same manner as the organic EL device in Example 4-1 except that the compound HT-2-1 contained in the third anode side organic layer was replaced with a compound shown in Table 4 and the compound BD-5 contained in the first emitting layer was replaced with a compound shown in Table 4.

TABLE 4

| | Hole transporting zone | | | | | | | | | | | | |
|---|---|---|---|---|---|---|---|---|---|---|---|---|---|
| | | | | | Second anode side | | | Third anode side | | | Fourth anode side | | |
| | First anode side organic layer | | | | organic layer | | | organic layer | | | organic layer | | |
| | | | Refrac- | Film | Second hole | Refrac- | Film | Third hole | Refrac- | Film | Fourth hole | Film | Refractive |
| | First | Seccond | tive | thick- | transporting | tive | thick- | transporting | tive | thick- | transporting | thick- | index |
| | organic | organic | index | ness | zone | index | ness | zone | index | ness | zone | ness | difference |
| | material | material | NM₁ | [nm] | material | NM₂ | [nm] | material | NM₃ | [nm] | material | [nm] | NM₂-NM₃ |
| Ex. 4-1 | HA | HT-1-3 | 1.94 | 10 | HT-1-3 | 1.94 | 40 | HT-2-1 | 1.85 | 40 | HT-3-3 | 5 | 0.09 |
| Comp. 4-1 | HA | HT-1-3 | 1.94 | 10 | HT-1-3 | 1.94 | 40 | HT-1-3 | 1.94 | 40 | HT-3-3 | 5 | 0.00 |
| | | | | Electron transporting zone | | | | | | | | | |
| | Emitting region | | | First electron | | Second electron | | | | | | | |
| | First emitting layer | | | transporting layer | | transporting layer | | | | | | | |
| | First | First | Film | | Film | | Film | | | | | | |
| | host | emitting | thick- | Com- | thick- | Com- | thick- | Device evaluation | | | | | |
| | mate- | com- | ness | pound | ness | pound | ness | Voltage | EQE | LT95 | | | |
| | rial | pound | [nm] | Name | [nm] | Name | [nm] | [V] | [%] | [hr] | | | |
| Ex. 4-1 | BH-3 | BD-5 | 25 | ET-3 | 10 | ET-2 | 15 | 4.0 | 12.3 | 80 | | | |
| Comp. 4-1 | BH-3 | Ref-1 | 25 | ET-3 | 10 | ET-2 | 15 | 4.0 | 6.5 | 15 | | | |

The organic EL devices in Example 4-1 in which the refractive index NM₂ of the constituent material contained in the second anode side organic layer and the refractive index NM₃ of the constituent material contained in the third anode side organic layer satisfied the relationship of the numerical formula (Numerical Formula NM)(NM₂>NM₃) emitted light at a higher efficiency with a longer lifetime than the organic EL device in Comparative 4-1 not satisfying the relationship of the numerical formula (Numerical Formula NM).

### Evaluation of Compounds

### Singlet Energy S1

A toluene solution of a measurement target compound at a concentration of 10 μmol/L was prepared and put in a quartz cell. An absorption spectrum (ordinate axis: absorption intensity, abscissa axis: wavelength) of the thus-obtained sample was measured at a normal temperature (300K). A tangent was drawn to the fall of the absorption spectrum close to the long-wavelength region, and a wavelength value λ_{edge} (nm) at an intersection of the tangent and the abscissa axis was assigned to a conversion equation (F2) below to calculate singlet energy.

Conversion Equation (F2): S₁[eV]=12390.85/λ_{edge}

A spectrophotometer (U3310 manufactured by Hitachi, Ltd.) was used for measuring absorption spectrum.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

### Triplet Energy T₁

A measurement target compound was dissolved in EPA (diethylether:isopentane:ethanol=5:5:2 in volume ratio) at a concentration of 10 μmol/L, and the obtained solution was put in a quartz cell to provide a measurement sample. A phosphorescence spectrum (ordinate axis: phosphorescent luminous intensity, abscissa axis: wavelength) of the measurement sample was measured at a low temperature (77K). A tangent was drawn to the rise of the phosphorescence spectrum close to the short-wavelength region. An energy amount was calculated by a conversion equation (F1) below on a basis of a wavelength value λ_{edge} [nm] at an intersection of the tangent and the abscissa axis. The calculated energy amount was defined as triplet energy T₁. It should be noted that the triplet energy T₁ may have an error of about plus or minus 0.02 eV depending on measurement conditions.

Conversion Equation (F1): T₁[eV]=12390.85/λ_{edge}

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 manufactured by Hitachi High-Technologies Corporation was used.

### Measurement of Maximum Fluorescence Peak Wavelength (FL-peak)

A measurement target compound was dissolved in toluene at a concentration of 4.9×10⁻⁶ mol/L to prepare a toluene solution. Using a fluorescence spectrometer (spectrophotofluorometer F-7000 produced by Hitachi High-Tech Science Corporation), the toluene solution of the measurement target compound was excited at 390 nm, where a maximum fluorescence peak wavelength A (unit: nm) was measured.

Table 5 shows measurement values of the singlet energy S₁ and the triplet energy T₁, and fluorescent maximum peak wavelength λ of the compounds used for producing the organic EL devices.

TABLE 5

| | S₁ | T₁ | λ |
|---|---|---|---|
| | [eV] | [eV] | [nm] |
| BH-3 | 3.01 | 1.86 | — |
| BH-4 | 3.01 | 1.86 | — |
| BH-5 | 3.01 | 1.82 | — |
| BH-6 | 3.04 | 1.85 | — |
| BD-1 | 2.71 | 2.64 | 455 |
| BD-2 | 2.74 | 2.65 | 451 |
| BD-3 | 2.80 | 2.45 | 457 |
| BD-4 | 2.81 | 2.30 | 450 |
| BD-5 | 2.70 | 2.44 | 460 |
| Ref-1 | 2.93 | 1.94 | 438 |

### Refractive Index

The refractive index of the constituent material (compound) forming the organic layer was measured as follows.

A measurement target material was vacuum-deposited on a glass substrate to form a film having an approximately 50 nm thickness. Using a spectroscopic ellipsometer (M-2000U1, produced by J. A. Woollam Co., Inc. (US)), the obtained sample film was irradiated with incident light (from ultraviolet light through visible light to near-infrared light) every 5 degrees in a measurement angle range of 45 degrees to 75 degrees to measure change in a deflection state of the light reflected on the sample surface. In order to improve the measurement accuracy of the extinction coefficient, a transmission spectrum in a substrate normal direction (direction perpendicular to a surface of the substrate of the organic EL device) was also measured by M-2000U1. Similarly, the same measurement was performed also on the glass substrate on which no measurement target material was vapor-deposited. The obtained measurement information was fitted using analysis software (Complete EASE) produced by J. A. Woollam Co., Inc.

Refractive indices in an in-plane direction and a normal direction, extinction coefficients in the in-plane direction and the normal direction, and an order parameter of an organic film formed on the substrate were calculated under fitting conditions of using an anisotropic model rotationally symmetric about one axis and setting a parameter MSE indicating a mean square error in said analysis software to be 3.0 or less. A peak close to the long-wavelength region of the extinction coefficient (in-plane direction) was defined as S1, and the order parameter was calculated by a peak wavelength of S1. As fitting conditions for the glass substrate, an isotropic model was used.

Typically, a film formed by vacuum-depositing a low molecular material on the substrate is rotationally symmetric about one axis extending along the substrate normal direction. When an angle formed by the substrate normal direction and a molecular axis in a thin film formed on the substrate is defined as 6 and the extinction coefficients in a substrate parallel direction (Ordinary direction) and a substrate perpendicular direction (Extra-Ordinary direction) obtained by performing the variable-angle spectroscopic ellipsometry measurement on the thin film are respectively defined as ko and ke, S′ represented by a formula below is the order parameter.

S′=1−<cos 2θ>=2ko/(ke+2ko)=⅔(1−S)

S=(½)<3 cos 2θ−1>=(ke−ko)/(ke+2ko)

An evaluation method of the molecular orientation is a publicly known method, and details thereof are described in Organic Electronics, volume 10, page 127 (2009). Further, the method for forming the thin film is a vacuum deposition method.

The order parameter S′ obtained by the variable-angle spectroscopic ellipsometry measurement is 1.0 when all the molecules are oriented in parallel with the substrate. When molecules are random without being oriented, the order parameter S′ is 0.66.

Herein, a value at 2.7 eV in the substrate parallel direction (Ordinary direction), from among the values measured above, is defined as a refractive index of the measurement target material.

When a layer was formed by a constituent material containing a plurality of compounds, a refractive index of the constituent material of the layer, the layer being a film formed by co-depositing the plurality of compounds as the measurement target material on the glass substrate or a film formed by vapor-depositing a mixture containing the plurality of compounds as the measurement target material, was measured using a spectroscopic ellipsometer in the same manner as above.

Tables 1 to 4 show the constituent materials of the second anode side organic layer and the third anode side organic layer, the refractive index of each of the constituent materials (compounds) thereof, and a difference in the refractive indexes NM₂−NM₃.

### EXPLANATION OF CODES

1, 1A, 1B, 1C . . . organic EL device, 10, 11, 12, 13 . . . organic layer, 100A, 100B, 1000, 100D, 100E, 100F . . . organic EL display device, 10B, 11B, 12B, 13B . . . blue-emitting organic EL device, 10G, 11G . . . green-emitting organic EL device, 10R . . . red-emitting organic EL device, 2, 2A . . . substrate, 3 . . . anode, 4 . . . cathode, 5, 5B . . . emitting region, 50B . . . blue emitting layer, 51 . . . first emitting layer, 52 . . . second emitting layer, 53 . . . green emitting layer, 531 . . . fifth anode side organic layer, 54 . . . red emitting layer, 541 . . . sixth anode side organic layer, 61, 61A . . . first anode side organic layer, 62, 62A . . . second anode side organic layer, 63, 63A . . . third anode side organic layer, 64, 64A . . . fourth anode side organic layer, 8 . . . electron transporting layer, 9 . . . electron injecting layer

1. An organic electroluminescence device, comprising:
a cathode;
an anode;
an emitting region provided between the cathode and the anode; and
a hole transporting zone provided between the anode and the emitting region, wherein the emitting region comprises at least one emitting layer,
the at least one emitting layer comprises a first emitting layer,
the hole transporting zone comprises a first anode side organic layer, a second anode side organic layer, and a third anode side organic layer,
the first anode side organic layer is in direct contact with the second anode side organic layer and the second anode side organic layer is in direct contact with the third anode side organic layer,
the first anode side organic layer, the second anode side organic layer, and the third anode side organic layer are arranged in this order from a side close to the anode between the anode and the emitting region,
the second anode side organic layer comprises a second hole transporting zone material,
the second hole transporting zone material is a monoamine compound having one substituted or unsubstituted amino group in a molecule or a diamine compound having two substituted or unsubstituted amino groups in a molecule,
the third anode side organic layer comprises a third hole transporting zone material,
the third hole transporting zone material is a monoamine compound having one substituted or unsubstituted amino group in a molecule or a diamine compound having two substituted or unsubstituted amino groups in a molecule,
the third anode side organic layer has a film thickness of 20 nm or more,
the second hole transporting zone material and the third hole transporting zone material are mutually the same or different,
the second anode side organic layer comprises at least one compound different from the compound comprised in the third anode side organic layer,
the first emitting layer is a fluorescent emitting layer, and
a refractive index NM₂ of a constituent material comprised in the second anode side organic layer and a refractive index NM₃ of a constituent material comprised in the third anode side organic layer satisfy a relationship of a numerical formula (Numerical Formula NM) below,
NM₂>NM₃ (Numerical Formula NM).

2. The organic electroluminescence device according to claim 1, wherein the first anode side organic layer does not comprise a compound comprised in the second anode side organic layer.

3. The organic electroluminescence device according to claim 1, wherein the first anode side organic layer is in direct contact with the anode.

4. The organic electroluminescence device according to claim 1, wherein each of the at least one emitting layer comprised in the emitting region is a fluorescent emitting layer.

5. (canceled)

6. The organic electroluminescence device according to claim 1, wherein a difference NM₂−NM₃ between the refractive index NM₂ of the constituent material comprised in the second anode side organic layer and the refractive index NM₃ of the constituent material comprised in the third anode side organic layer satisfies a relationship of a numerical formula (Numerical Formula NM2) below,
NM₂−NM₃≥0.05 (Numerical Formula NM2).

7. The organic electroluminescence device according to claim 1, wherein a difference NM₂−NM₃ between the refractive index NM₂ of the constituent material comprised in the second anode side organic layer and the refractive index NM₃ of the constituent material comprised in the third anode side organic layer satisfies a relationship of a numerical formula (Numerical Formula NM3) below,
NM₂−NM₃≥0.075 (Numerical Formula NM3).

8. The organic electroluminescence device according to claim 1, wherein a difference NM₂−NM₃ between the refractive index NM₂ of the constituent material comprised in the second anode side organic layer and the refractive index NM₃ of the constituent material comprised in the third anode side organic layer satisfies a relationship of a numerical formula (Numerical Formula N4) below,
NM₂−NM₃≥0.10 (Numerical Formula NM4).

9. The organic electroluminescence device according to claim 1, wherein a refractive index NM₁ of a constituent material comprised in the first anode side organic layer and the refractive index NM₂ of the constituent material comprised in the second anode side organic layer satisfy a relationship of a numerical formula (Numerical Formula L1) below,
NM₁>NM₂ (Numerical Formula L1).

10-12. (canceled)

13. The organic electroluminescence device according to claim 1, wherein the emitting region consists of the first emitting layer.

14. The organic electroluminescence device according to claim 1, wherein the emitting region further comprises a second emitting layer in addition to the first emitting layer.

15. (canceled)

16. The organic electroluminescence device according to claim 1, wherein the first anode side organic layer has a film thickness of 20 nm or less.

17. The organic electroluminescence device according to claim 1, wherein the third anode side organic layer has a film thickness of 25 nm or more.

18. (canceled)

19. The organic electroluminescence device according to claim 1, wherein the third anode side organic layer has a film thickness in a range from 30 nm to 80 nm.

20. (canceled)

21. The organic electroluminescence device according to claim 1, wherein the third hole transporting zone material is at least one compound selected from the group consisting of a compound represented by a formula (C1) below and a compound represented by a formula (C3) below, 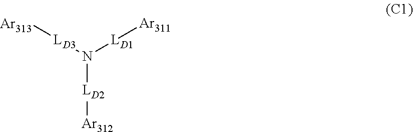
where, in the formula (C1):
Ar₃₁₁, Ar₃₁₂, and Ar₃₁₃ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different; and
L_{D1}, L_{D2}, and L_{D3} are each independently a single bond, a substituted or unsubstituted arylene group having 6 to 50 ring carbon atoms, or a substituted or unsubstituted divalent heterocyclic group having 5 to 50 ring atoms, 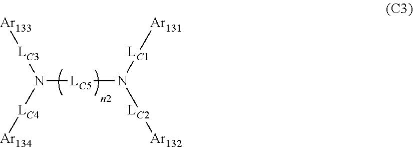
where, in the formula (C3):
L_{C1}, L_{C2}, L_{C3}, and L_{C4} are each independently a single bond, a substituted or unsubstituted arylene group having 6 to 50 ring carbon atoms, or a substituted or unsubstituted divalent heterocyclic group having 5 to 50 ring atoms;
n2 is 1, 2, 3, or 4;
when n2 is 1, L_{C5} is a substituted or unsubstituted arylene group having 6 to 50 ring carbon atoms, or a substituted or unsubstituted divalent heterocyclic group having 5 to 50 ring atoms;
when n2 is 2, 3, or 4, a plurality of L_{C5} are mutually the same or different;
when n2 is 2, 3, or 4, a plurality of L_{C5} are mutually bonded to form a substituted or unsubstituted monocyclic ring, mutually bonded to form a substituted or unsubstituted fused ring, or not mutually bonded;
L_{C5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
Ar₁₃₁, Ar₁₃₂, Ar₁₃₃, and Ar₁₃₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different; and
a first amino group represented by a formula (C3-1) below and a second amino group represented by a formula (C3-2) below are an identical group, 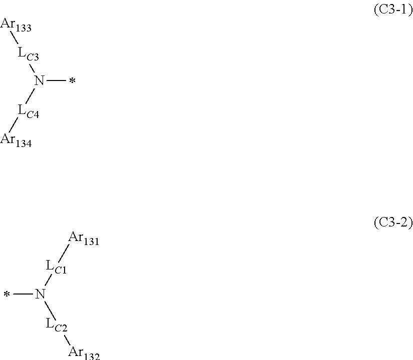
where, in the formulae (C3-1) and (C3-2), * each represent a bonding position to L_{C5}, and
in the compound represented by the formula (C3), the substituent for the “substituted or unsubstituted” group is not a group represented by —N(R_{C6})(R_{C7}), and R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

22. The organic electroluminescence device according to claim 21, wherein
the compound represented by the formula (C1) is at least one compound selected from the group consisting of a compound represented by a formula (cHT3-1) below, a compound represented by a formula (cHT3-2) below, a compound represented by a formula (cHT3-3) below, and a compound represented by a formula (cHT3-4) below, 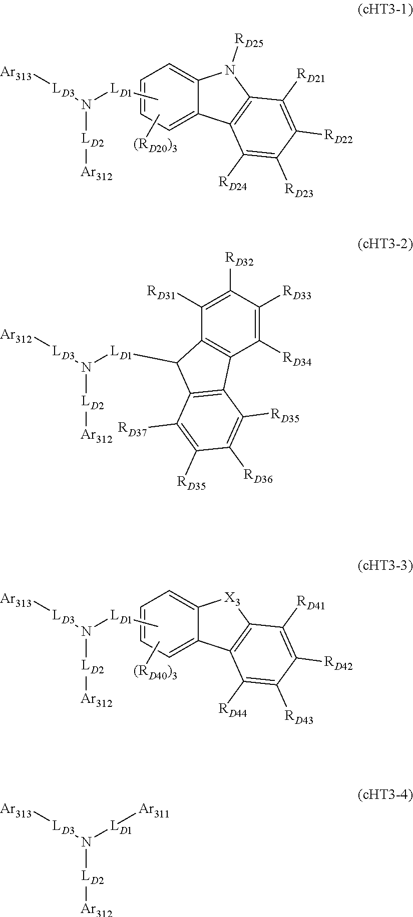
where, in the formulae (cHT3-1), (cHT3-2), (cHT3-3), and (cHT3-4):
Ar₃₁₂, Ar₃₁₃, L_{D1}, L_{D2}, and L_{D3} each independently represent the same as Ar₃₁₂, Ar₃₁₃, L_{D1}, L_{D2}, and L_{D3} in the formula (C1);
Ar₃₁₁ is a group represented by one of formulae (1-a), (1-b), (1-c), and (1-d) below;
at least one combination of adjacent two or more of R_{D20} to R_{D24} are mutually bonded to form a substituted or unsubstituted monocyclic ring, mutually bonded to form a substituted or unsubstituted fused ring, or not mutually bonded;
at least one combination of adjacent two or more of R_{D31} to R_{D38} are mutually bonded to form a substituted or unsubstituted monocyclic ring, mutually bonded to form a substituted or unsubstituted fused ring, or not mutually bonded;
at least one combination of adjacent two or more of R_{D40} to R_{D44} are mutually bonded to form a substituted or unsubstituted monocyclic ring, mutually bonded to form a substituted or unsubstituted fused ring, or not mutually bonded;
X₃ is an oxygen atom, a sulfur atom, or C(R_{D45})(R_{D46});
a combination of R_{D45} and R_{D46} are mutually bonded to form a substituted or unsubstituted monocyclic ring, mutually bonded to form a substituted or unsubstituted fused ring, or not mutually bonded;
R_{D25}, and R_{D20} to R_{D24}, R_{D31} to R_{D38}, R_{D40} to R_{D44}, R_{D45} and R_{D46} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a plurality of R_{D20} are mutually the same or different;
a plurality of R_{D40} are mutually the same or different;
R₉₀₁ to R₉₀₄ in the compounds represented by the formulae (cHT3-1), (cHT3-2), (cHT3-3), and (cHT3-4) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different, 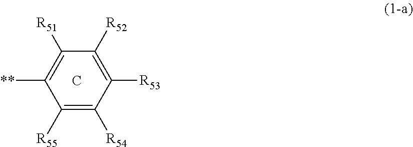
where, in the formula (1-a):
none of a combination(s) of adjacent two or more of R₅₁ to R₅₅ are bonded to each other;
R₅₁ to R₅₅ are each independently a hydrogen atom or a substituted or unsubstituted alkyl group having 1 to 6 carbon atoms; and
** represents a bonding position to L_{D1}, 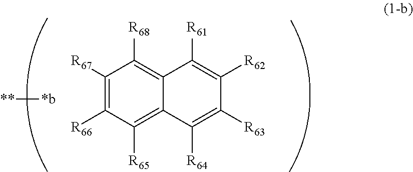
where, in the formula (1-b):
one of R₆₁ to R₆₈ is a single bond with *b;
none of a combination(s) of adjacent two or more of R₆₁ to R₆₈ not being the single bond with *b are bonded to each other;
R₆₁ to R₆₈ not being the single bond with *b are each independently a hydrogen atom, a substituted or unsubstituted alkyl group having 1 to 6 carbon atoms, or a substituted or unsubstituted aryl group having 6 to 12 ring carbon atoms; and
** represents a bonding position to L_{D1}, 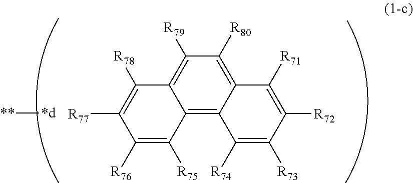
where, in the formula (1-c):
one of R₇₁ to R₈₀ is a single bond with *d;
none of a combination(s) of adjacent two or more of R₇₁ to R₈₀ not being the single bond with *d are bonded to each other;
R₇₁ to R₈₀ not being the single bond with *d are each independently a hydrogen atom, a substituted or unsubstituted alkyl group having 1 to 6 carbon atoms, or a substituted or unsubstituted aryl group having 6 to 12 ring carbon atoms; and
** represents a bonding position to L_{D1}, 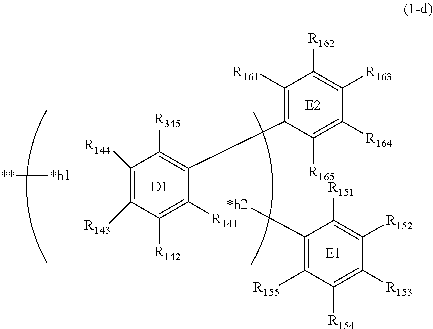
where, in the formula (1-d):
one of R₁₄₁ to R₁₄₅ is a single bond with *h1, and another one of R₁₄₁ to R₁₄₅ is a single bond with *h2;
none of a combination(s) of adjacent two or more of R₁₄₁ to R₁₄₅ not being the single bond with *h1 and not being the single bond with *h2 are bonded to each other;
at least one combination of adjacent two or more of R₁₅₁ to R₁₅₅ are mutually bonded to form a substituted or unsubstituted monocyclic ring, mutually bonded to form a substituted or unsubstituted fused ring, or not mutually bonded;
at least one combination of adjacent two or more of R₁₆₁ to R₁₆₅ are mutually bonded to form a substituted or unsubstituted monocyclic ring, mutually bonded to form a substituted or unsubstituted fused ring, or not mutually bonded;
R₁₄₁ to R₁₄₅ not being the single bond with *h1 and not being the single bond with *h2 as well as R₁₅₁ to R₁₅₅ and R₁₆₁ to R₁₆₅ forming neither the substituted or unsubstituted monocyclic ring nor the substituted or unsubstituted fused ring are each independently a hydrogen atom or a substituted or unsubstituted alkyl group having 1 to 6 carbon atoms, or a substituted or unsubstituted aryl group having 6 to 12 ring carbon atoms; and
** represents a bonding position to L_{D1}.

23. (canceled)

24. The organic electroluminescence device according to claim 1, wherein
the second hole transporting zone material comprised in the second anode side organic layer and a second organic material comprised in the first anode side organic layer are each independently at least one compound selected from the group consisting of a compound represented by a formula (cHT2-1) below, a compound represented by a formula (cHT2-2) below, and a compound represented by a formula (cHT2-3) below, 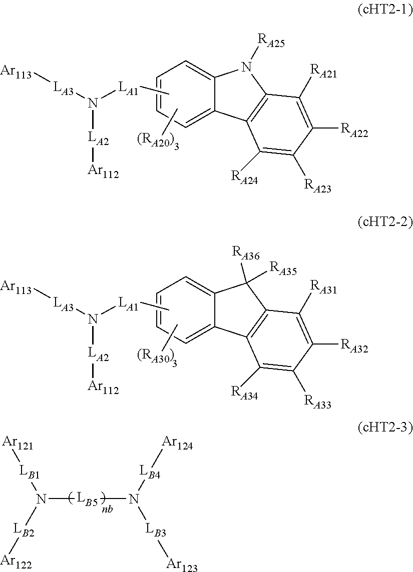
where, in the formulae (cHT2-1), (cHT2-2), and (cHT2-3):
Ar₁₁₂, A₁₁₃, Ar₁₂₁, Ar₁₂₂, Ar₁₂₃, and Ar₁₂₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different;
L_{A1}, L_{A2}, L_{A3}, L_{B1}, L_{B2}, L_{B3}, and L_{B4} are each independently a single bond, a substituted or unsubstituted arylene group having 6 to 50 ring carbon atoms, or a substituted or unsubstituted divalent heterocyclic group having 5 to 50 ring atoms;
nb is 1, 2, 3 or 4;
when nb is 1, L_{B5} is a substituted or unsubstituted arylene group having 6 to 50 ring carbon atoms, or a substituted or unsubstituted divalent heterocyclic group having 5 to 50 ring atoms;
when nb is 2, 3, or 4, a plurality of L_{B5} are mutually the same or different;
when nb is 2, 3, or 4, a plurality of L_{B5} are mutually bonded to form a substituted or unsubstituted monocyclic ring, mutually bonded to form a substituted or unsubstituted fused ring, or not mutually bonded;
L_{B5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
a combination of R_{A35} and R_{A36} are mutually bonded to form a substituted or unsubstituted monocyclic ring, mutually bonded to form a substituted or unsubstituted fused ring, or not mutually bonded;
R_{A25}, and R_{A35} and R_{A36} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
at least one combination of adjacent two or more of R_{A20} to R_{A24} are mutually bonded to form a substituted or unsubstituted monocyclic ring, mutually bonded to form a substituted or unsubstituted fused ring, or not mutually bonded;
at least one combination of adjacent two or more of R_{A30} to R_{A34} are mutually bonded to form a substituted or unsubstituted monocyclic ring, mutually bonded to form a substituted or unsubstituted fused ring, or not mutually bonded;
R_{A20} to R_{A24} and R_{A30} to R_{A34} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a plurality of R_{A20} are mutually the same or different;
a plurality of R_{A30} are mutually the same or different;
R₉₀₁ to R₉₀₄ in the compounds represented by the formulae (cHT2-1), (cHT2-2), and (cHT2-3) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

25. The organic electroluminescence device according to claim 24, wherein
the second hole transporting zone material and the second organic material each independently comprise at least one group selected from the group consisting of a group represented by a formula (2-a), a group represented by a formula (2-b), a group represented by a formula (2-c), a group represented by a formula (2-d), a group represented by a formula (2-e), and a group represented by a formula (2-f) below, 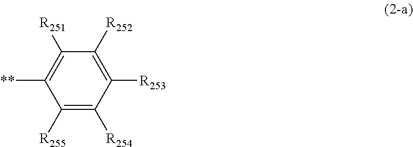
where, in the formula (2-a):
none of a combination(s) of adjacent two or more of R₂₅₁ to R₂₅₅ are bonded to each other;
R₂₅₁ to R₂₅₅ are each independently a hydrogen atom, or a substituted or unsubstituted alkyl group having 1 to 6 carbon atoms; and
** represents a bonding position, 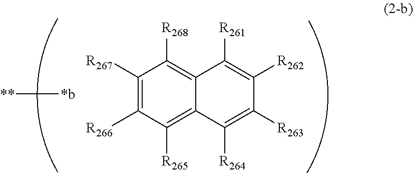
where, in the formula (2-b):
one of R₂₆₁ to R₂₆₈ is a single bond with *b;
none of a combination(s) of adjacent two or more of R₂₆₁ to R₂₆₈ not being the single bond with *b are bonded to each other;
R₂₆₁ to R₂₆₈ not being the single bond with *b are each independently a hydrogen atom, a substituted or unsubstituted alkyl group having 1 to 6 carbon atoms, or a substituted or unsubstituted aryl group having 6 to 12 ring carbon atoms; and
** represents a bonding position, 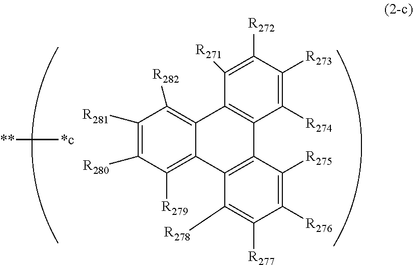
where, in the formula (2-c):
one of R₂₇₁ to R₂₈₂ is a single bond with *c;
none of a combination(s) of adjacent two or more of R₂₇₁ to R₂₈₂ not being the single bond with *c are bonded to each other;
R₂₇₁ to R₂₈₂ not being the single bond with *c are each independently a hydrogen atom, a substituted or unsubstituted alkyl group having 1 to 6 carbon atoms, or a substituted or unsubstituted aryl group having 6 to 12 ring carbon atoms; and
** represents a bonding position, 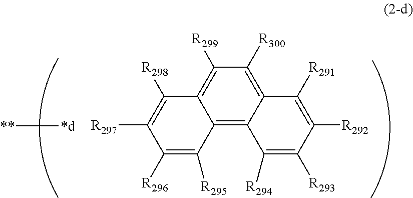
where, in the formula (2-d):
one of R₂₉₁ to R₃₀₀ is a single bond with *d;
none of a combination(s) of adjacent two or more of R₂₉₁ to R₃₀₀ not being the single bond with *d are bonded to each other;
R₂₉₁ to R₃₀₀ not being the single bond with *d are each independently a hydrogen atom, a substituted or unsubstituted alkyl group having 1 to 6 carbon atoms, or a substituted or unsubstituted aryl group having 6 to 12 ring carbon atoms; and
** represents a bonding position, 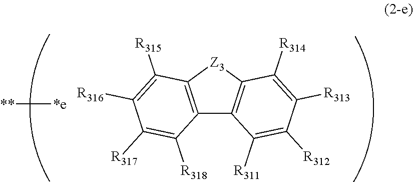
where, in the formula (2-e):
Z₃ is an oxygen atom, a sulfur atom, NR₃₁₉, or C(R₃₂₀)(R₃₂₁);
one of R₃₁₁ to R₃₂₁ is a single bond with *e, or one of carbon atoms of a substituted or unsubstituted benzene ring, described below, formed by mutually bonding a combination of adjacent two or more of R₃₁₁ to R₃₁₈ is bonded to *e by a single bond;
a combination of adjacent two or more of R₃₁₁ to R₃₁₈ not being the single bond with *e are mutually bonded to form a substituted or unsubstituted benzene ring, or not mutually bonded;
R₃₁₁ to R₃₁₈ not being the single bond with *e and not forming the substituted or unsubstituted benzene ring are each independently a hydrogen atom, a substituted or unsubstituted alkyl group having 1 to 6 carbon atoms, a substituted or unsubstituted aryl group having 6 to 12 ring carbon atoms, or a substituted or unsubstituted heterocyclic group having 5 to 10 ring atoms;
R₃₁₉ not being the single bond with *e is a hydrogen atom, a substituted or unsubstituted alkyl group having 1 to 6 carbon atoms, or a substituted or unsubstituted aryl group having 6 to 12 ring carbon atoms;
a combination of R₃₂₀ and R₃₂₁ not being the single bond with *e are mutually bonded to form a substituted or unsubstituted monocyclic ring, mutually bonded to form a substituted or unsubstituted fused ring, or not mutually bonded;
R₃₂₀ and R₃₂₁ not being the single bond with *e, not forming the substituted or unsubstituted monocyclic ring, and not forming the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
** represents a bonding position, 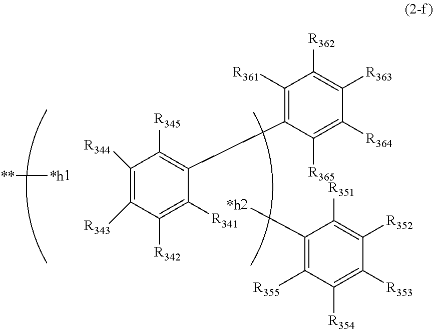
where, in the formula (2-f):
one of R₃₄₁ to R₃₄₅ is a single bond with *h1, and another one of R₃₄₁ to R₃₄₅ is a single bond with *h2;
none of a combination(s) of adjacent two or more of R₃₄₁ to R₃₄₅ not being the single bond with *h1 and not being the single bond with *h2 are bonded to each other;
at least one combination of adjacent two or more of R₃₅₁ to R₃₅₅ are mutually bonded to form a substituted or unsubstituted monocyclic ring, mutually bonded to form a substituted or unsubstituted fused ring, or not mutually bonded;
at least one combination of adjacent two or more of R₃₆₁ to R₃₆₅ are mutually bonded to form a substituted or unsubstituted monocyclic ring, mutually bonded to form a substituted or unsubstituted fused ring, or not mutually bonded;
R₃₄₁ to R₃₄₅ not being the single bond with *h1 and not being the single bond with *h2 as well as R₃₅₁ to R₃₅₅ and R₃₆₁ to R₃₆₅ forming neither the substituted or unsubstituted monocyclic ring nor the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
** represents a bonding position.

26. (canceled)

27. The organic electroluminescence device according to claim 25, wherein
the second hole transporting zone material and the second organic material are each independently a monoamine compound having one substituted or unsubstituted amino group in a molecule, and
the group represented by the formula (2-a), the group represented by the formula (2-b), the group represented by the formula (2-c), the group represented by the formula (2-d), the group represented by the formula (2-e), and the group represented by the formula (2-f) are each independently bonded directly, with a phenylene group, or with a biphenylene group to a nitrogen atom of an amino group of the monoamine compound.

28. The organic electroluminescence device according to claim 24, wherein the first anode side organic layer comprises the second organic material and a first organic material.

29. (canceled)

30. The organic electroluminescence device according to claim 1, wherein
the hole transporting zone further comprises a fourth anode side organic layer, and
the fourth anode side organic layer is provided between the third anode side organic layer and the emitting region.

31. (canceled)

32. The organic electroluminescence device according to claim 1, wherein the first emitting layer comprises a first host material and a first emitting compound that emits light having a maximum peak wavelength of 500 nm or less.

33. The organic electroluminescence device according to claim 32, wherein the first emitting compound has a full width at half maximum in a range from 1 nm to 30 nm at a maximum peak.

34. The organic electroluminescence device according to claim 32, wherein the first emitting compound is a compound represented by a formula (6) below, 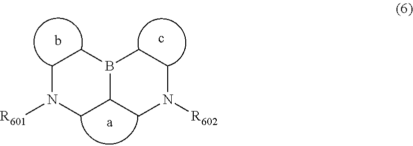
where, in the formula (6):
a ring a, a ring b and a ring c are each independently a substituted or unsubstituted aromatic hydrocarbon ring having 6 to 50 ring carbon atoms, or a substituted or unsubstituted heterocyclic ring having 5 to 50 ring atoms;
R₆₀₁ and R₆₀₂ are each independently bonded to the ring a, ring b or ring c to form a substituted or unsubstituted heterocycle, or not bonded thereto to form no substituted or unsubstituted heterocycle; and
R₆₀₁ and R₆₀₂ not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

35. The organic electroluminescence device according to claim 1, wherein the first host material comprises at least one deuterium atom.

36. The organic electroluminescence device according to claim 1, wherein the first host material is a compound represented by a formula (H1) below, 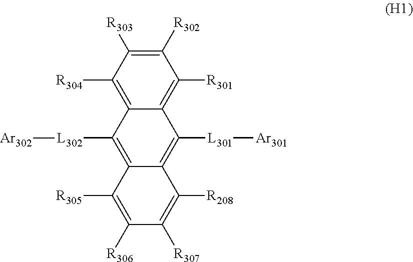
where, in the formula (H1):
R₃₀₁ to R₃₀₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₃₀₁ and L₃₀₂ are each independently a single bond, a substituted or unsubstituted arylene group having 6 to 50 ring carbon atoms, or a substituted or unsubstituted divalent heterocyclic group having 5 to 50 ring atoms; and
Ar₃₀₁ and Ar₃₀₂ are each independently a substituted or unsubstituted aryl group having 6 to 50 ring carbon atoms, or a substituted or unsubstituted heterocyclic group having 5 to 50 ring atoms,
in a compound represented by the formula (H1), R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

37. The organic electroluminescence device according to claim 1, further comprising an electron transporting zone provided between the cathode and the emitting region, wherein
the electron transporting zone comprises at least one electron transporting layer, and
the at least one electron transporting layer in the electron transporting zone comprises a nitrogen-containing compound having at least one of a five-membered ring having a nitrogen atom or a six-membered ring having a nitrogen atom.

38. (canceled)

39. An organic electroluminescence device, comprising:
a cathode;
an anode;
an emitting region provided between the cathode and the anode; and
a hole transporting zone provided between the anode and the emitting region; and an electron transporting zone provided between the cathode and the emitting region, wherein
the emitting region comprises at least one emitting layer,
the at least one emitting layer comprises a first emitting layer,
the hole transporting zone comprises a first anode side organic layer, a second anode side organic layer, and a third anode side organic layer,
the first anode side organic layer is in direct contact with the second anode side organic layer and the second anode side organic layer is in direct contact with the third anode side organic layer,
the first anode side organic layer, the second anode side organic layer, and the third anode side organic layer are arranged in this order from a side close to the anode between the anode and the emitting region,
the second anode side organic layer comprises a second hole transporting zone material,
the second hole transporting zone material is a monoamine compound having one substituted or unsubstituted amino group in a molecule or a diamine compound having two substituted or unsubstituted amino groups in a molecule,
the third anode side organic layer comprises a third hole transporting zone material,
the third hole transporting zone material is a monoamine compound having one substituted or unsubstituted amino group in a molecule or a diamine compound having two substituted or unsubstituted amino groups in a molecule,
the third anode side organic layer has a film thickness of 20 nm or more,
the second hole transporting zone material and the third hole transporting zone material are mutually the same or different,
the second anode side organic layer comprises at least one compound different from the compound comprised in the third anode side organic layer,
at least one electron transporting layer in the electron transporting zone comprises a phenanthroline compound having a phenanthroline skeleton,
the phenanthroline compound is a compound represented by a formula (20) below and having at least one group represented by a formula (21) below,
the first emitting layer is a fluorescent emitting layer, and
a refractive index NM₂ of a constituent material comprised in the second anode side organic layer and a refractive index NM₃ of a constituent material comprised in the third anode side organic layer satisfy a relationship of a numerical formula (Numerical Formula NM) below,
NM₂>NM₃ (Numerical Formula NM). 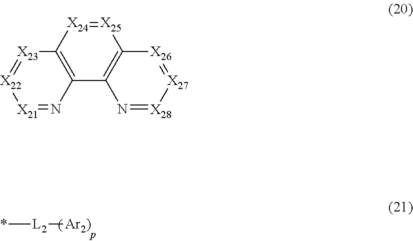
where, in the formula (20):
X₂₁ to X₂₈ are each independently a nitrogen atom, CR₂₁ or a carbon atom bonded to a group represented by the formula (21);
at least one of X₂₁ to X₂₈ is a carbon atom bonded to a group represented by the formula (21);
when a plurality of groups represented by the formula (21) are present, the plurality of groups represented by the formula (21) are mutually the same or different;
at least one combination of adjacent two or more of a plurality of R₂₁ are mutually bonded to form a substituted or unsubstituted monocyclic ring, mutually bonded to form a substituted or unsubstituted fused ring, or not mutually bonded; and
R₂₁ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₃₁, a group represented by —COOR₉₃₂, a group represented by —S(═O)₂R₉₃₃, a group represented by —B(R₉₃₄)(R₉₃₅), a group represented by —P(═O)(R₉₃₆)(R₉₃₇), a halogen atom, a cyano group, a nitro group, a substituted or unsubstituted aryl group having 6 to 50 ring carbon atoms, or a substituted or unsubstituted heterocyclic group having 5 to 50 ring atoms,
in the formula (21):
Ar₂ is a substituted or unsubstituted aryl group having 6 to 50 ring carbon atoms, or a substituted or unsubstituted heterocyclic group having 5 to 50 ring atoms;
p is 1, 2, 3, 4, or 5;
when two or more Ar₂ are present, the two or more Ar₂ are mutually the same or different;
L₂ is a single bond or a linking group;
L₂ as a linking group is a substituted or unsubstituted polyvalent linear, branched or cyclic aliphatic hydrocarbon group having 1 to 50 carbon atoms, a substituted or unsubstituted polyvalent aromatic hydrocarbon group having 6 to 50 ring carbon atoms, a substituted or unsubstituted polyvalent heterocyclic group having 5 to 50 ring atoms, or a polyvalent multiple linking group obtained by bonding two or three groups selected from the polyvalent aromatic hydrocarbon ring group and the polyvalent heterocyclic group;
the aromatic hydrocarbon ring group and the heterocyclic group forming L₂ as the multiple linking group are mutually the same or different, and adjacent ones of the aromatic hydrocarbon ring group and the heterocyclic group are mutually bonded to form a ring, or not mutually bonded;
Ar₂ and L₂ as a linking group are mutually bonded to form a ring, or not mutually bonded;
L₂ as a linking group and a carbon atom or R₂₁ of CR₂₁ in one of X₂₁ to X₂₈ adjacent to a carbon atom bonded to L₂ are mutually bonded to form a ring, or not mutually bonded; and
* in the formula (21) represents a bonding position to a ring represented by the formula (20),
in the phenanthroline compound, R₉₀₁, R₉₀₂, R₉₀₃, R₉₀₄, R₉₀₅, R₉₀₆, R₉₀₇, R₉₃₁, R₉₃₂, R₉₃₃, R₉₃₄, R₉₃₅, R₉₃₆, and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

40. An organic electroluminescence device, comprising:
a cathode;
an anode;
an emitting region provided between the cathode and the anode; and
a hole transporting zone provided between the anode and the emitting region, wherein the emitting region comprises at least one emitting layer,
the at least one emitting layer comprises a first emitting layer,
the first emitting layer comprises a first host material and a first emitting compound,
the first host material is a compound represented by a formula (H1) below,
the compound represented by the formula (H1) comprises at least one deuterium atom,
the hole transporting zone comprises a first anode side organic layer, a second anode side organic layer, and a third anode side organic layer,
the first anode side organic layer is in direct contact with the second anode side organic layer and the second anode side organic layer is in direct contact with the third anode side organic layer,
the first anode side organic layer, the second anode side organic layer, and the third anode side organic layer are arranged in this order from a side close to the anode between the anode and the emitting region,
the second anode side organic layer comprises a second hole transporting zone material,
the second hole transporting zone material is a monoamine compound having one substituted or unsubstituted amino group in a molecule or a diamine compound having two substituted or unsubstituted amino groups in a molecule,
the third anode side organic layer comprises a third hole transporting zone material,
the third hole transporting zone material is a monoamine compound having one substituted or unsubstituted amino group in a molecule or a diamine compound having two substituted or unsubstituted amino groups in a molecule,
the third anode side organic layer has a film thickness of 20 nm or more,
the second hole transporting zone material and the third hole transporting zone material are mutually the same or different,
the second anode side organic layer comprises at least one compound different from the compound comprised in the third anode side organic layer,
the first emitting layer is a fluorescent emitting layer, and
a refractive index NM₂ of a constituent material comprised in the second anode side organic layer and a refractive index NM₃ of a constituent material comprised in the third anode side organic layer satisfy a relationship of a numerical formula (Numerical Formula NM) below,
NM₂>NM₃ (Numerical Formula NM), 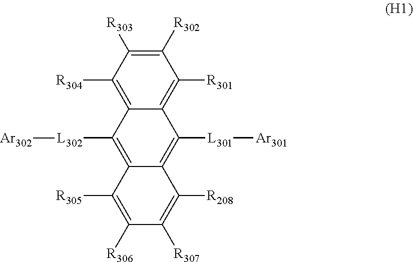
where, in the formula (H1):
R₃₀₁ to R₃₀₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₃₀₁ and L₃₀₂ are each independently a single bond, a substituted or unsubstituted arylene group having 6 to 50 ring carbon atoms, or a substituted or unsubstituted divalent heterocyclic group having 5 to 50 ring atoms; and
Ar₃₀₁ and Ar₃₀₂ are each independently a substituted or unsubstituted aryl group having 6 to 50 ring carbon atoms, or a substituted or unsubstituted heterocyclic group having 5 to 50 ring atoms,
in a compound represented by the formula (H1), R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

41. An organic electroluminescence display device, comprising:
an anode and a cathode arranged opposite each other; and
a first organic electroluminescence device as a first pixel and a second organic electroluminescence device as a second pixel, wherein
the first pixel comprises the organic electroluminescence device according to claim 1 as the first organic electroluminescence device;
the first organic electroluminescence device comprises a first emitting region as the emitting region, and a first hole transporting zone as the hole transporting zone provided between the first emitting region and the anode;
the first anode side organic layer, the second anode side organic layer, and the third anode side organic layer are provided in a shared manner across the second organic electroluminescence device;
the first emitting layer of the first emitting region comprises a first emitting compound;
the second organic electroluminescence device comprises a second emitting region provided between the anode and the cathode, and a second hole transporting zone provided between the second emitting region and the anode;
the second hole transporting zone comprises the first anode side organic layer, the second anode side organic layer, and the third anode side organic layer;
in the second hole transporting zone, the first anode side organic layer is in direct contact with the second anode side organic layer and the second anode side organic layer is in direct contact with the third anode side organic layer;
the first anode side organic layer, the second anode side organic layer, and the third anode side organic layer are arranged in this order from a side close to the anode between the anode and the second emitting region;
the second emitting region comprises at least one emitting layer;
the at least one emitting layer of the second emitting region comprises a third emitting layer;
the third emitting layer of the second emitting region comprises a third emitting compound;
a maximum peak wavelength of the first emitting compound comprised in the first emitting layer and a maximum peak wavelength of the third emitting compound comprised in the third emitting layer are mutually the same or different; and
a refractive index NM₁ of a constituent material comprised in the first anode side organic layer and a refractive index NM₂ of a constituent material comprised in the second anode side organic layer satisfy a relationship of a numerical formula (Numerical Formula L1) below,
NM₁>NM₂ (Numerical Formula L1).

42. The organic electroluminescence display device according to claim 41, wherein a maximum peak wavelength of the first emitting compound is different from a maximum peak wavelength of the third emitting compound.

43. The organic electroluminescence display device according to claim 41, wherein a maximum peak wavelength of an emitting compound comprised in the emitting layer of the first emitting region is different from a maximum peak wavelength of an emitting compound comprised in the emitting layer of the second emitting region.

44-45. (canceled)

46. An organic electroluminescence display device, comprising:
an anode and a cathode arranged opposite each other; and
a first organic electroluminescence device as a first pixel and a second organic electroluminescence device as a second pixel, wherein
the first pixel comprises the organic electroluminescence device according to claim 39 as the first organic electroluminescence device;
the first organic electroluminescence device comprises a first emitting region as the emitting region, and a first hole transporting zone as the hole transporting zone provided between the first emitting region and the anode;
the first anode side organic layer, the second anode side organic layer, and the third anode side organic layer are provided in a shared manner across the second organic electroluminescence device;
the first emitting layer of the first emitting region comprises a first emitting compound;
the second organic electroluminescence device comprises a second emitting region provided between the anode and the cathode, and a second hole transporting zone provided between the second emitting region and the anode;
the second hole transporting zone comprises the first anode side organic layer, the second anode side organic layer, and the third anode side organic layer;
in the second hole transporting zone, the first anode side organic layer is in direct contact with the second anode side organic layer and the second anode side organic layer is in direct contact with the third anode side organic layer;
the first anode side organic layer, the second anode side organic layer, and the third anode side organic layer are arranged in this order from a side close to the anode between the anode and the second emitting region;
the second emitting region comprises at least one emitting layer;
the at least one emitting layer of the second emitting region comprises a third emitting layer;
the third emitting layer of the second emitting region comprises a third emitting compound;
a maximum peak wavelength of the first emitting compound comprised in the first emitting layer and a maximum peak wavelength of the third emitting compound comprised in the third emitting layer are mutually the same or different; and
a refractive index NM₁ of a constituent material comprised in the first anode side organic layer and a refractive index NM₂ of a constituent material comprised in the second anode side organic layer satisfy a relationship of a numerical formula (Numerical Formula L1) below,
NM₁>NM₂ (Numerical Formula L1).

47. The organic electroluminescence display device according to claim 46, wherein a maximum peak wavelength of the first emitting compound is different from a maximum peak wavelength of the third emitting compound.

48. The organic electroluminescence display device according to claim 46, wherein a maximum peak wavelength of an emitting compound comprised in the emitting layer of the first emitting region is different from a maximum peak wavelength of an emitting compound comprised in the emitting layer of the second emitting region.

49. An organic electroluminescence display device, comprising:
an anode and a cathode arranged opposite each other; and
a first organic electroluminescence device as a first pixel and a second organic electroluminescence device as a second pixel, wherein
the first pixel comprises the organic electroluminescence device according to claim 40 as the first organic electroluminescence device;
the first organic electroluminescence device comprises a first emitting region as the emitting region, and a first hole transporting zone as the hole transporting zone provided between the first emitting region and the anode;
the first anode side organic layer, the second anode side organic layer, and the third anode side organic layer are provided in a shared manner across the second organic electroluminescence device;
the first emitting layer of the first emitting region comprises a first emitting compound;
the second organic electroluminescence device comprises a second emitting region provided between the anode and the cathode, and a second hole transporting zone provided between the second emitting region and the anode;
the second hole transporting zone comprises the first anode side organic layer, the second anode side organic layer, and the third anode side organic layer;
in the second hole transporting zone, the first anode side organic layer is in direct contact with the second anode side organic layer and the second anode side organic layer is in direct contact with the third anode side organic layer;
the first anode side organic layer, the second anode side organic layer, and the third anode side organic layer are arranged in this order from a side close to the anode between the anode and the second emitting region;
the second emitting region comprises at least one emitting layer;
the at least one emitting layer of the second emitting region comprises a third emitting layer;
the third emitting layer of the second emitting region comprises a third emitting compound;
a maximum peak wavelength of the first emitting compound comprised in the first emitting layer and a maximum peak wavelength of the third emitting compound comprised in the third emitting layer are mutually the same or different; and
a refractive index NM₁ of a constituent material comprised in the first anode side organic layer and a refractive index NM₂ of a constituent material comprised in the second anode side organic layer satisfy a relationship of a numerical formula (Numerical Formula L1) below,
NM₁>NM₂ (Numerical Formula L1).

50. The organic electroluminescence display device according to claim 49, wherein a maximum peak wavelength of the first emitting compound is different from a maximum peak wavelength of the third emitting compound.

51. The organic electroluminescence display device according to claim 49, wherein a maximum peak wavelength of an emitting compound comprised in the emitting layer of the first emitting region is different from a maximum peak wavelength of an emitting compound comprised in the emitting layer of the second emitting region.
